(19) United States
(12) Patent Application Publication
(10) Pub. No.: US 2026/0358707 A1
(43) Pub. Date: Nov. 12, 2026

(54) RESIST PATTERN FORMING PROCESS

(71) Applicant: SHIN-ETSU CHEMICAL CO., LTD., Tokyo (JP)

(72) Inventors: Shun Kikuchi, Joetsu-shi (JP); Ryo Nishikawa, Joetsu-shi (JP); Satoshi Kusama, Joetsu-shi (JP); Kousuke Ohyama, Joetsu-shi (JP); Masaki Ohashi, Joetsu-shi (JP)

(73) Assignee: SHIN-ETSU CHEMICAL CO., LTD., Tokyo (JP)

(21) Appl. No.: 19/642,958

(22) Filed: Apr. 9, 2026

(30) Foreign Application Priority Data
Apr. 21, 2025 (JP) 2025-069671

(51) Int. Cl. G03F 7/038; G03F 7/004; G03F 7/32

(52) U.S. Cl. CPC G03F 7/038; G03F 7/0045; G03F 7/325

(57) ABSTRACT

The present invention is to provide a non-chemically amplified resist composition excellent in maximum resolution when processed by photolithography using high-energy radiation, and a pattern forming process using the resist composition. The resist pattern forming process comprises the steps of: (i) applying a resist composition containing: a hypervalent iodine compound; a carboxy group-containing compound; and a solvent onto a substrate or onto an underlayer film laminated on a substrate to form a resist film, (ii) exposing the resist film to high-energy radiation, and (iii) developing the exposed resist film with a developer containing an organic acid to form a negative pattern.

### CROSS-REFERENCE TO RELATED APPLICATION

This non-provisional application claims priority under 35 U.S.C. § 119 (a) on Patent Application No. 2025-069671 filed in Japan on Apr. 21, 2025, the entire contents of which are hereby incorporated by reference.

### TECHNICAL FIELD

This invention relates to a resist pattern forming process.

### BACKGROUND ART

While a higher integration density, higher operating speed and lower power consumption of LSIs are demanded to comply with the expanding IoT market, the effort to reduce the pattern rule is in rapid progress. The wide-spreading logic device market drives forward the miniaturization technology. As the advanced miniaturization technology, microelectronic devices of 10-nm node are manufactured in a mass scale by the double, triple or quadro-patterning version of the immersion ArF lithography. Active research efforts have been made on the manufacture of 7-nm node devices by the next generation EUV lithography of wavelength 13.5 nm.

As the feature size is reduced, image blurs due to acid diffusion become a problem (see Non-Patent Document 1). To insure resolution for fine patterns with a feature size of 45 nm et seq., not only an improvement in dissolution contrast is requisite, but the control of acid diffusion is also important (see Non-Patent Document 2). Since chemically amplified resist compositions are designed such that sensitivity and contrast are enhanced by acid diffusion, an attempt to minimize acid diffusion by reducing the temperature and/or time of post-exposure bake (PEB) fails, resulting in drastic reductions of sensitivity and contrast.

Addition of an acid generator capable of generating a bulky acid is effective for suppressing acid diffusion. It is then proposed to copolymerize a polymer with an acid generator in the form of an onium salt having polymerizable olefin. With respect to the patterning of a resist film to a feature size of 16 nm et seq., it is believed impossible in the light of acid diffusion to form such a pattern from a chemically amplified resist composition. It would be desirable to have a non-chemically amplified resist composition.

A typical non-chemically amplified resist material is polymethyl methacrylate (PMMA). It is a positive resist material which increases solubility in organic solvent developer through the mechanism that the molecular weight becomes lower as a result of scission of the main chain upon EUV exposure.

Hydrogensilsesquioxane (HSQ) is a negative resist material which turns insoluble in alkaline developer through crosslinking by condensation reaction of silanol generated upon EUV exposure. Also chlorine-substituted calixarene functions as negative resist material. Since these negative resist materials have a small molecular size prior to crosslinking and avoid any blur caused by acid diffusion, they exhibit reduced edge roughness and very high resolution. They are thus used as a pattern transfer material for representing the resolution limit of the exposure tool. However, these materials are insufficient in sensitivity, with further improvements being needed.

One of the causes that retard the development of EUV lithography materials is a small number of photons available with EUV exposure. The energy of EUV is extremely higher than that of ArF excimer laser. The number of photons available with EUV exposure is 1/14 of the number by ArF exposure. The size of pattern features formed by the EUV lithography is less than half the size by the ArF lithography. Therefore, the EUV lithography is quite sensitive to a variation of photon number. A variation in number of photons in the radiation region of extremely short wavelength is shot noise as a physical phenomenon. It is impossible to eliminate the influence of shot noise. Attention is thus paid to stochastics. While it is impossible to eliminate the influence of shot noise, discussions are held how to reduce the influence. There is observed a phenomenon that under the influence of shot noise, values of CDU and LWR are increased and holes are blocked at a probability of one several millionth. The blockage of holes leads to electric conduction failure to prevent transistors from operation, adversely affecting the performance of an overall device. In view of practically acceptable sensitivity, resist compositions based on PMMA or HSQ are largely affected by stochastics, failing to gain the desired resolution.

As the means for reducing the influence of shot noise on the resist side, it is noteworthy to incorporate an element having high EUV absorption. Patent Document 1 discloses a chemically amplified resist composition containing highly EUV-absorbing iodine atoms. However, as mentioned above, the chemically amplified resist composition cannot reach the resolution desired in the EUV lithography where the pattern feature size becomes smaller than ever. In particular, the line-and-space pattern has remarkably increased pattern collapse and disconnection as the pattern size is reduced. Therefore, reducing them leads to improvement in maximum resolution.

Patent Document 2 discloses a negative resist composition comprising a tin compound. Based on tin element having high EUV absorption, this resist composition is improved in stochastics, and high sensitivity and high resolution can be realized. Such so-called metal resist compositions, however, suffer from many problems including insufficient solubility to a resist solvent, poor shelf stability, and defectiveness due to post-etching residues. Further, the metal resist compositions are of negative tone wherein the exposed region becomes a metal oxide which is insoluble in the developer. In their application to the patterning of contact holes, an additional reversal step is necessary, leaving an economical concern.

### CITATION LIST

Patent Document 1: JP-A 2018-5224
Patent Document 2: JP-A 2021-503482
Non-Patent Document 1: SPIE Vol. 5039 p1 (2003)
Non-Patent Document 2: SPIE Vol. 6520 p65203L-1 (2007)

### SUMMARY OF THE INVENTION

The present invention has been made in view of the above circumstances, and an object of the invention is to provide a non-chemically amplified resist composition excellent in maximum resolution when processed by photolithography using high-energy radiation, typically EB and EUV lithography, and a pattern forming process using the resist composition.

As a result of intensive studies to achieve the above object, the inventors have found that a resist composition based on a predetermined hypervalent iodine compound and a carboxy group-containing compound (polymer or monomolecular compound) forms a resist film having a satisfactory resolution, and is quite useful in precise micropatterning when an organic acid is used as a developer. Thereby, the present invention has been achieved.

That is, the present invention provides the following resist pattern forming process.
1. A resist pattern forming process comprising the steps of:
   (i) applying a resist composition containing: a hypervalent iodine compound; a carboxy group-containing compound; and a solvent onto a substrate or onto an underlayer film laminated on a substrate to form a resist film,
   (ii) exposing the resist film to high-energy radiation, and
   (iii) developing the exposed resist film with a developer containing an organic acid to form a negative pattern.
2. The resist pattern forming process of 1 wherein the hypervalent iodine compound contains at least one selected from the compounds having any of the formulae (1) to (16):

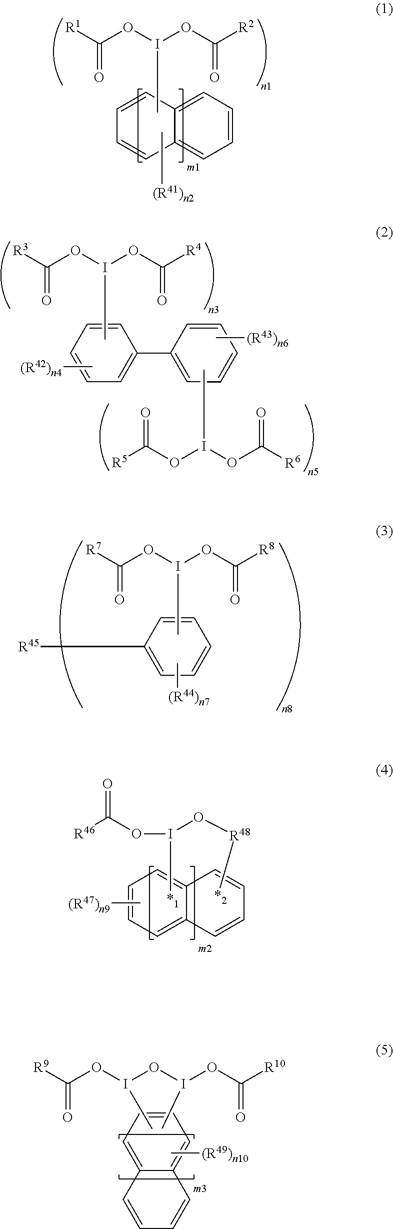

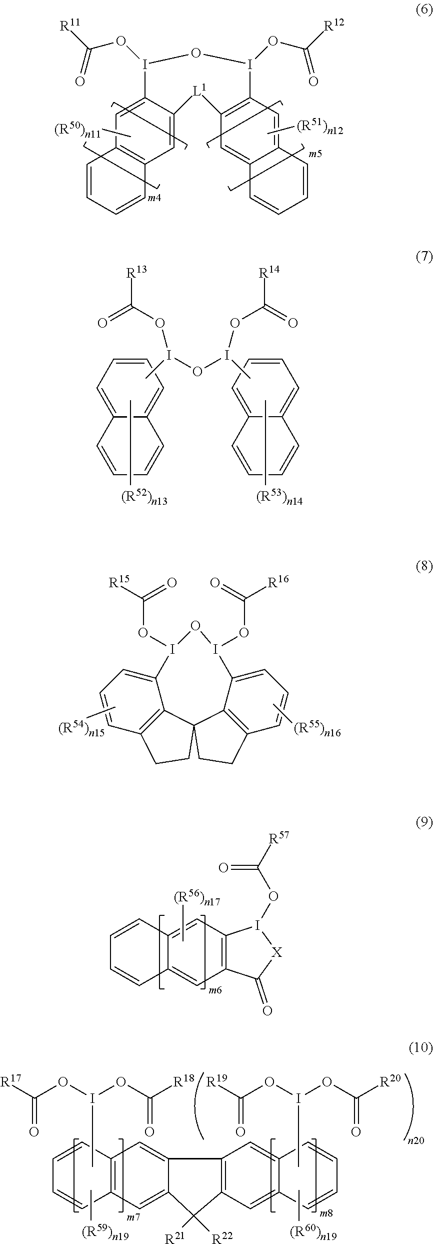

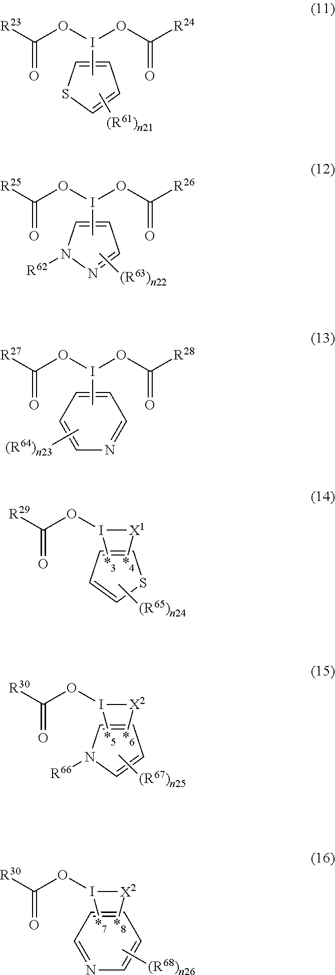

wherein
   m1 is 0, 1, or 2; when m1 is 0, n1 is 1, 2, or 3, n2 is 0, 1, 2, 3, 4, or 5, and 1≤n1+n2≤6; when m1 is 1, n1 is 1, 2, or 3, n2 is 0, 1, 2, 3, 4, 5, 6, or 7, and 1≤n1+n2≤8; when m1 is 2, n1 is 1, 2, or 3, n2 is 0, 1, 2, 3, 4, 5, 6, 7, 8, or 9, and 1≤n1+n2≤10;
   n3 is 1 or 2, n4 is 0, 1, 2, 3, or 4, and 1≤n3+n4≤5; n5 is 1 or 2, n6 is 0, 1, 2, 3, or 4, and 1≤n5+n6≤5;
   n7 is 0, 1, 2, 3, or 4, and n8 is 1, 2, 3, or 4;
   m2 is 0, 1, or 2; when m2 is 0, n9 is 0, 1, 2, 3, or 4; when m2 is 1, n9 is 0, 1, 2, 3, 4, 5, or 6; when m2 is 2, n9 is 0, 1, 2, 3, 4, 5, 6, 7, or 8;
   m3 is 0, 1, or 2; when m3 is 0, n10 is 0, 1, 2, 3, or 4; when m3 is 1, n10 is 0, 1, 2, 3, 4, 5, or 6; when m3 is 2, n10 is 0, 1, 2, 3, 4, 5, 6, 7, or 8;
   m4 is 0 or 1; when m4 is 0, n11 is 0, 1, 2, 3, or 4; when m4 is 1, n11 is 0, 1, 2, 3, 4, 5, or 6;
   m5 is 0 or 1; when m5 is 0, n12 is 0, 1, 2, 3, or 4; when m5 is 1, n12 is 0, 1, 2, 3, 4, 5, or 6;
   n13 and n14 are each independently 0, 1, 2, 3, 4, 5, or 6;
   n15 and n16 are each independently 0, 1, 2, or 3;
   m6 is 0, 1, or 2; when m6 is 0, n17 is 0, 1, 2, 3, or 4; when m6 is 1, n17 is 0, 1, 2, 3, 4, 5, or 6; when m6 is 2, n17 is 0, 1, 2, 3, 4, 5, 6, 7, or 8;
   m7 is 0, 1, or 2; when m7 is 0, n18 is 0, 1, 2, or 3; when m7 is 1, n18 is 0, 1, 2, 3, 4, or 5; when m7 is 2, n18 is 0, 1, 2, 3, 4, 5, 6, or 7;
   m8 is 0, 1, or 2; when m8 is 0, n19 is 0, 1, 2, or 3, and n20 is 0 or 1; when m8 is 1, n19 is 0, 1, 2, 3, 4, or 5, and n20 is 0 or 1; when m8 is 2, n19 is 0, 1, 2, 3, 4, 5, 6, or 7, and n20 is 0 or 1;
   n21 is 0, 1, 2, or 3, n22 is 0, 1, or 2, n23 is 0, 1, 2, 3, or 4, n24 is 0, 1, or 2, n25 is 0 or 1, and n26 is 0, 1, 2, or 3;
   R¹ to R³¹ are each independently a halogen atom or a C₁-C₁₀ hydrocarbyl group which may contain a heteroatom, and R²¹ and R²² may bond together to form a ring with the carbon atoms to which they are attached;
   R⁴¹ to R⁴⁴, R⁴⁷, R⁴⁹ to R⁵⁶, R⁵⁹, R⁶⁰, and R⁶¹ to R⁶⁸ are each independently a halogen atom or a C₁-C₄₀ hydrocarbyl group which may contain a heteroatom; when n2 is 2 or more, each R⁴¹ may be the same or different from each other, and a plurality of R⁴¹s may bond to each other to form a ring with the carbon atoms of the aromatic ring to which they are attached; when n4 is 2 or more, each R⁴² may be the same or different from each other, and a plurality of R⁴²s may bond to each other to form a ring with the carbon atoms of the aromatic ring to which they are attached; when n6 is 2 or more, each R⁴³ may be the same or different from each other, and a plurality of R⁴³s may bond to each other to form a ring with the carbon atoms of the aromatic ring to which they are attached; when n7 is 2 or more, each R⁴⁴ may be the same or different from each other, and a plurality of R⁴⁴s may bond to each other to form a ring with the carbon atoms of the aromatic ring to which they are attached; when n9 is 2 or more, each R⁴⁷ may be the same or different from each other, and a plurality of R⁴⁷s may bond to each other to form a ring with the carbon atoms of the aromatic ring to which they are attached; when n10 is 2 or more, each R⁴⁹ may be the same or different from each other, and a plurality of R⁴⁹s may bond to each other to form a ring with the carbon atoms of the aromatic ring to which they are attached; when n11 is 2 or more, each R⁵⁰ may be the same or different from each other, and a plurality of R⁵⁰s may bond to each other to form a ring with the carbon atoms of the aromatic ring to which they are attached; when n12 is 2 or more, each R⁵¹ may be the same or different from each other, and a plurality of R⁵¹s may bond to each other to form a ring with the carbon atoms of the aromatic ring to which they are attached; when n13 is 2 or more, each R⁵² may be the same or different from each other, and a plurality of R⁵²s may bond to each other to form a ring with the carbon atoms of the aromatic ring to which they are attached; when n14 is 2 or more, each R⁵³ may be the same or different from each other, and a plurality of R⁵³s may bond to each other to form a ring with the carbon atoms of the aromatic ring to which they are attached; when n15 is 2 or more, each R⁵⁴ may be the same or different from each other, and a plurality of R⁵⁴s may bond to each other to form a ring with the carbon atoms of the aromatic ring to which they are attached; when n16 is 2 or more, each R⁵⁵ may be the same or different from each other, and a plurality of R⁵⁵s may bond to each other to form a ring with the carbon atoms of the aromatic ring to which they are attached; when n17 is 2 or more, each R⁵⁶ may be the same or different from each other, and a plurality of R⁵⁶s may bond to each other to form a ring with the carbon atoms of the aromatic ring to which they are attached; when n18 is 2 or more, each R⁵⁹ may be the same or different from each other, and a plurality of R⁵⁹s may bond to each other to form a ring with the carbon atoms of the aromatic ring to which they are attached; when n19 is 2 or more, each R⁶⁰ may be the same or different from each other, and a plurality of R⁶⁰s may bond to each other to form a ring with the carbon atoms of the aromatic ring to which they are attached; when n21 is 2 or more, each R⁶¹ may be the same or different from each other, and a plurality of R⁶¹s may bond to each other to form a ring with the carbon atoms of the aromatic ring to which they are attached; when n22 is 2 or more, each R⁶³ may be the same or different from each other, and a plurality of R⁶³s may bond to each other to form a ring with the carbon atoms of the aromatic ring to which they are attached; when n23 is 2 or more, each R⁶⁴ may be the same or different from each other, and a plurality of R⁶⁴s may bond to each other to form a ring with the carbon atoms of the aromatic ring to which they are attached; when n24 is 2 or more, each R⁶⁵ may be the same or different from each other, and a plurality of R⁶⁵s may bond to each other to form a ring with the carbon atoms of the aromatic ring to which they are attached; and when n26 is 2 or more, each R⁶⁸ may be the same or different from each other, and a plurality of R⁶⁸s may bond to each other to form a ring with the carbon atoms of the aromatic ring to which they are attached;
   when n8 is 1, 3, or 4, R⁴⁵ is a C₁-C₄₀ (n8)-valent hydrocarbon group or a C₂— C₄₀ (n8)-valent heterocyclic group; when n8 is 2, R⁴⁵ is an ether bond, a carbonyl group, an azo group, a thioether bond, a carbonate bond, a carbamate bond, a sulfinyl group, a sulfonyl group, a thioketone bond, C₁-C₄₀ (n8)-valent hydrocarbon group, or a C₂— C₄₀ (n8)-valent heterocyclic group; and some or all of the hydrogen atoms of the (n8)-valent hydrocarbon group or the (n8)-valent heterocyclic group may be substituted with a heteroatom-containing moiety, some of —CH₂— of the (n8)-valent hydrocarbon group may be substituted with a heteroatom-containing moiety, and R⁴⁴ and R⁴⁵ may bond together to form a ring with the carbon atoms to which they are attached and the intervenient atoms; R⁴⁸ is a carbonyl group or a C₁-C₁₀ hydrocarbylene group which may contain a heteroatom;
   R⁵⁶ is a halogen atom or a C₁-C₁₀ hydrocarbyl group which may contain a heteroatom;
   R⁵⁷ is a halogen atom or a C₁-C₁₀ hydrocarbyl group which may contain a heteroatom;
   *1, *2, *3, *4, *5, *6, *7, and *8 each designate a point of attachment to a carbon atom or a heteroatom on the aromatic ring or the hetero ring in the formulae; provided that *1 and *2, *3 and *4, *5 and *6, and *7 and *8 each are bonded to adjacent atoms of the aromatic ring or adjacent atoms of the hetero ring;
   L¹ is no bond, a single bond, —O—, —S—, —NH—, or —CH₂—;
   X is —S— or —N(R⁵⁸)—; R⁵⁸ is a hydrogen atom, a halogen atom, or a C₁-C₂₀ hydrocarbyl group which may contain a heteroatom; and
   X¹ and X² are each independently *—O—X¹¹— or *—X¹²—C(═O)—; X³ is *—O—X¹¹—, *—S—X¹¹—, or *—X¹²—C(═O)—; X¹¹ is a carbonyl group or a C₁-C₁₀ hydrocarbylene group which may contain a heteroatom; X¹² is —S— or —N(R⁶⁹)—; and R⁶⁹ is a hydrogen atom, a halogen atom, or a C₁-C₂₀ hydrocarbyl group which may contain a heteroatom.
3. The resist pattern forming process of 1 or 2 wherein the carboxy group-containing compound is a carboxy group-containing polymer containing a repeat unit having the formula (a-1) or a carboxylic acid having the formula (a-2):

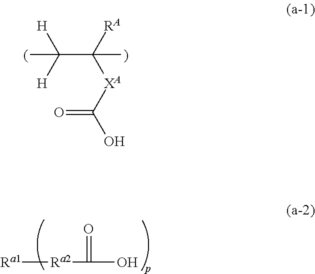

wherein
   R^{A} is a hydrogen atom, a halogen atom, a methyl group, or a trifluoromethyl group, X^{A} is a single bond, a phenylene group, a naphthylene group, or *—C(═O)—O—X^{A1}— wherein X^{A1} is a C₁-C₁₀ saturated hydrocarbylene group, a phenylene group, or a naphthylene group, the saturated hydrocarbylene group may contain a hydroxy group, an ether bond, an ester bond, or a lactone ring, and * designates a valence bond to a carbon atom in a main chain; wherein
   p is 1, 2, 3, or 4;
   when p is 1, 3, or 4, R^{a1} is a C₁-C₄₀ p-valent hydrocarbon group or a C₂— C₄₀ p-valent heterocyclic group; when p is 2, R^{a1} is an ether bond, a carbonyl group, an azo group, a thioether bond, a carbonate bond, a carbamate bond, a sulfinyl group, a sulfonyl group, a C₁-C₄₀ p-valent hydrocarbon group, or a C₂— C₄₀ p-valent heterocyclic group; and some or all of the hydrogen atoms in the p-valent hydrocarbon group or the p-valent heterocyclic group may be substituted by a heteroatom-containing moiety, and some constituent —CH₂— in the p-valent hydrocarbon group may be replaced by a heteroatom-containing moiety; and
   R^{a2} is a single bond or a C₁-C₂₀ hydrocarbylene group, and some or all of the hydrogen atoms in the hydrocarbylene group may be substituted by a heteroatom-containing moiety, and some constituent —CH₂— in the hydrocarbylene group may be replaced by a heteroatom-containing moiety, and when p is 2, 3, or 4, each R^{a2} may be the same or different from each other.
4. The resist pattern forming process of any one of 1 to 3 wherein the organic acid contains at least one selected from the compounds having any of the formulae (b-1) to (b-7):

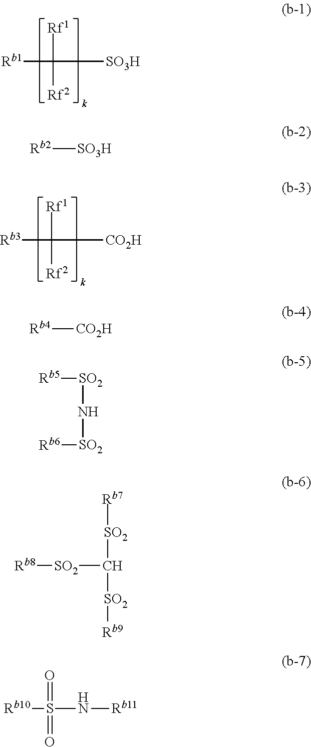

wherein
   k is 1, 2, 3, or 4;
   Rf¹ and Rf² are each independently a hydrogen atom, a fluorine atom, or a C₁-C₆ fluorine-containing alkyl group, excluding a case where all of Rf¹s and Rf²s are hydrogen atoms at the same time;
   R^{b1} is a hydrogen atom, a halogen atom, a hydroxy group, or a C₁-C₅₀ hydrocarbyl group which may contain a heteroatom;
   R^{b2} is a hydrogen atom, a halogen atom, a hydroxy group, or a C₁-C₅₀ hydrocarbyl group which may contain a heteroatom, excluding a case where hydrogen atoms on the carbon atoms at the α-position and the β-position of the sulfo group are substituted with a fluorine atom or a fluoroalkyl group;
   R^{b3} is a hydrogen atom, a halogen atom, a hydroxy group, or a C₁-C₅₀ hydrocarbyl group which may contain a heteroatom;
   R^{b4} is a hydrogen atom, a halogen atom, a hydroxy group, or a C₁-C₅₀ hydrocarbyl group which may contain a heteroatom, excluding a case where hydrogen atoms on the carbon atoms at the α-position and the β-position of the carboxy group are substituted with a fluorine atom or a fluoroalkyl group;
   R^{b5} and R^{b6} are each independently a C₁-C₅₀ hydrocarbyl group which may contain a heteroatom;
   R^{b7} to R^{b9} are each independently a C₁-C₅₀ hydrocarbyl group which may contain a heteroatom;
   R^{b10} is a fluorine atom or a C₁-C₁₀ fluorinated hydrocarbyl group, and the fluorinated hydrocarbyl group may contain a hydroxy group, an ether bond, or an ester bond; R^{b11} is a hydrogen atom or a C₁-C₂₀ hydrocarbyl group, and the hydrocarbyl group may contain a hydroxy group, an ether bond, or an ester bond; and R^{b10} and Roll may bond to each other to form a ring with the atoms to which they are attached.
5. The resist pattern forming process of any one of 1 to 4 wherein the high-energy radiation is i-ray, KrF excimer laser beam, ArF excimer laser beam, electron beam, or extreme ultraviolet ray.

### Advantageous Effects of the Invention

The resist composition exhibits both high sensitivity and resolution when processed by lithography with i-ray, KrF and ArF excimer laser beam, EB, or EUV, and is quite useful in micropatterning.

### DESCRIPTION OF THE PREFERRED EMBODIMENT

### [Resist Composition]

The resist composition used in the inventive resist pattern forming process contains a predetermined hypervalent iodine compound; a carboxy group-containing compound; and a solvent.

### [Hypervalent Iodine Compound]

As the hypervalent iodine compound, it is preferable to use at least one selected from the hypervalent iodine compounds having any of the formulae (1) to (16).

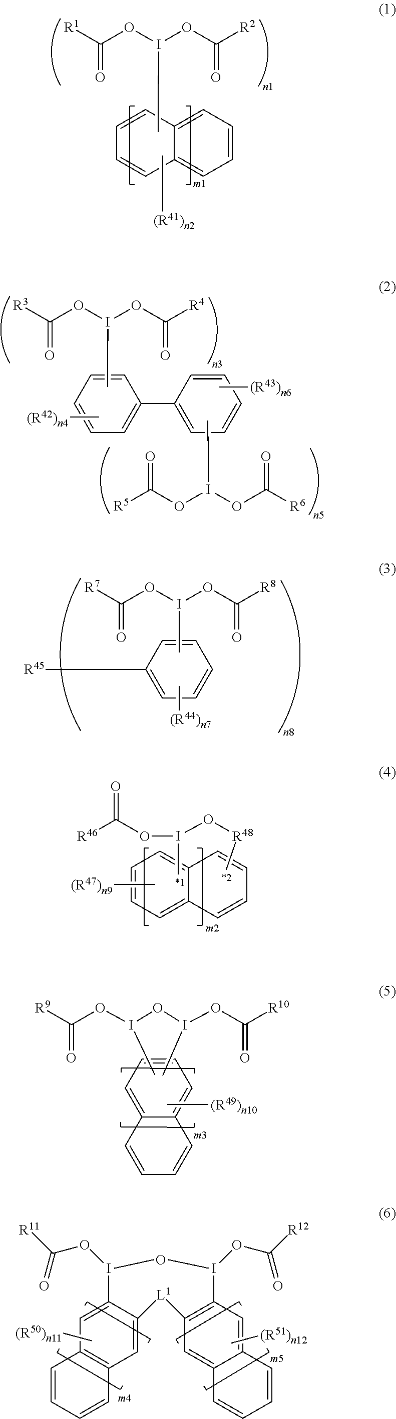

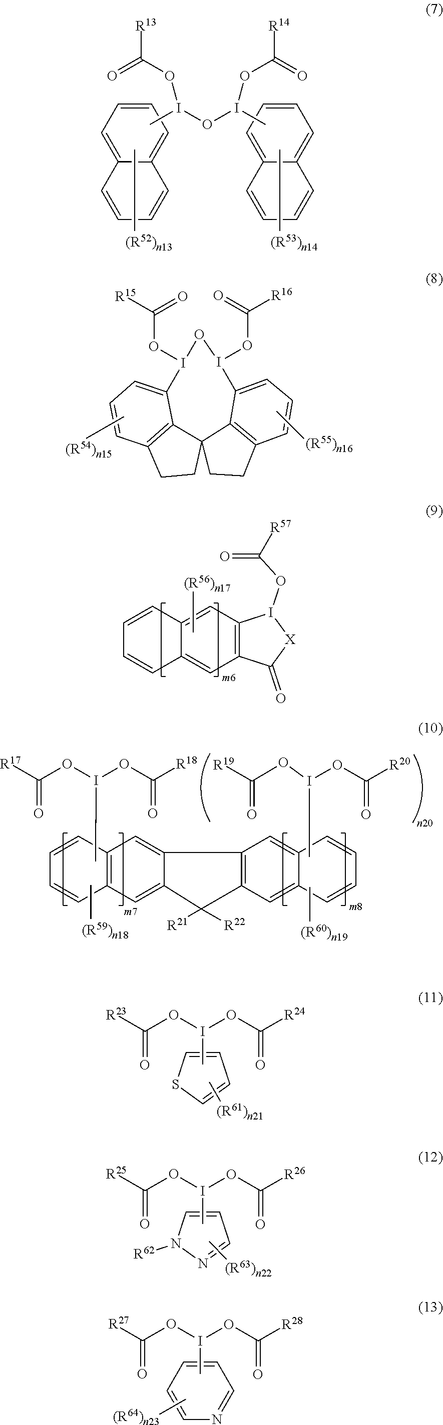

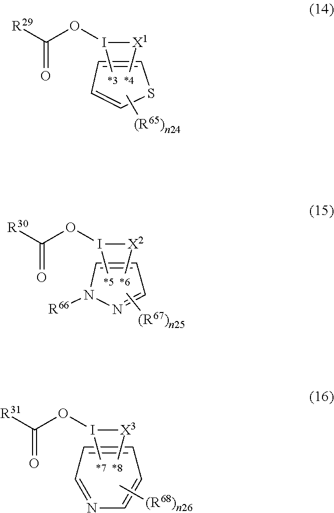

In the formula (1), m1 is 0, 1, or 2. When m1 is 0, n1 is 1, 2, or 3, n2 is 0, 1, 2, 3, 4, or 5, and 1≤n1+n2≤6. When m1 is 1, n1 is 1, 2, or 3, n2 is 0, 1, 2, 3, 4, 5, 6, or 7, and 1≤n1+n2≤8. When m1 is 2, n1 is 1, 2, or 3, n2 is 0, 1, 2, 3, 4, 5, 6, 7, 8, or 9, and 1≤n1+n2≤10.

In the formula (2), n3 is 1 or 2, n4 is 0, 1, 2, 3, or 4, and 1≤n3+n4≤5; n5 is 1 or 2, n6 is 0, 1, 2, 3, or 4, and 1≤n5+n6≤5.

In the formula (3), n7 is 0, 1, 2, 3, or 4, and n8 is 1, 2, 3, or 4.

In the formula (4), m2 is 0, 1, or 2. When m2 is 0, n9 is 0, 1, 2, 3, or 4; when m2 is 1, n9 is 0, 1, 2, 3, 4, 5, or 6; when m2 is 2, n9 is 0, 1, 2, 3, 4, 5, 6, 7, or 8.

In the formula (5), m3 is 0, 1, or 2. When m3 is 0, n10 is 0, 1, 2, 3, or 4; when m3 is 1, n10 is 0, 1, 2, 3, 4, 5, or 6; when m3 is 2, n10 is 0, 1, 2, 3, 4, 5, 6, 7, or 8.

In the formula (6), m4 is 0 or 1. When m4 is 0, n11 is 0, 1, 2, 3, or 4; when m4 is 1, n11 is 0, 1, 2, 3, 4, 5, or 6.

In the formula (6), m5 is 0 or 1. When m5 is 0, n12 is 0, 1, 2, 3, or 4; when m5 is 1, n12 is 0, 1, 2, 3, 4, 5, or 6.

In the formula (7), n13 and n14 are each 0, 1, 2, 3, 4, 5, or 6.

In the formula (8), n15 and n16 are each 0, 1, 2, or 3.

In the formula (9), m6 is 0, 1, or 2. When m6 is 0, n17 is 0, 1, 2, 3, or 4; when m6 is 1, n17 is 0, 1, 2, 3, 4, 5, or 6; when m6 is 2, n17 is 0, 1, 2, 3, 4, 5, 6, 7, or 8.

In the formula (10), m7 is 0, 1, or 2. When m7 is 0, n18 is 0, 1, 2, or 3; when m7 is 1, n18 is 0, 1, 2, 3, 4, or 5; when m7 is 2, n18 is 0, 1, 2, 3, 4, 5, 6, or 7.

In the formula (10), m8 is 0, 1, or 2. When m8 is 0, n19 is 0, 1, 2, or 3, and n20 is 0 or 1; when m8 is 1, n19 is 0, 1, 2, 3, 4, or 5, and n20 is 0 or 1; when m8 is 2, n19 is 0, 1, 2, 3, 4, 5, 6, or 7, and n20 is 0 or 1.

In the formula (11), n21 is 0, 1, 2, or 3. In the formula (12), n22 is 0, 1, or 2. In the formula (13), n23 is 0, 1, 2, 3, or 4. In the formula (14), n24 is 0, 1, or 2. In the formula (15), n25 is 0 or 1. In the formula (16), n26 is 0, 1, 2, or 3.

In the formulae (1) to (16), R¹ to R³¹ are each independently a halogen atom or a C₁-C₁₀ hydrocarbyl group which may contain a heteroatom. R²¹ and R²² may bond together to form a ring with the carbon atoms to which they are attached.

Suitable halogen atoms of R¹ to R³¹ include fluorine, chlorine, bromine and iodine. The C₁-C₁₀ hydrocarbyl group of R¹ to R³¹ may be saturated or unsaturated and straight, branched or cyclic. Examples thereof include C₁-C₁₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₁₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}] decyl, and adamantyl, alkenyl groups such as vinyl and allyl, C₆-C₁₀ aryl groups such as phenyl and naphthyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—). R¹ to R³¹ are preferably C₁-C₄ hydrocarbyl groups.

In the formulae (1) to (16), R⁴¹ to R⁴⁴, R⁴⁷, R⁴⁹ to R⁵⁶, R⁵⁹, R⁶⁰, and R⁶¹ to R⁶⁸ are each independently a halogen atom or a C₁-C₄₀ hydrocarbyl group which may contain a heteroatom. When n2 is 2 or more, each R⁴¹ may be the same or different from each other, and a plurality of R⁴¹s may bond to each other to form a ring with the carbon atoms of the aromatic ring to which they are attached. When n4 is 2 or more, each R⁴² may be the same or different from each other, and a plurality of R⁴²s may bond to each other to form a ring with the carbon atoms of the aromatic ring to which they are attached. When n6 is 2 or more, each R⁴³ may be the same or different from each other, and a plurality of R⁴³s may bond to each other to form a ring with the carbon atoms of the aromatic ring to which they are attached. When n7 is 2 or more, each R⁴⁴ may be the same or different from each other, and a plurality of R⁴⁴s may bond to each other to form a ring with the carbon atoms of the aromatic ring to which they are attached. When n9 is 2 or more, each R⁴⁷ may be the same or different from each other, and a plurality of R⁴⁷s may bond to each other to form a ring with the carbon atoms of the aromatic ring to which they are attached. When n10 is 2 or more, each R⁴⁹ may be the same or different from each other, and a plurality of R⁴⁹s may bond to each other to form a ring with the carbon atoms of the aromatic ring to which they are attached. When n11 is 2 or more, each R⁵⁰ may be the same or different from each other, and a plurality of R⁵⁰s may bond to each other to form a ring with the carbon atoms of the aromatic ring to which they are attached. When n12 is 2 or more, each R⁵¹ may be the same or different from each other, and a plurality of R⁵¹s may bond to each other to form a ring with the carbon atoms of the aromatic ring to which they are attached. When n13 is 2 or more, each R⁵² may be the same or different from each other, and a plurality of R⁵²s may bond to each other to form a ring with the carbon atoms of the aromatic ring to which they are attached. When n14 is 2 or more, each R⁵³ may be the same or different from each other, and a plurality of R⁵³s may bond to each other to form a ring with the carbon atoms of the aromatic ring to which they are attached. When n15 is 2 or more, each R⁵⁴ may be the same or different from each other, and a plurality of R⁵⁴s may bond to each other to form a ring with the carbon atoms of the aromatic ring to which they are attached. When n16 is 2 or more, each R⁵⁵ may be the same or different from each other, and a plurality of R⁵⁵s may bond to each other to form a ring with the carbon atoms of the aromatic ring to which they are attached. When n17 is 2 or more, each R⁵⁶ may be the same or different from each other, and a plurality of R⁵⁶s may bond to each other to form a ring with the carbon atoms of the aromatic ring to which they are attached. When n18 is 2 or more, each R⁵⁹ may be the same or different from each other, and a plurality of R⁵⁹s may bond to each other to form a ring with the carbon atoms of the aromatic ring to which they are attached. When n19 is 2 or more, each R⁶⁰ may be the same or different from each other, and a plurality of R⁶⁰s may bond to each other to form a ring with the carbon atoms of the aromatic ring to which they are attached. When n21 is 2 or more, each R⁶¹ may be the same or different from each other, and a plurality of R⁶¹s may bond to each other to form a ring with the carbon atoms of the aromatic ring to which they are attached. When n22 is 2 or more, each R⁶³ may be the same or different from each other, and a plurality of R⁶³s may bond to each other to form a ring with the carbon atoms of the aromatic ring to which they are attached. When n23 is 2 or more, each R⁶⁴ may be the same or different from each other, and a plurality of R⁶⁴s may bond to each other to form a ring with the carbon atoms of the aromatic ring to which they are attached. When n24 is 2 or more, each R⁶⁵ may be the same or different from each other, and a plurality of R⁶⁵s may bond to each other to form a ring with the carbon atoms of the aromatic ring to which they are attached. When n26 is 2 or more, each R⁶⁸ may be the same or different from each other, and a plurality of R⁶⁸s may bond to each other to form a ring with the carbon atoms of the aromatic ring to which they are attached.

Suitable halogen atoms of R⁴¹ to R⁴⁴, R⁴⁷, R⁴⁹ to R⁵⁶, R⁵⁹, R⁶⁰, and R⁶¹ to R⁶⁸ include fluorine, chlorine, bromine and iodine. The C₁-C₄₀ hydrocarbyl group of R⁴¹ to R⁴⁴, R⁴⁷, R⁴⁹ to R⁵⁶, R⁵⁹, R⁶⁰, and R⁶¹ to R⁶⁸ may be saturated or unsaturated and straight, branched or cyclic. Examples thereof include C₁-C₄₀ alkyl groups such as methyl, ethyl, propyl, isopropyl, n-butyl, isobutyl, sec-butyl, tert-butyl, n-pentyl, tert-pentyl, n-hexyl, n-octyl, 2-ethylhexyl, n-nonyl, and n-decyl, C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}] decyl, adamantyl, and adamantylmethyl, and C₆-C₄₀ aryl groups such as phenyl, naphthyl, and anthracenyl. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, amide bond, lactone ring, sultone ring, or carboxylic anhydride (—C(═O)—O—C(═O)—).

In the formula (3), when n8 is 1, 3, or 4, R⁴⁵ is a C₁-C₄₀ (n8)-valent hydrocarbon group or a C₂— C₄₀ (n8)-valent heterocyclic group; when n8 is 2, R⁴⁵ is an ether bond, a carbonyl group, an azo group, a thioether bond, a carbonate bond, a carbamate bond, a sulfinyl group, a sulfonyl group, a thioketone bond, C₁-C₄₀ (n8)-valent hydrocarbon group, or a C₂— C₄₀ (n8)-valent heterocyclic group. Some or all of the hydrogen atoms of the (n8)-valent hydrocarbon group or the (n8)-valent heterocyclic group may be substituted with a heteroatom-containing moiety, some of —CH₂— of the (n8)-valent hydrocarbon group may be substituted with a heteroatom-containing moiety, and R⁴⁴ and R⁴⁵ may bond together to form a ring with the carbon atoms to which they are attached and the intervenient atoms.

The (n8)-valent hydrocarbon group of R⁴⁵ may be saturated or unsaturated and straight, branched or cyclic. The (n8)-valent hydrocarbon group is obtained by removing (n8) number of hydrogen atoms from a hydrocarbon. Suitable hydrocarbons include C₁-C₄₀ alkanes, C₂— C₄₀ alkenes, C₂— C₄₀ alkynes, C₃-C₄₀ cyclic saturated hydrocarbons, C₃-C₄₀ cyclic unsaturated hydrocarbons, and C₆-C₄₀ aromatic hydrocarbons.

Exemplary C₁-C₄₀ alkanes include methane, ethane, propane, butane, pentane, hexane, heptane, octane, nonane, decane, and structural isomers thereof.

Exemplary C₂— C₄₀ alkenes include ethylene, propylene, butene, pentene, hexene, heptene, octene, nonene, decene, and structural isomers thereof.

Exemplary C₂— C₄₀ alkynes include acetylene, propyne, butyne, pentyne, hexyne, heptyne, octyne, nonyne, decyne, and structural isomers thereof.

Exemplary C₃-C₄₀ cyclic saturated hydrocarbons include cyclopropane, cyclobutane, cyclohexane, cycloheptane, cyclooctane, adamantane, and norbornane.

Exemplary C₃-C₄₀ cyclic unsaturated hydrocarbons include cyclopropene, cyclobutene, cyclopentene, cyclohexene, cycloheptene, cyclooctene, and norbornene.

Exemplary C₆-C₄₀ aromatic hydrocarbons include benzene, naphthalene, and biphenyl.

The (n8)-valent heterocyclic group of R⁴⁵ is obtained by removing (n8) number of hydrogen atoms from a heterocyclic compound. Suitable heterocyclic compounds include furan, pyridine, pyrazole, and thiazolidine.

In the (n8)-valent hydrocarbon group and (n8)-valent heterocyclic group of R⁴⁵, some or all of the hydrogen atoms may be substituted by a moiety containing a heteroatom such as oxygen, sulfur, nitrogen or halogen, so that the group may contain hydroxy, cyano, fluorine, chlorine, bromine, or iodine. In the (n8)-valent hydrocarbon group, some constituent —CH₂— may be replaced by a moiety containing a heteroatom such as oxygen, sulfur or nitrogen, so that the group may contain carbonyl, ether bond, thioether bond, ester bond, sulfonic ester bond, carbonate bond, carbamate bond, amide bond, lactone ring, sultone ring, or carboxylic anhydride (—C(═O)—O—C(═O)—).

In the formula (4), R⁴⁸ is a carbonyl group or a C₁-C₁₀ hydrocarbylene group which may contain a heteroatom. The hydrocarbylene group may be saturated or unsaturated and straight, branched or cyclic. Examples of the hydrocarbylene group of R⁴⁸ are the same as the C₁-C₁₀ hydrocarbylene groups among those that will be exemplified later for the hydrocarbylene group of R^{a2} in the formula (a-2).

In the formula (9), R⁵⁶ is a halogen atom or a C₁-C₁₀ hydrocarbyl group which may contain a heteroatom. The hydrocarbyl group may be saturated or unsaturated and straight, branched or cyclic. Examples of the halogen atom and hydrocarbyl group of R⁵⁶ are the same as exemplified above for the halogen atom and hydrocarbyl group of R¹ to R³¹.

In the formula (9), R⁵⁷ is a halogen atom or a C₁-C₁₀ hydrocarbyl group which may contain a heteroatom. The hydrocarbyl group may be saturated or unsaturated and straight, branched or cyclic. Examples of the halogen atom and hydrocarbyl group of R⁵⁷ are the same as exemplified above for the halogen atom and hydrocarbyl group of R¹ to R³¹.

In the formulae (5) and (14) to (16), *1, *2, *3, *4, *5, *6, *7, and *8 each designate a point of attachment to a carbon atom or a heteroatom on the aromatic ring or the hetero ring in the formulae, provided that *1 and *2, *3 and *4, *5 and *6, and *7 and *8 each are bonded to adjacent atoms of the aromatic ring or adjacent atoms of the hetero ring.

In the formula (6), L¹ is no bond, a single bond, —O—, —S—, —NH—, or —CH₂—.

In the formula (9), X is —S— or —N(R⁵⁸)—. R⁵⁸ is a hydrogen atom, a halogen atom, or a C₁-C₂₀ hydrocarbyl group which may contain a heteroatom. The hydrocarbyl group may be saturated or unsaturated and straight, branched or cyclic. Examples of the halogen atom and hydrocarbyl group of R⁵⁸ are the same as exemplified above for the halogen atom and hydrocarbyl group of R¹ to R³¹

X¹ and X² are each independently *—O—X¹¹— or *—X¹²—C(═O)—. X³ is *—O—X¹¹—, *—S—X¹¹—, or *—X¹²—C(═O)—. X¹¹ is a carbonyl group or a C₁-C₁₀ hydrocarbylene group which may contain a heteroatom. The hydrocarbylene group may be saturated or unsaturated and straight, branched or cyclic. Examples of the hydrocarbylene group of X¹¹ are the same as the C₁-C₁₀ hydrocarbylene groups among those that will be exemplified later for the hydrocarbylene group of R^{a2} in the formula (a-2). X¹² is —S— or —N(R⁶⁹)—. R⁶⁹ is a hydrogen atom, a halogen atom, or a C₁-C₂₀ hydrocarbyl group which may contain a heteroatom. The hydrocarbyl group may be saturated or unsaturated and straight, branched or cyclic. Examples of the halogen atom and hydrocarbyl group of R⁶⁹ are the same as exemplified above for the halogen atom and hydrocarbyl group of R¹ to R³¹

Examples of the hypervalent iodine compound having the formula (1) are shown

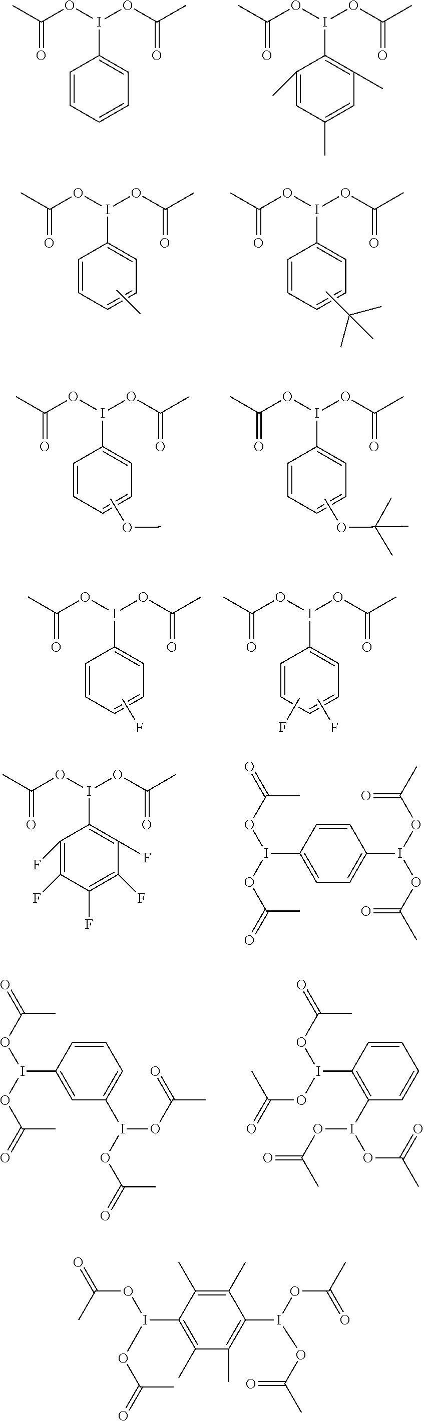

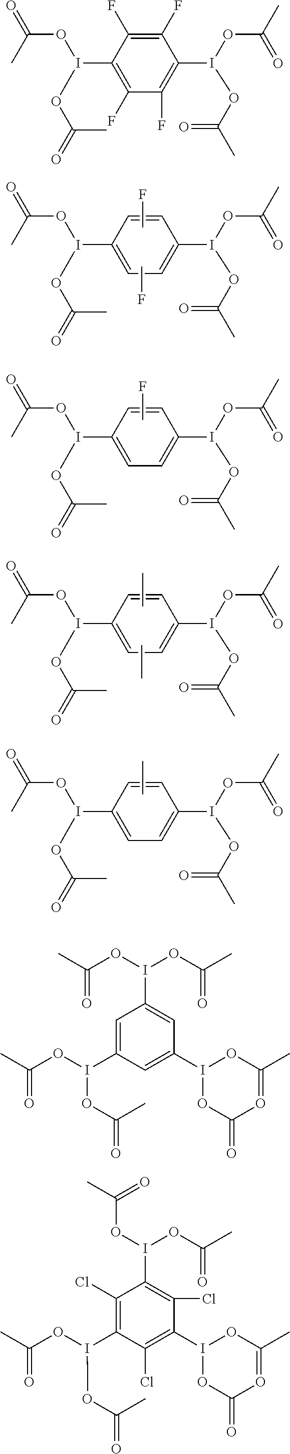

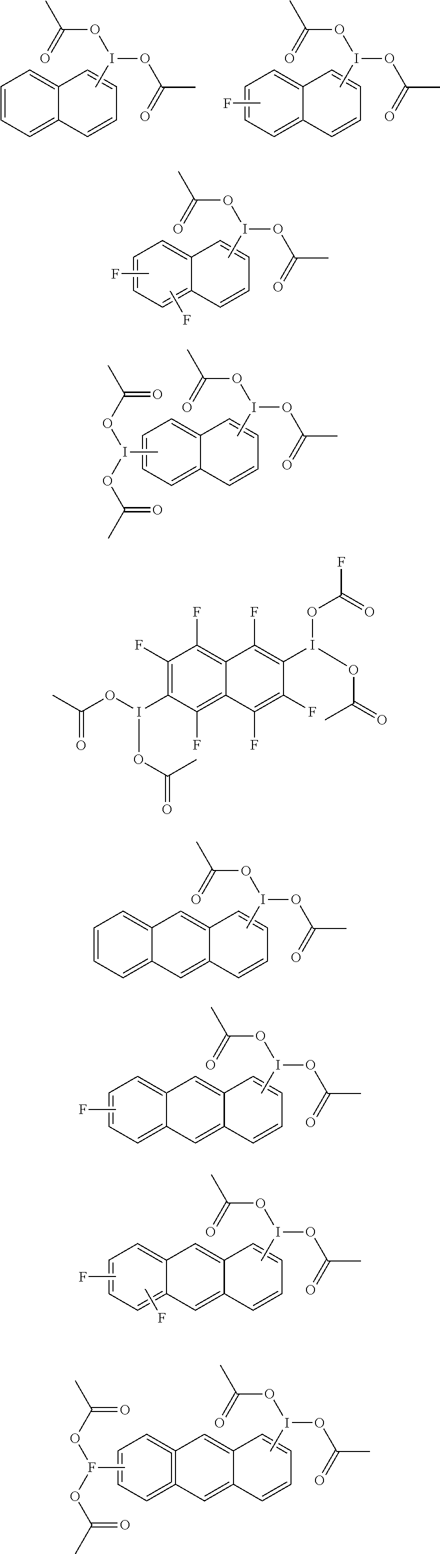

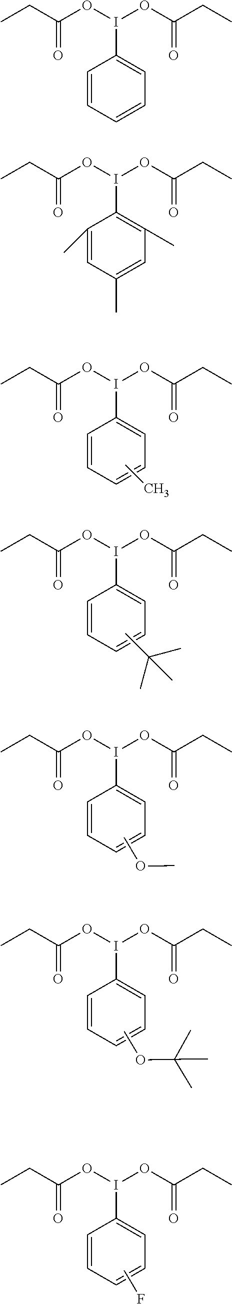

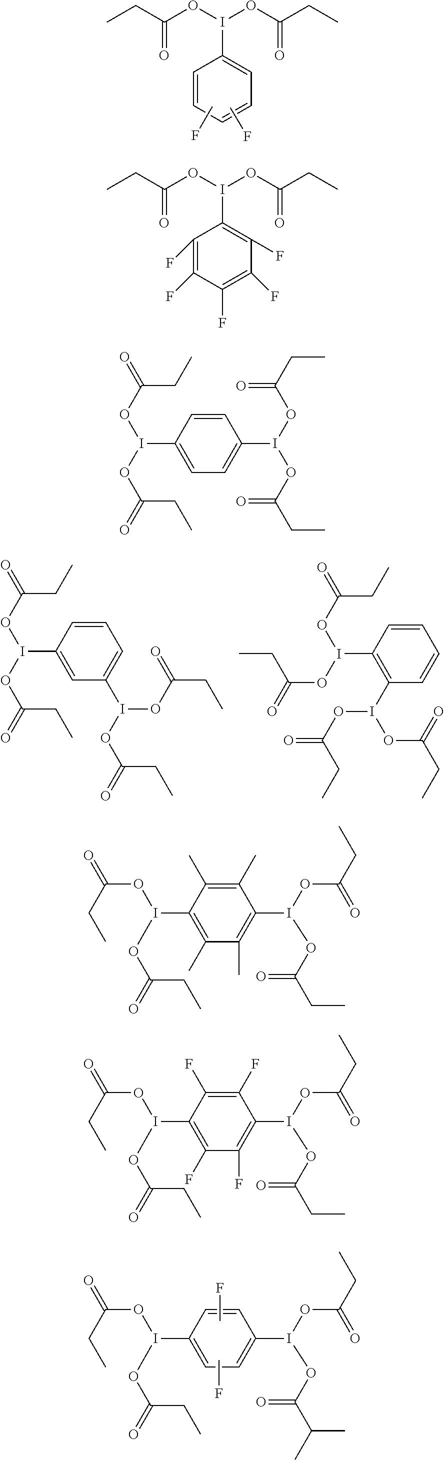

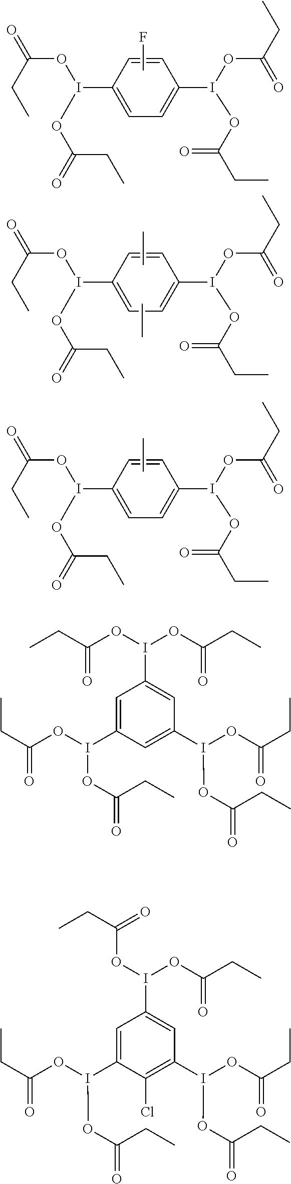

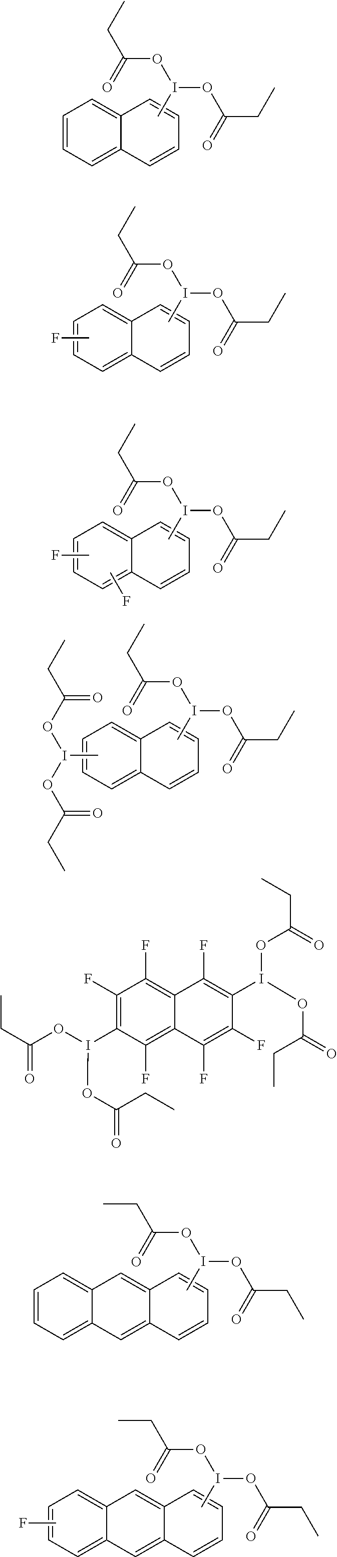

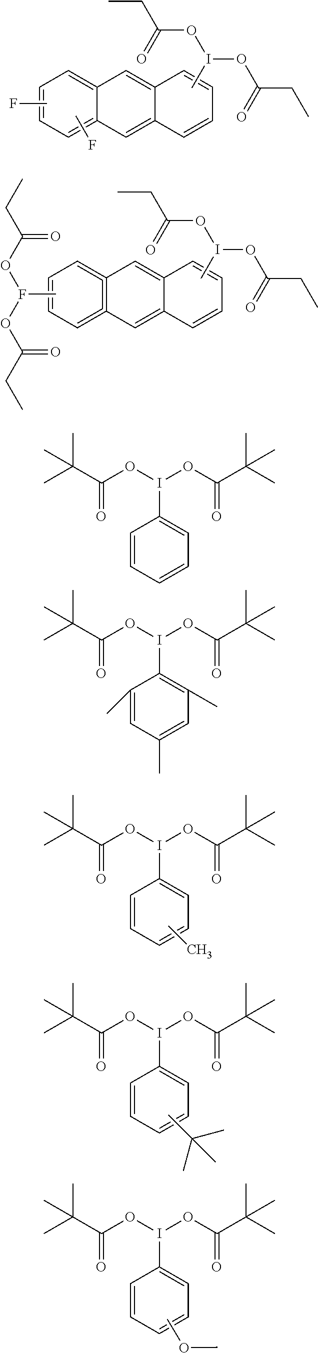

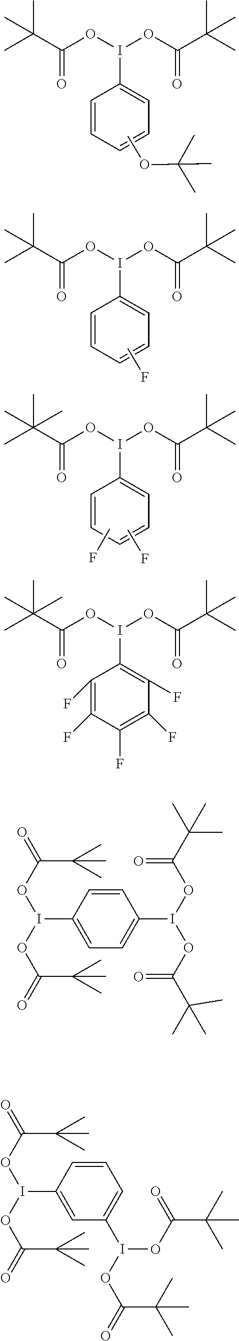

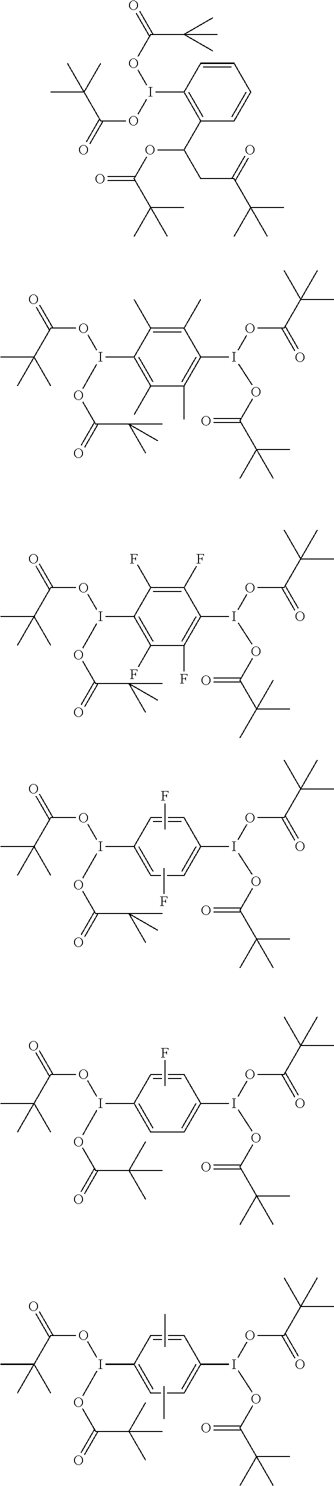

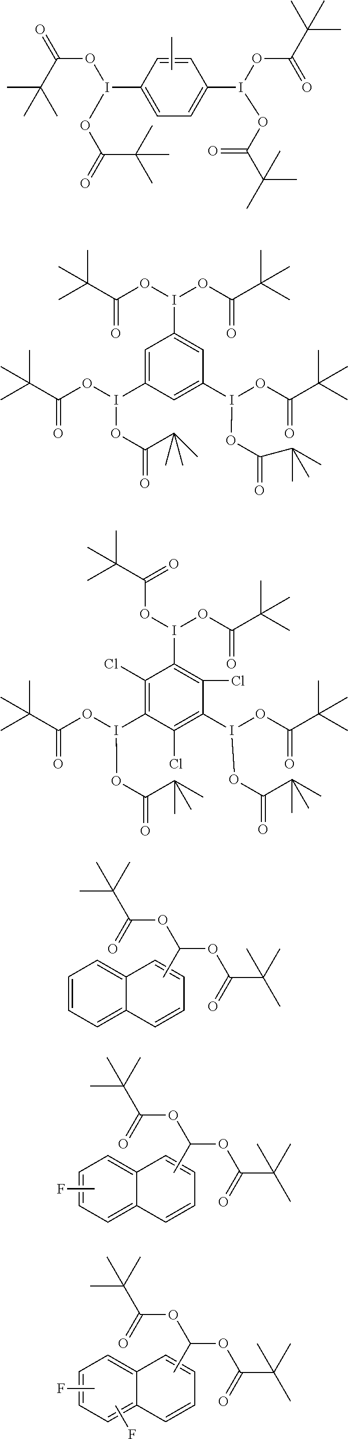

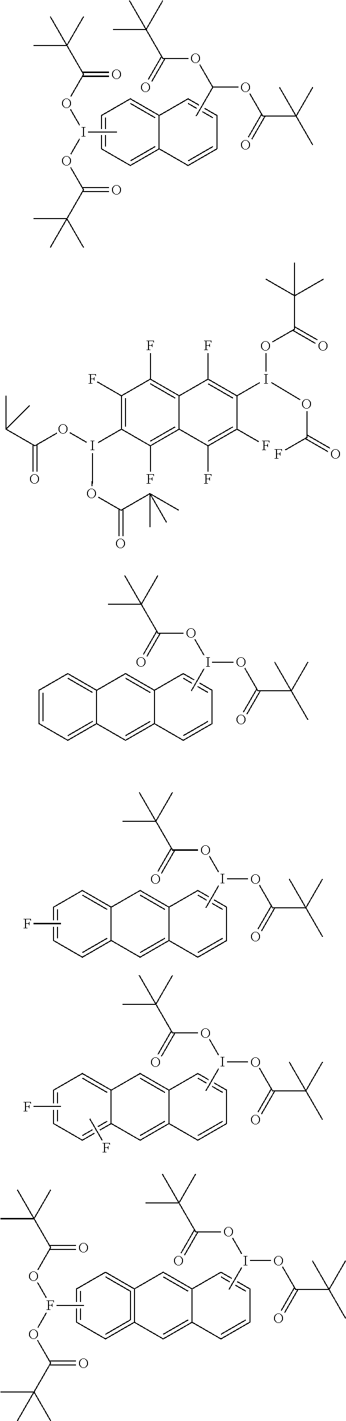

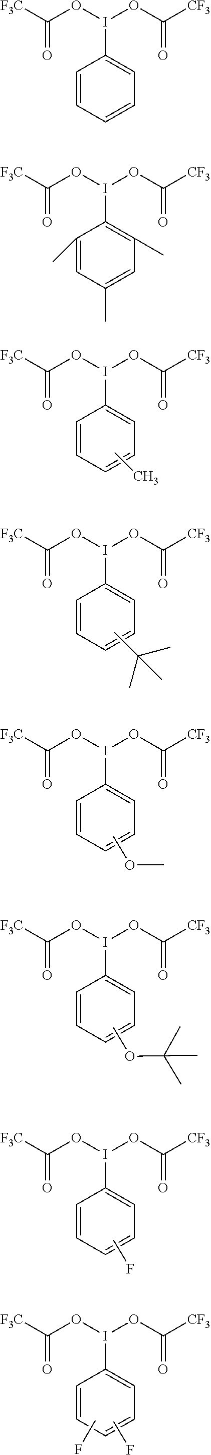

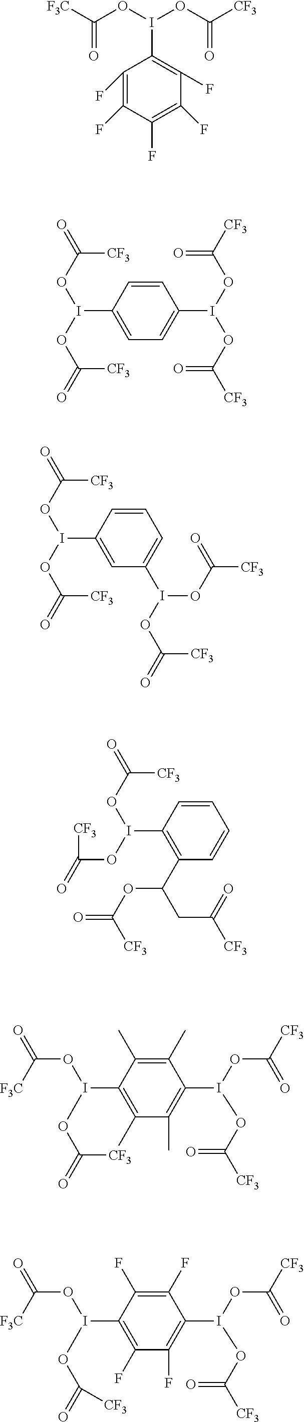 [SMILES: O=C(OI(OC(=O)C(F)(F)F)c1c(F)c(F)c(F)c(F)c1F)C(F)(F)F ; O=C(OI(OC(=O)C(F)(F)F)c1ccc(I(OC(=O)C(F)(F)F)OC(=O)C(F)(F)F)cc1)C(F)(F)F ; O=C(OI(OC(=O)C(F)(F)F)c1cccc(I(OC(=O)C(F)(F)F)OC(=O)C(F)(F)F)c1)C(F)(F)F ; O=C(CC(OC(=O)C(F)(F)F)c1ccccc1I(OC(=O)C(F)(F)F)OC(=O)C(F)(F)F)C(F)(F)F ; Cc1c(C)c(I(OC(=O)C(F)(F)F)OC(=O)C(F)(F)F)c(C)c(C)c1I(OC(=O)C(F)(F)F)OC(=O)C(F)(F)F ; O=C(OI(OC(=O)C(F)(F)F)c1c(F)c(F)c(I(OC(=O)C(F)(F)F)OC(=O)C(F)(F)F)c(F)c1F)C(F)(F)F]

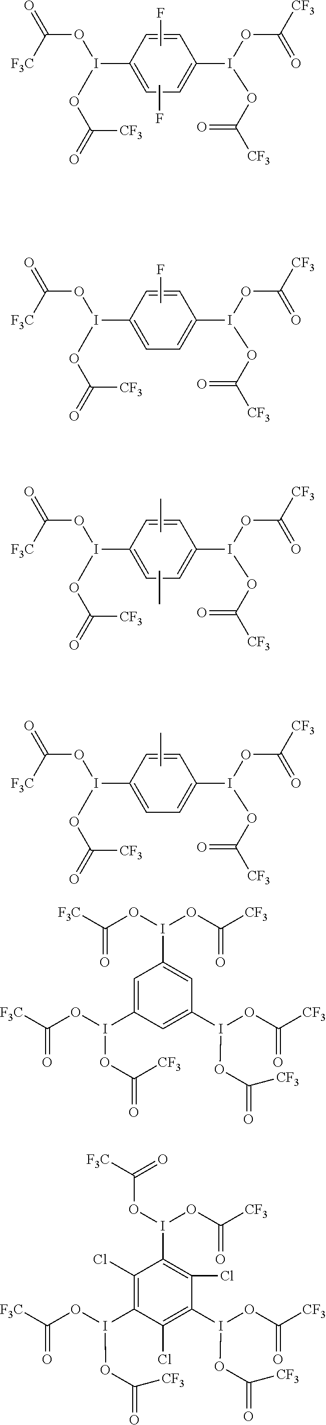

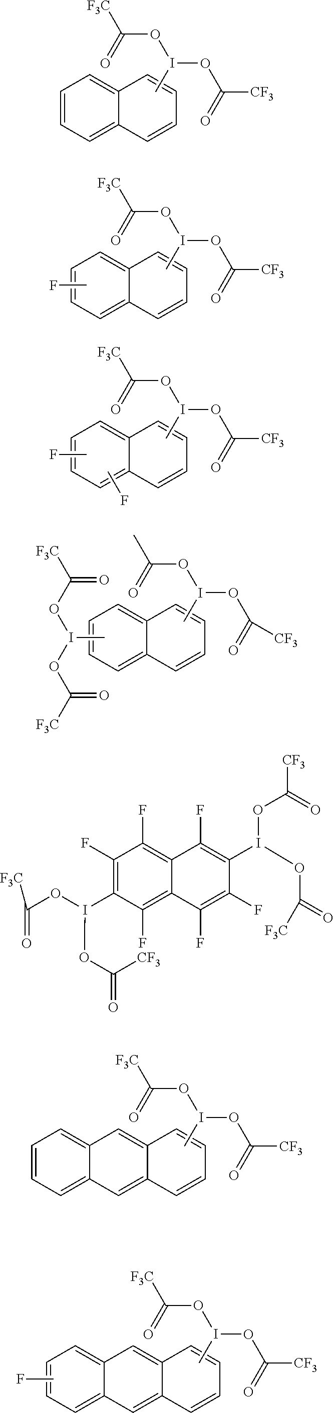

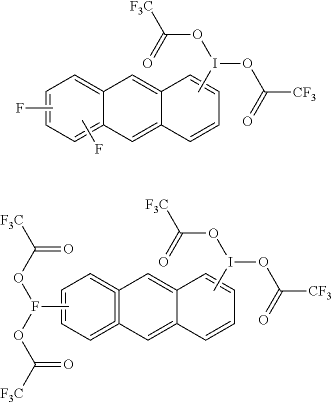

Examples of the hypervalent iodine compound having the formula (2) are shown

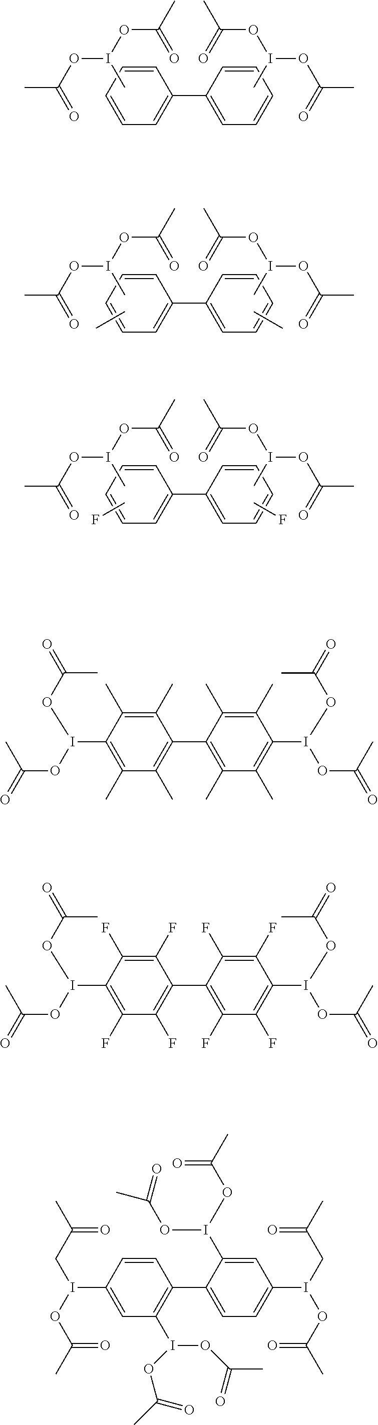

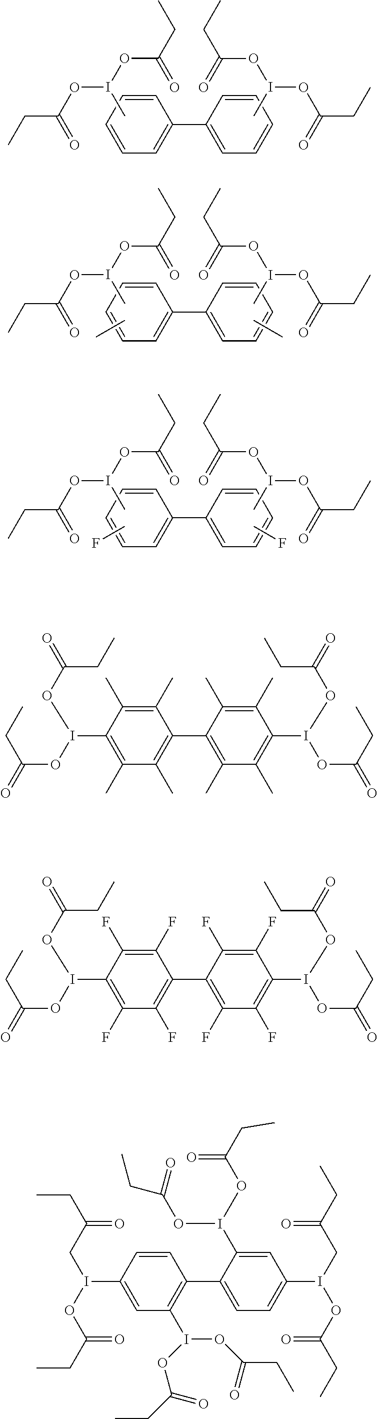

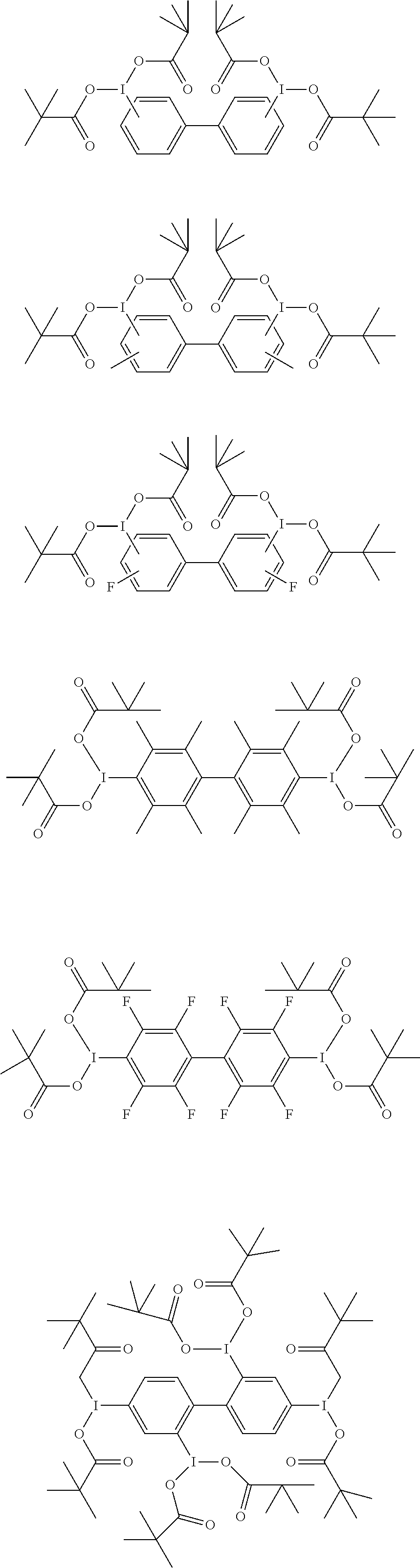

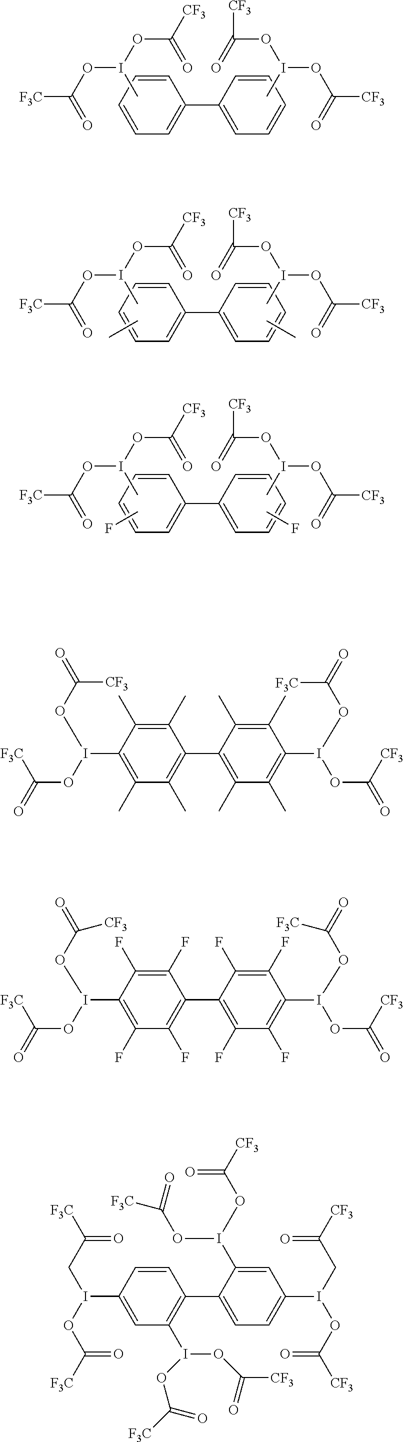

Examples of the hypervalent iodine compound having the formula (3) are shown

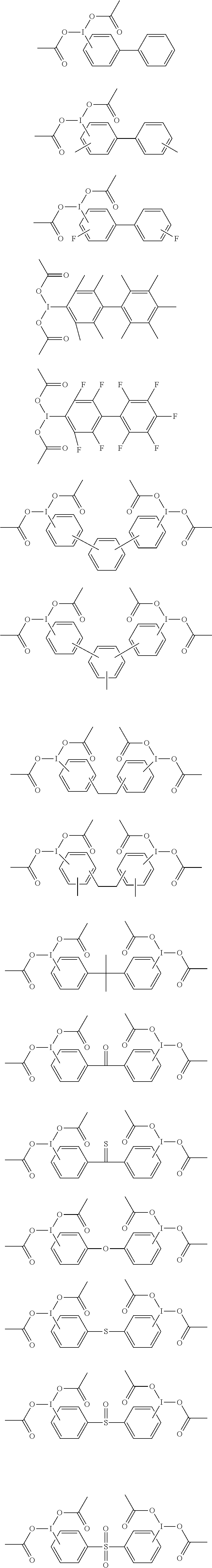

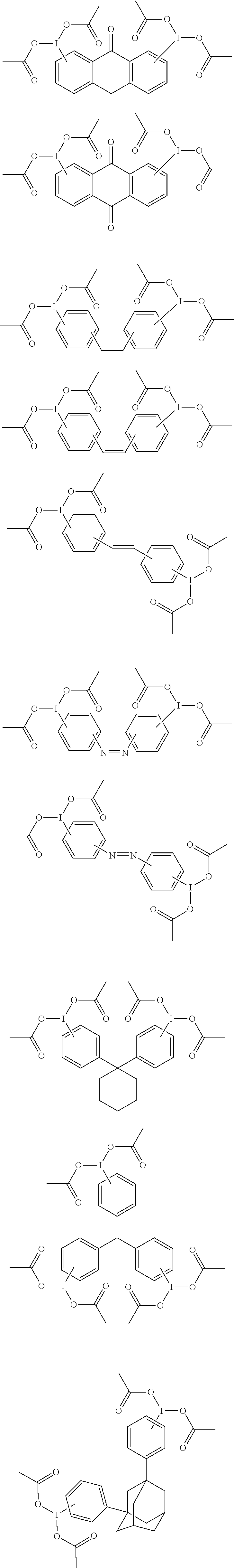

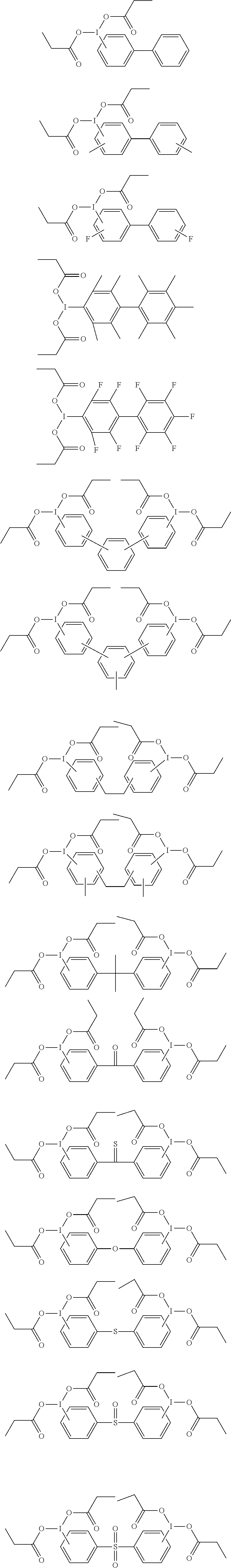

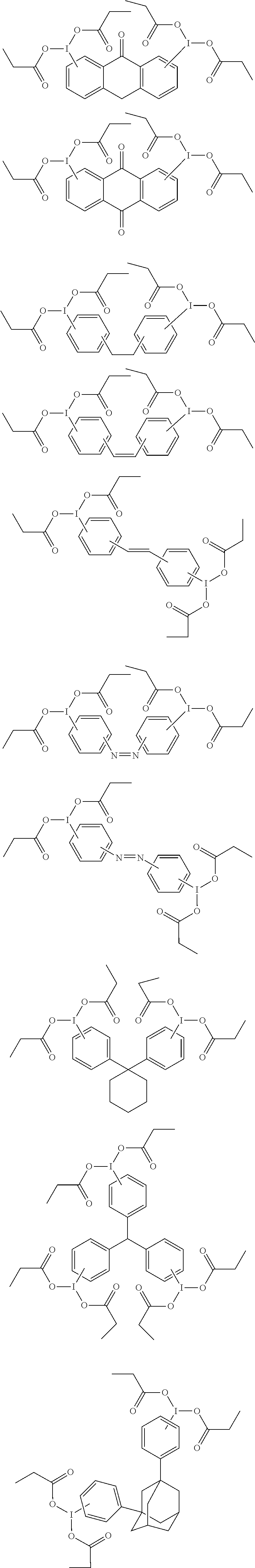

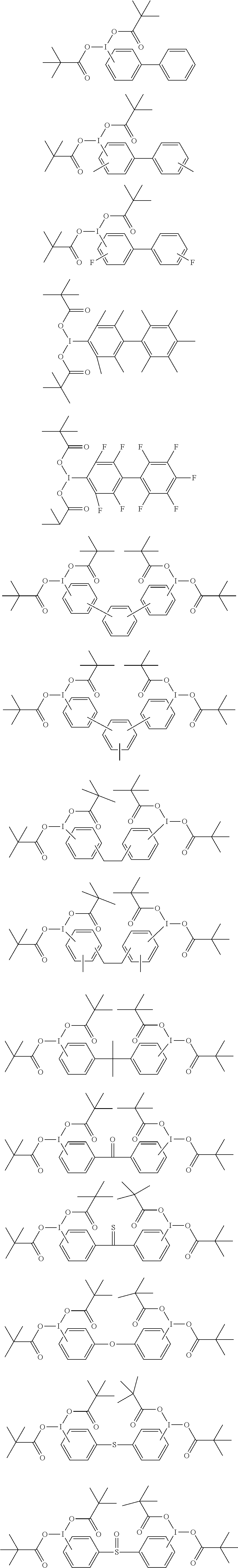

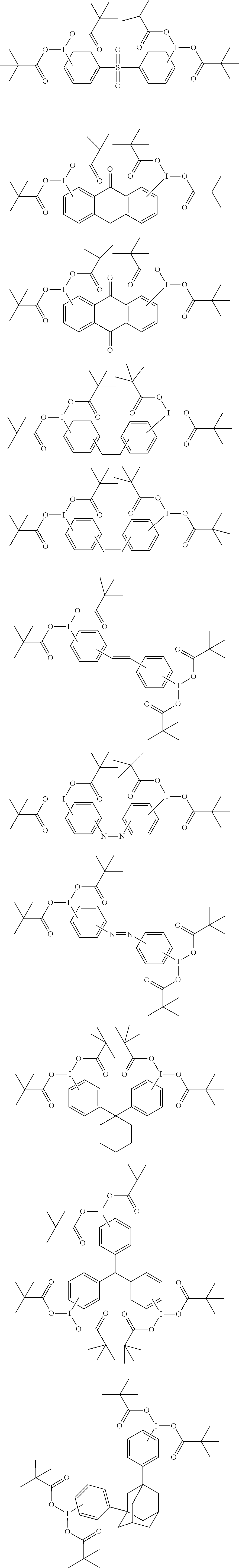

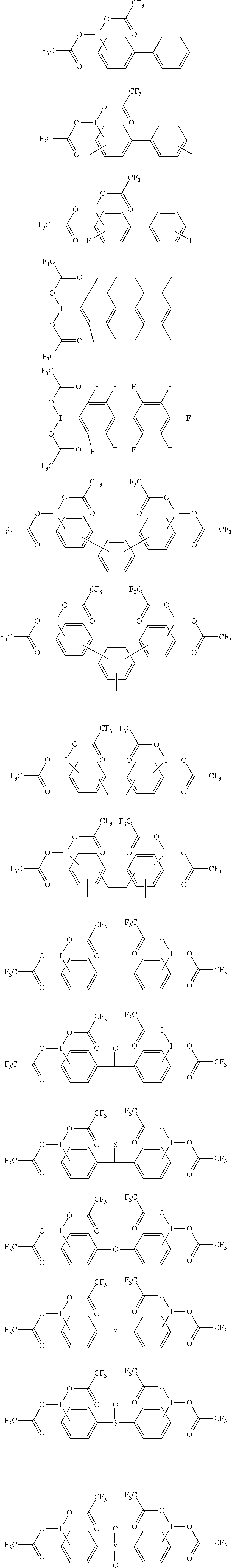

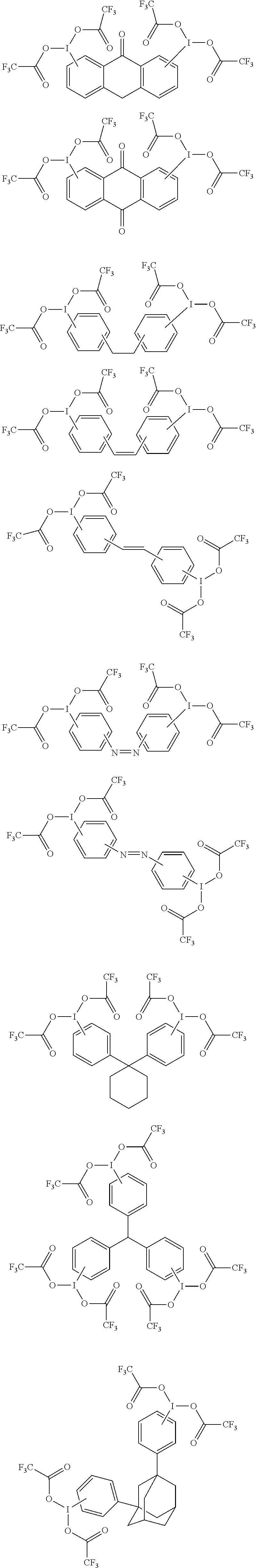

Examples of the hypervalent iodine compound having the formula (4) are shown below, but are not limited thereto. In the formula, Me is a methyl group.

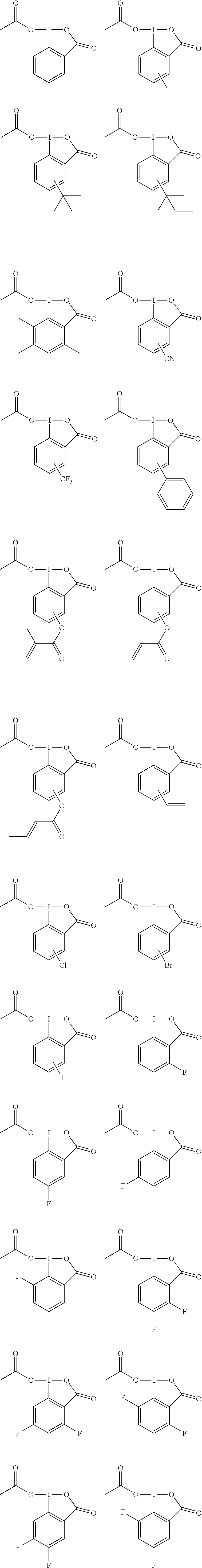

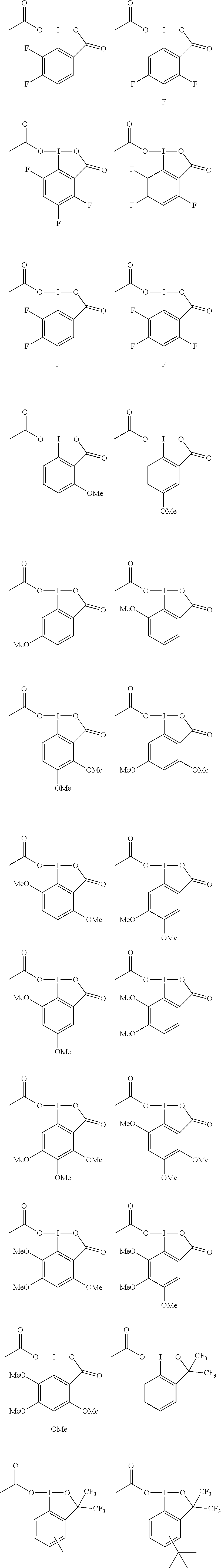

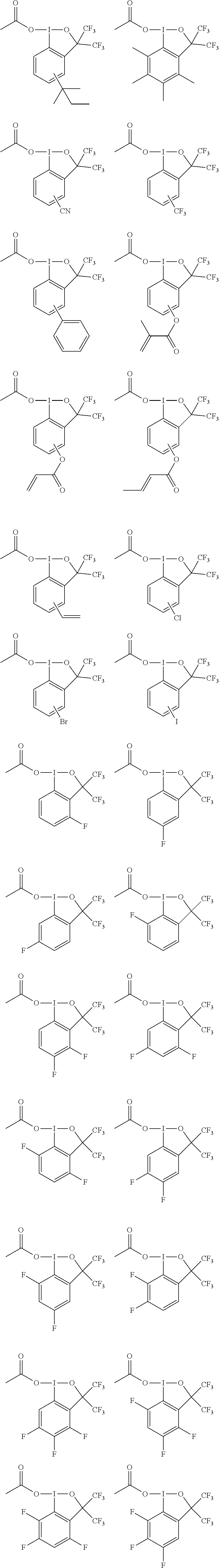

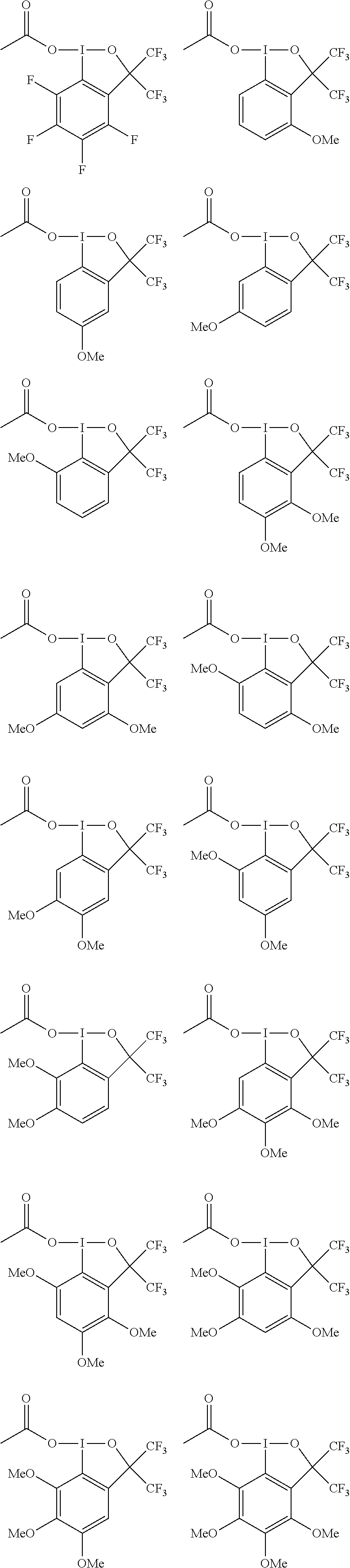

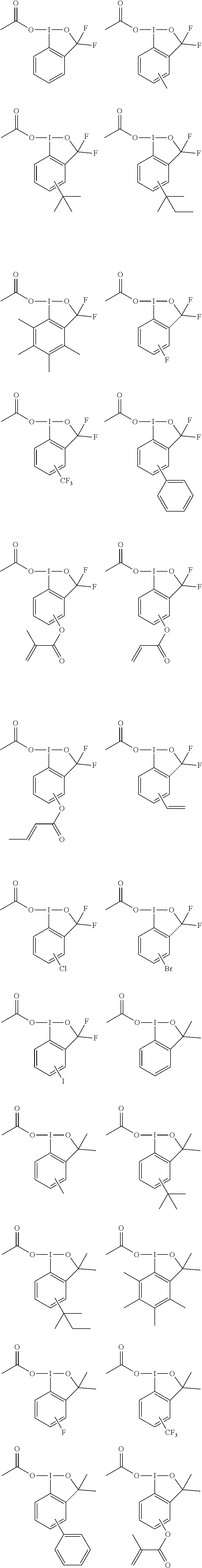

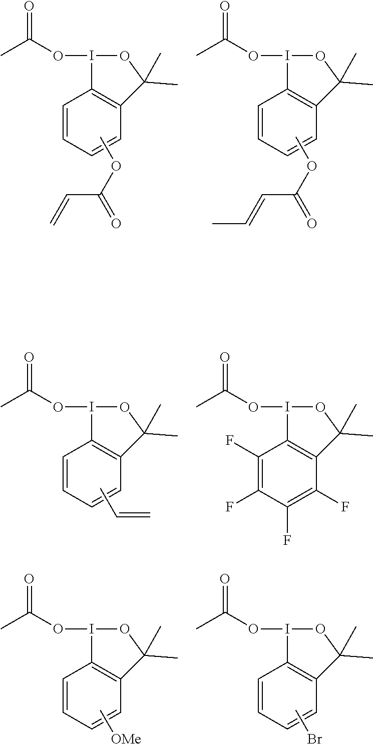

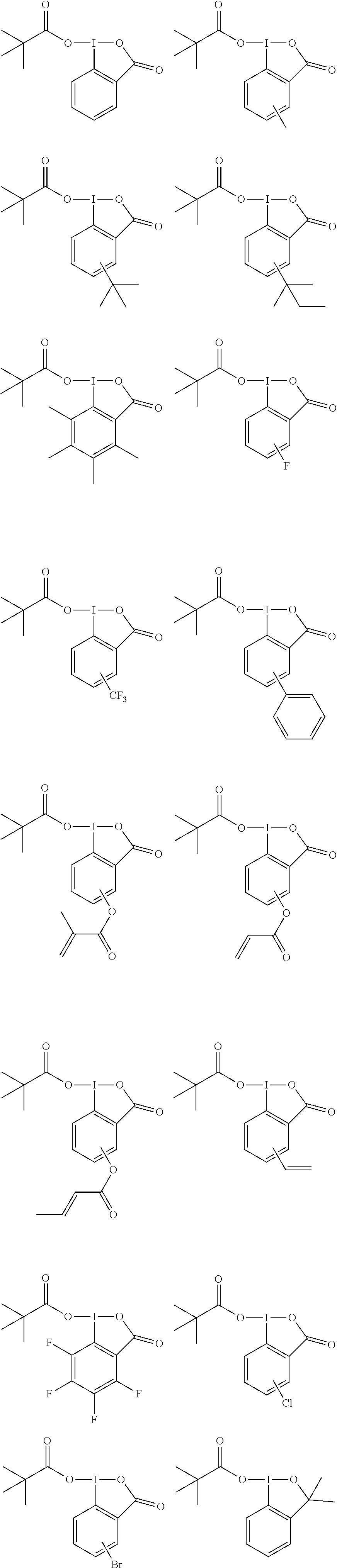

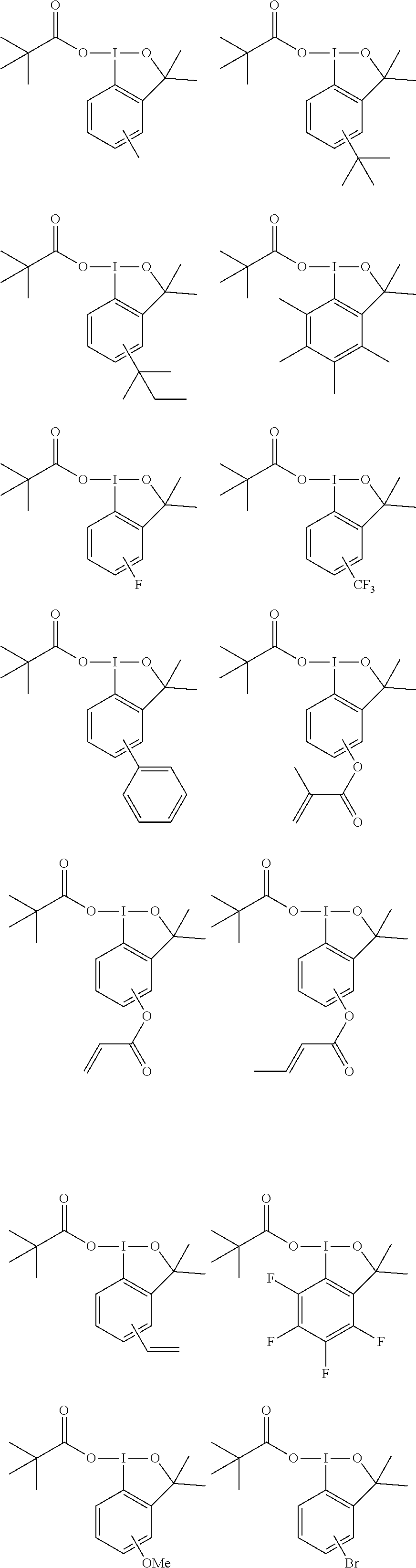

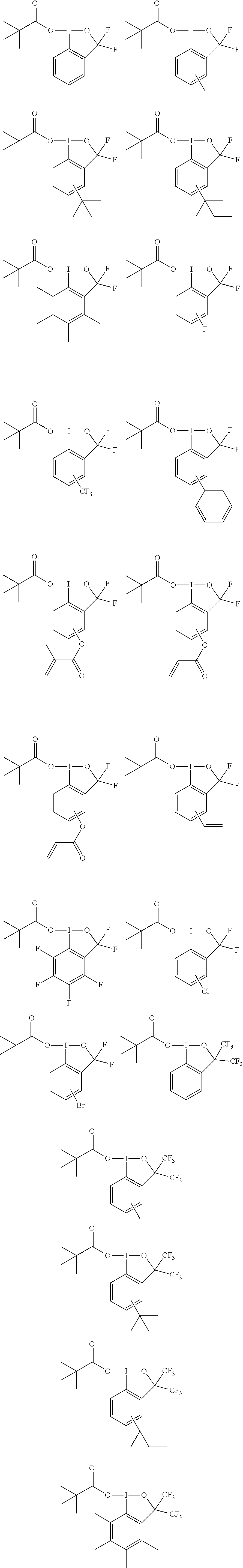

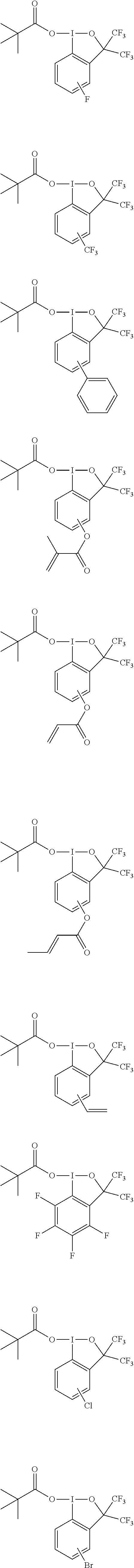

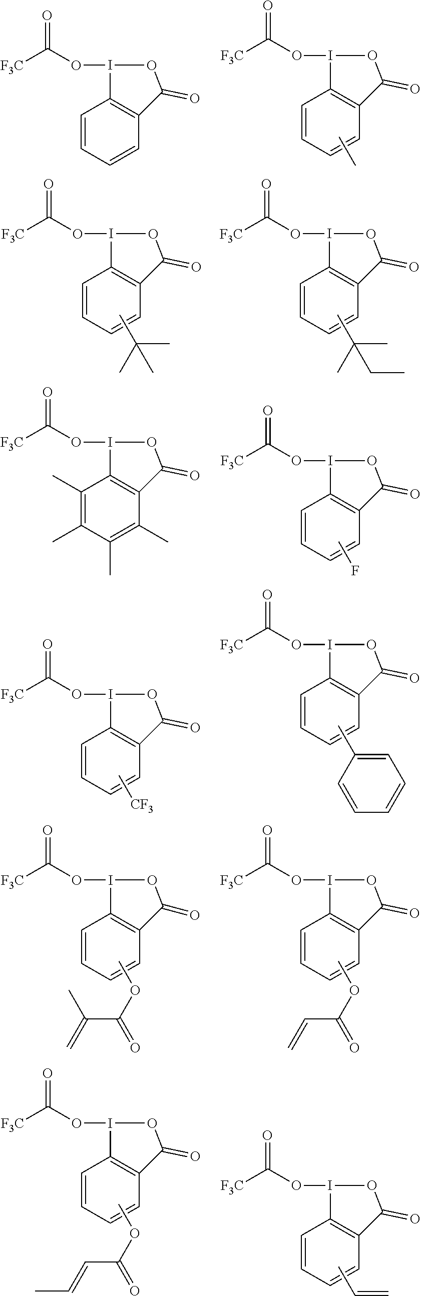

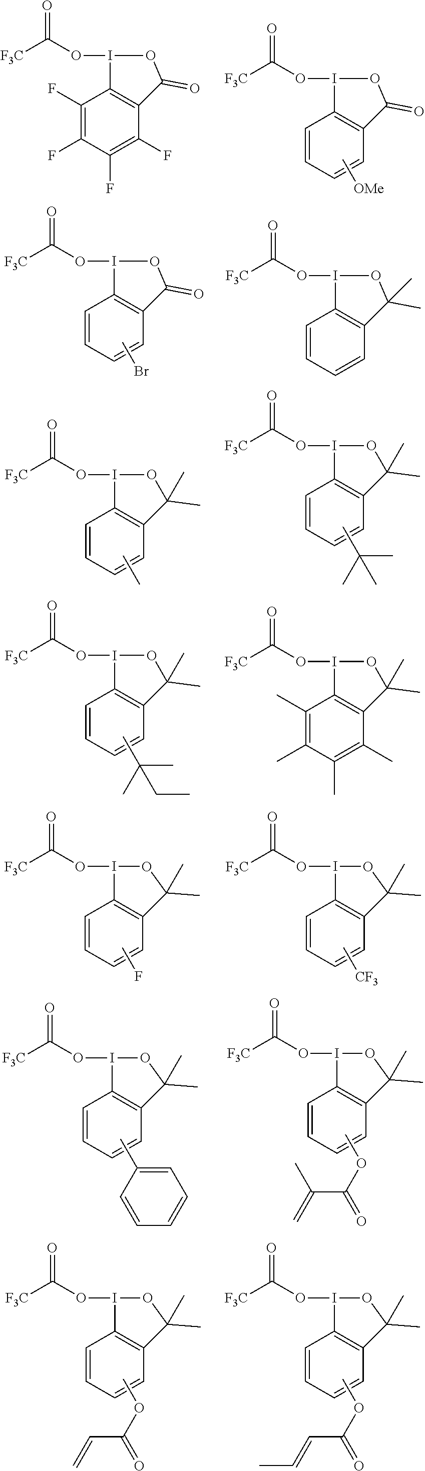

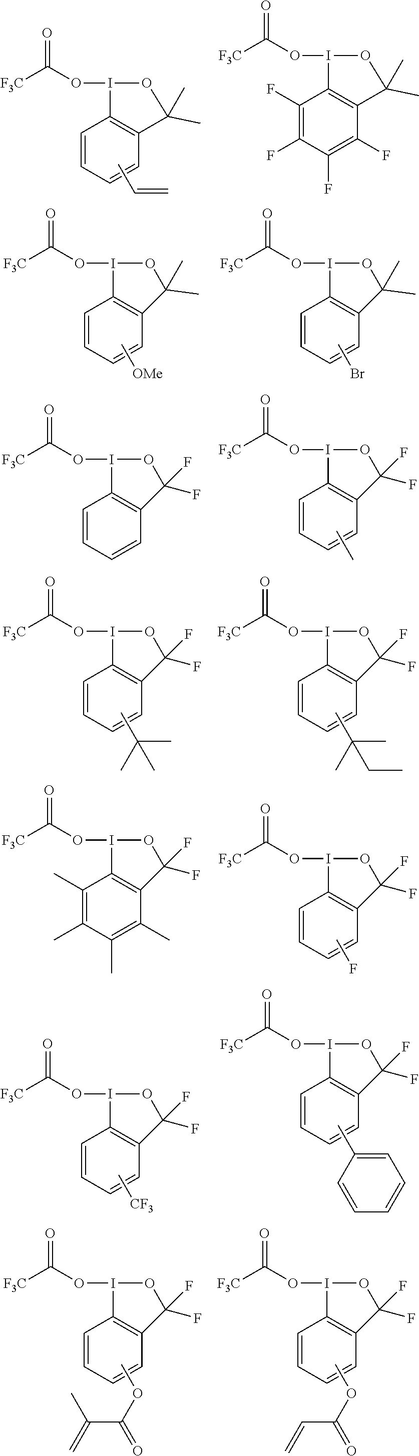

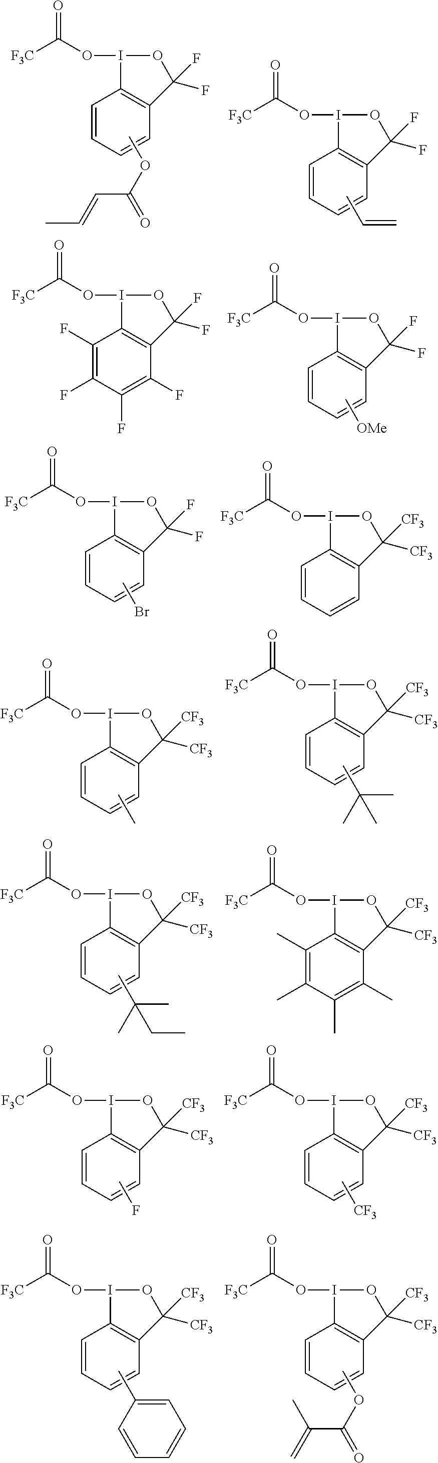

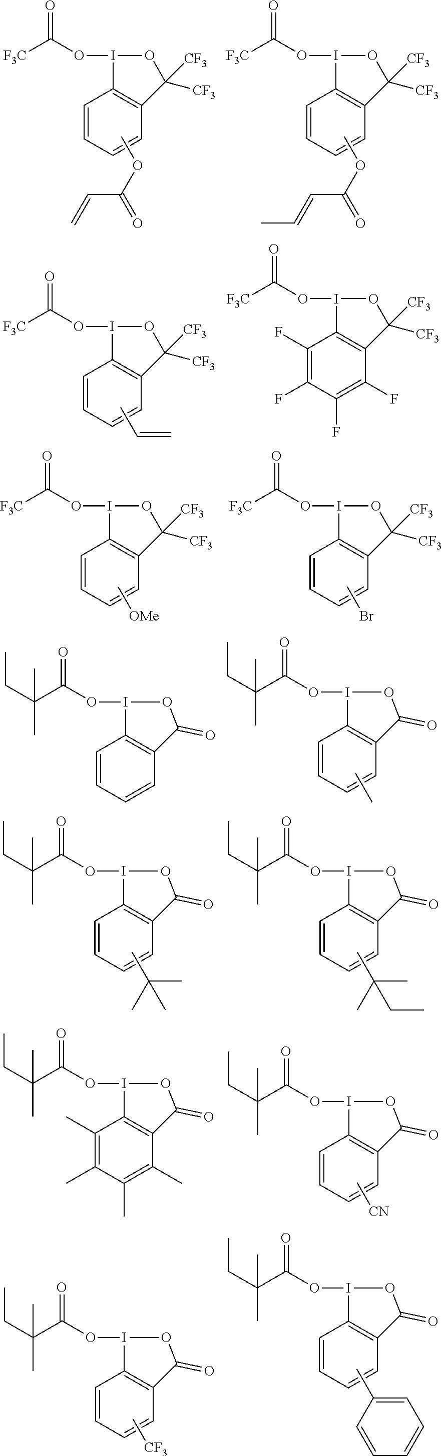

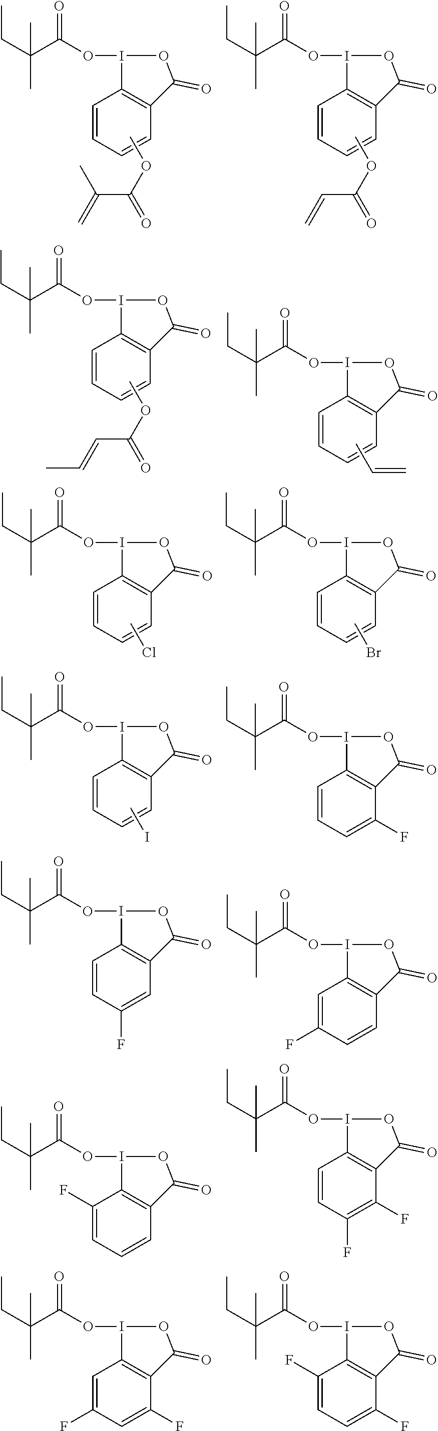

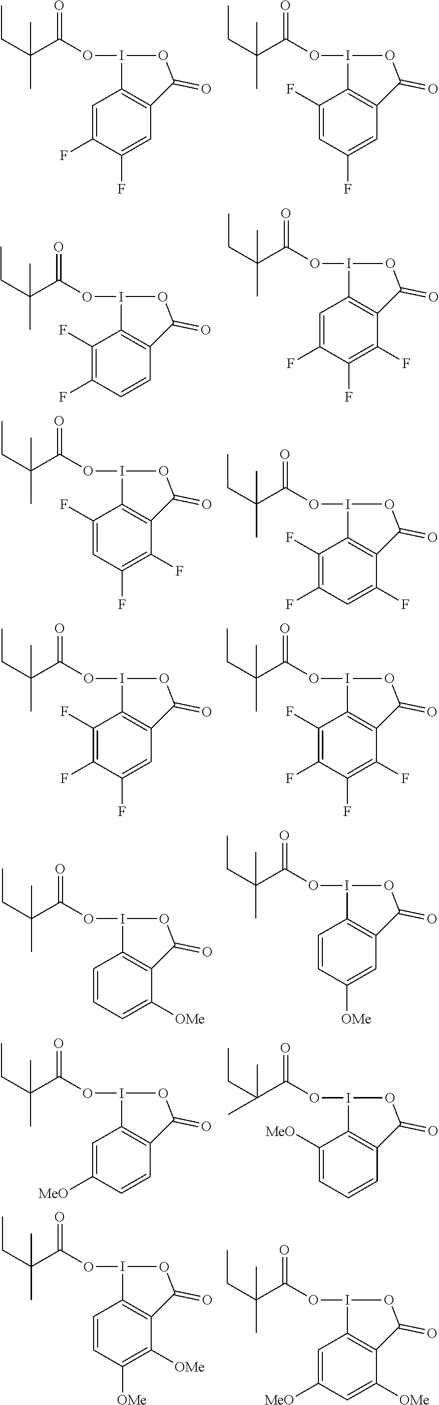

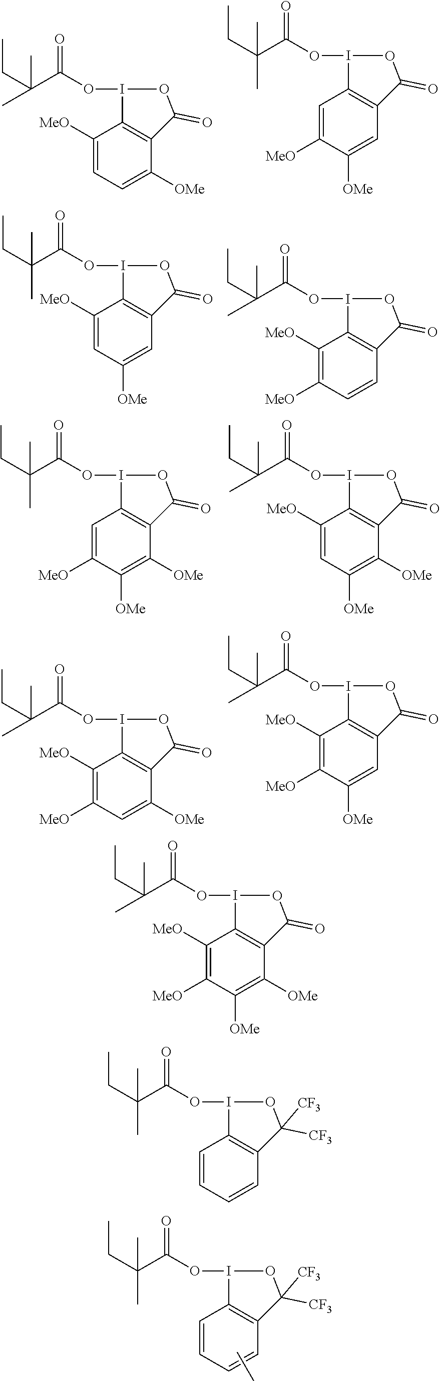

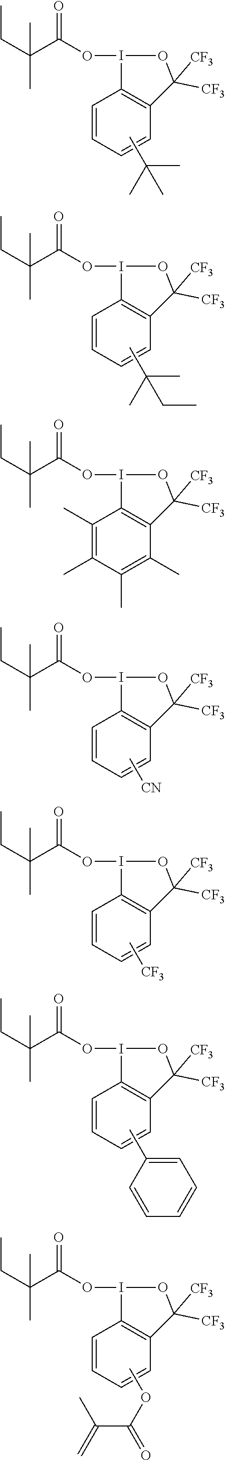

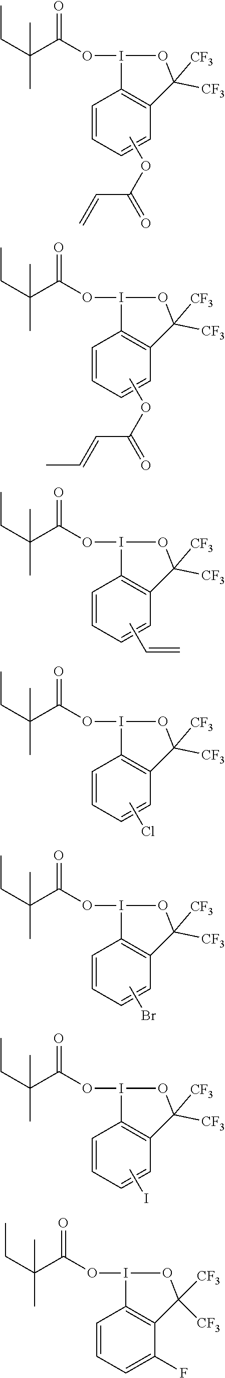

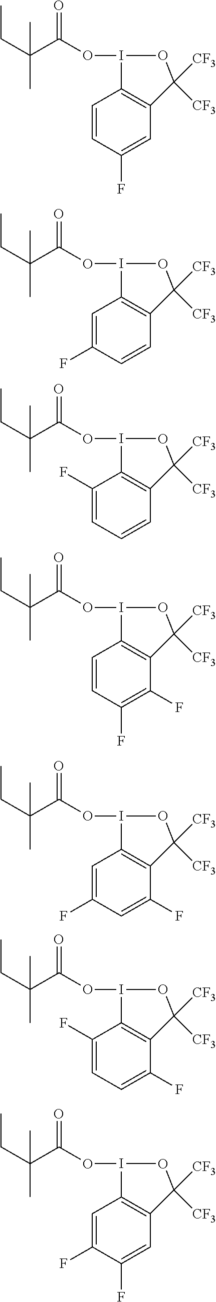

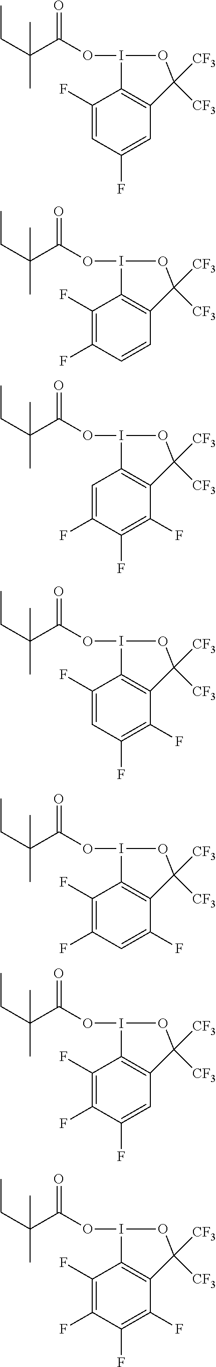

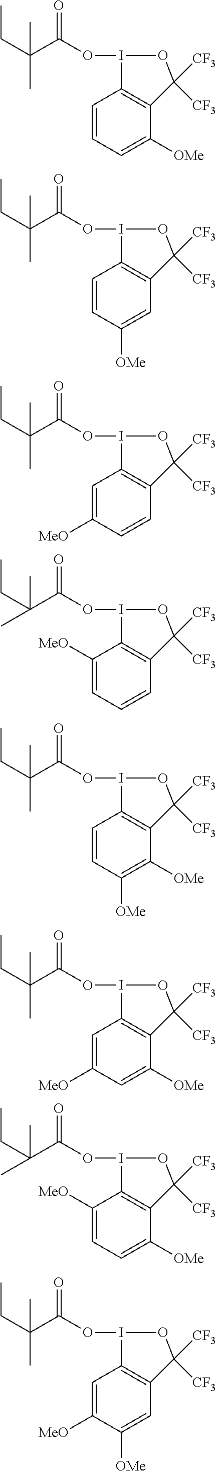

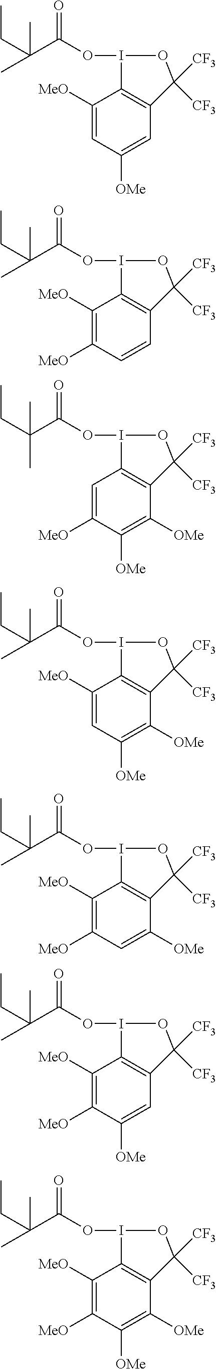

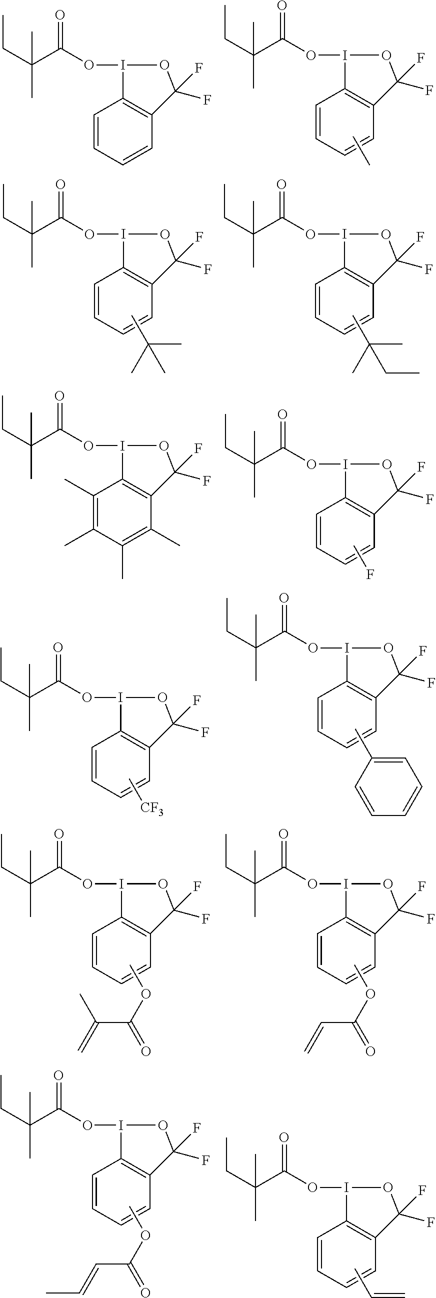

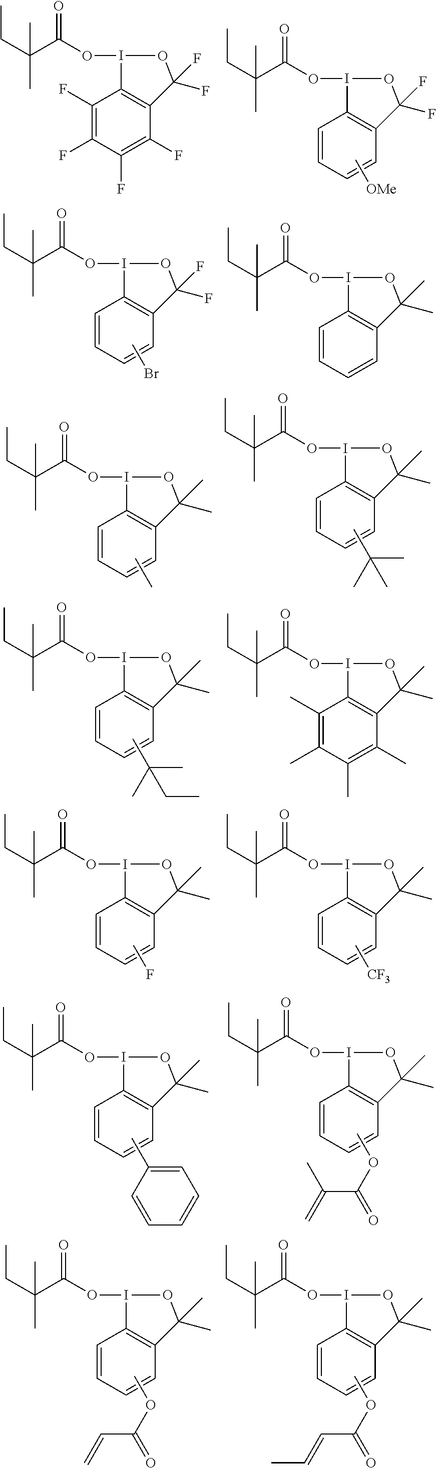

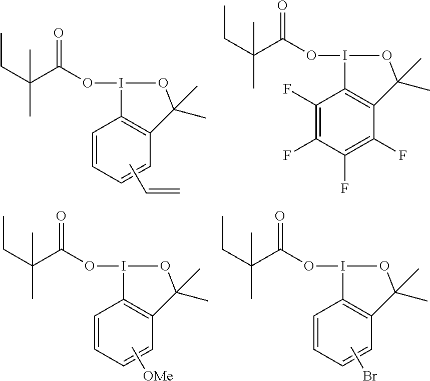

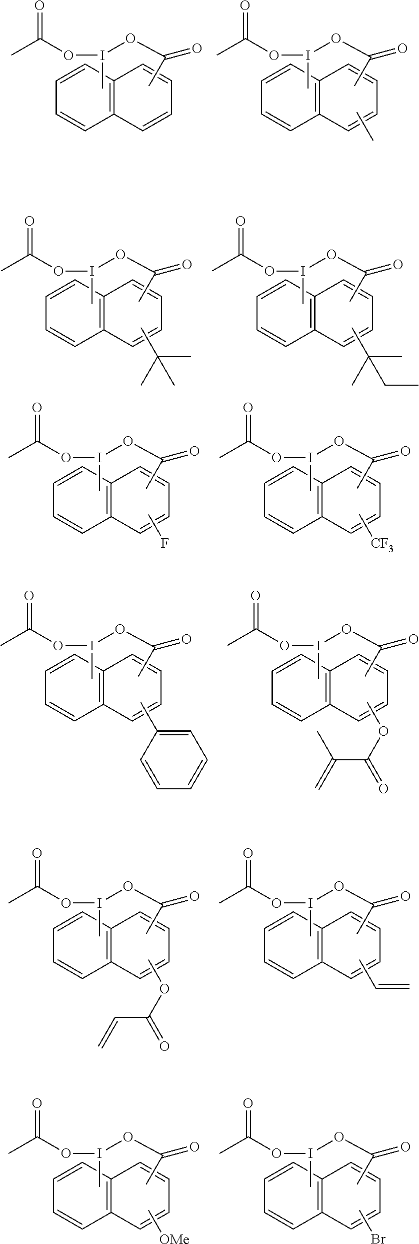

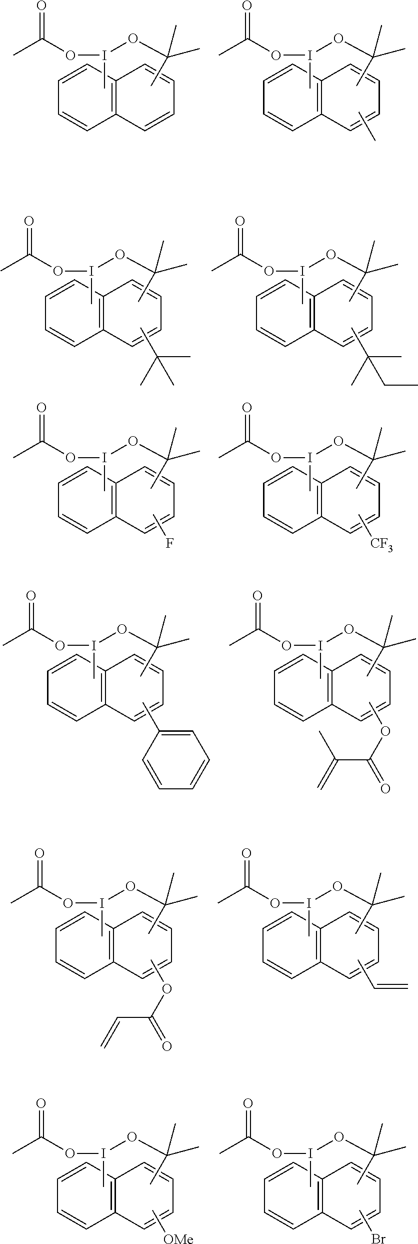

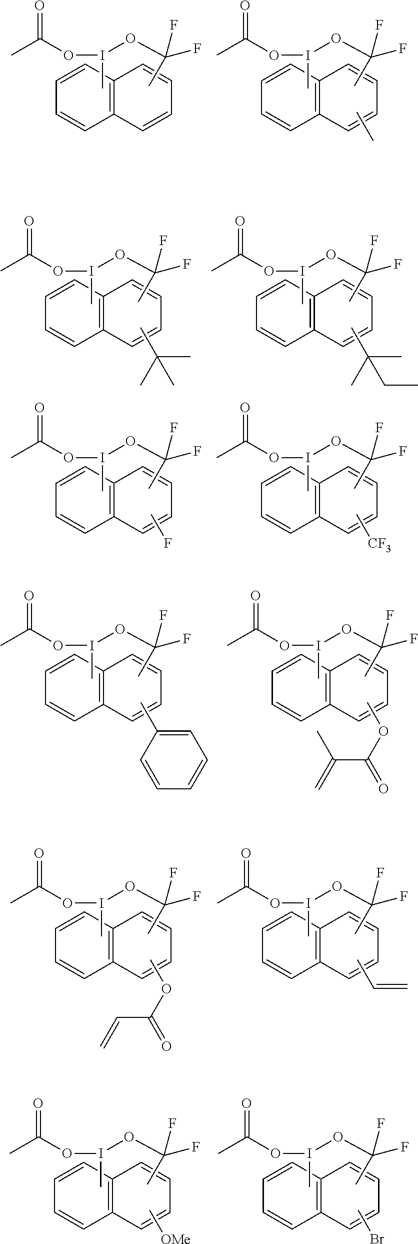

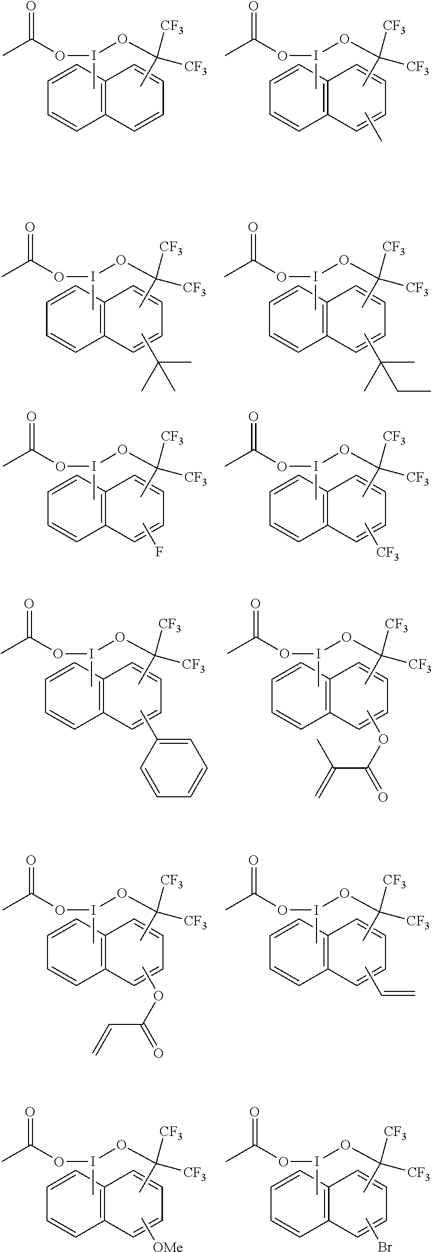

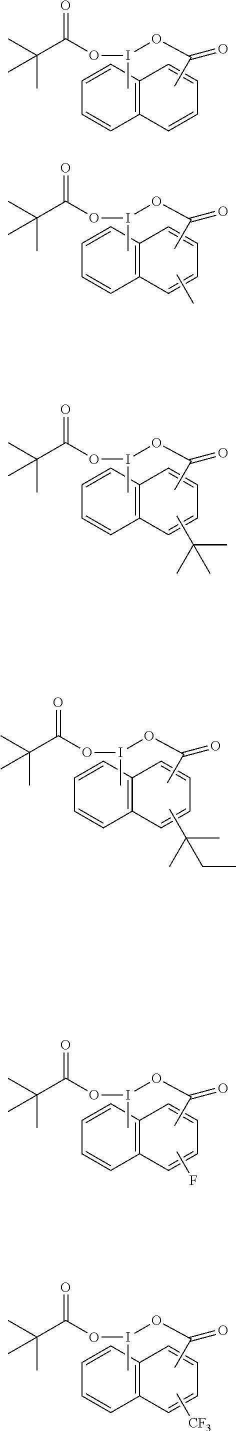

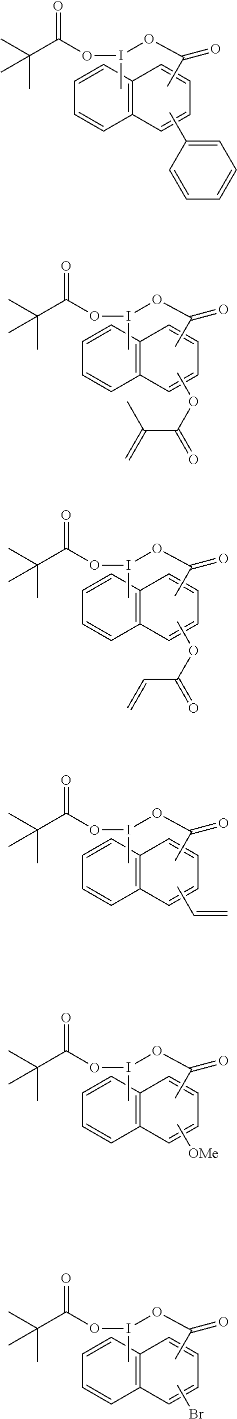

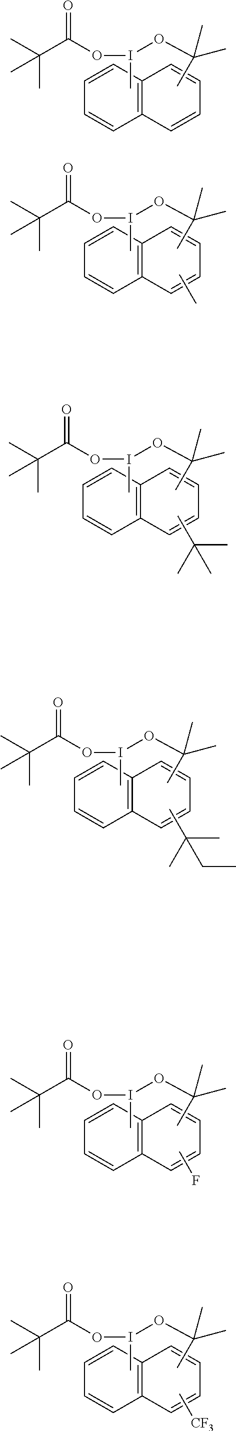

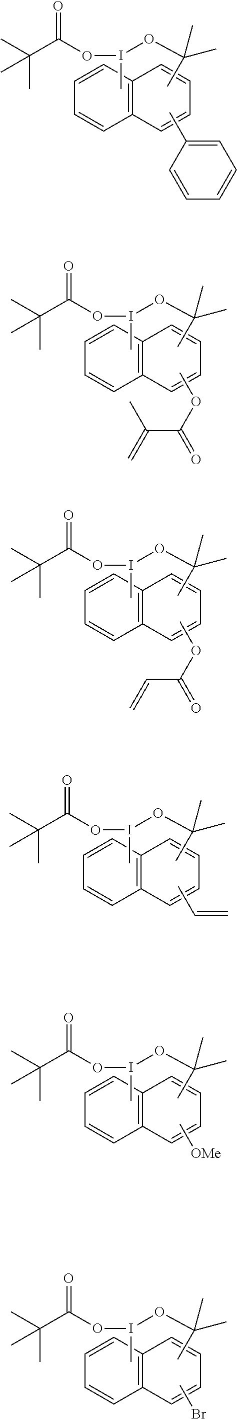

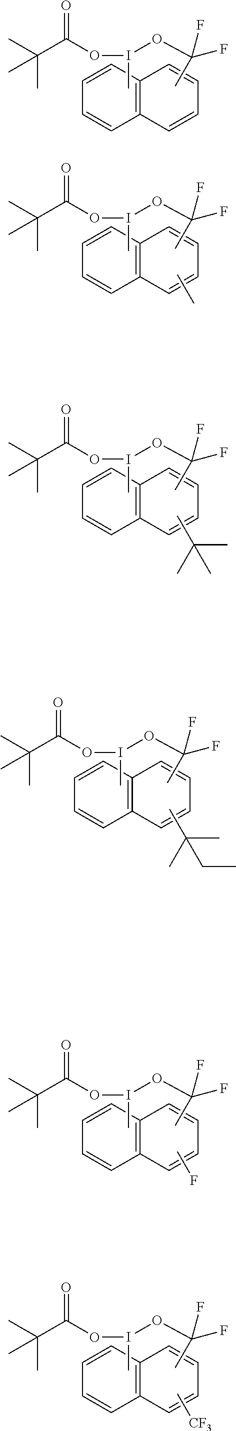

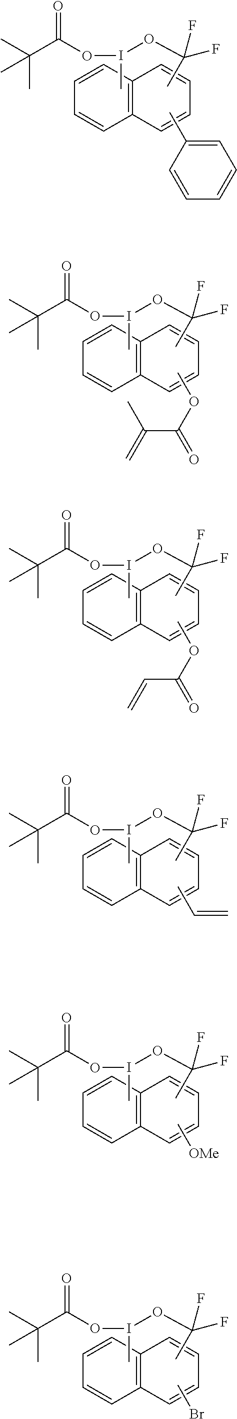

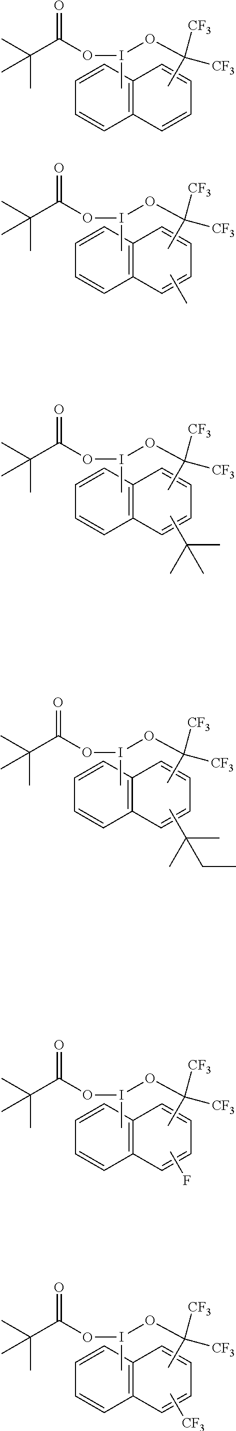

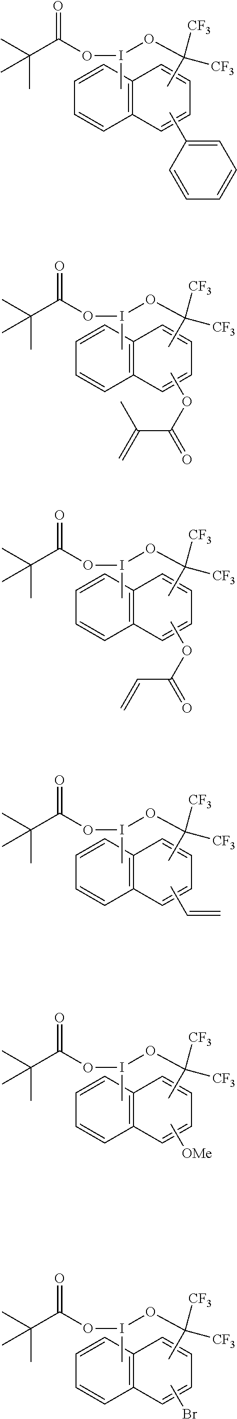

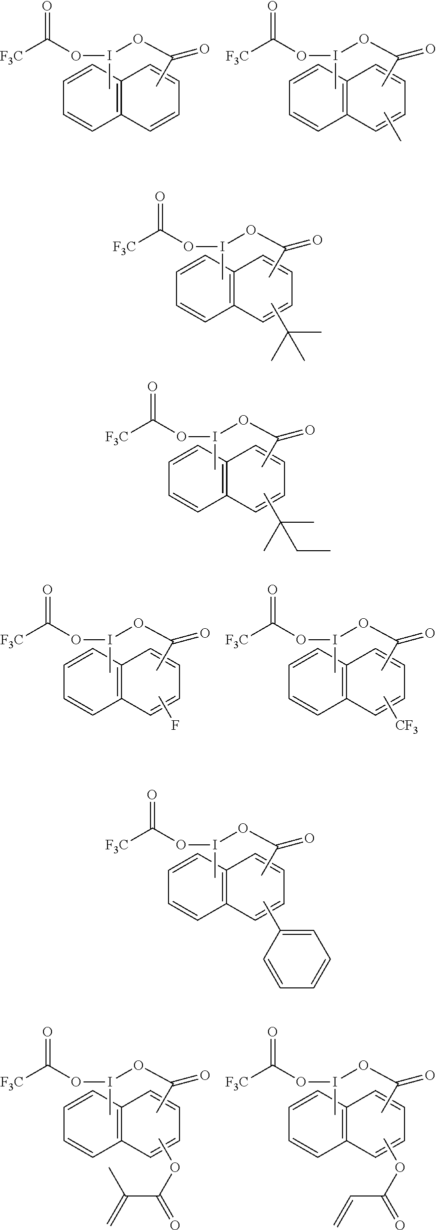

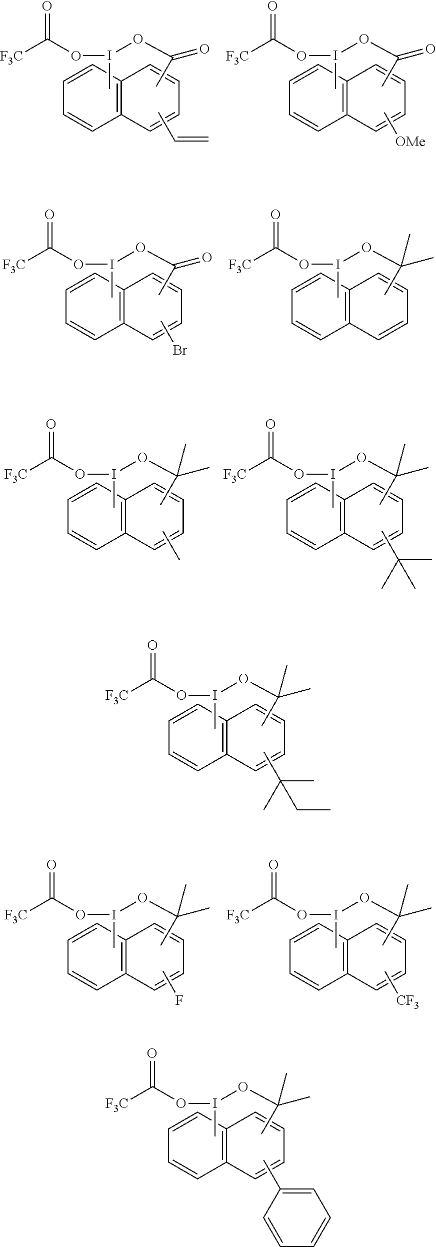

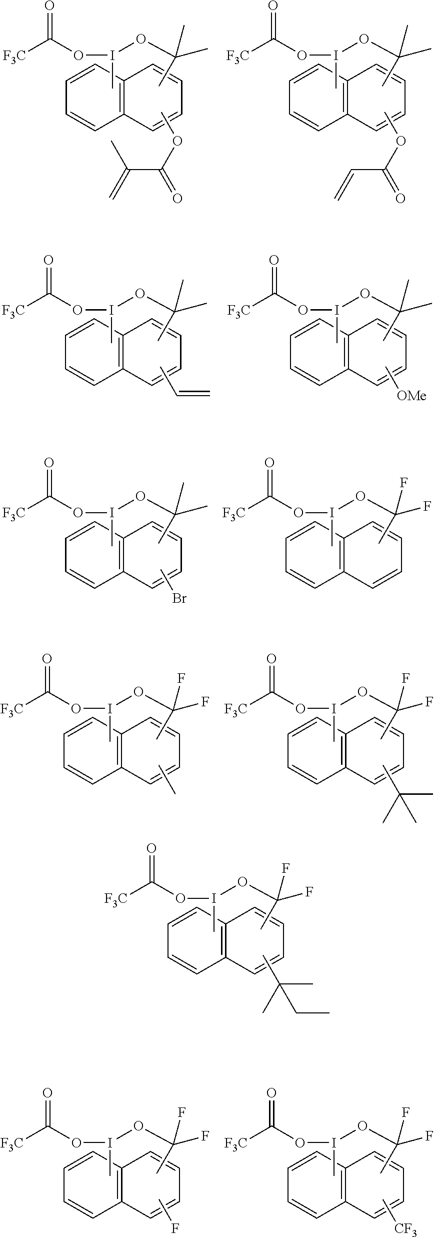

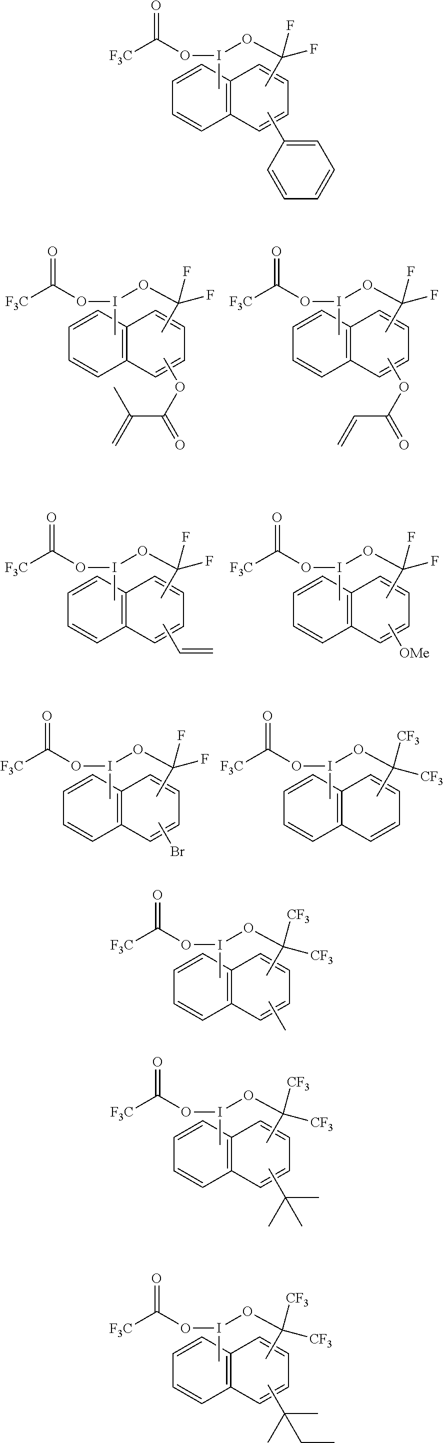

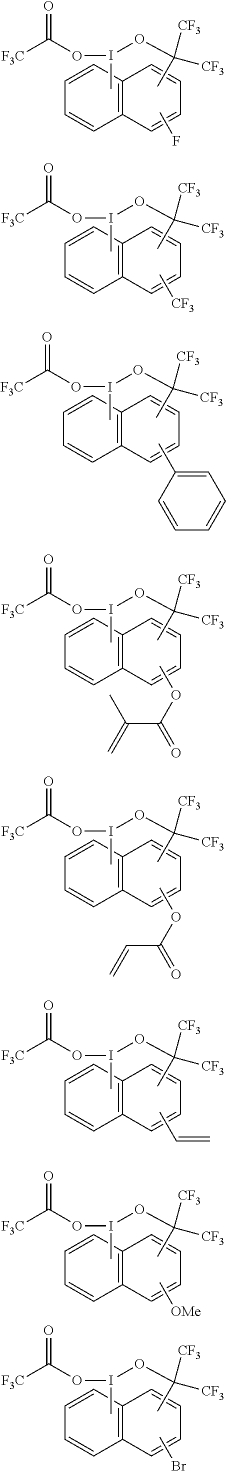

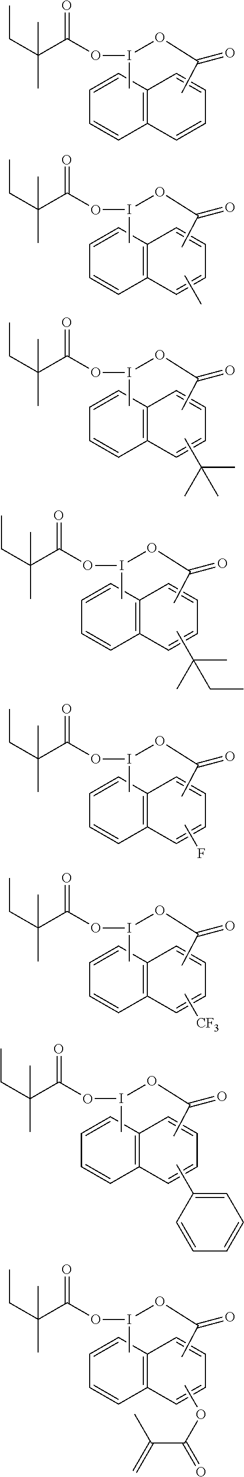

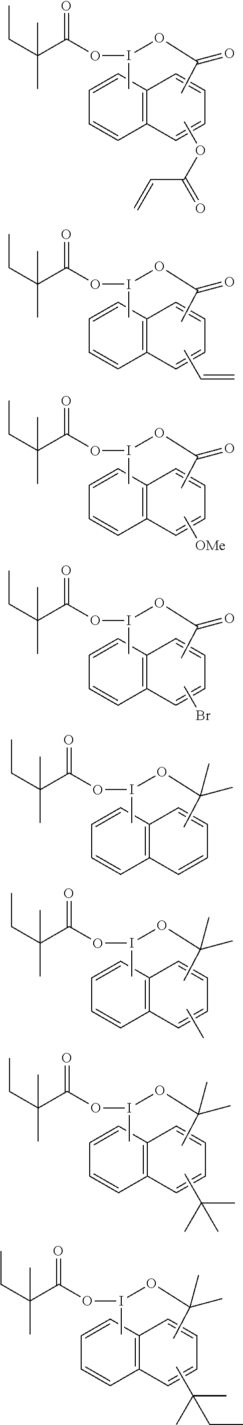

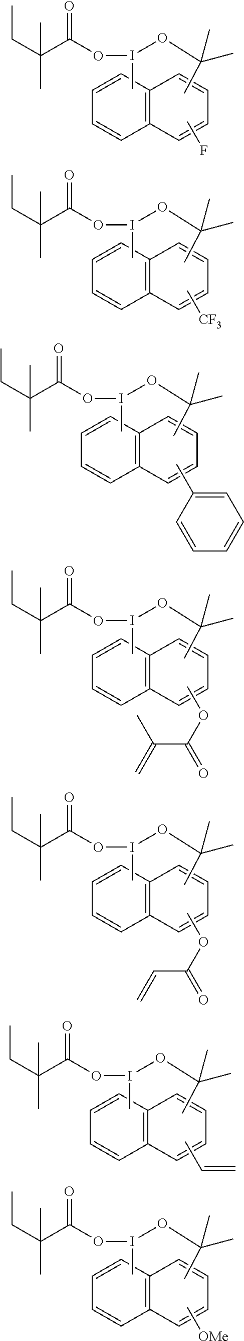

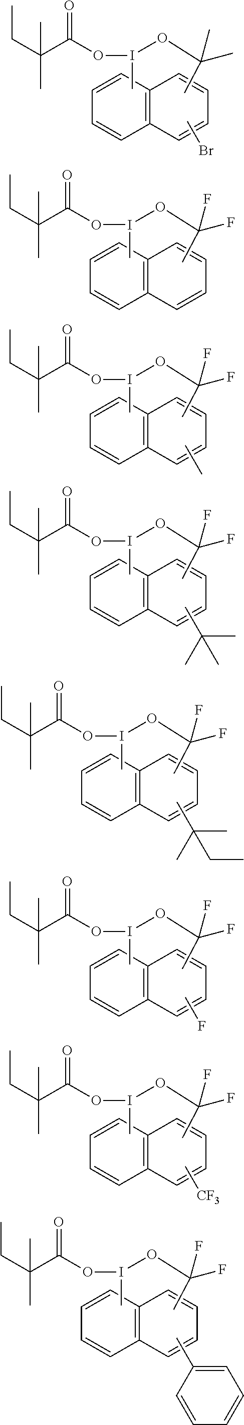

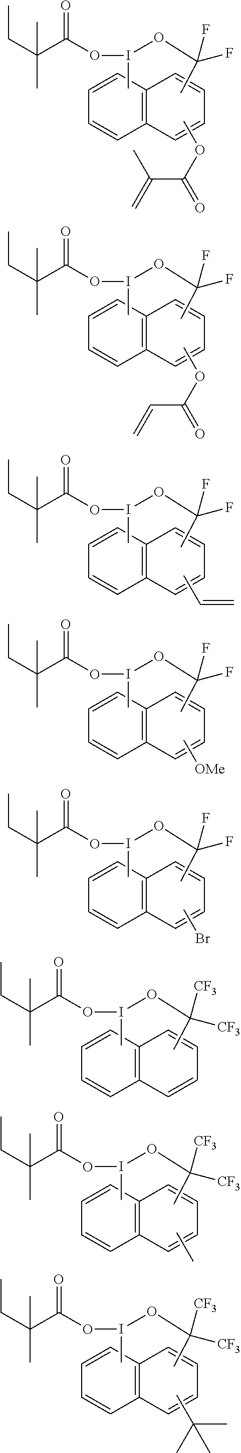

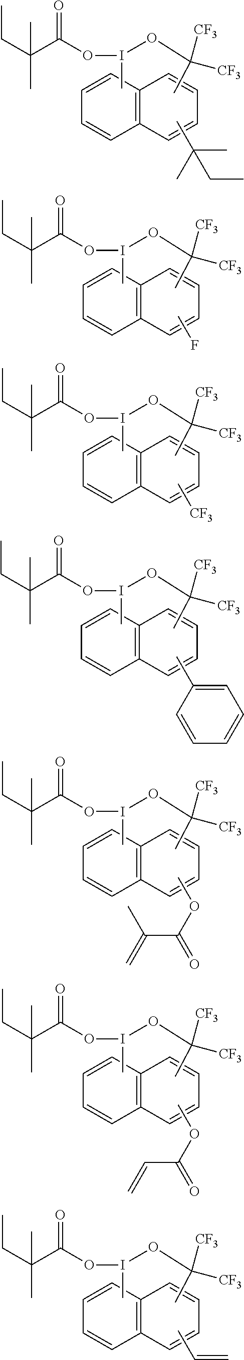

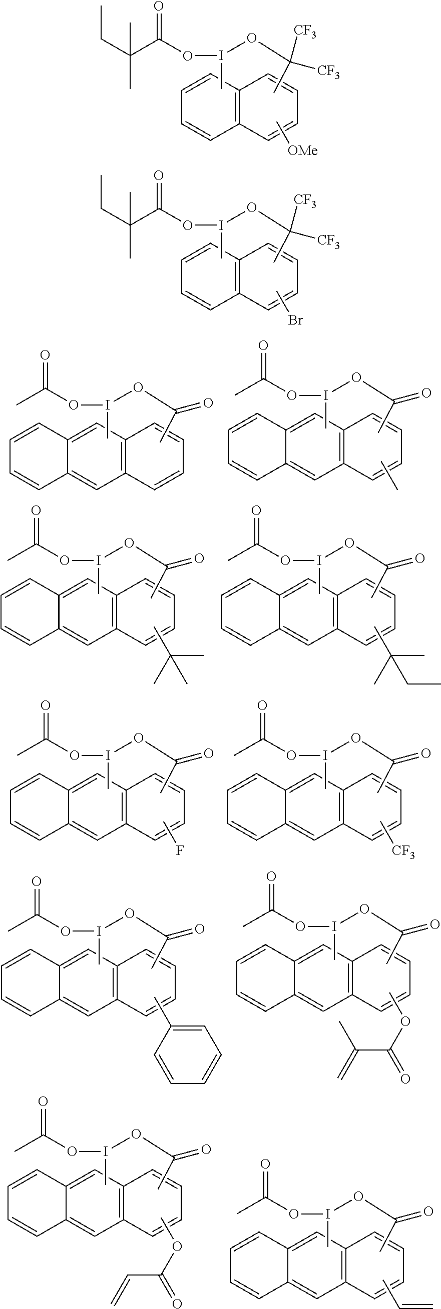

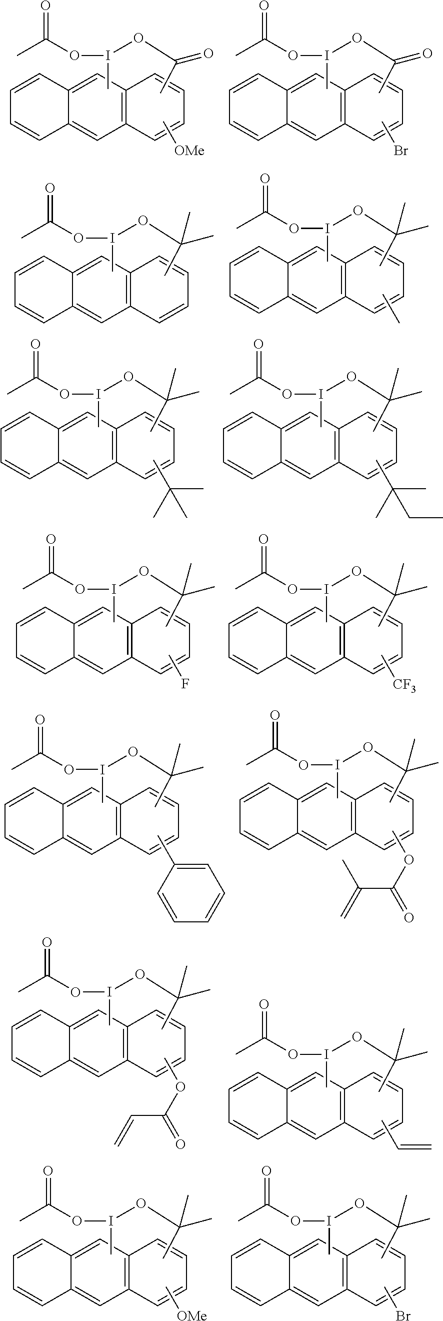

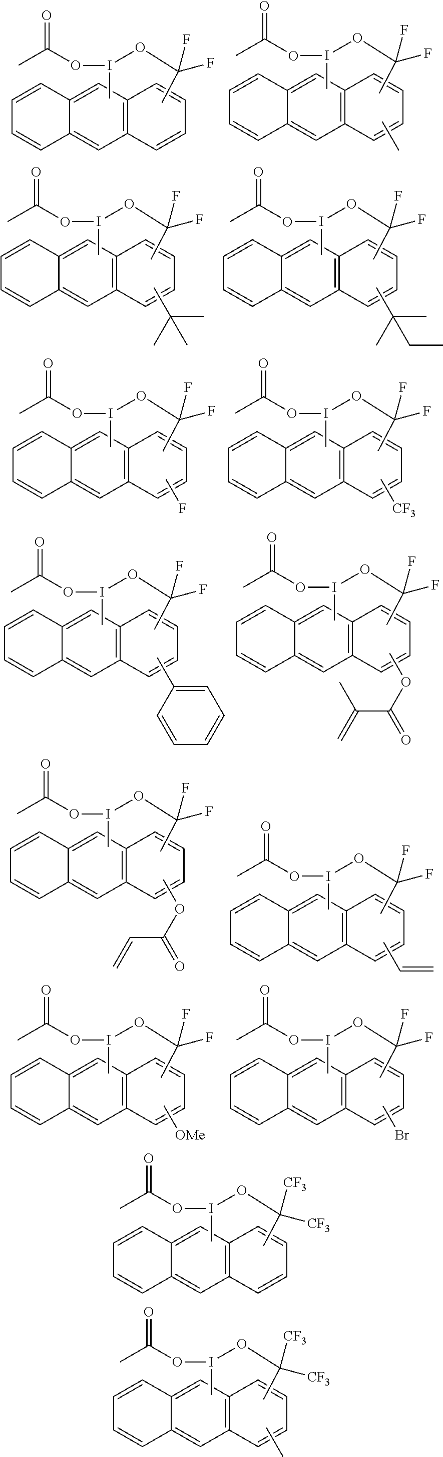

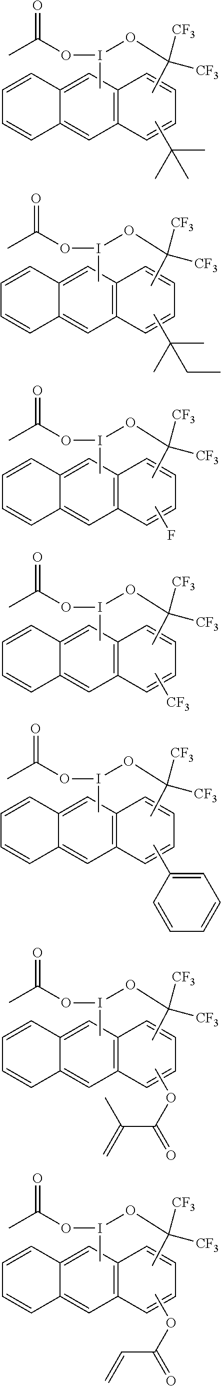

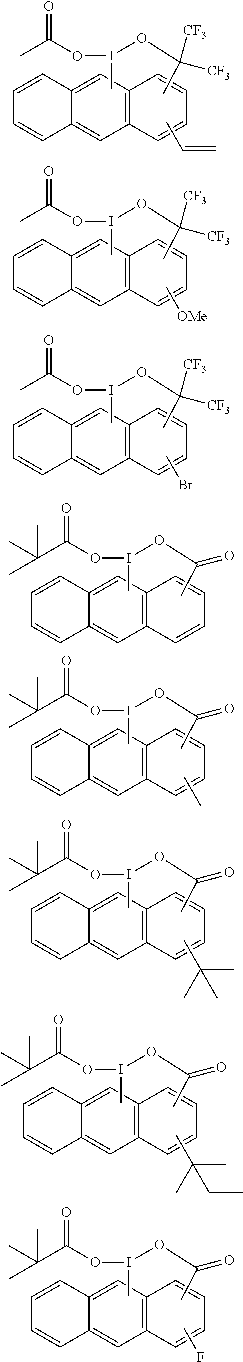

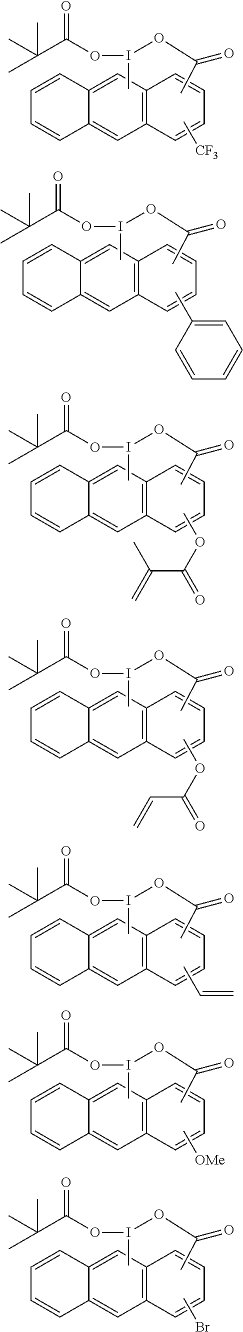

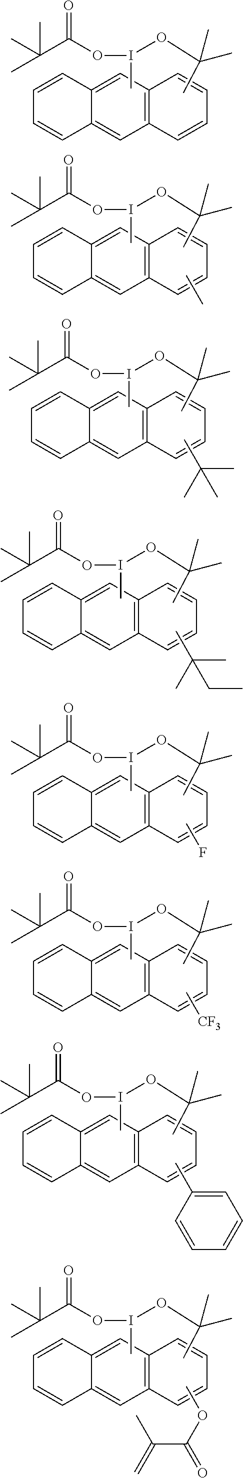

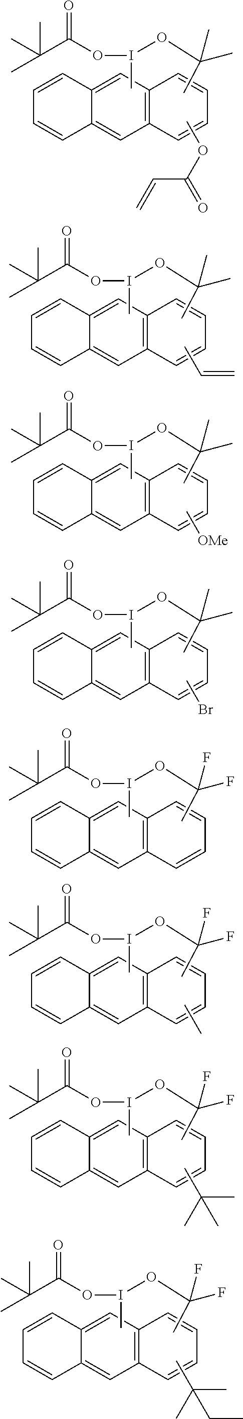

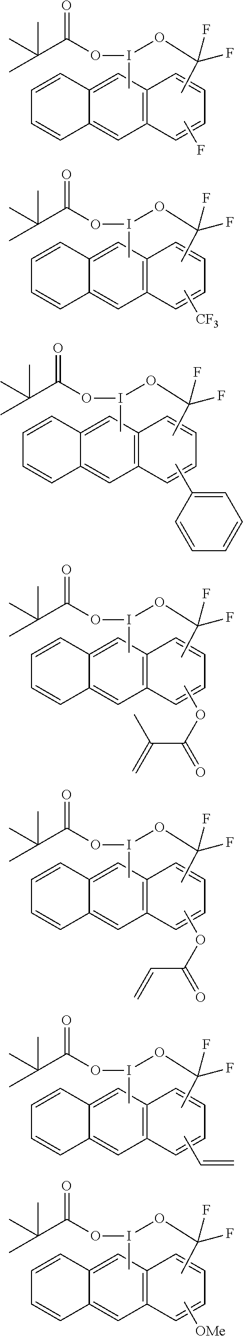

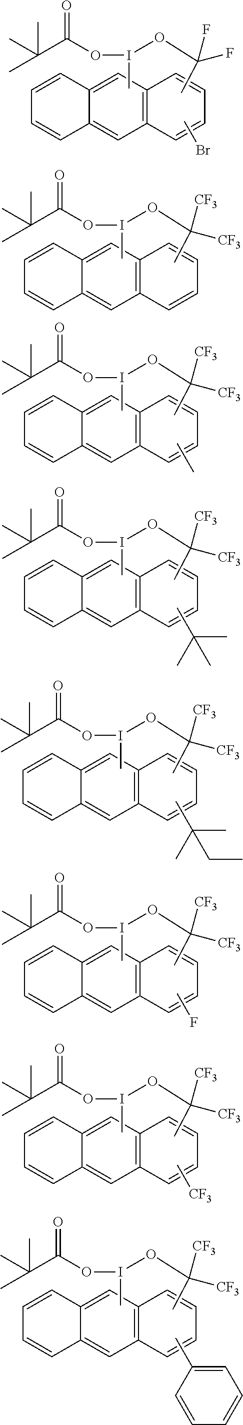

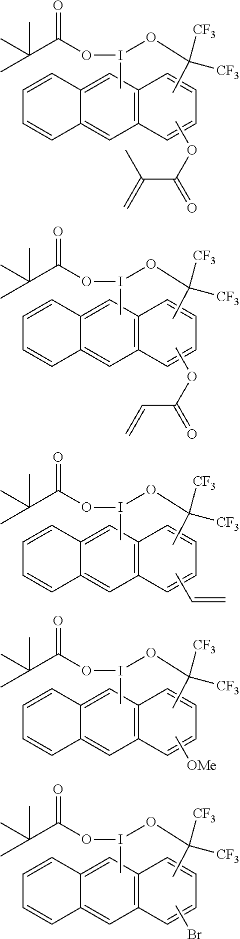

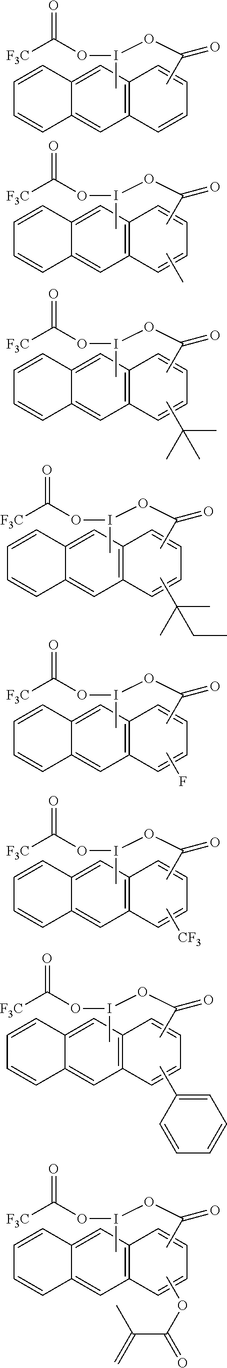

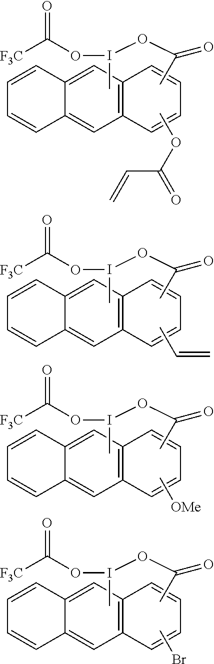

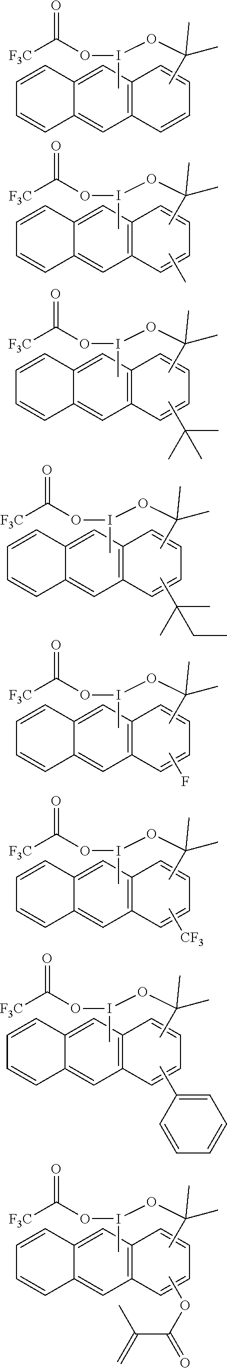

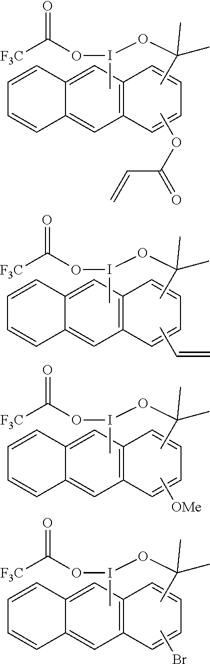

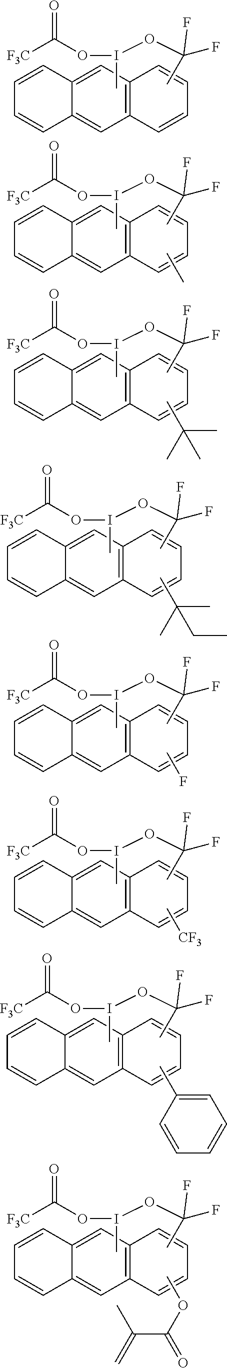

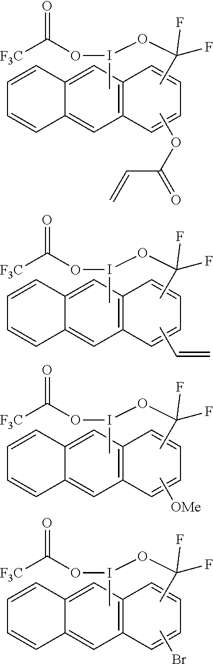

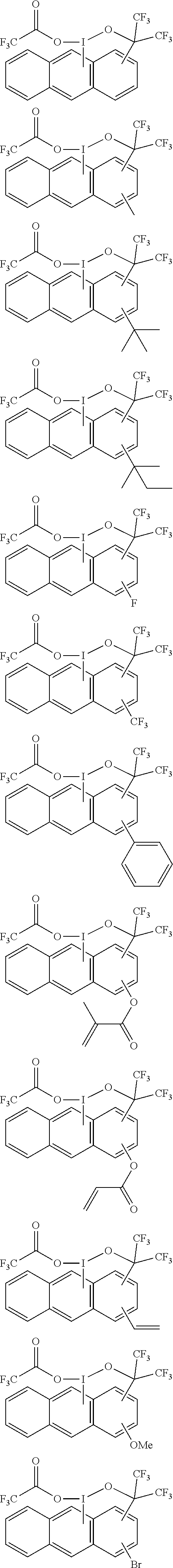

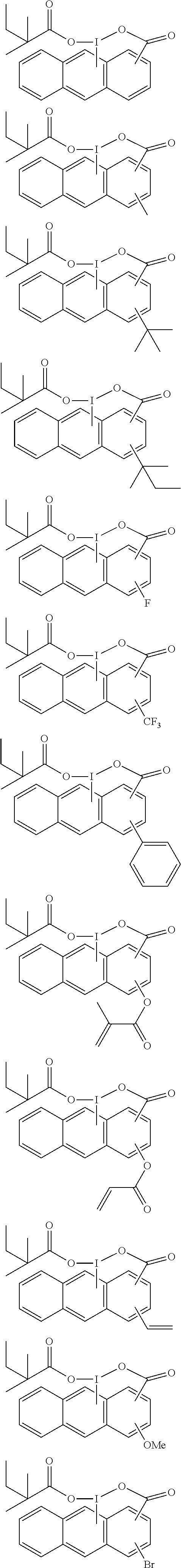

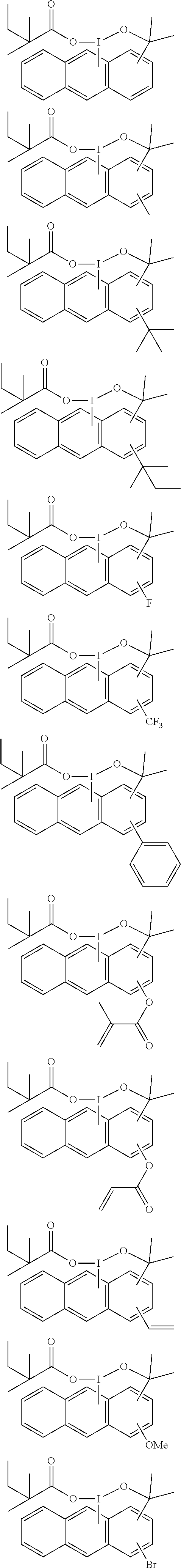

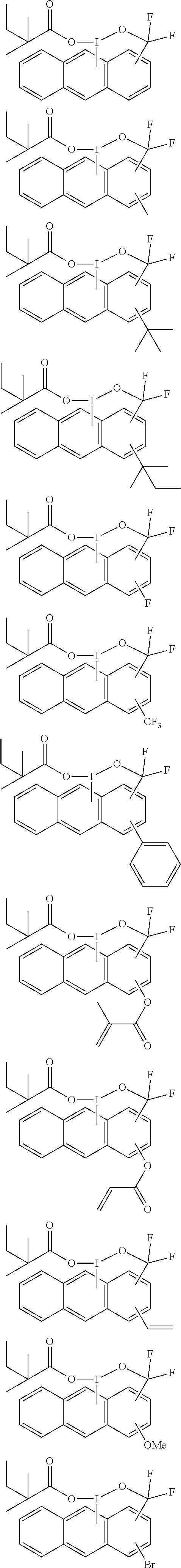

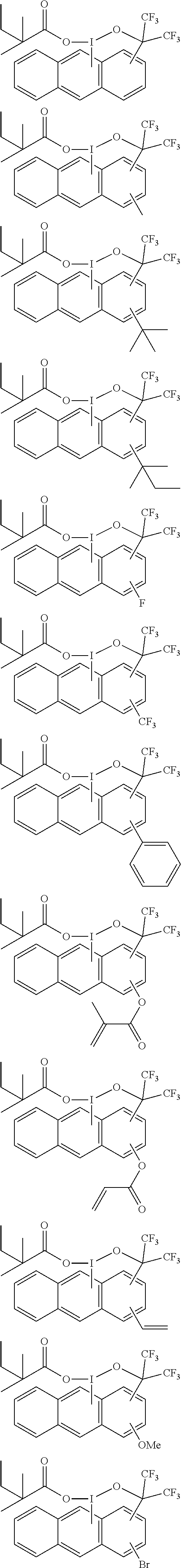

Examples of the hypervalent iodine compound having the formula (5) are shown

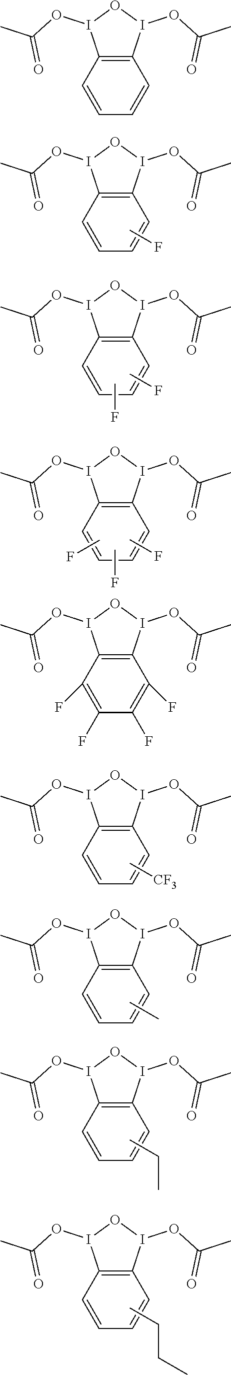

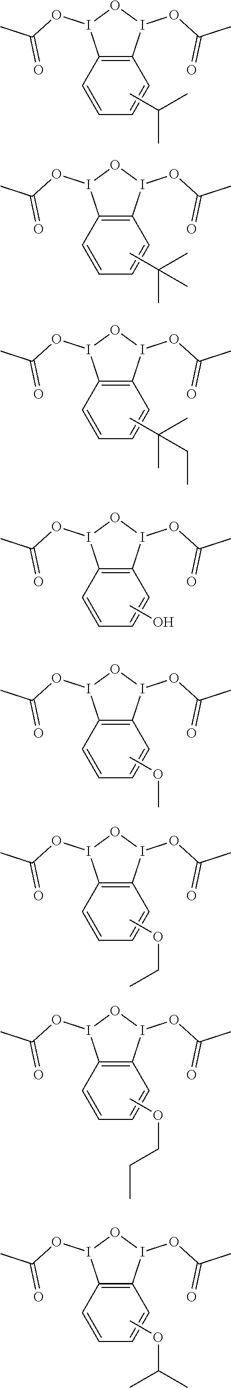

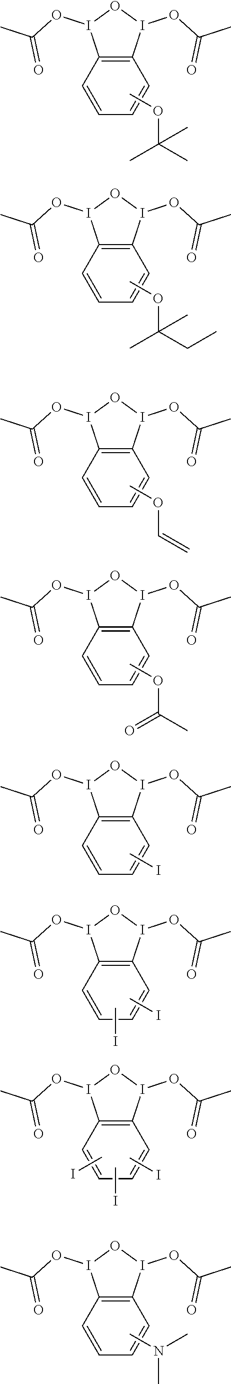

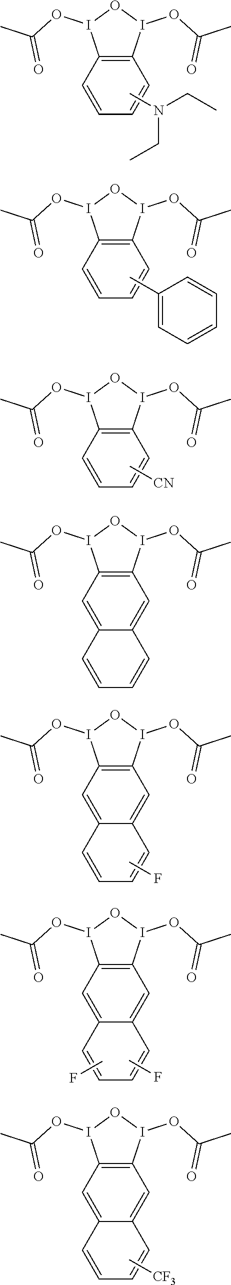

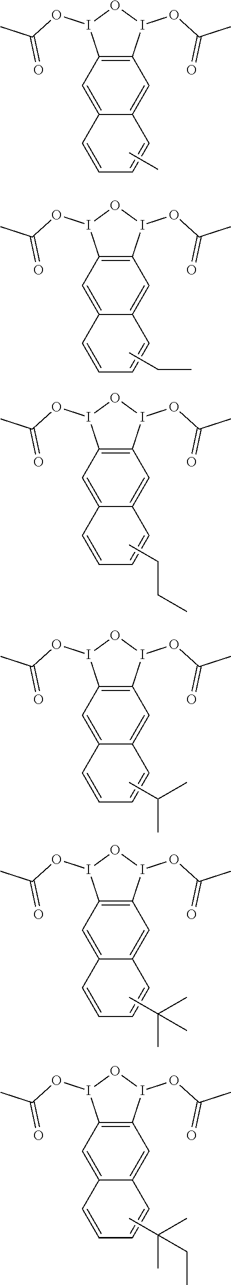

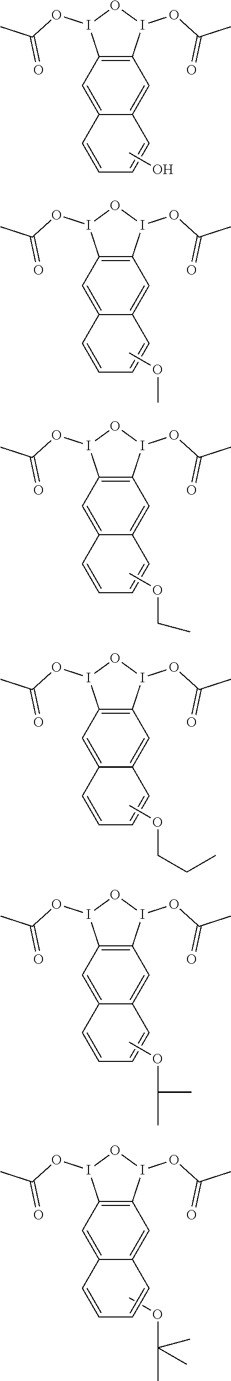

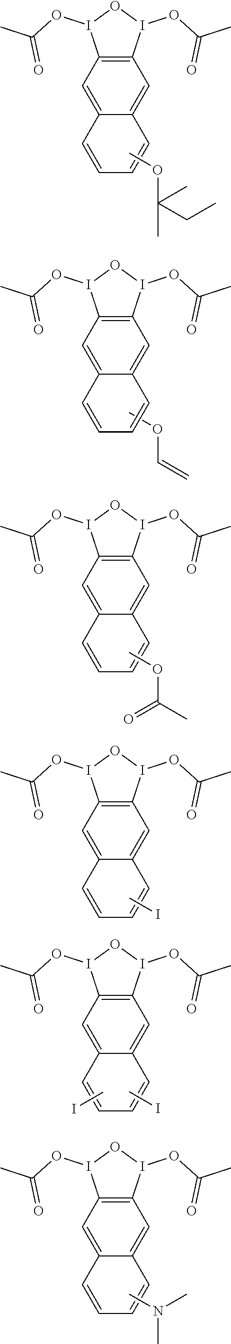

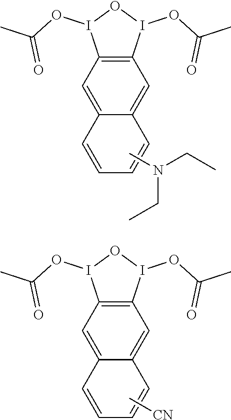

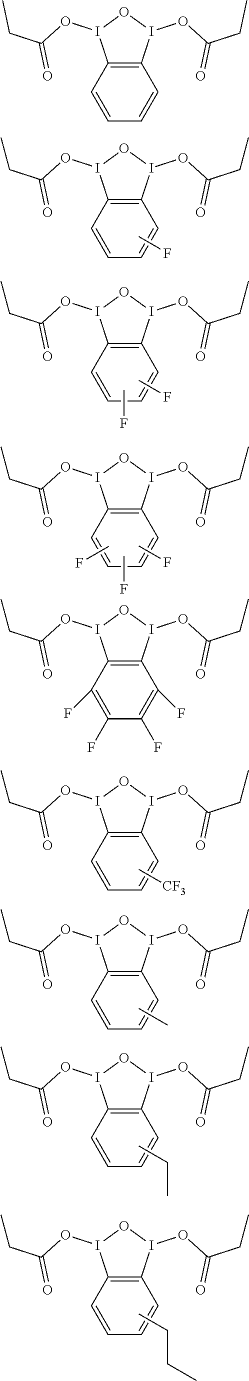

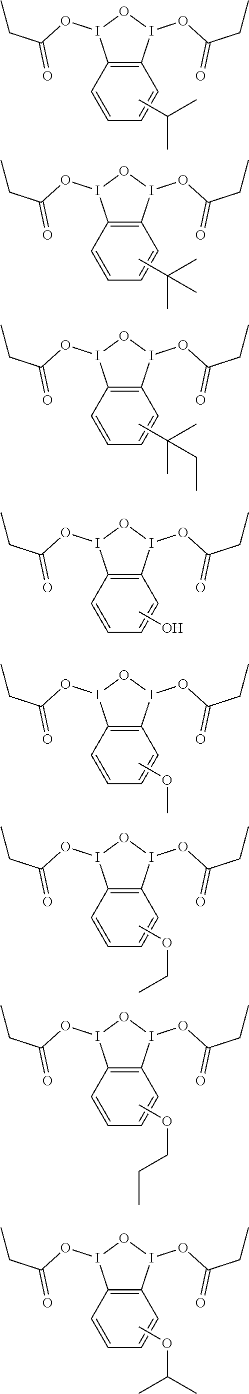

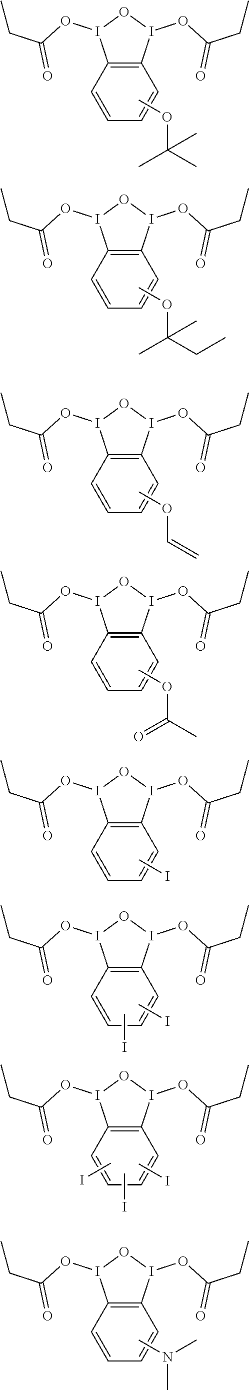

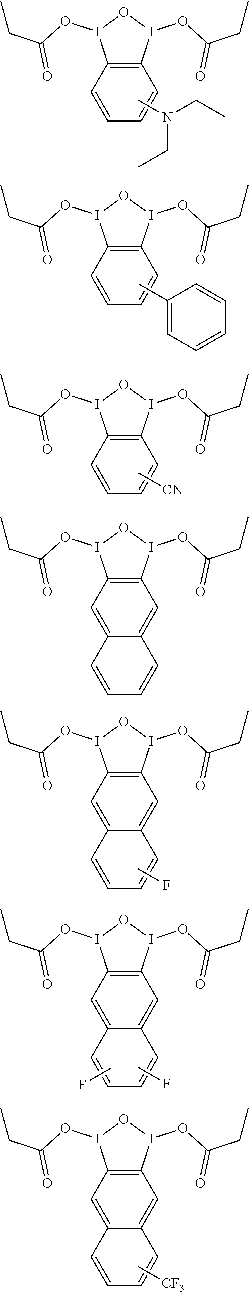

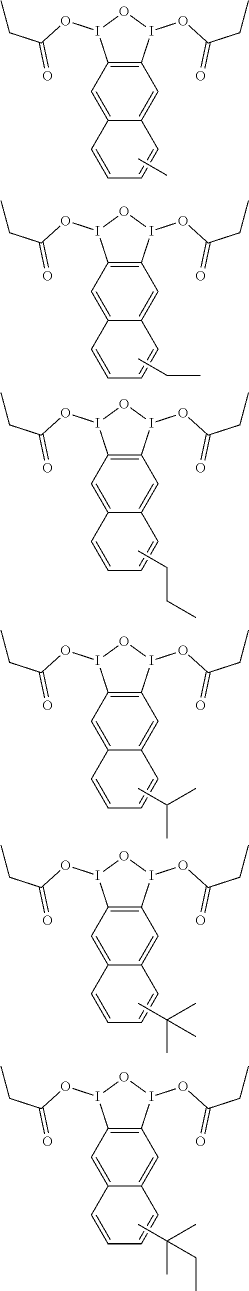

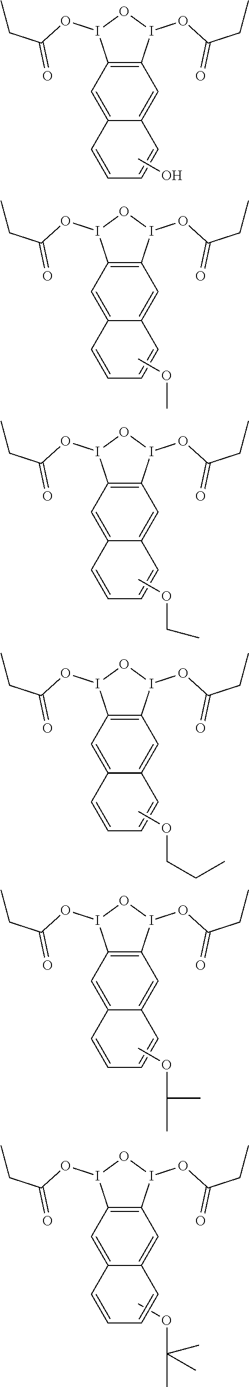

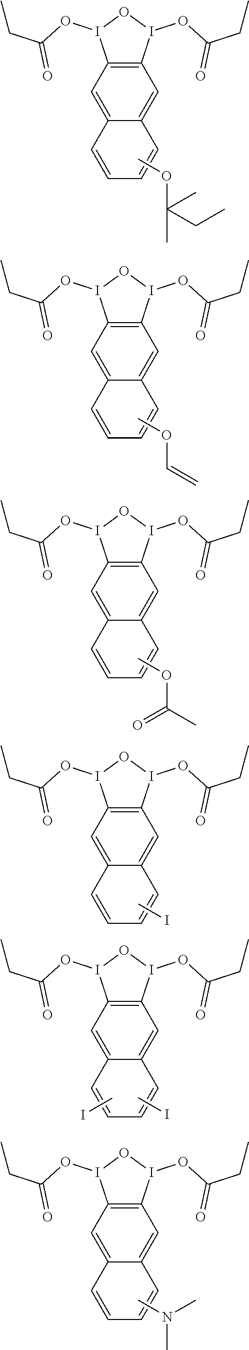

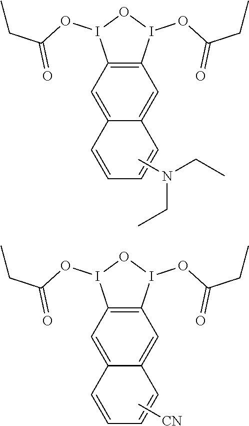

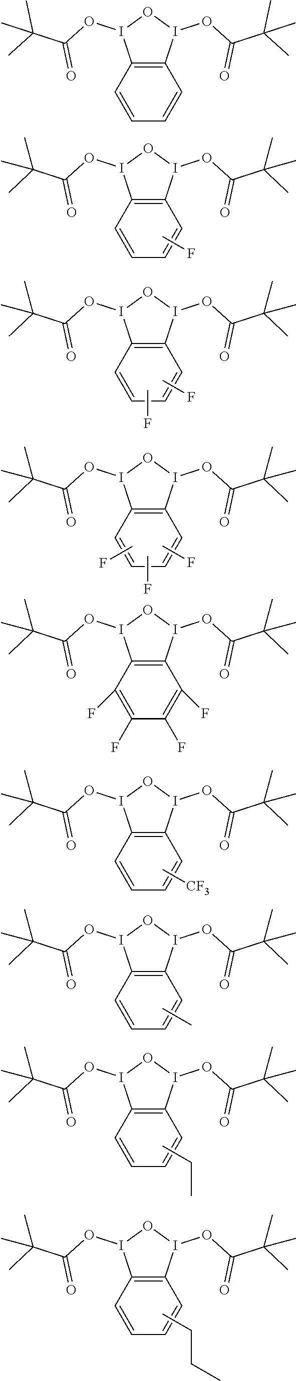

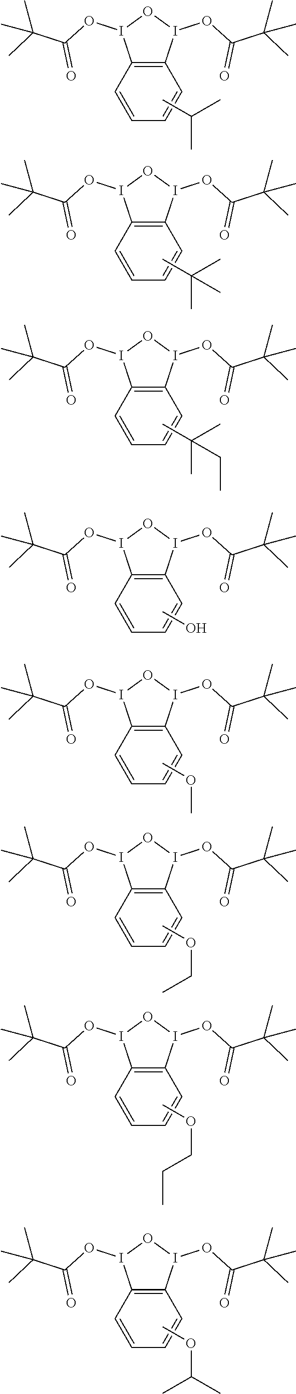

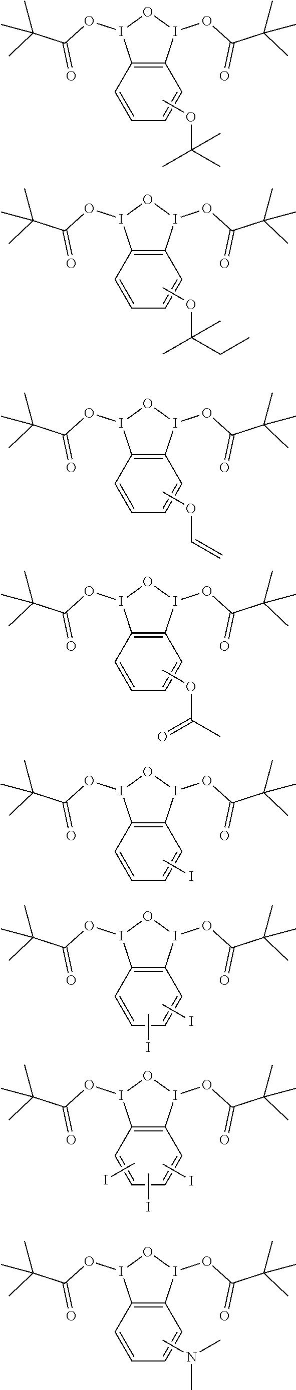

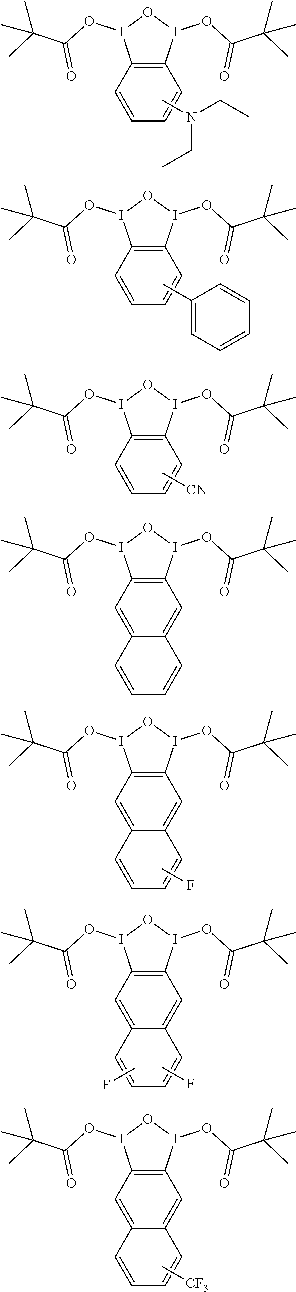

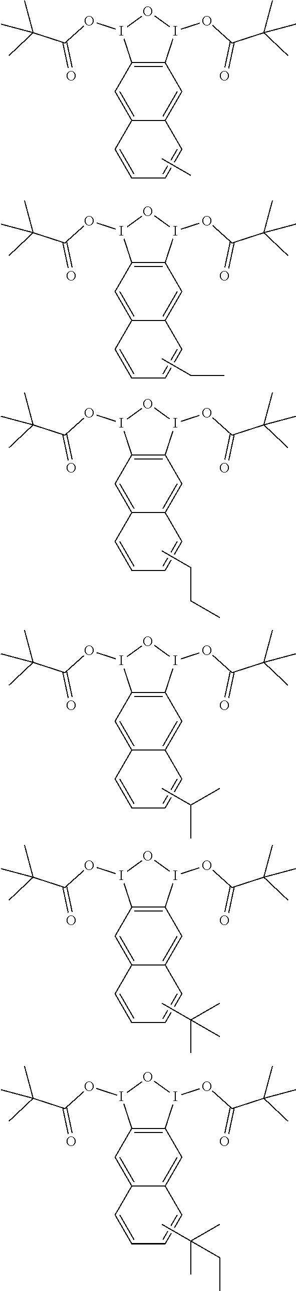

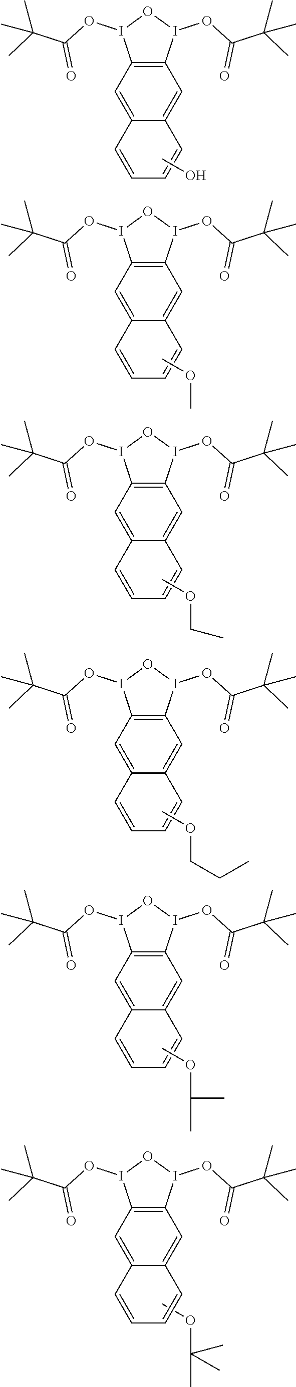

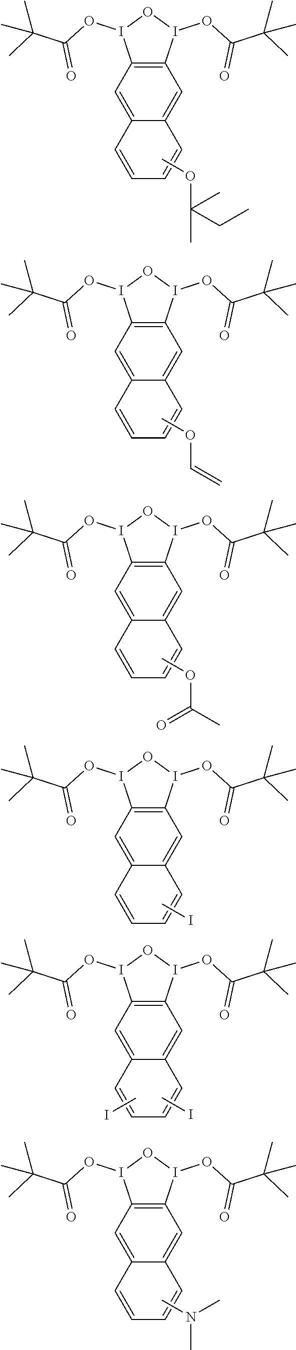

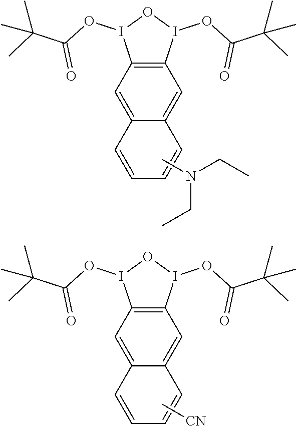

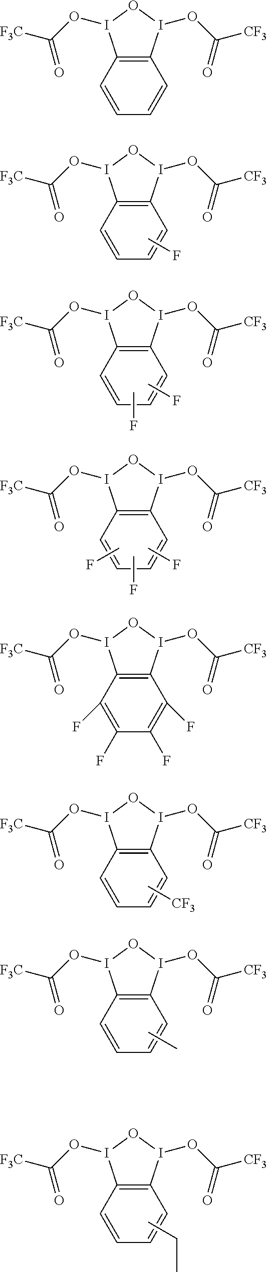

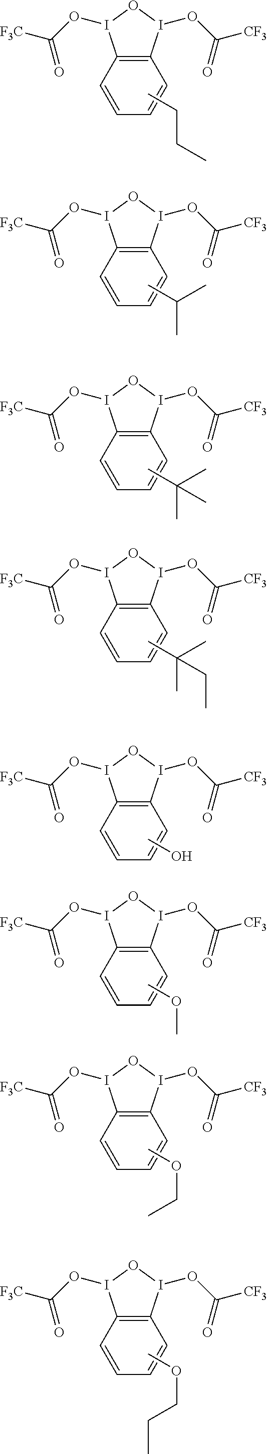

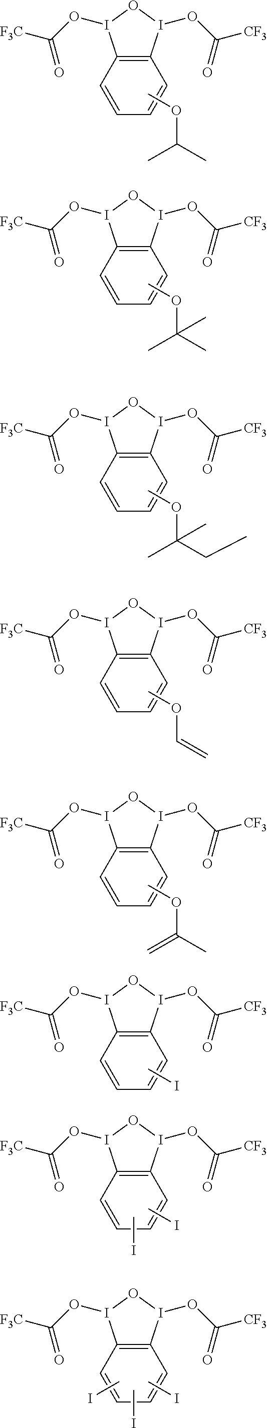

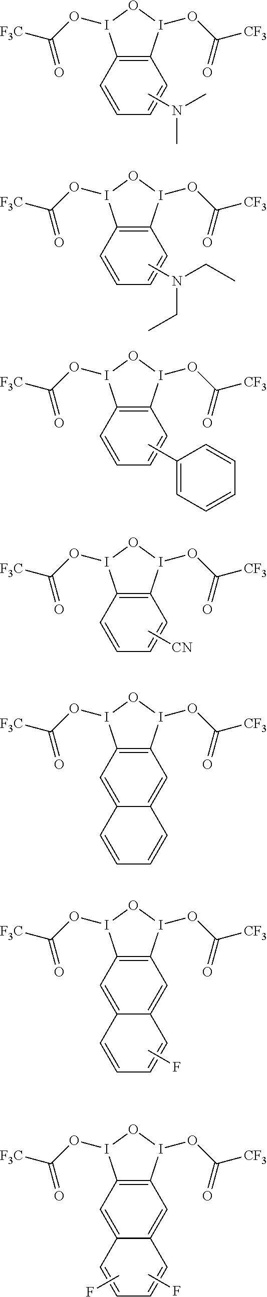

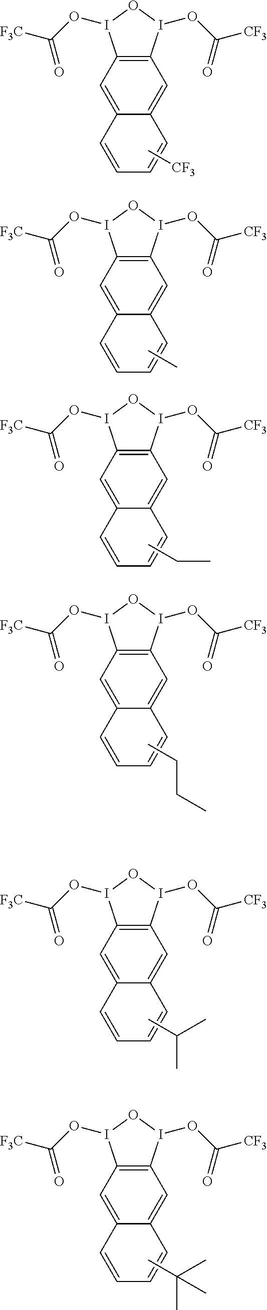

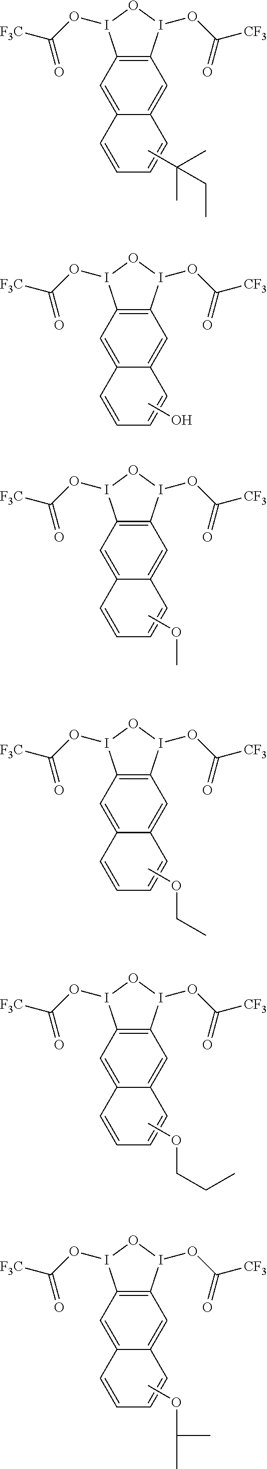

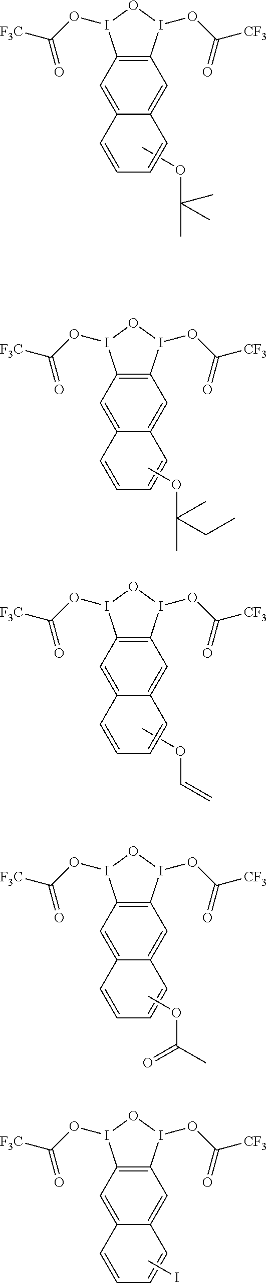

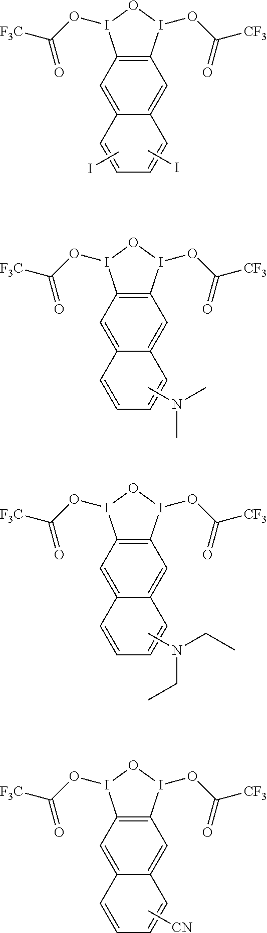

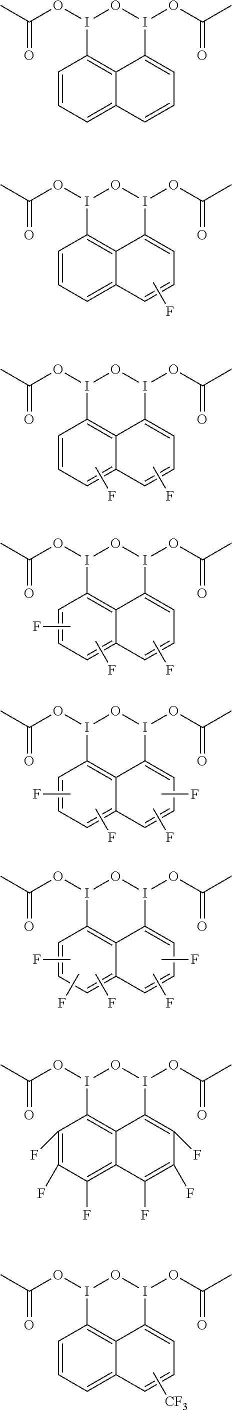

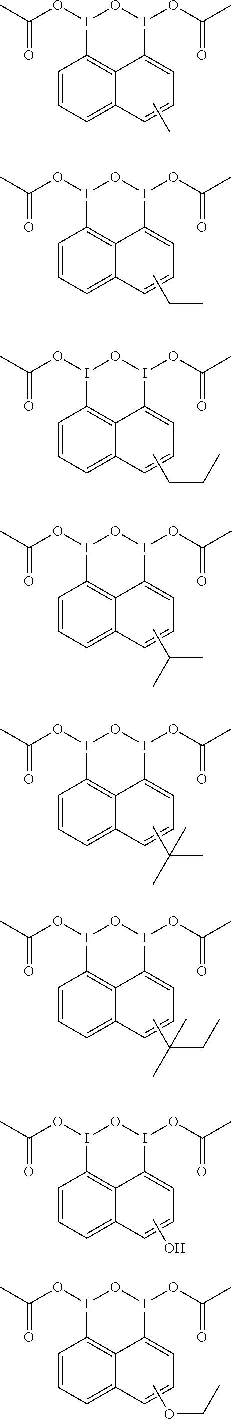

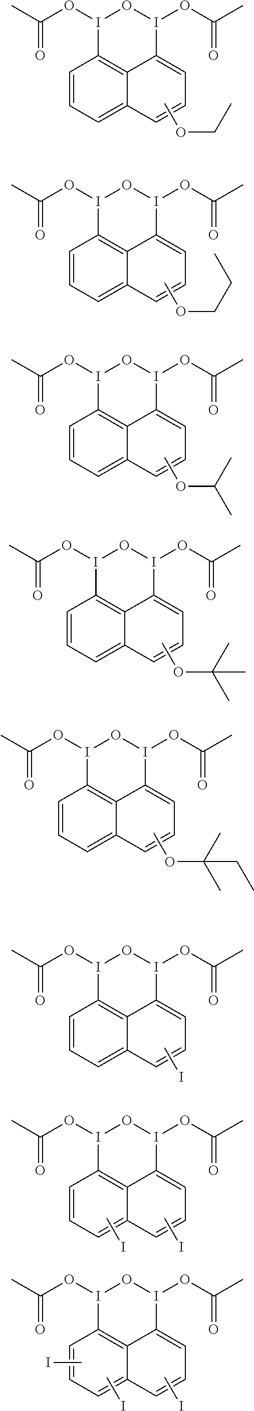

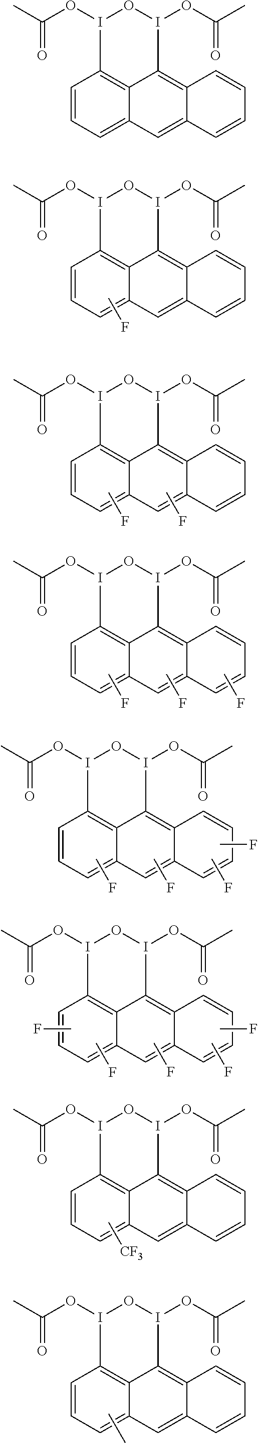

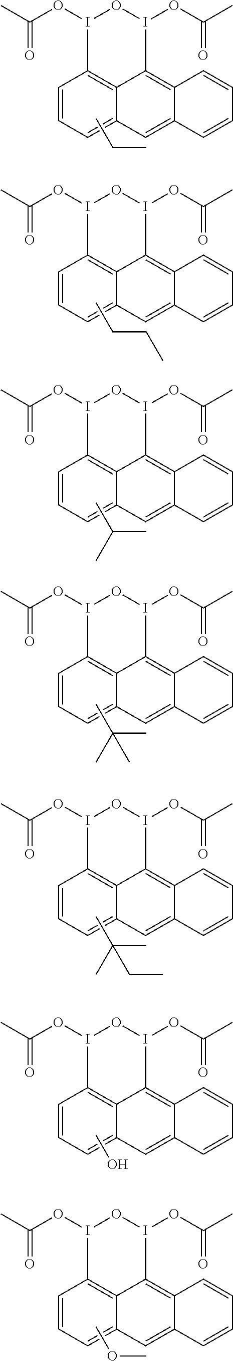

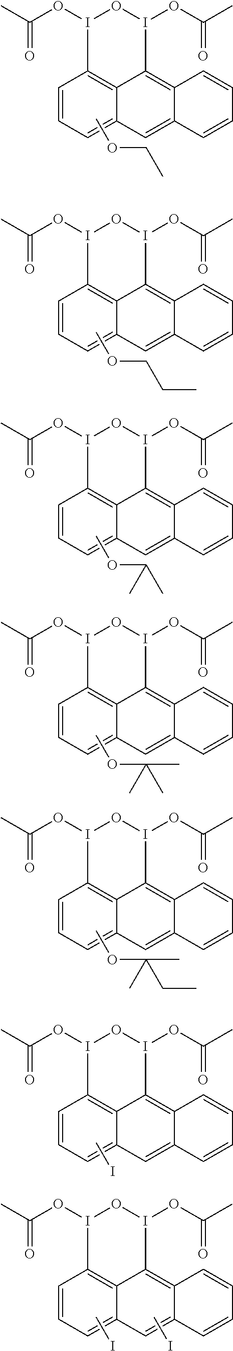

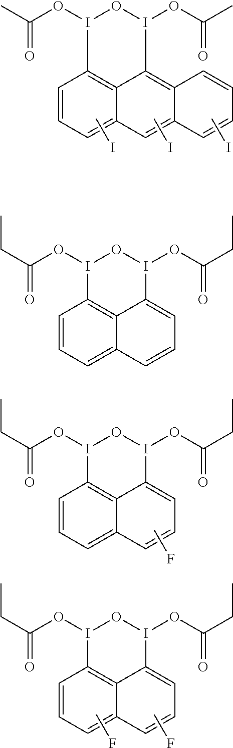

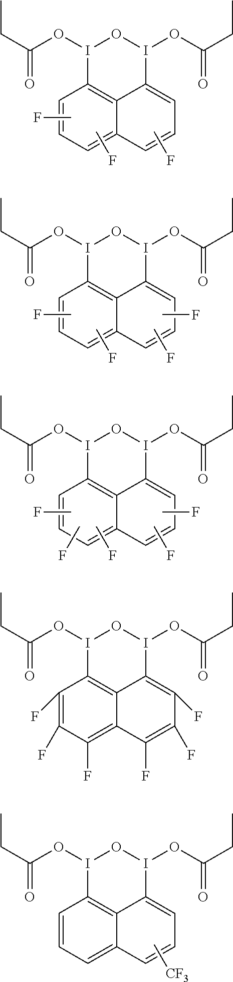

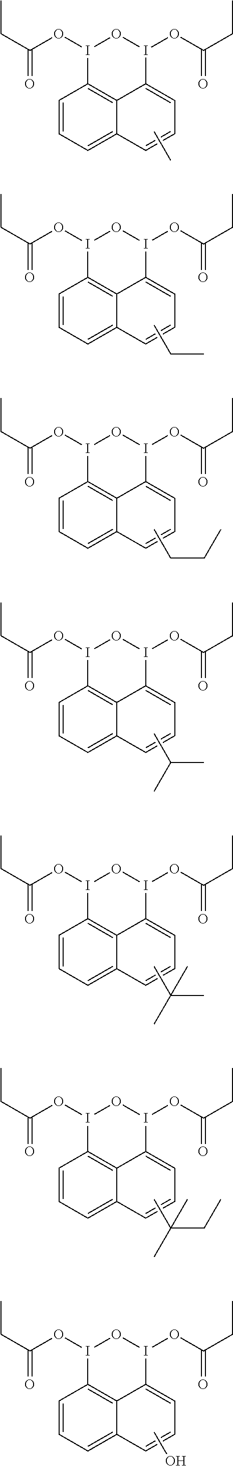

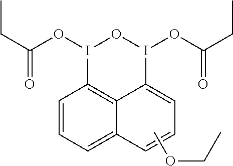

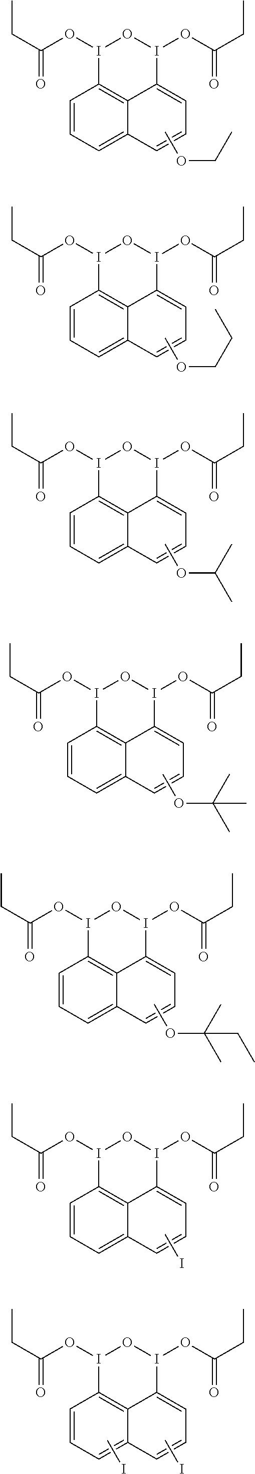

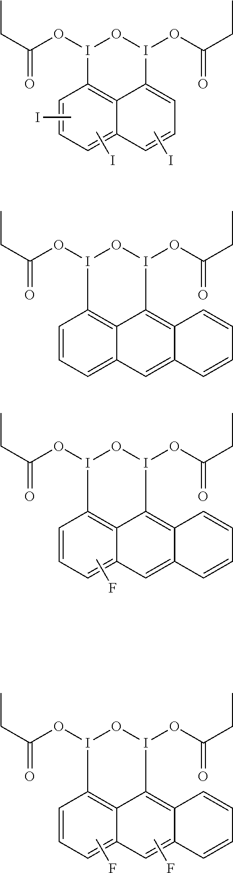

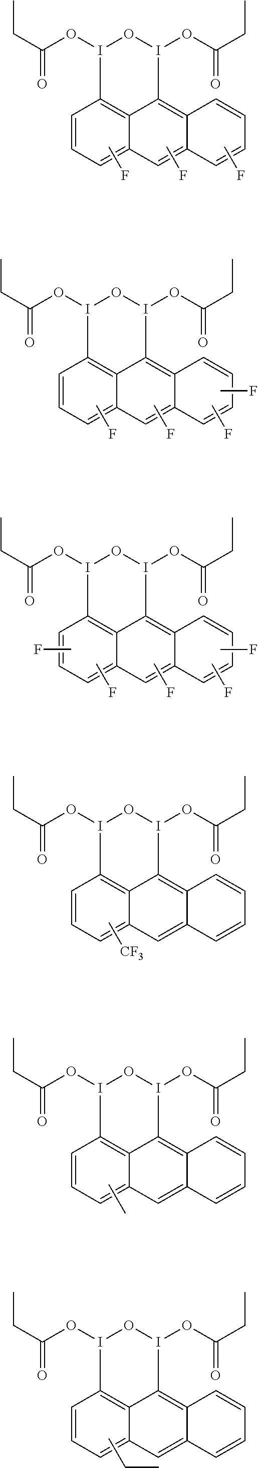

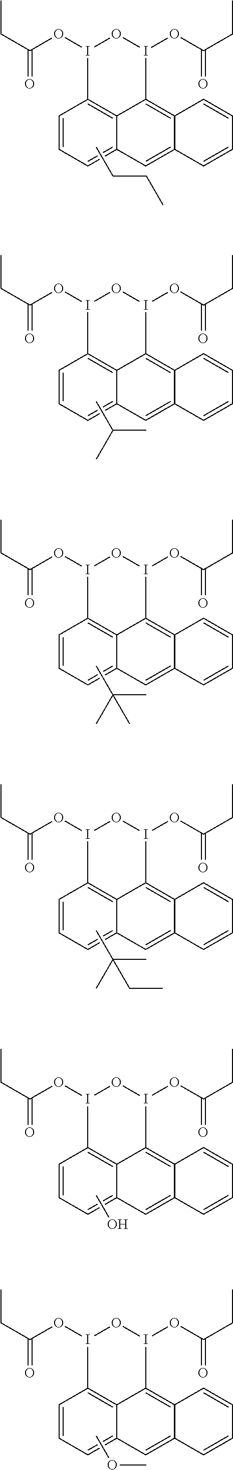

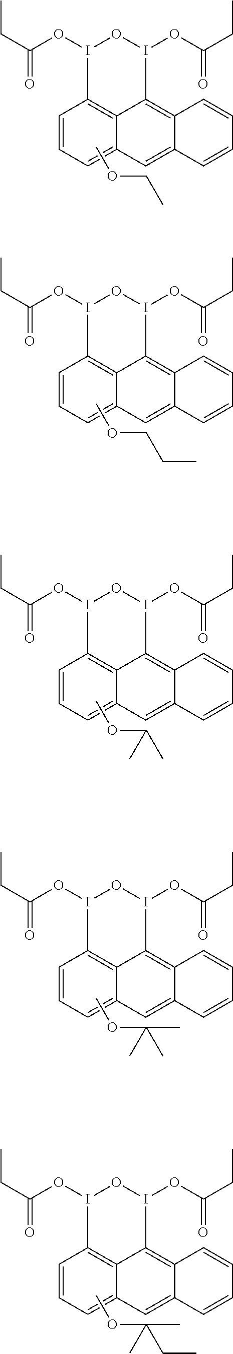

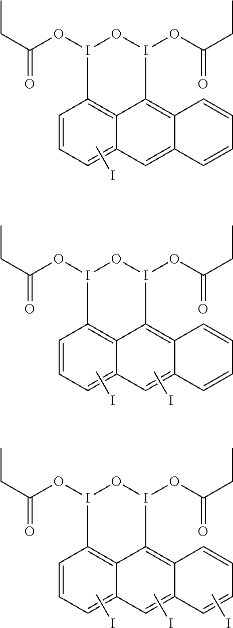

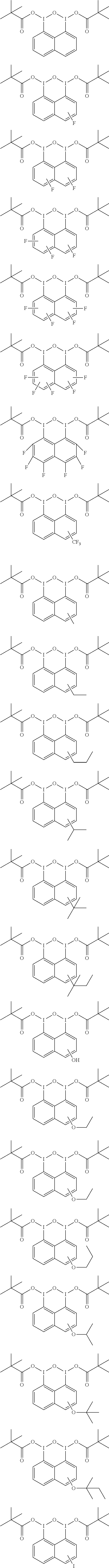

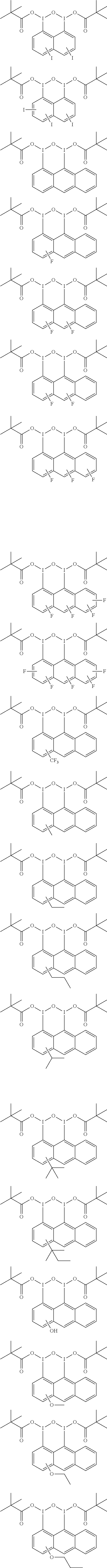

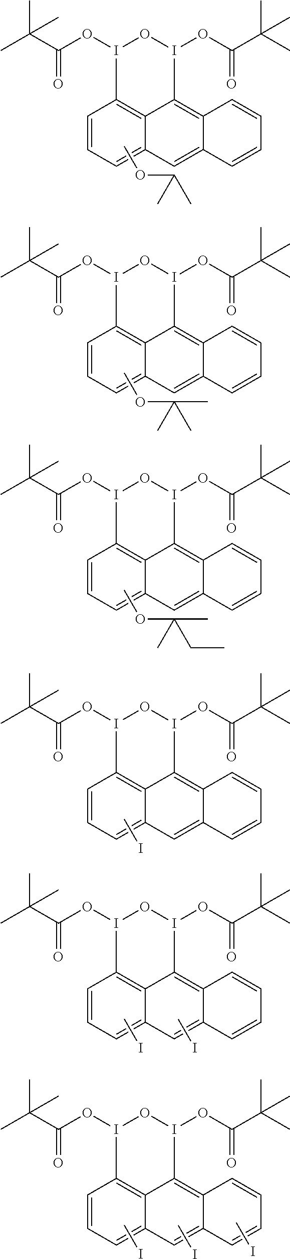

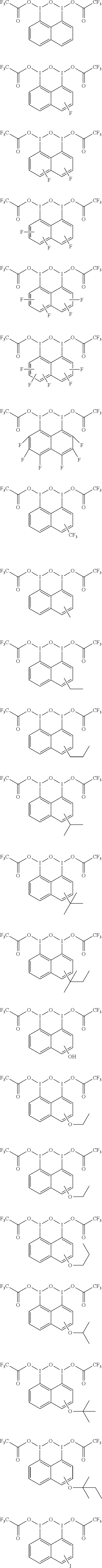

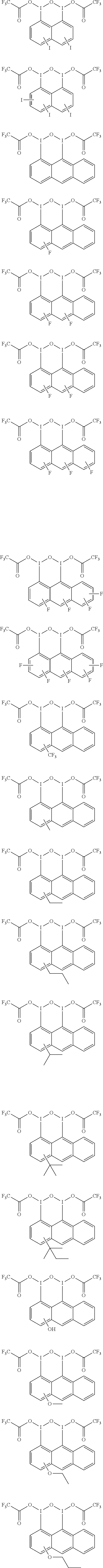

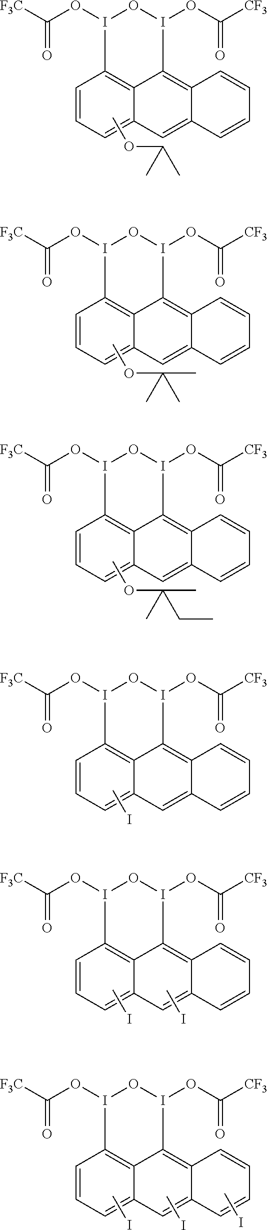

Examples of the hypervalent iodine compound having the formula (6) are shown below, but are not limited thereto. In the formulae, L¹ is the same as described above.

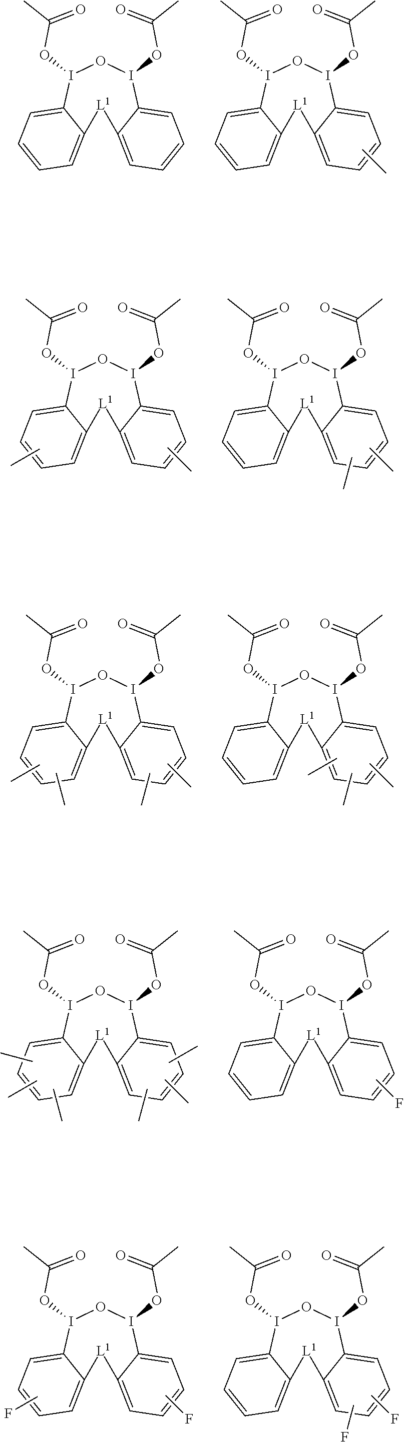

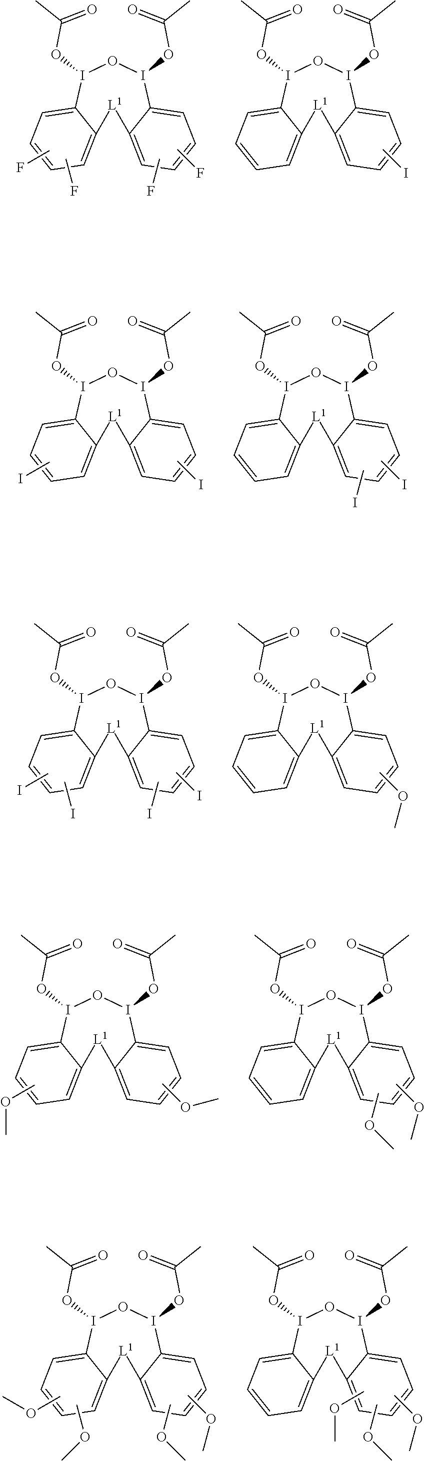

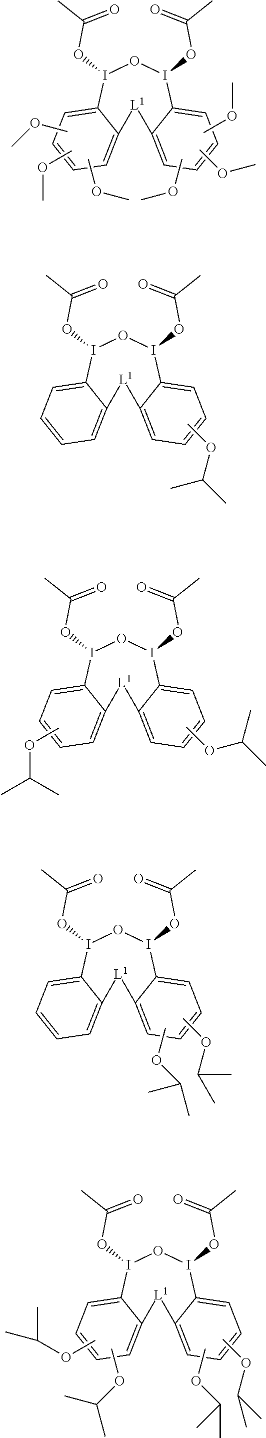

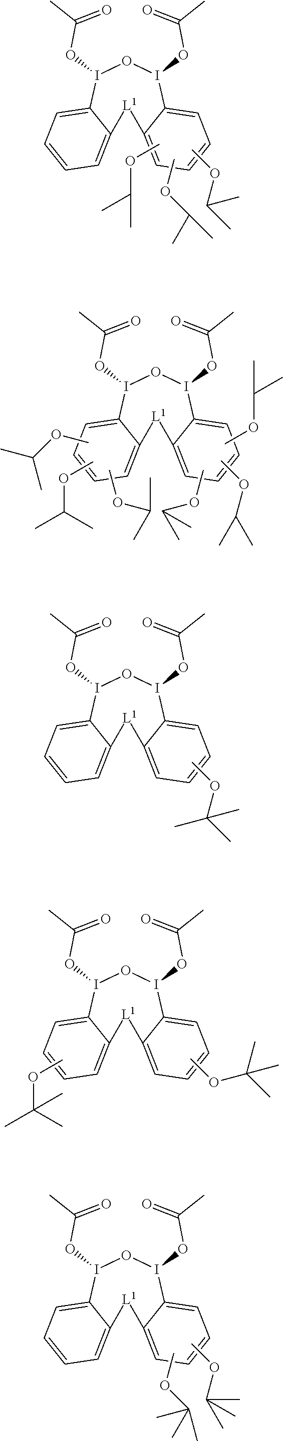

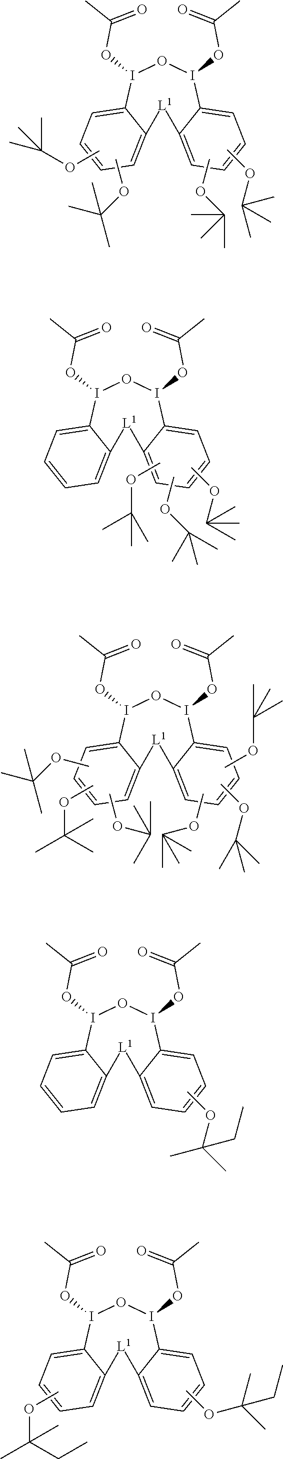

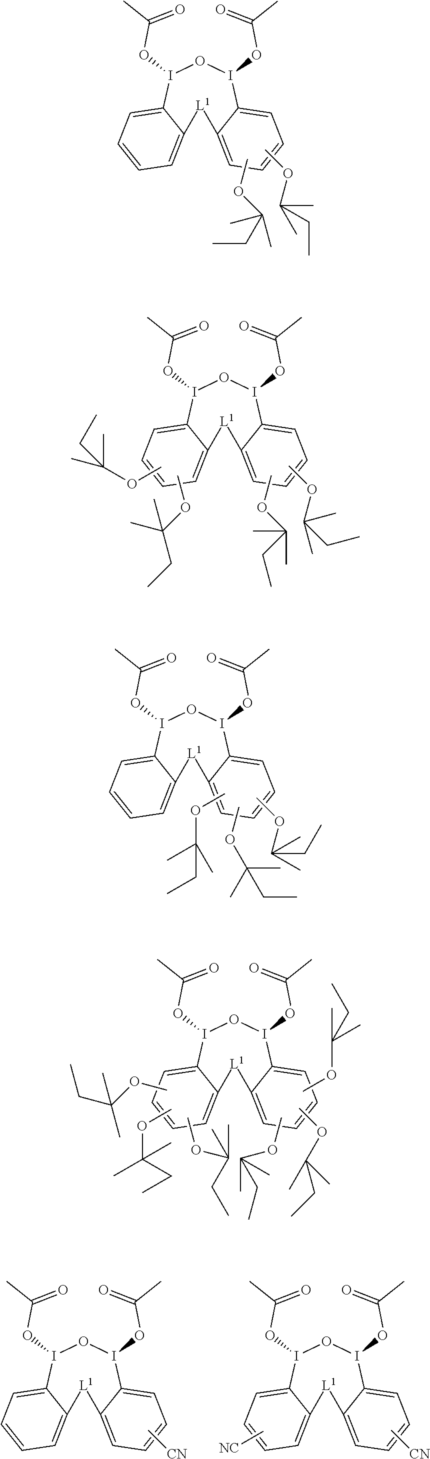

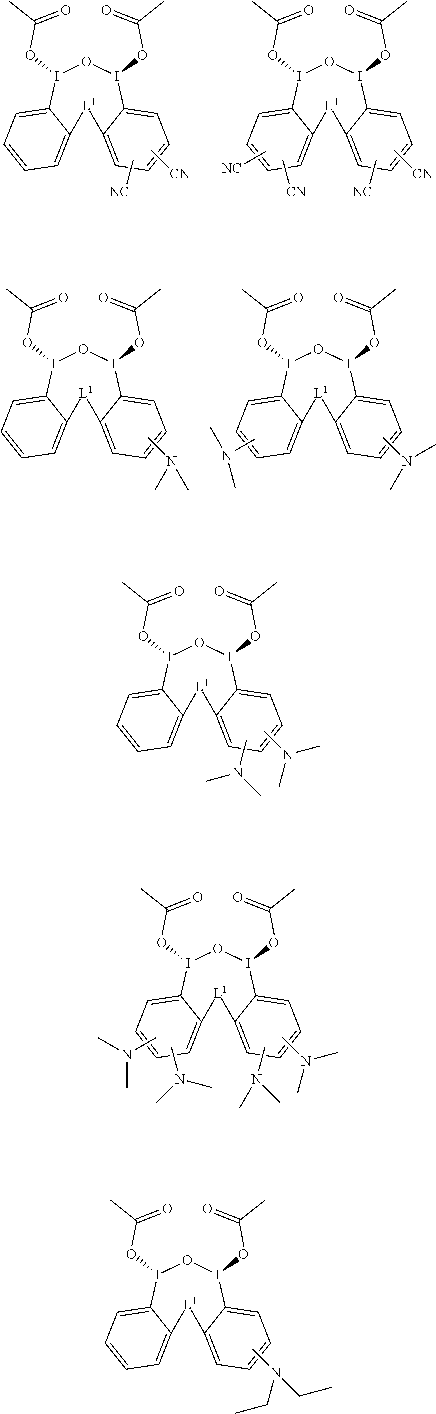

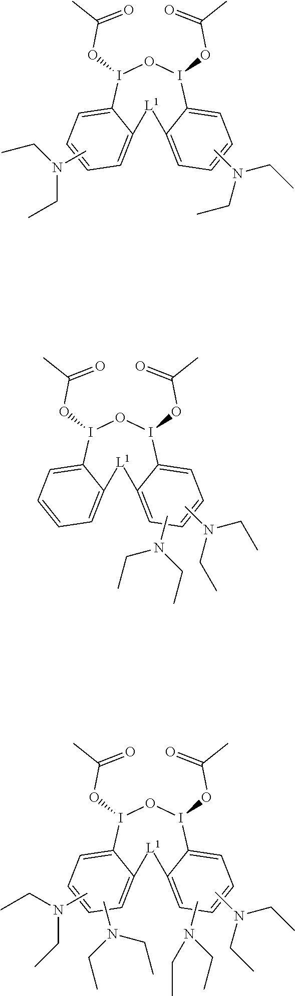

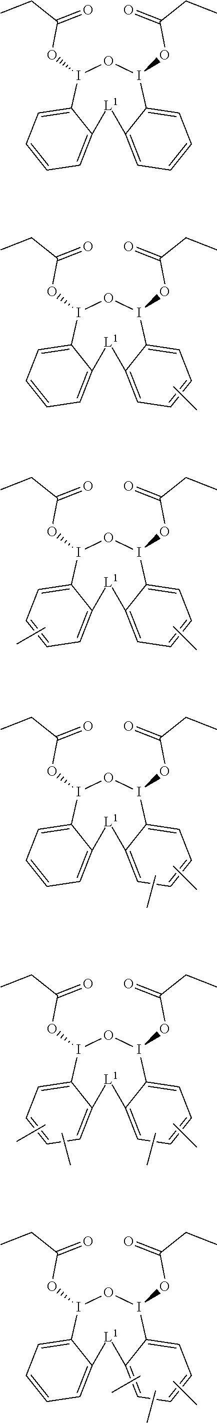

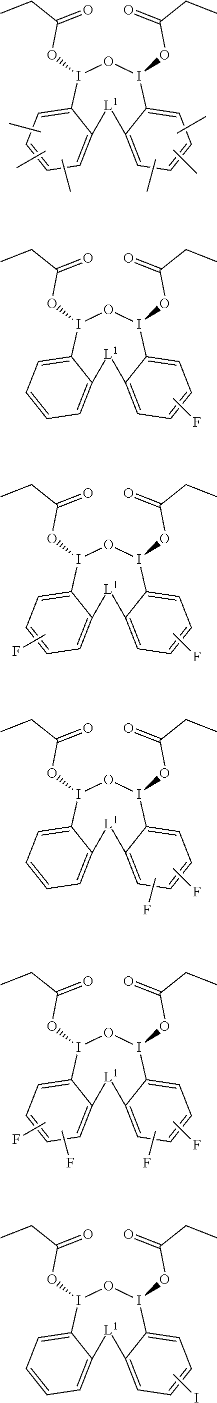

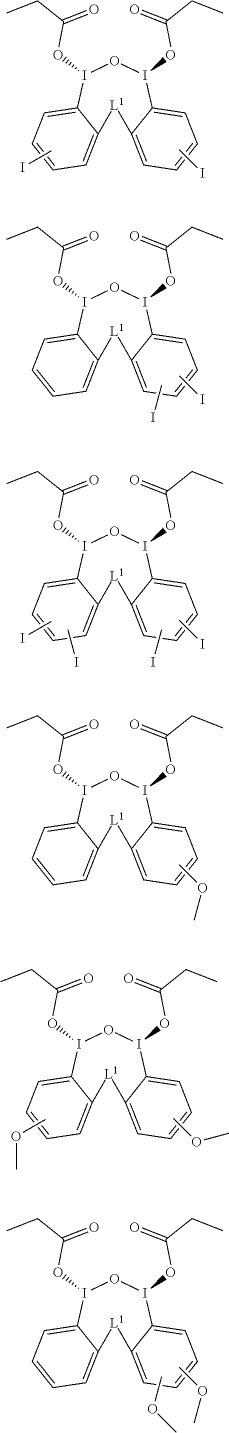

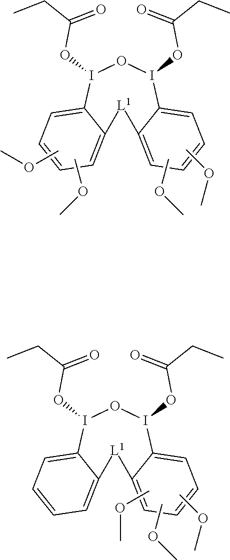

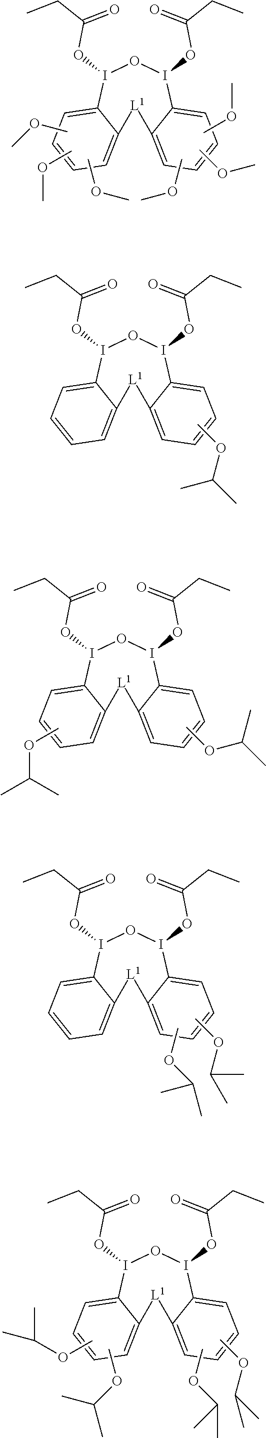

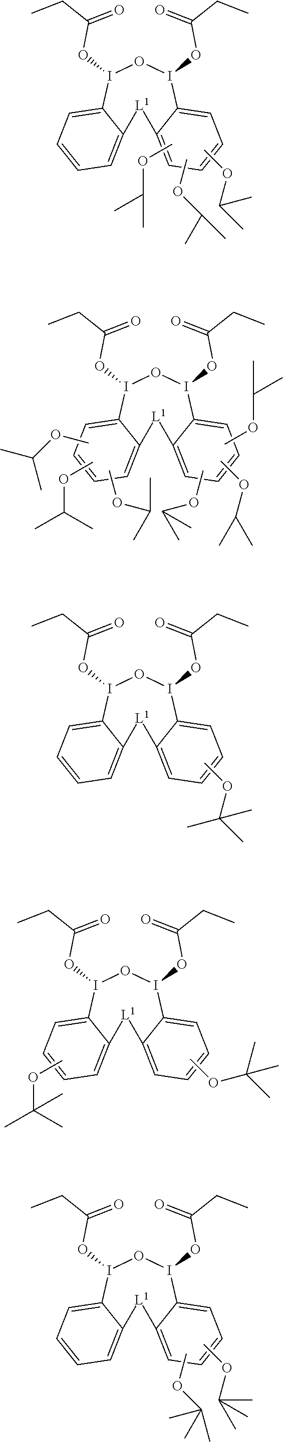

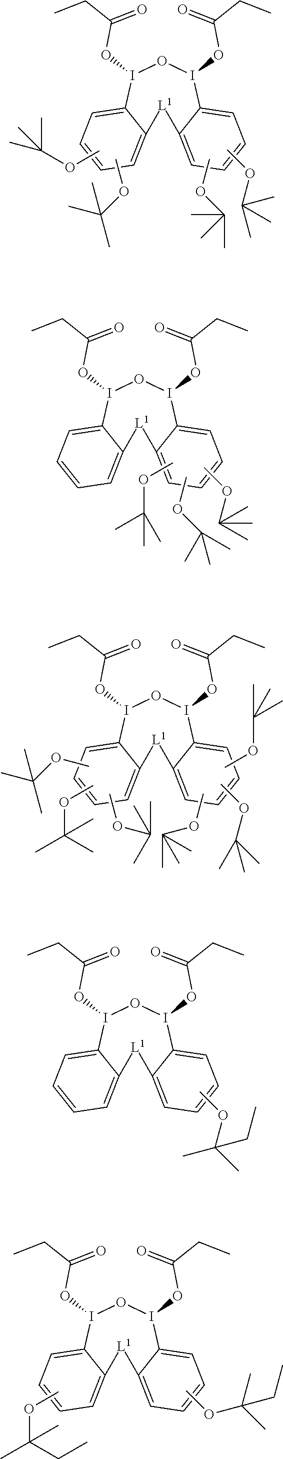

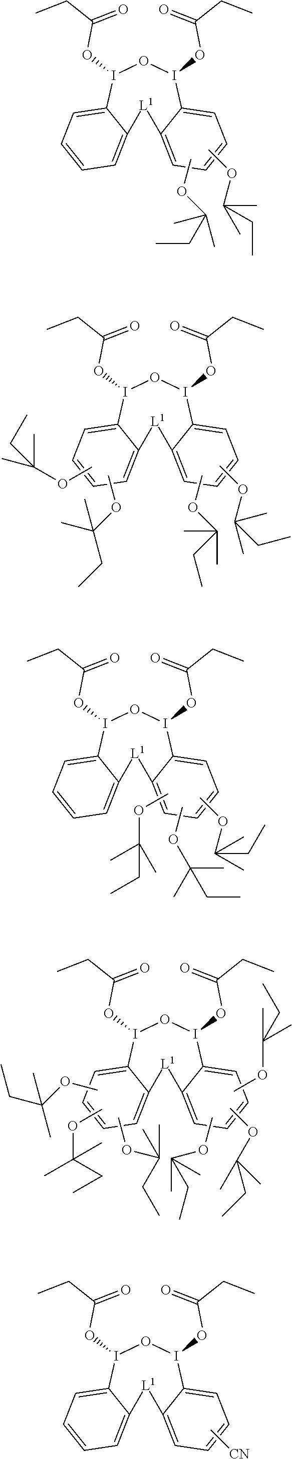

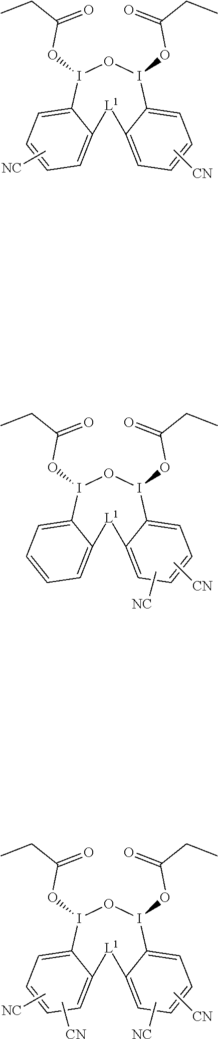

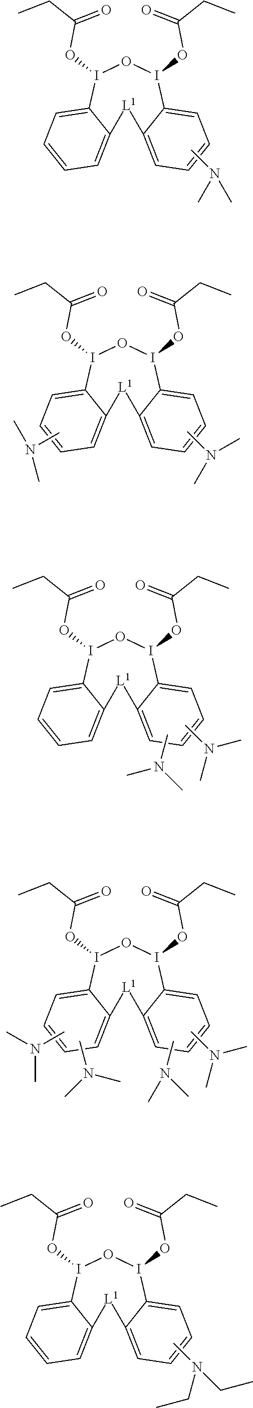

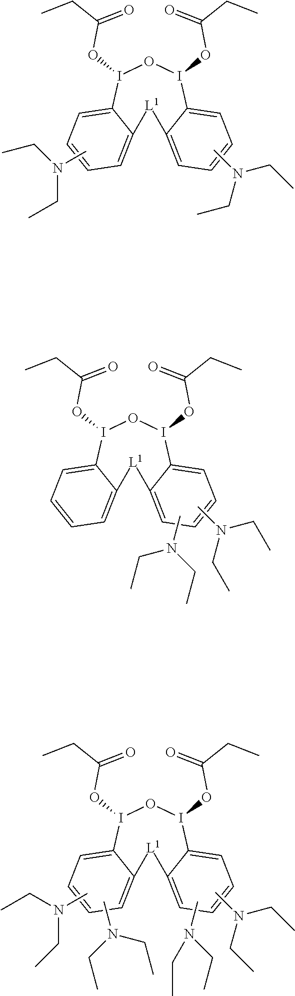

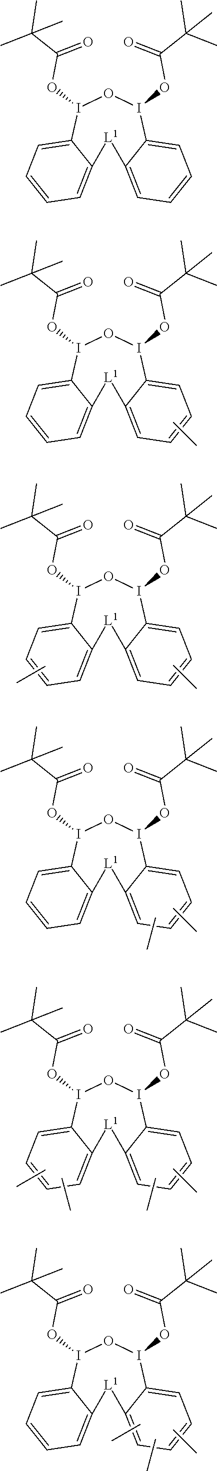

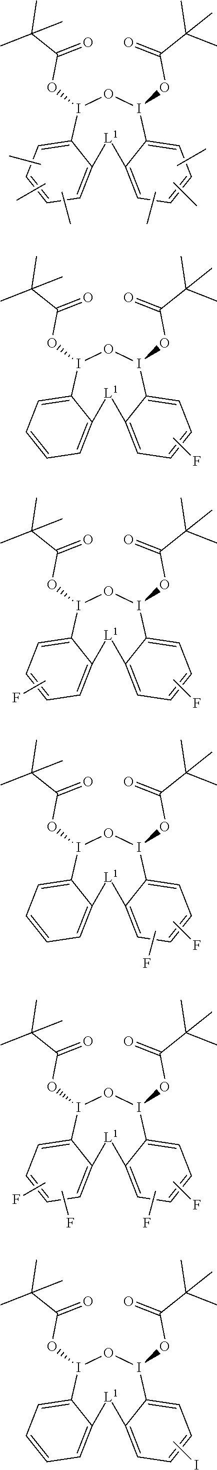

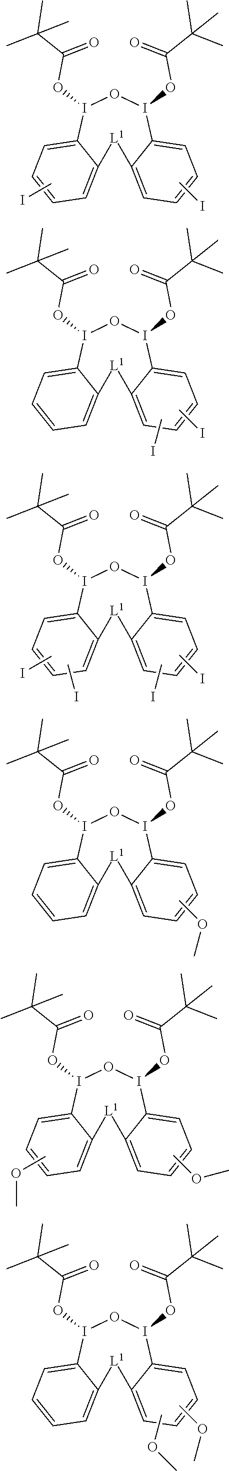

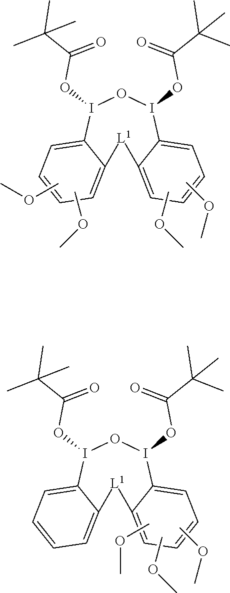

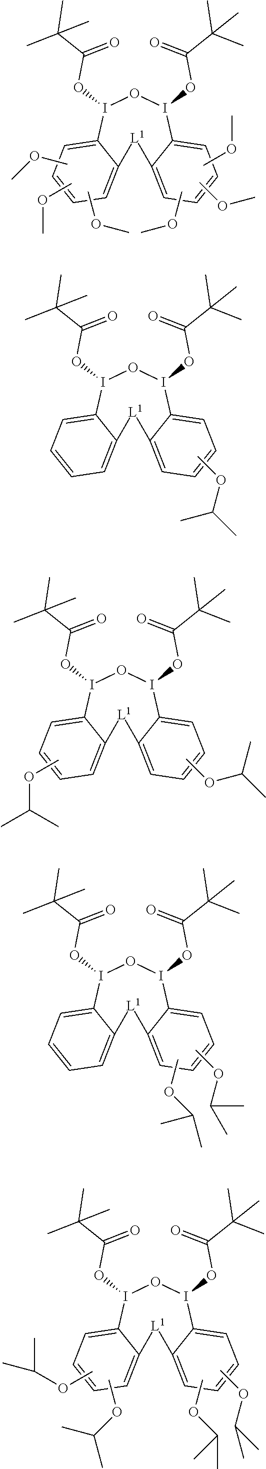

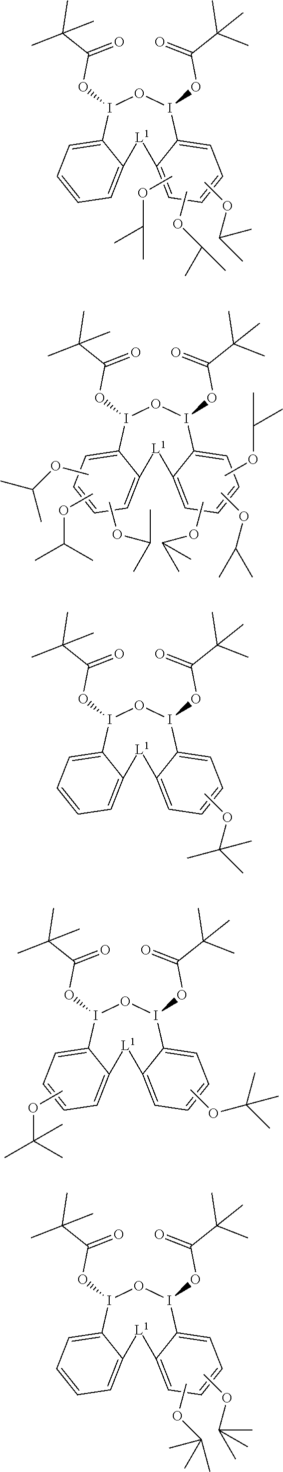

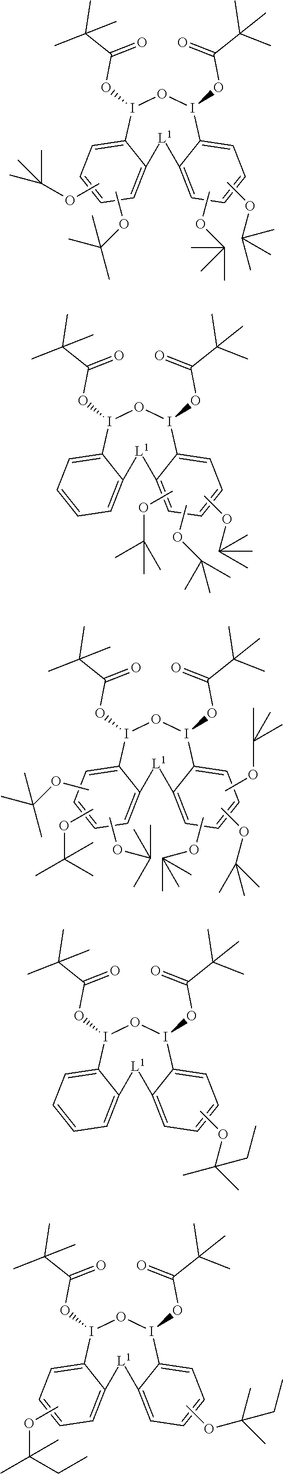

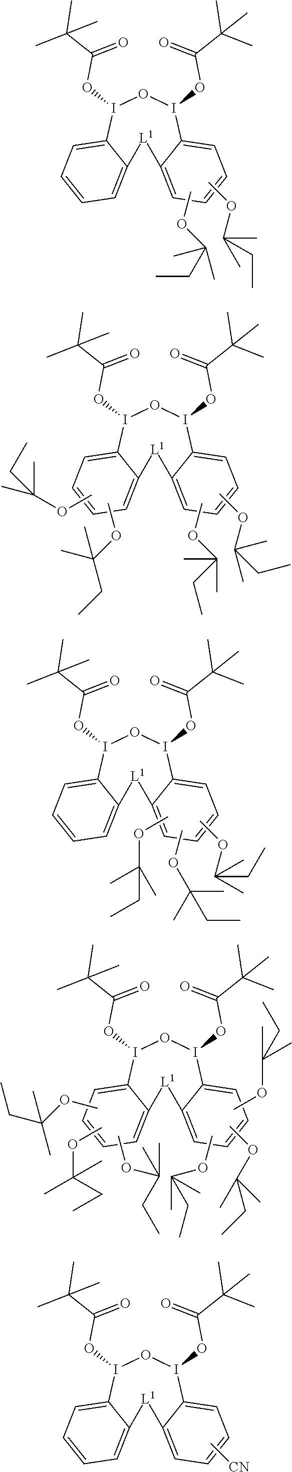

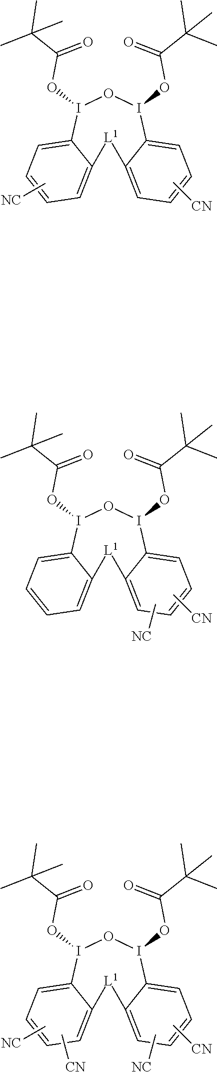

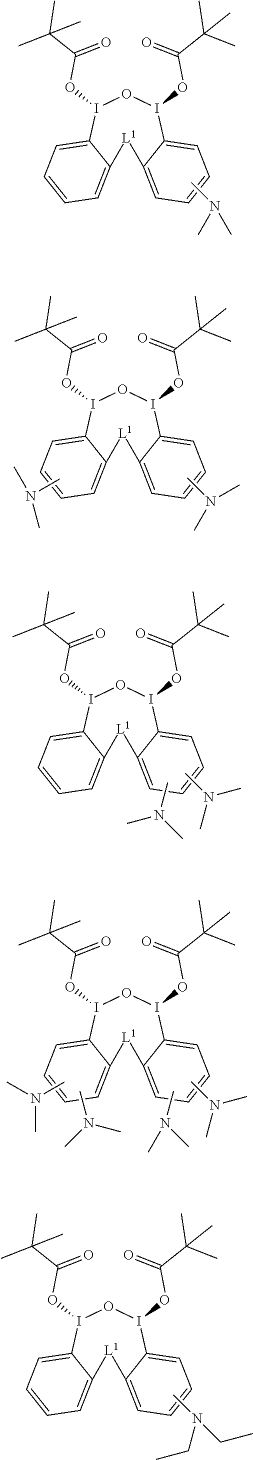

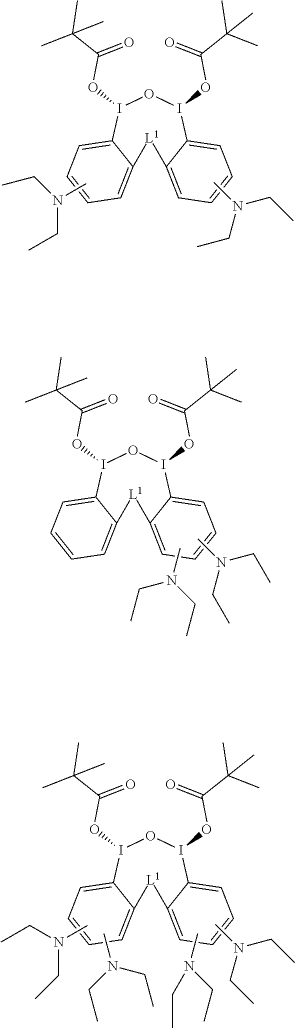

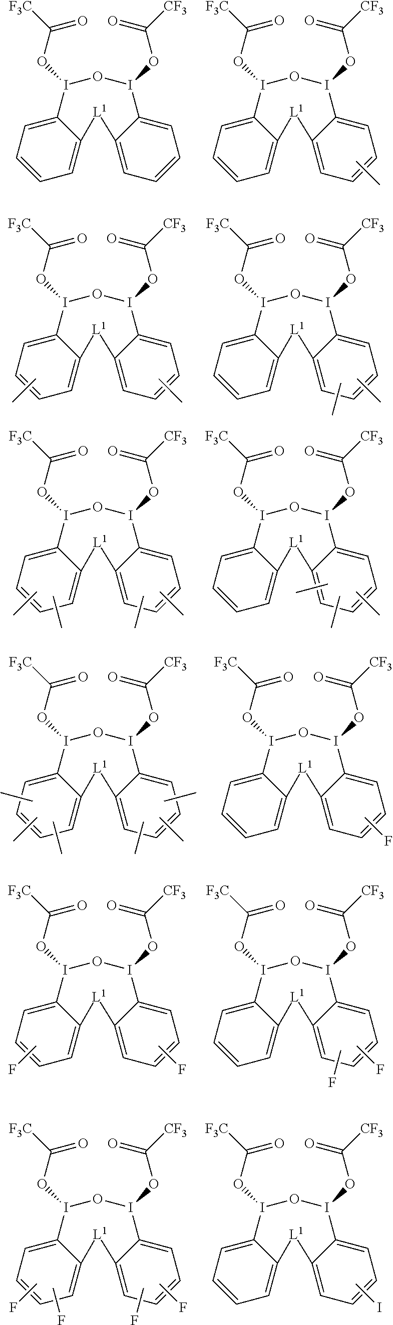

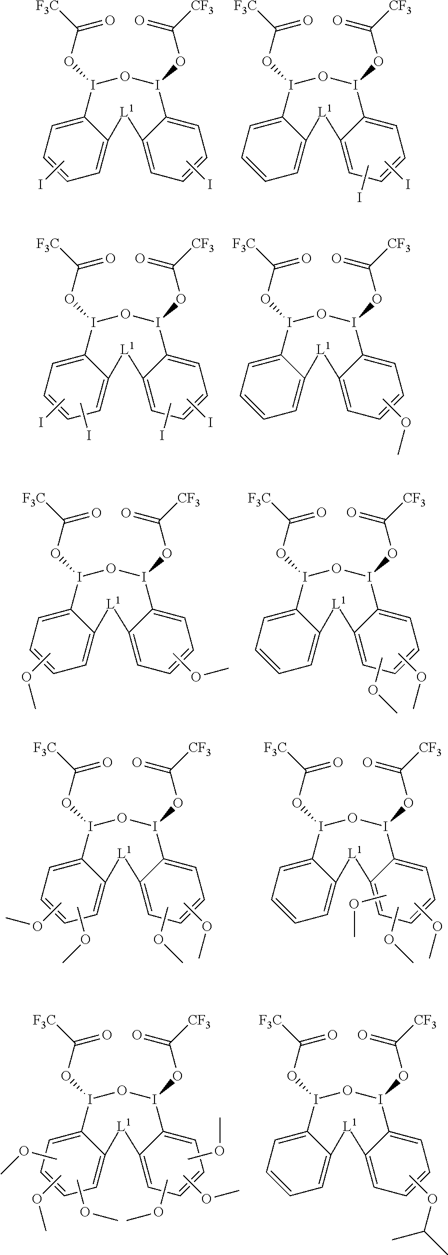

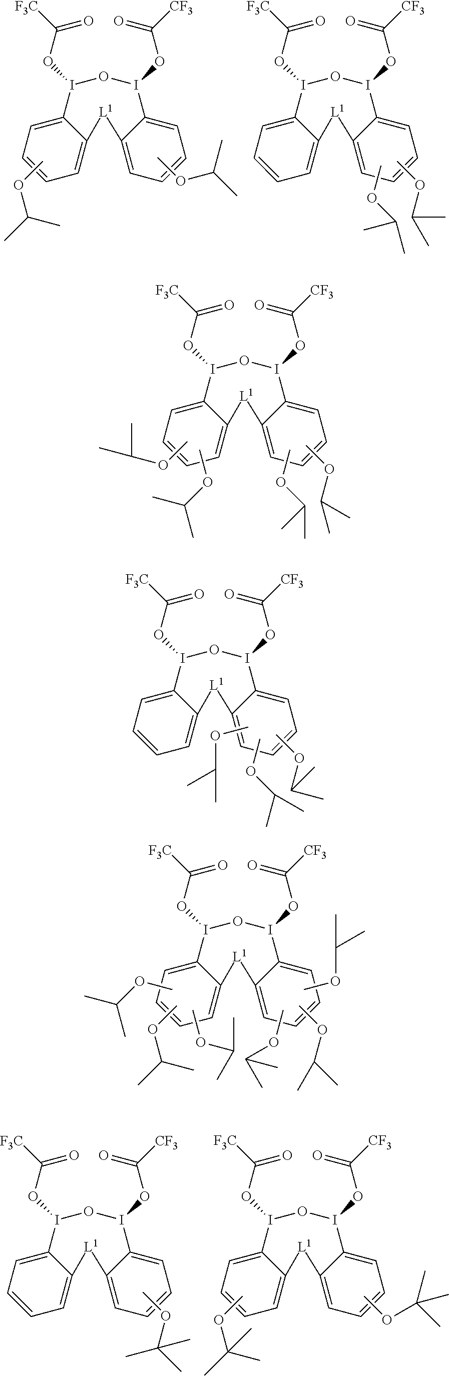

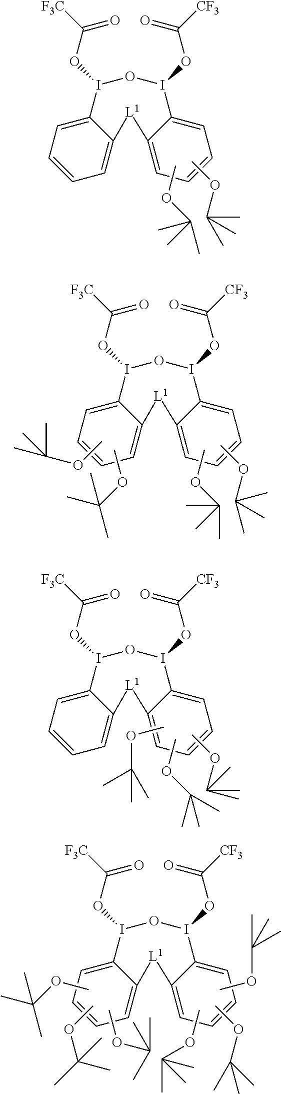

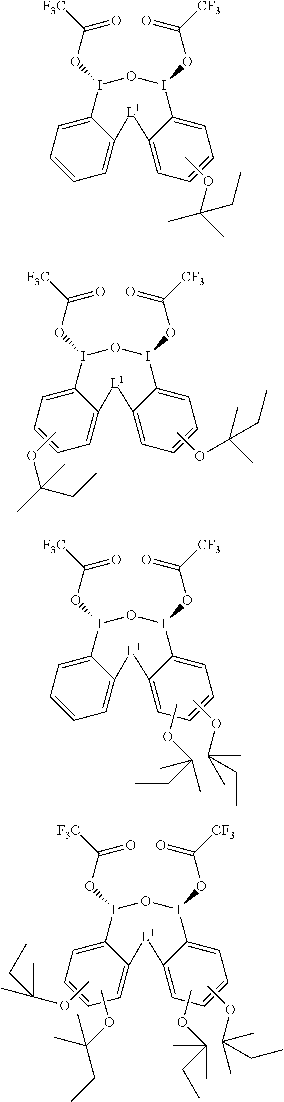

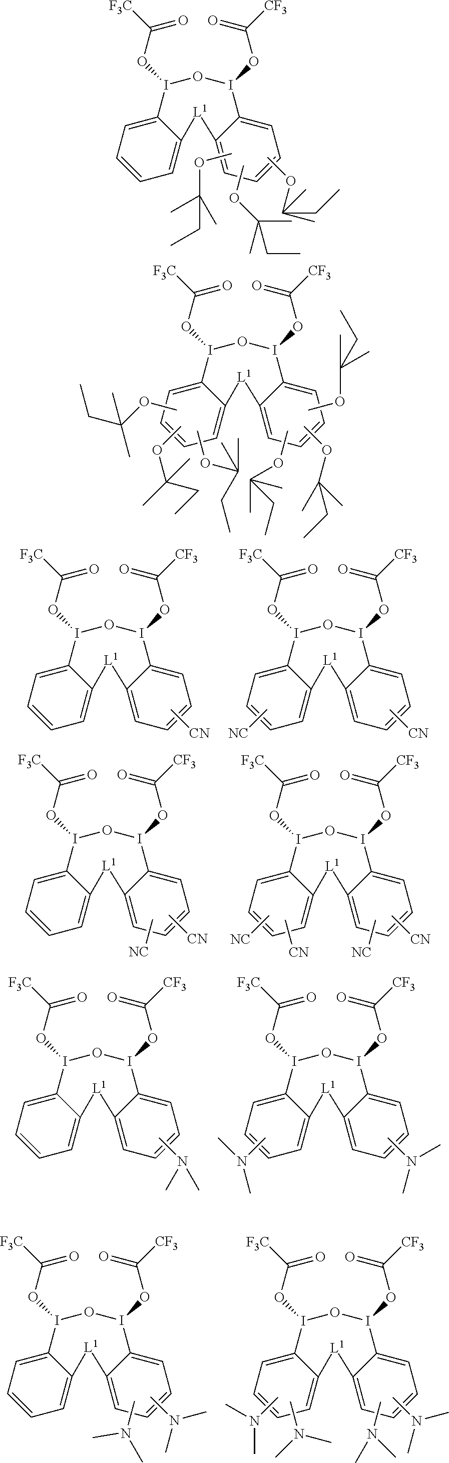

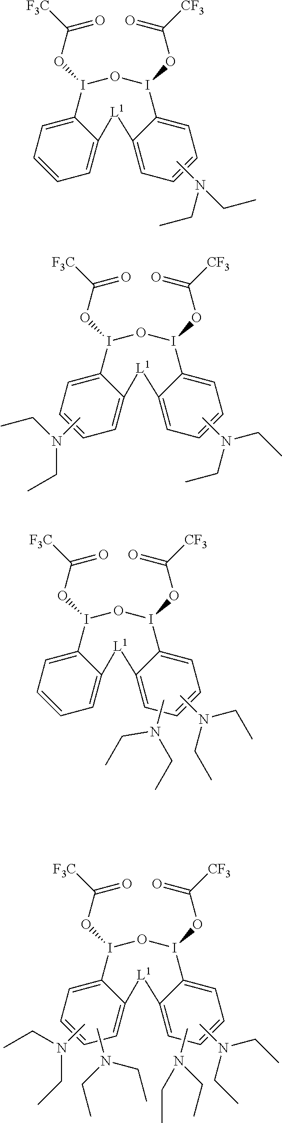

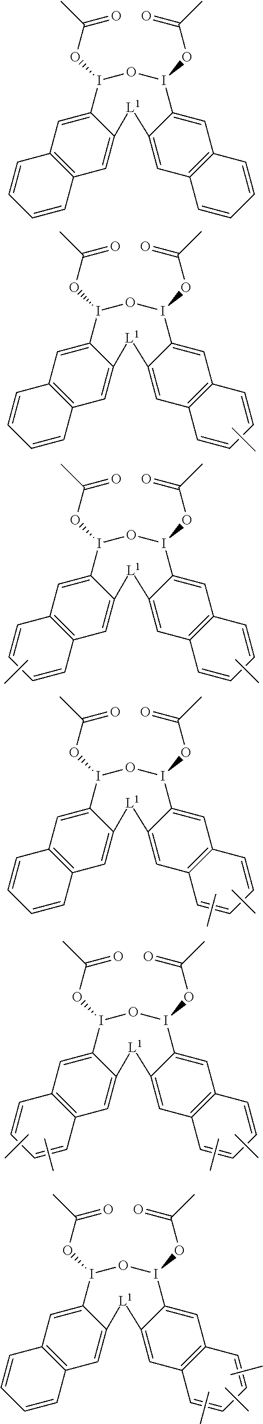

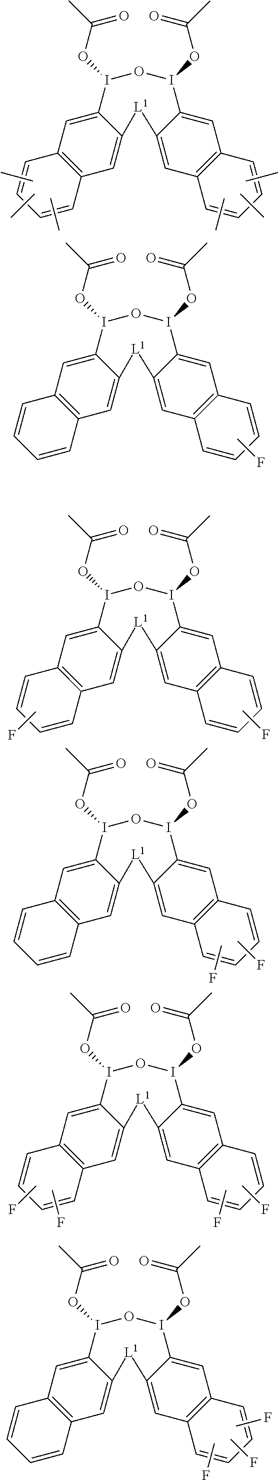

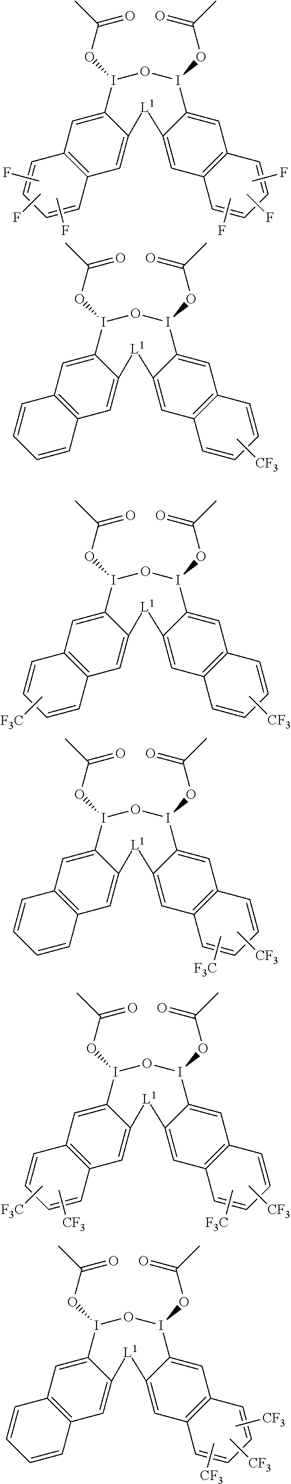

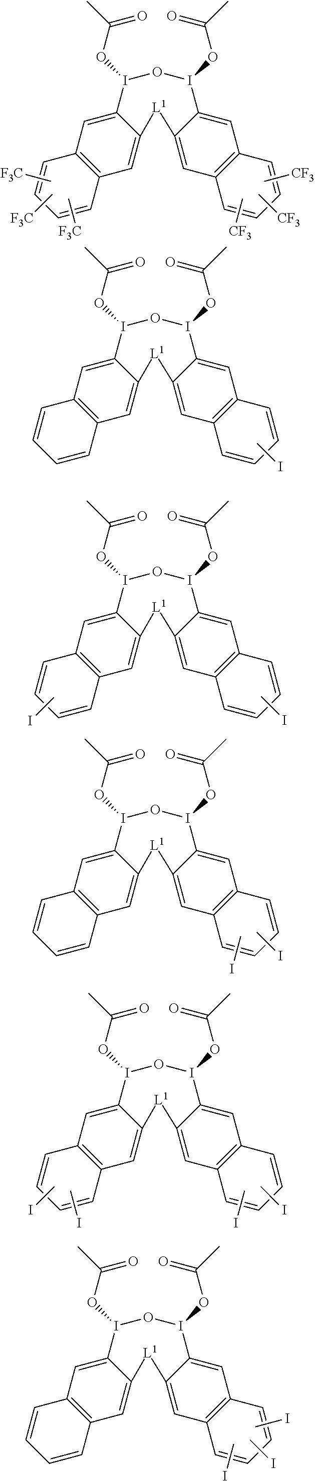

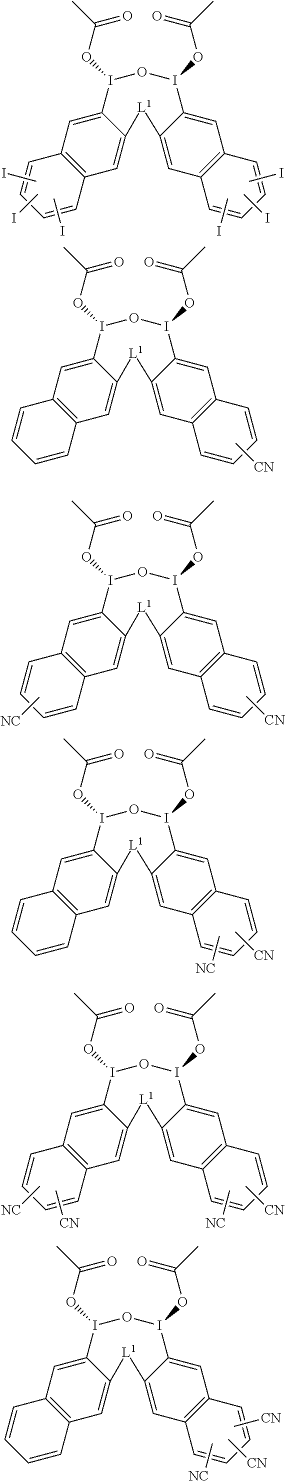

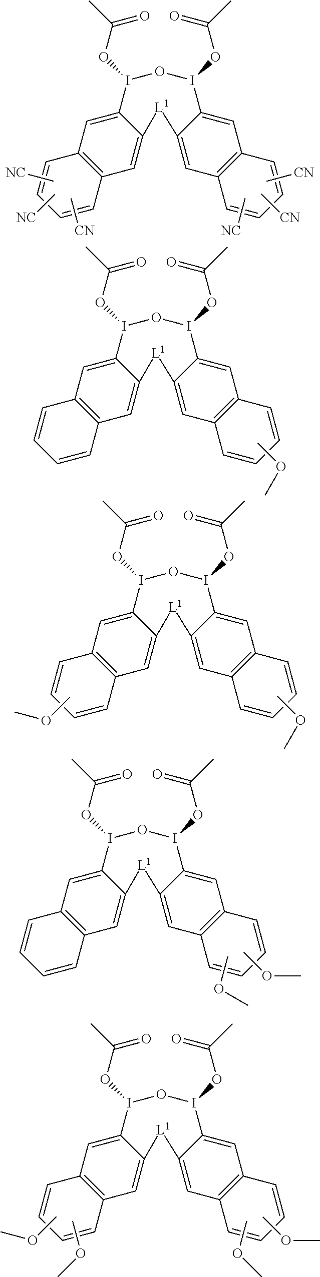

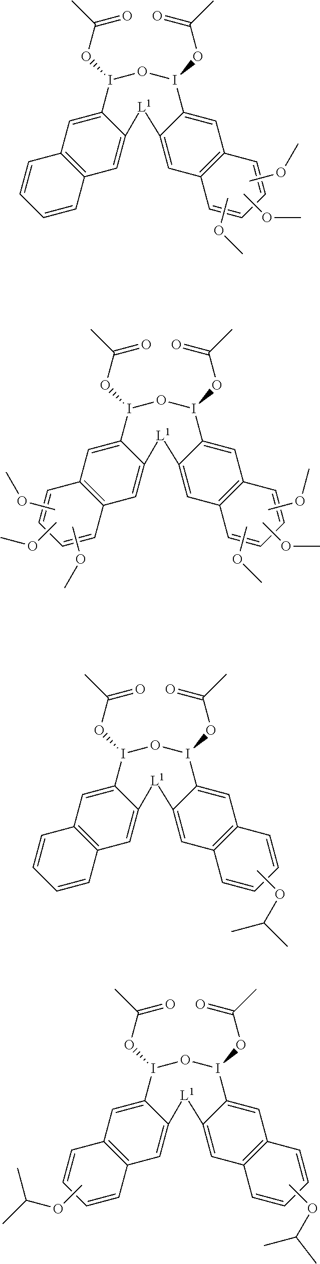

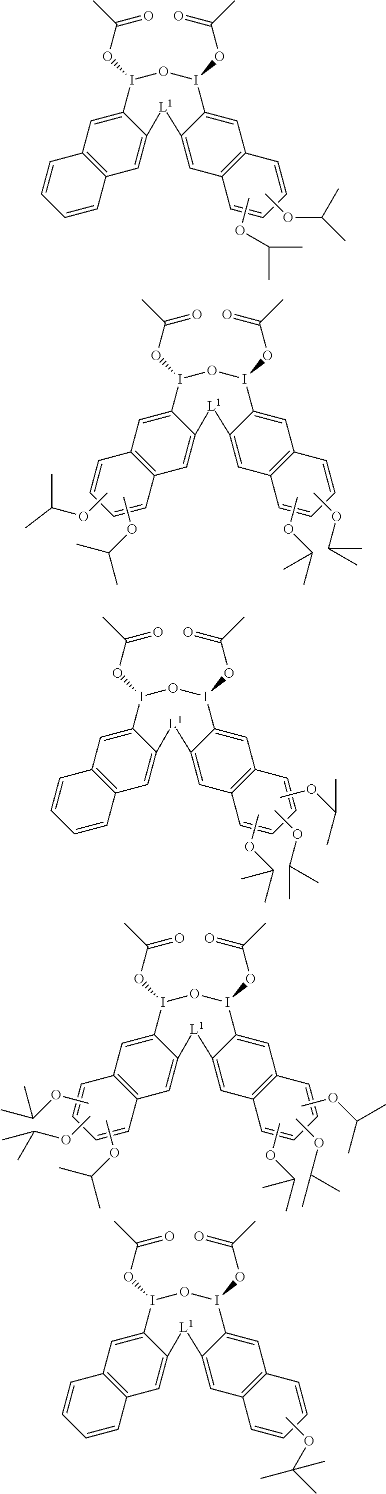

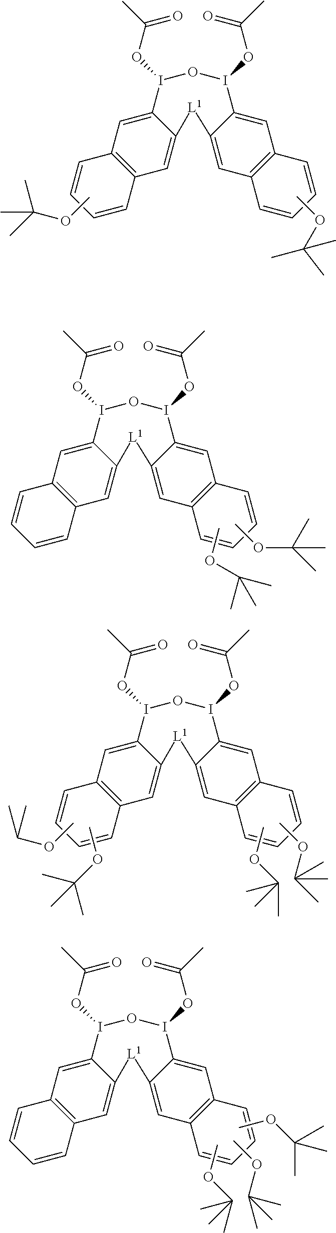

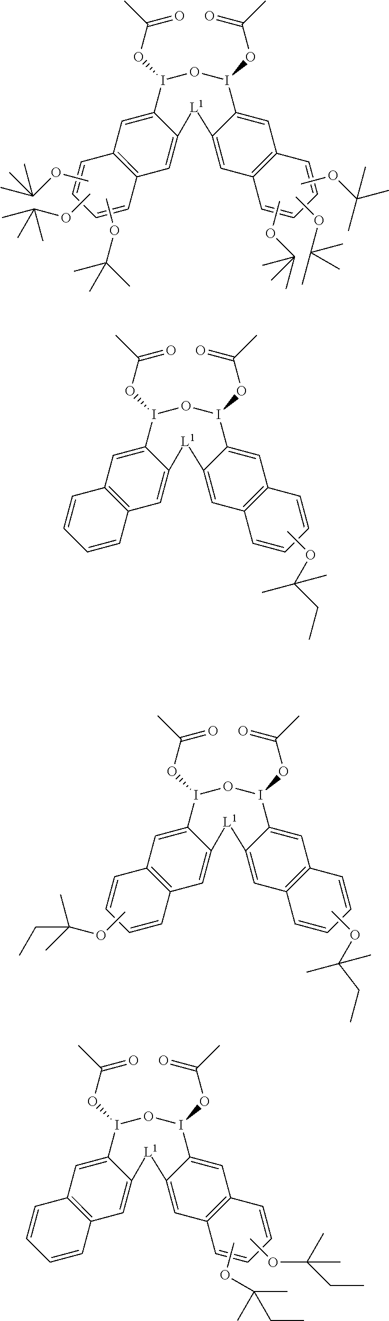

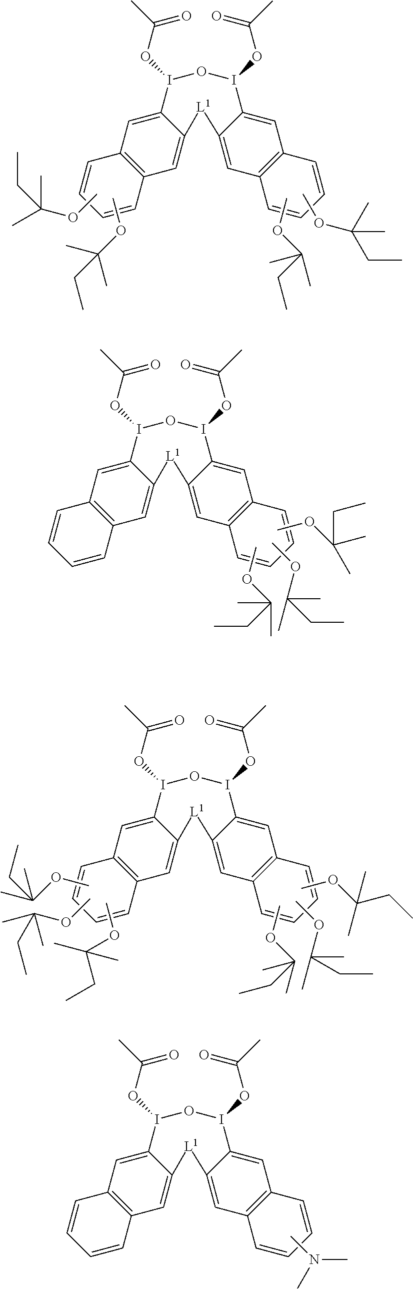

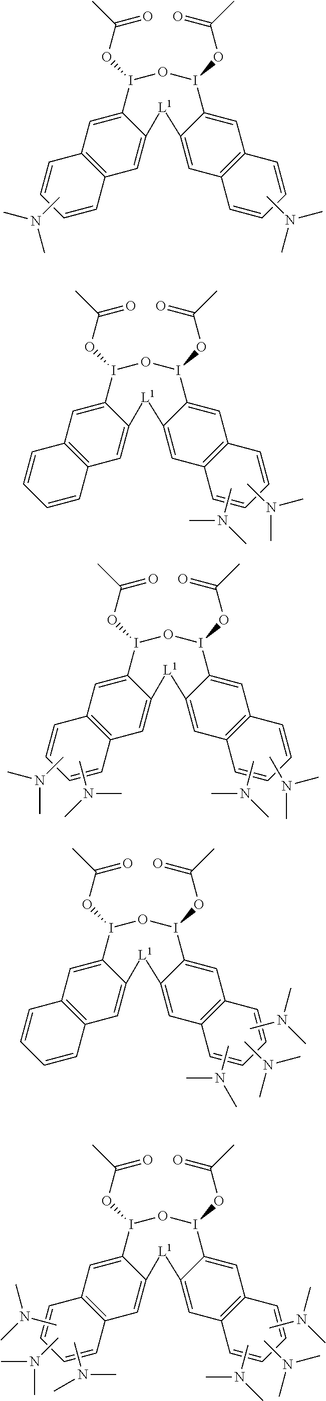

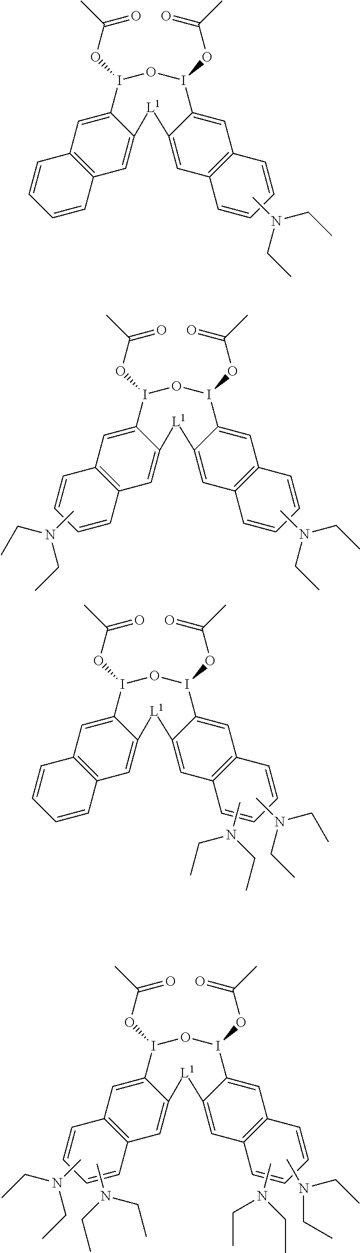

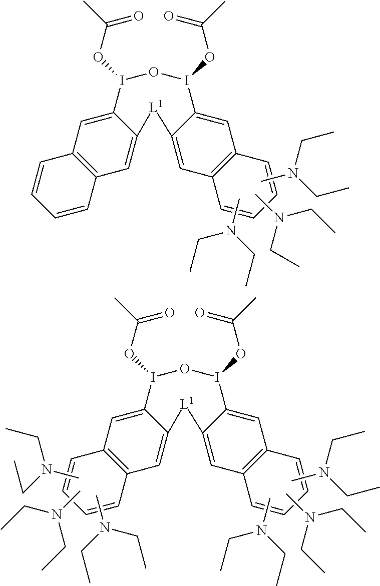

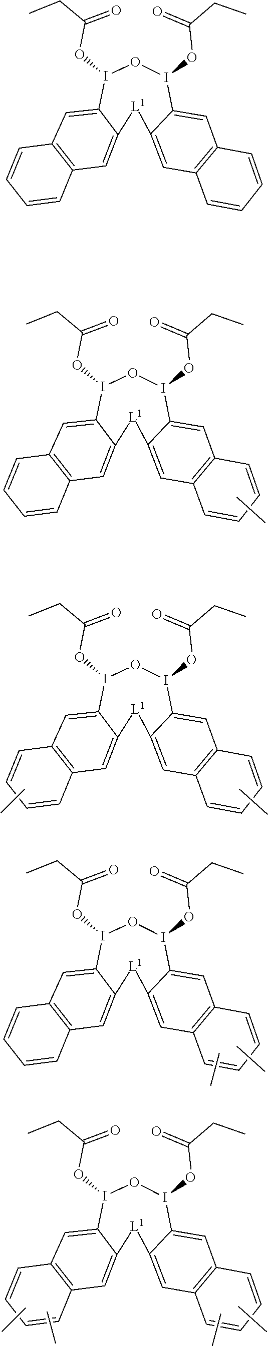

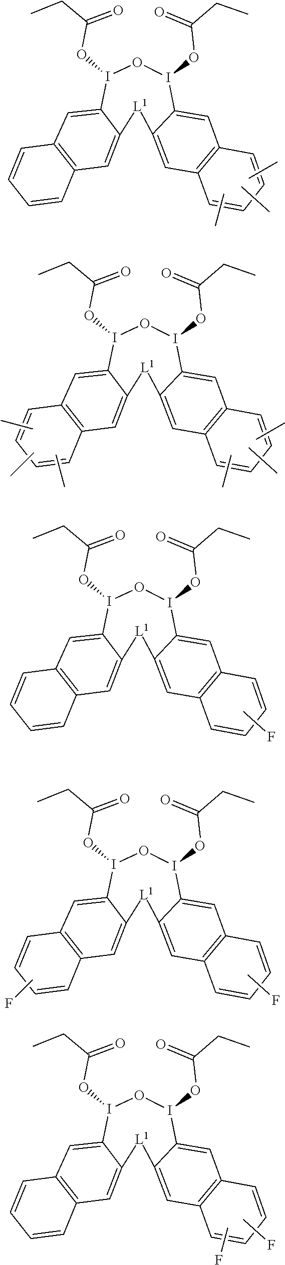

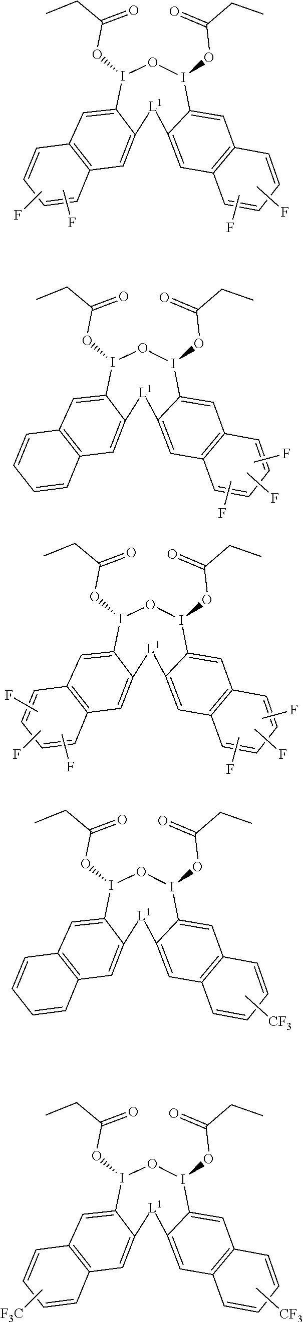

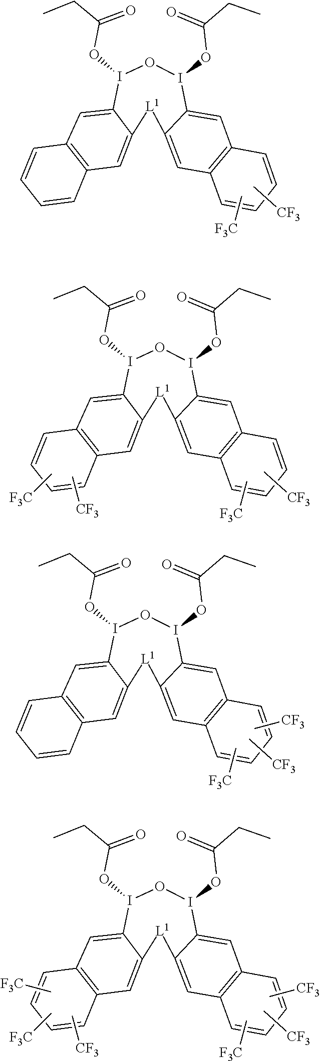

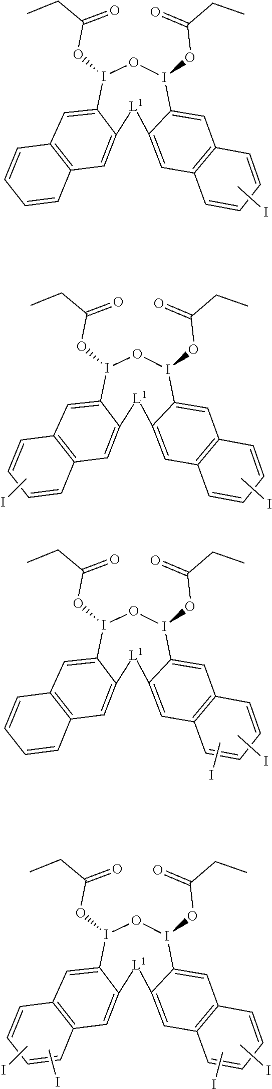

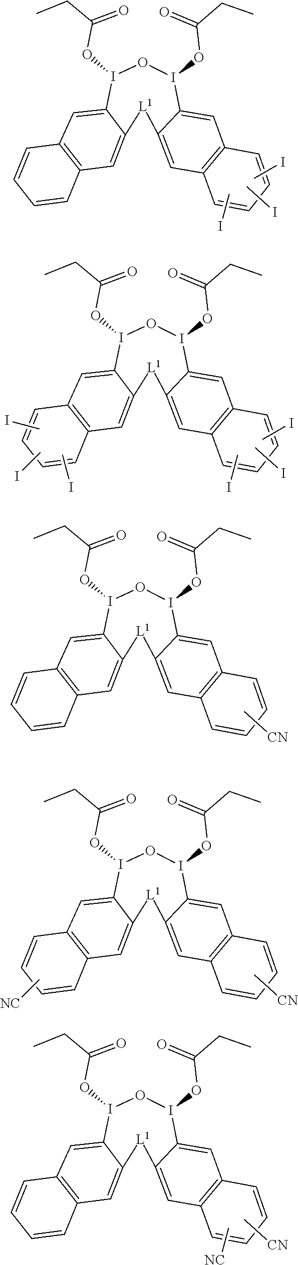

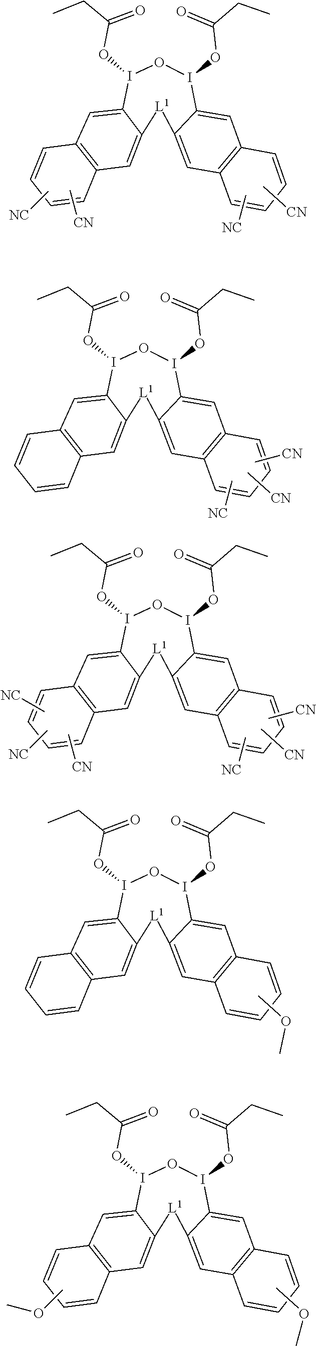

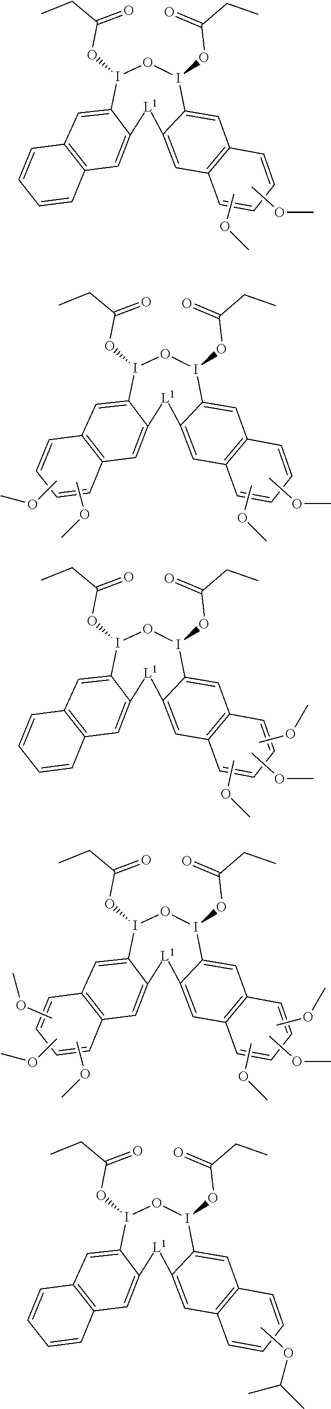

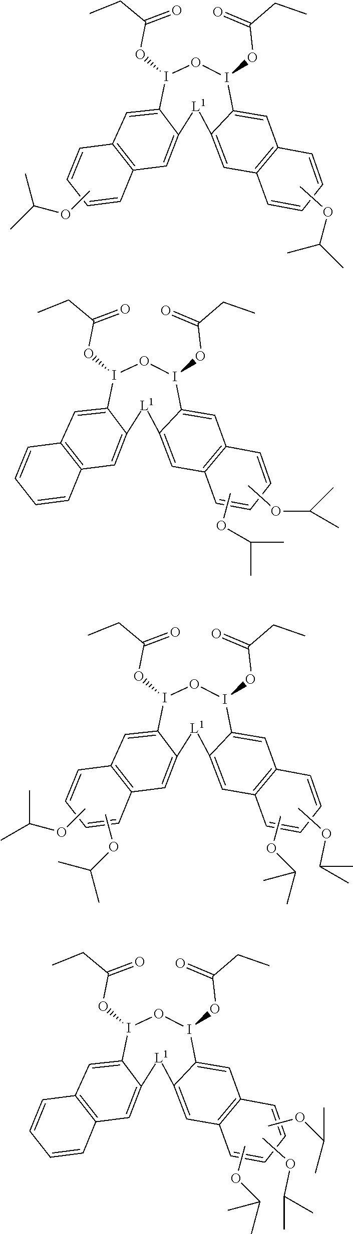

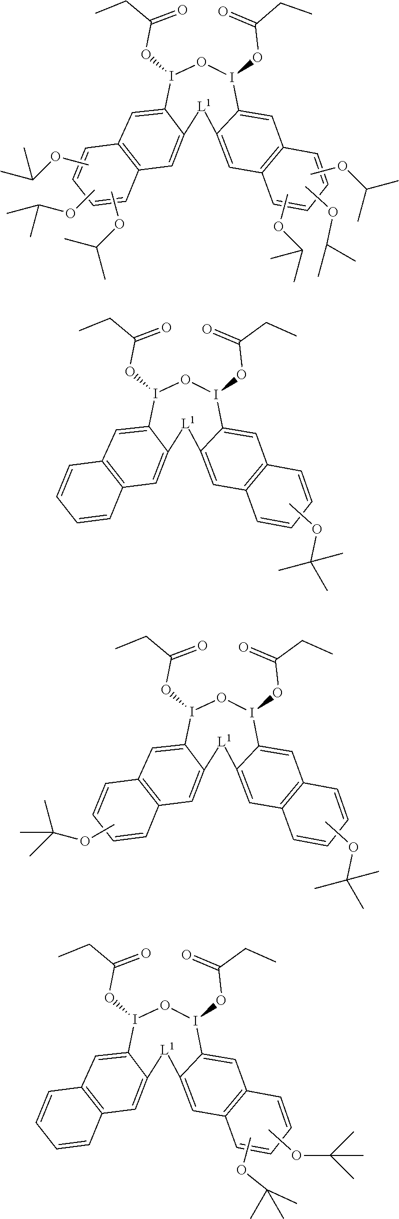

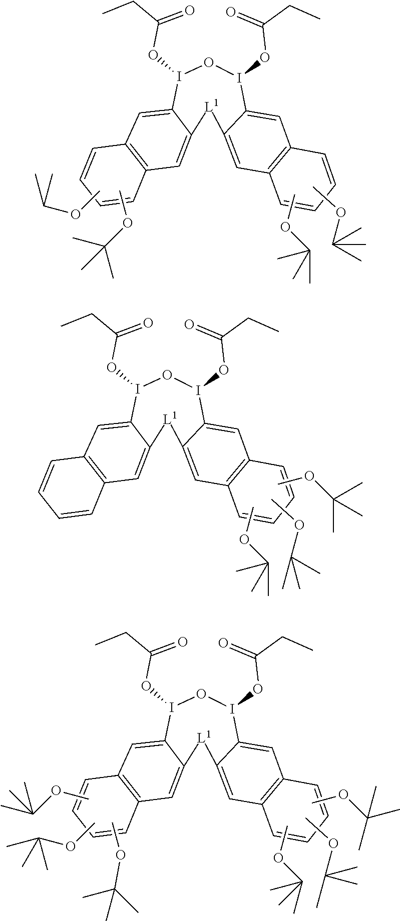

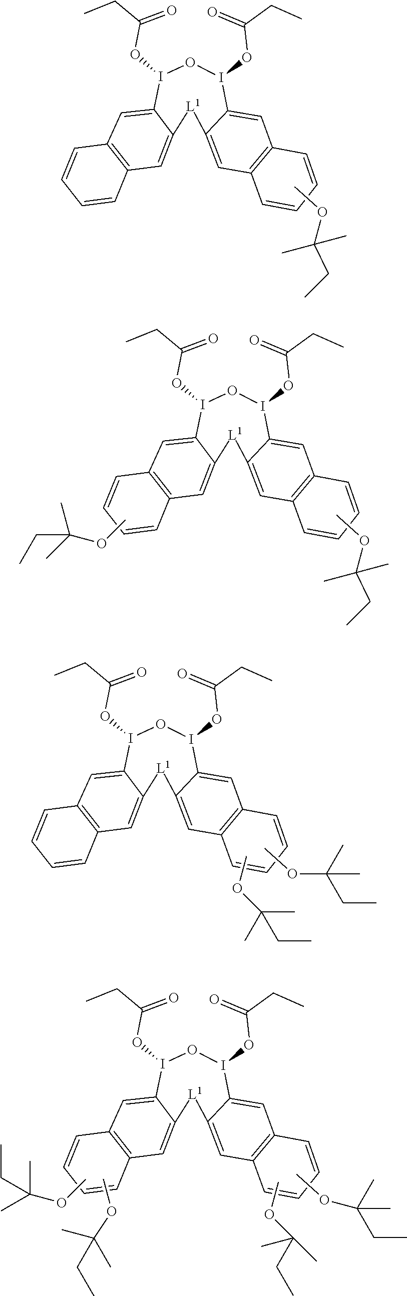

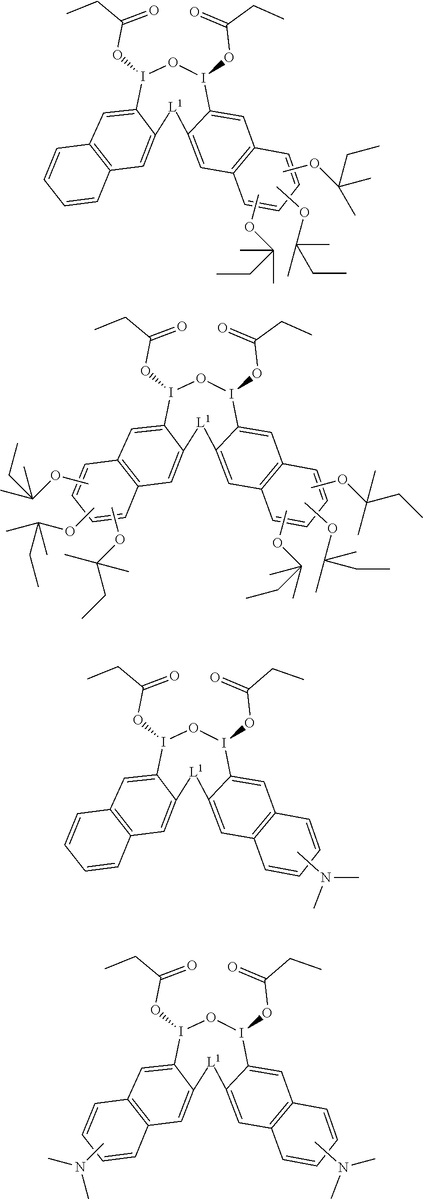

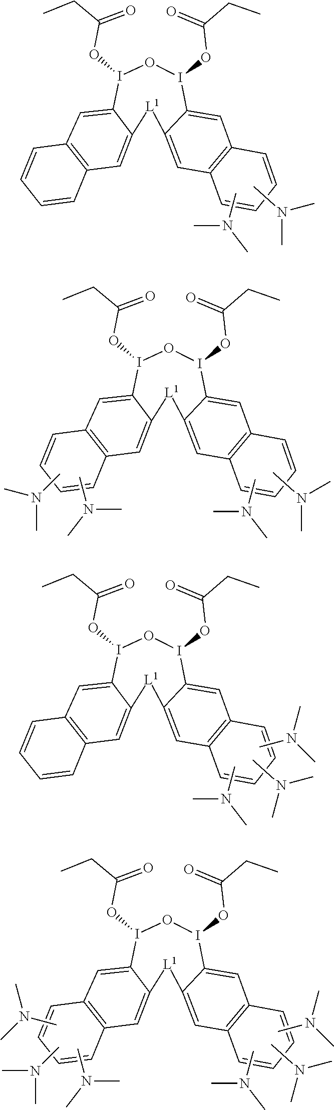

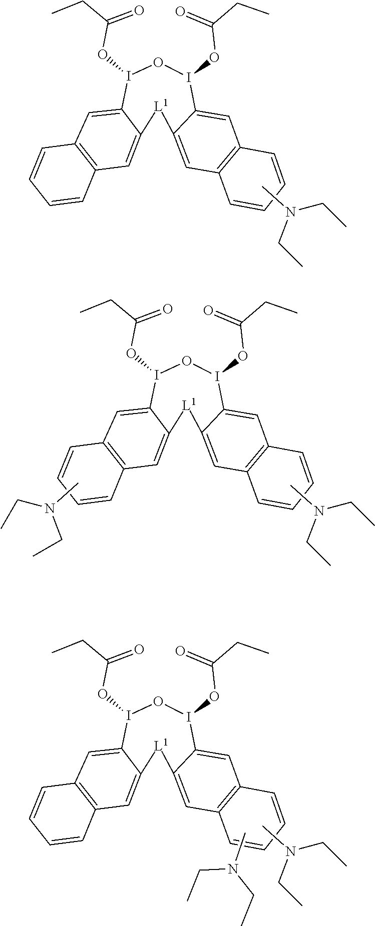

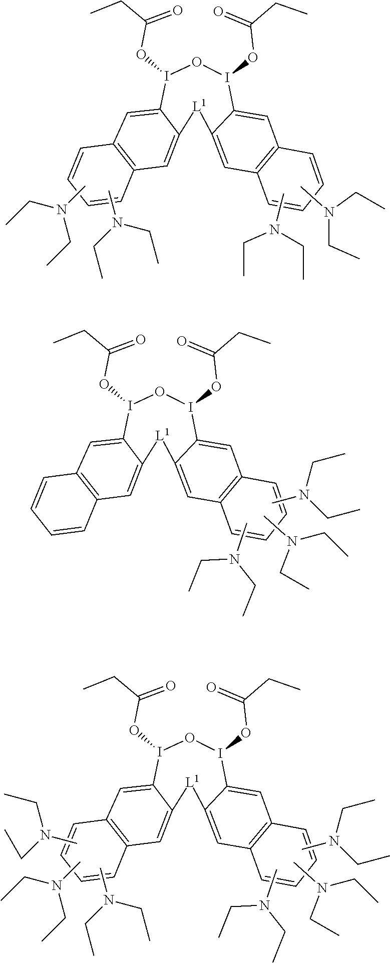

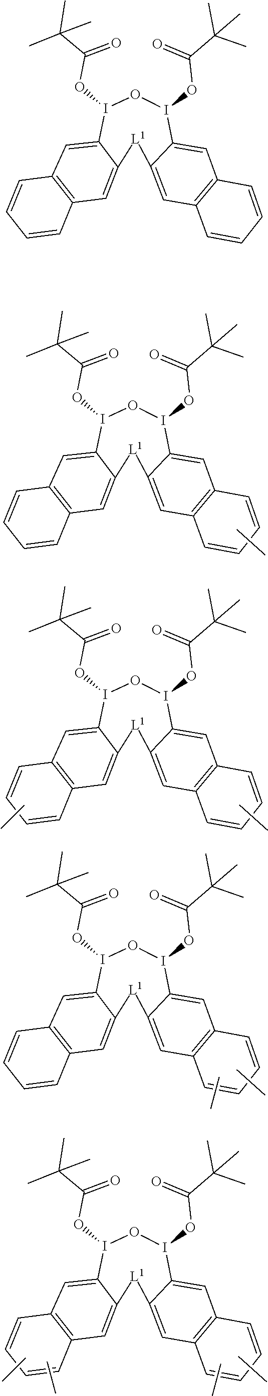

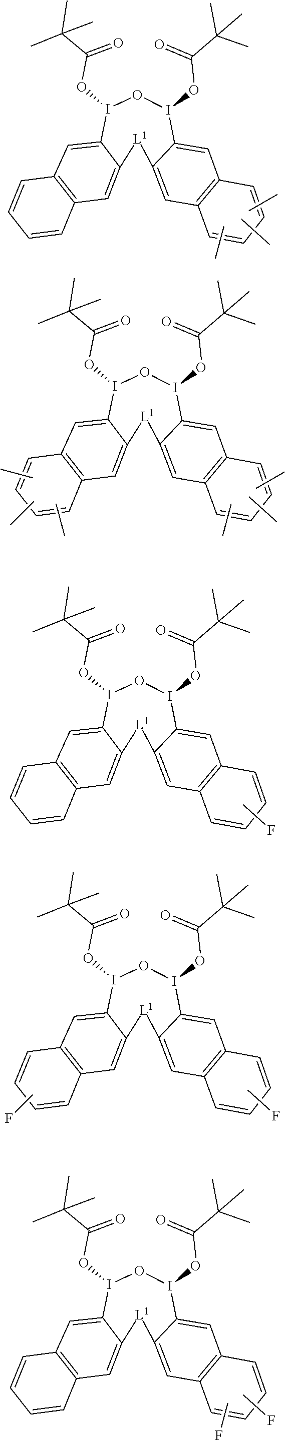

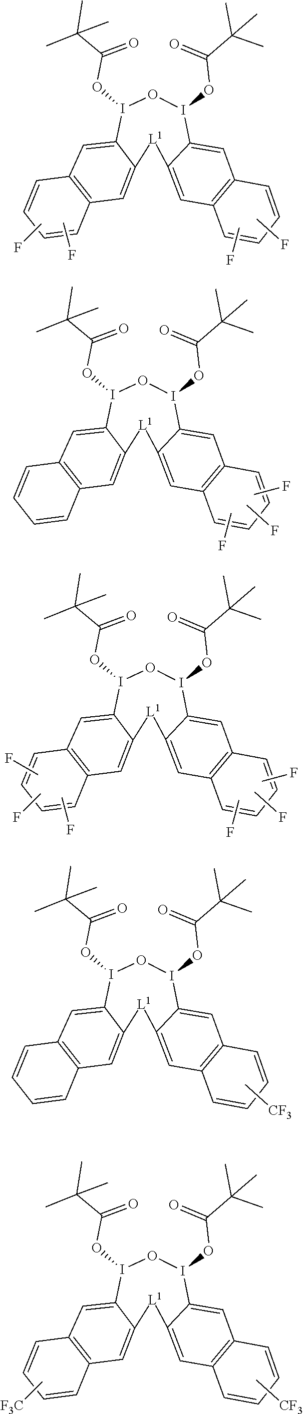

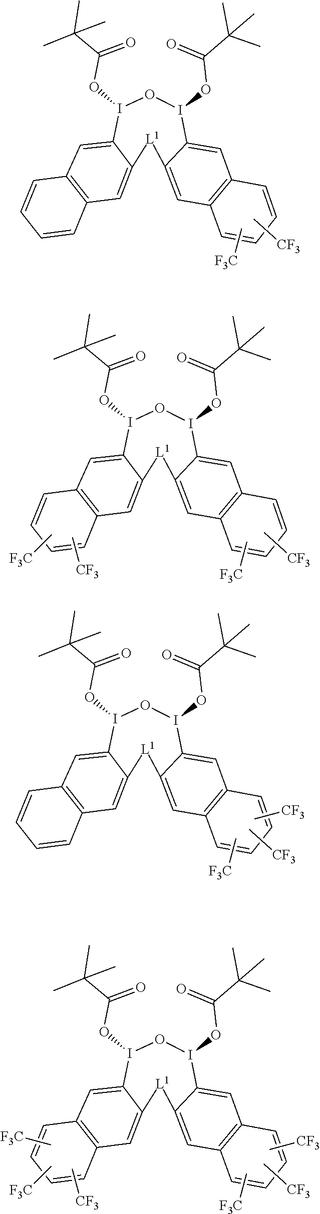

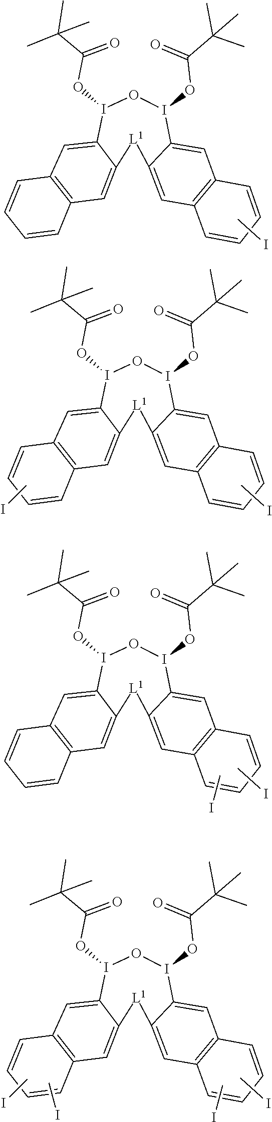

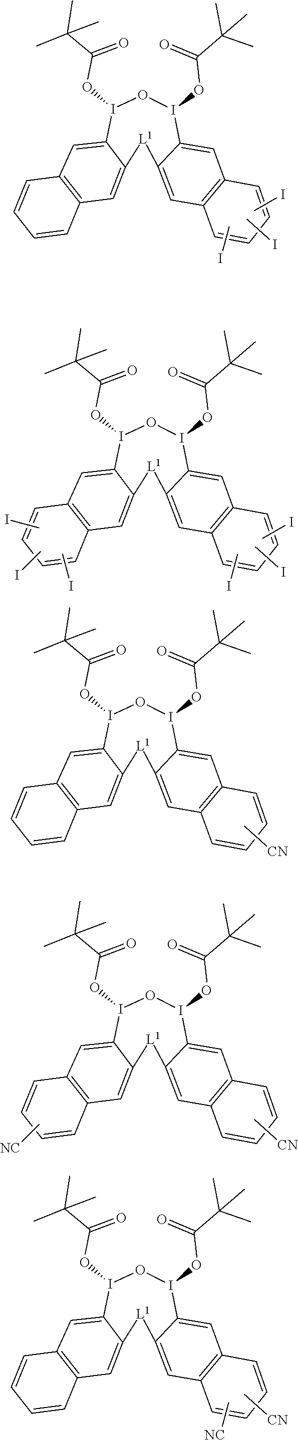

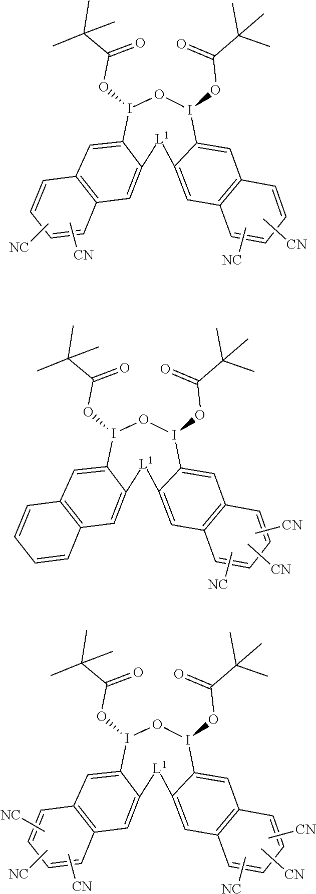

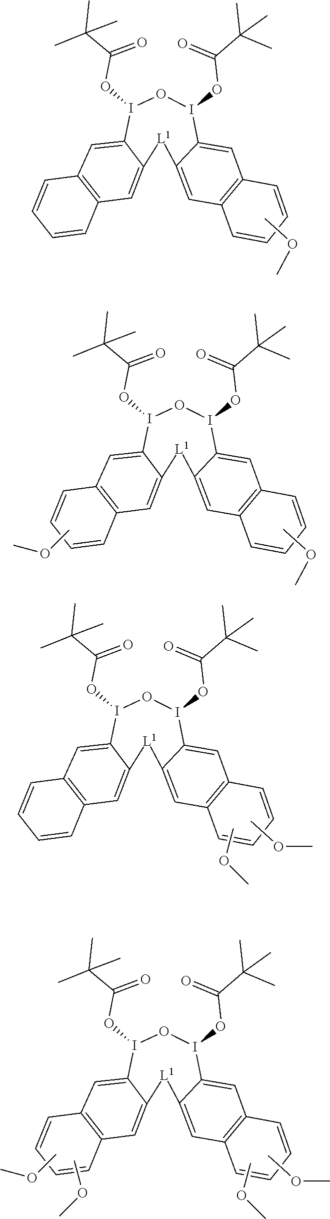

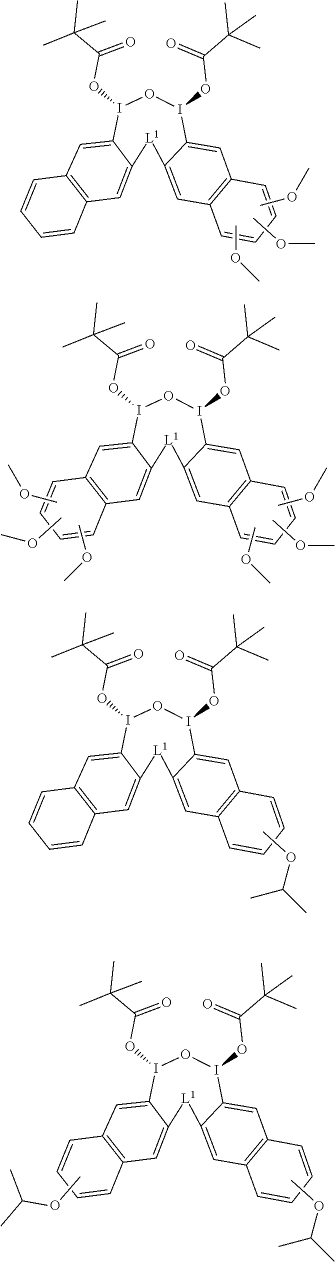

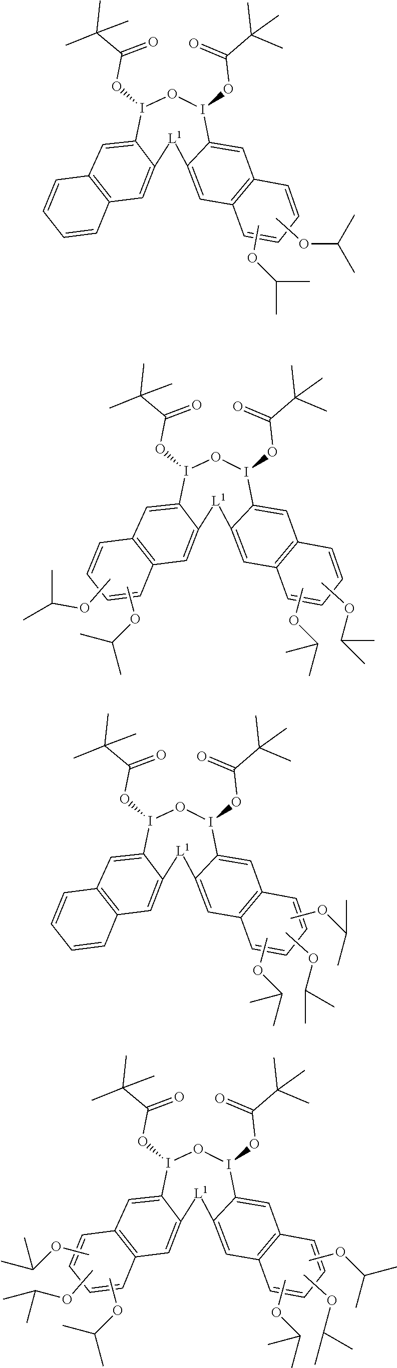

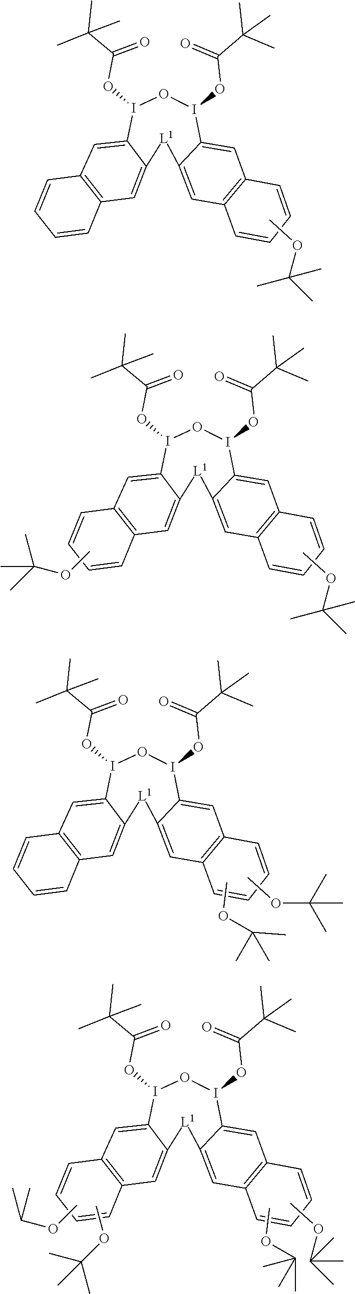

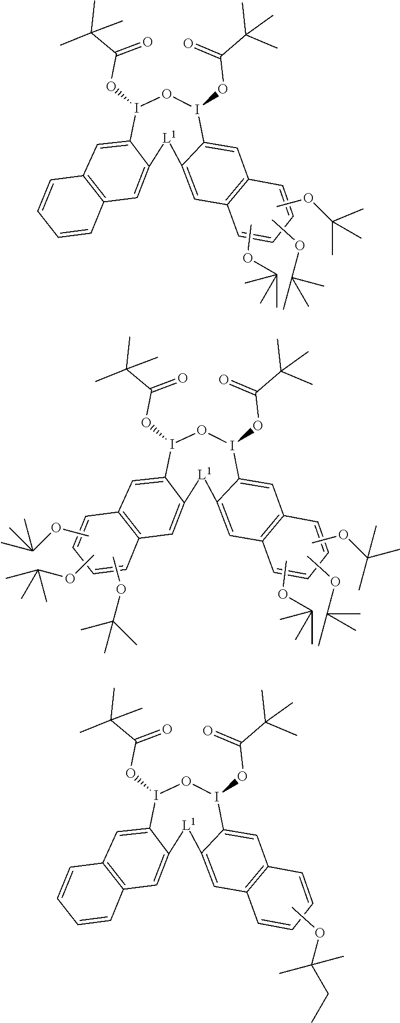

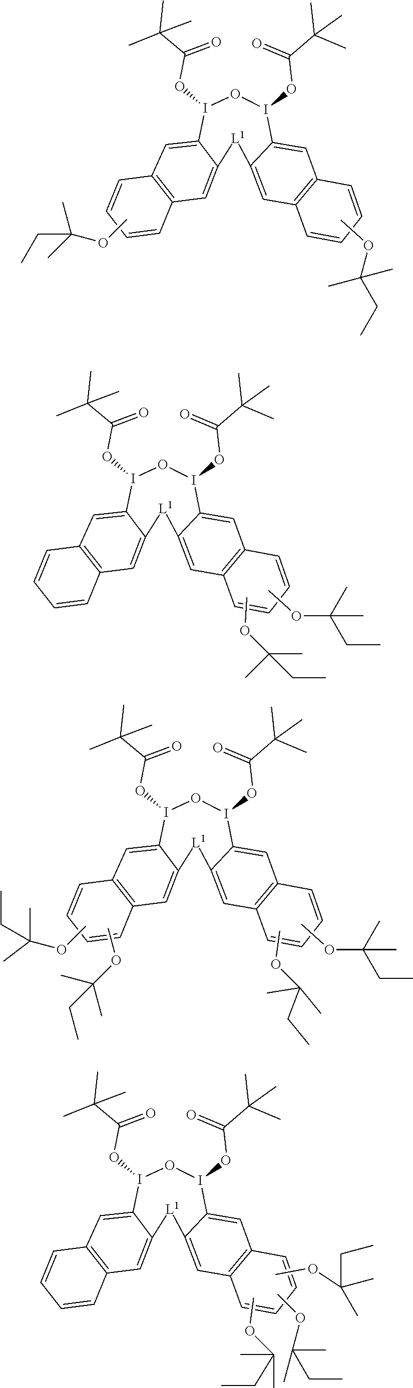

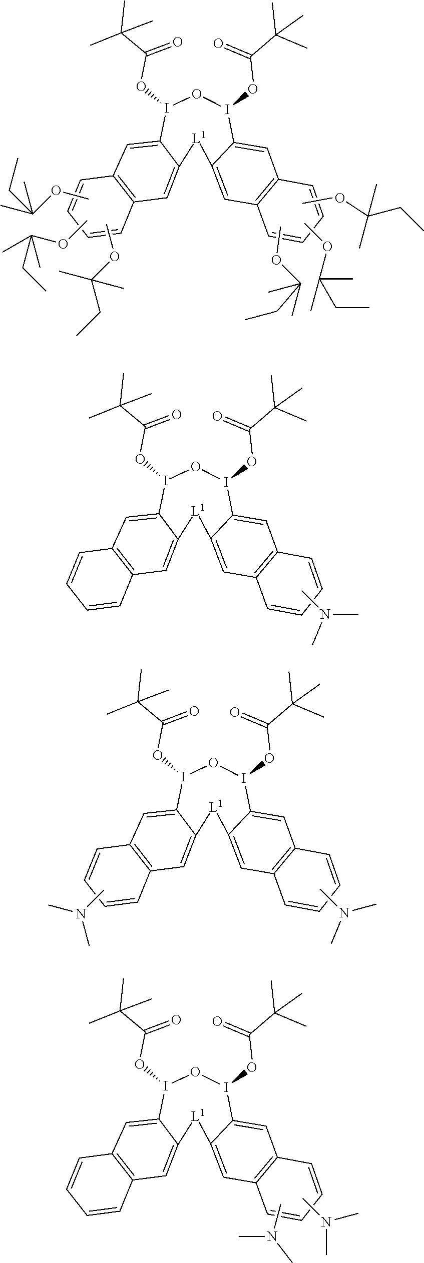

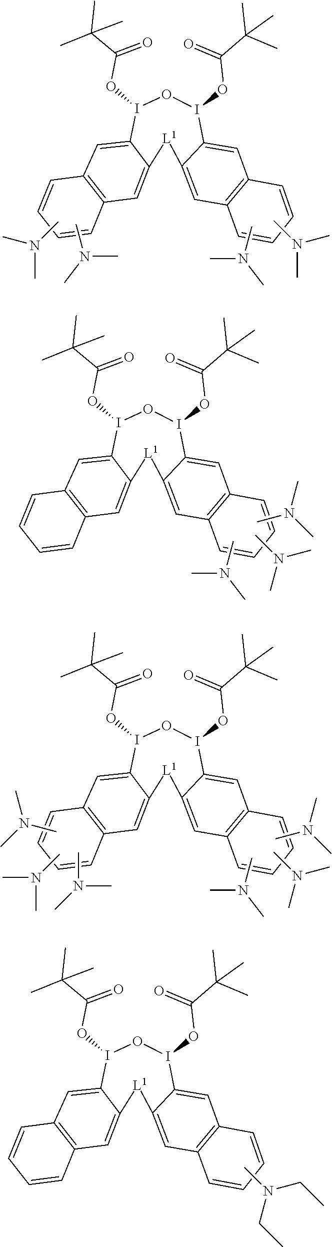

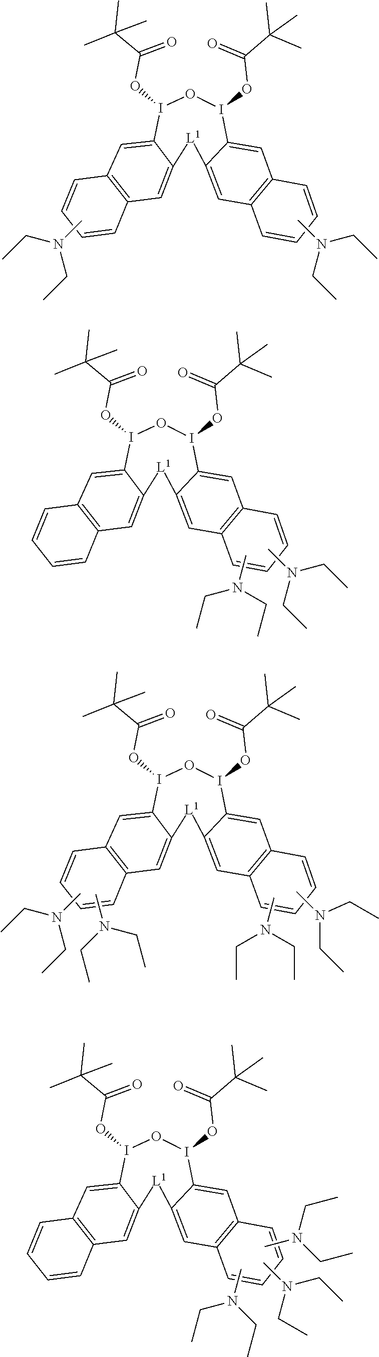

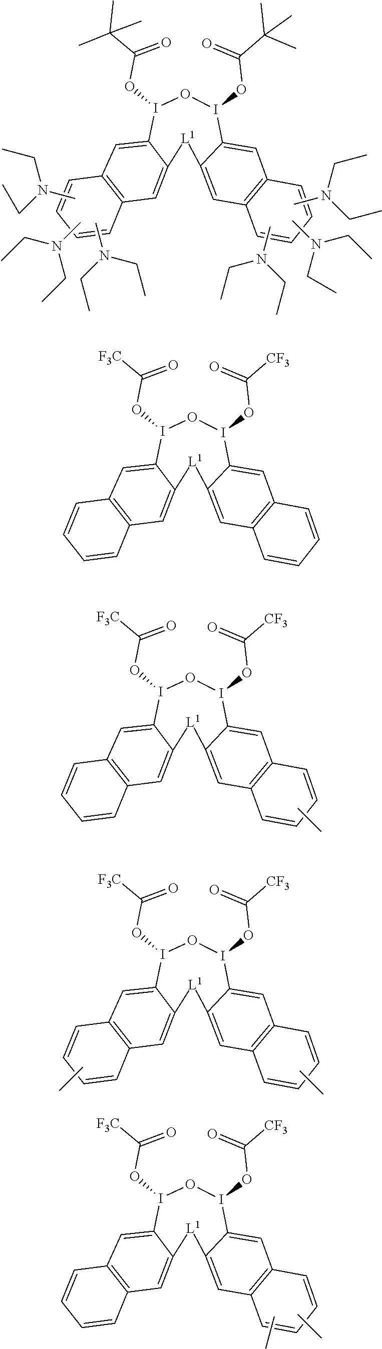

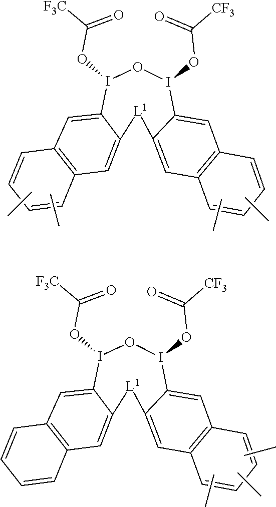

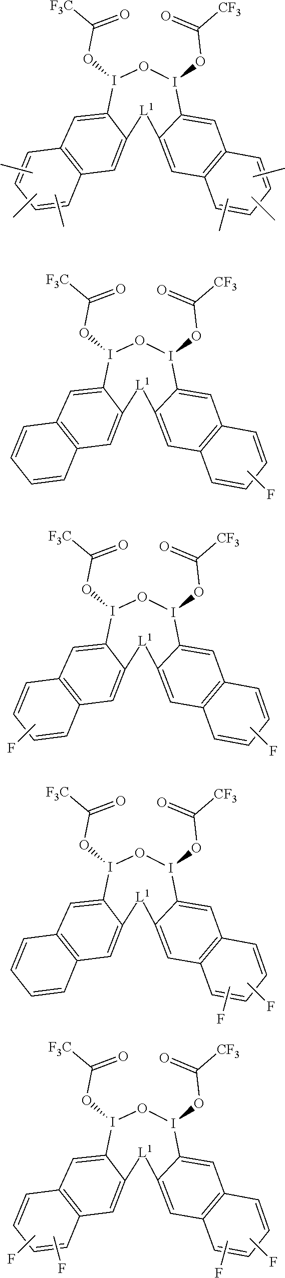

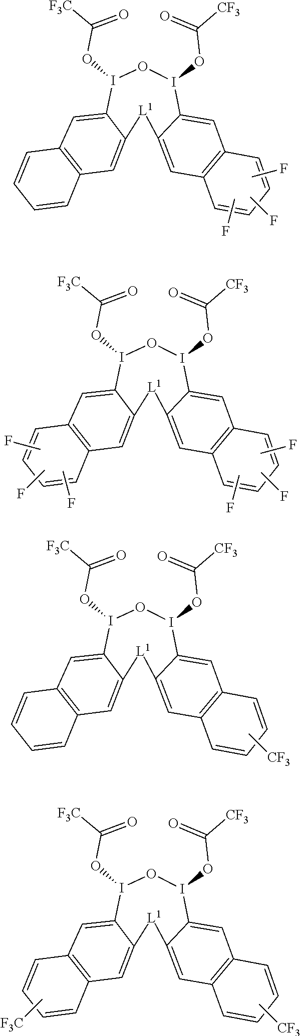

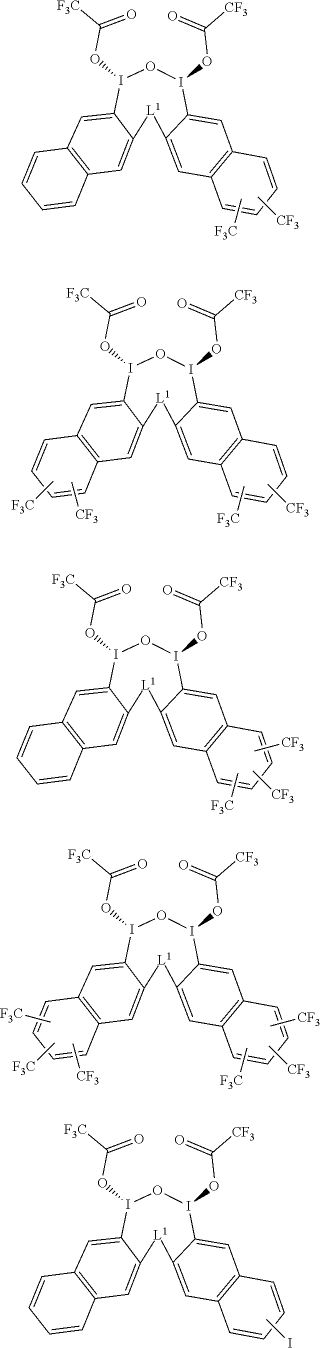

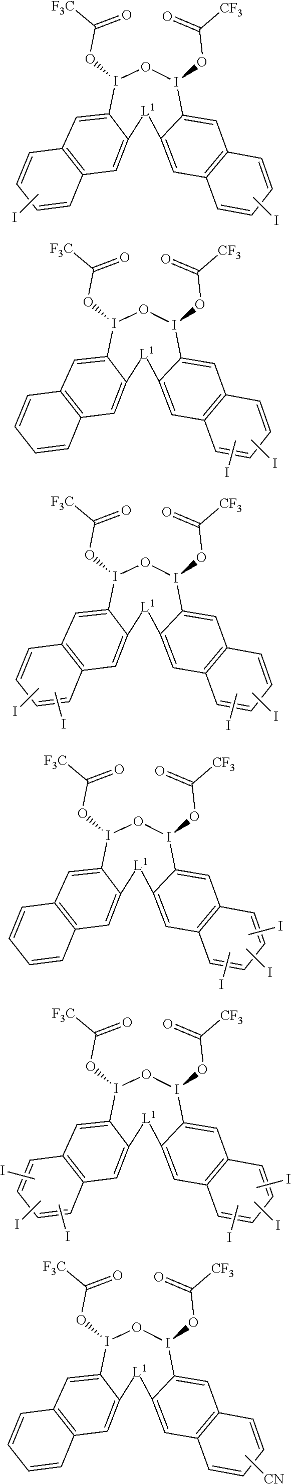

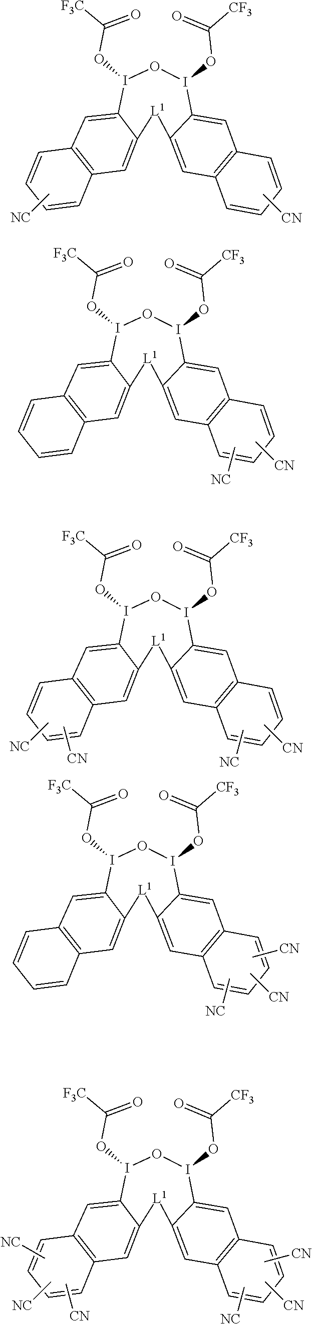

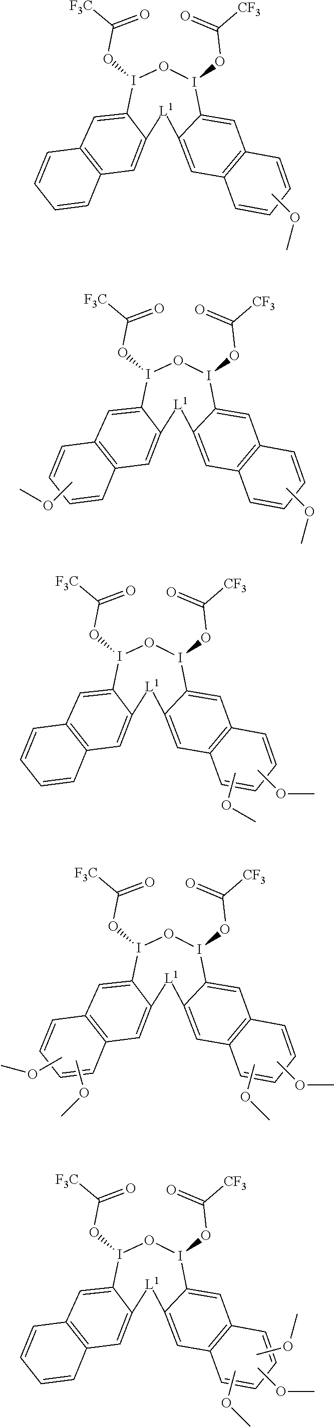

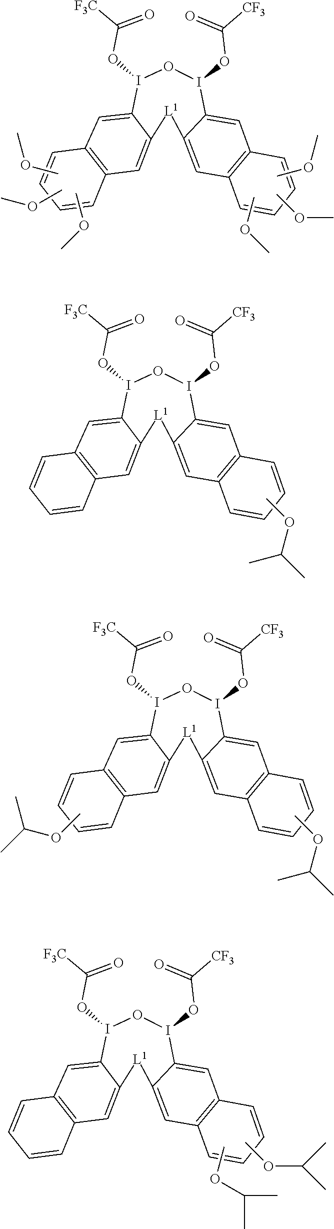

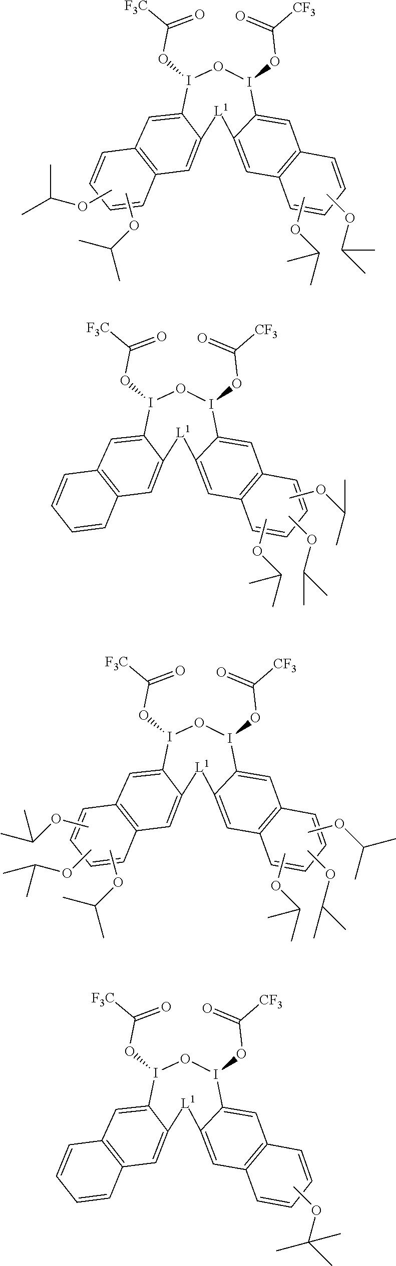

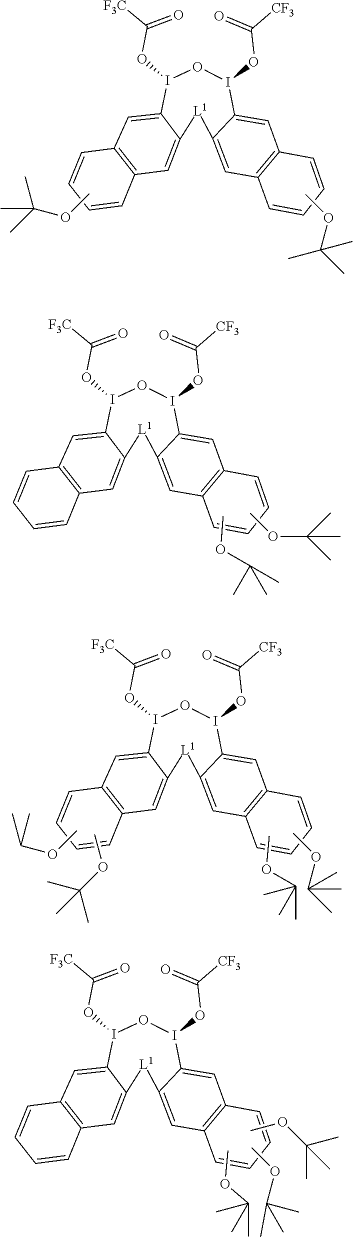

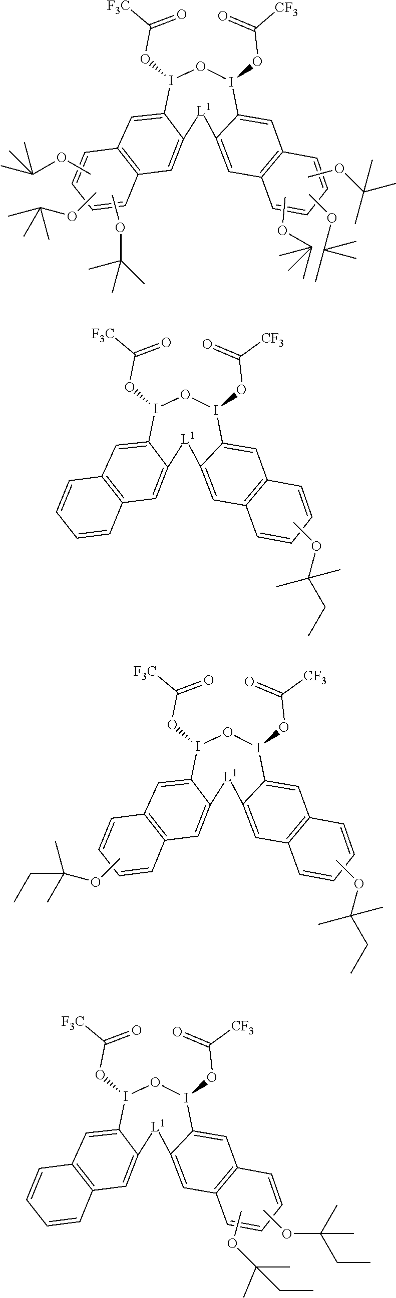

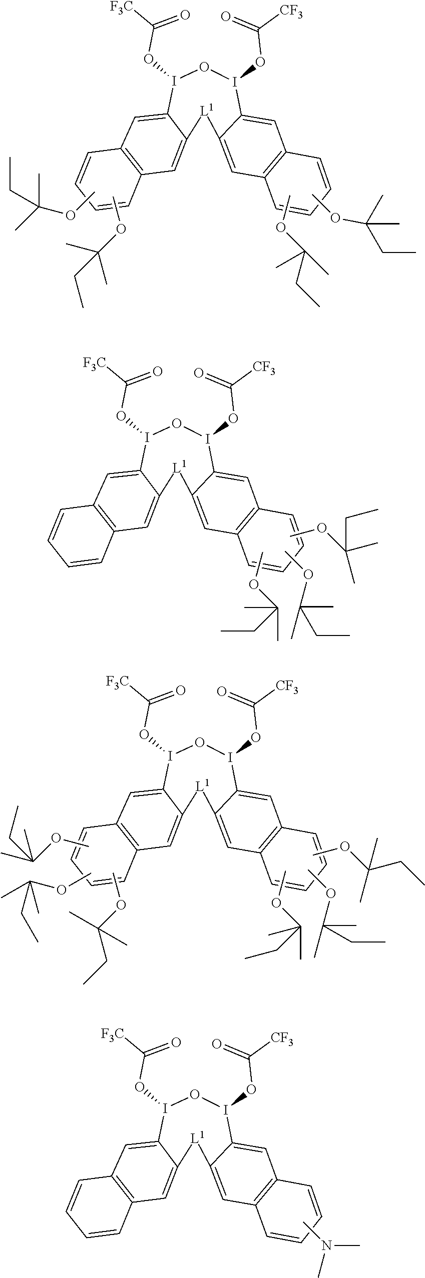

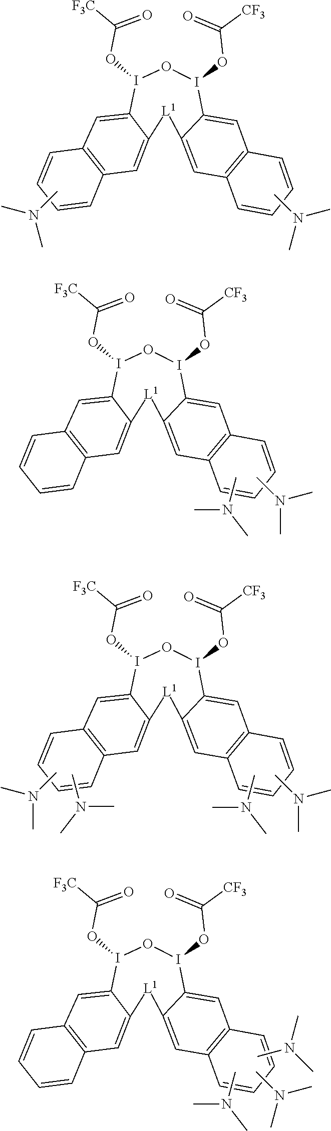

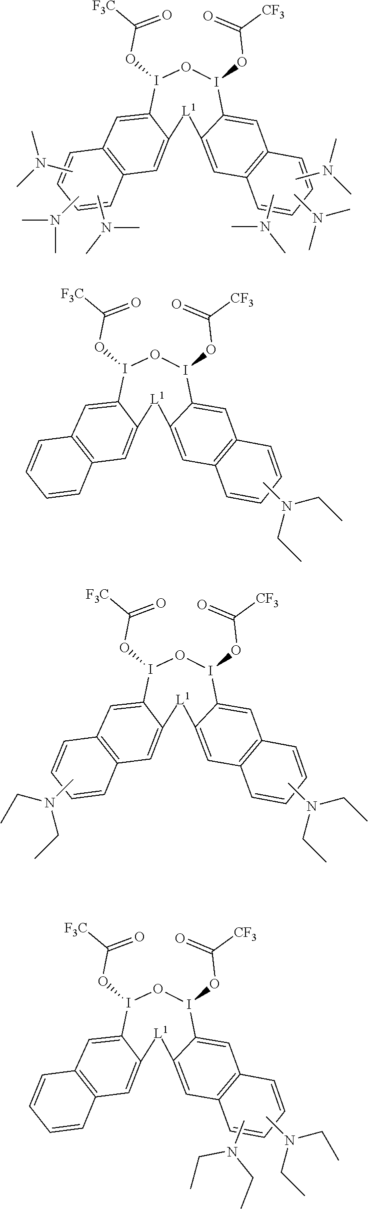

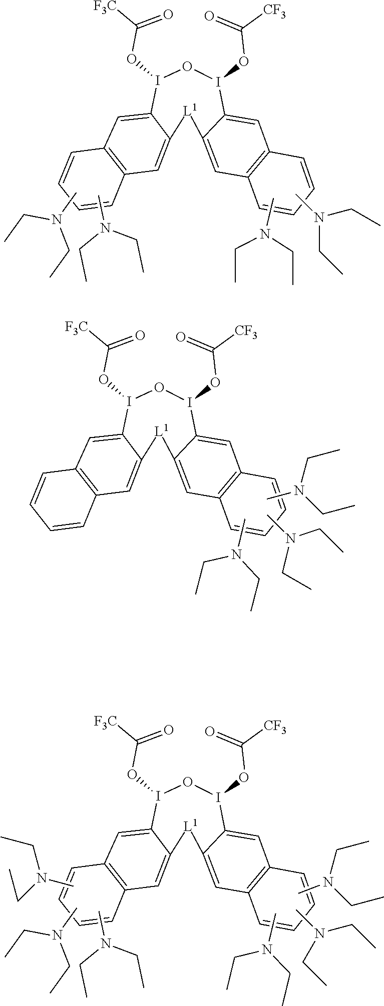

Examples of the hypervalent iodine compound having the formula (7) are shown

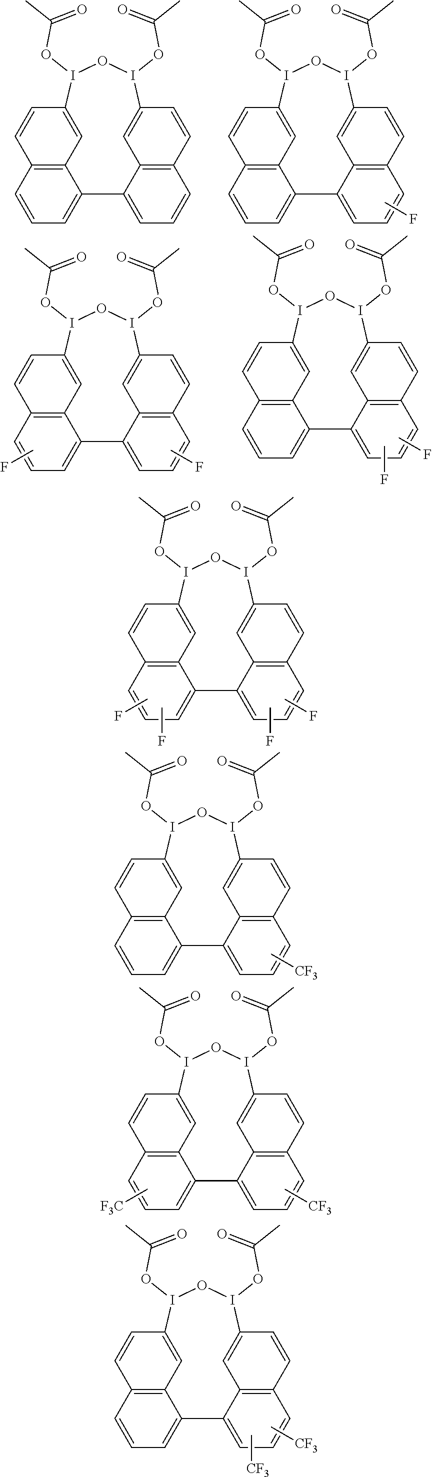

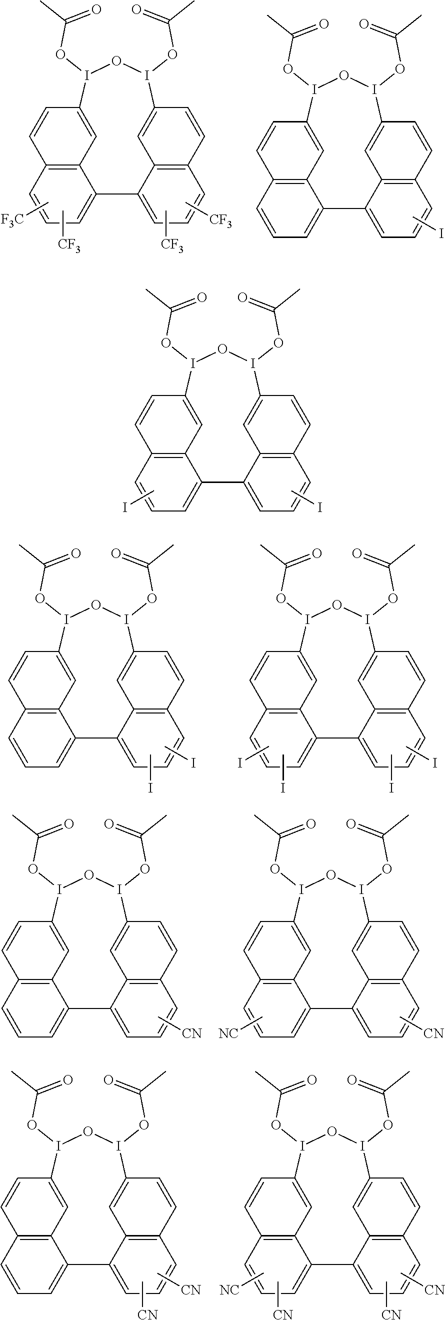

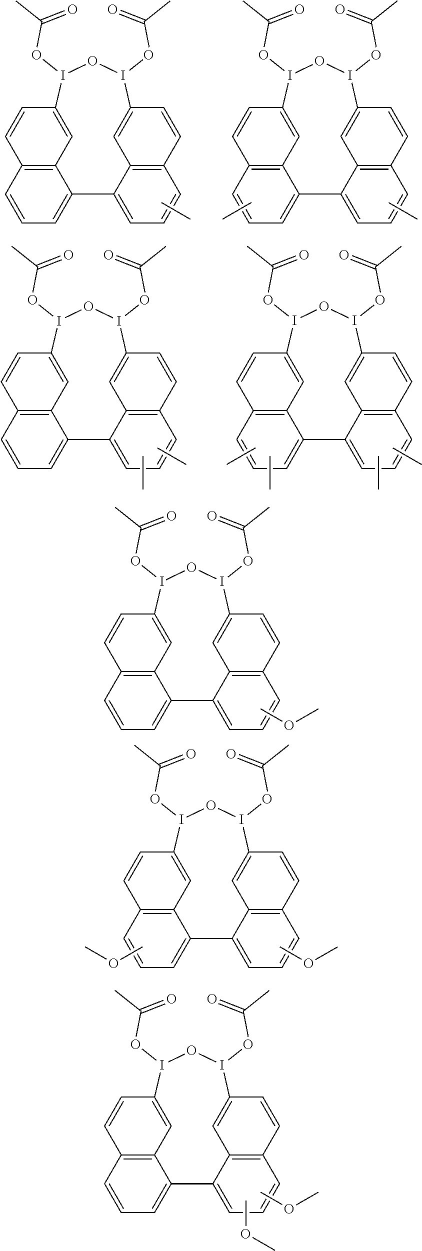

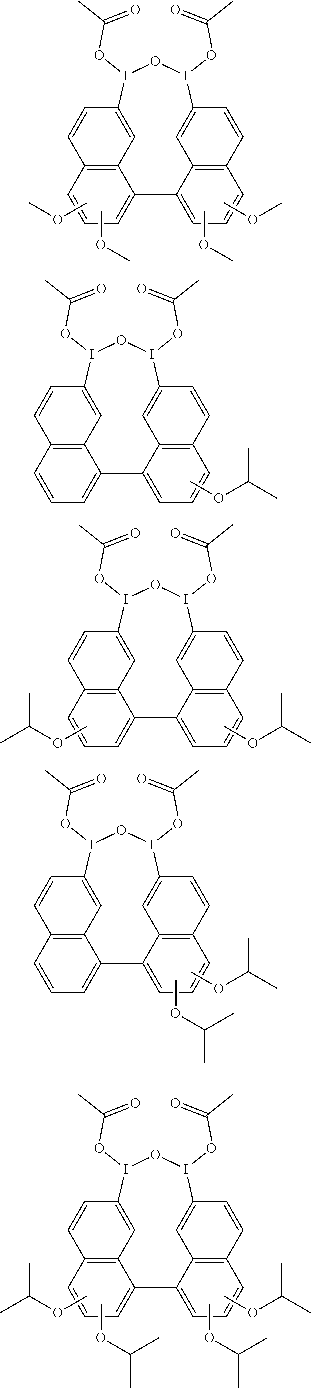

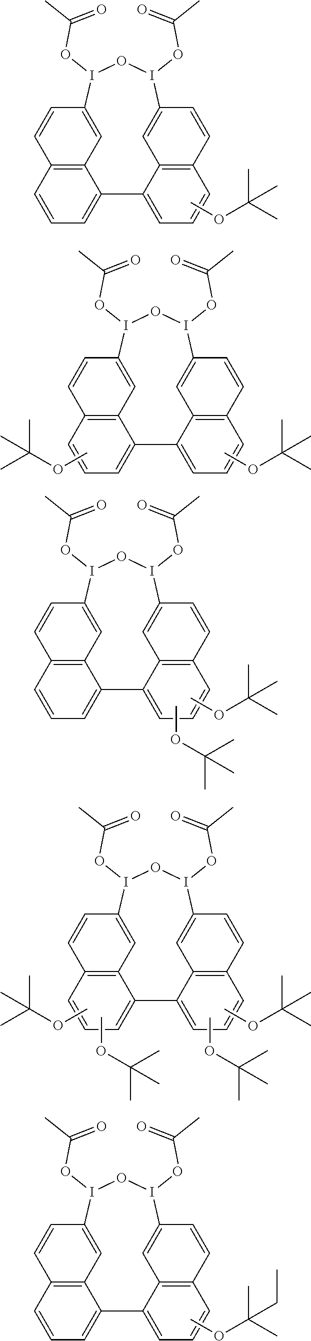

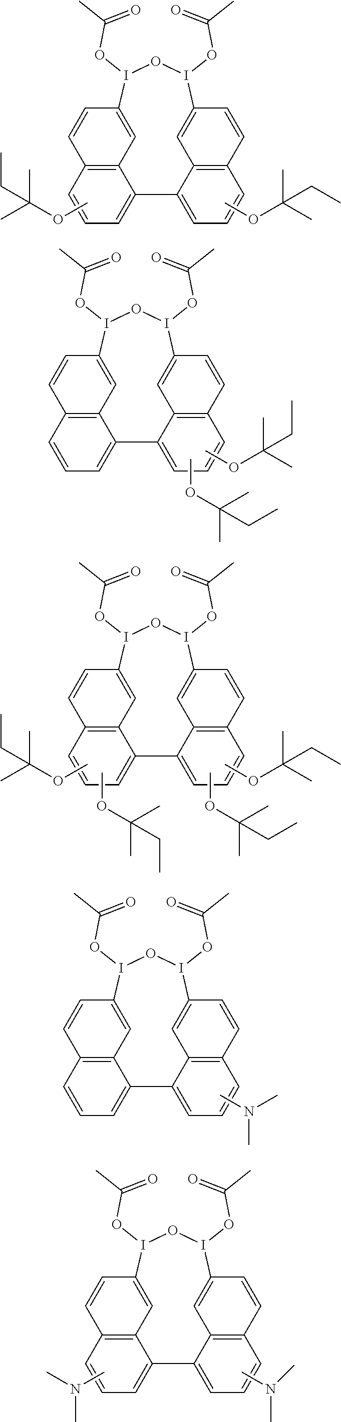

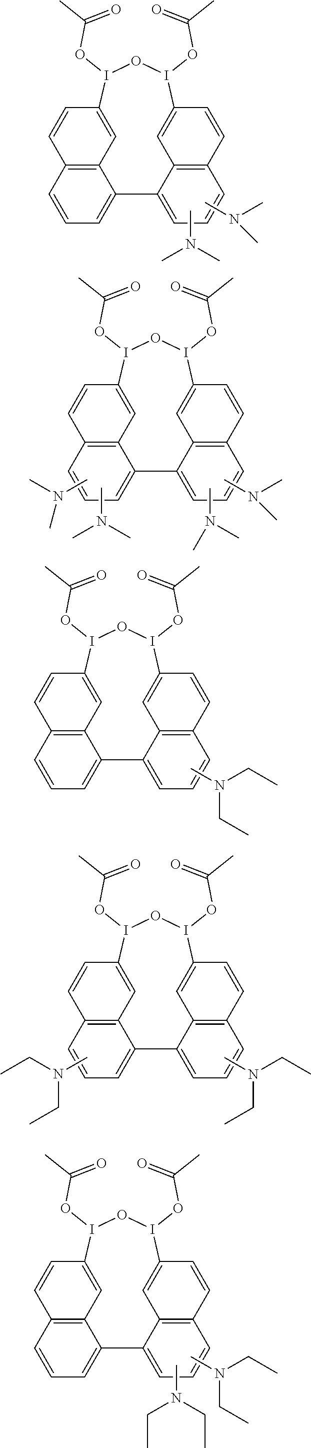

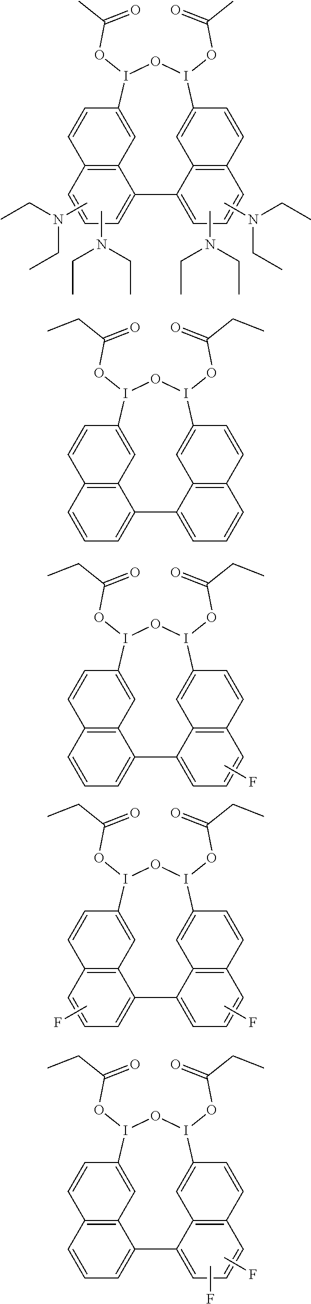

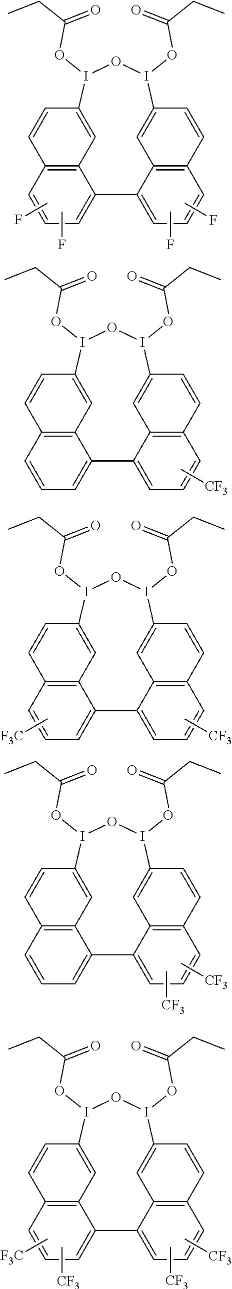

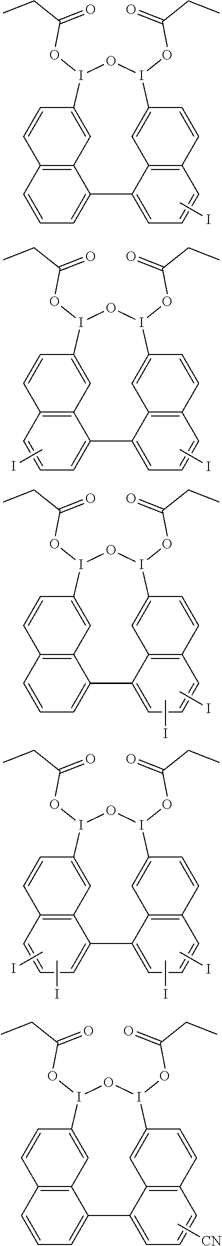

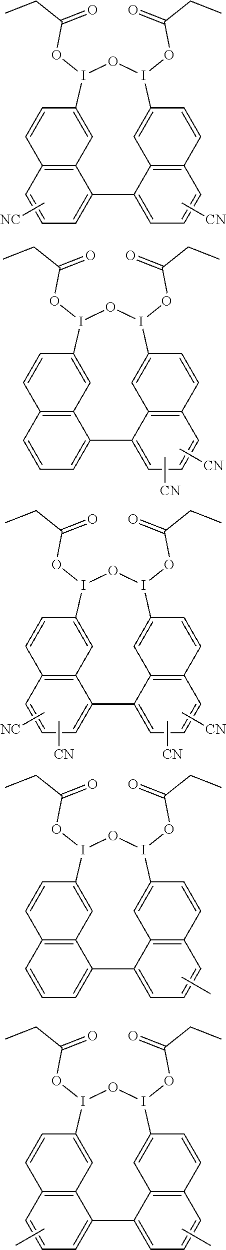

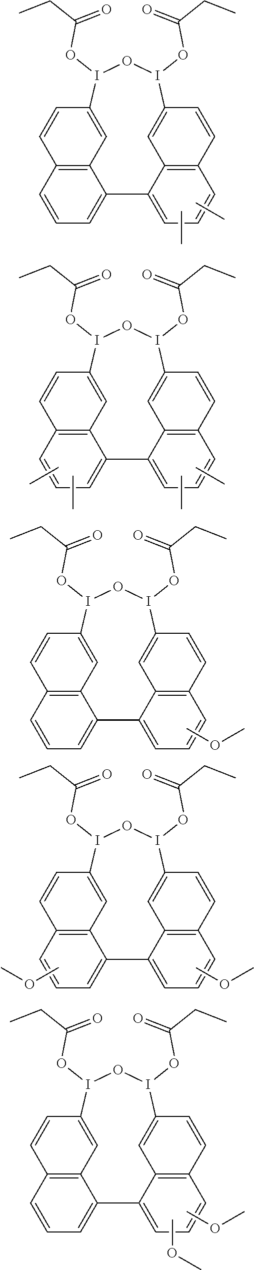

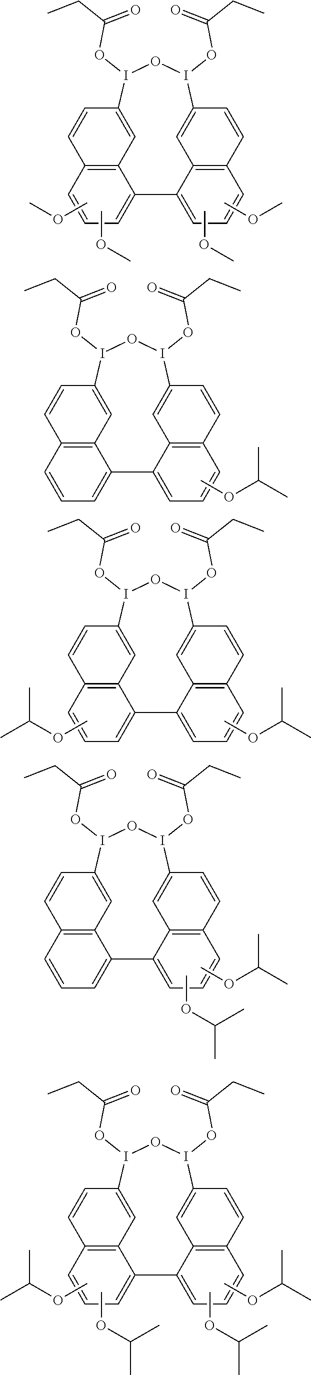

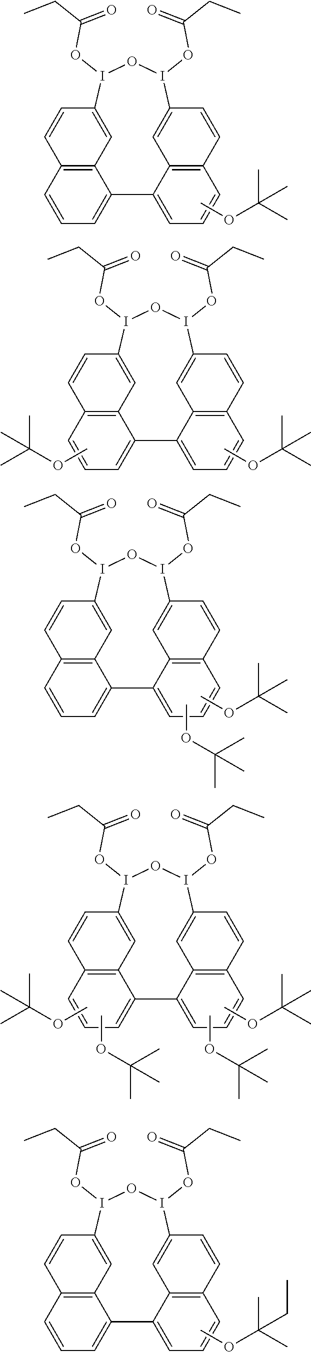

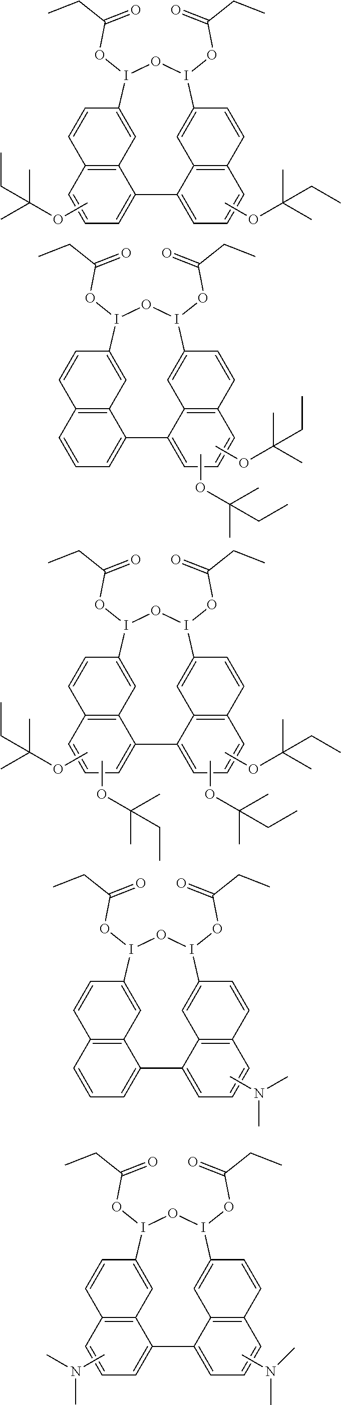

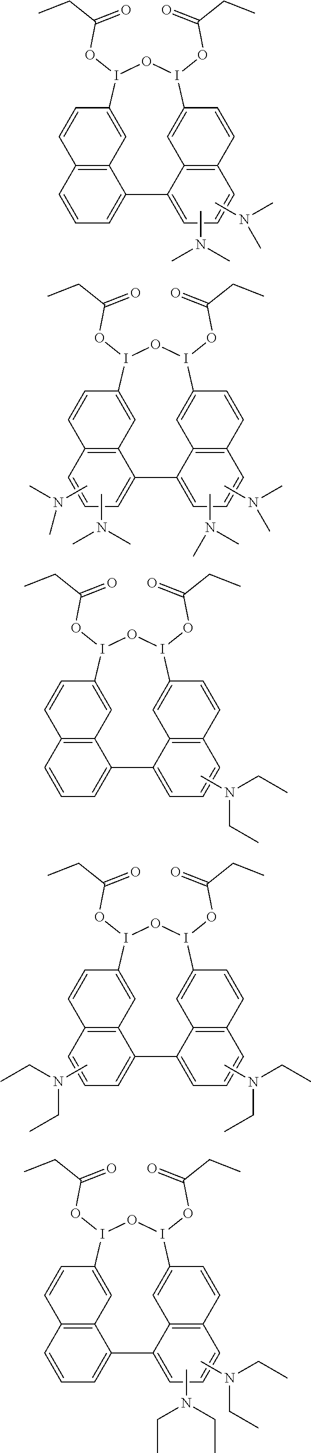

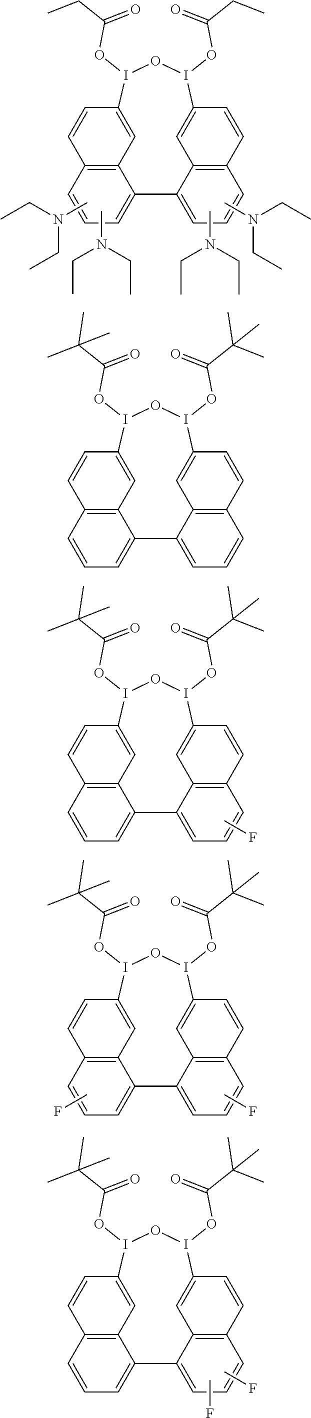

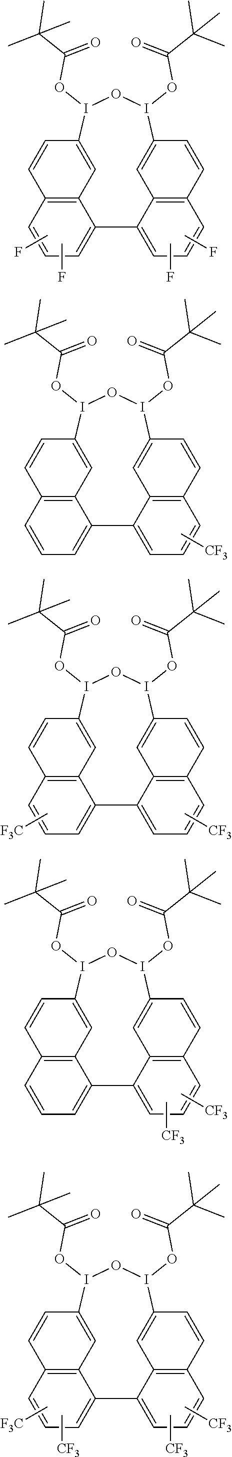

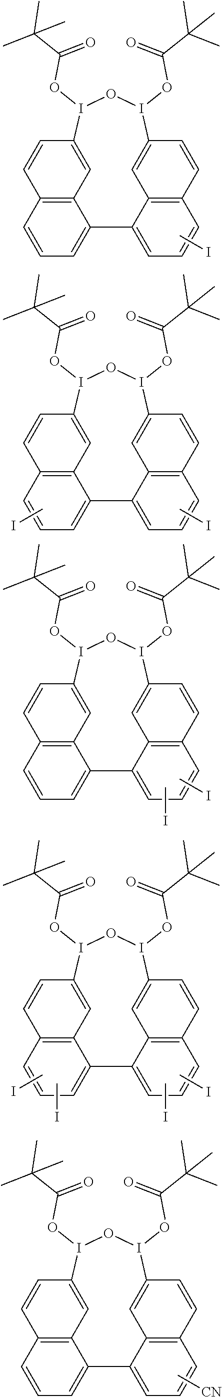

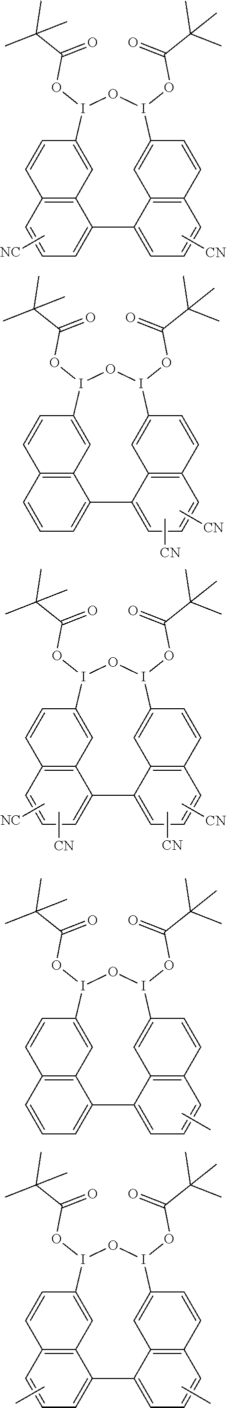

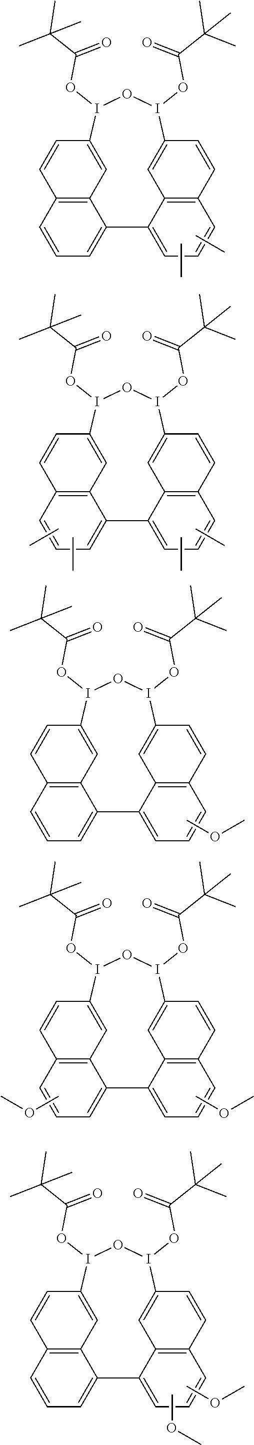

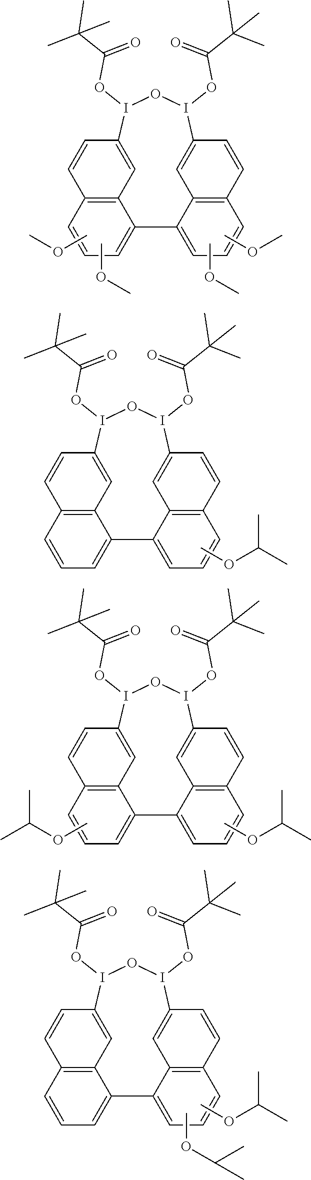

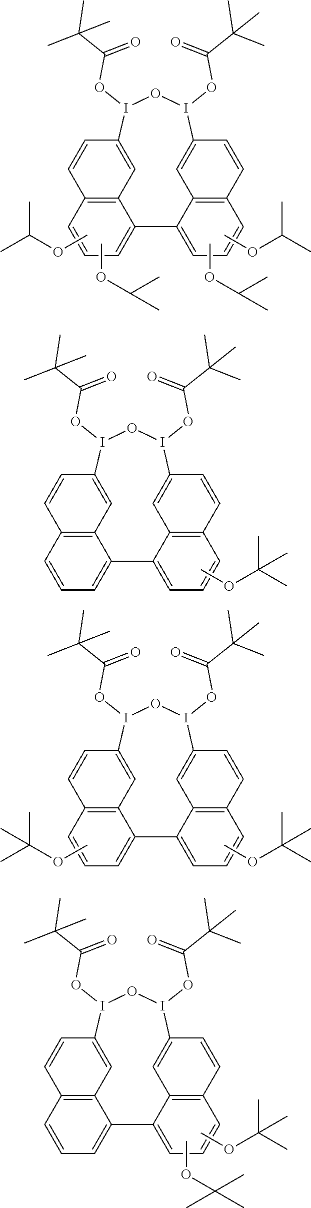

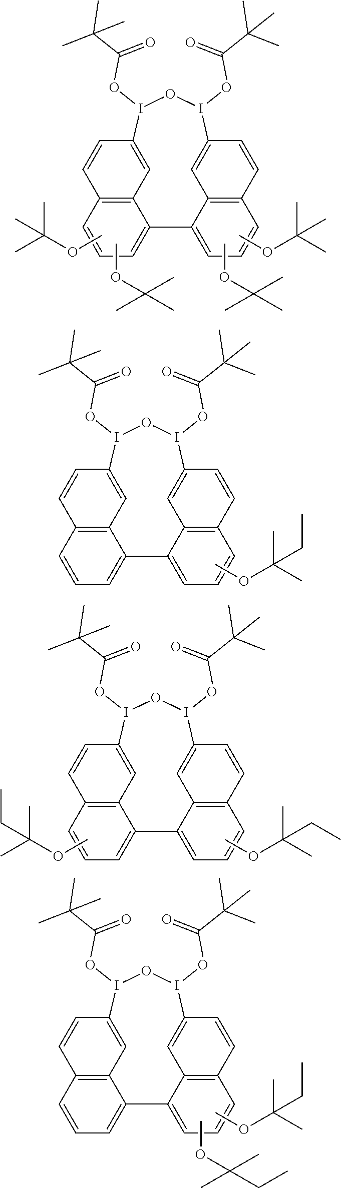

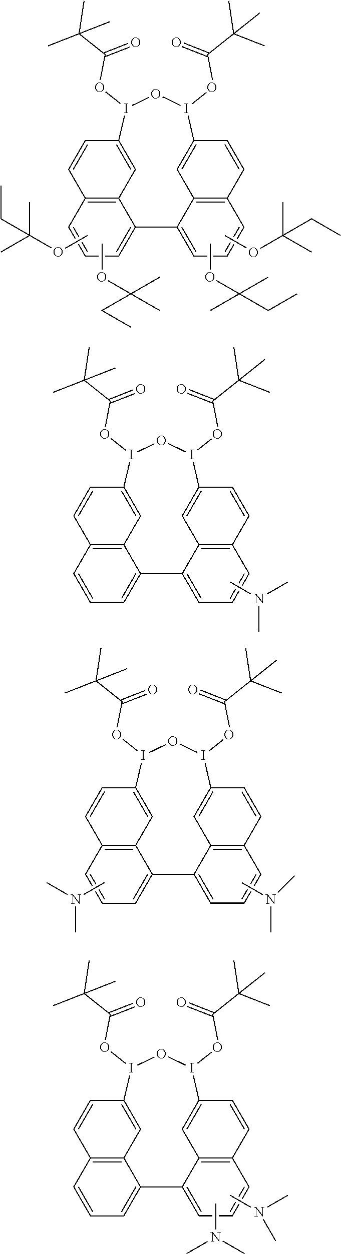

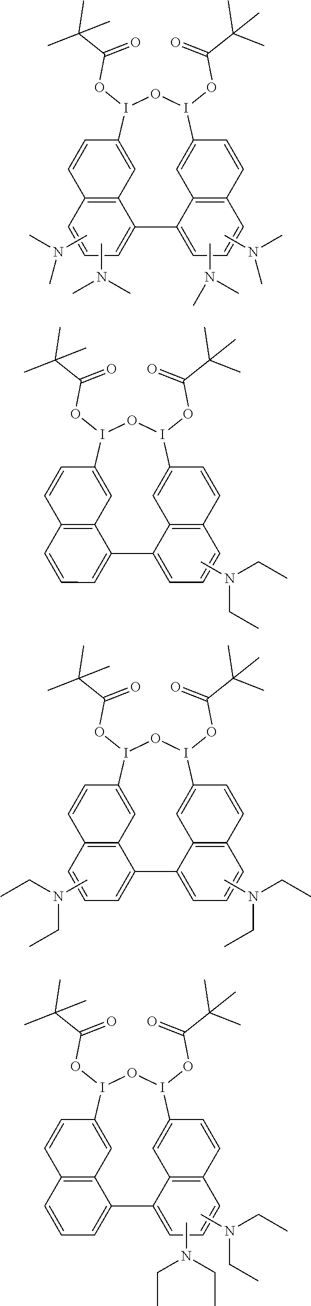

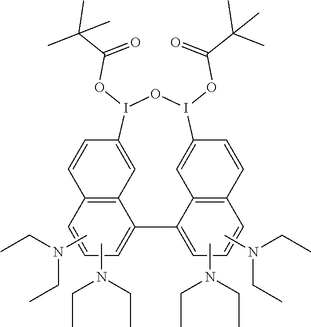

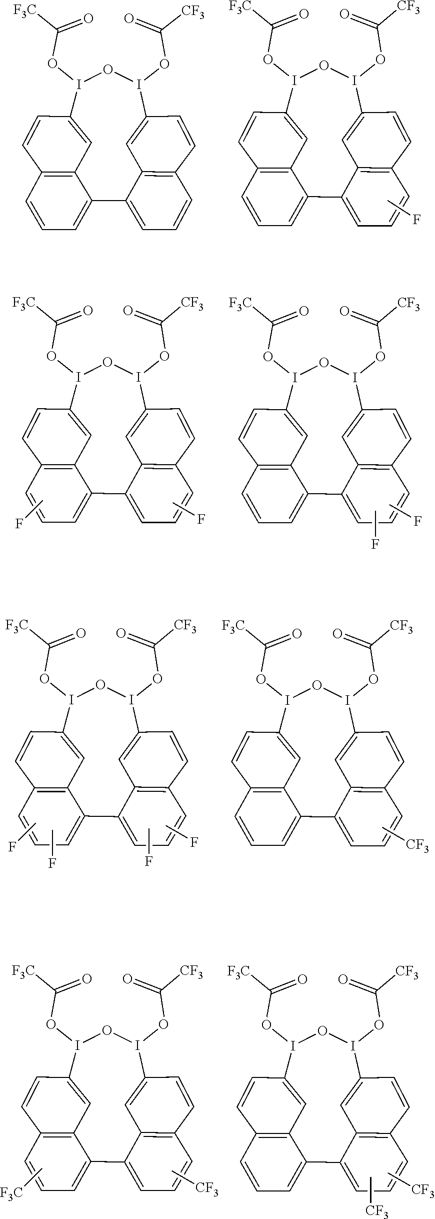

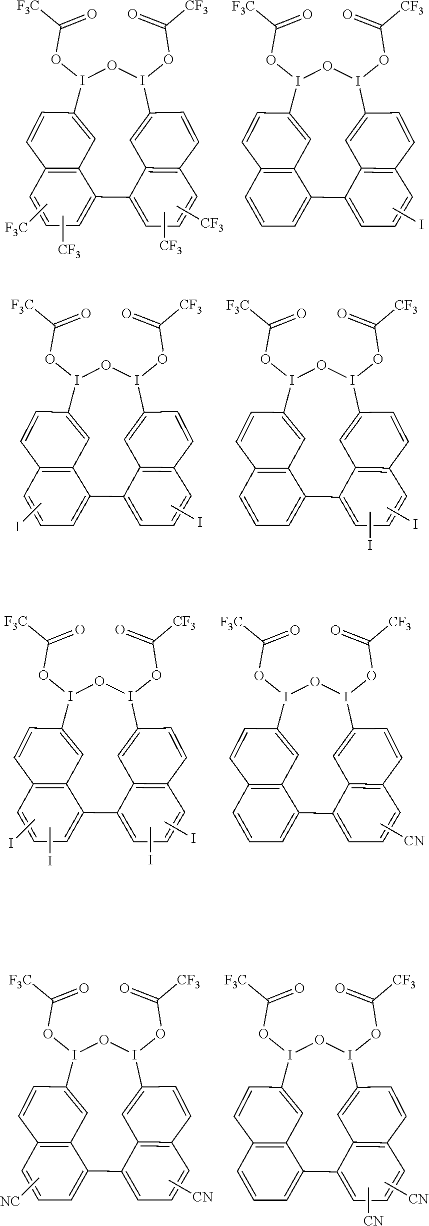

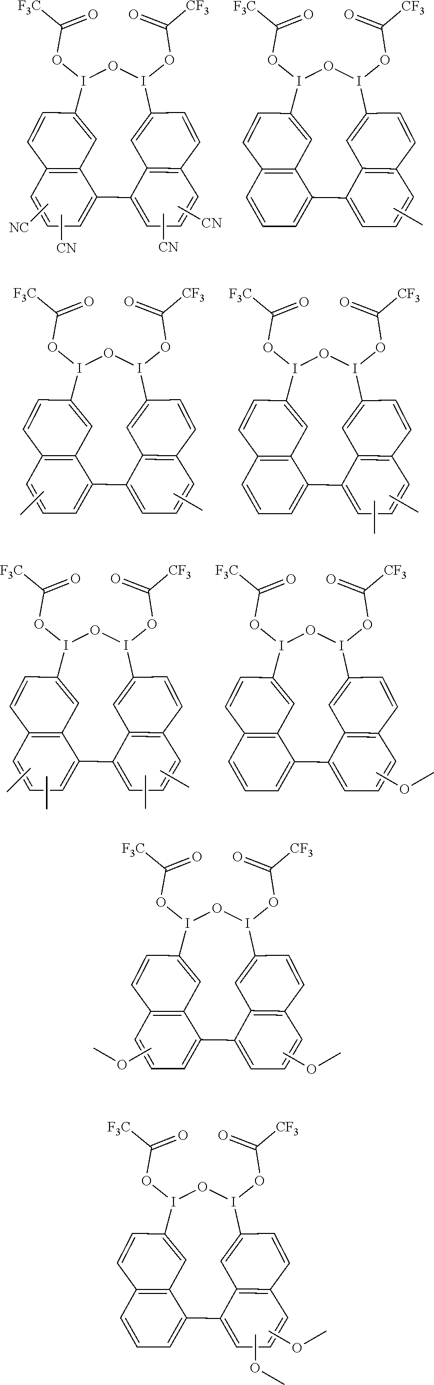

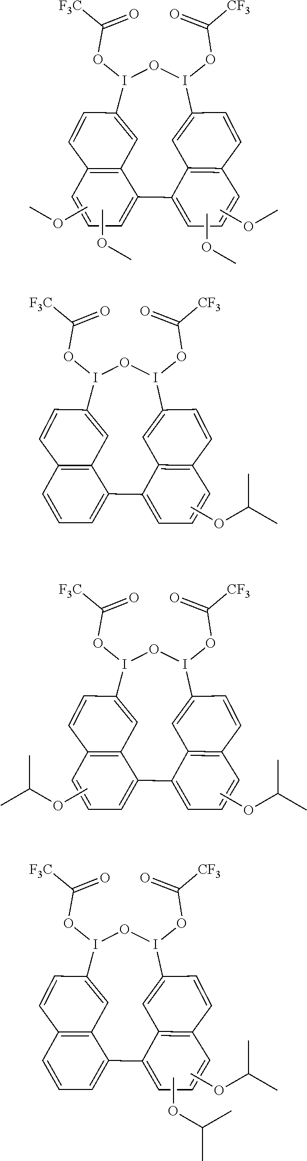

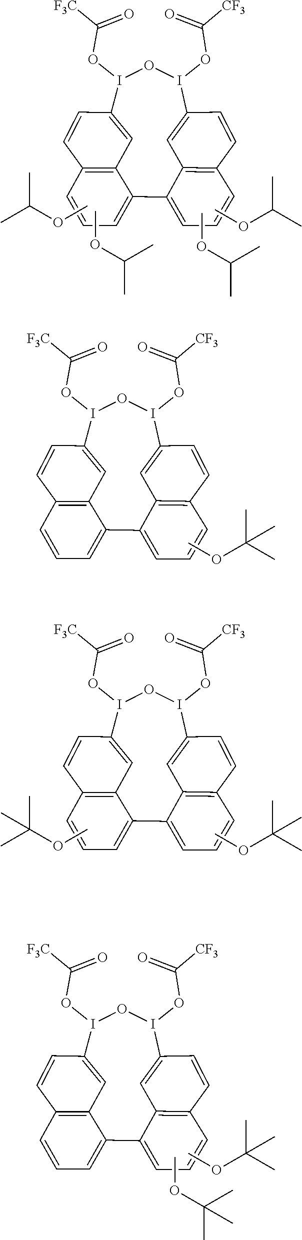

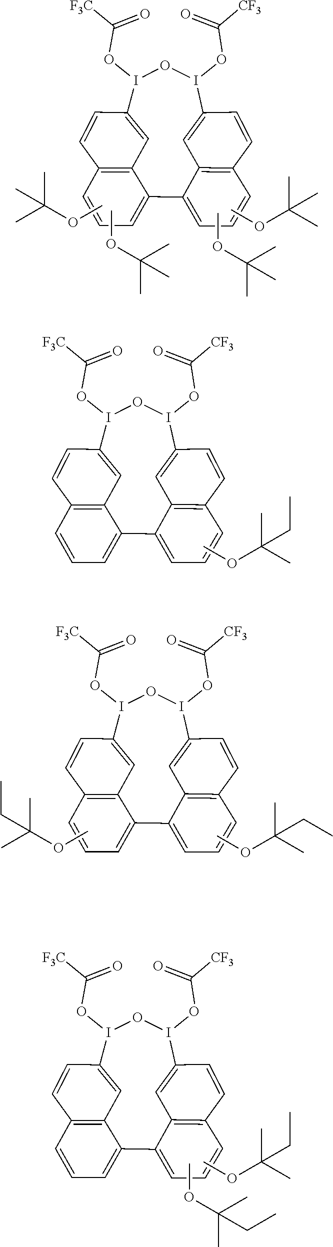

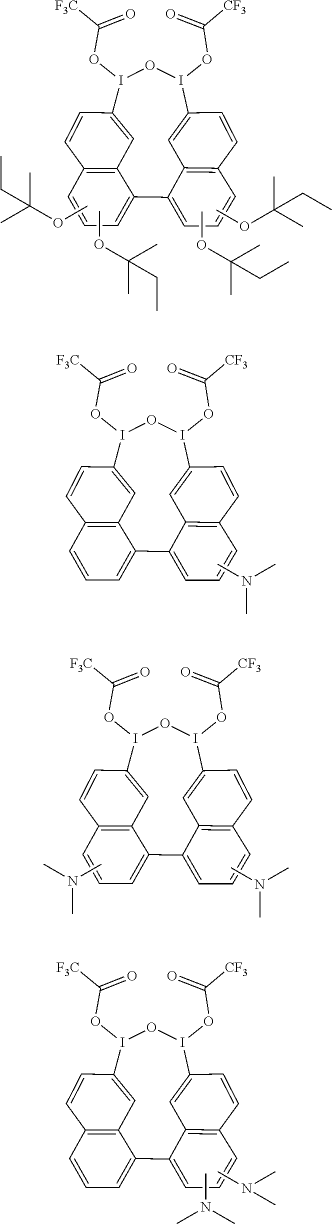

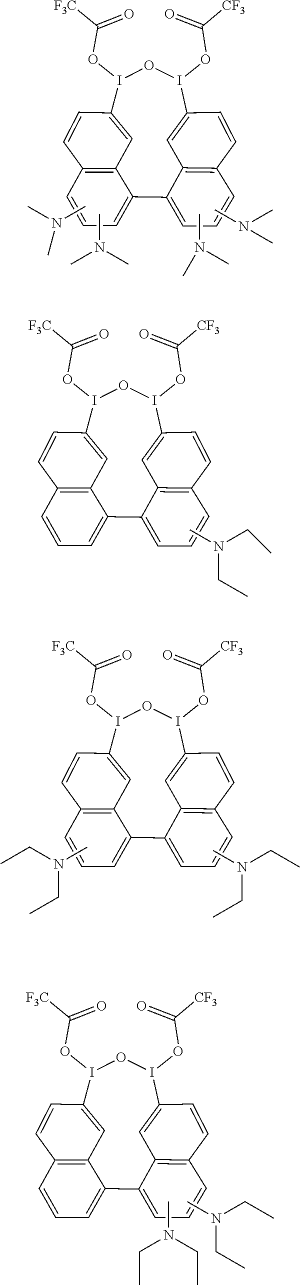

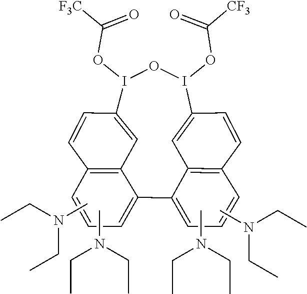

Examples of the hypervalent iodine compound having the formula (8) are shown

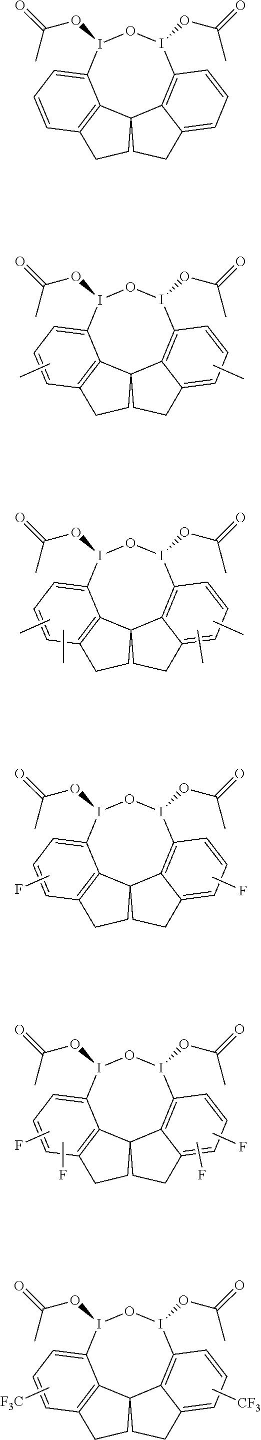

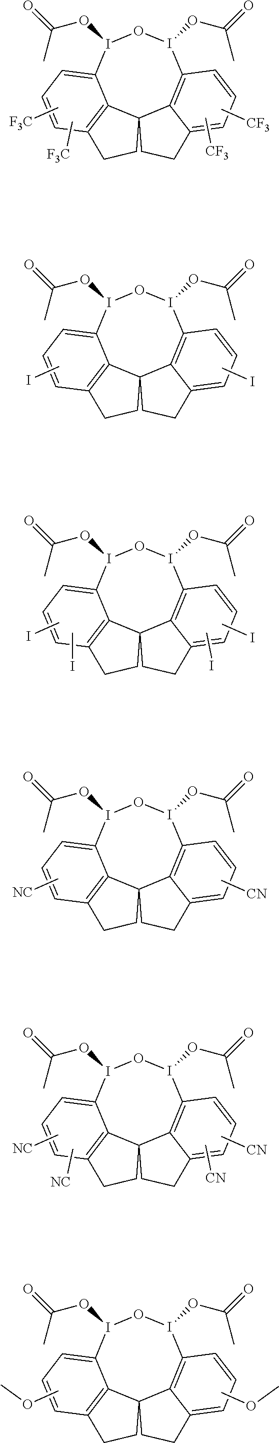

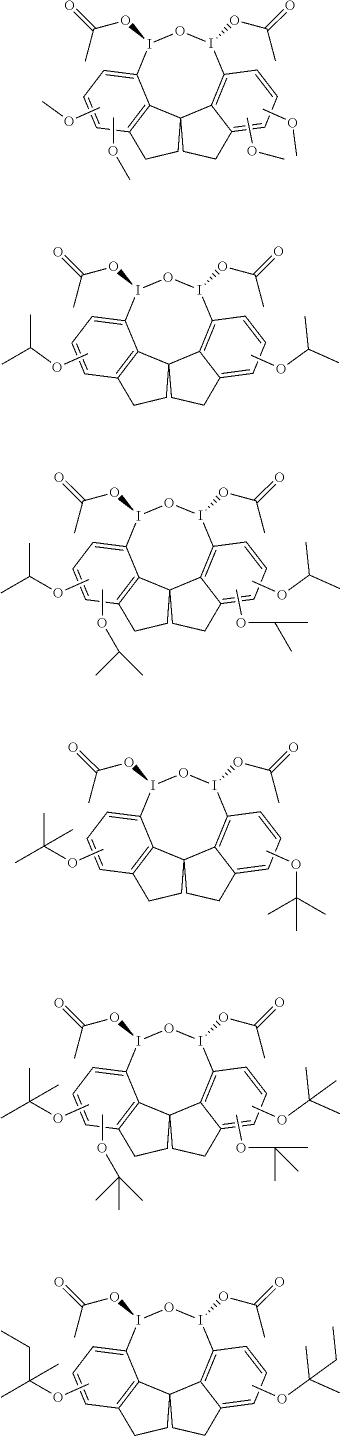

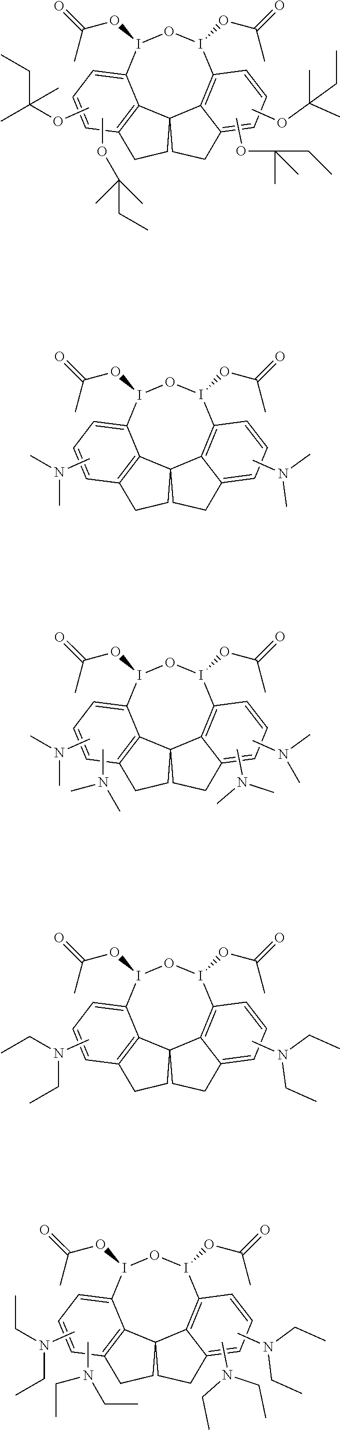

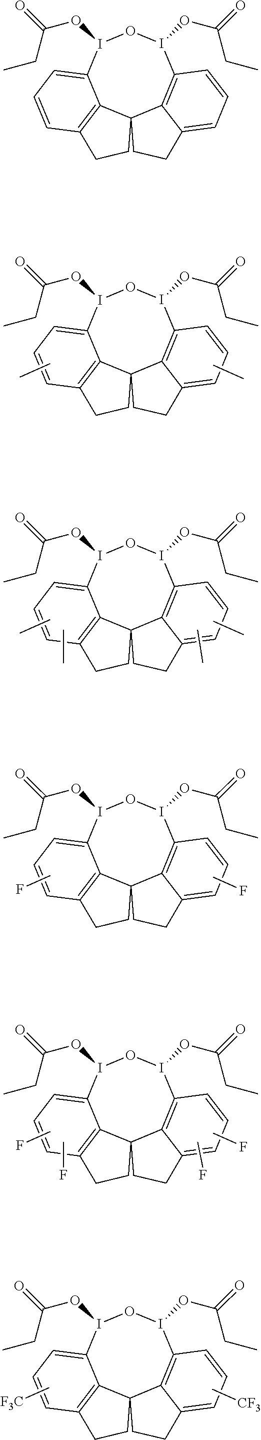

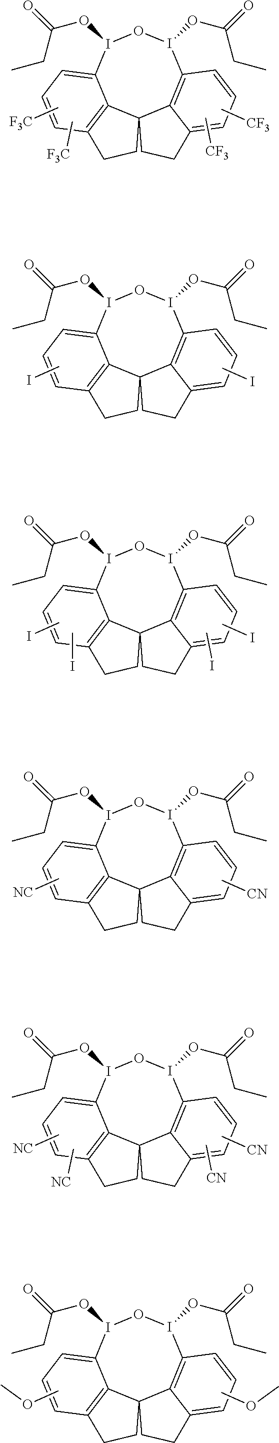

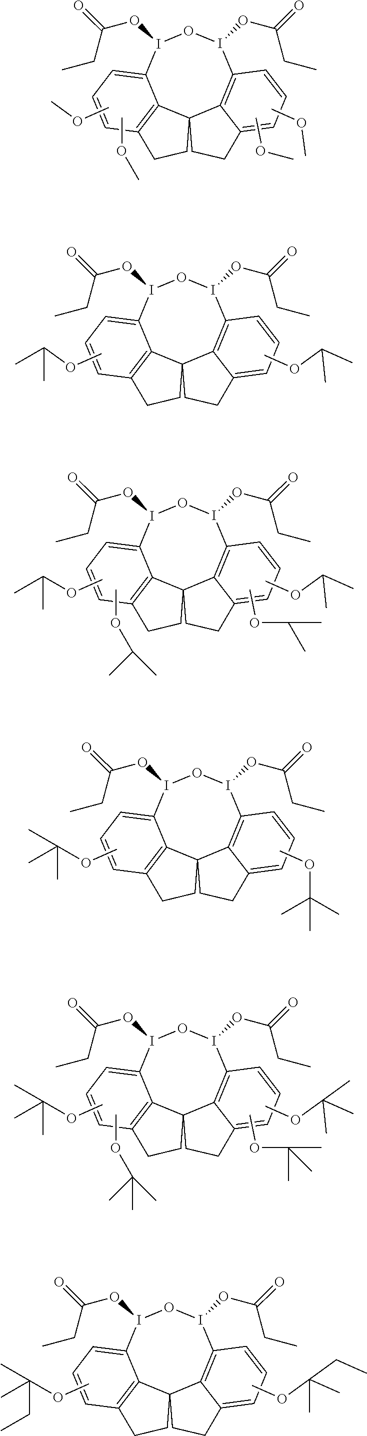

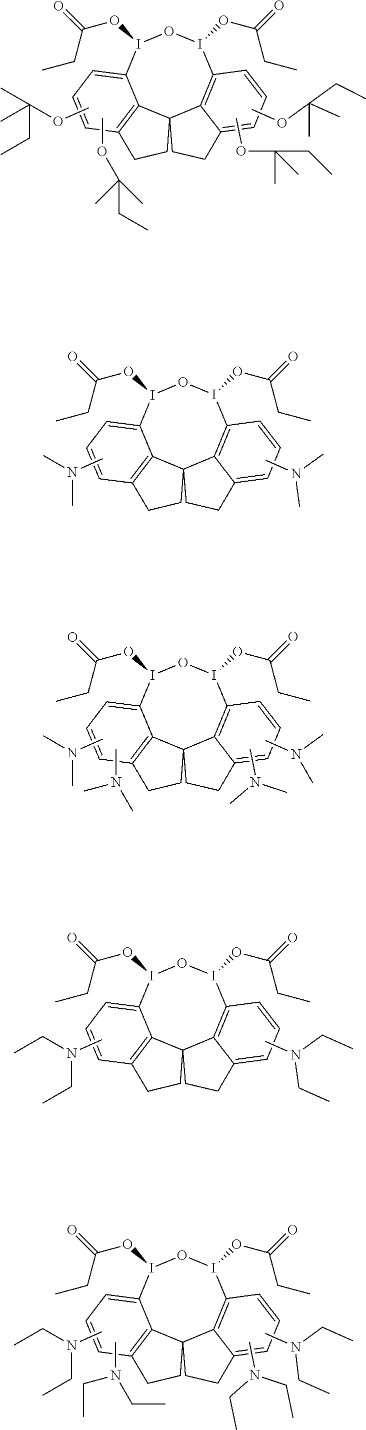

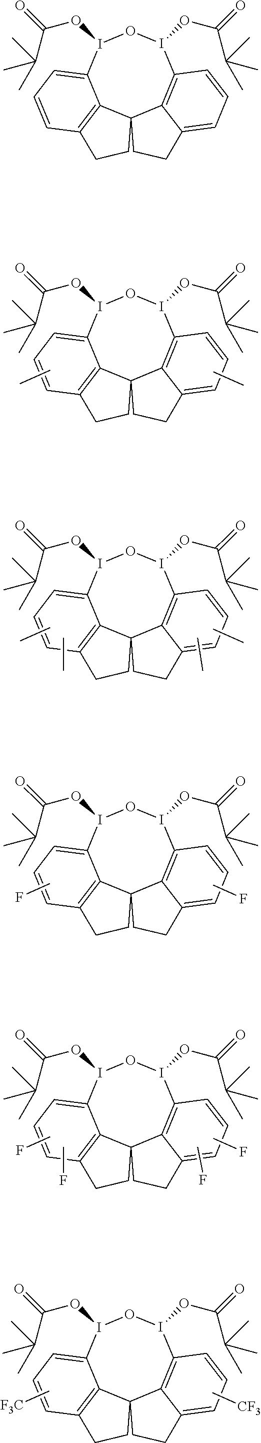

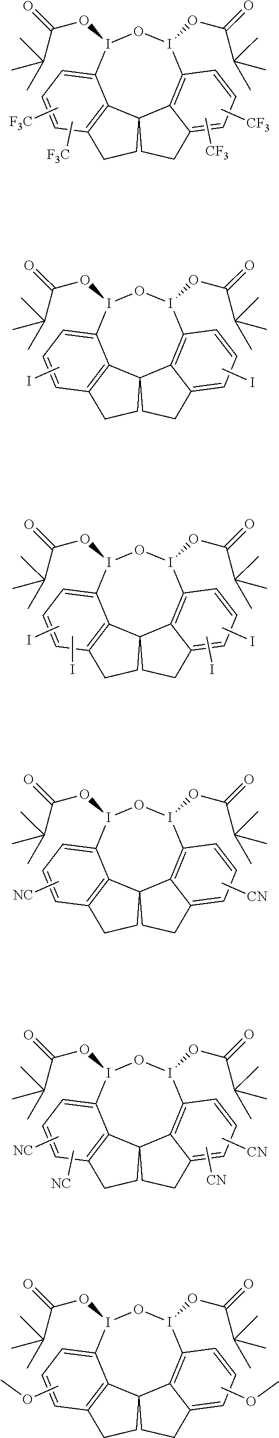

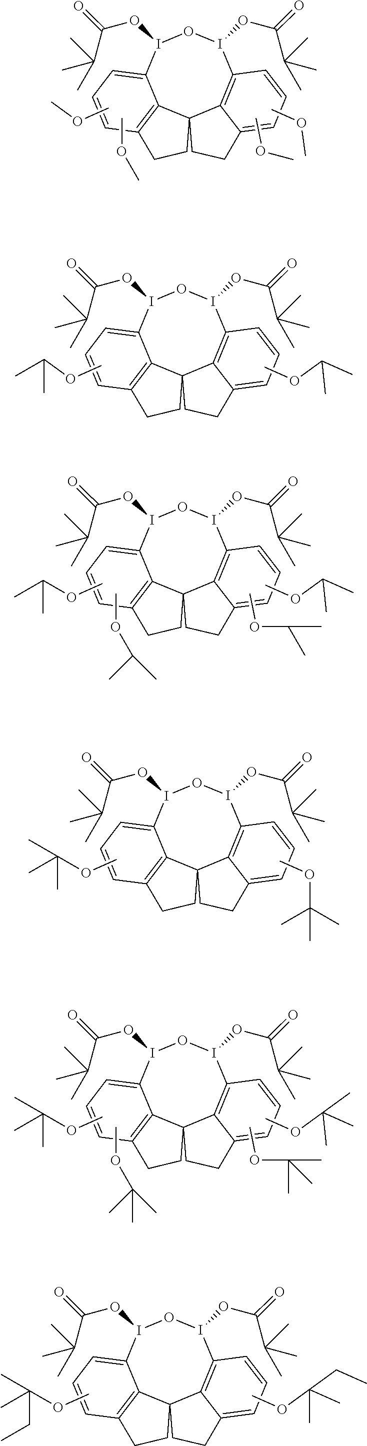

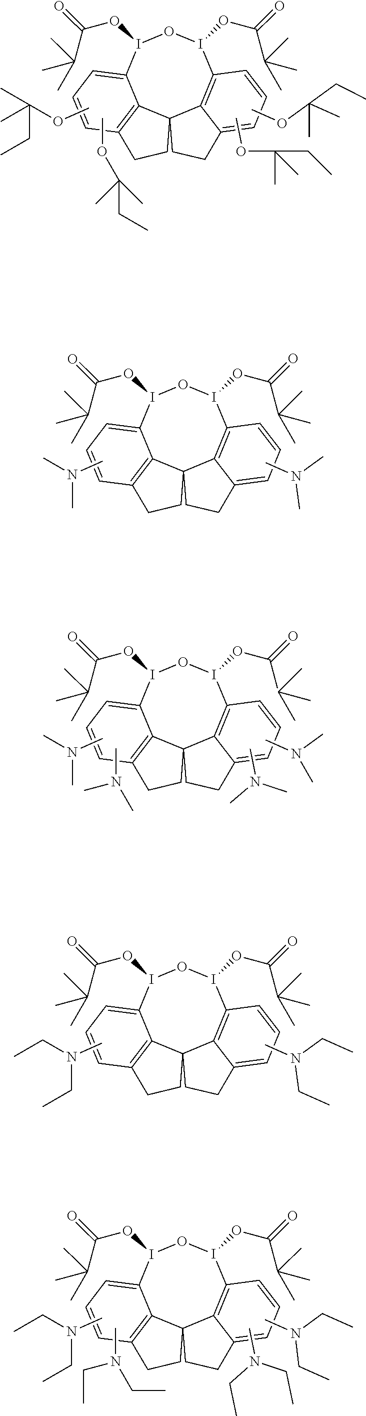

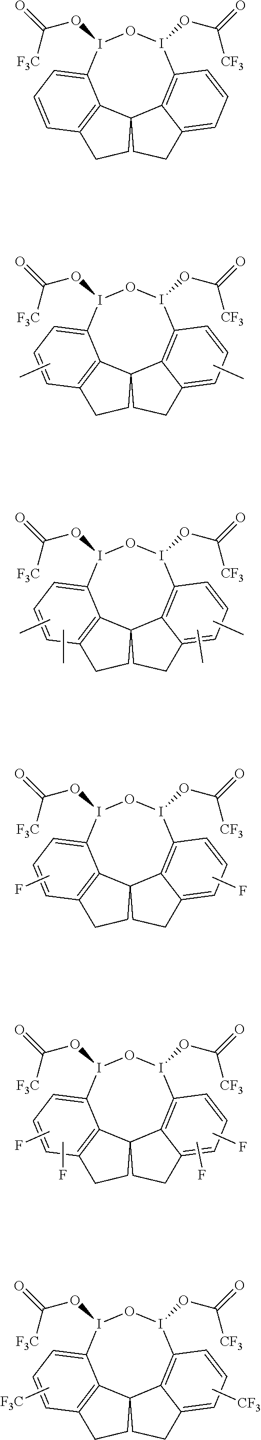

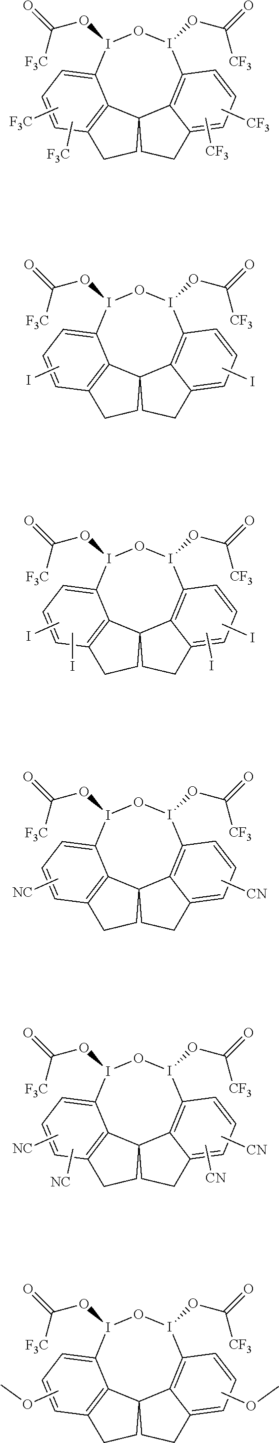

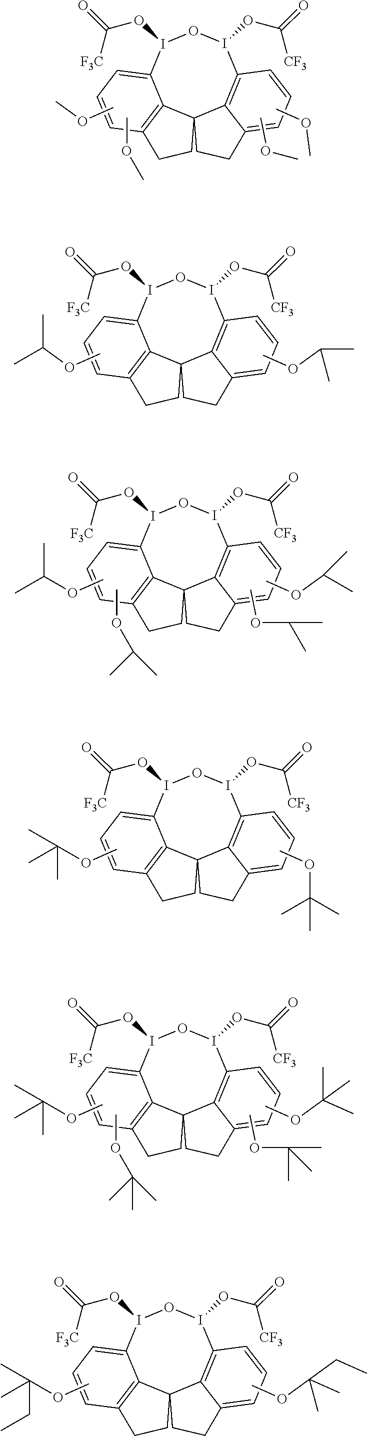

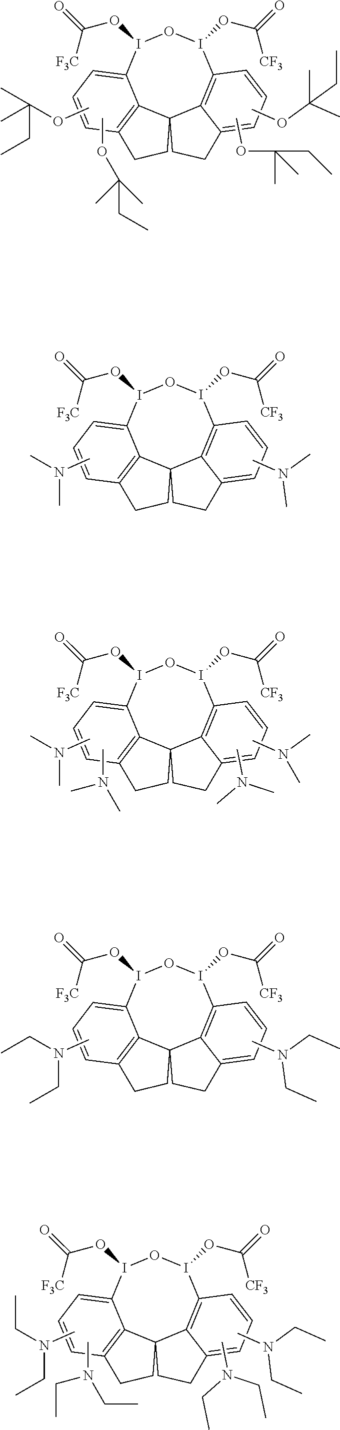

Examples of the hypervalent iodine compound having the formula (9) are shown

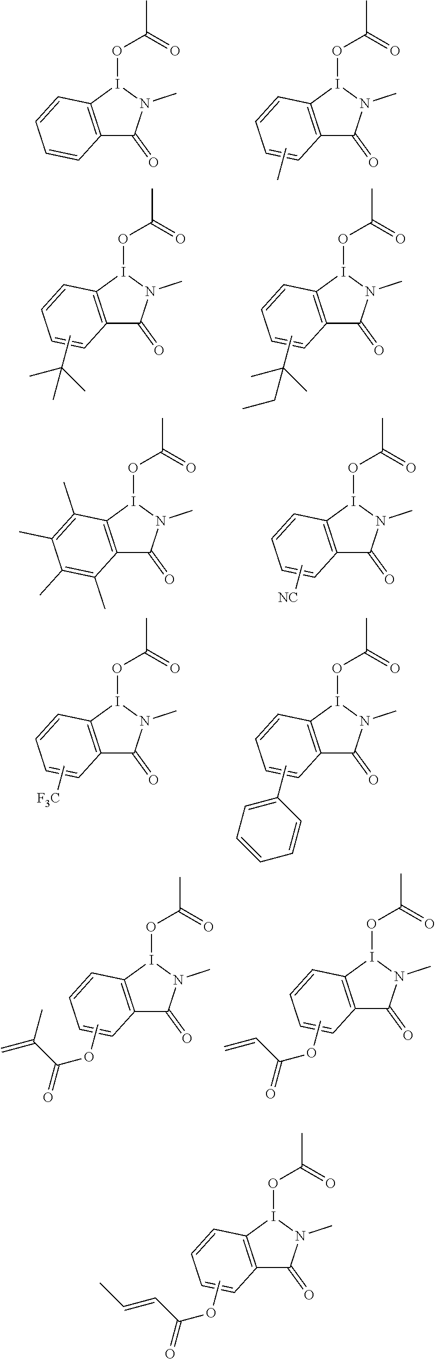

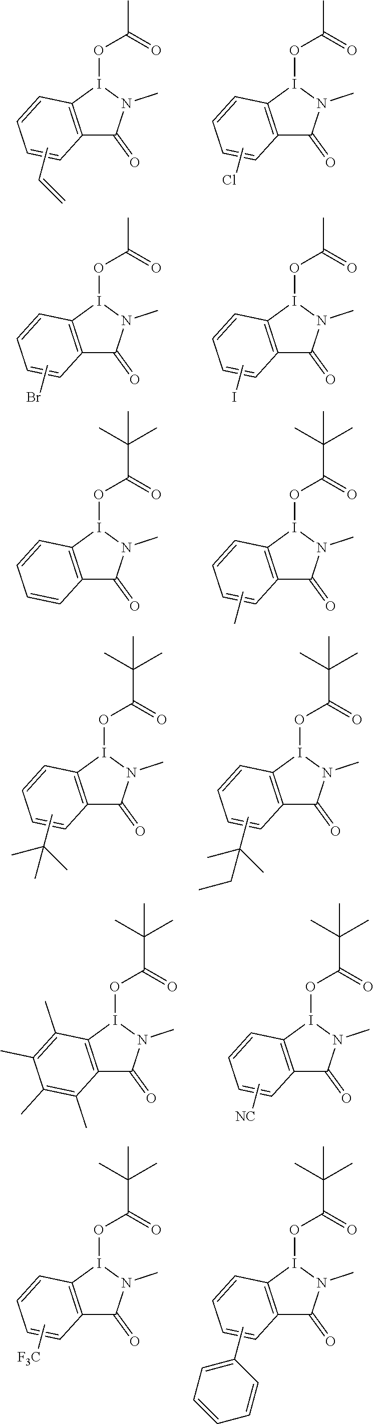

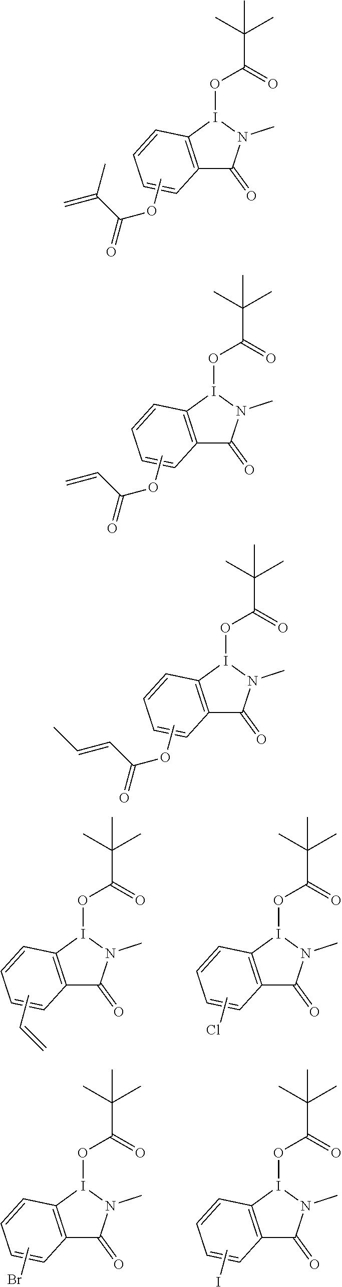

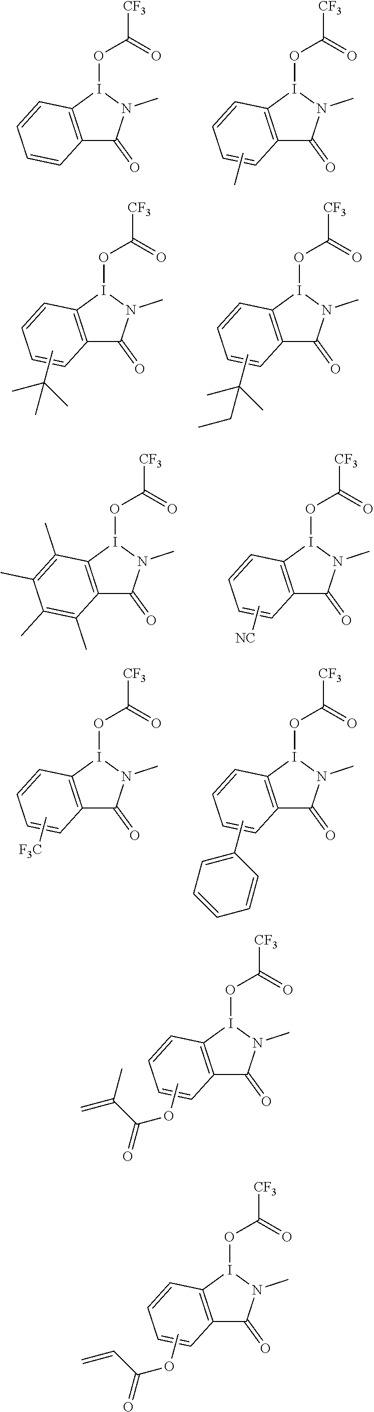

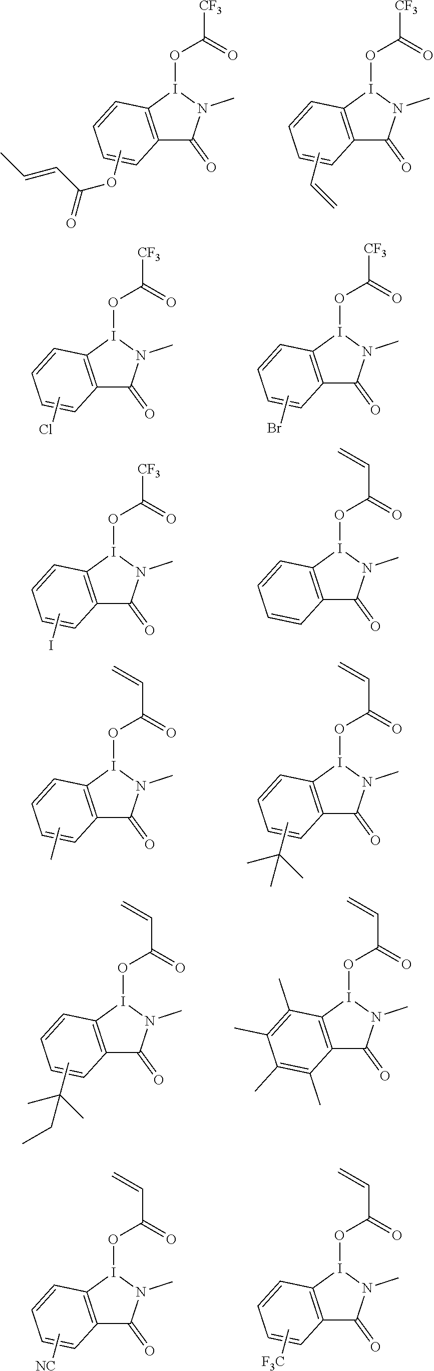

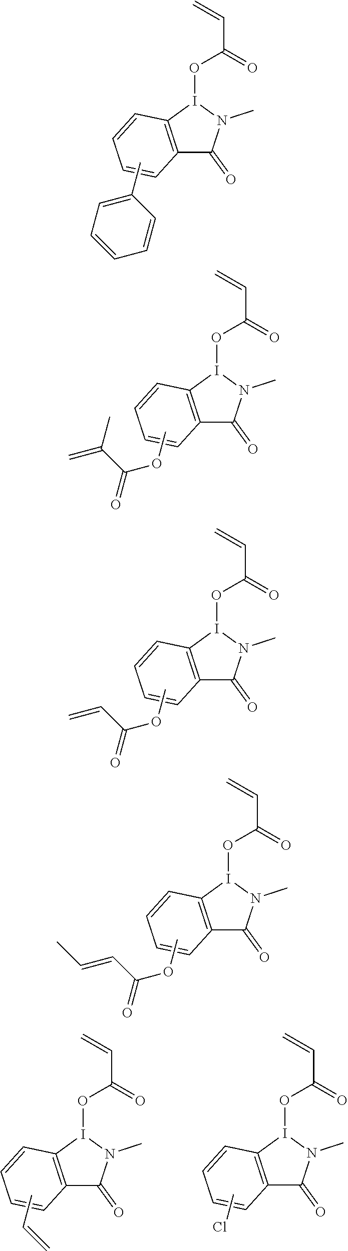

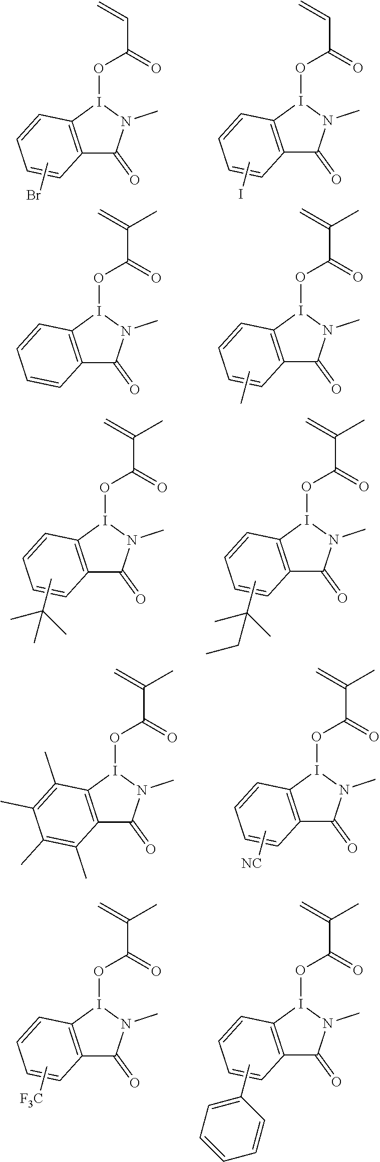

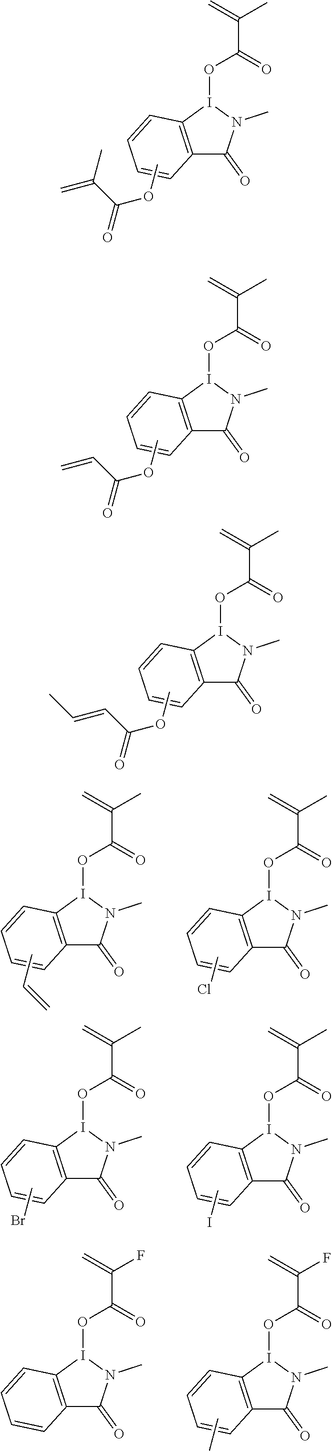

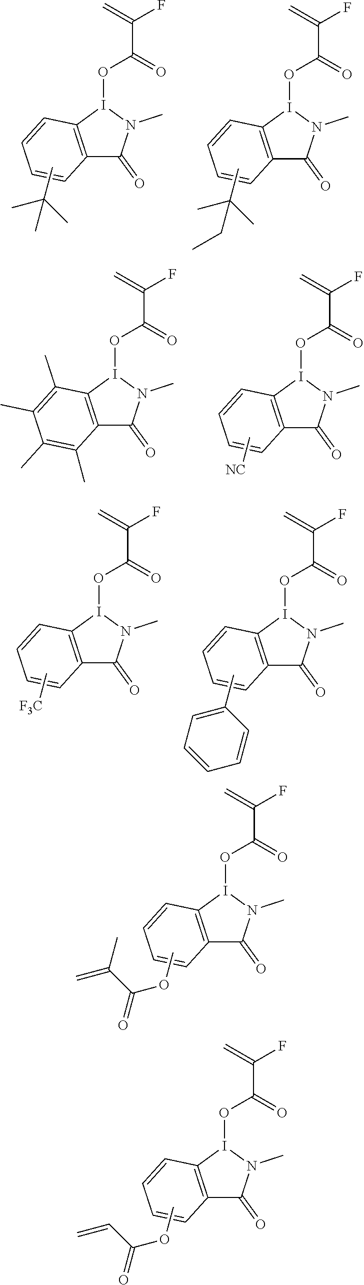

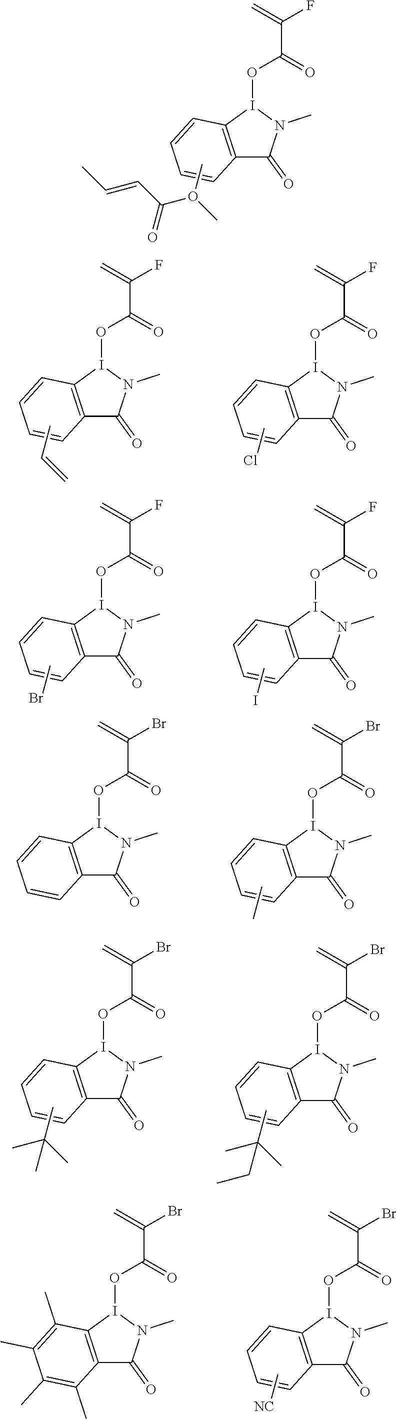

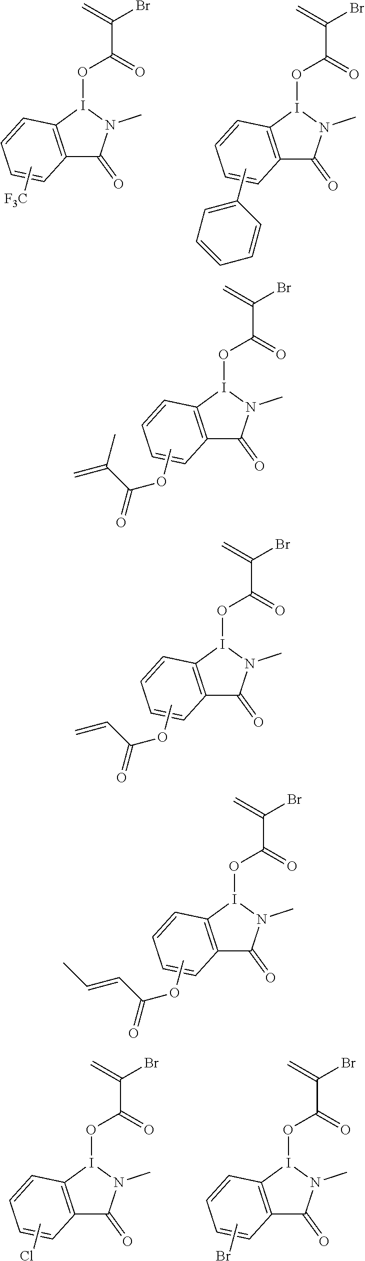

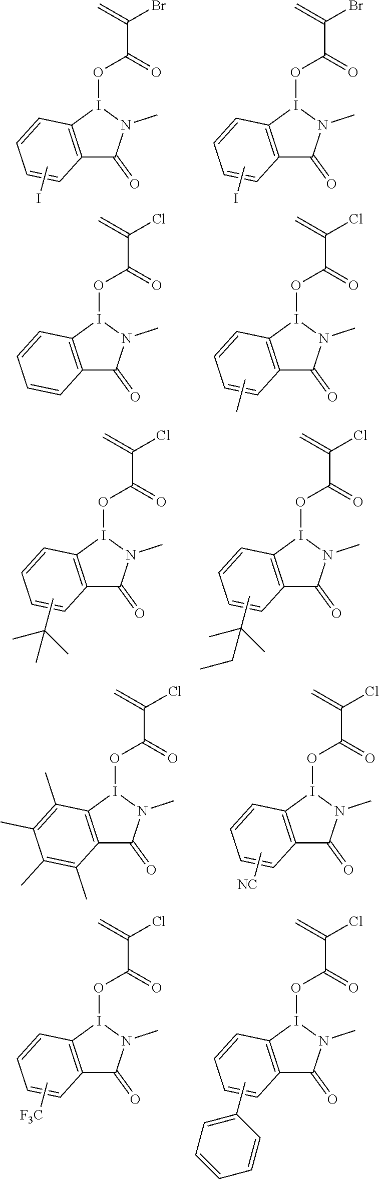

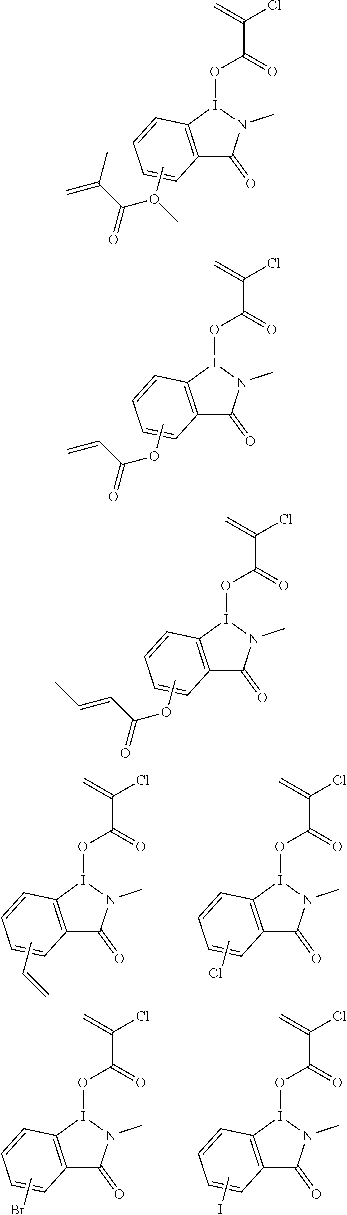

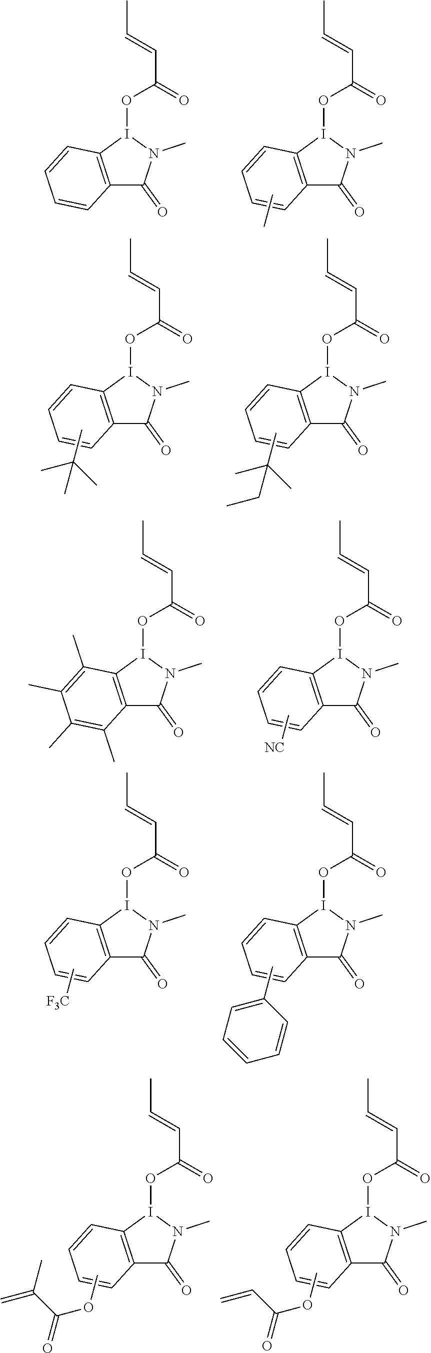

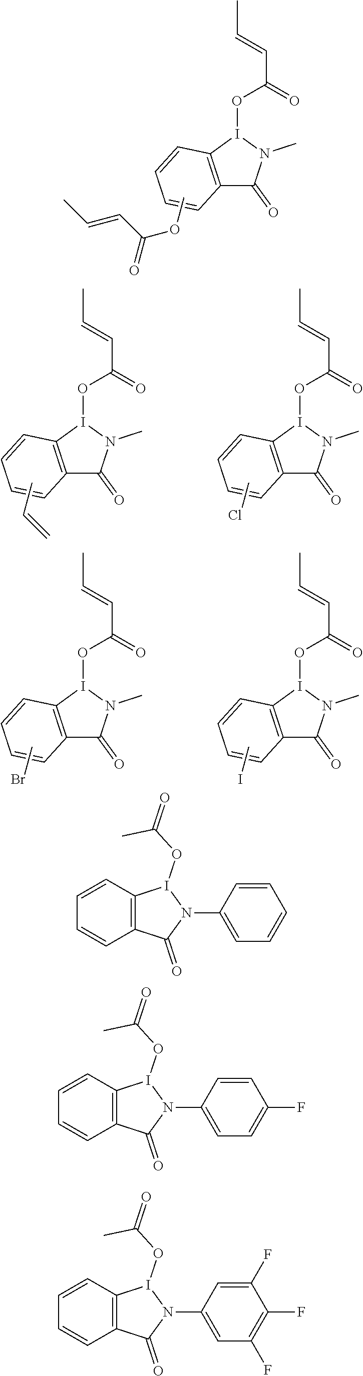

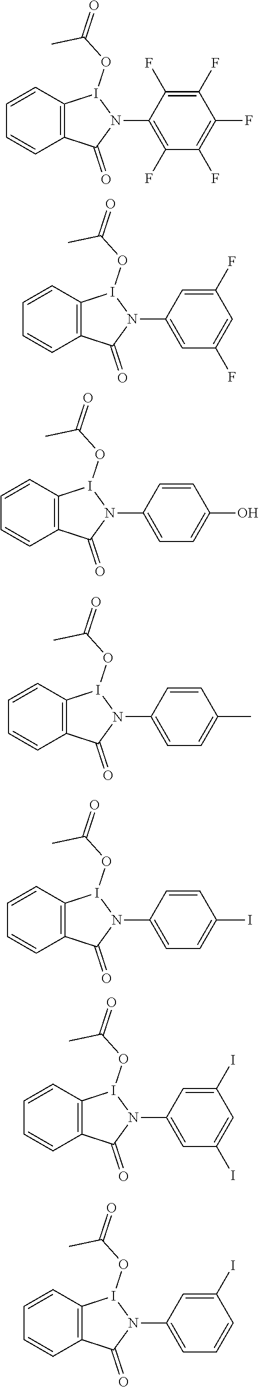

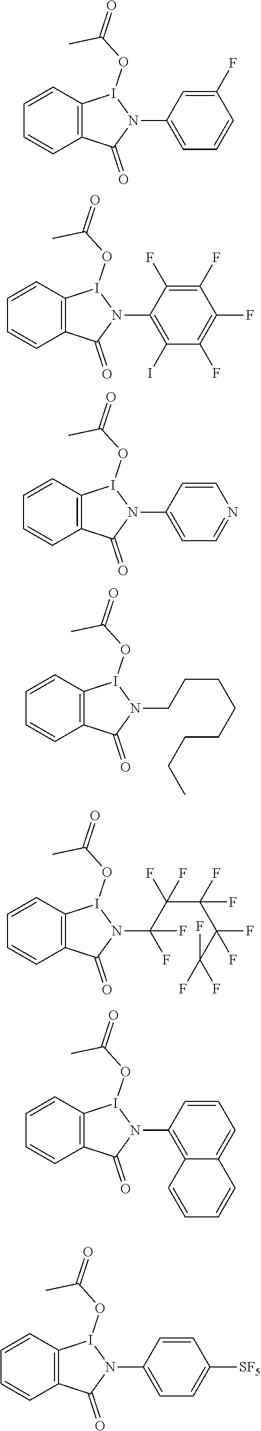

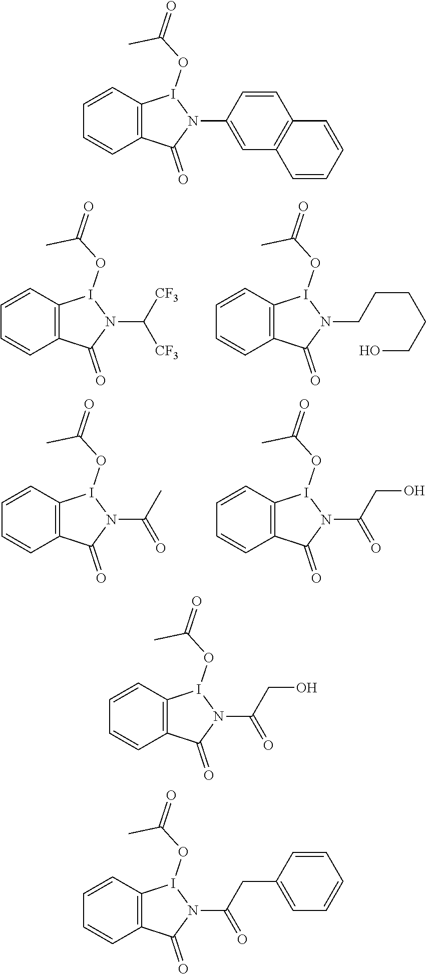

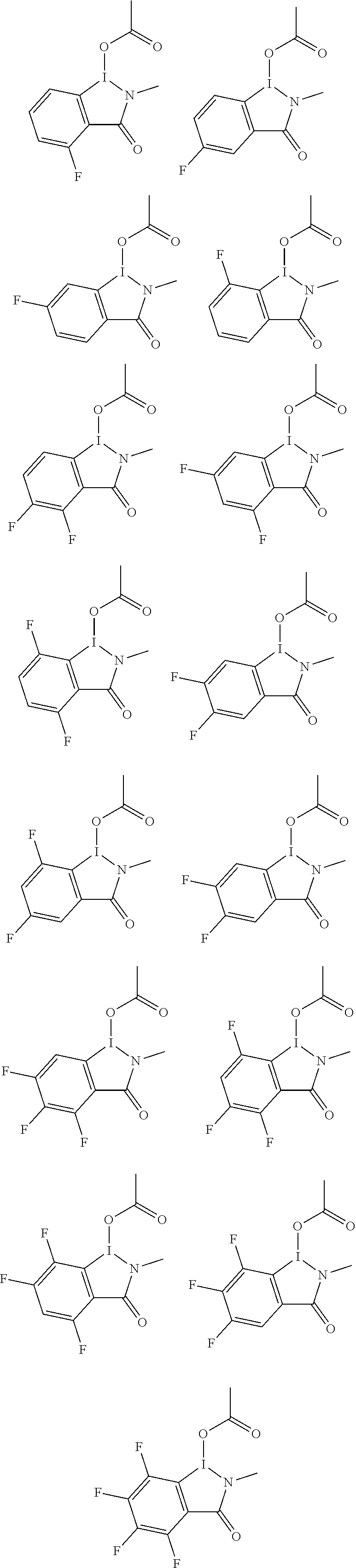

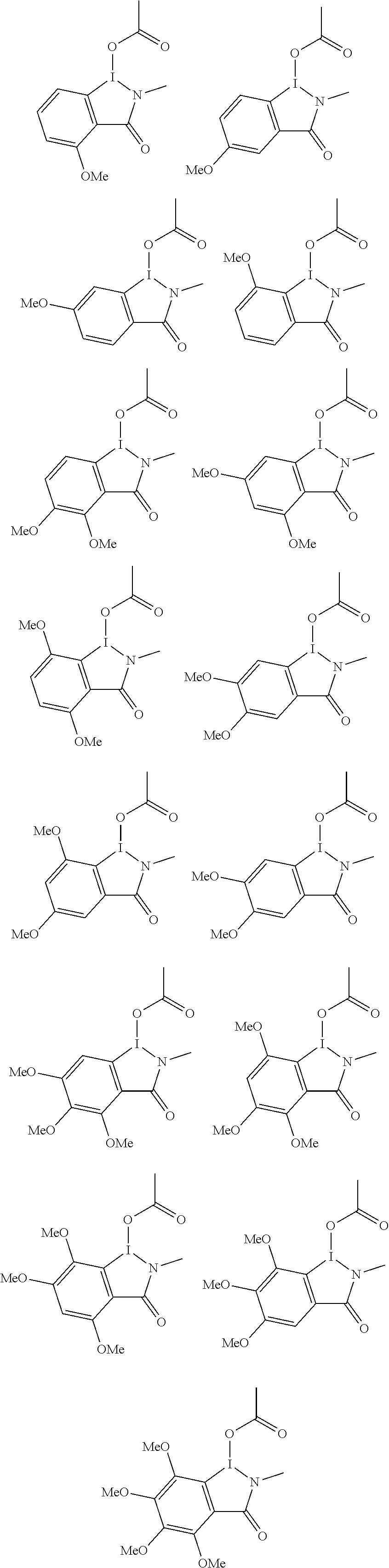

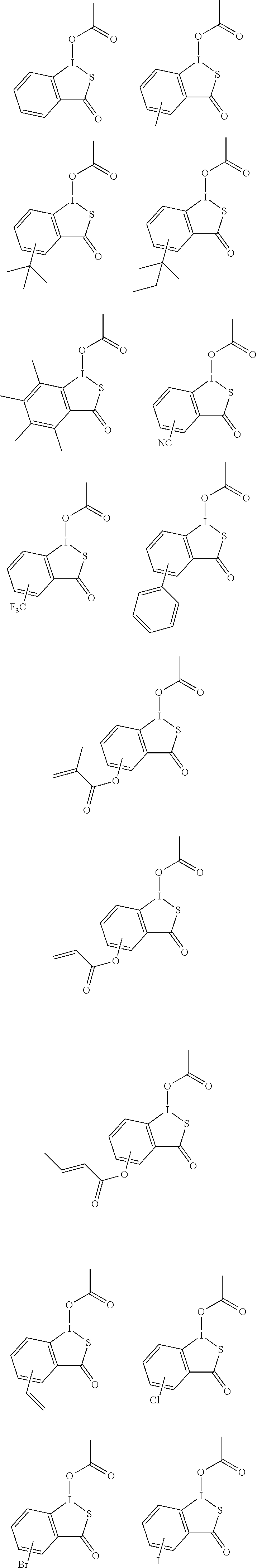

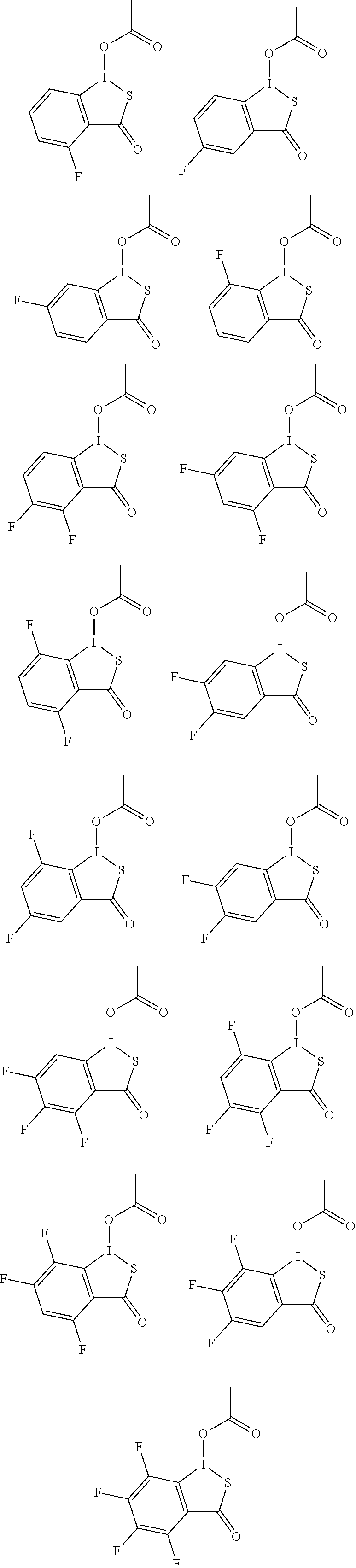

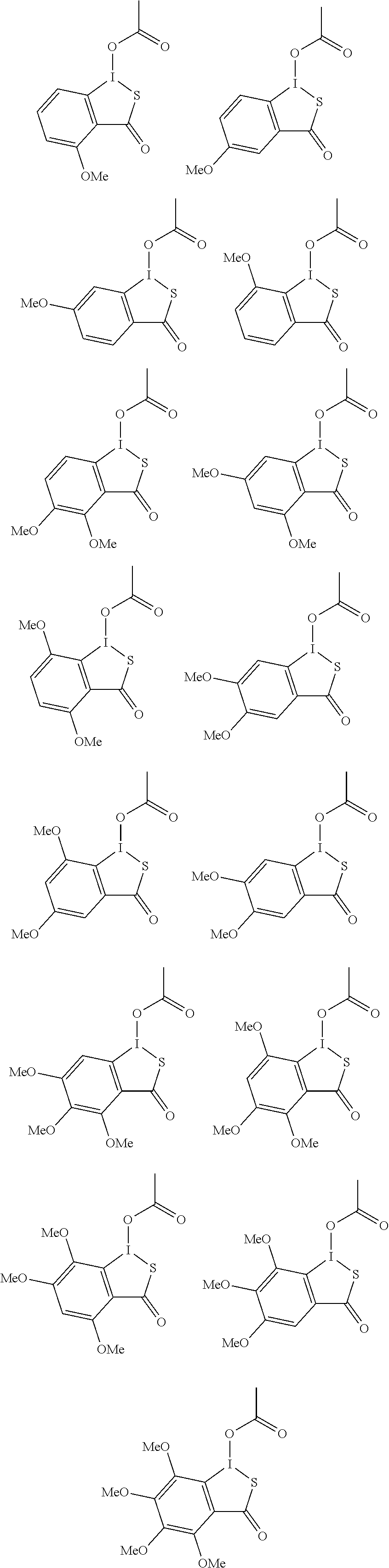

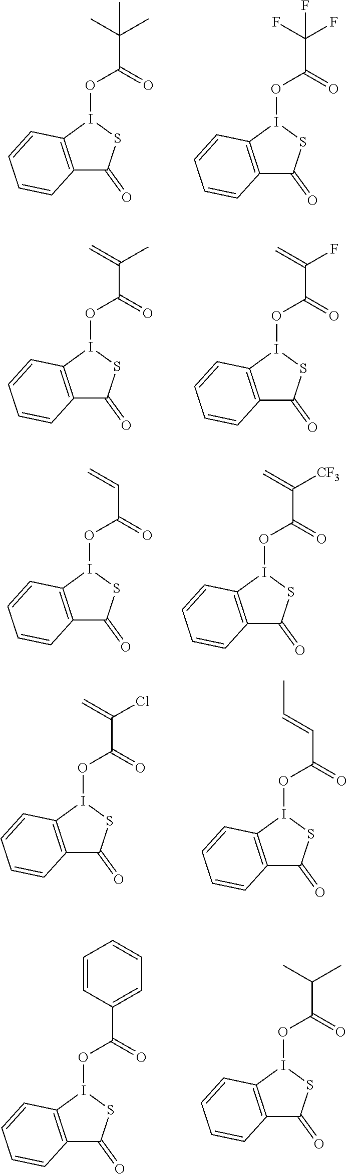

Examples of the hypervalent iodine compound having the formula (10) are shown

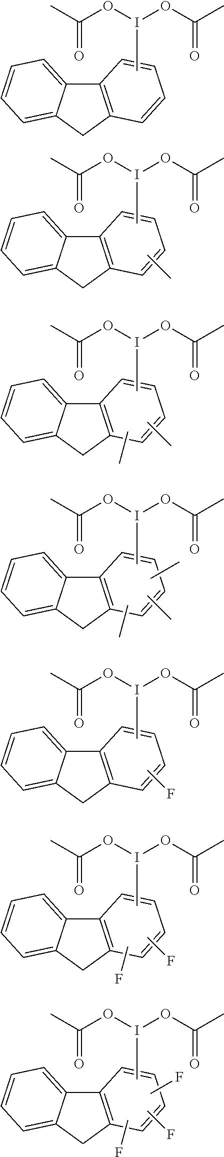

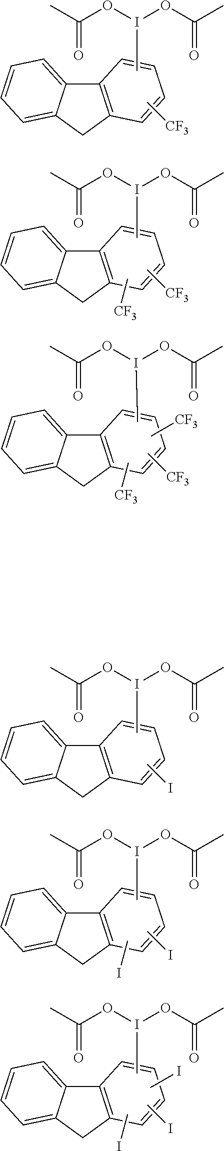

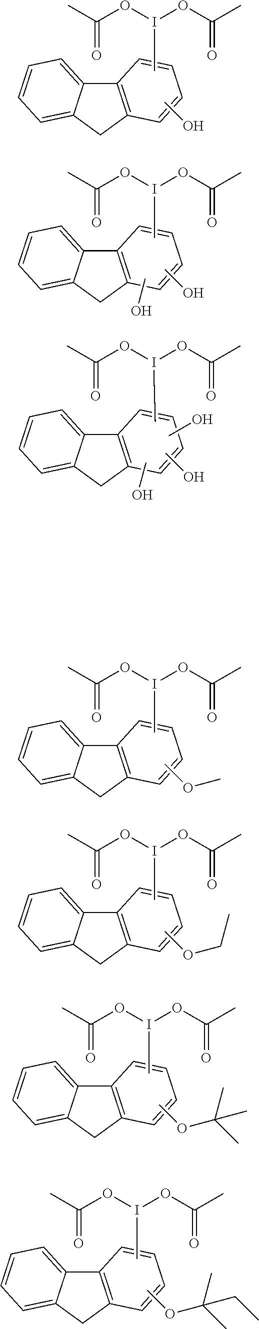

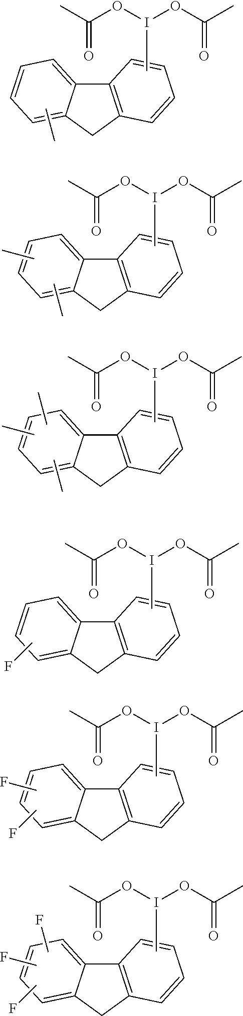

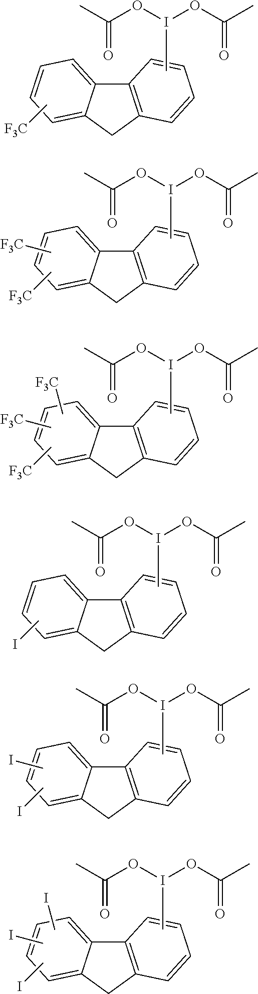

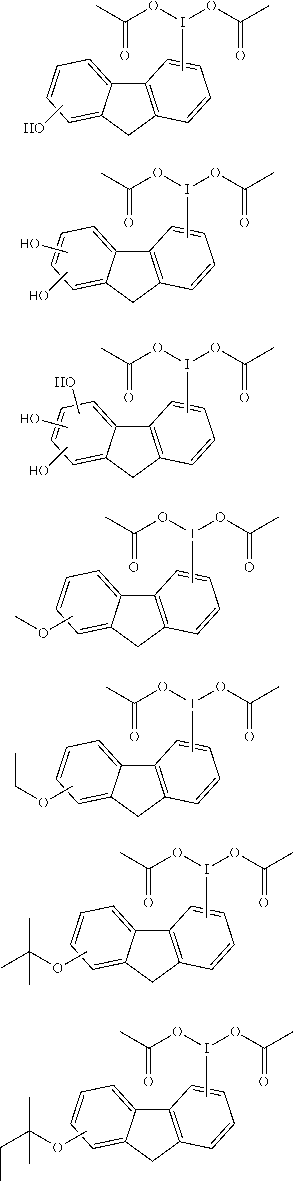

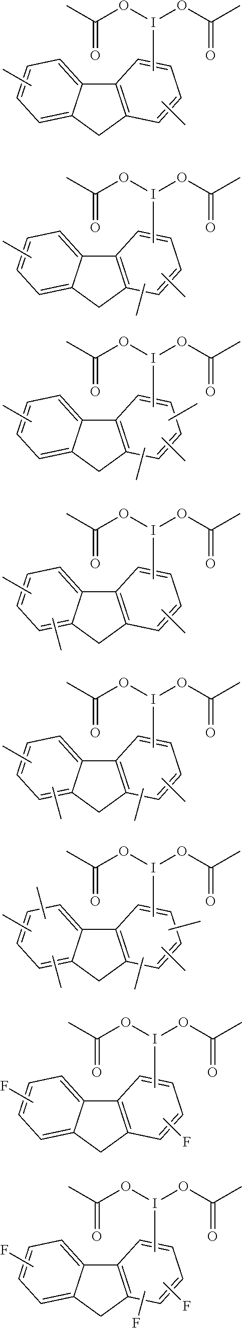

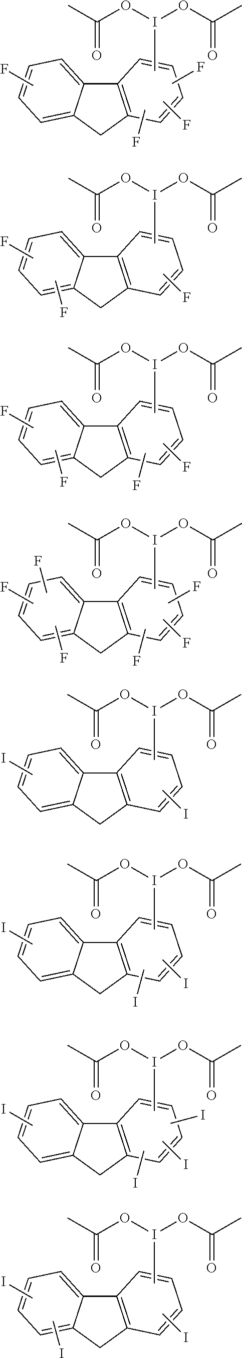

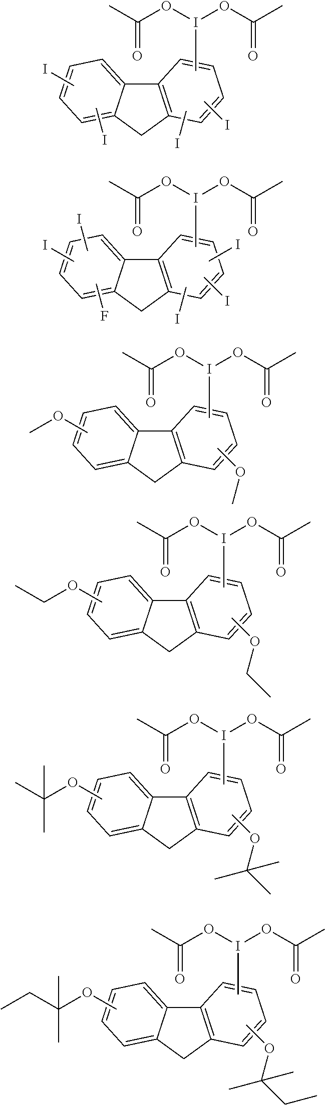

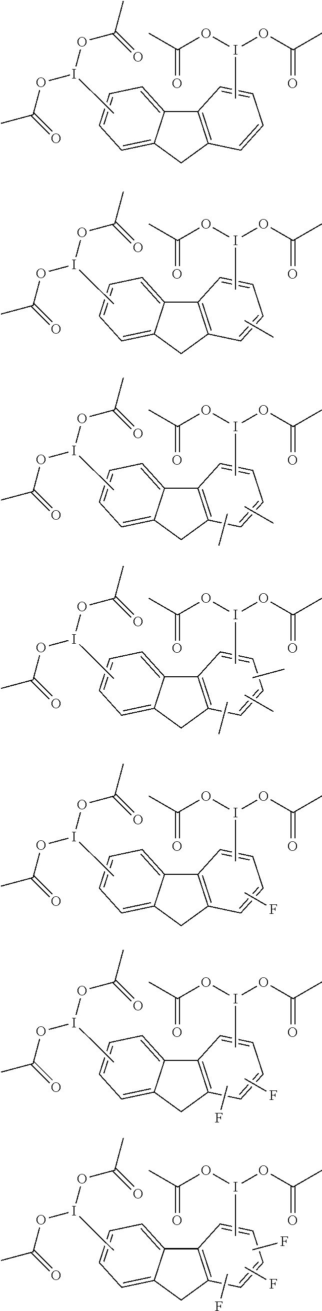

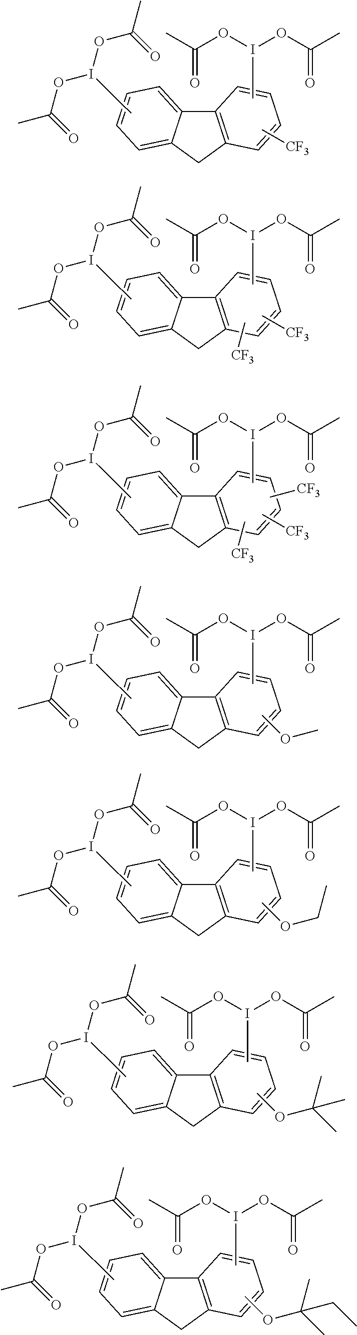

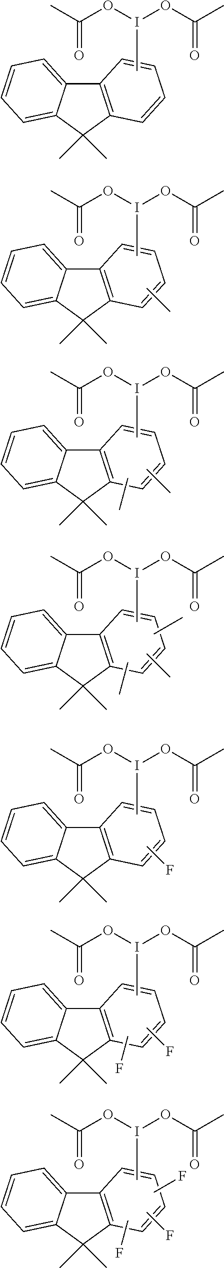

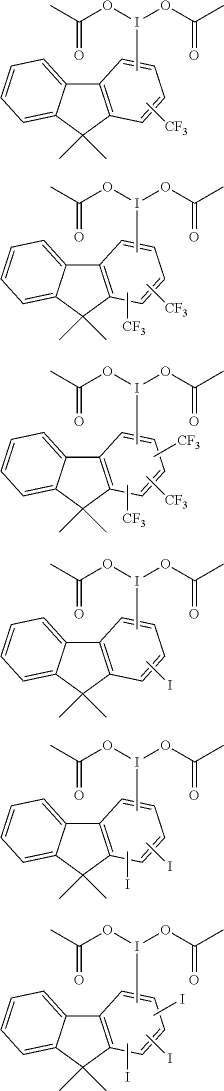

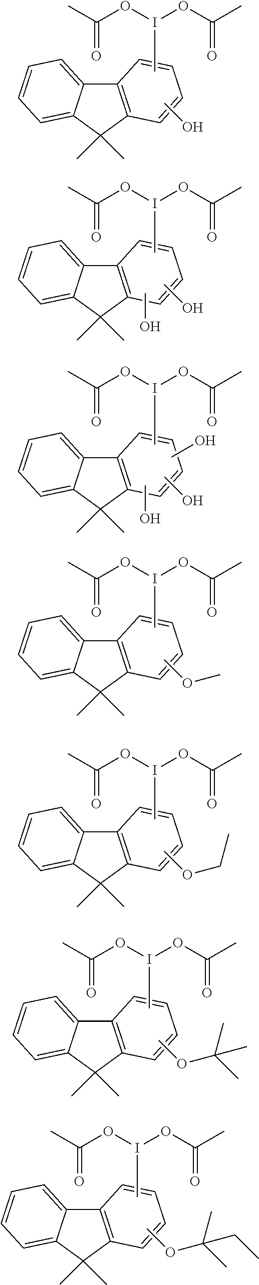

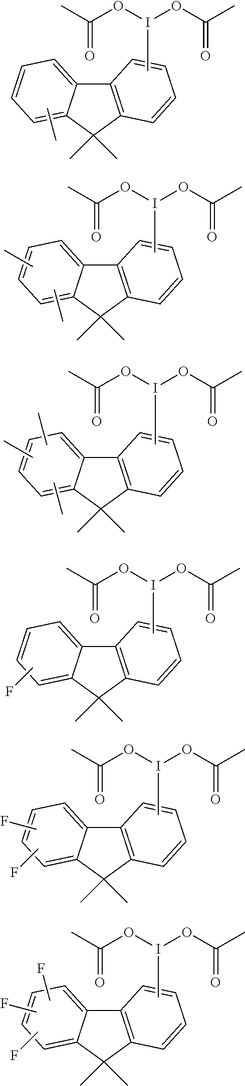

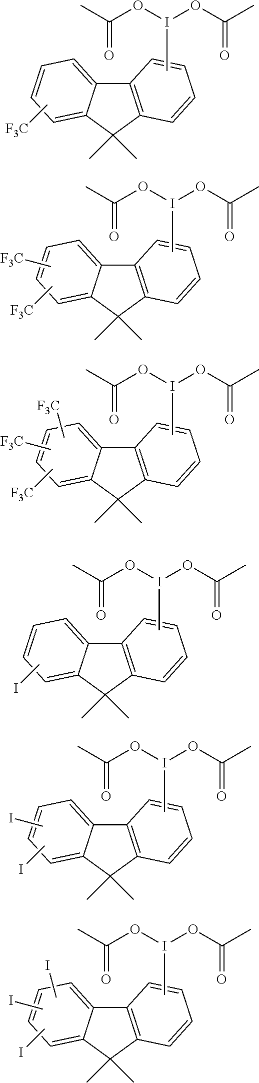

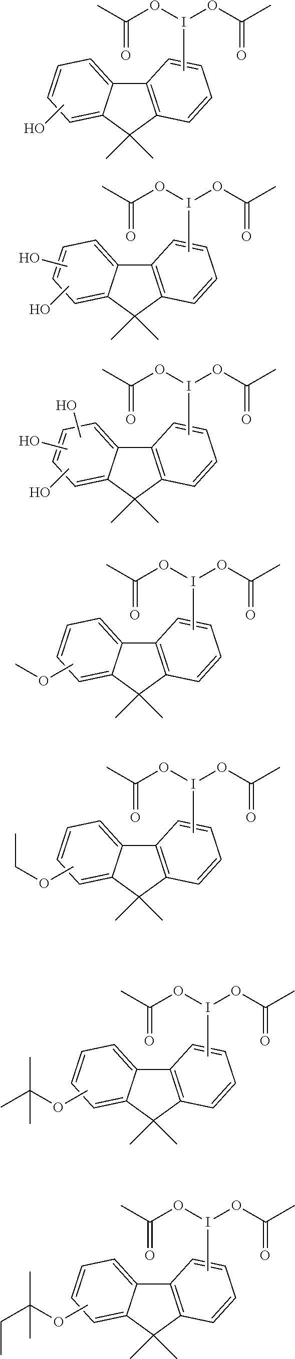

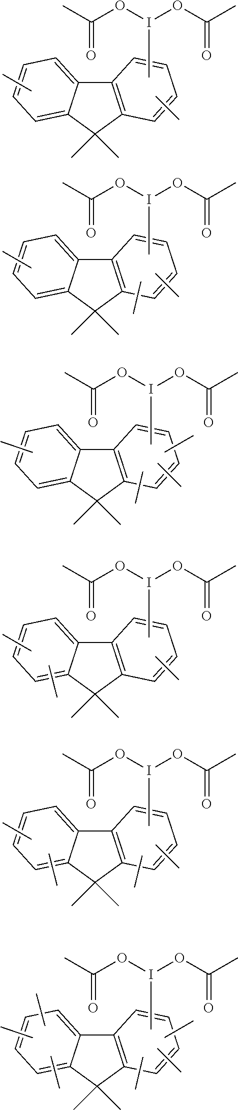

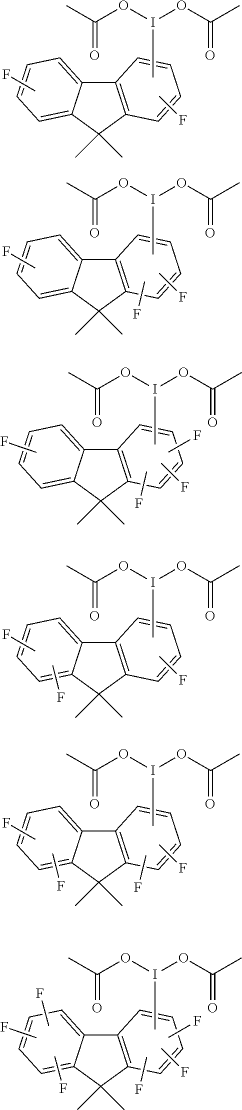

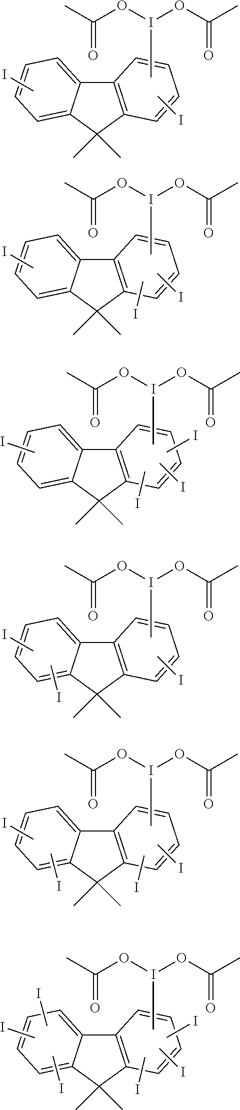

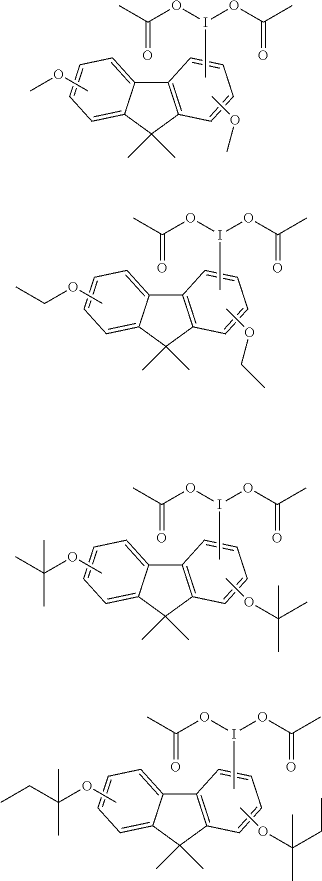

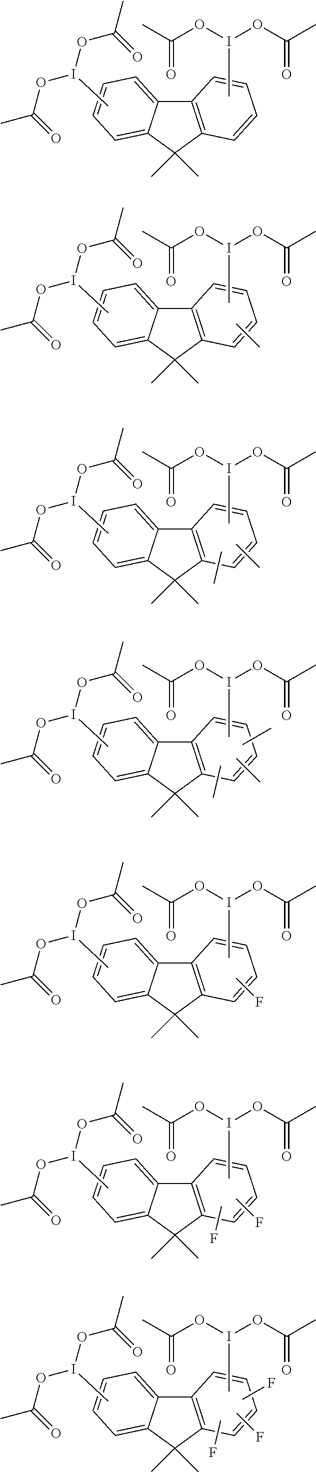

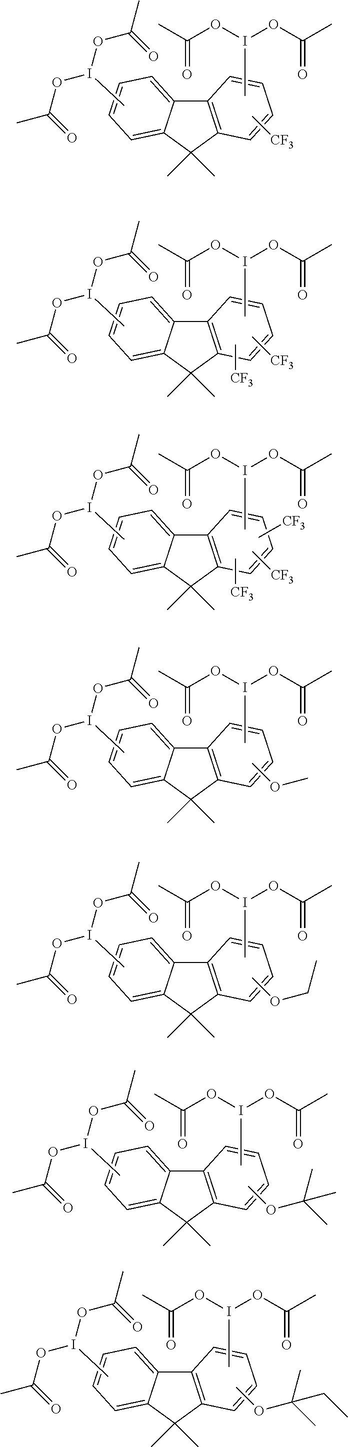

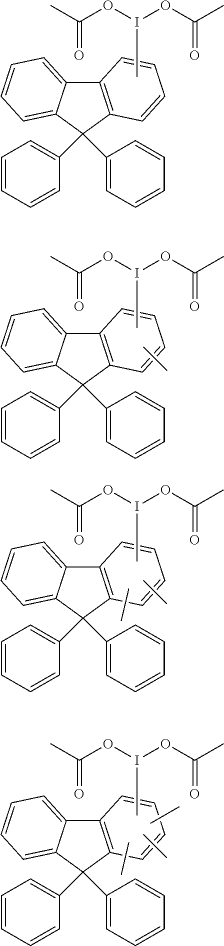

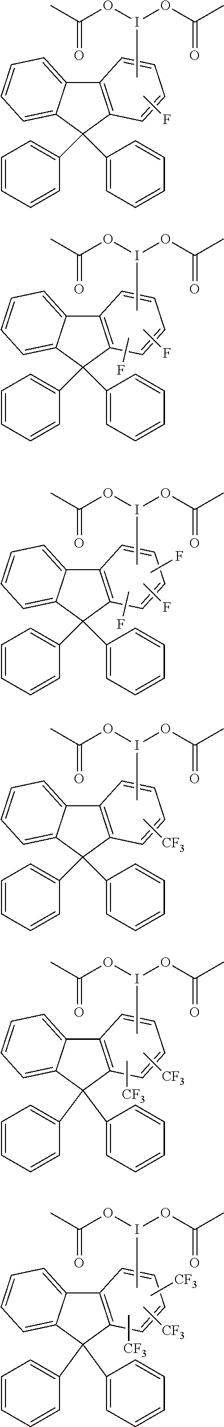

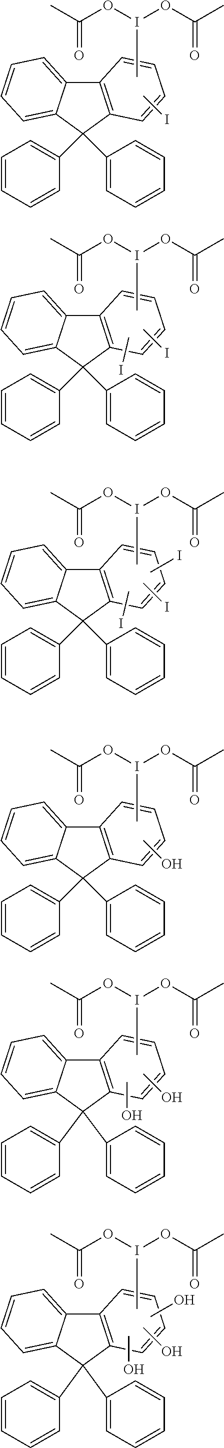

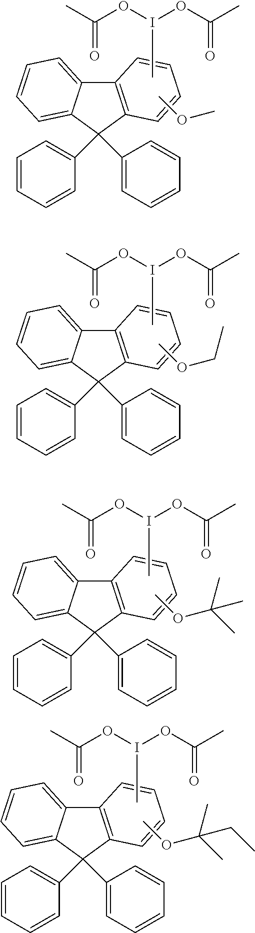

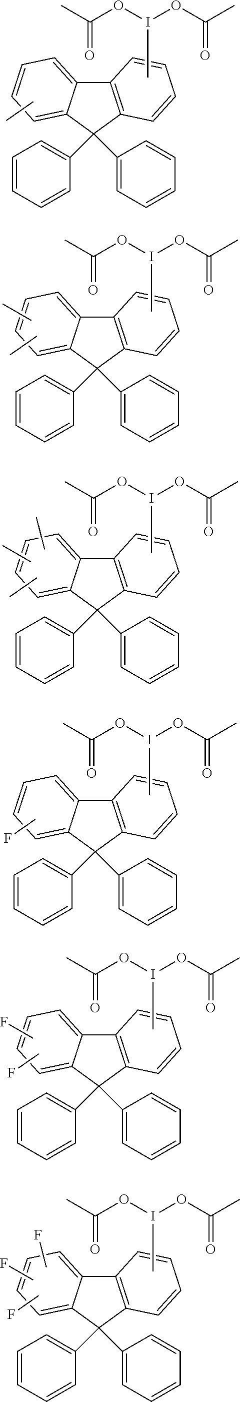

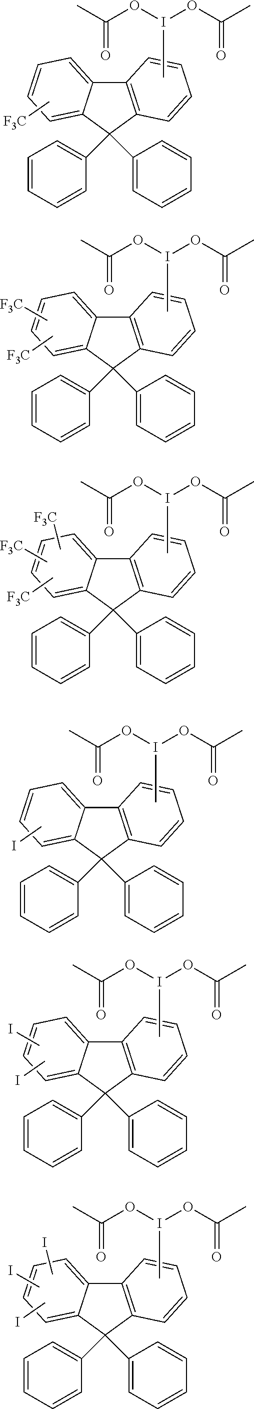

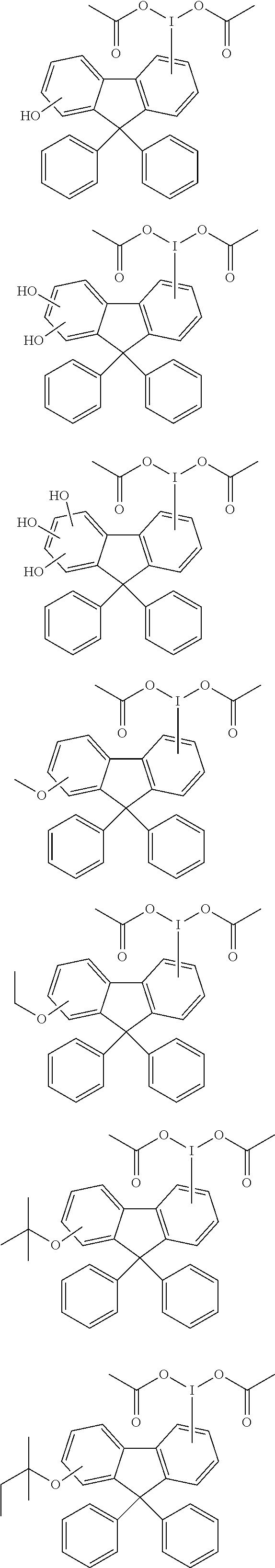

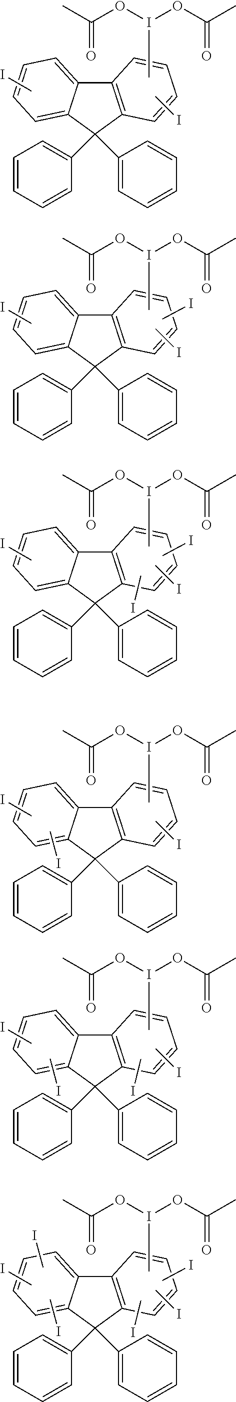

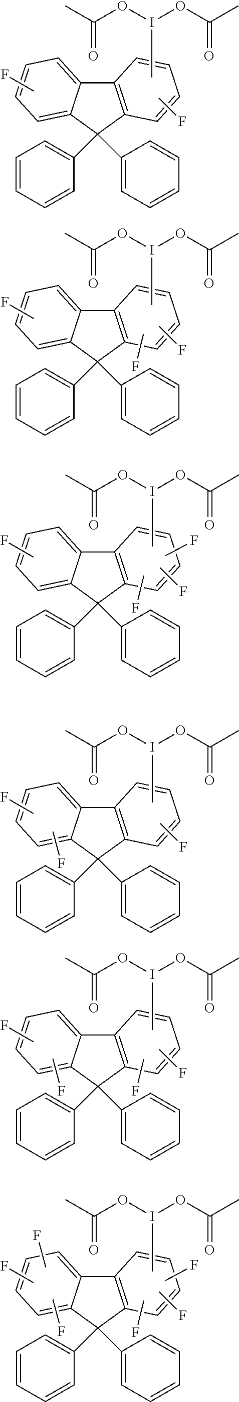

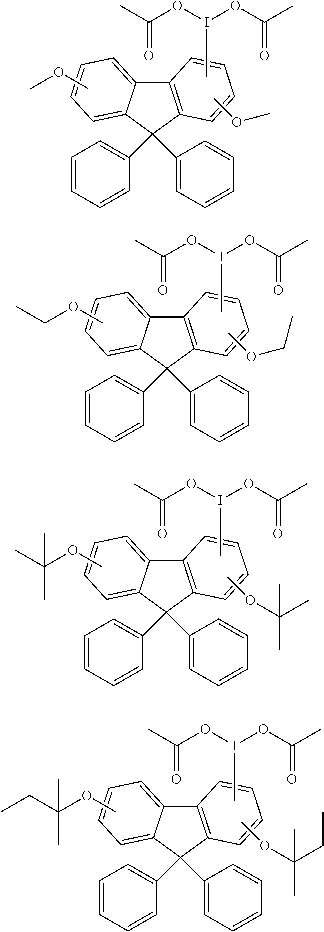

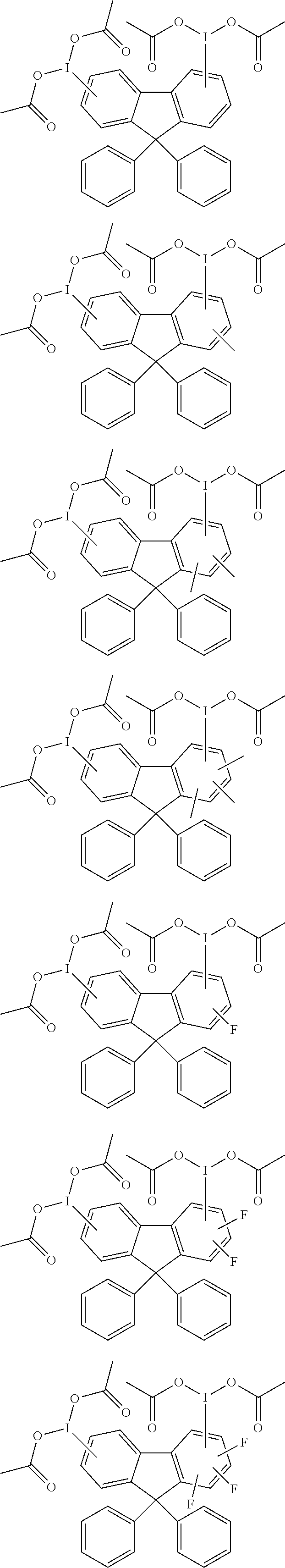

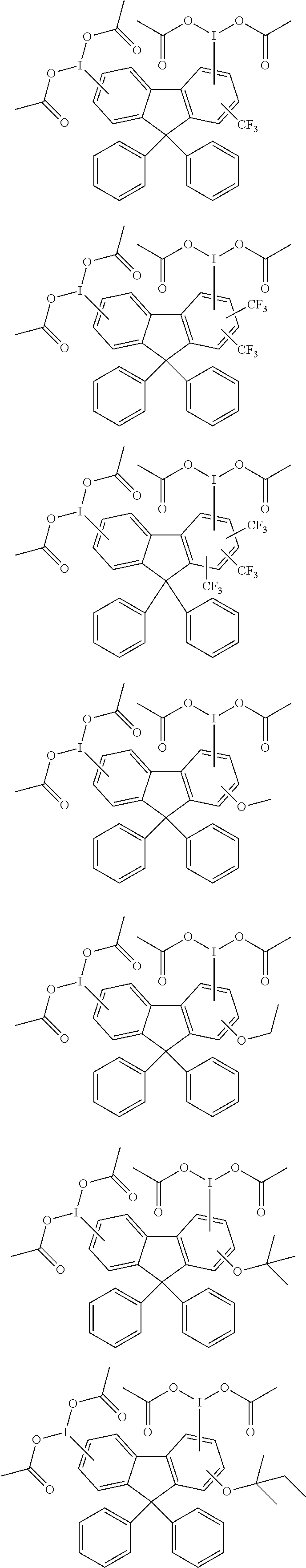

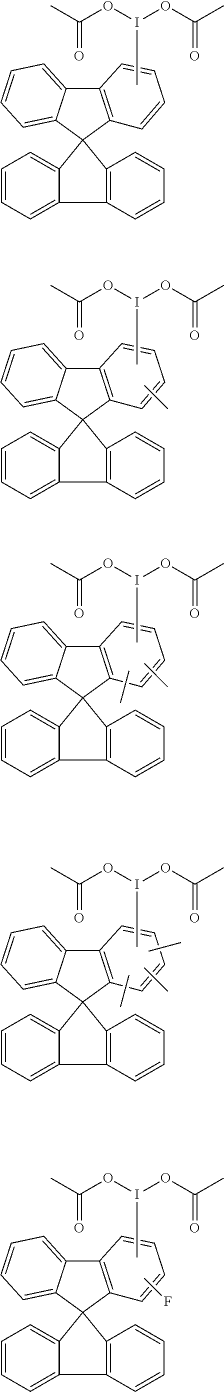

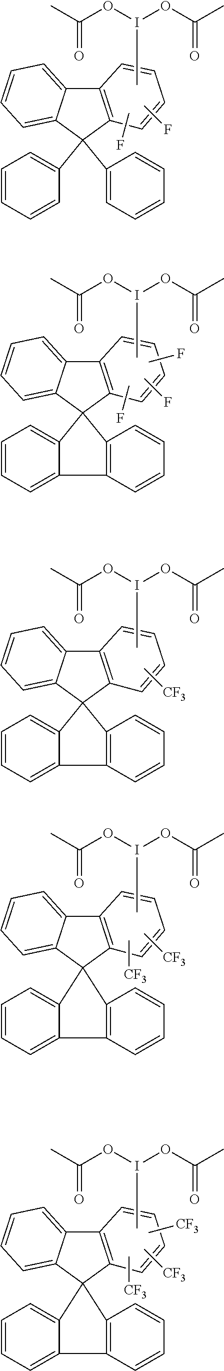

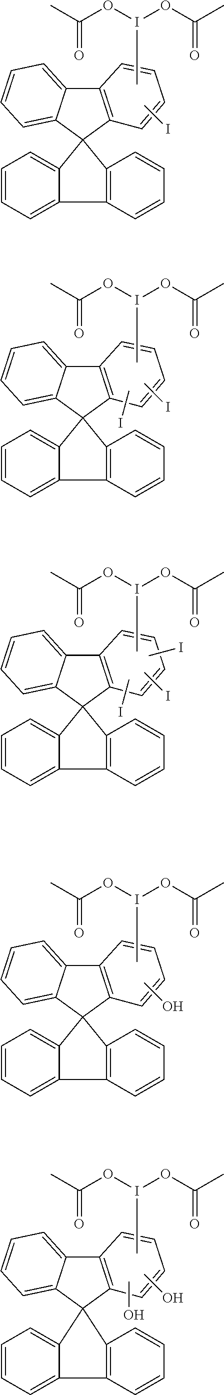

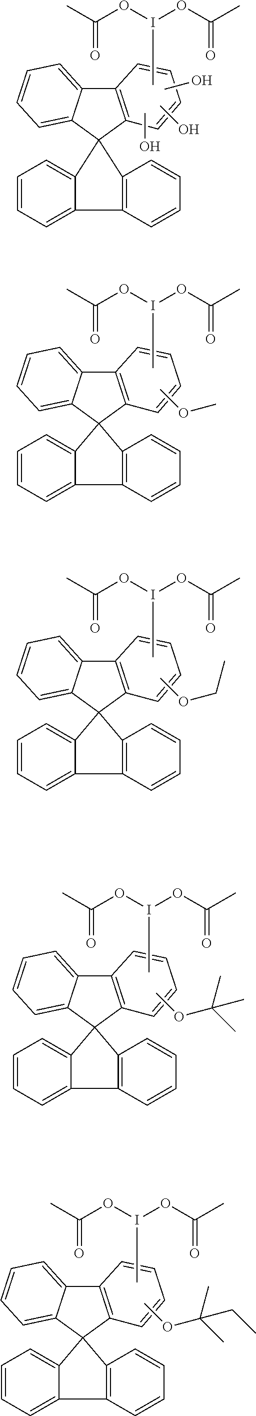

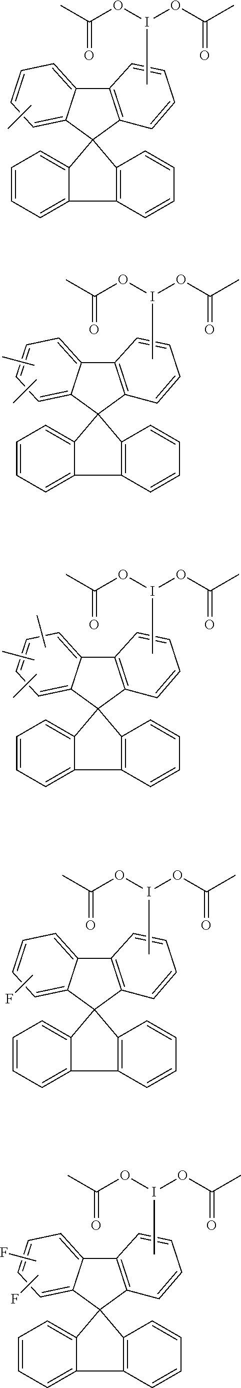

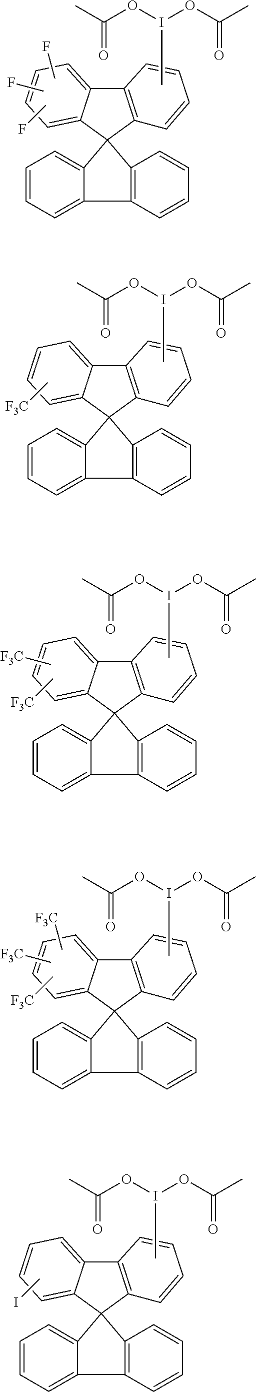

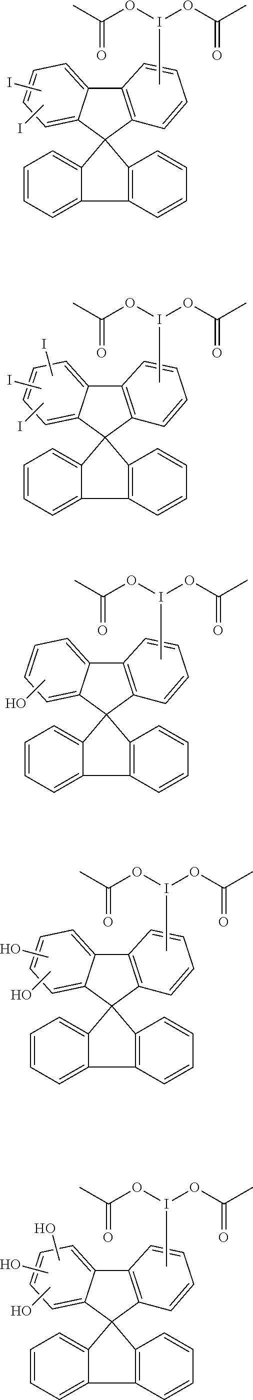

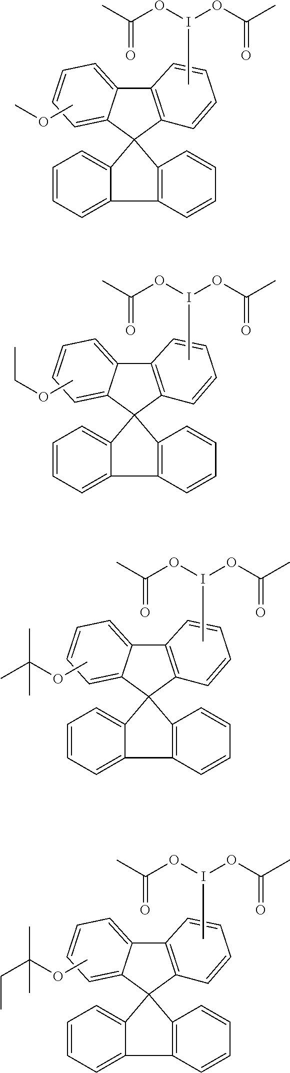

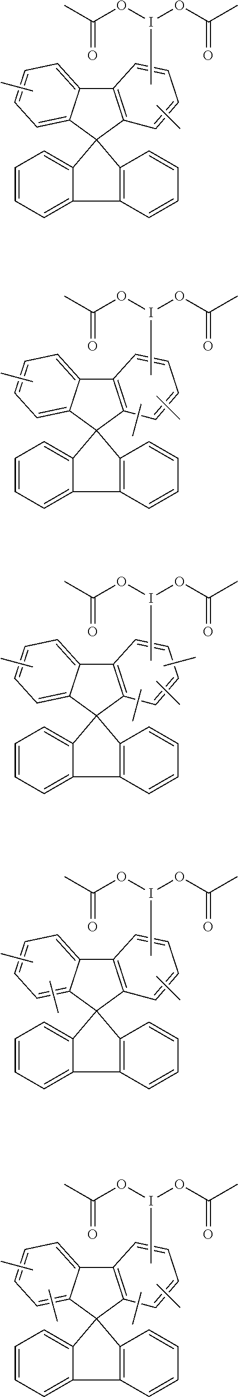

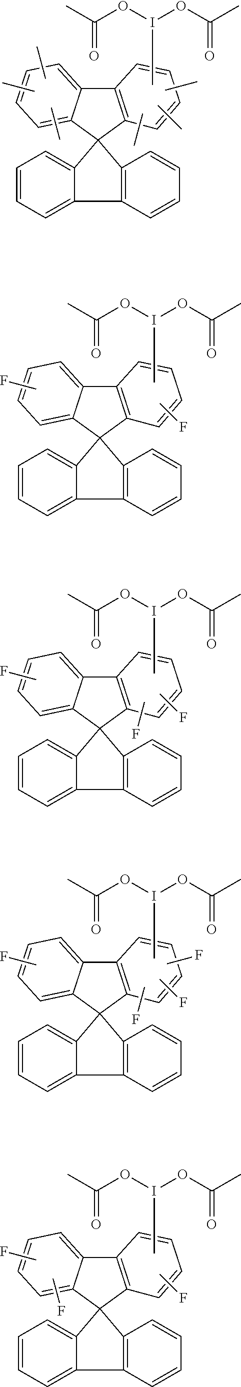

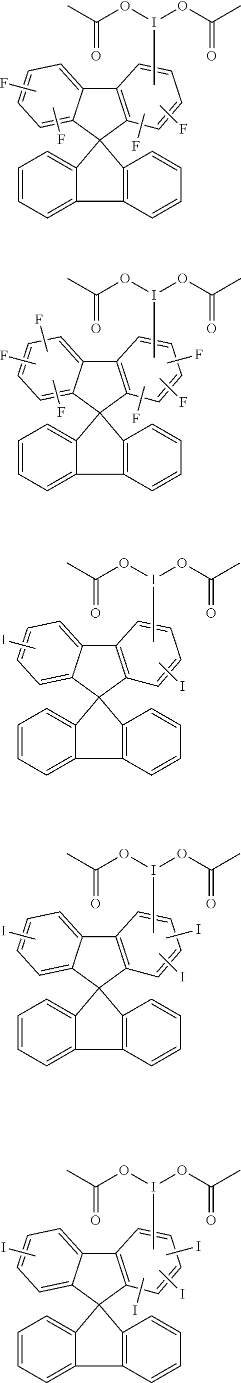

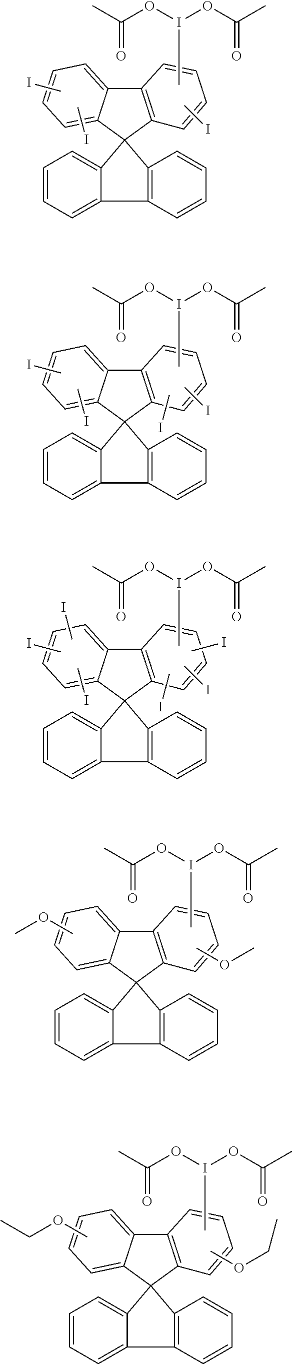

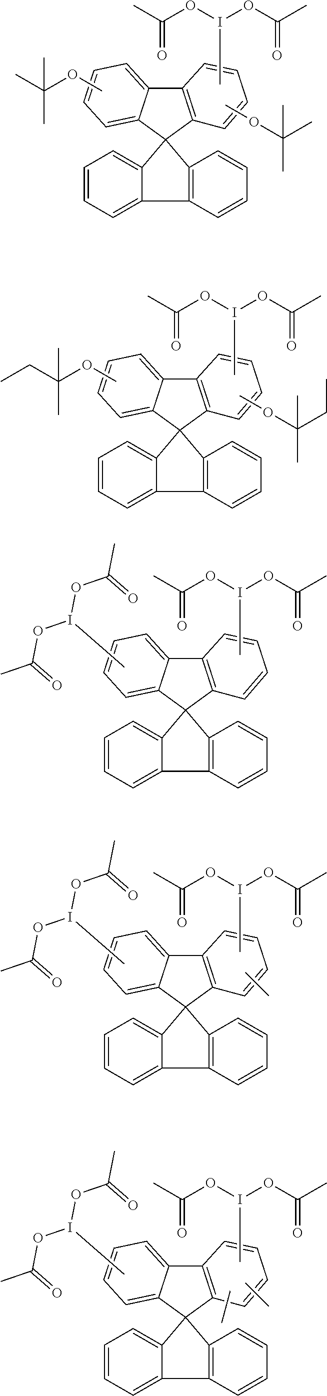

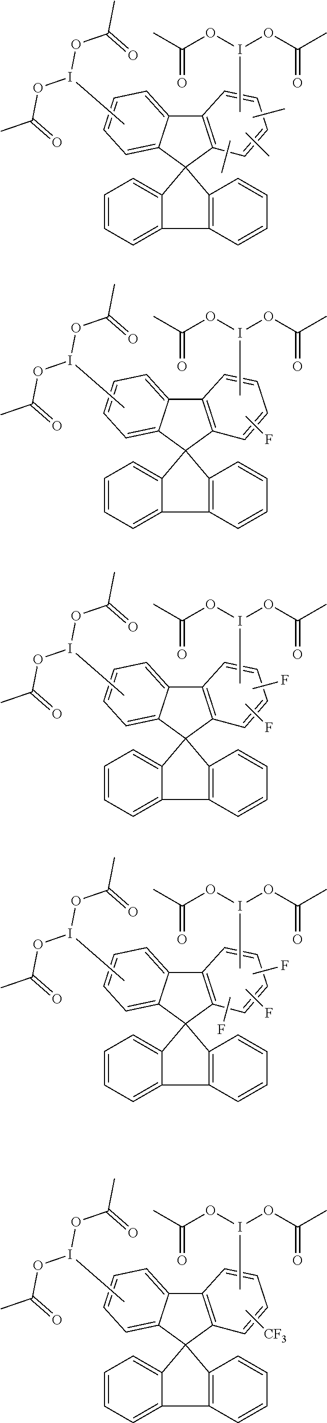

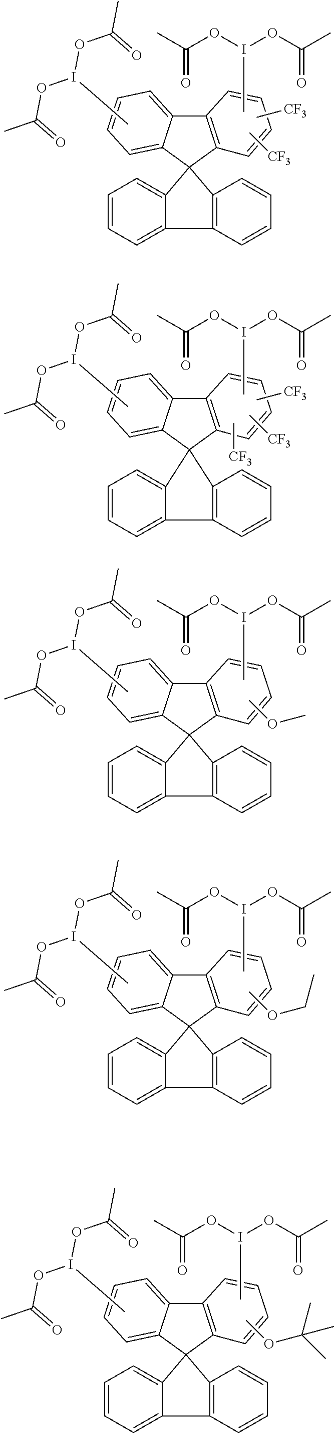

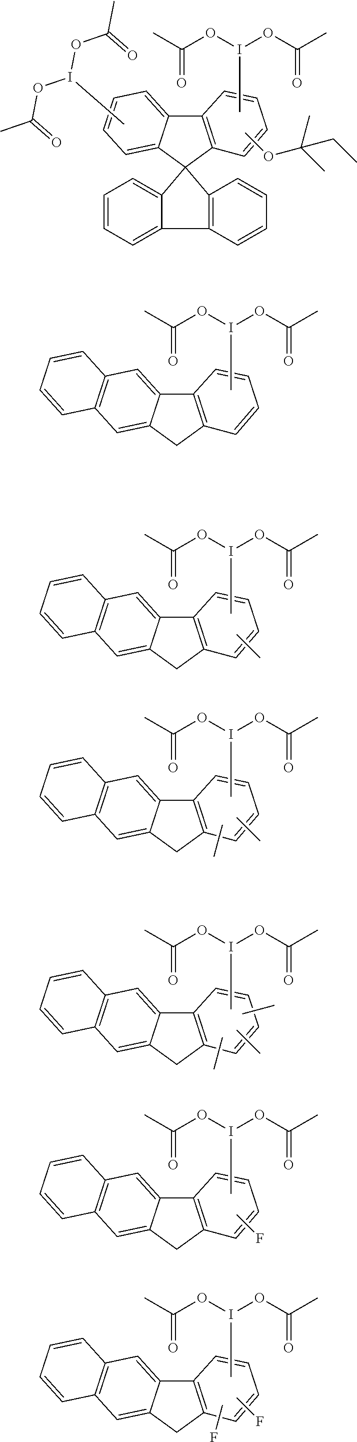

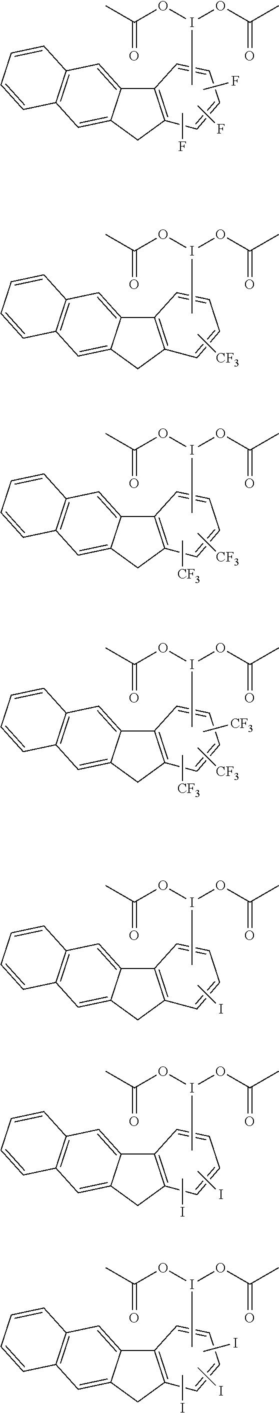

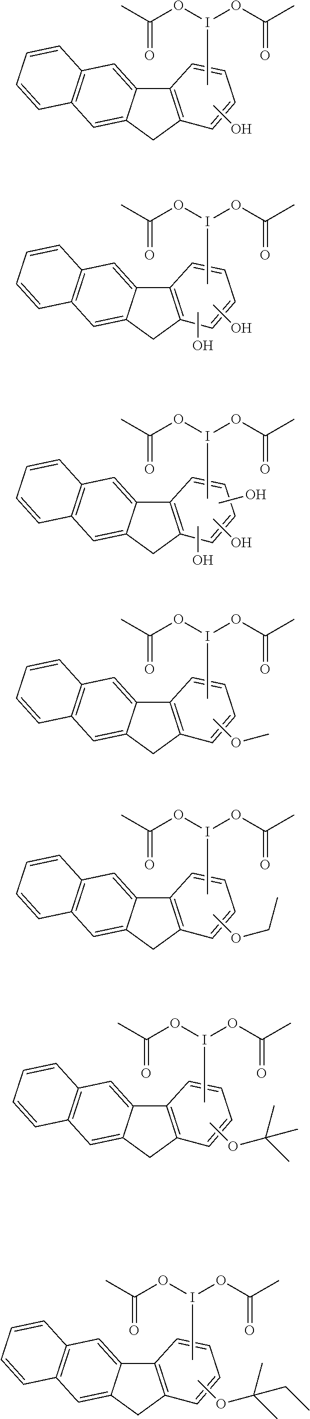

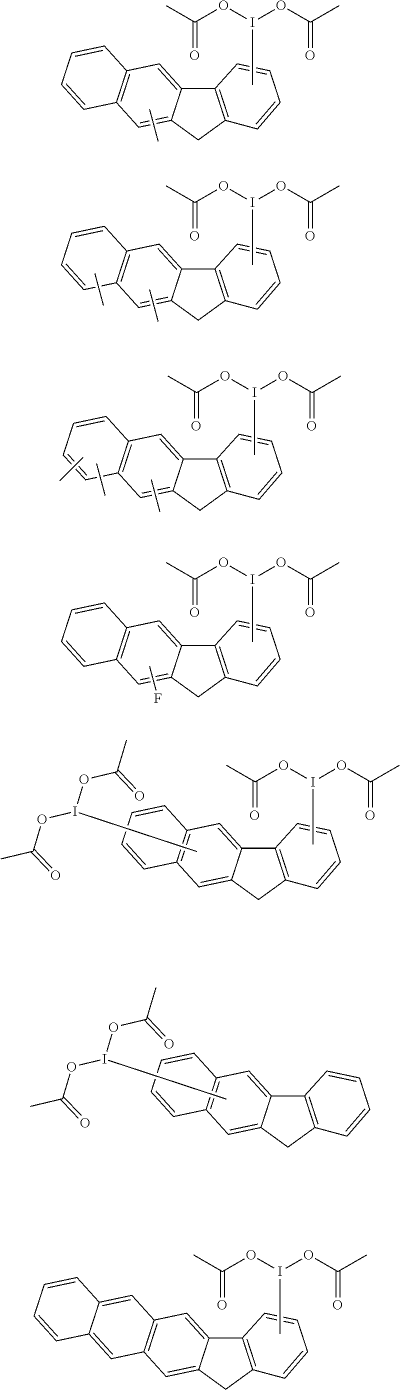

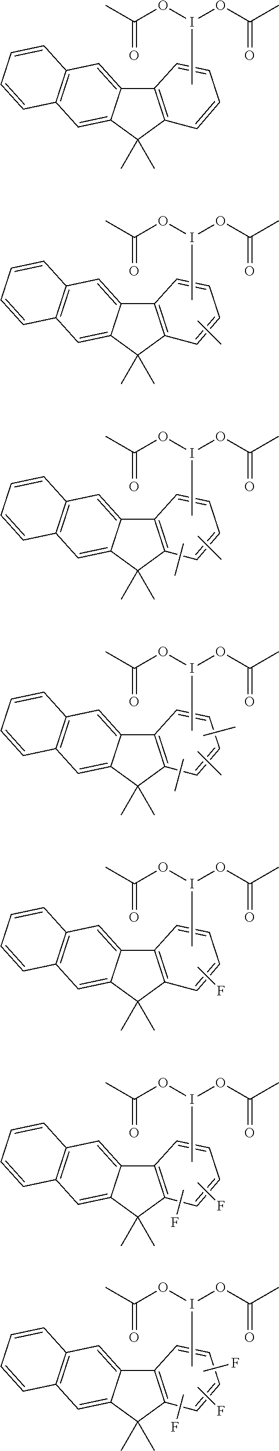

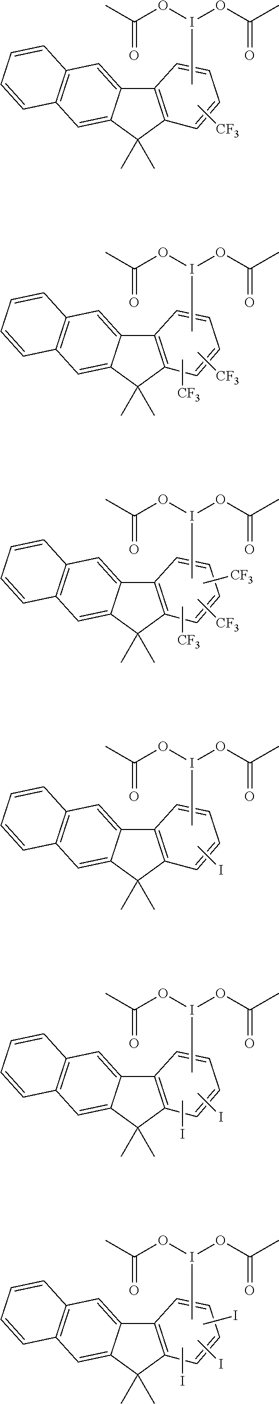

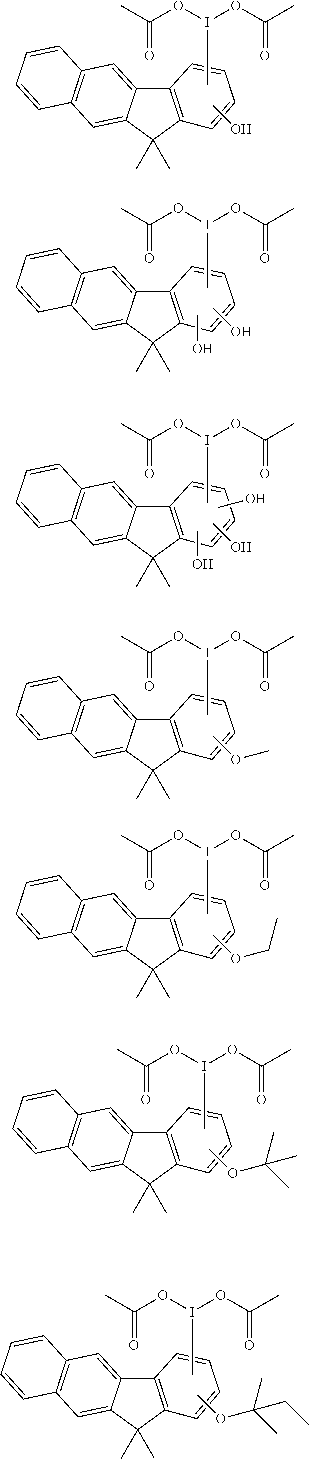

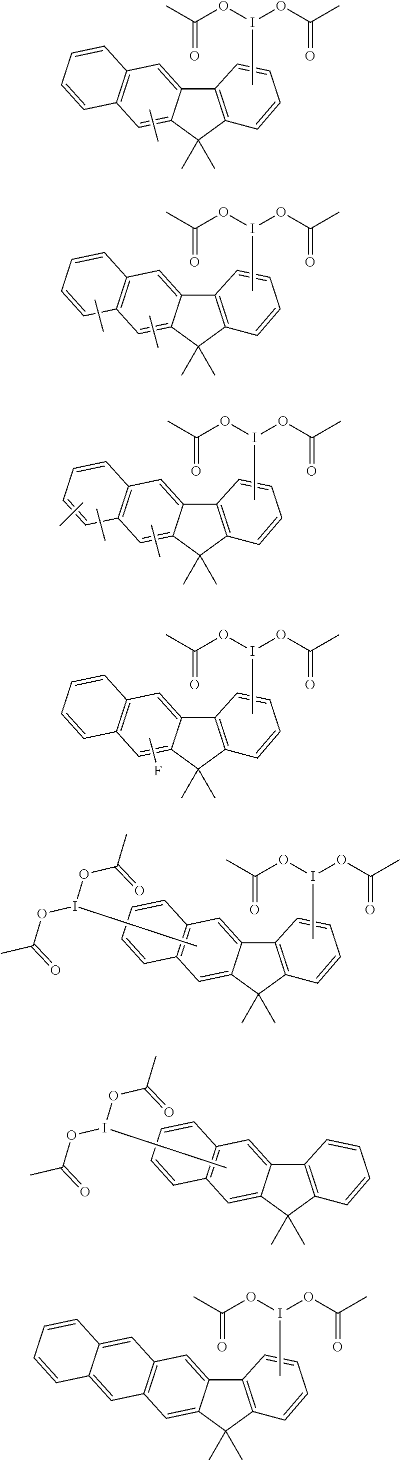

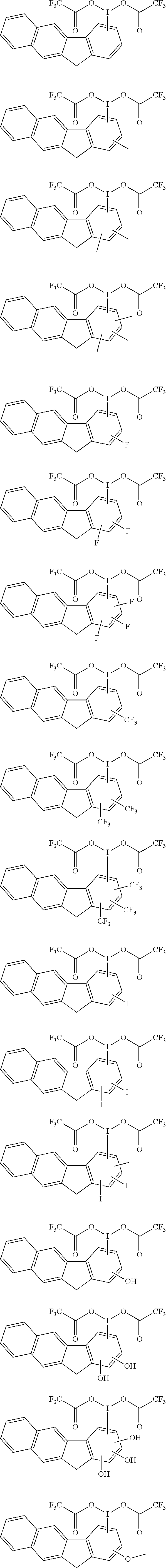

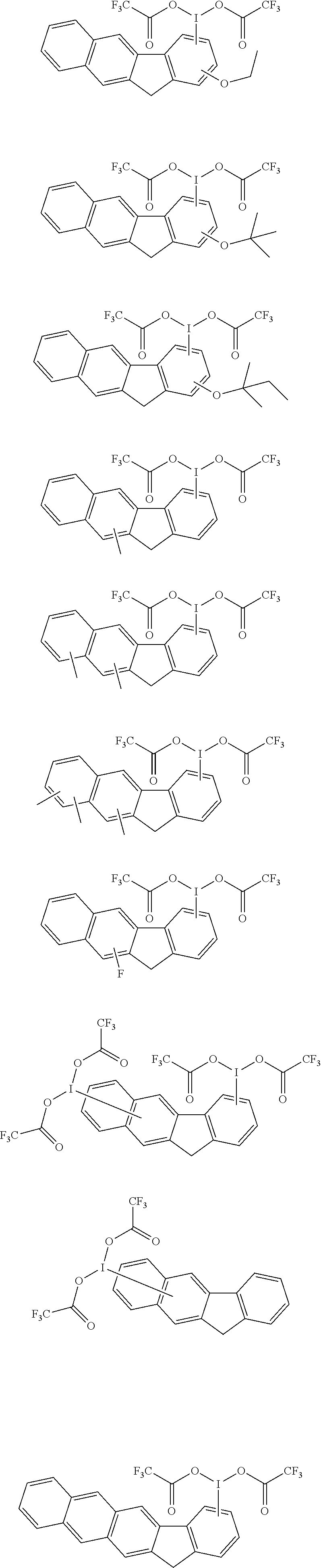

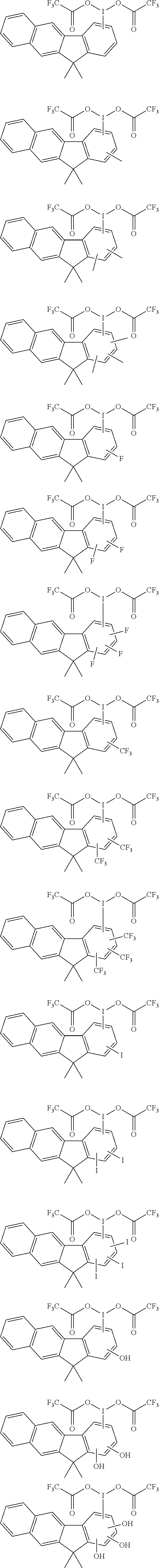

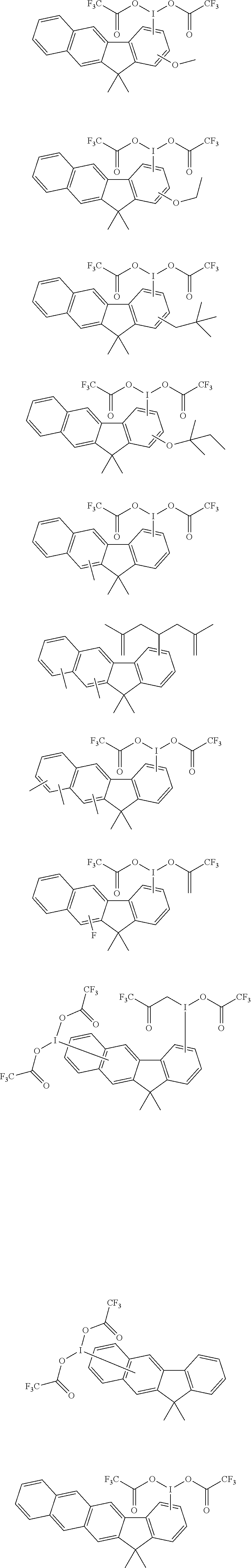

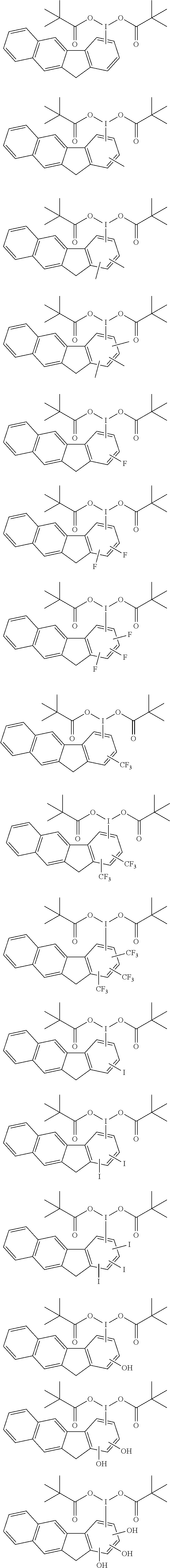

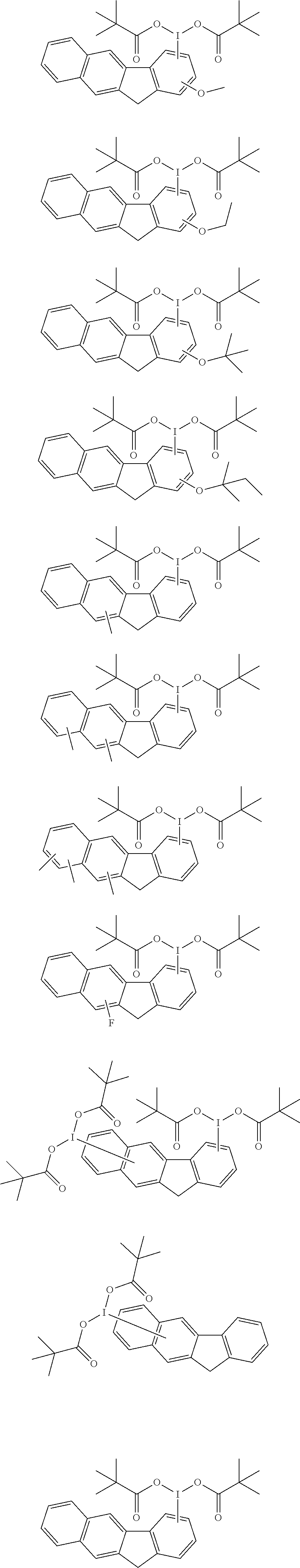

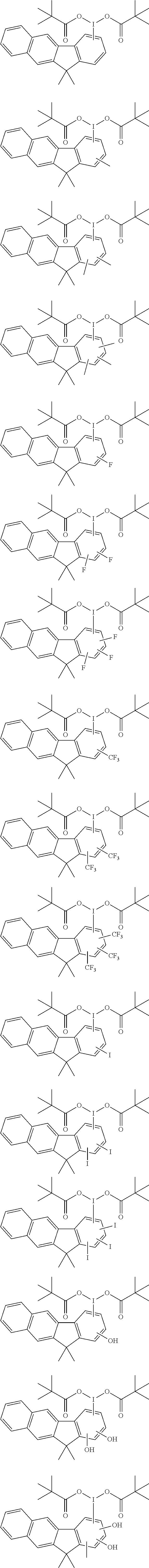

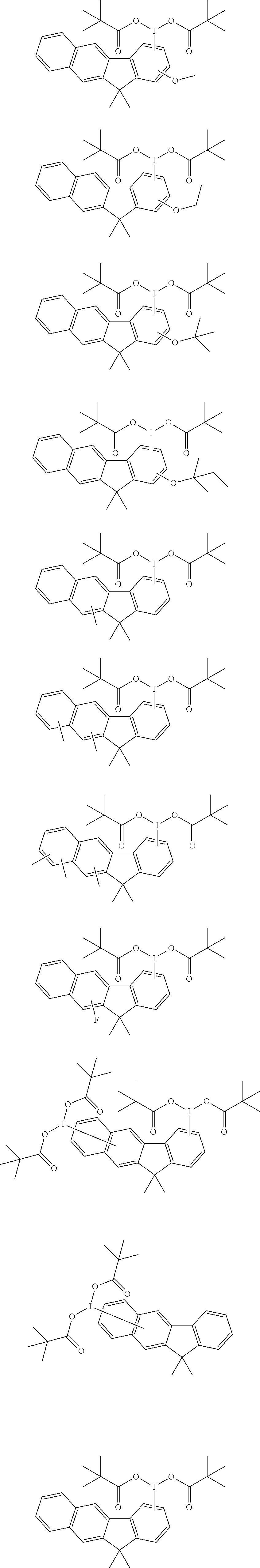

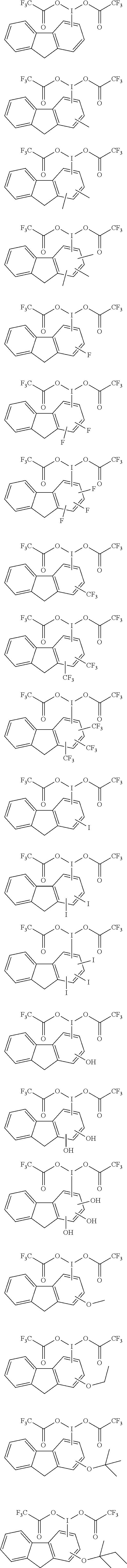

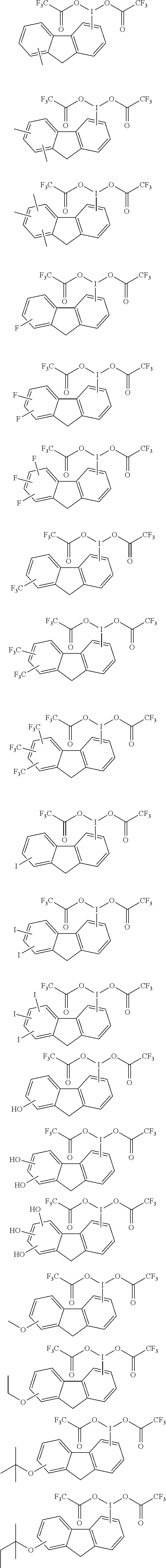

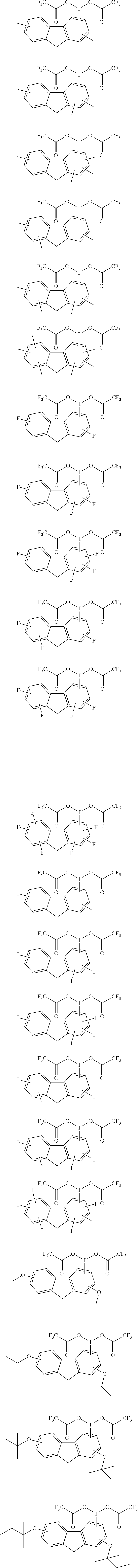

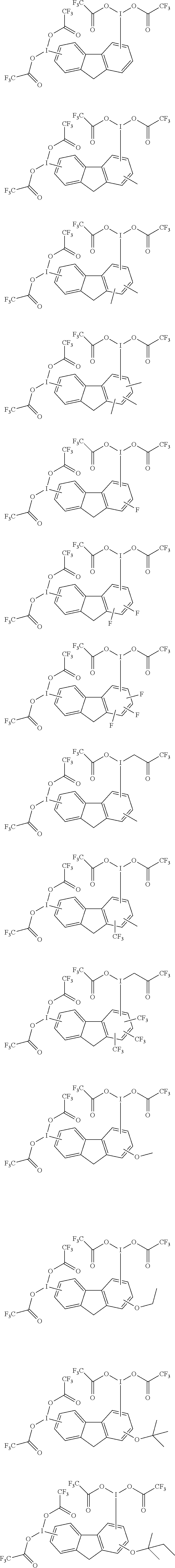

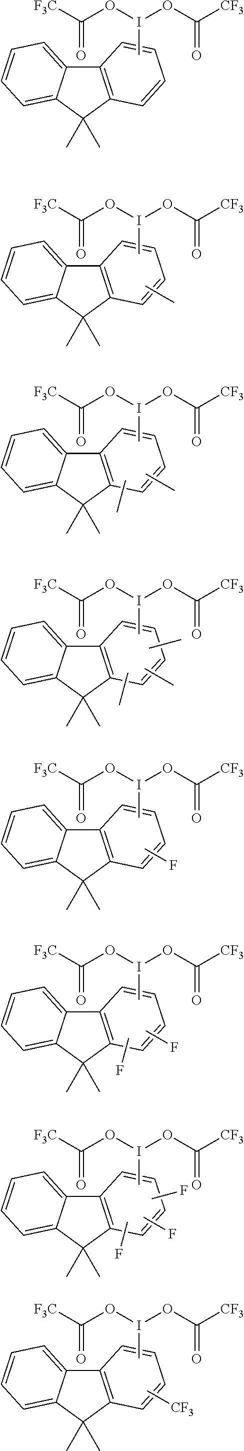

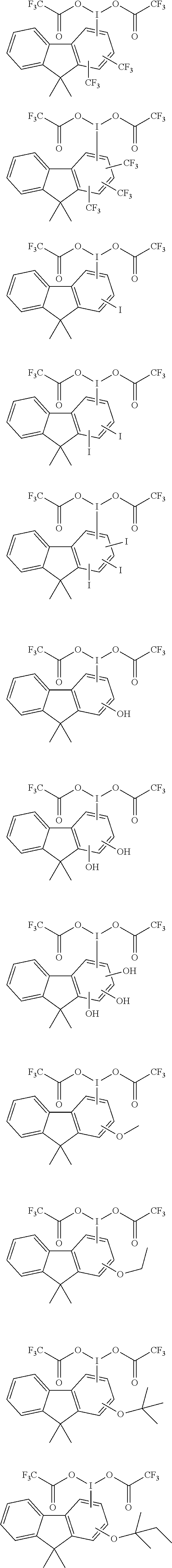

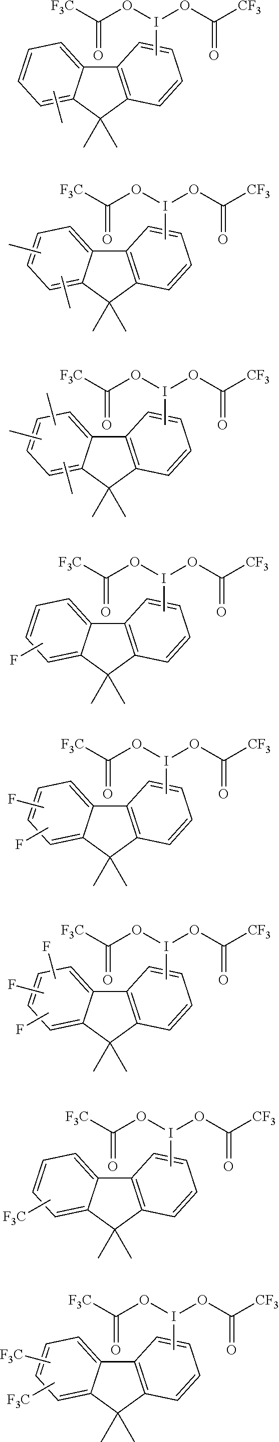

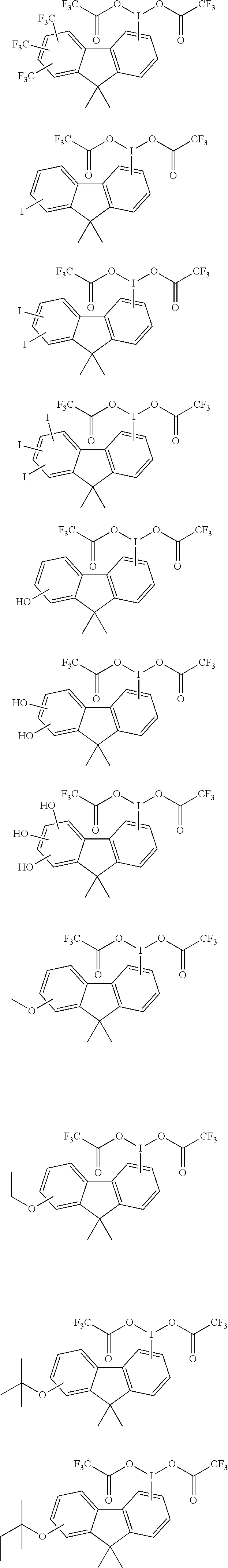

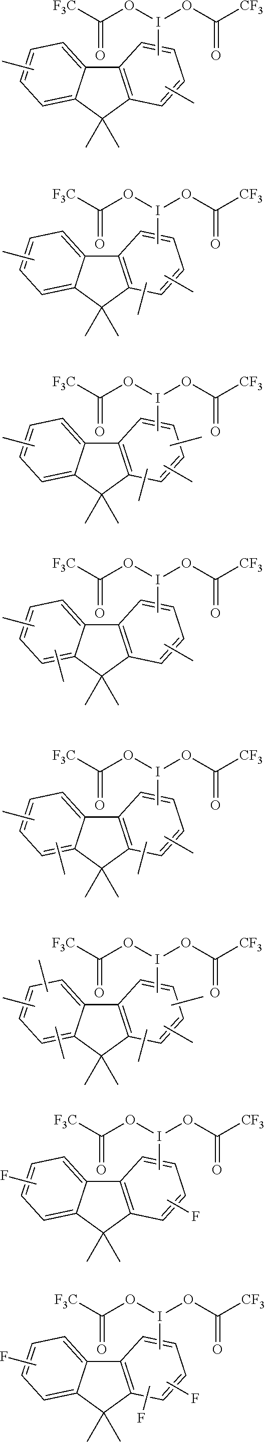

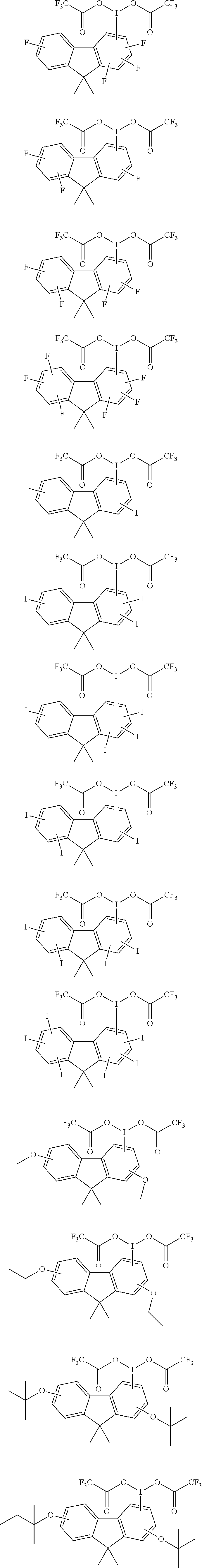

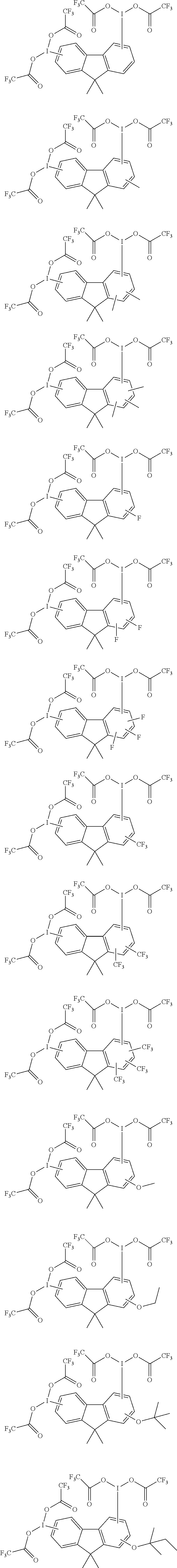

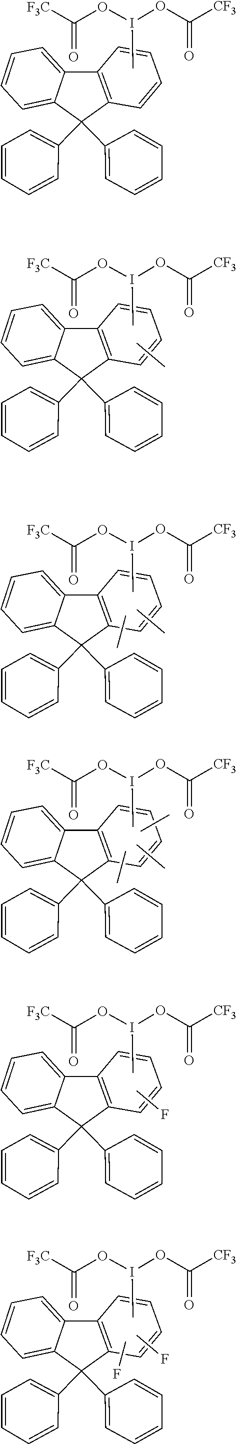

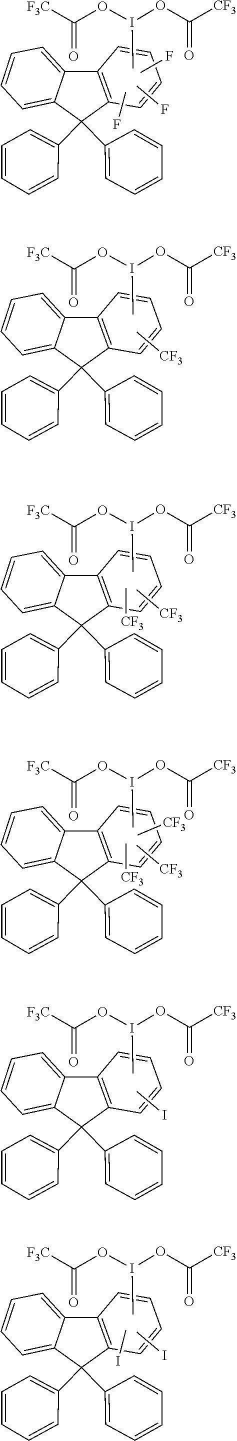

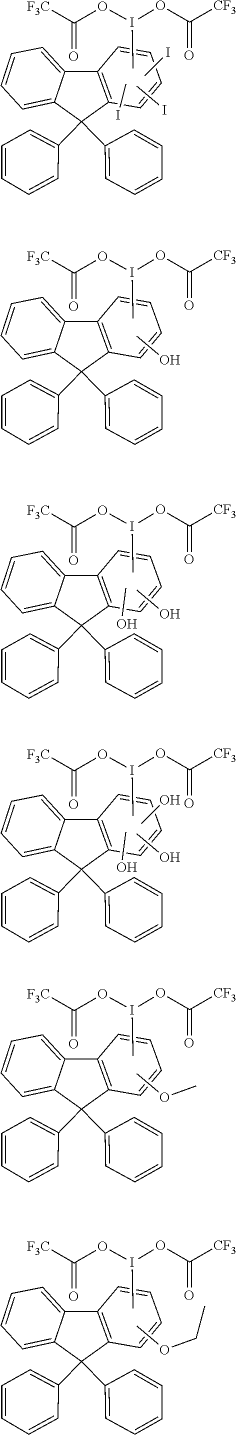

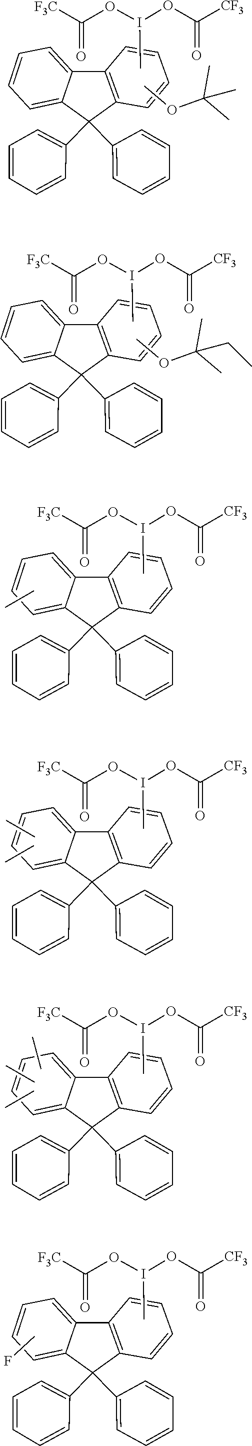

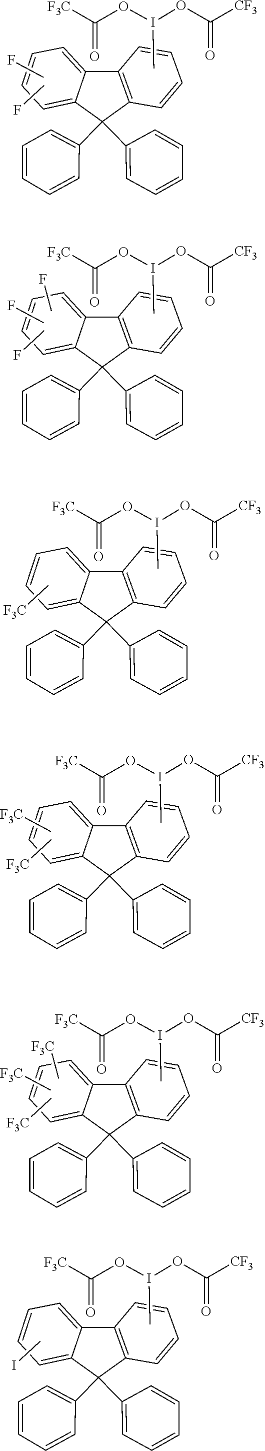

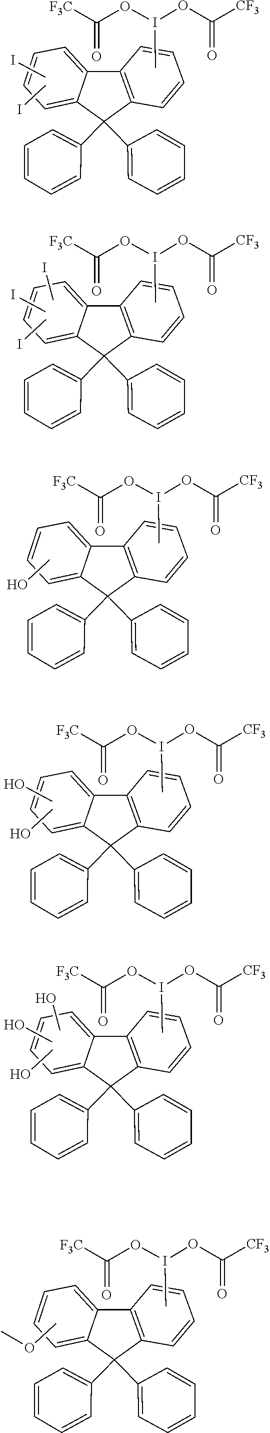

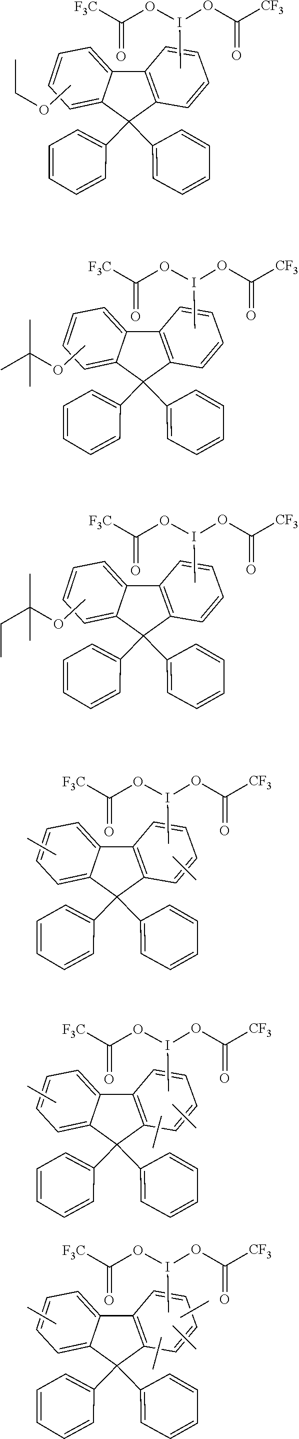

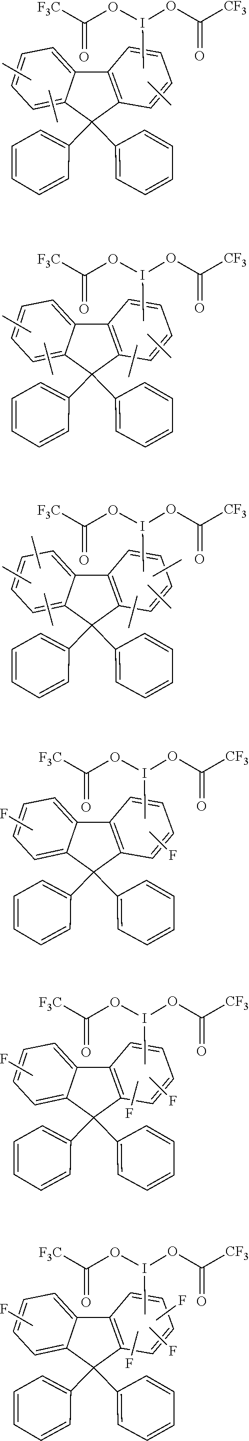

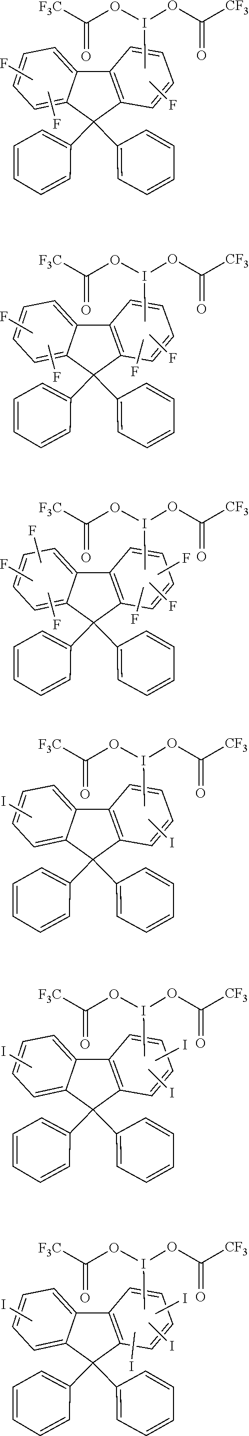

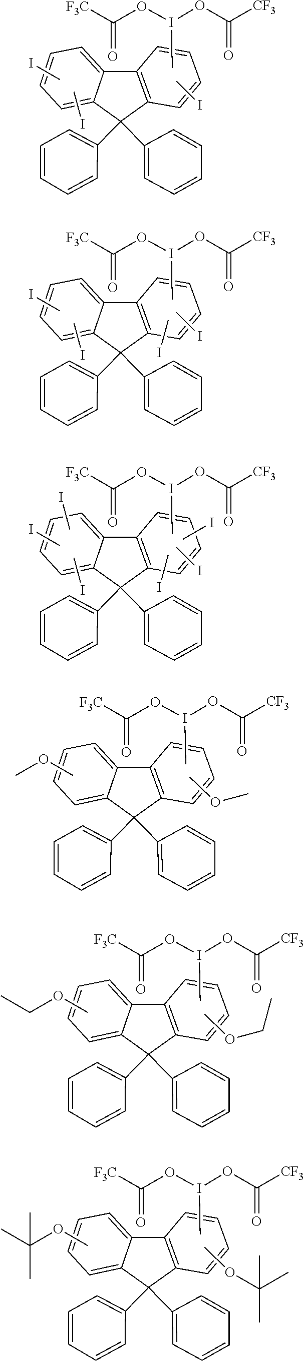

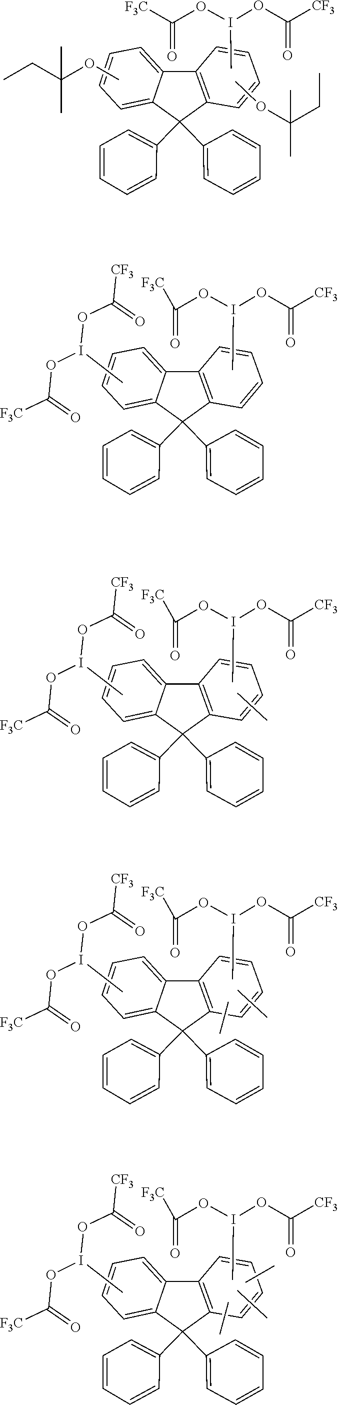

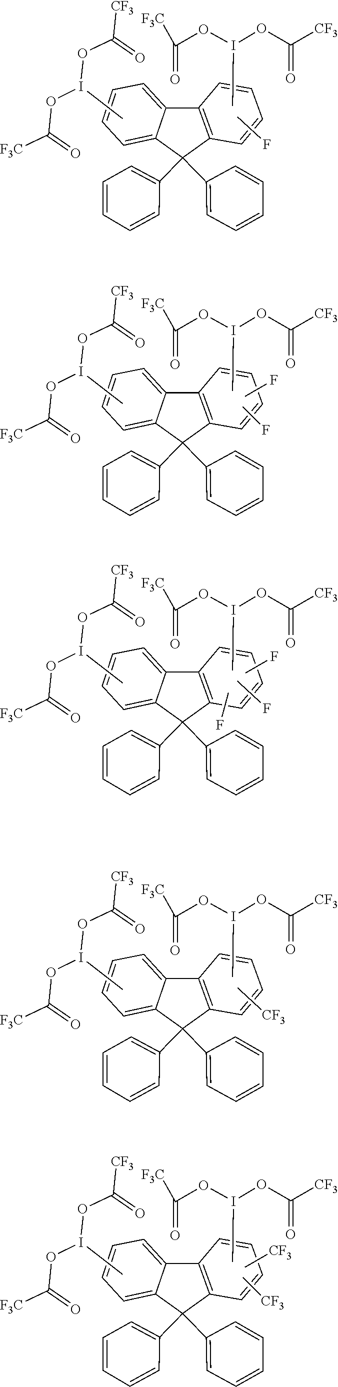

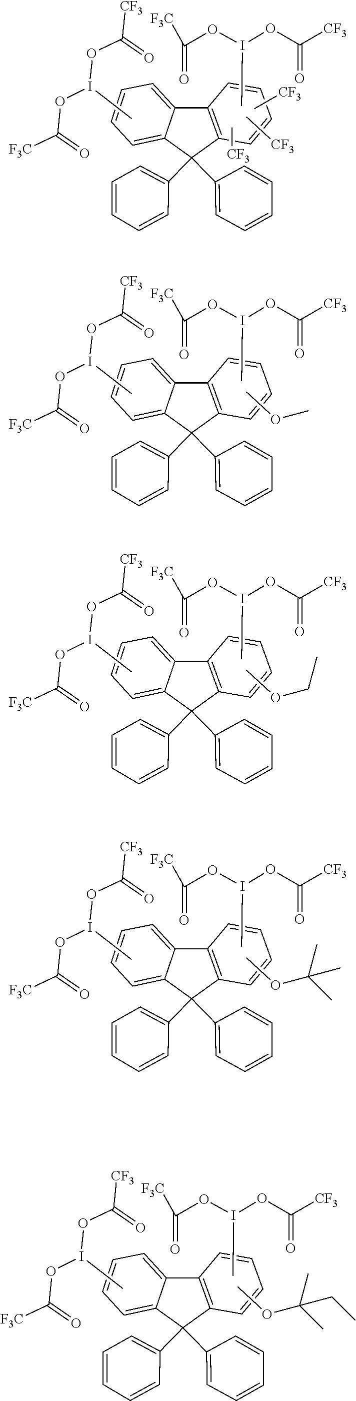

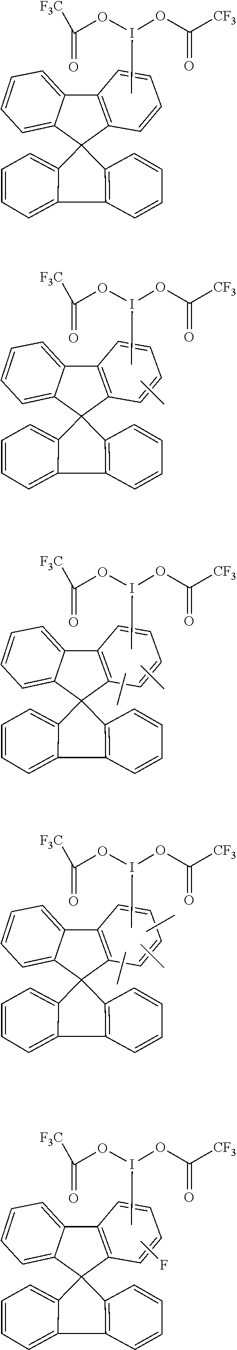

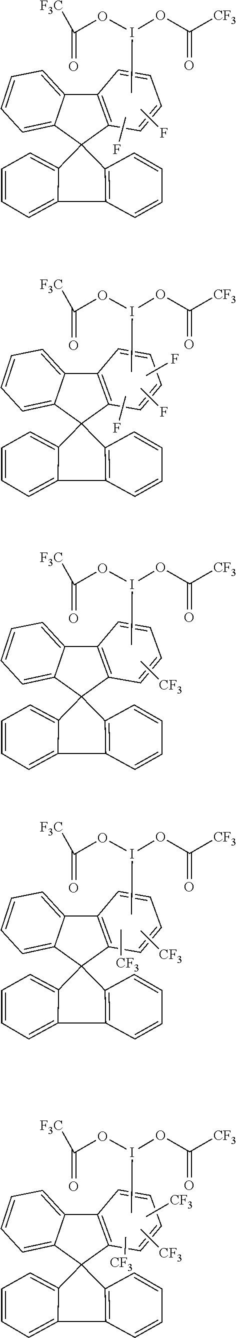

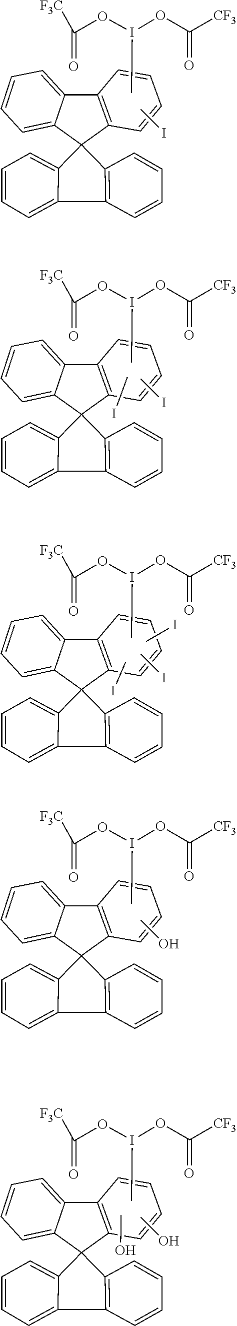

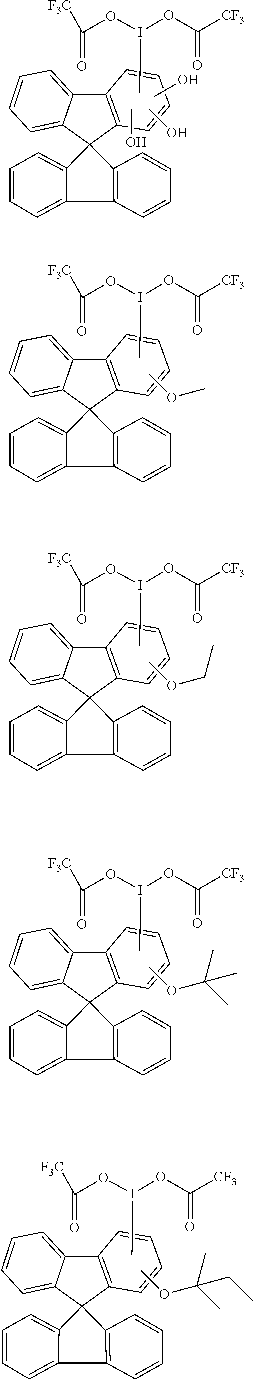

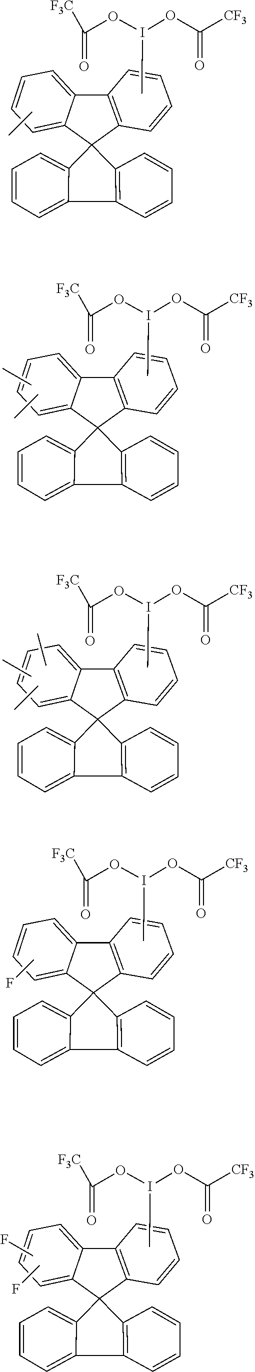

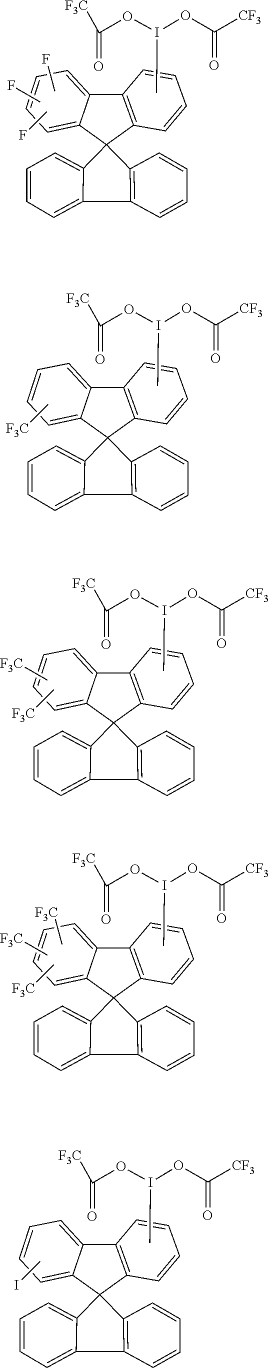

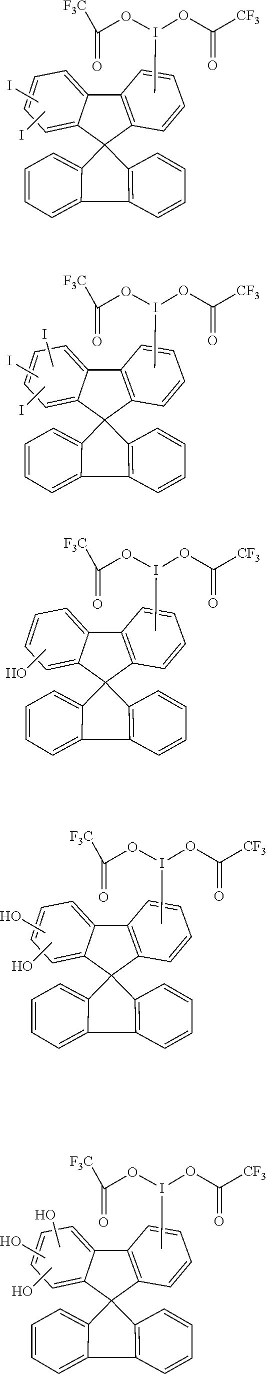

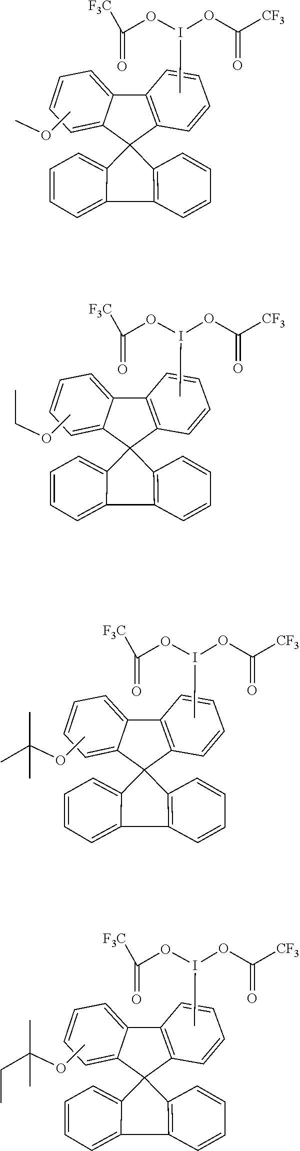

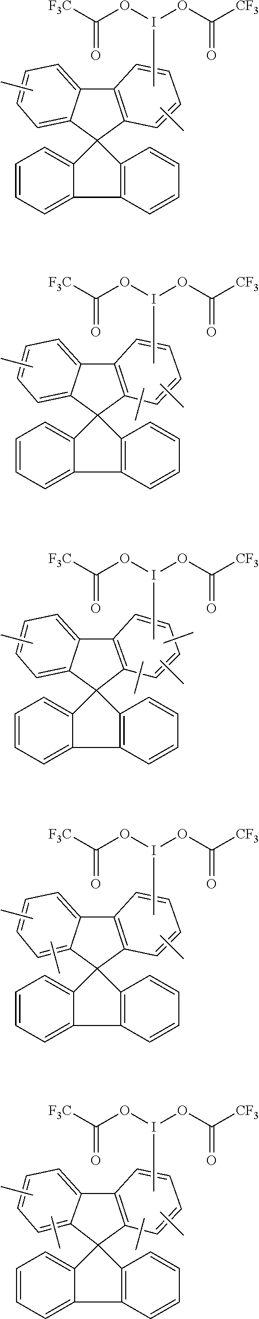

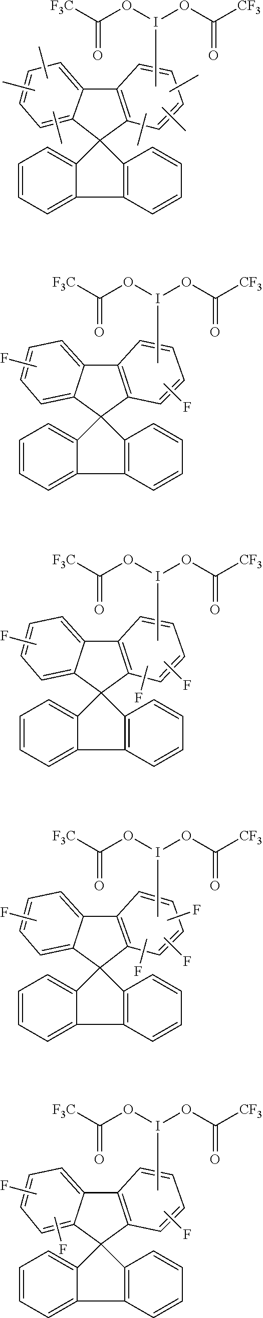

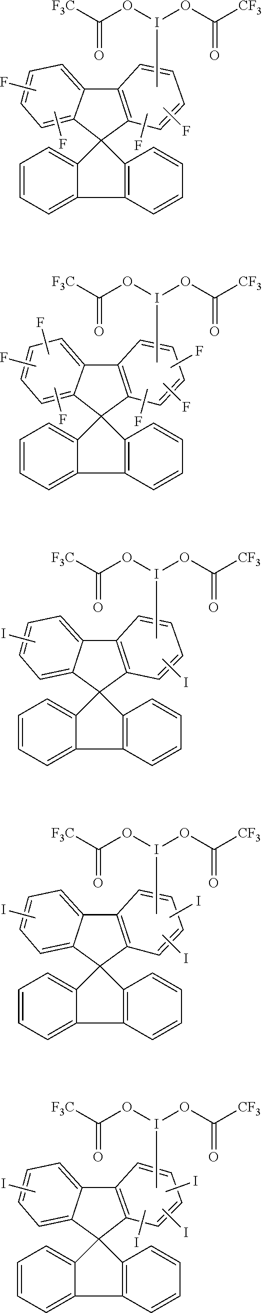

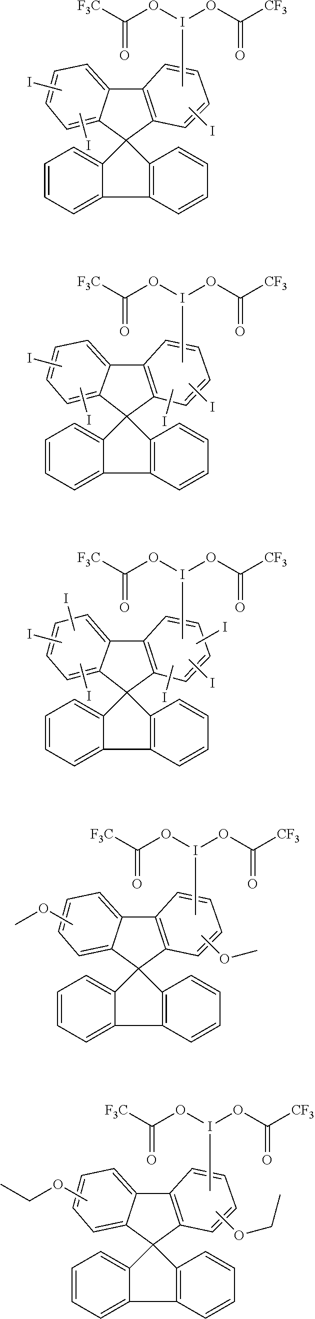

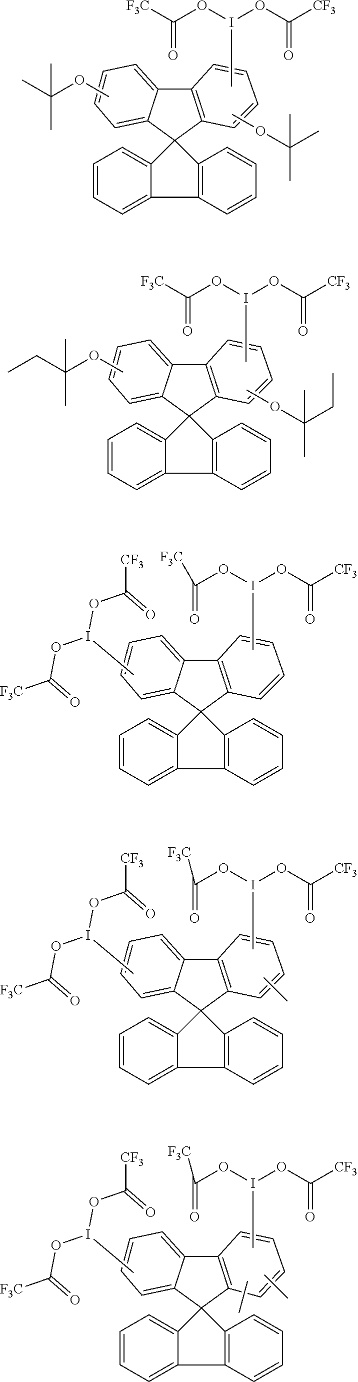

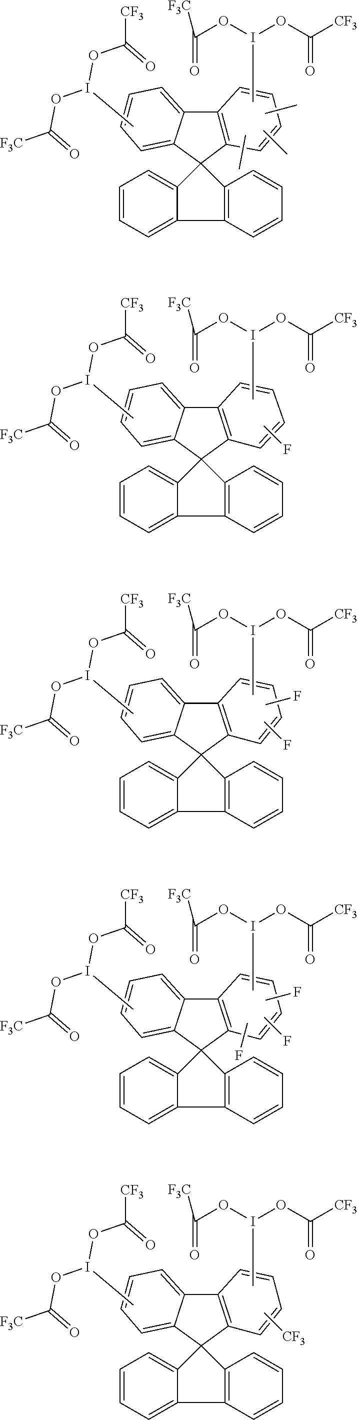

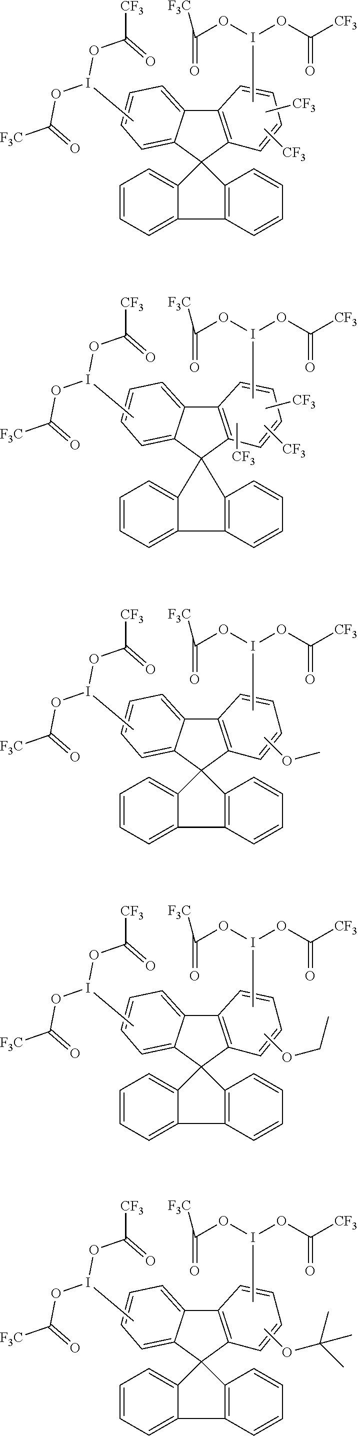

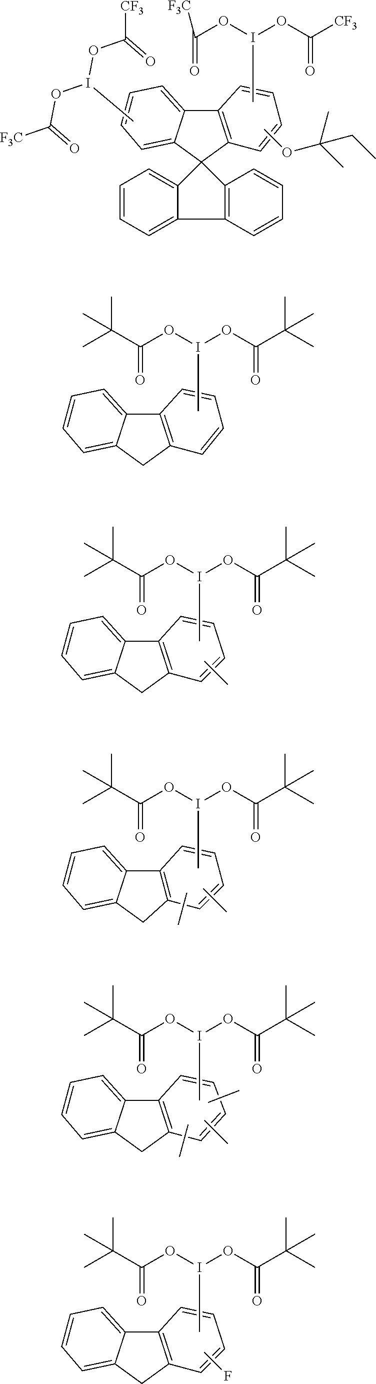

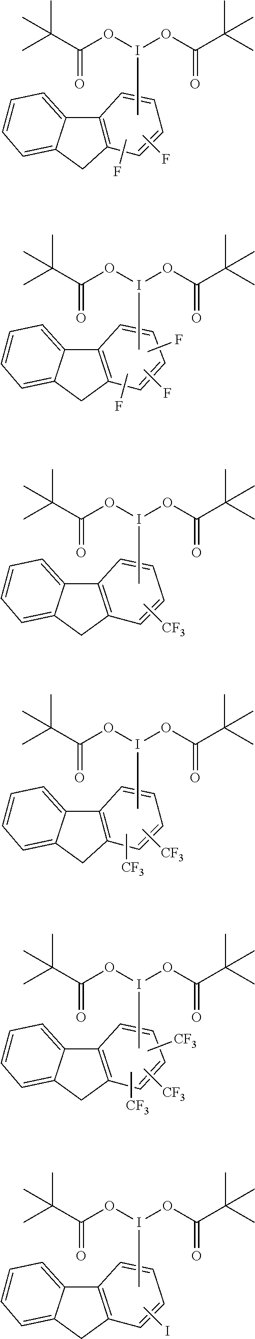

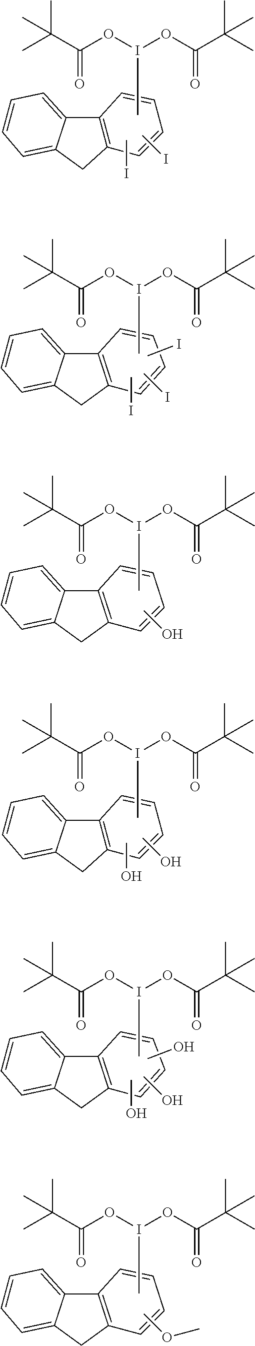

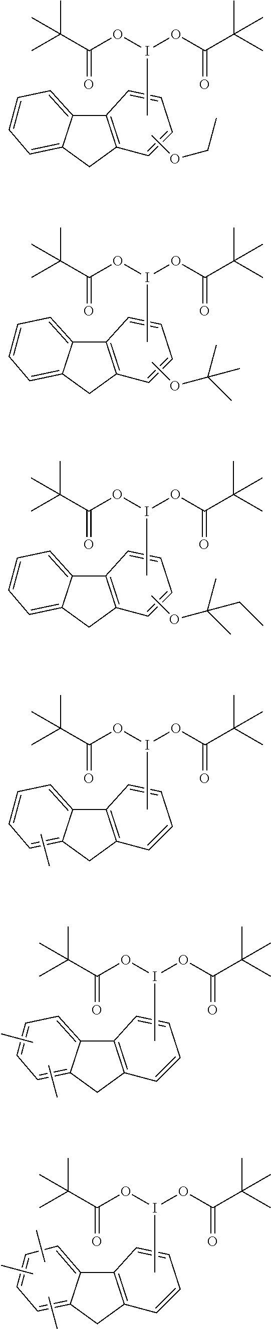

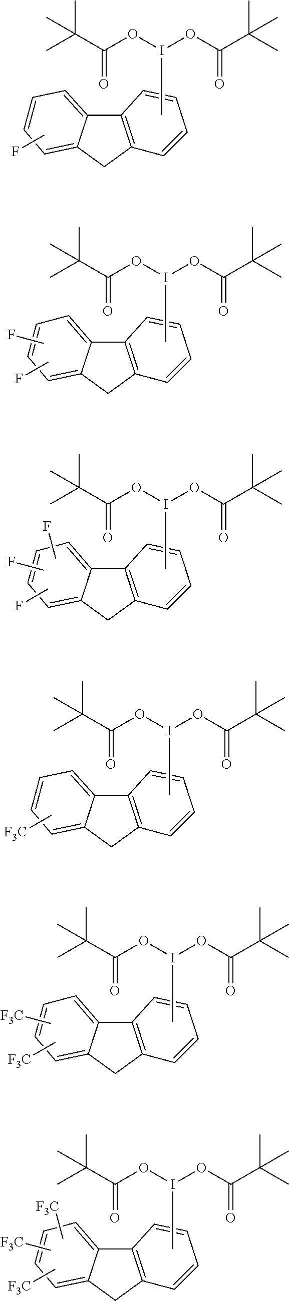

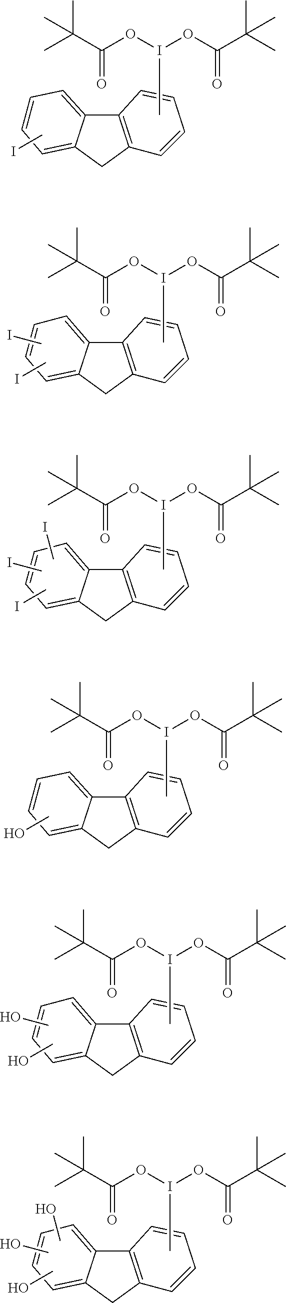

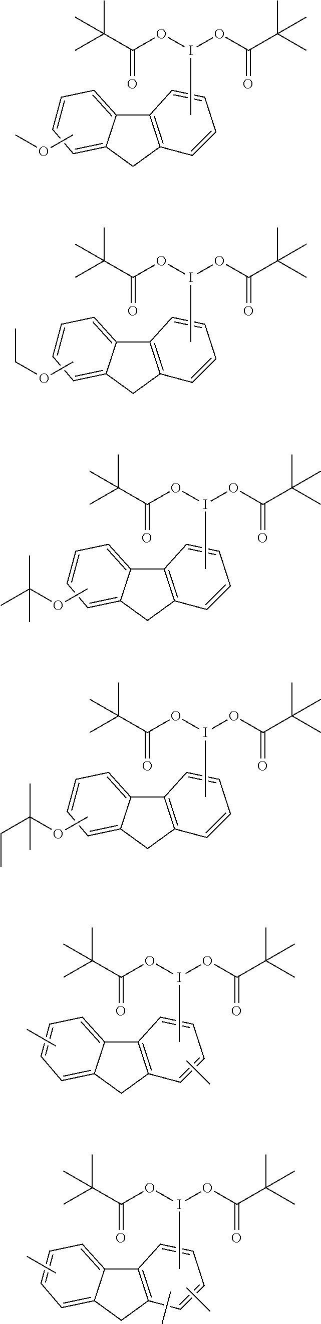

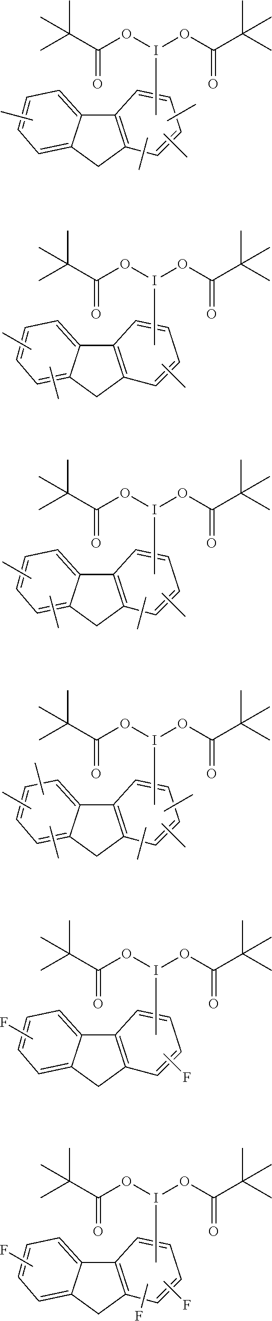

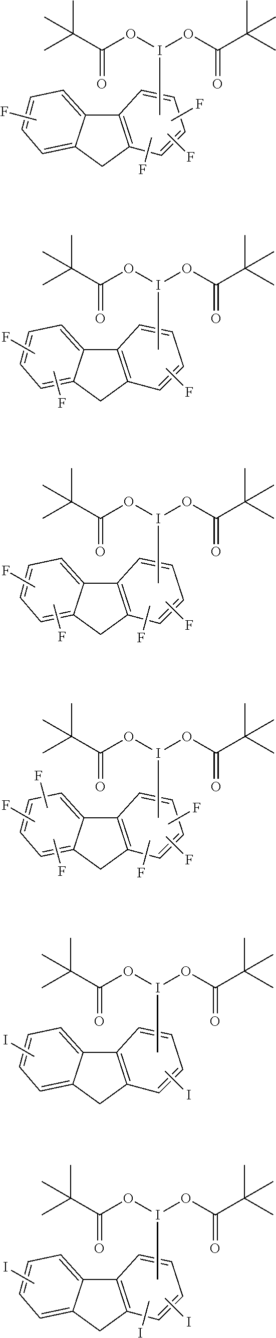

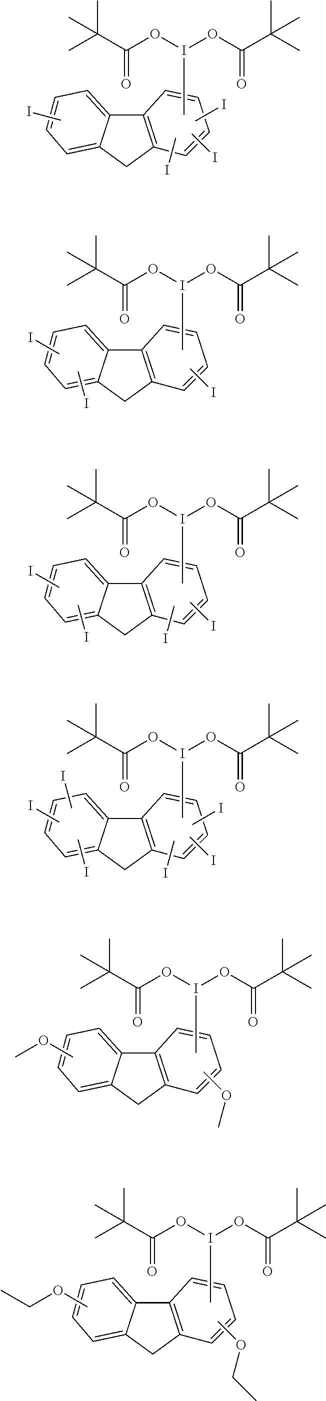

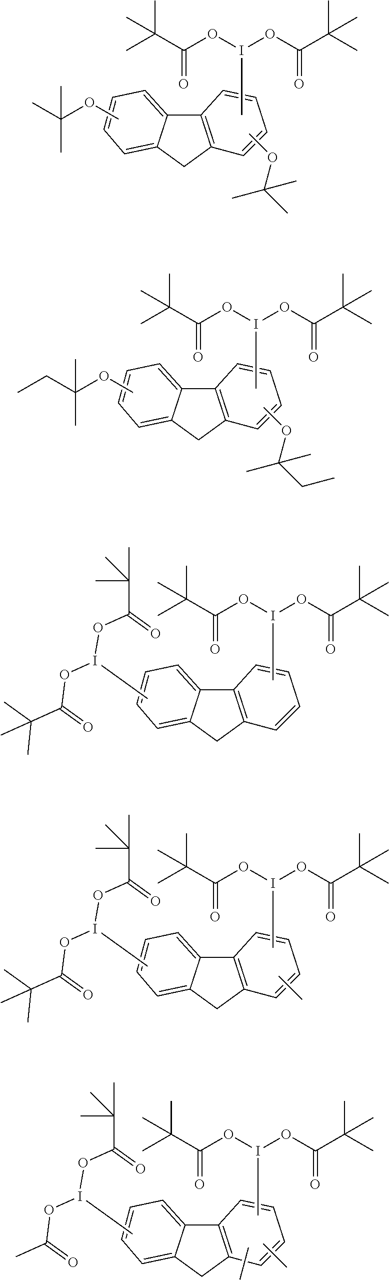

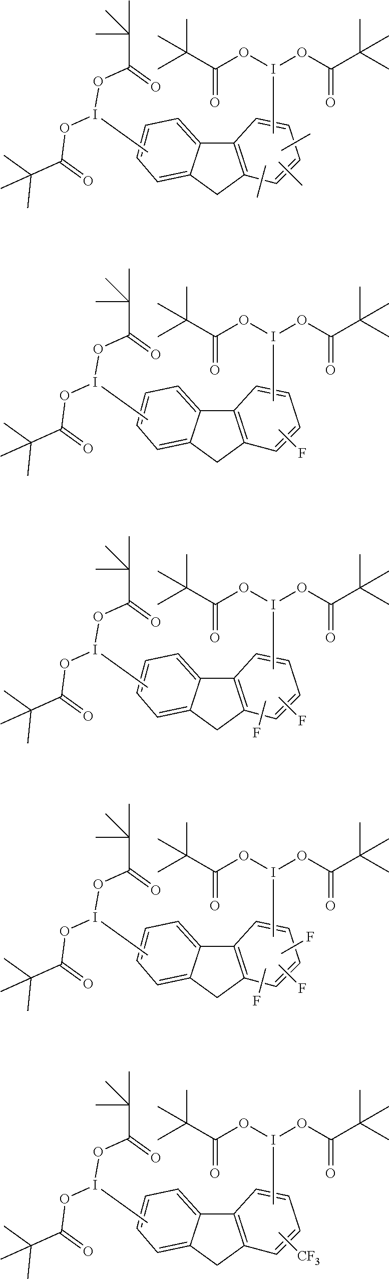

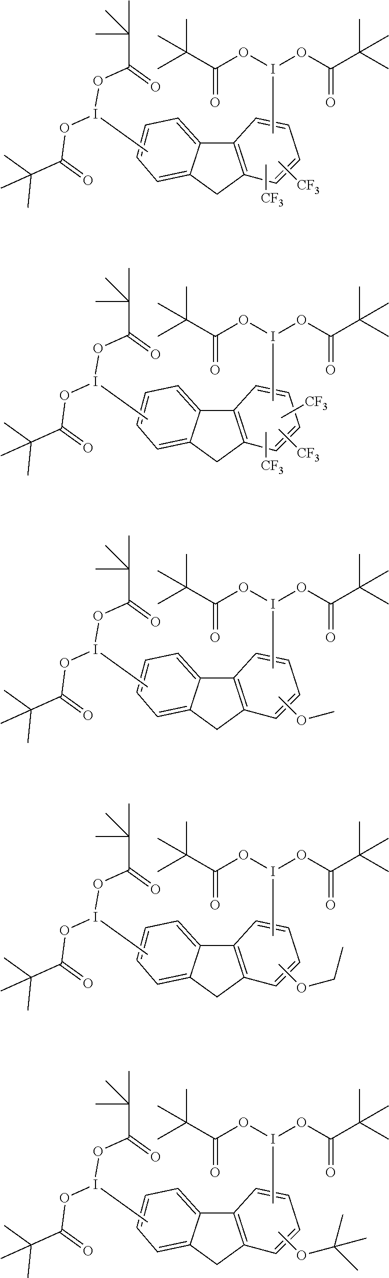

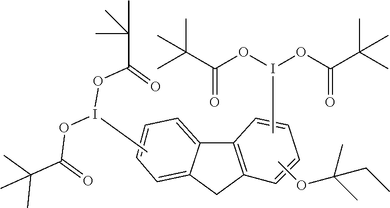

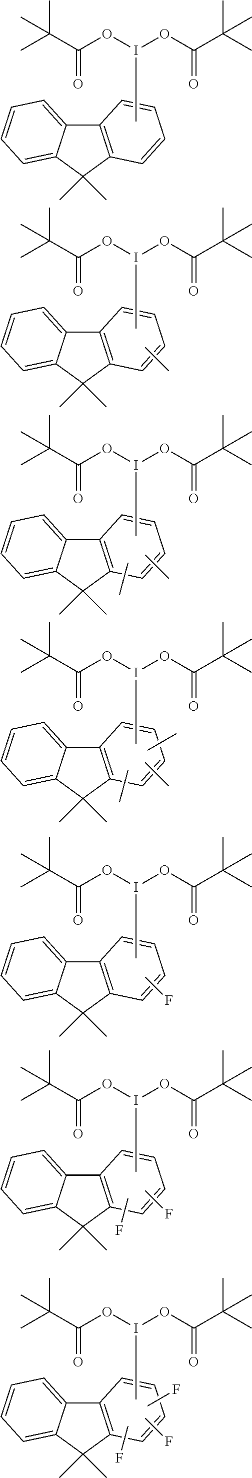

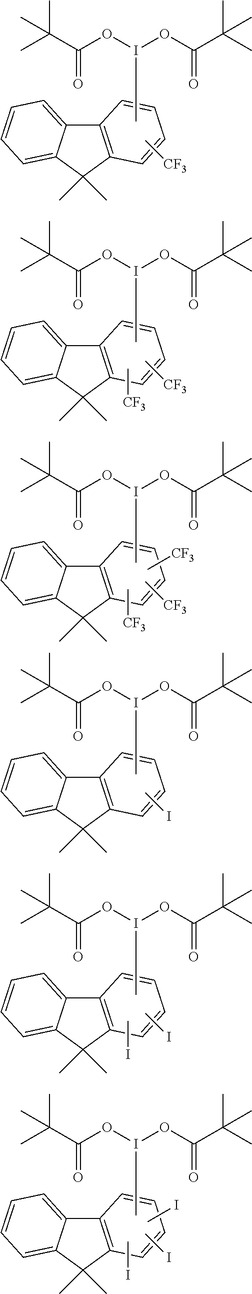

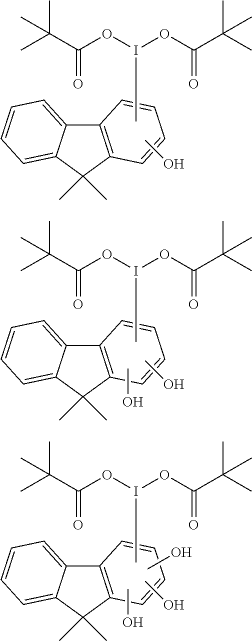

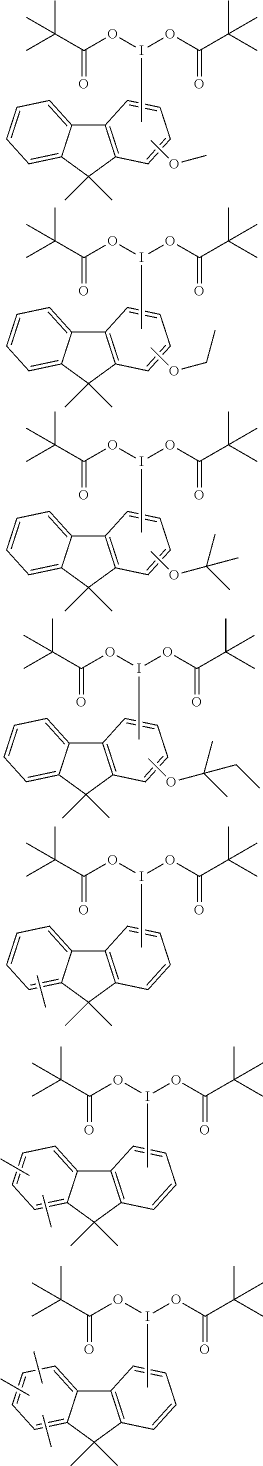

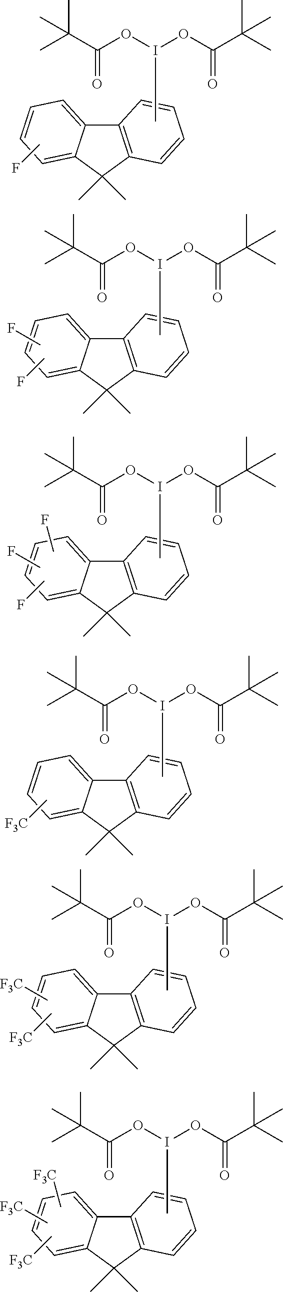

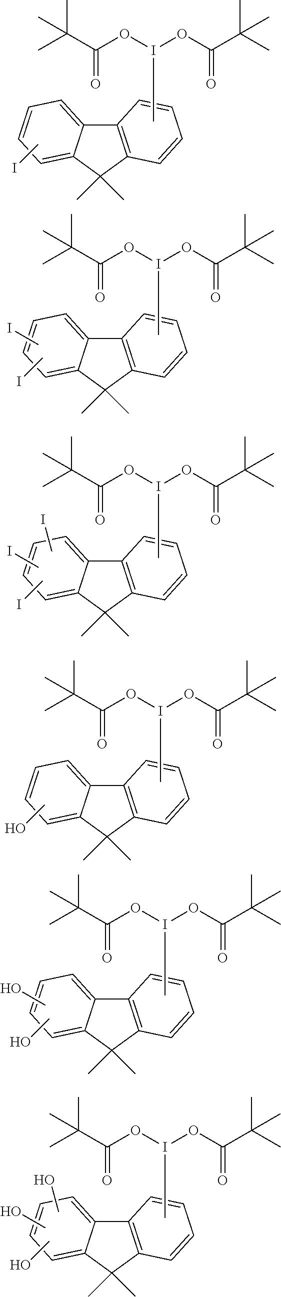

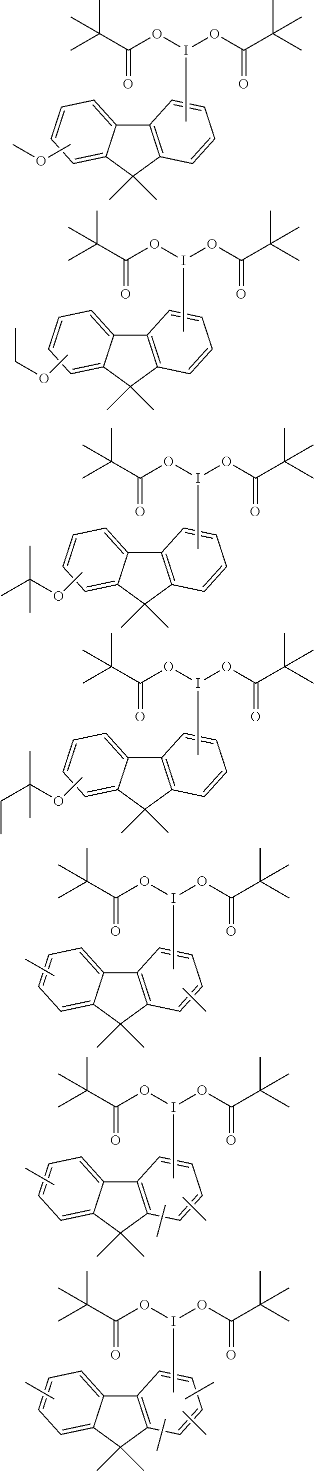

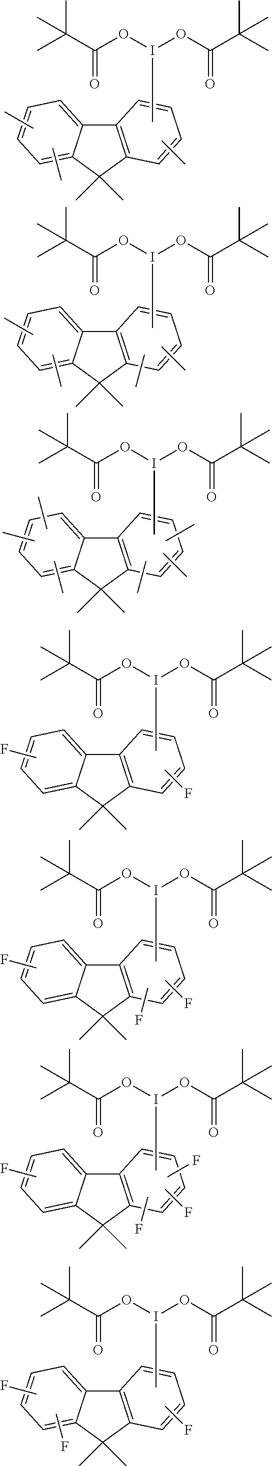

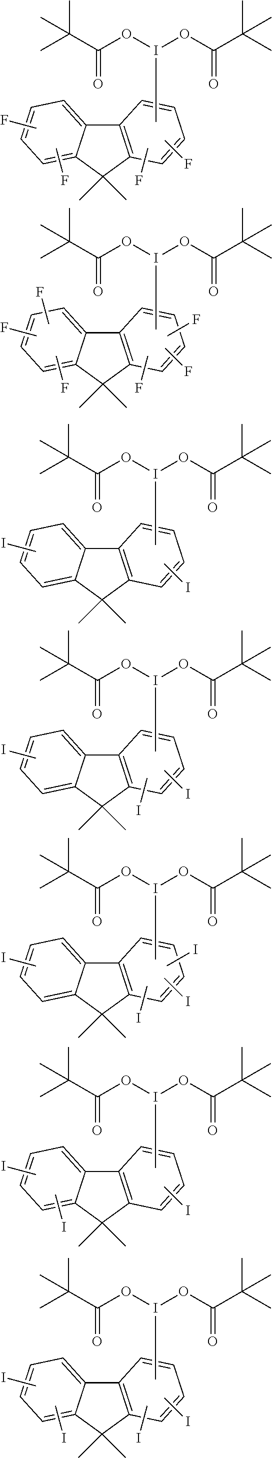

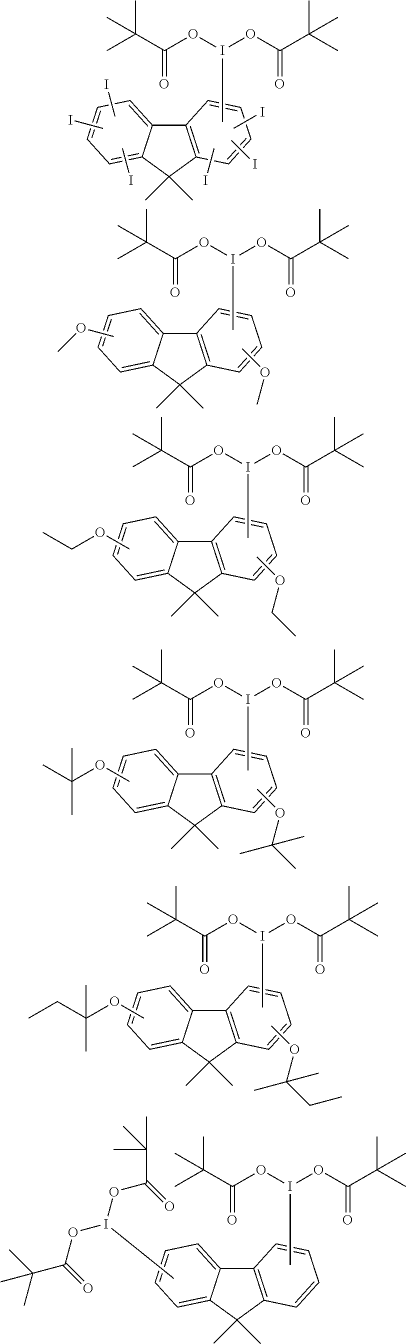

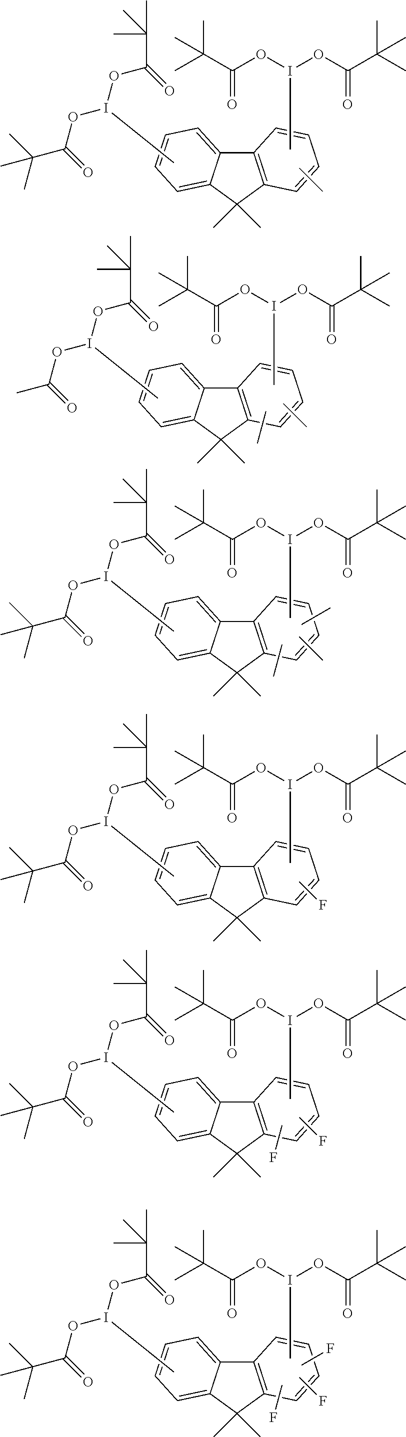

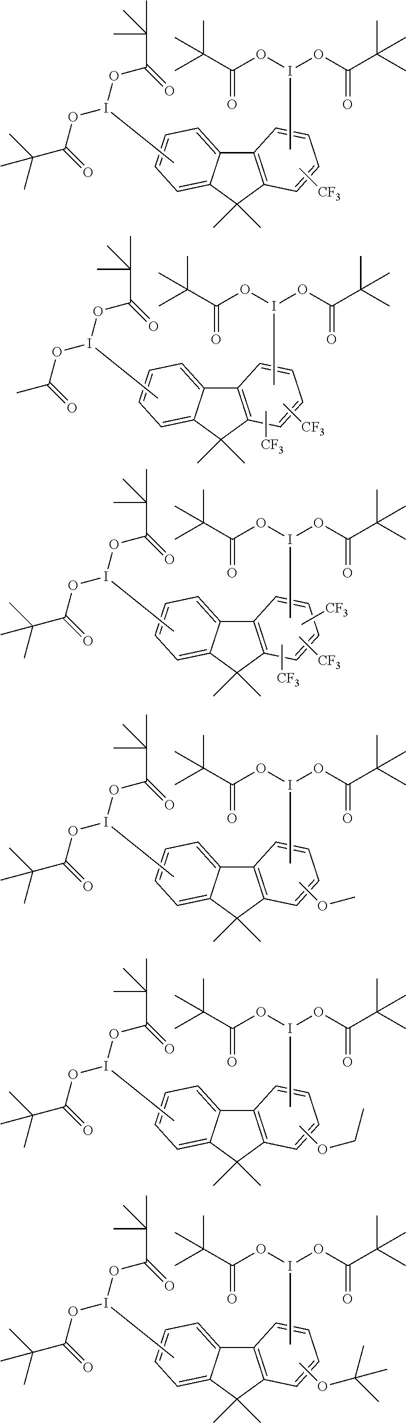

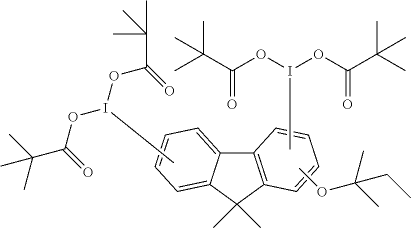

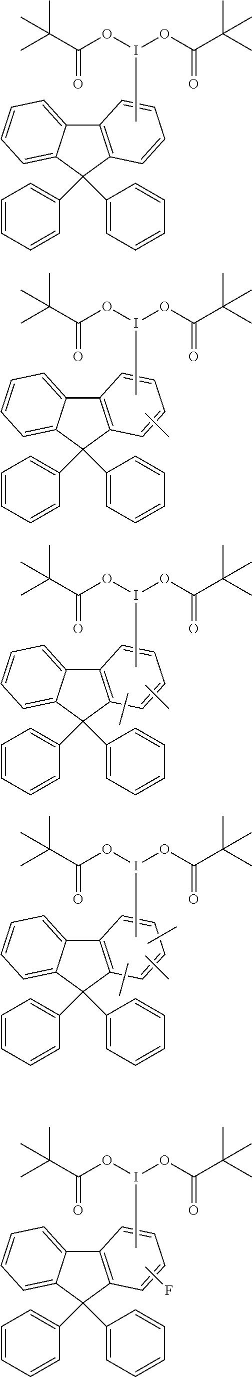

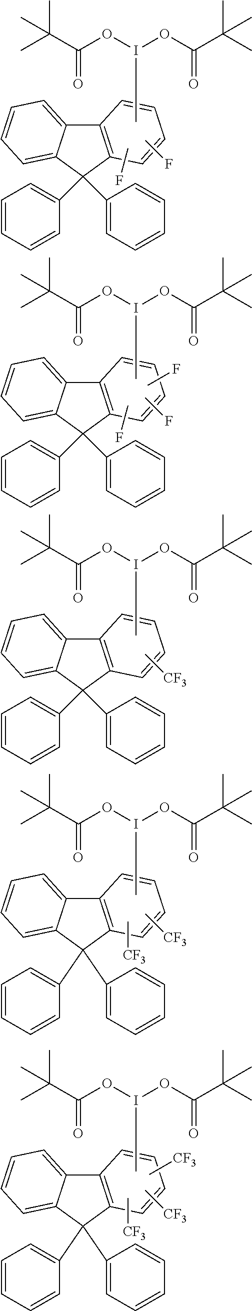

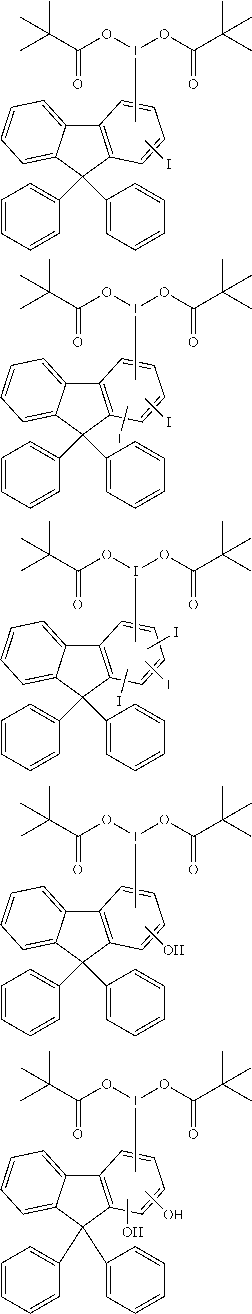

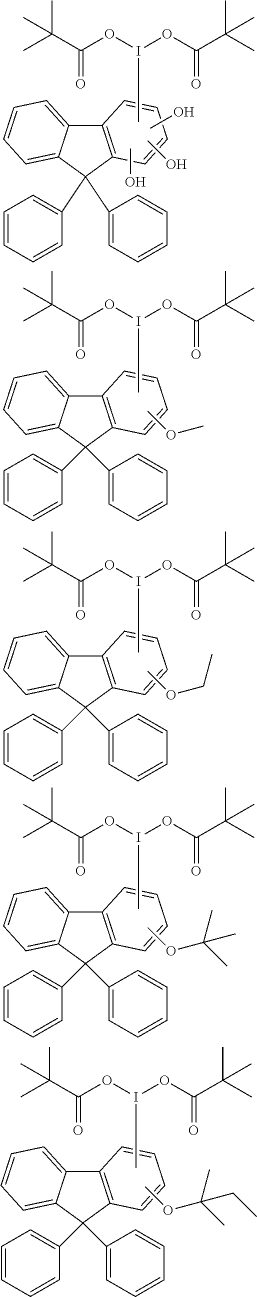

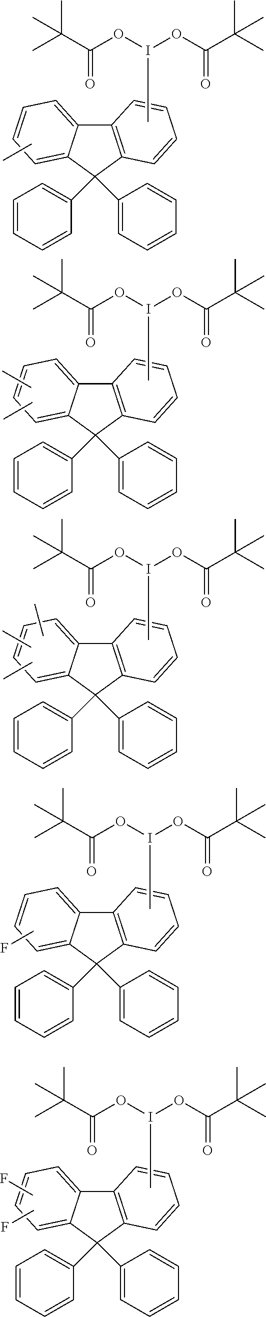

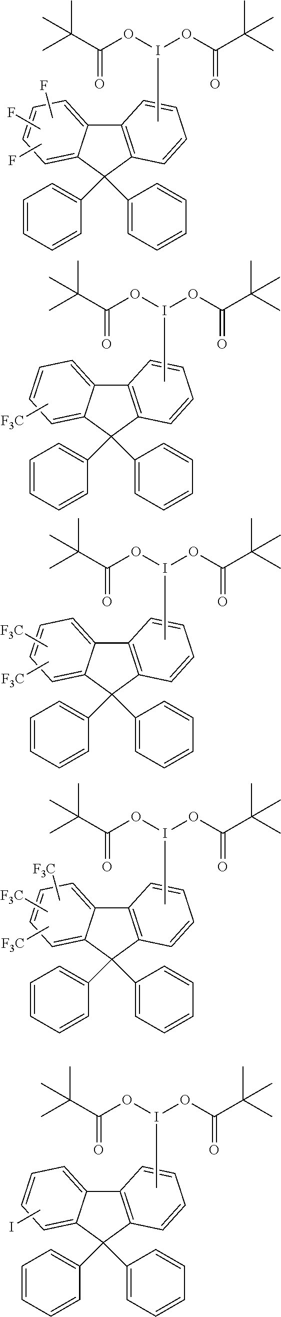

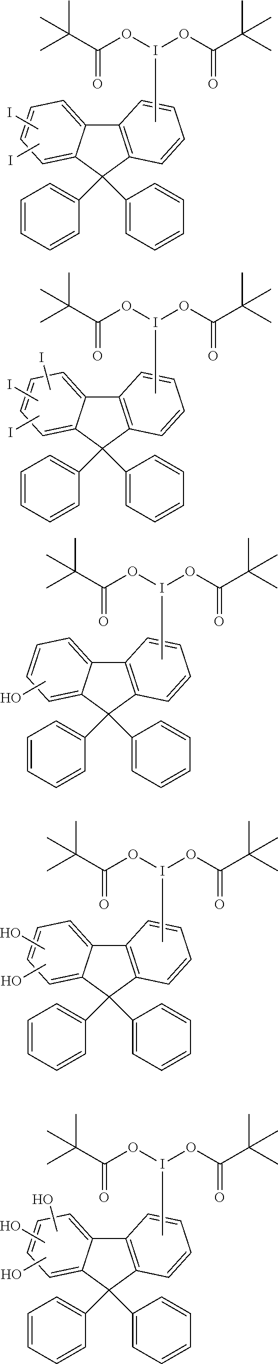

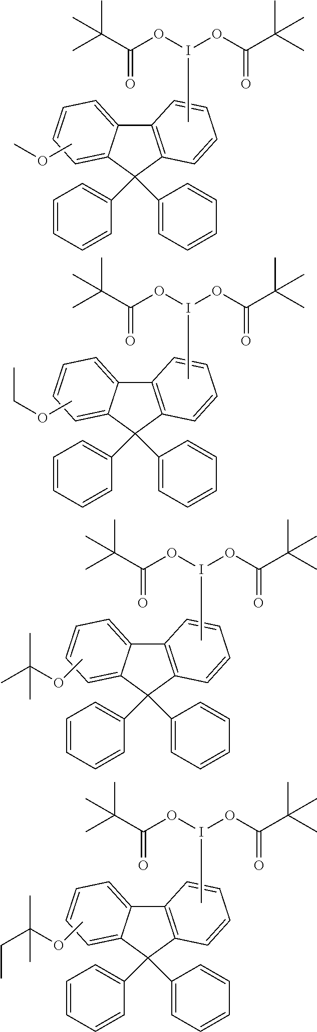

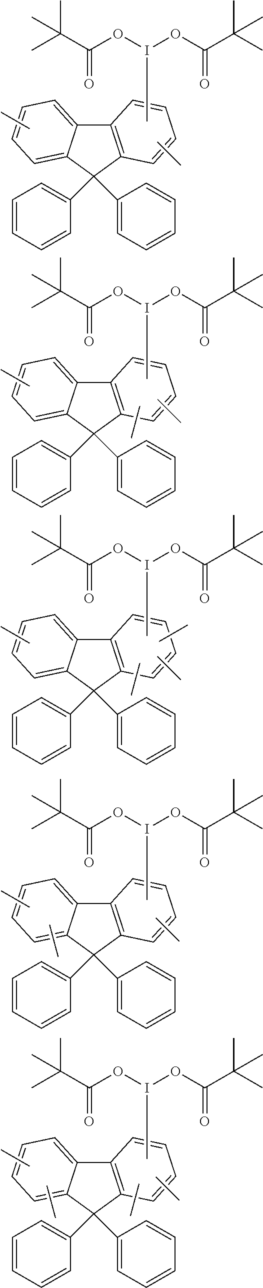

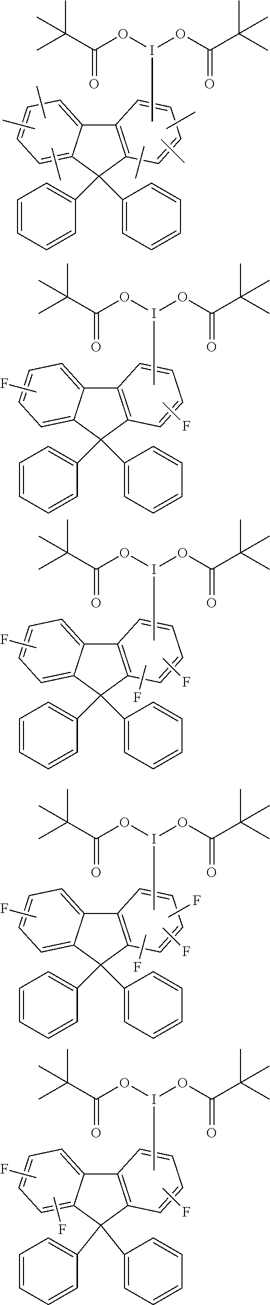

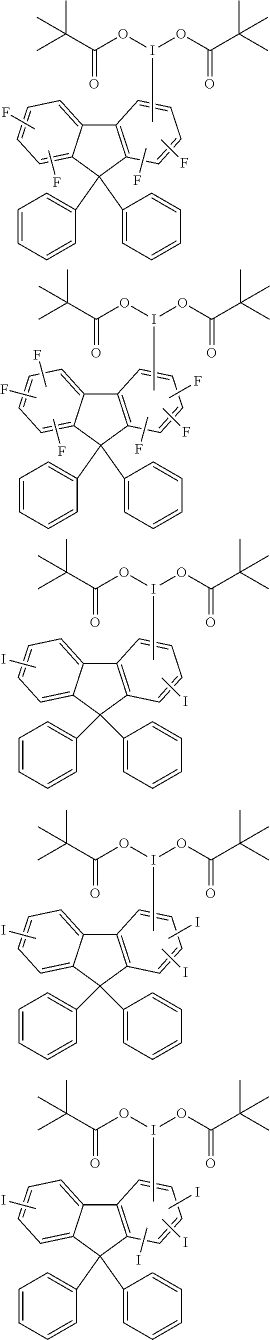

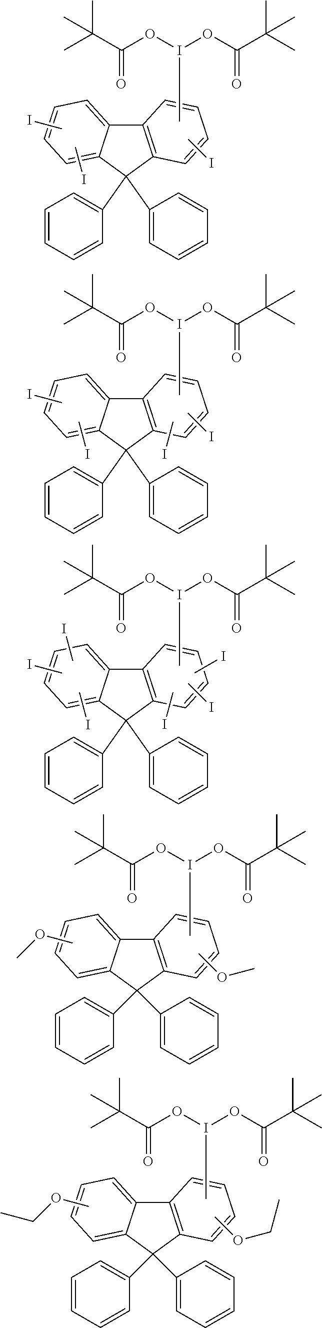

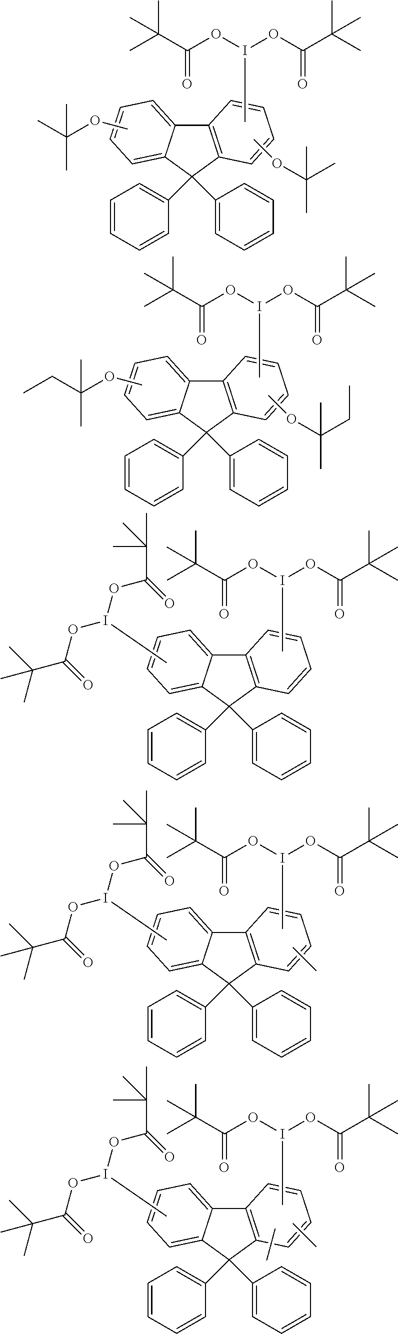

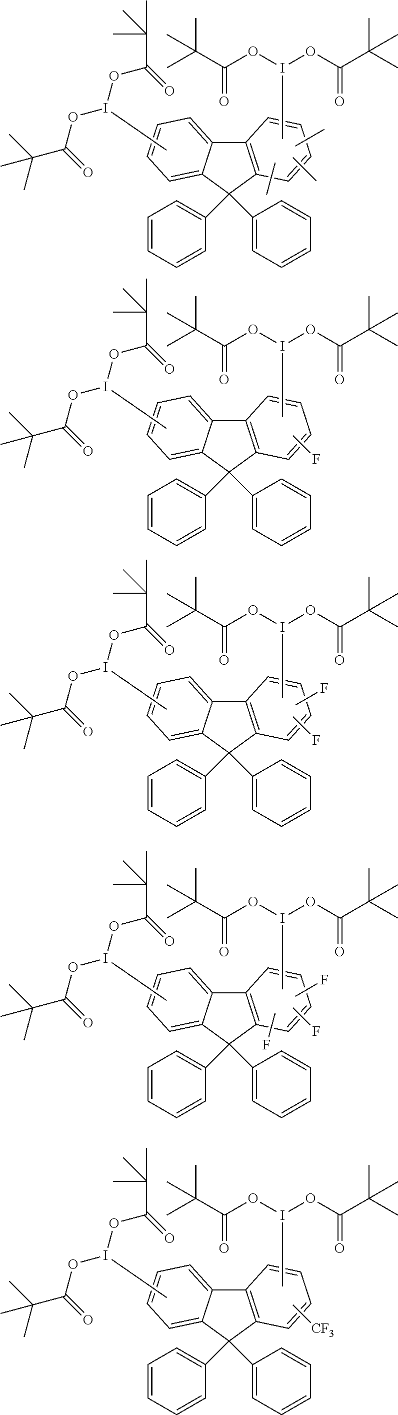

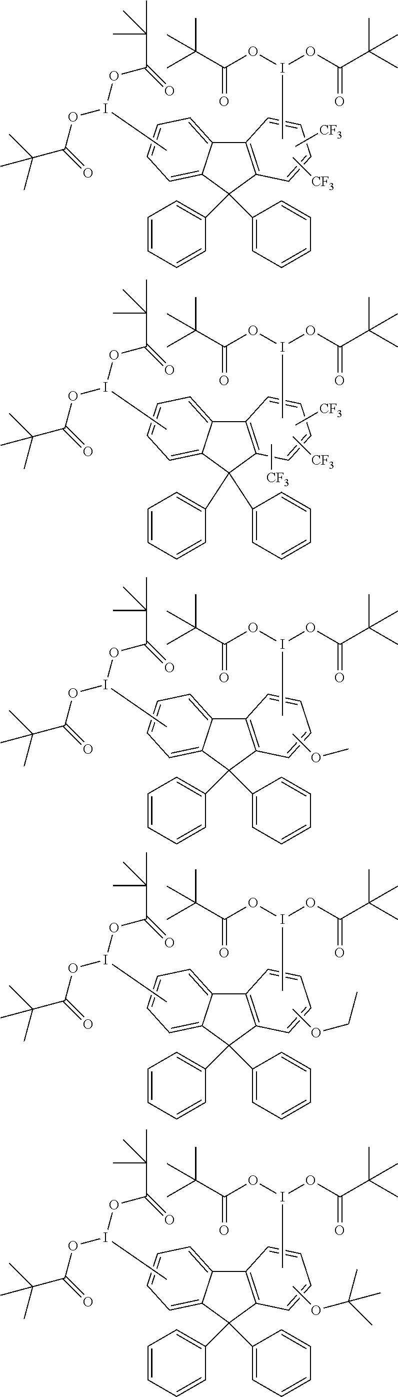

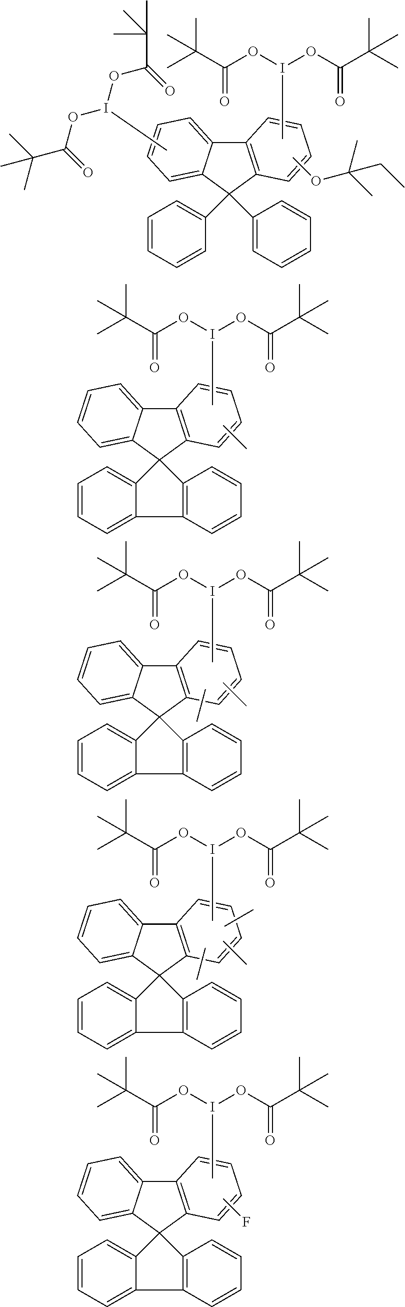

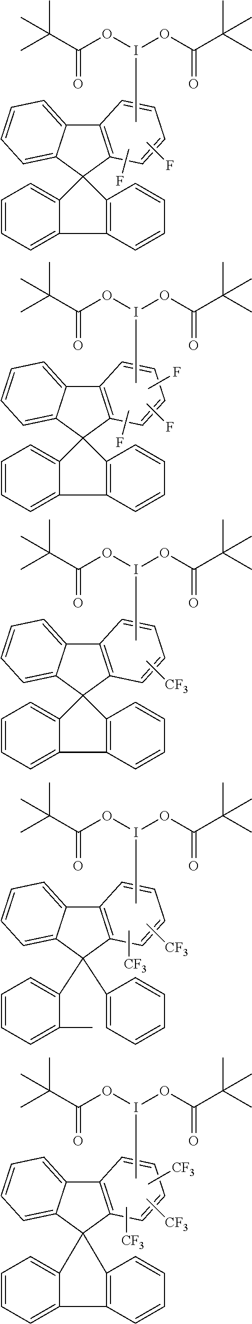

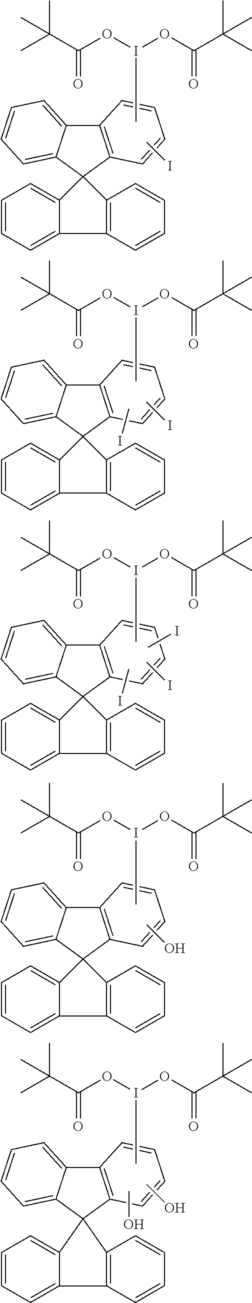

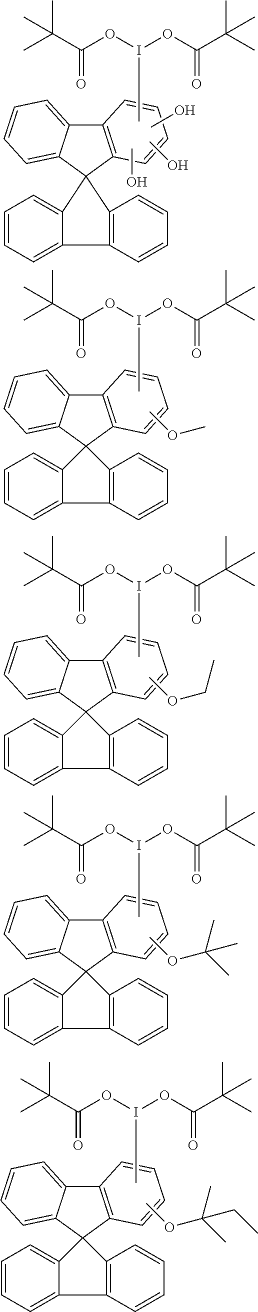

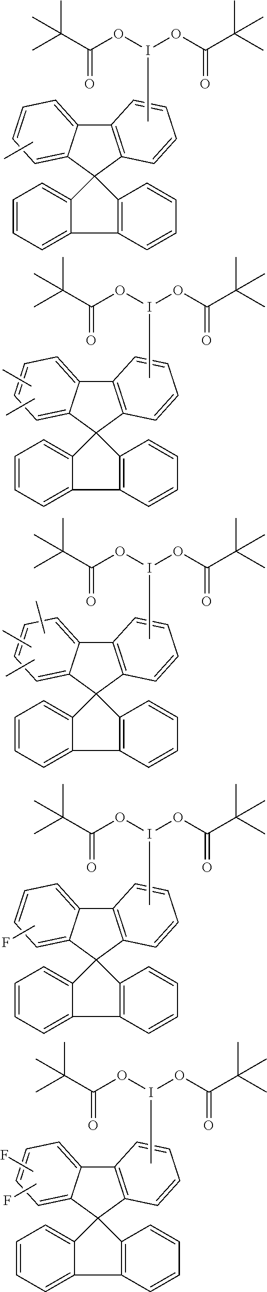

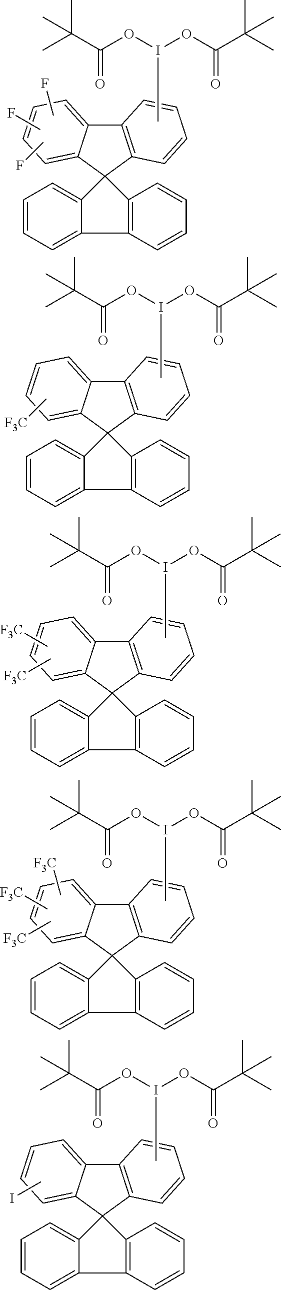

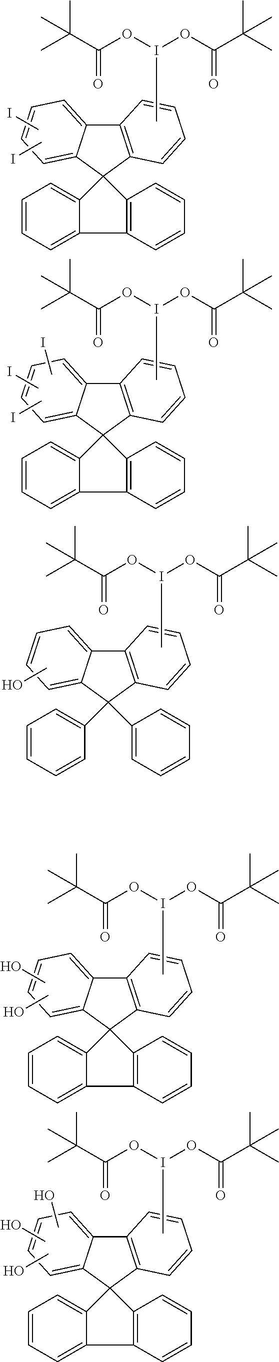

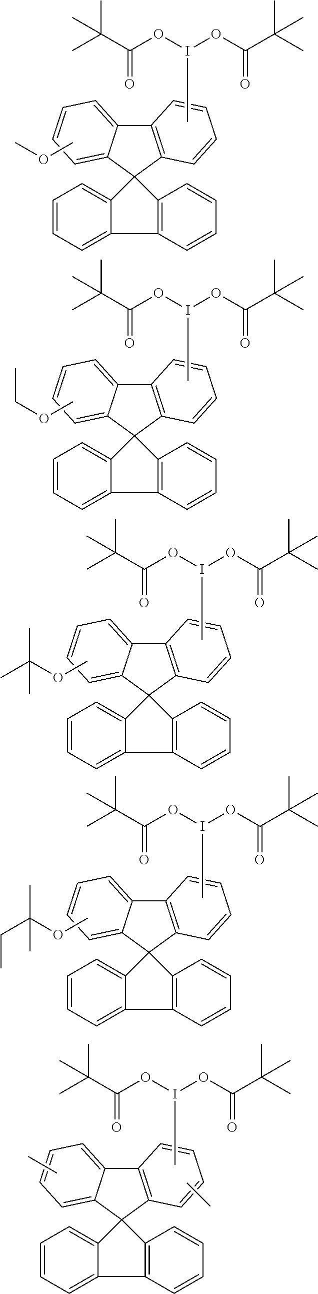

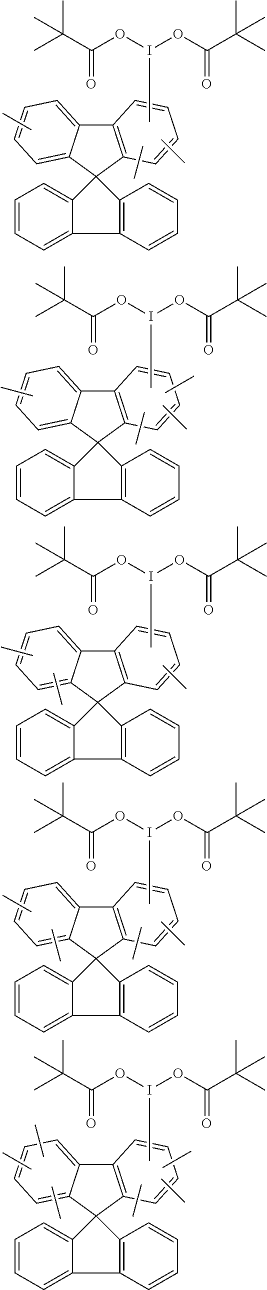

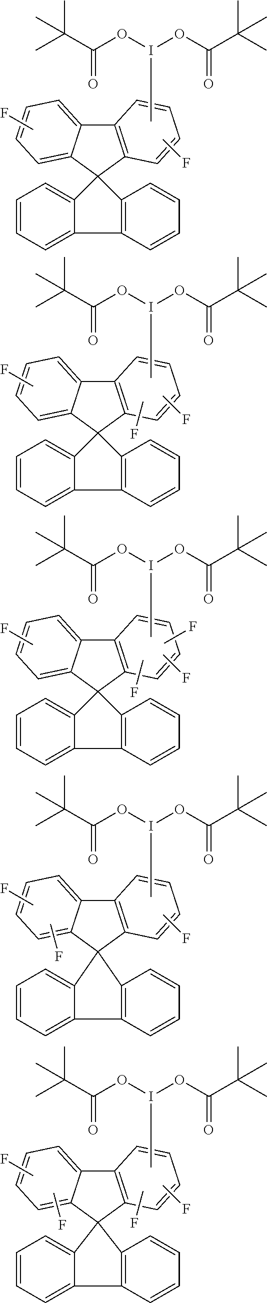

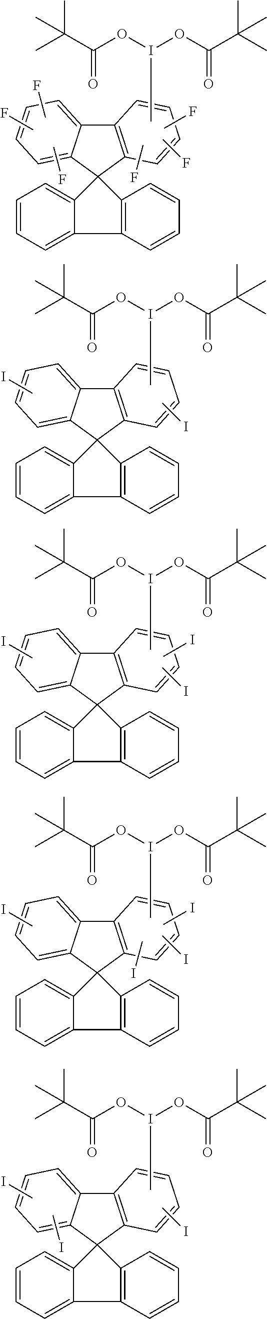

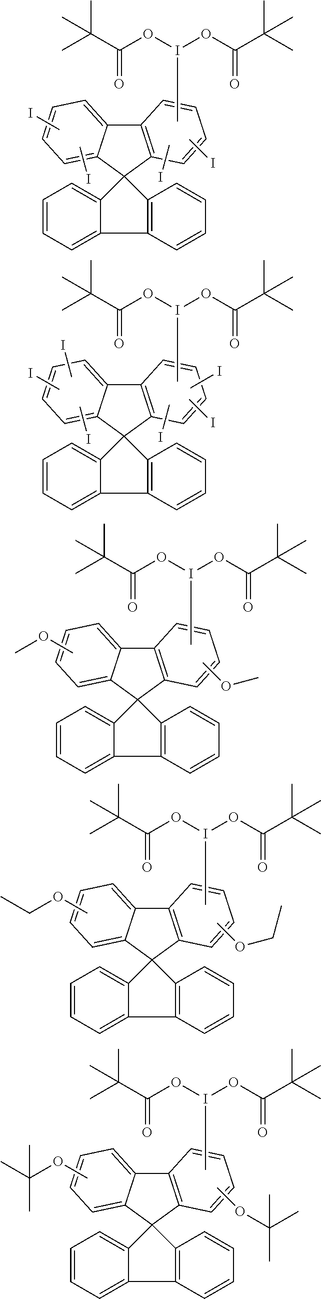

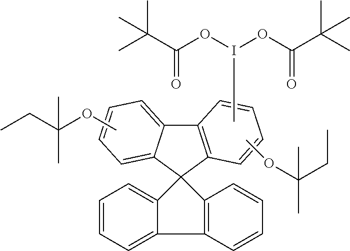

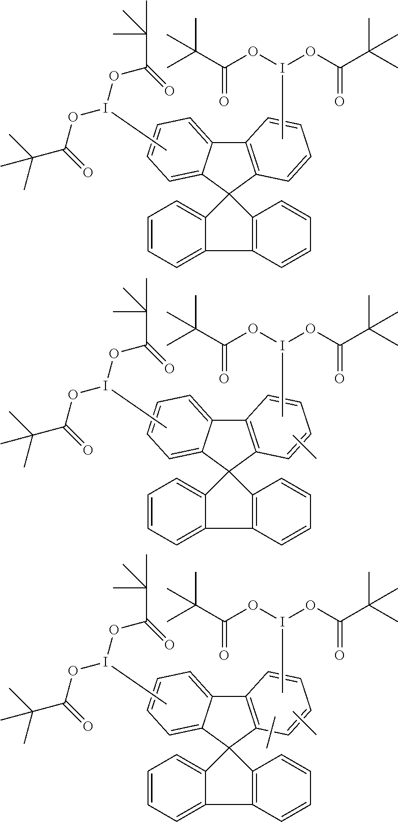

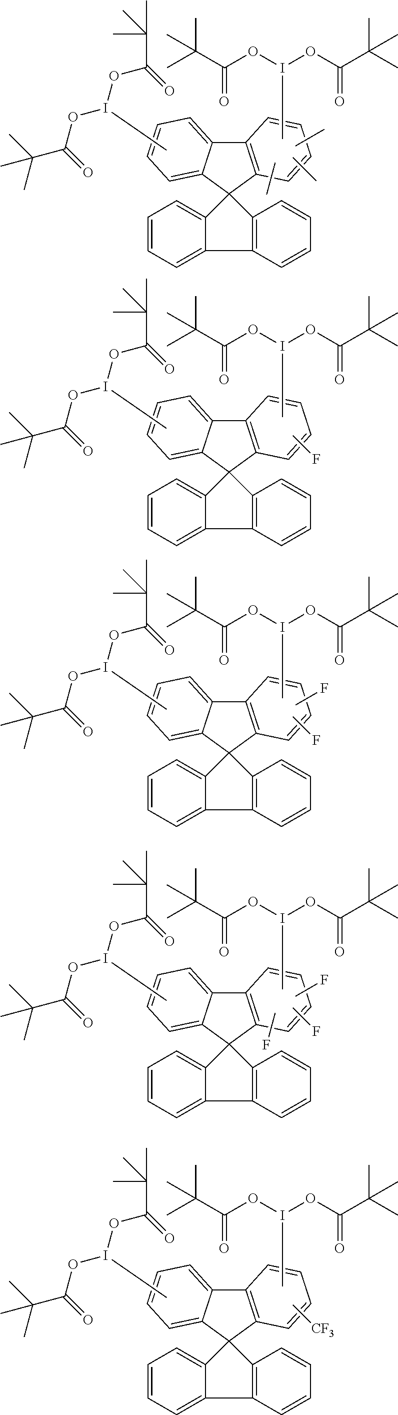

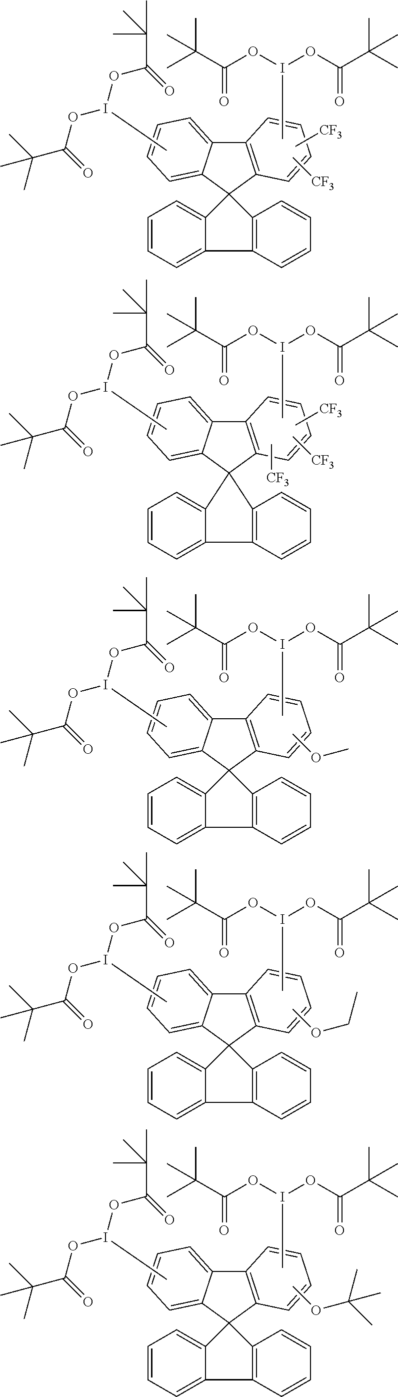

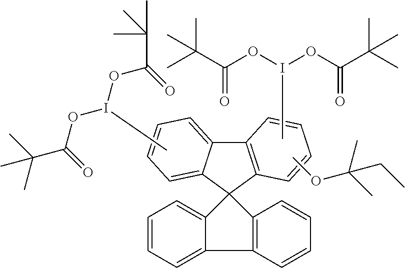

Examples of the hypervalent iodine compound having the formula (11) are shown

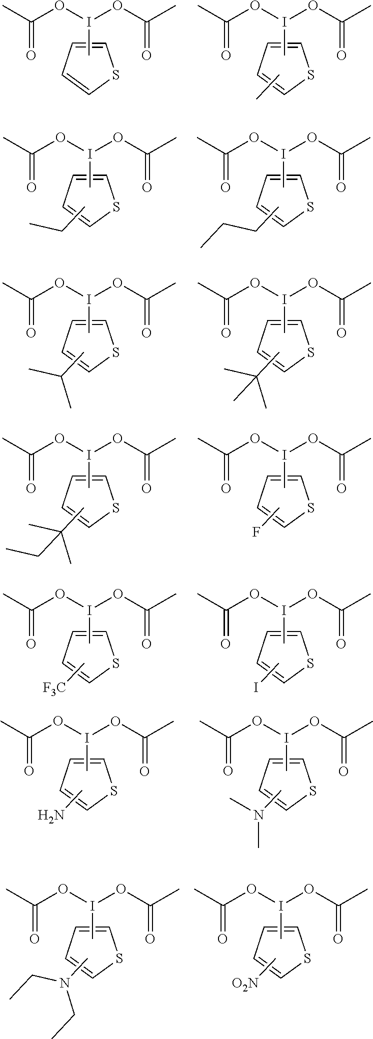

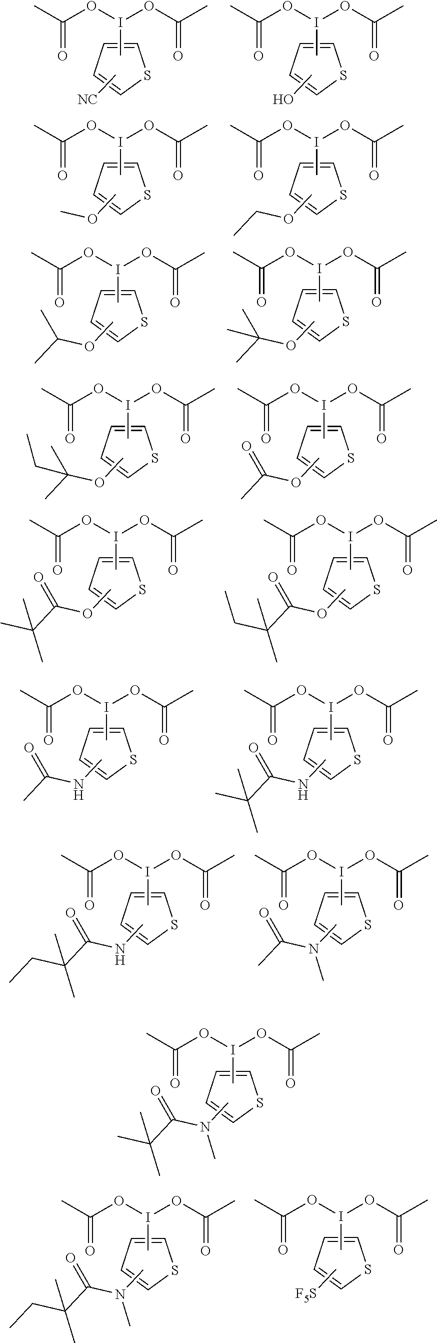

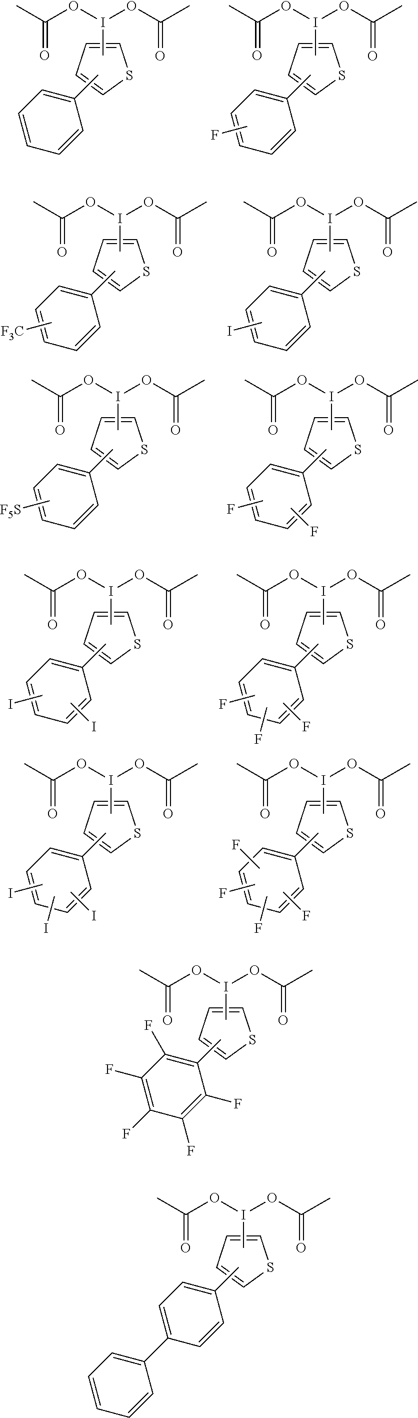

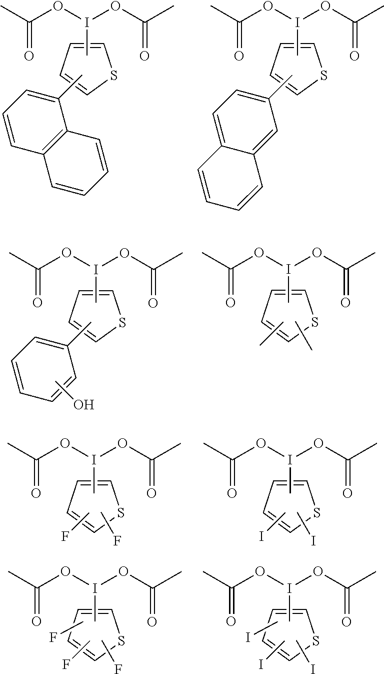

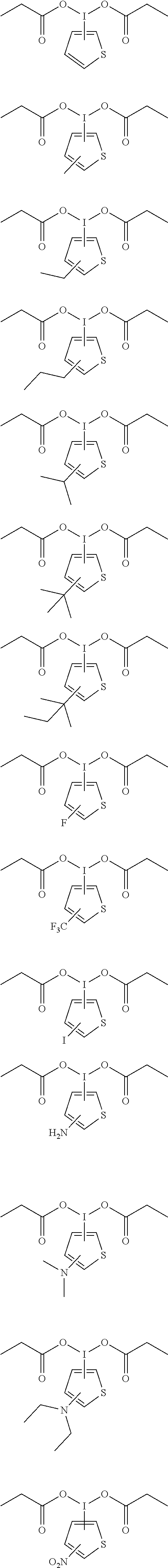

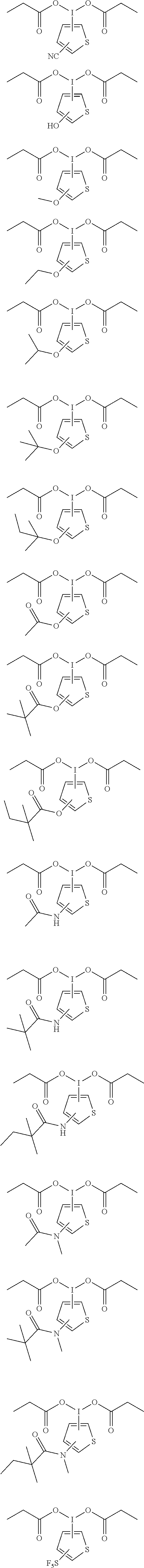

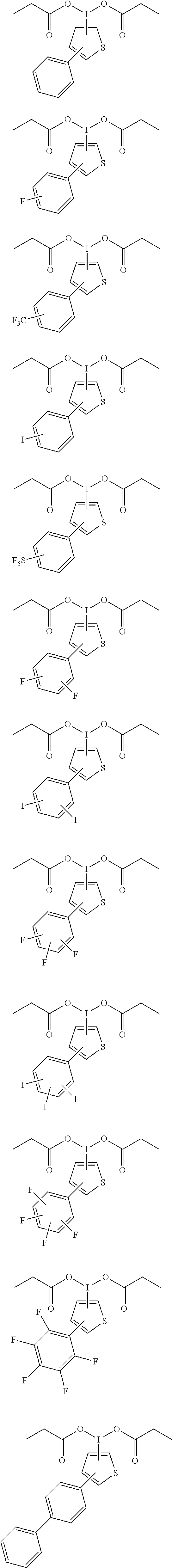

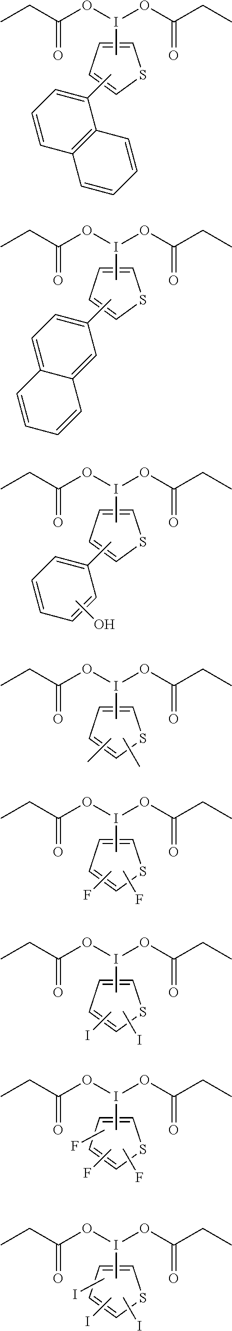

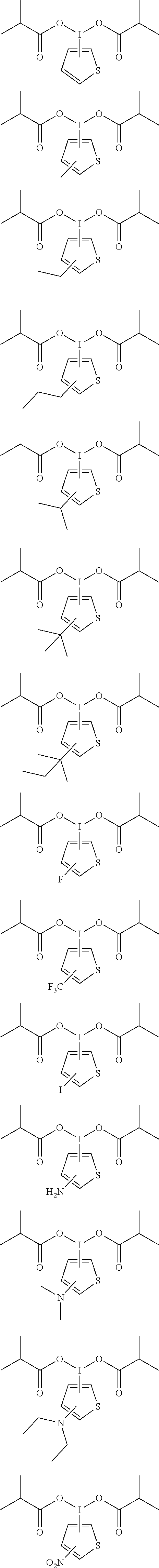

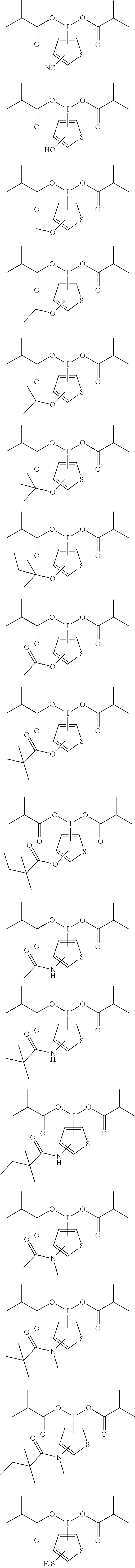

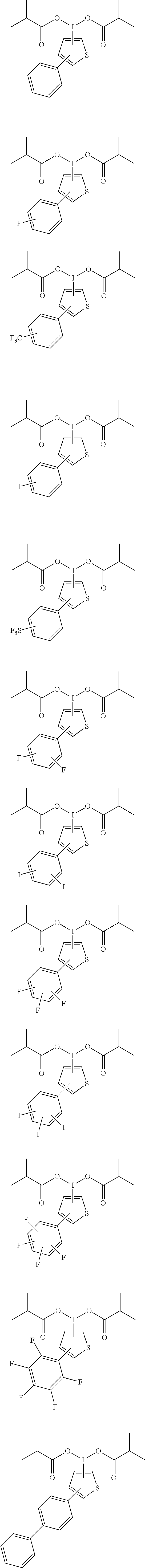

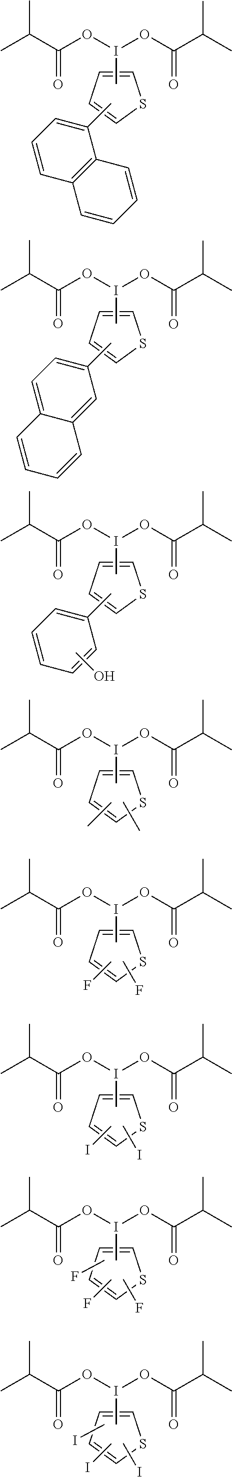

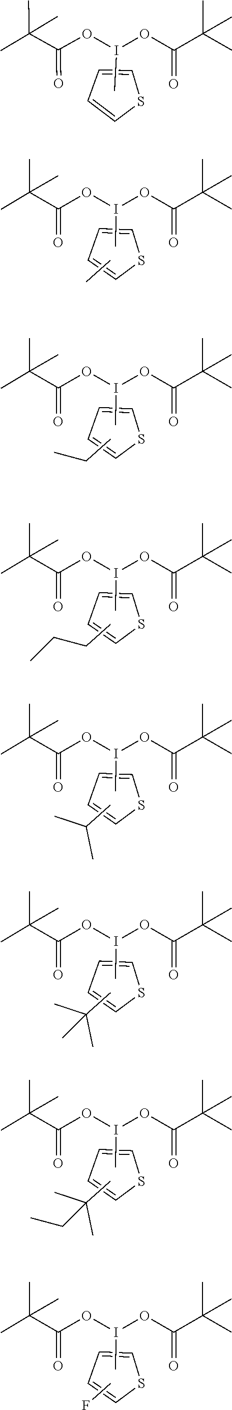

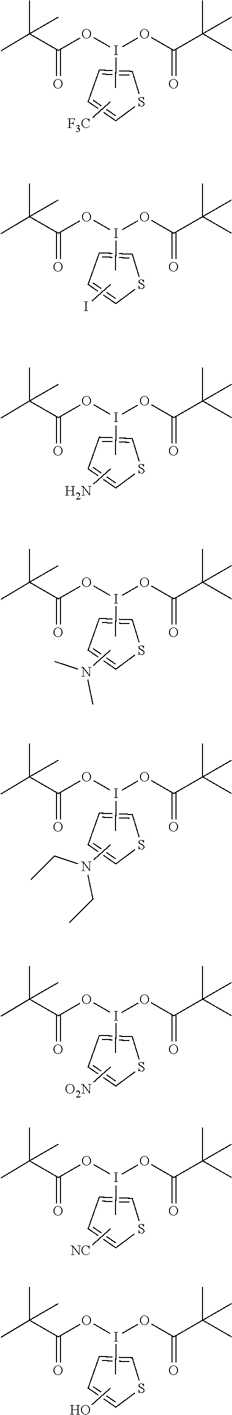

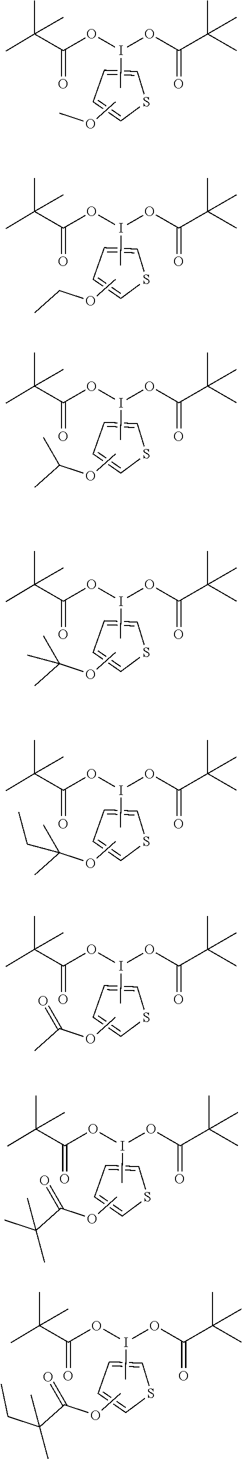

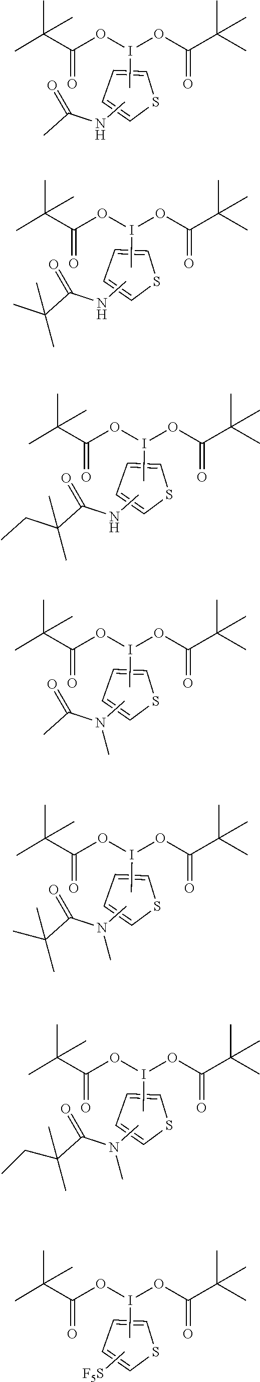

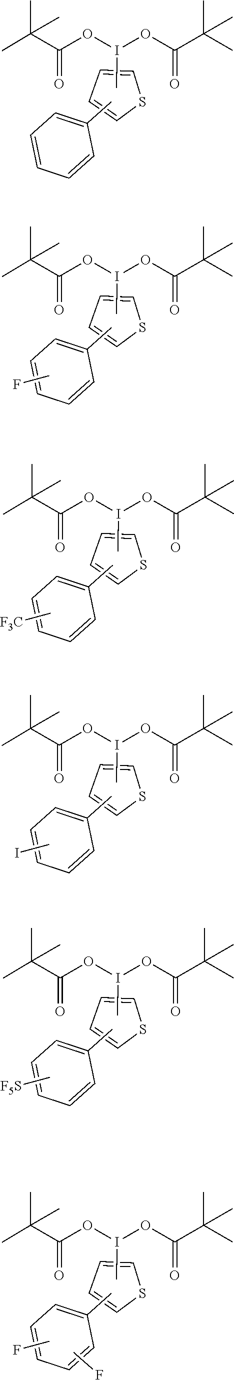

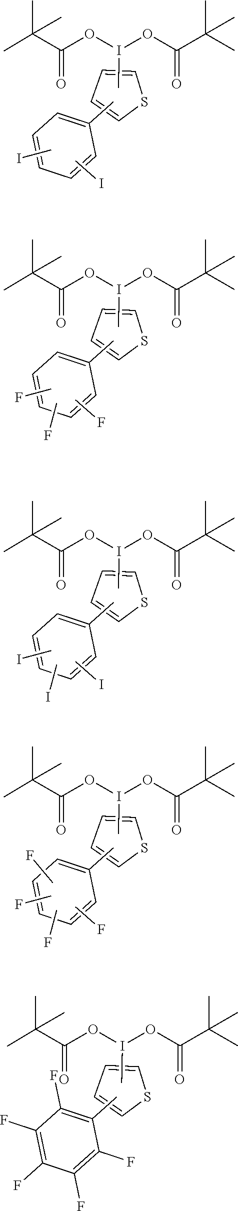

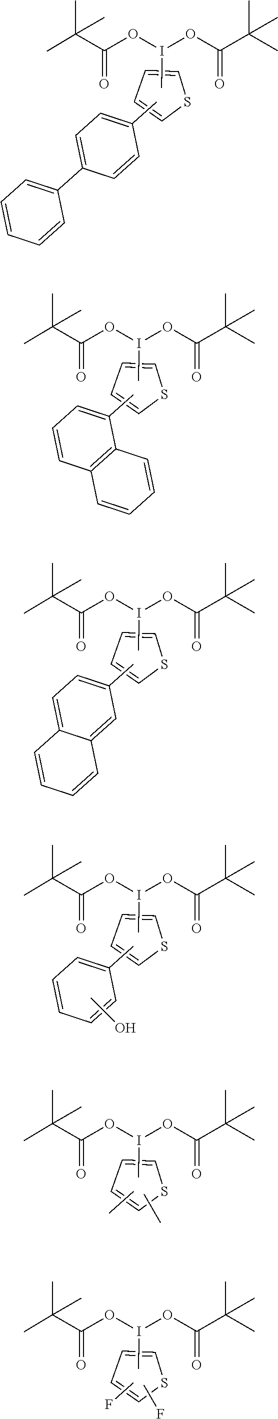

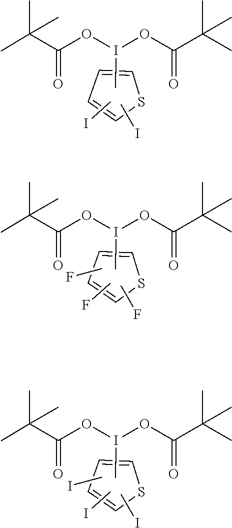

Examples of the hypervalent iodine compound having the formula (12) are shown

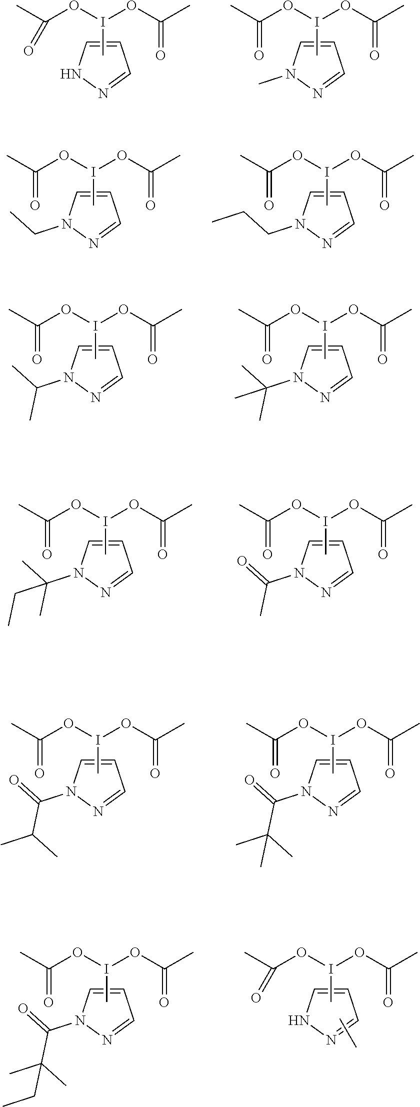

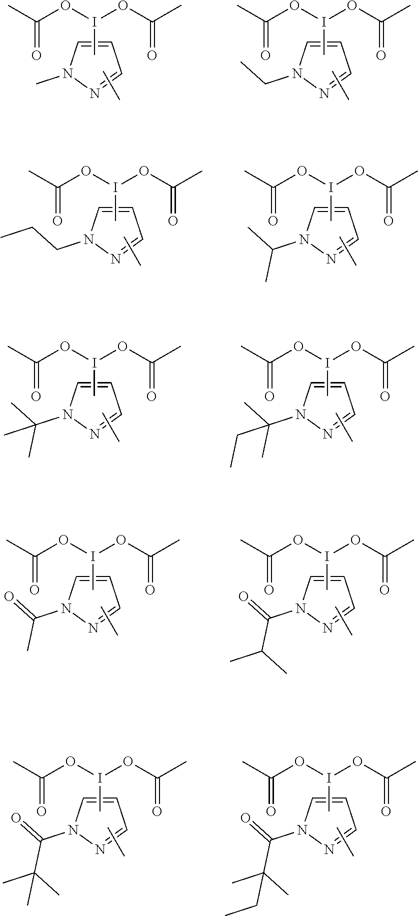

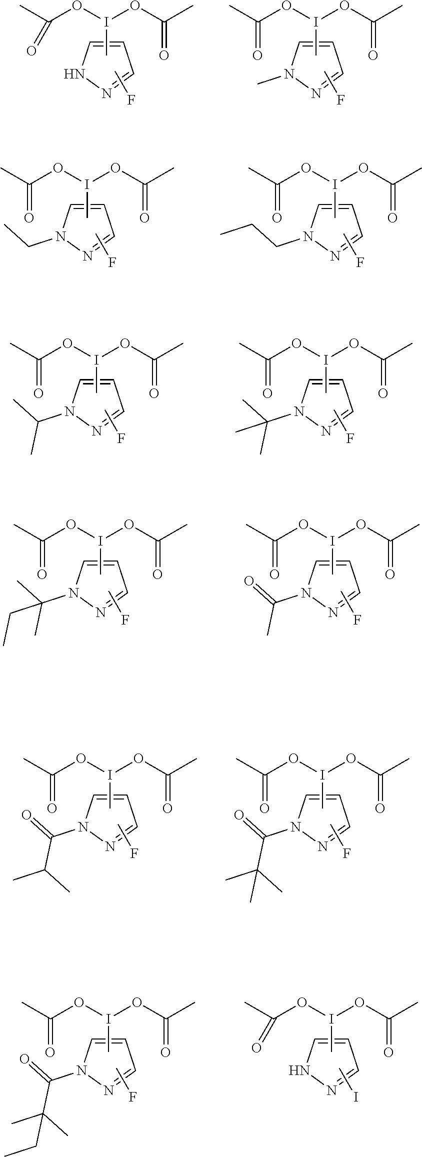

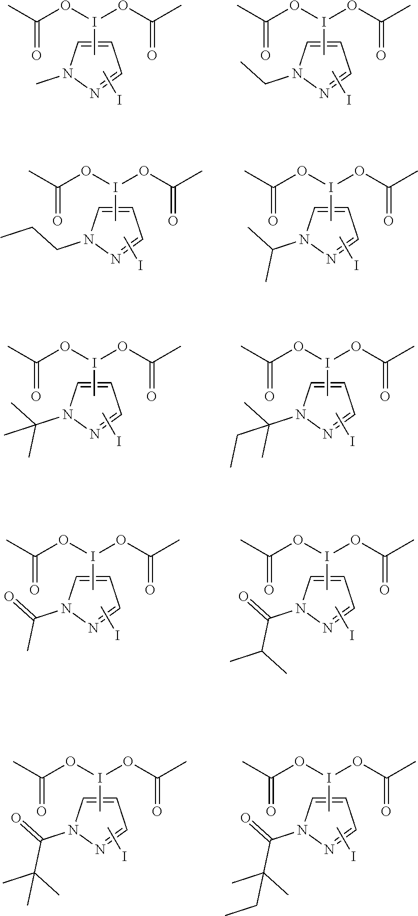

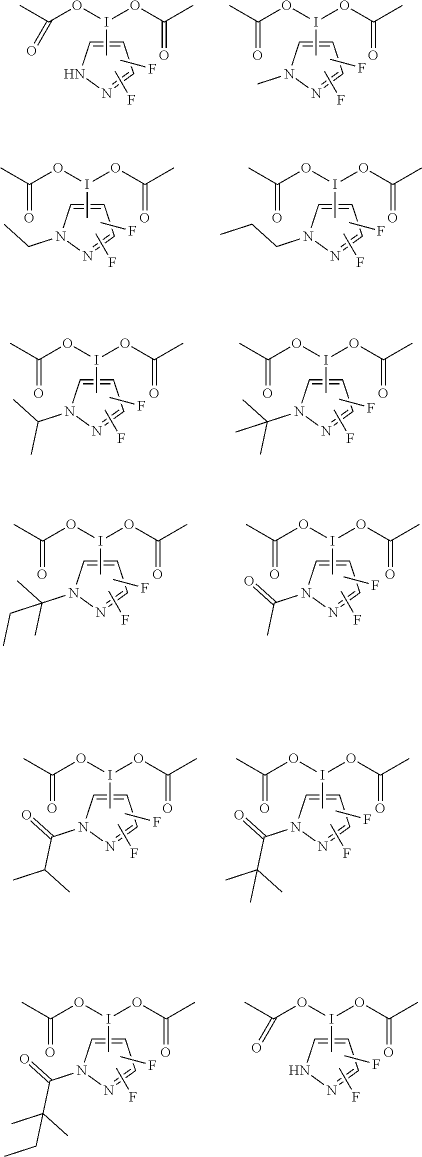

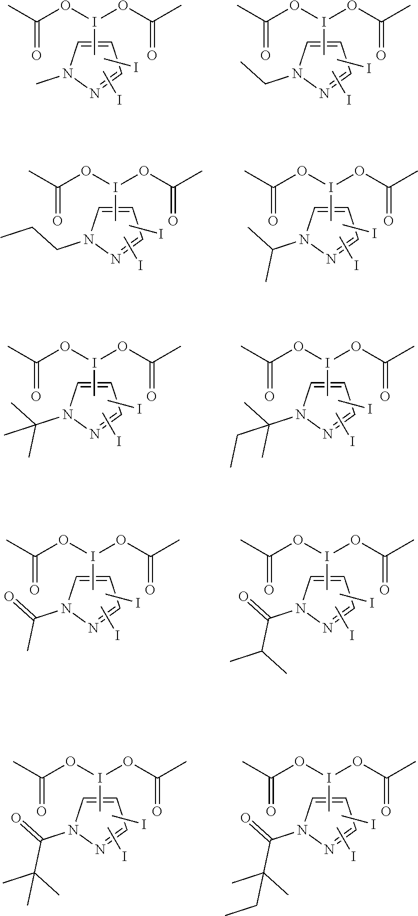

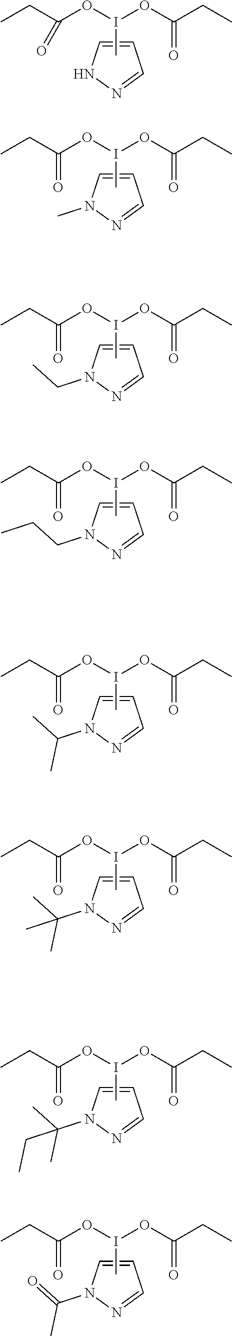

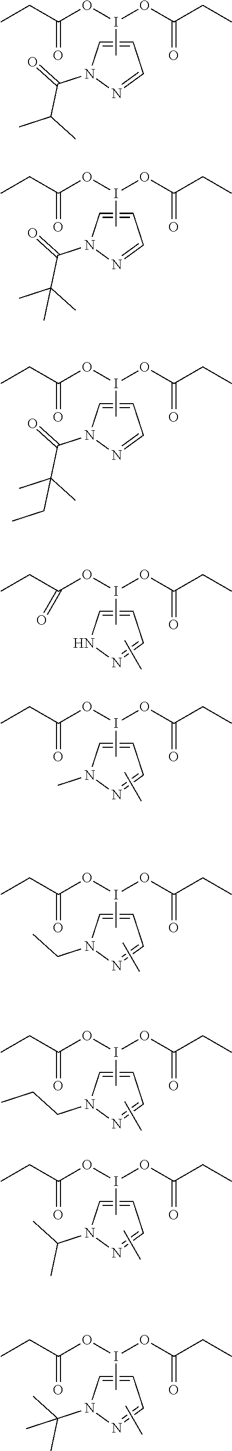

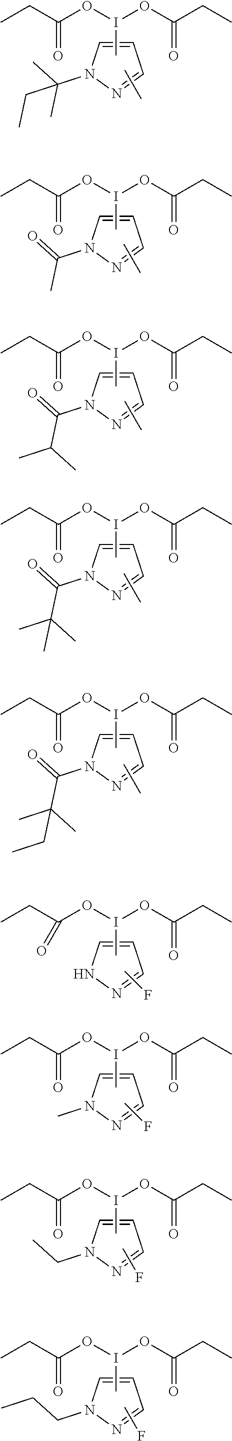

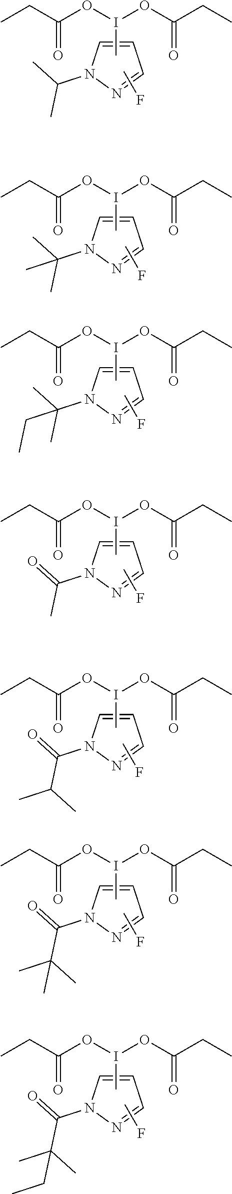

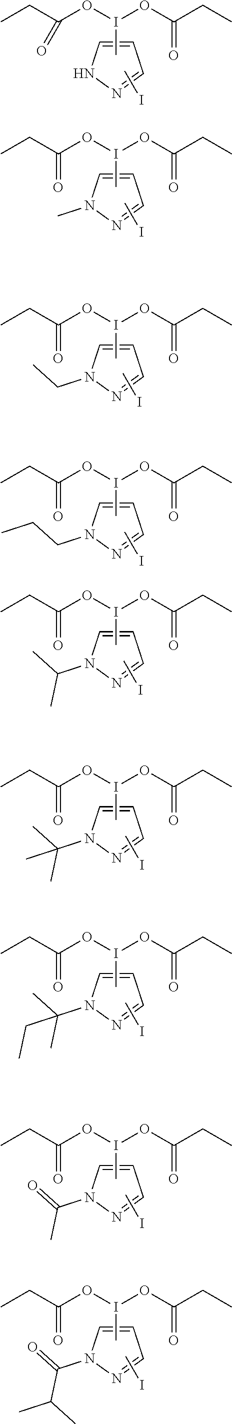

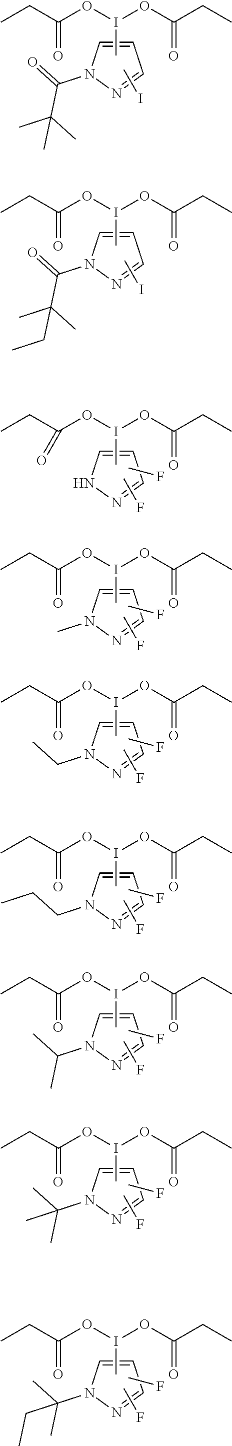

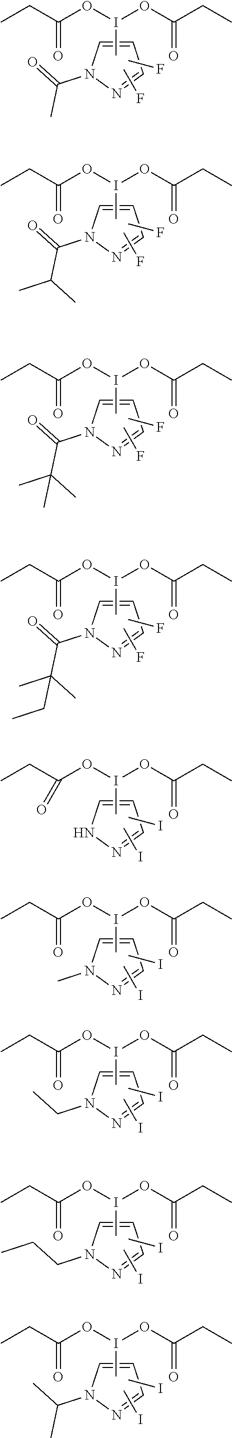

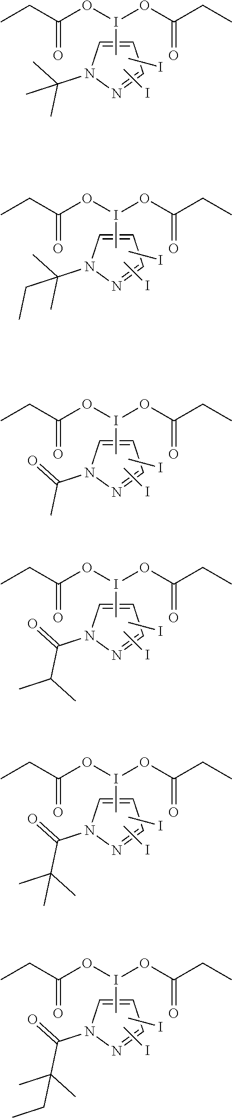

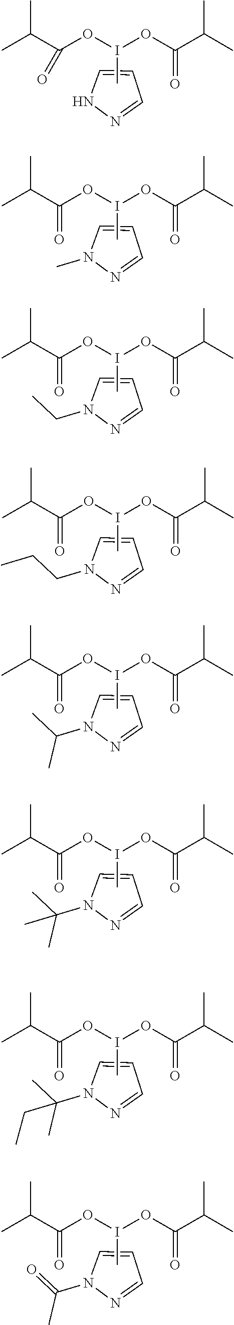

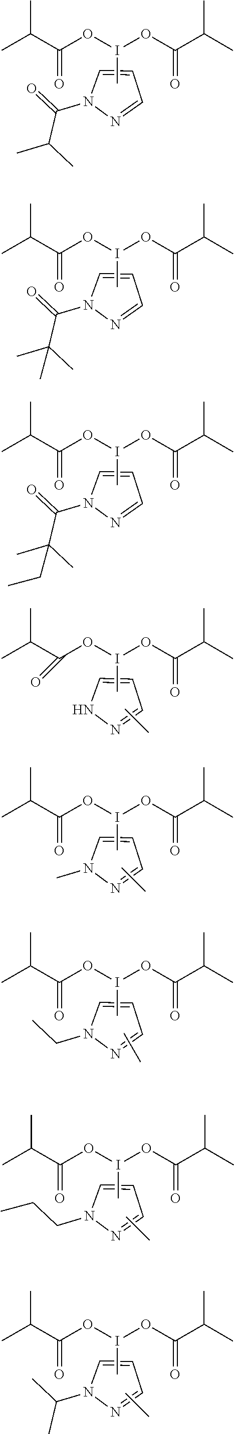

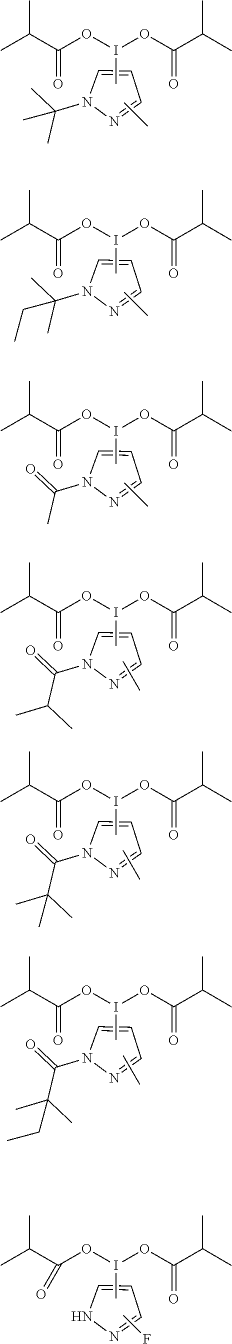

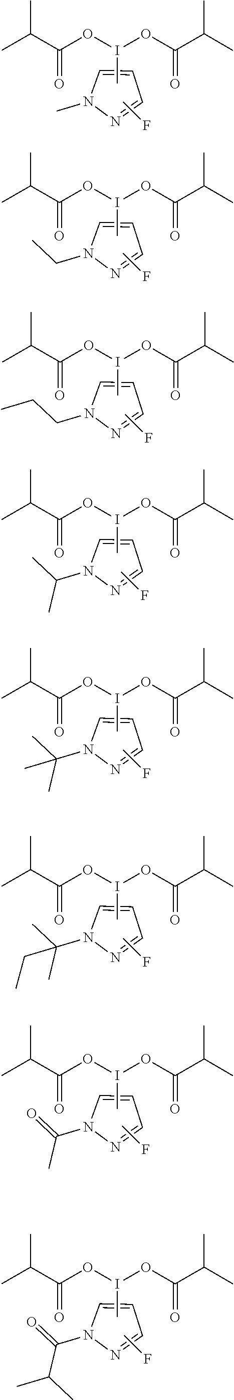

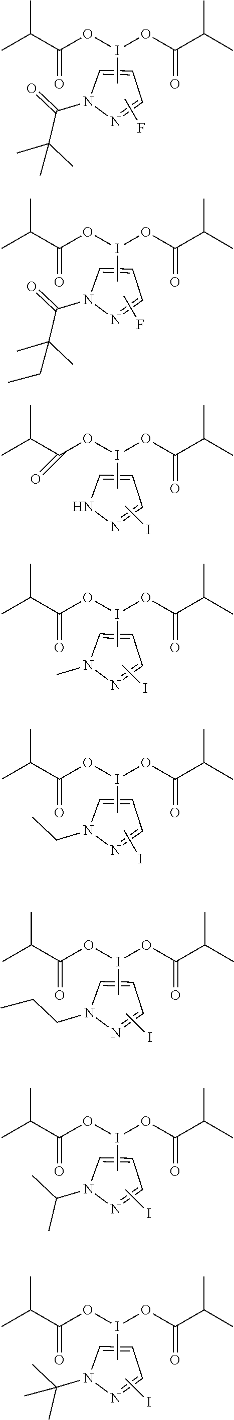

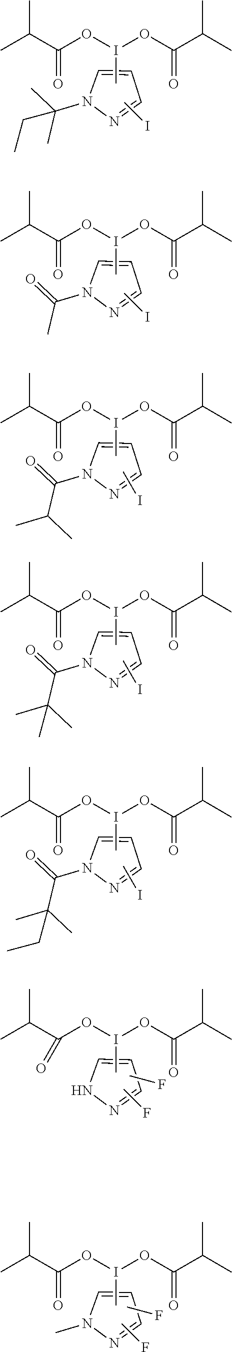

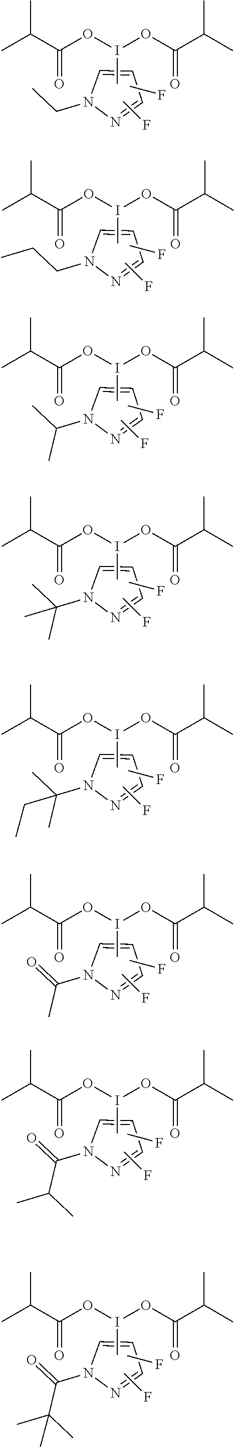

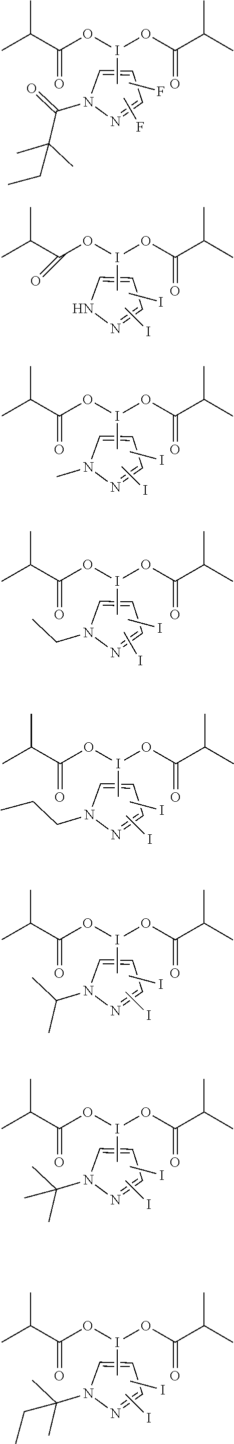

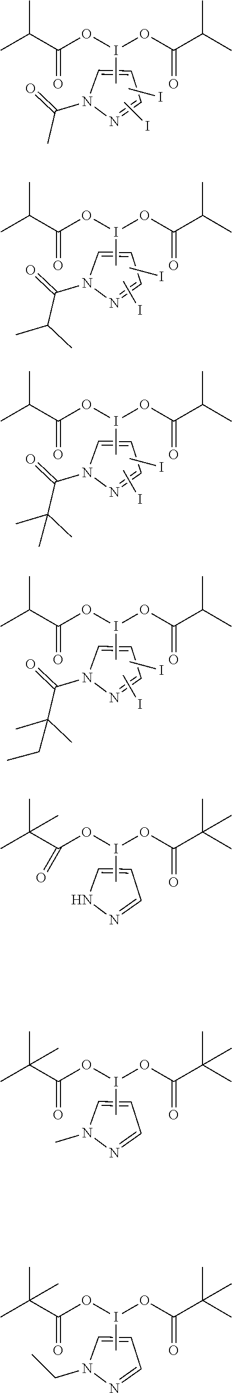

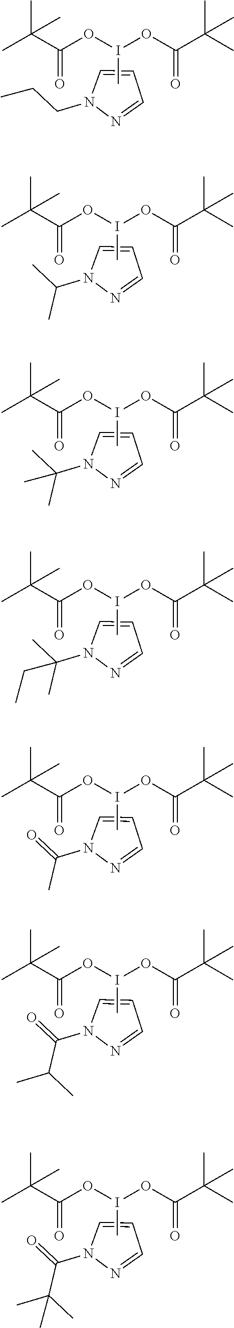

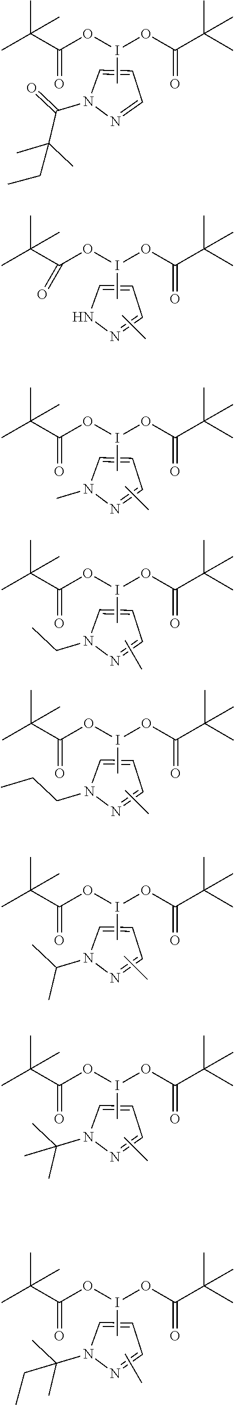

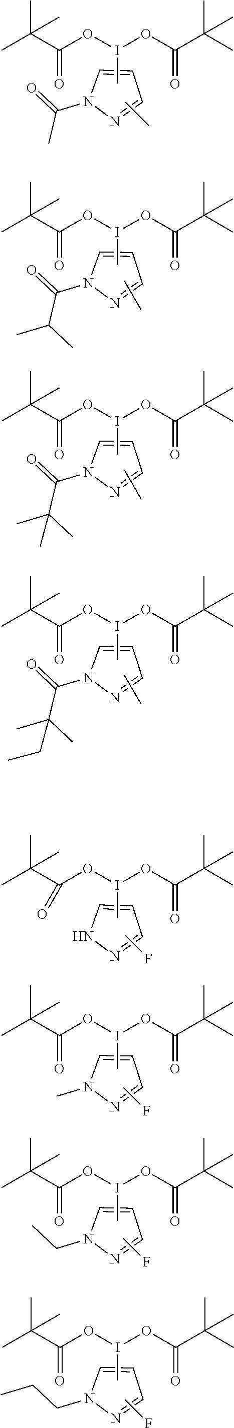

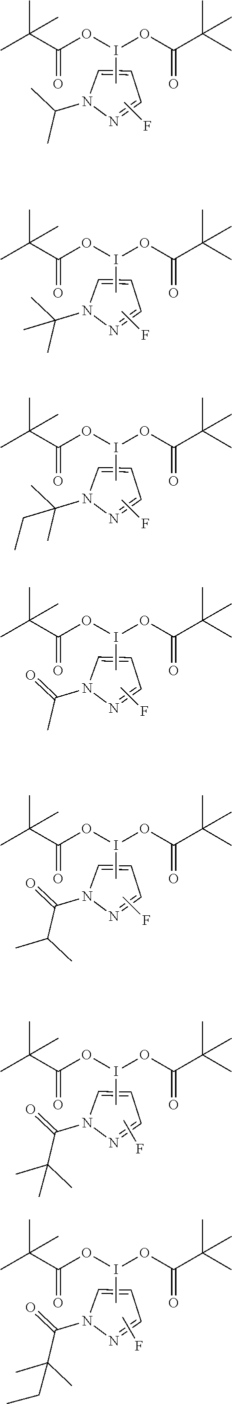

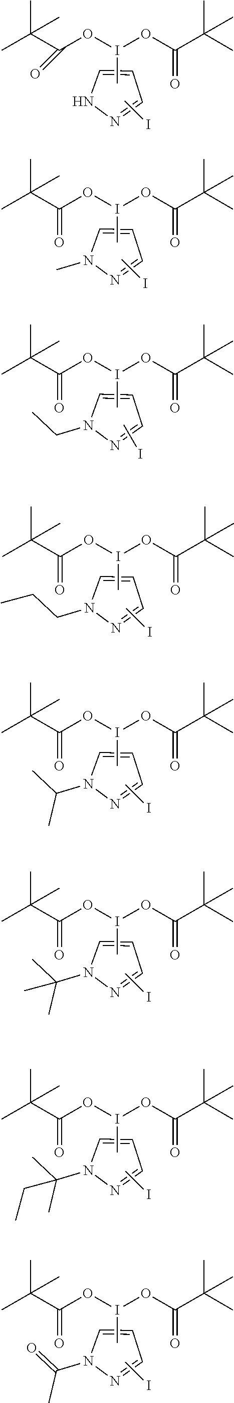

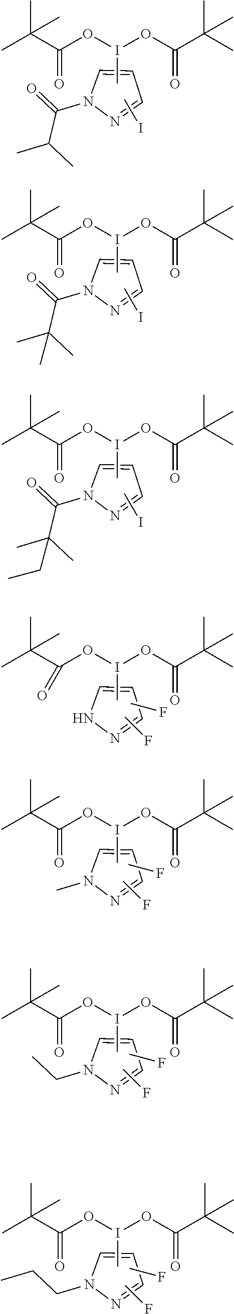

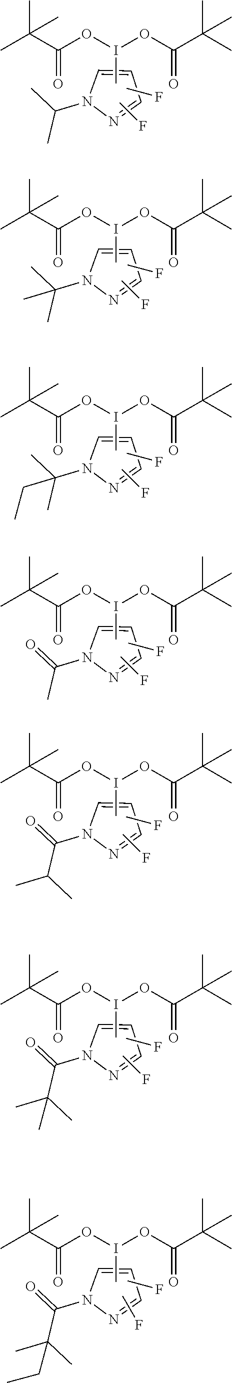

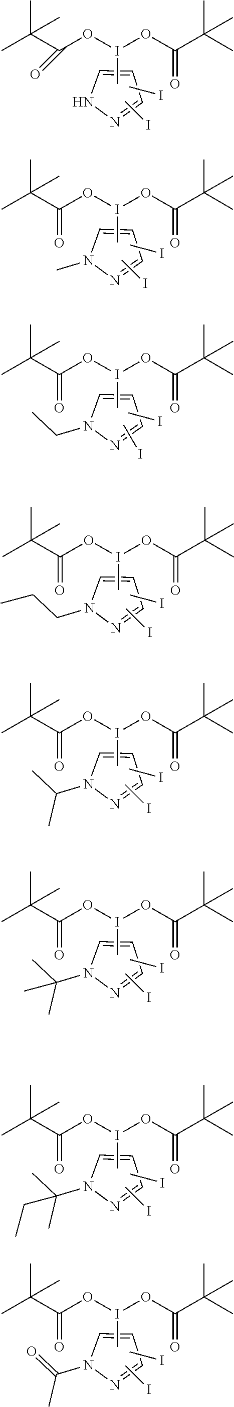

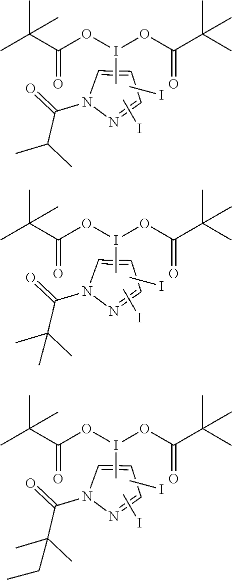

Examples of the hypervalent iodine compound having the formula (13) are shown

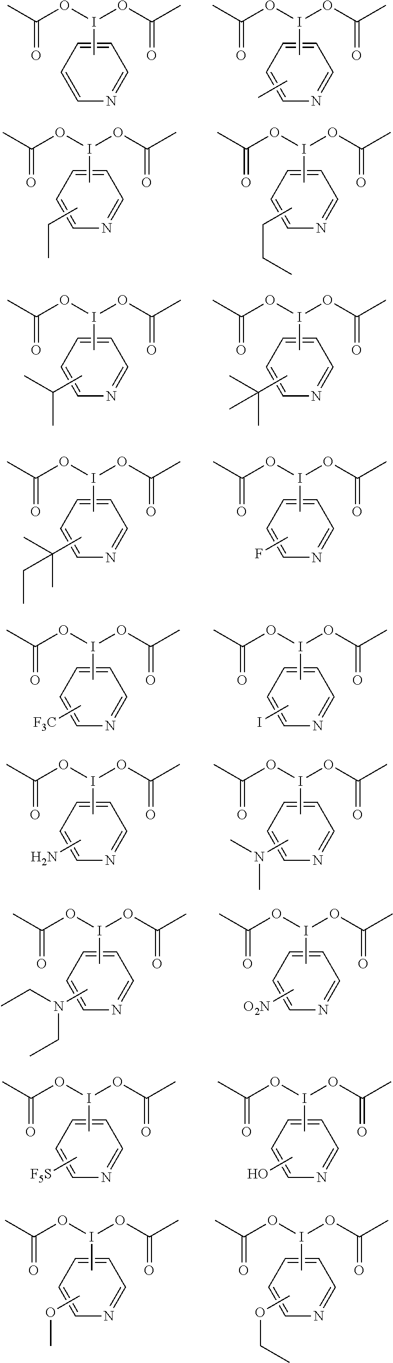

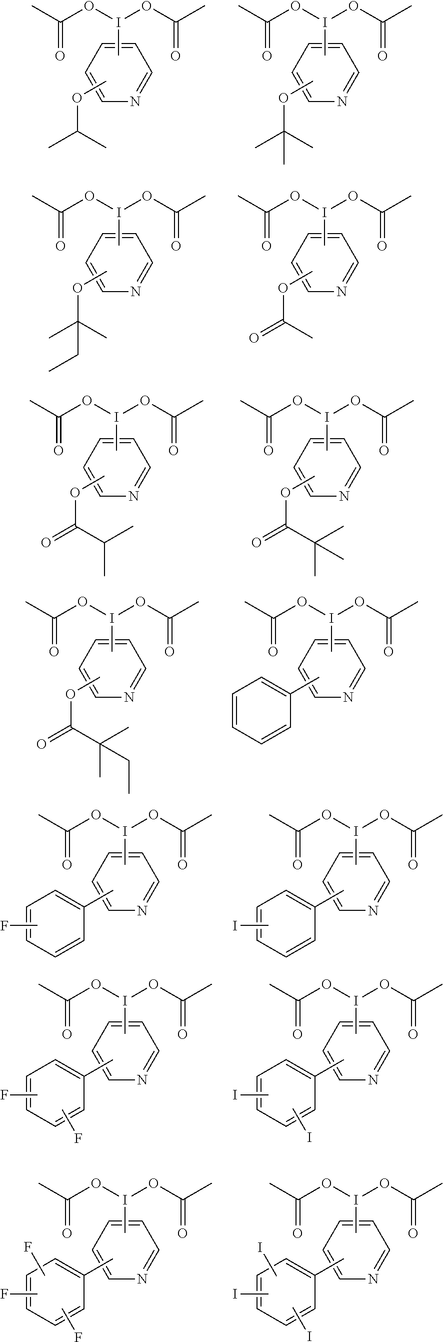

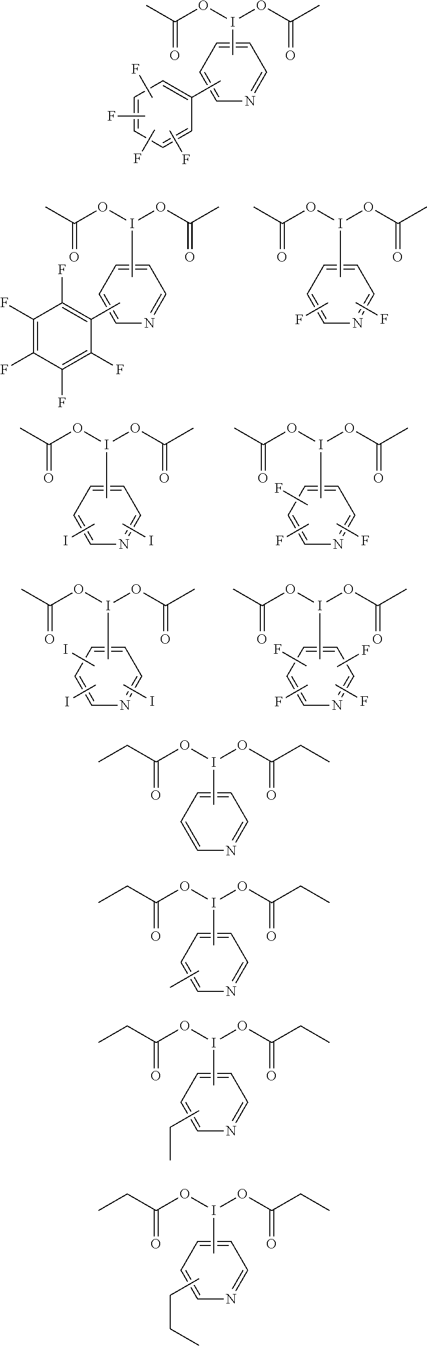

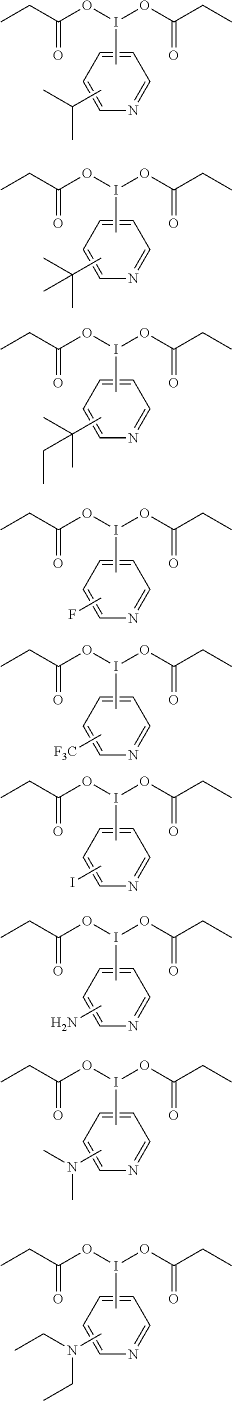

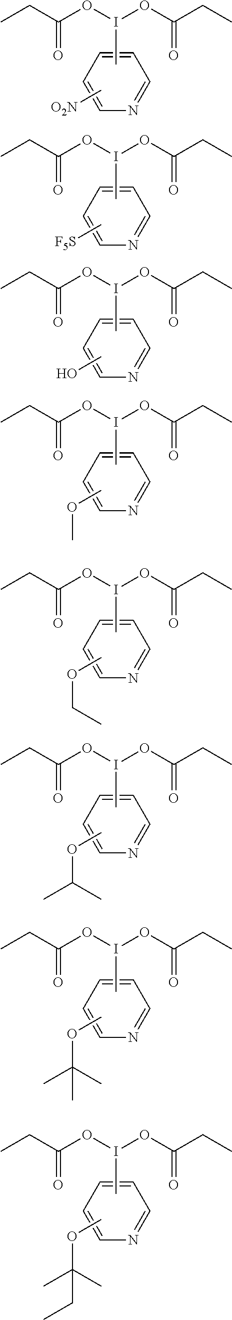

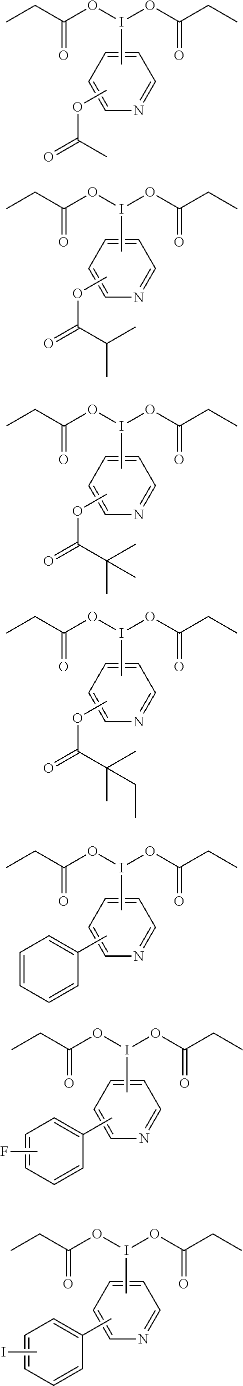

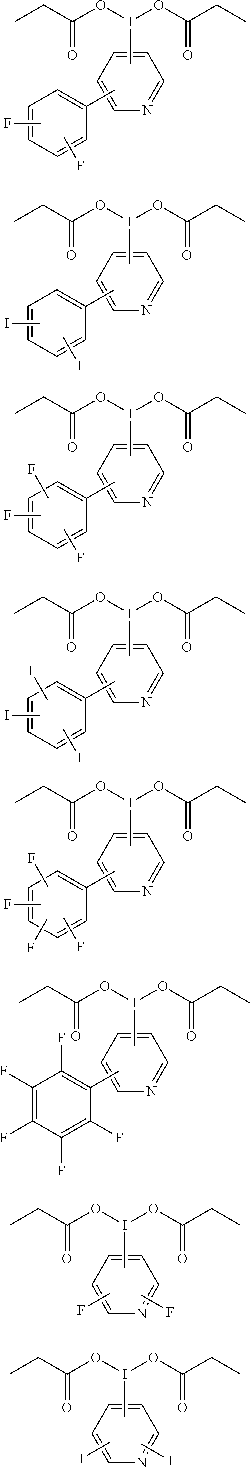

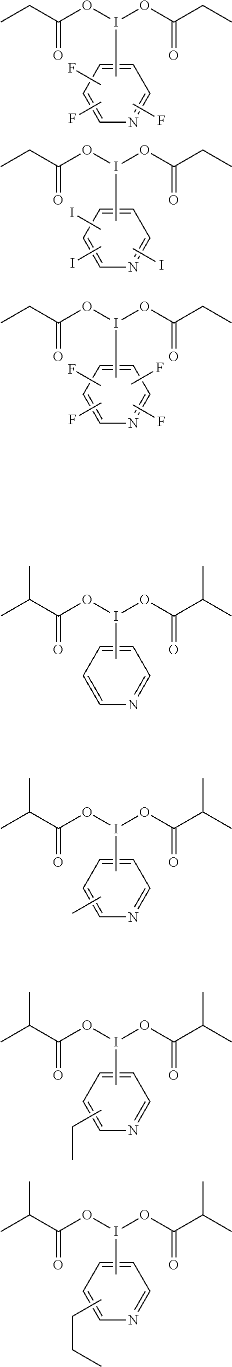

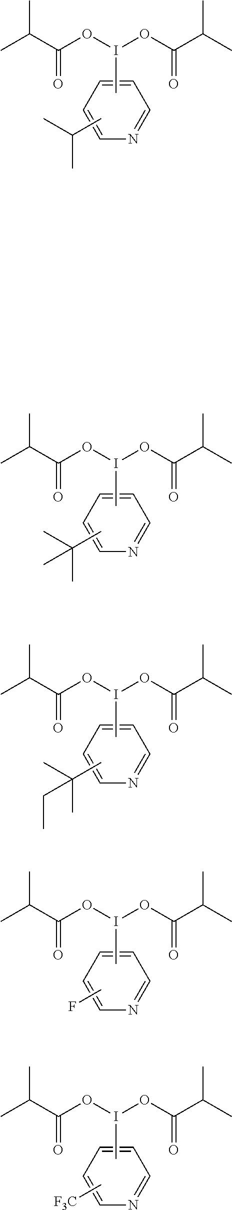

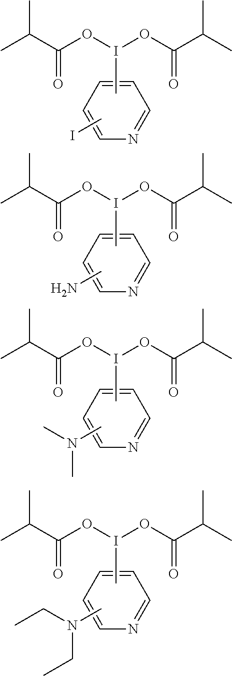

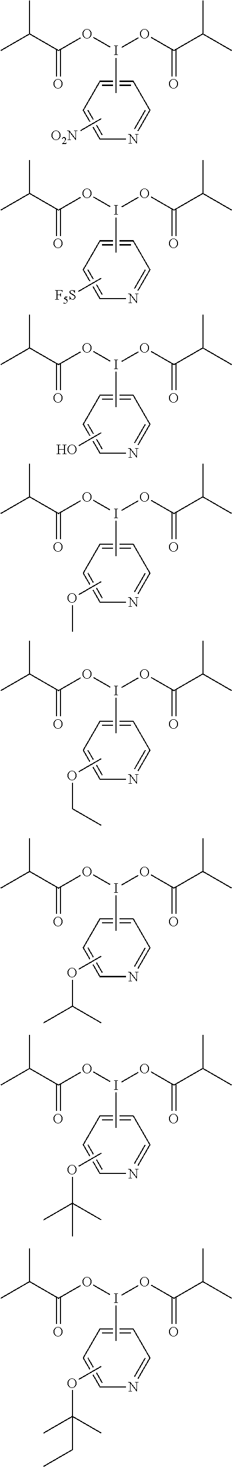

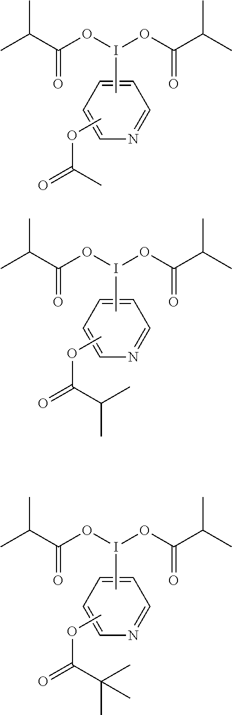

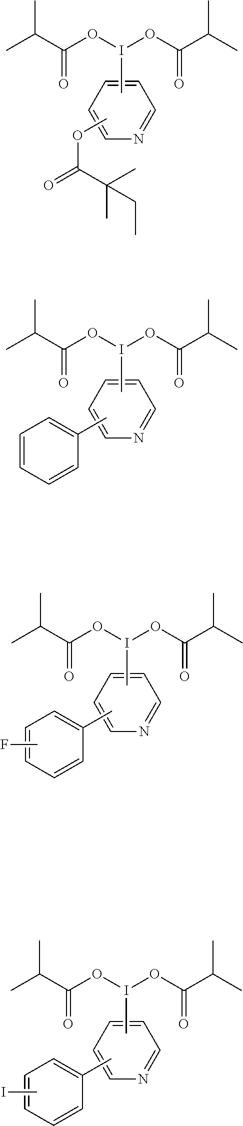

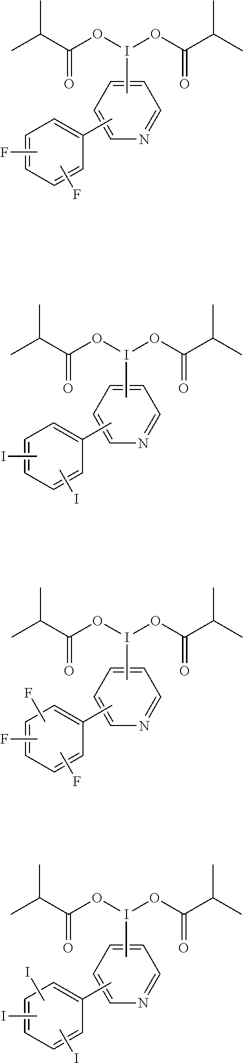

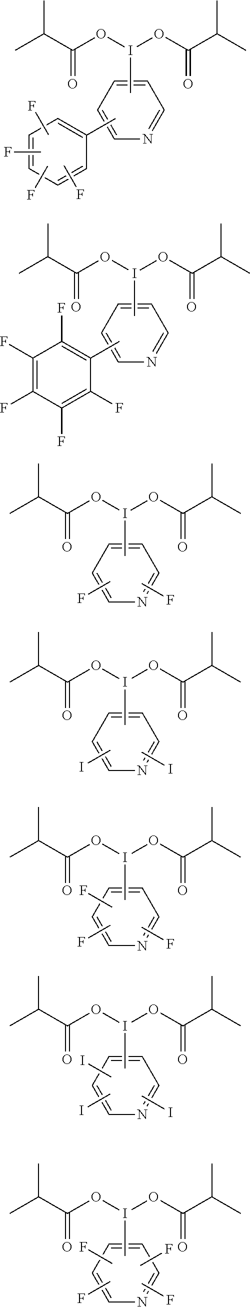

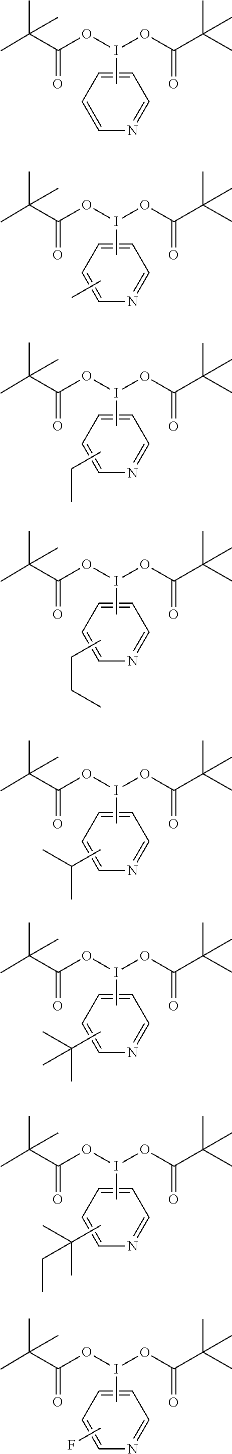

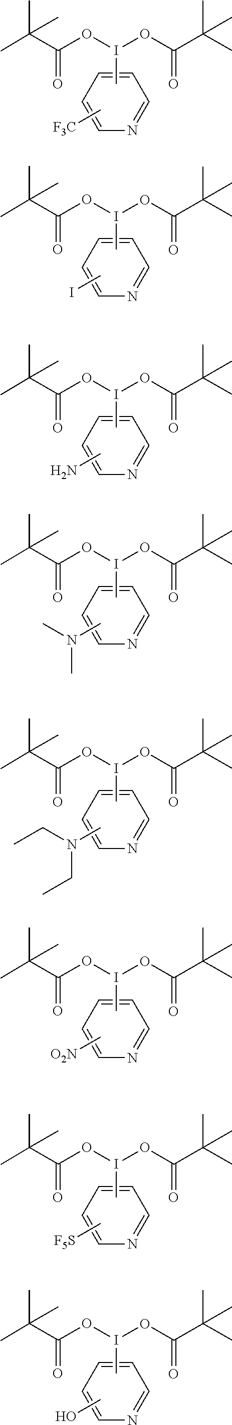

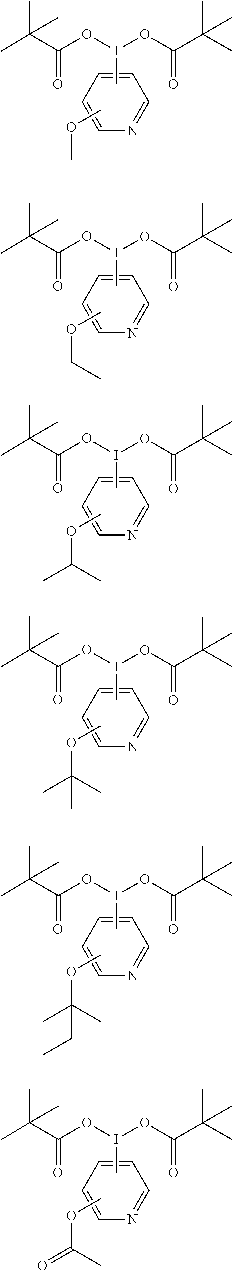

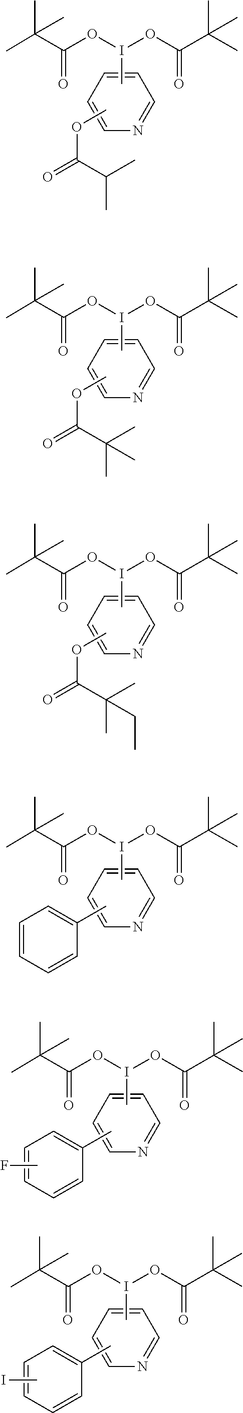

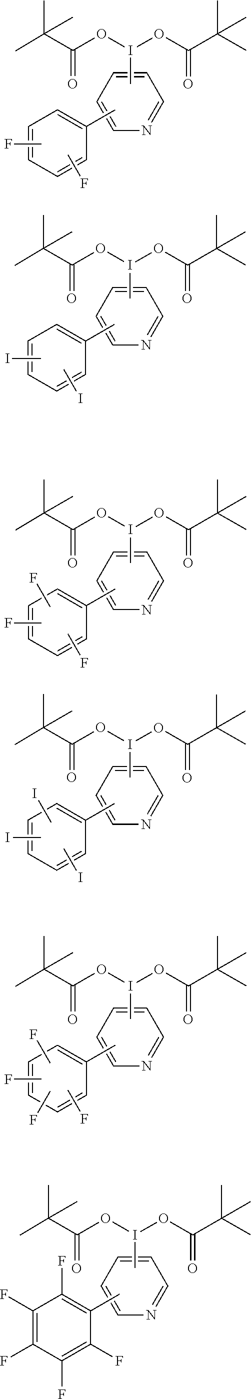

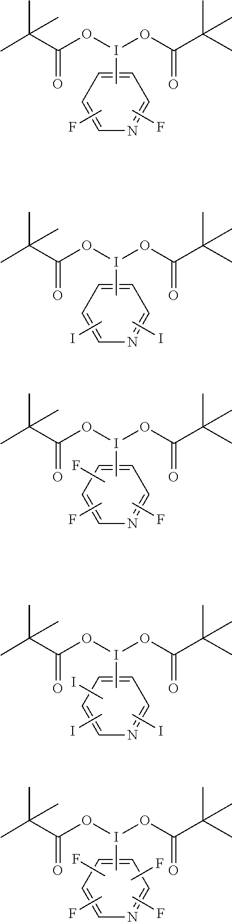

Examples of the hypervalent iodine compound having the formula (14) are shown below, but are not limited thereto. In the formulae, Me is a methyl group, and *3 and *4 are the same as described above.

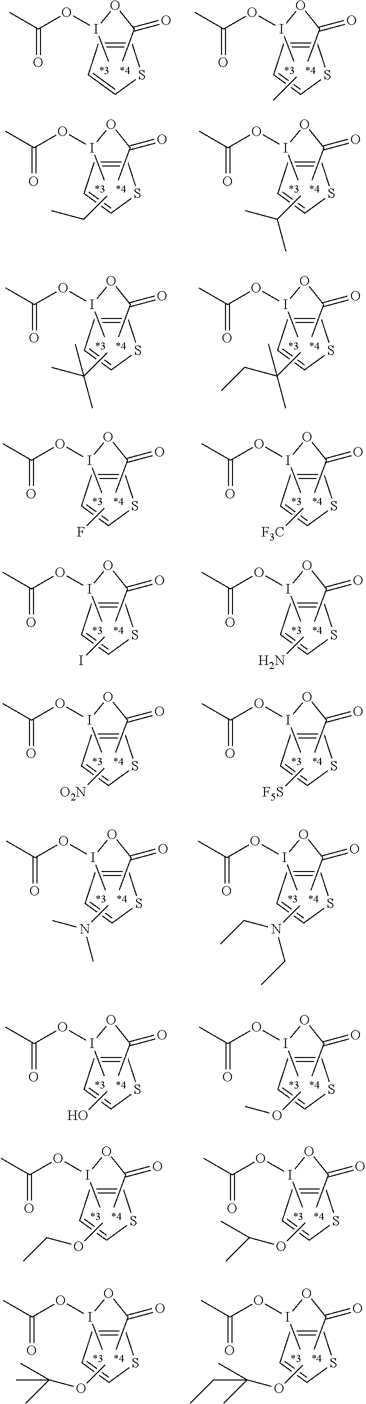

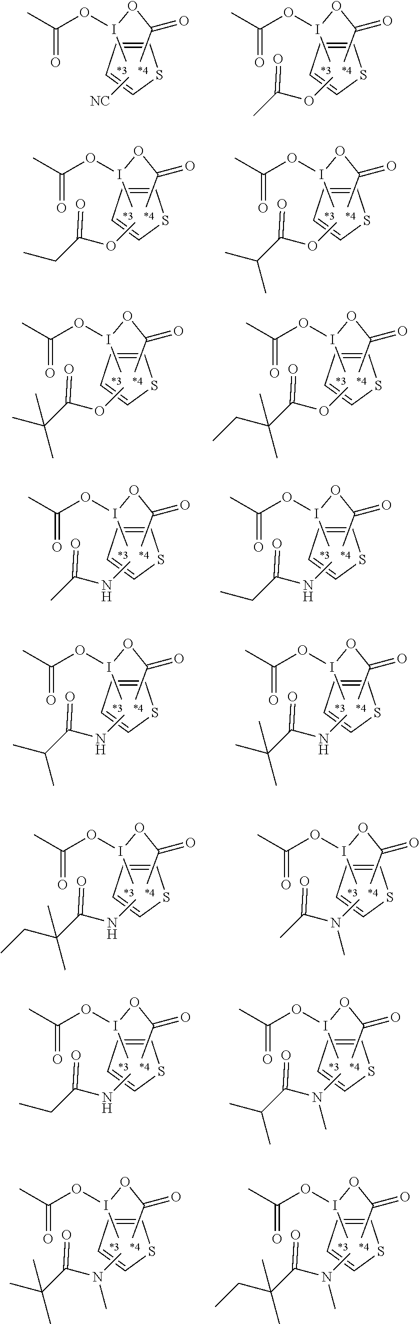

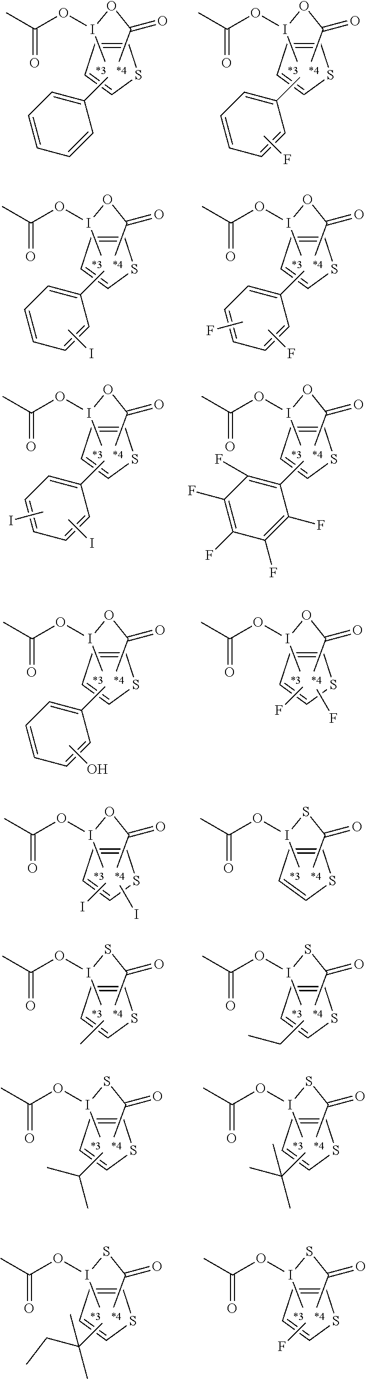

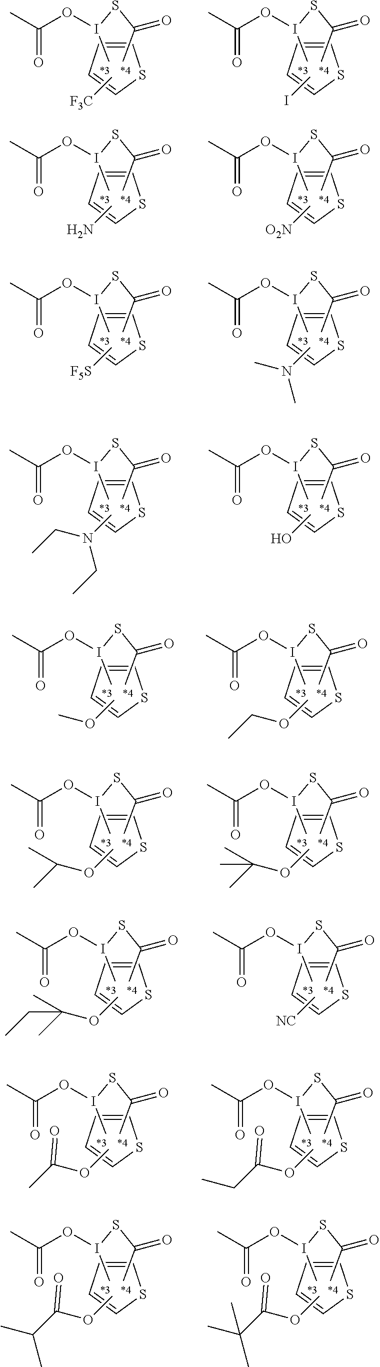

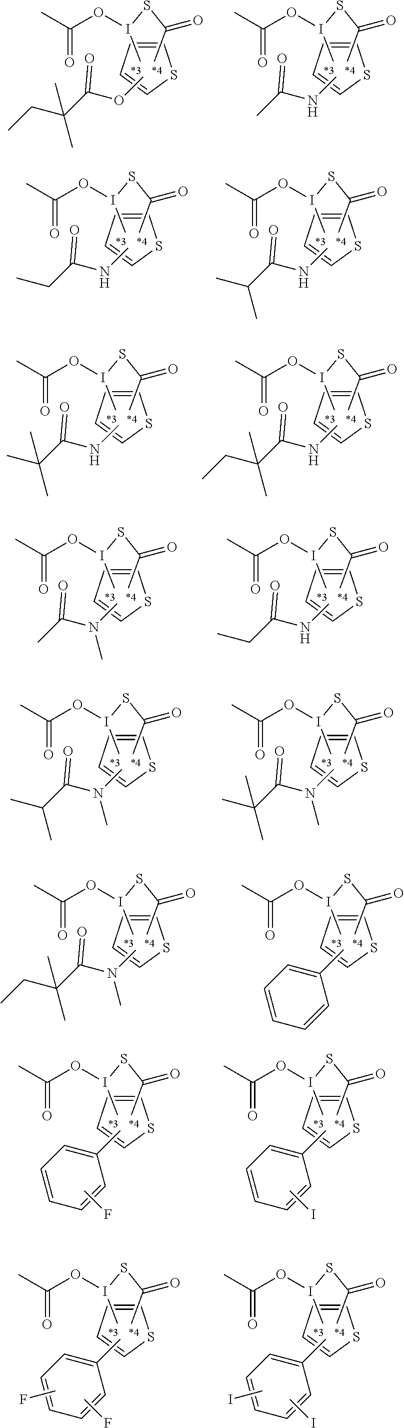

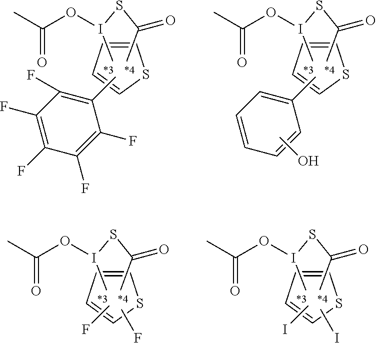

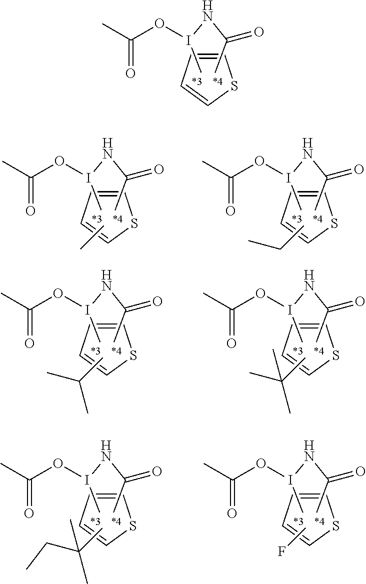

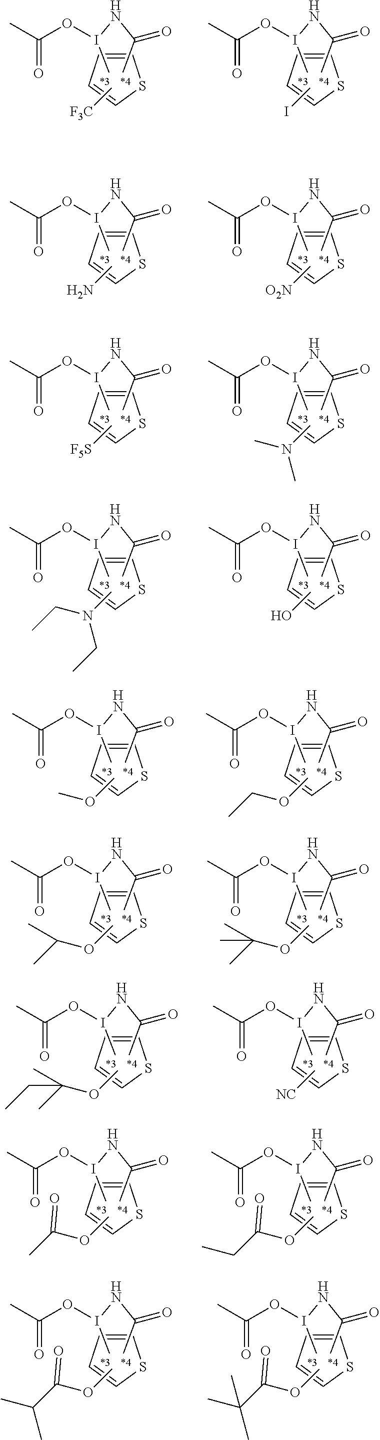

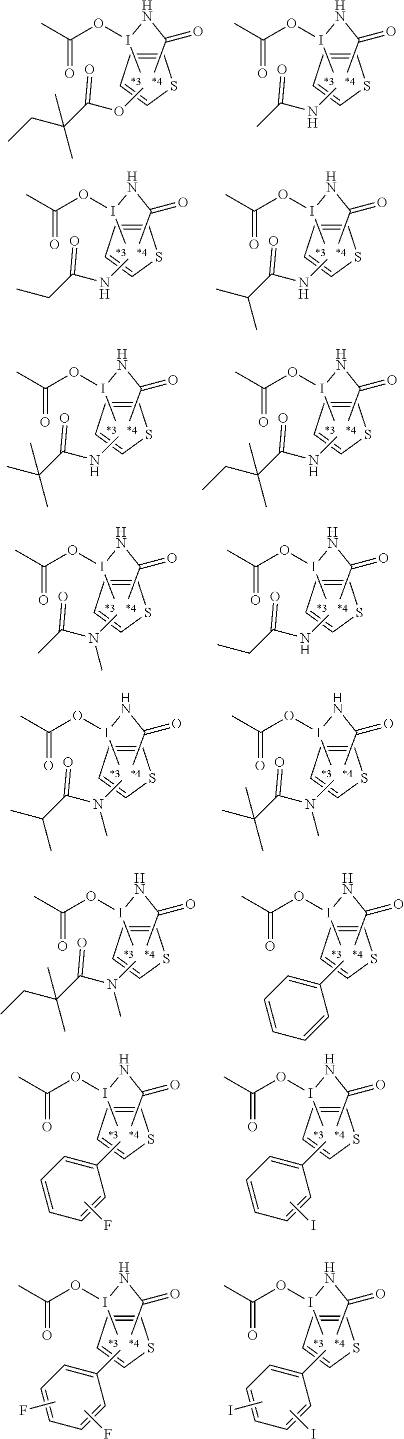

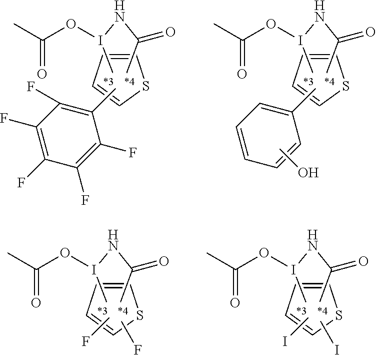

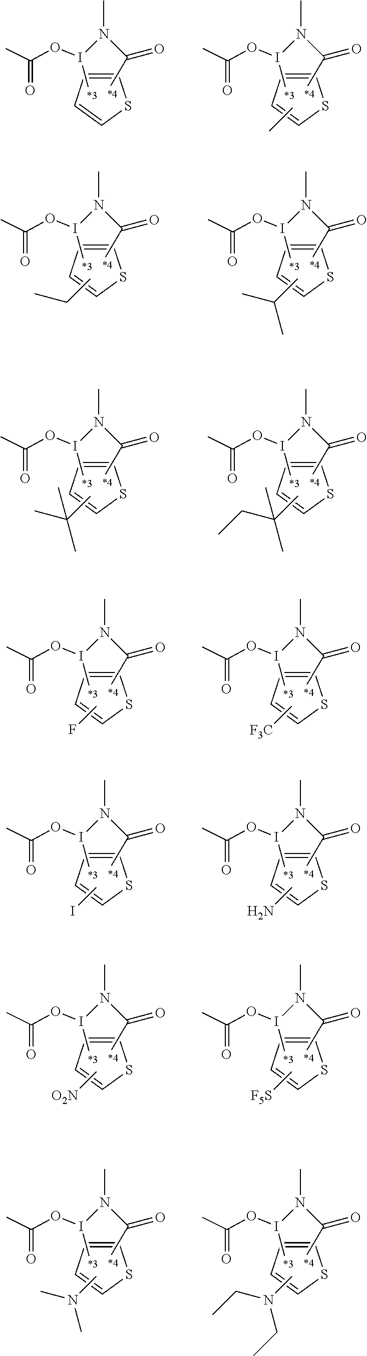

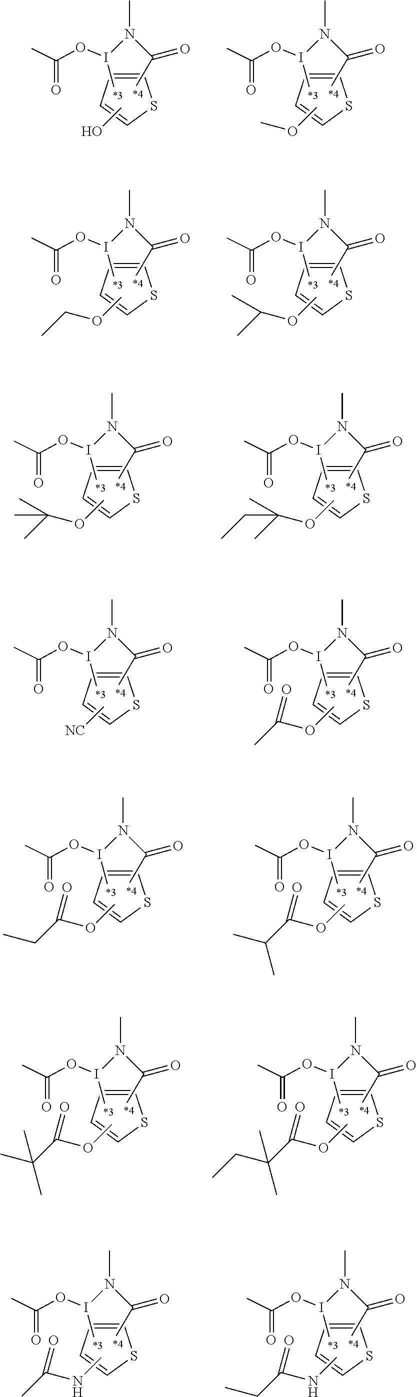

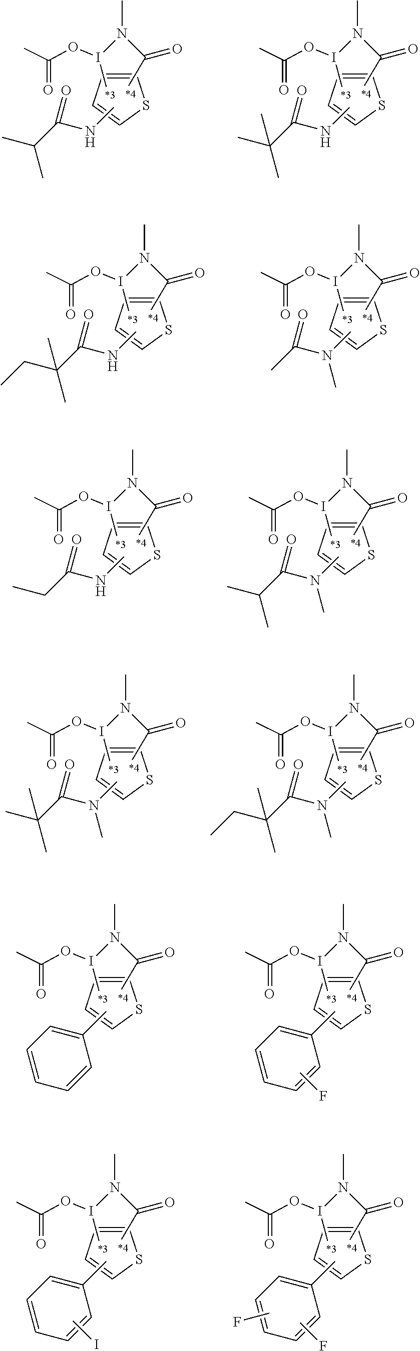

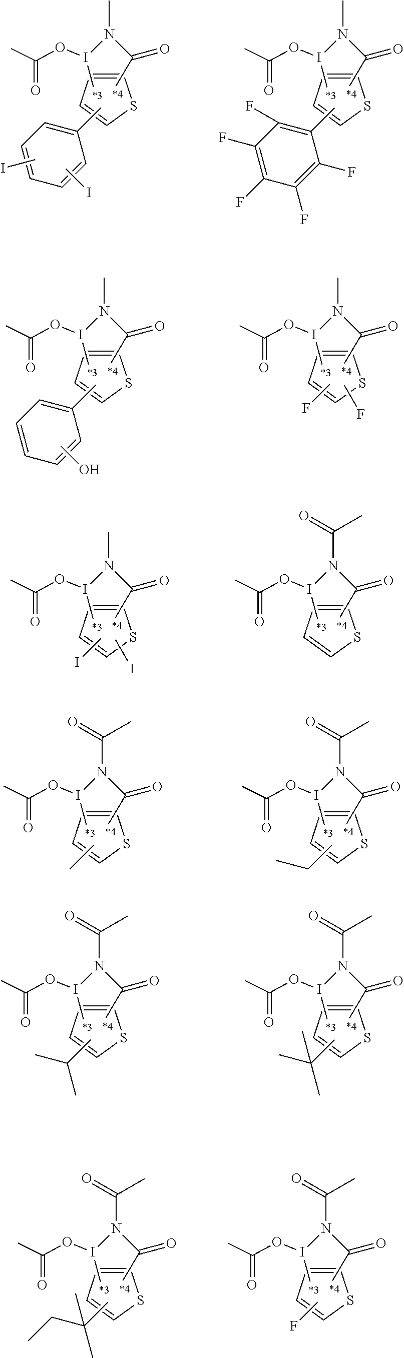

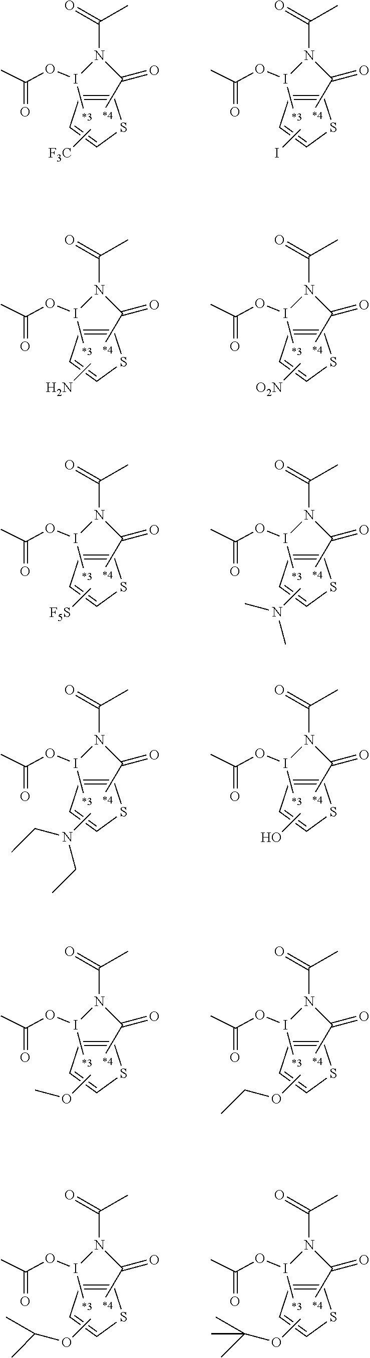

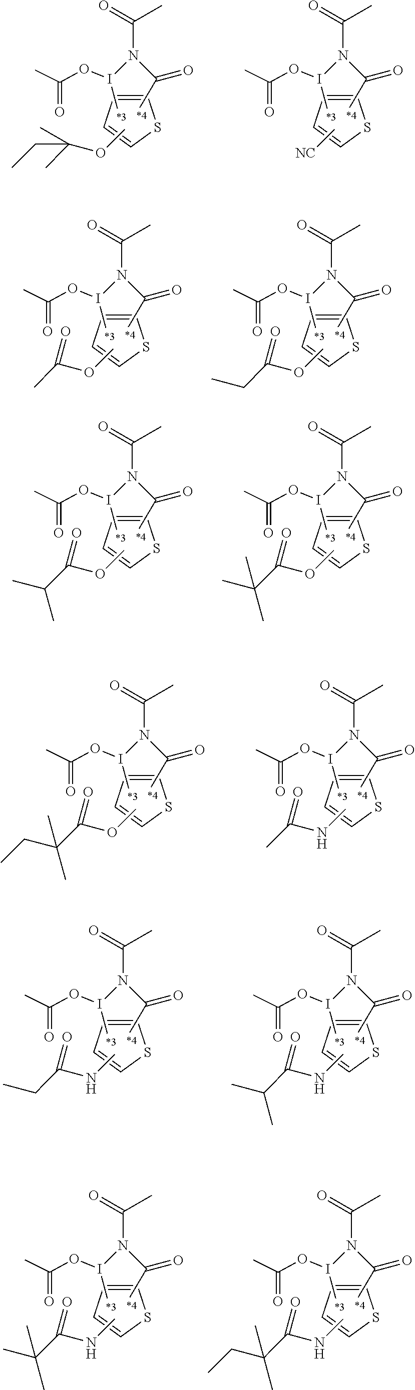

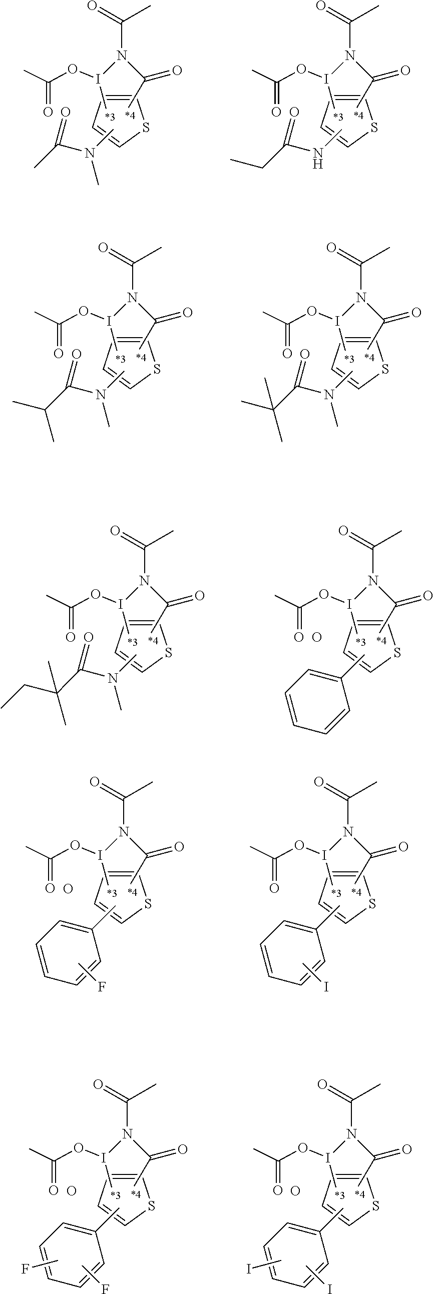

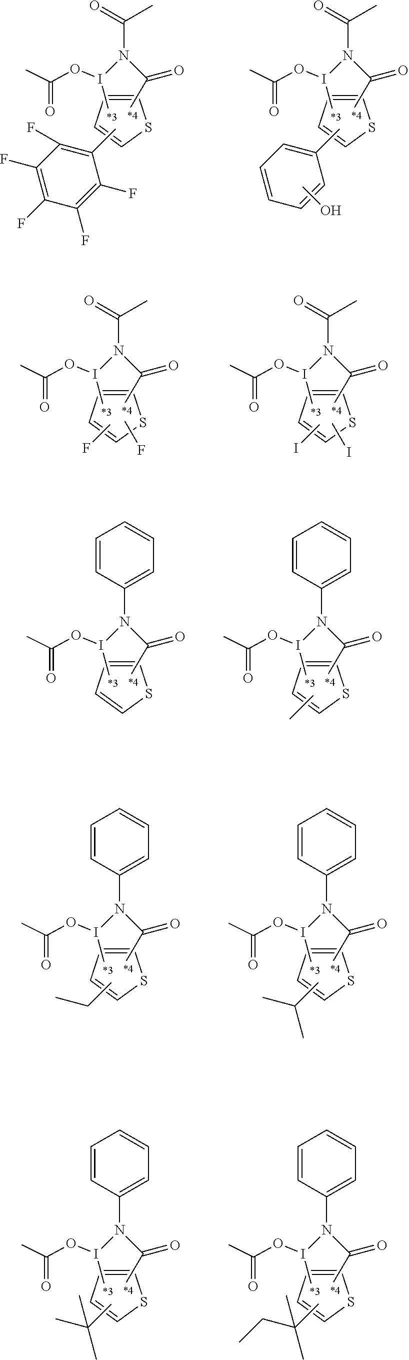

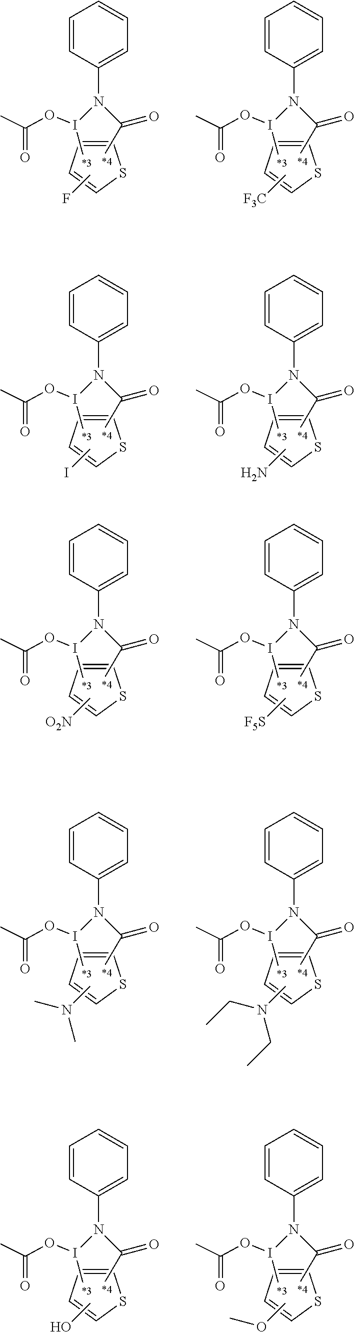

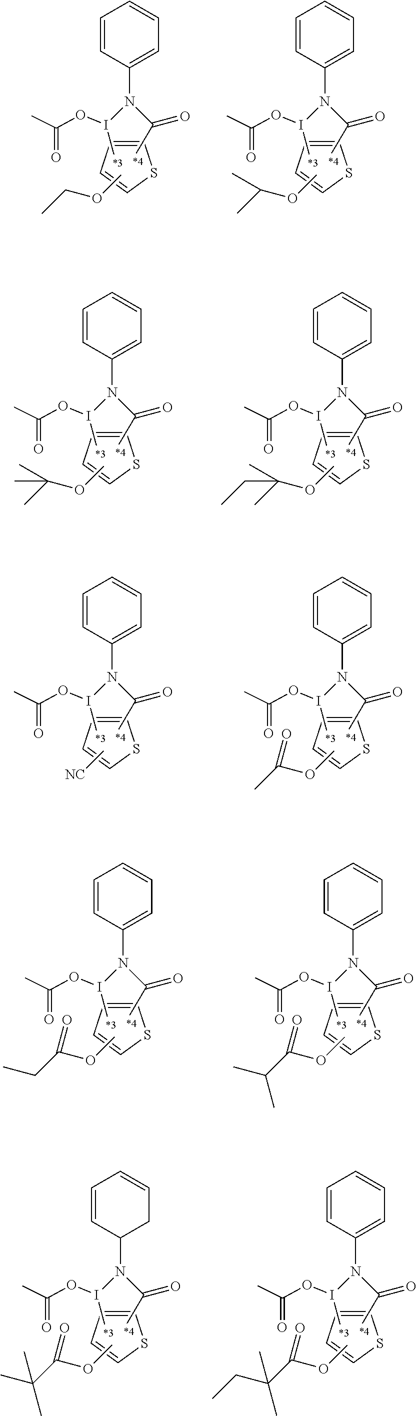

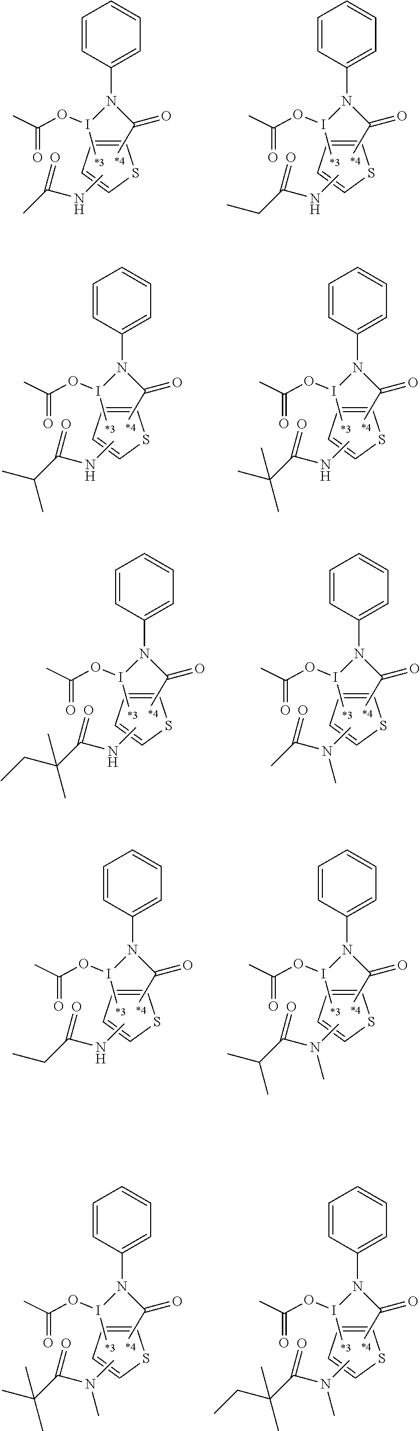

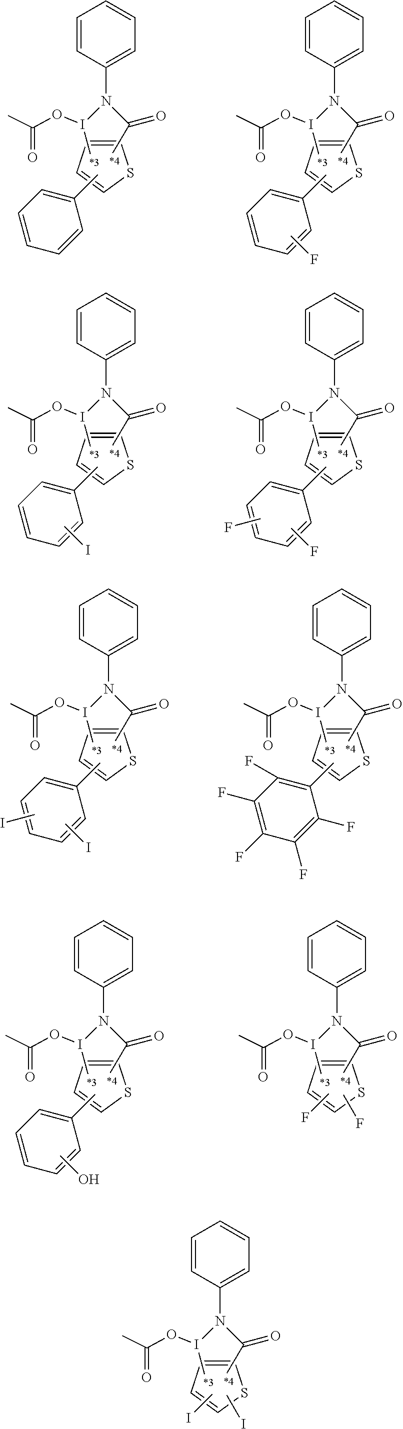

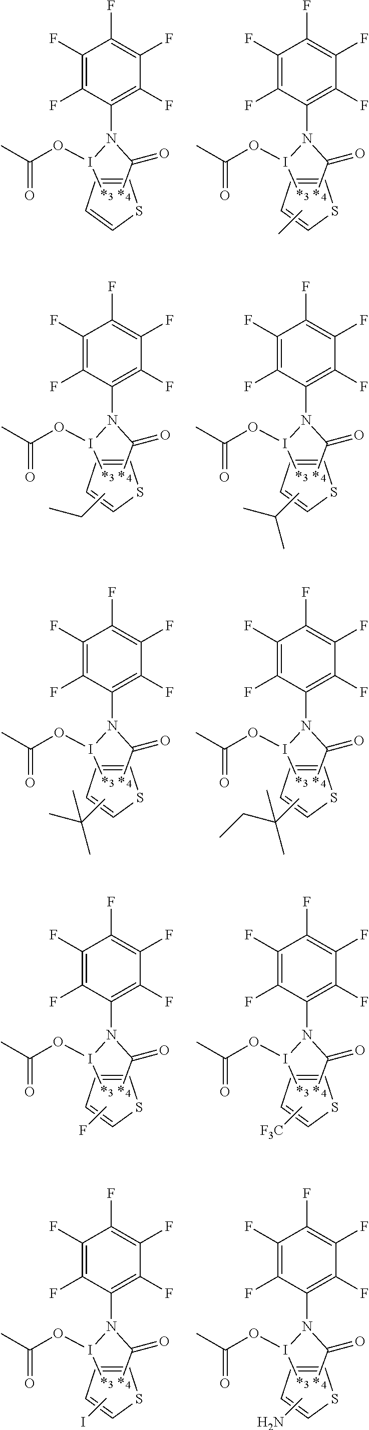

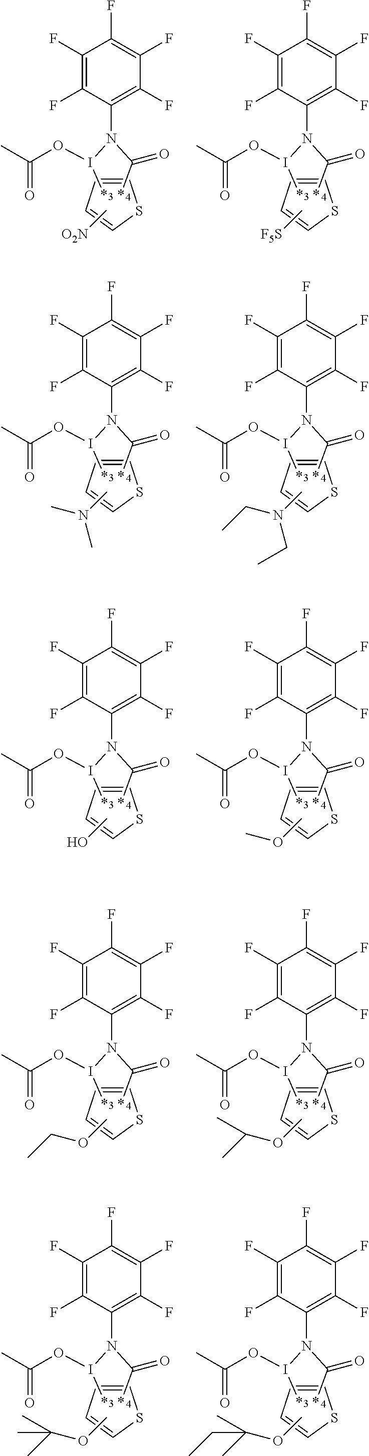

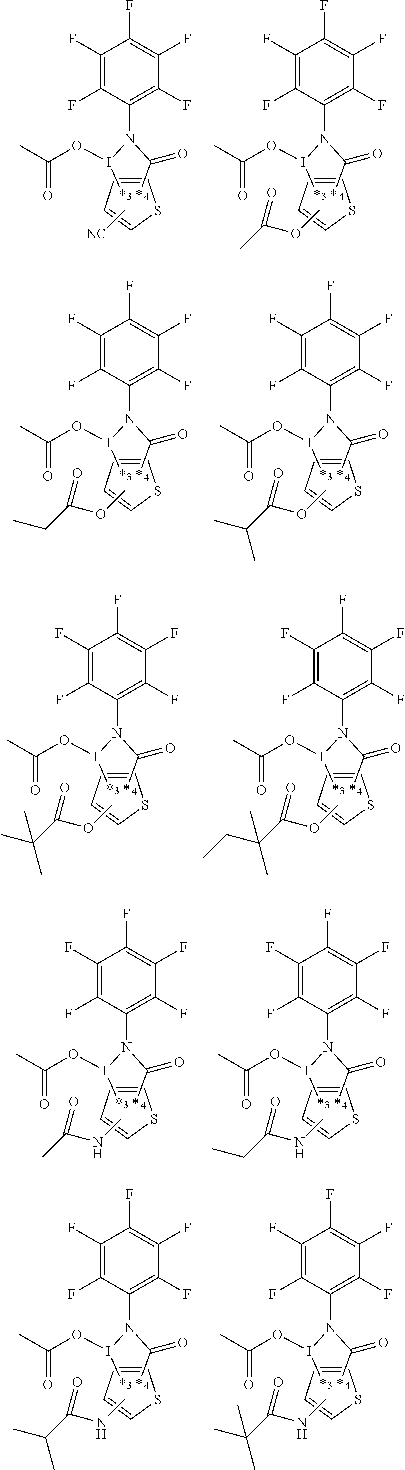

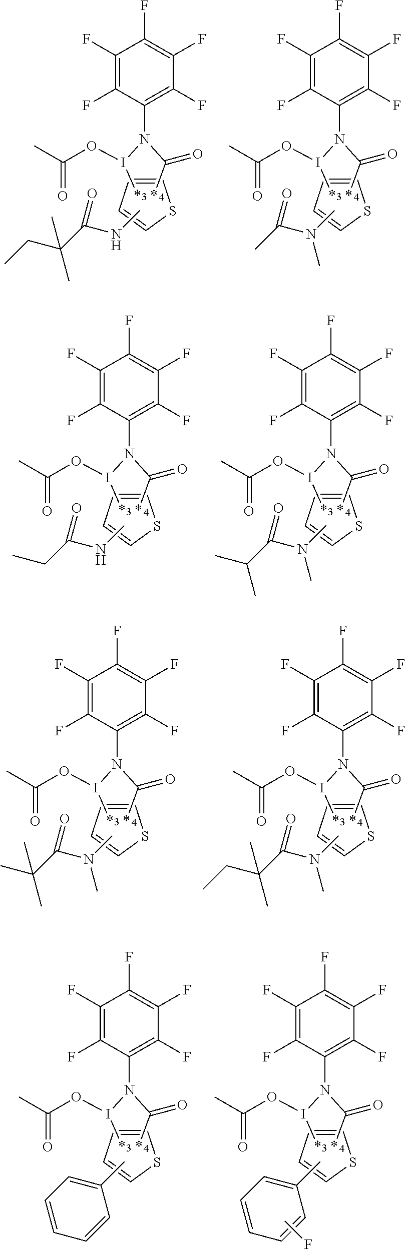

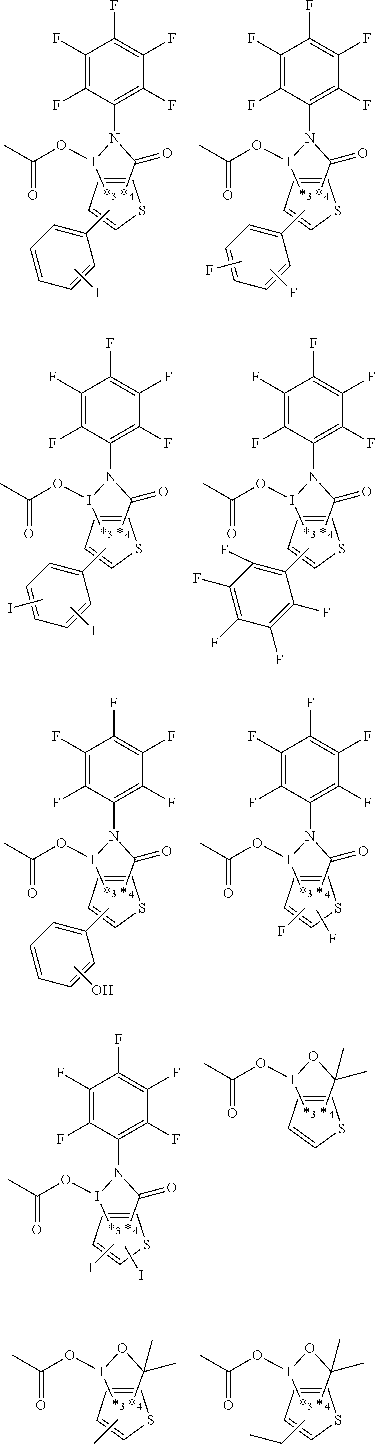

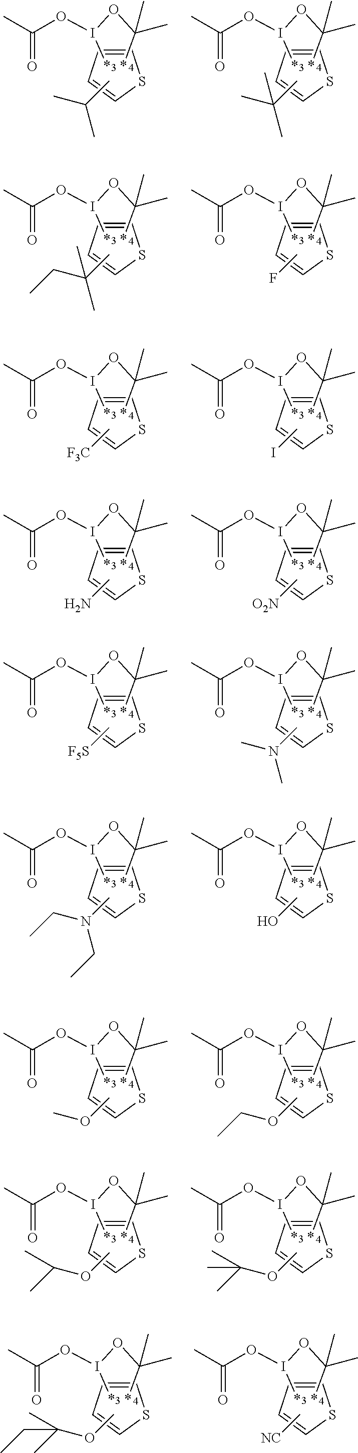

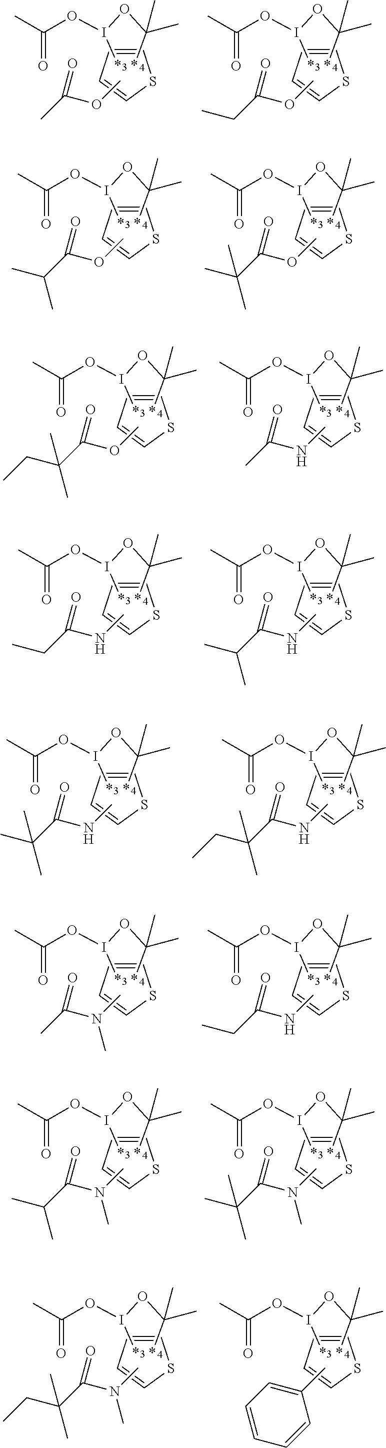

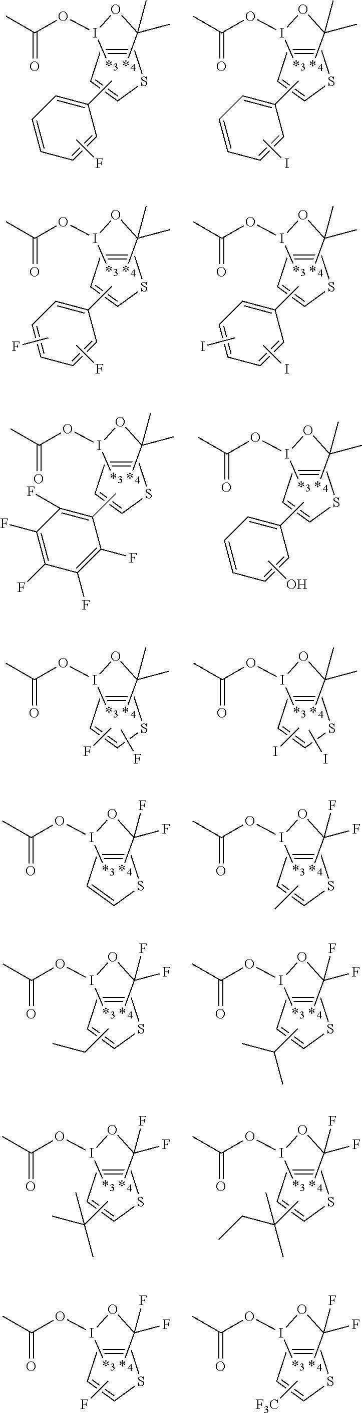

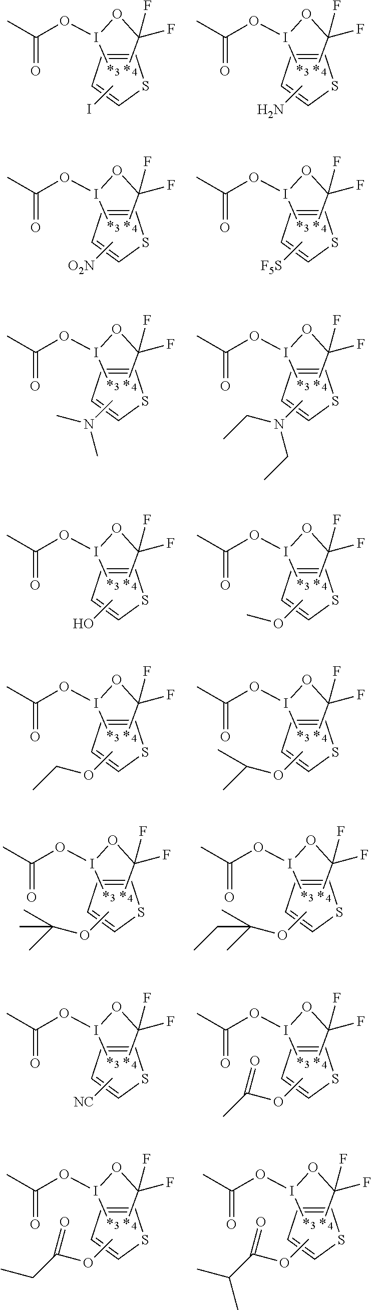

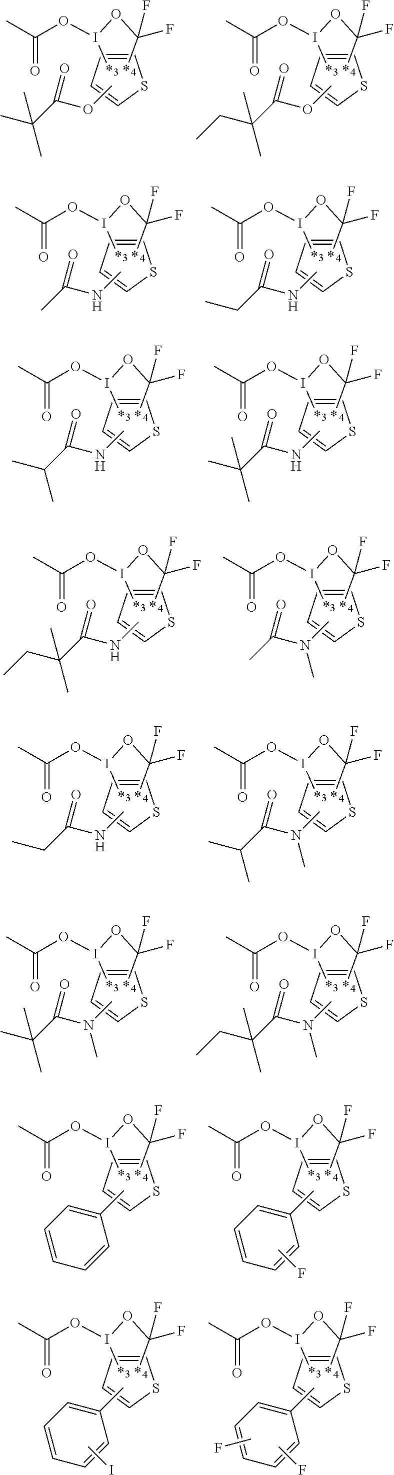

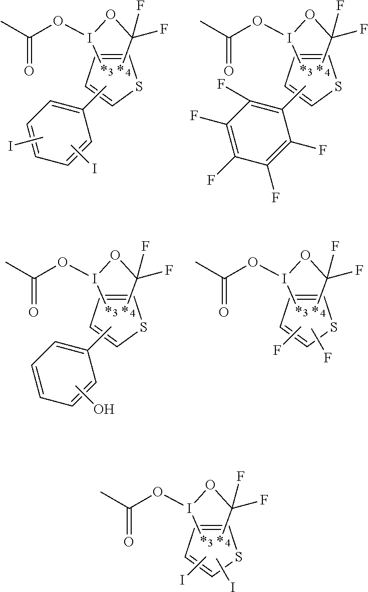

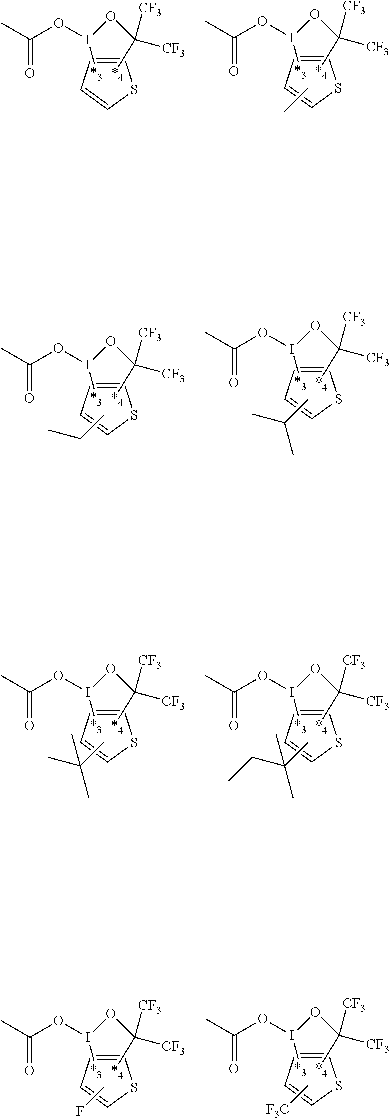

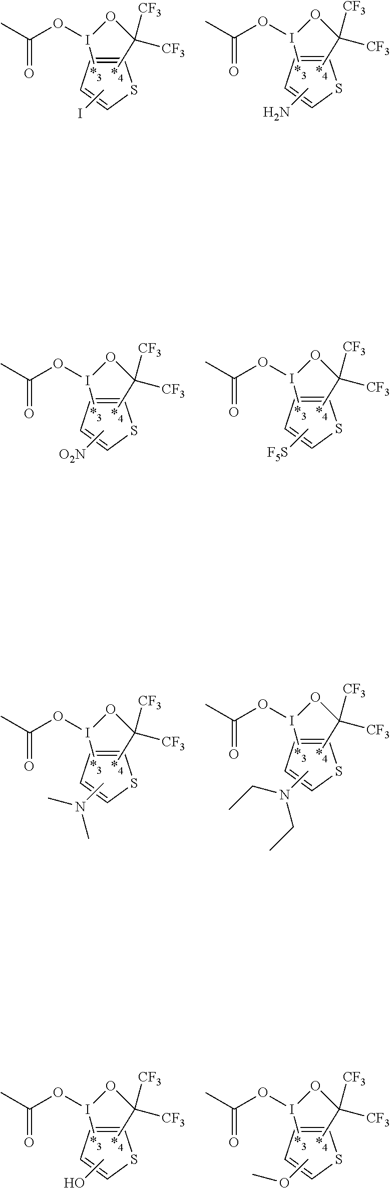

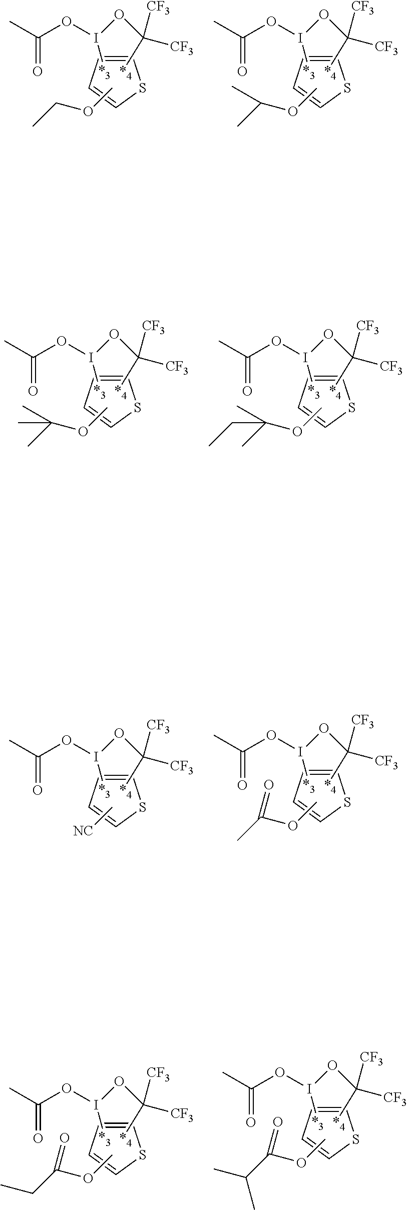

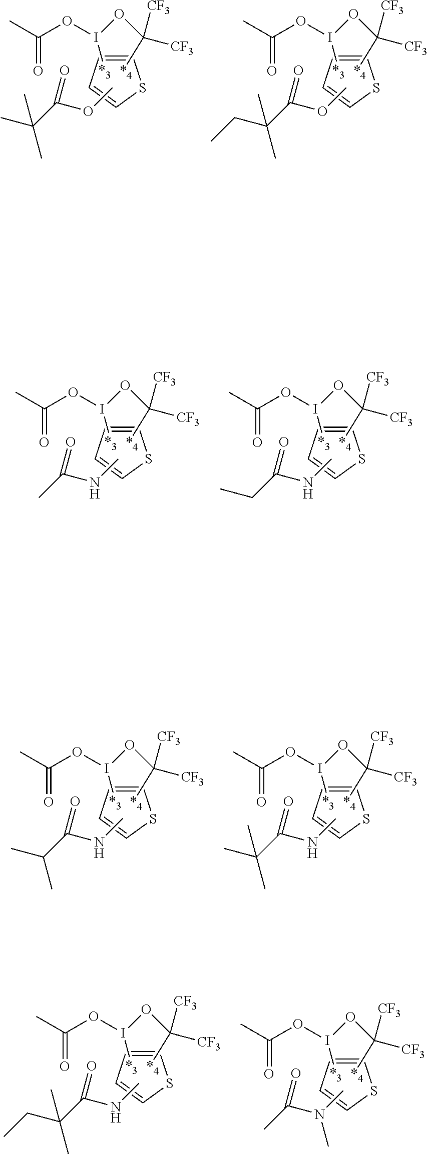

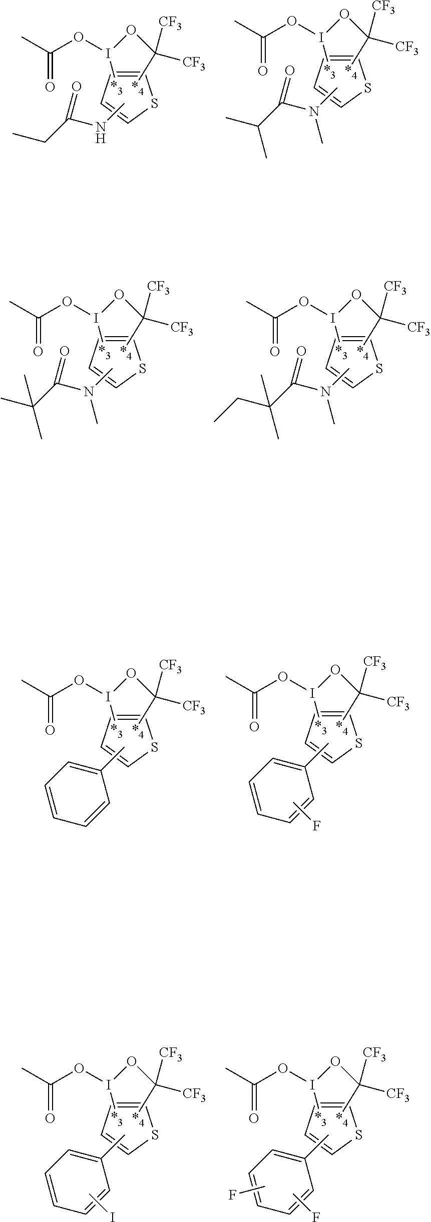

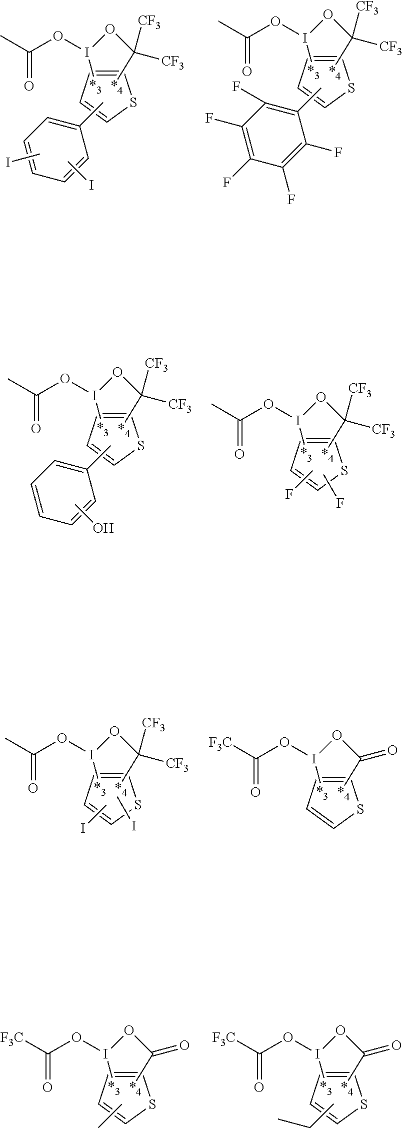

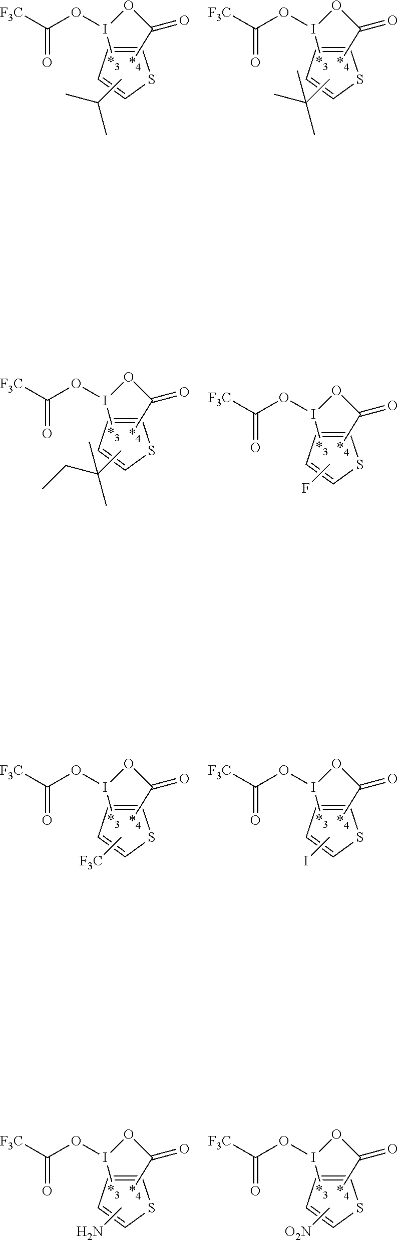

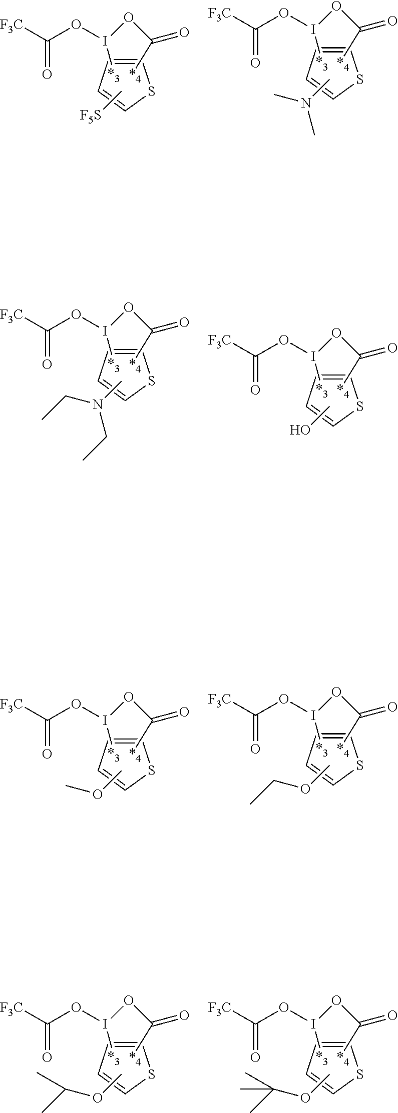

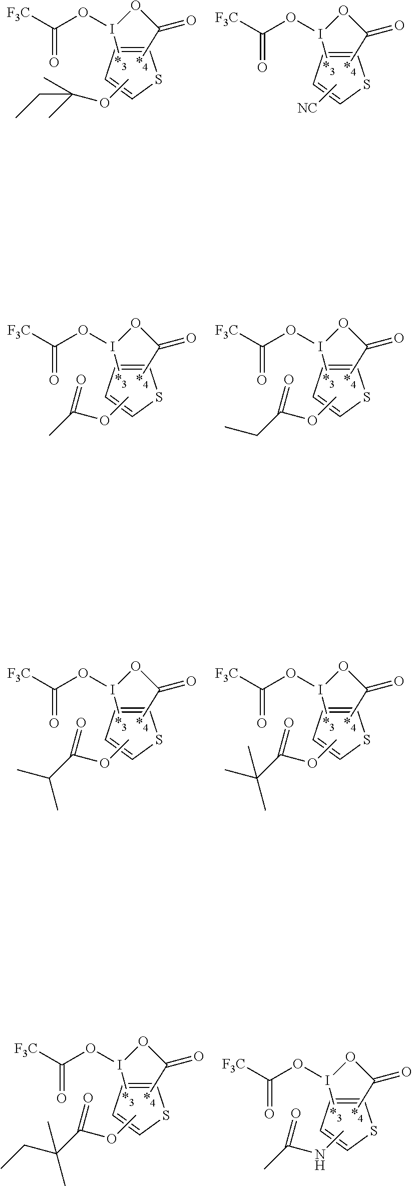

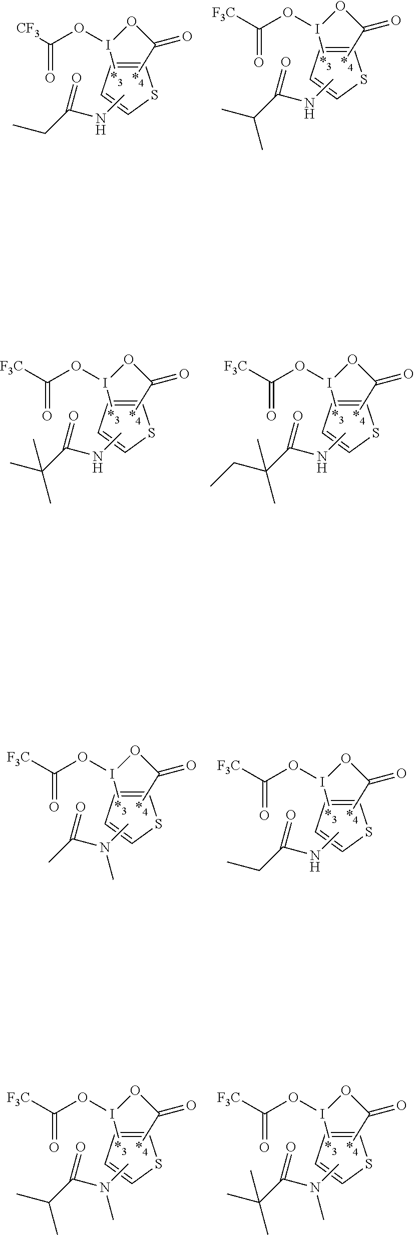

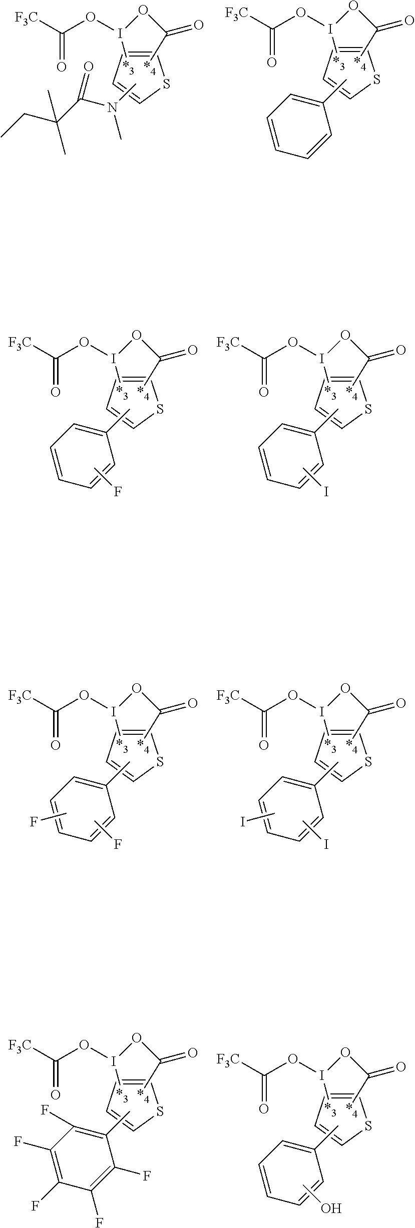

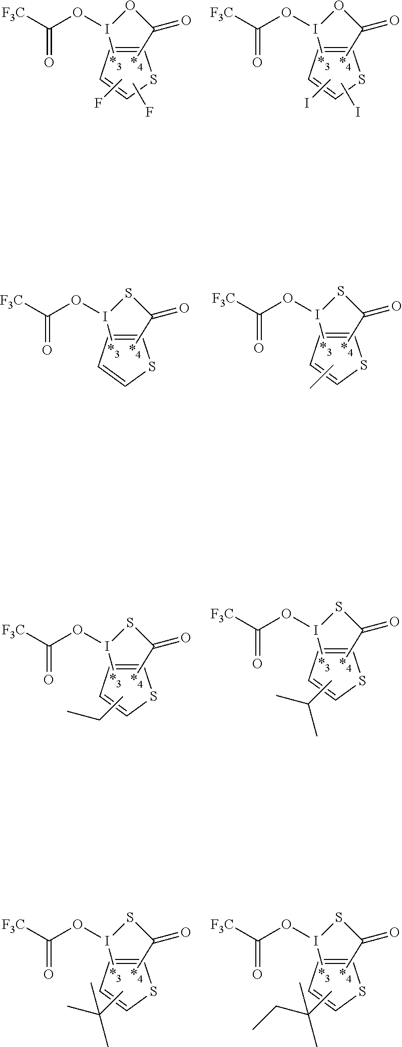

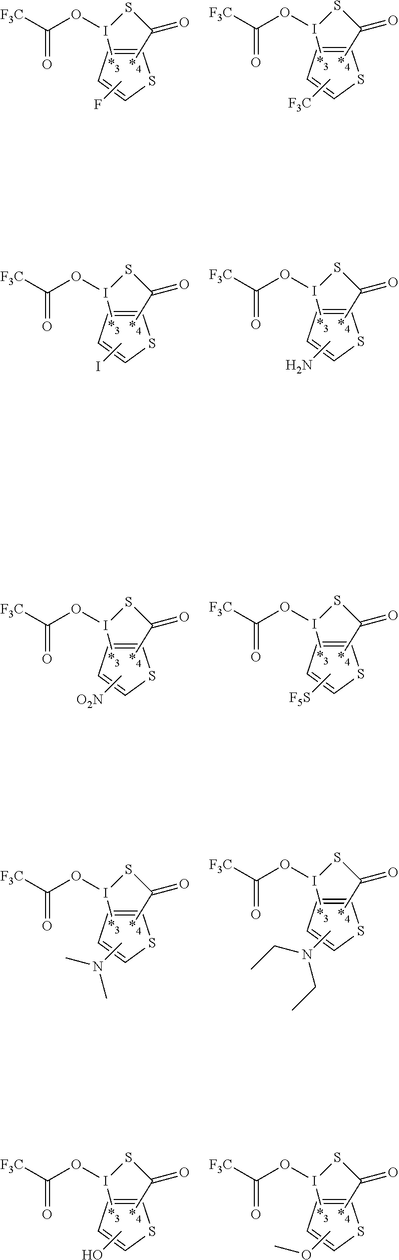

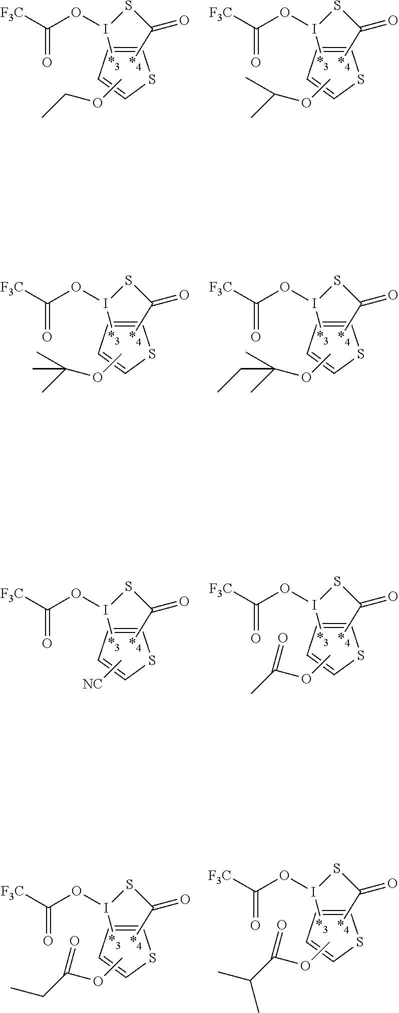

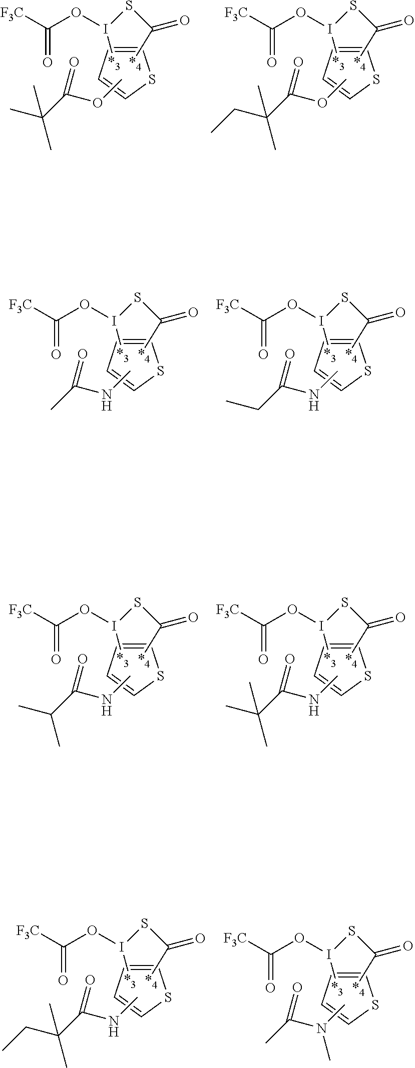

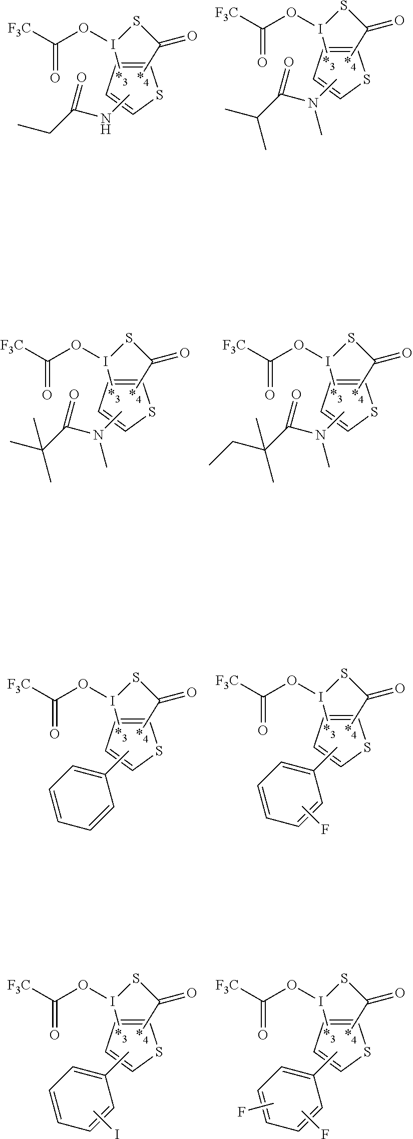

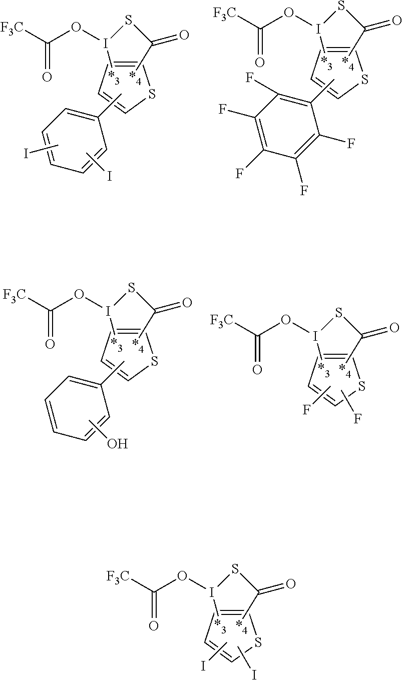

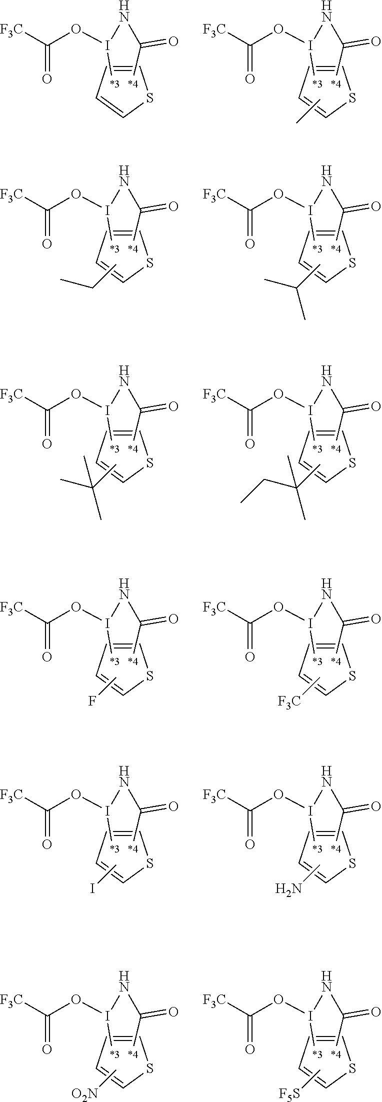

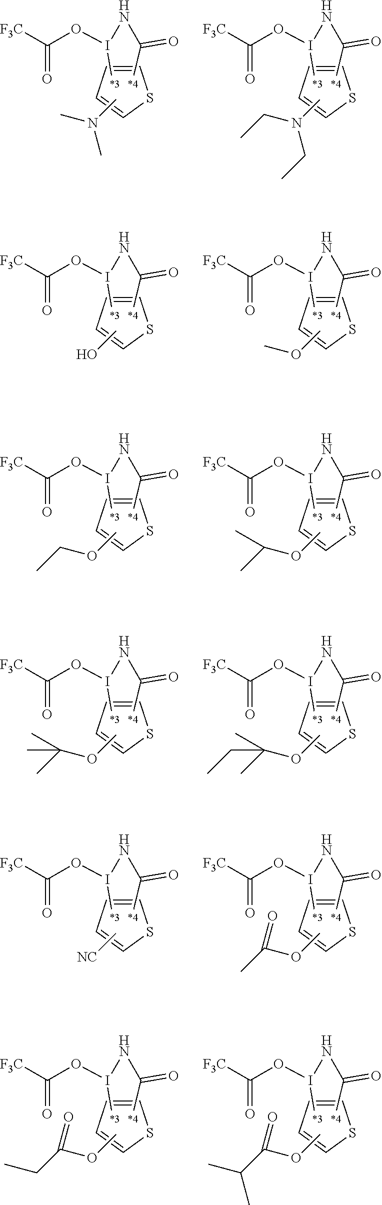

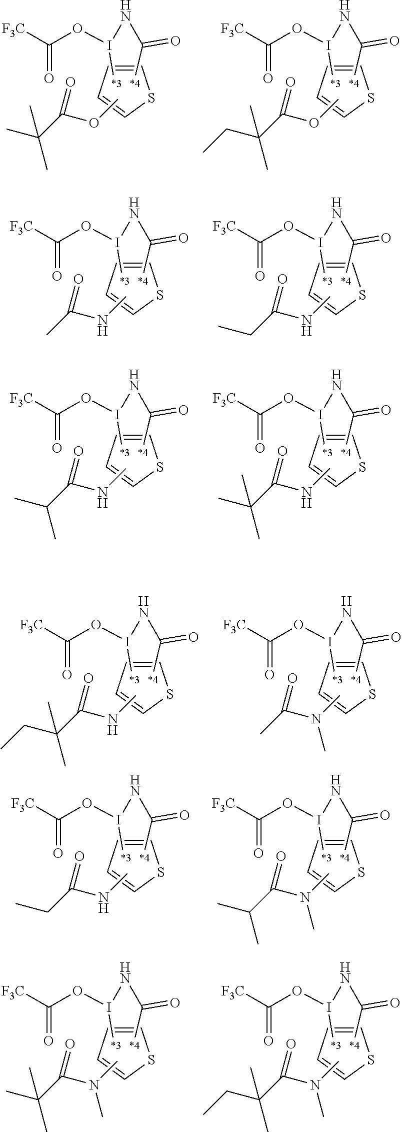

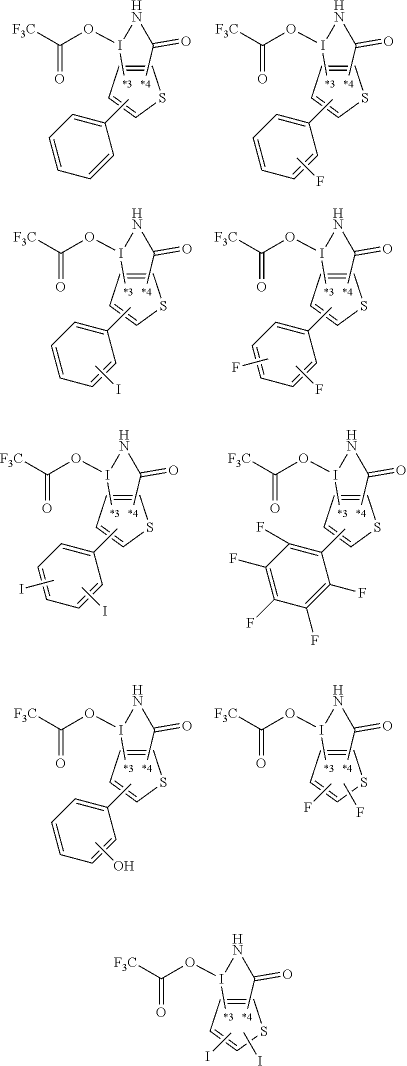

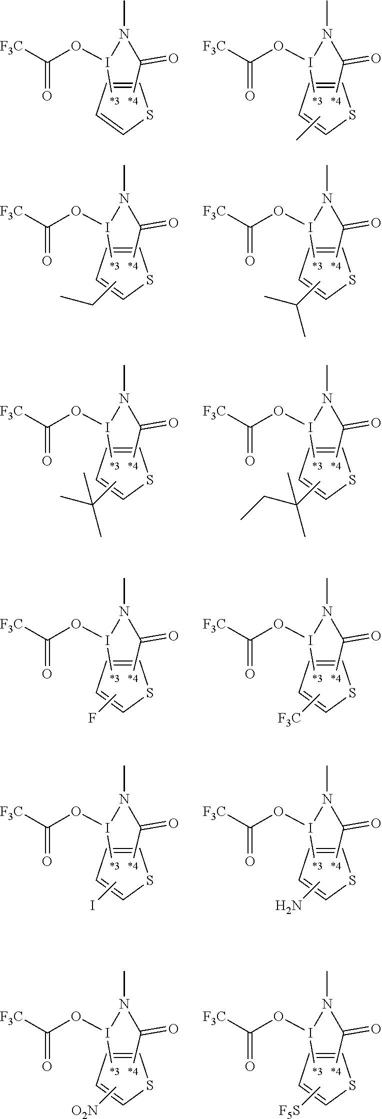

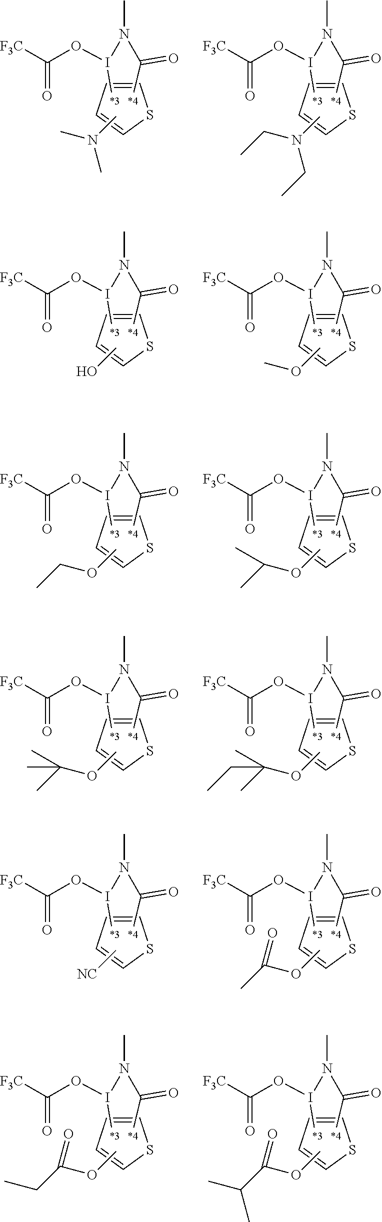

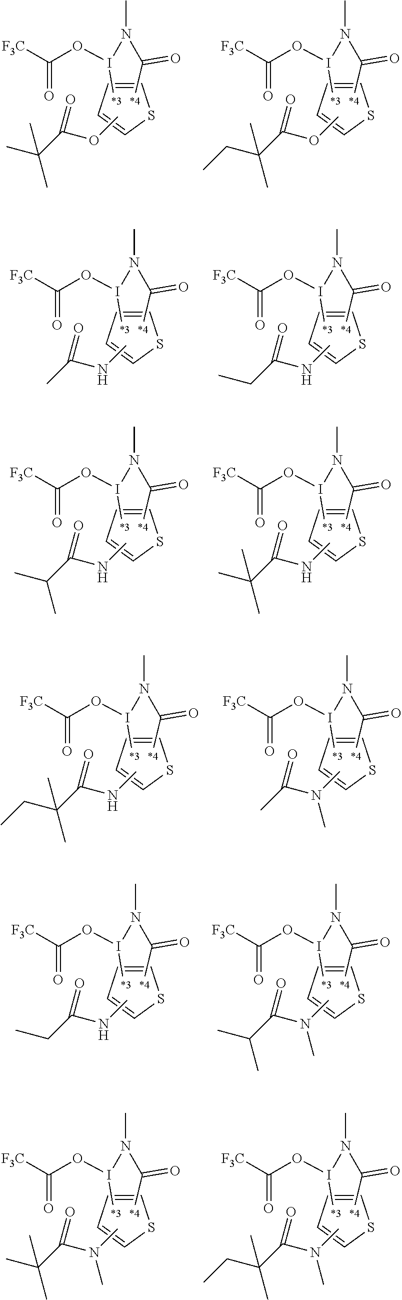

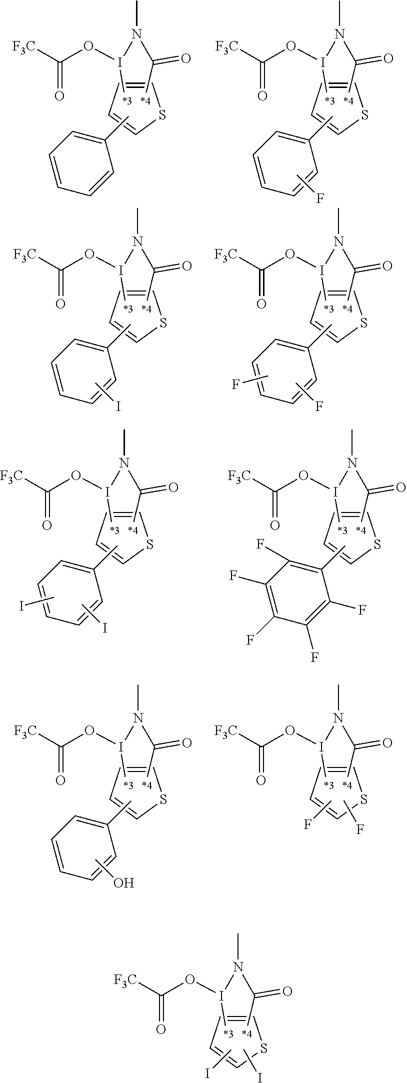

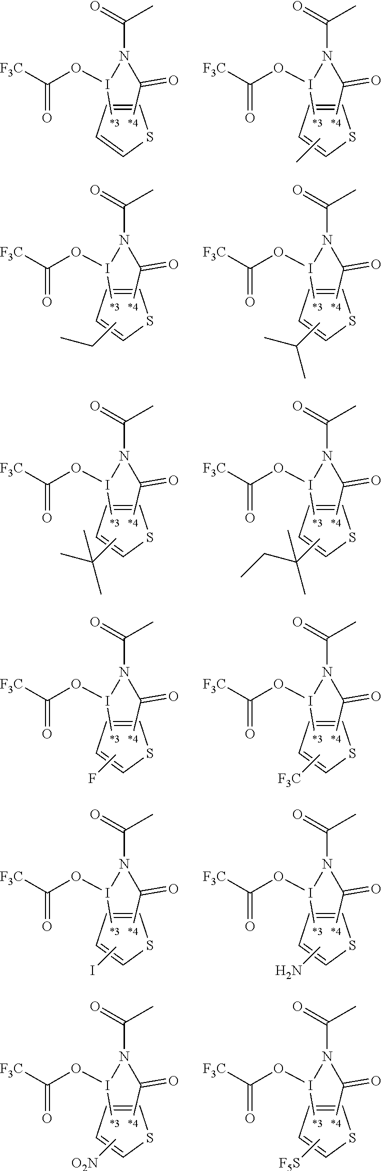

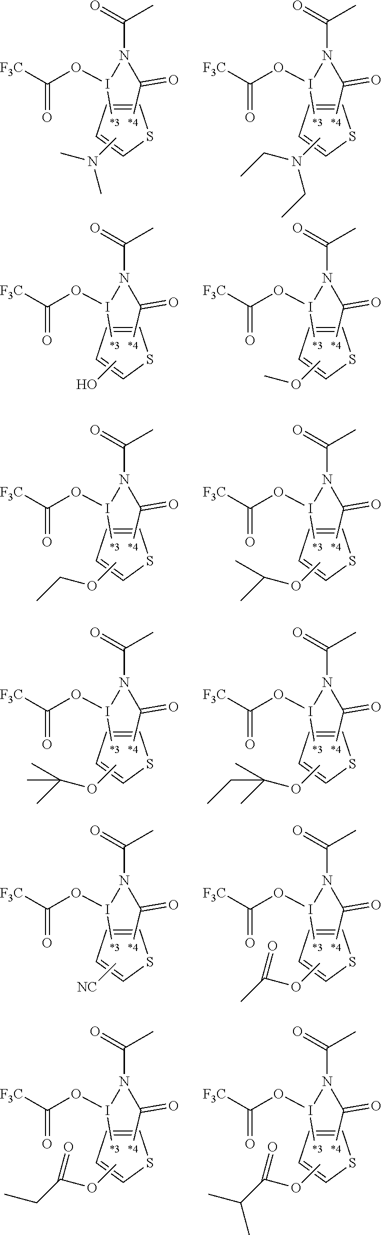

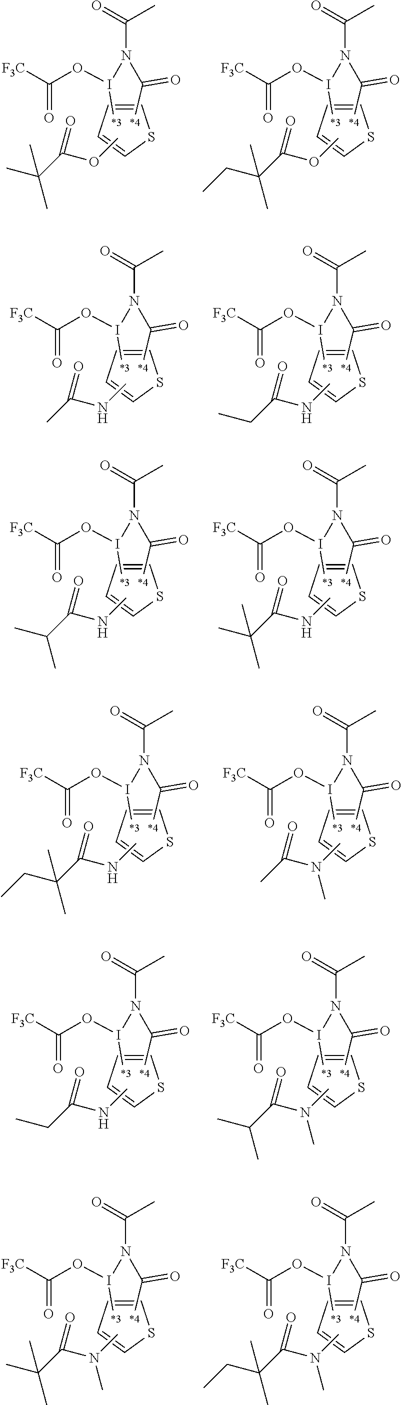

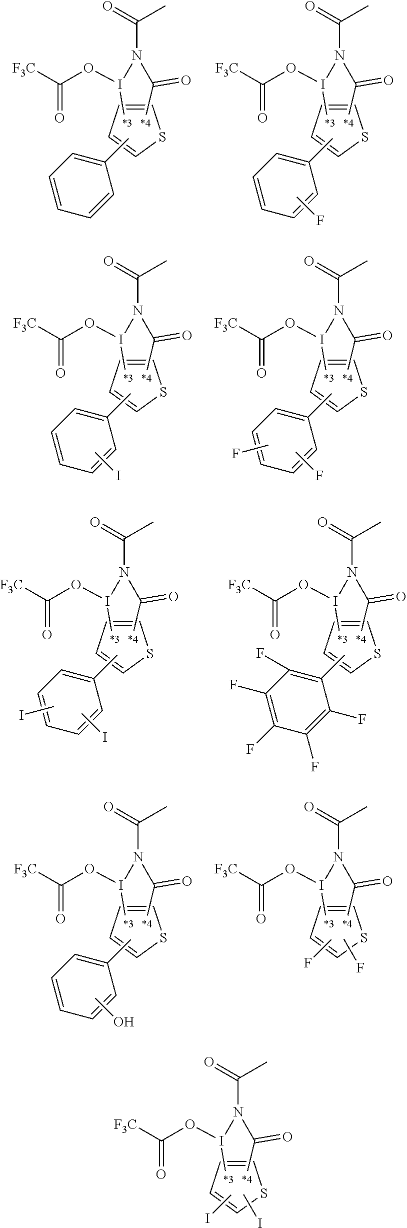

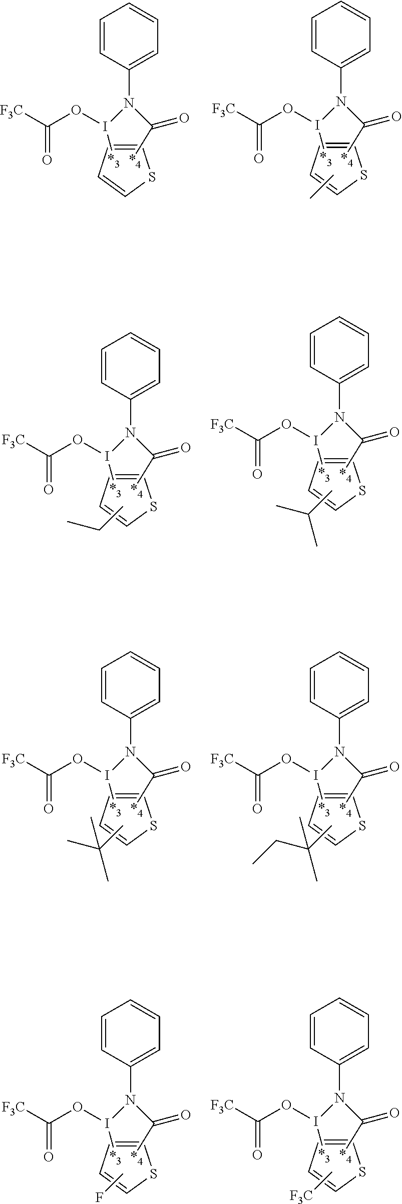

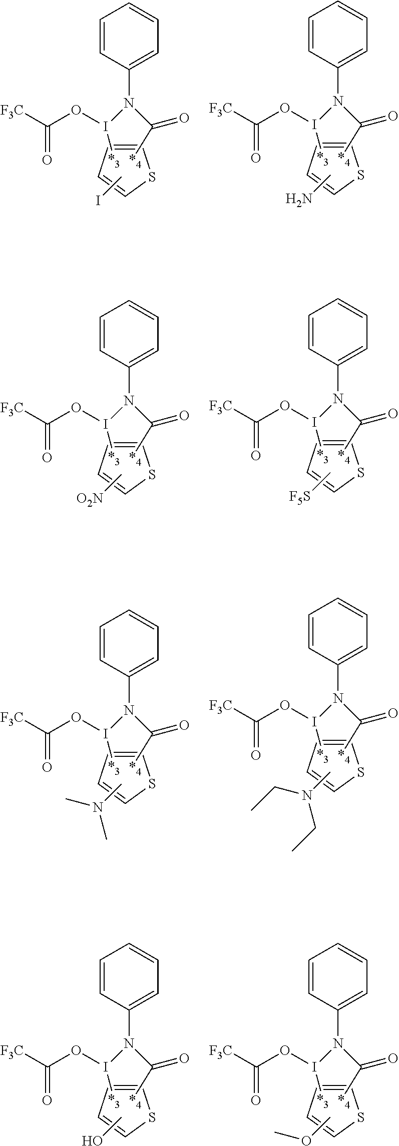

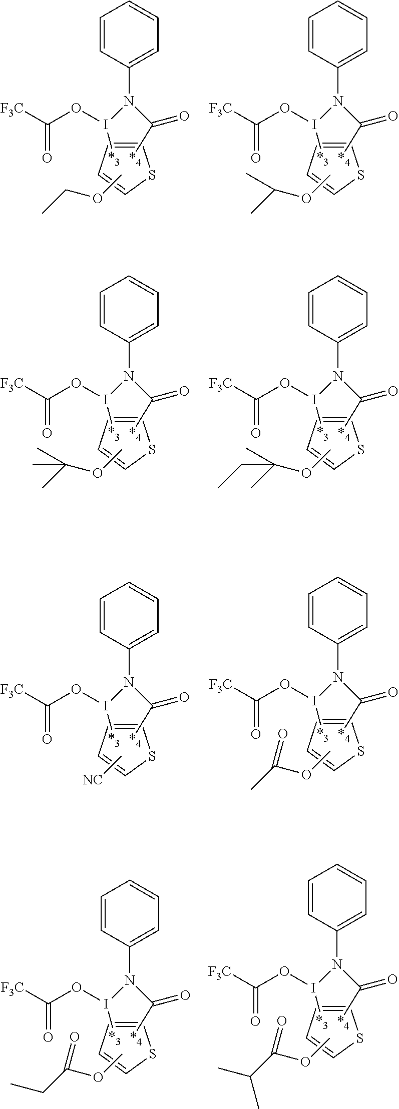

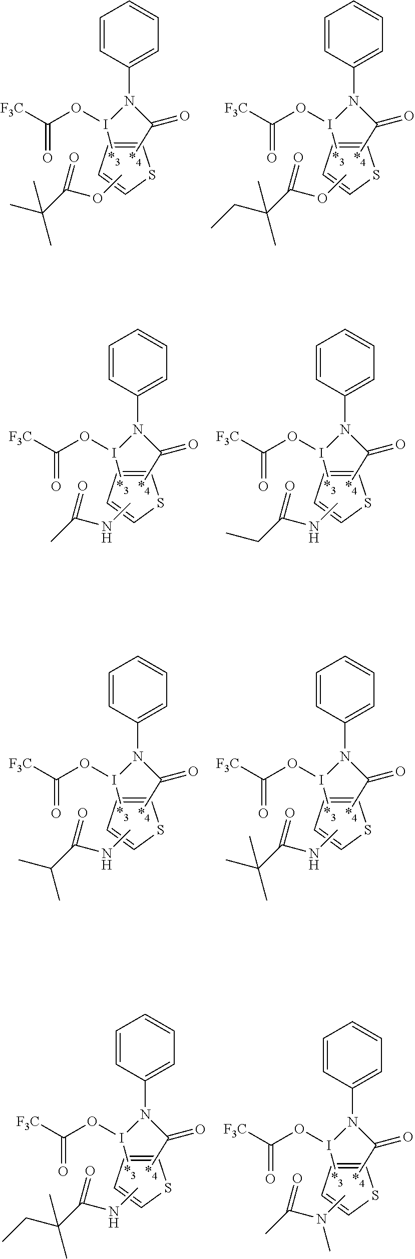

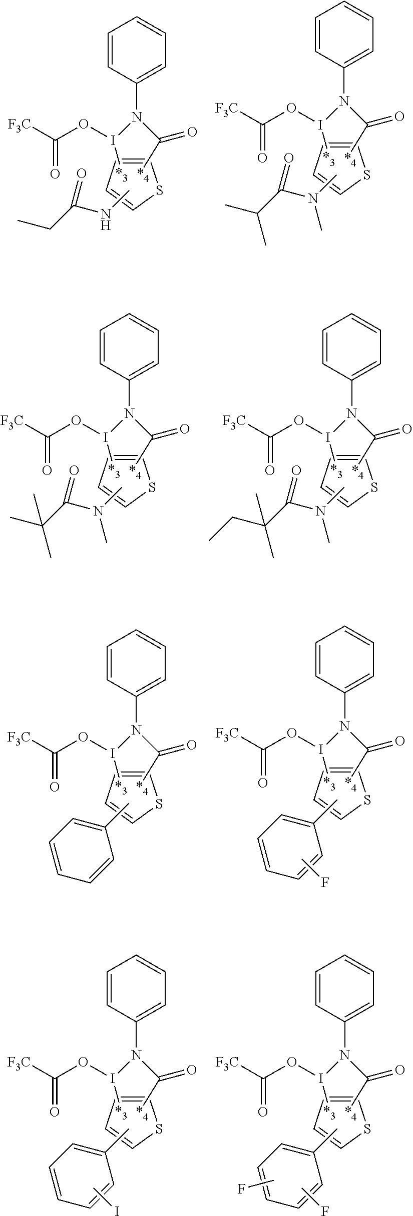

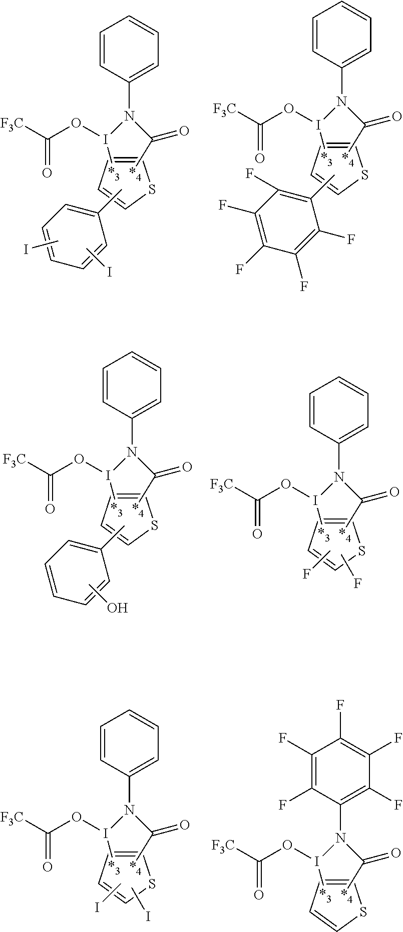

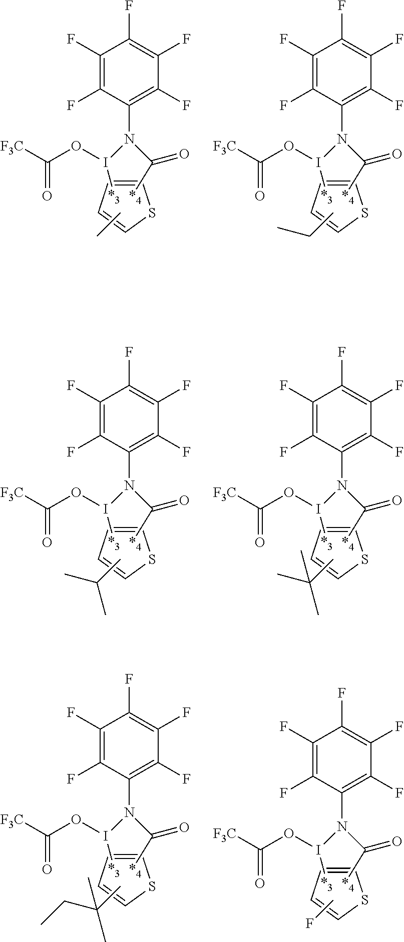

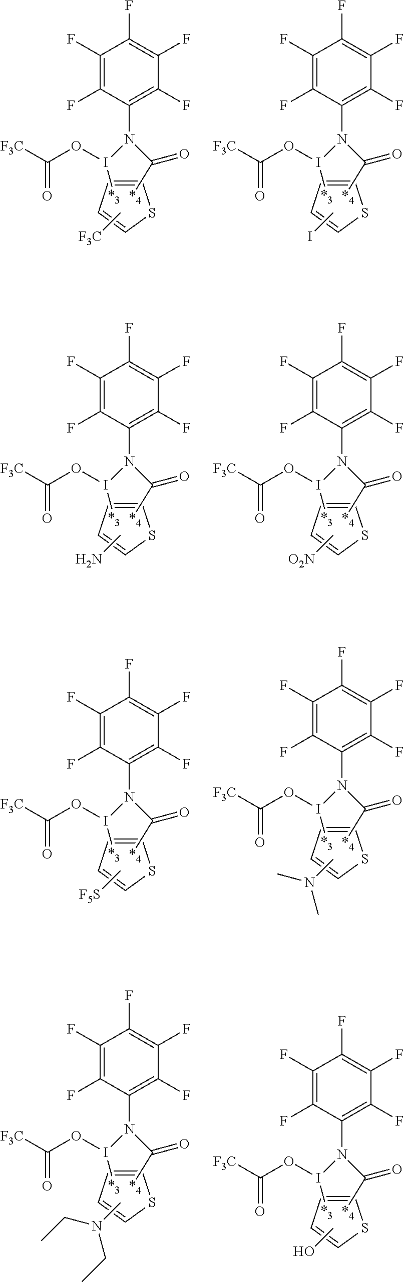

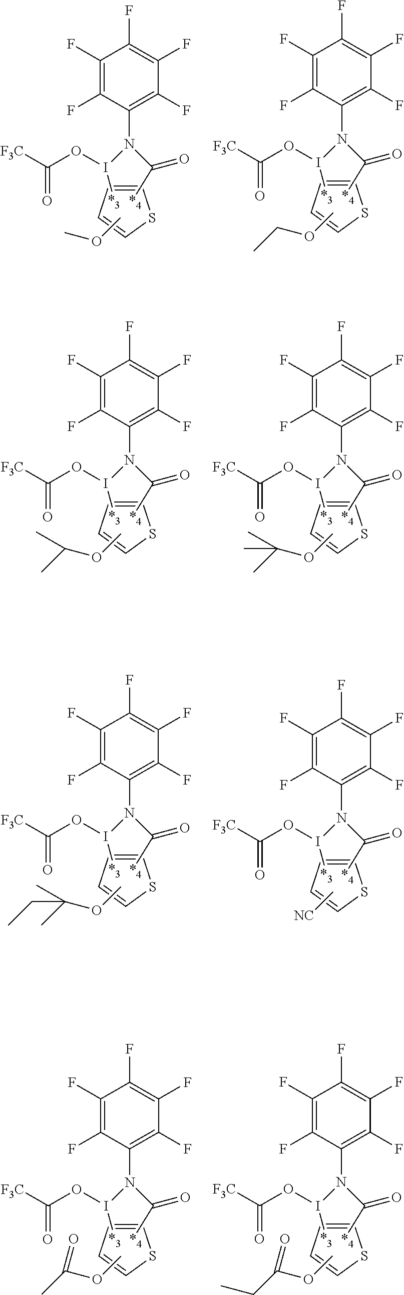

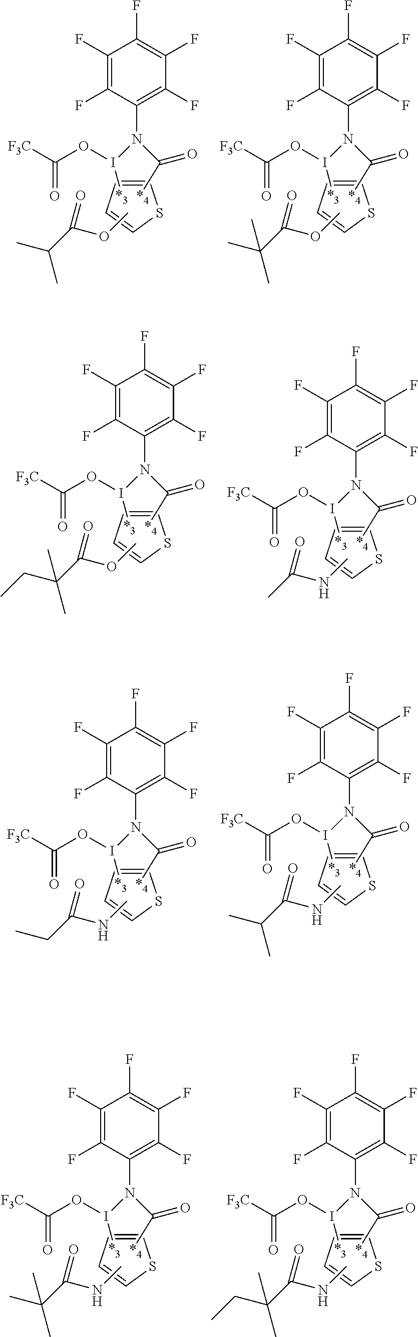

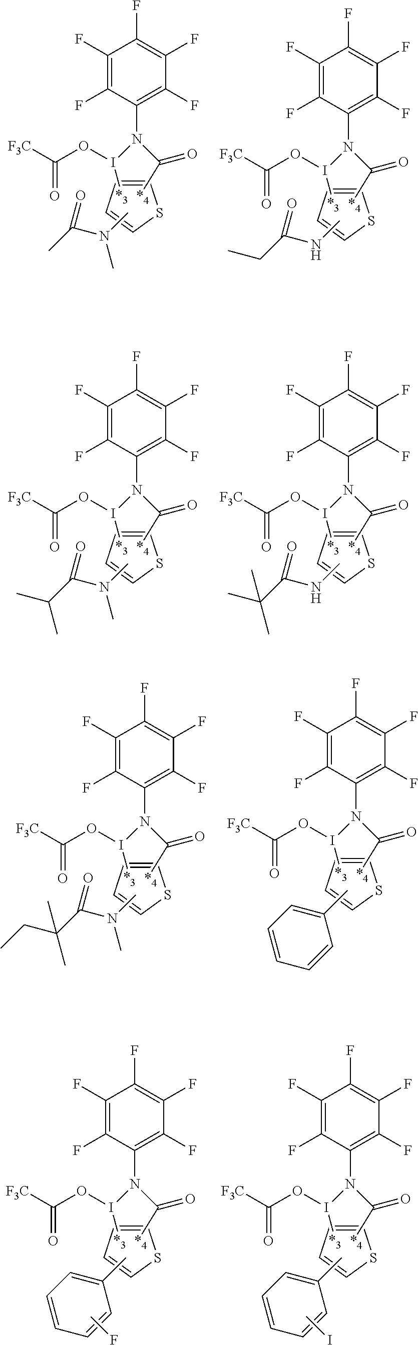

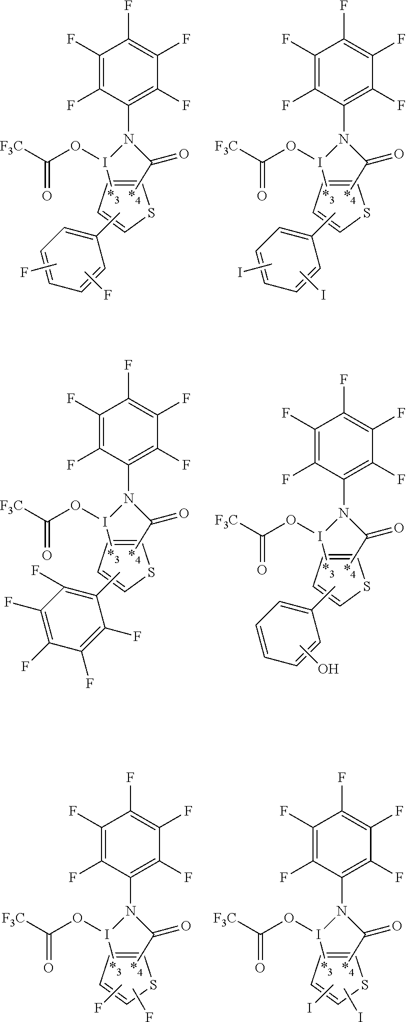

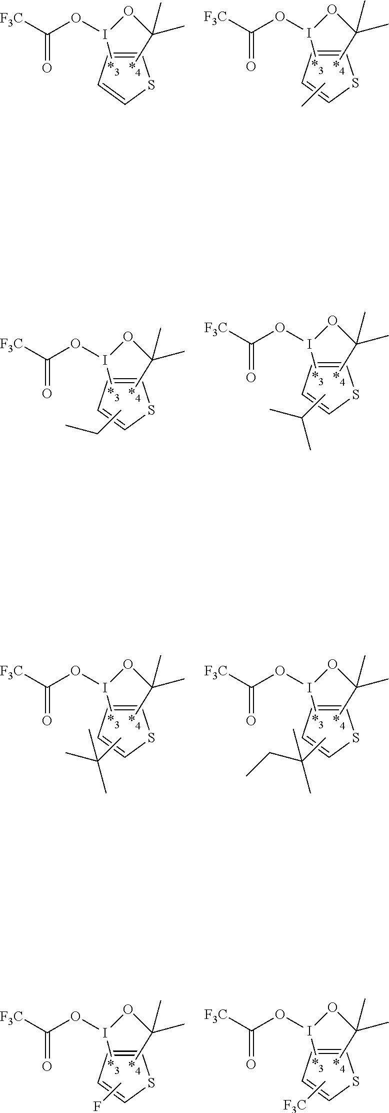

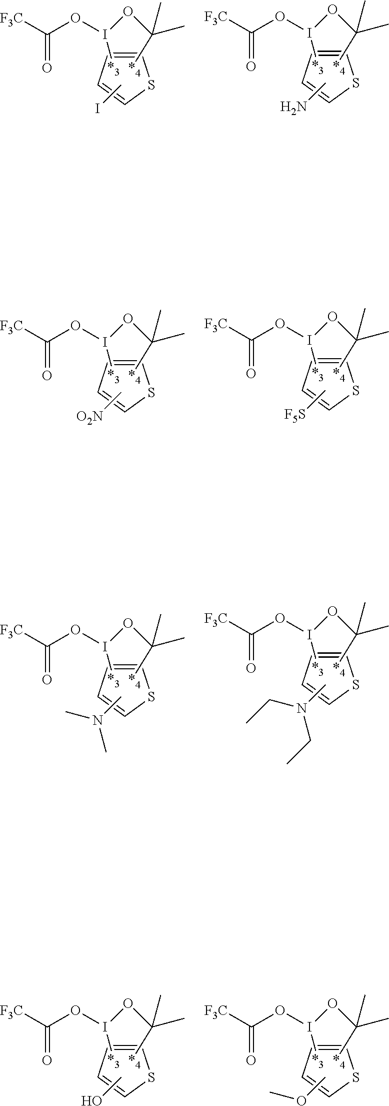

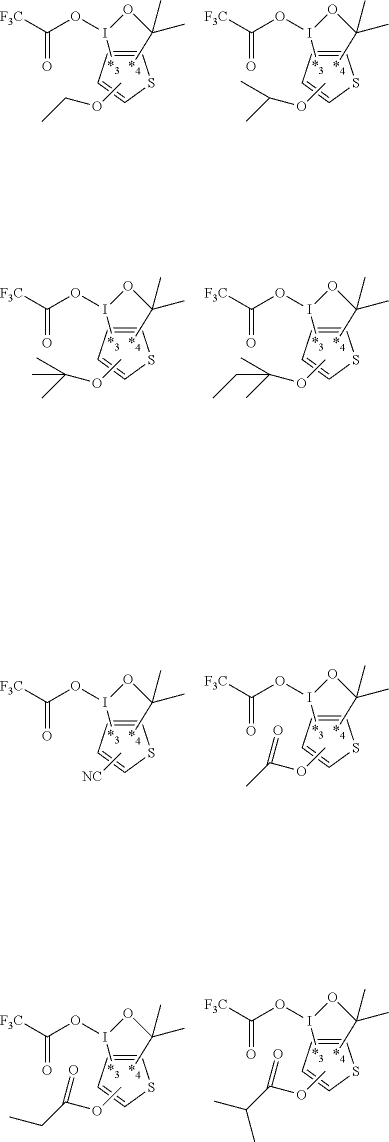

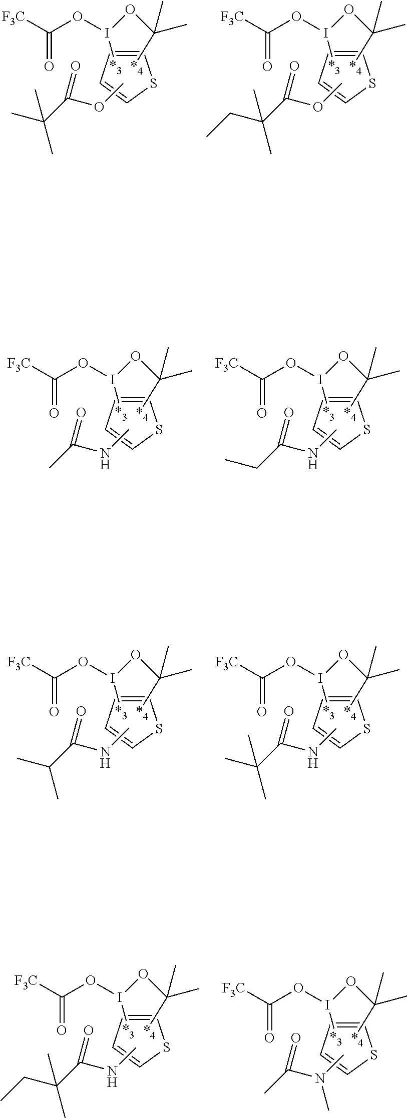

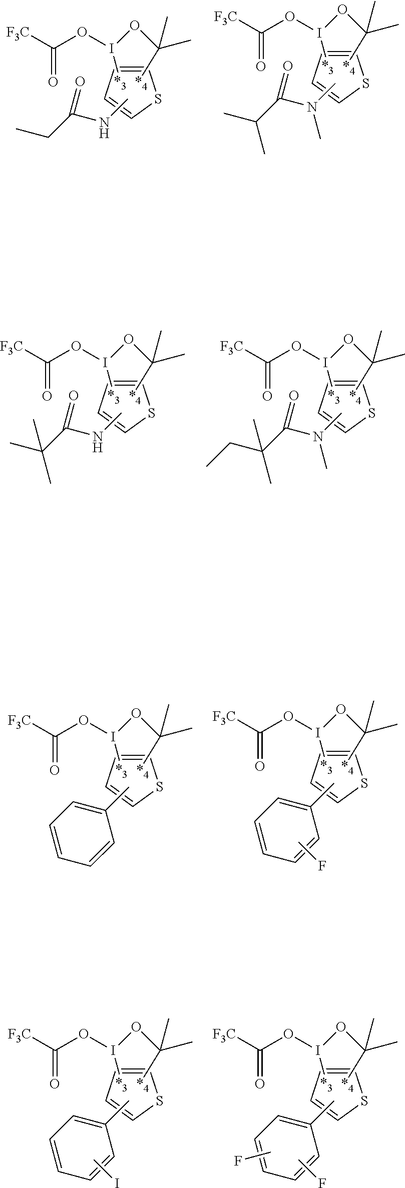

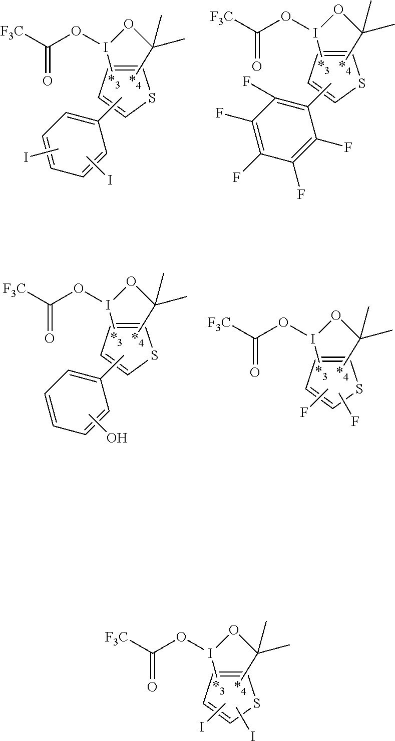

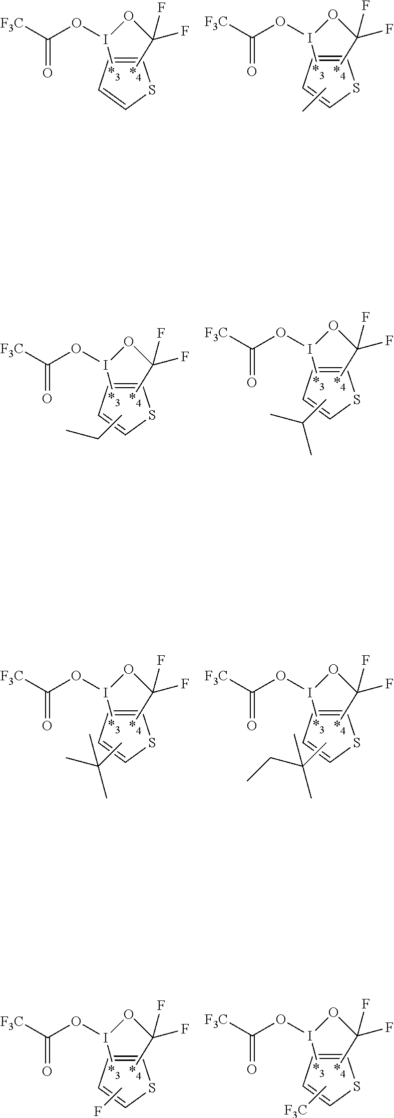

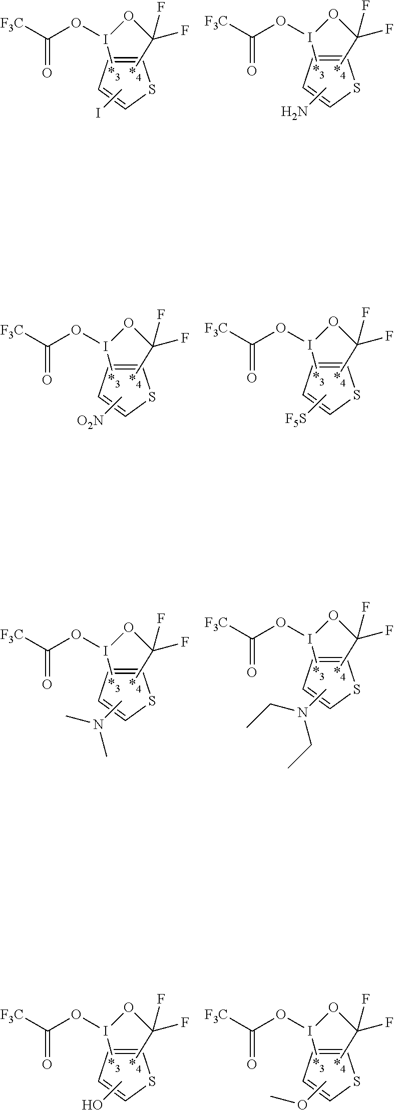

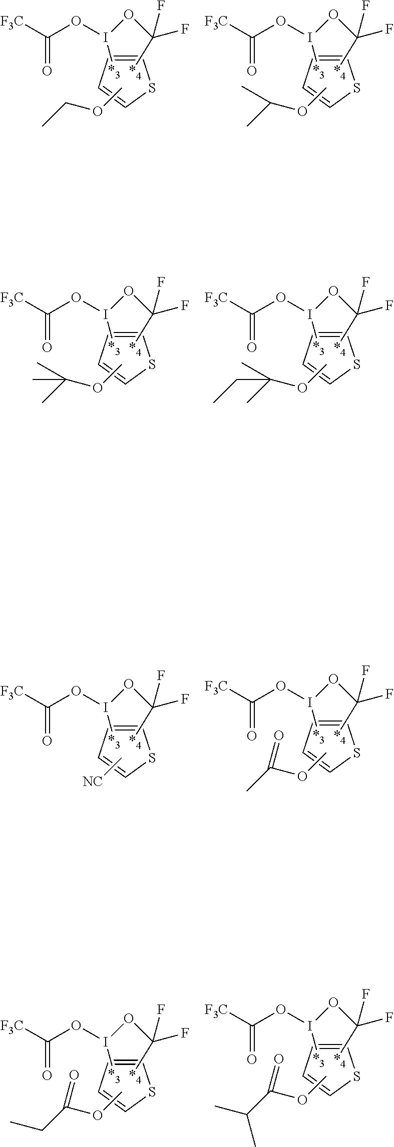

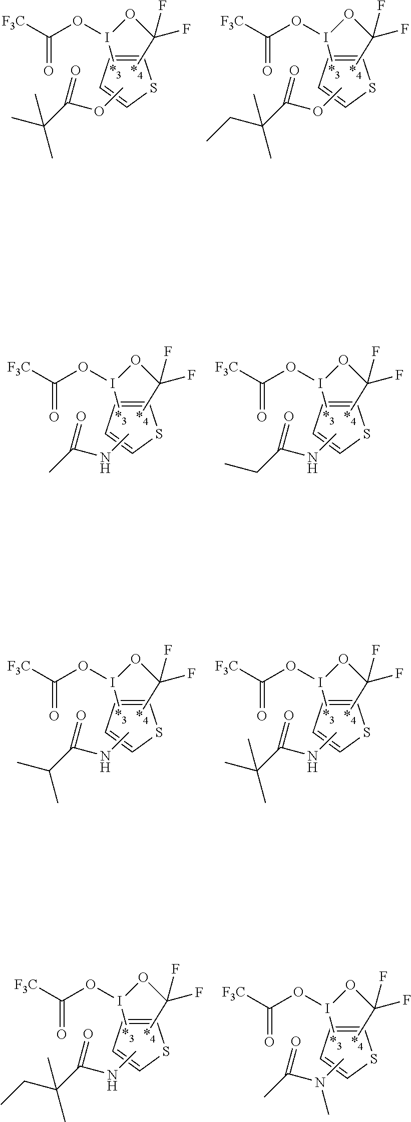

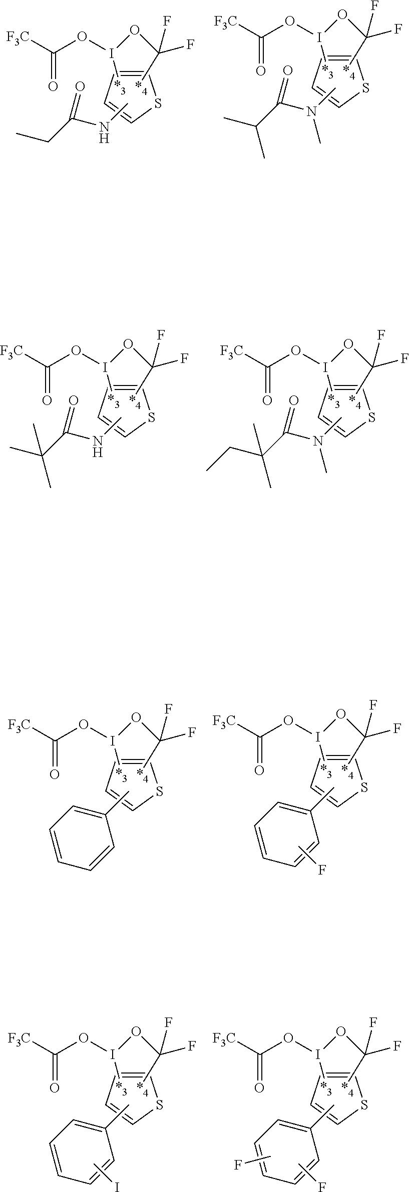

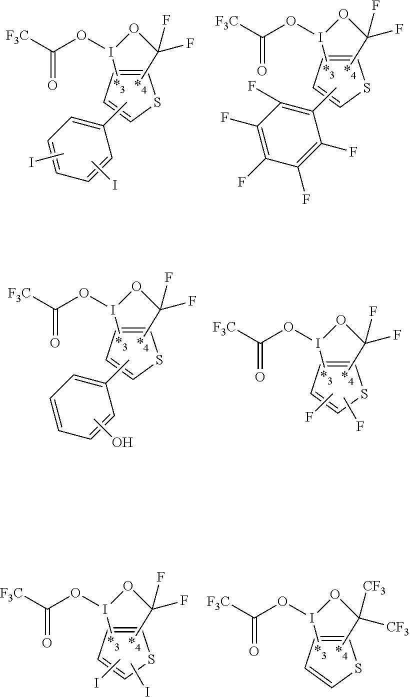

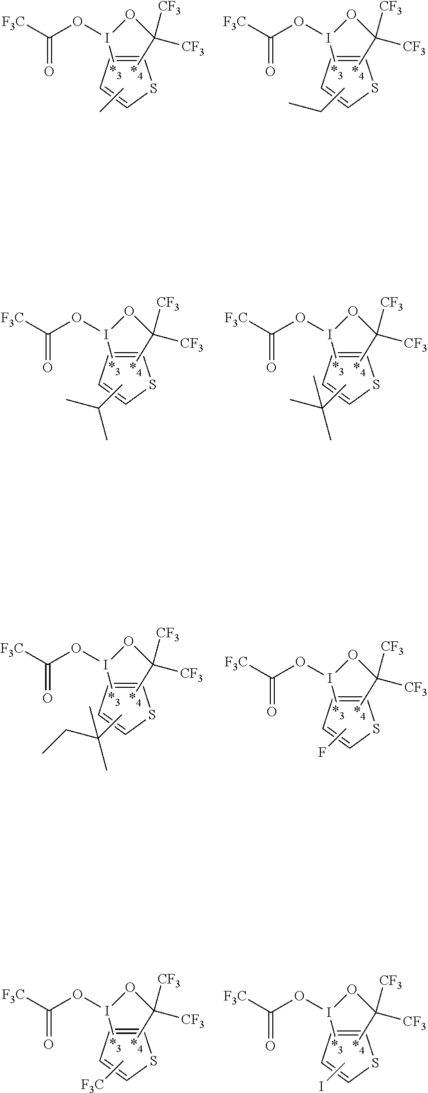

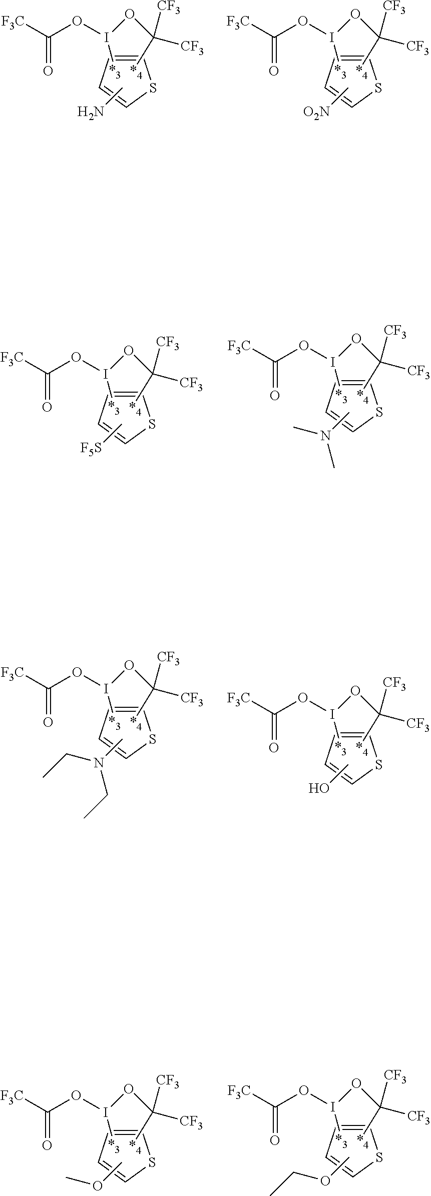

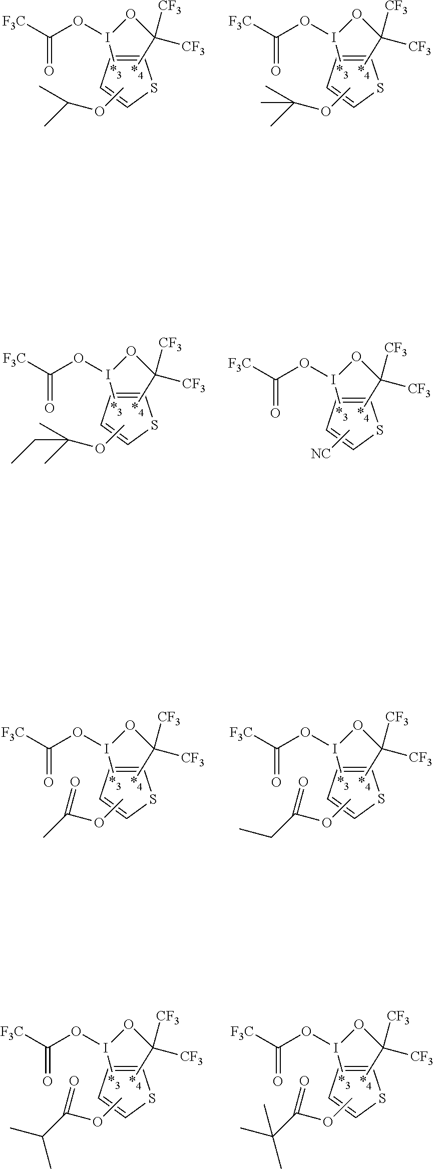

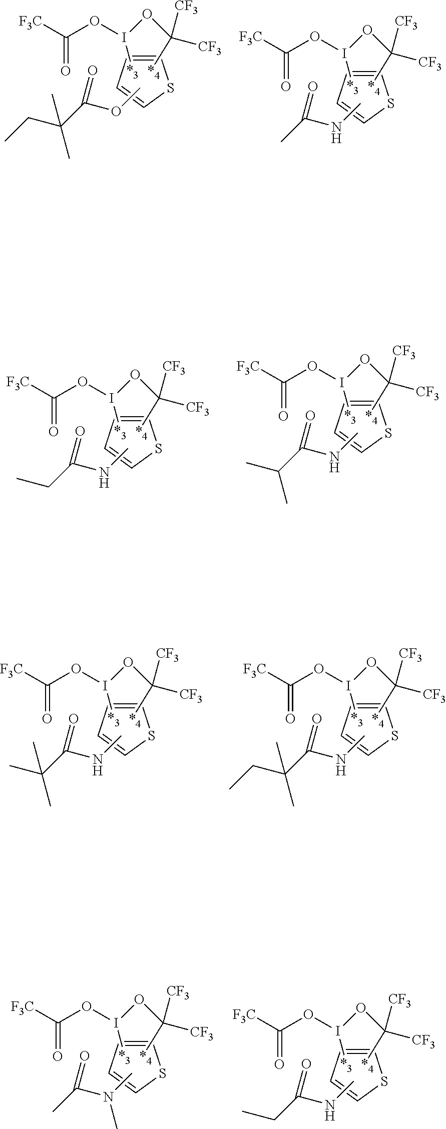

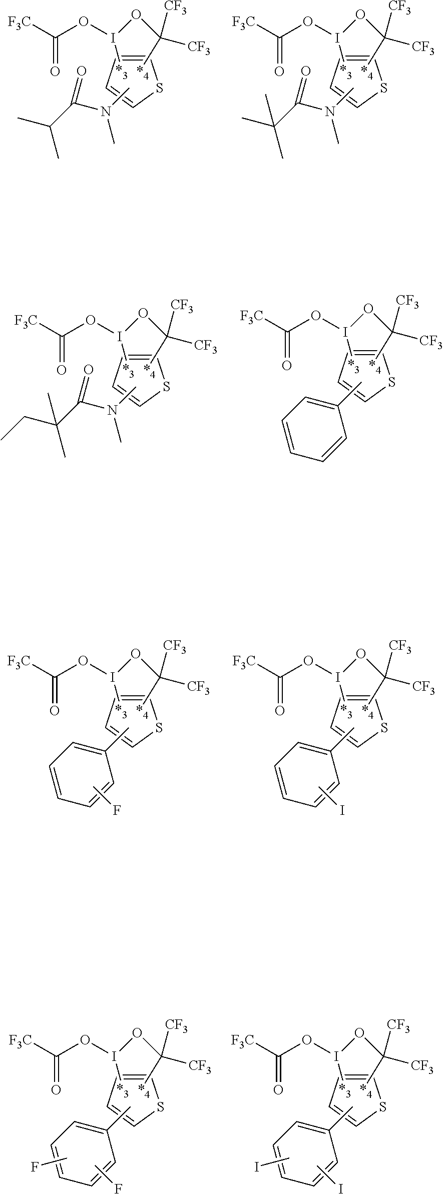

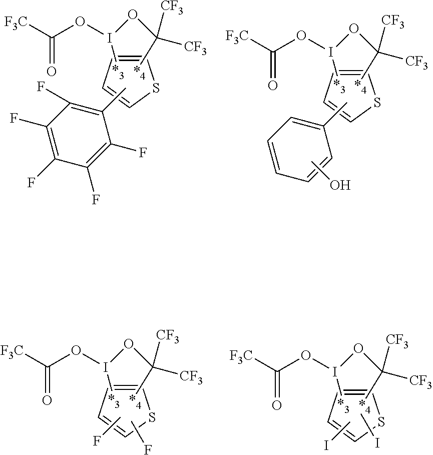

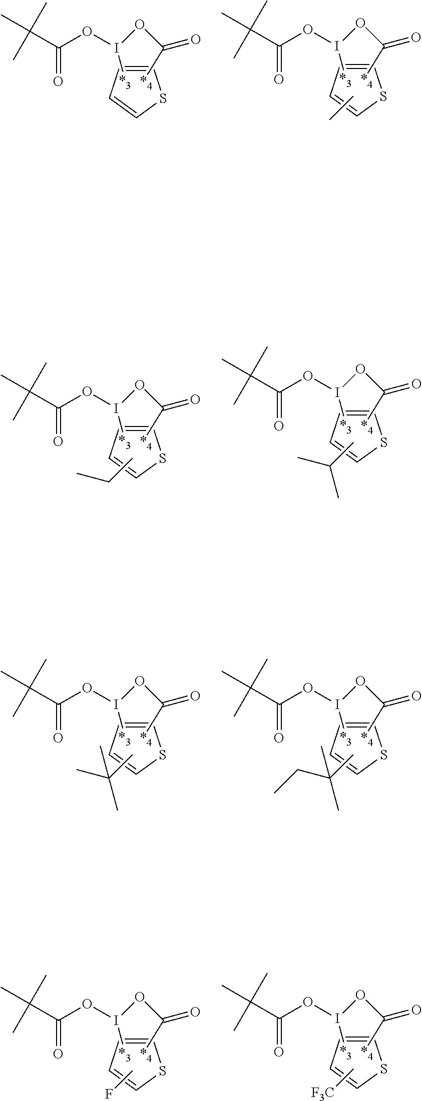

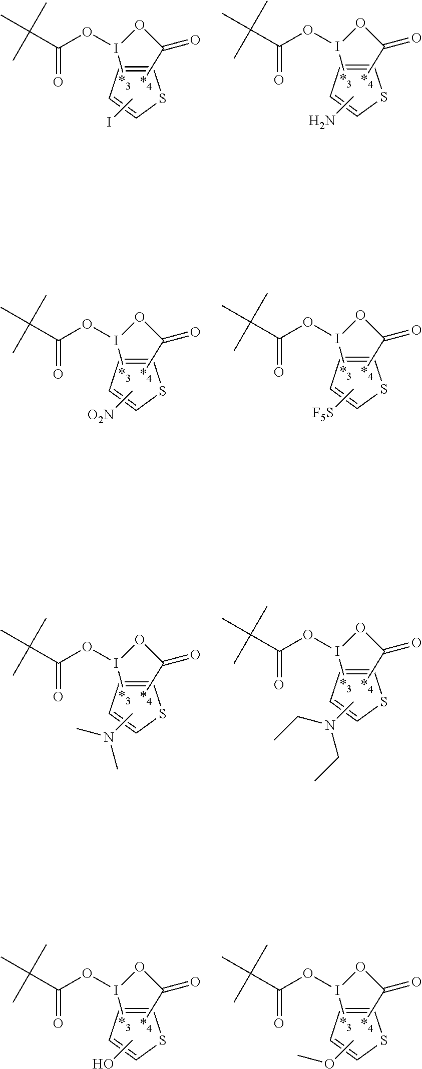

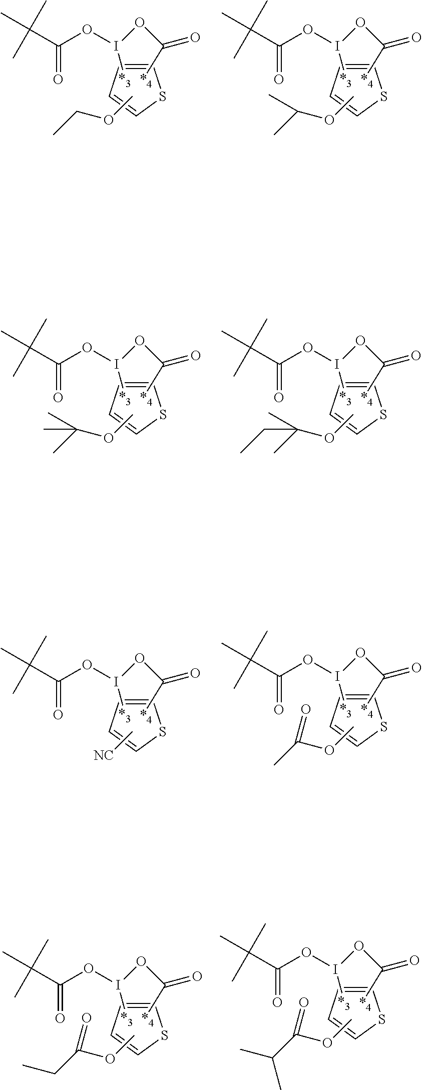

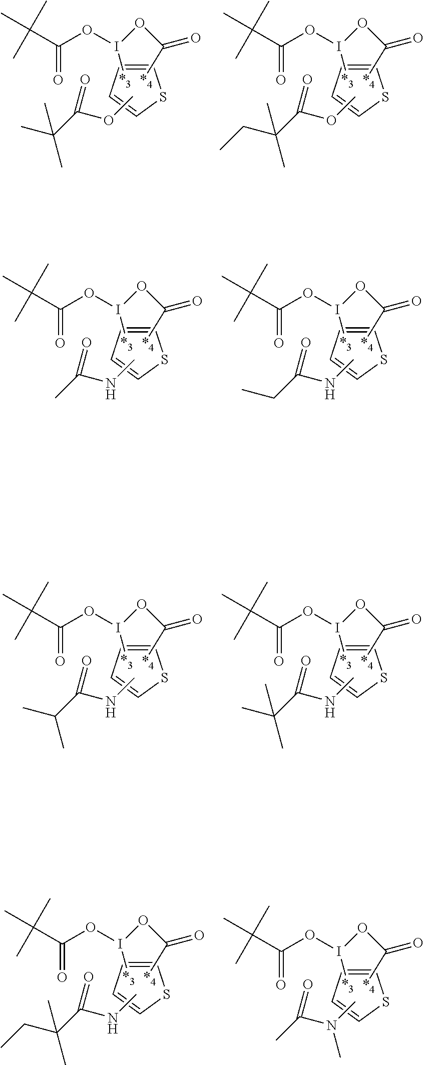

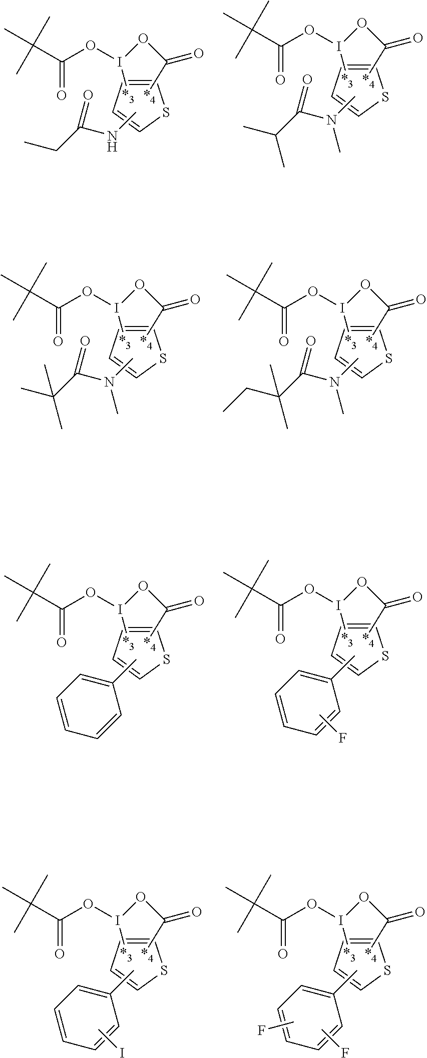

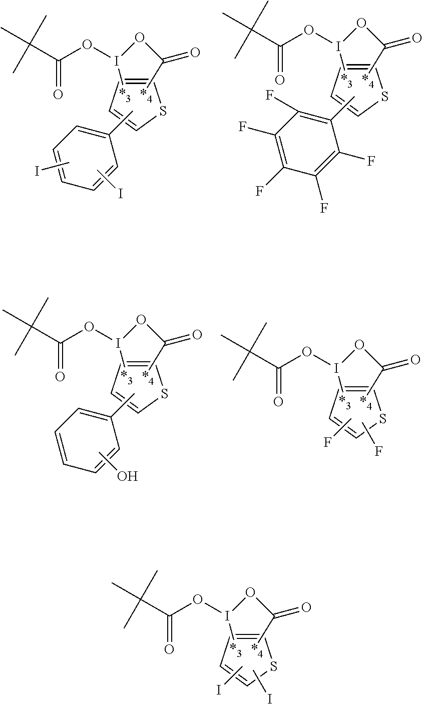

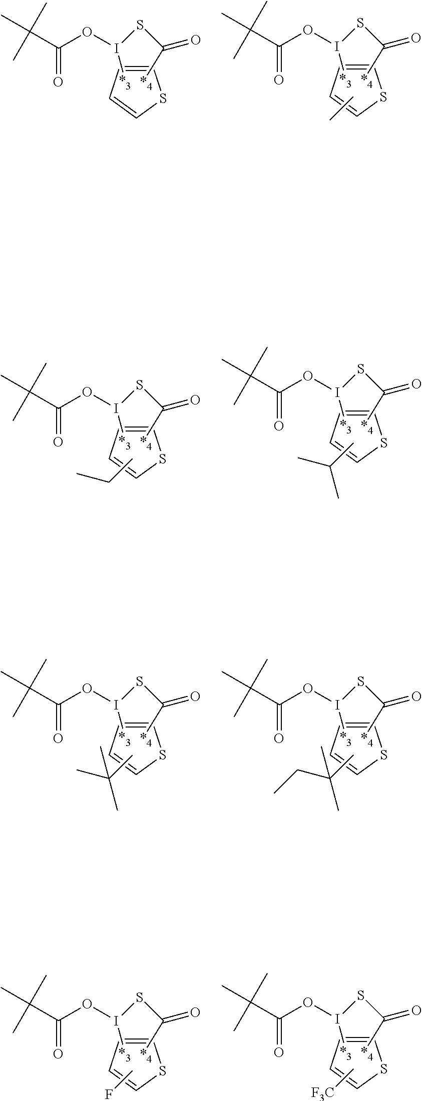

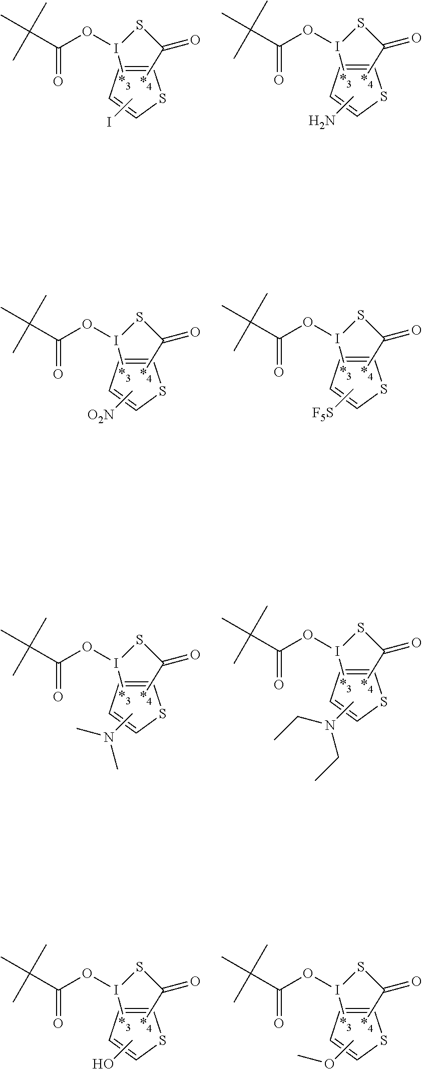

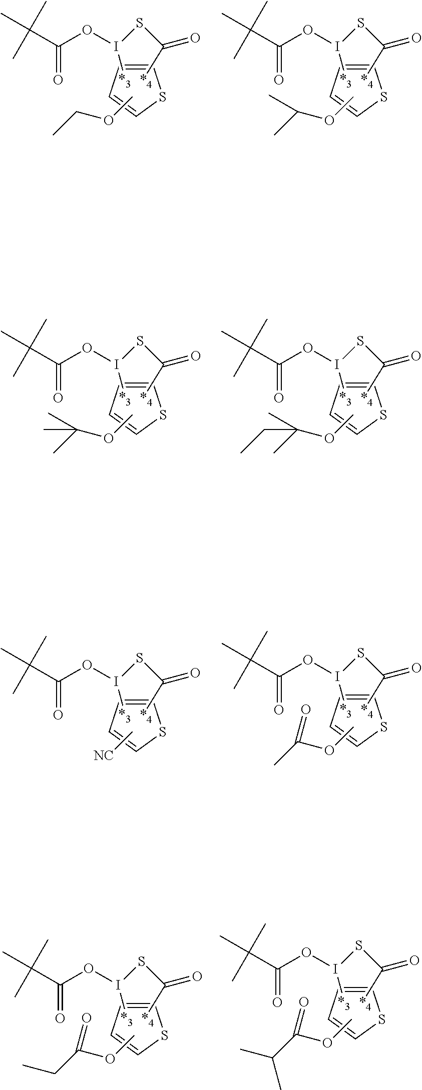

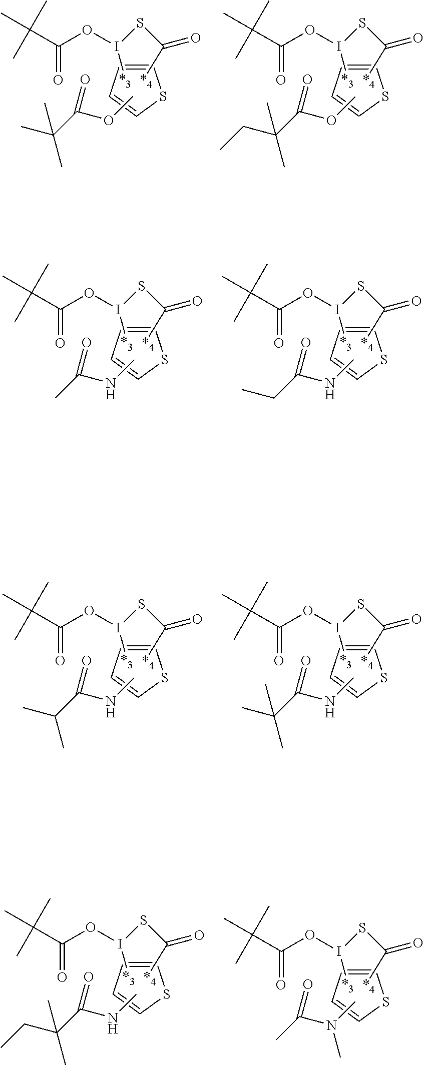

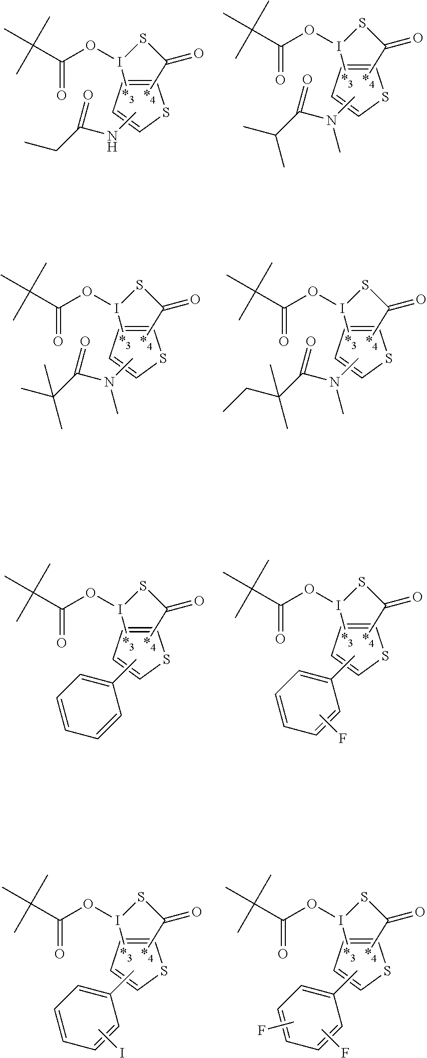

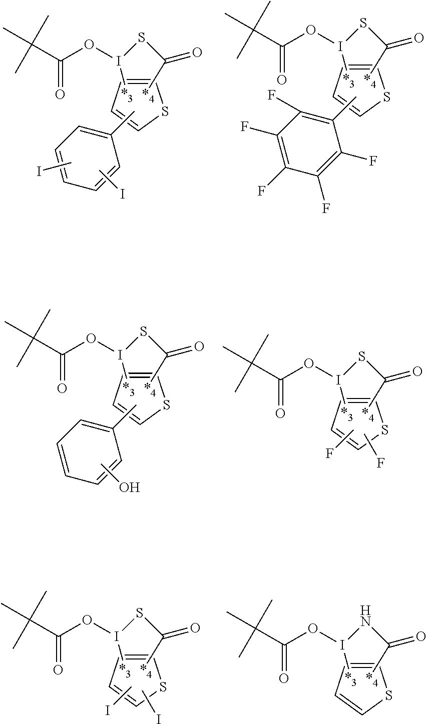

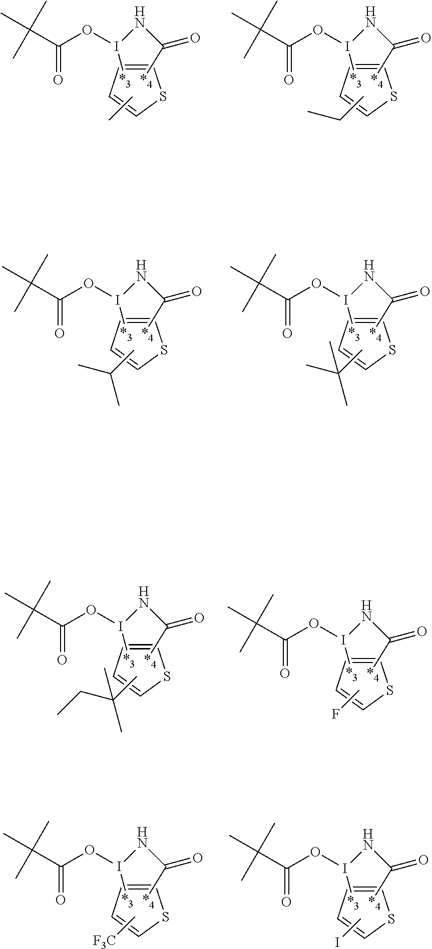

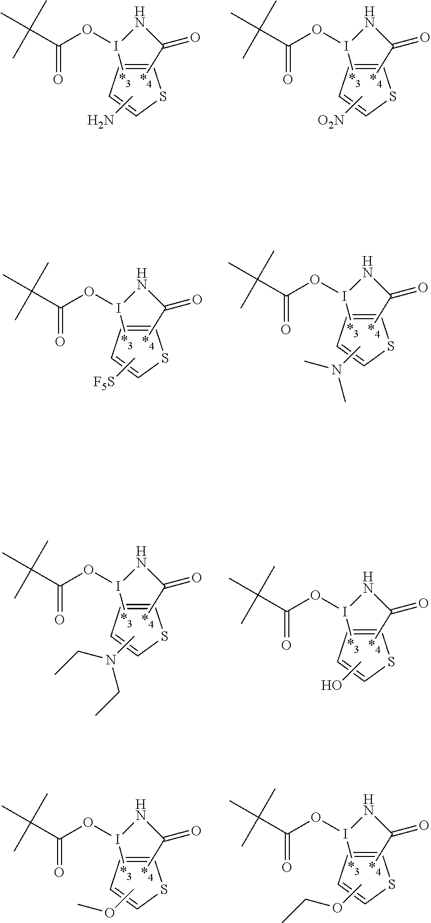

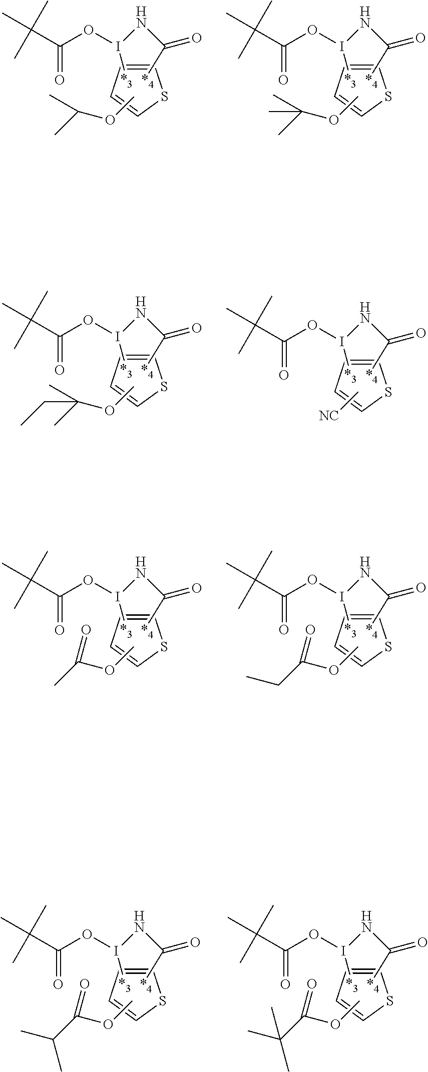

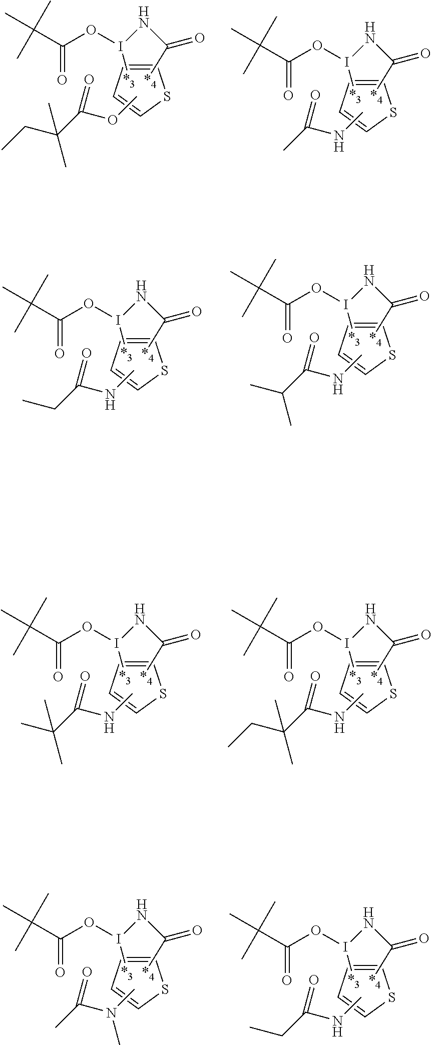

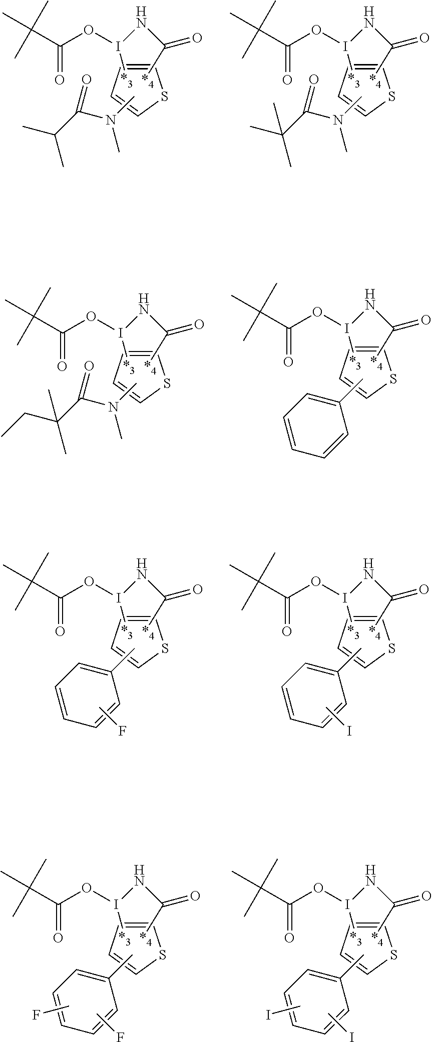

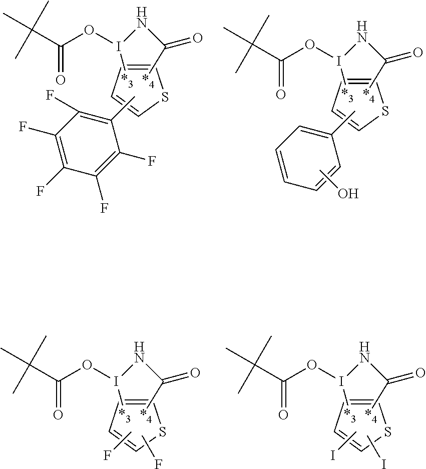

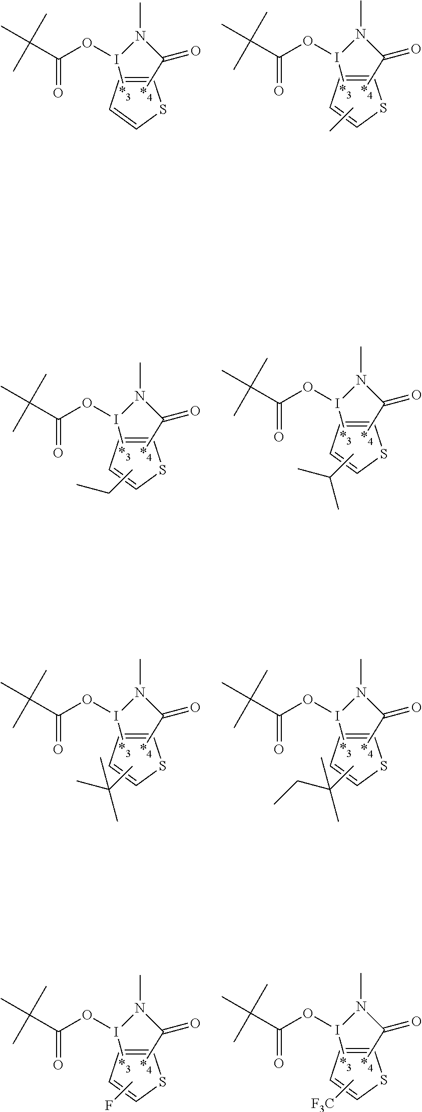

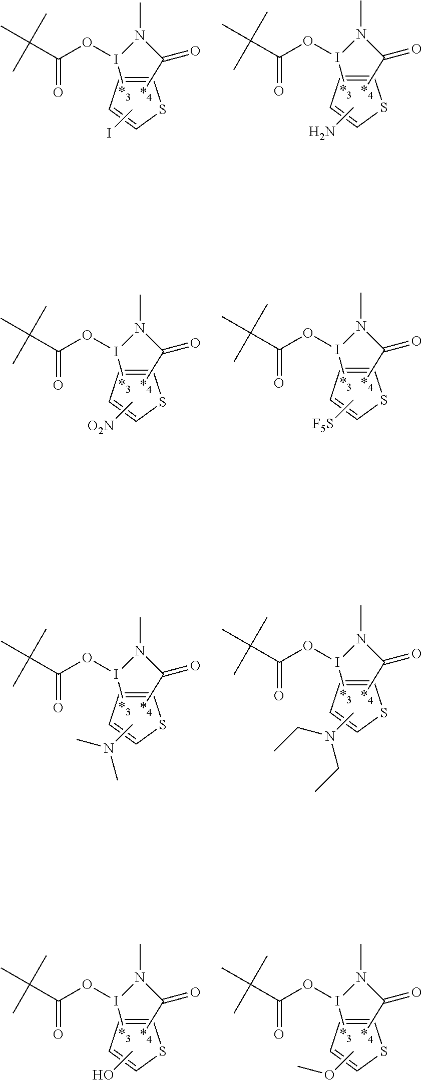

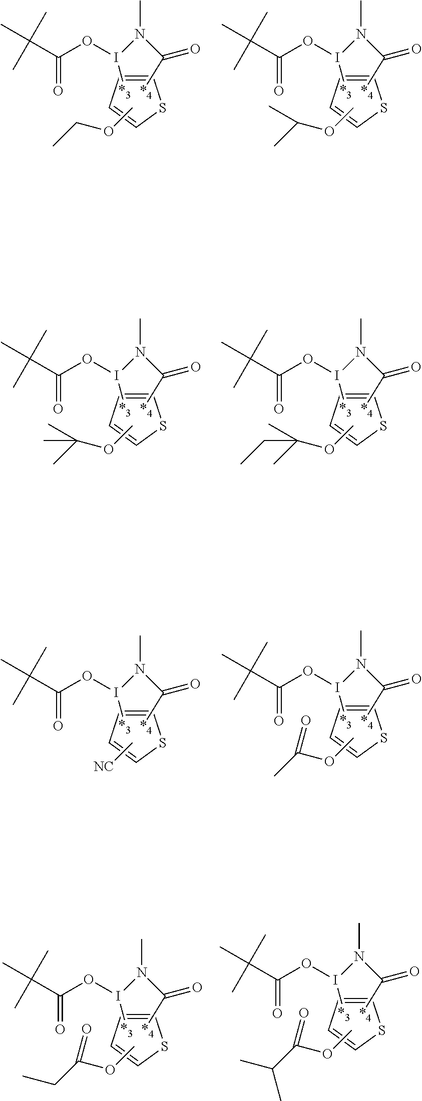

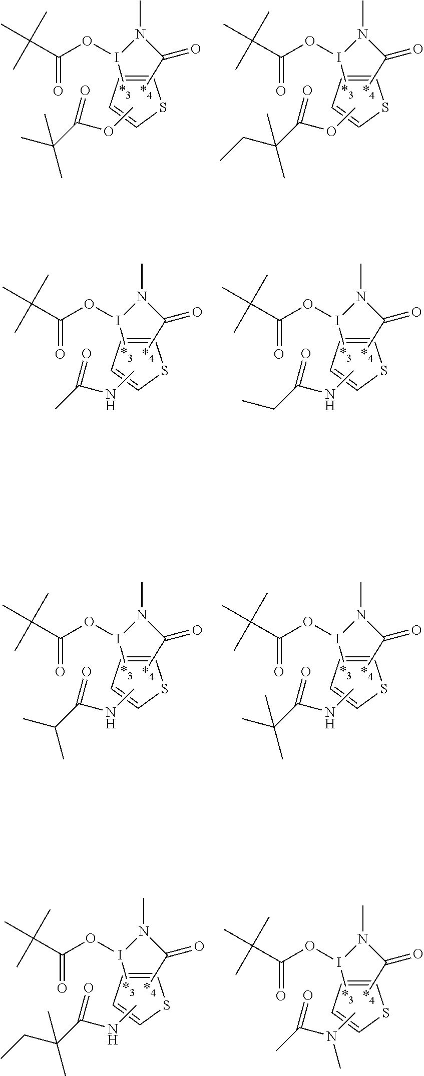

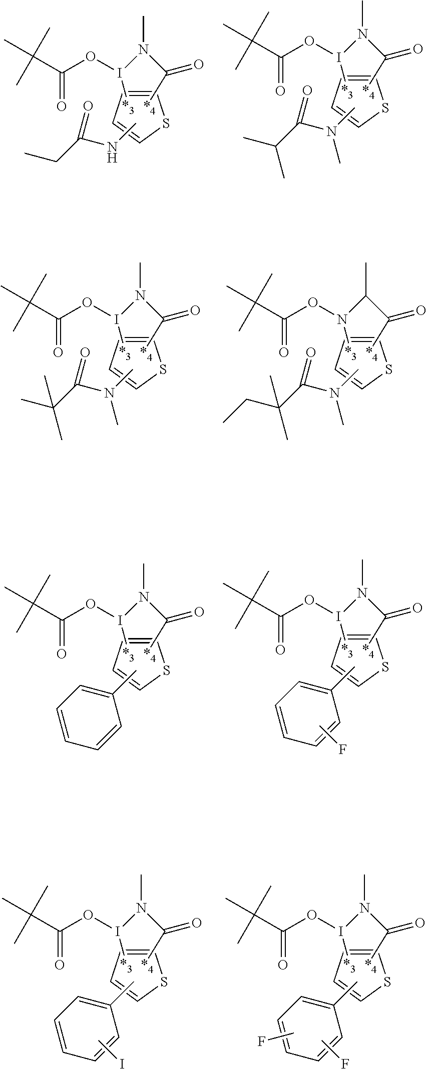

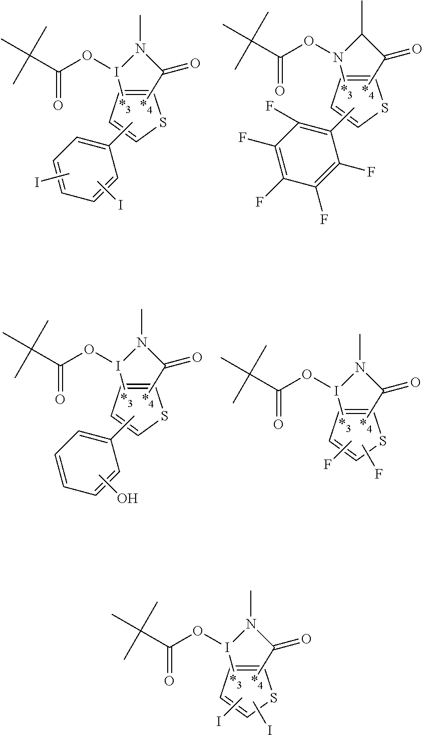

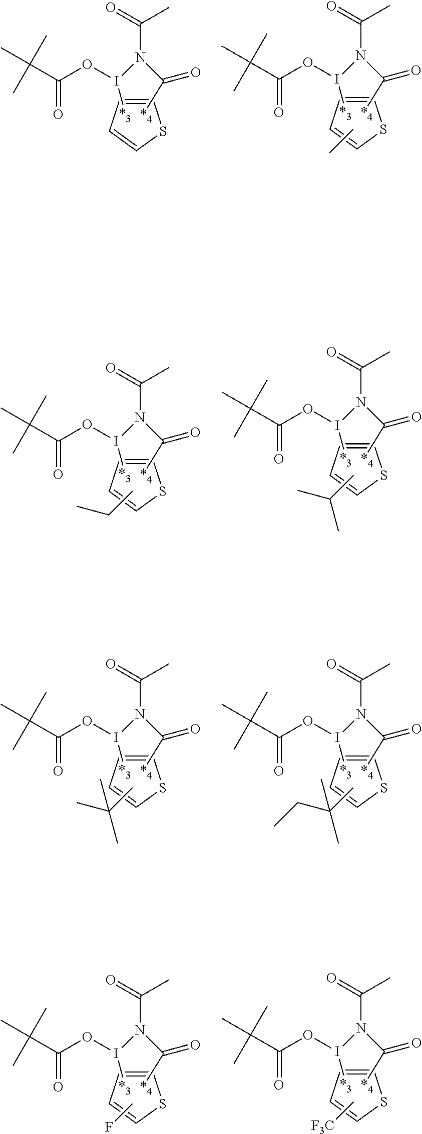

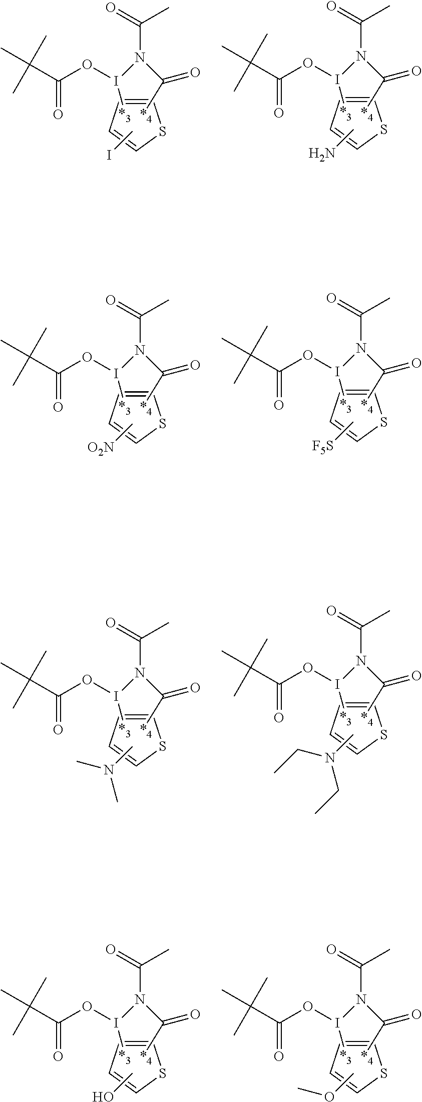

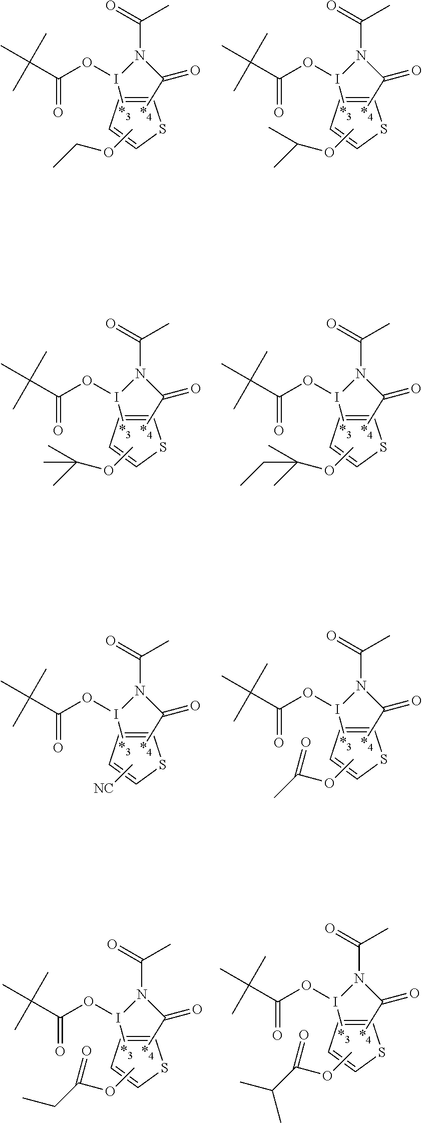

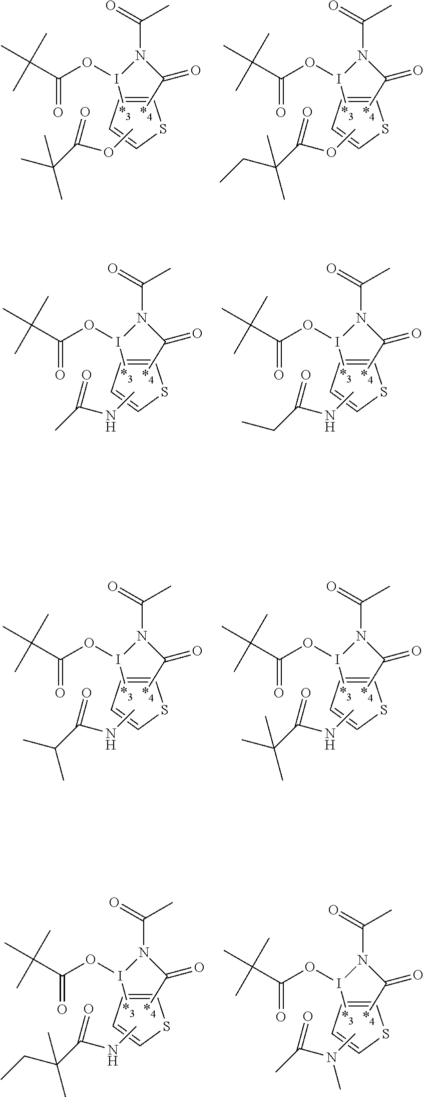

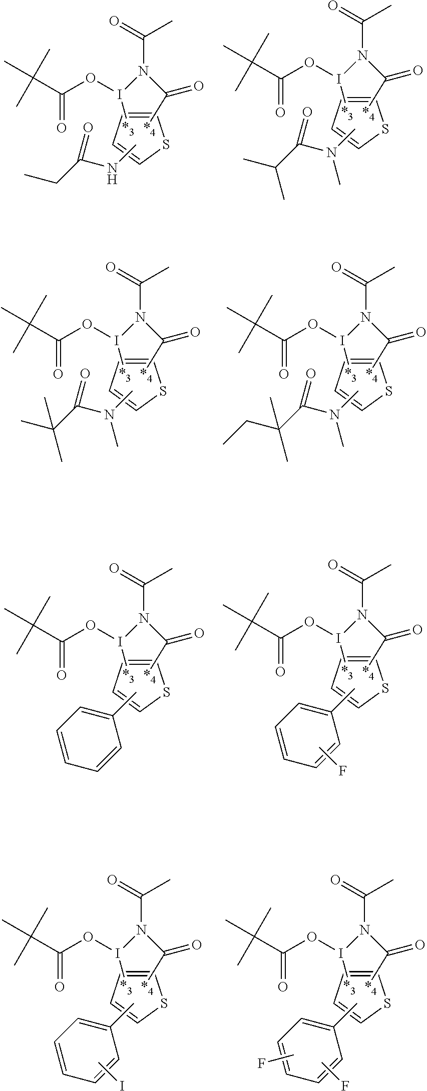

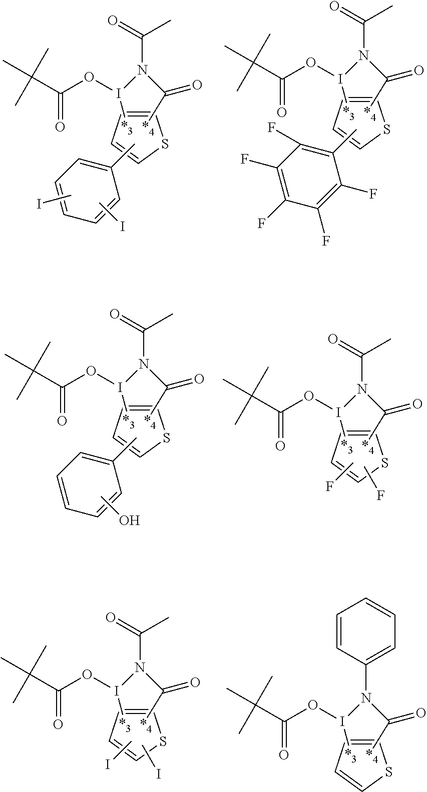

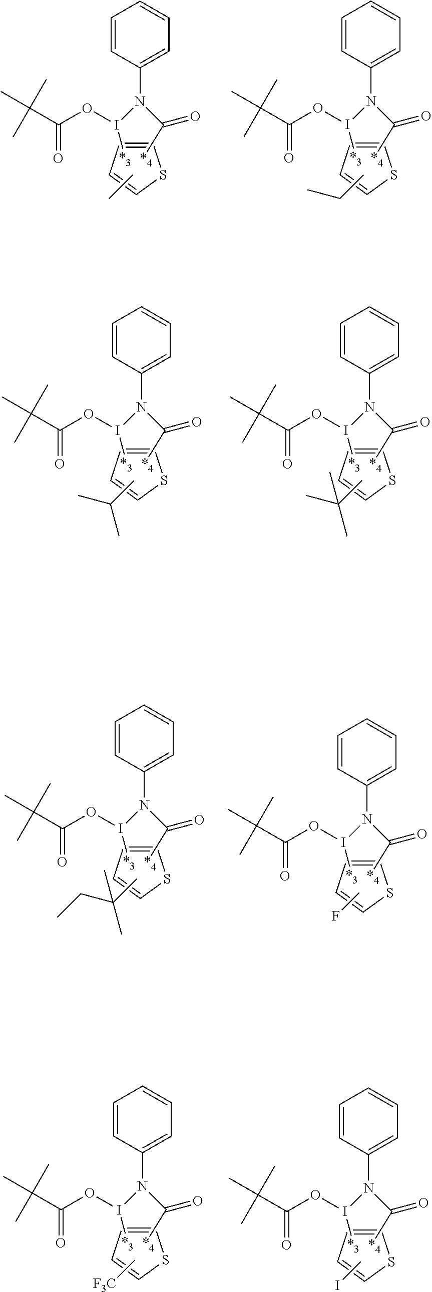

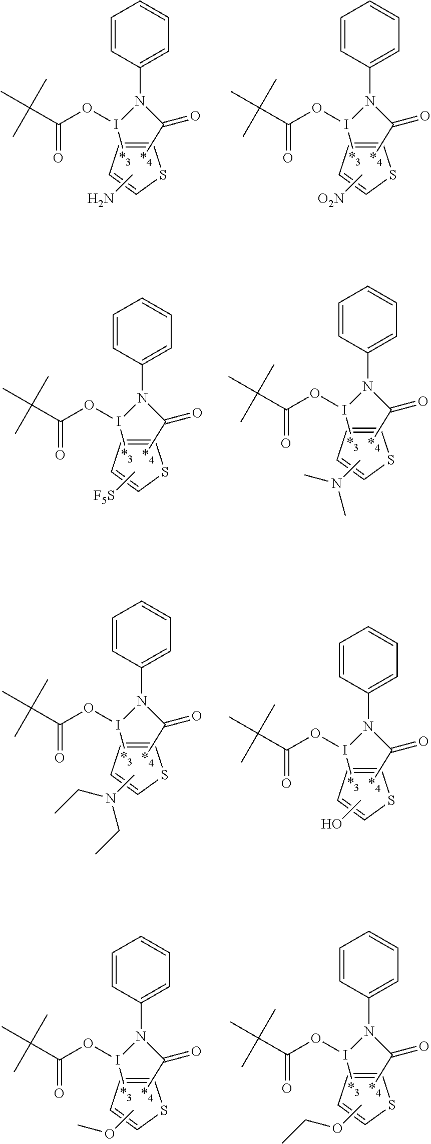

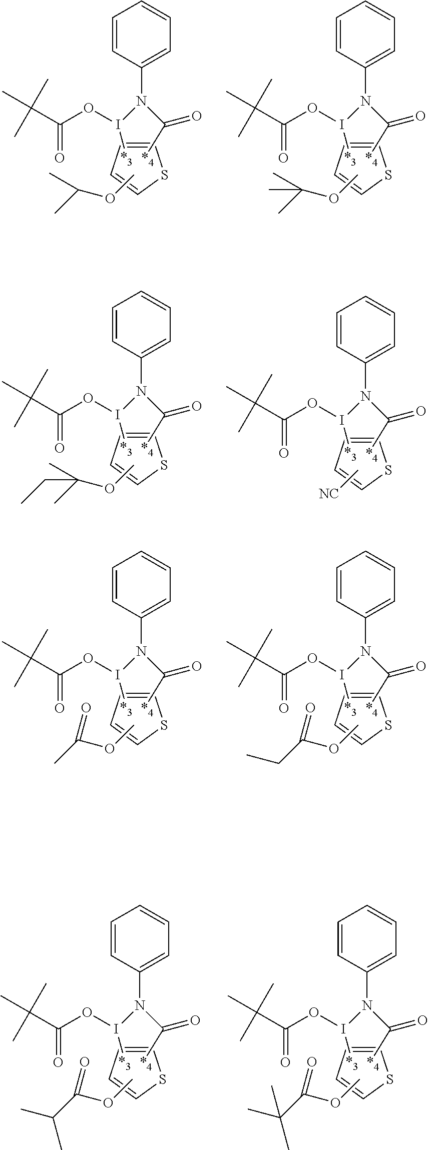

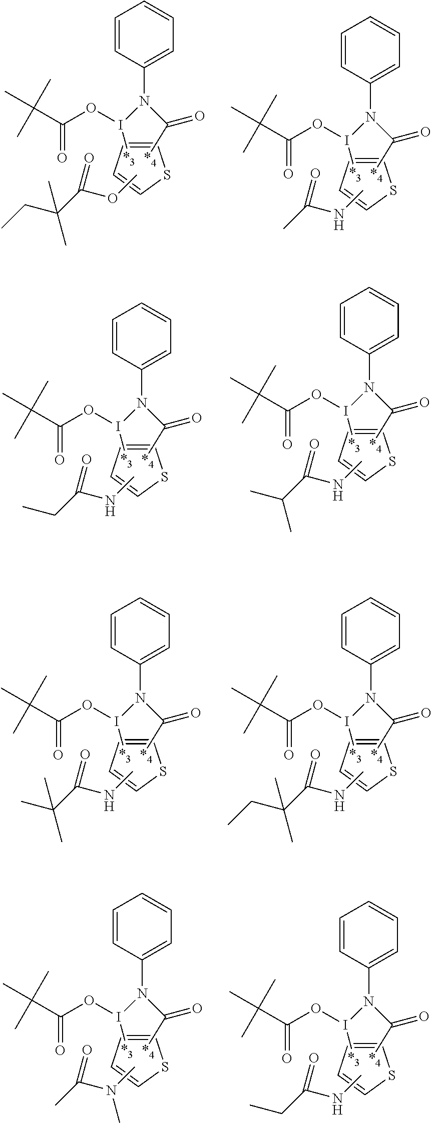

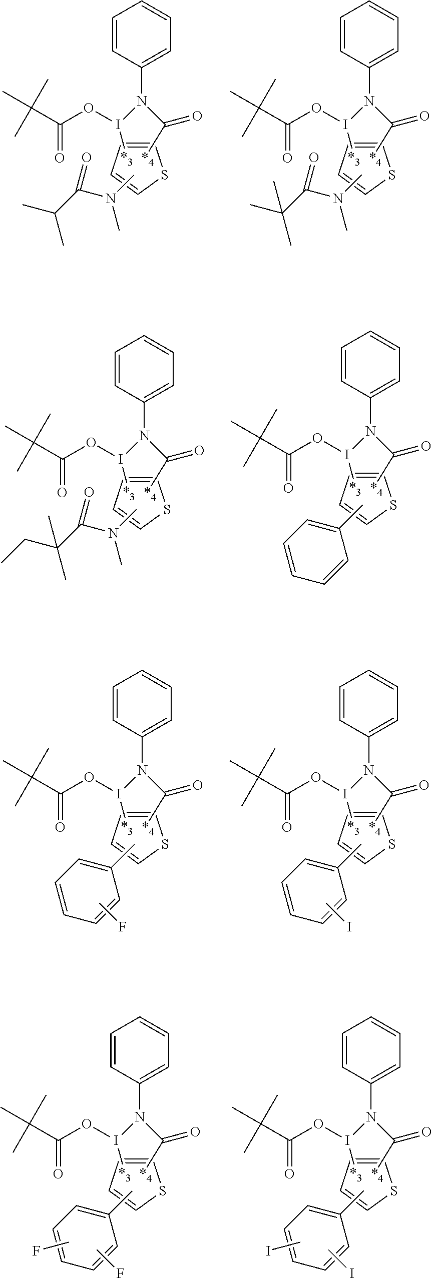

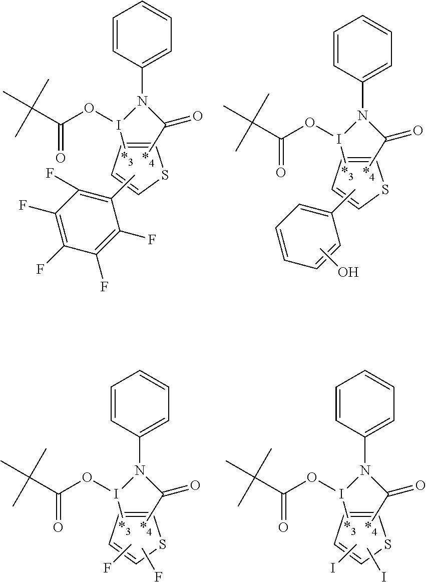

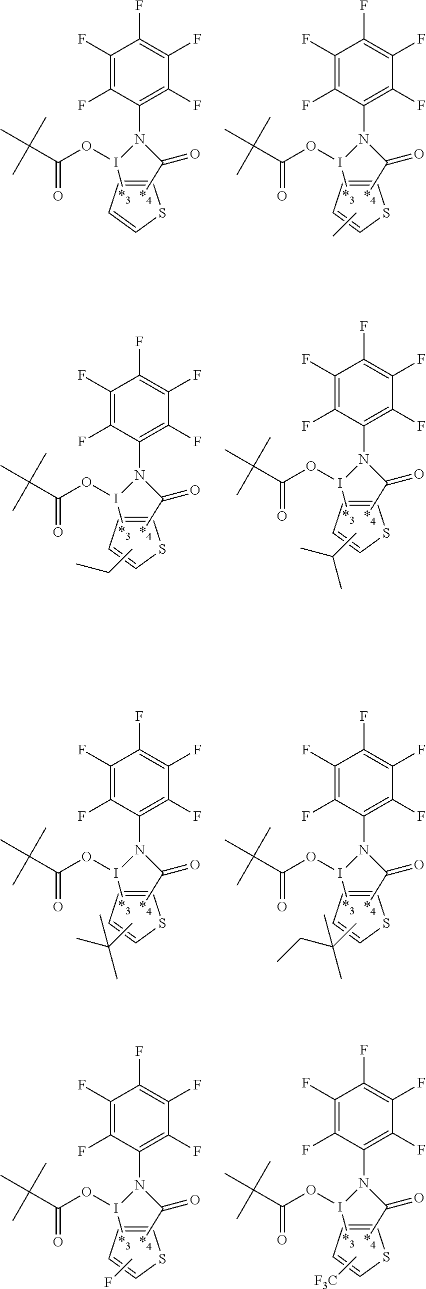

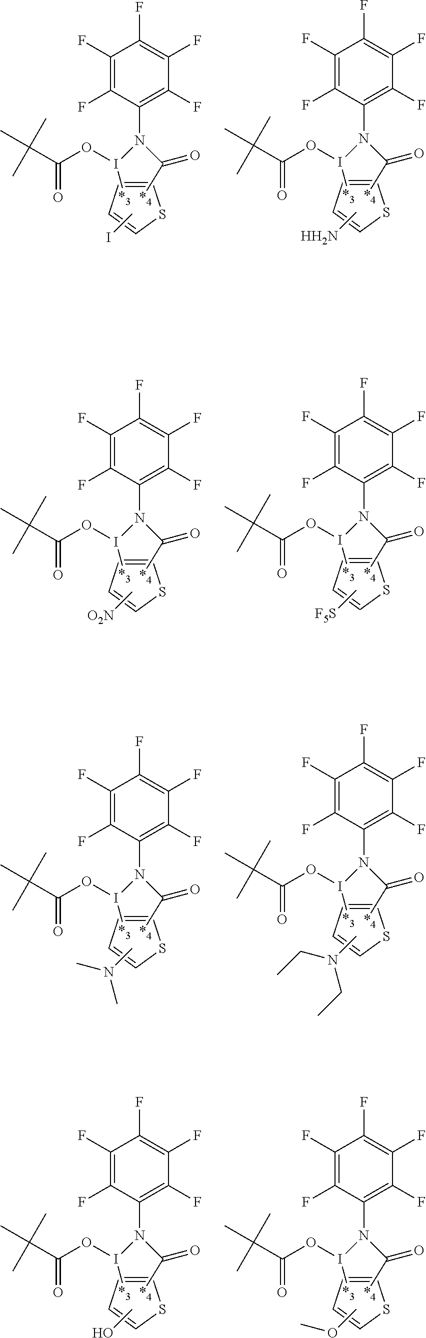

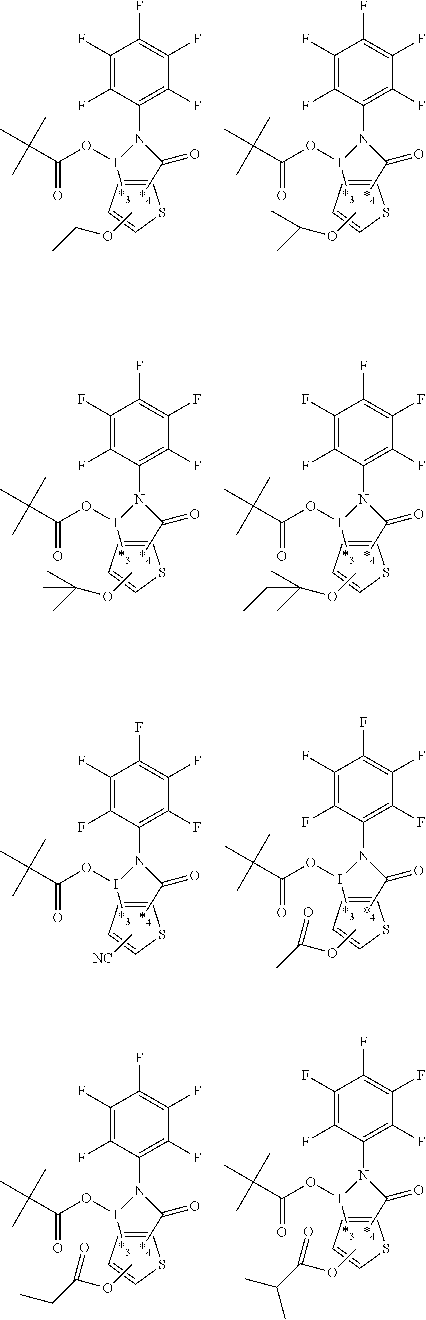

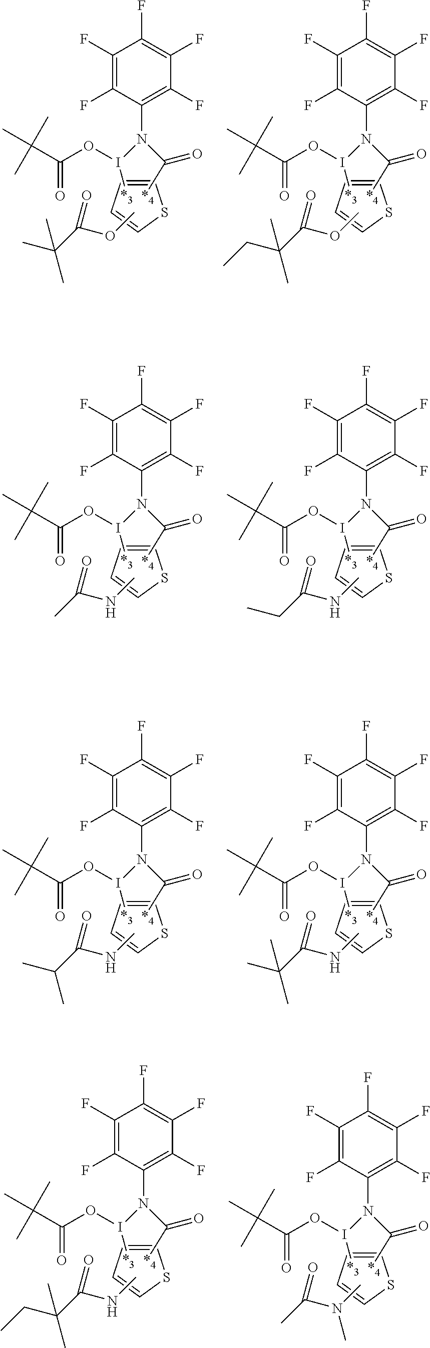

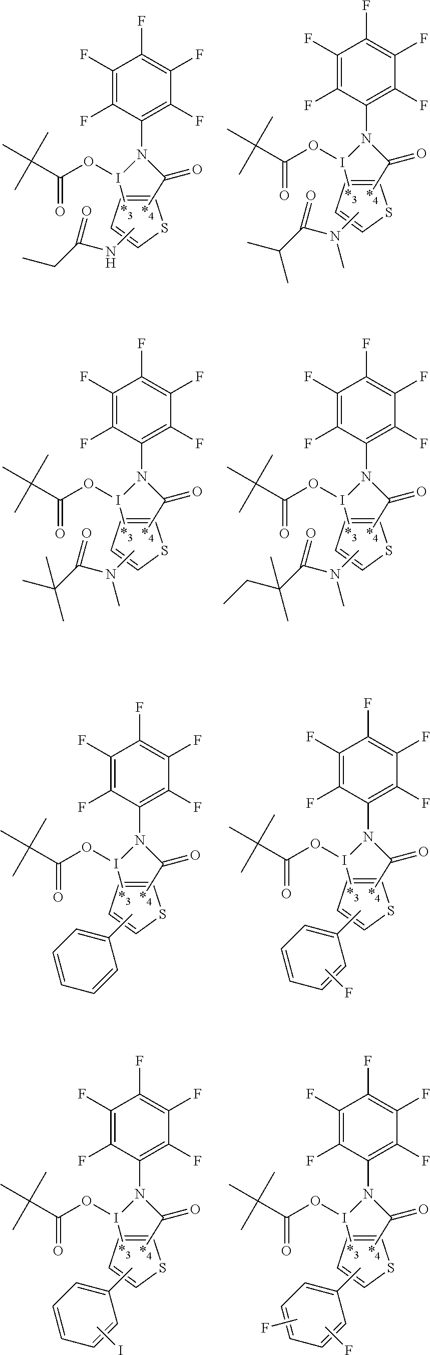

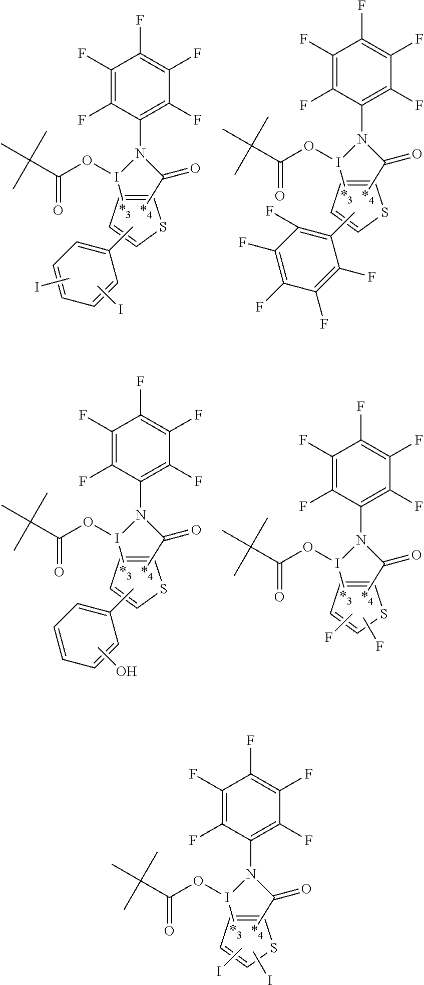

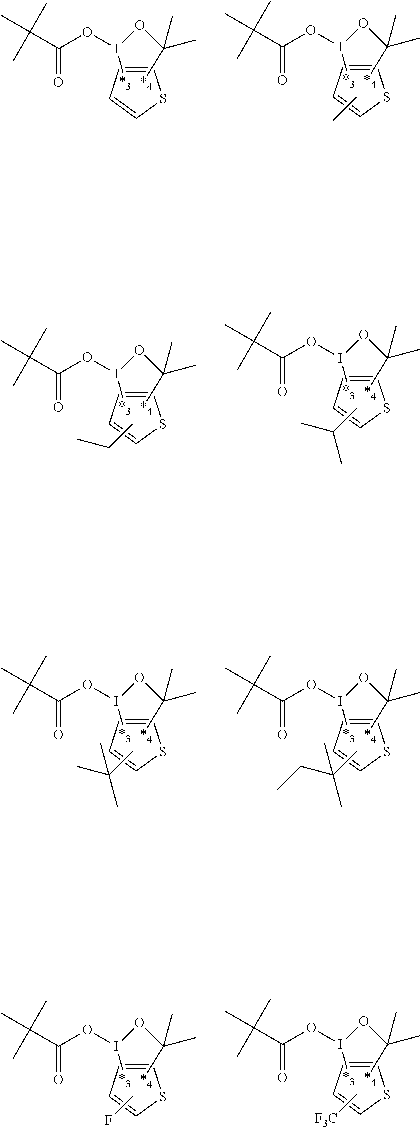

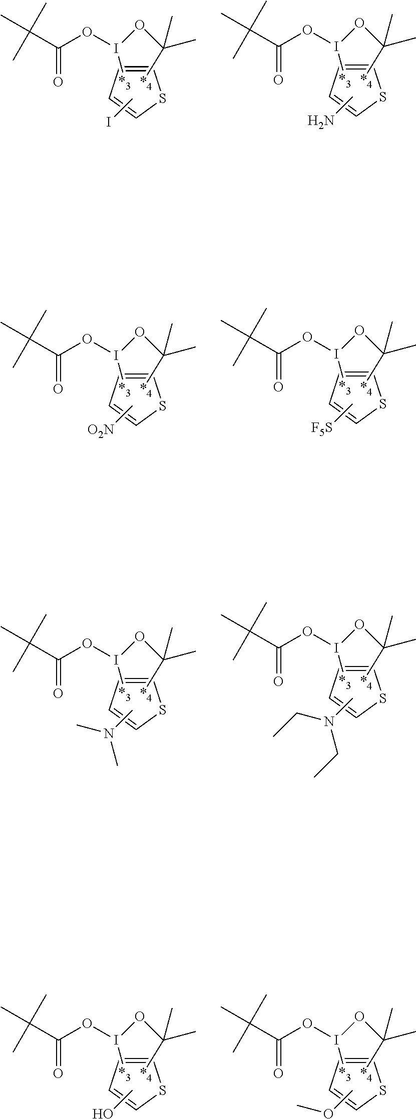

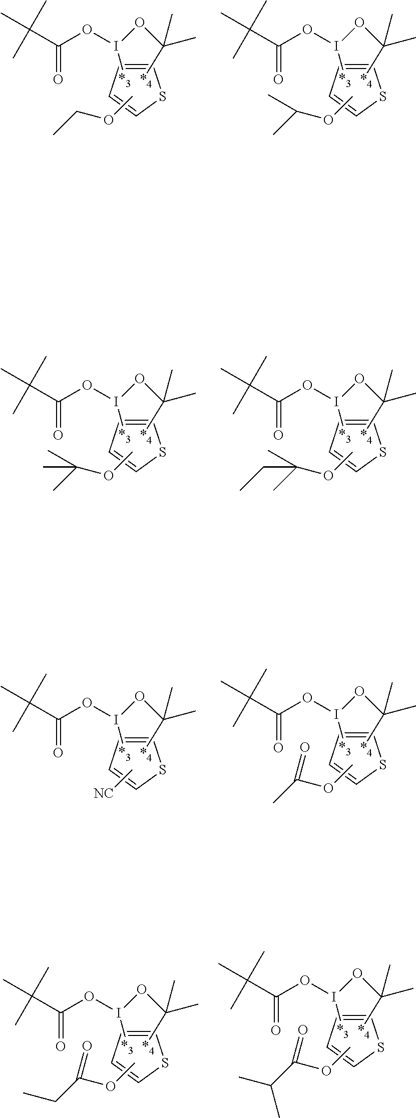

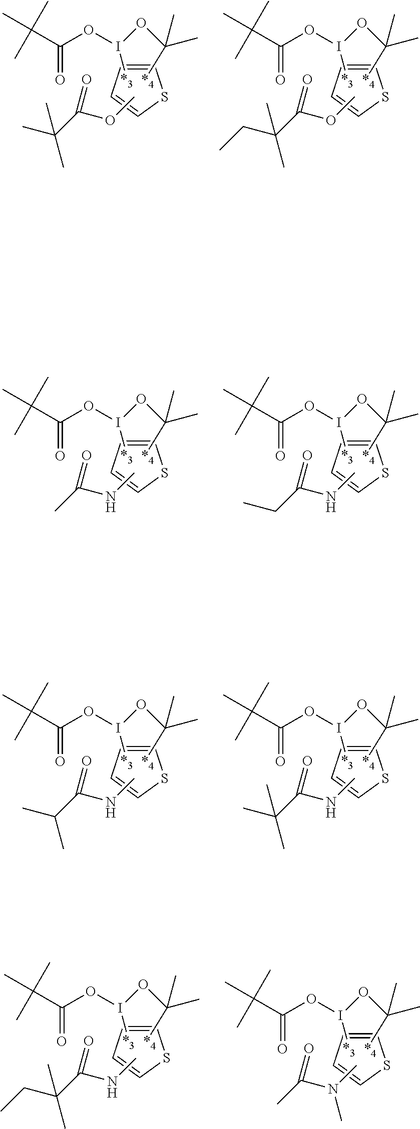

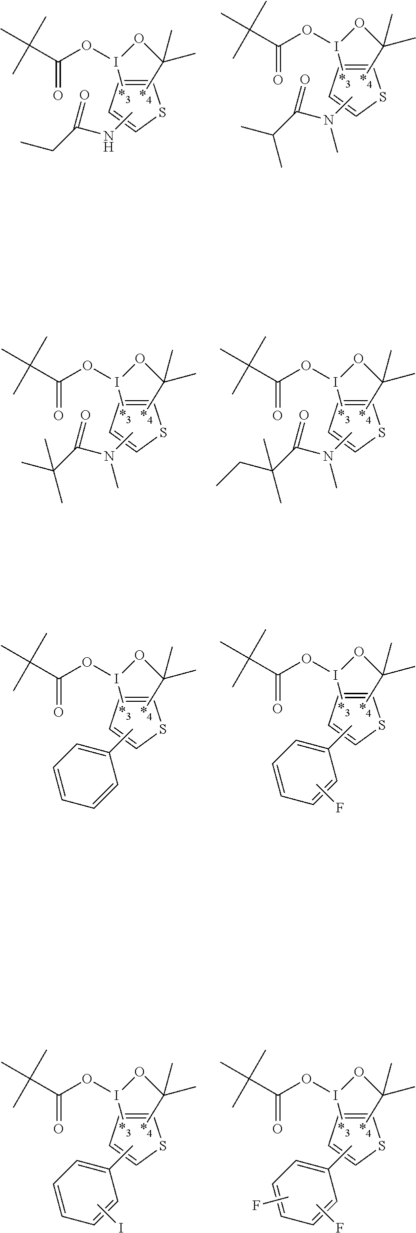

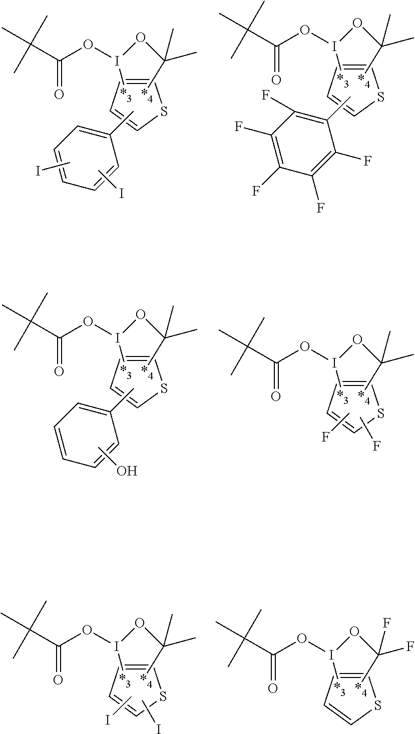

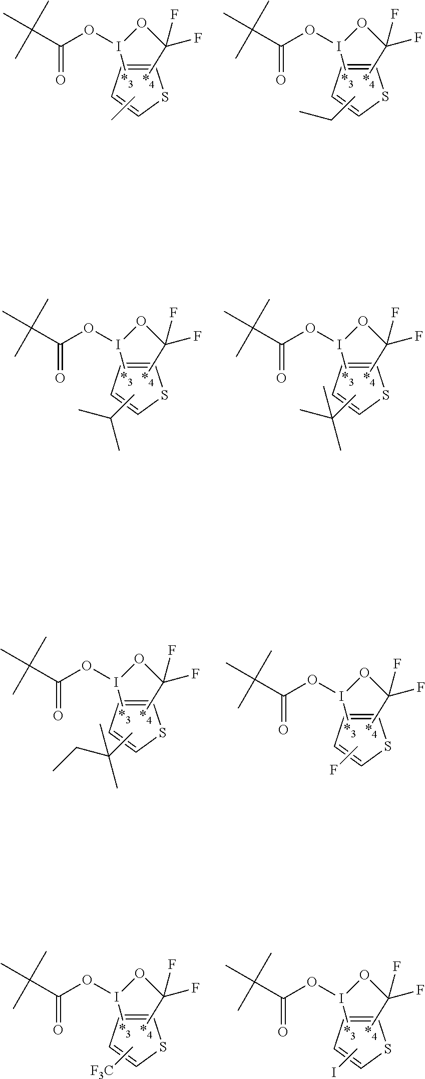

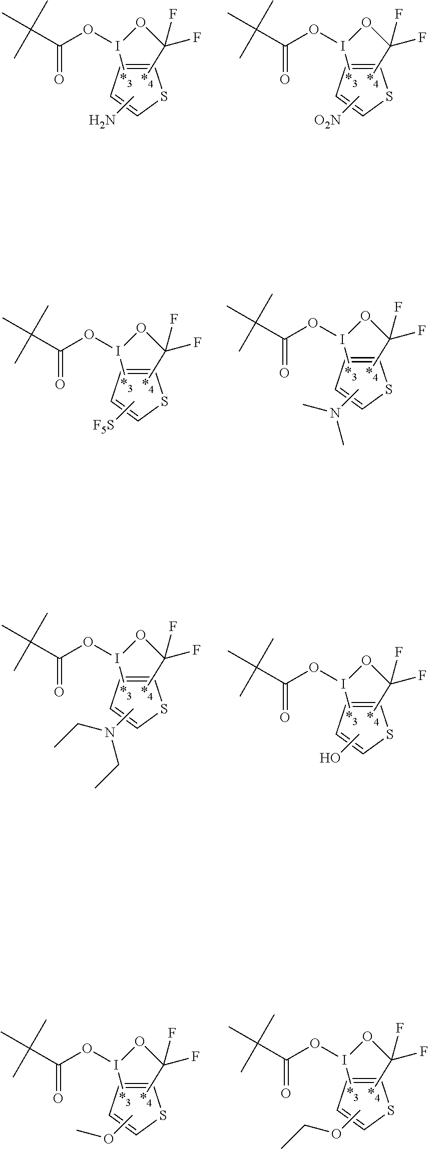

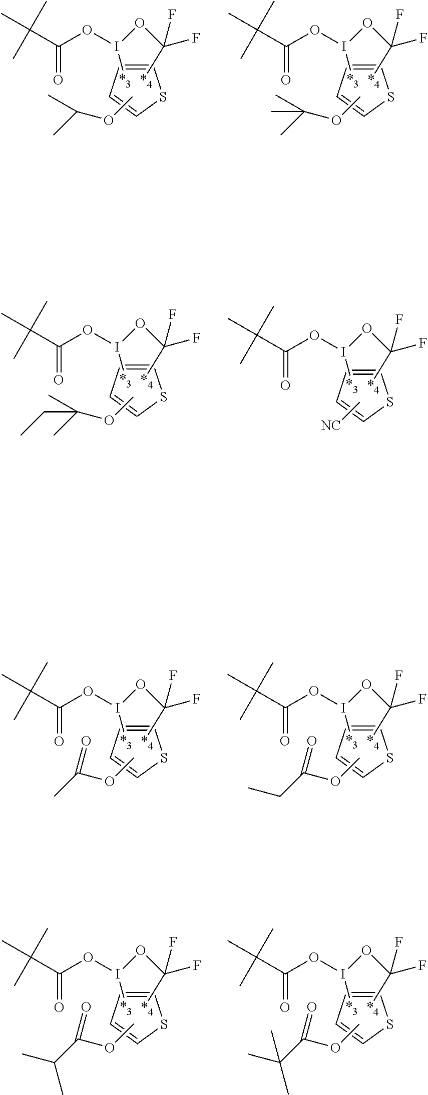

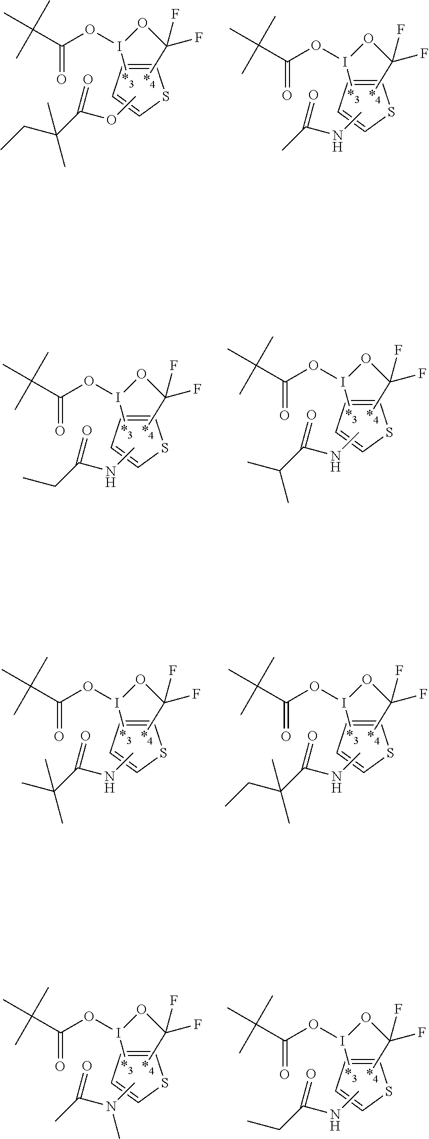

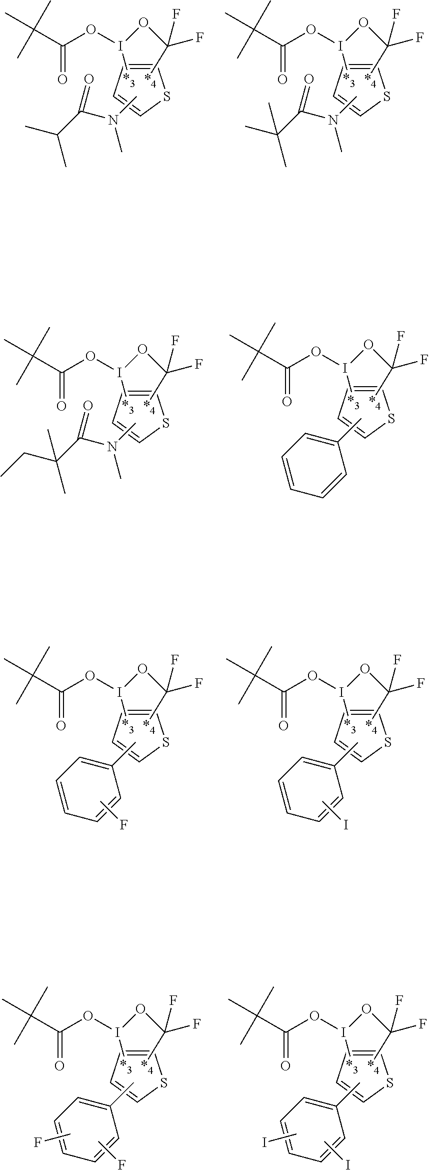

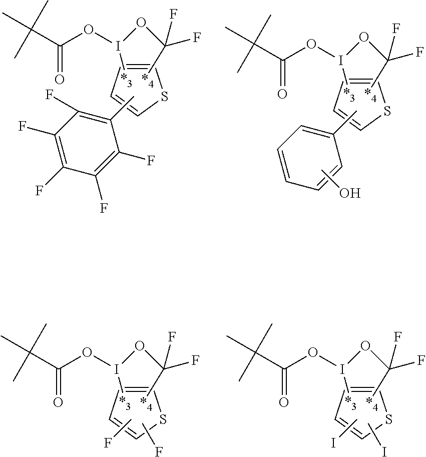

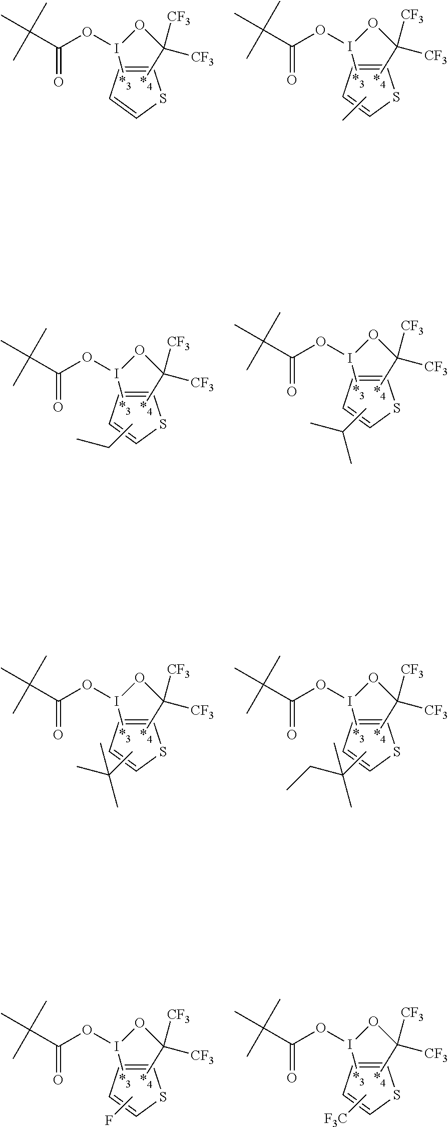

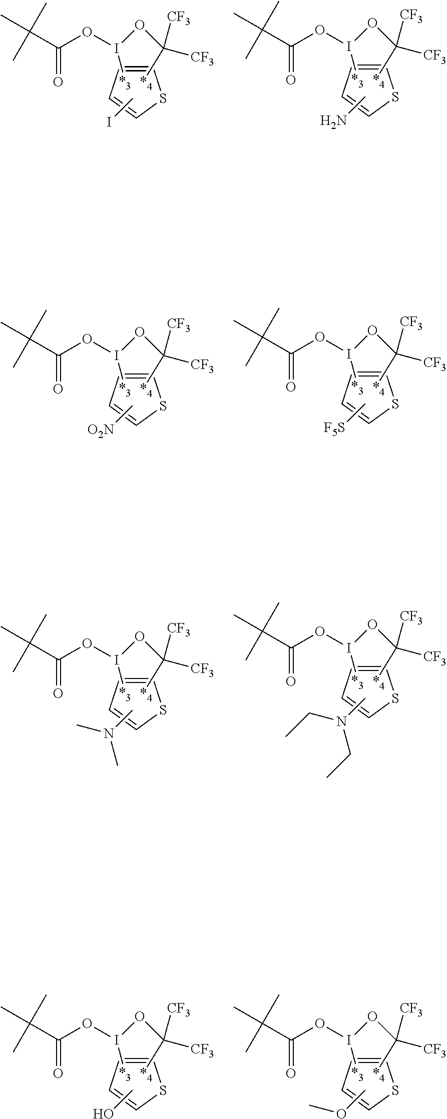

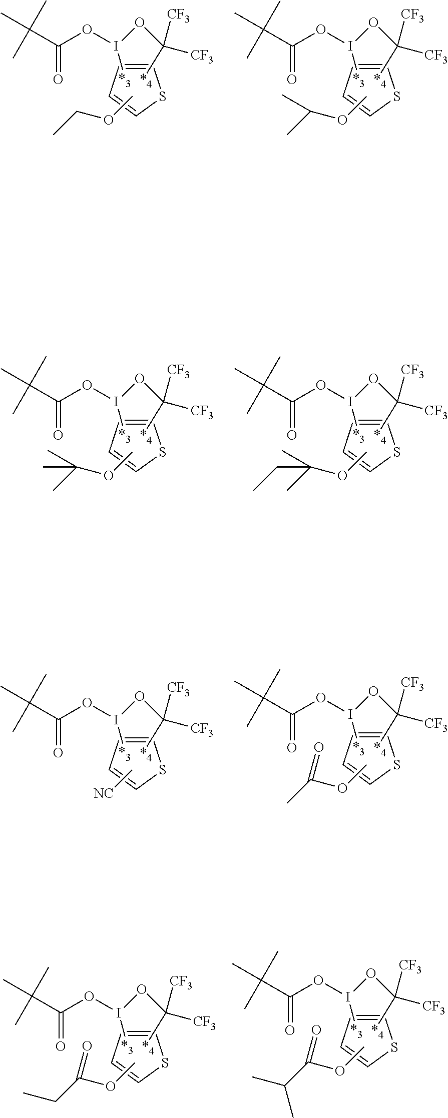

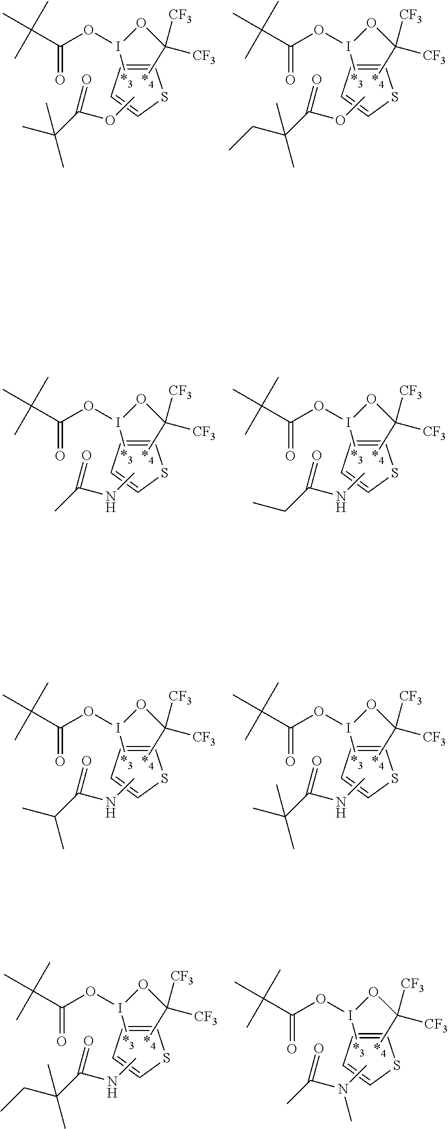

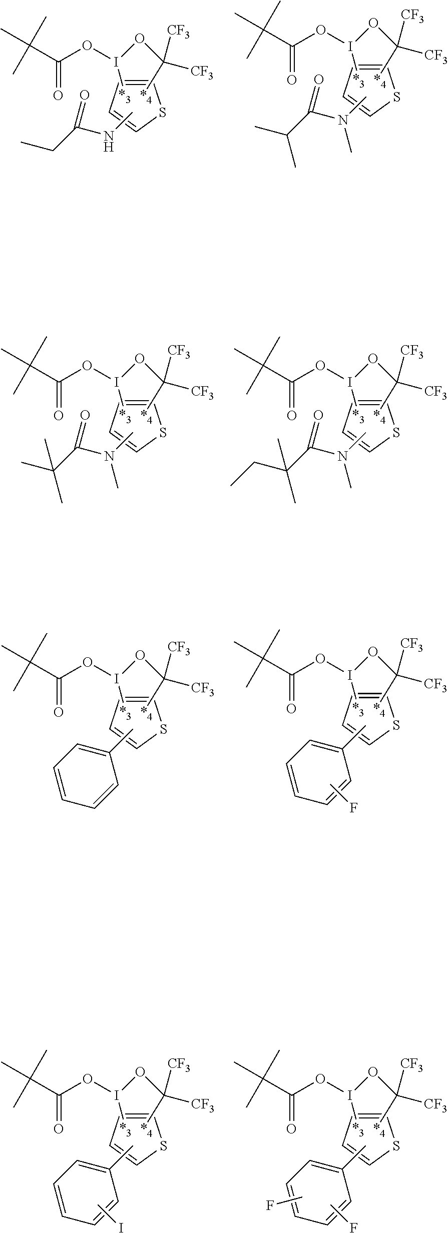

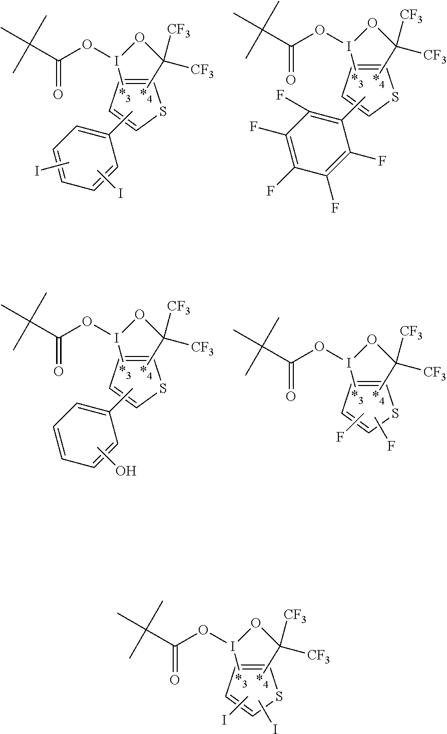

Examples of the hypervalent iodine compound having the formula (15) are shown below, but are not limited thereto. In the formulae, *5 and *6 are the same as described

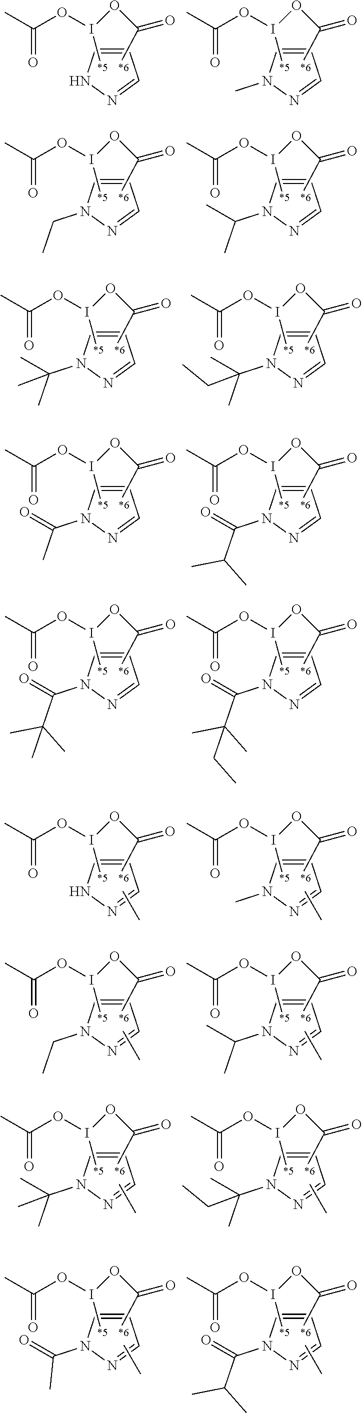

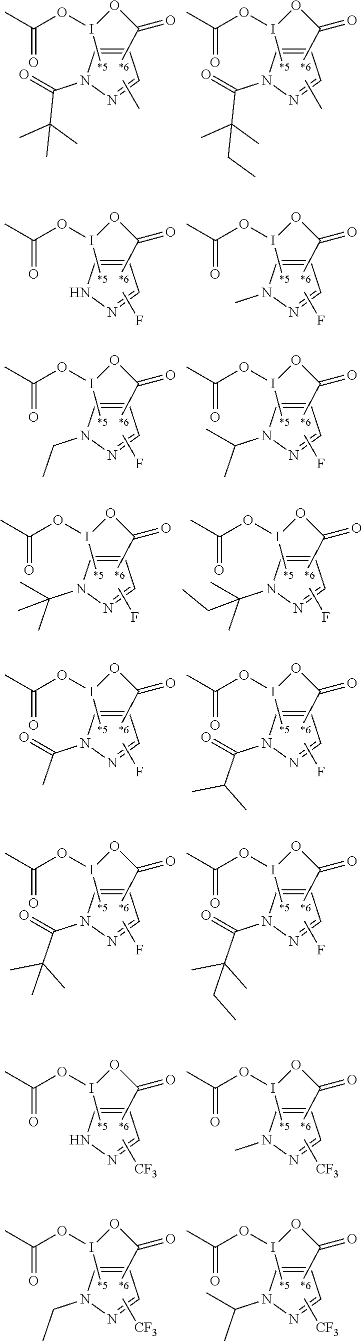

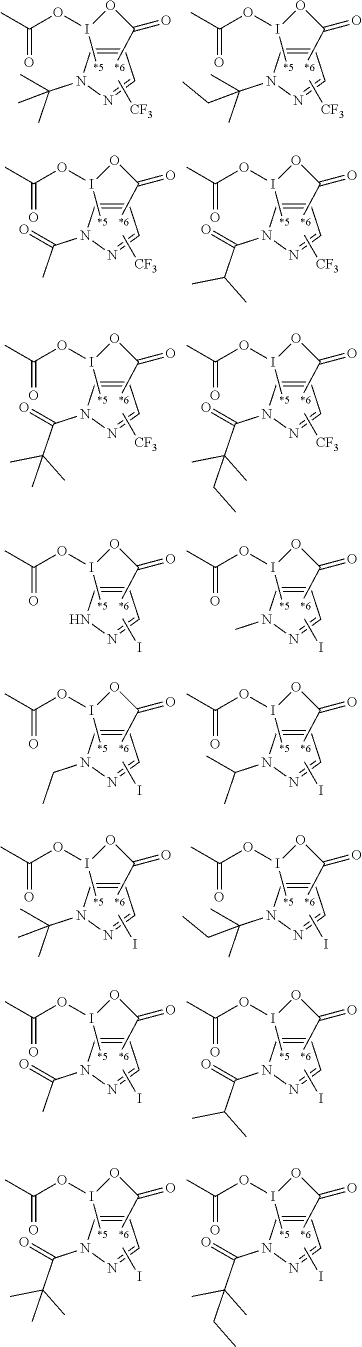

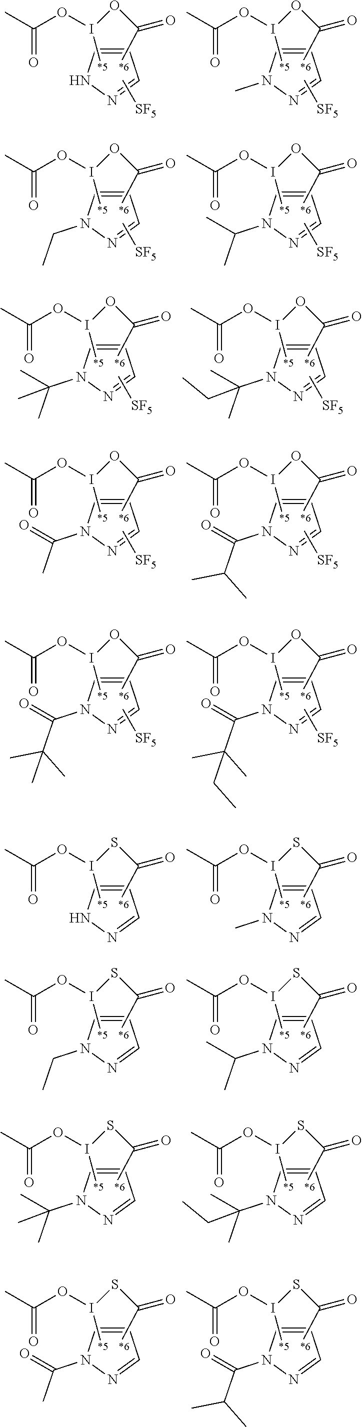

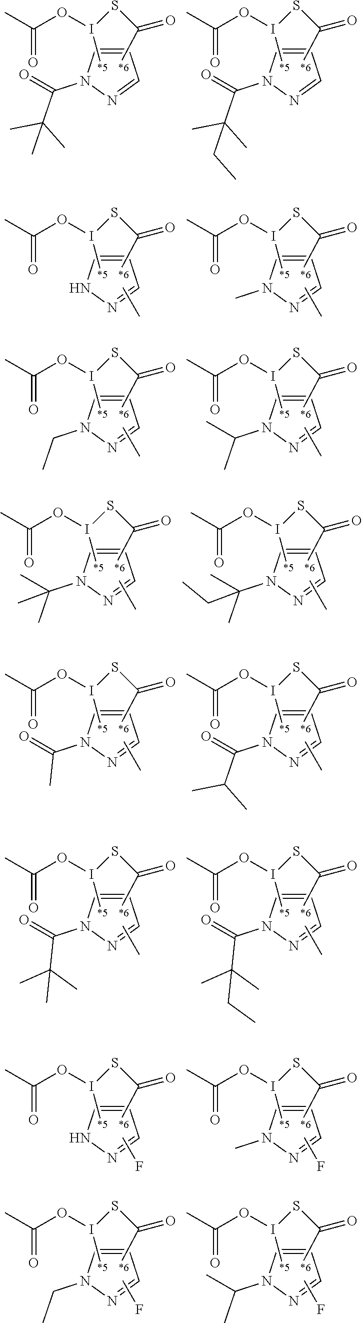

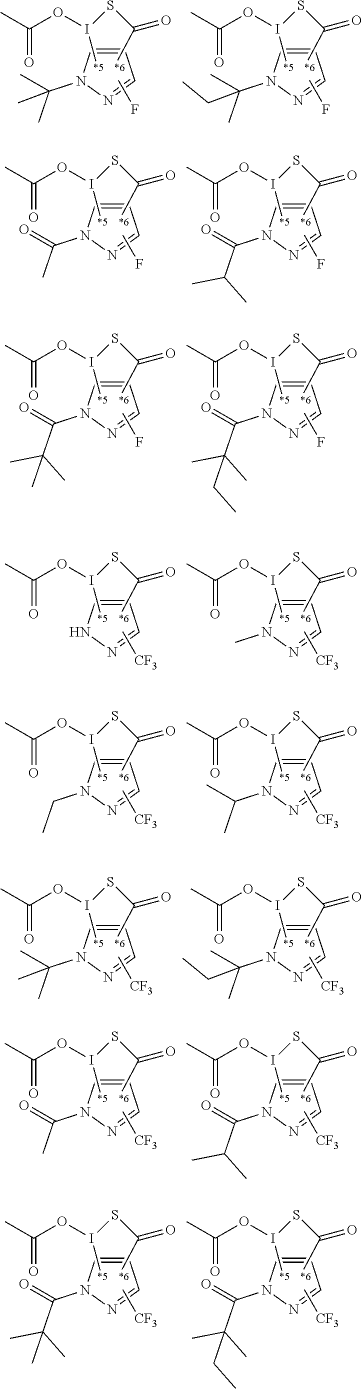

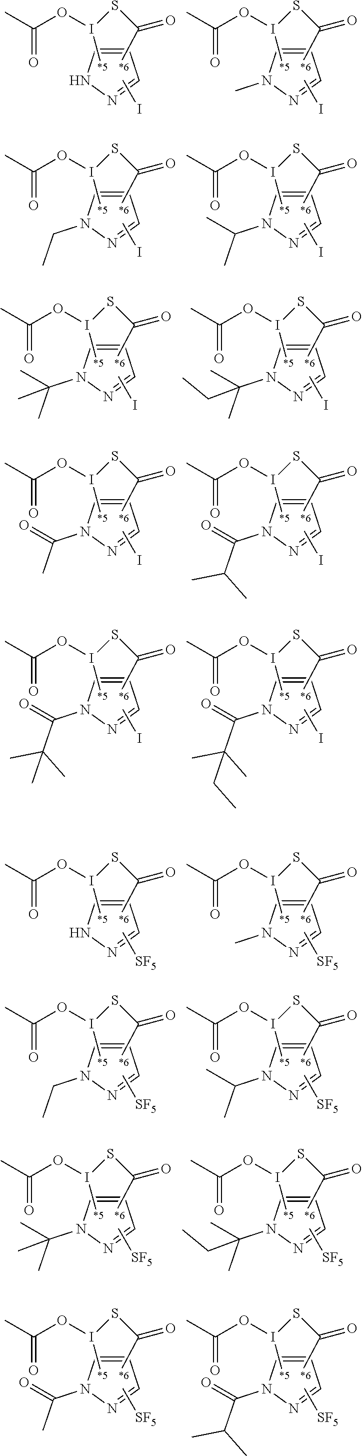

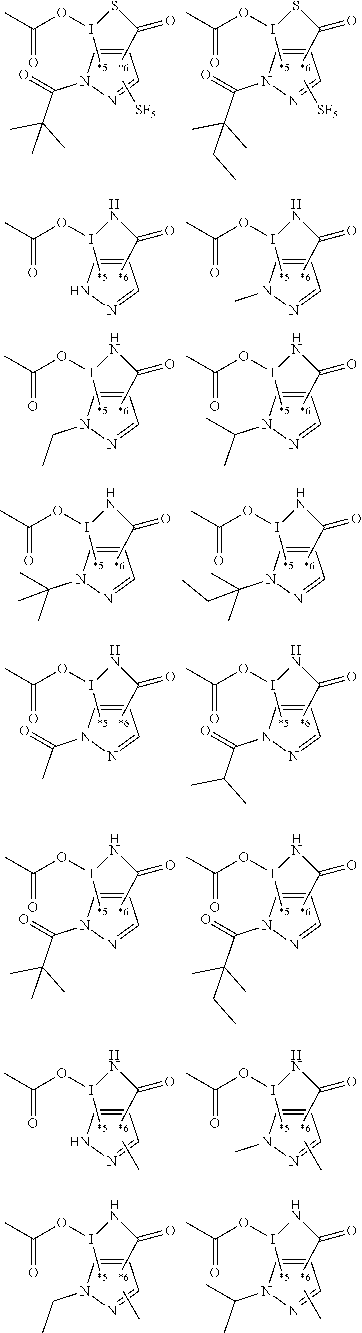

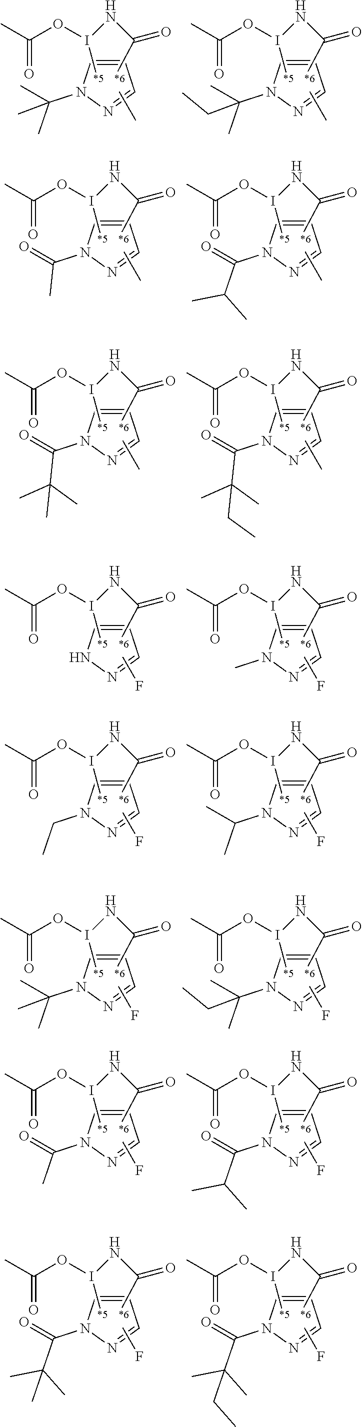

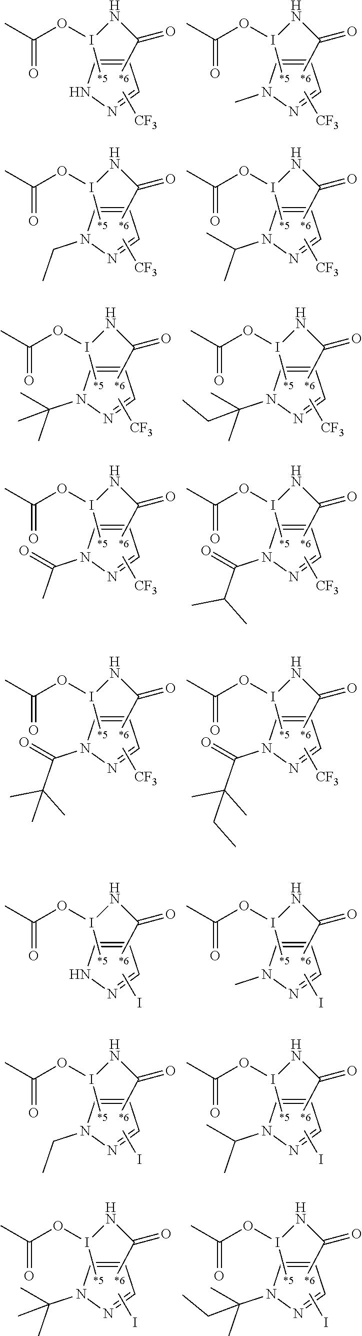

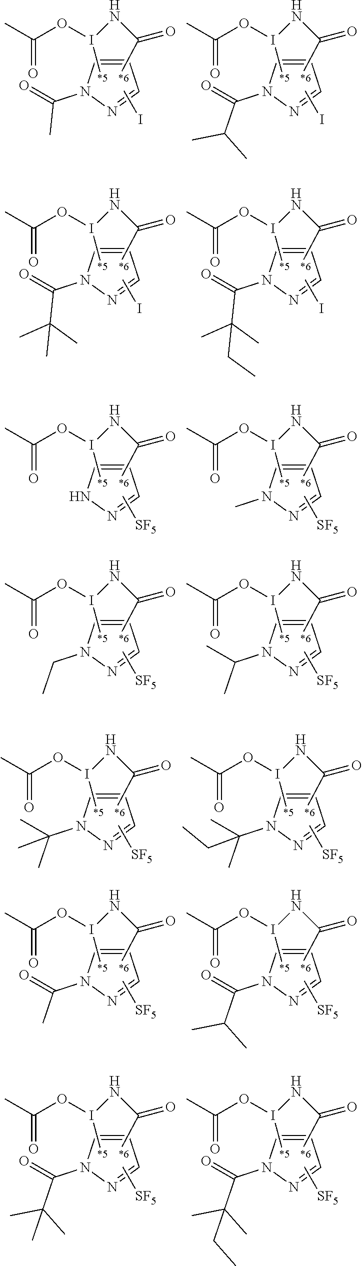

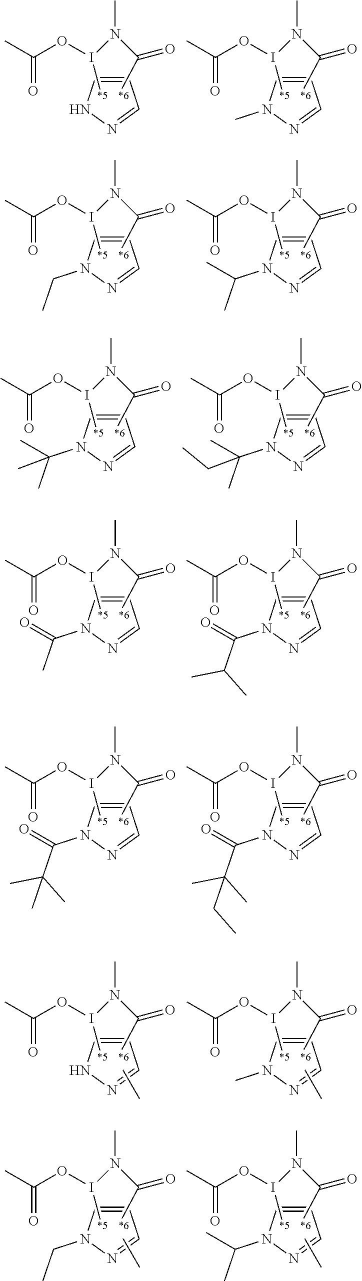

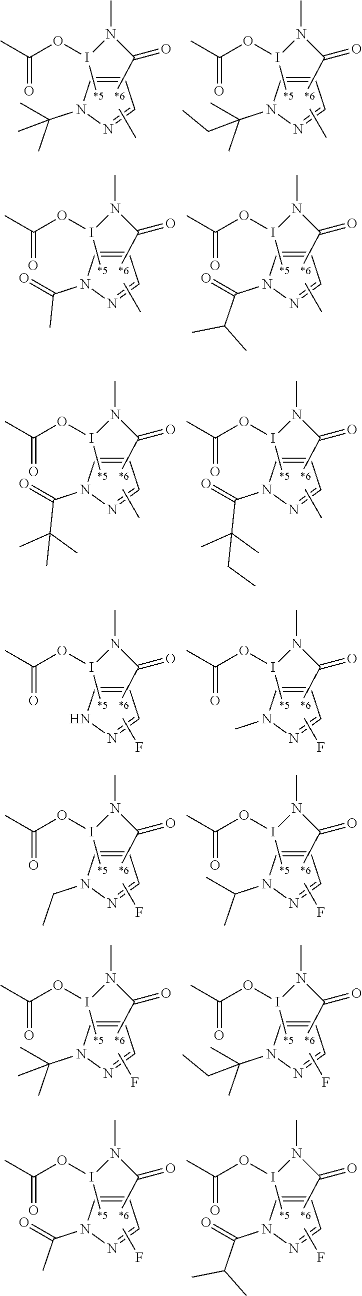

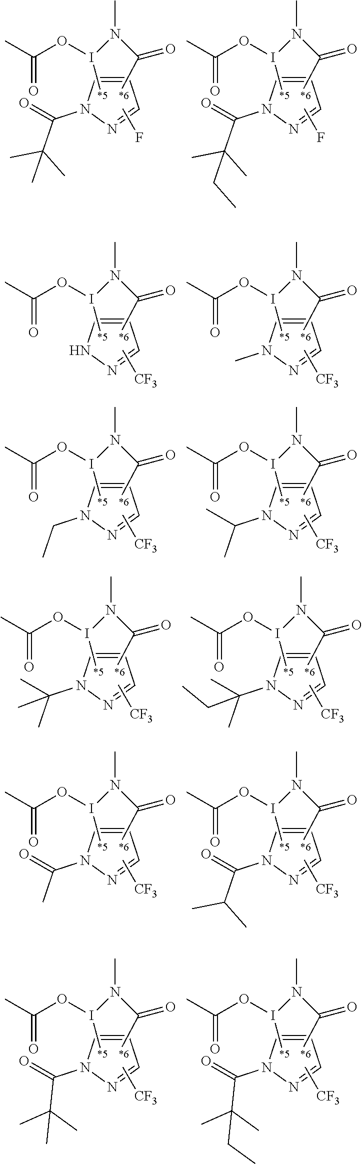

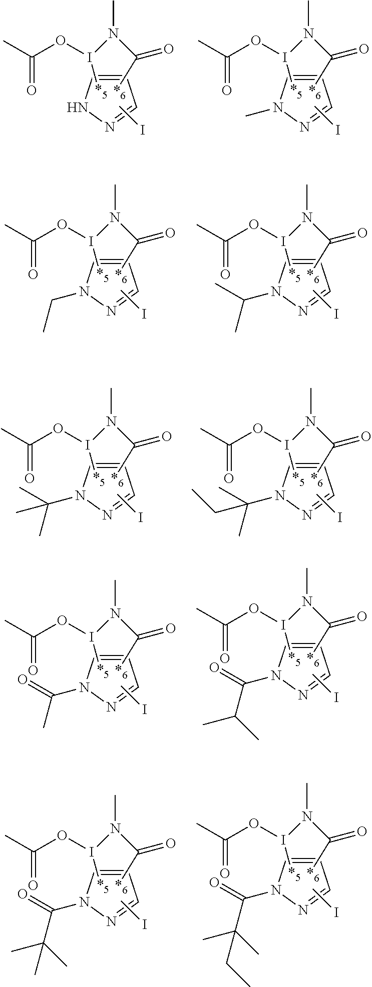

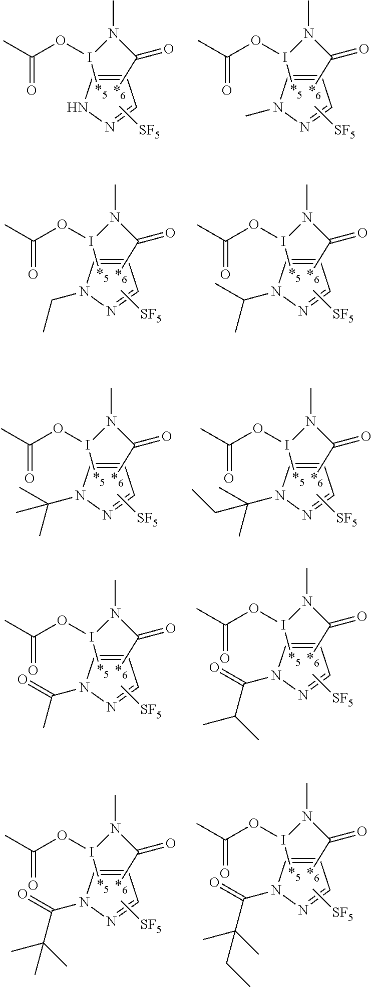

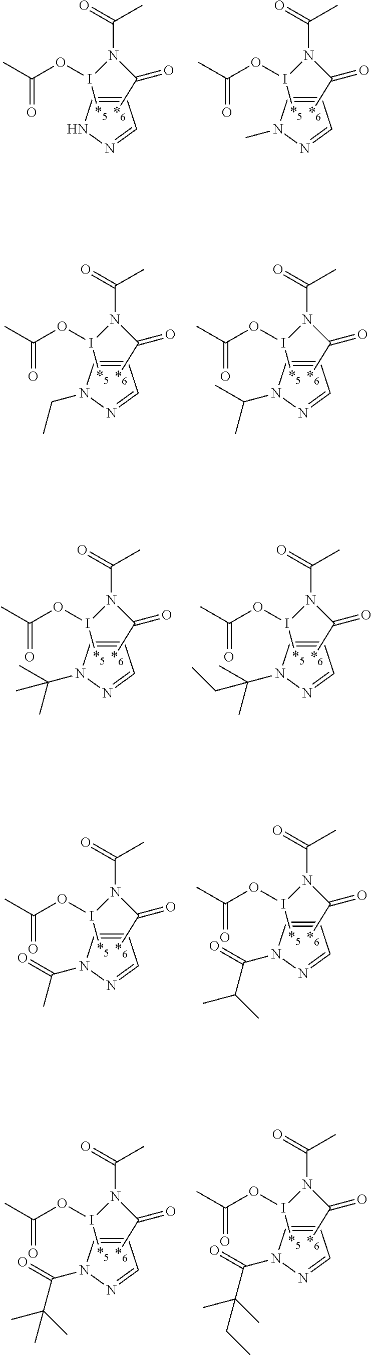

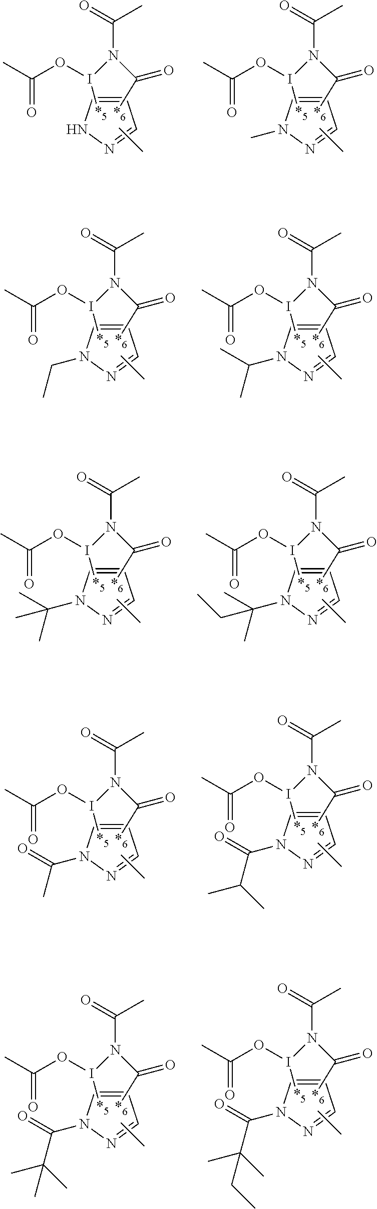

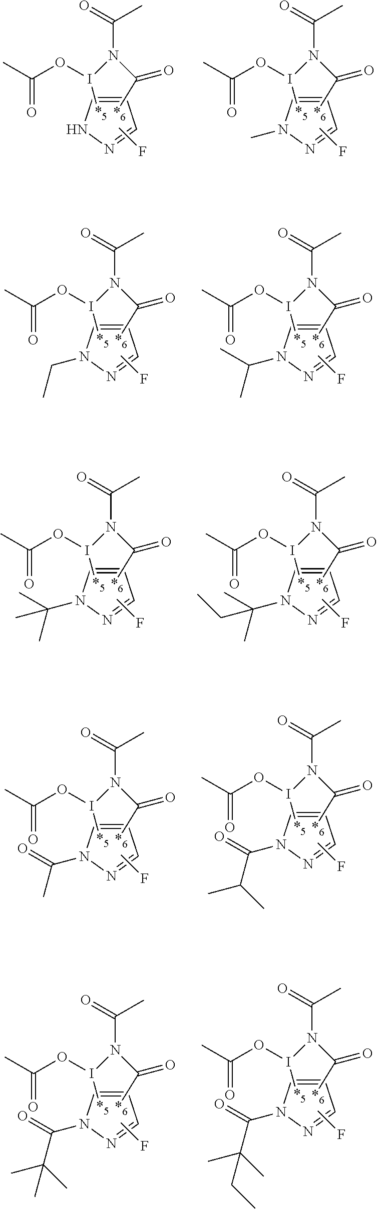

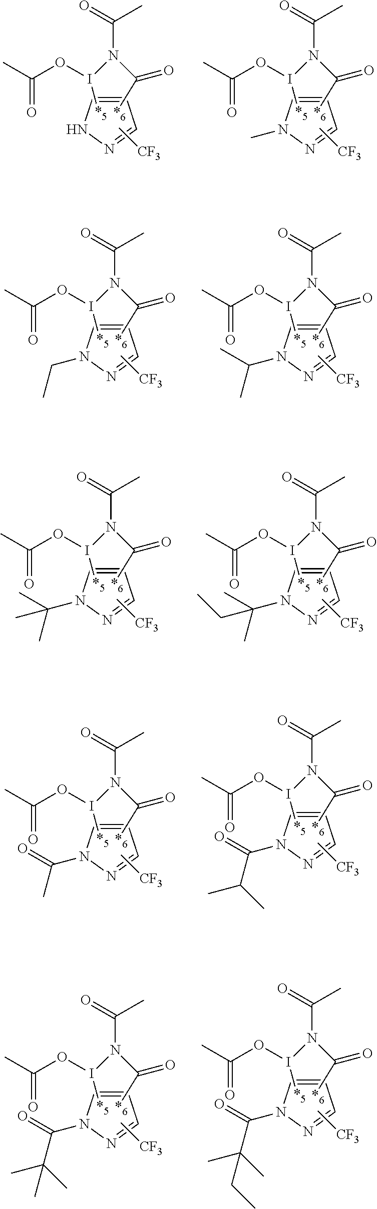

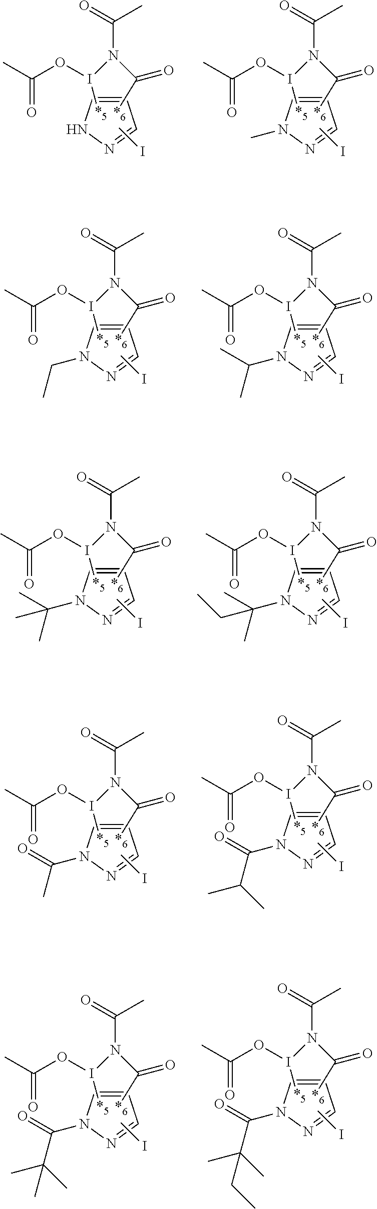

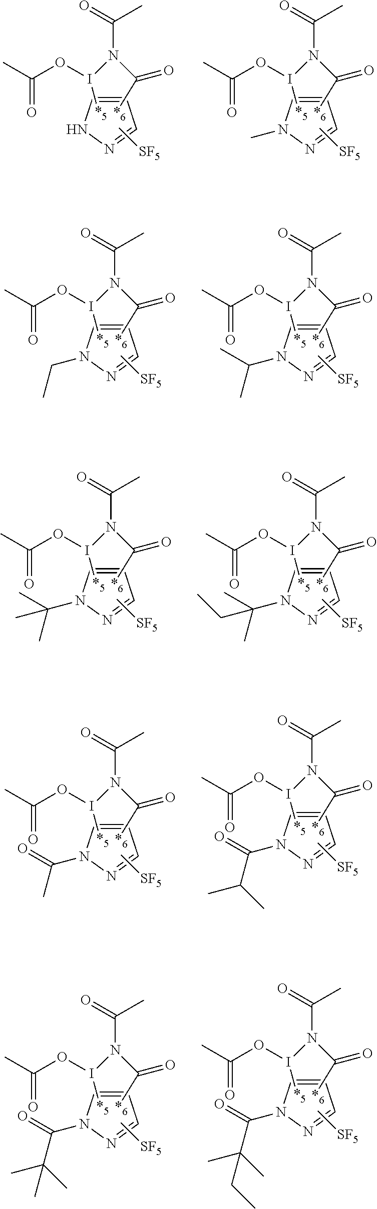

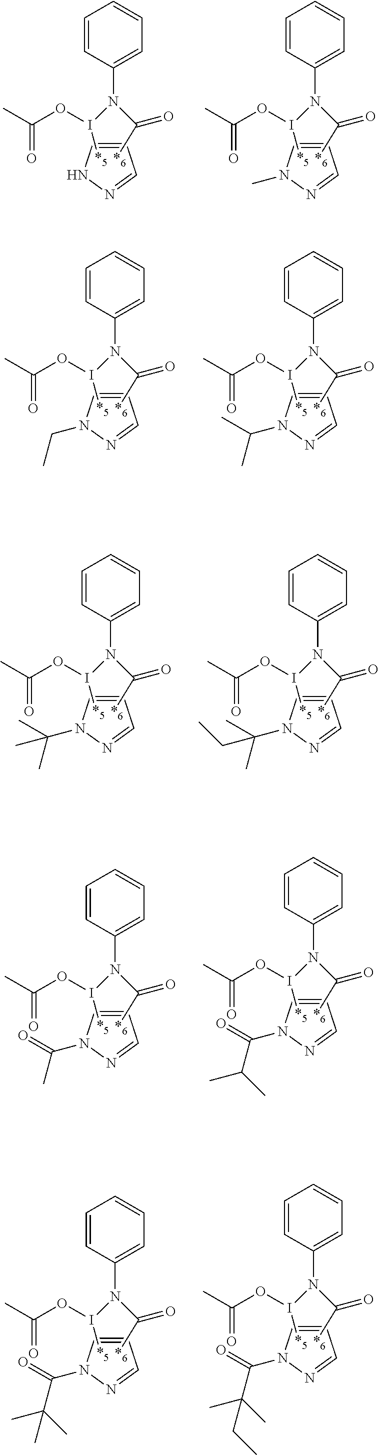

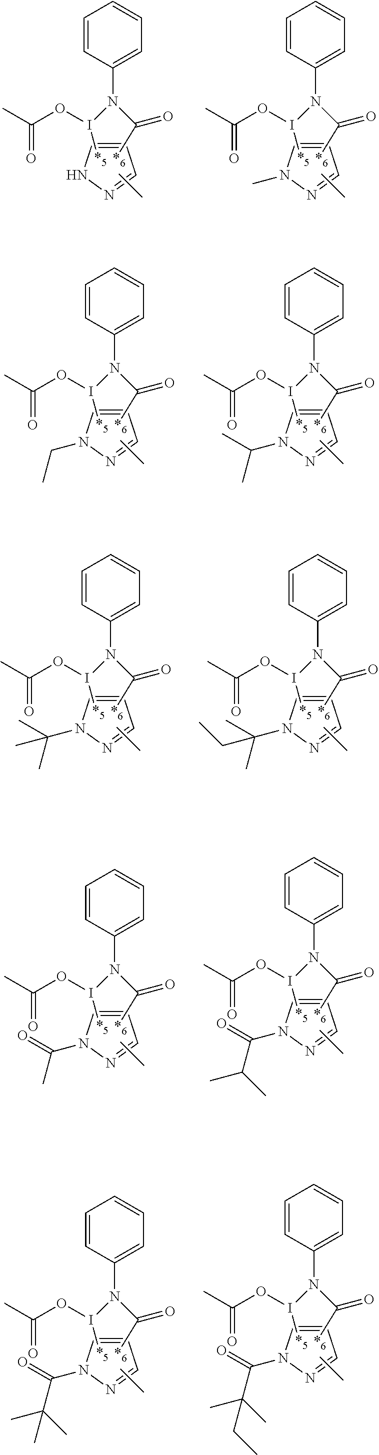

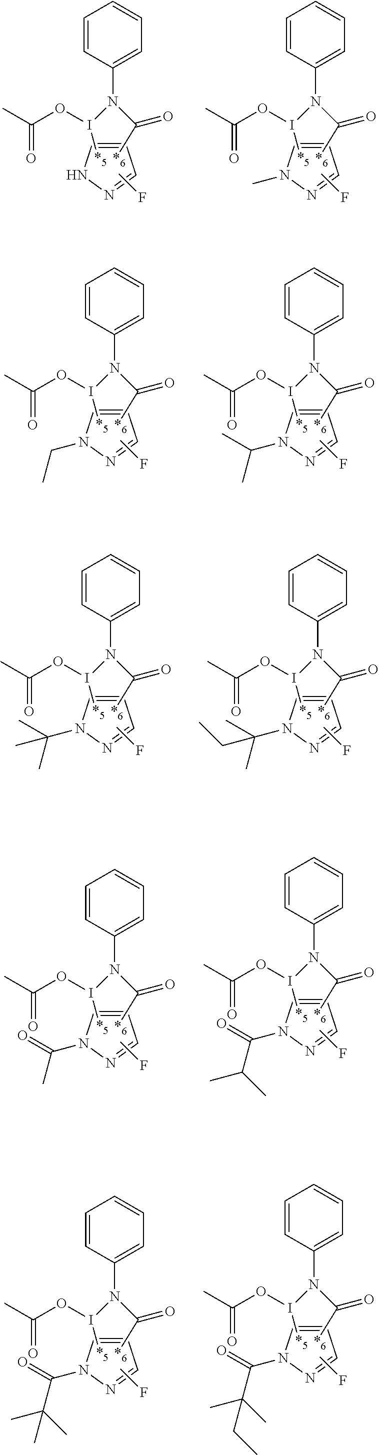

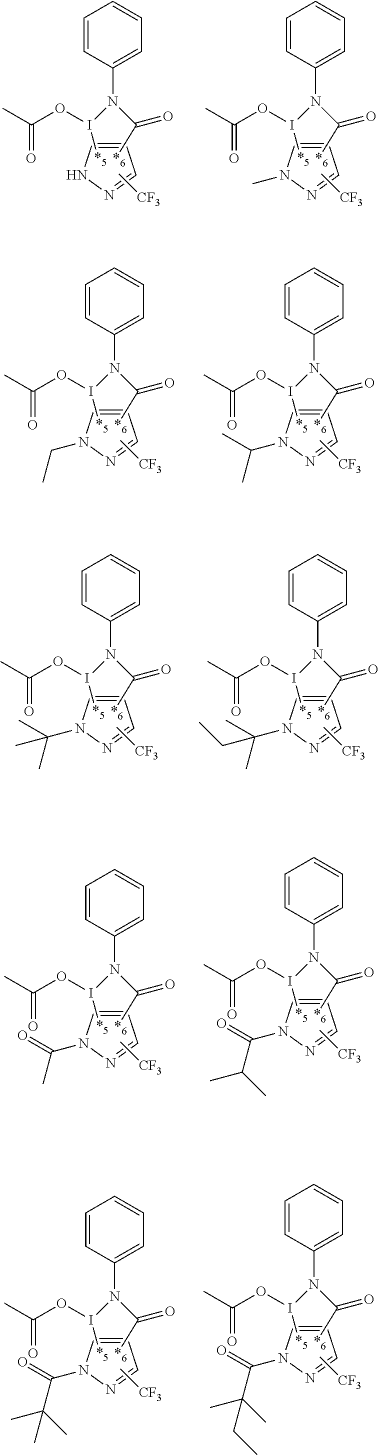

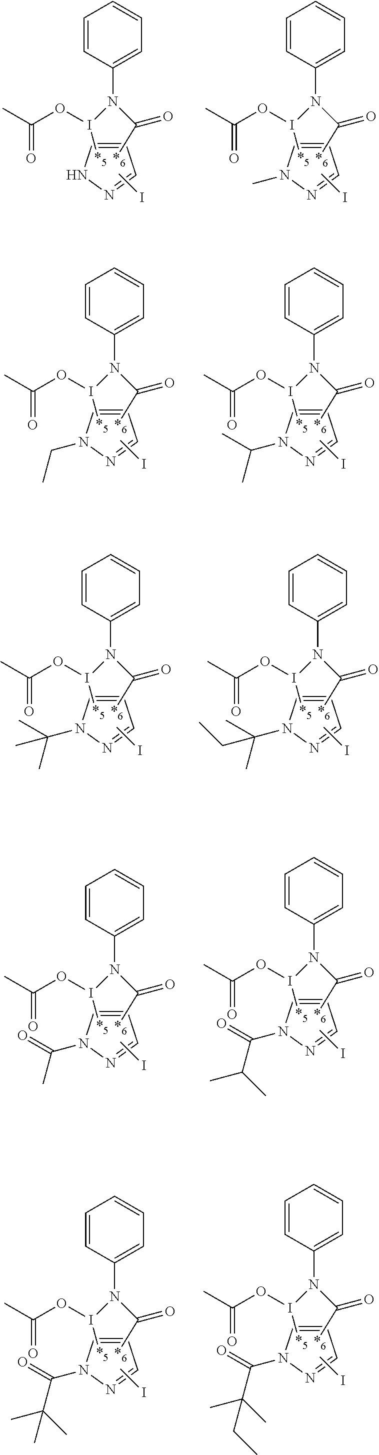

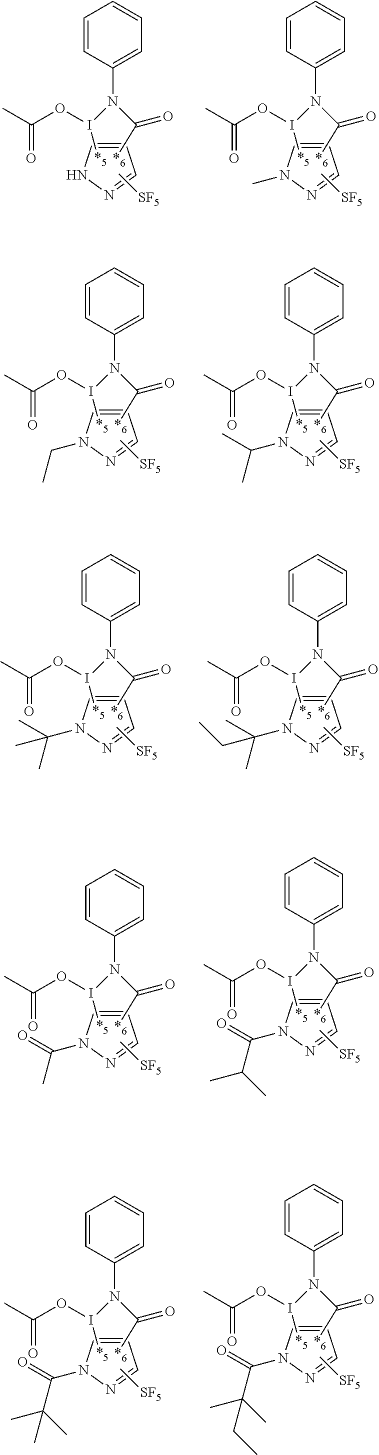

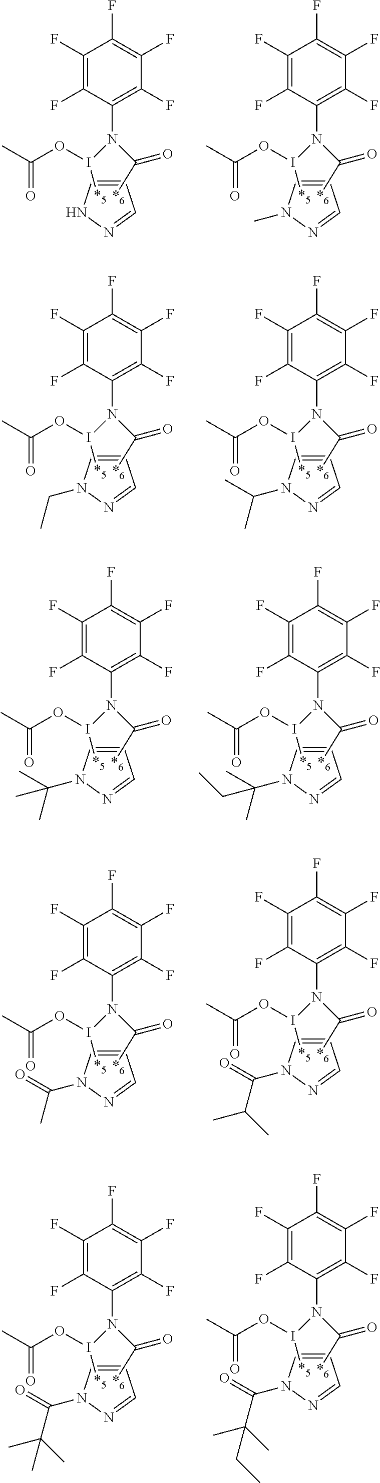

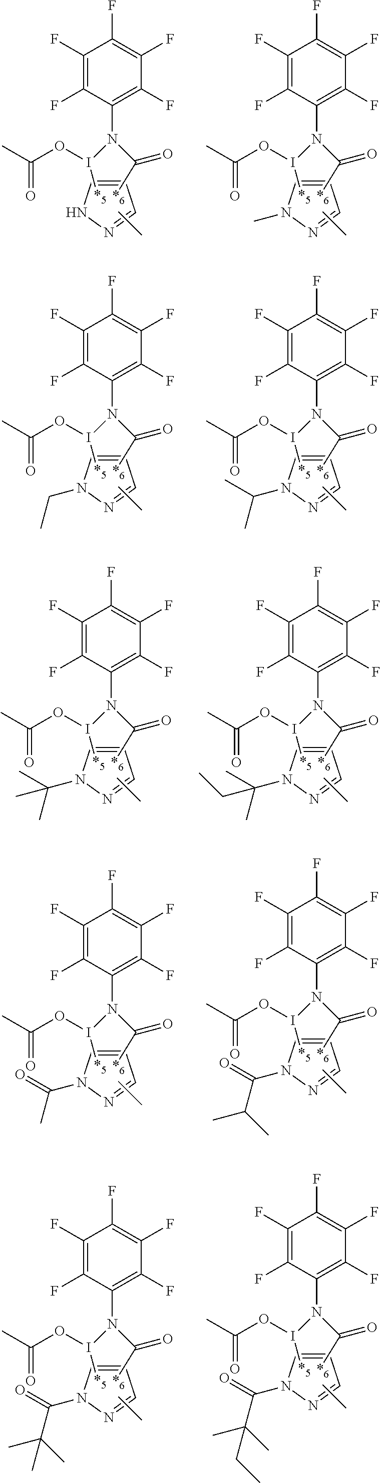

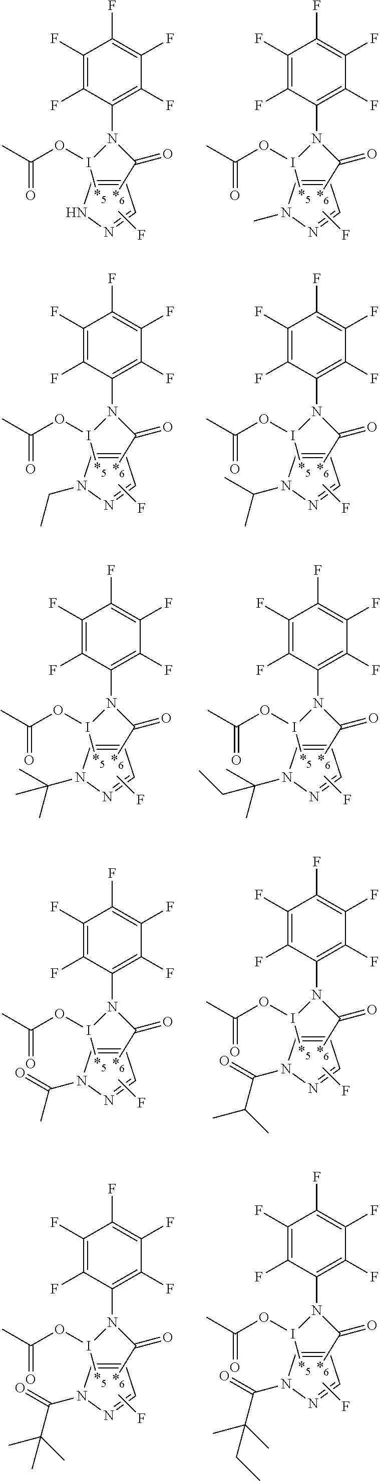

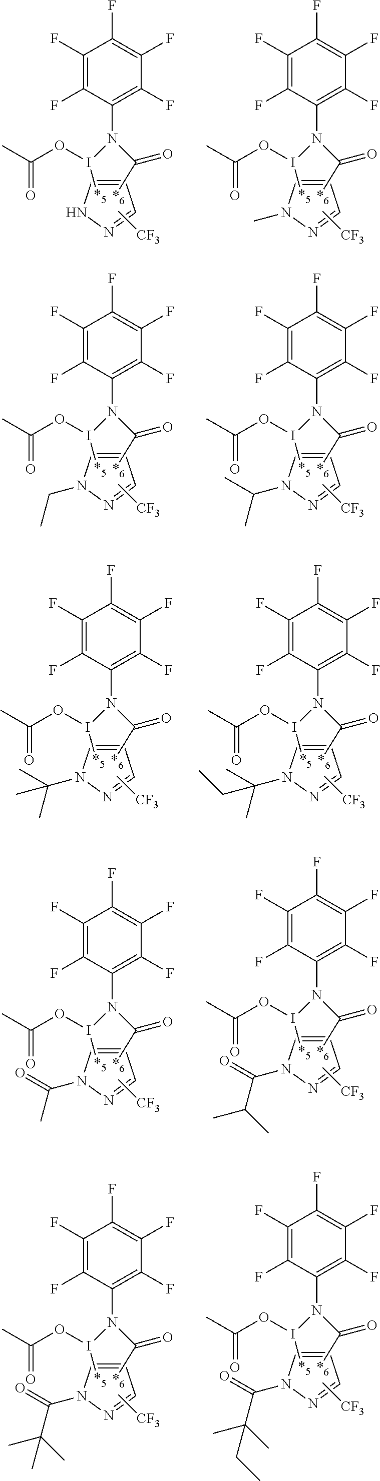

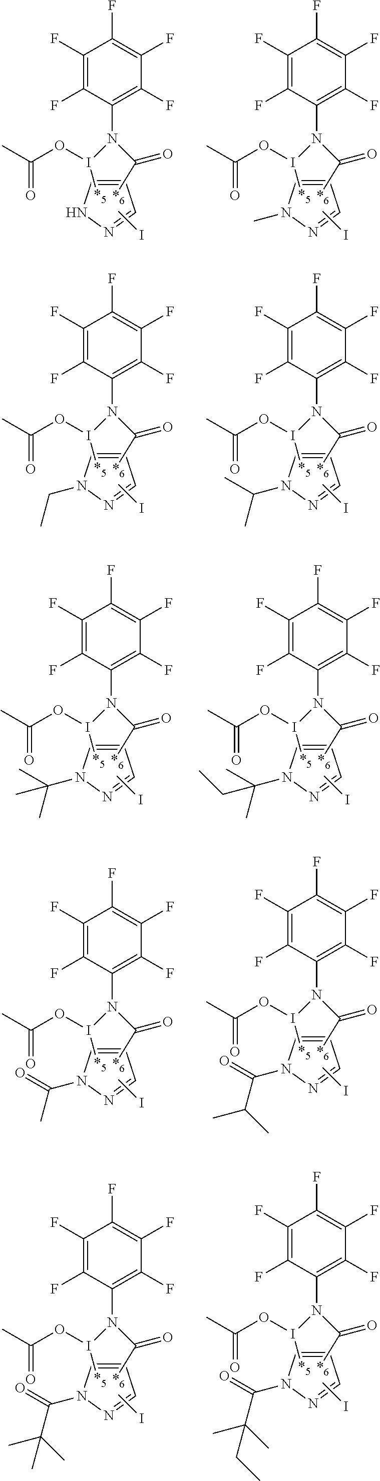

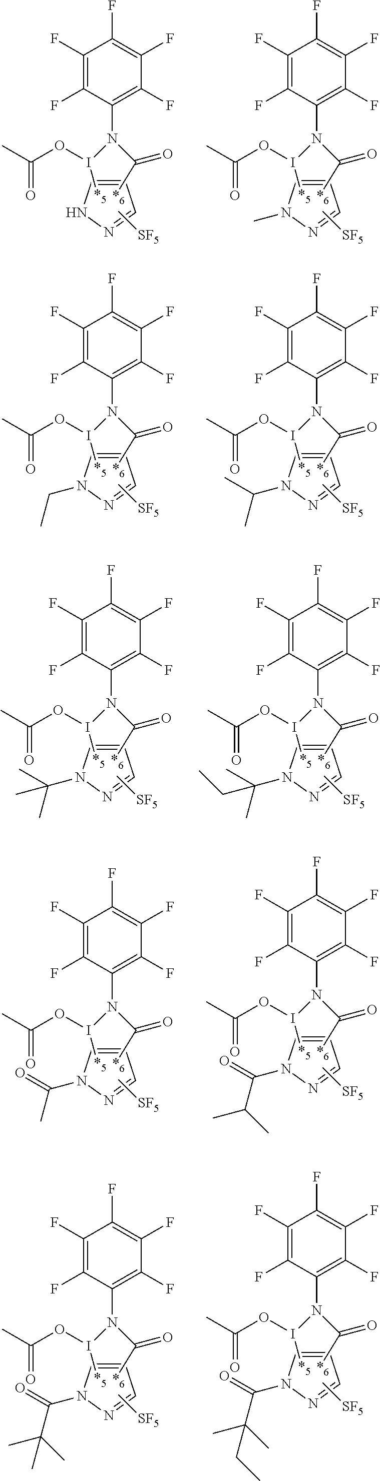

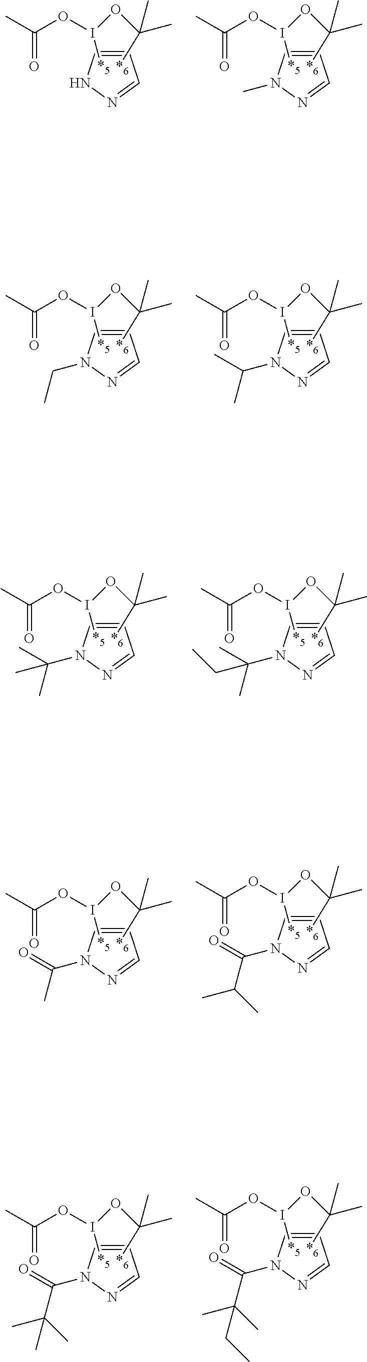

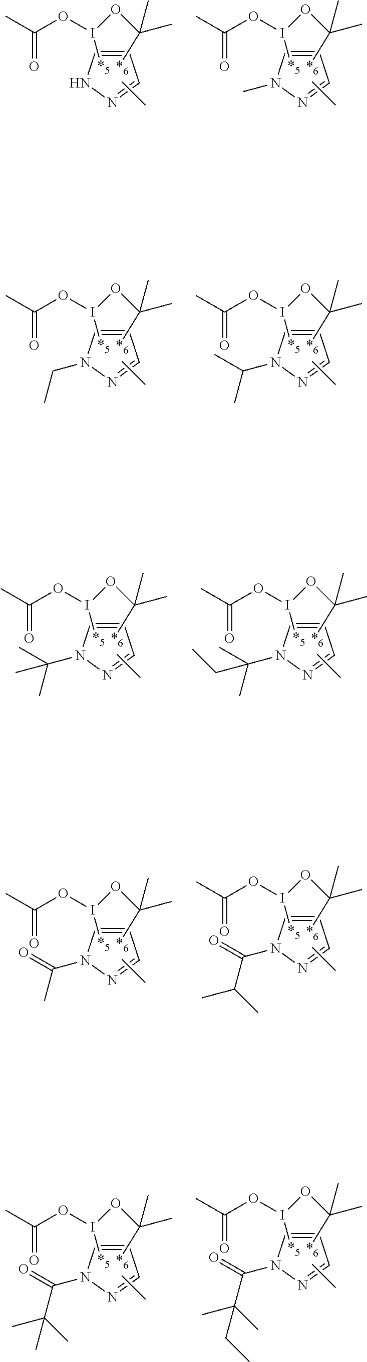

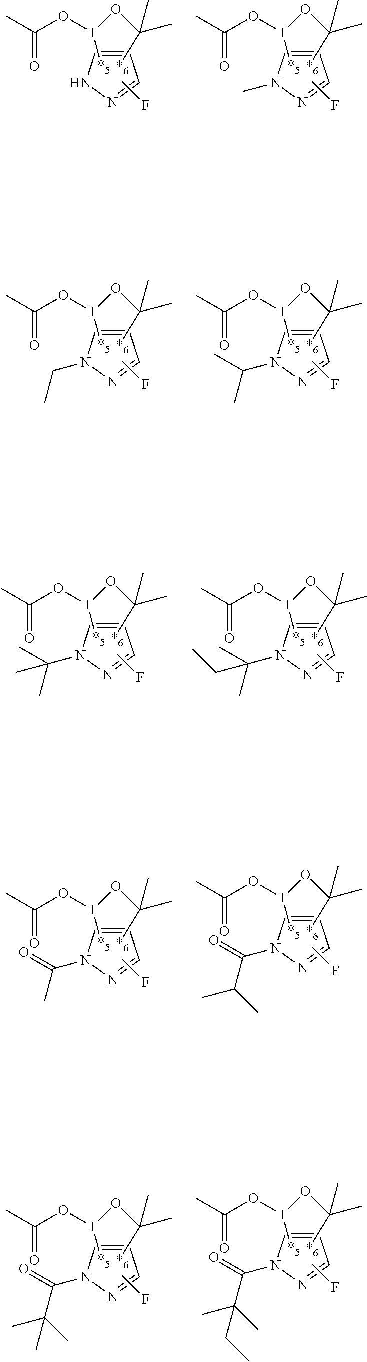

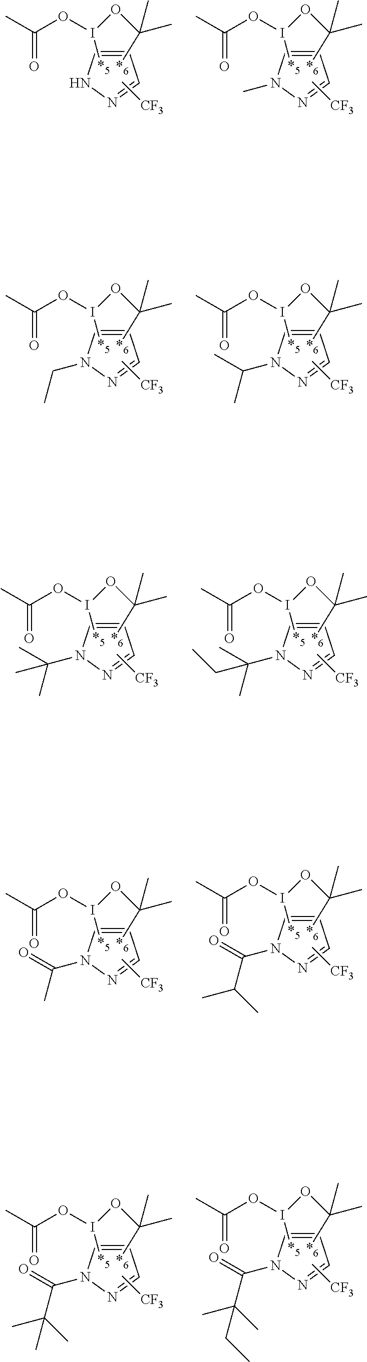

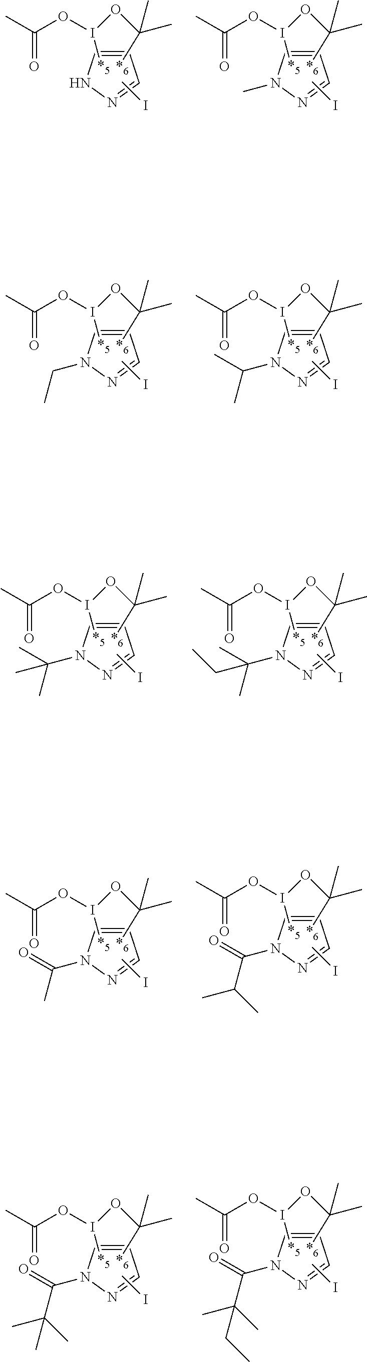

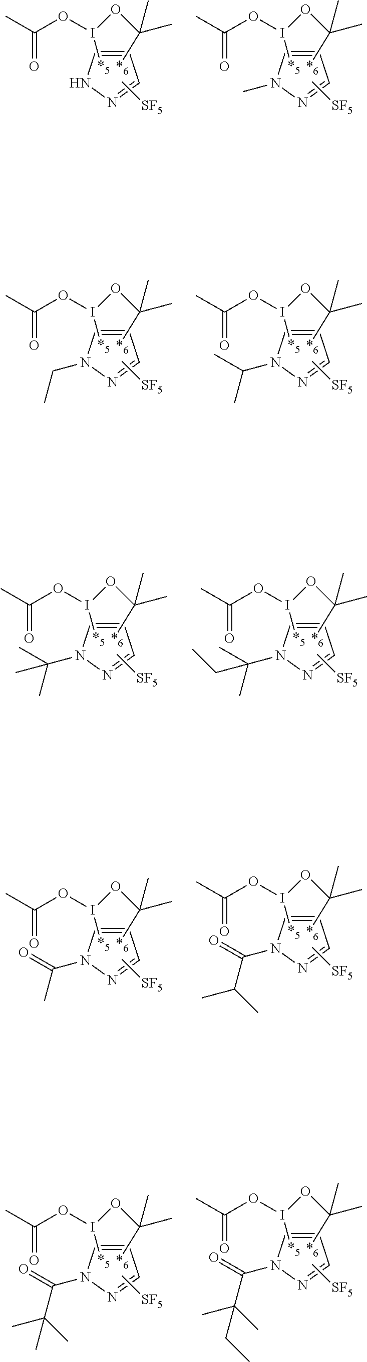

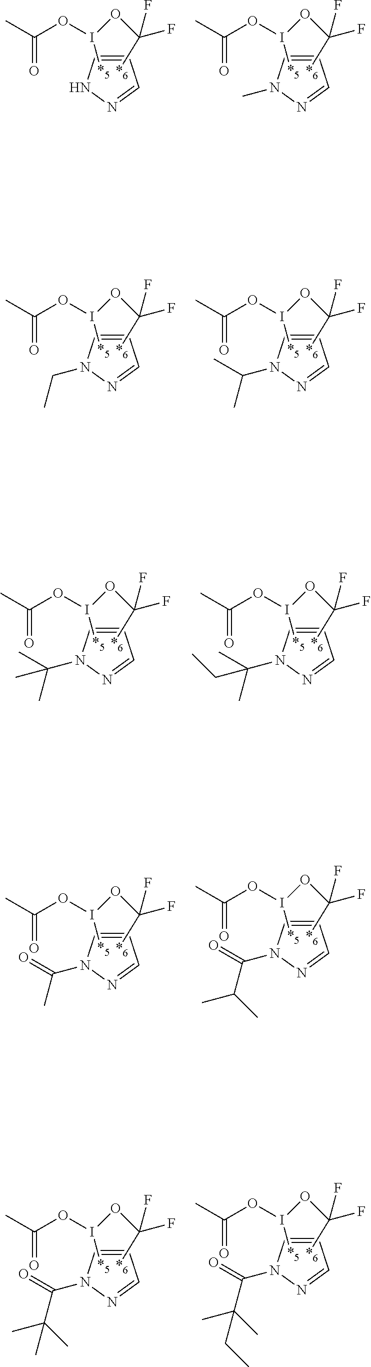

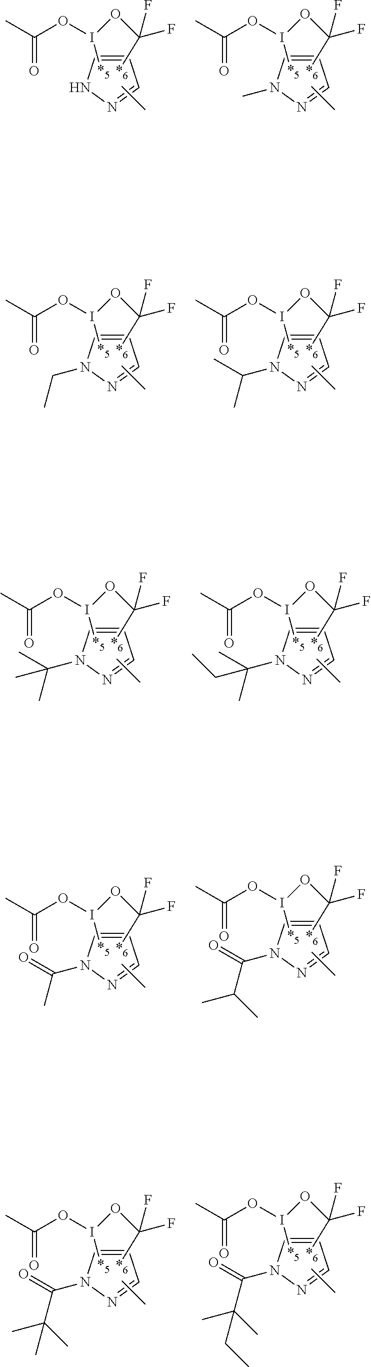

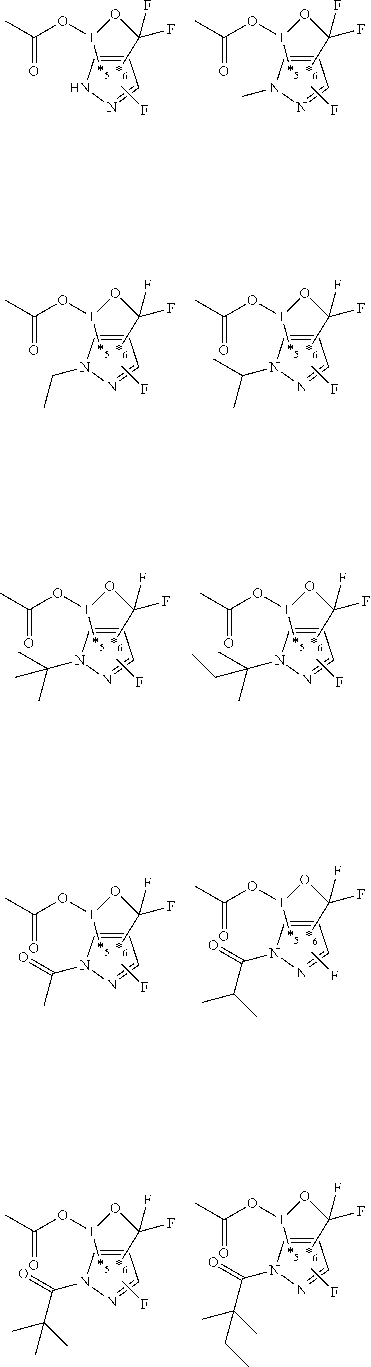

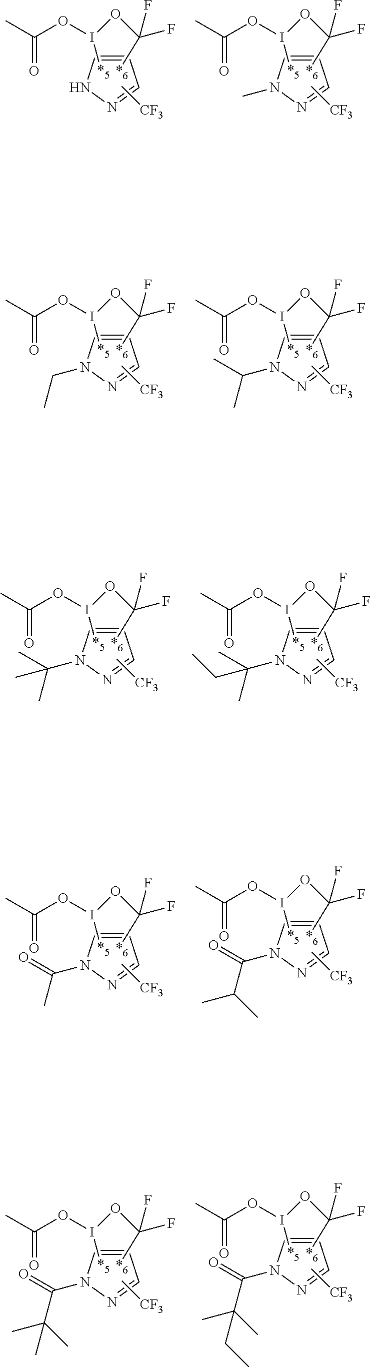

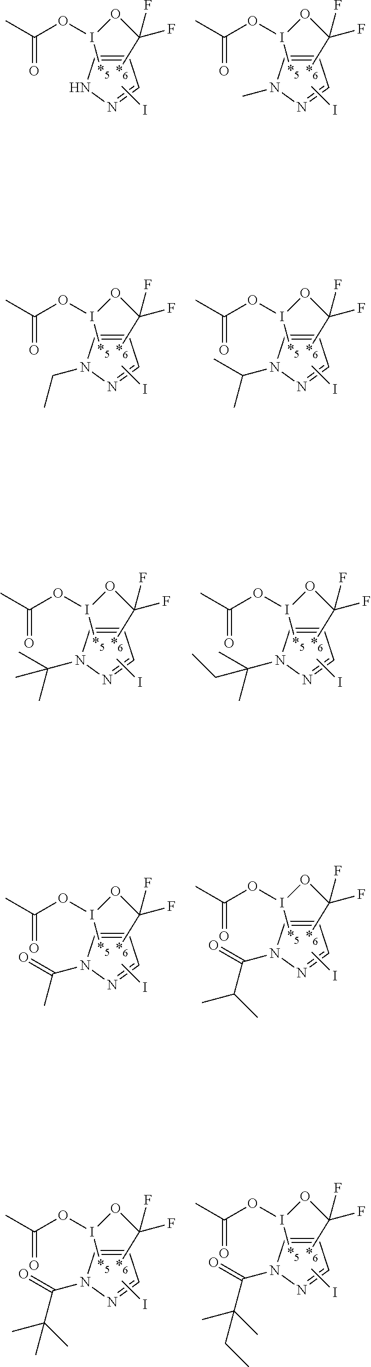

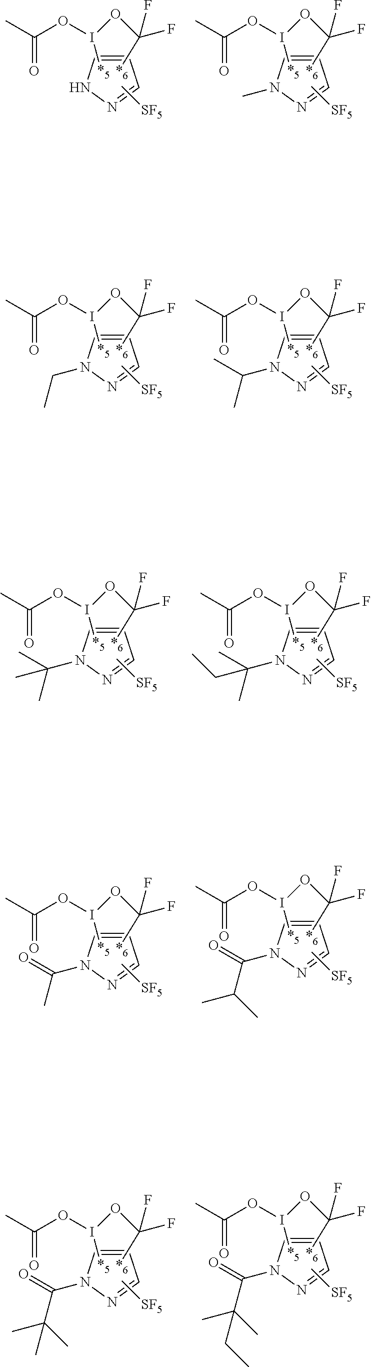

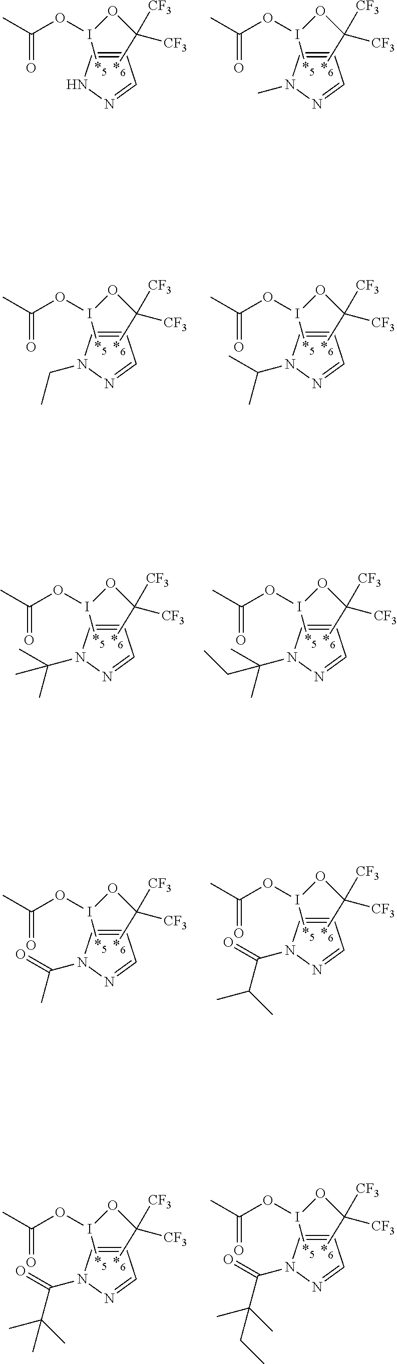

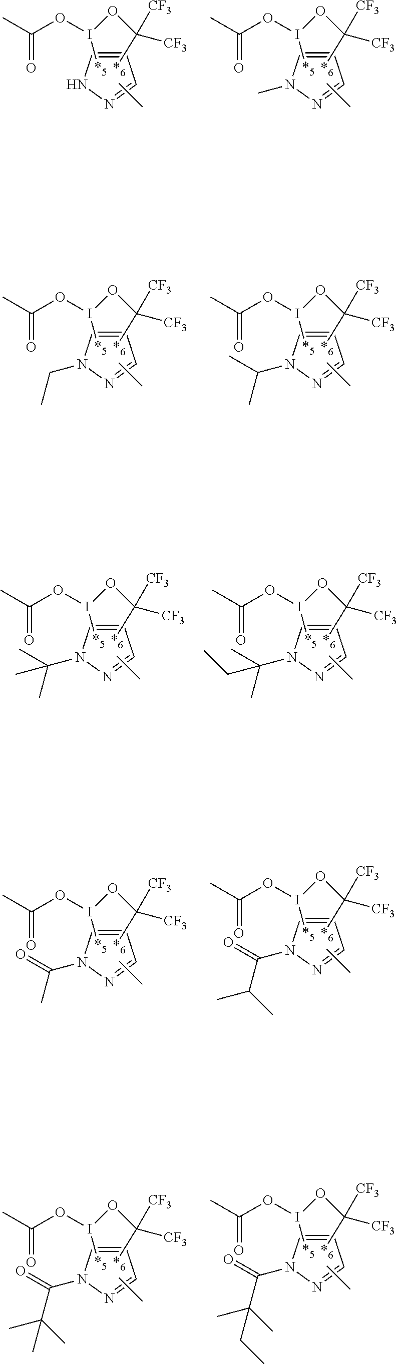

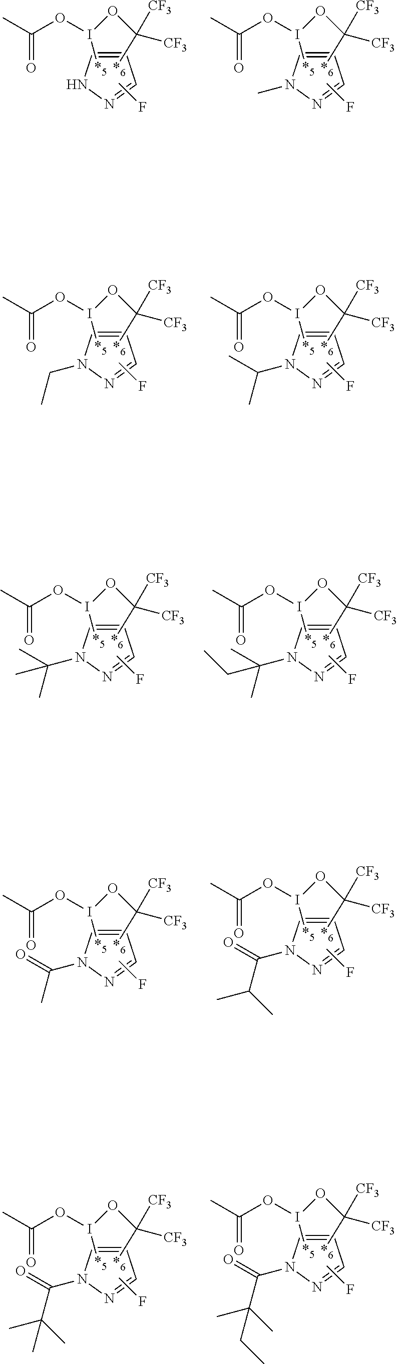

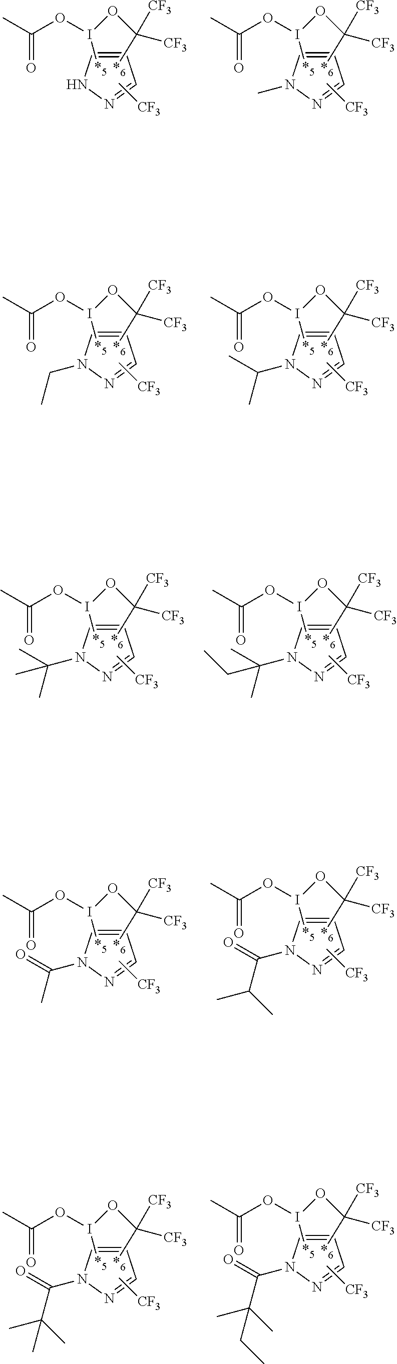

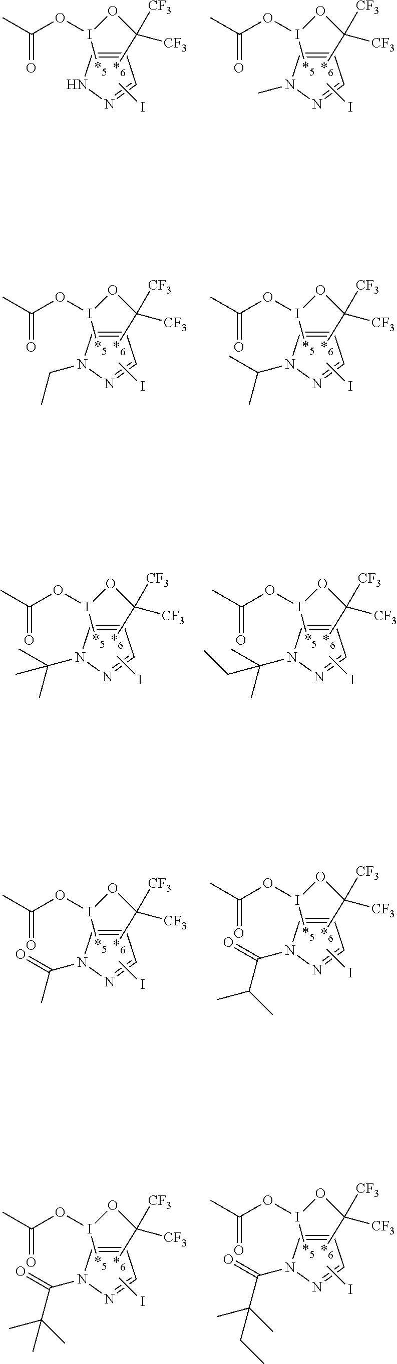

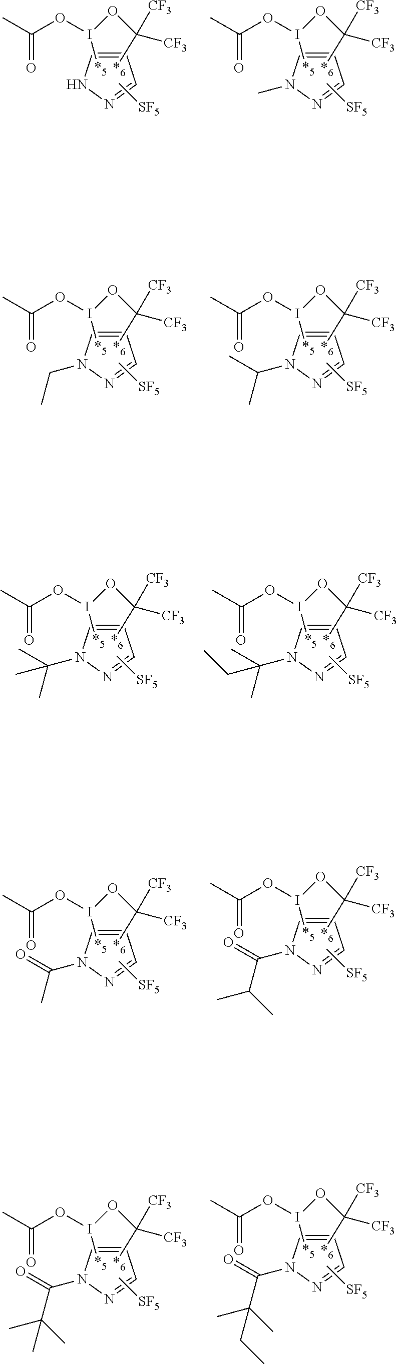

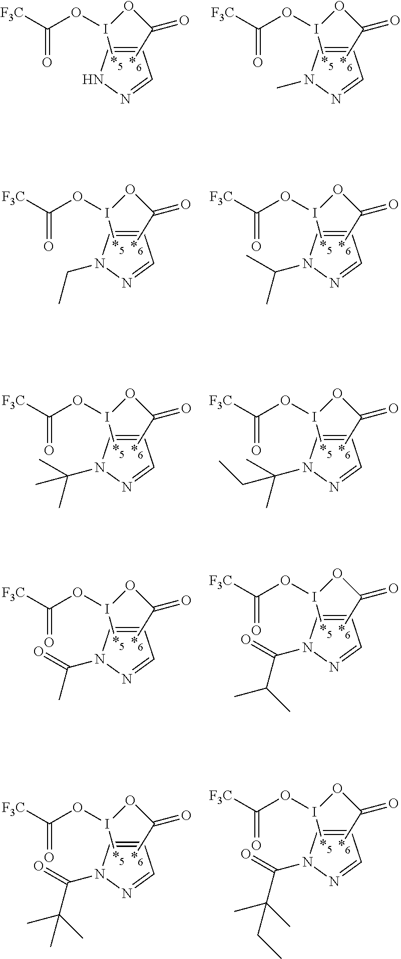

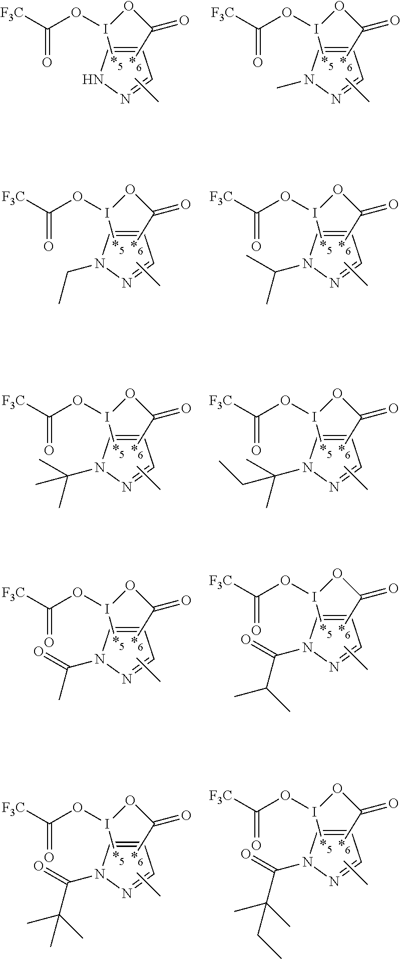

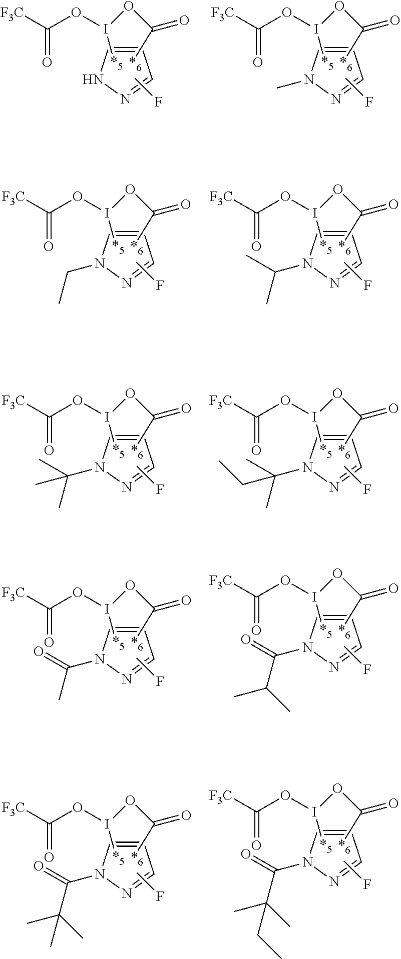

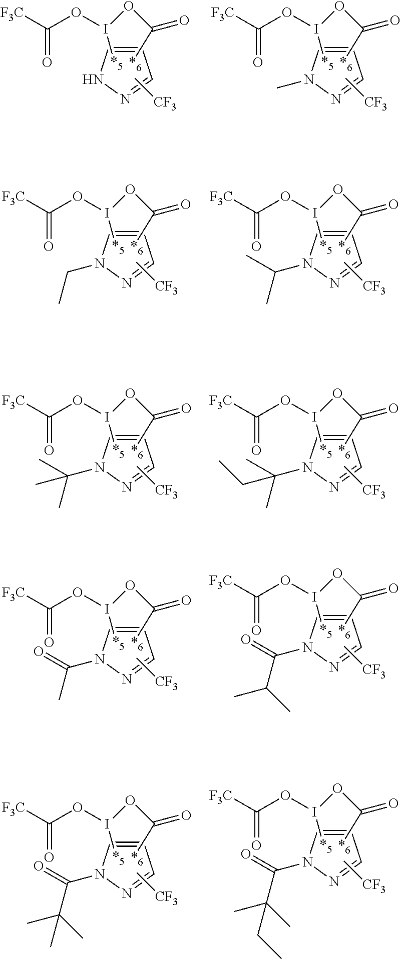

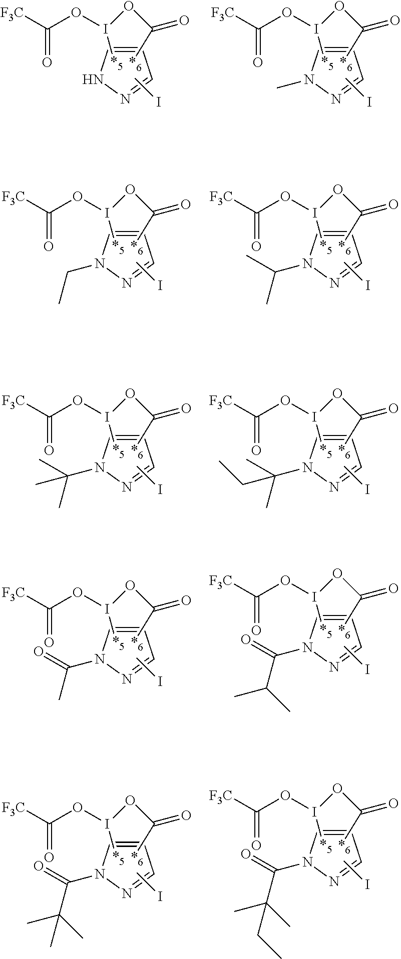

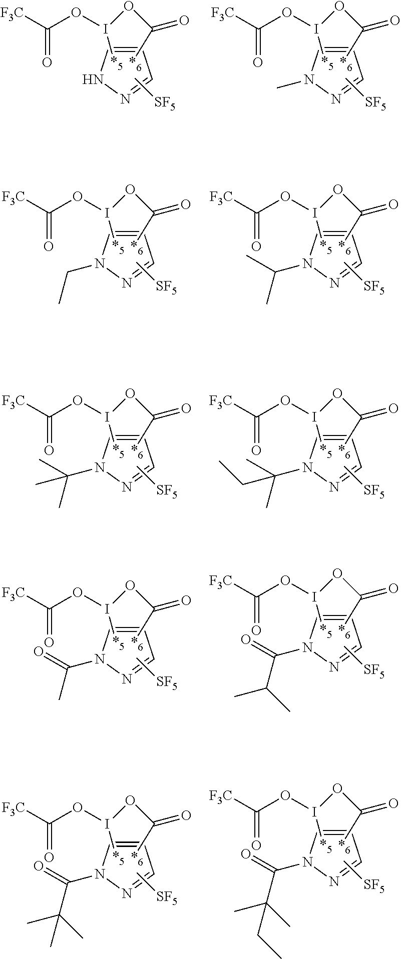

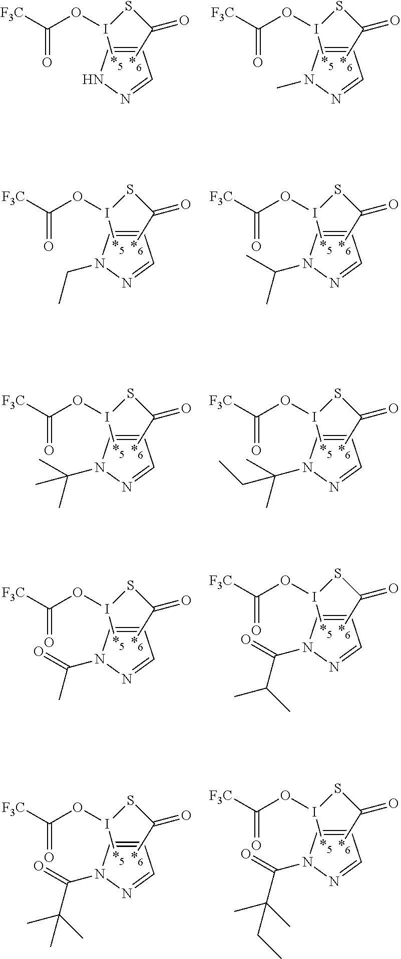

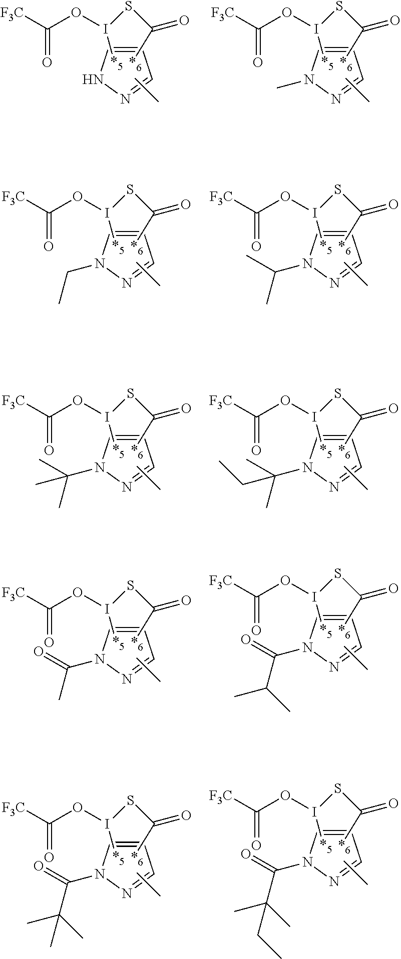

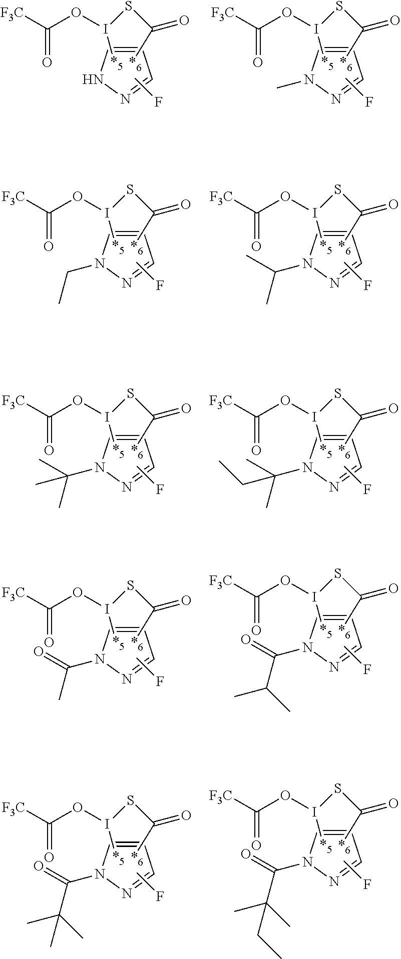

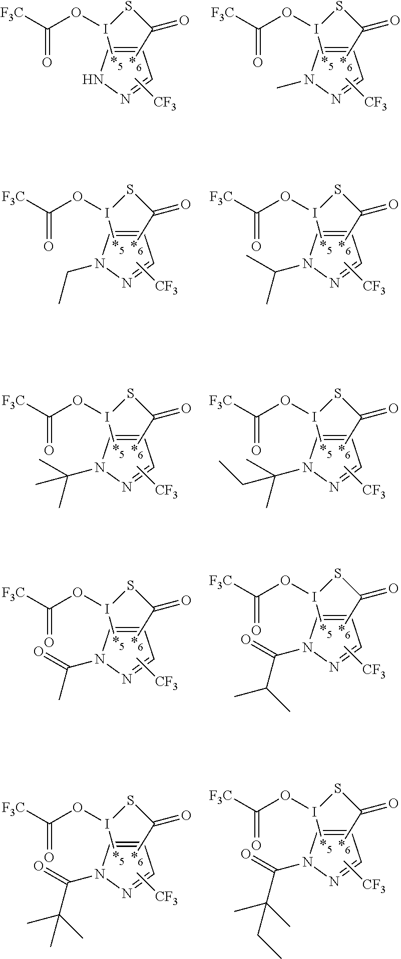

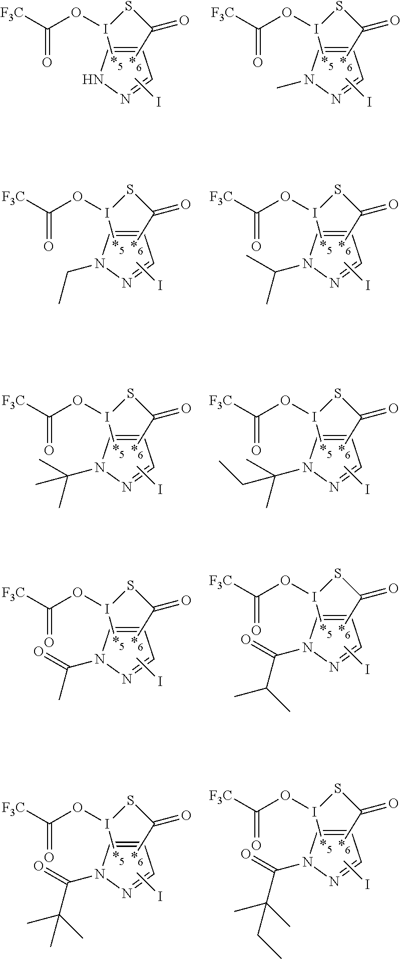

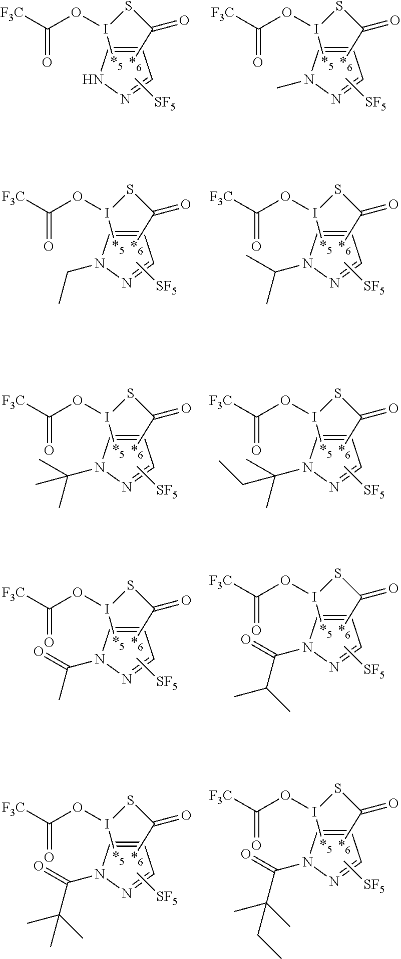

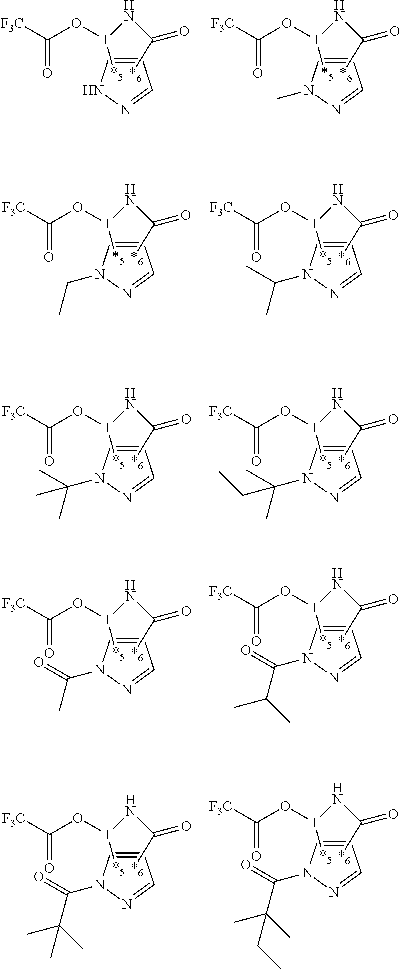

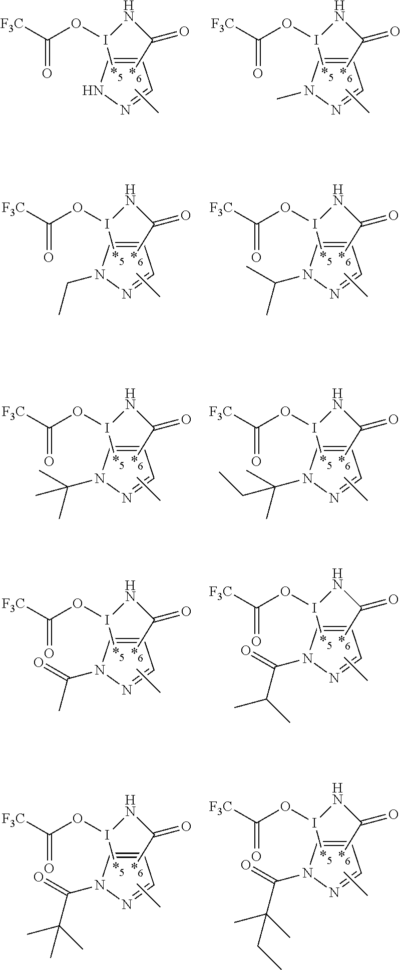

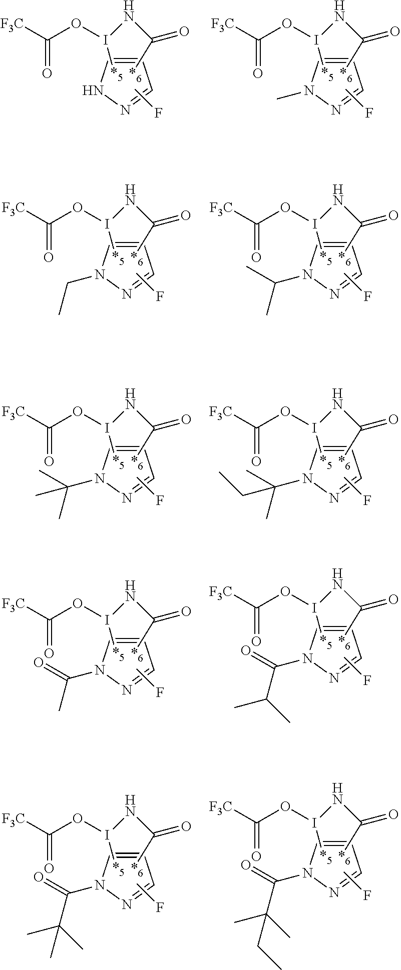

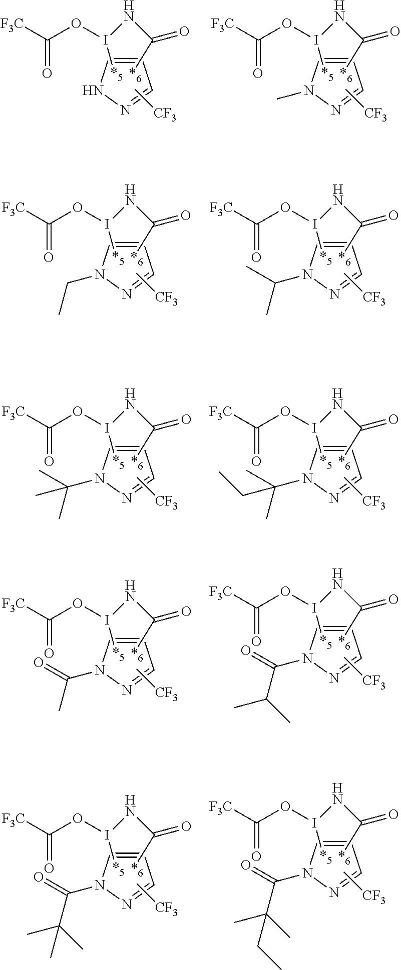

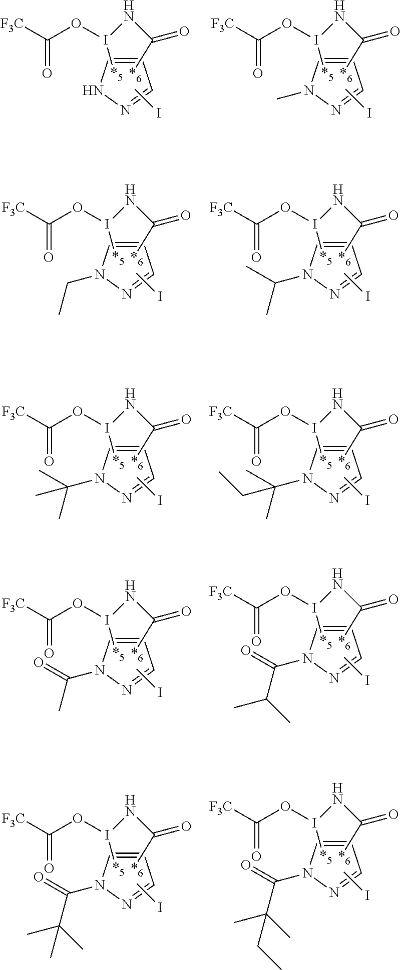

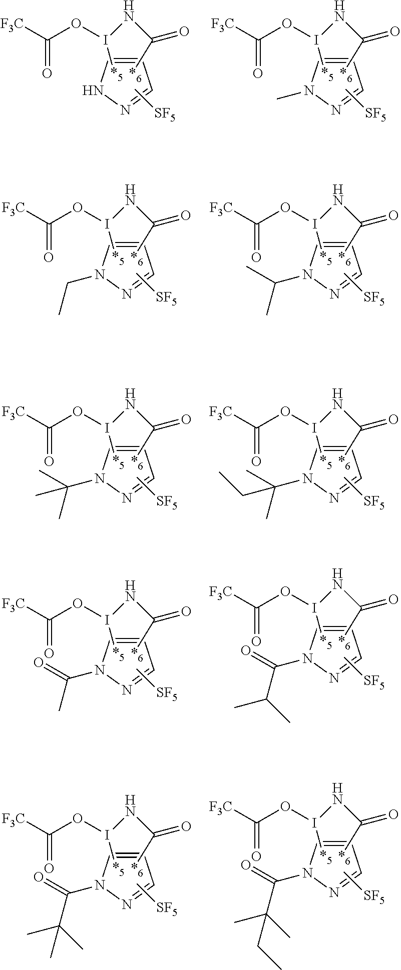

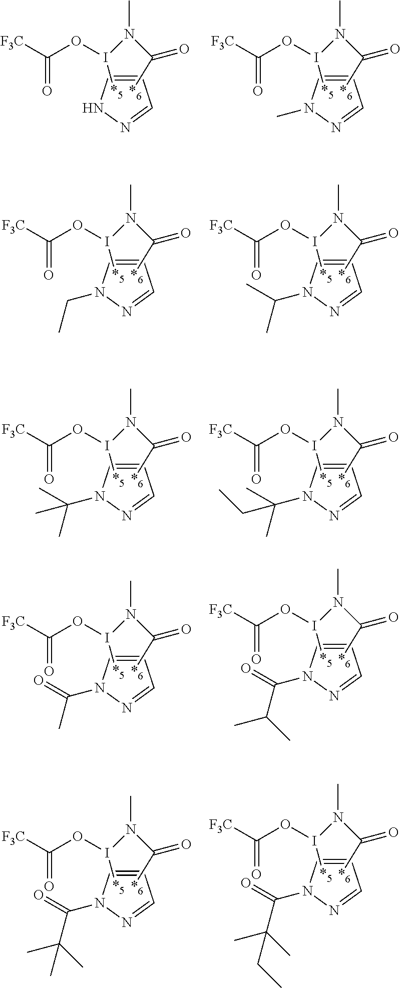

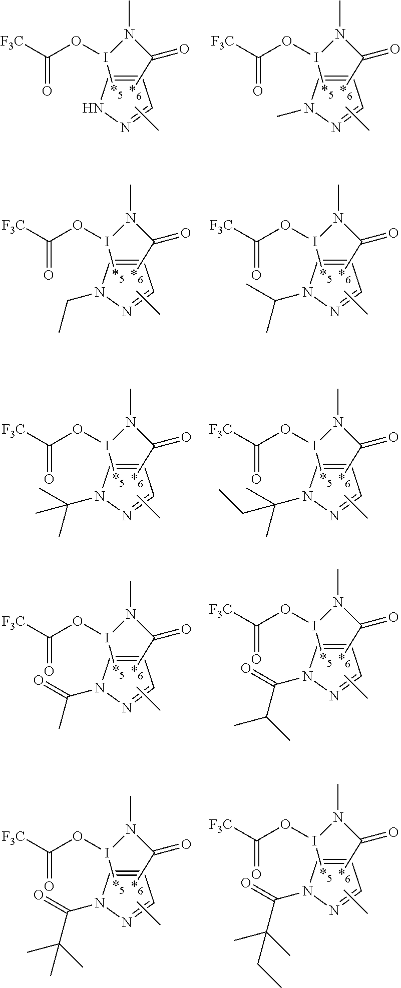

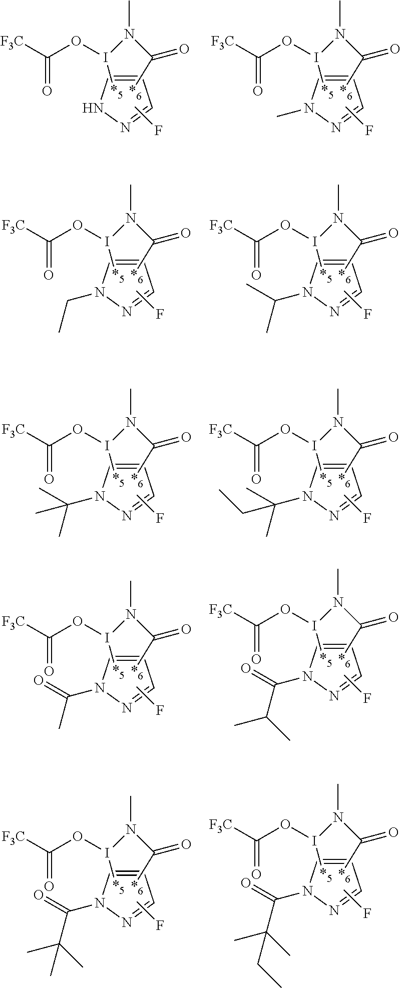

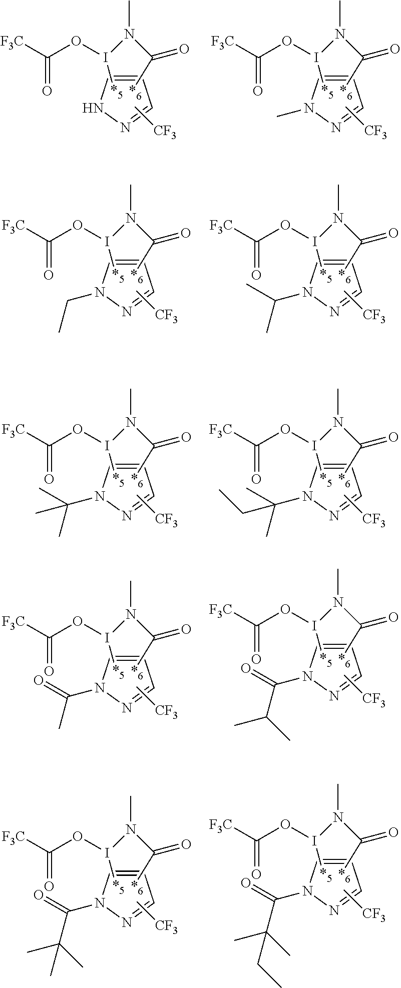

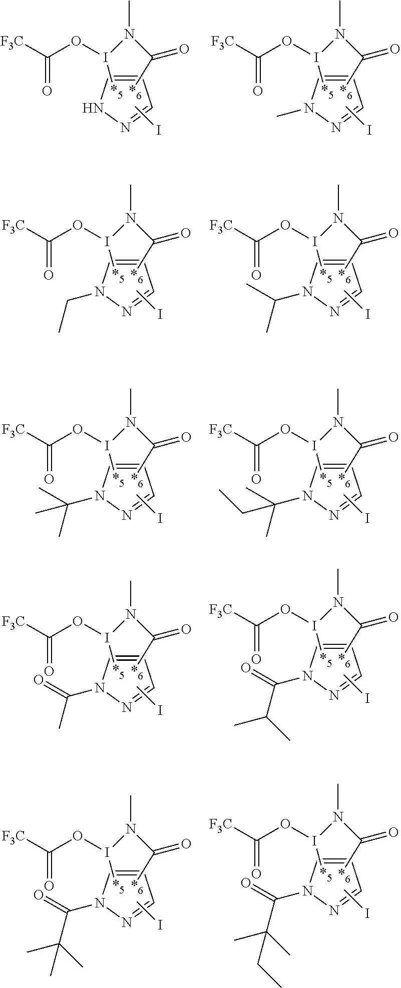

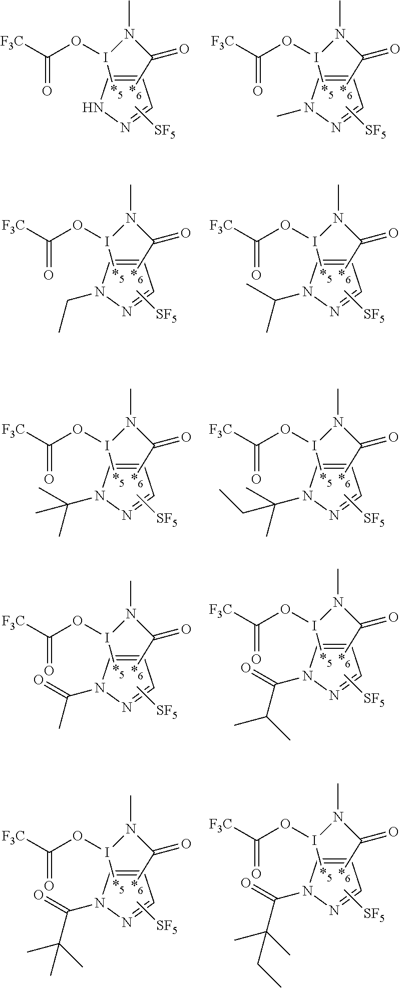

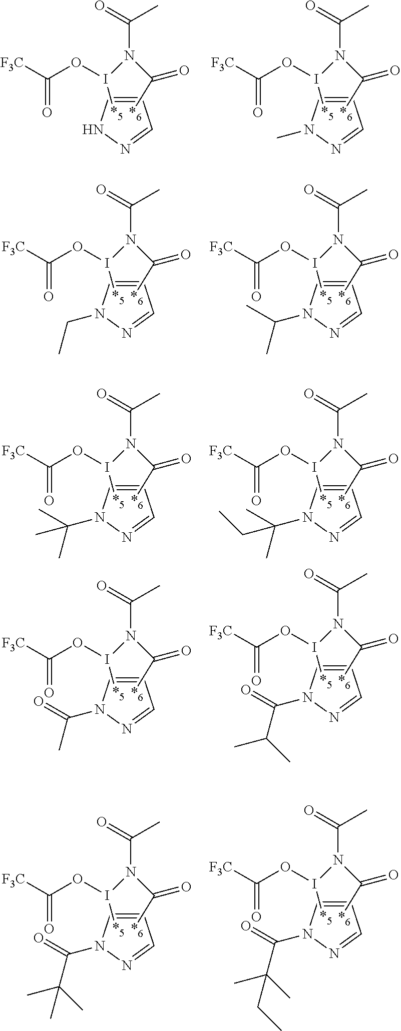

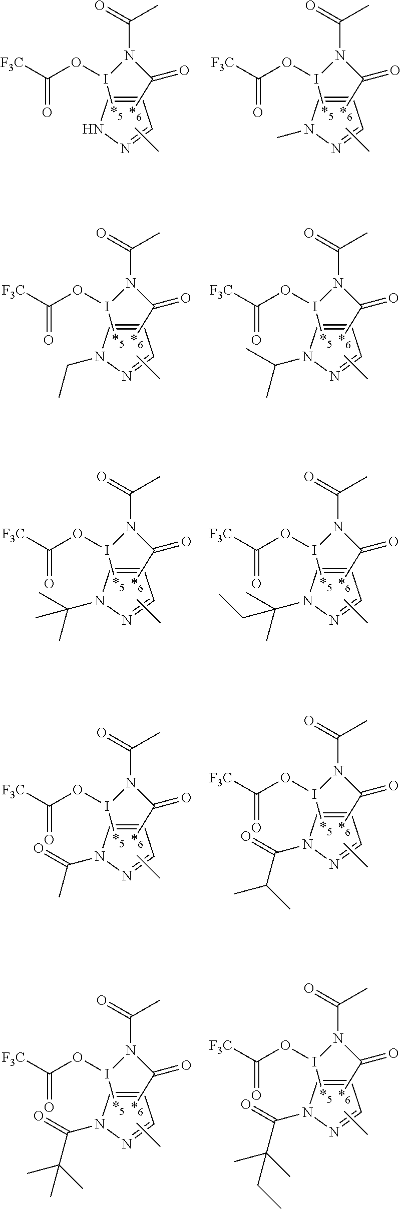

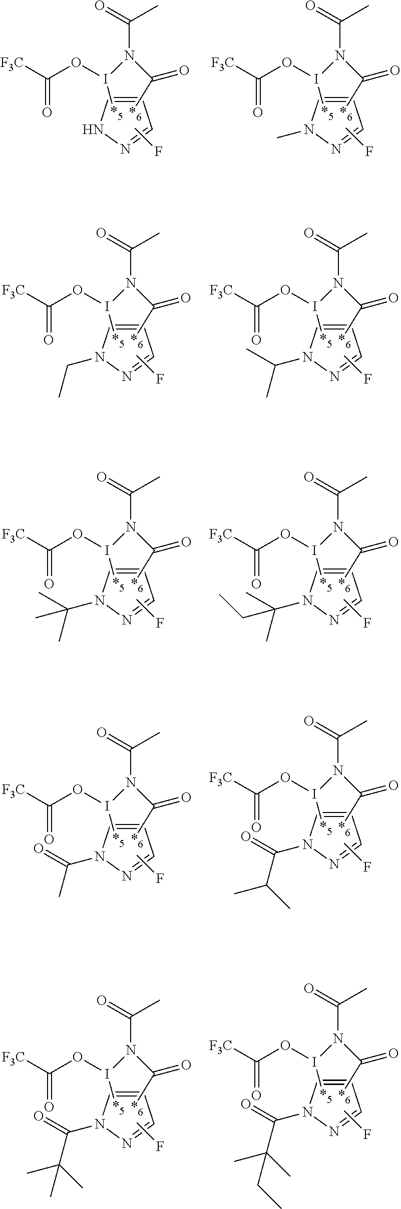

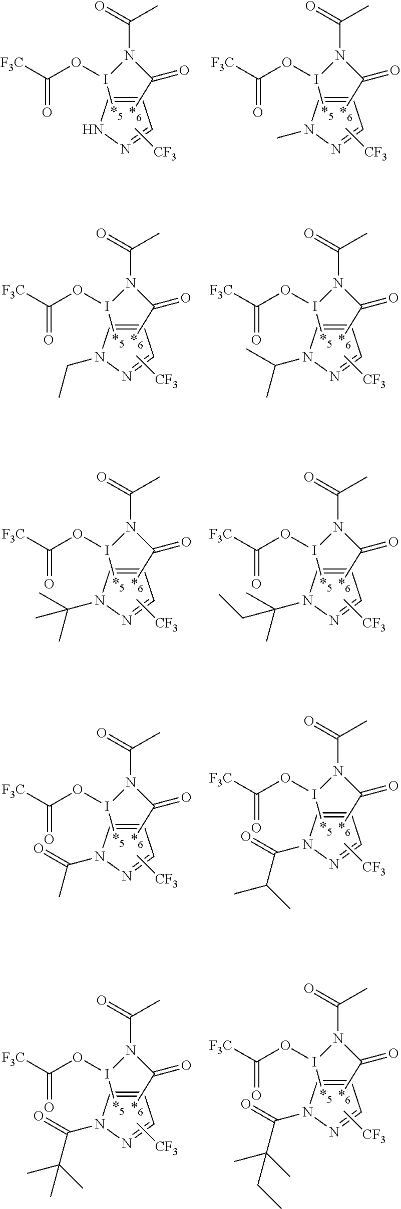

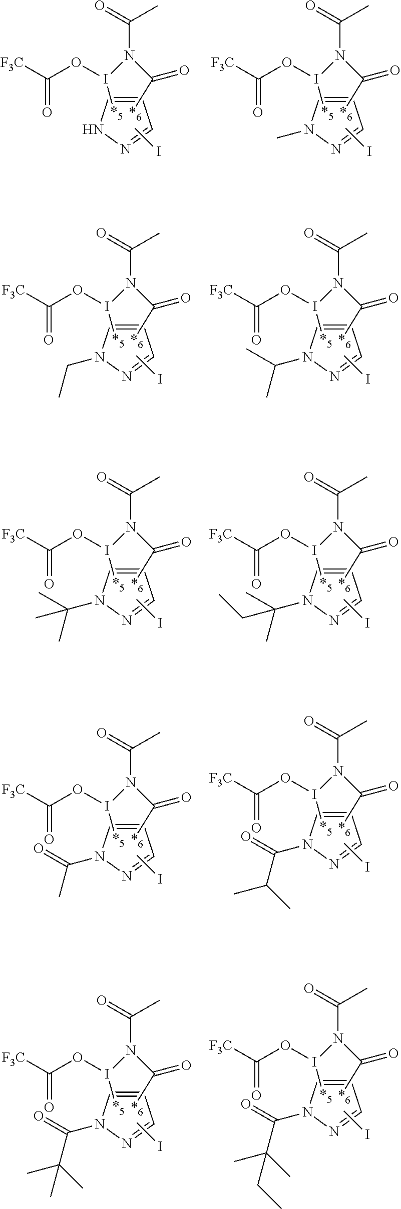

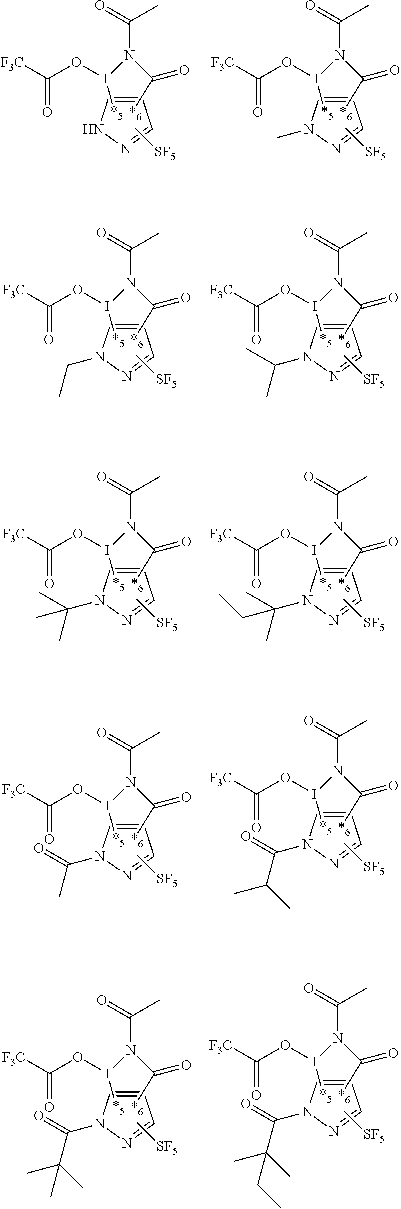

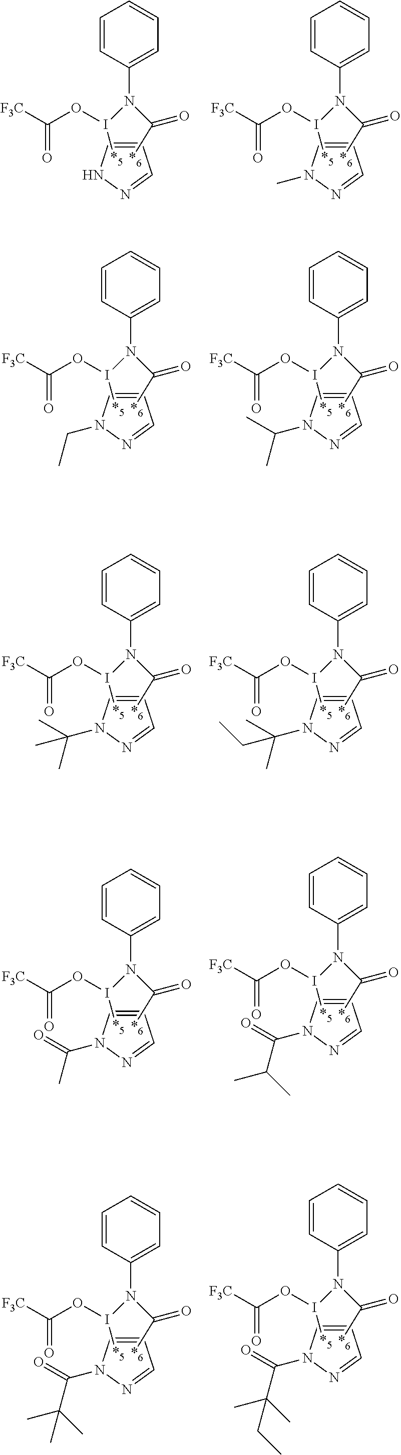

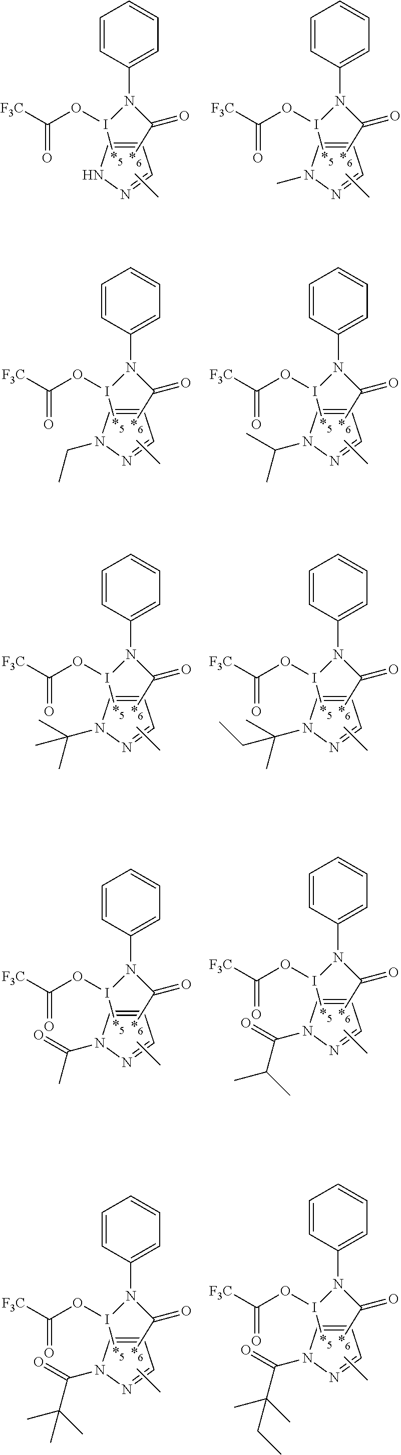

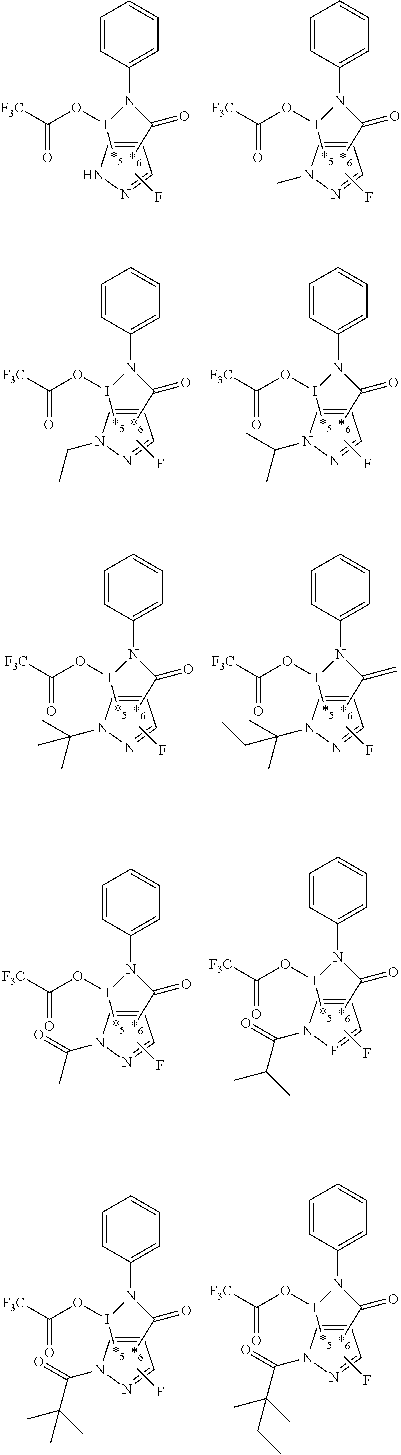

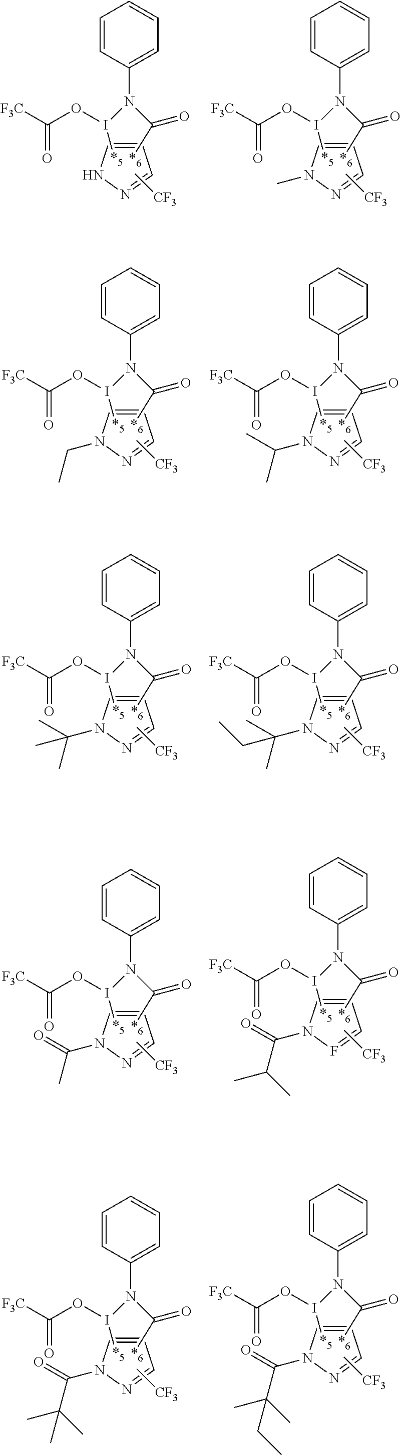

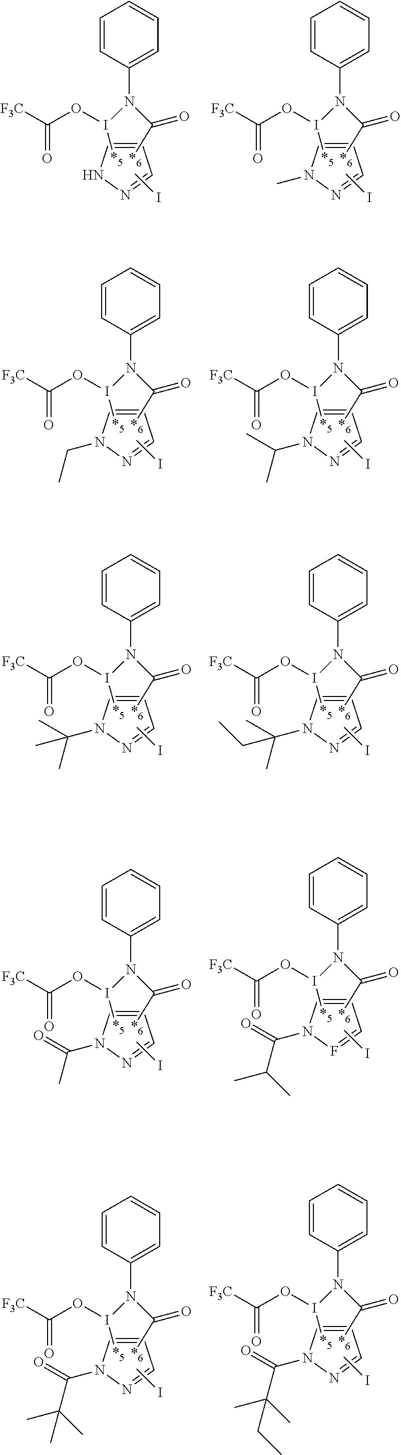

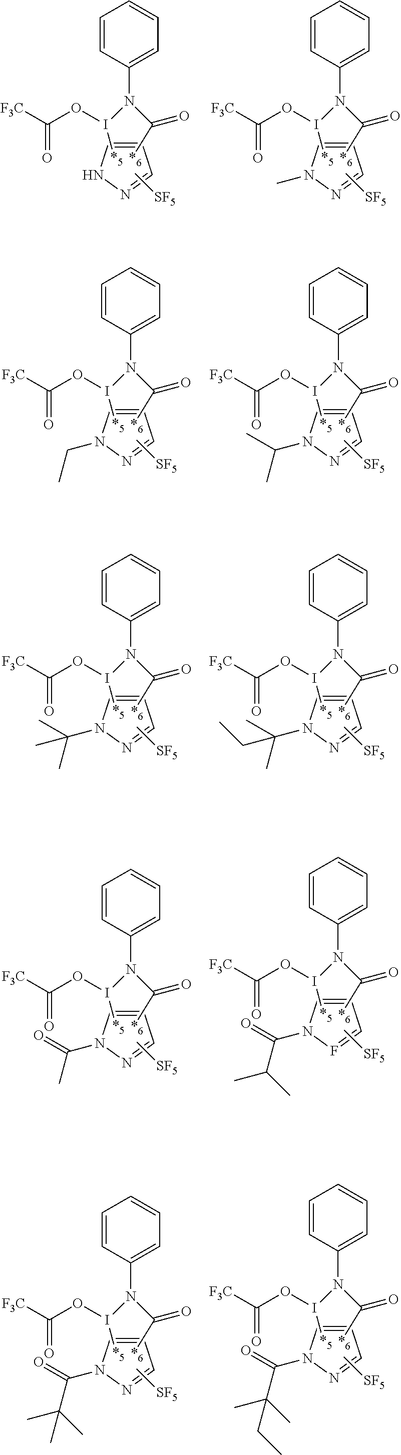

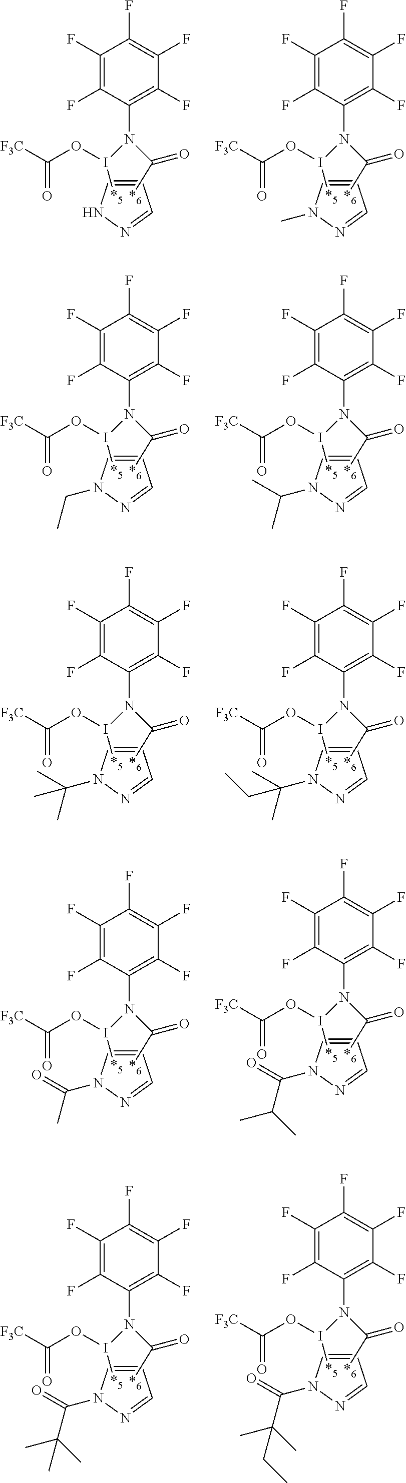

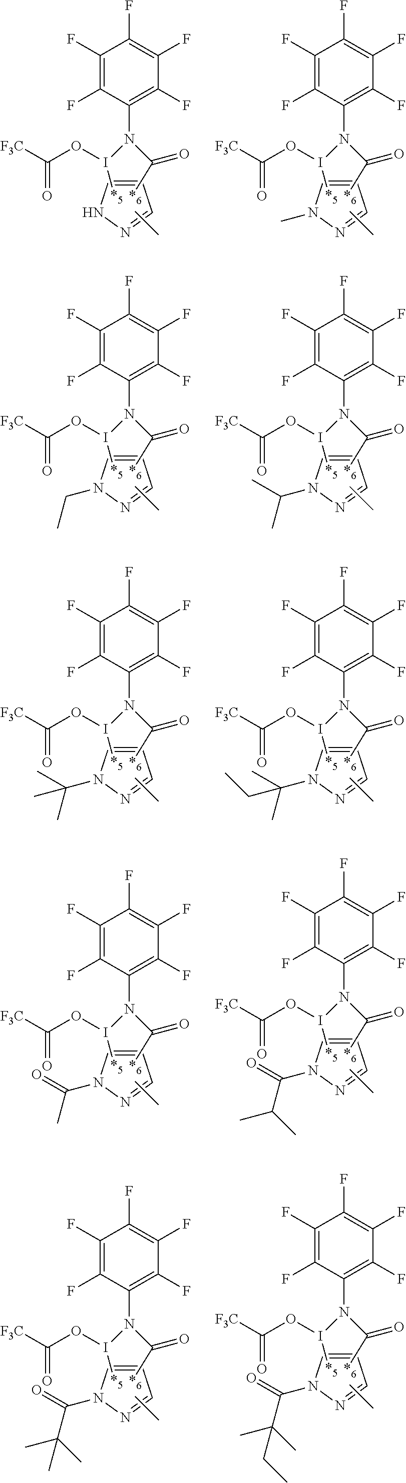

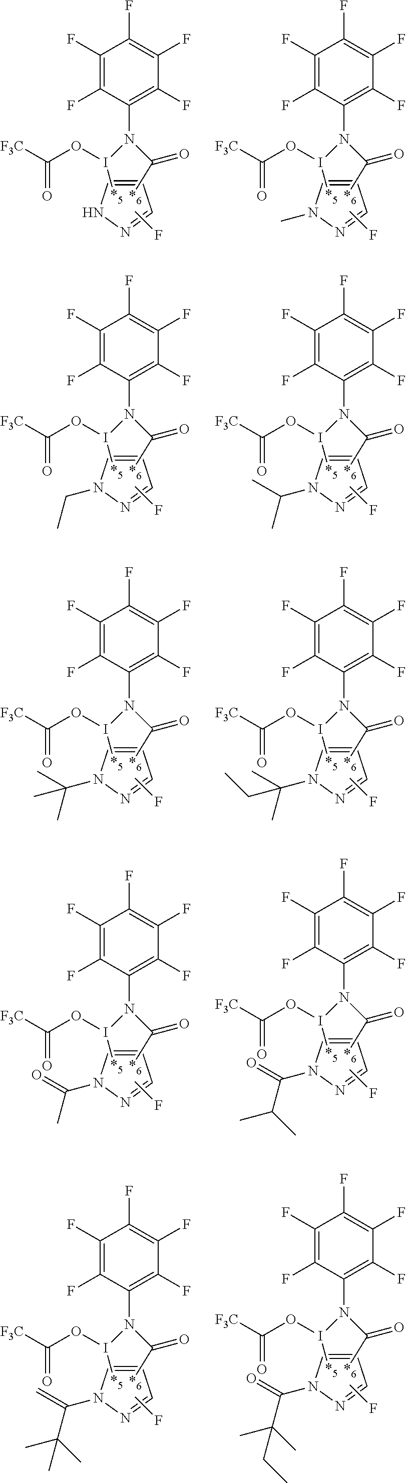

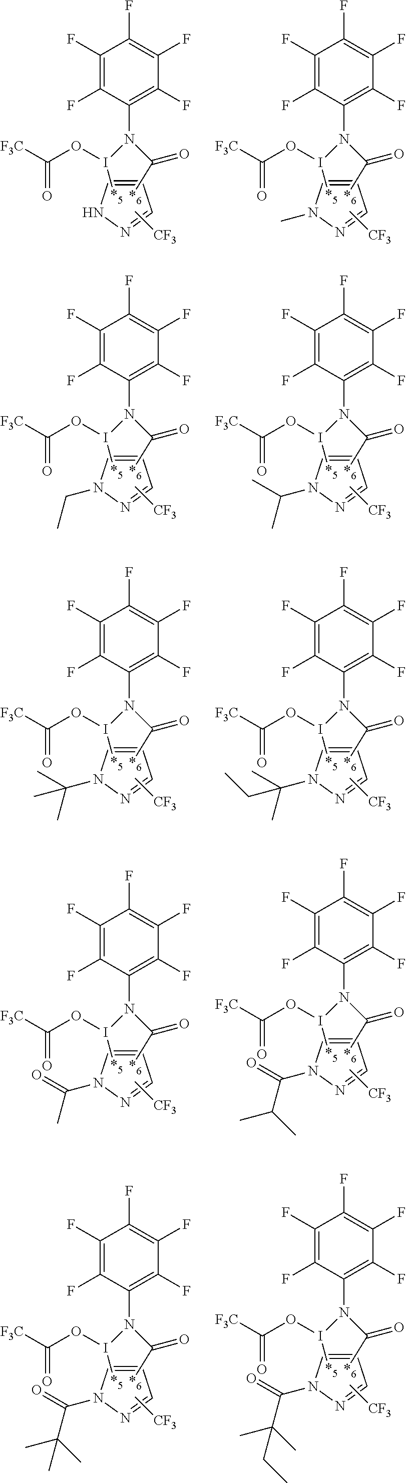

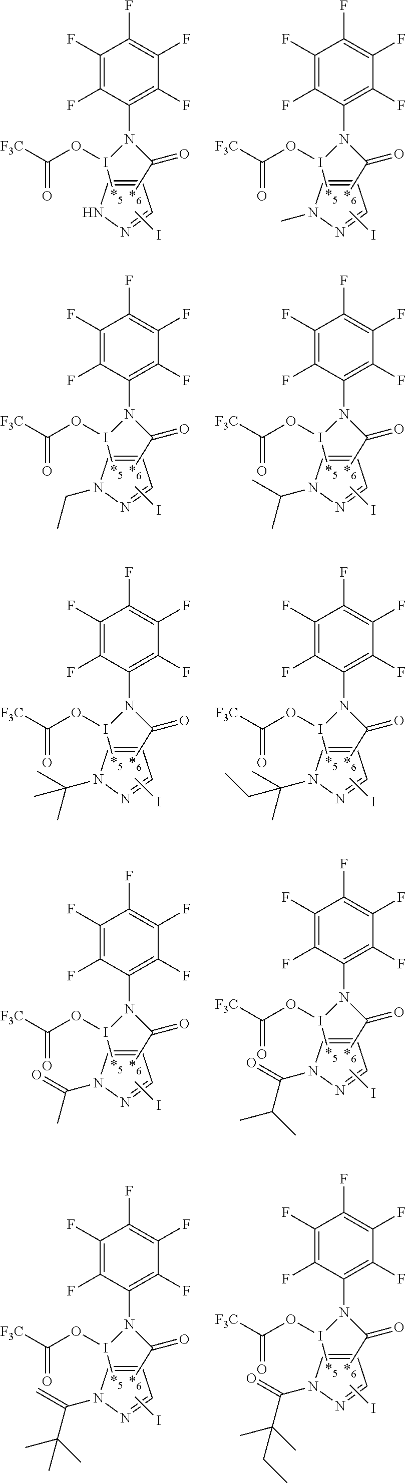

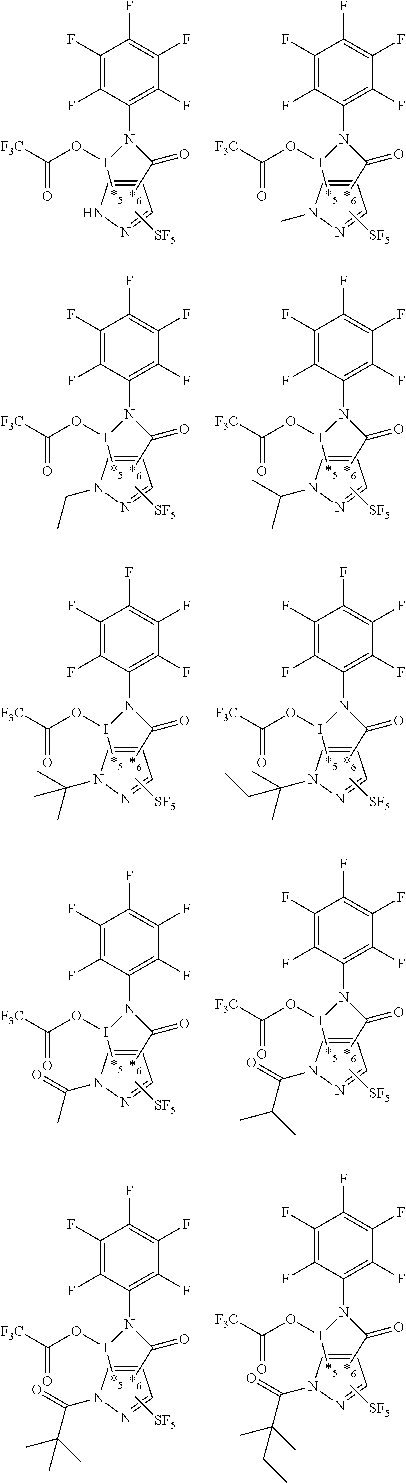

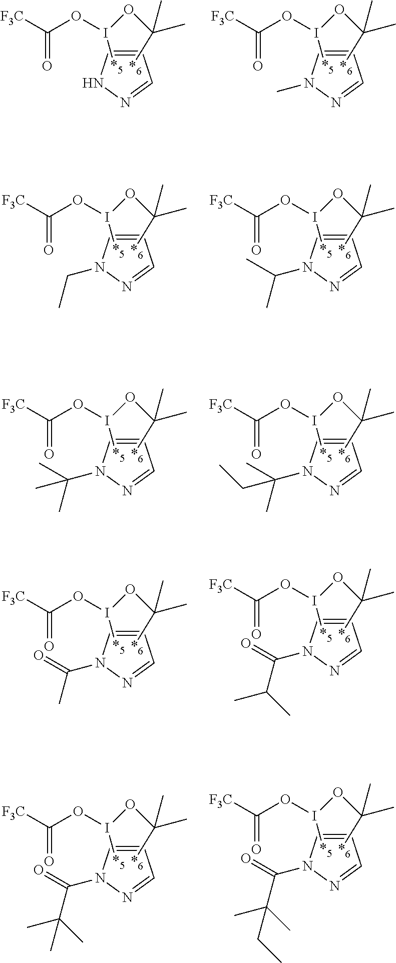

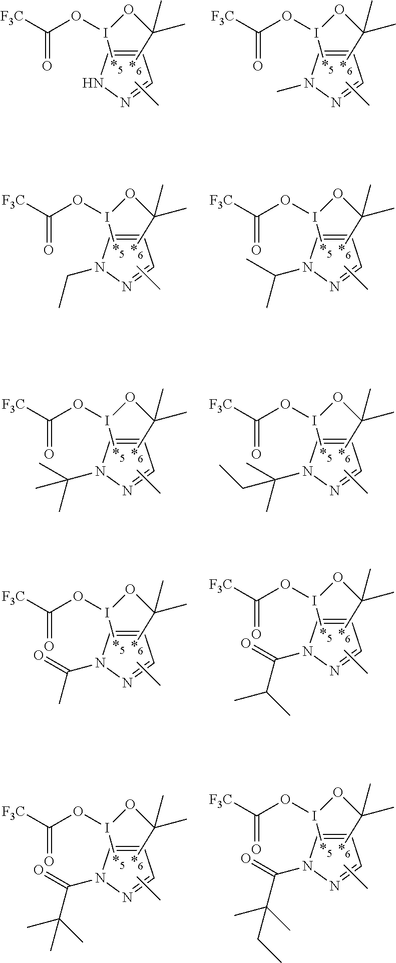

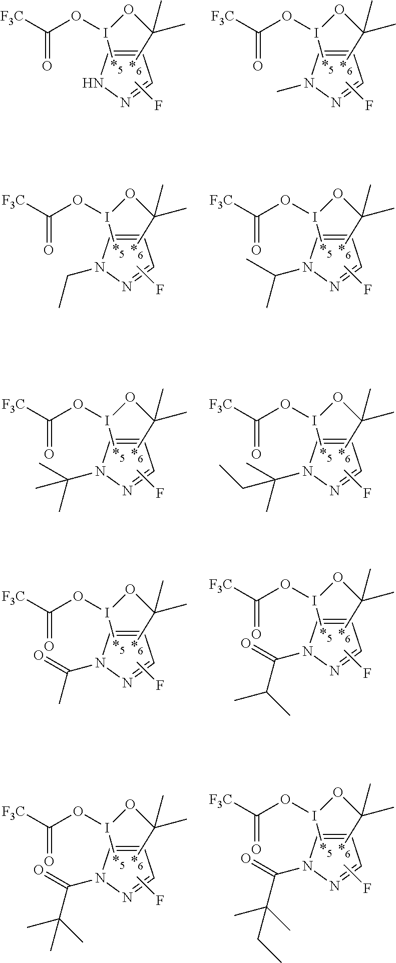

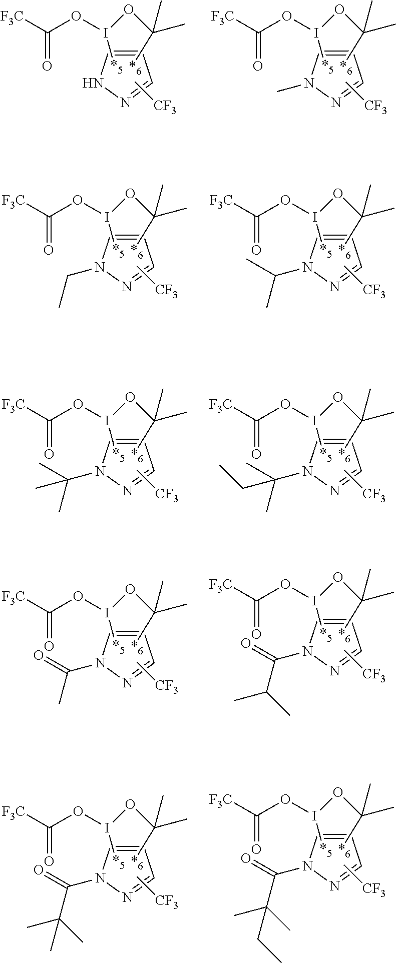

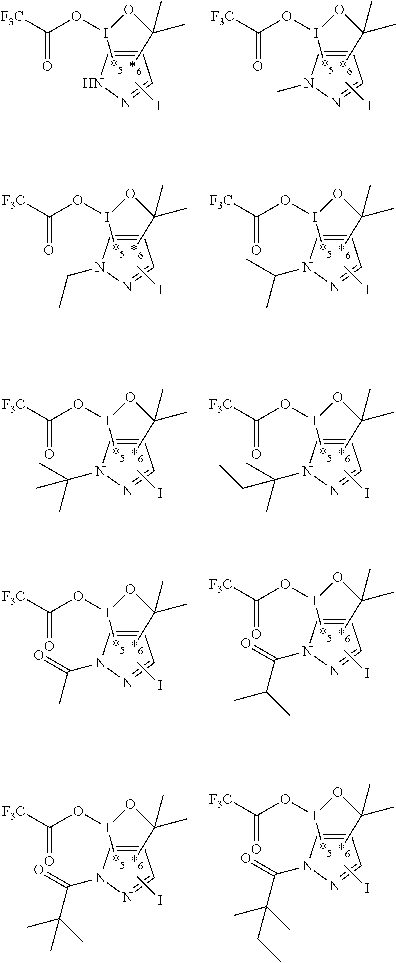

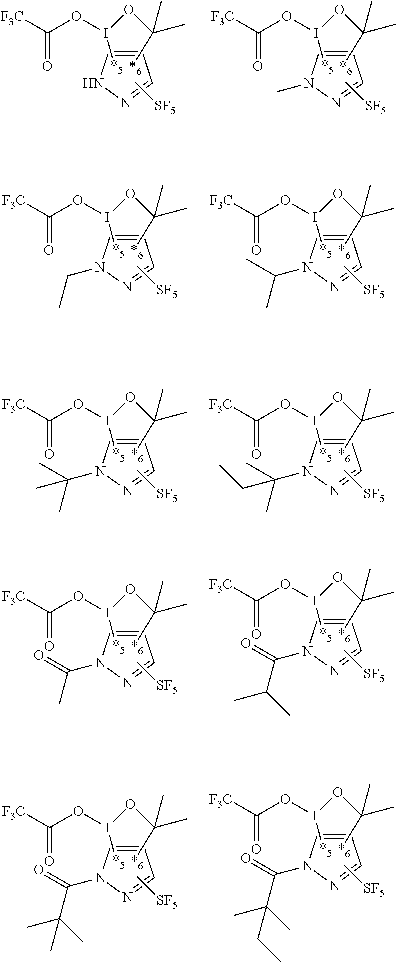

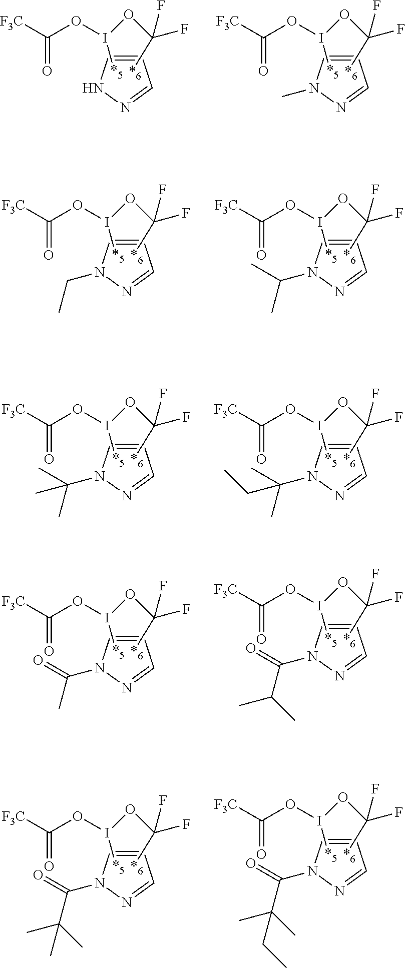

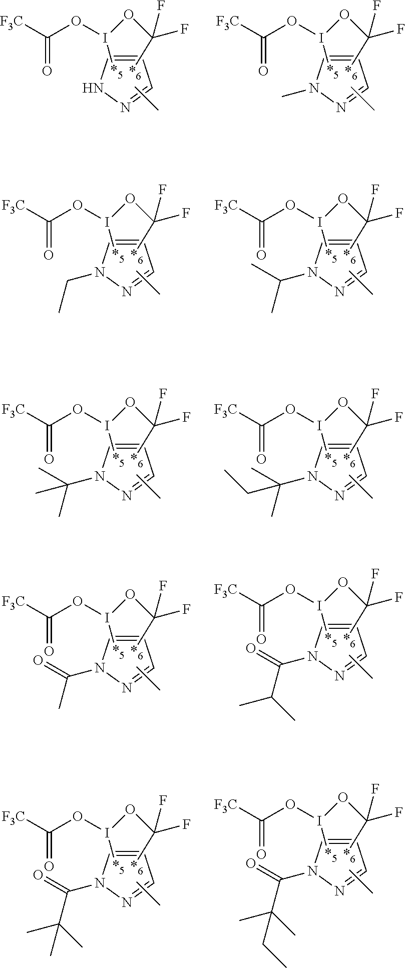

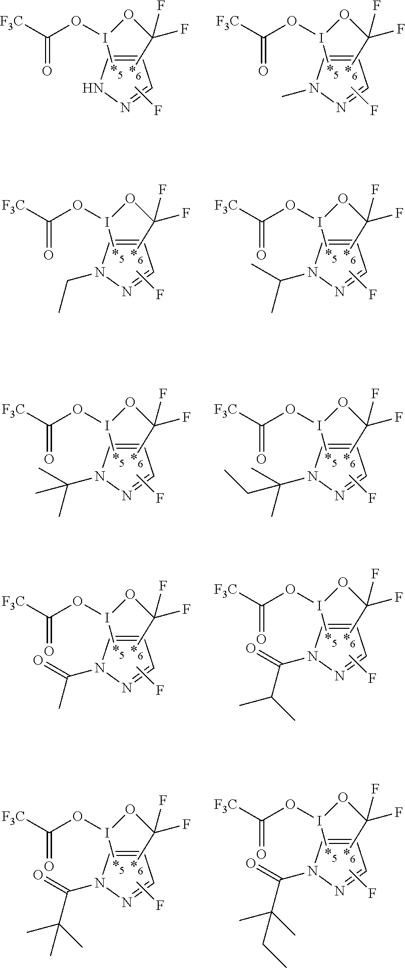

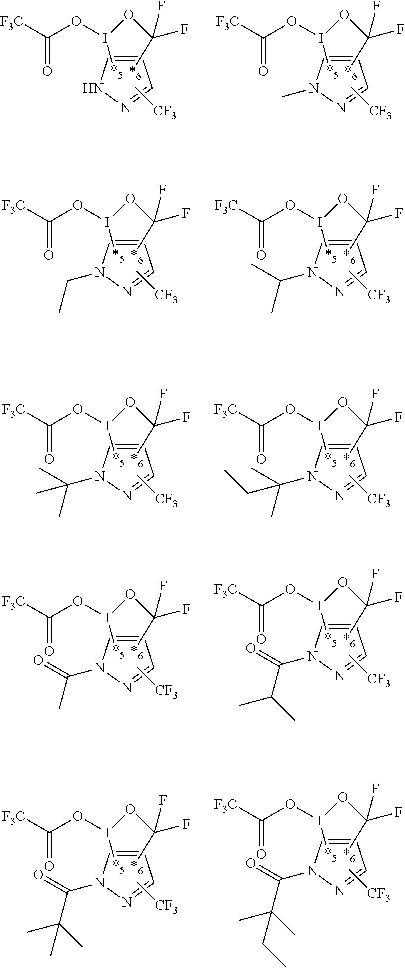

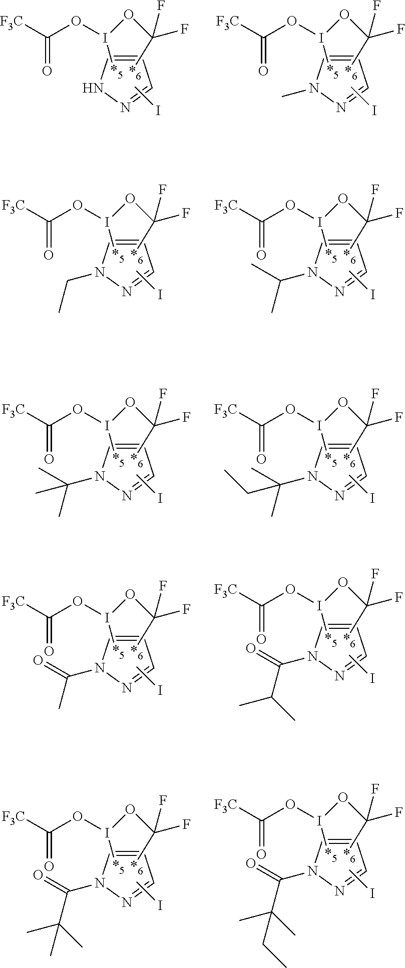

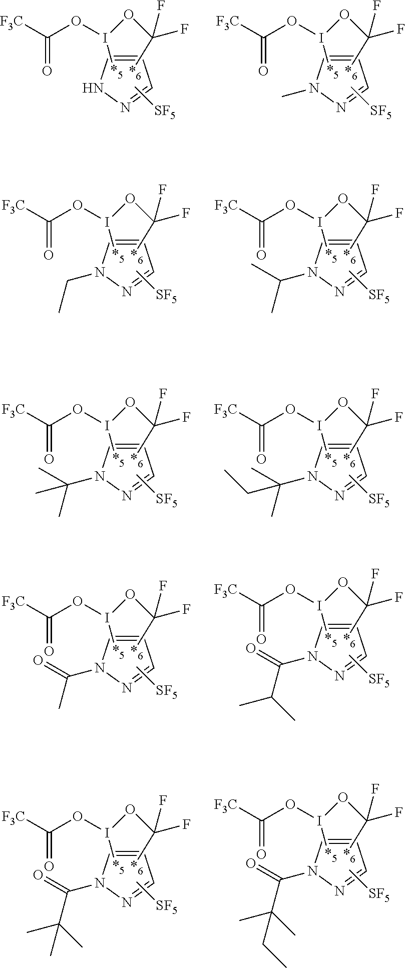

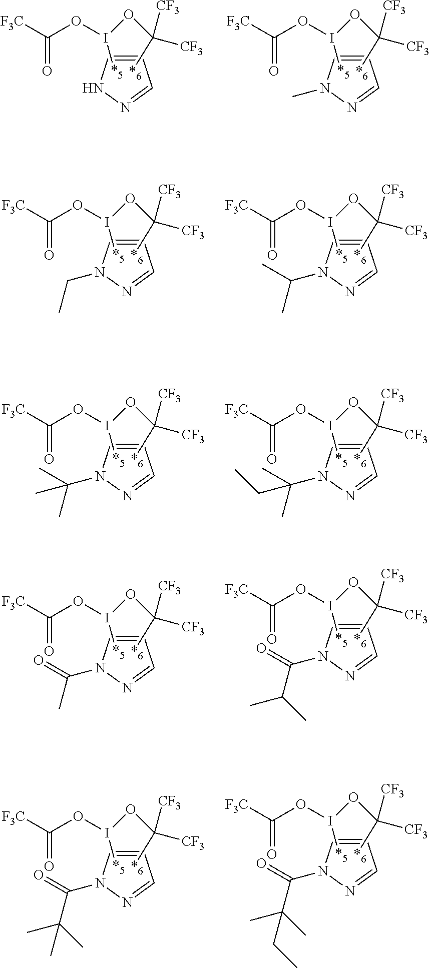

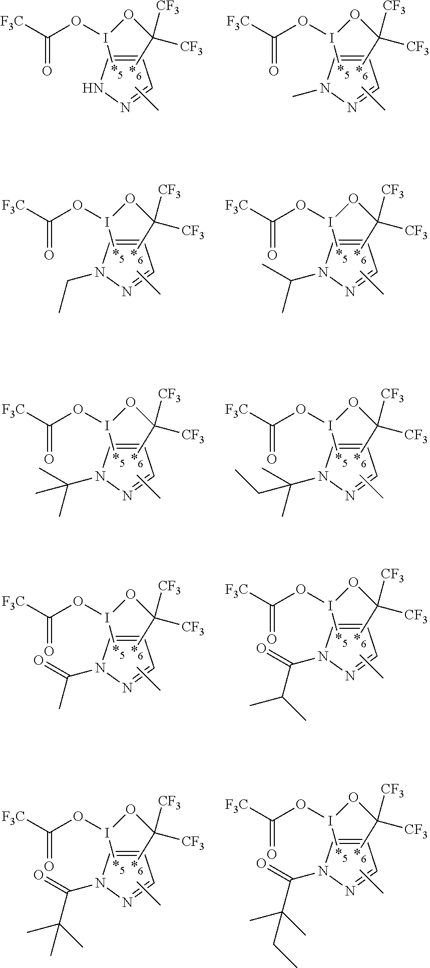

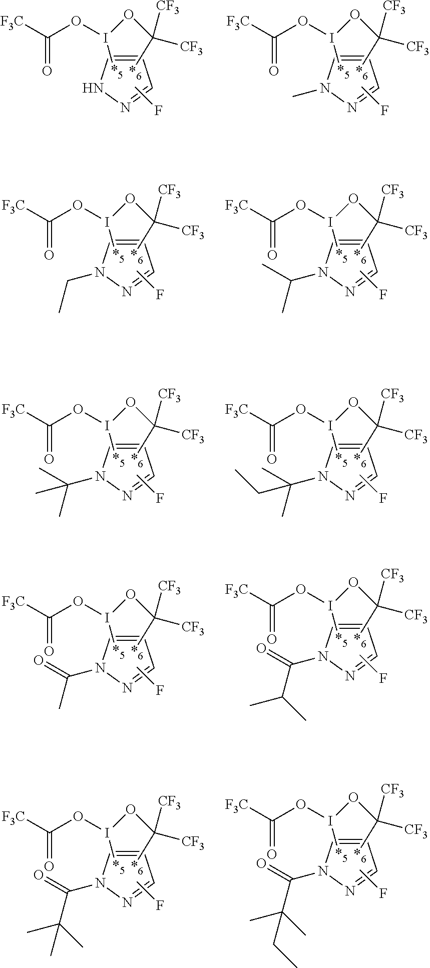

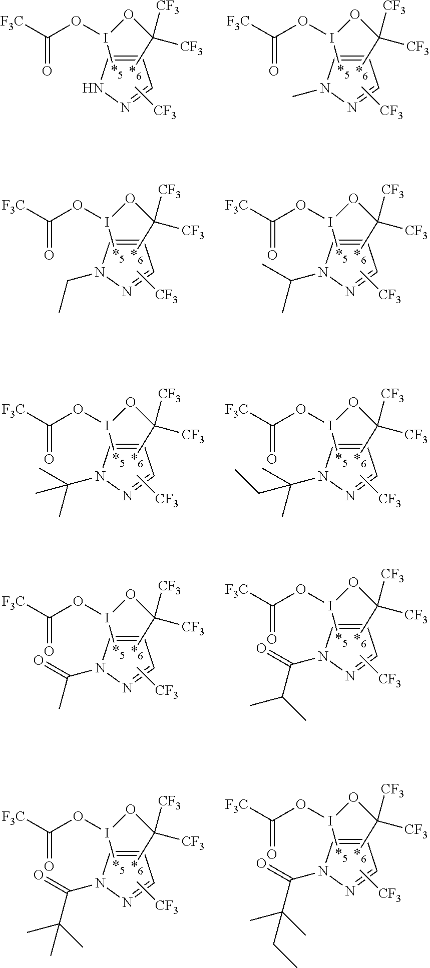

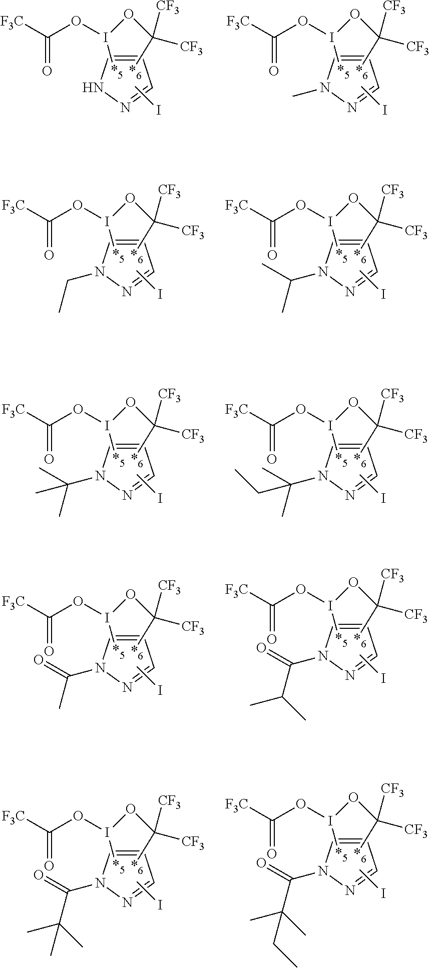

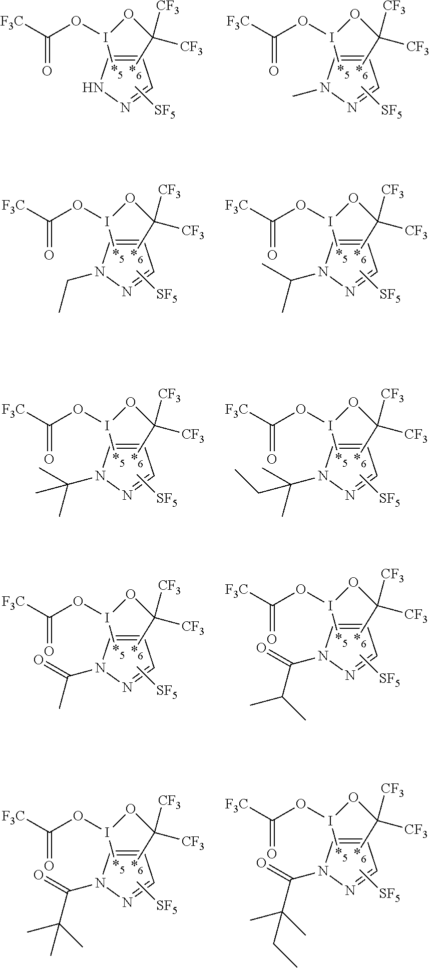

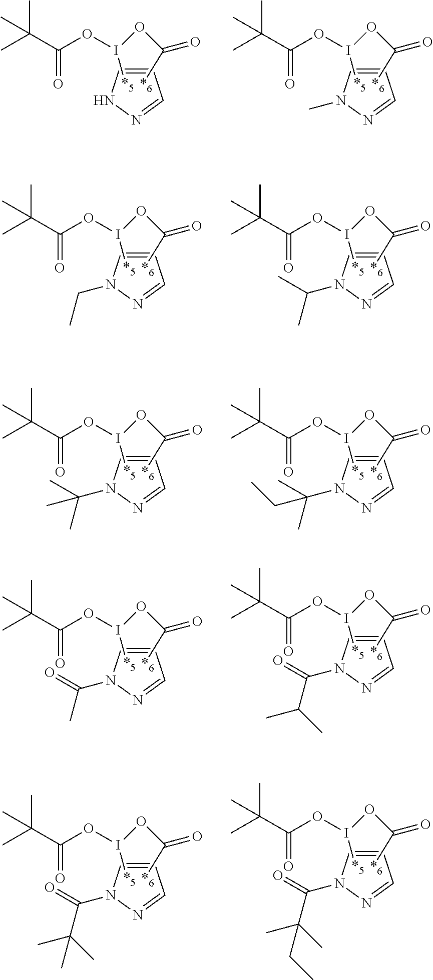

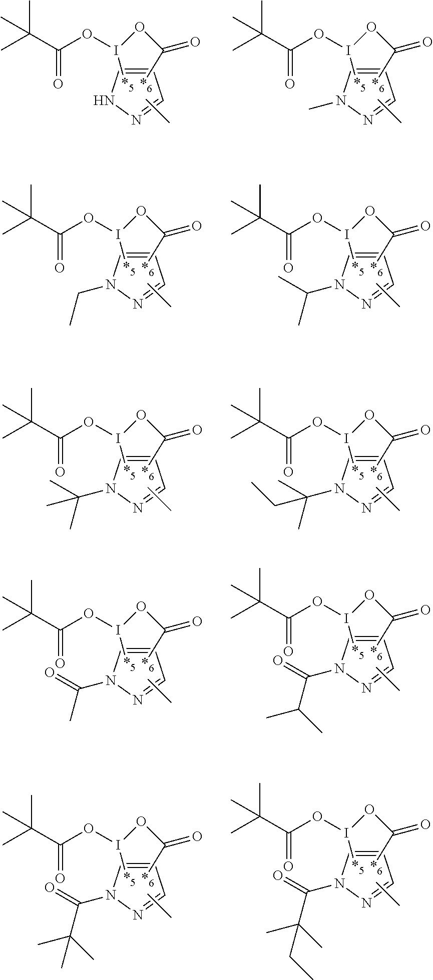

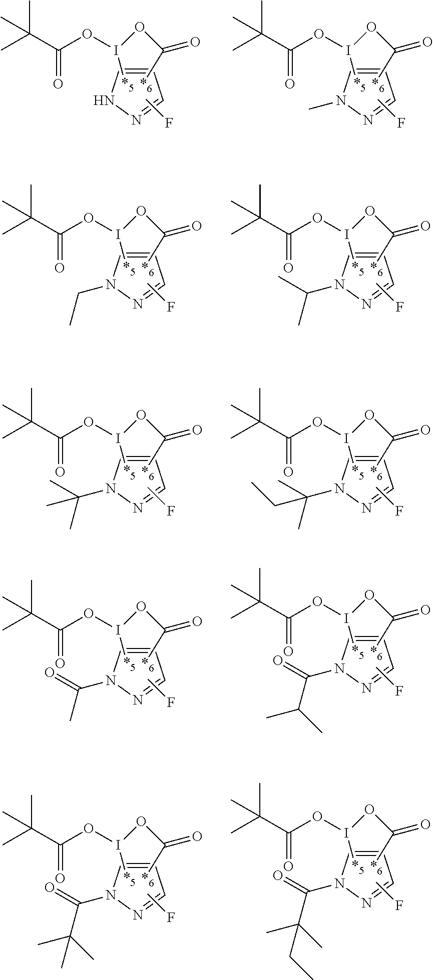

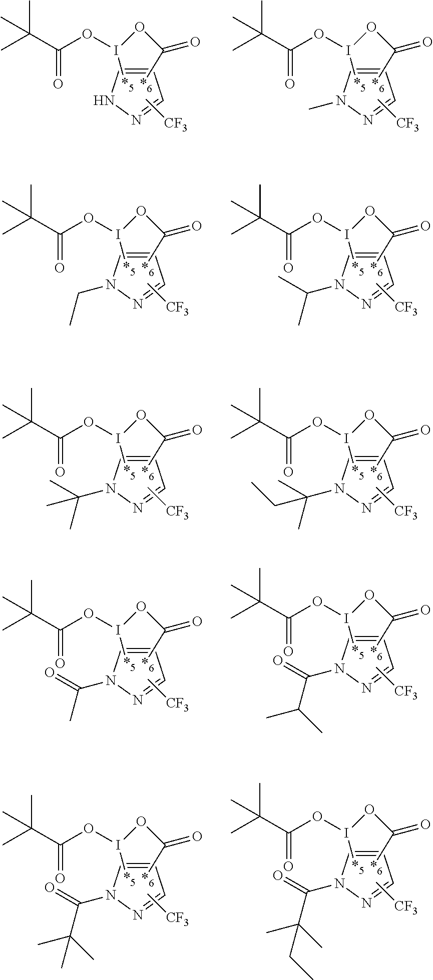

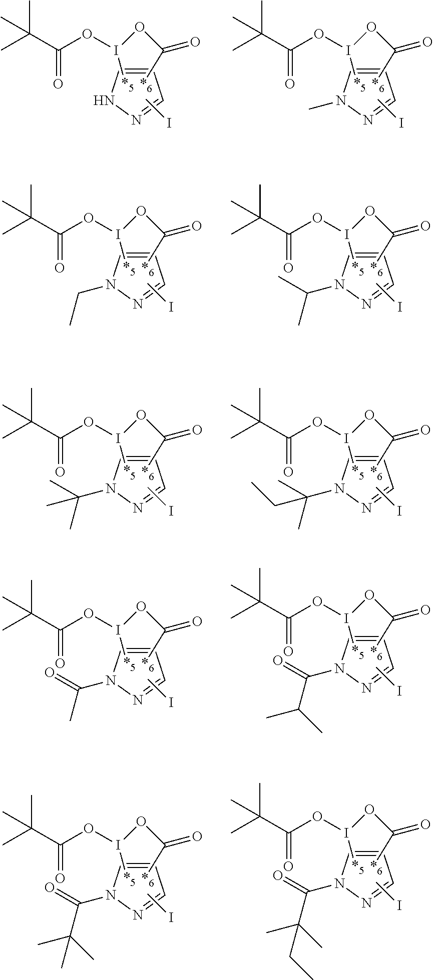

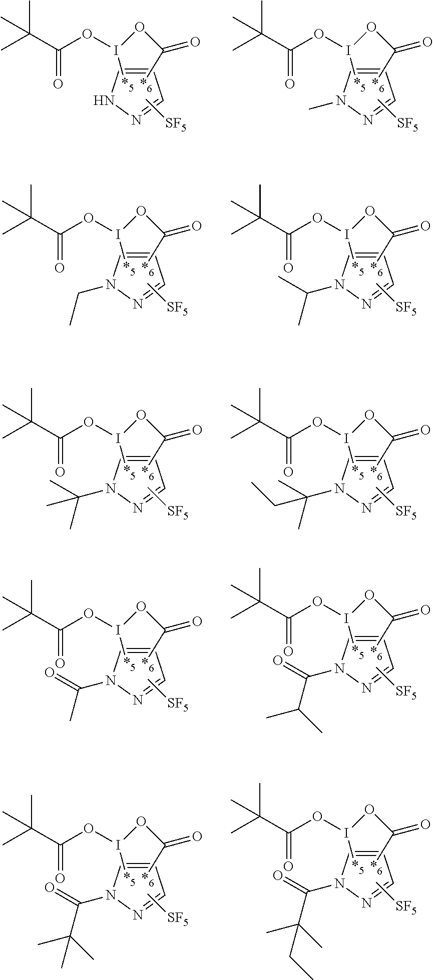

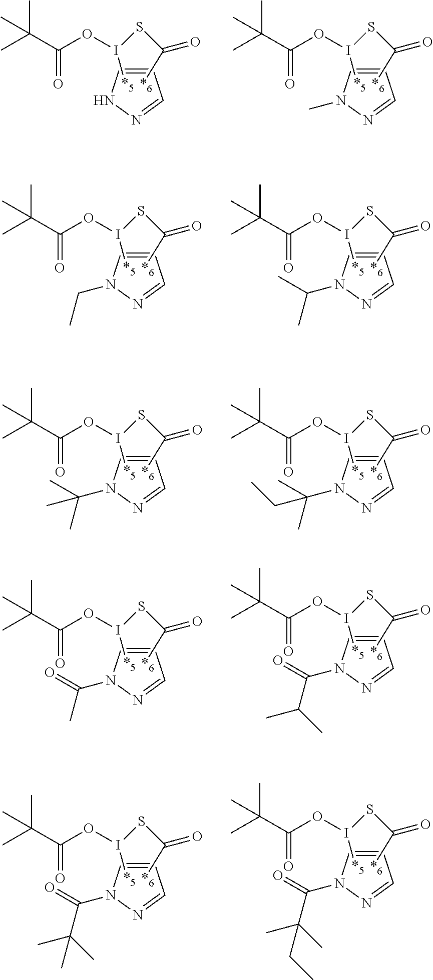

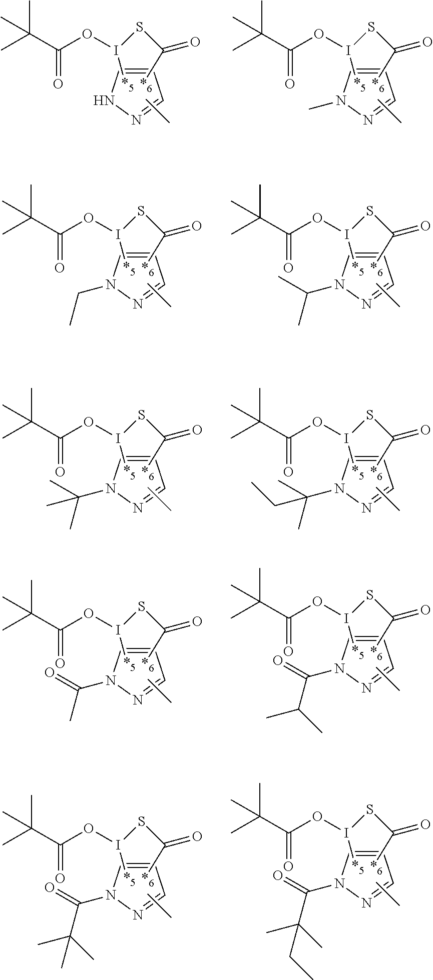

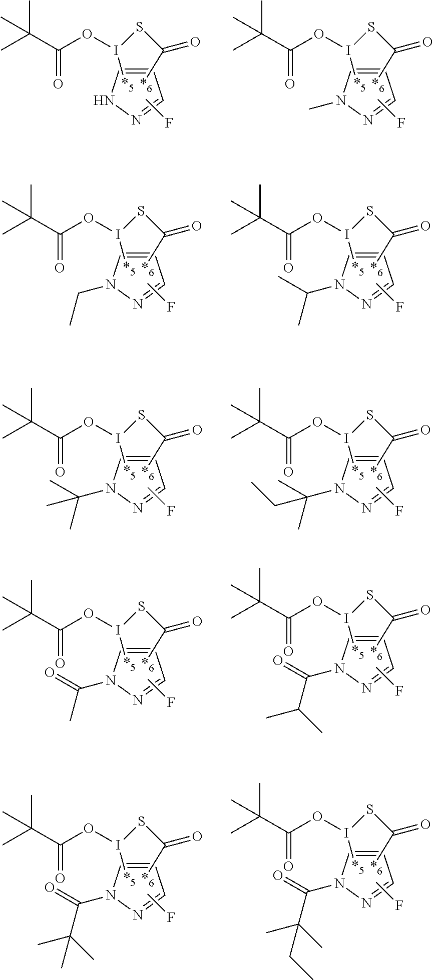

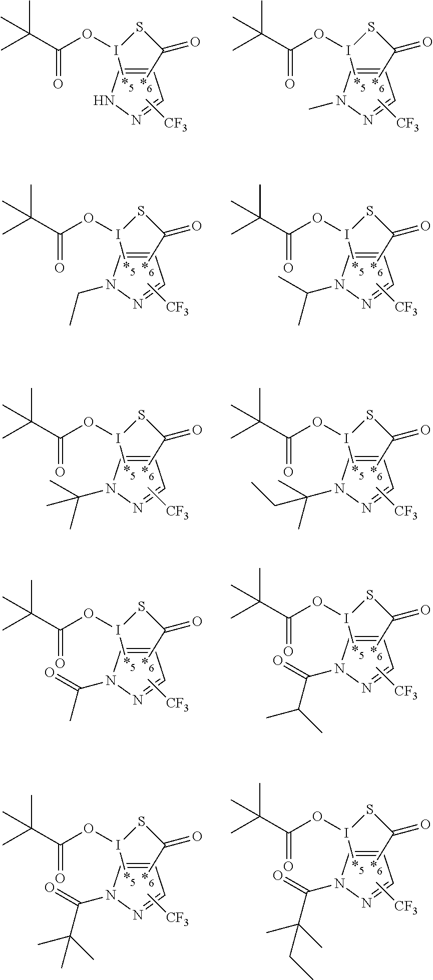

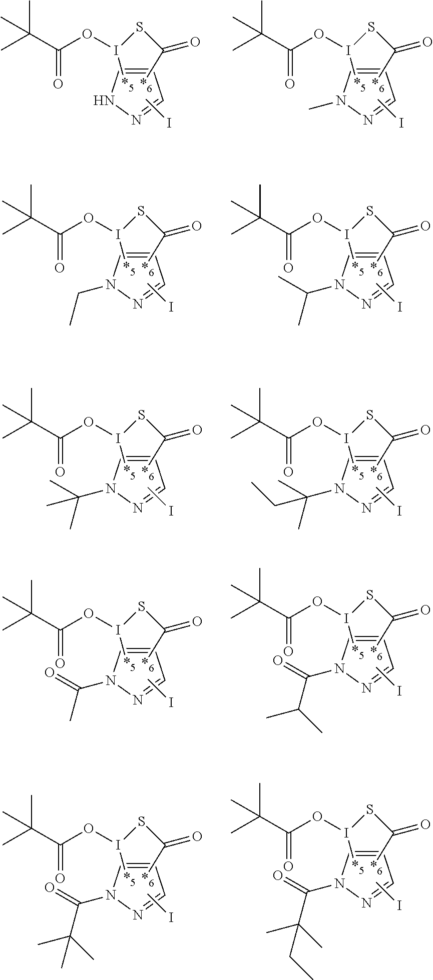

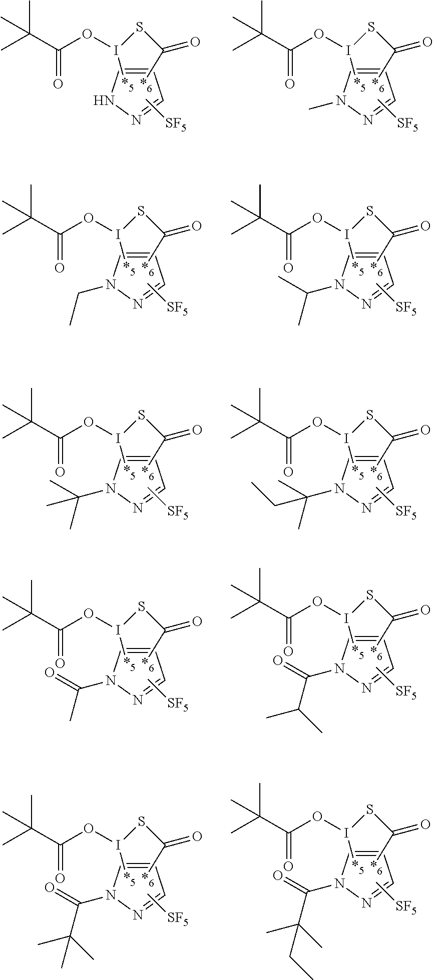

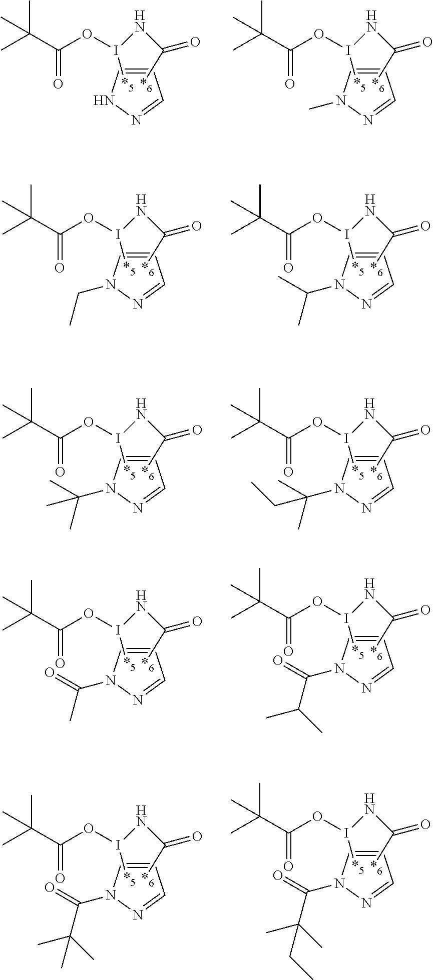

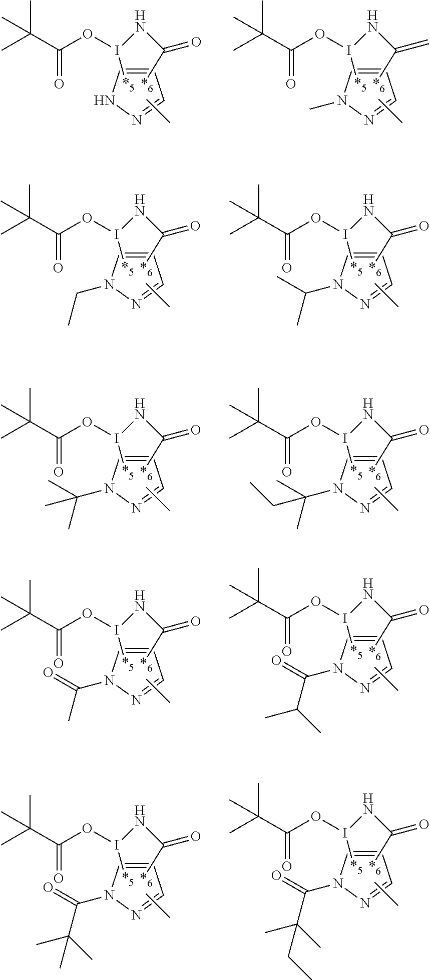

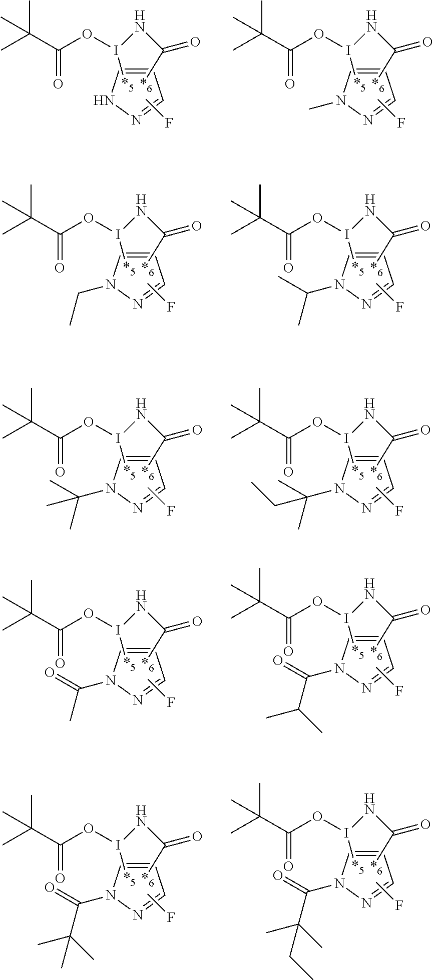

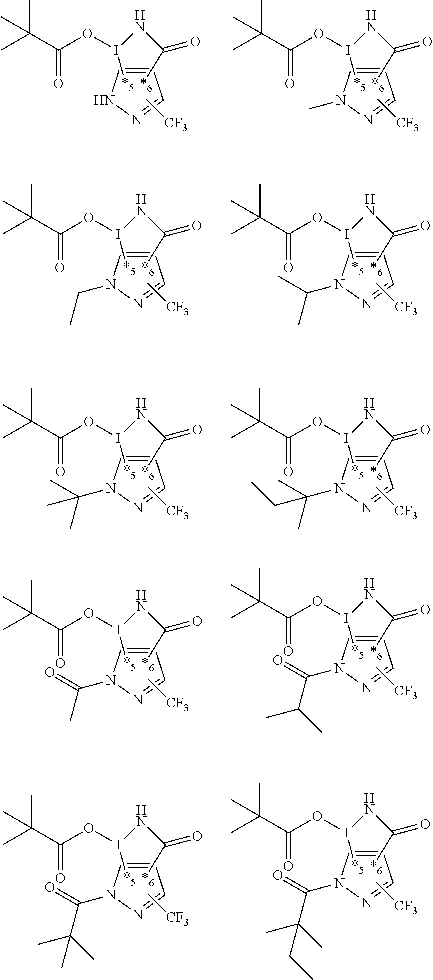

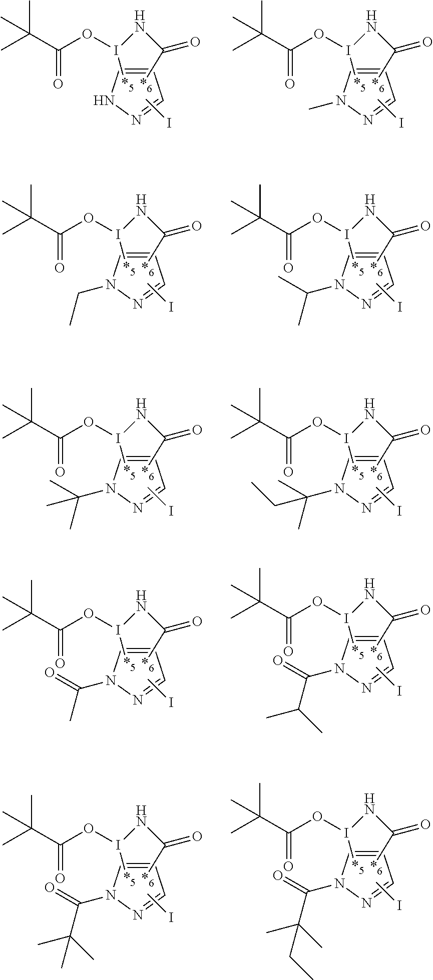

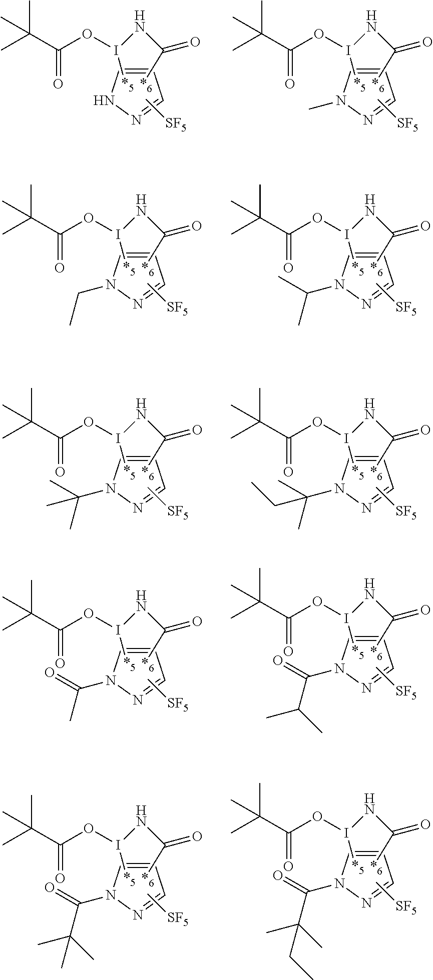

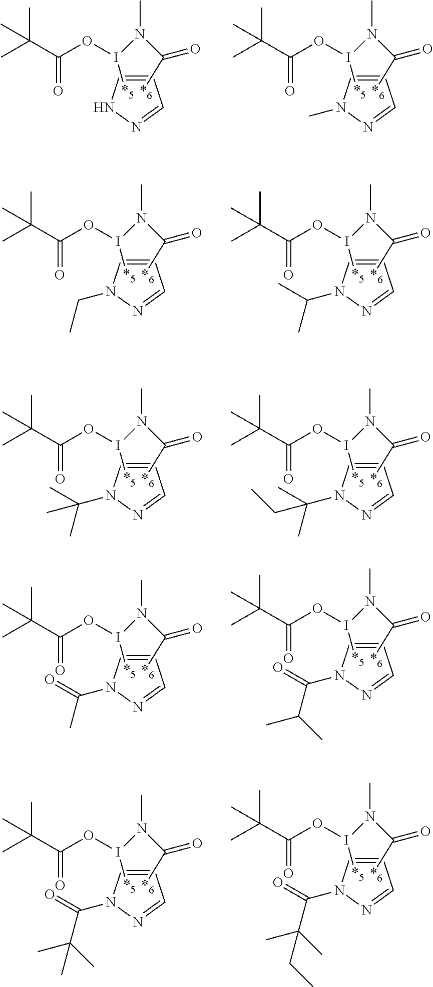

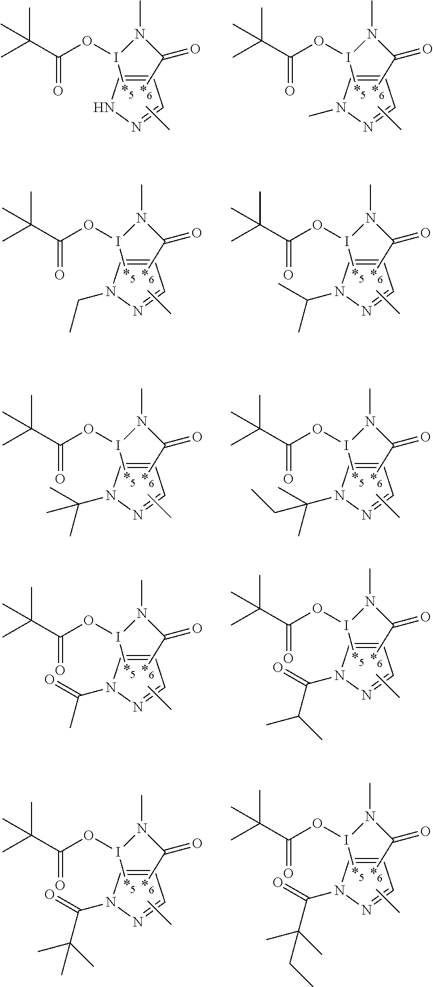

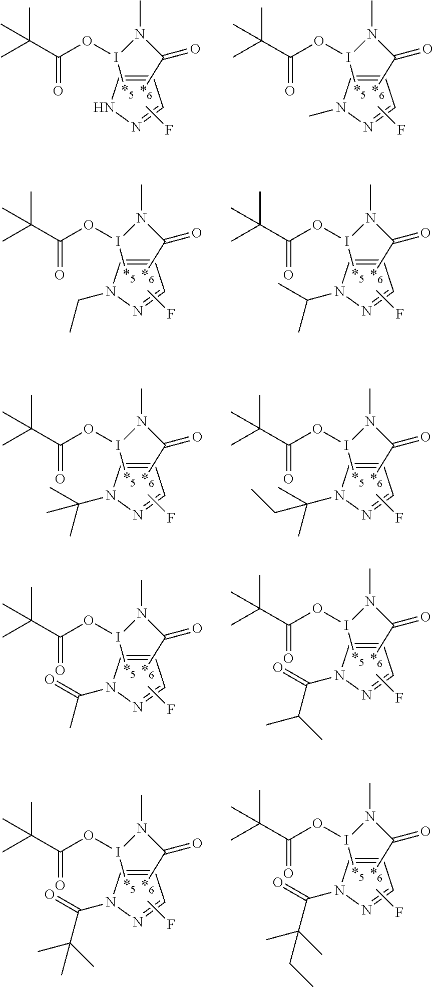

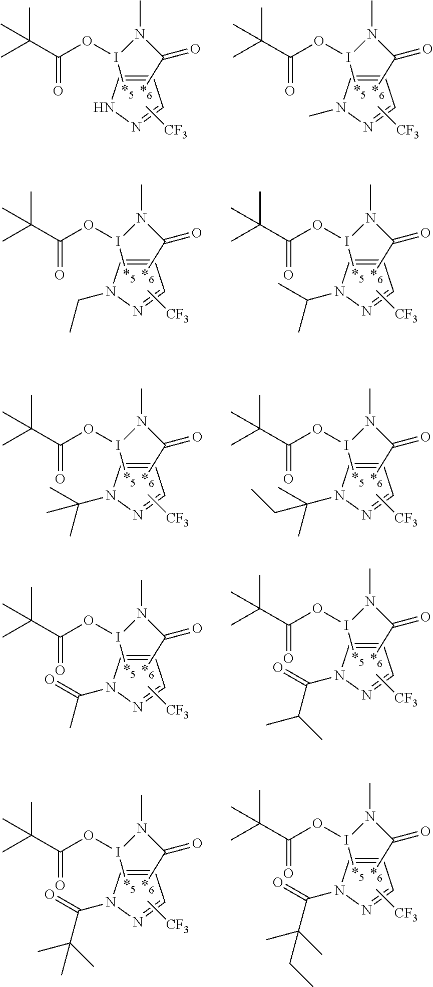

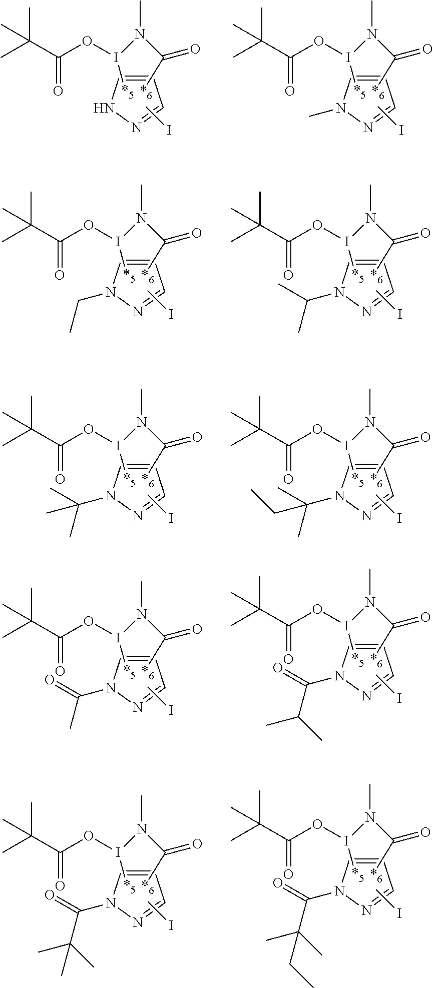

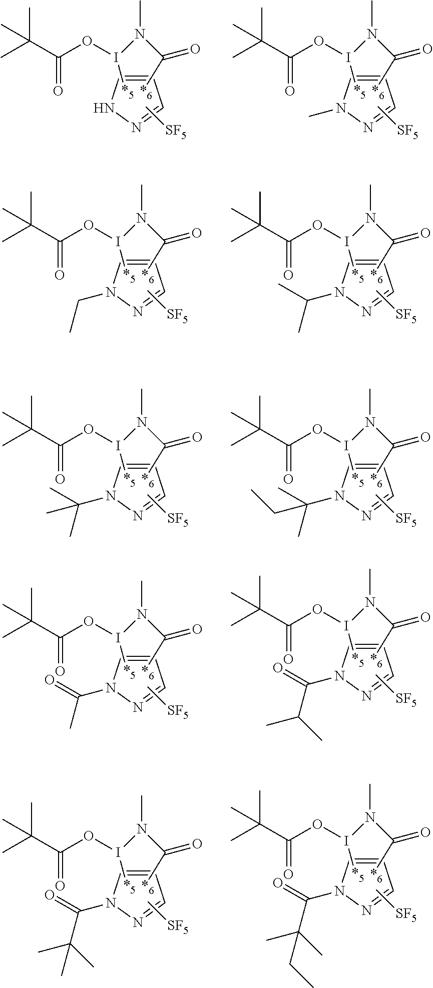

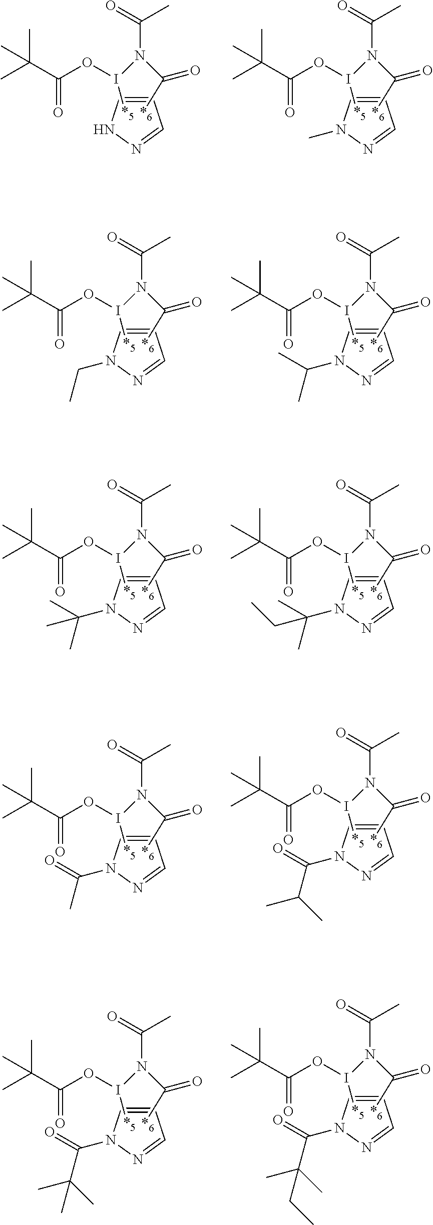

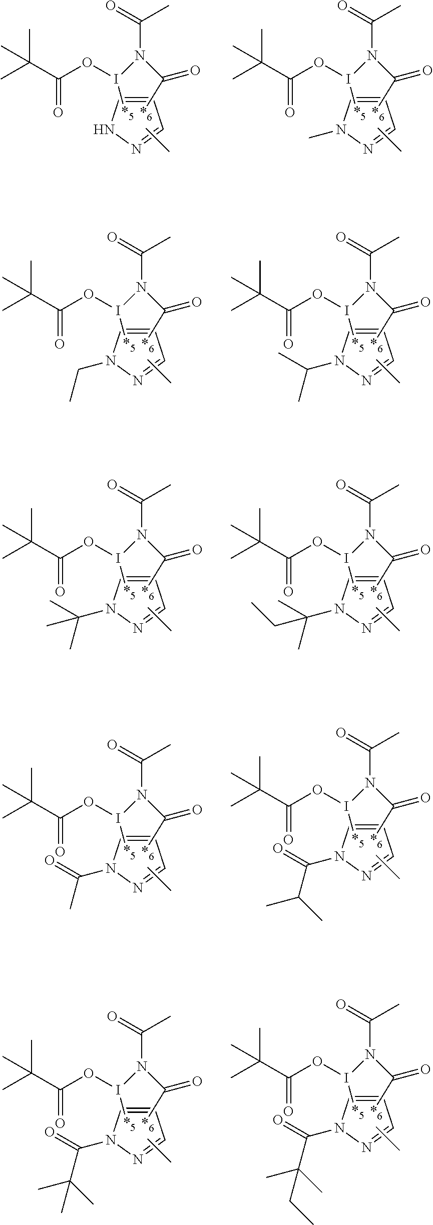

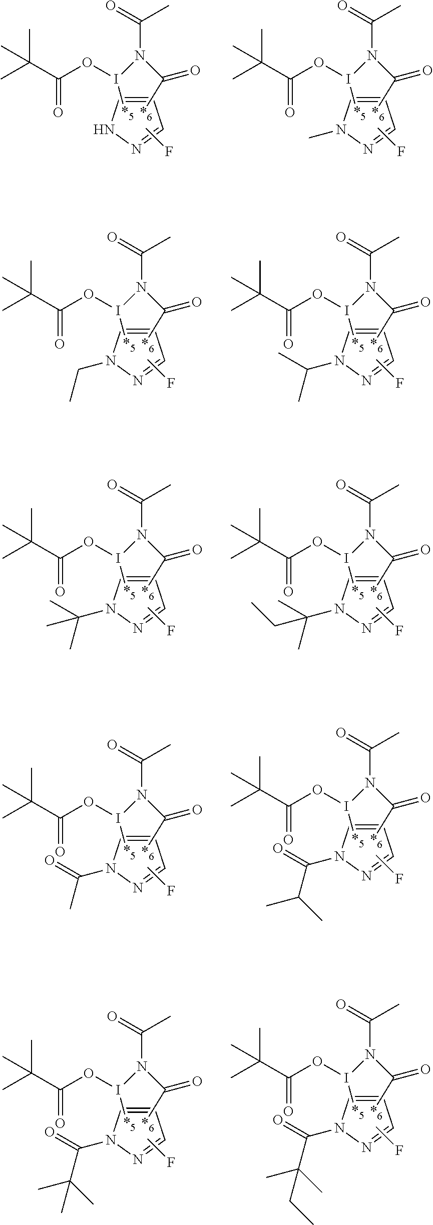

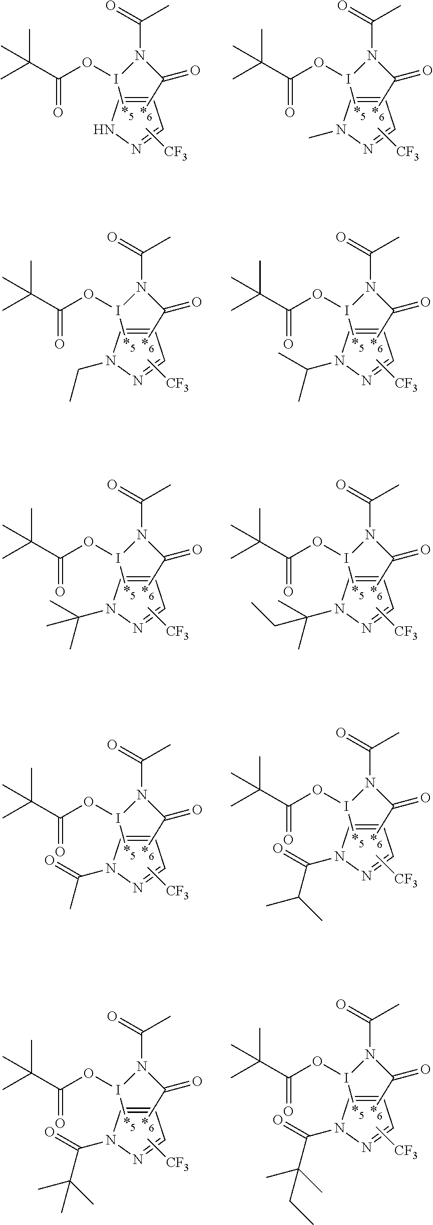

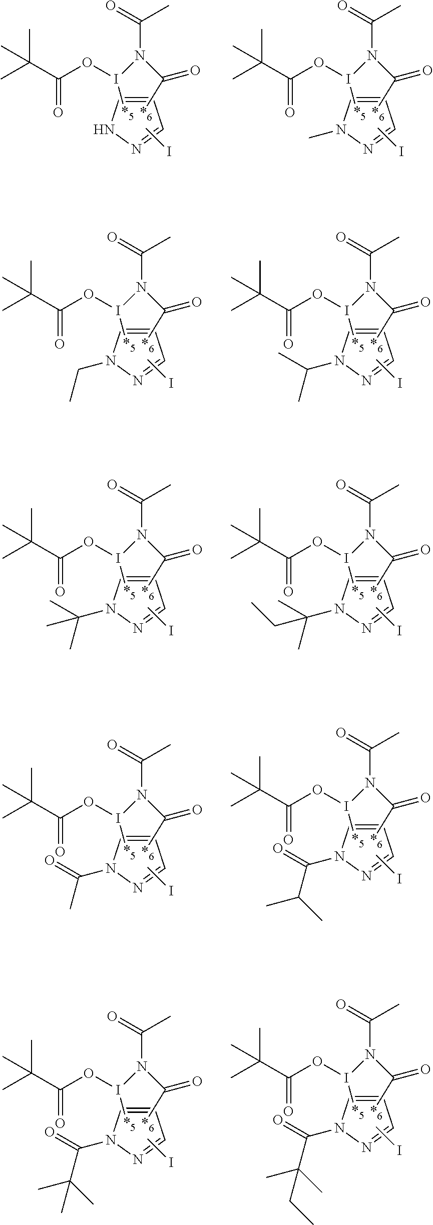

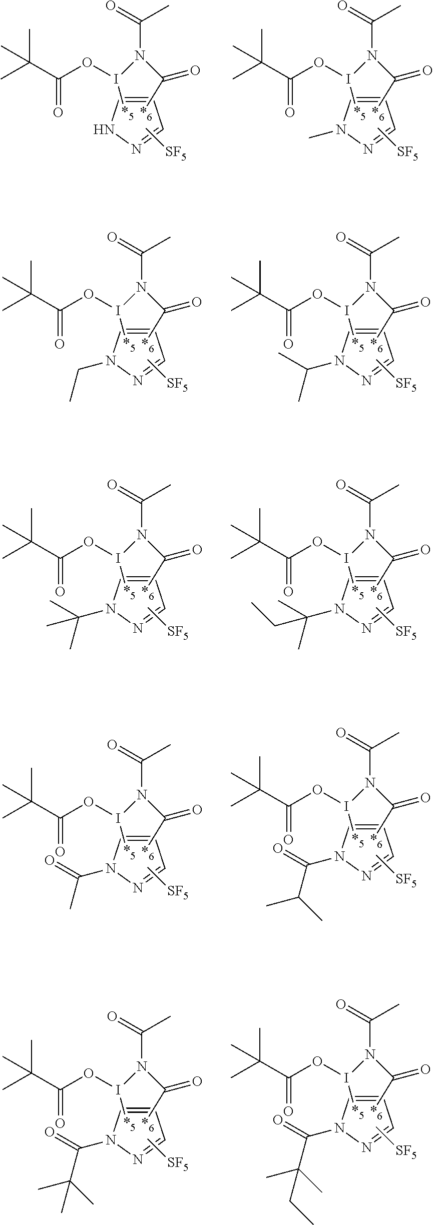

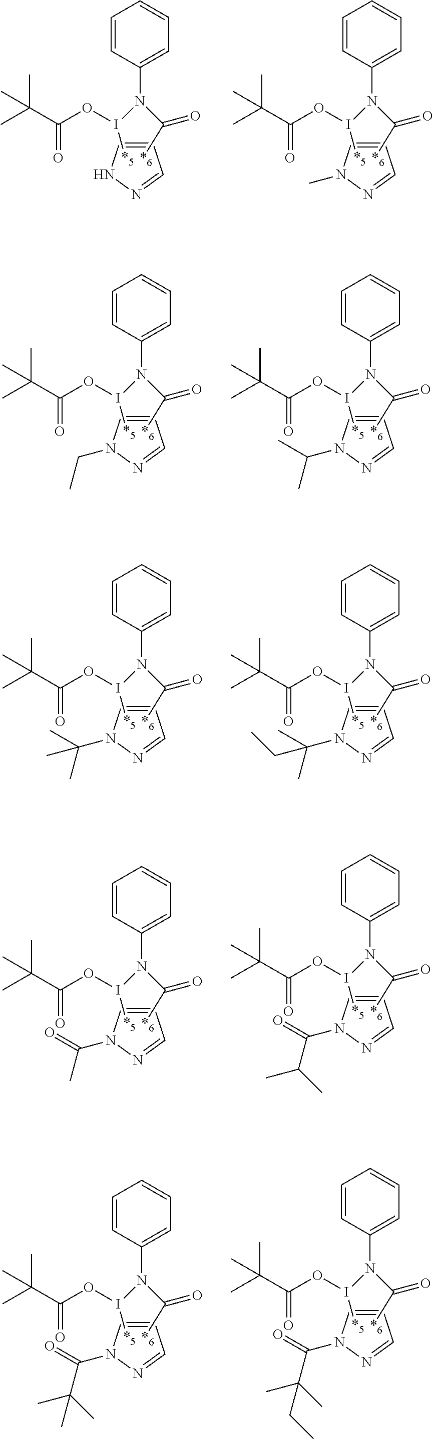

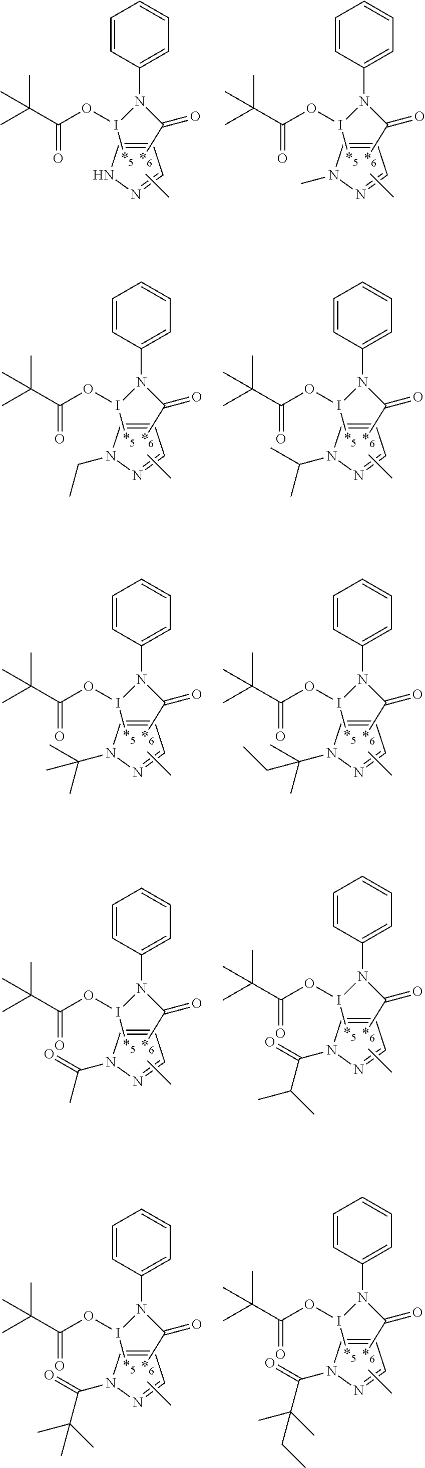

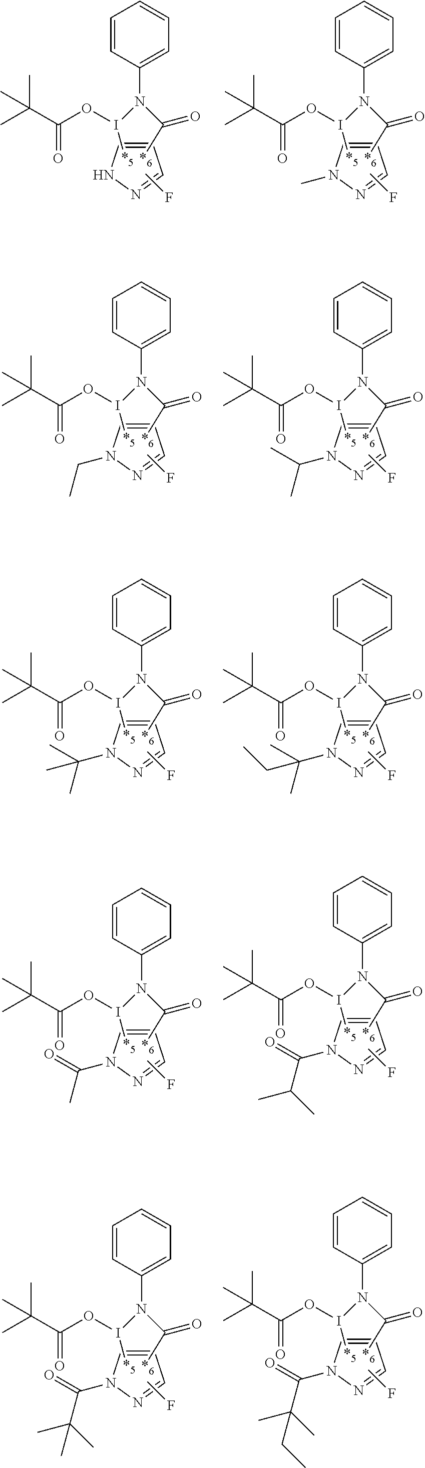

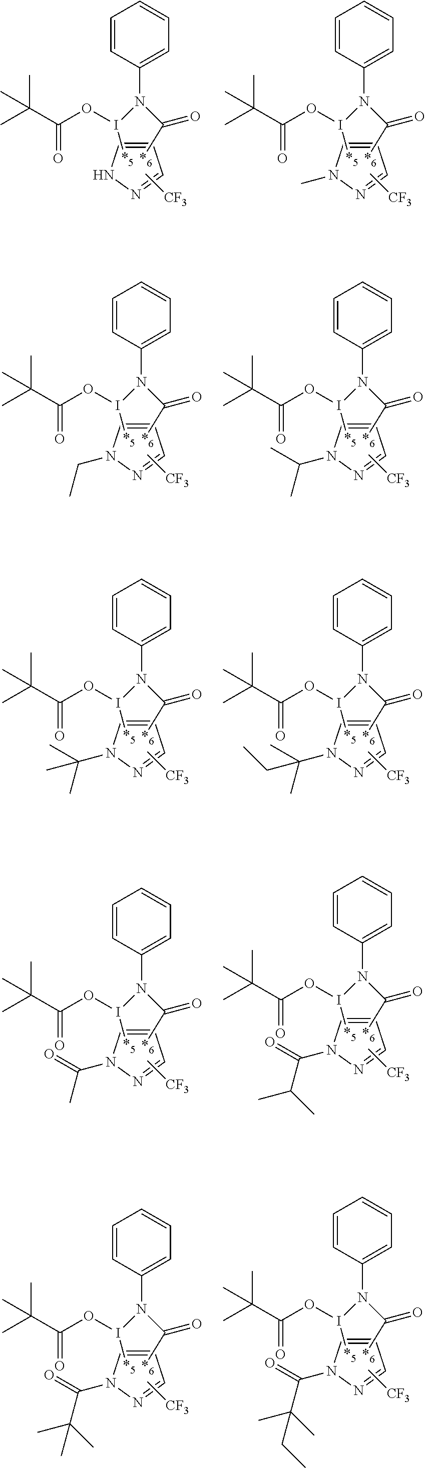

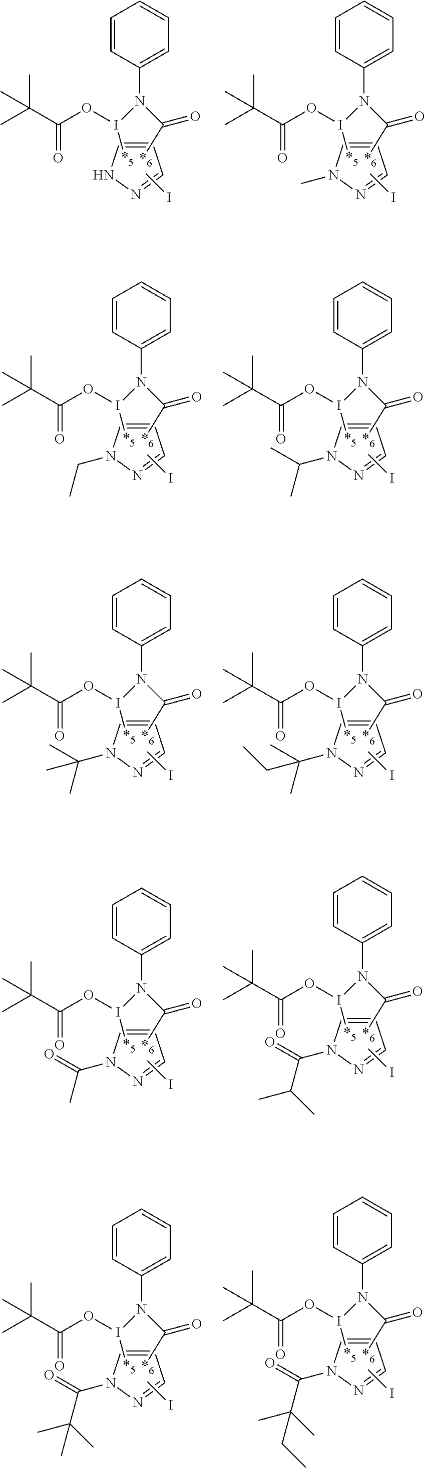

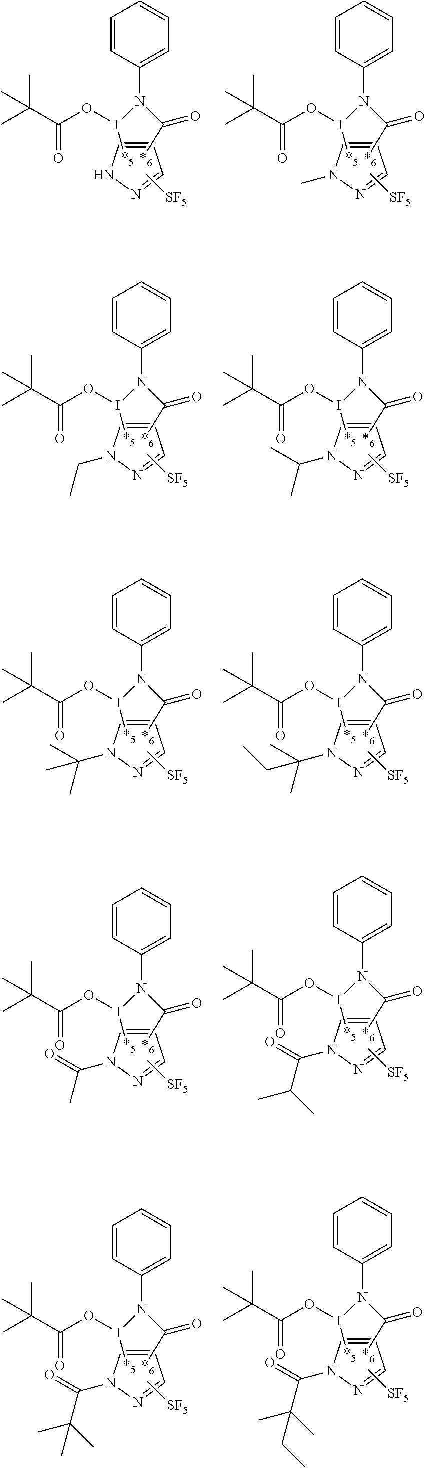

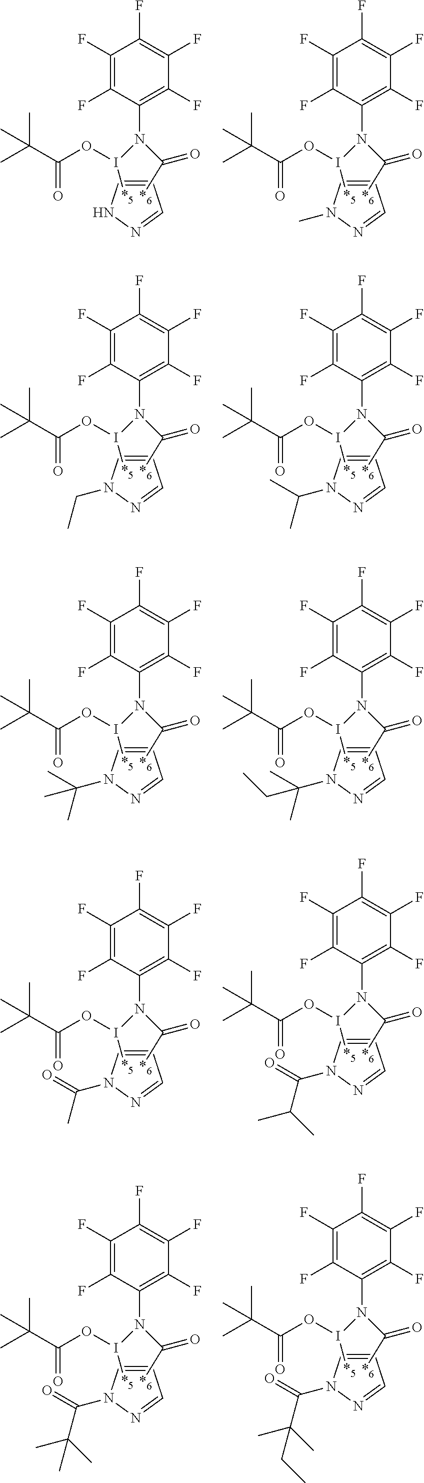

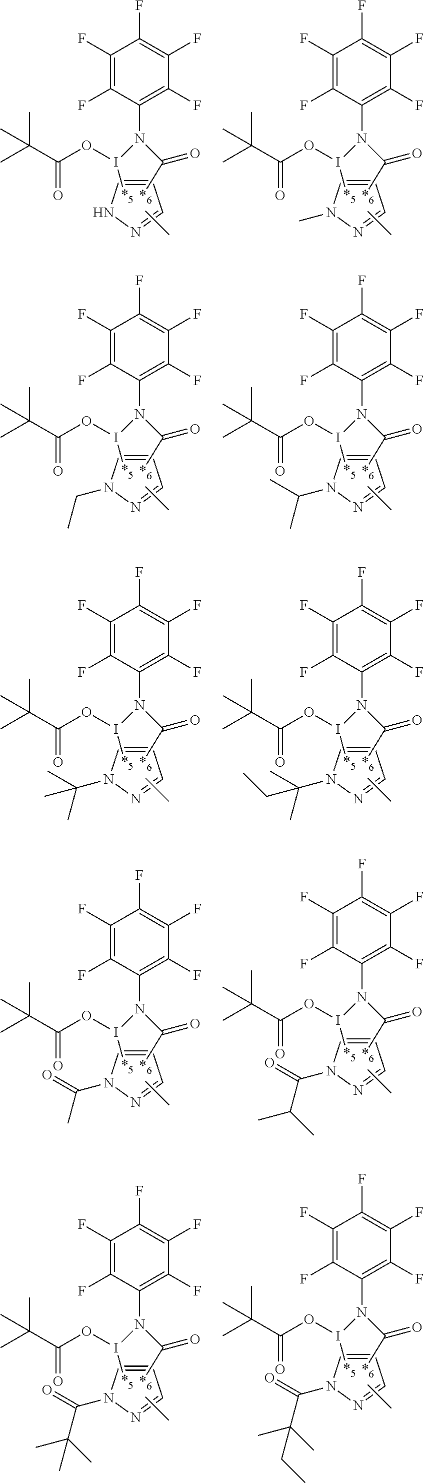

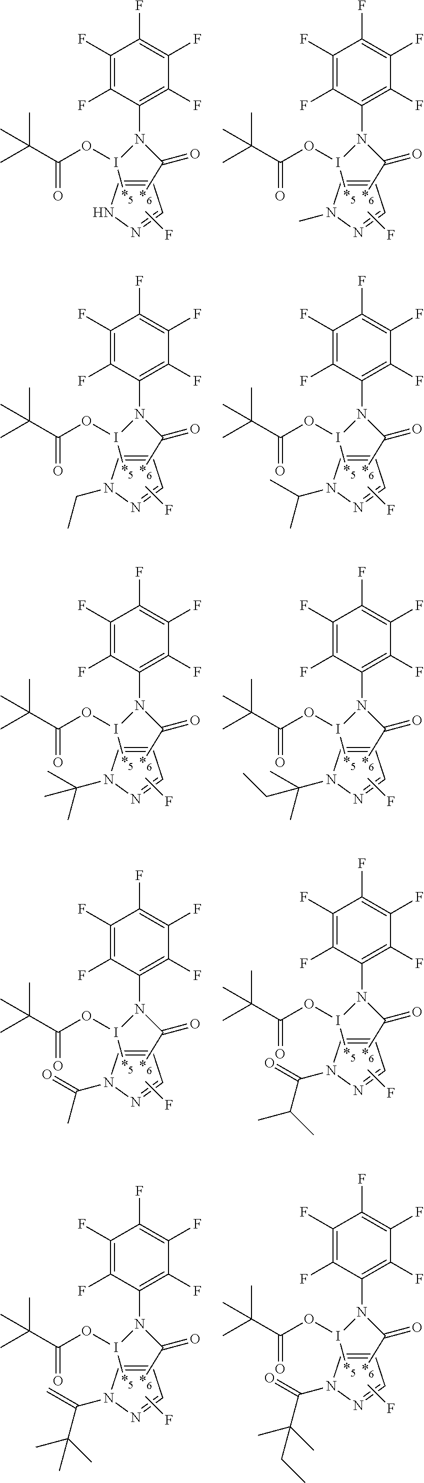

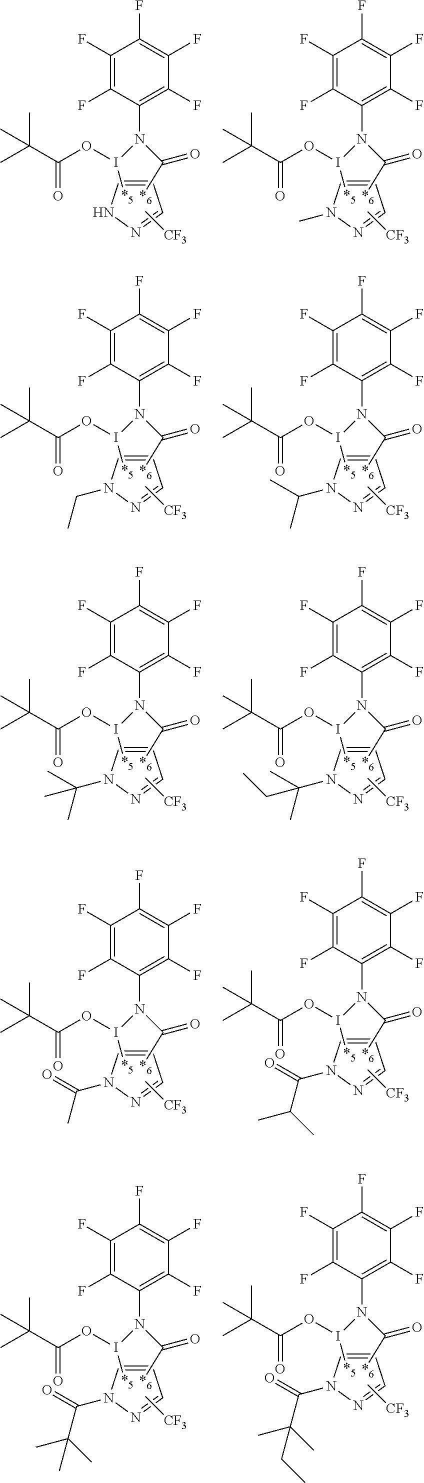

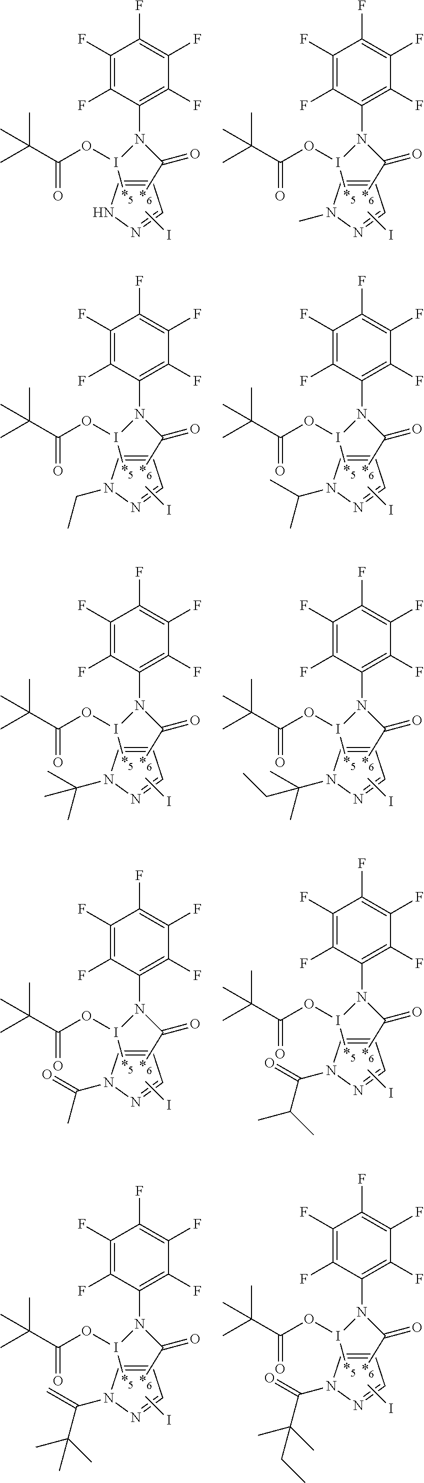

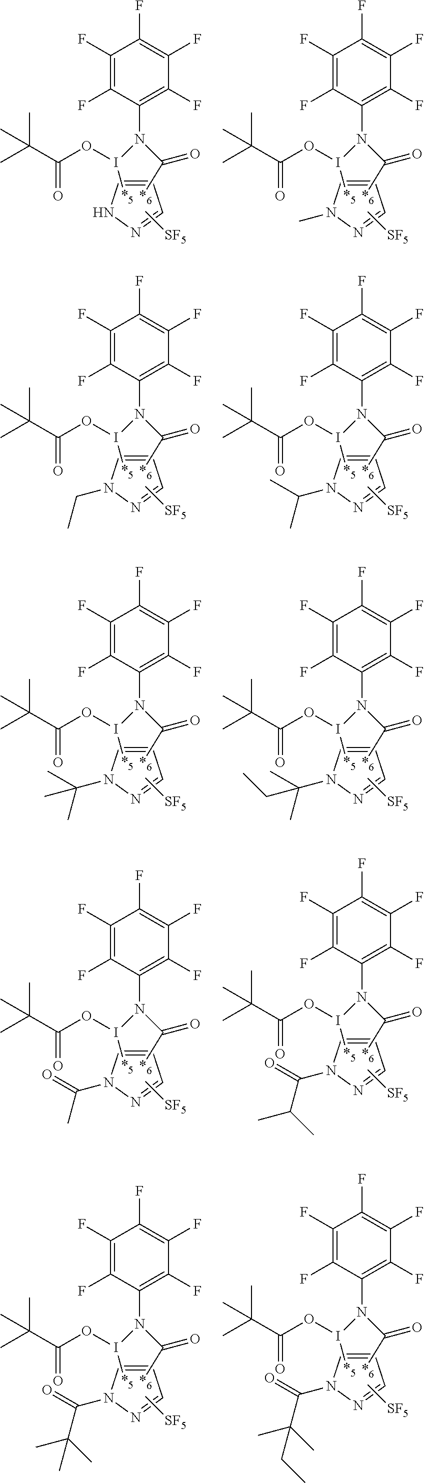

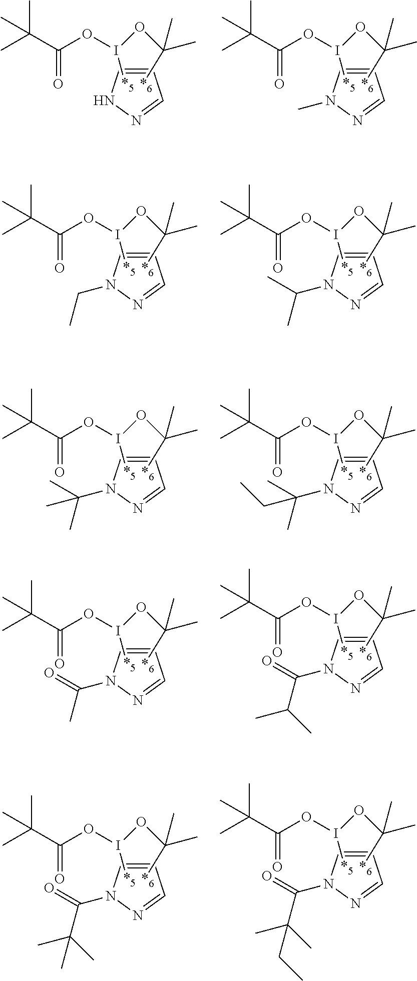

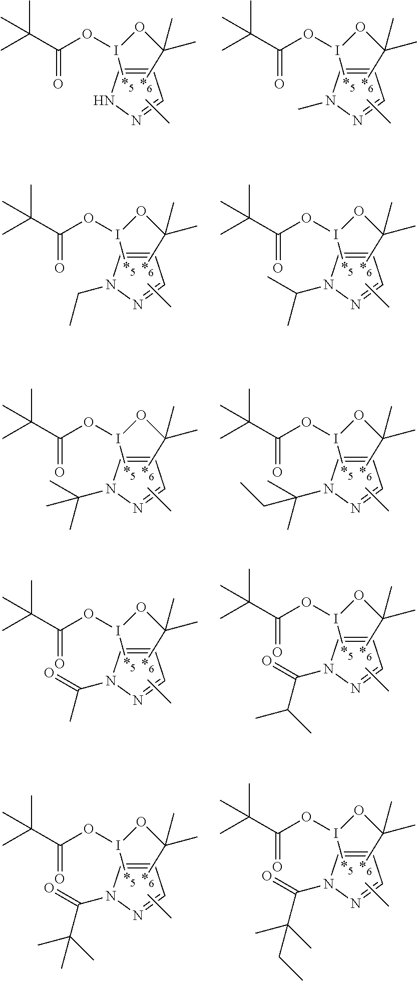

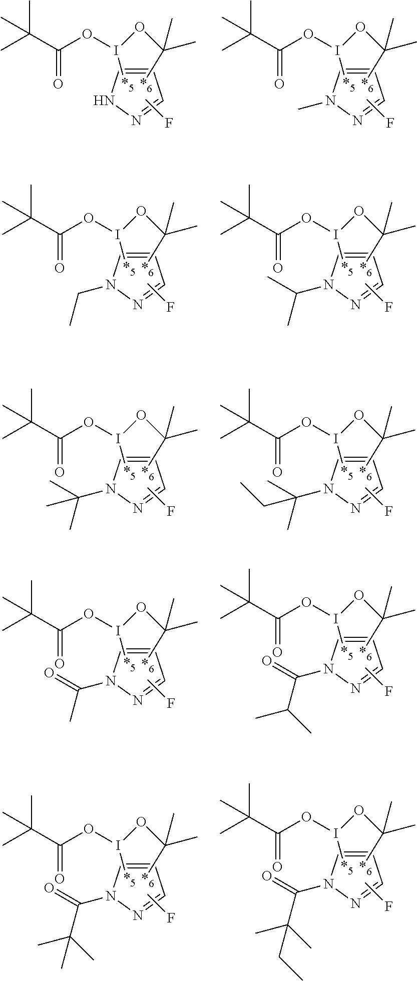

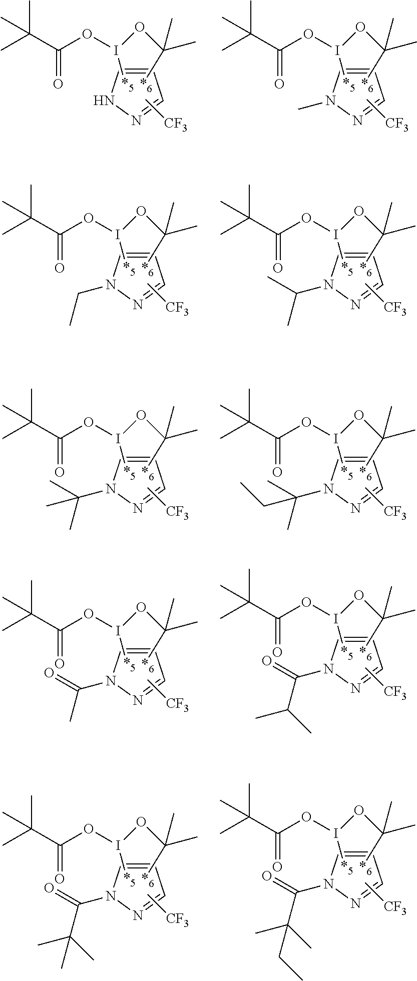

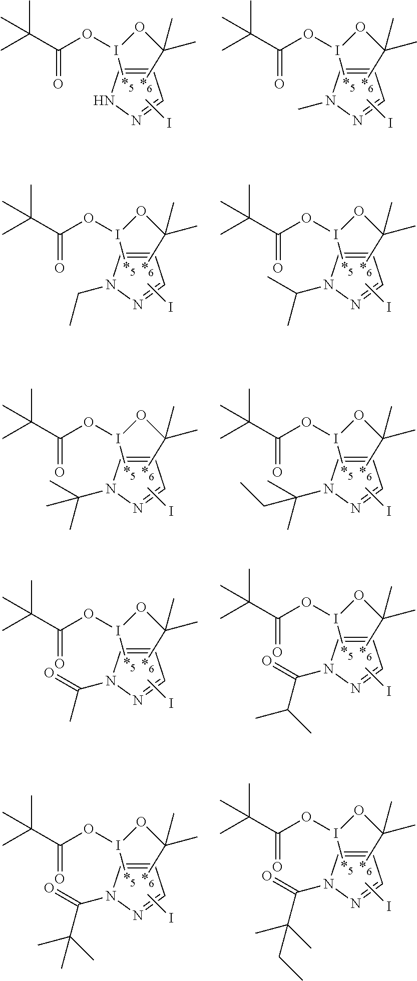

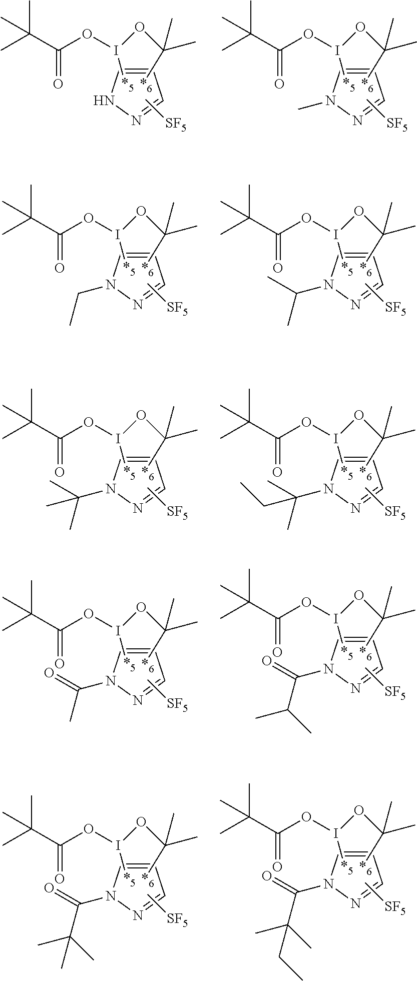

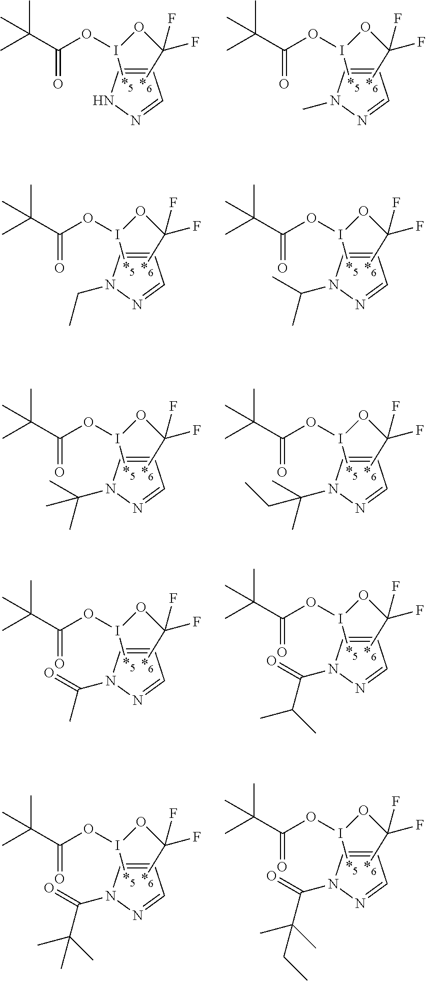

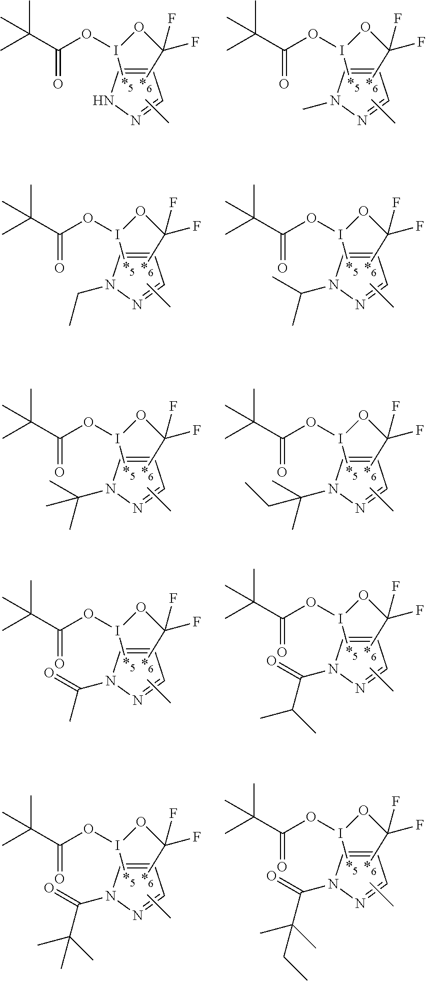

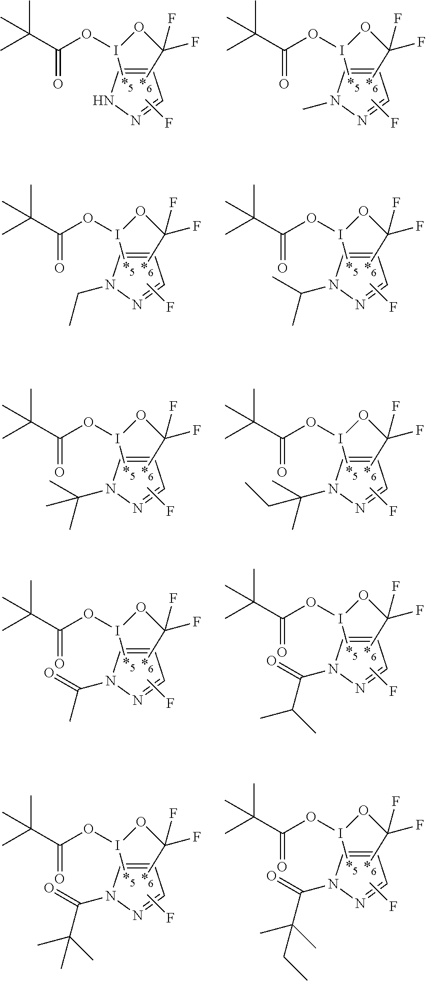

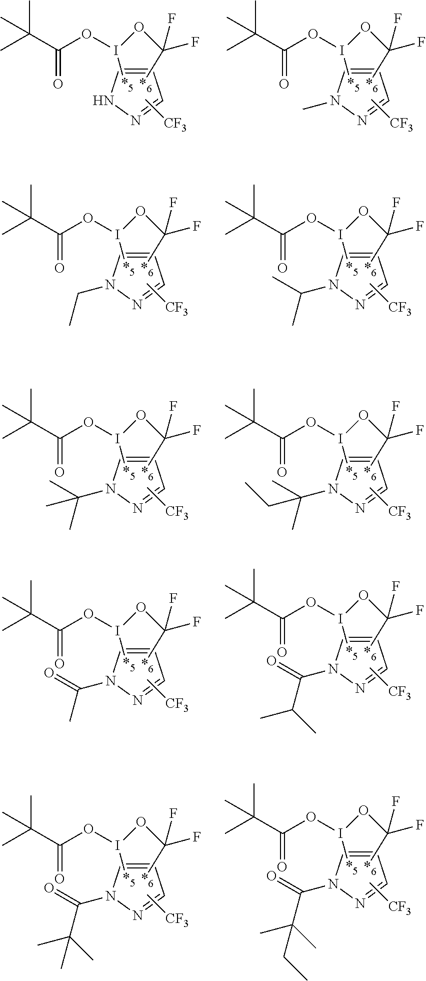

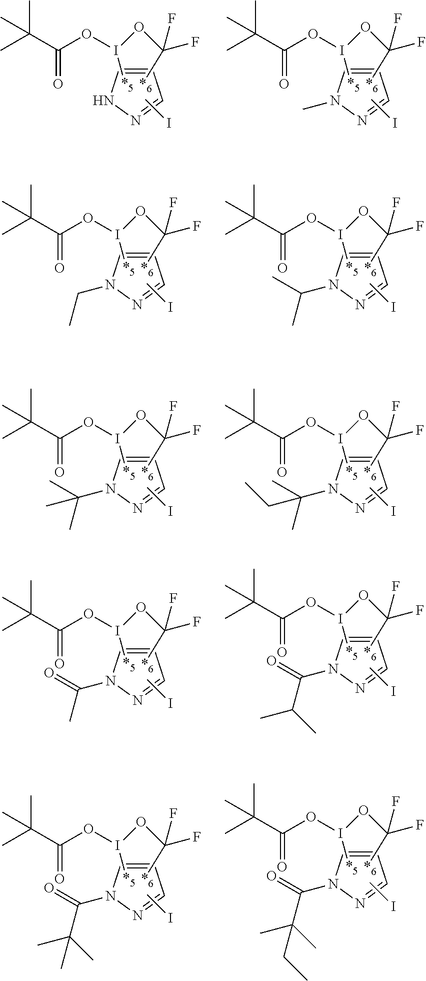

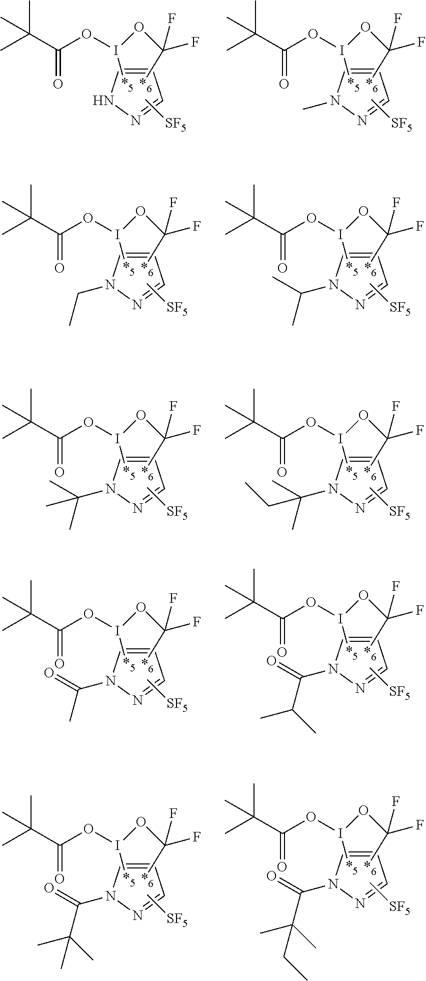

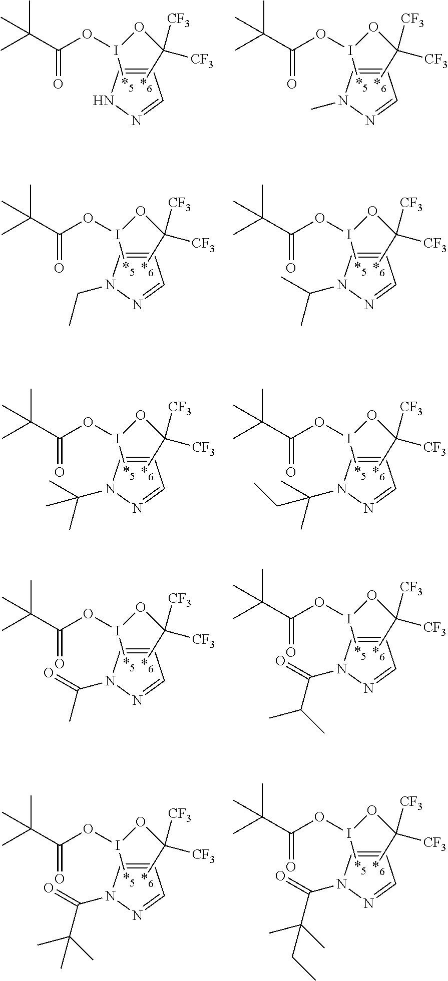

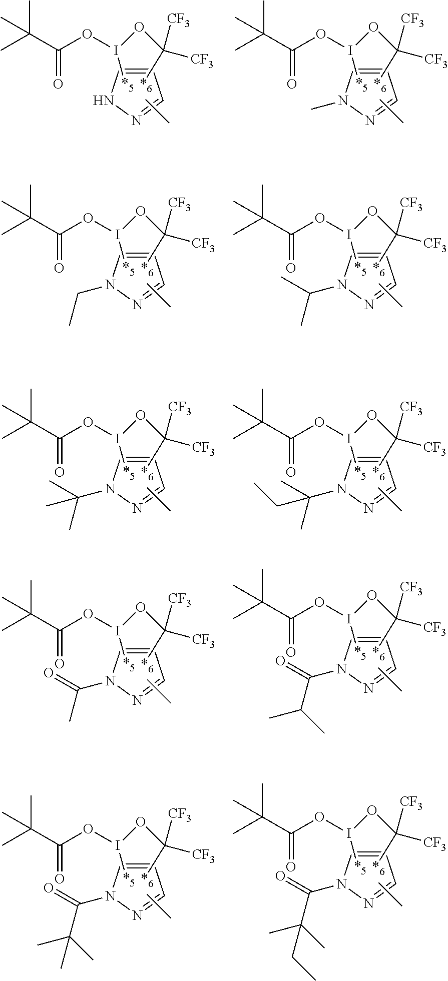

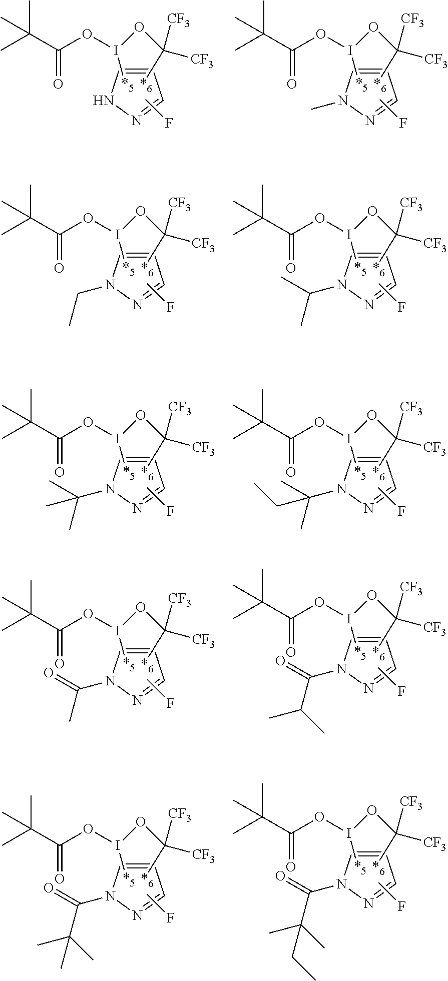

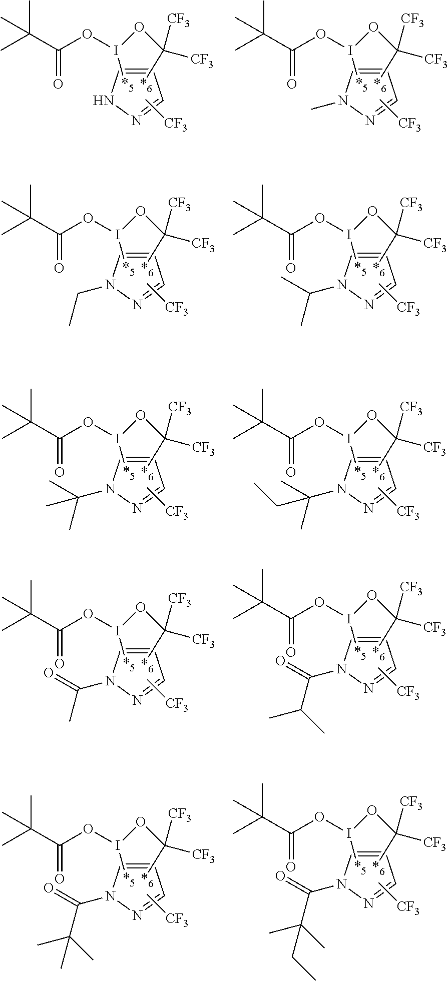

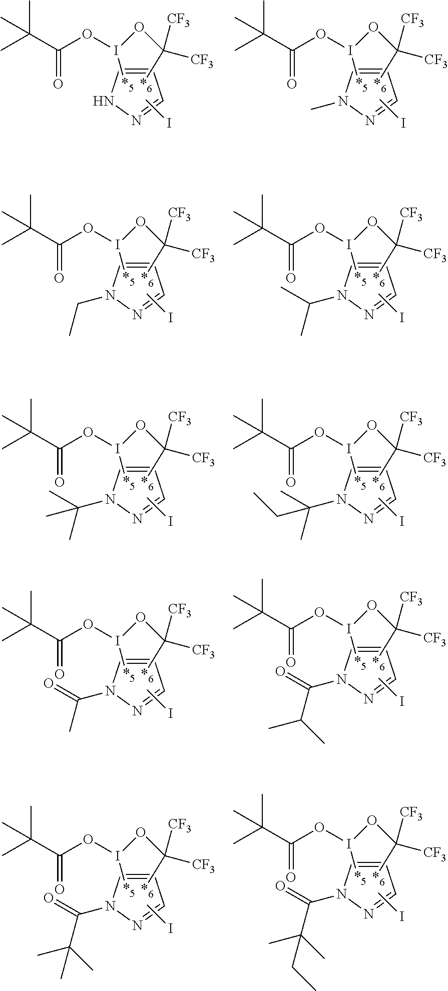

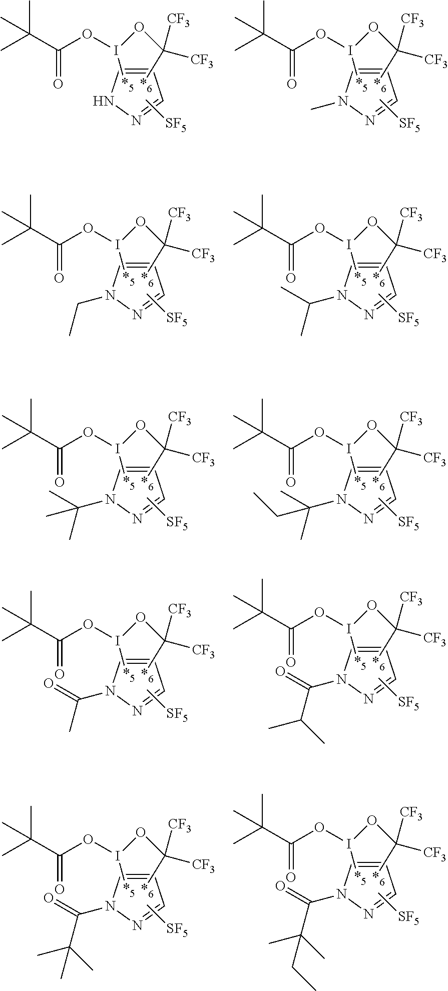

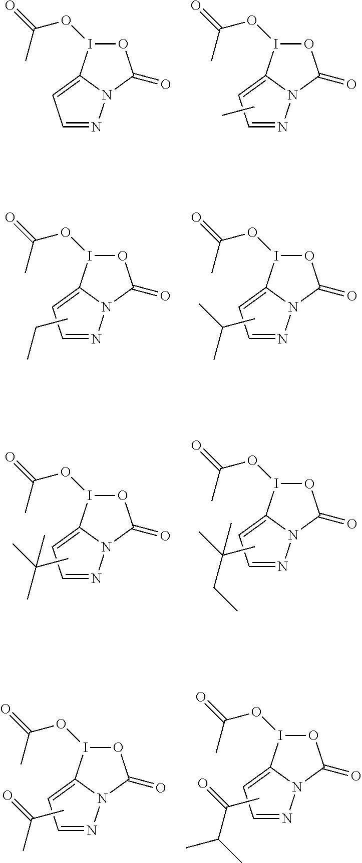

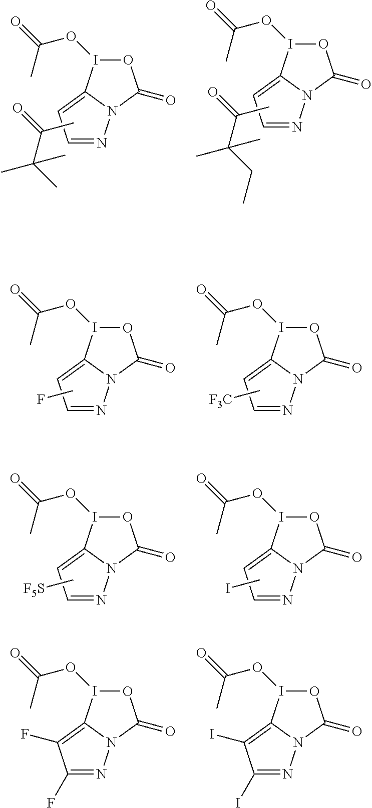

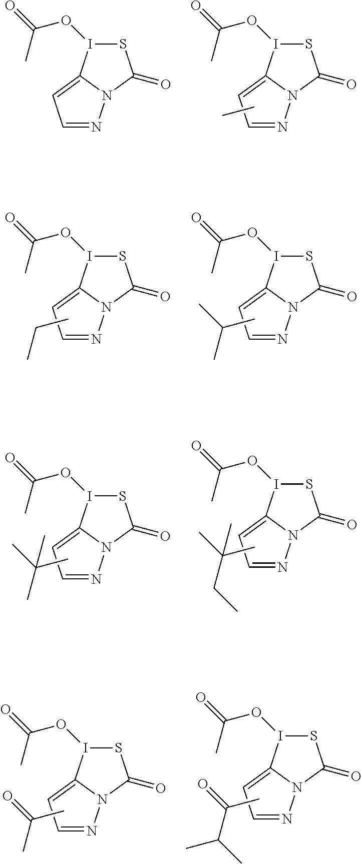

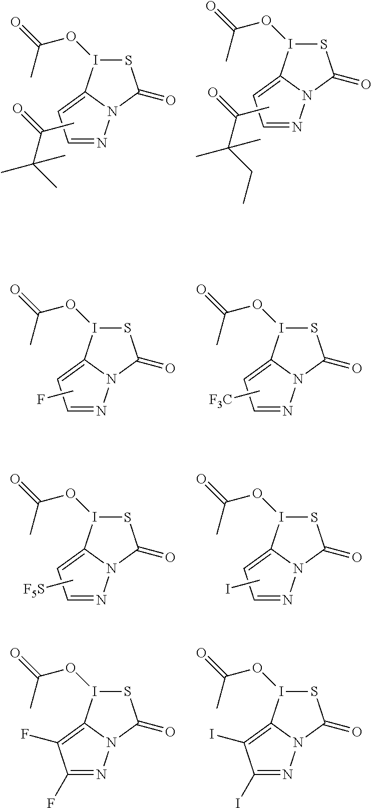

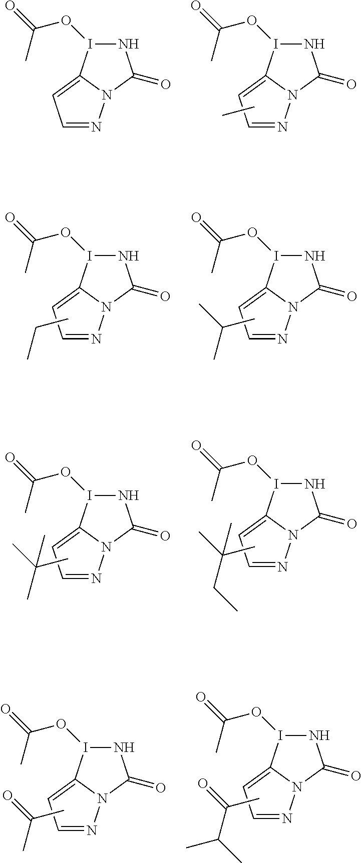

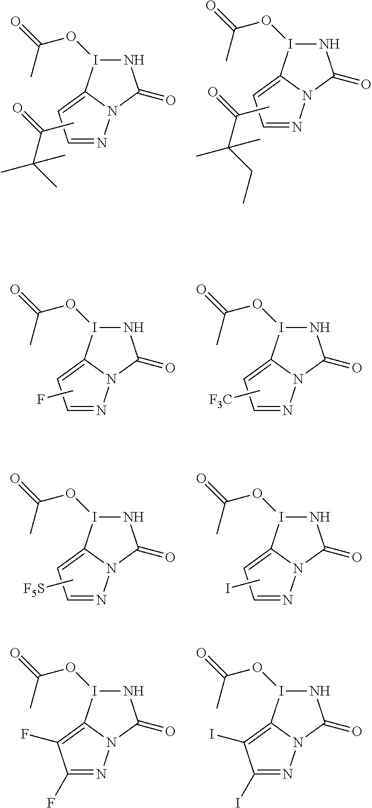

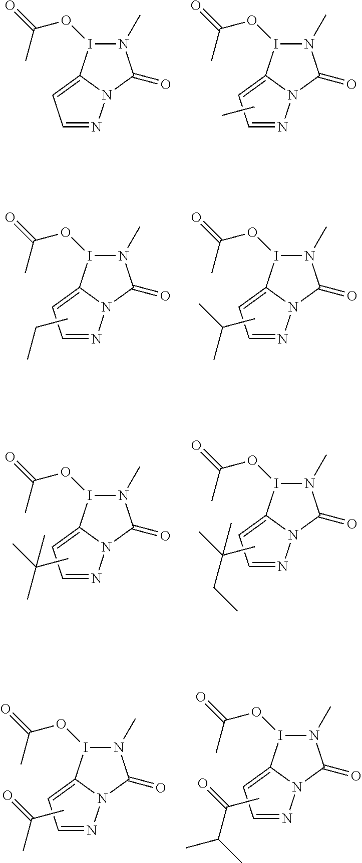

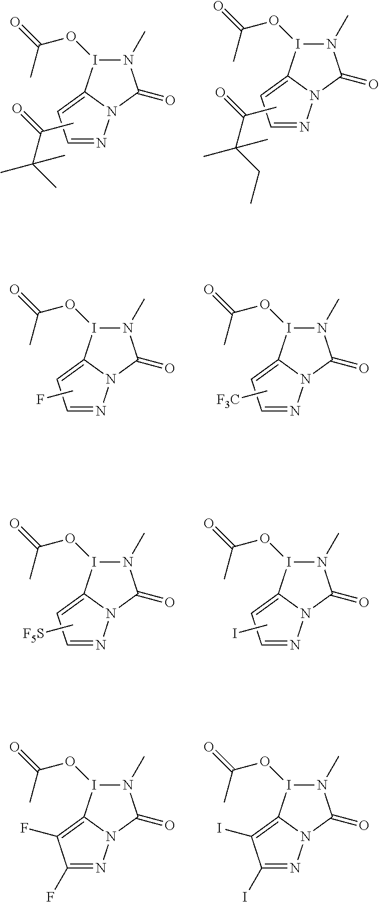

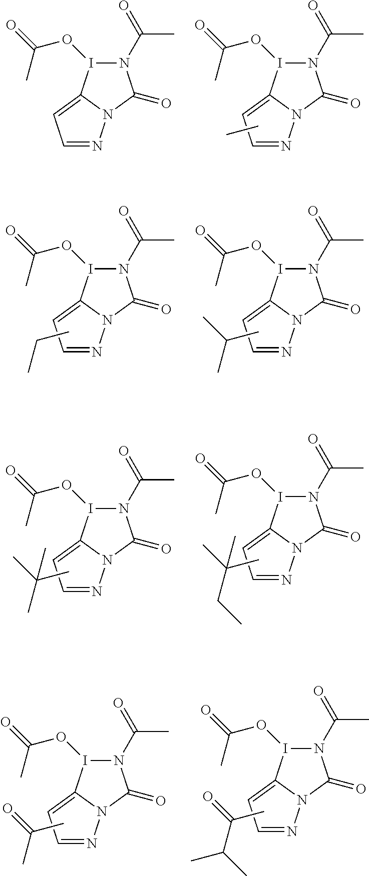

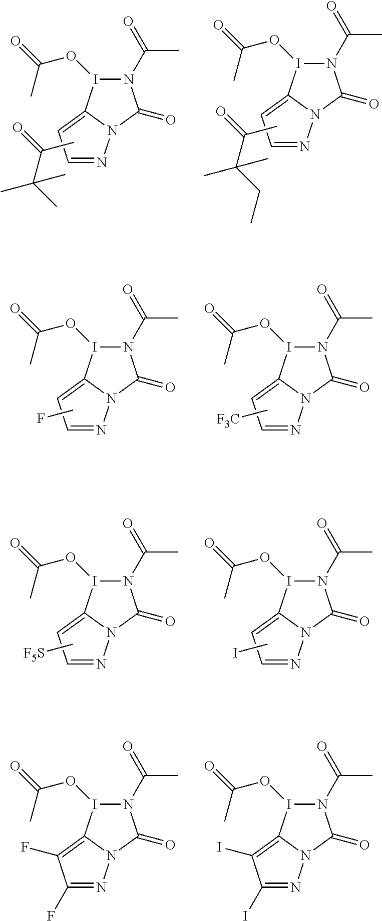

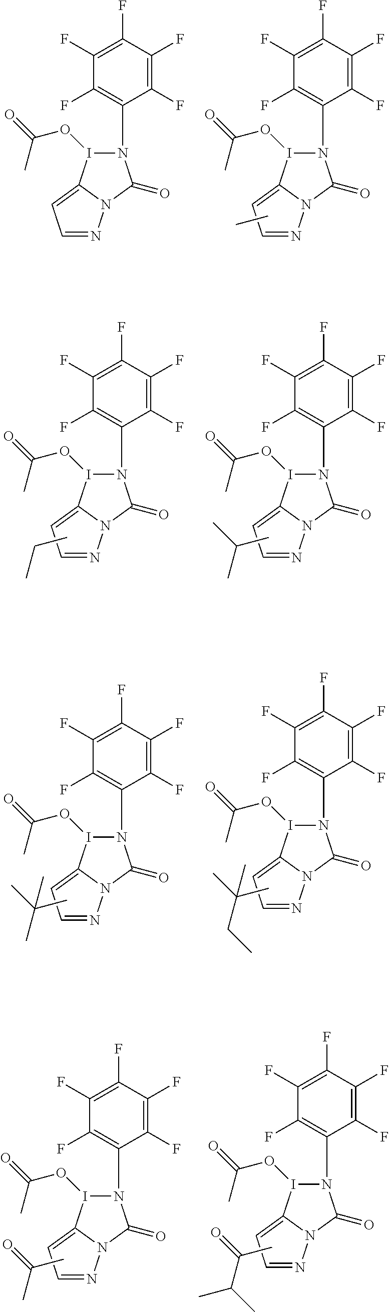

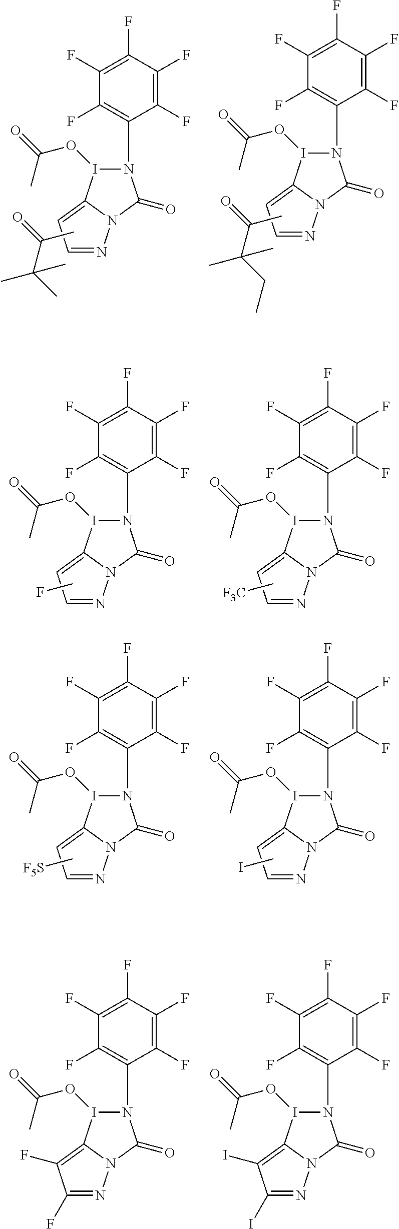

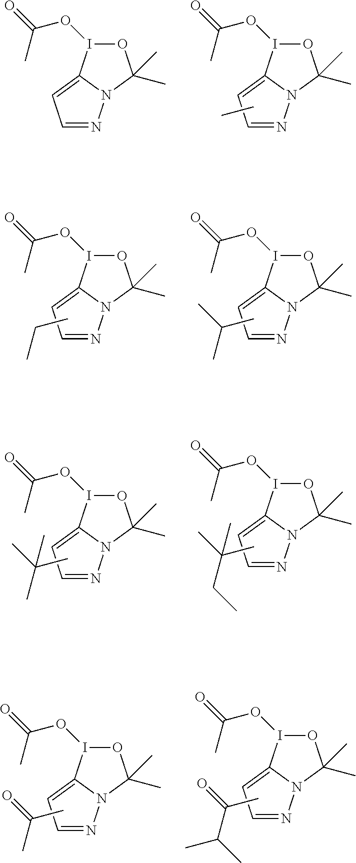

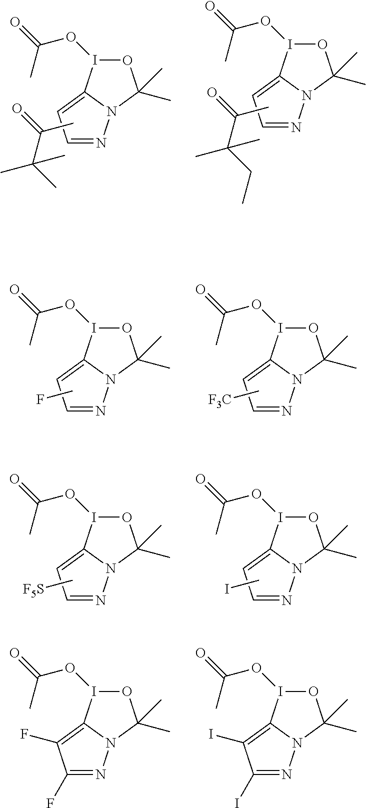

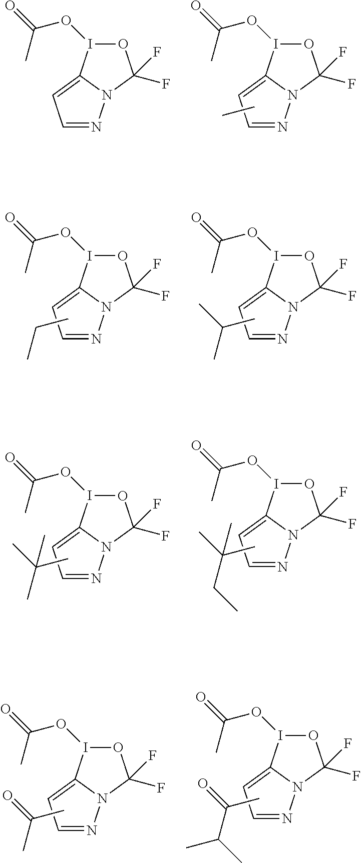

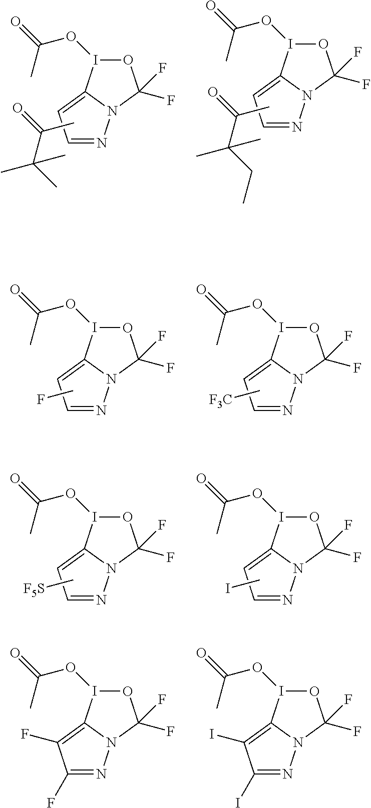

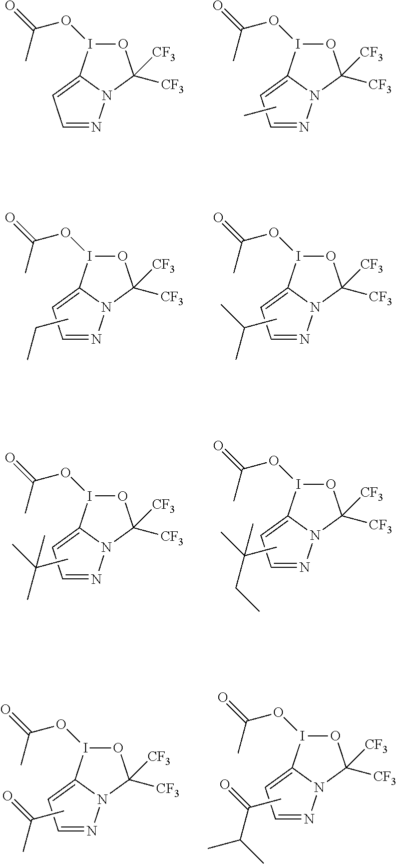

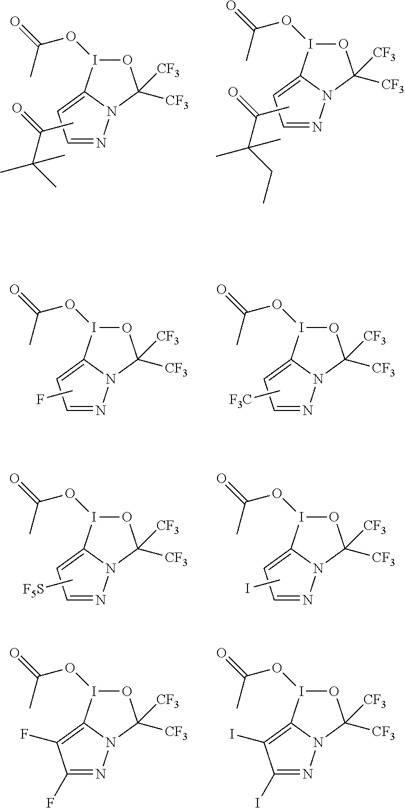

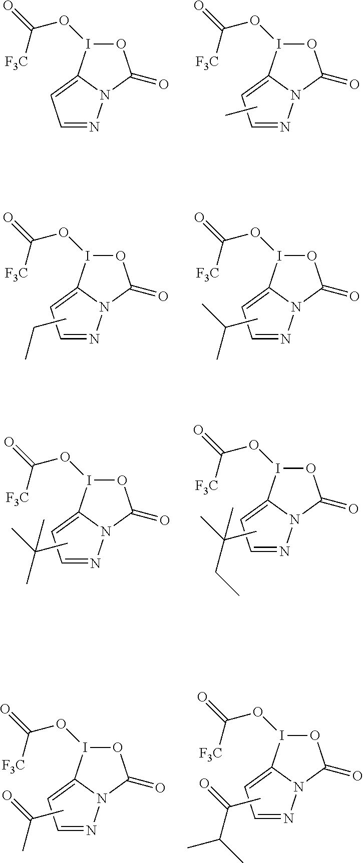

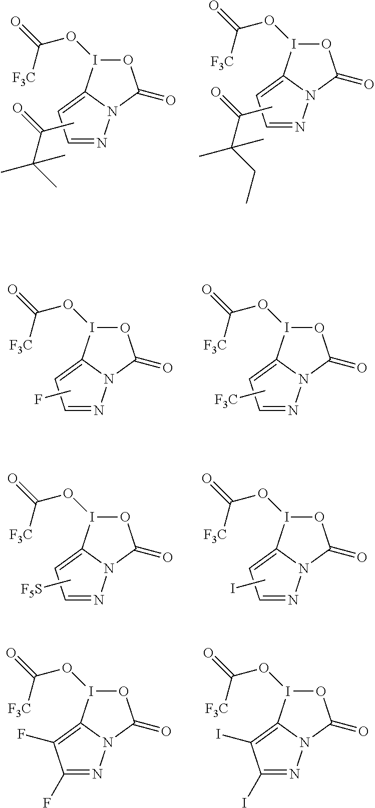

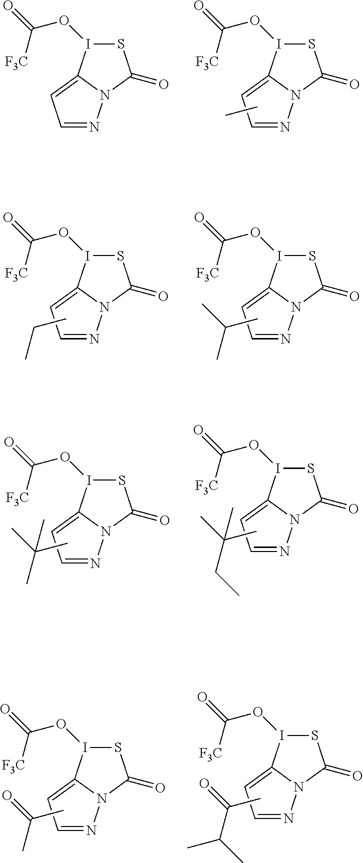

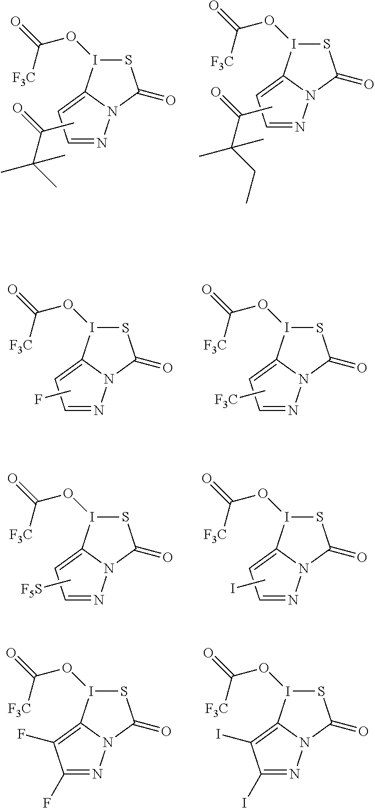

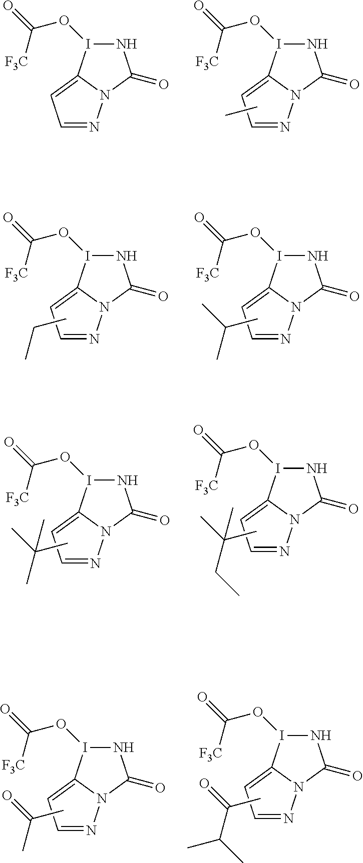

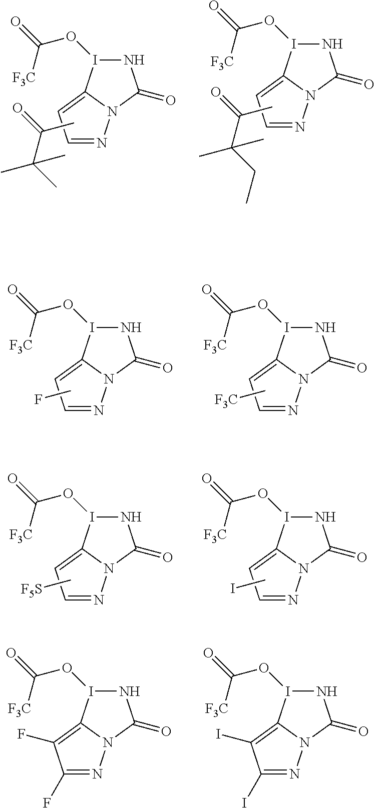

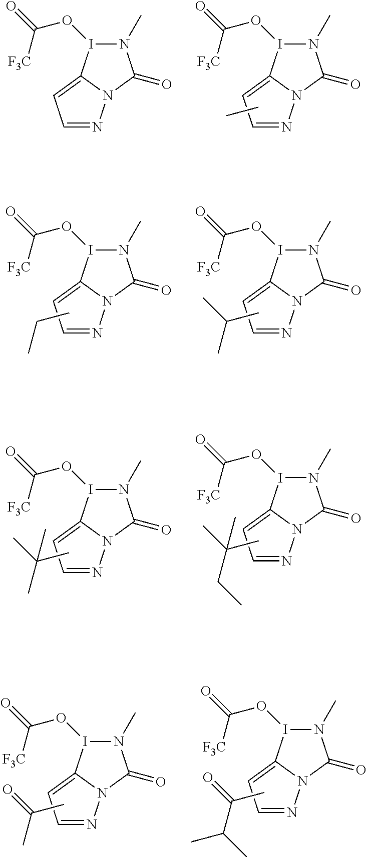

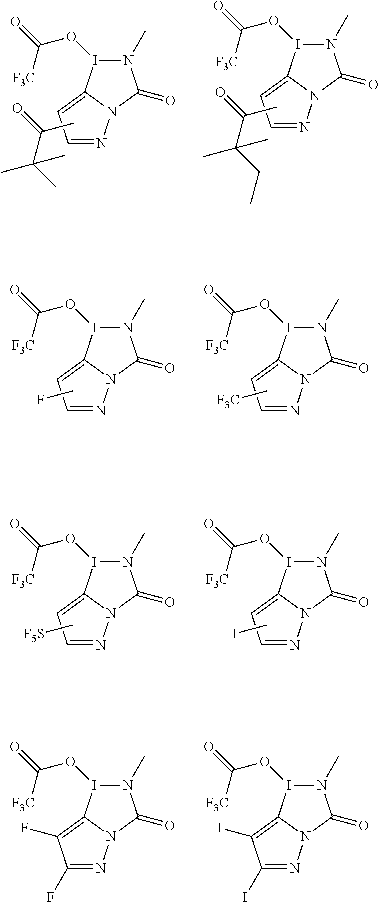

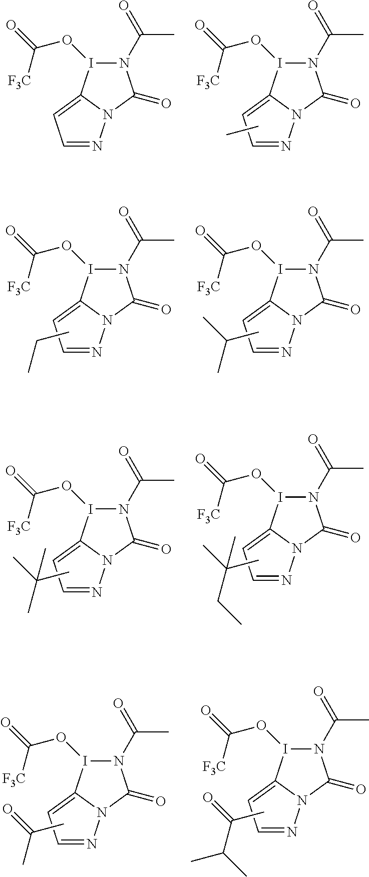

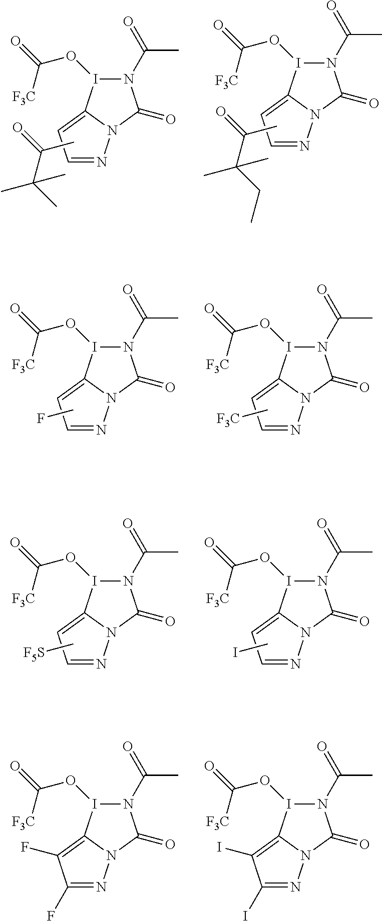

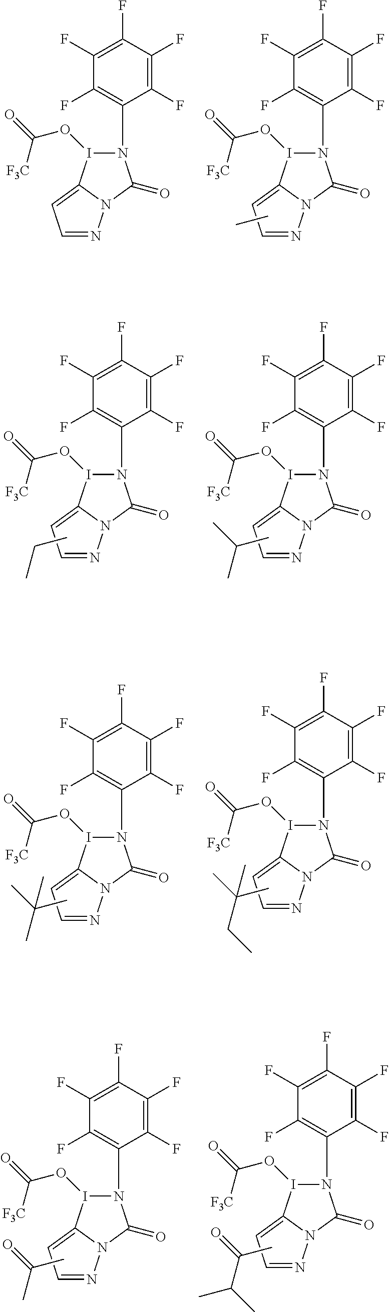

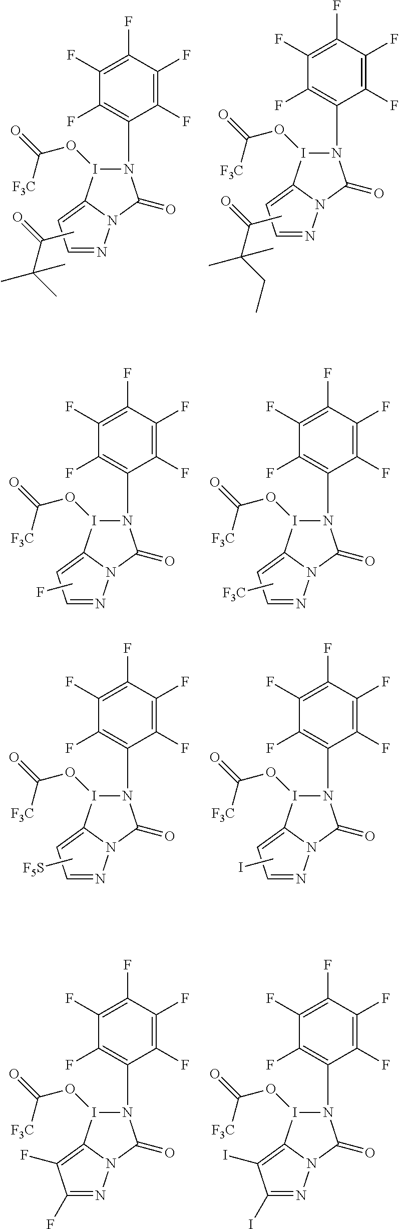

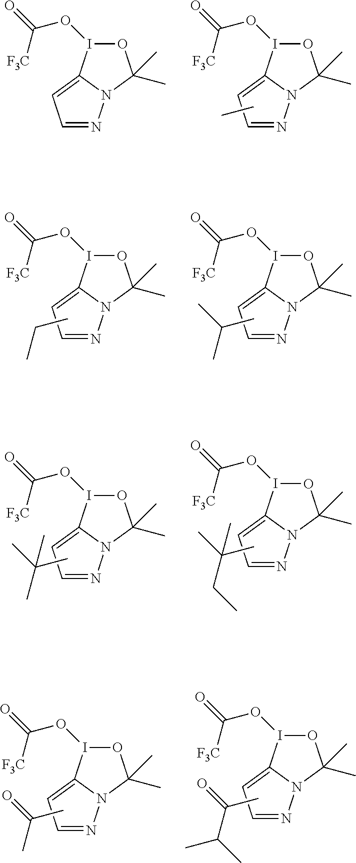

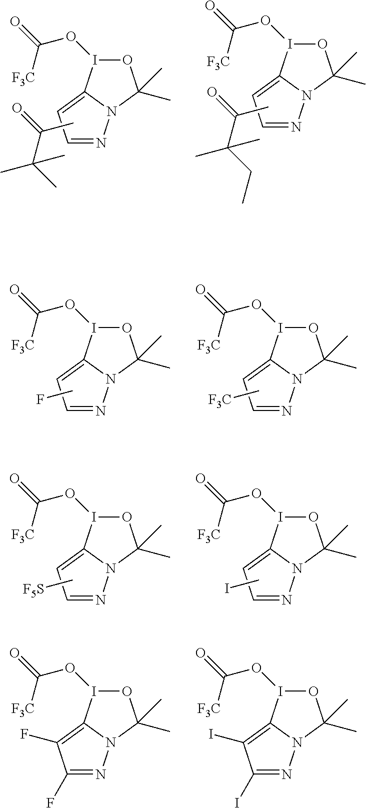

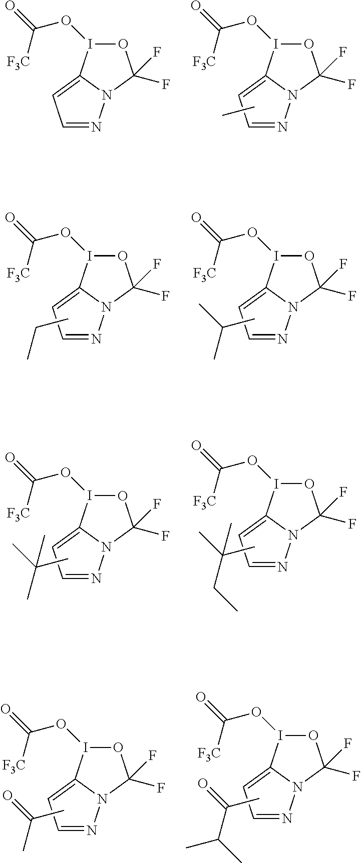

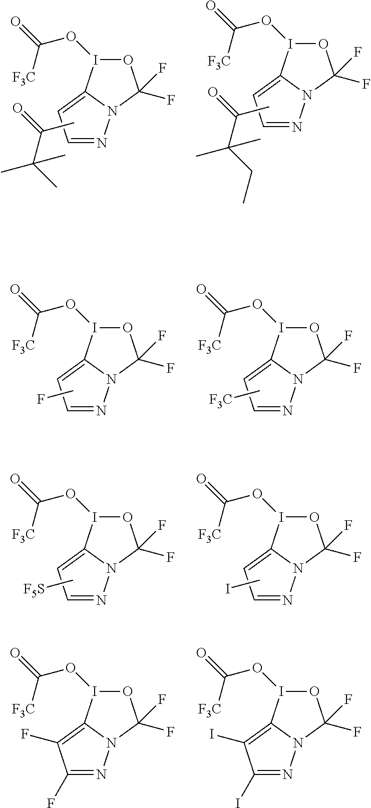

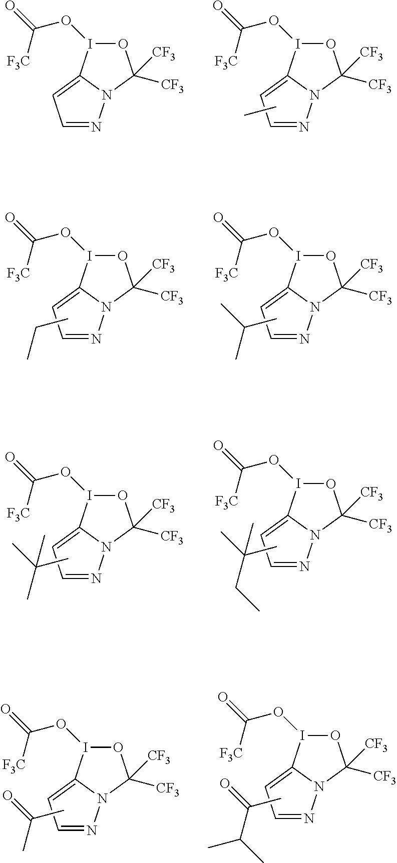

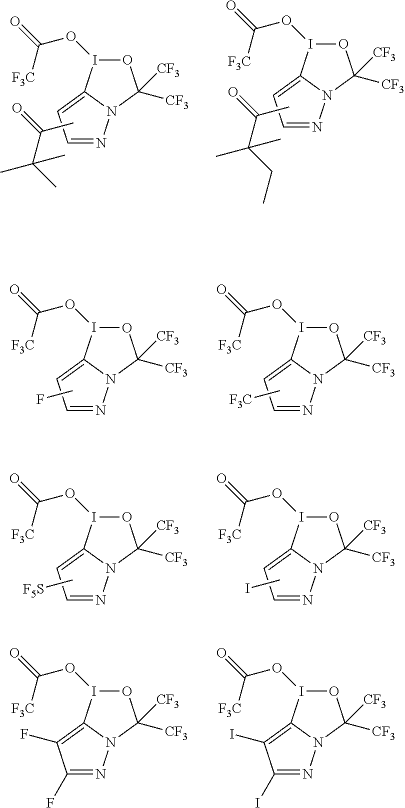

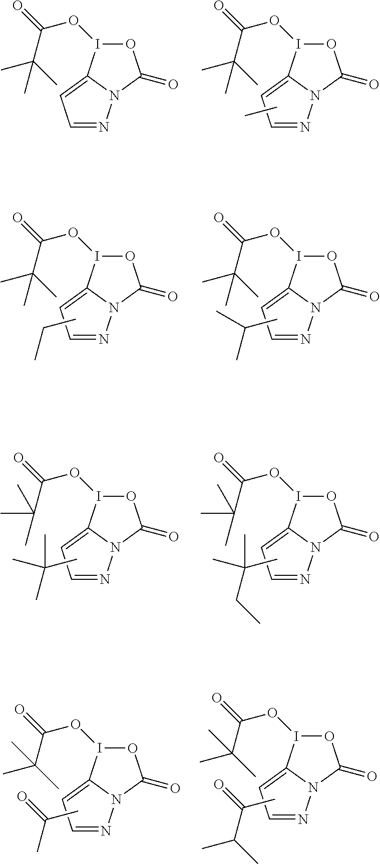

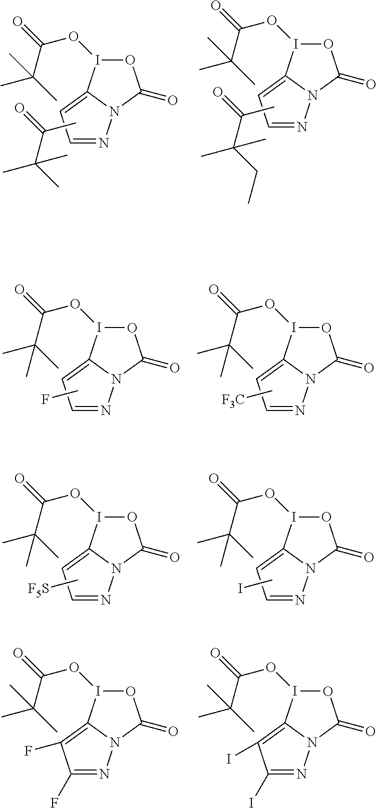

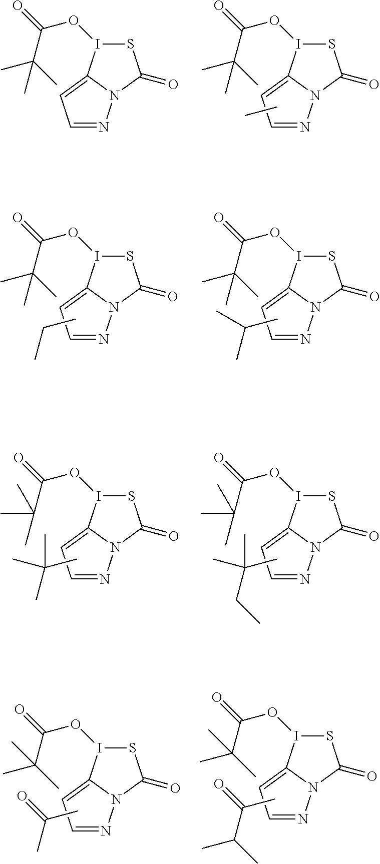

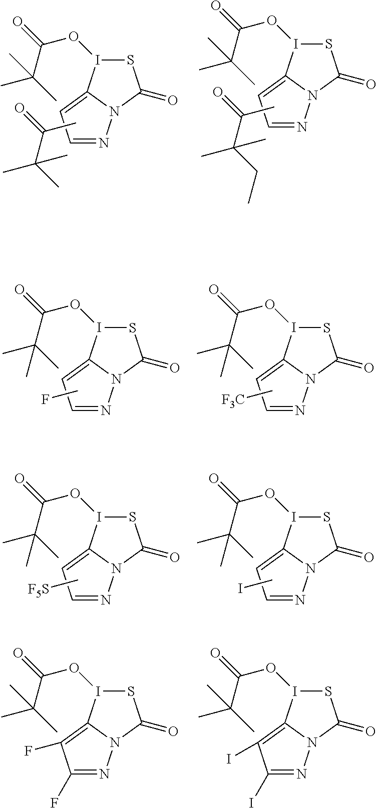

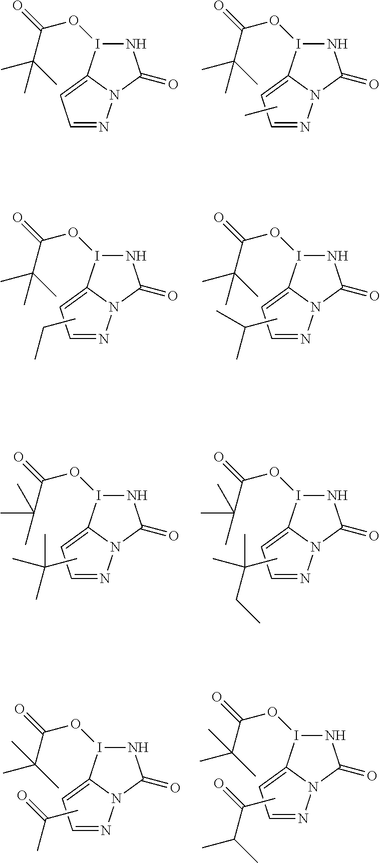

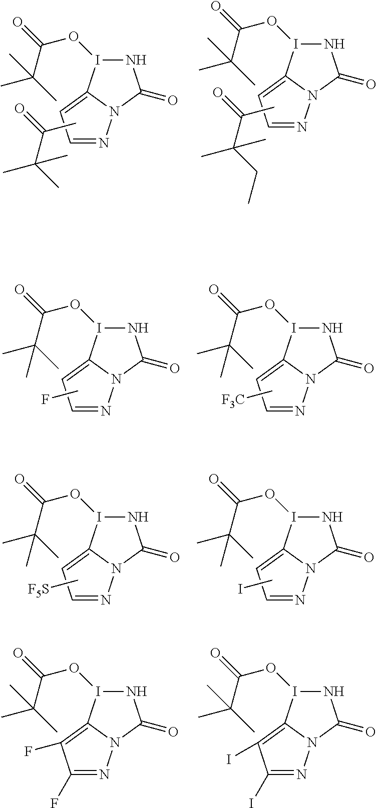

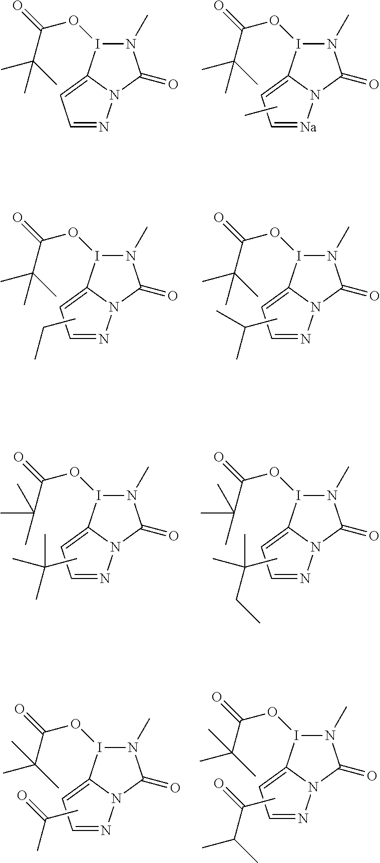

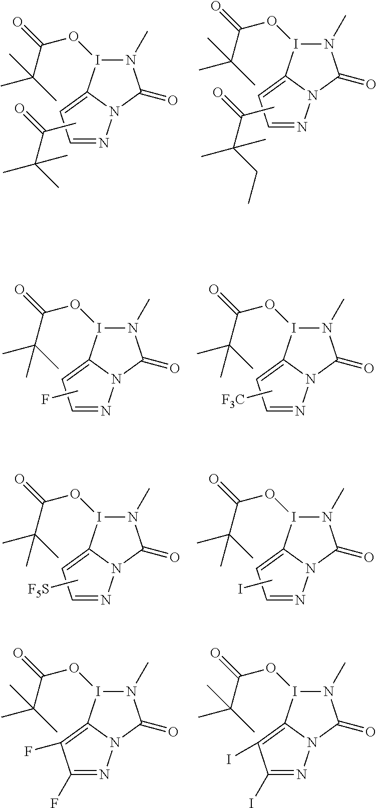

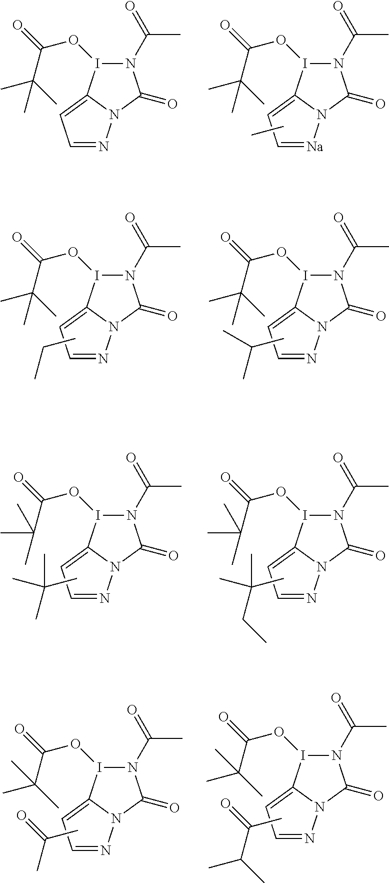

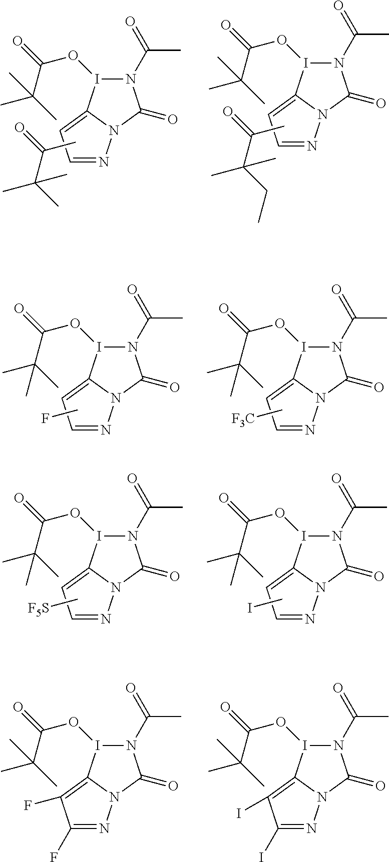

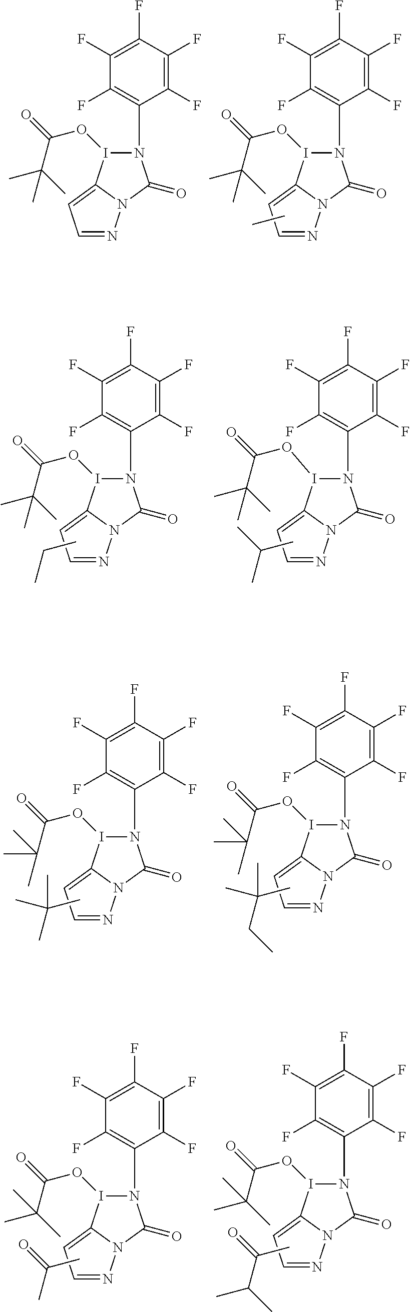

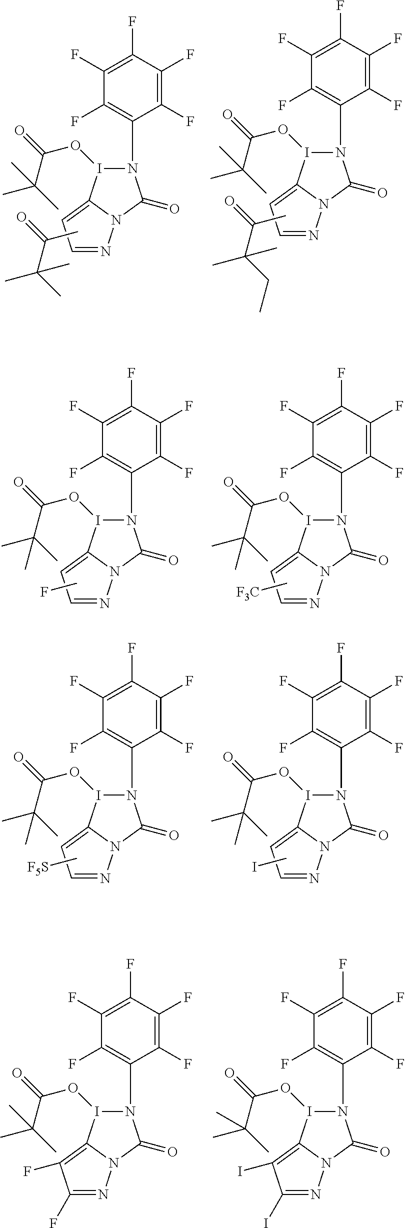

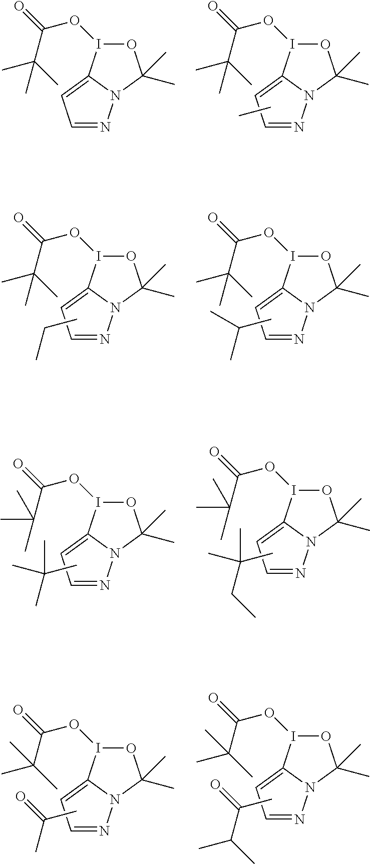

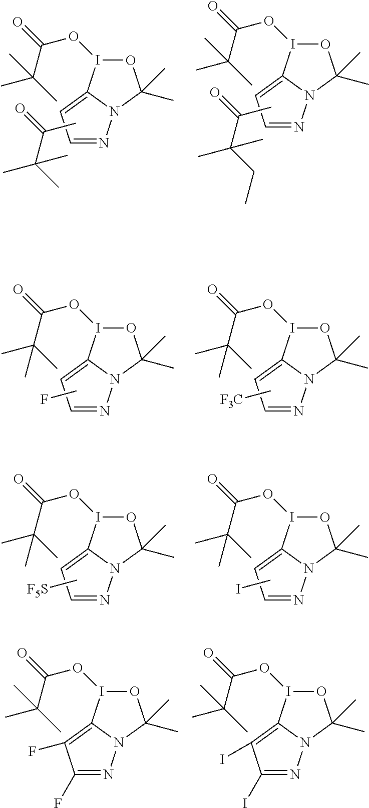

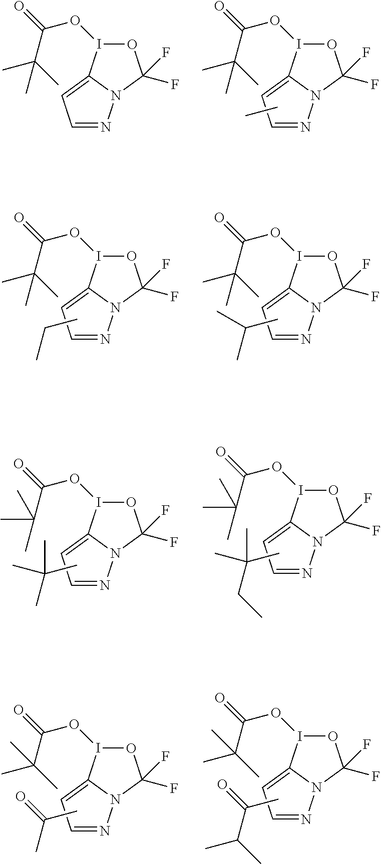

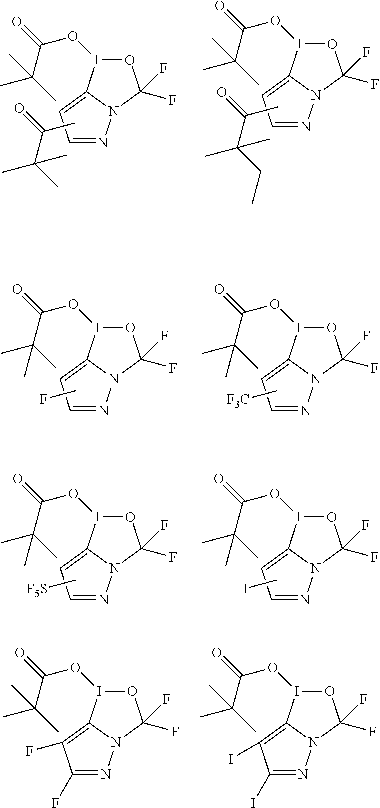

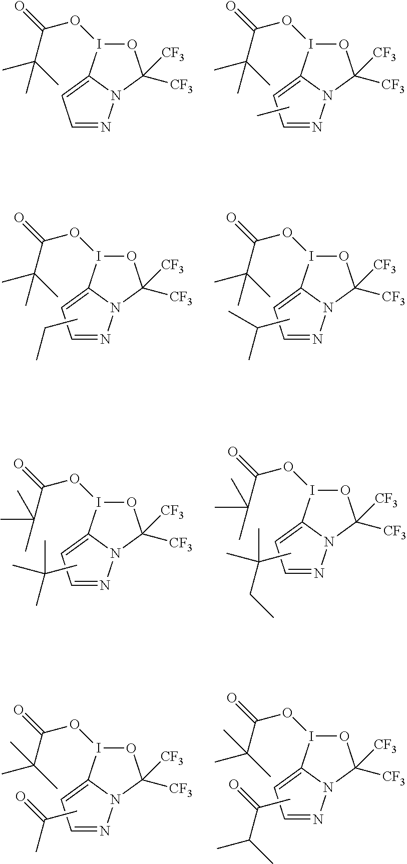

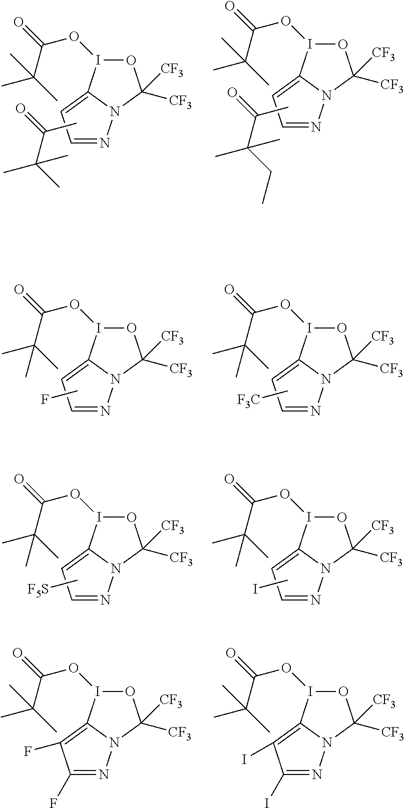

Examples of the hypervalent iodine compound having the formula (16) are shown below, but are not limited thereto. In the formulae, *7 and *8 are the same as described

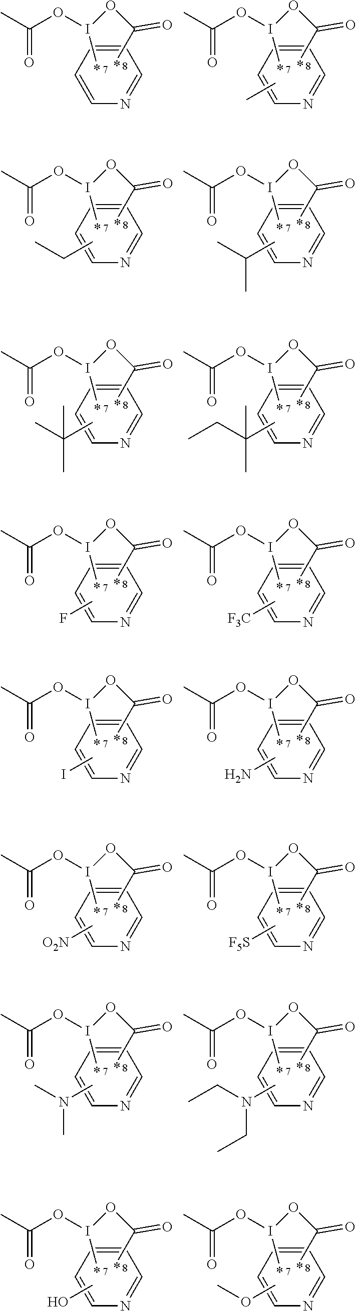

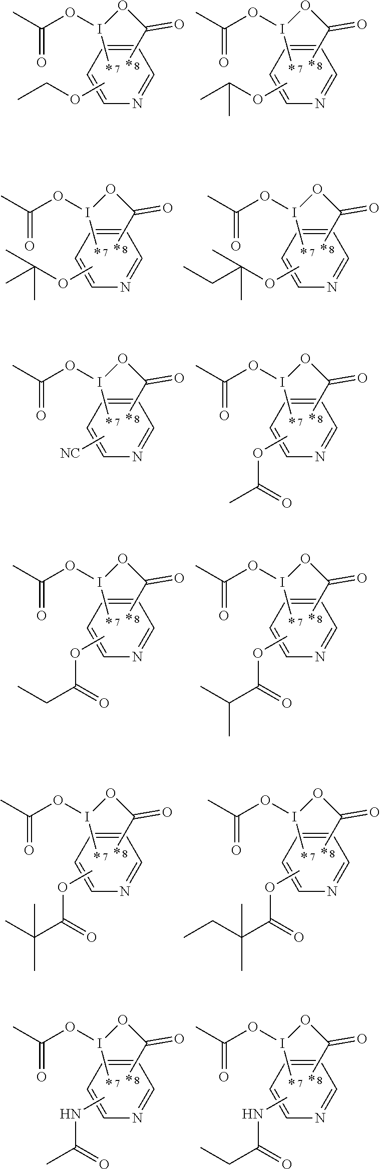

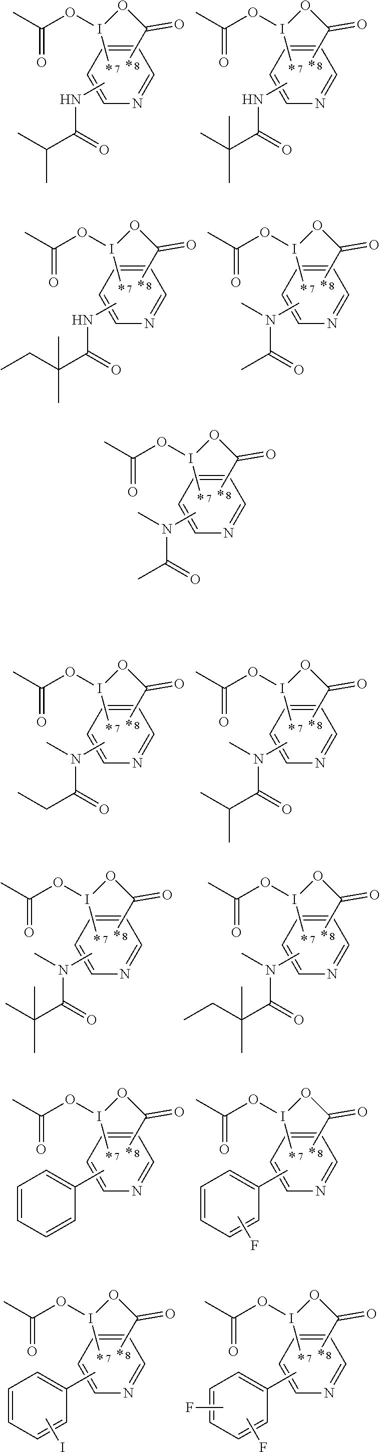

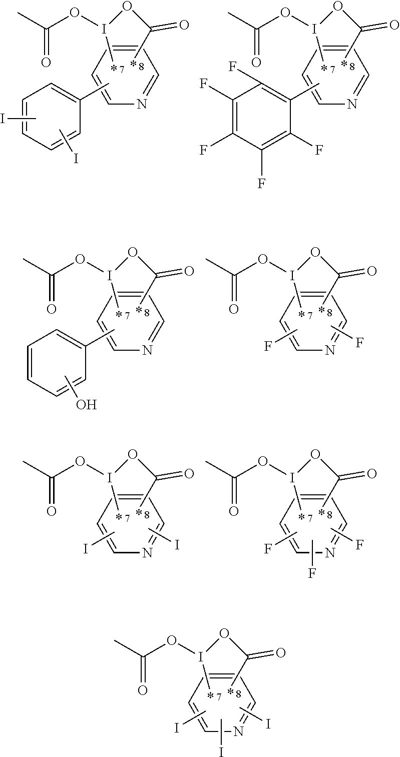

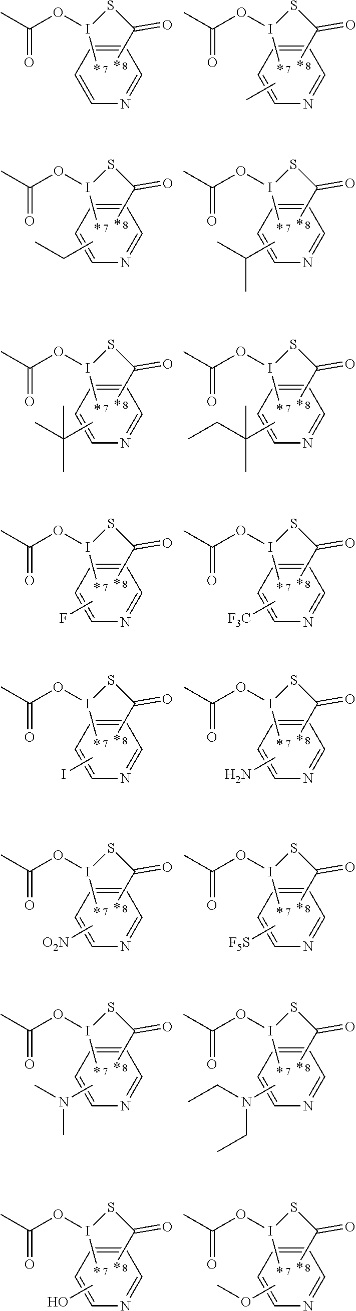

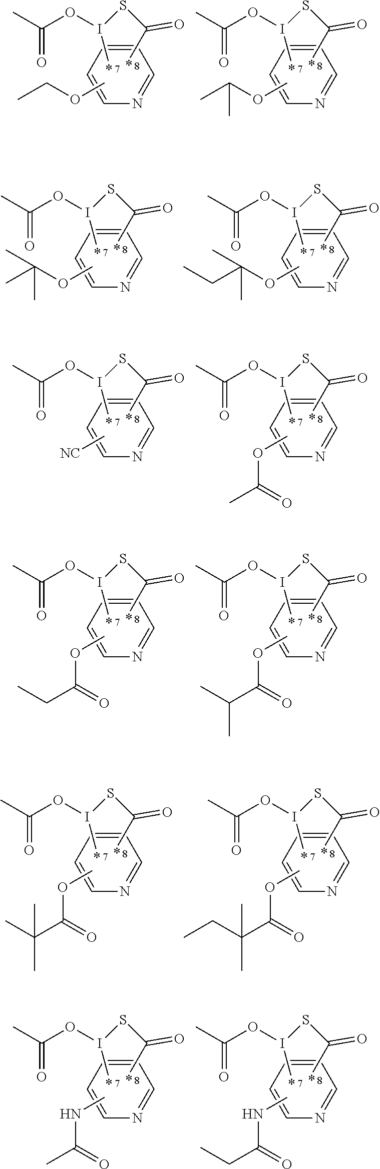

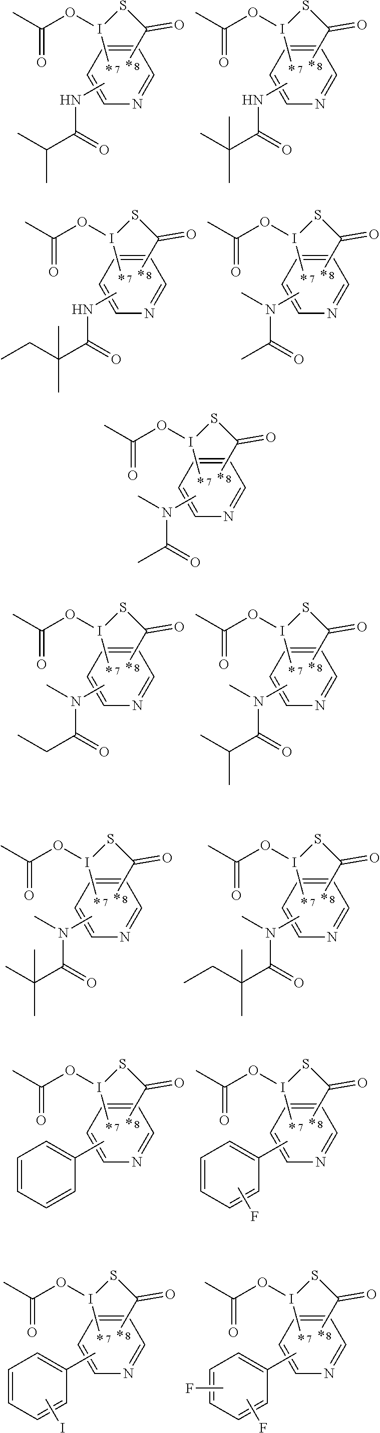

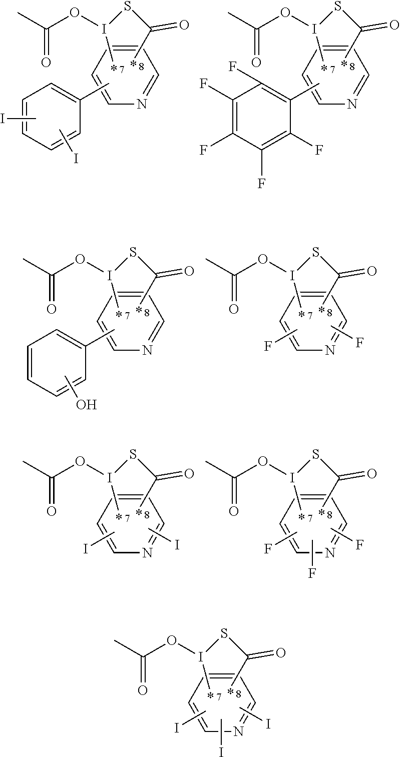

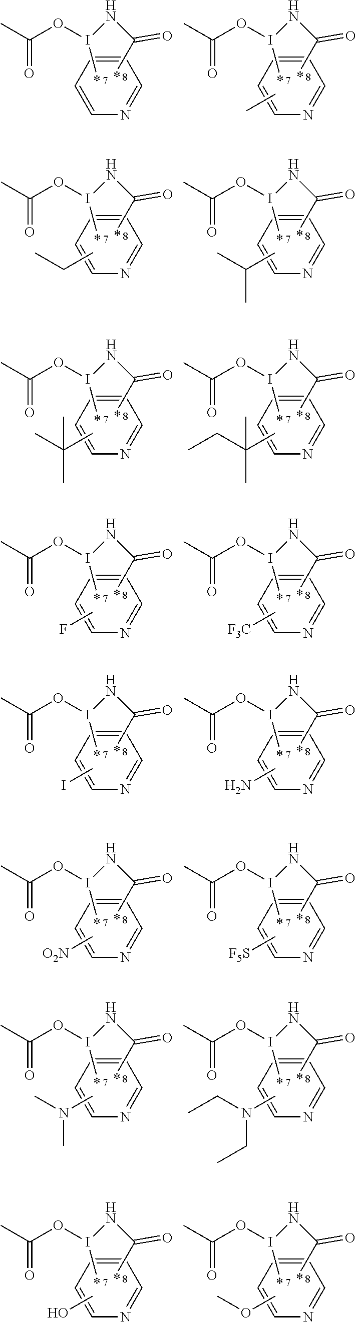

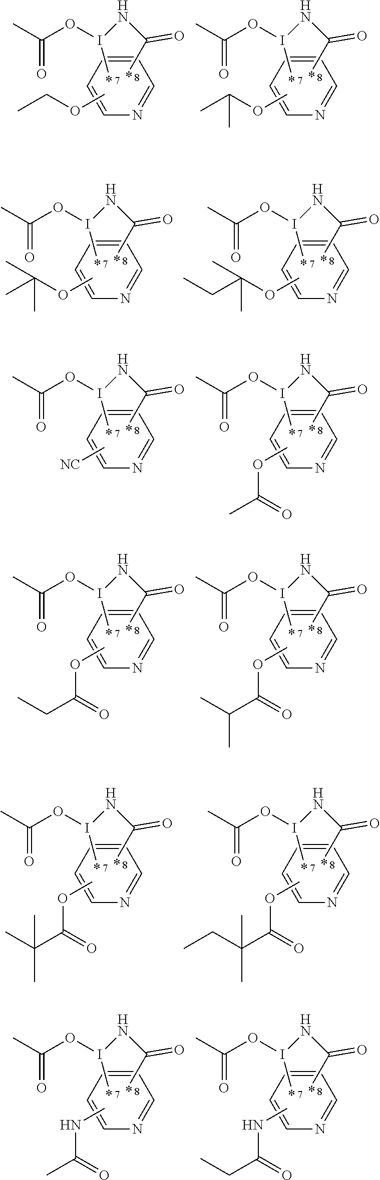

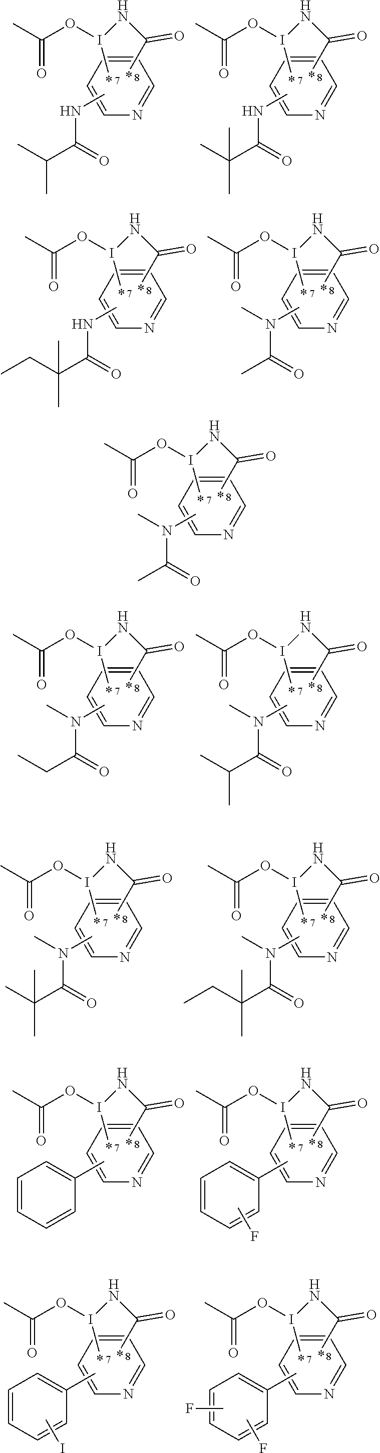

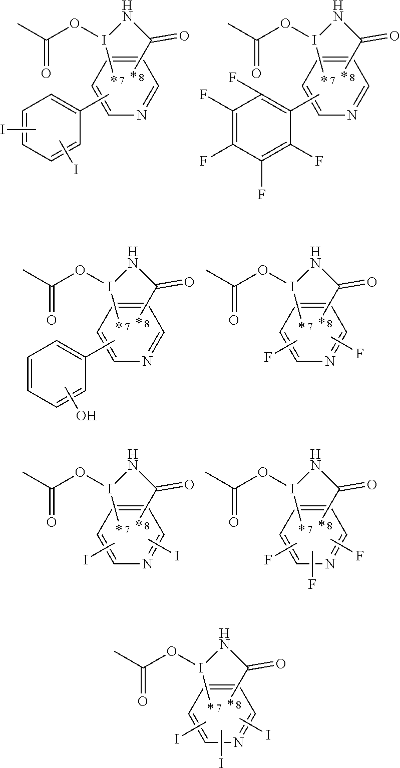

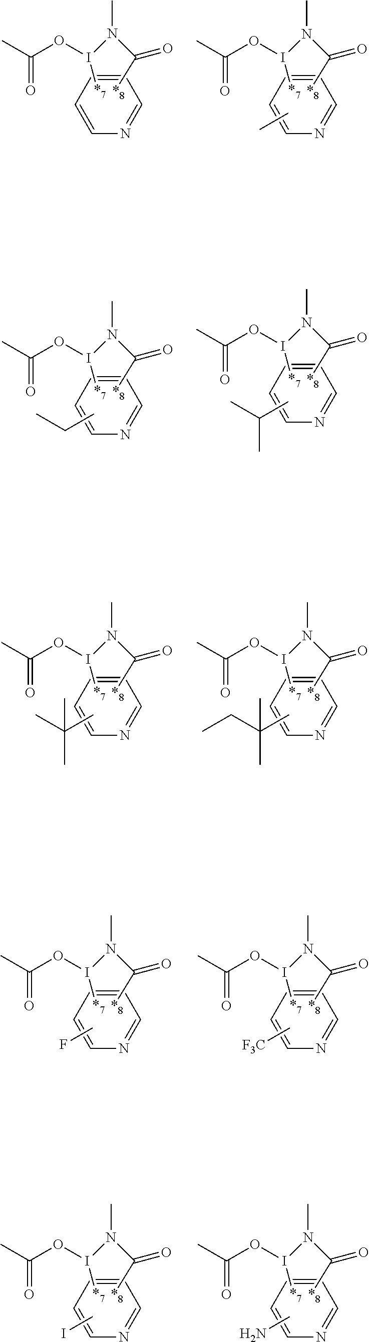

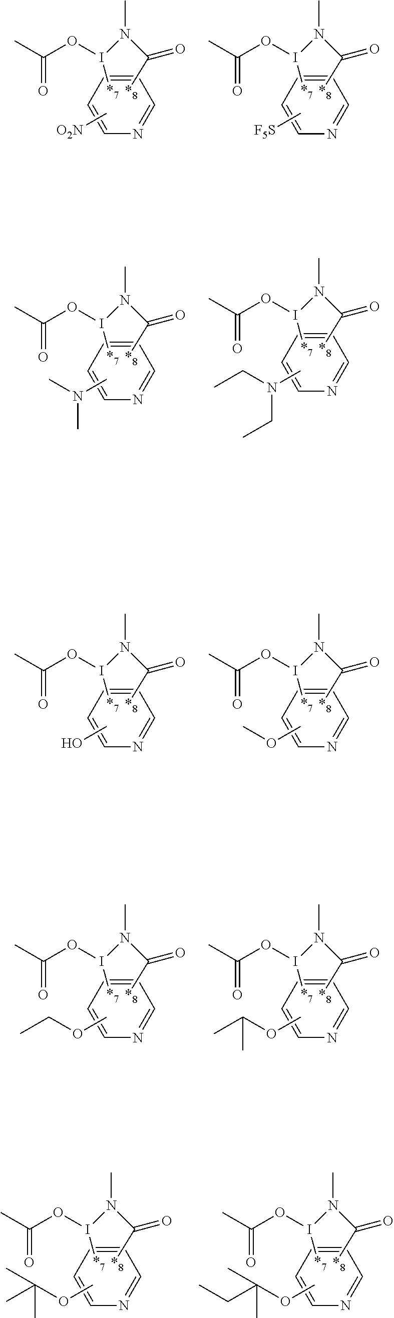

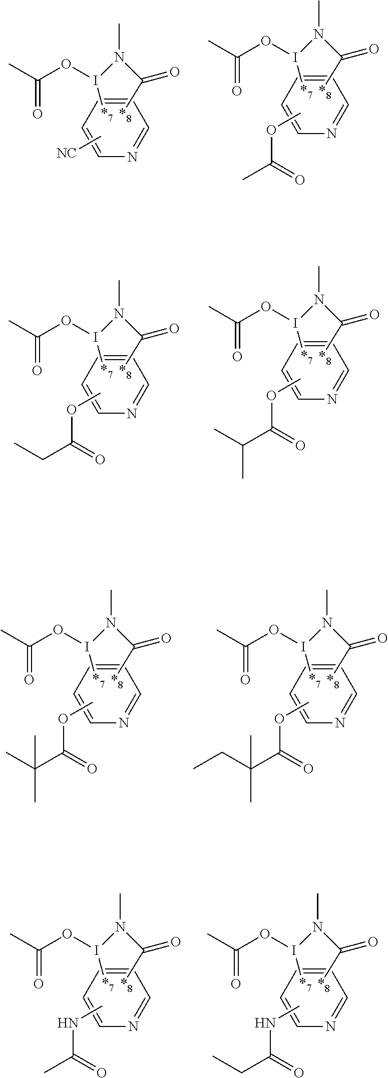

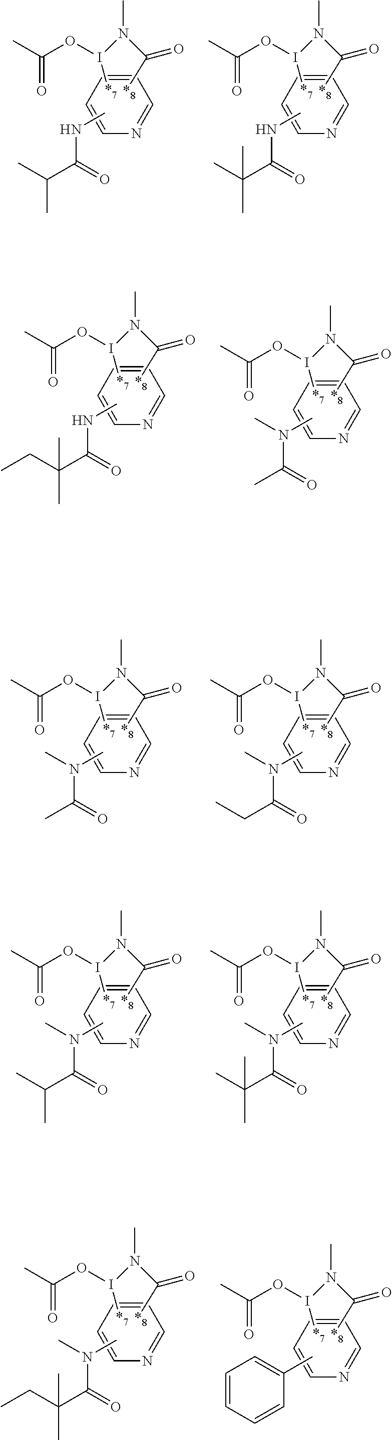

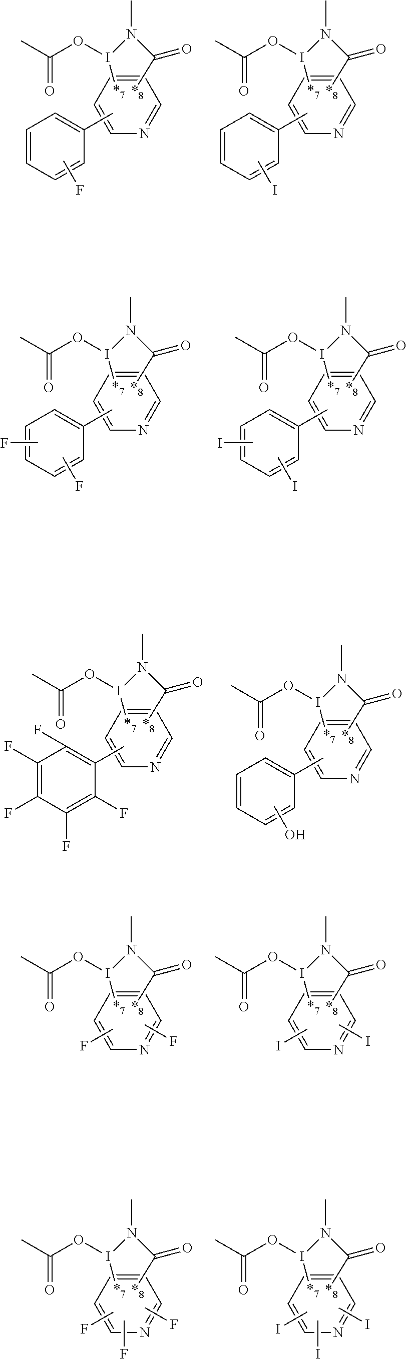

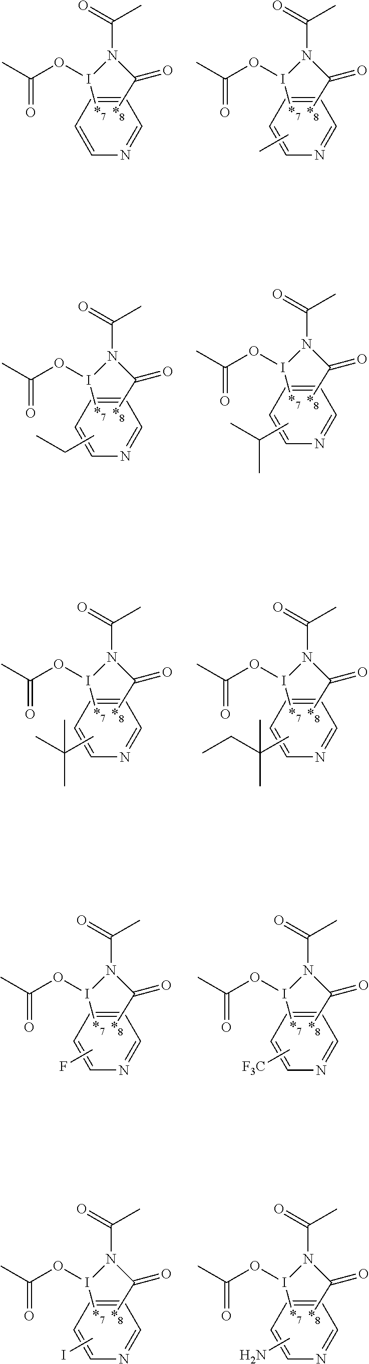

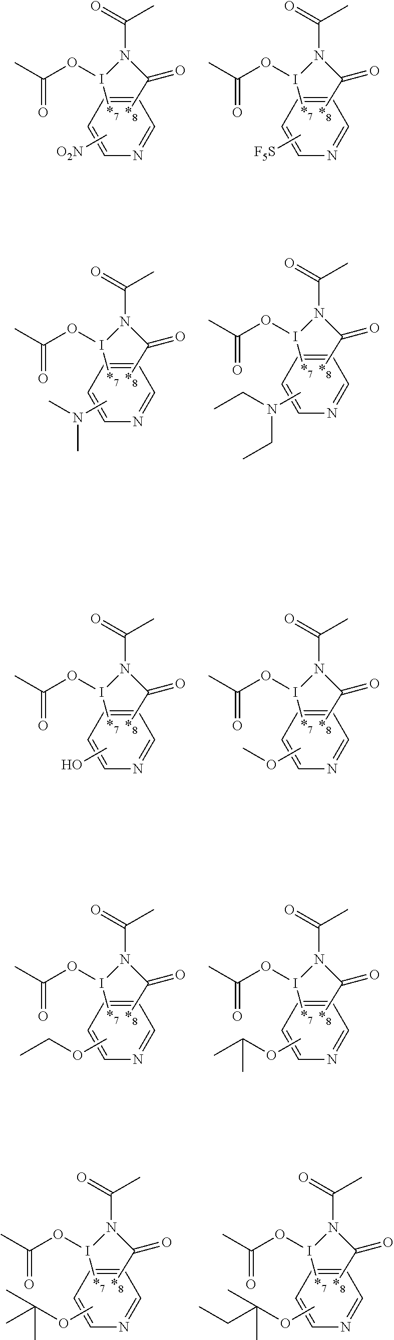

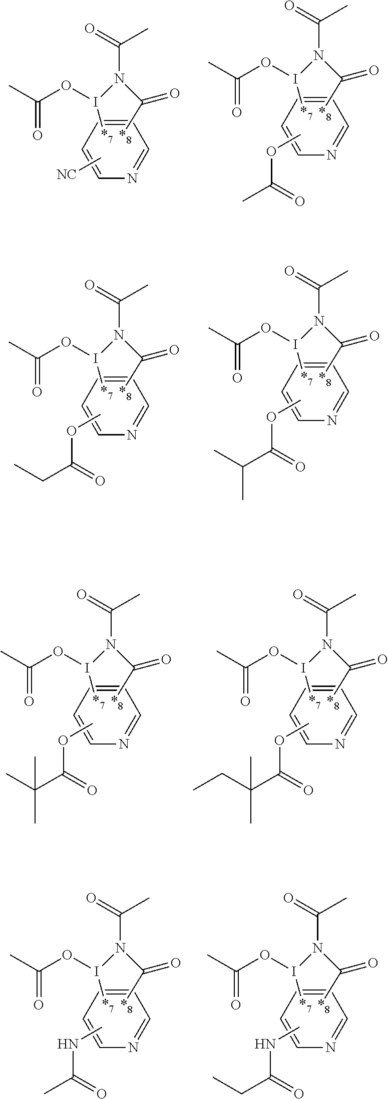

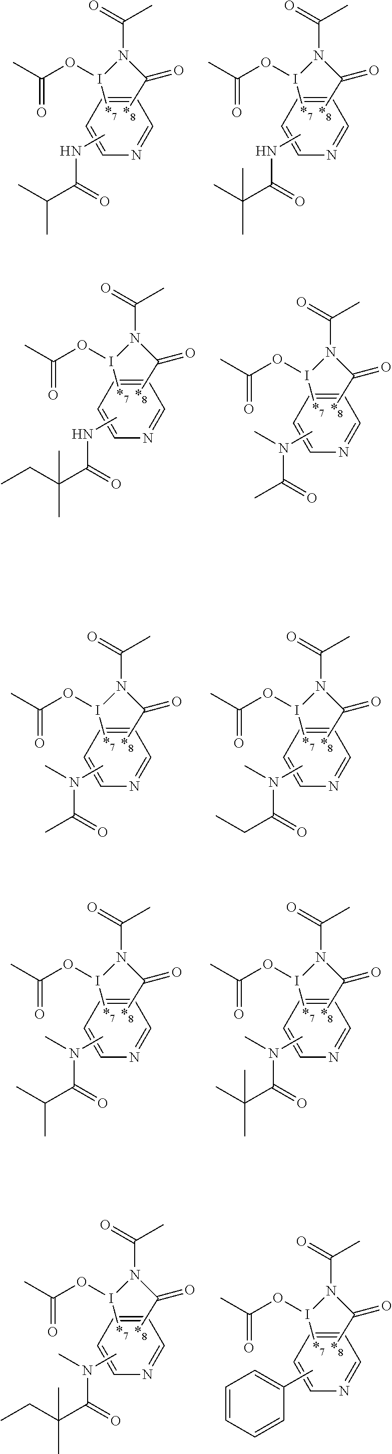

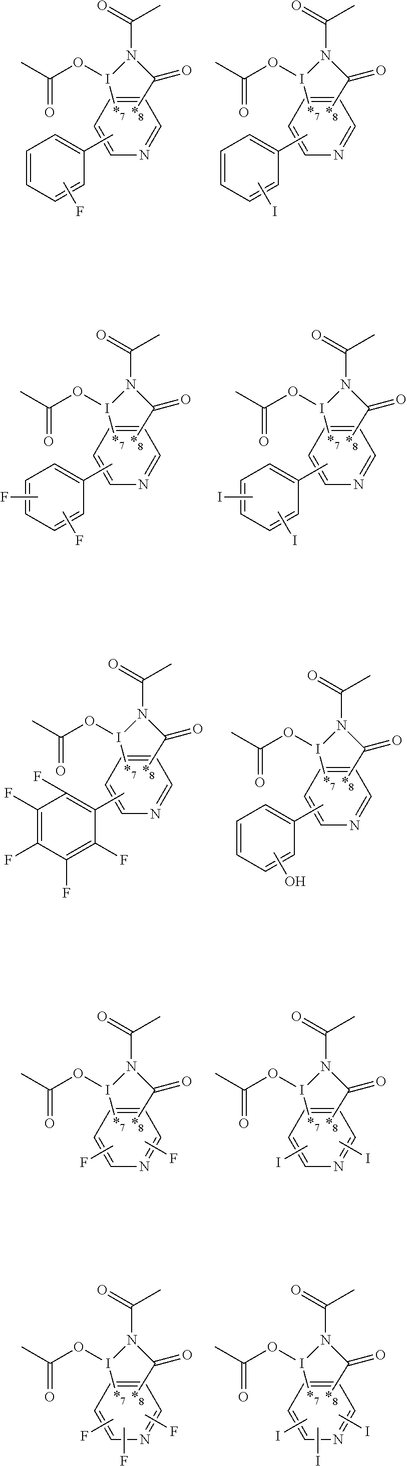

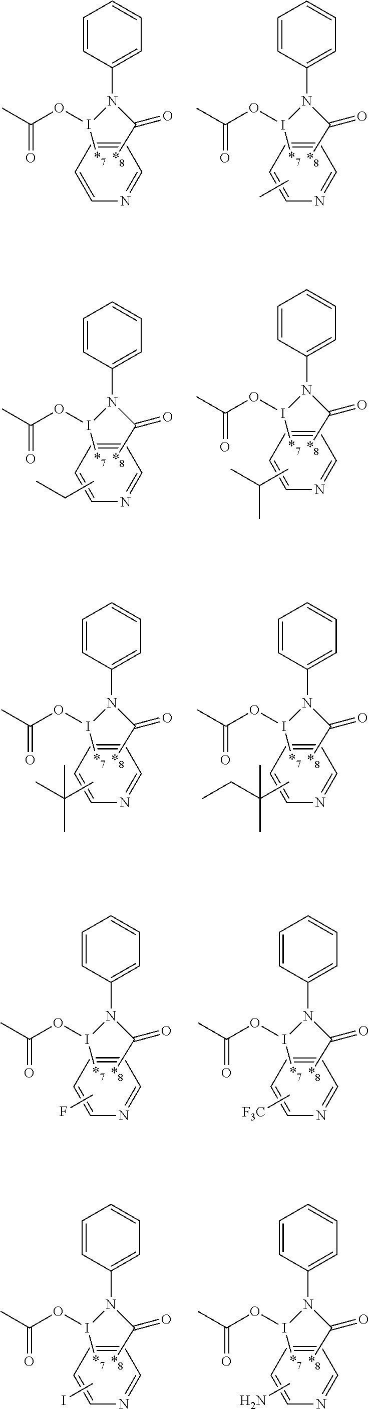

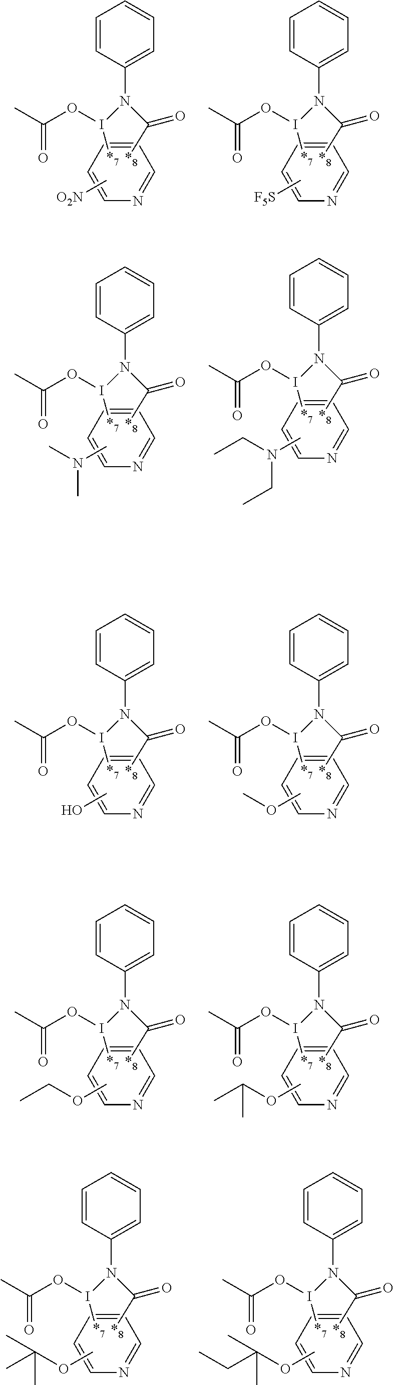

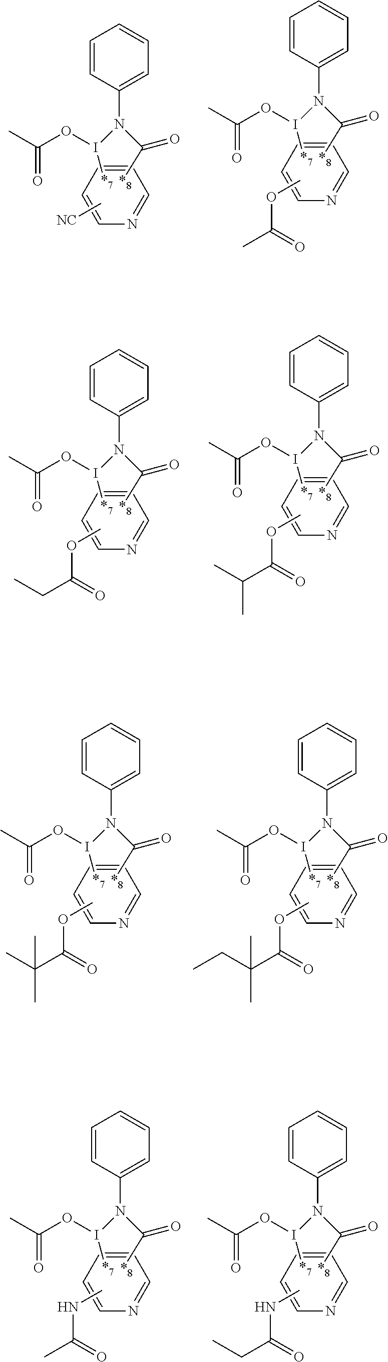

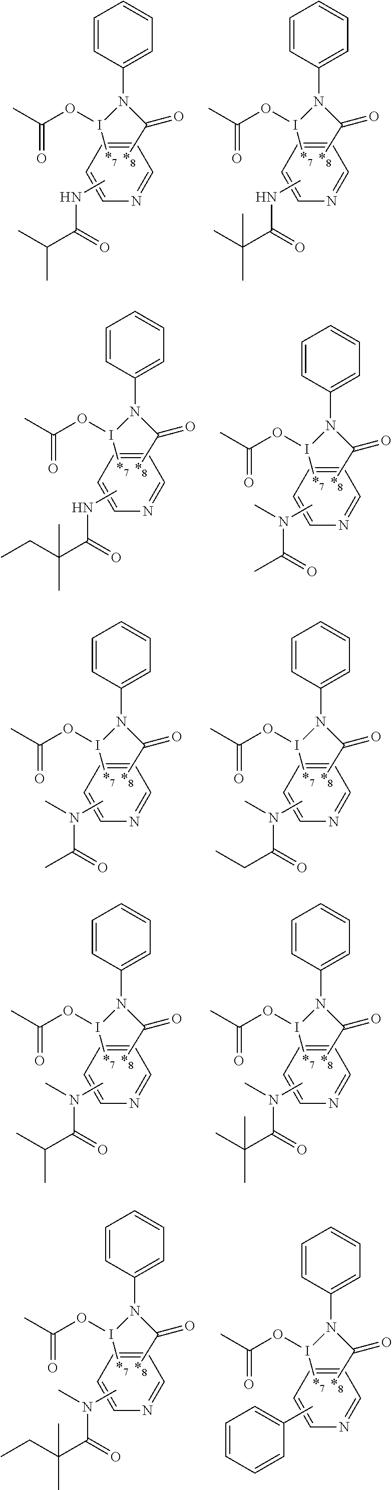

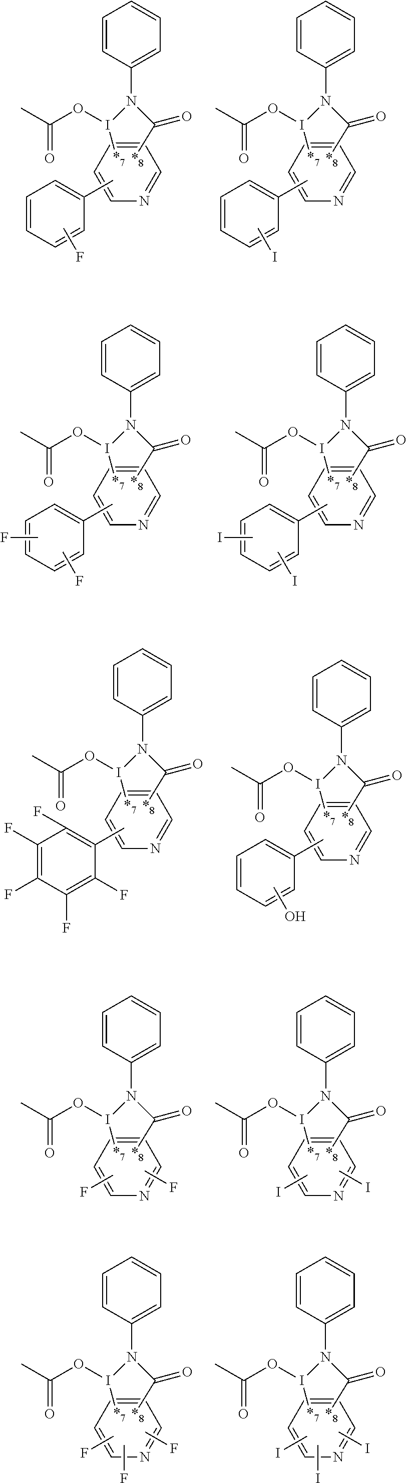

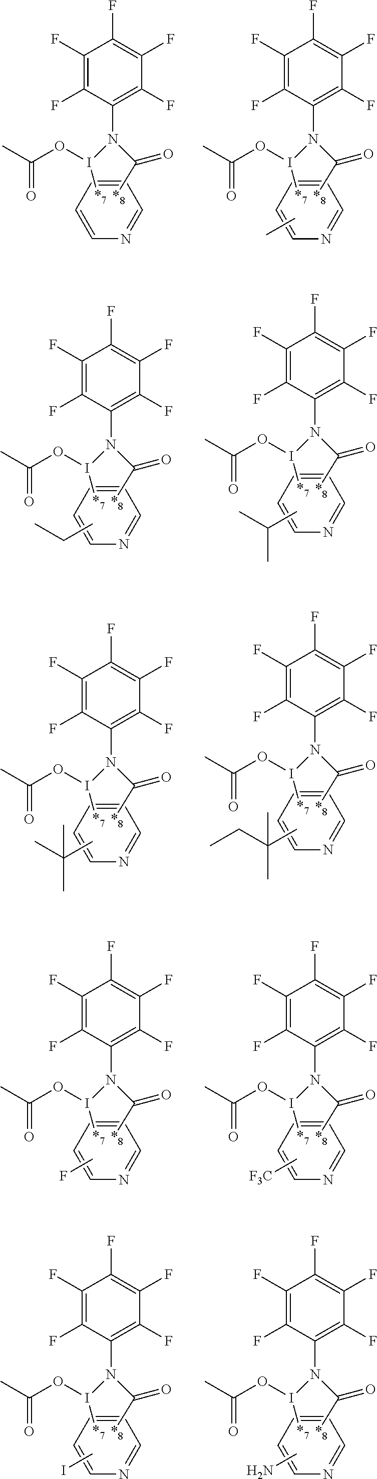

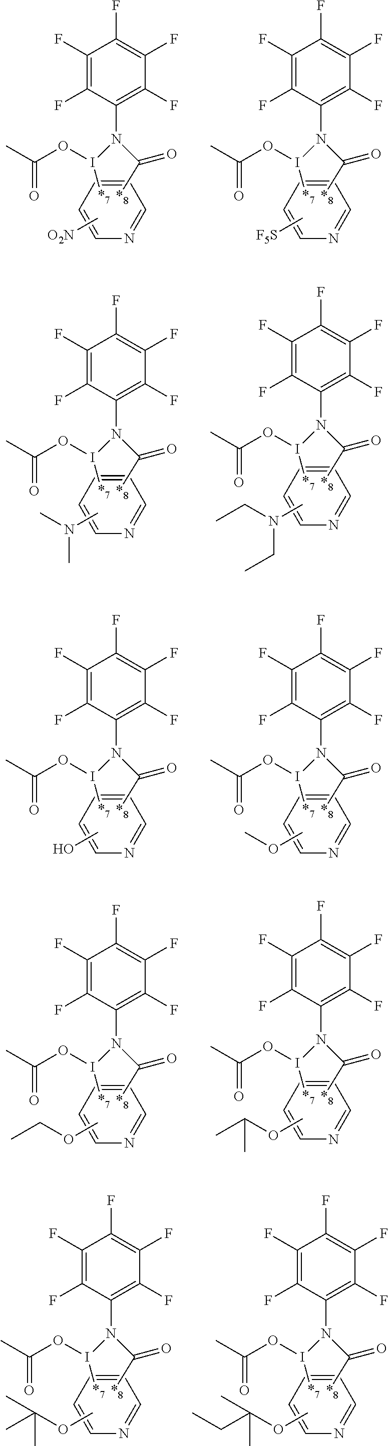

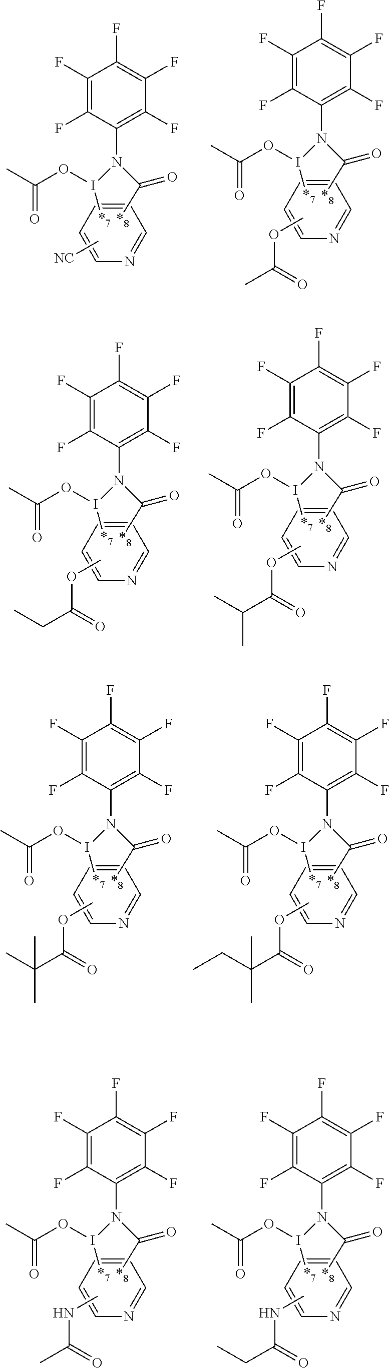

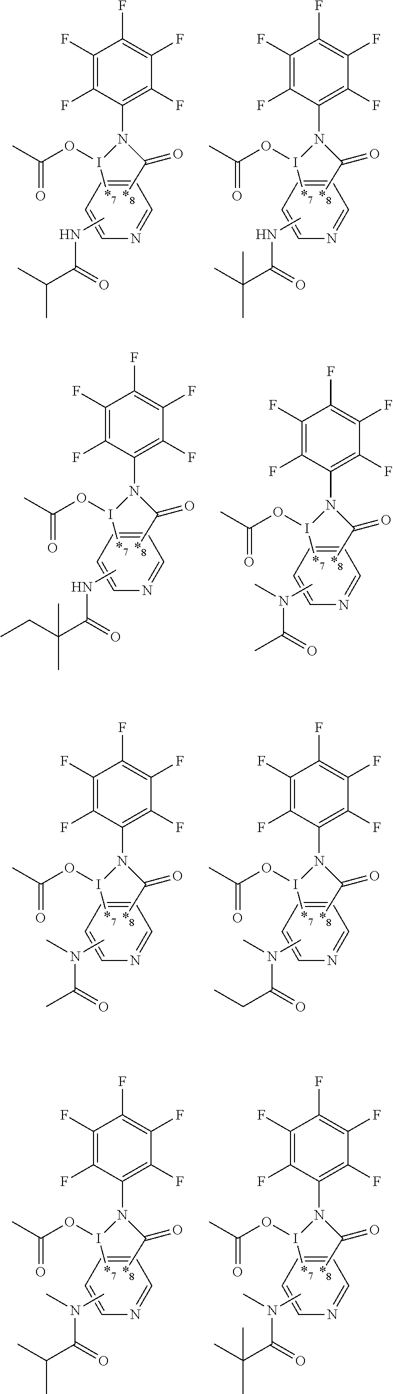

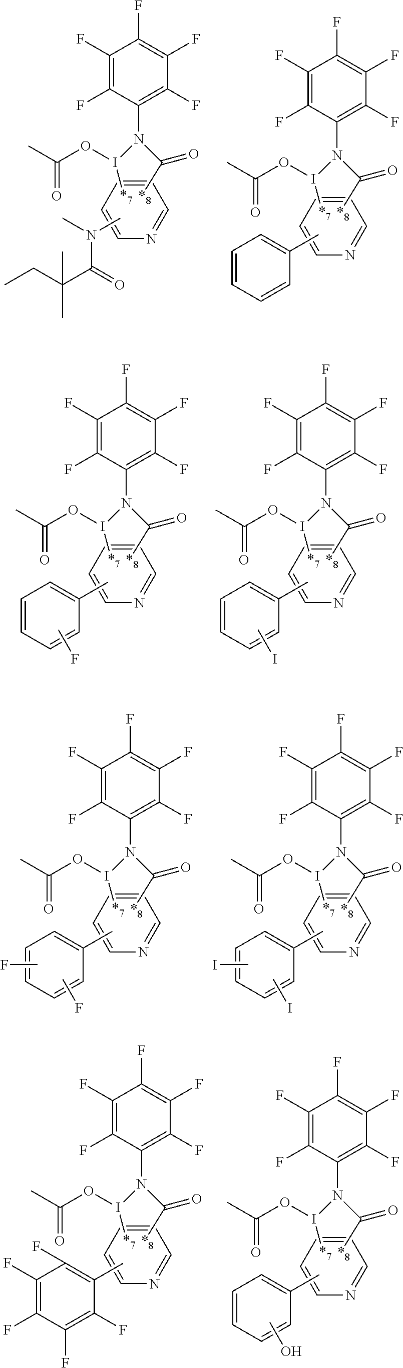

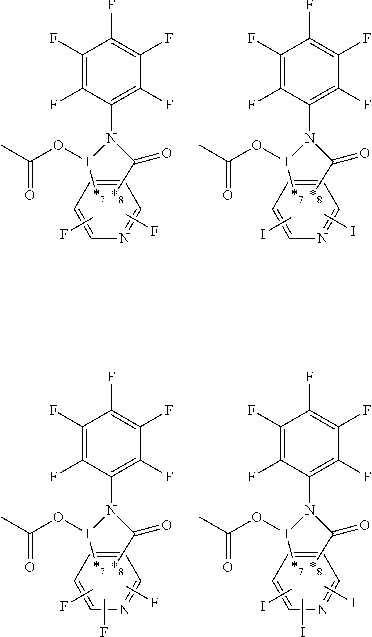

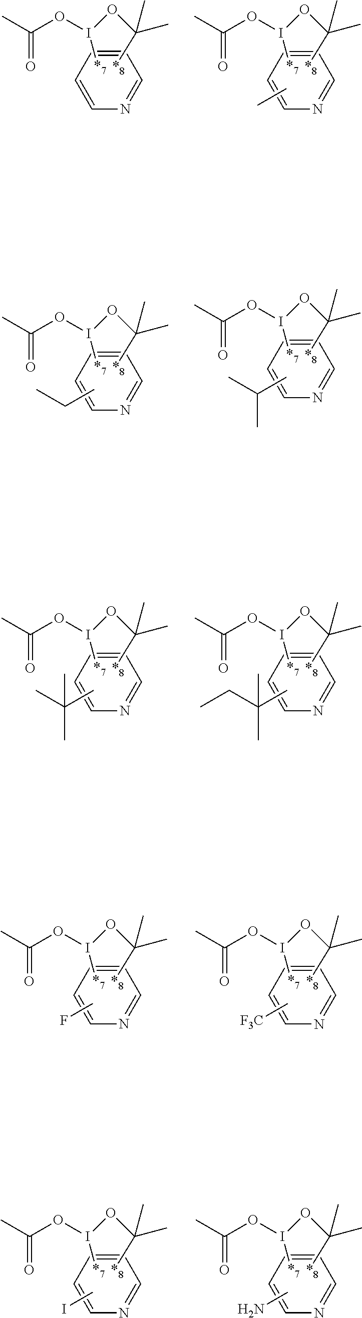

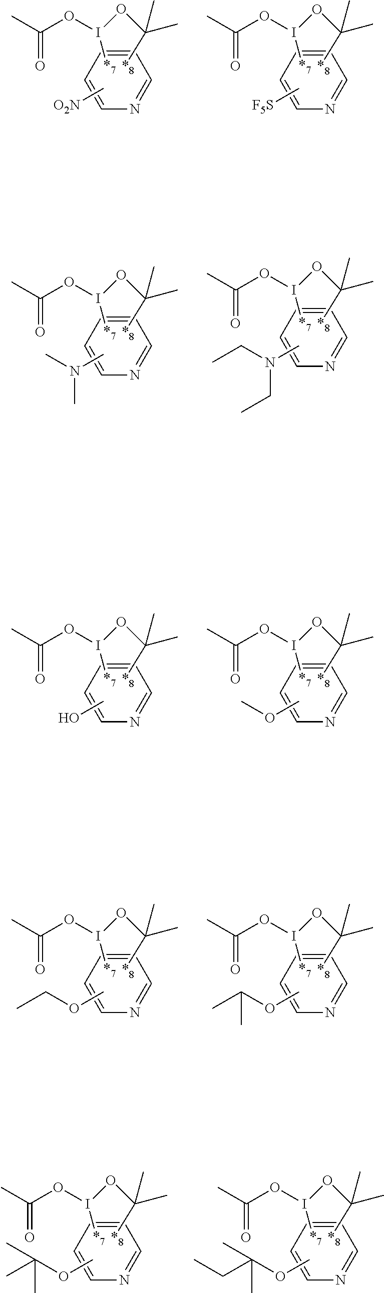

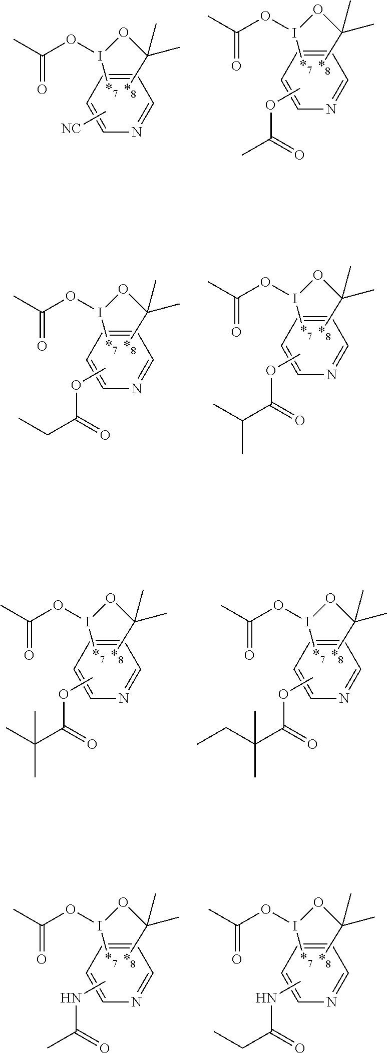

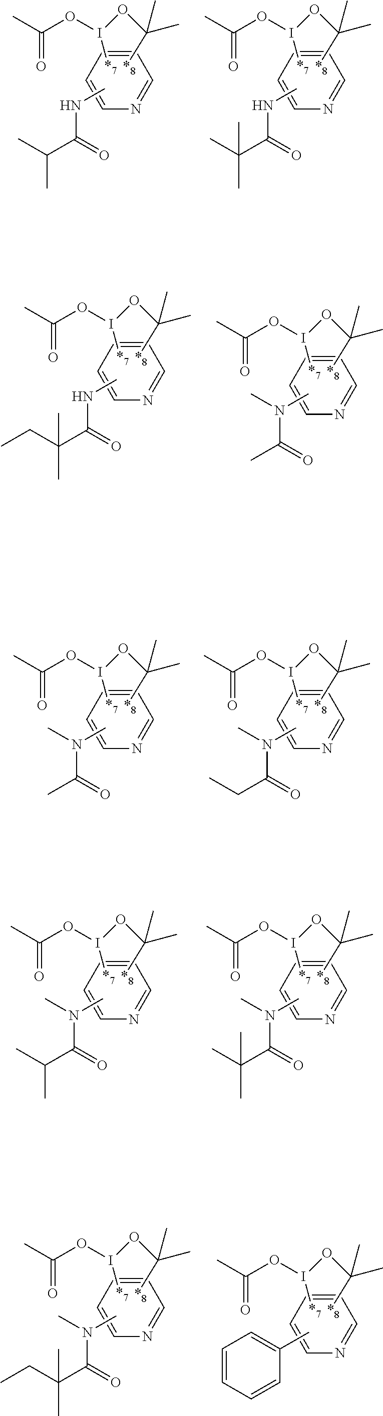

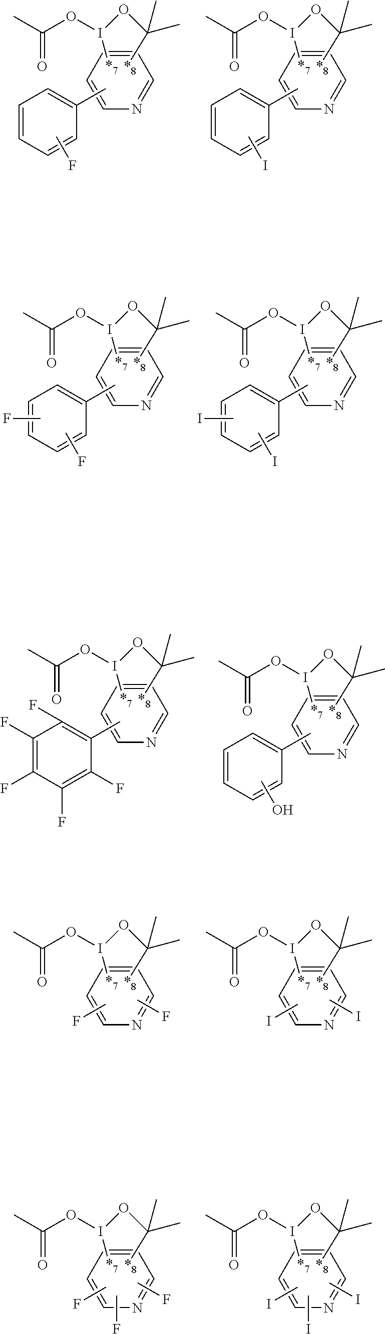

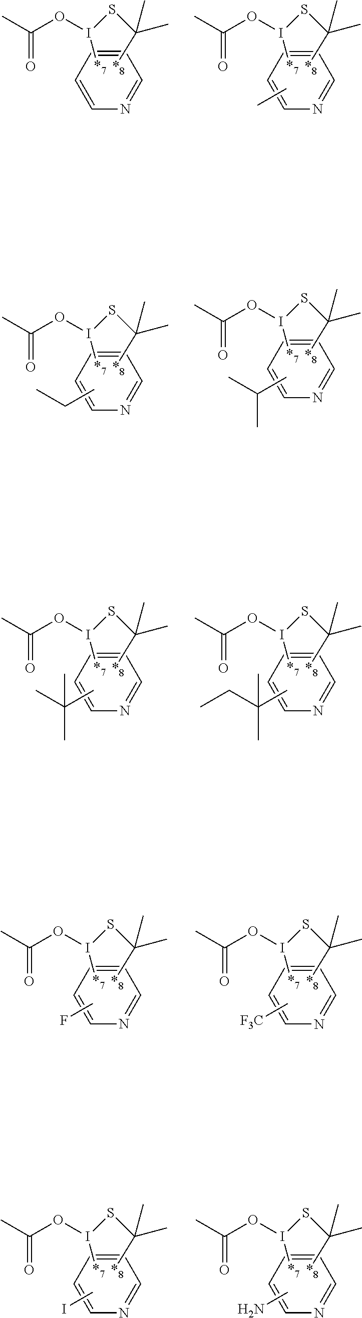

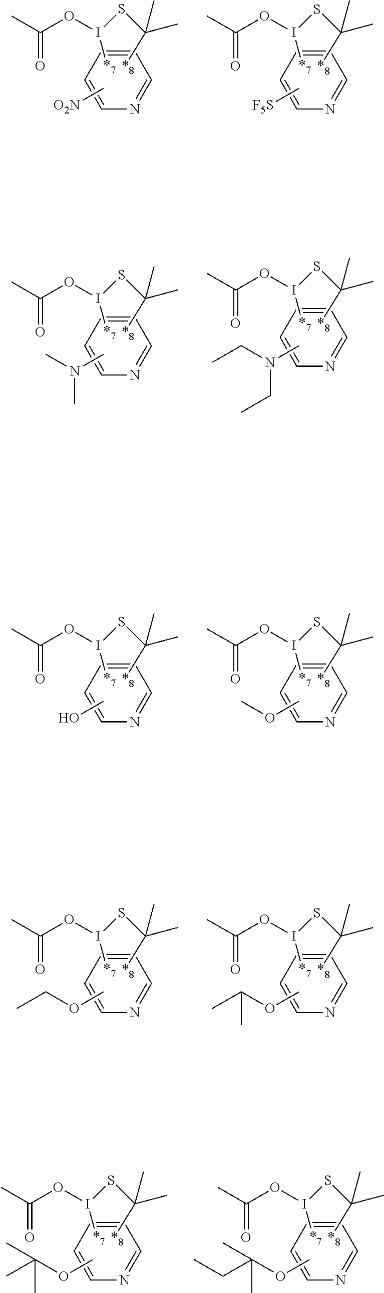

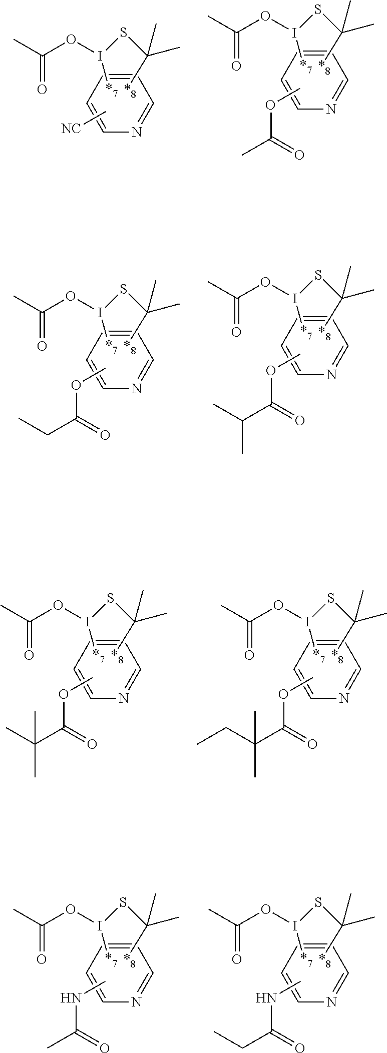

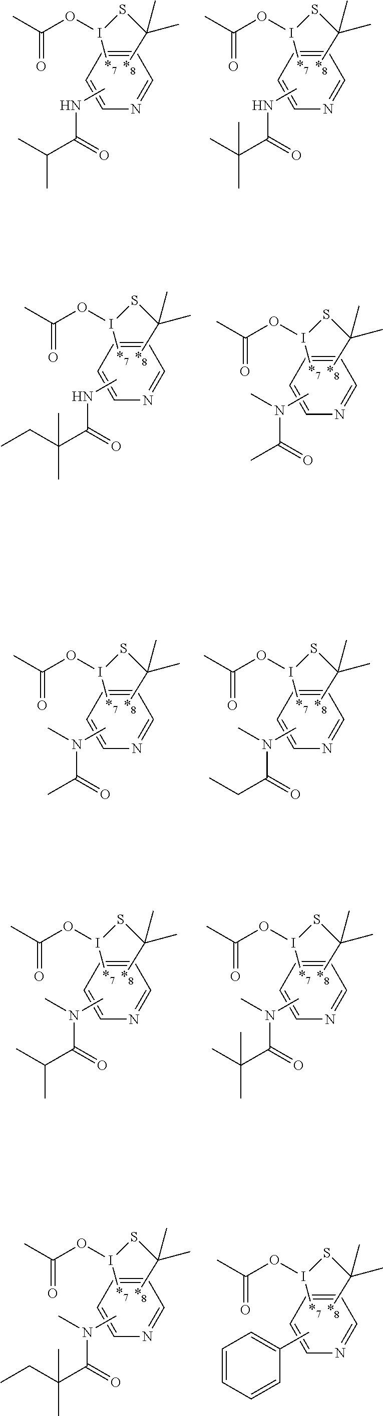

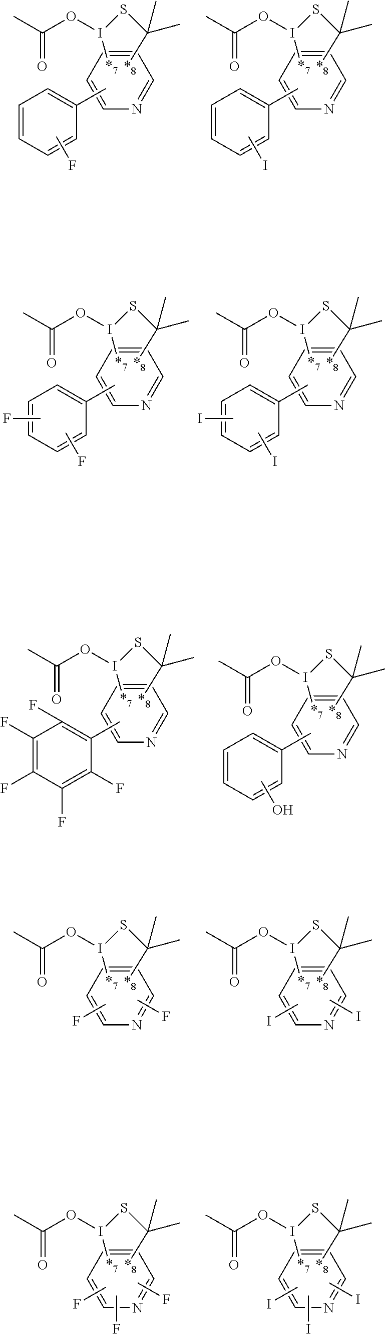

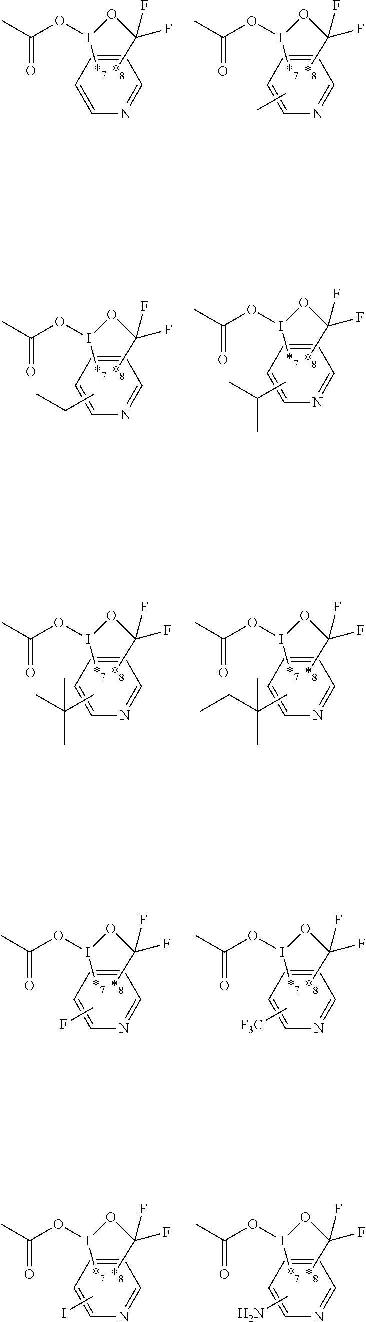

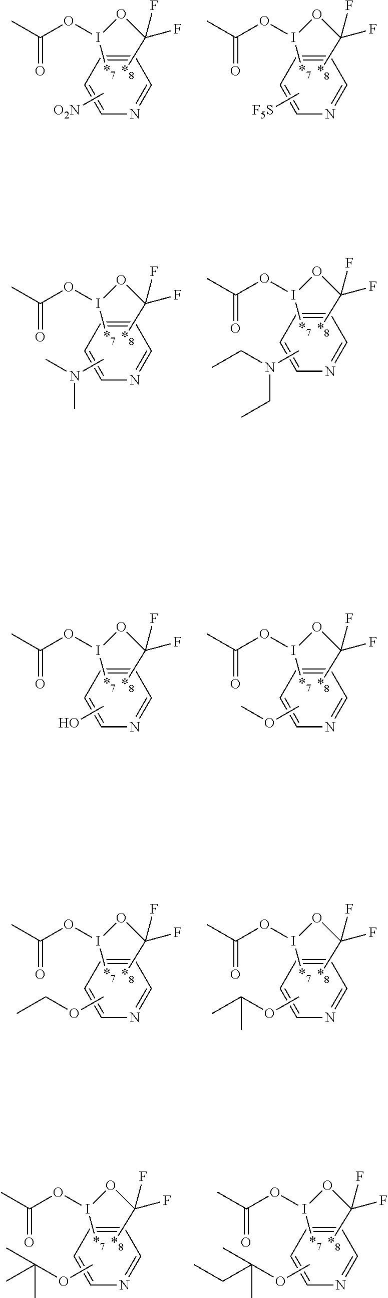

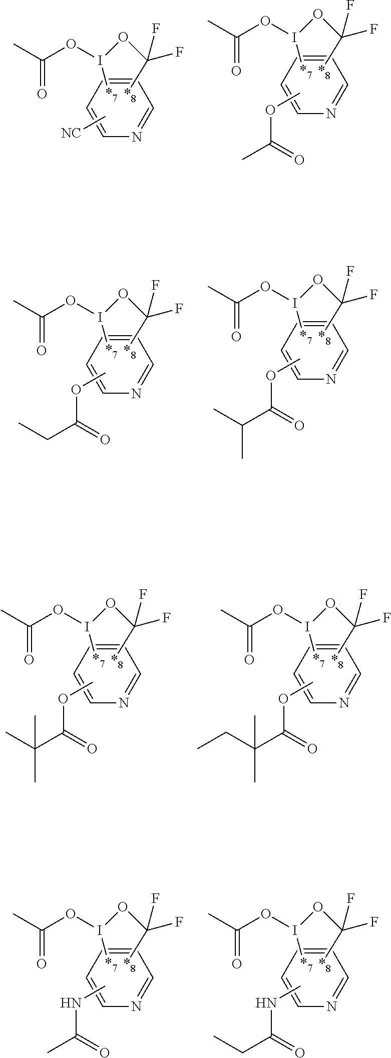

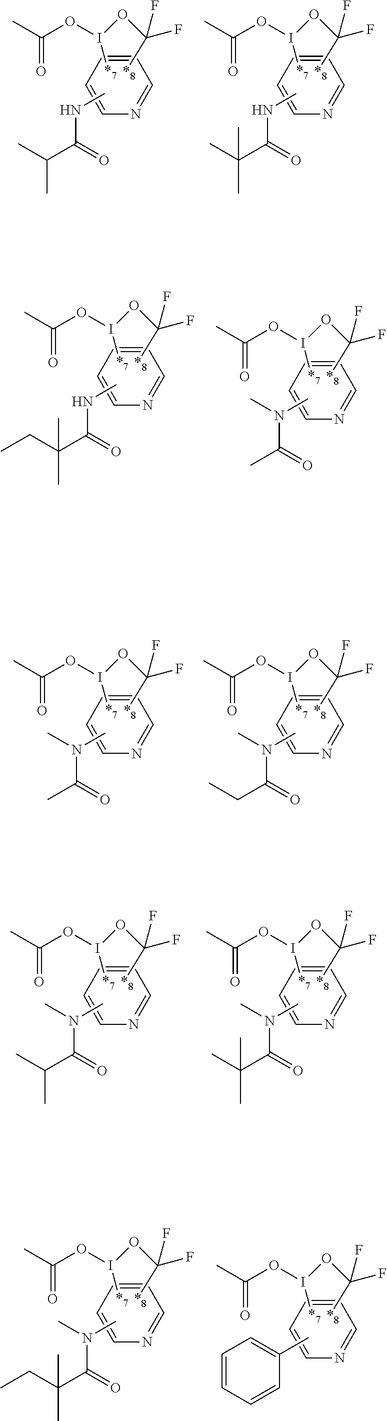

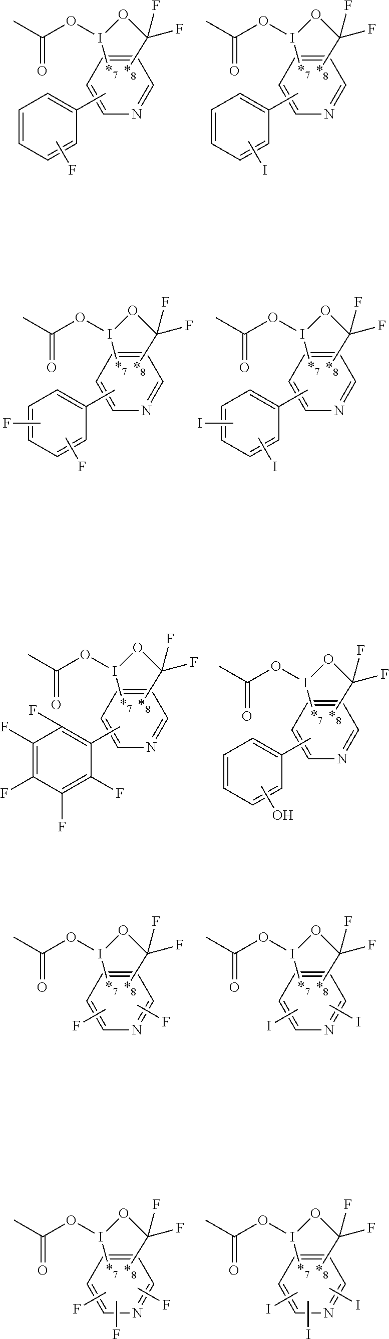

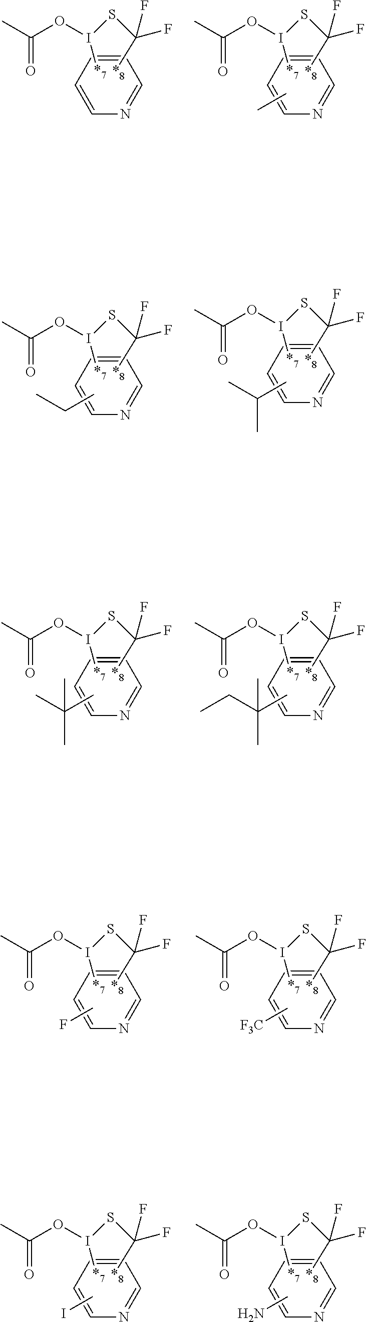

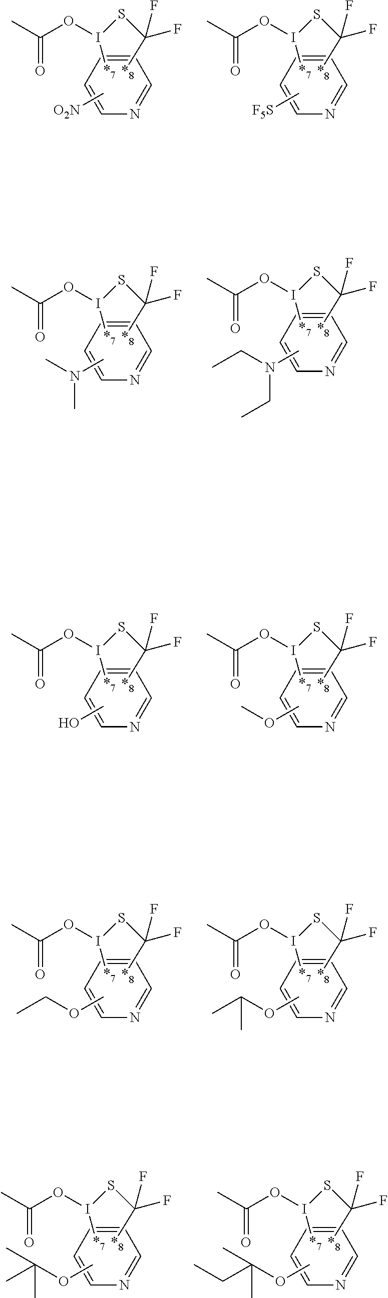

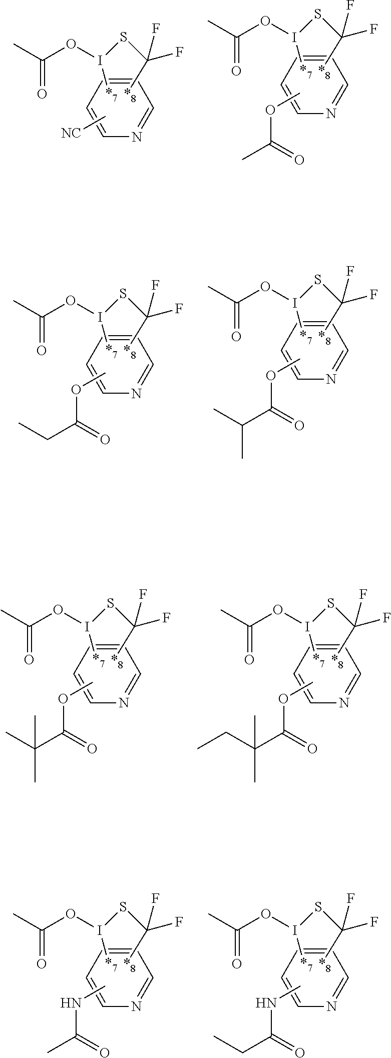

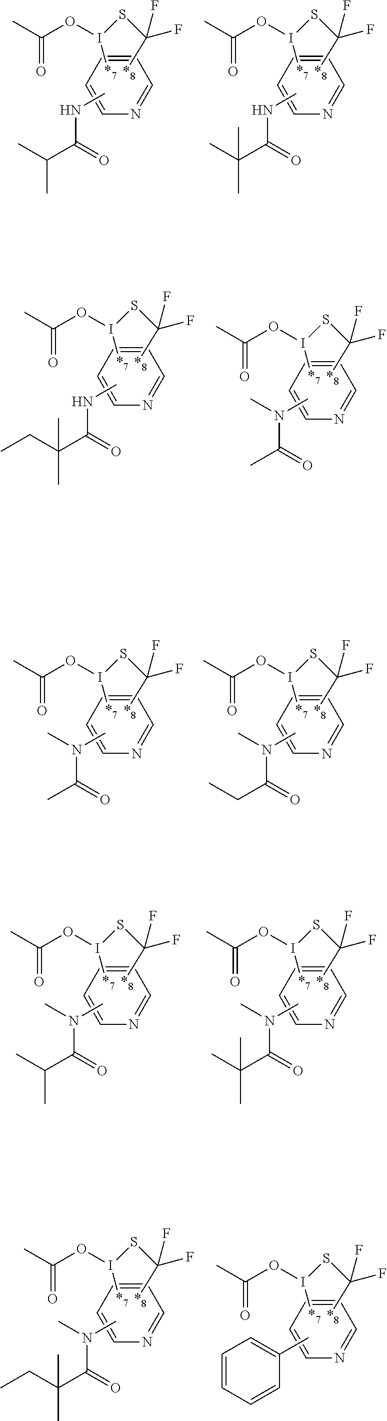

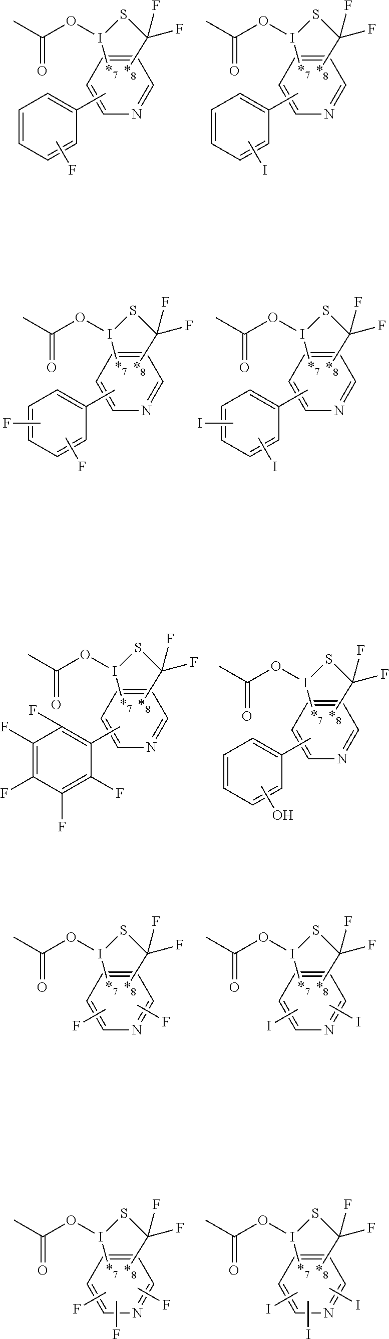

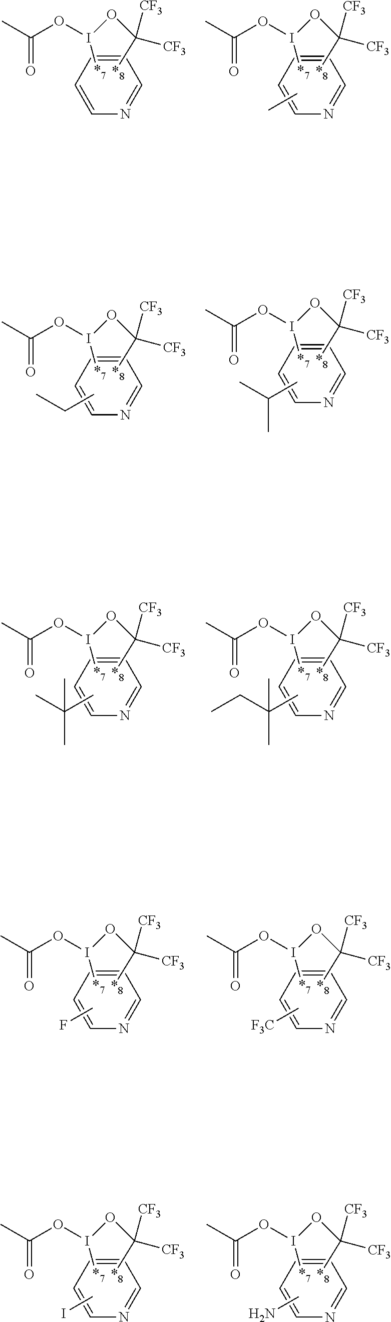

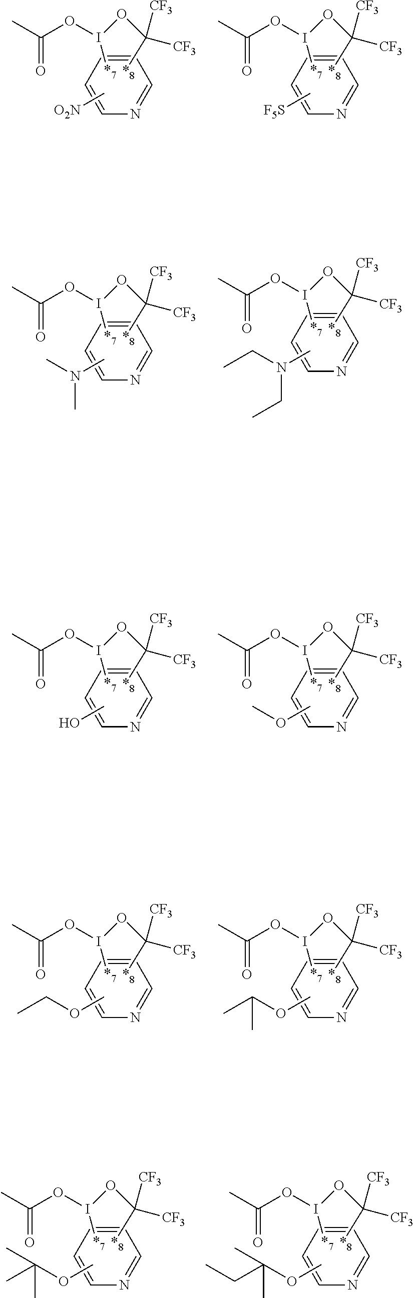

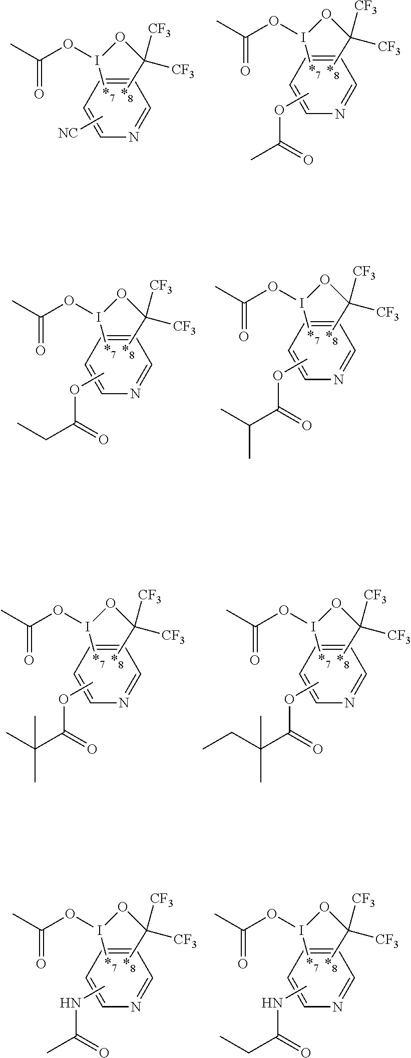

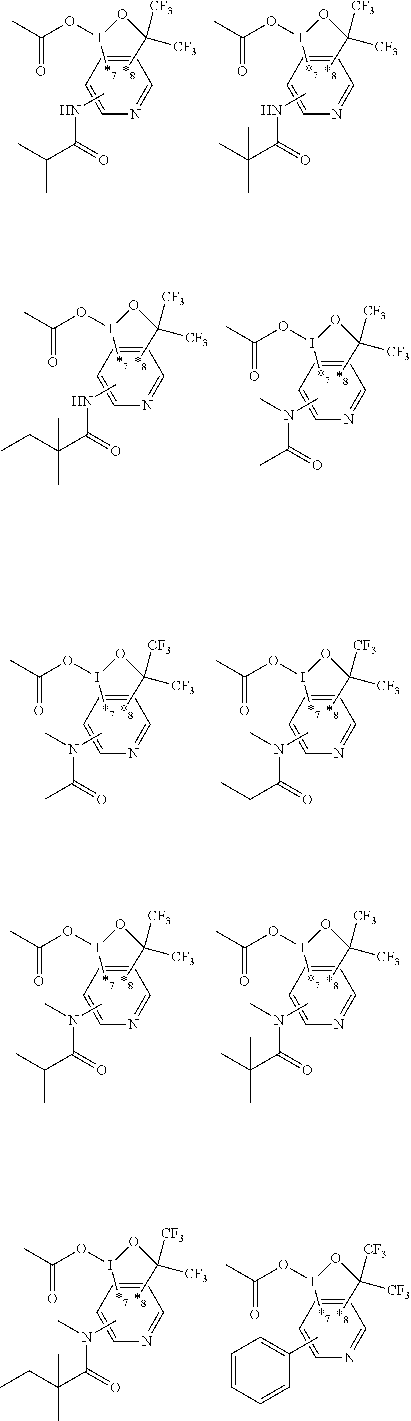

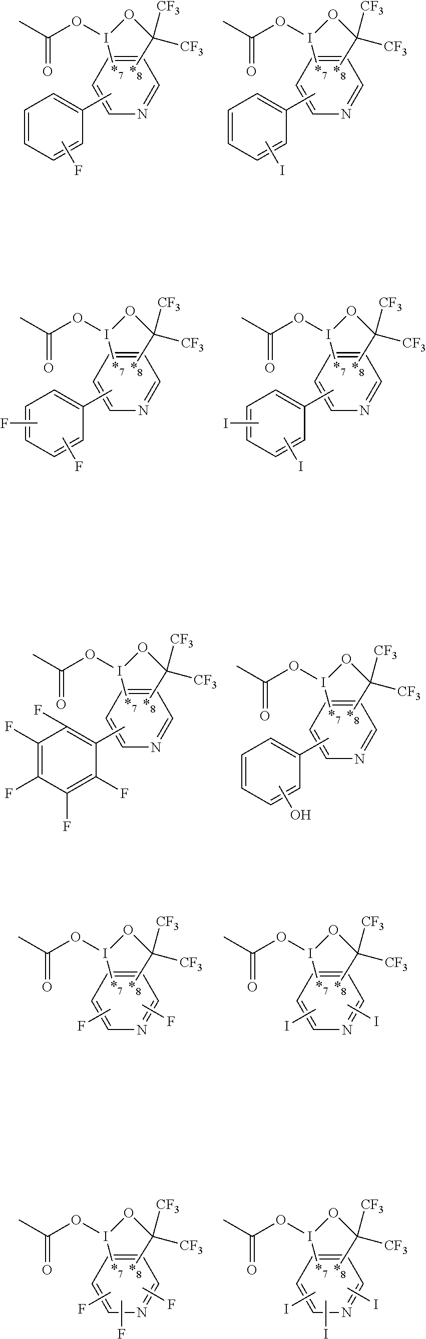

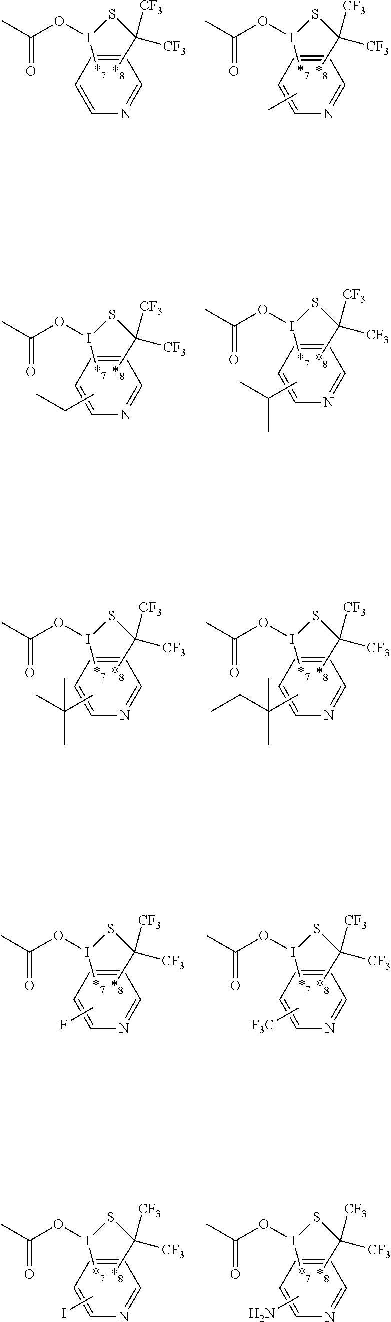

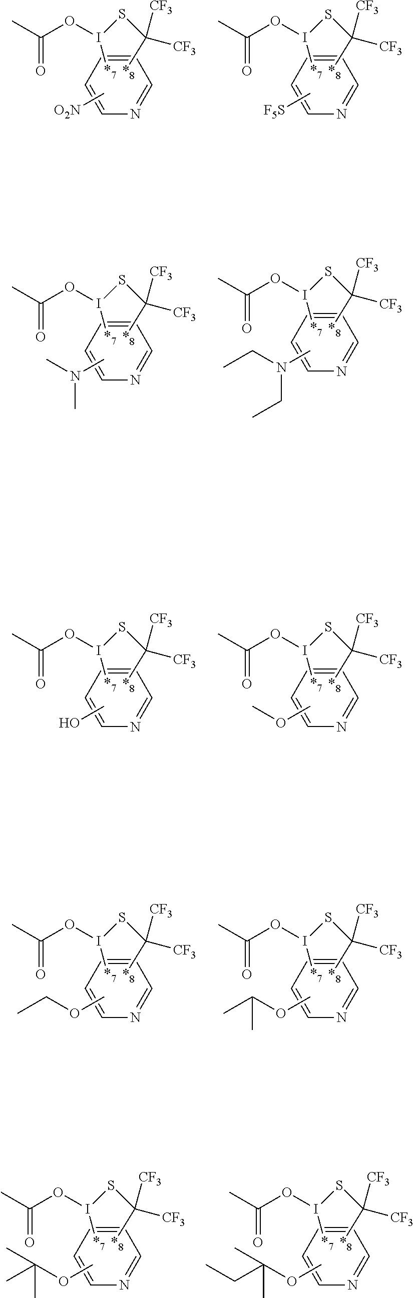

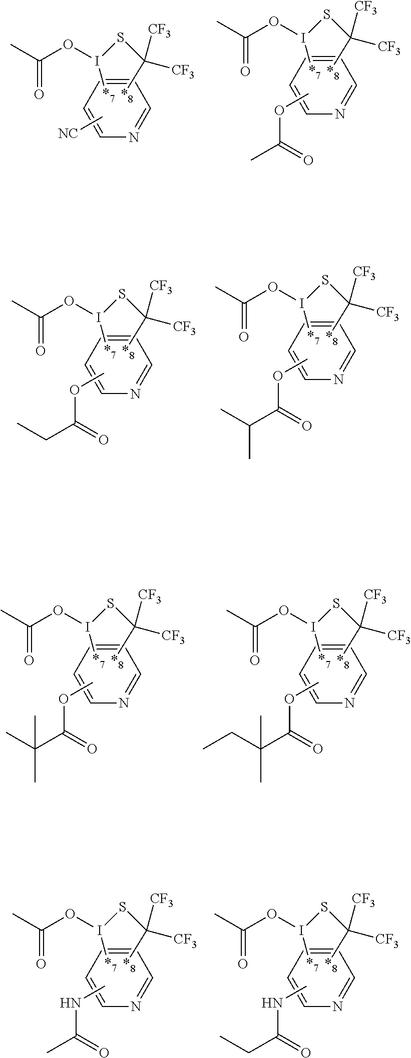

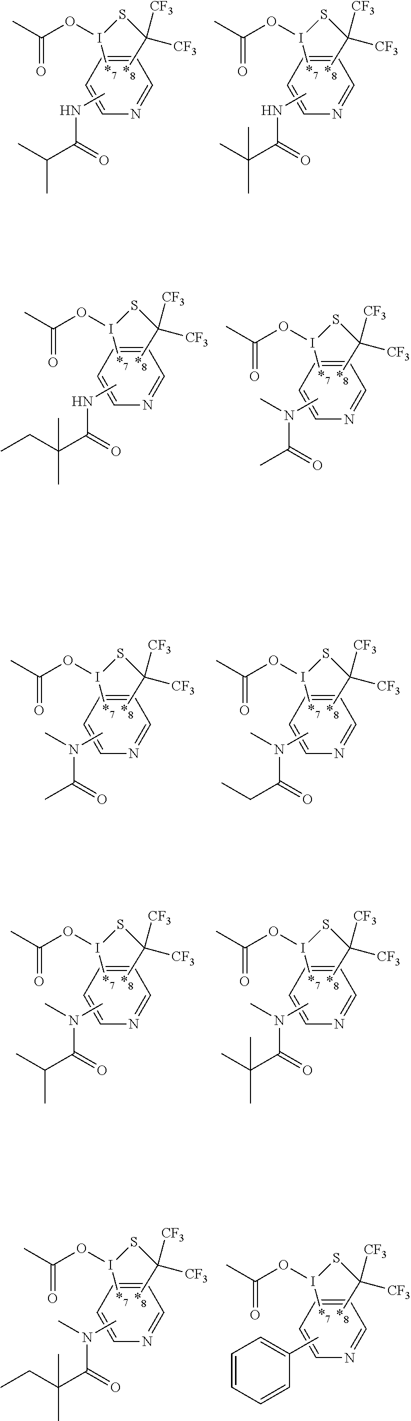

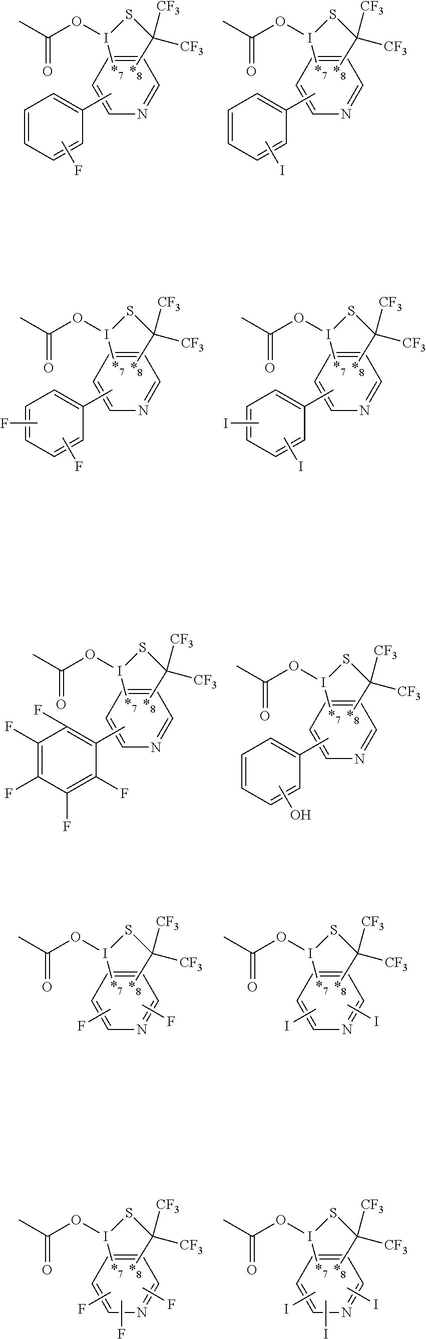

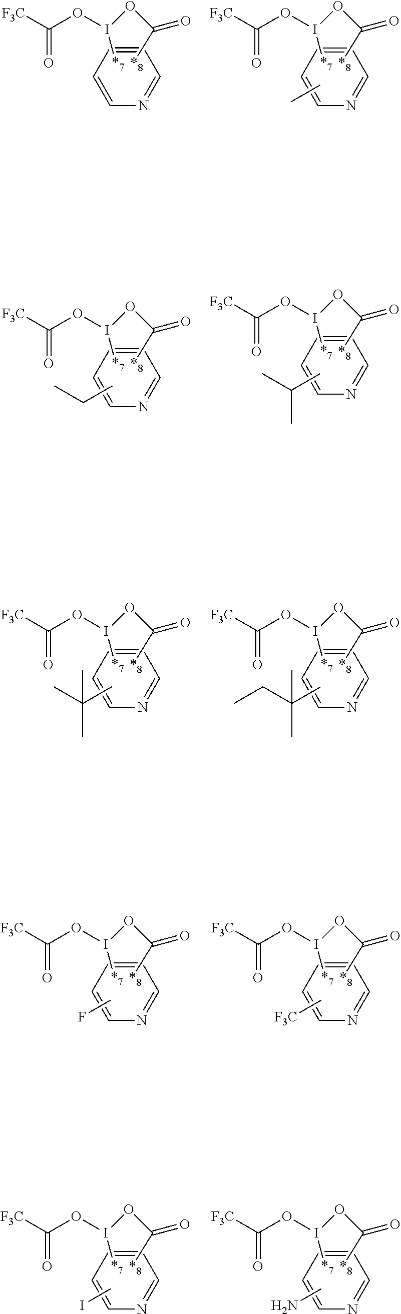

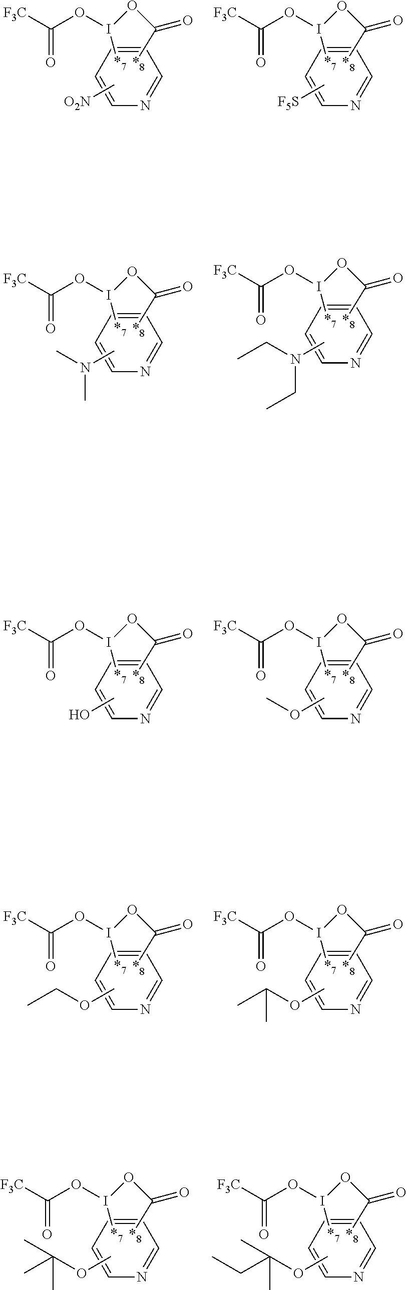

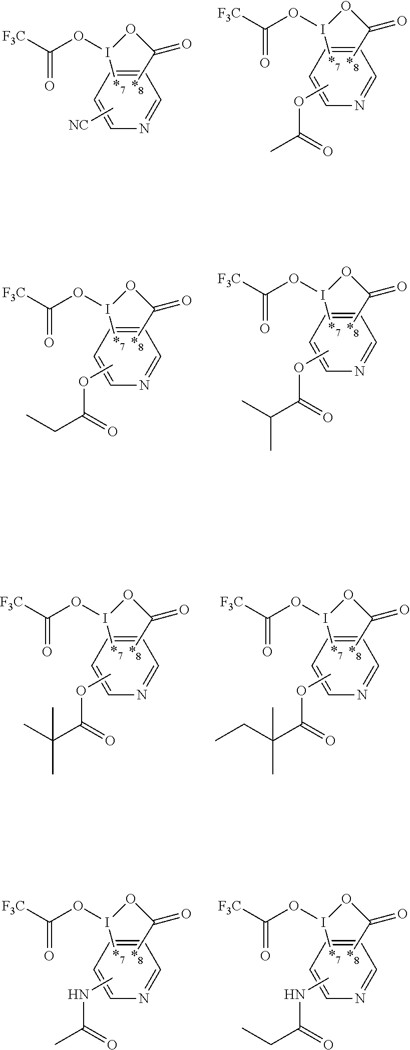

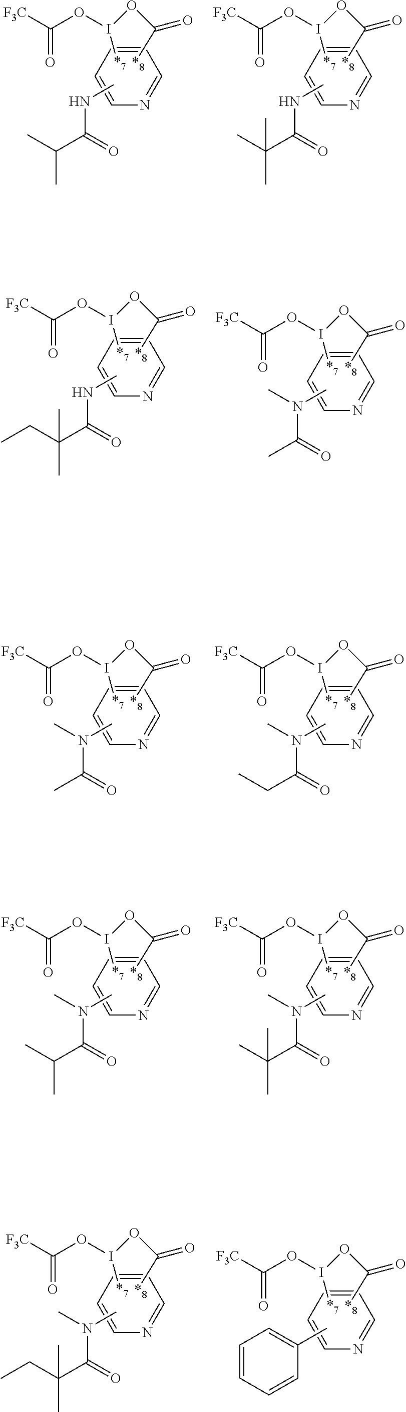

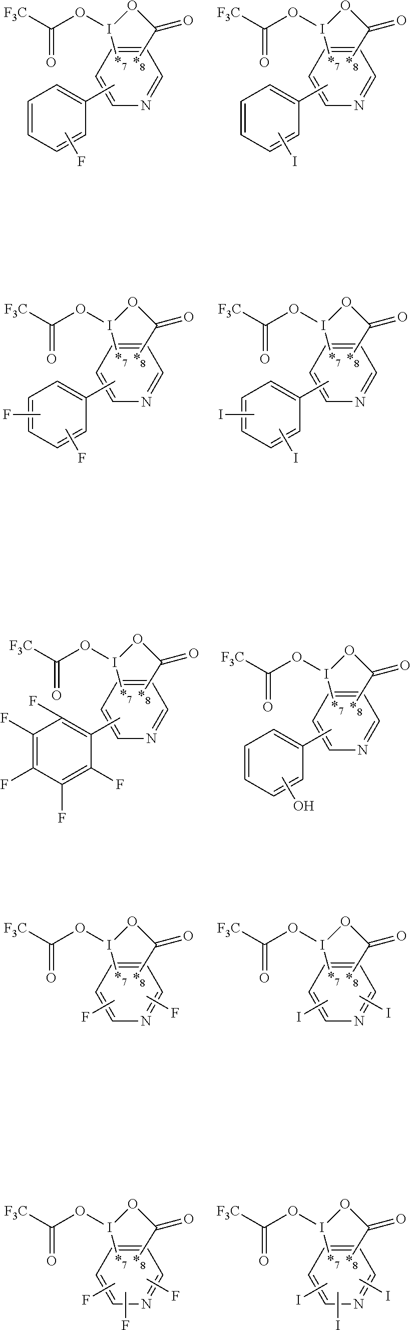

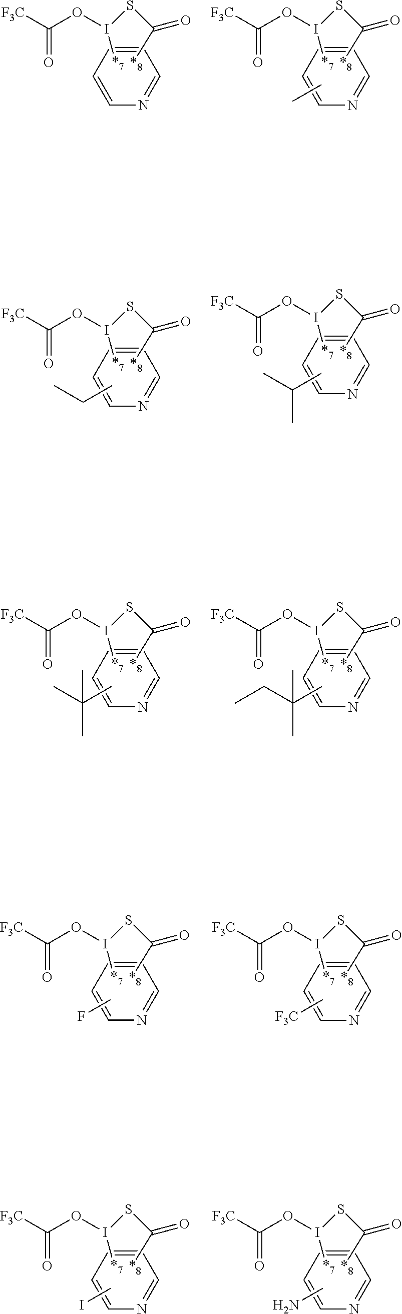

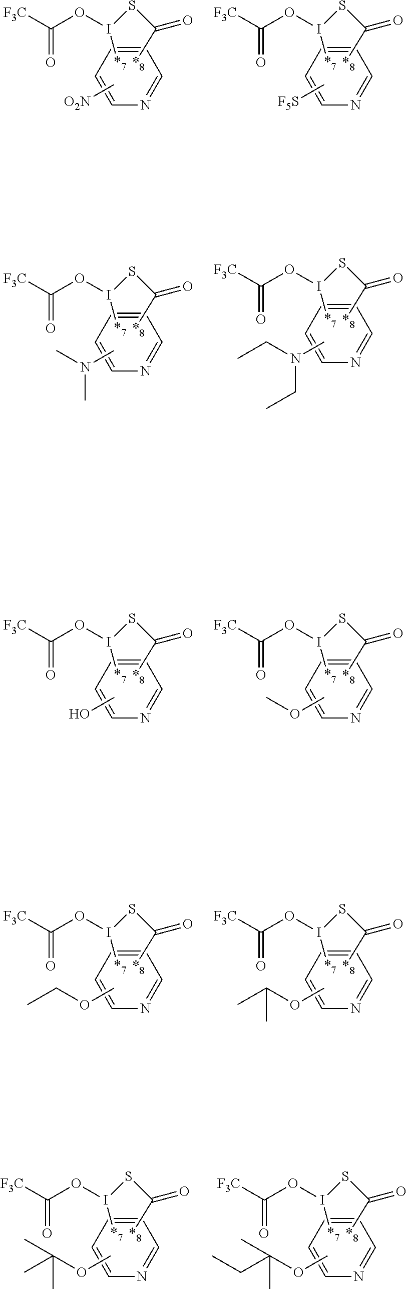

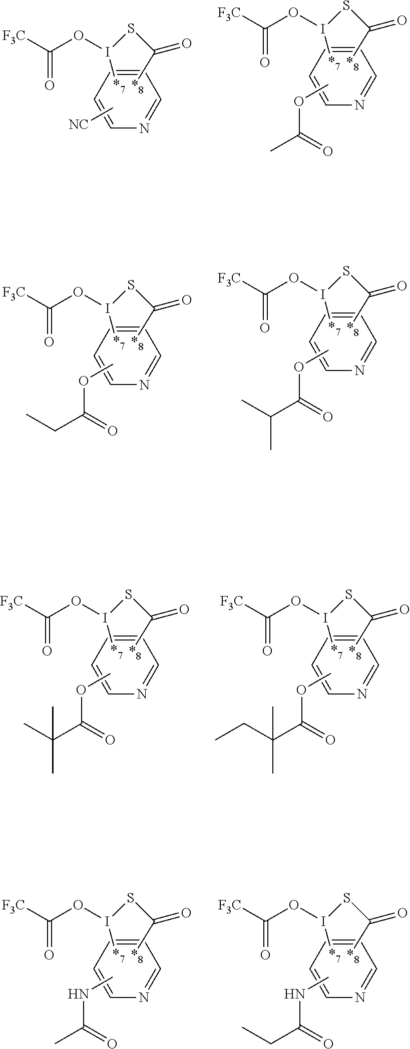

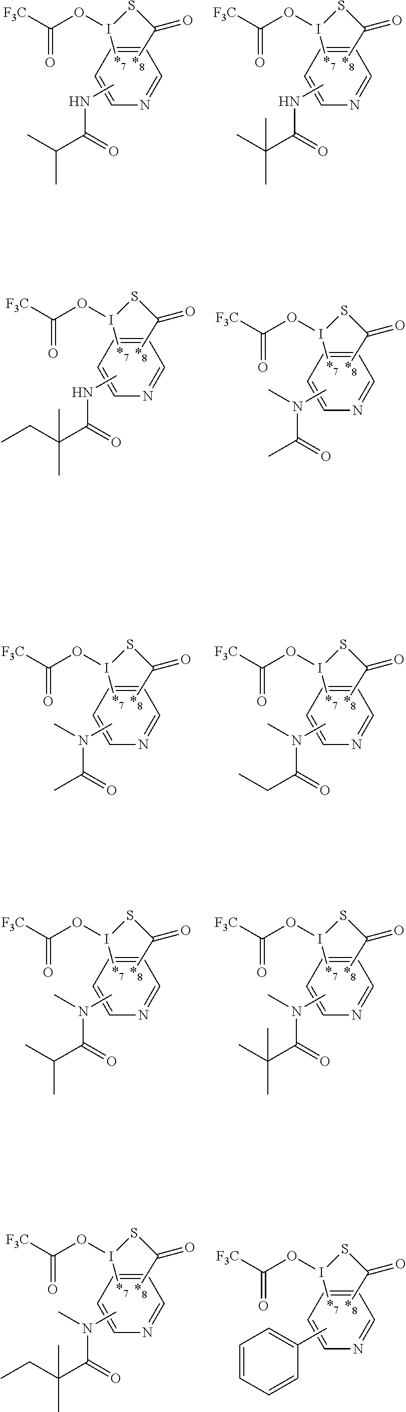

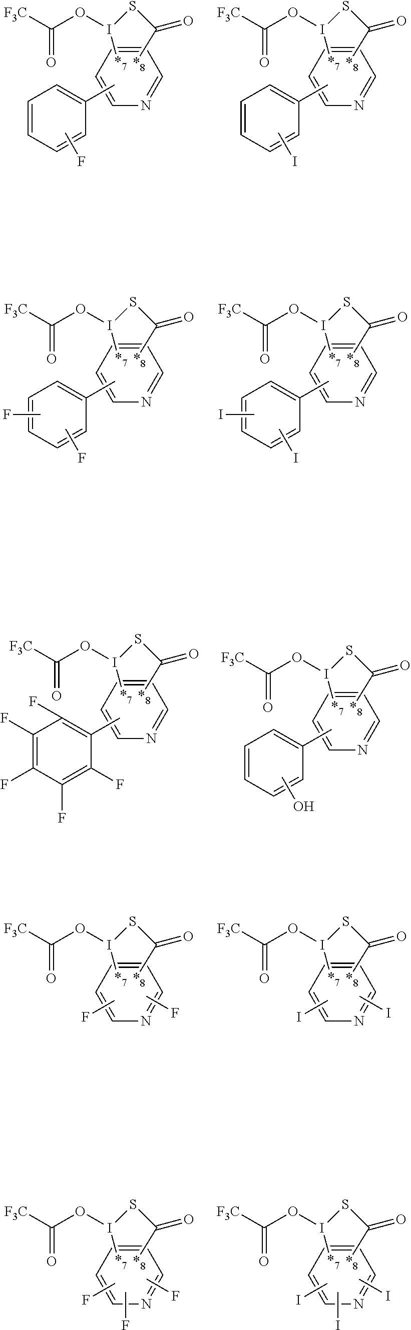

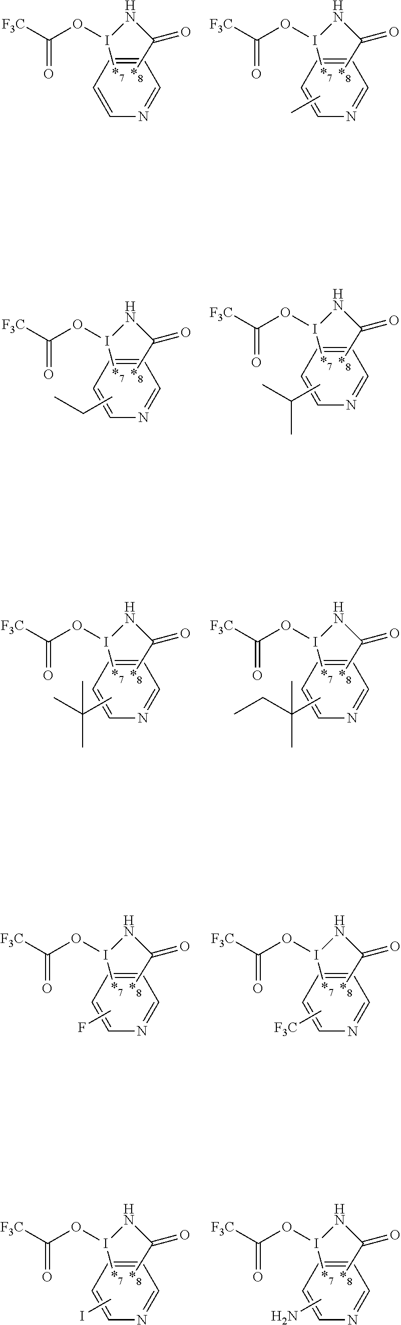

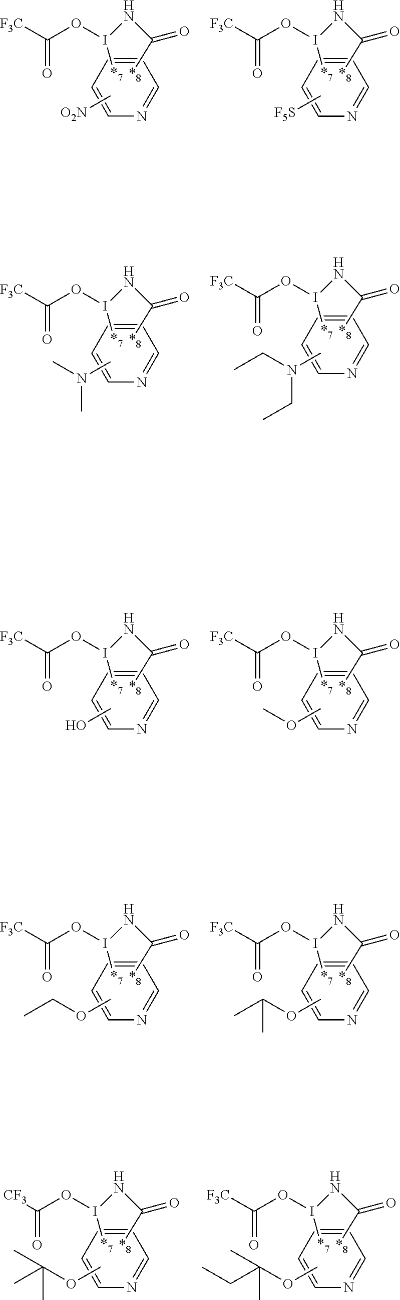

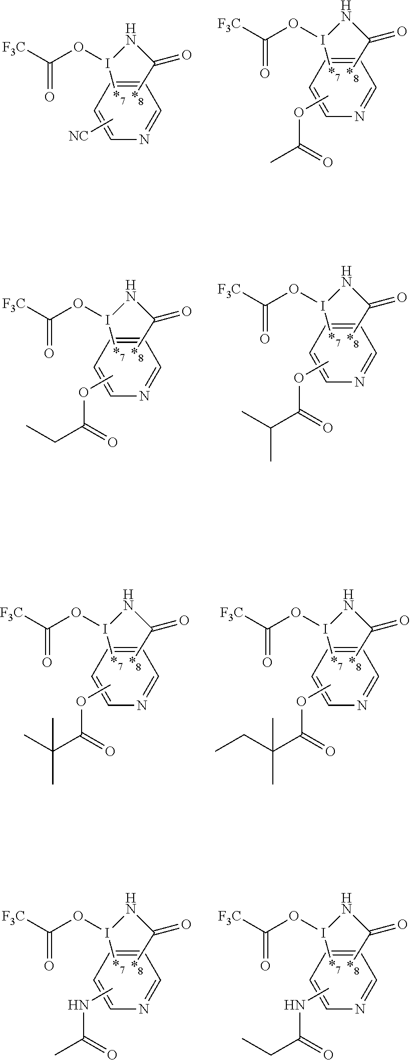

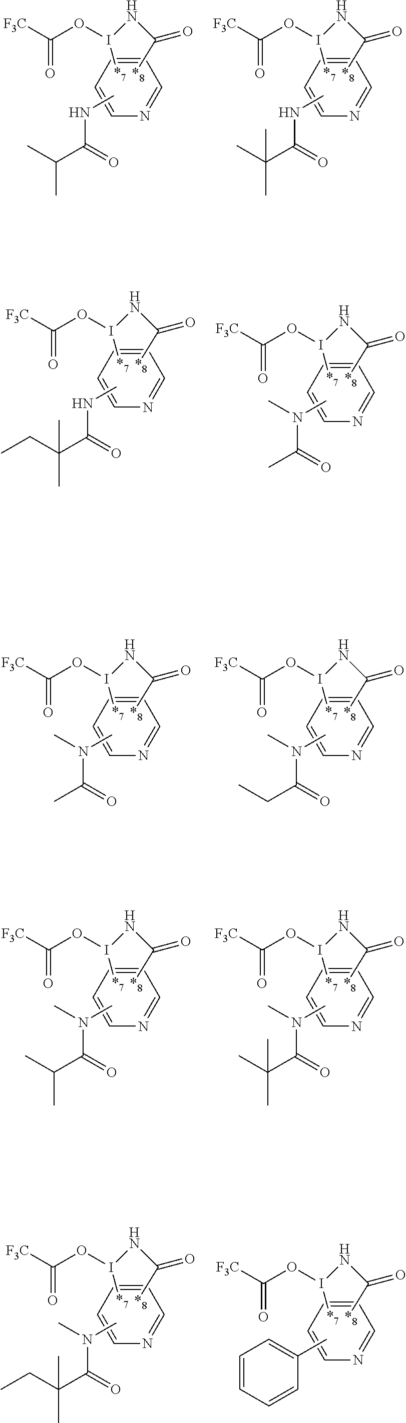

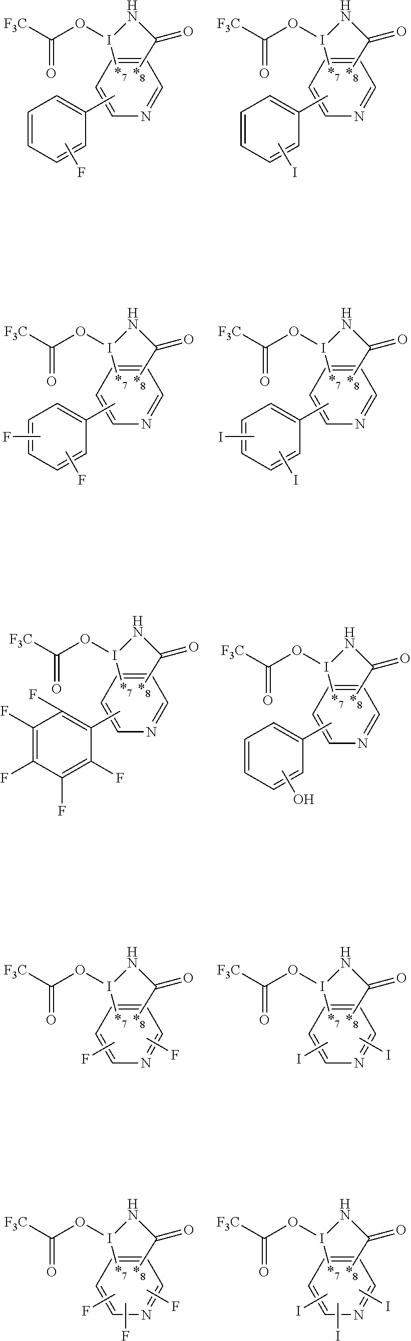

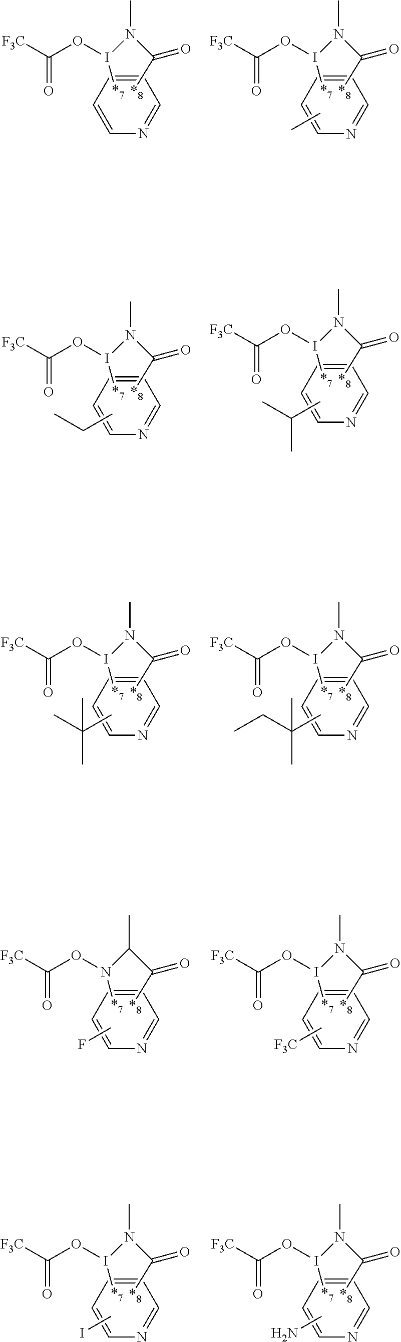

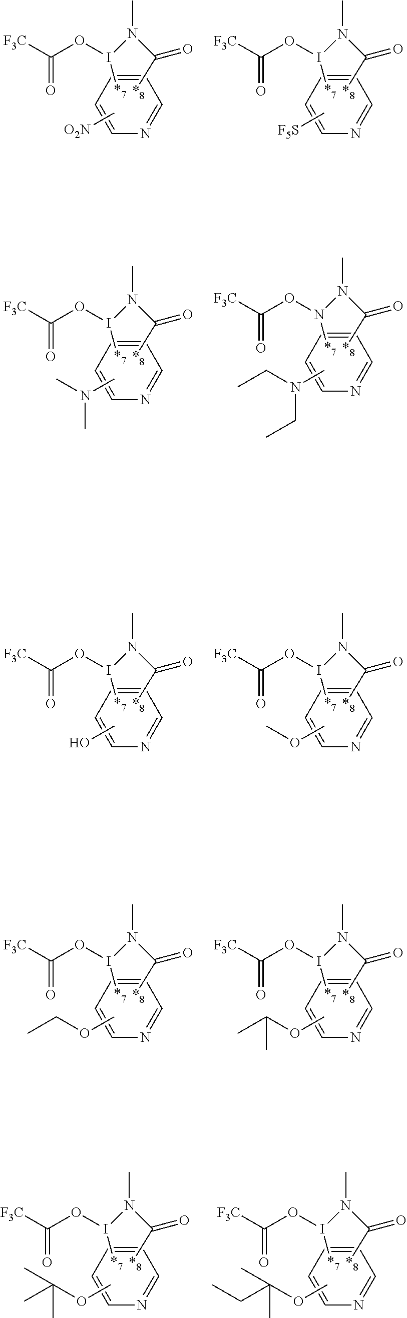

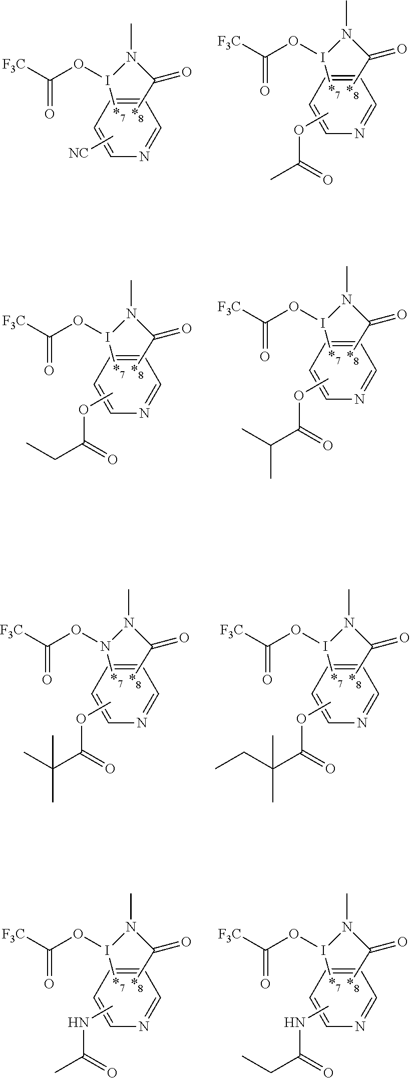

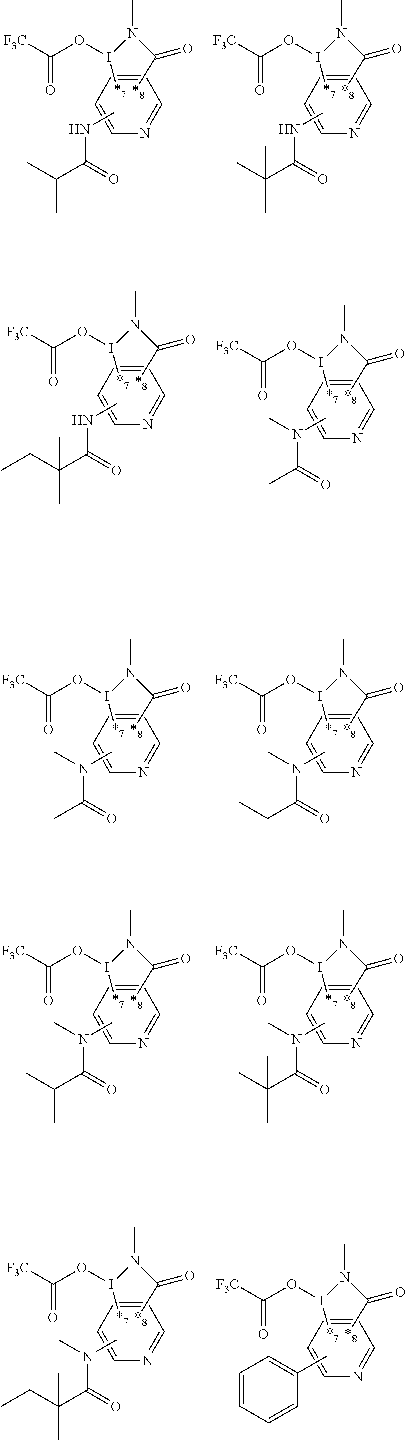

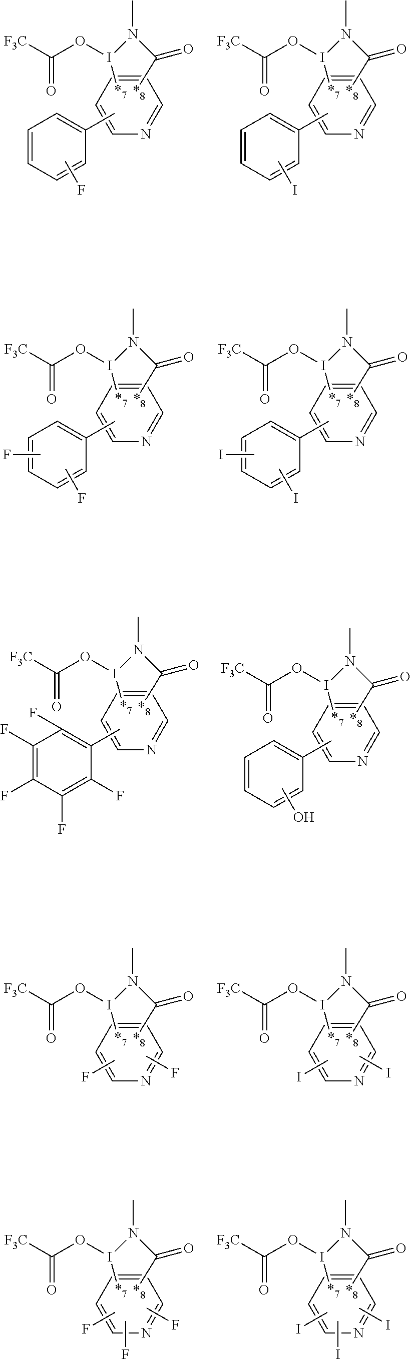

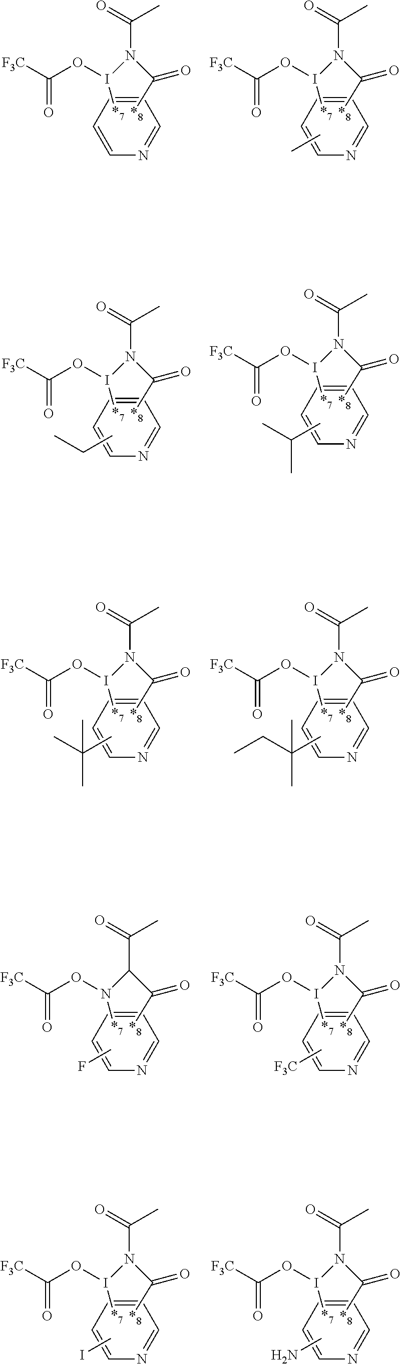

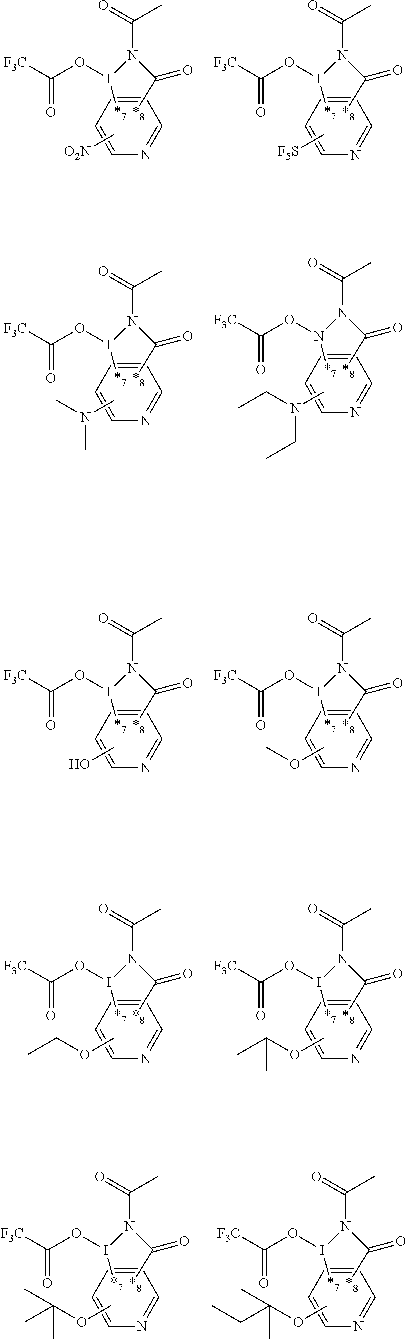

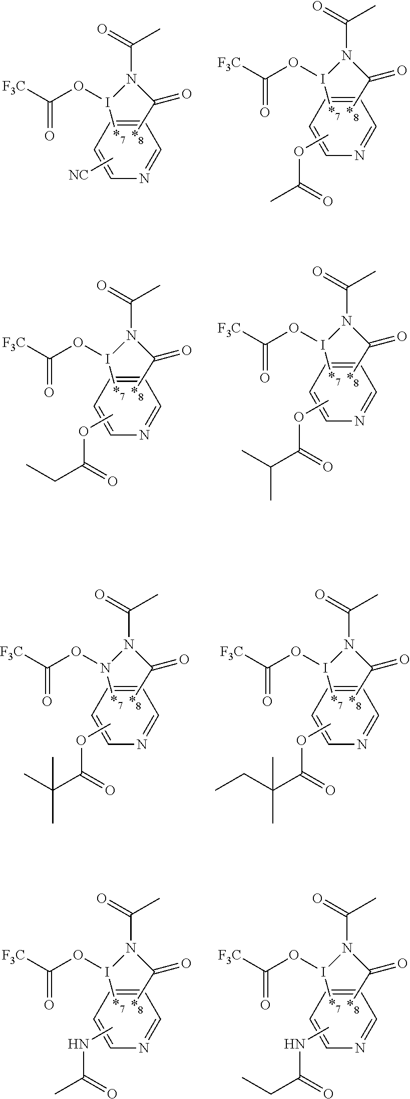

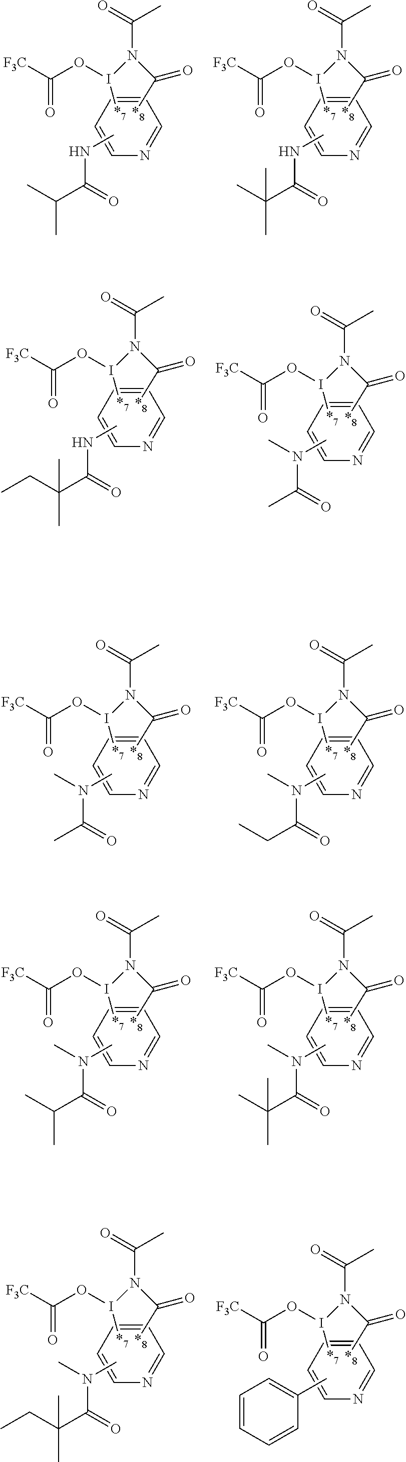

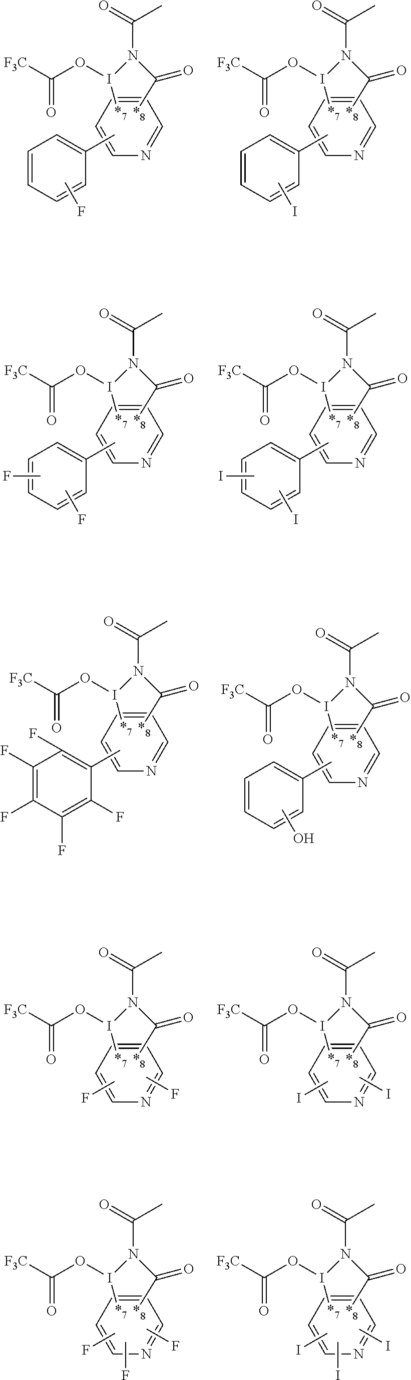

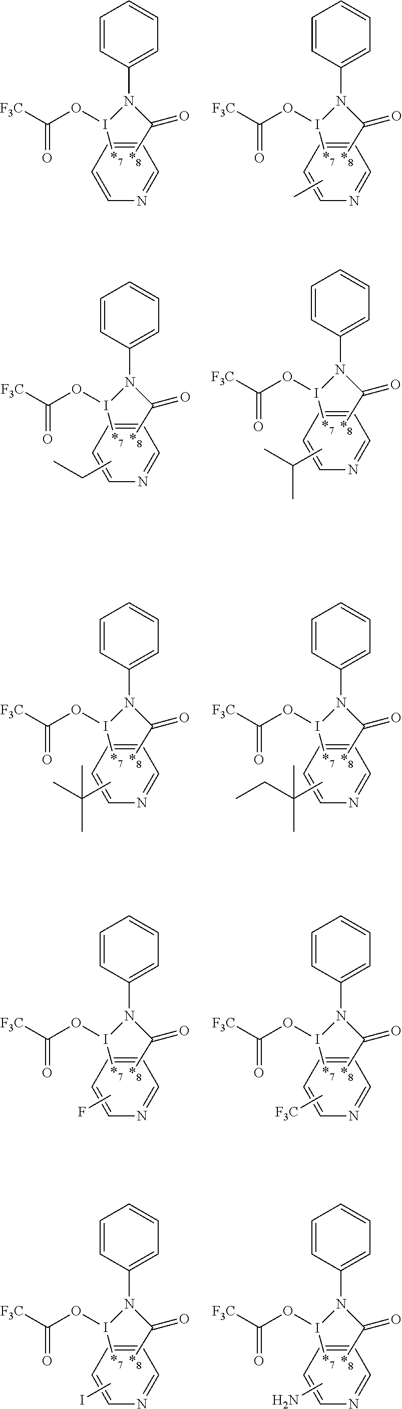

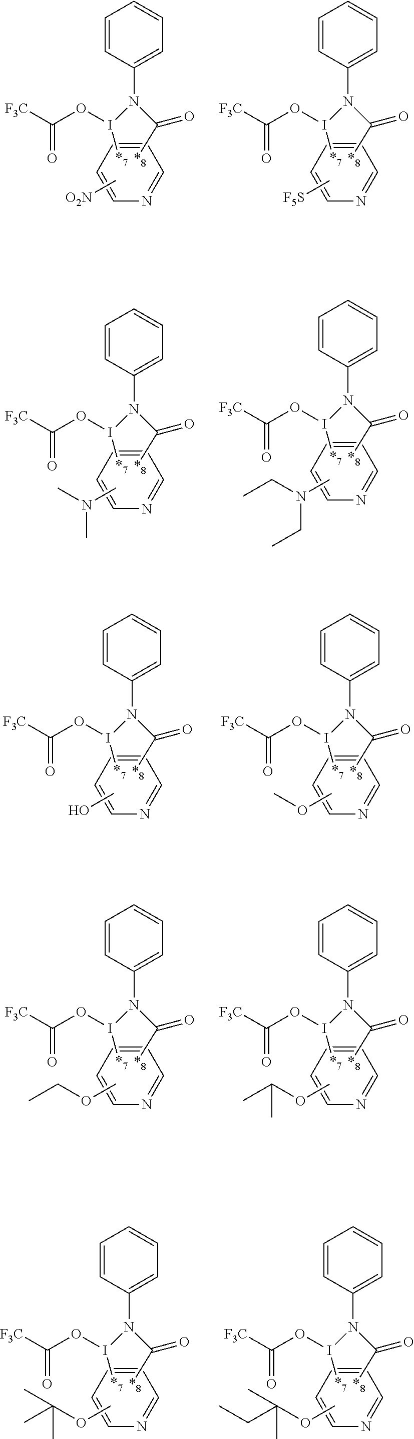

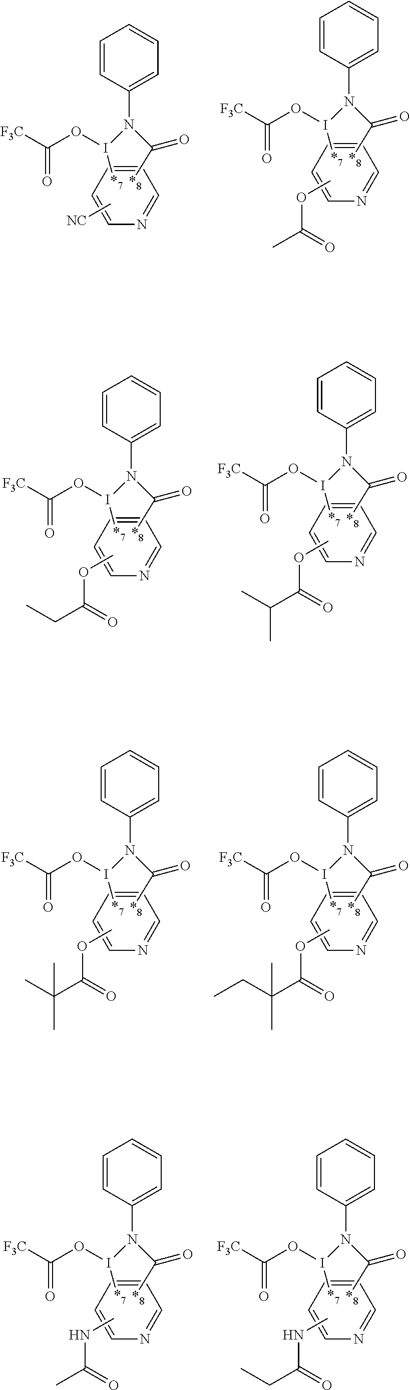

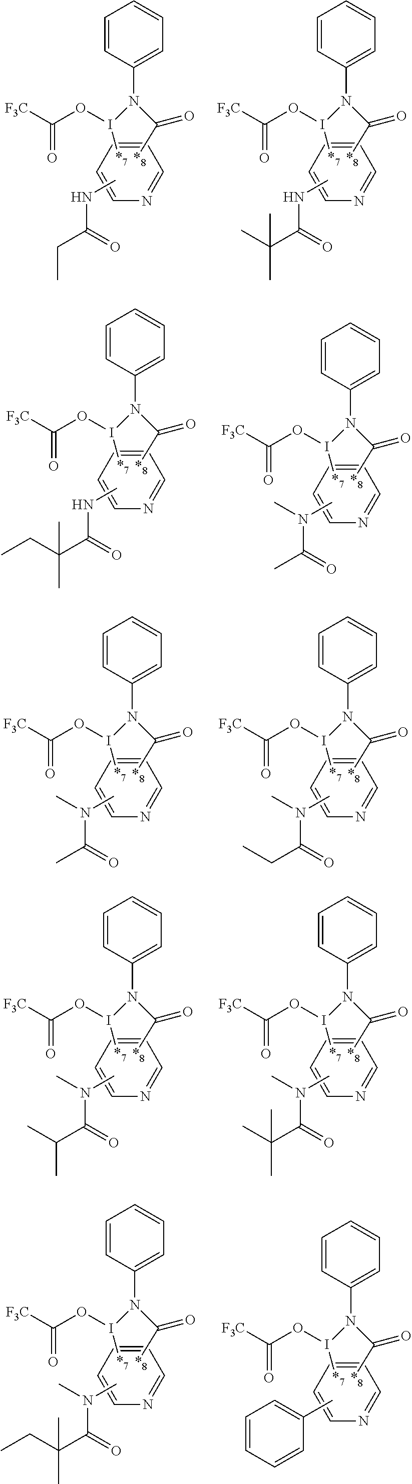

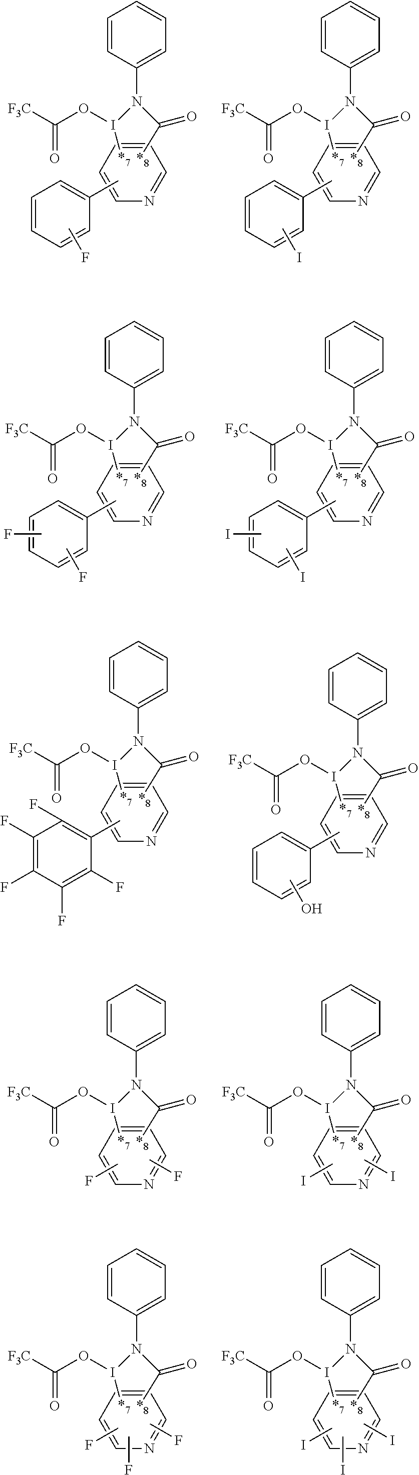

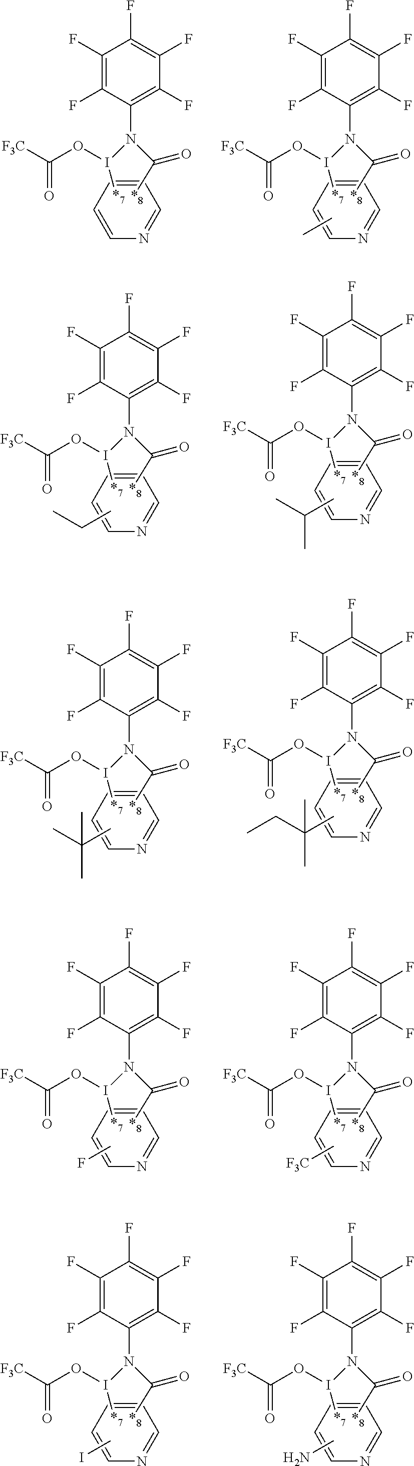

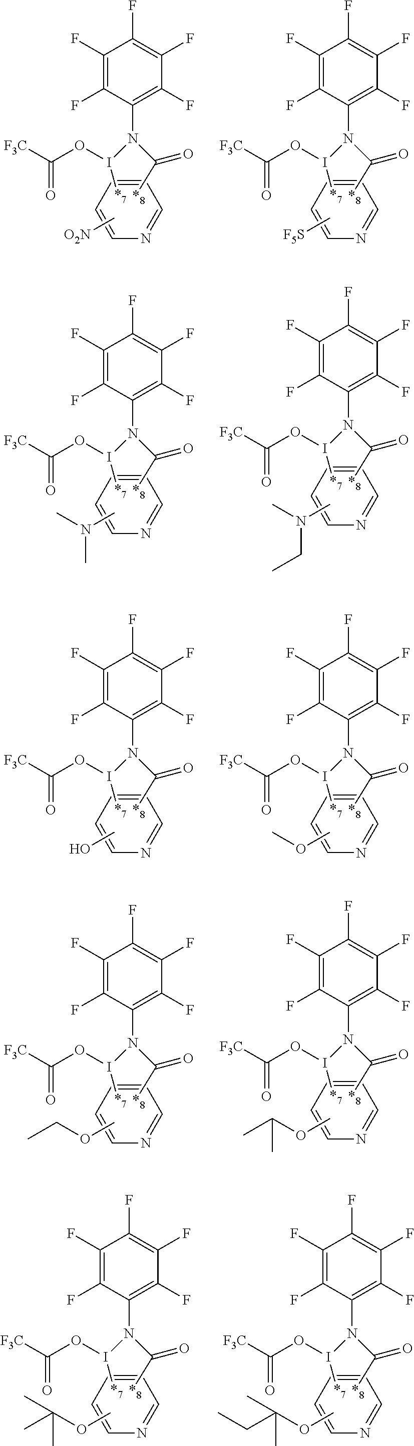

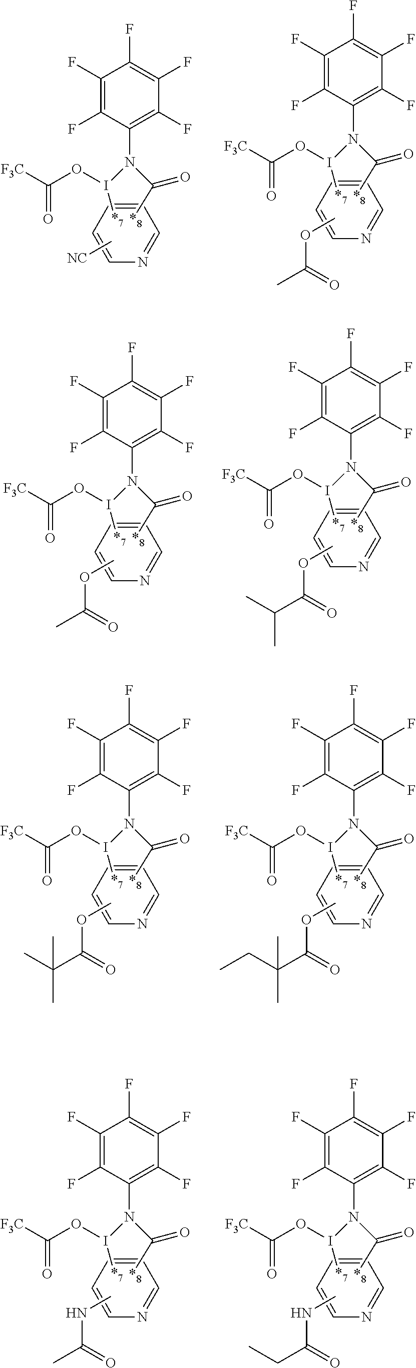

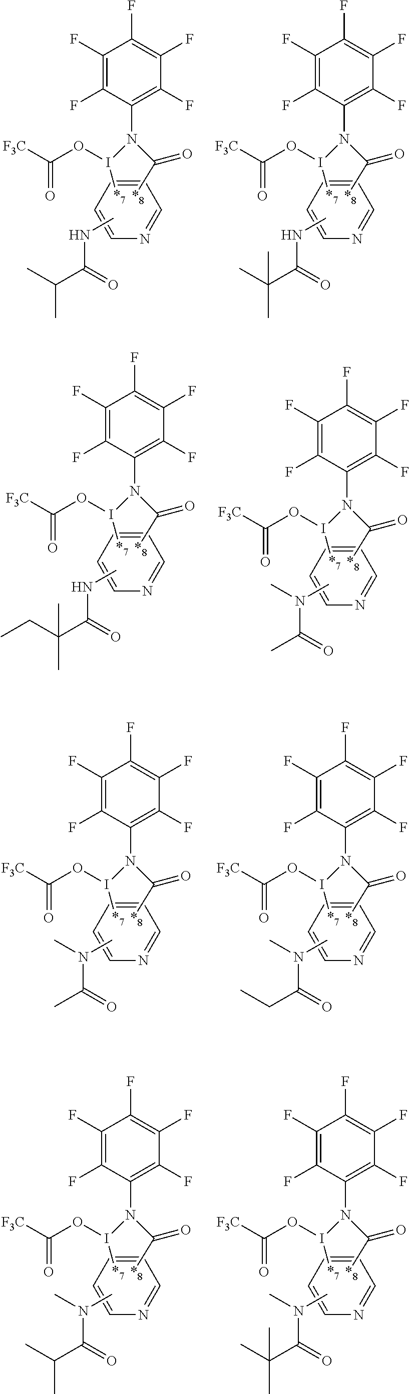

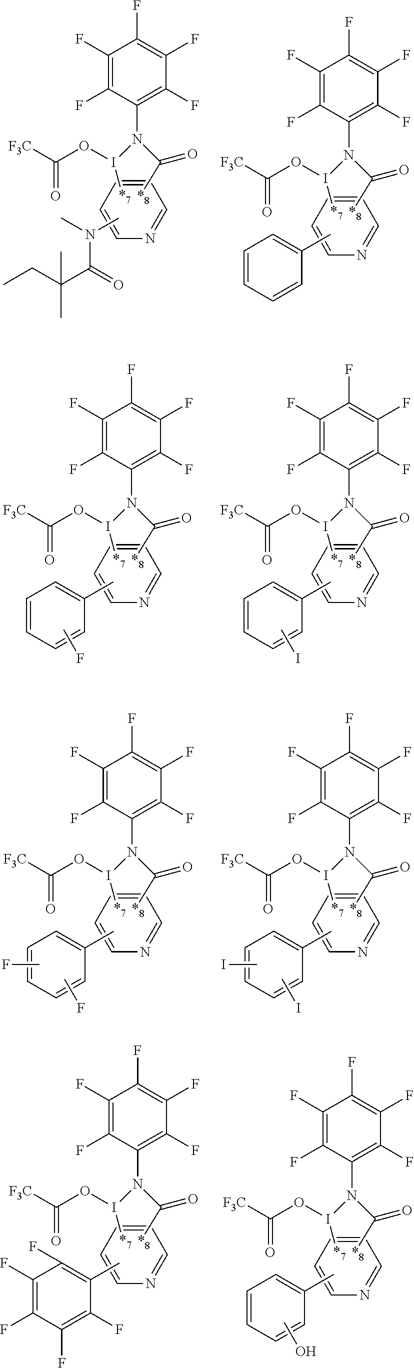

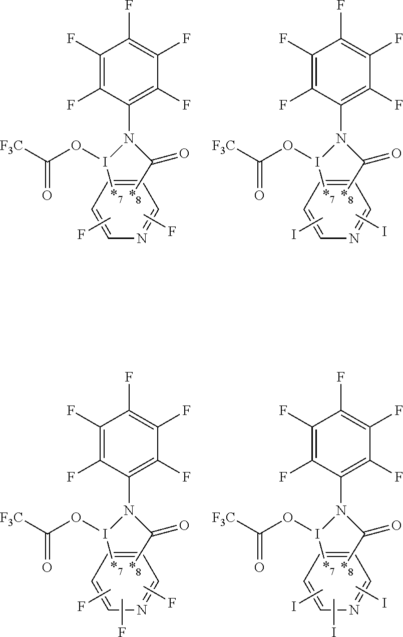

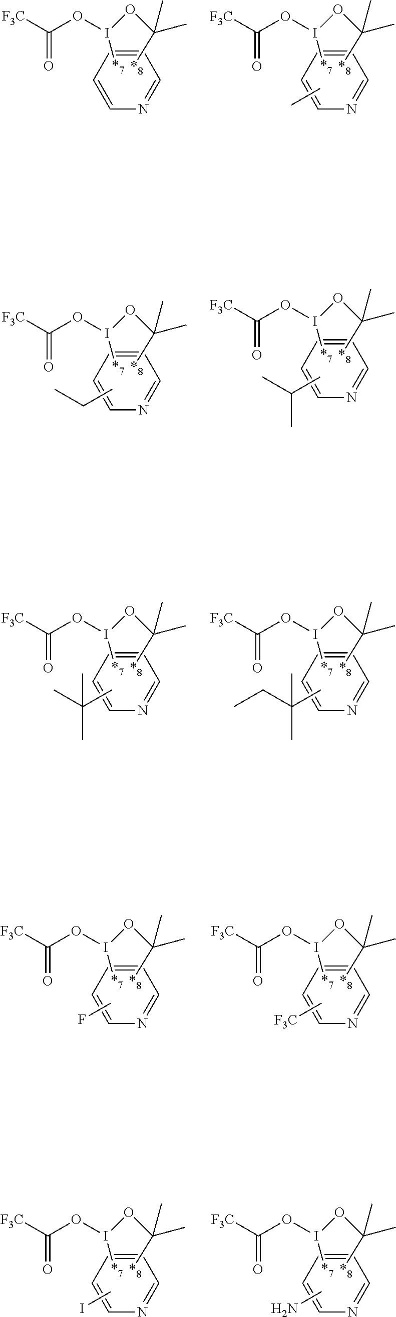

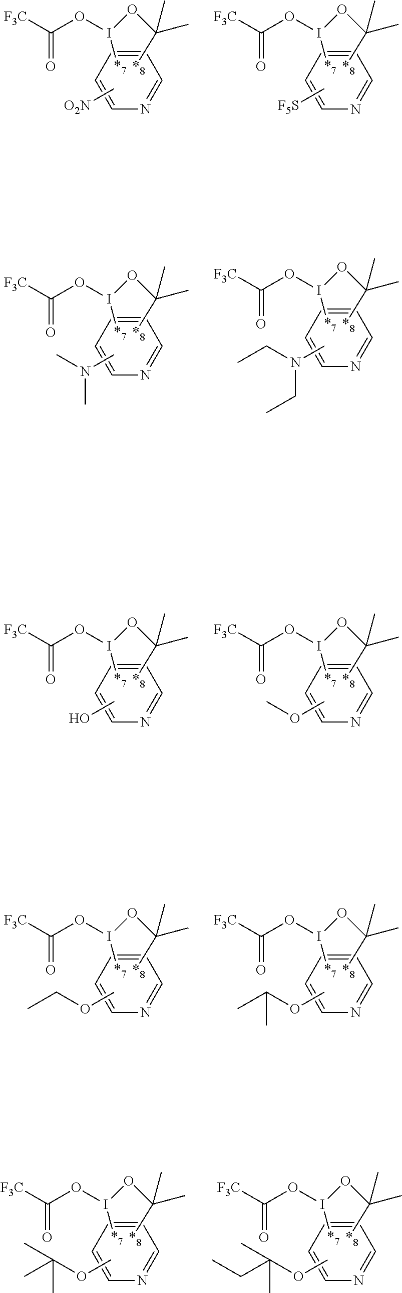

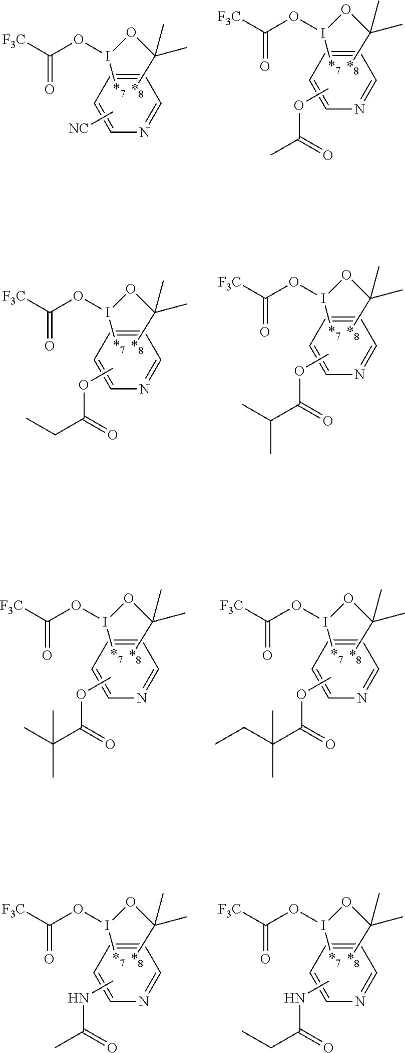

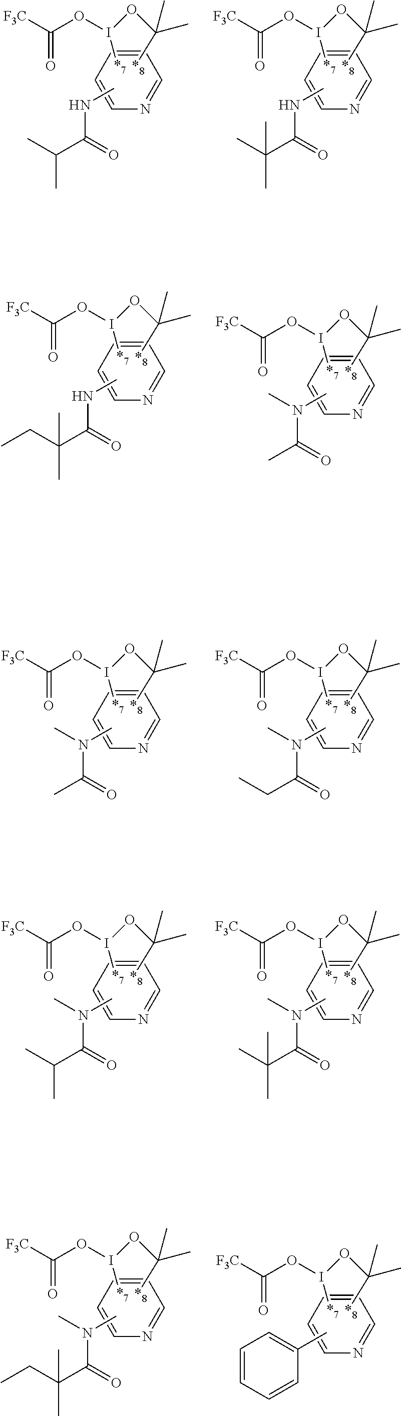

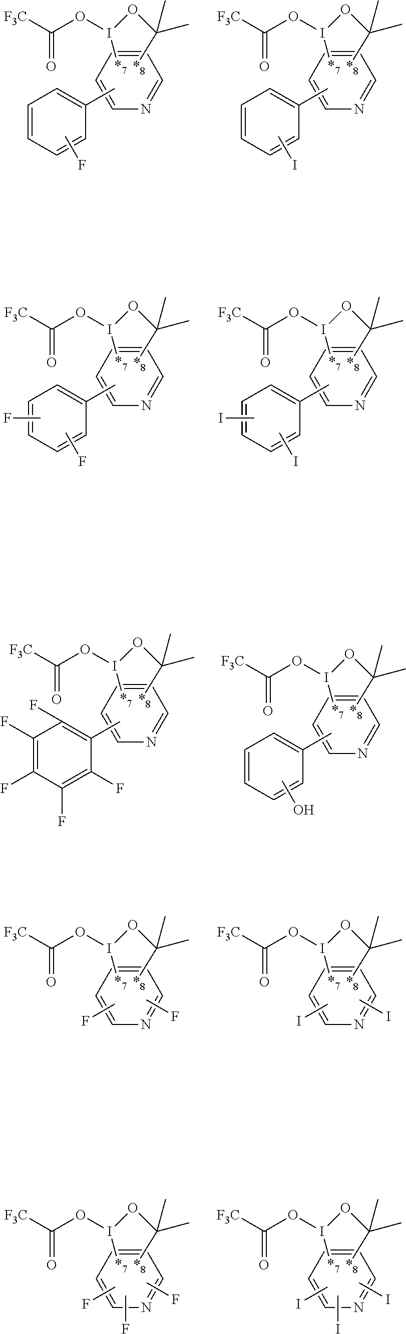

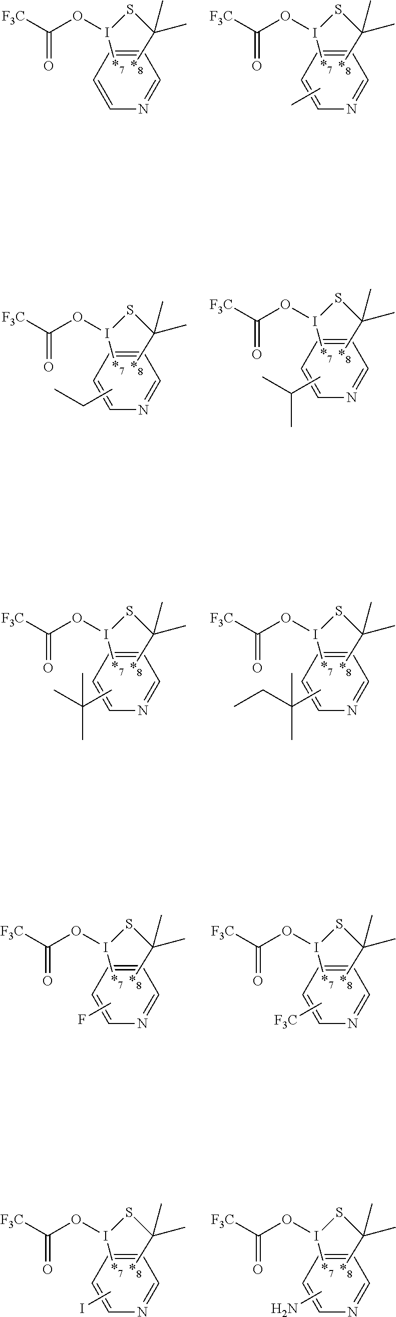

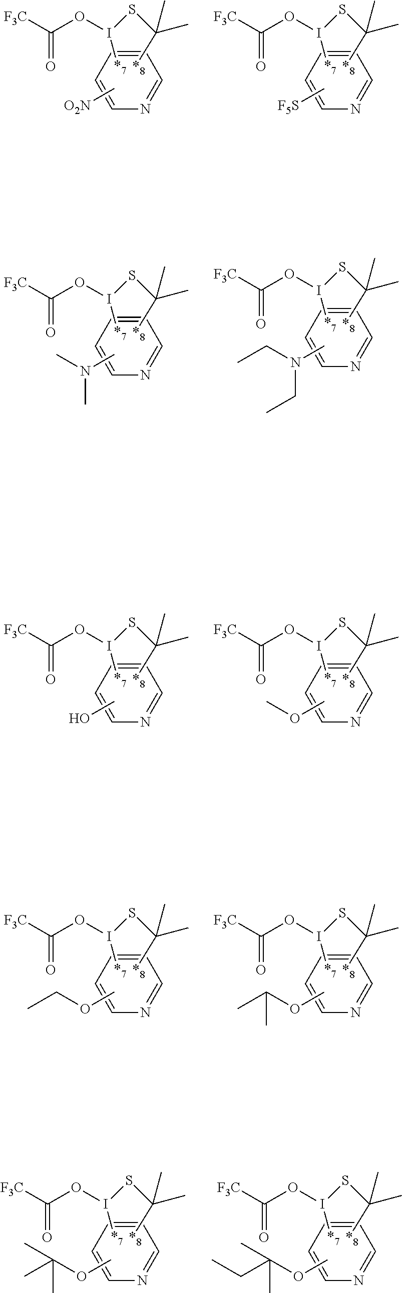

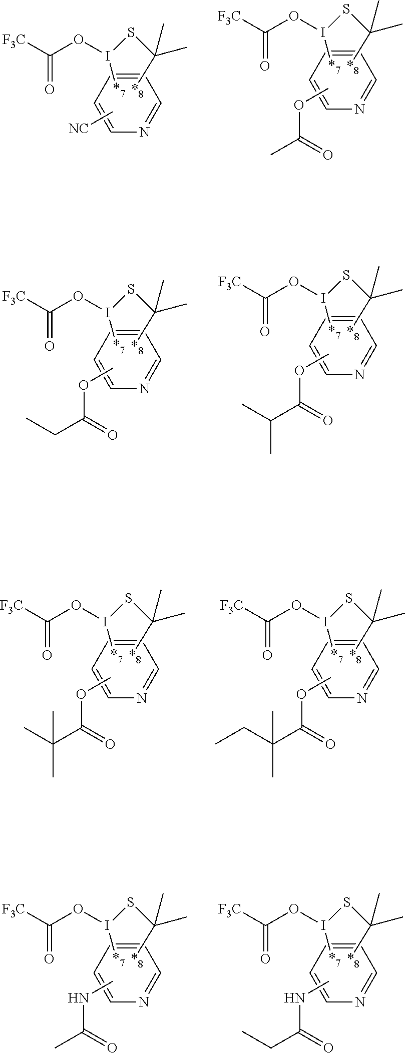

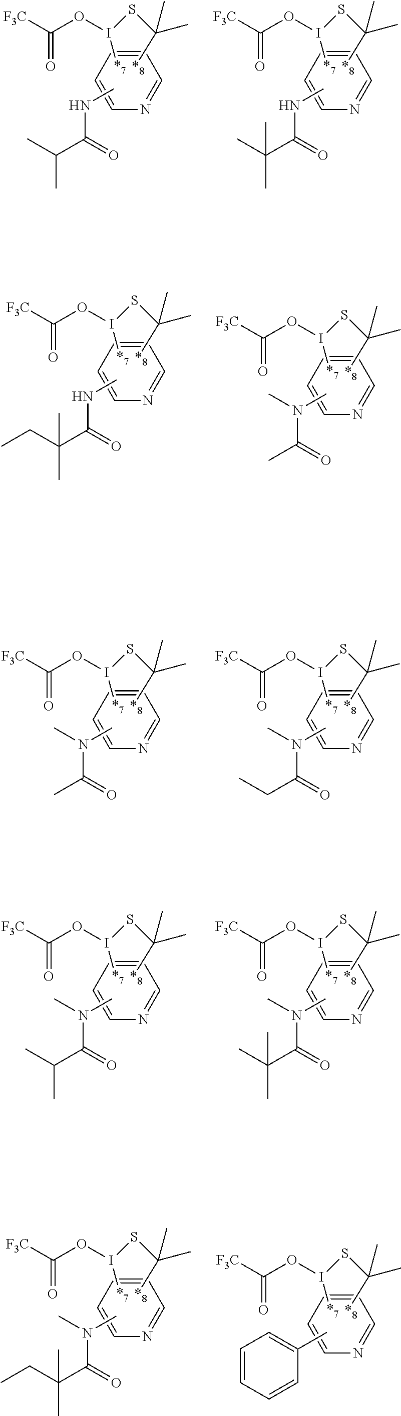

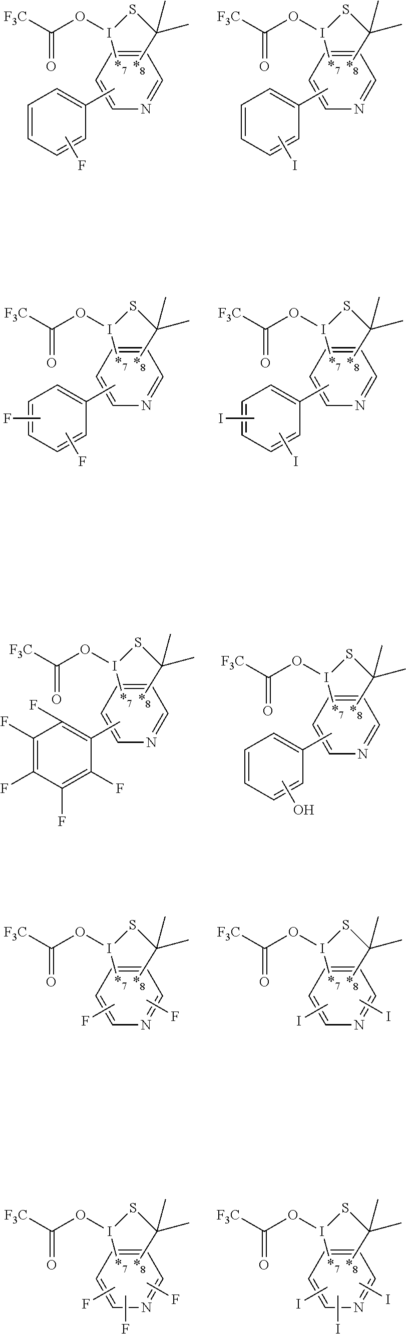

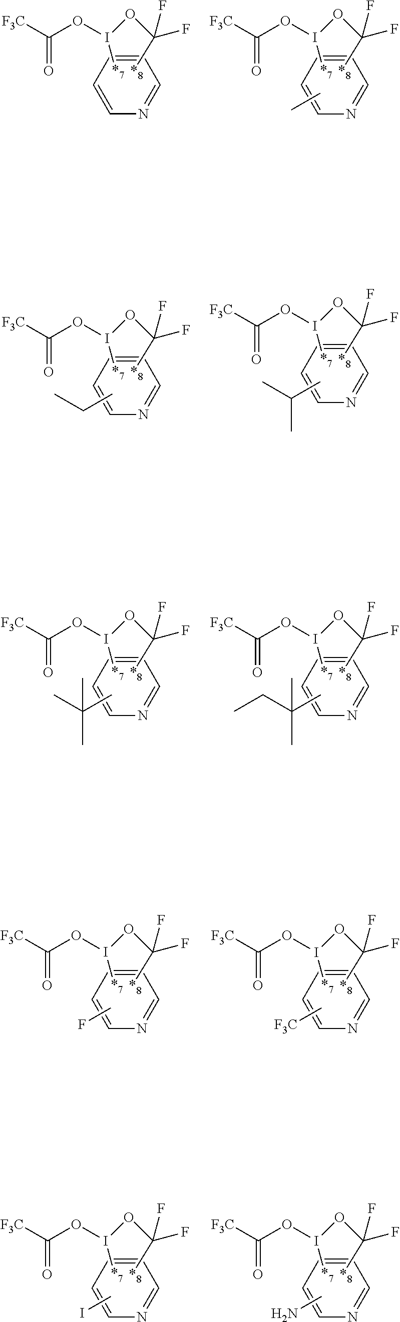

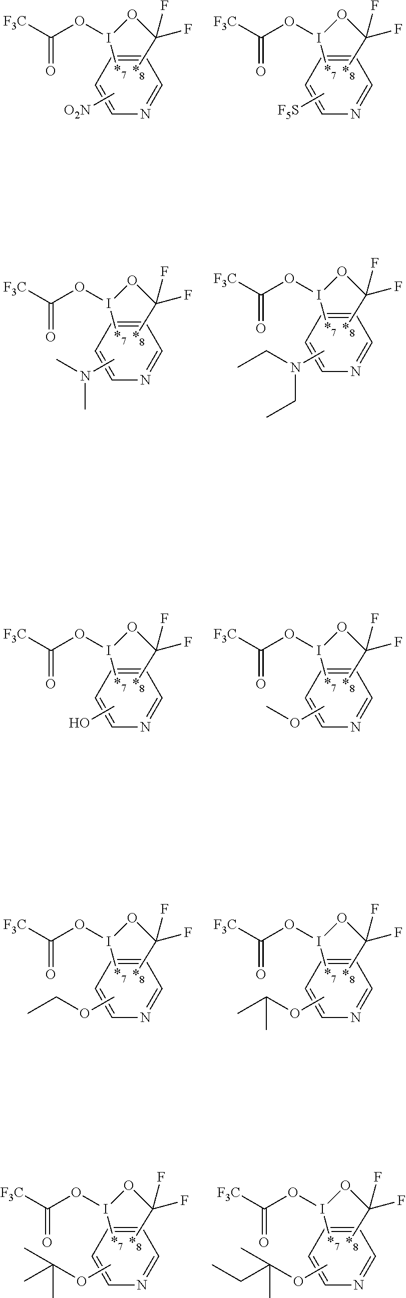

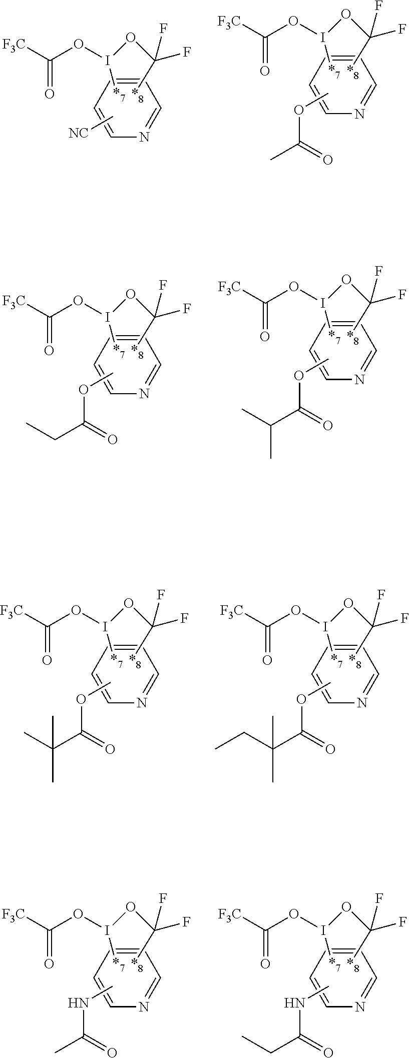

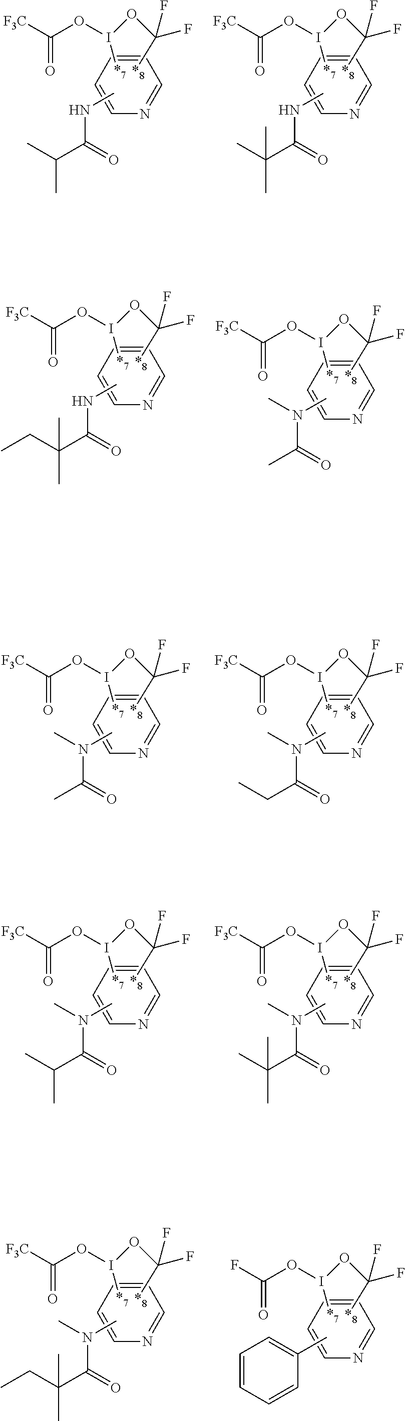

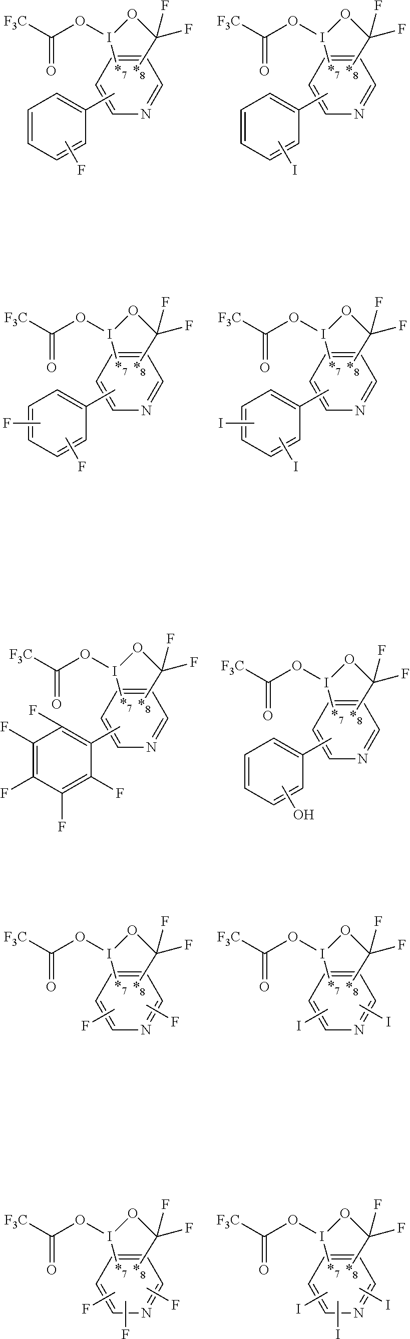

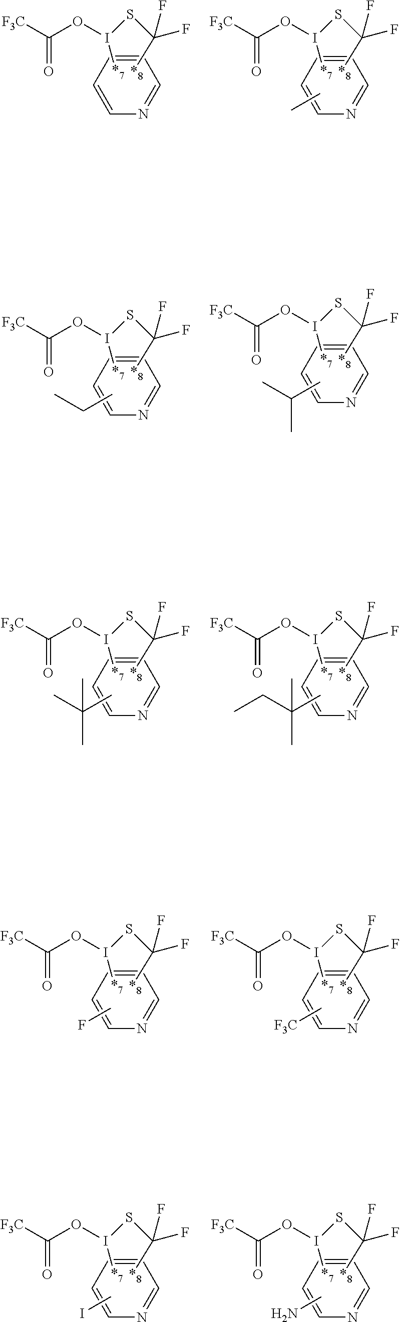

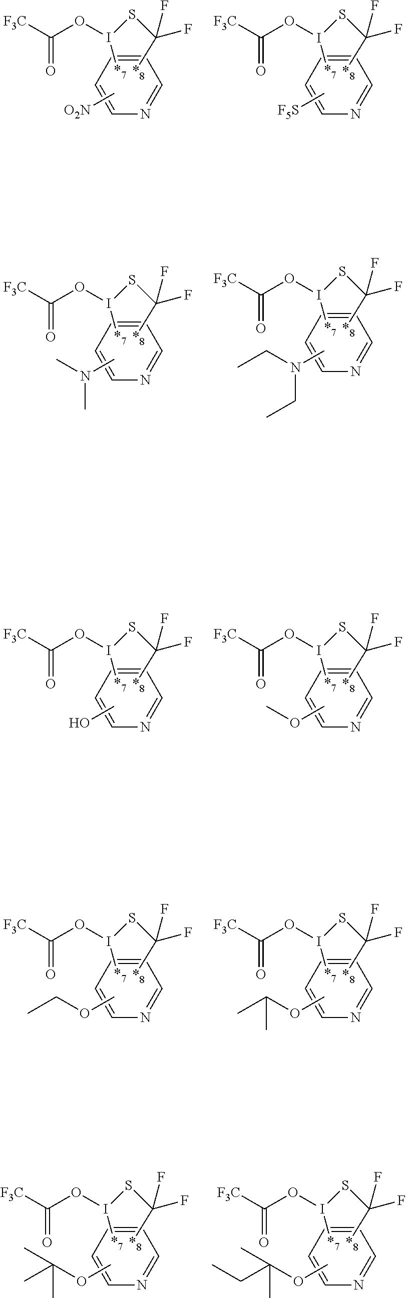

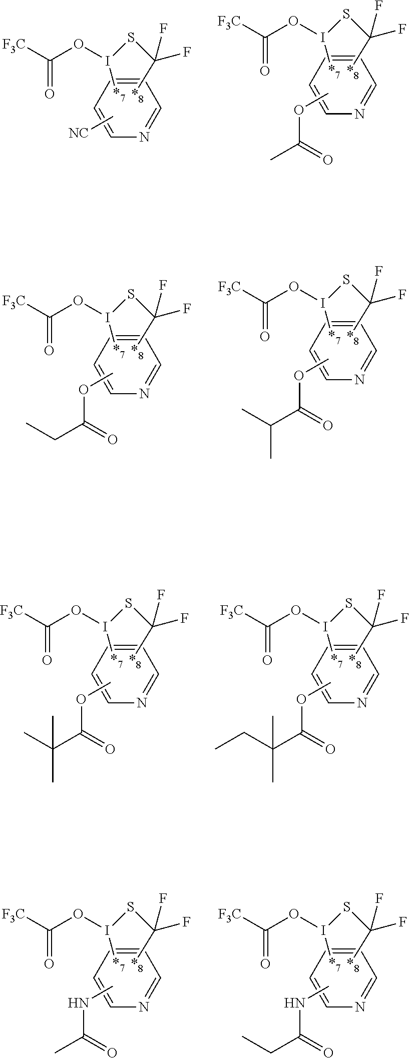

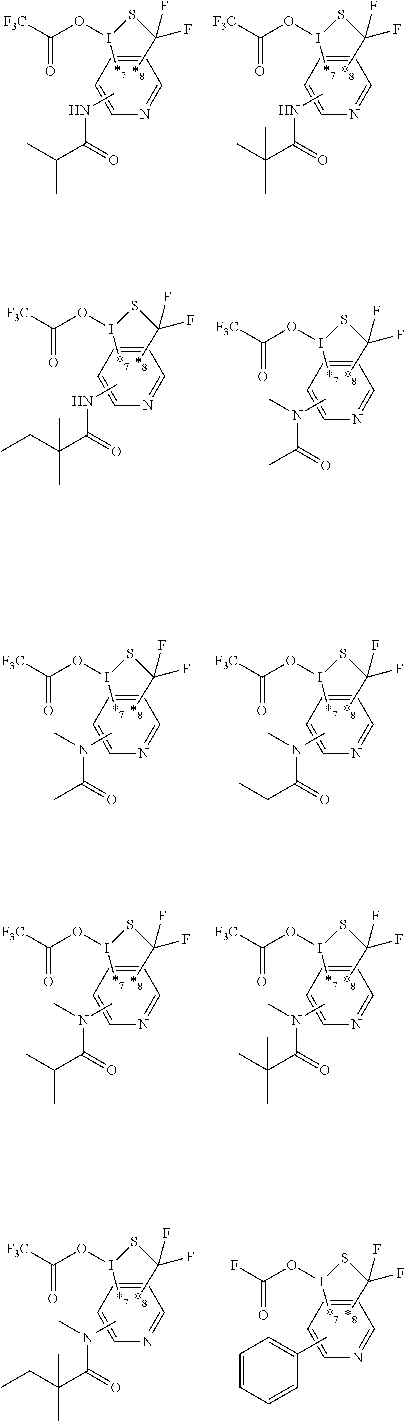

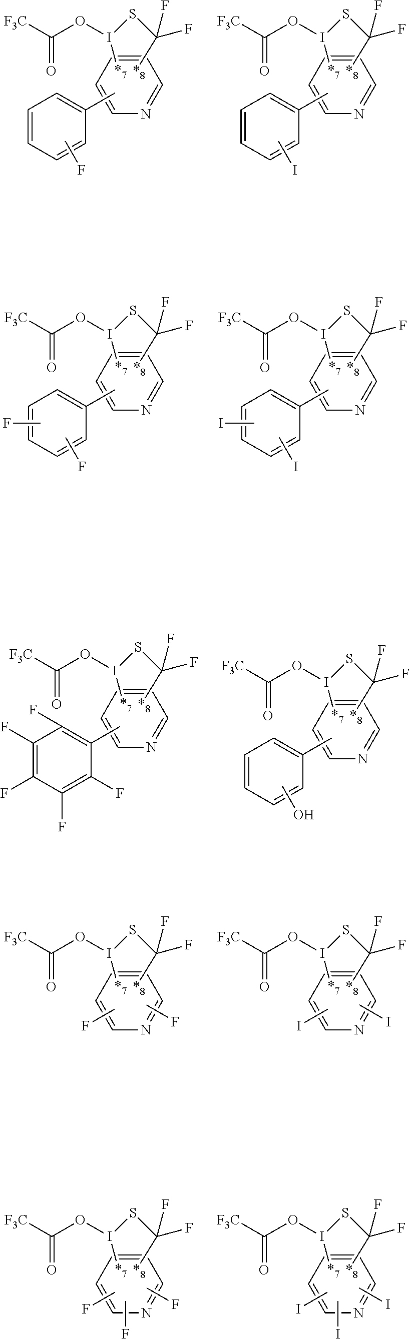

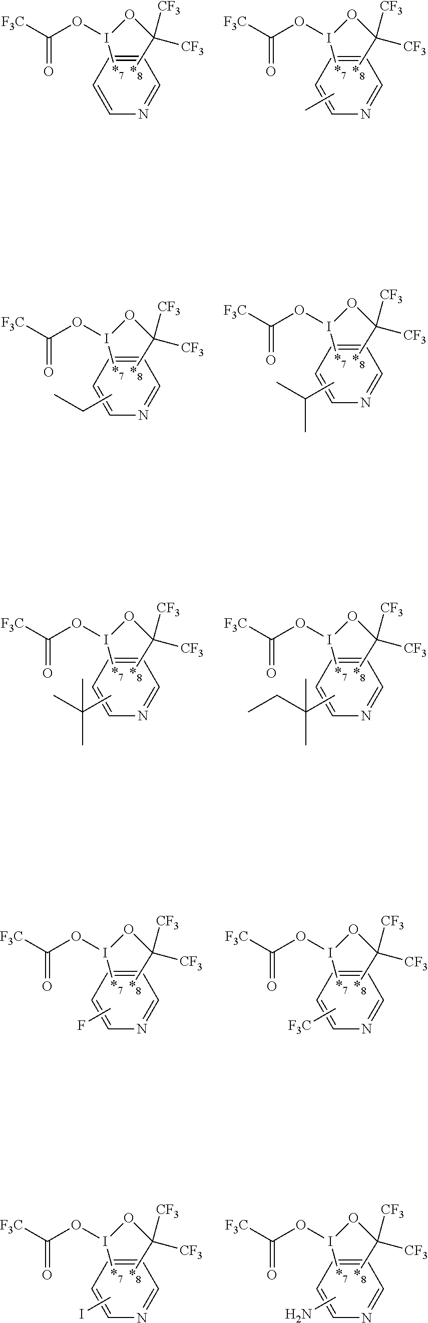

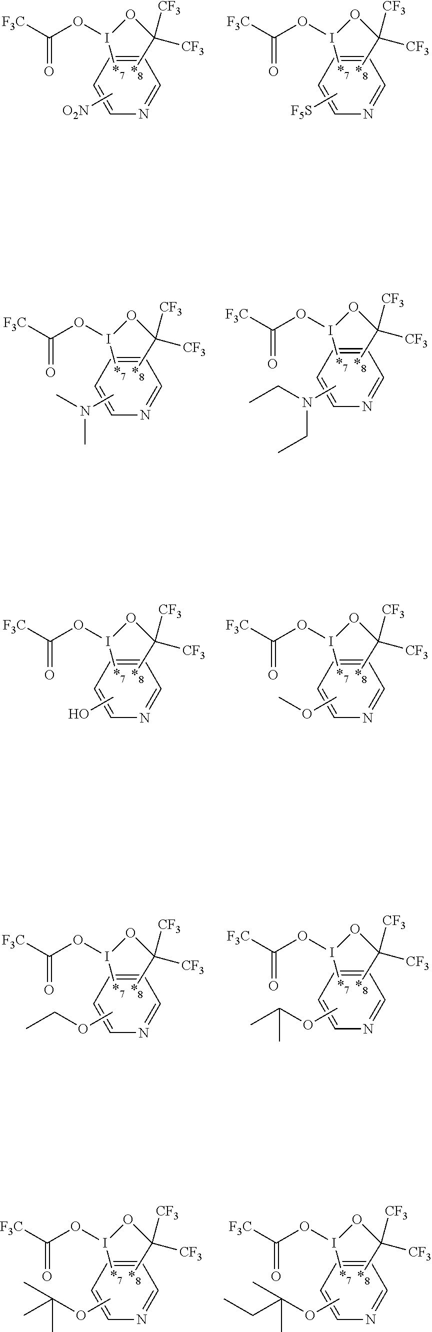

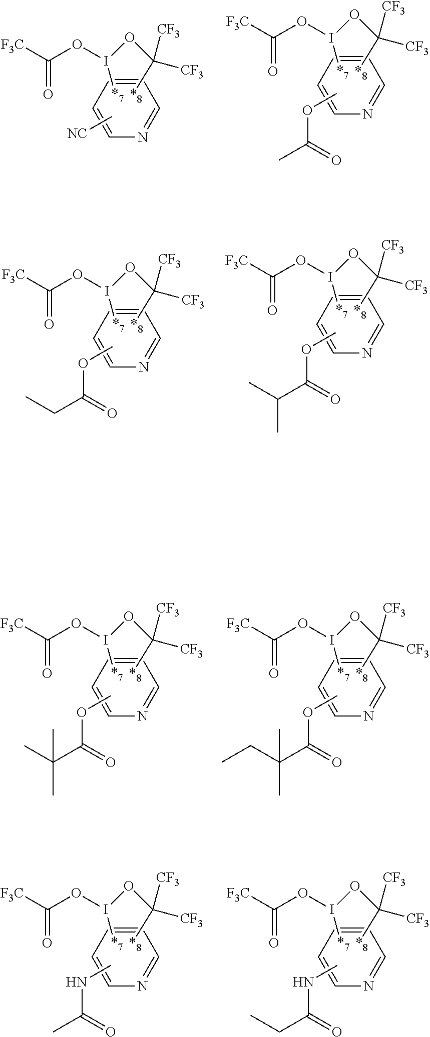

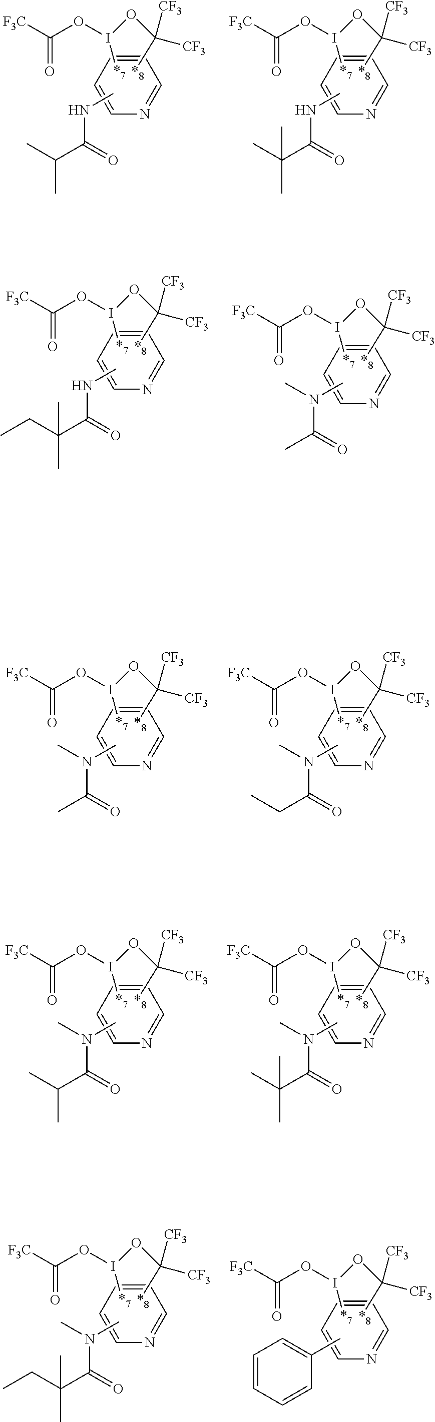

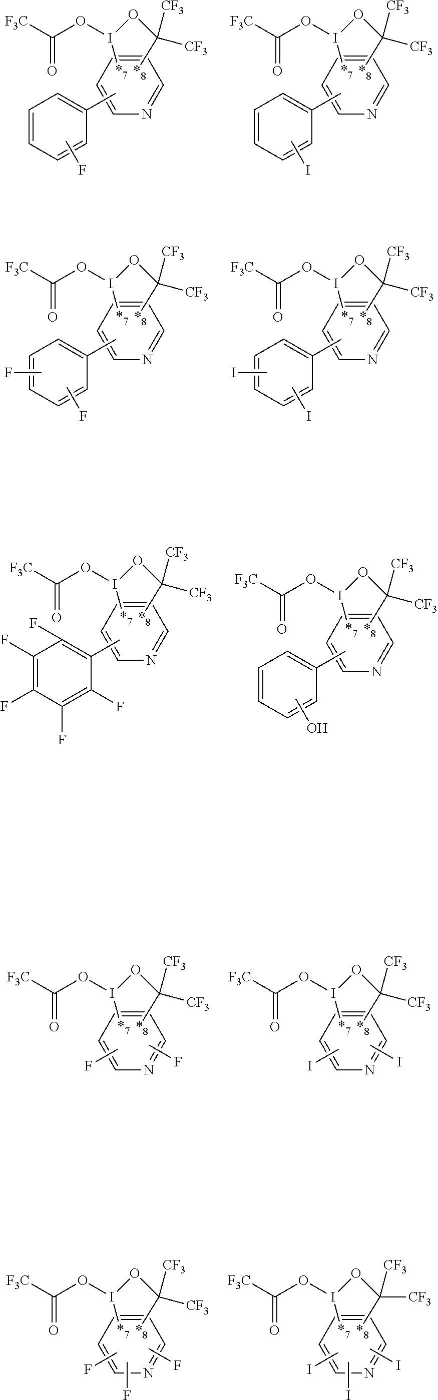

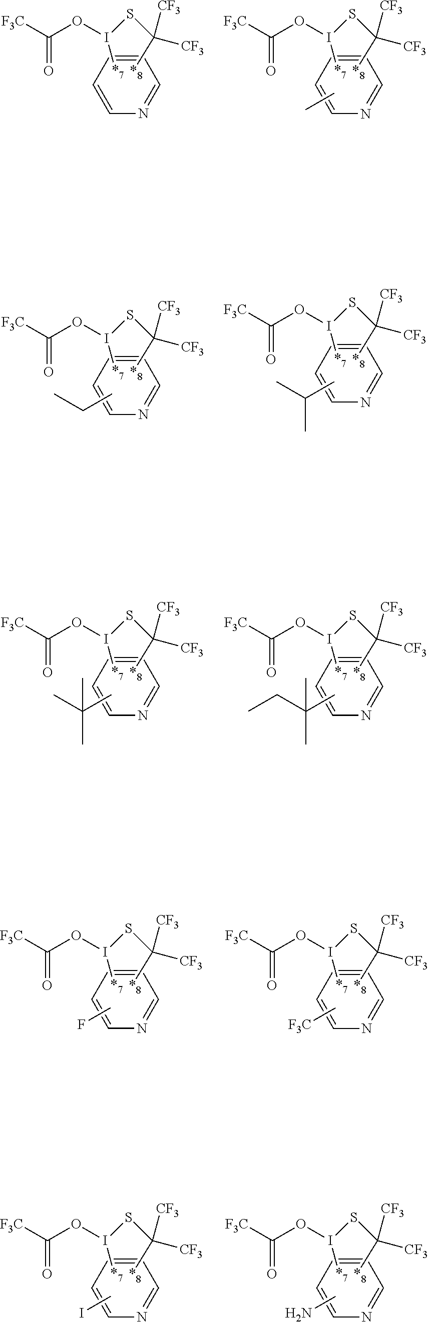

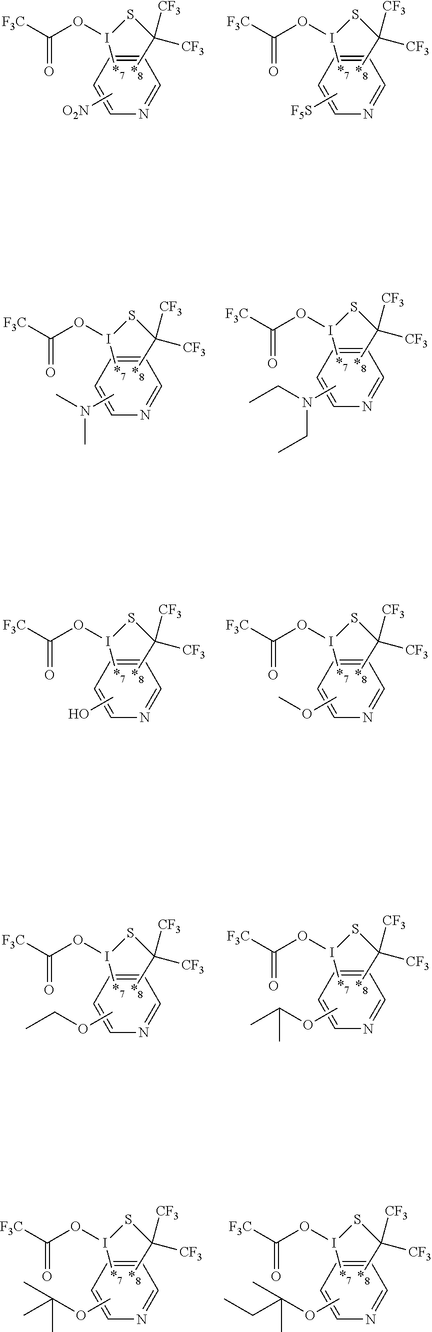

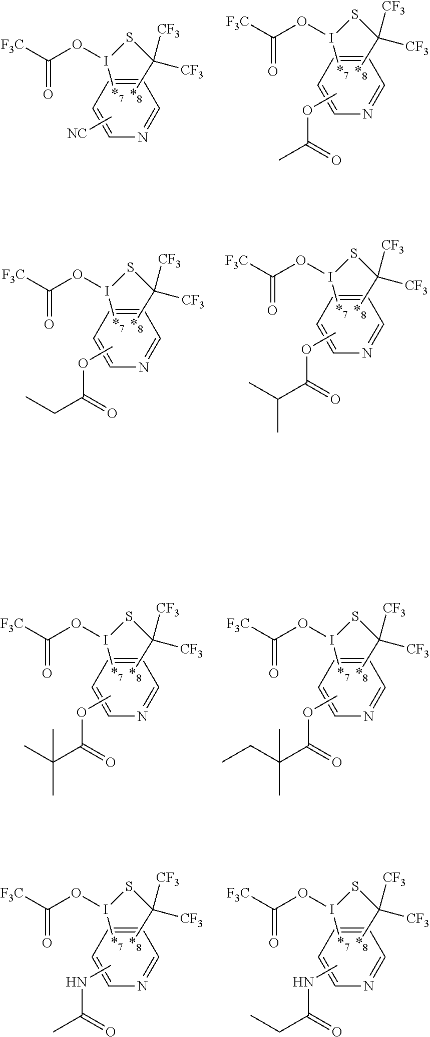

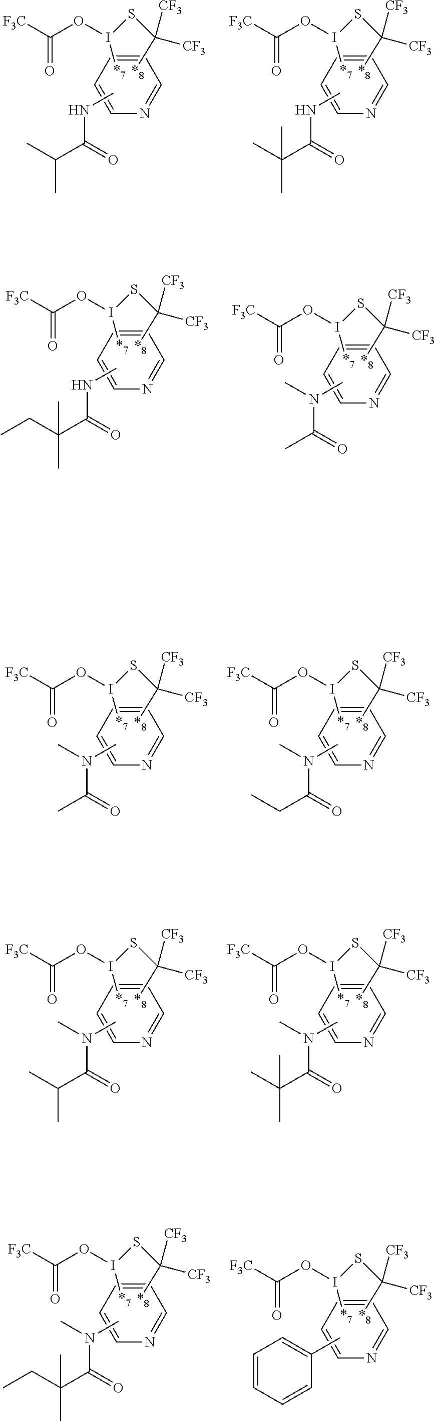

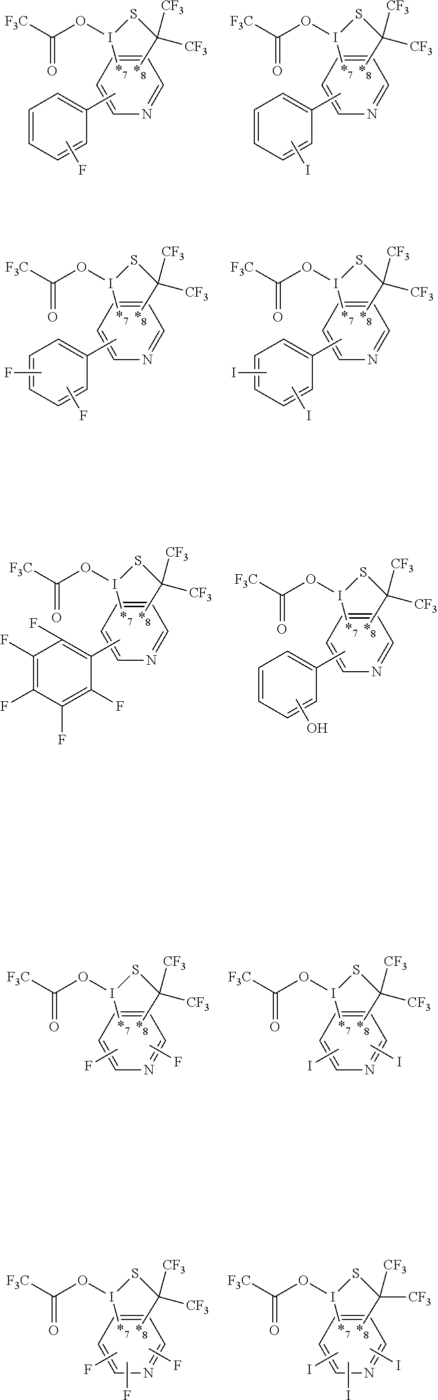

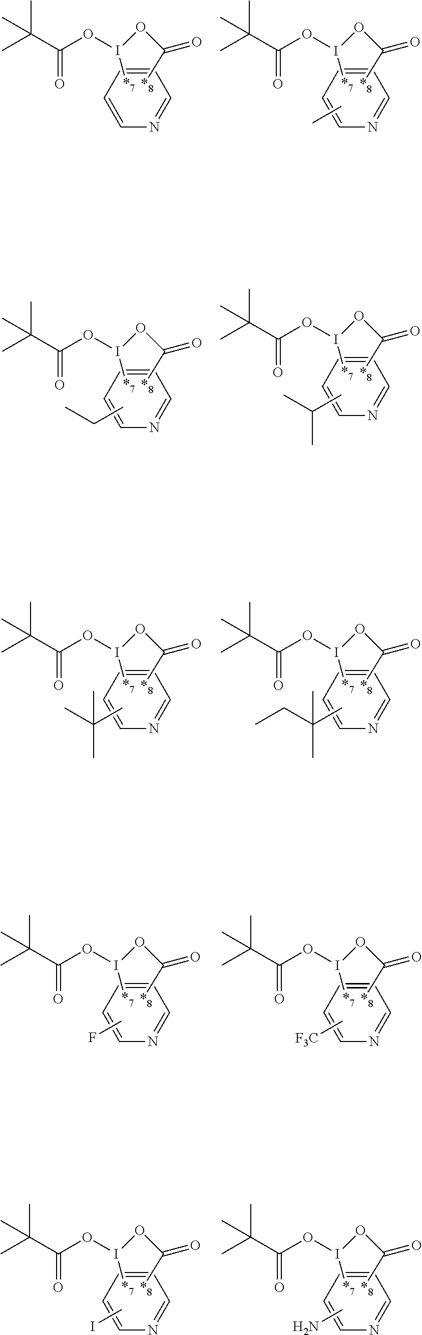

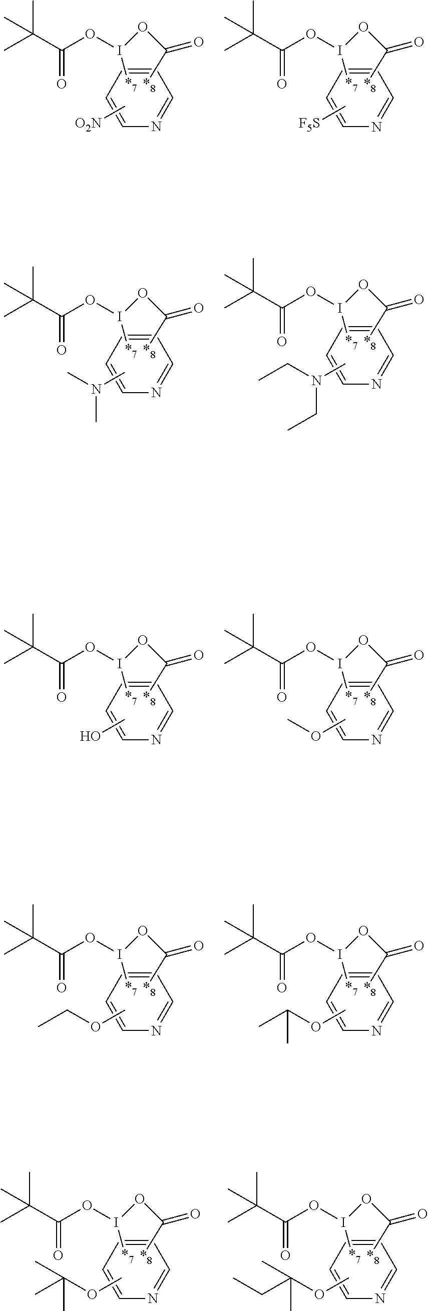

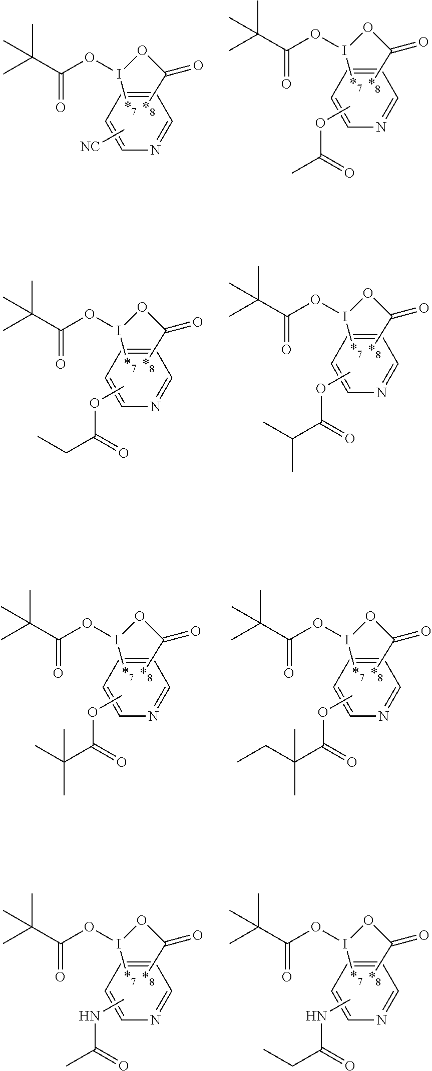

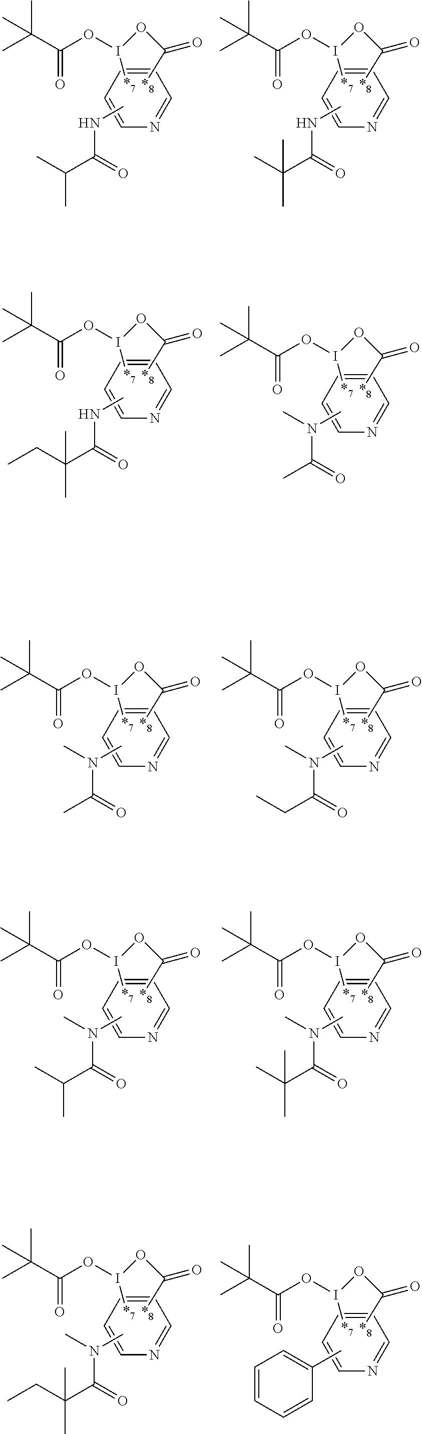

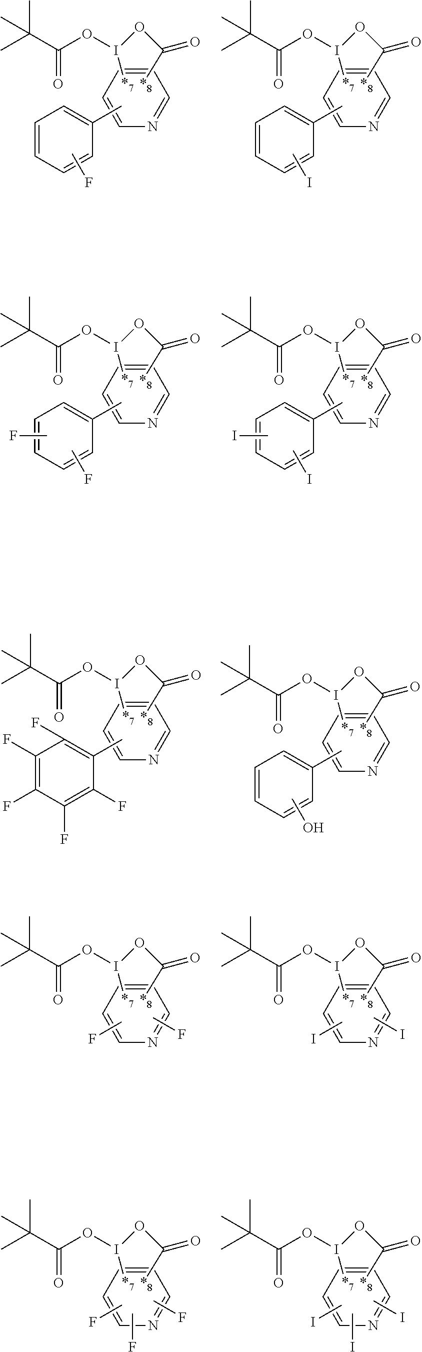

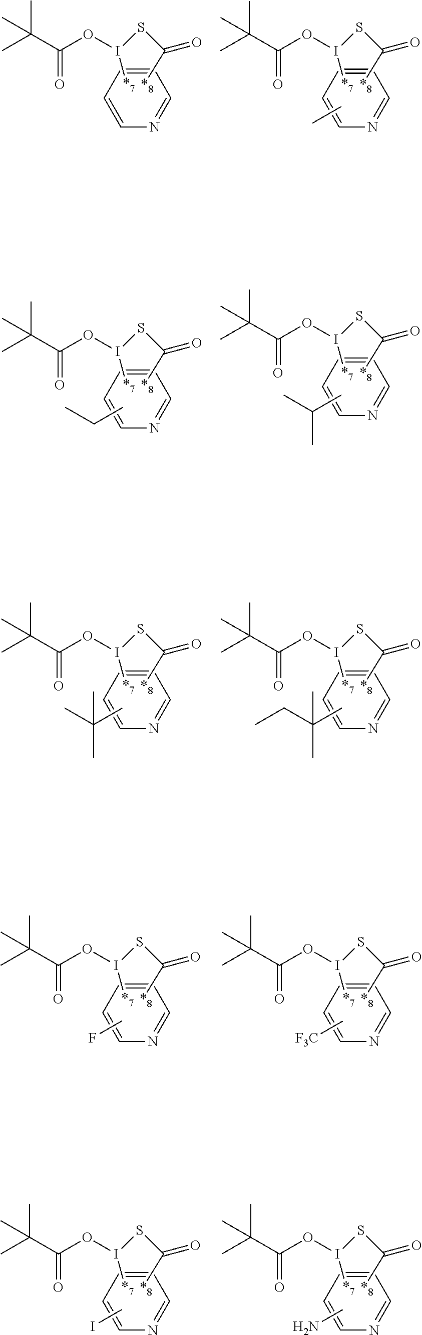

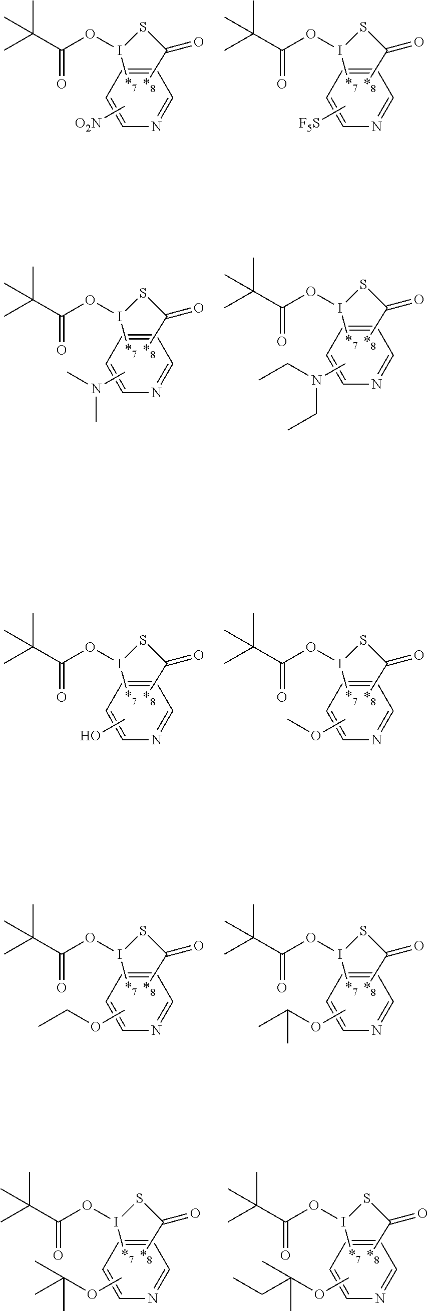

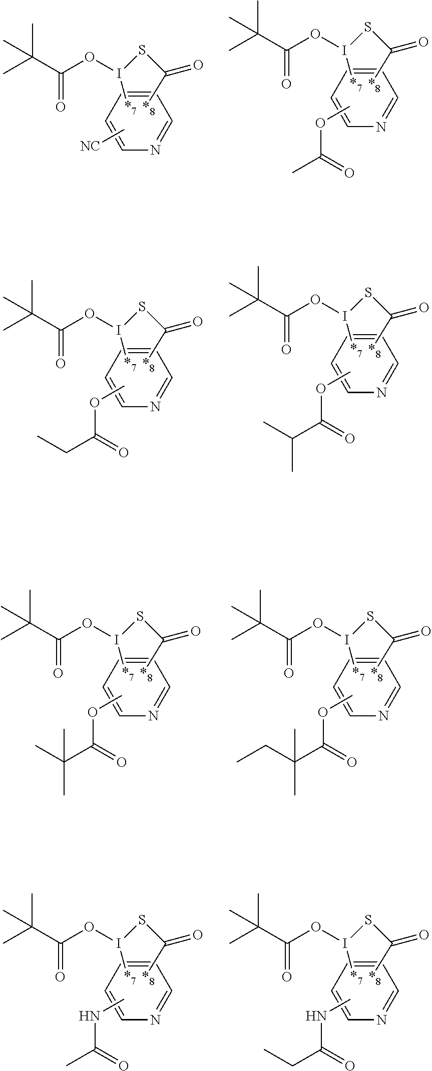

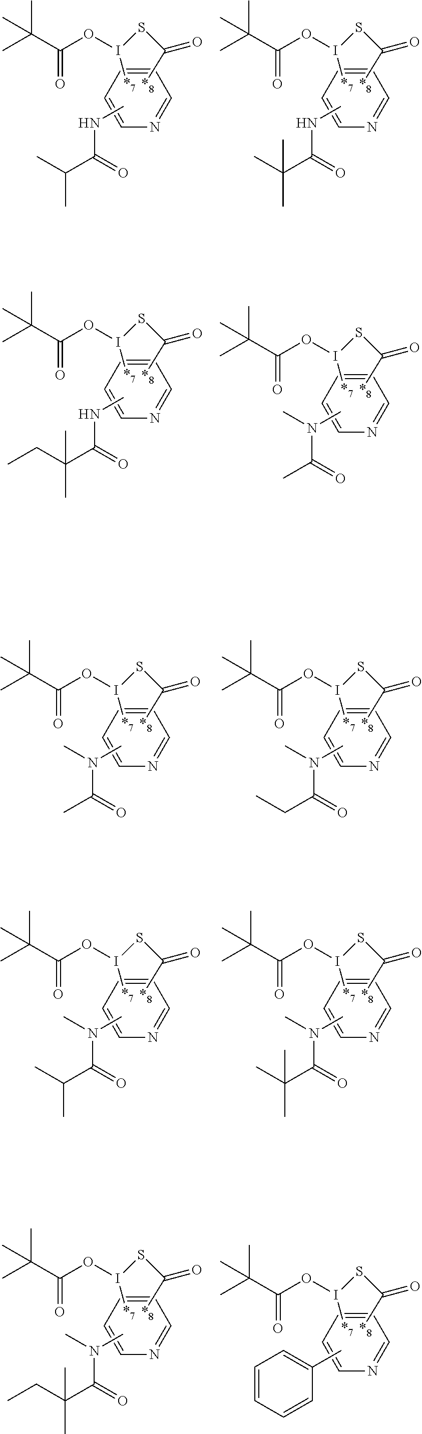

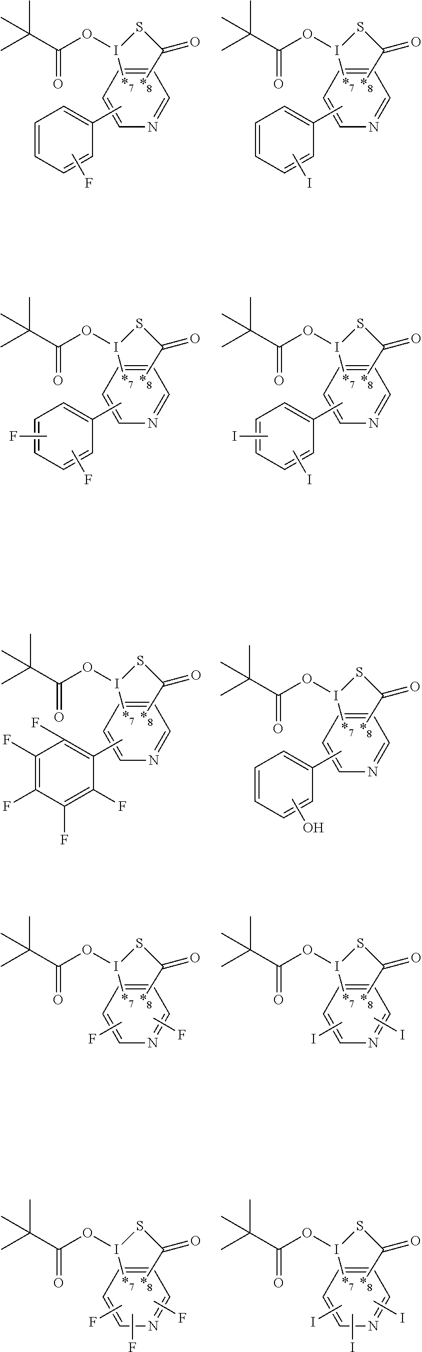

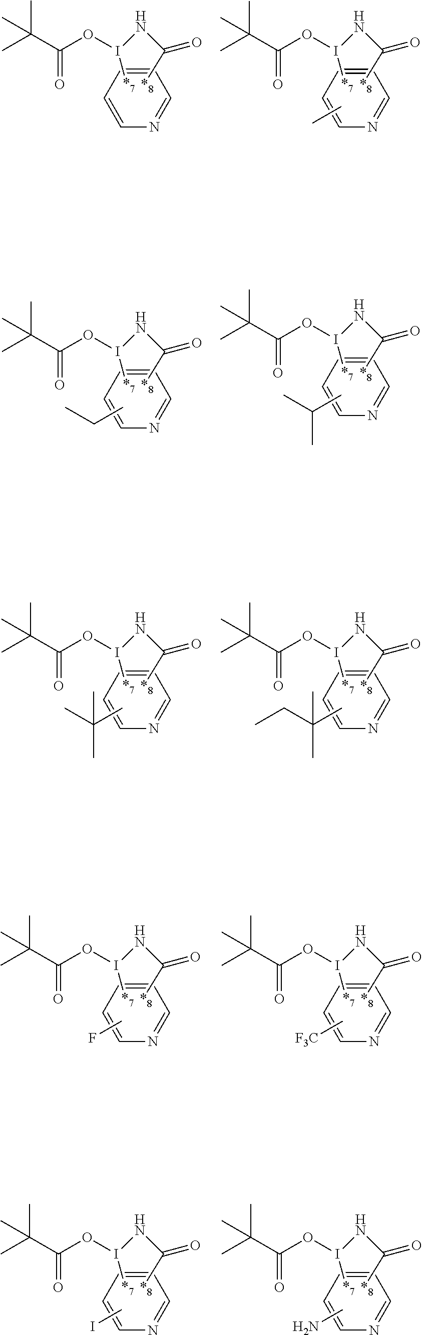

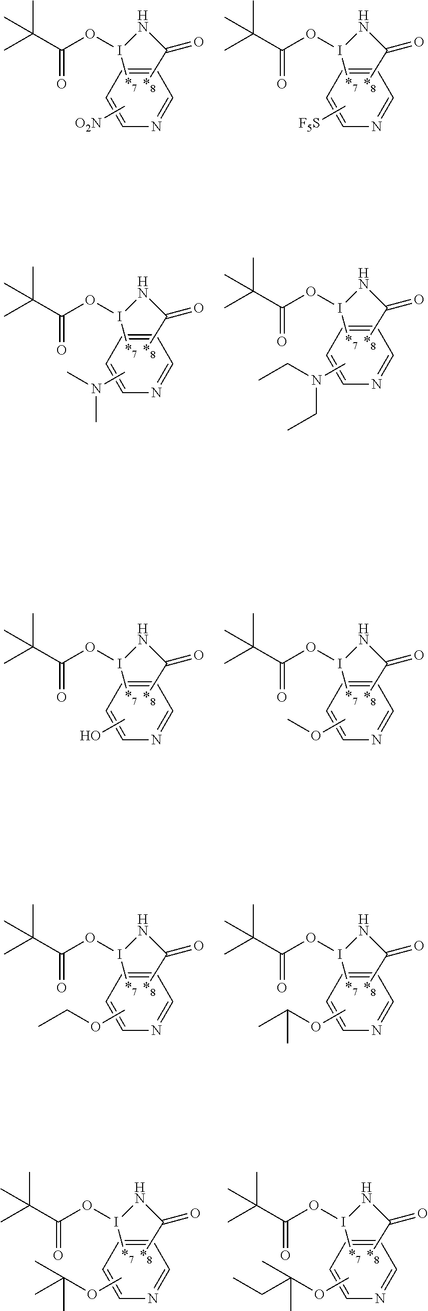

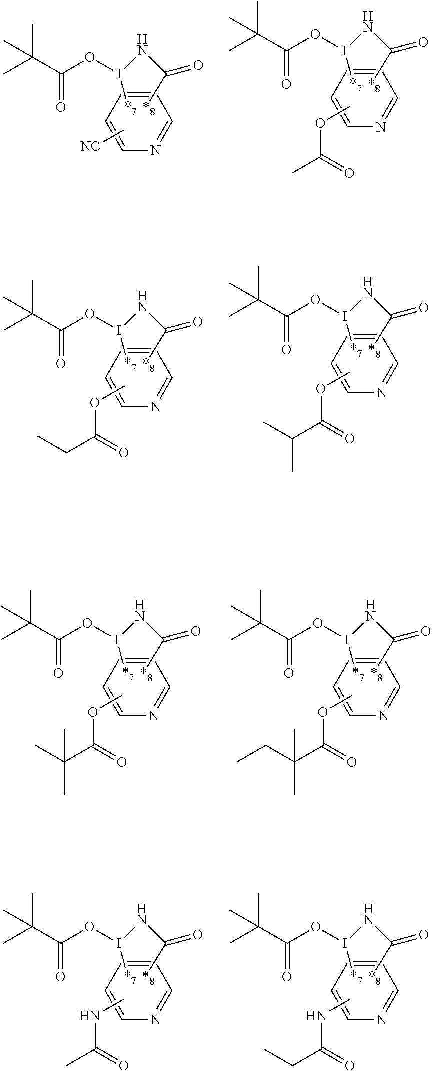

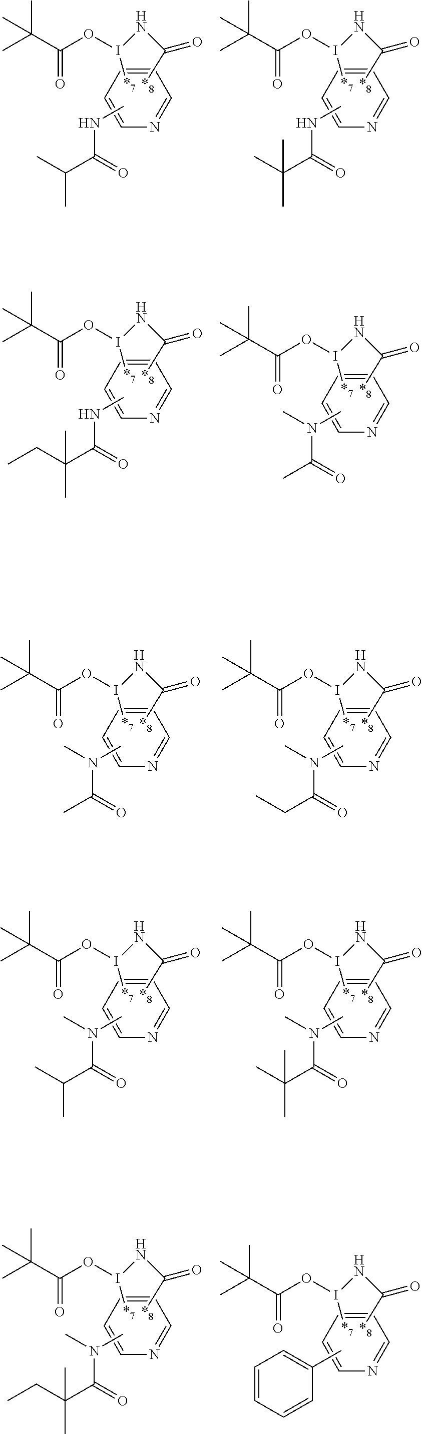

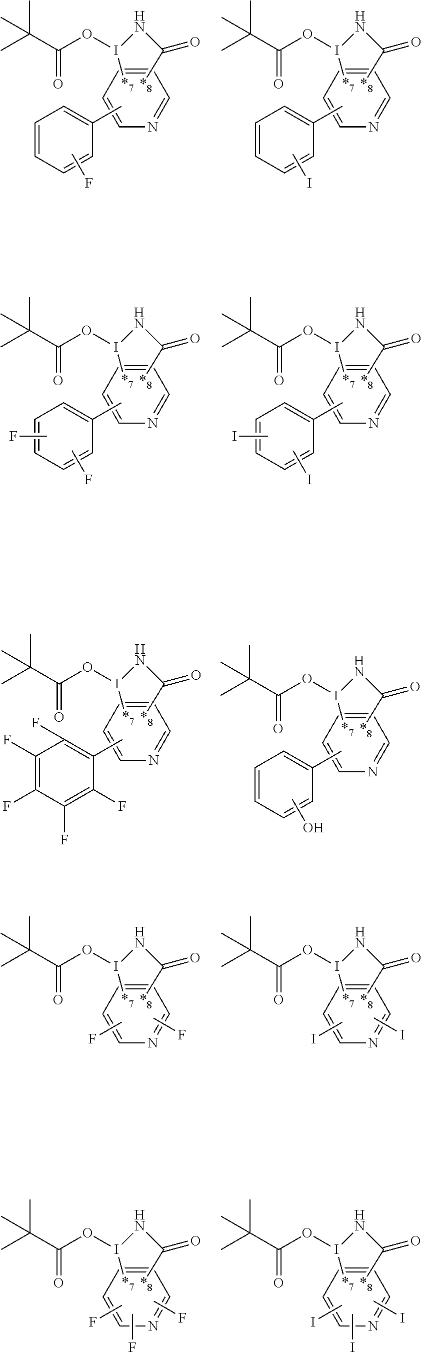

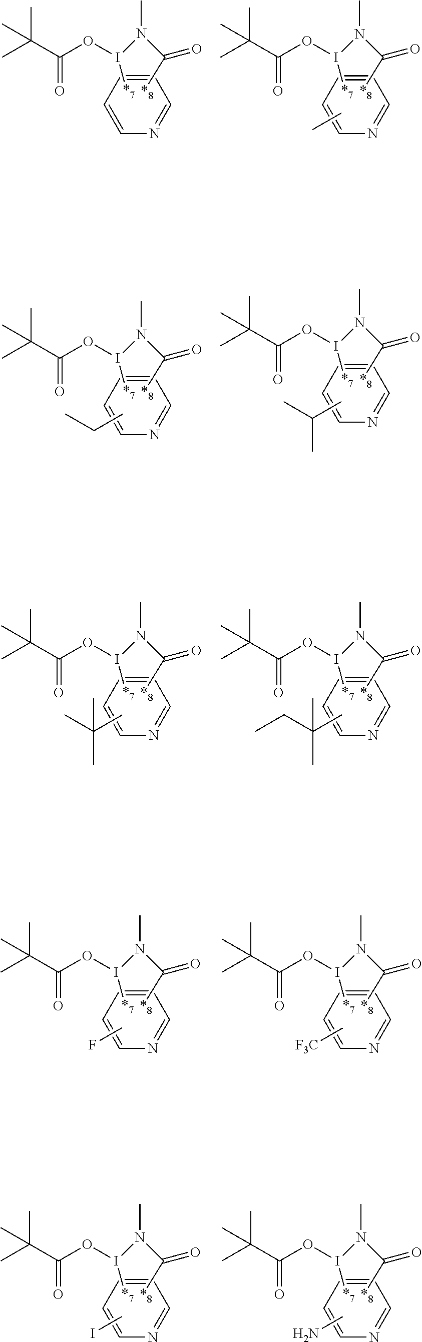

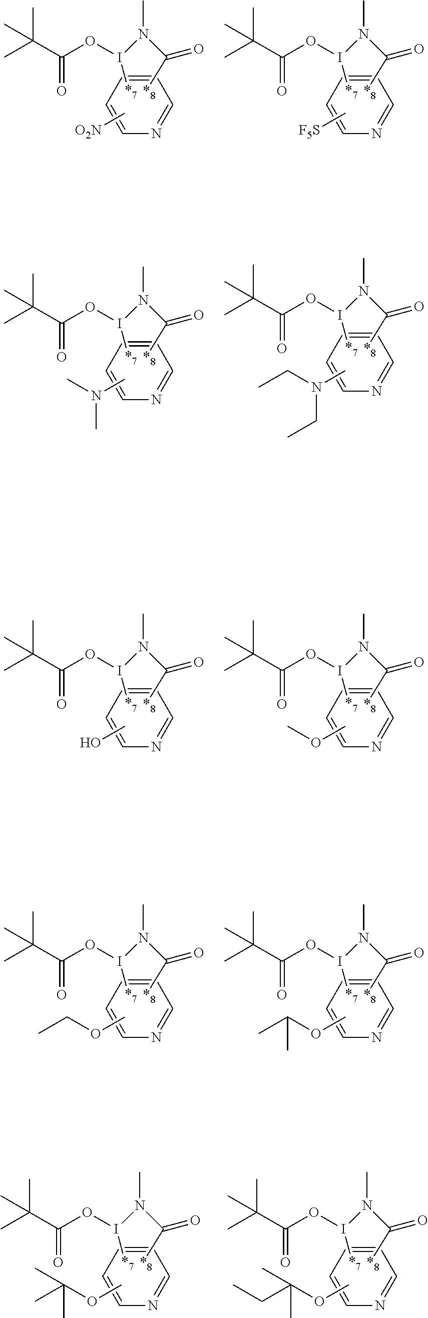

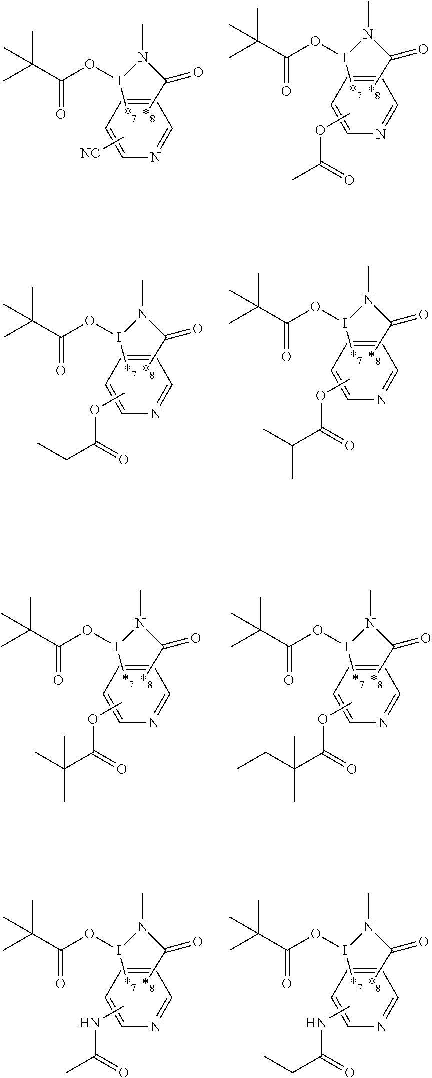

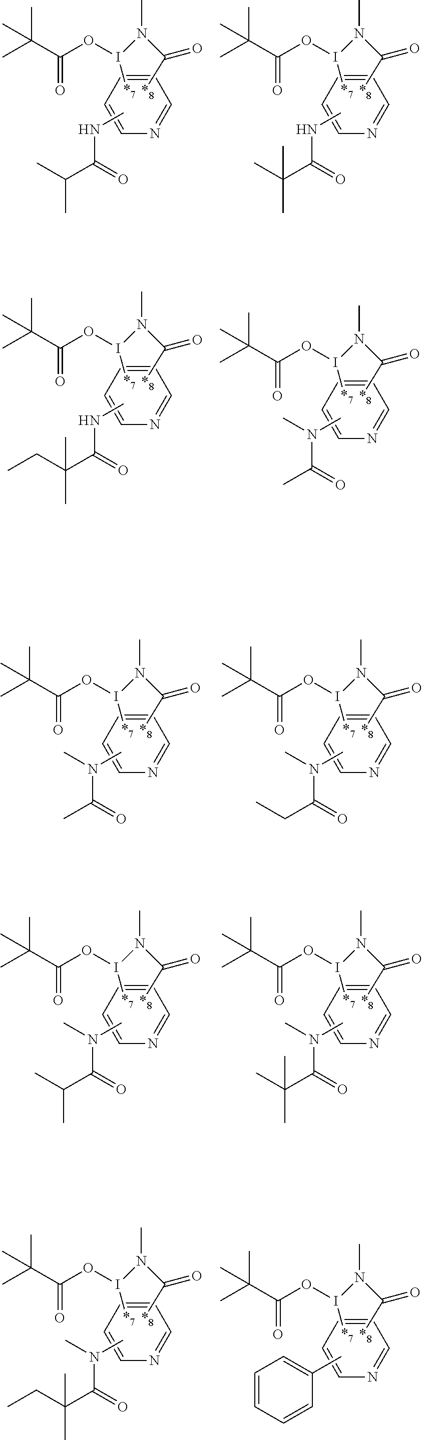

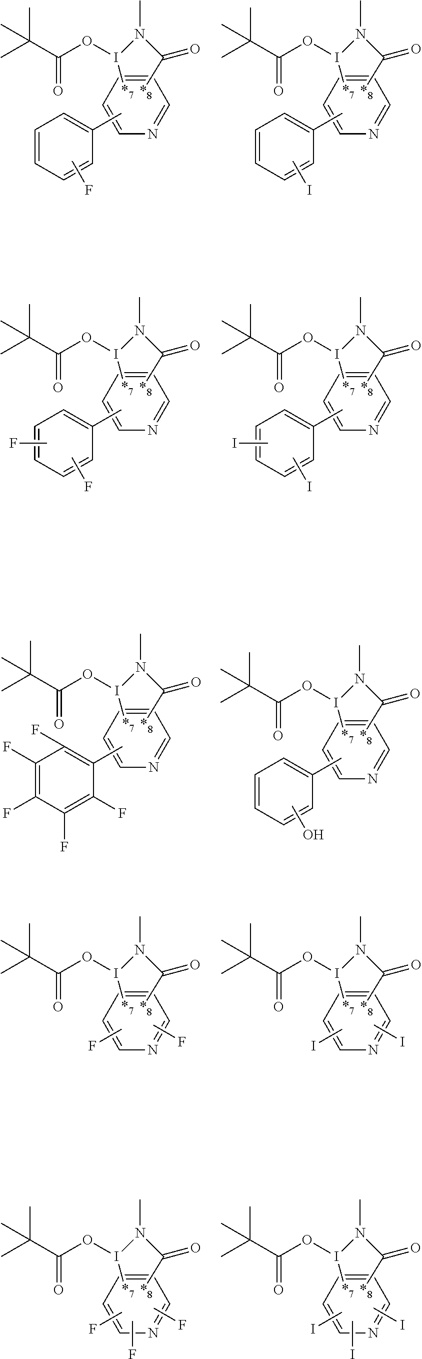

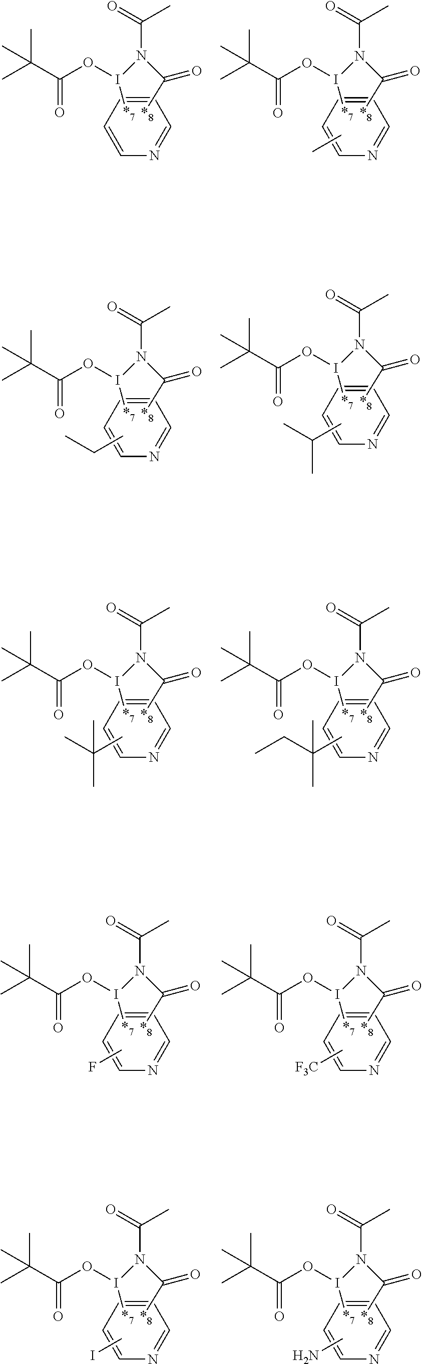

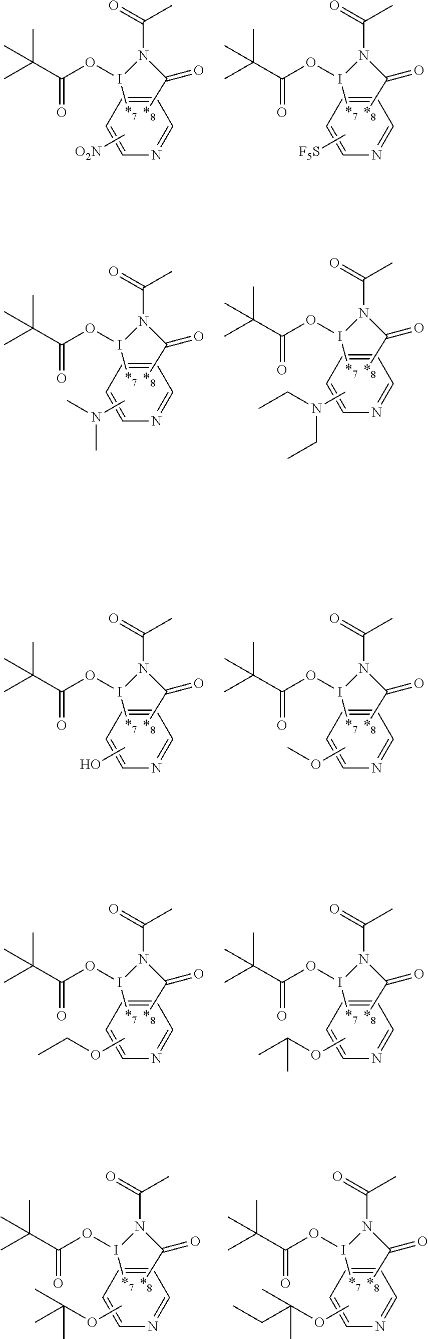

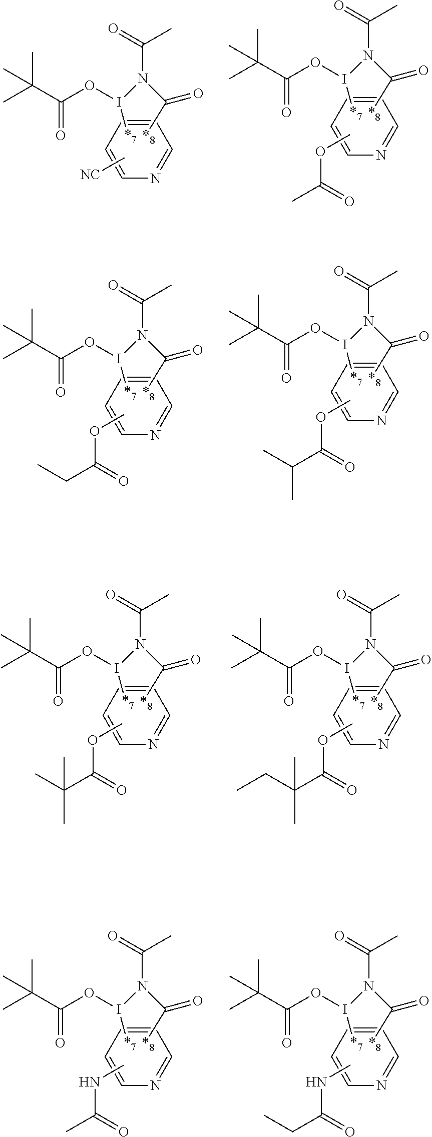

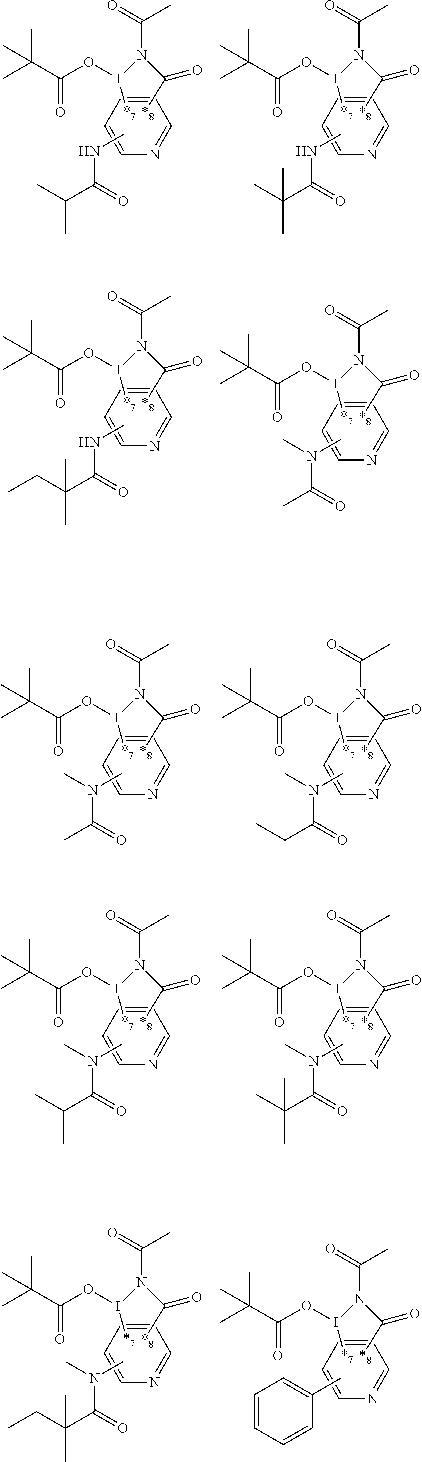

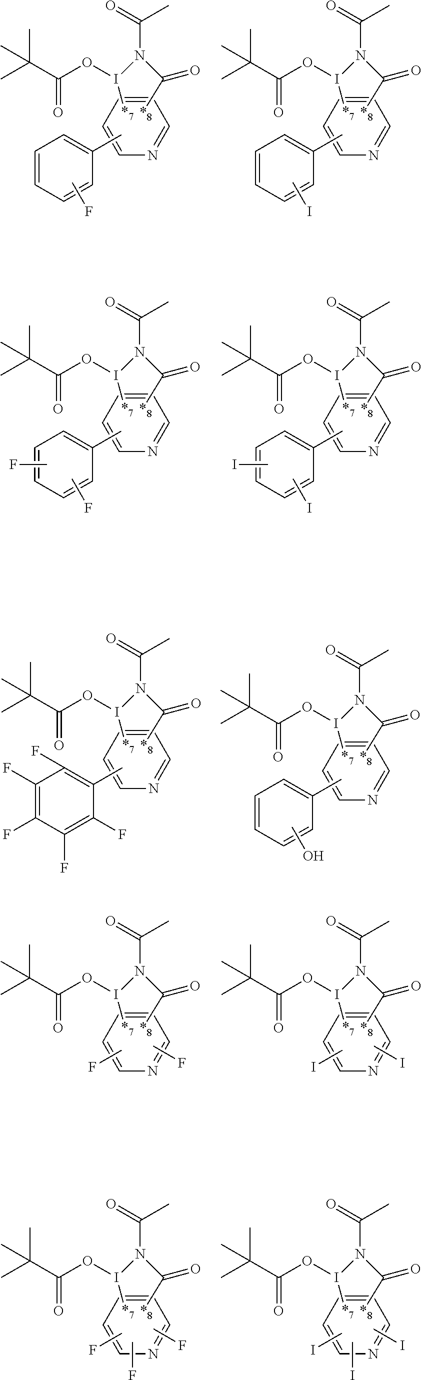

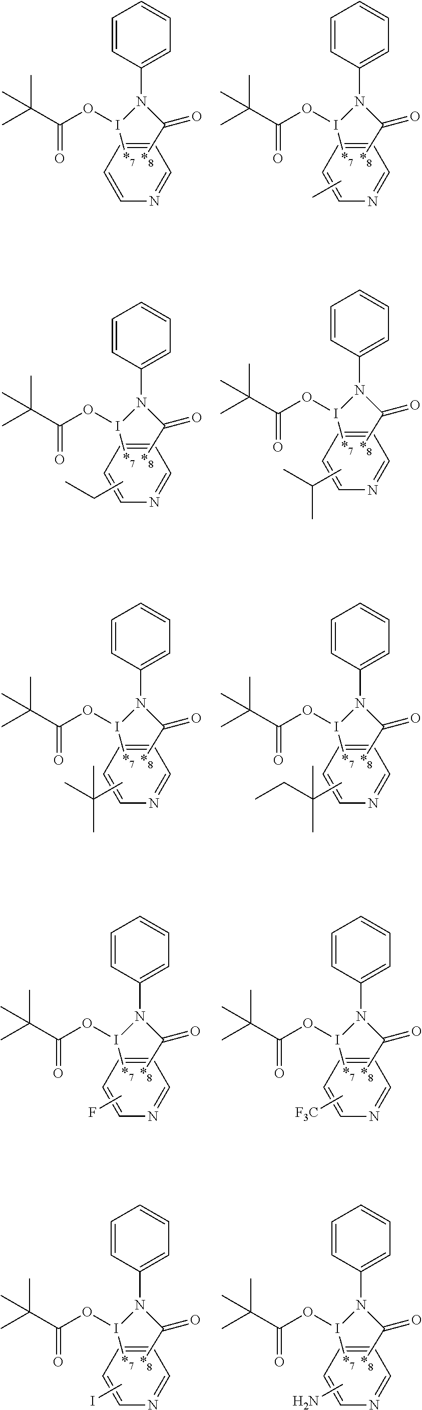

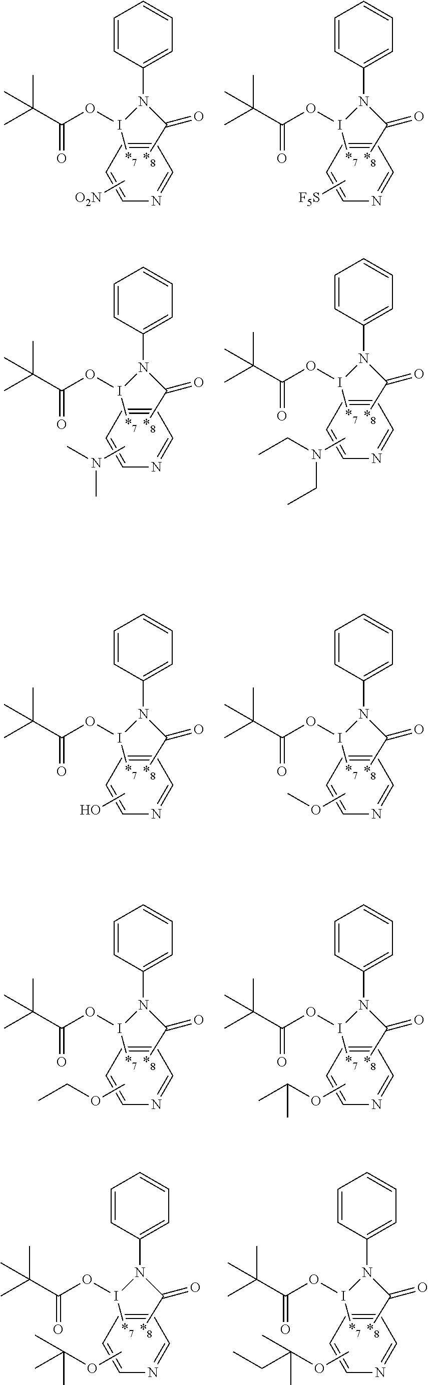

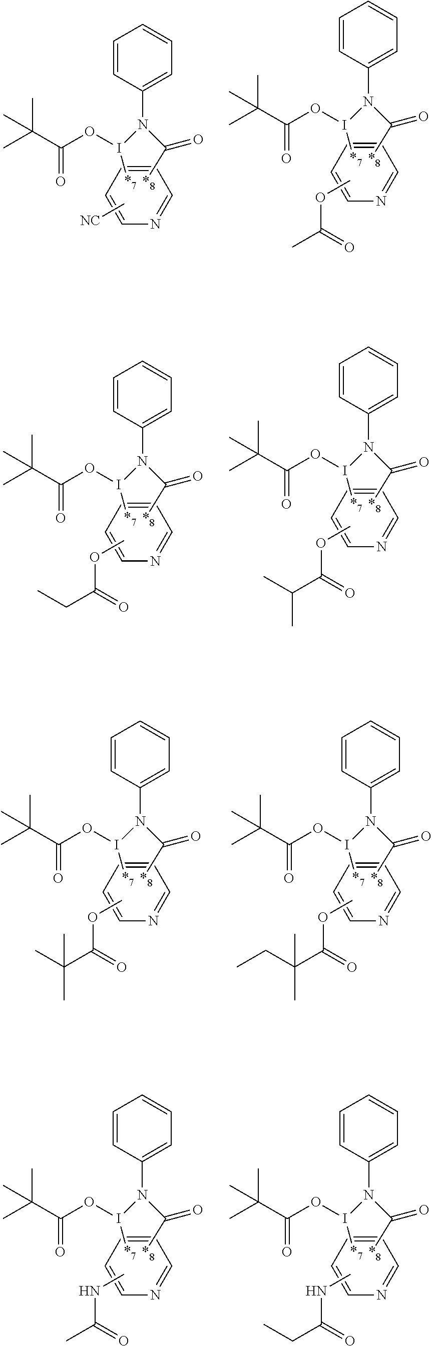

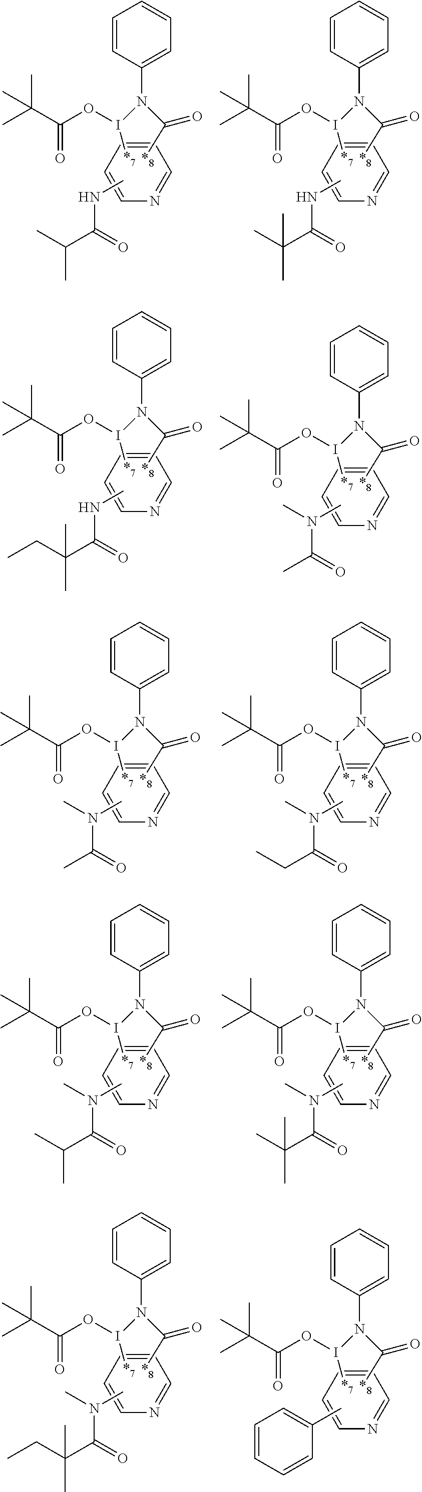

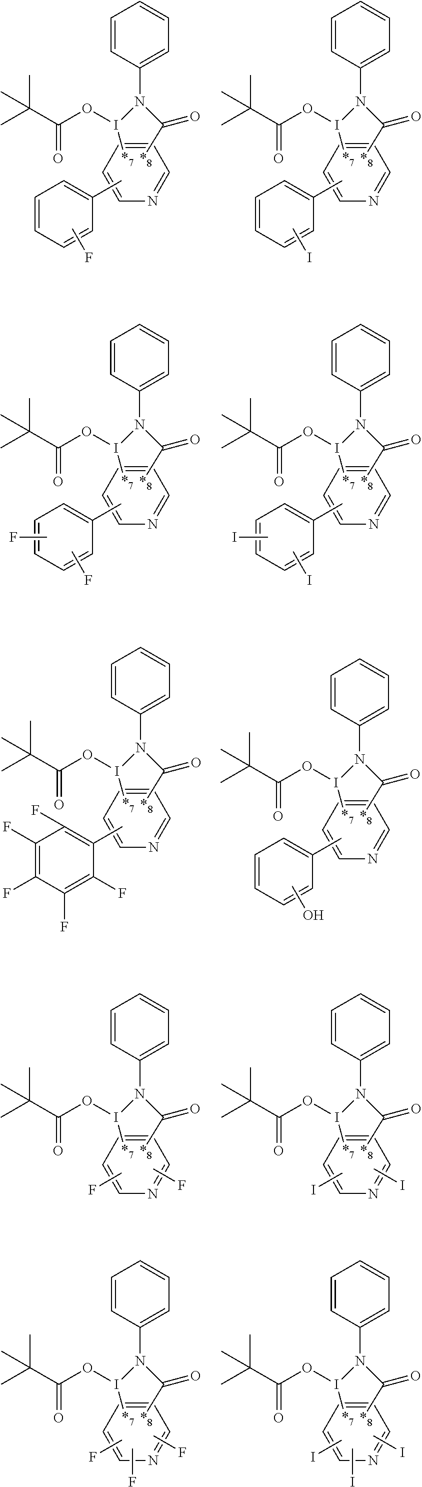

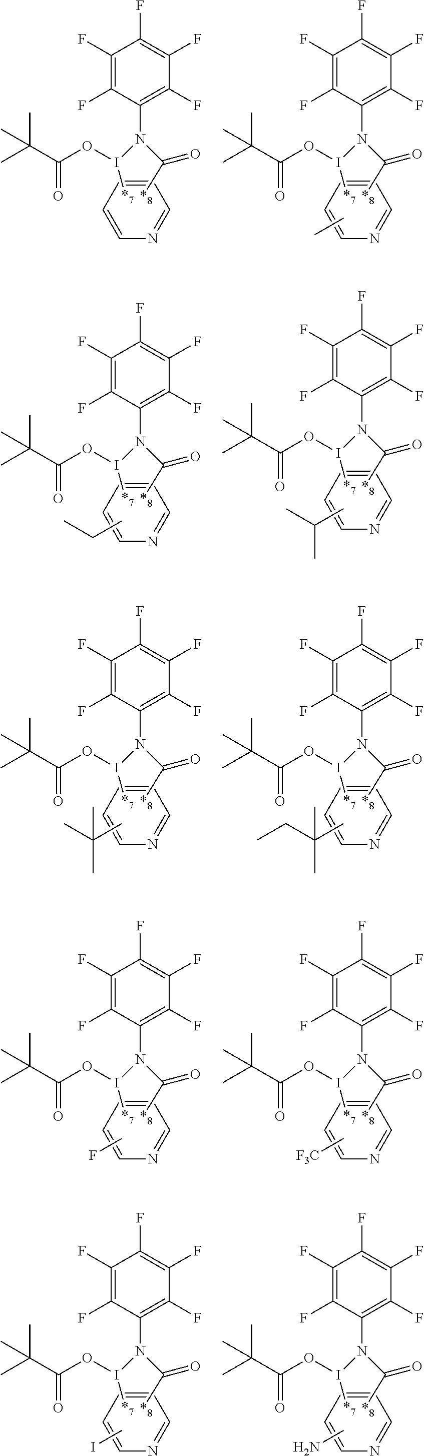

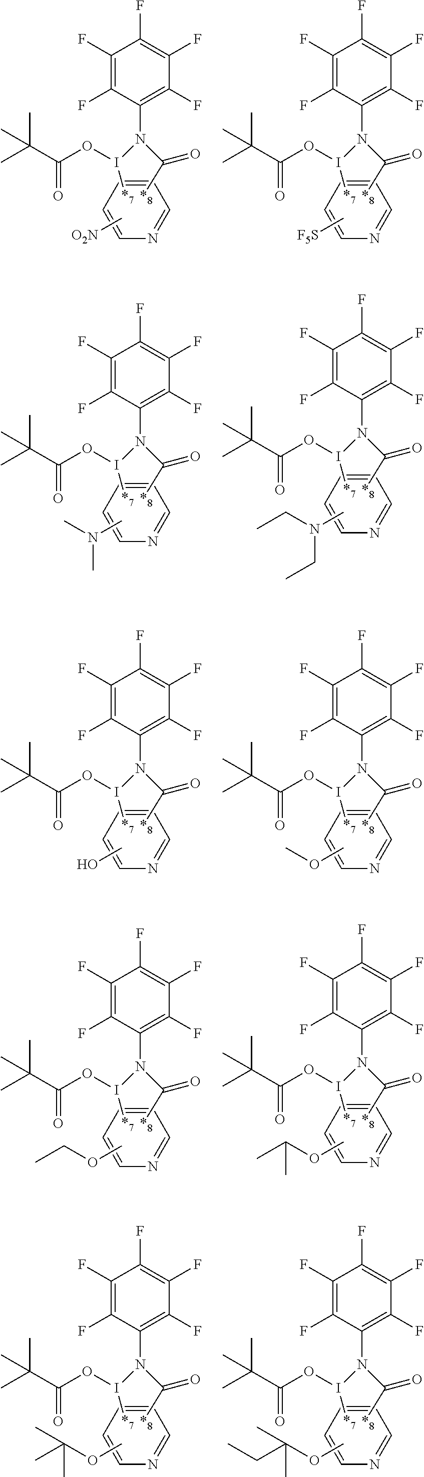

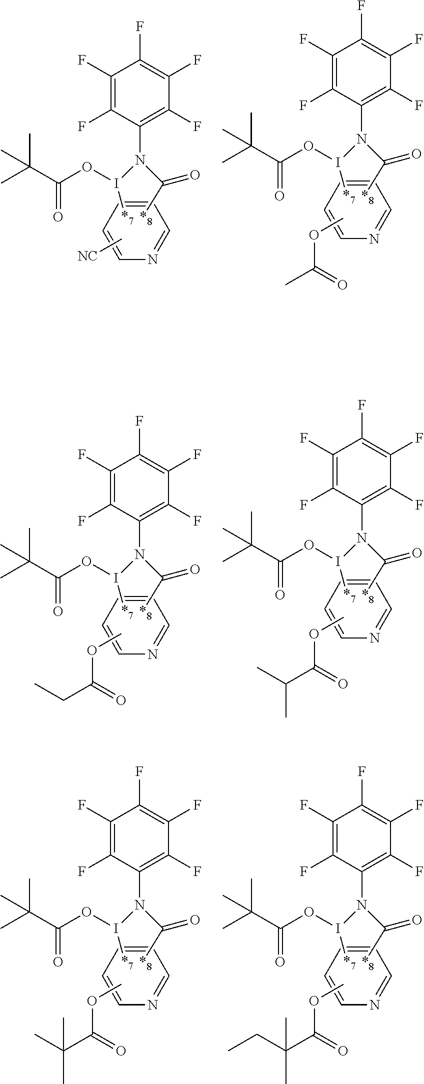

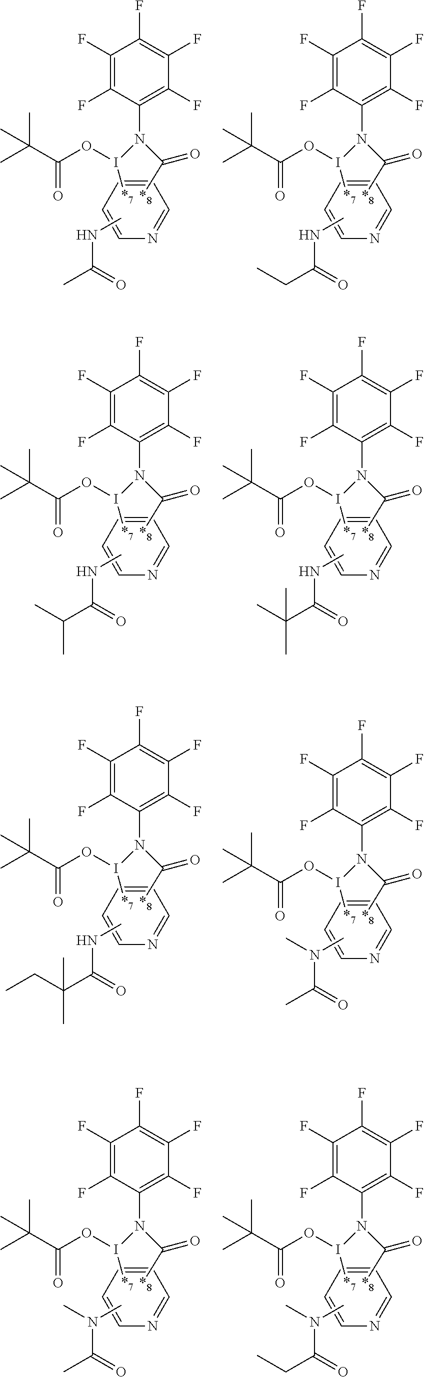

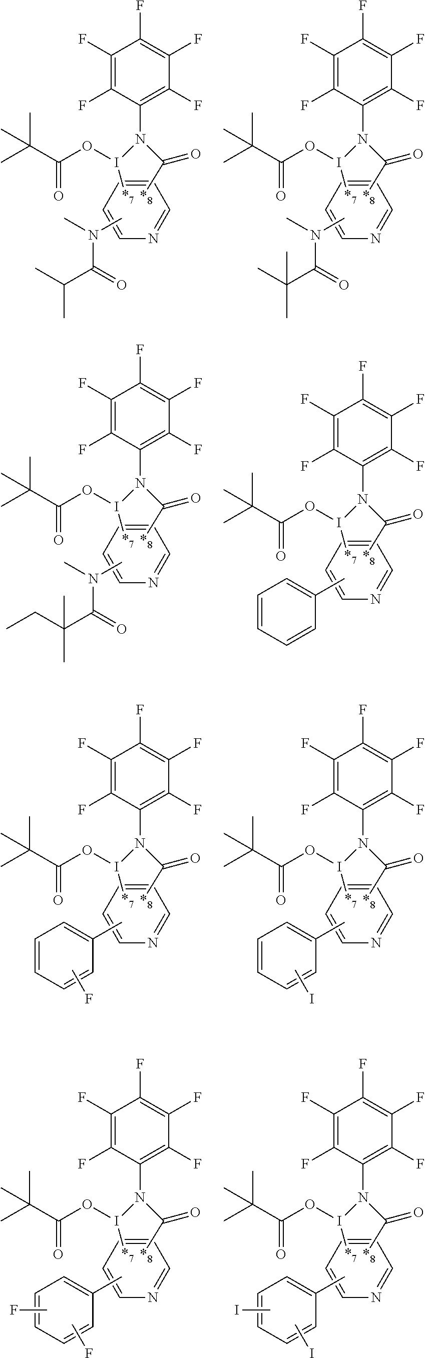

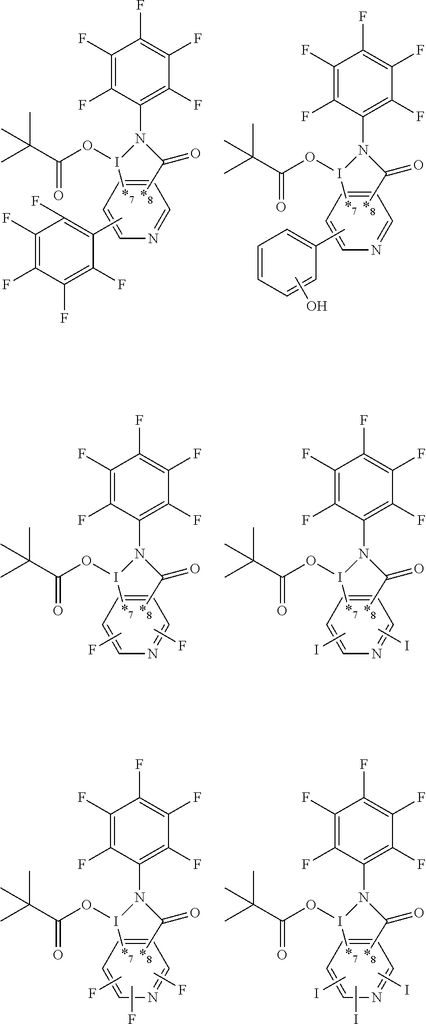

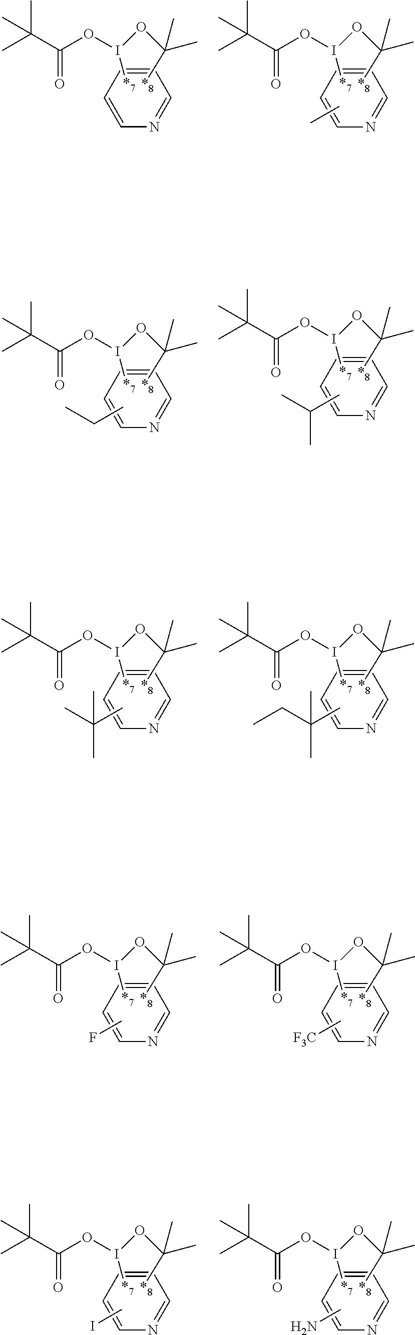

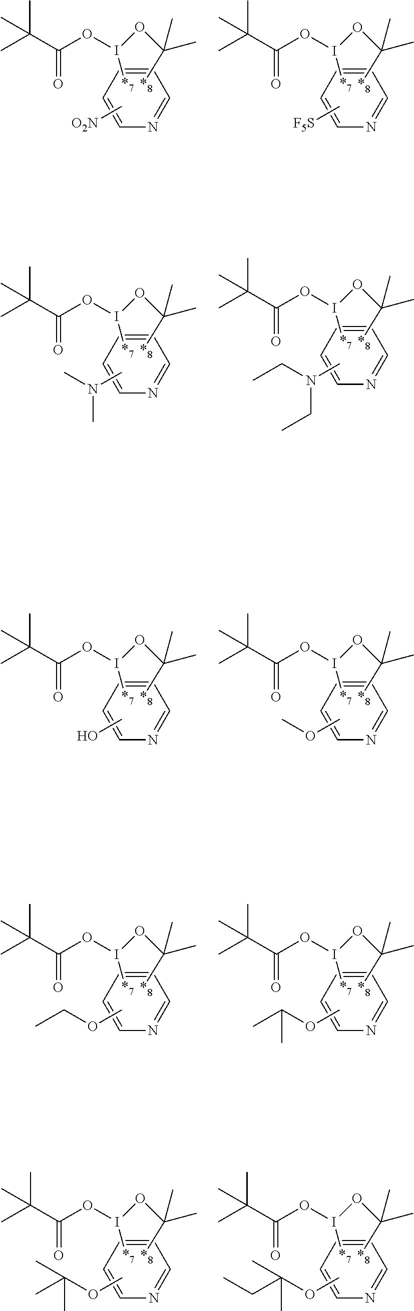

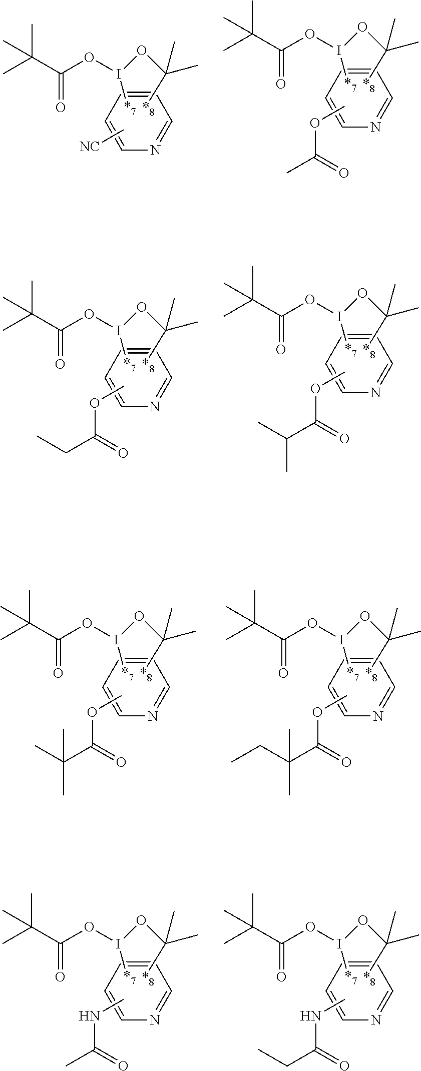

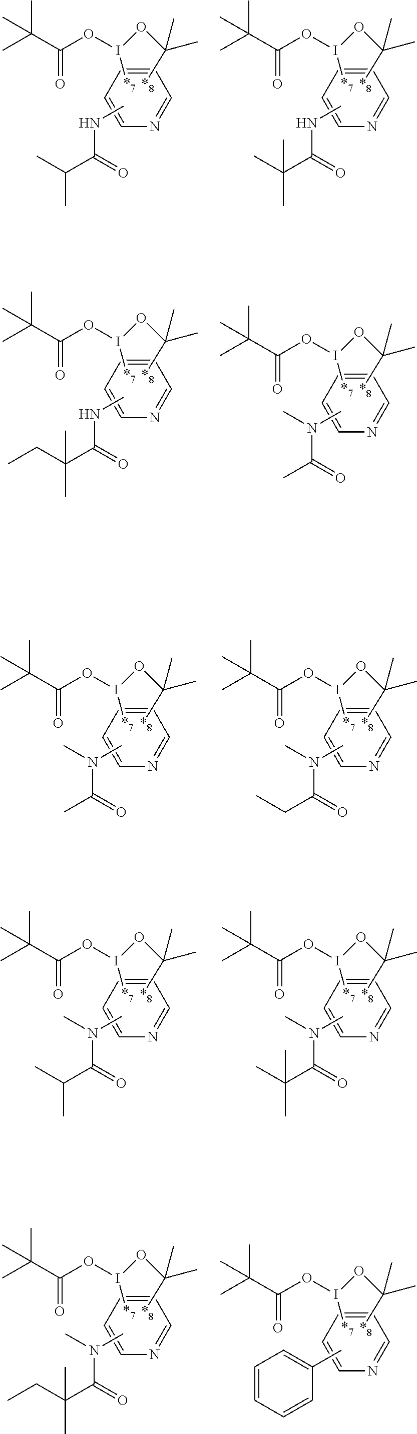

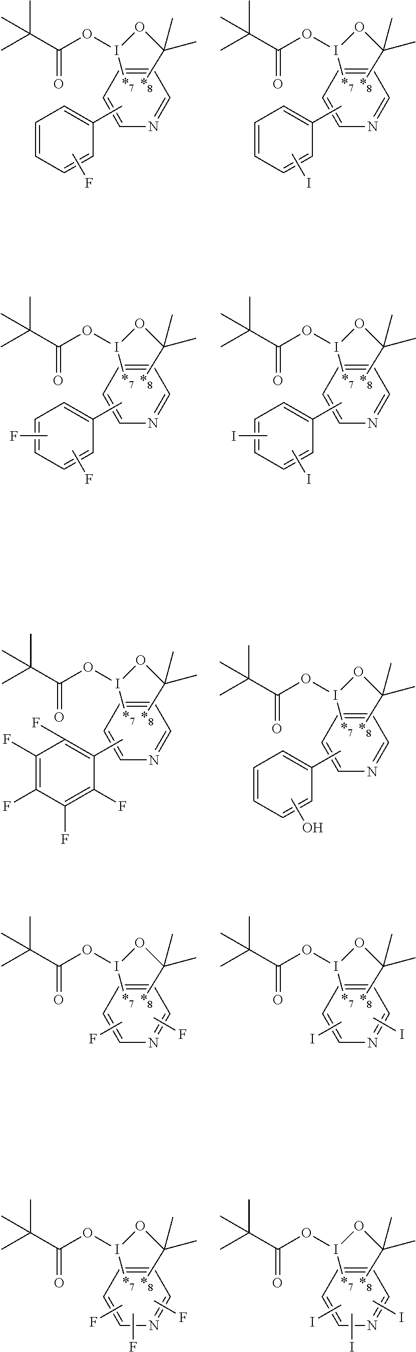

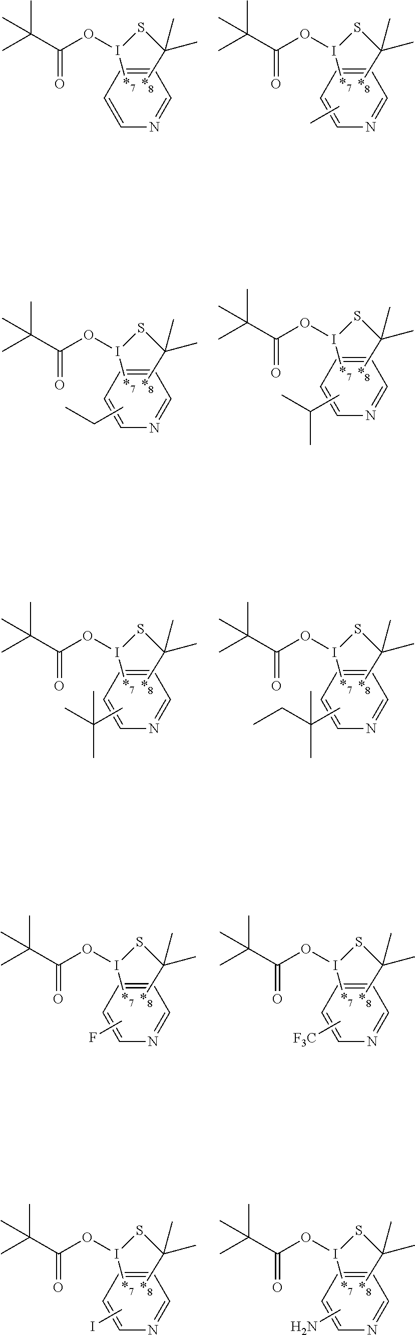

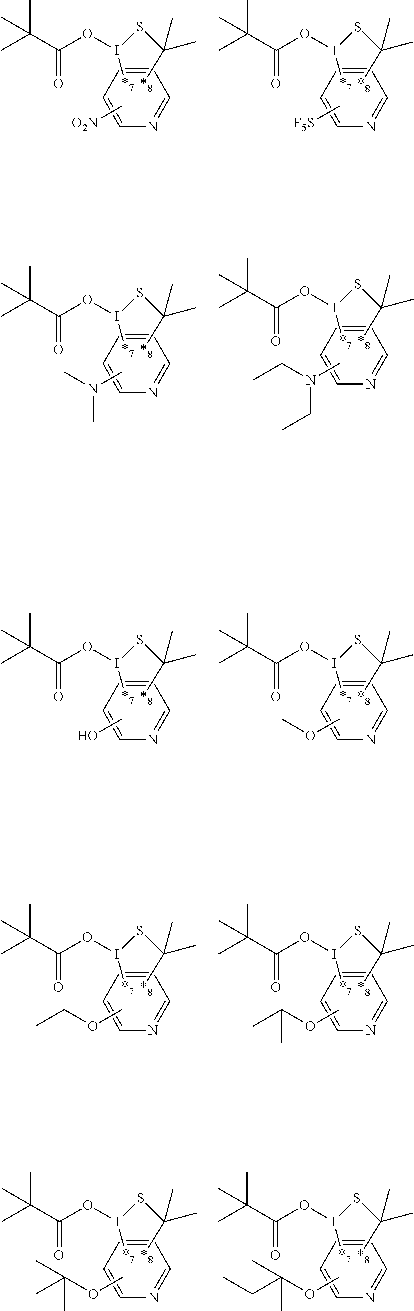

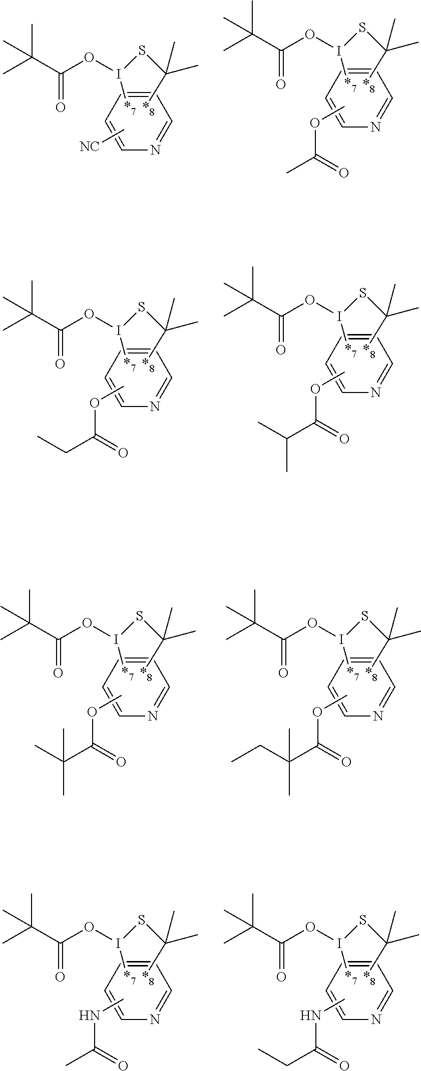

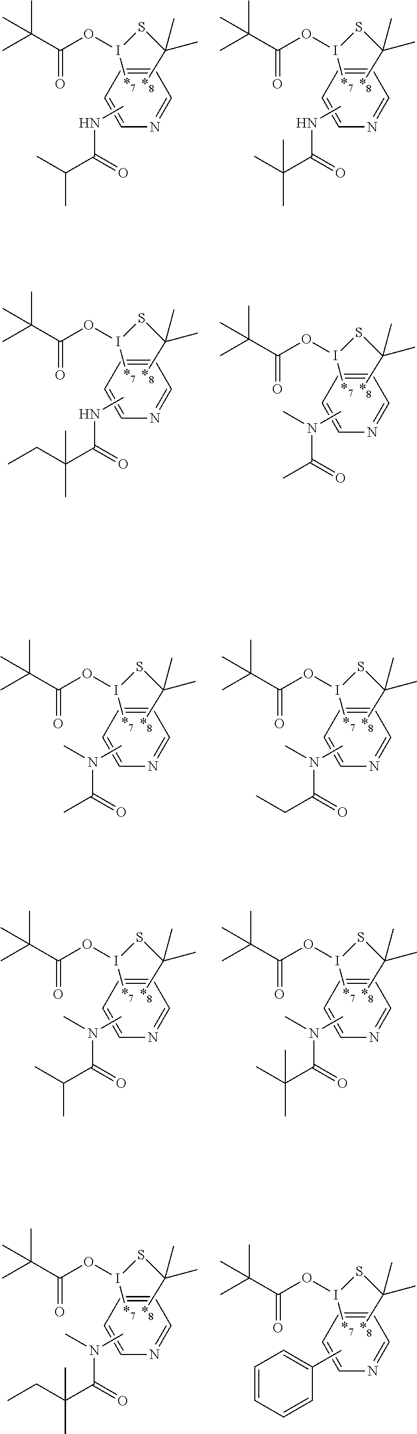

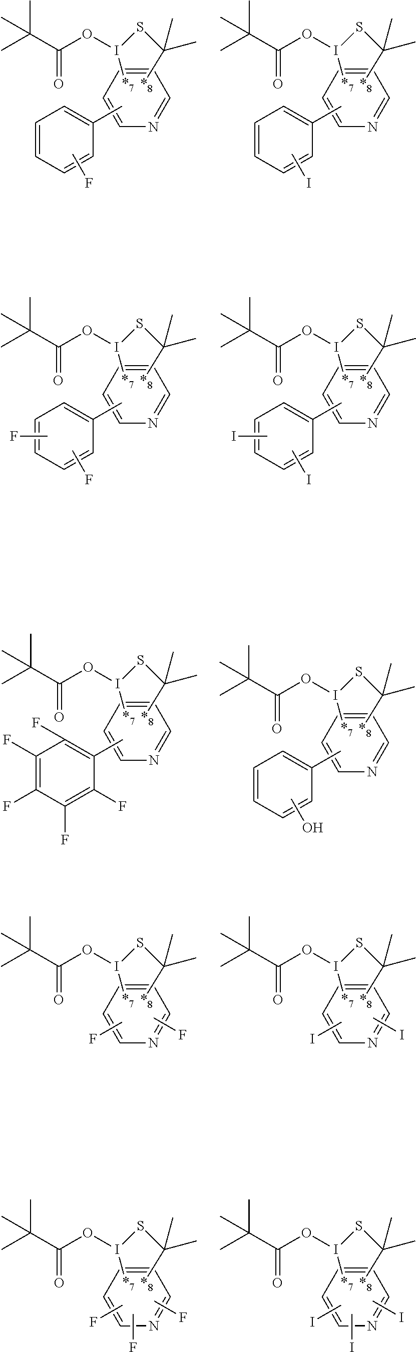

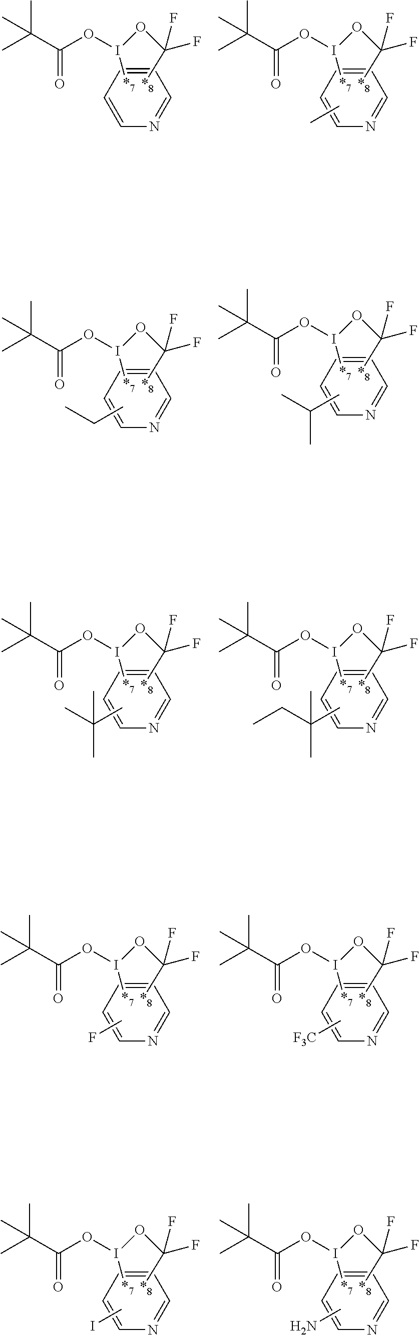

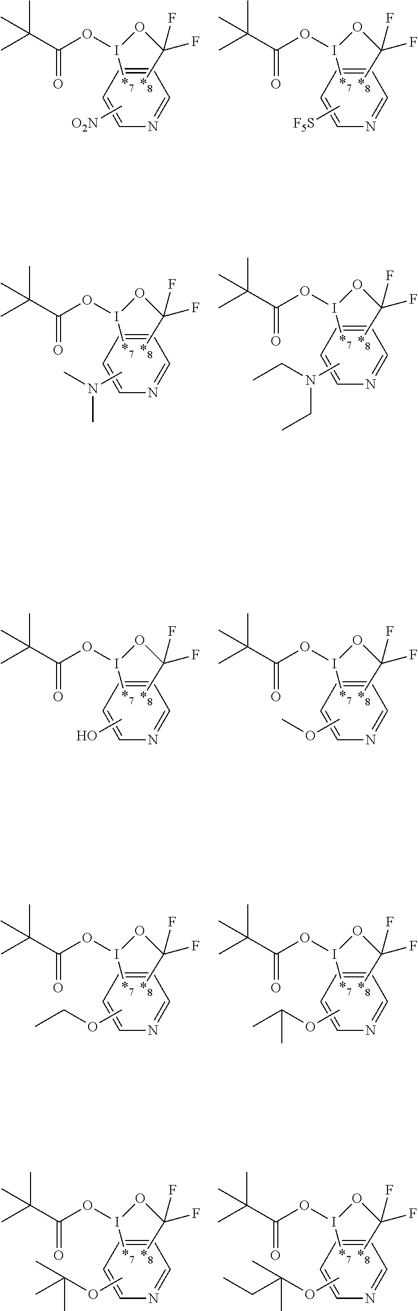

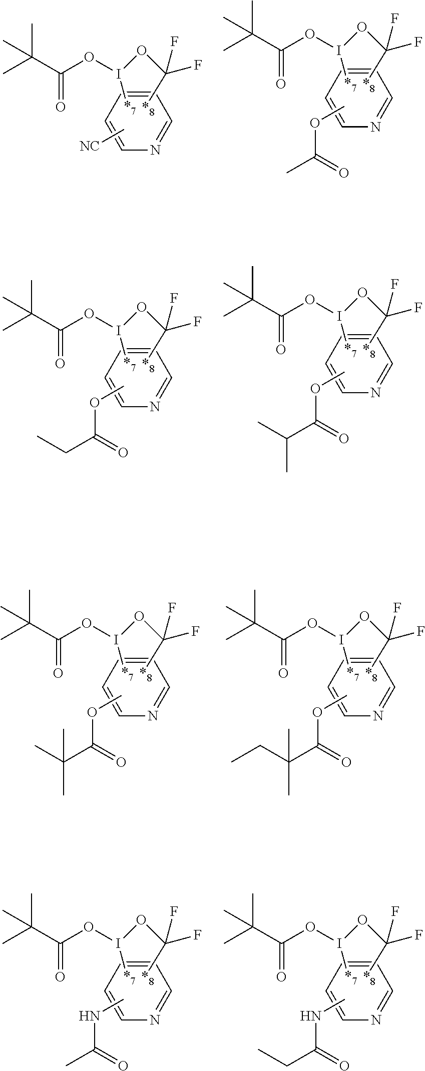

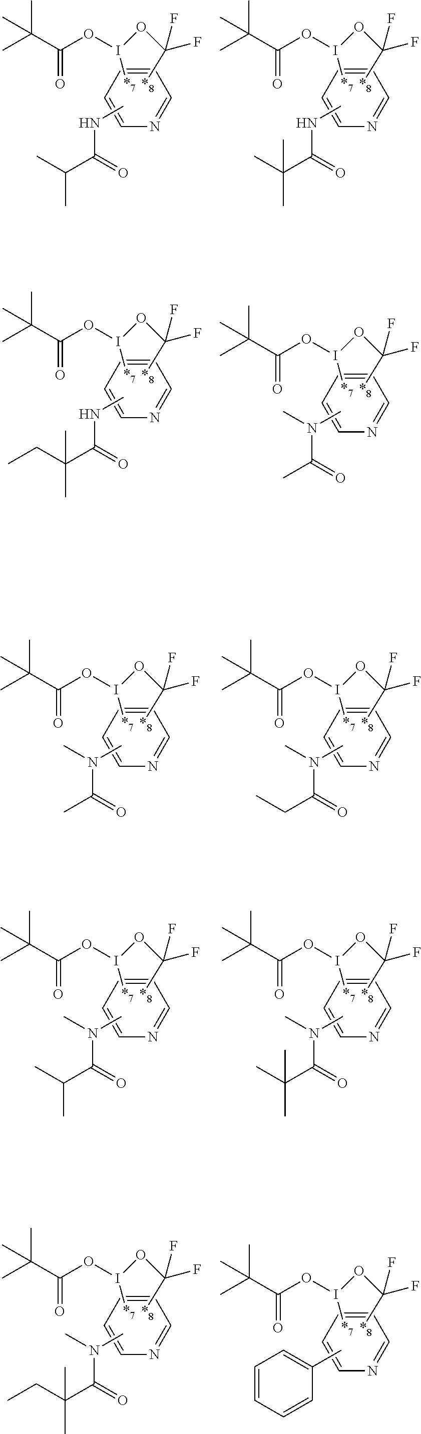

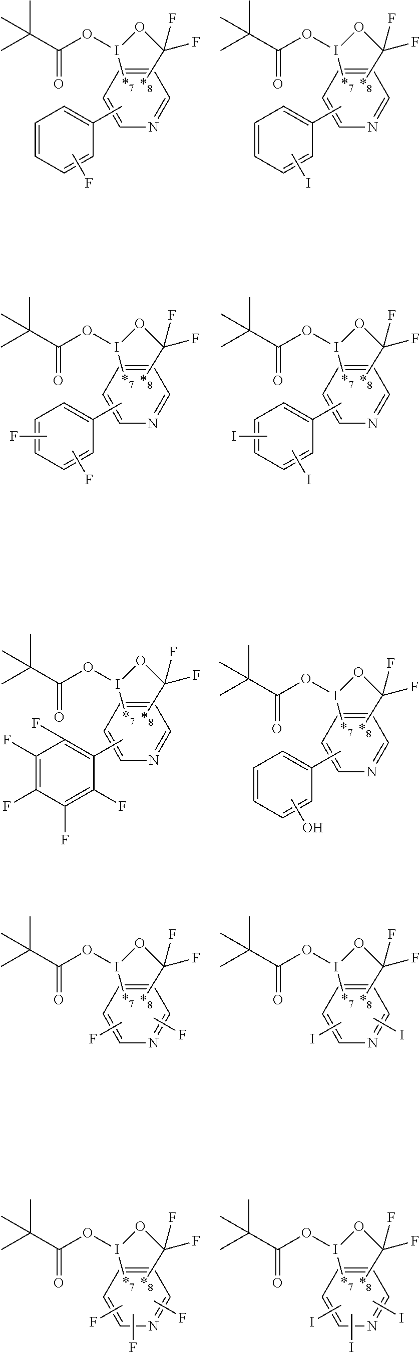

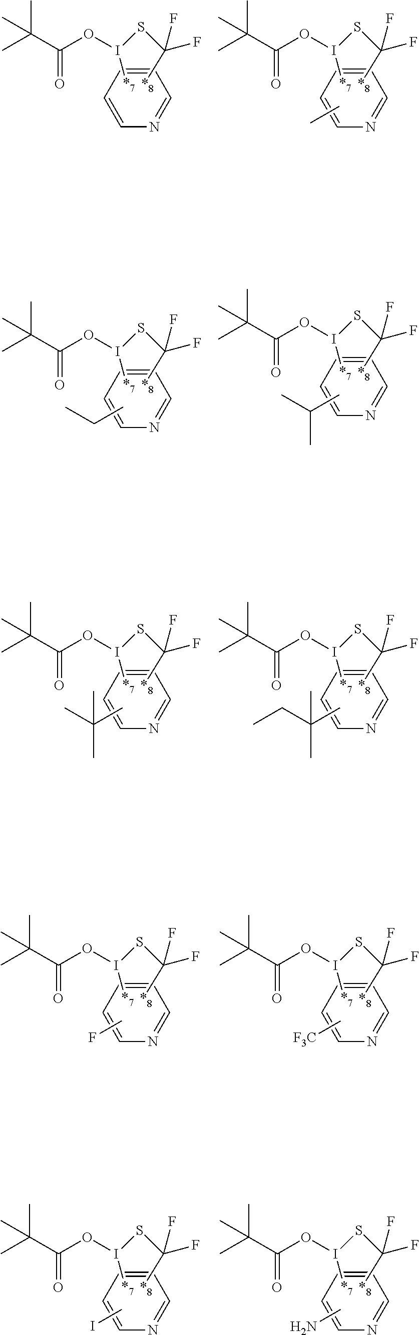

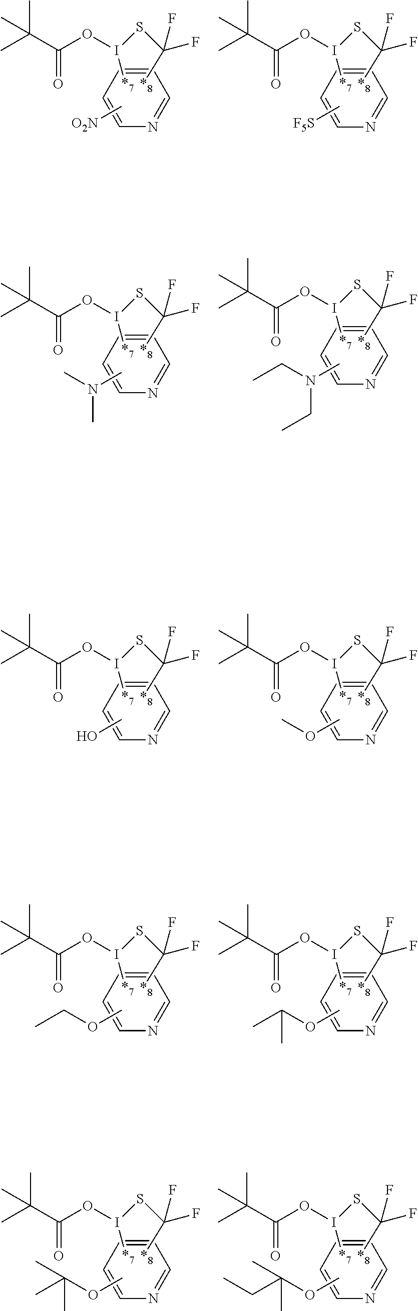

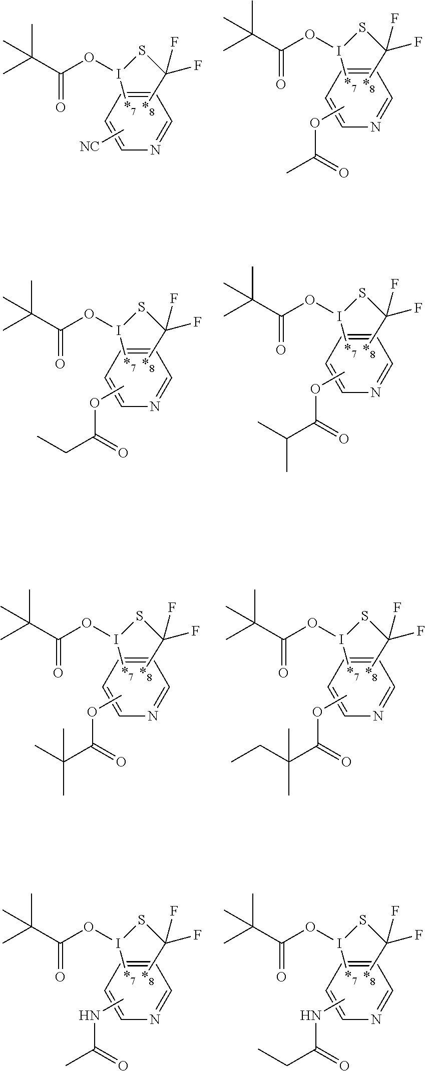

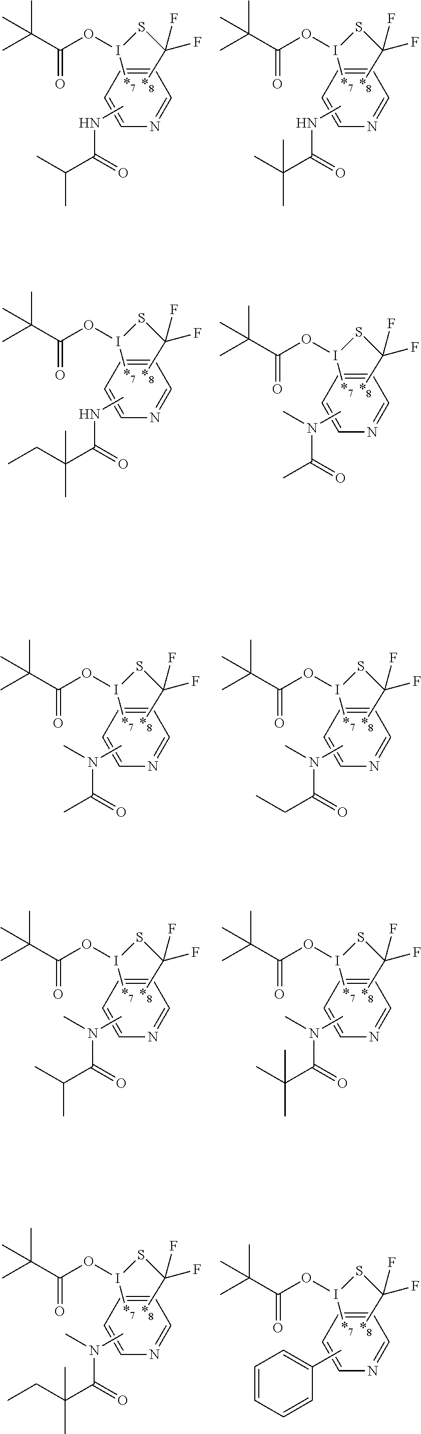

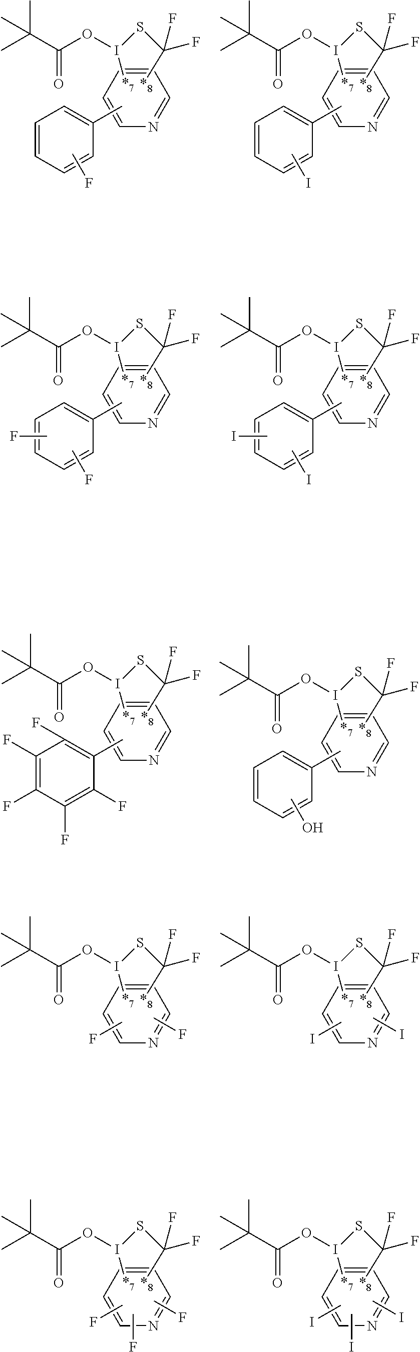

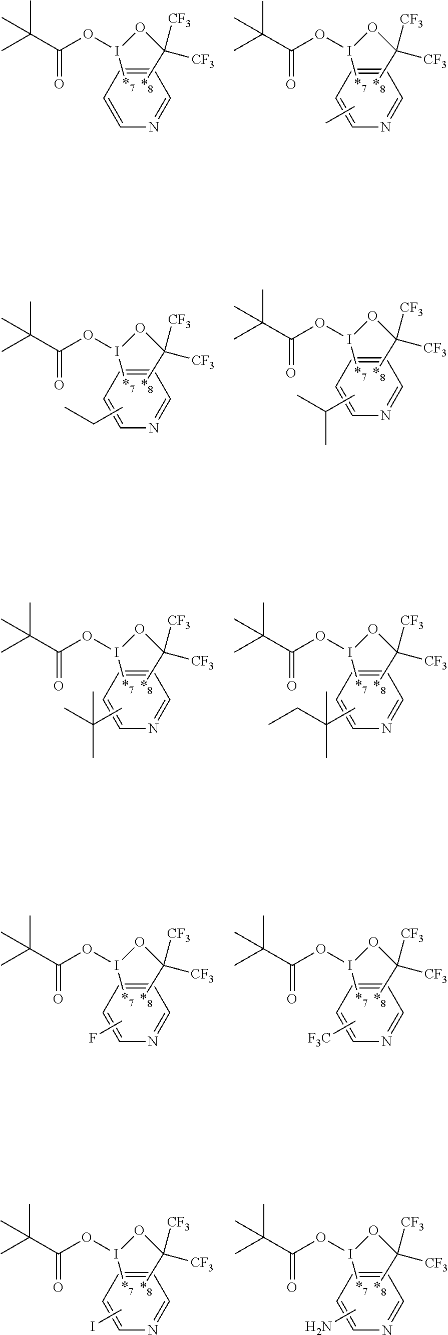

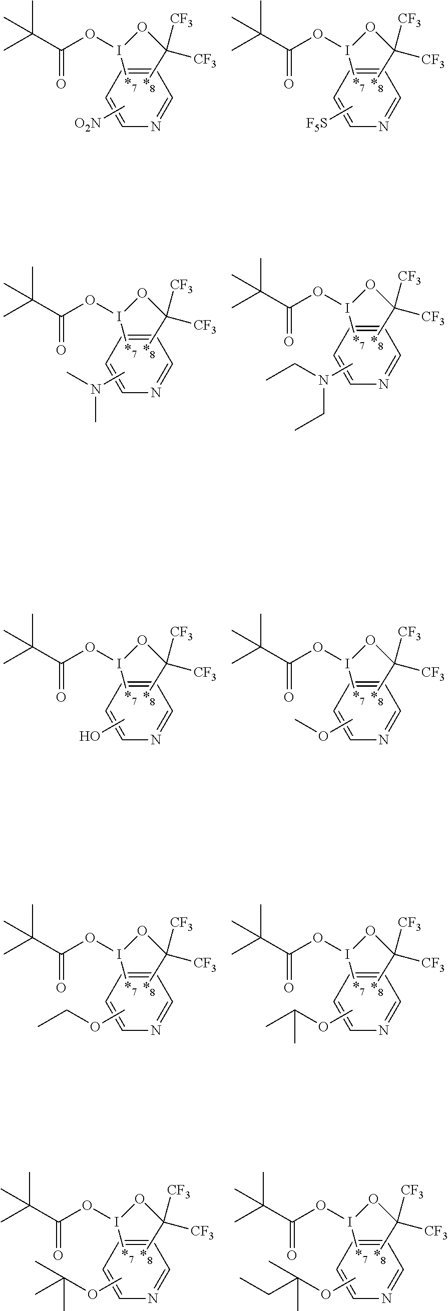

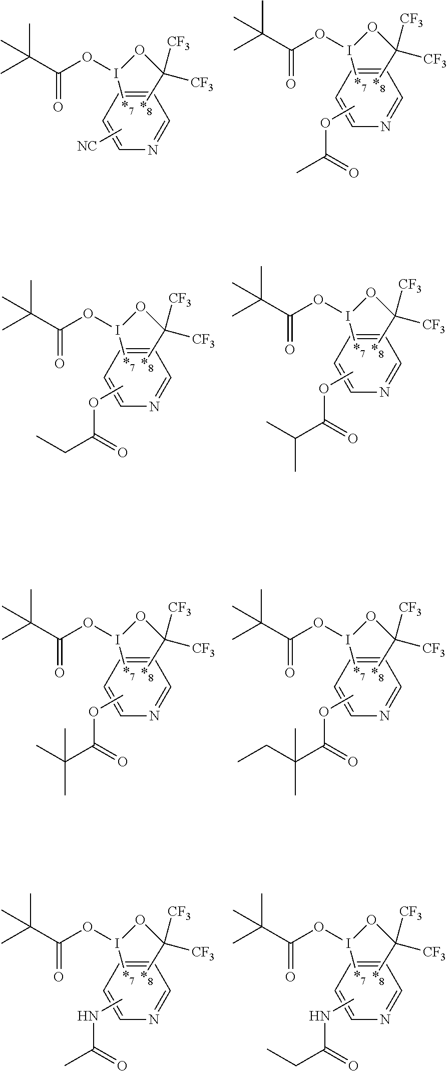

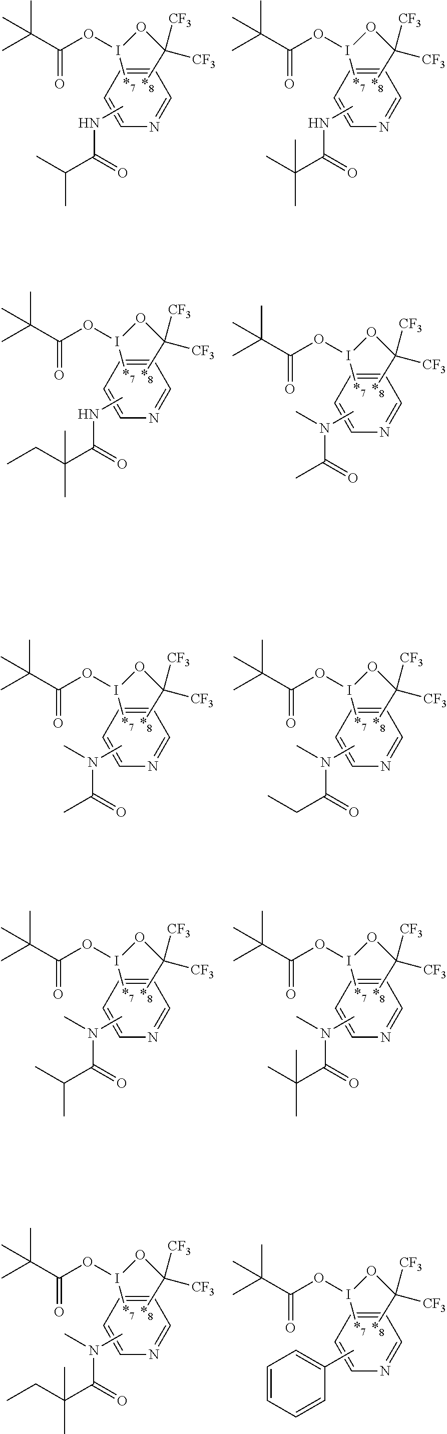

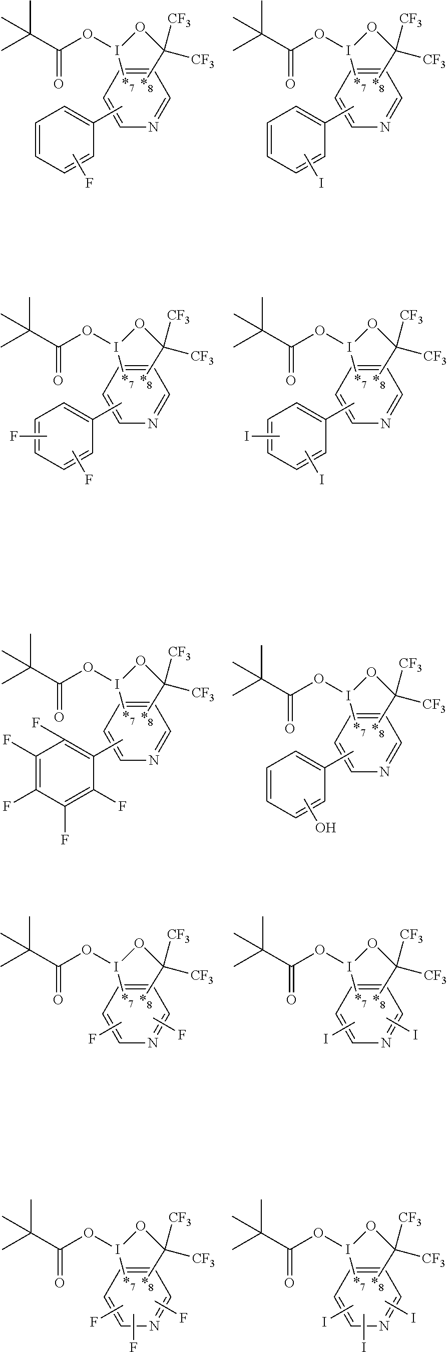

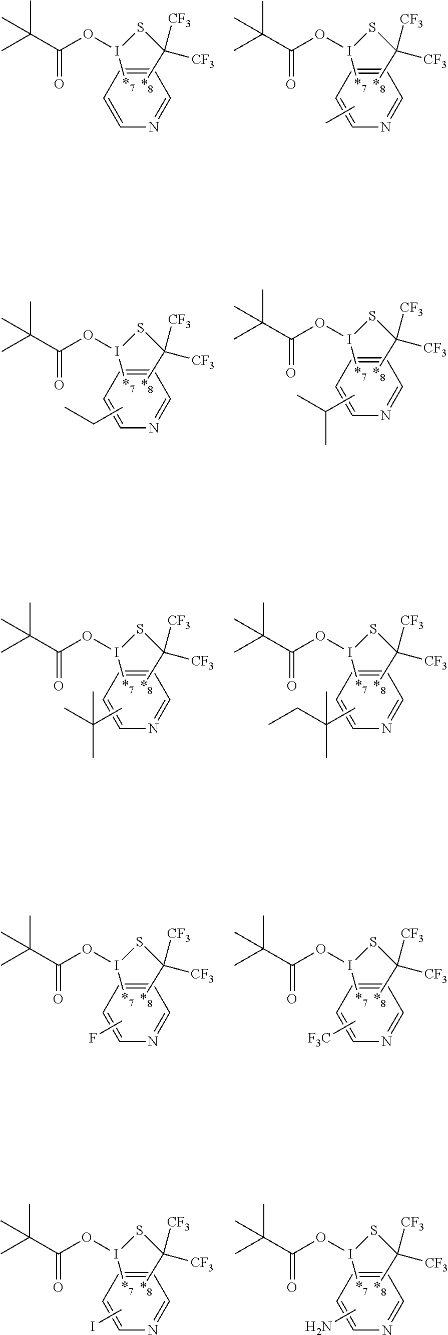

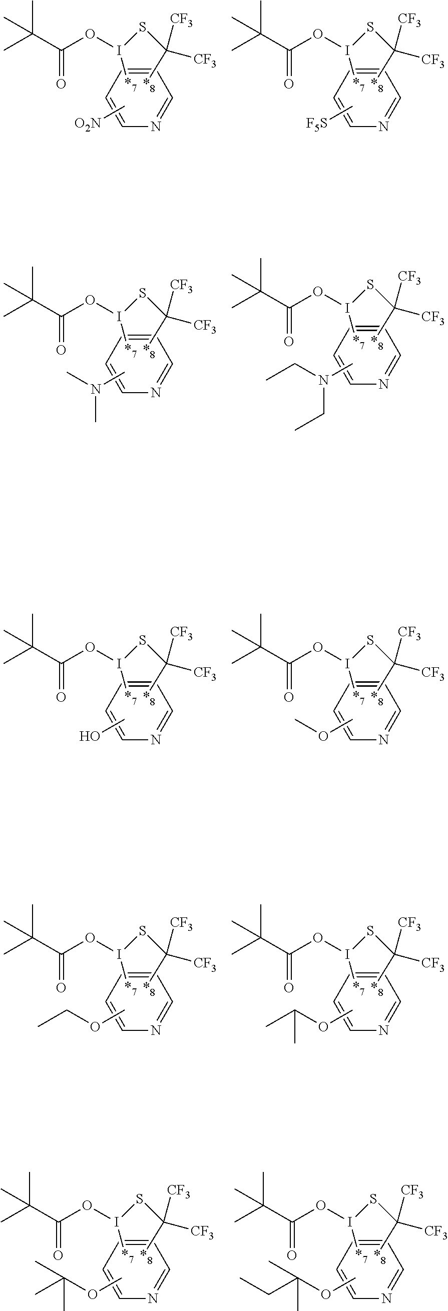

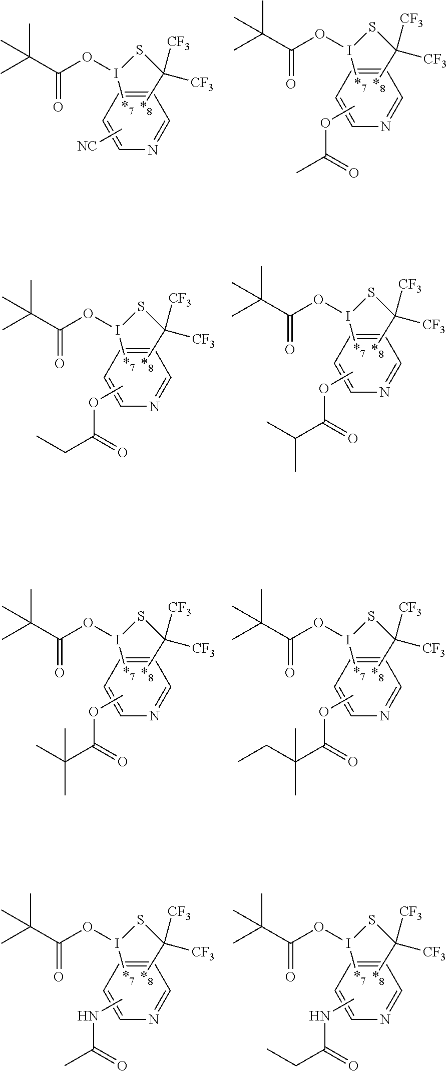

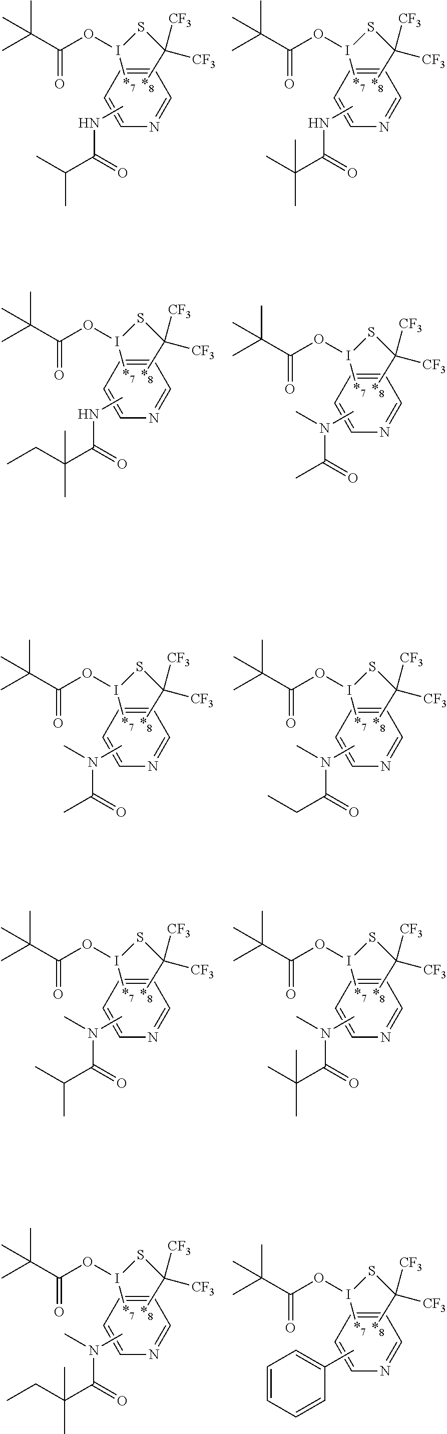

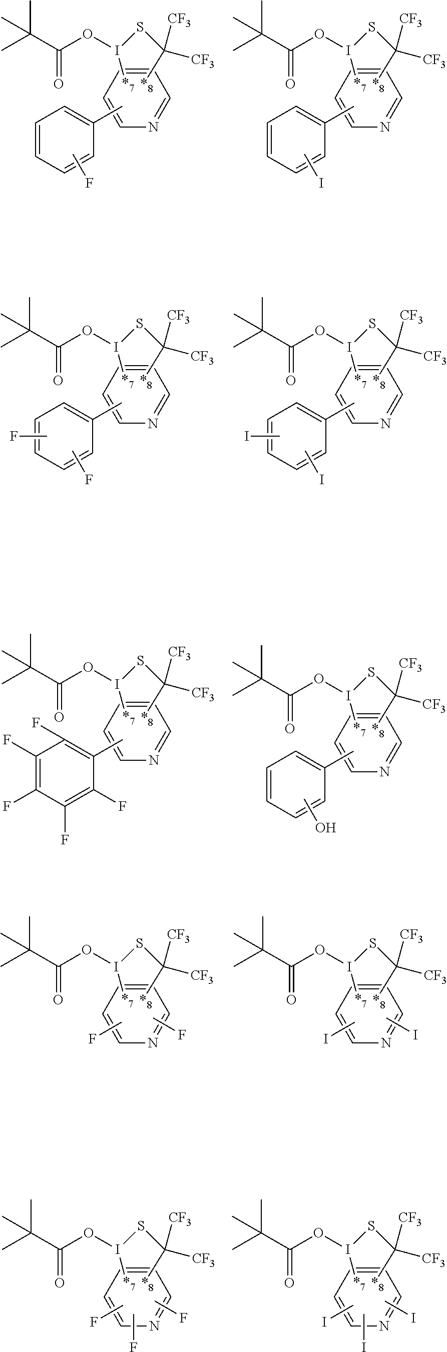

### [Carboxy Group-Containing Compound]

The carboxy group-containing compound is preferably a carboxy group-containing polymer containing a repeat unit having the formula (a-1) or a carboxylic acid having the formula (a-2).

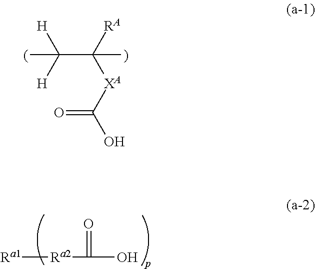

In the formula (a-1), R^{A} is a hydrogen atom, a halogen atom, a methyl group, or a trifluoromethyl group. X^{A} is a single bond, a phenylene group, a naphthylene group, or *—C(═O)—O—X^{A1}—X^{A1} is a C₁-C₁₀ saturated hydrocarbylene group, a phenylene group, or a naphthylene group, and the saturated hydrocarbylene group may contain a hydroxy group, an ether bond, an ester bond, or a lactone ring. * designates a valence bond to a carbon atom in a main chain.

In the formula (a-2), p is 1, 2, 3, or 4.

In the formula (a-2), when p is 1, 3, or 4, R^{a1} is a C₁-C₄₀ p-valent hydrocarbon group or a C₂— C₄₀ p-valent heterocyclic group; when p is 2, R^{a1} is an ether bond, a carbonyl group, an azo group, a thioether bond, a carbonate bond, a carbamate bond, a sulfinyl group, a sulfonyl group, a C₁-C₄₀ p-valent hydrocarbon group, or a C₂— C₄₀ p-valent heterocyclic group. Some or all of the hydrogen atoms in the p-valent hydrocarbon group or the p-valent heterocyclic group may be substituted by a heteroatom-containing moiety, and some constituent —CH₂— in the p-valent hydrocarbon group may be replaced by a heteroatom-containing moiety.

In the formula (a-2), R^{a2} is a single bond or a C₁-C₂₀ hydrocarbylene group, and some or all of the hydrogen atoms in the hydrocarbylene group may be substituted by a heteroatom-containing moiety, and some constituent —CH₂— in the hydrocarbylene group may be replaced by a heteroatom-containing moiety. When p is 2, 3, or 4, each R^{a2} may be the same or different from each other.

The p-valent hydrocarbon group of R^{a1} may be saturated or unsaturated and straight, branched or cyclic. The p-valent hydrocarbon group is obtained by removing p number of hydrogen atoms from a hydrocarbon. Suitable hydrocarbons include C₁-C₄₀ alkanes, C₂-C₄₀ alkenes, C₂— C₄₀ alkynes, C₃-C₄₀ cyclic saturated hydrocarbons, C₃-C₄₀ cyclic unsaturated hydrocarbons, and C₆-C₄₀ aromatic hydrocarbons.

Exemplary C₁-C₄₀ alkanes include methane, ethane, propane, butane, pentane, hexane, heptane, octane, nonane, decane, and structural isomers thereof.

Exemplary C₂— C₄₀ alkenes include ethylene, propylene, butene, pentene, hexene, heptene, octene, nonene, decene, and structural isomers thereof.

Exemplary C₂— C₄₀ alkynes include acetylene, propyne, butyne, pentyne, hexyne, heptyne, octyne, nonyne, decyne, and structural isomers thereof.

Exemplary C₃-C₄₀ cyclic saturated hydrocarbons include cyclopropane, cyclobutane, cyclohexane, cycloheptane, cyclooctane, adamantane, and norbornane.

Exemplary C₃-C₄₀ cyclic unsaturated hydrocarbons include cyclopropene, cyclobutene, cyclopentene, cyclohexene, cycloheptene, cyclooctene, and norbornene.

Exemplary C₆-C₄₀ aromatic hydrocarbons include benzene, naphthalene, and biphenyl.

The p-valent heterocyclic group of R^{a1} is obtained by removing p number of hydrogen atoms from a heterocyclic compound. Suitable heterocyclic compounds include furan, pyridine, pyrazole, and thiazolidine.

In the p-valent hydrocarbon group and p-valent heterocyclic group, some or all of the hydrogen atoms may be substituted by a moiety containing a heteroatom such as oxygen, sulfur, nitrogen or halogen, so that the group may contain hydroxy, cyano, fluorine, chlorine, bromine, or iodine. In the p-valent hydrocarbon group, some constituent —CH₂— may be replaced by a moiety containing a heteroatom such as oxygen, sulfur or nitrogen, so that the group may contain carbonyl, ether bond, thioether bond, ester bond, sulfonic ester bond, carbonate bond, carbamate bond, lactone ring, sultone ring, or carboxylic anhydride (—C(═O)—O—C(═O)—).

The hydrocarbylene group of R^{a2} may be saturated or unsaturated and straight, branched or cyclic. Examples thereof include C₁-C₂₀ alkanediyl groups such as methanediyl, ethane-1,1-diyl, ethane-1,2-diyl, propane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, and dodecane-1,12-diyl, C₃-C₂₀ cyclic saturated hydrocarbylene groups such as cyclopentanediyl, cyclohexanediyl, norbornanediyl, and adamantanediyl, C₂— C₂₀ unsaturated aliphatic hydrocarbylene groups such as vinylene and propene-1,3-diyl, C₆-C₂₀ arylene groups such as phenylene and naphthylene, and combinations thereof. In the hydrocarbylene group, some or all of the hydrogen atoms may be substituted by a moiety containing a heteroatom such as oxygen, sulfur, nitrogen or halogen, and some constituent —CH₂— may be replaced by a moiety containing a heteroatom such as oxygen, sulfur or nitrogen, so that the group may contain hydroxy, cyano, fluorine, chlorine, bromine, iodine, carbonyl, ether bond, thioether bond, ester bond, sulfonic ester bond, carbonate bond, carbamate bond, lactone ring, sultone ring, or carboxylic anhydride.

Of the carboxylic acids, those compounds of the formula (a-2) wherein p is 2, 3, or 4 are preferred because when mixed with the hypervalent iodine compound, they form a high molecular weight, robust resist film having etching resistance and developer resistance.

Examples of the carboxy group-containing repeat unit having the formula (a-1) are shown below, but are not limited thereto. In the formulae, R^{A} is the same as described above.

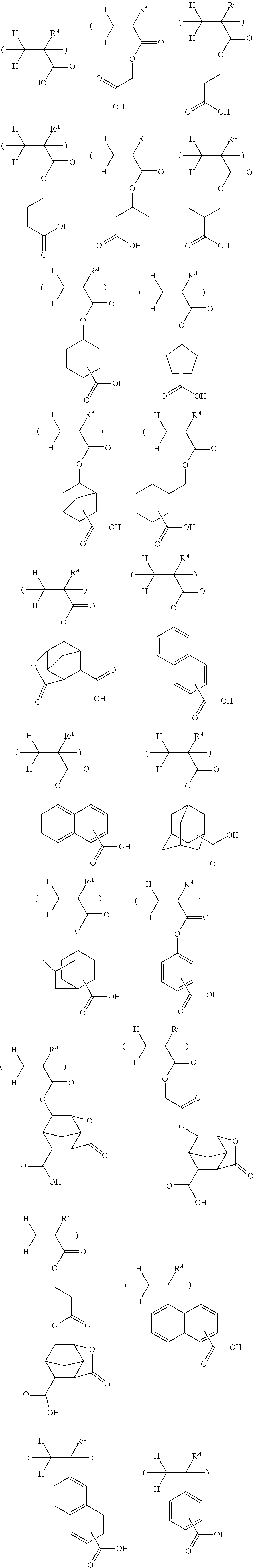

Examples of the carboxylic acid having formula (a-2) are shown below, but are not limited thereto.

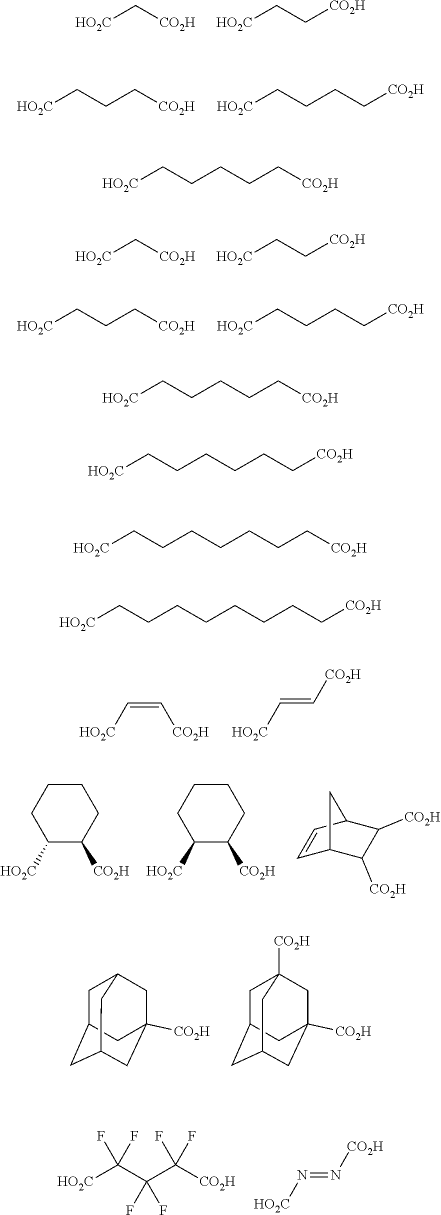

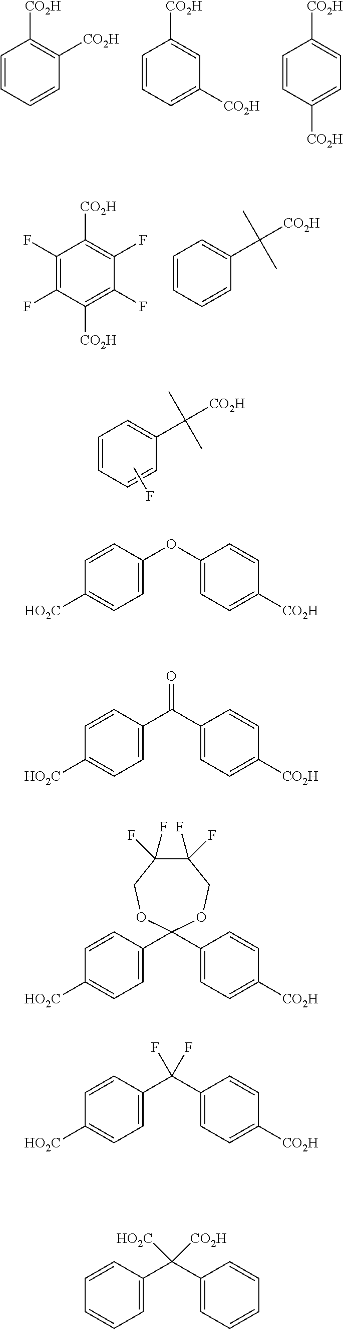

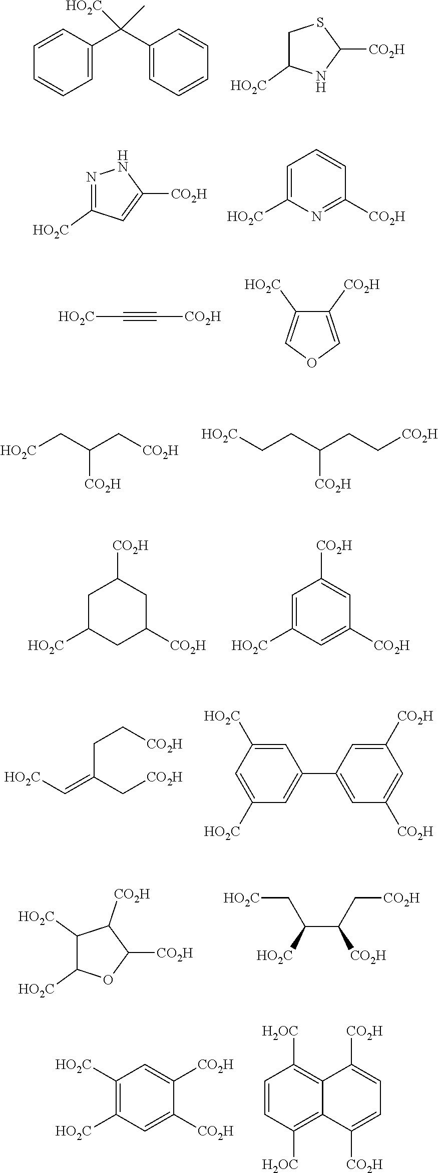

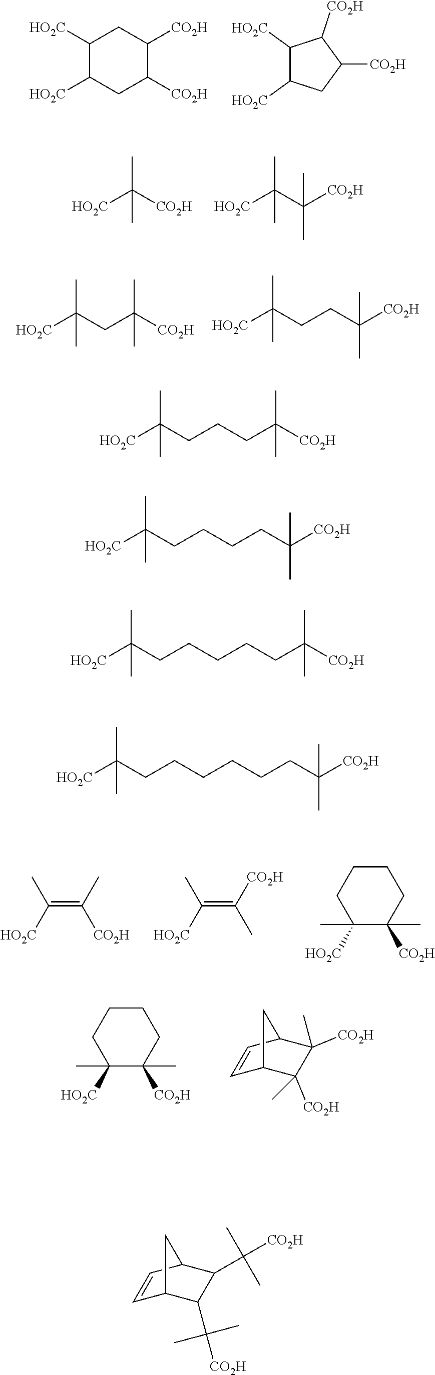

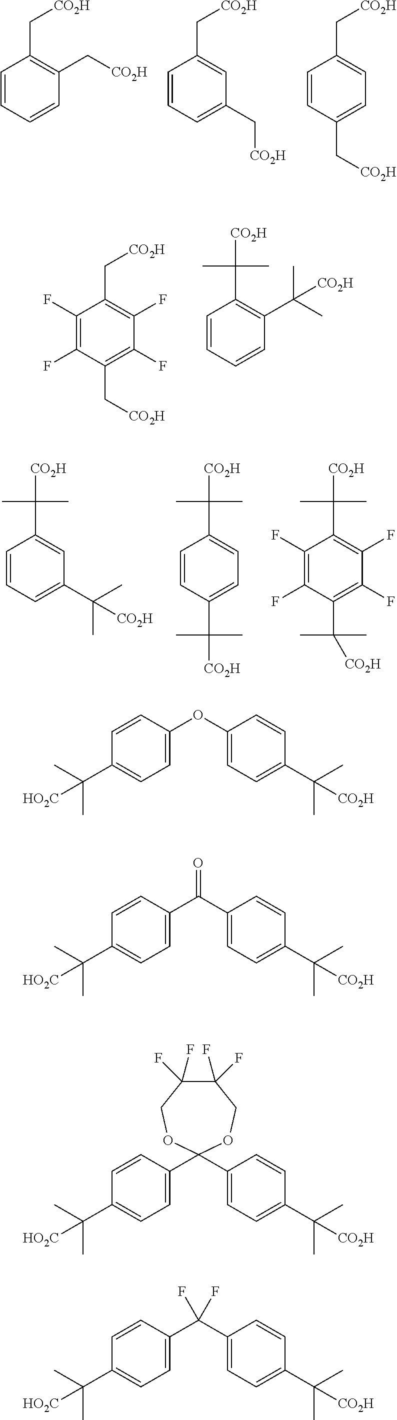

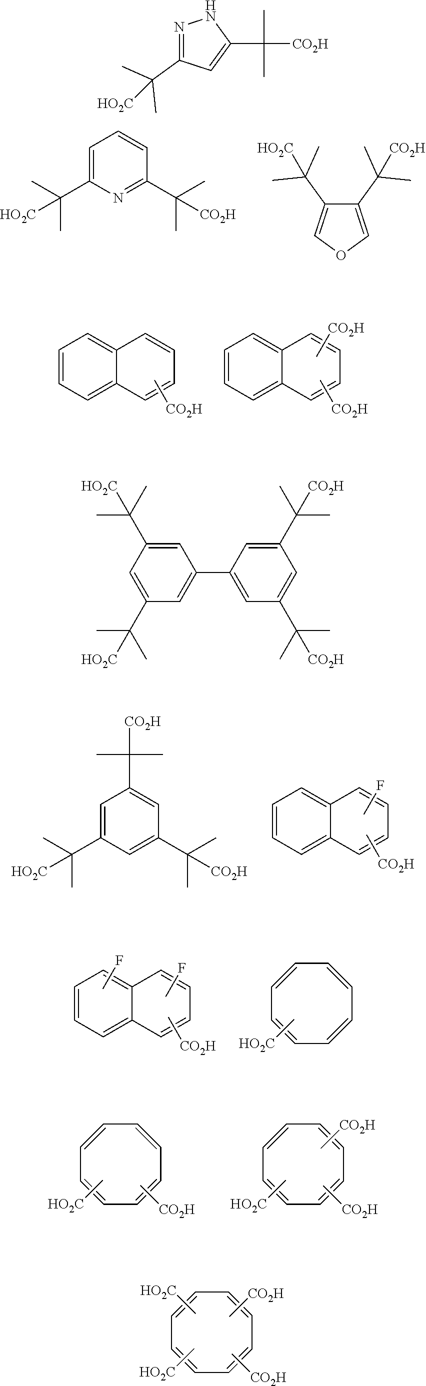

The carboxy group-containing polymer may further contain a repeat unit other than the repeat unit having the formula (a-1) (hereinafter, also referred to as another repeat unit). Another repeat unit is not particularly limited, and a repeat unit is preferable that is capable of improving the solubility, in a solvent, of an insoluble polymer containing only a repeat unit having a carboxy group. Another repeat unit is preferably a repeat unit having a cyclic structure that is a rigid skeleton and expected to have high etching resistance, or a repeat unit having a styrene skeleton.

Examples of another repeat unit are shown below, but are not limited thereto. In the formulae, R^{A} is the same as described above, and X^{B} is each independently —CH₂— or —O—.

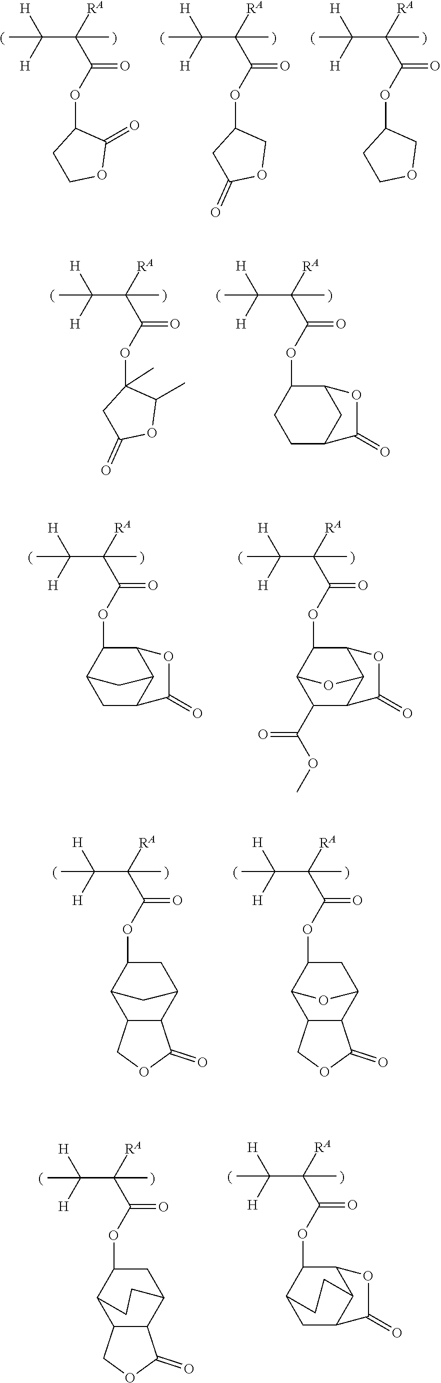

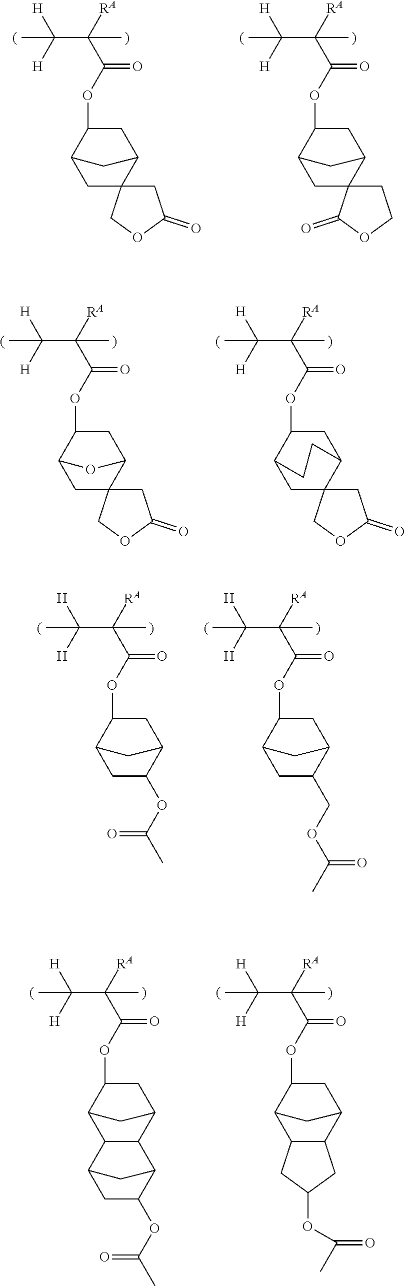

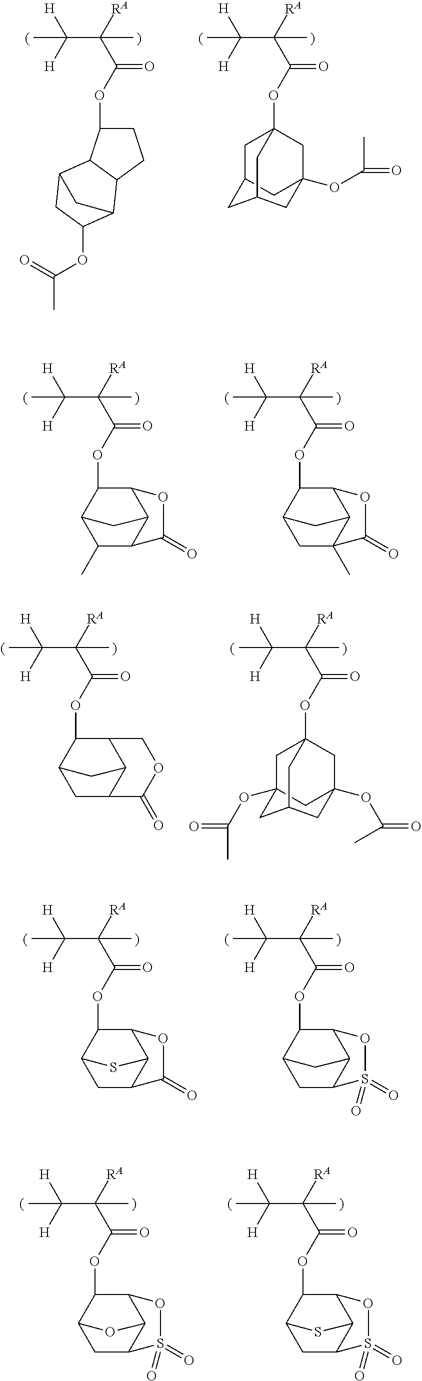

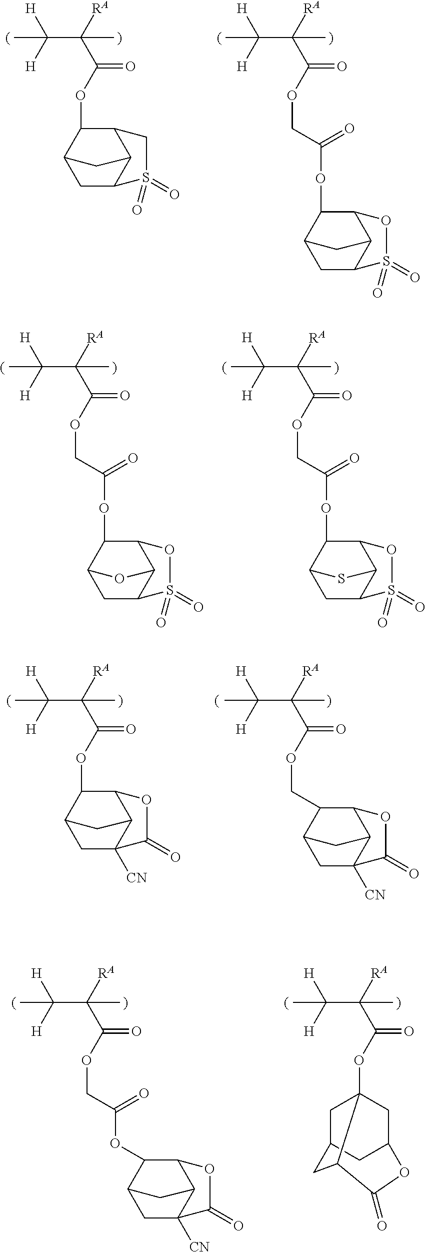

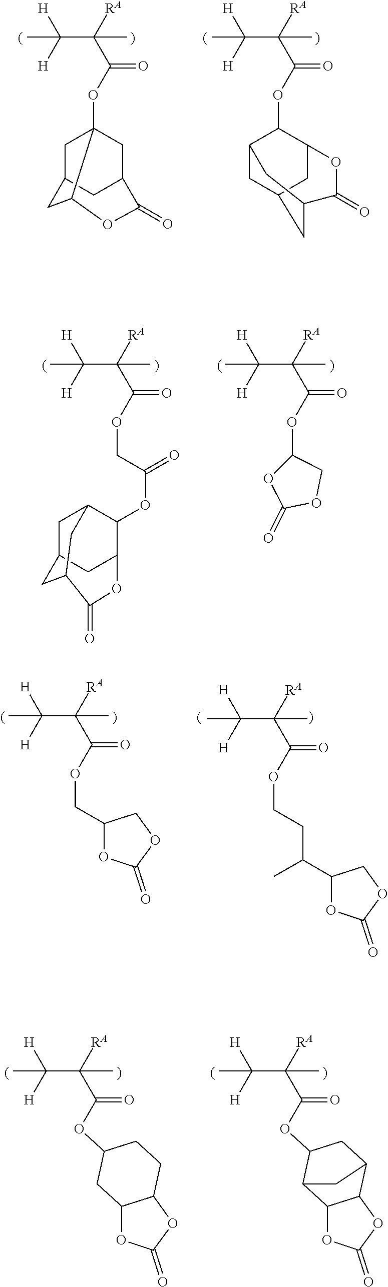

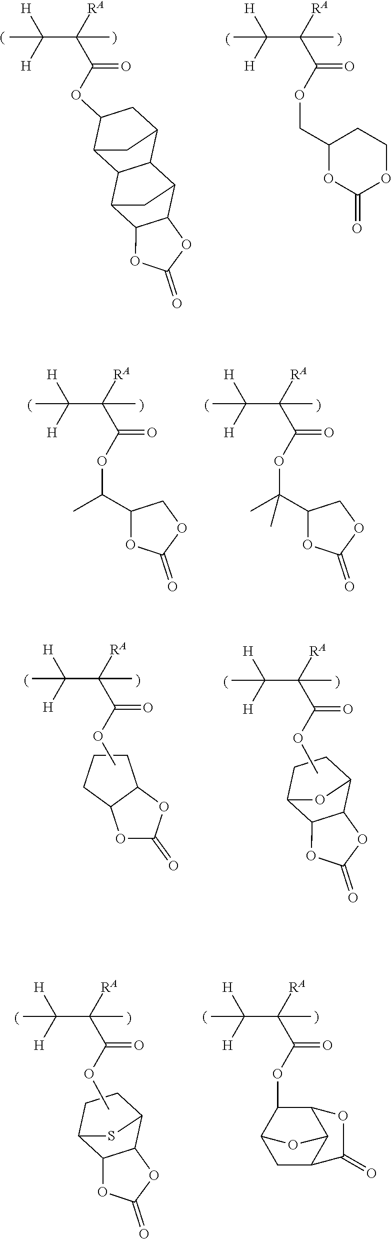

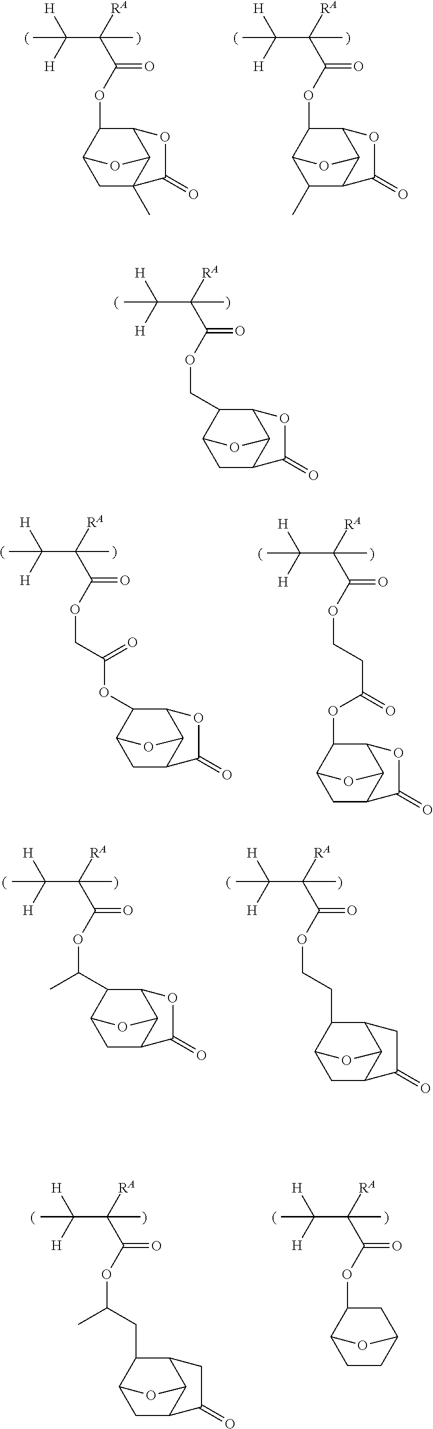

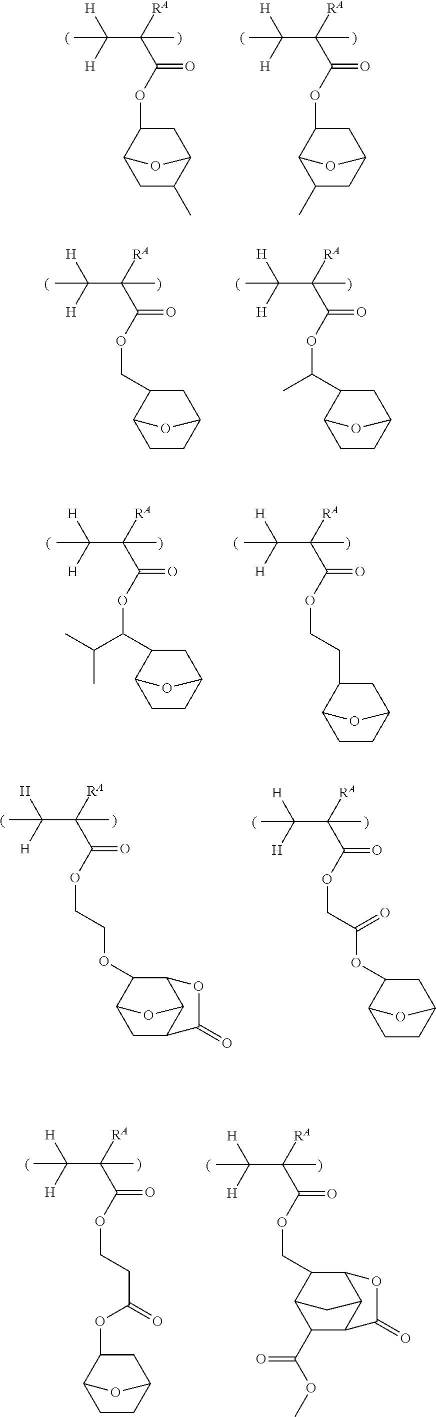

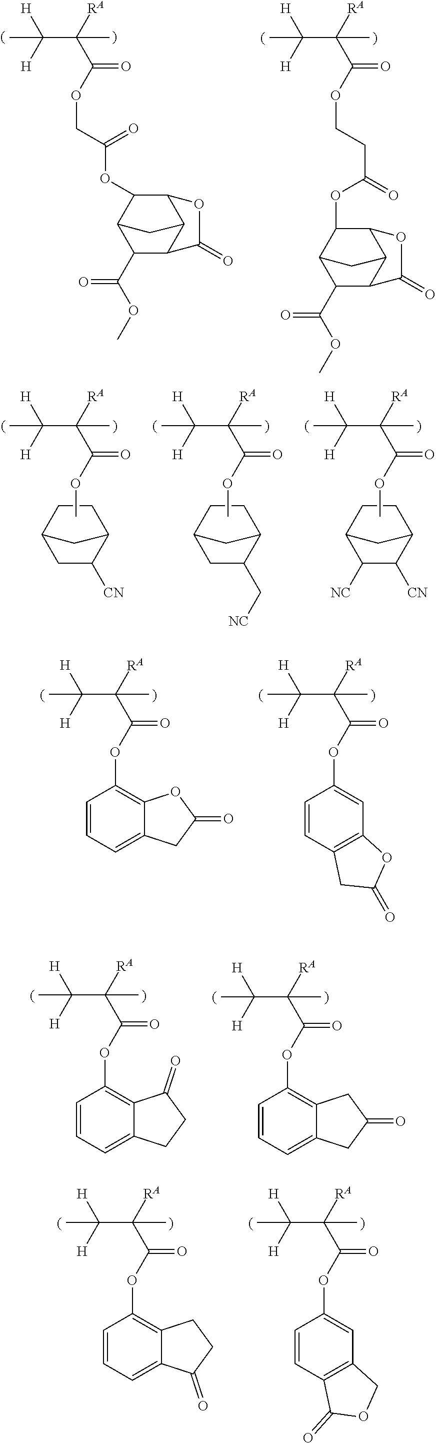

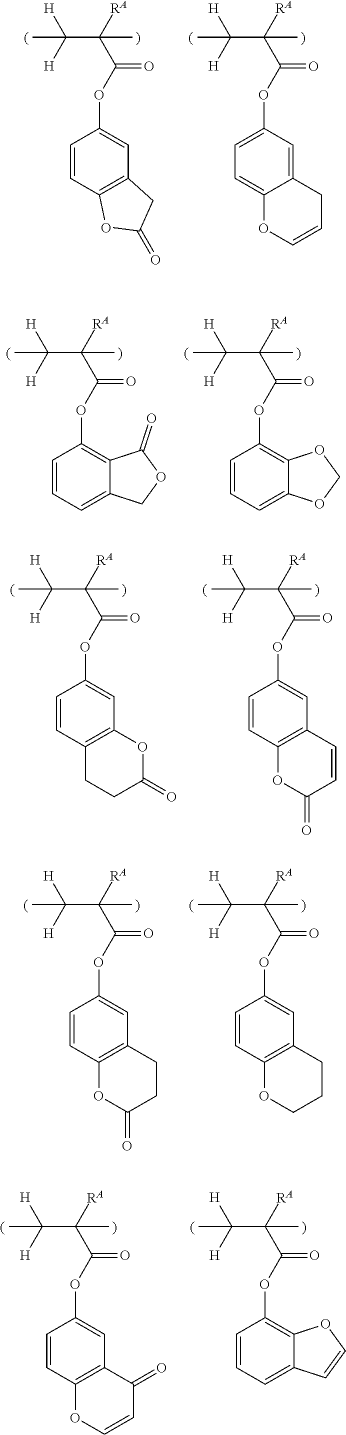

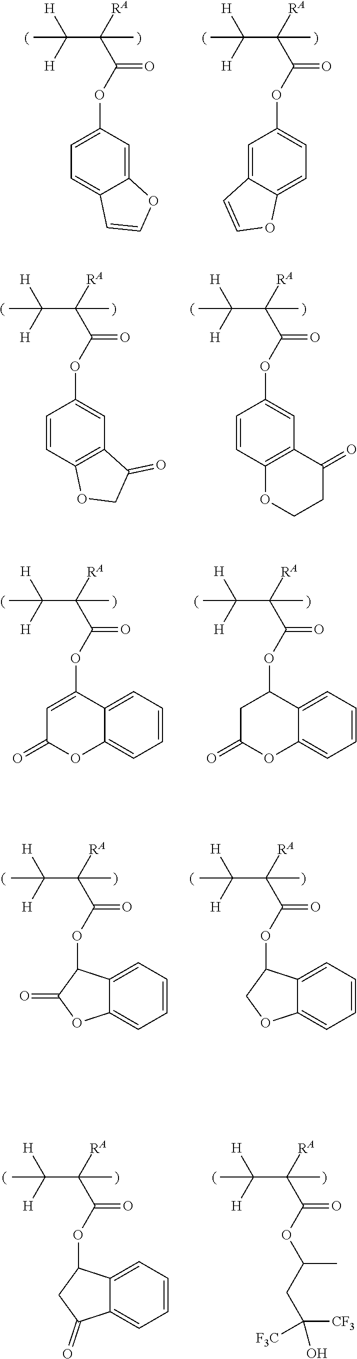

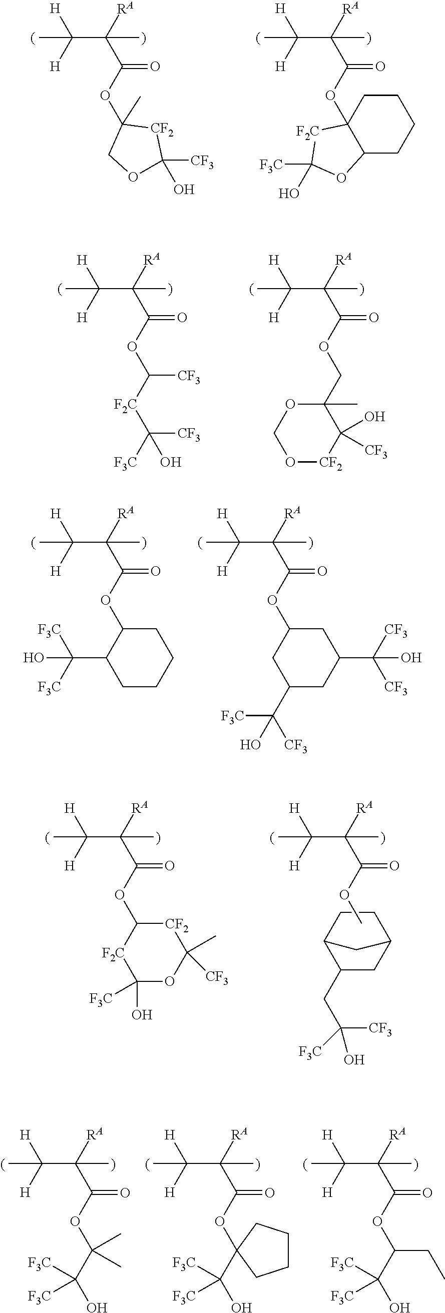

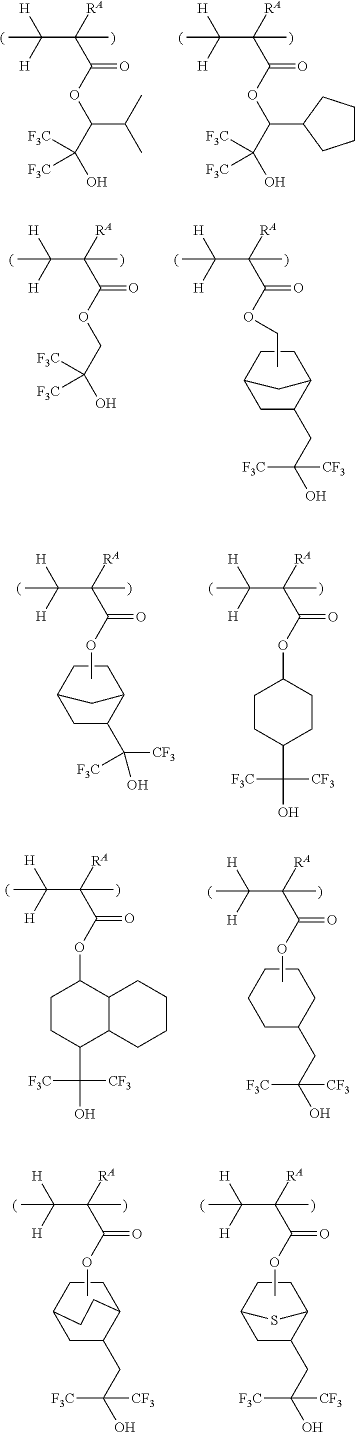

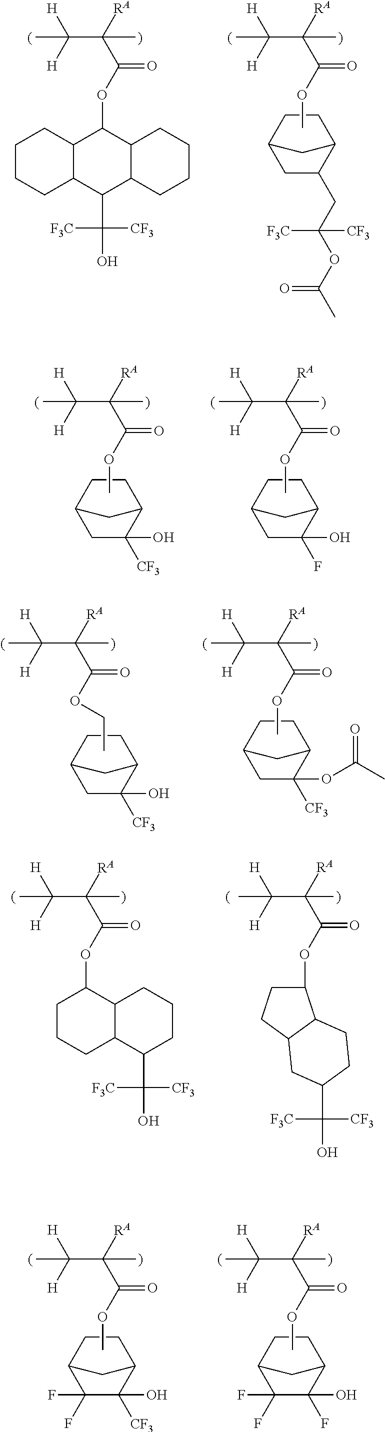

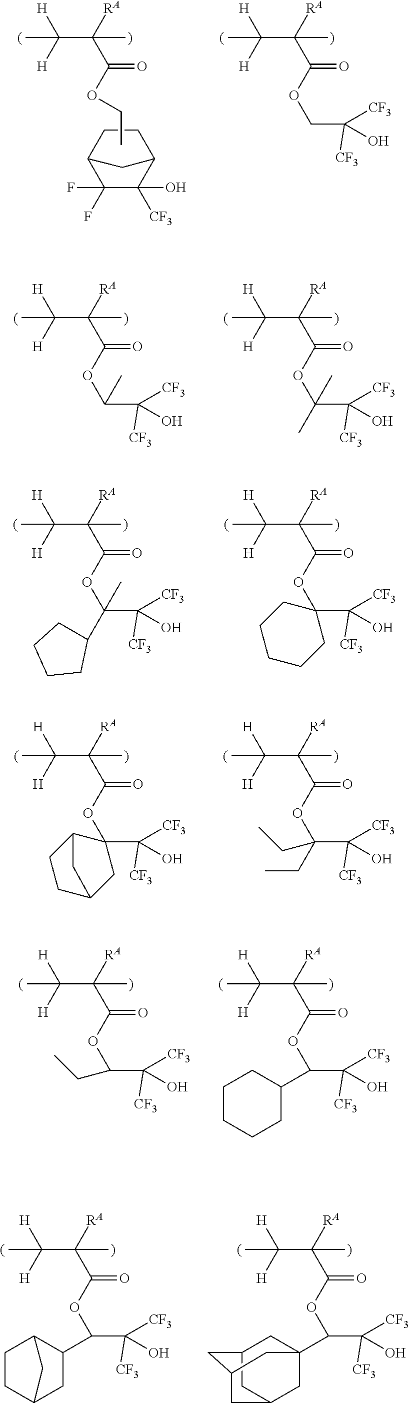

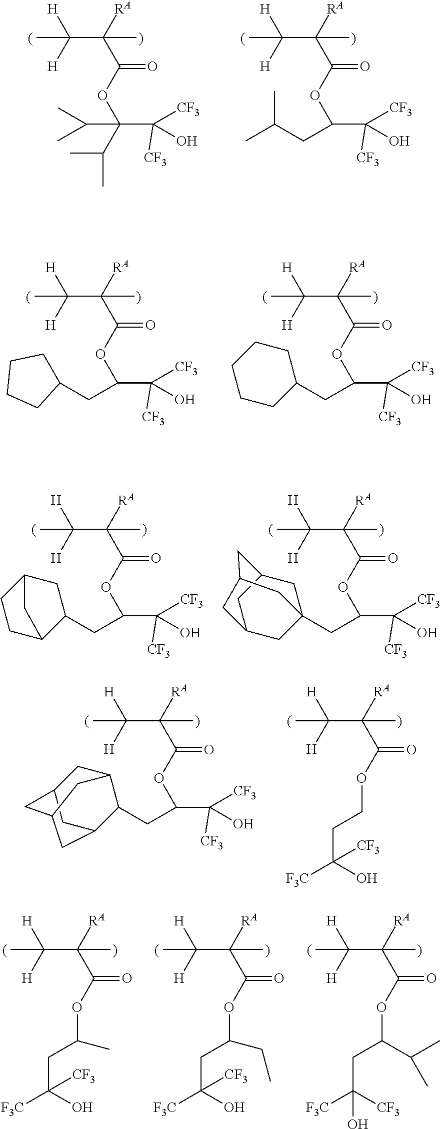

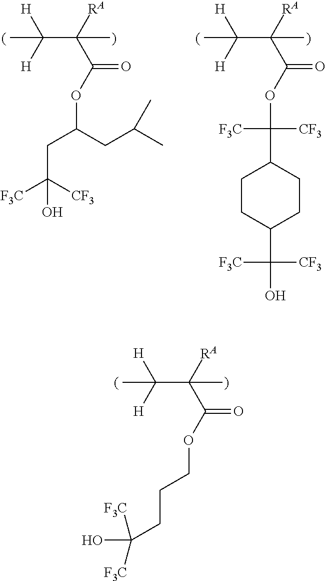

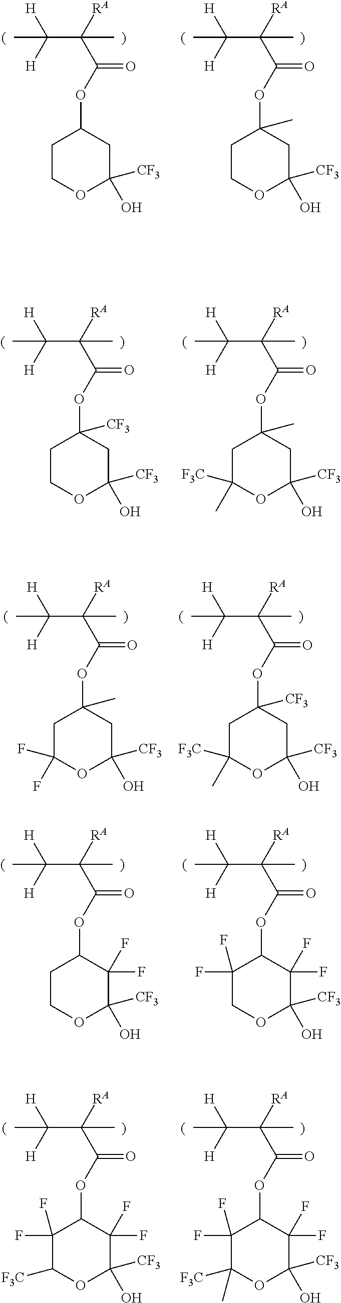

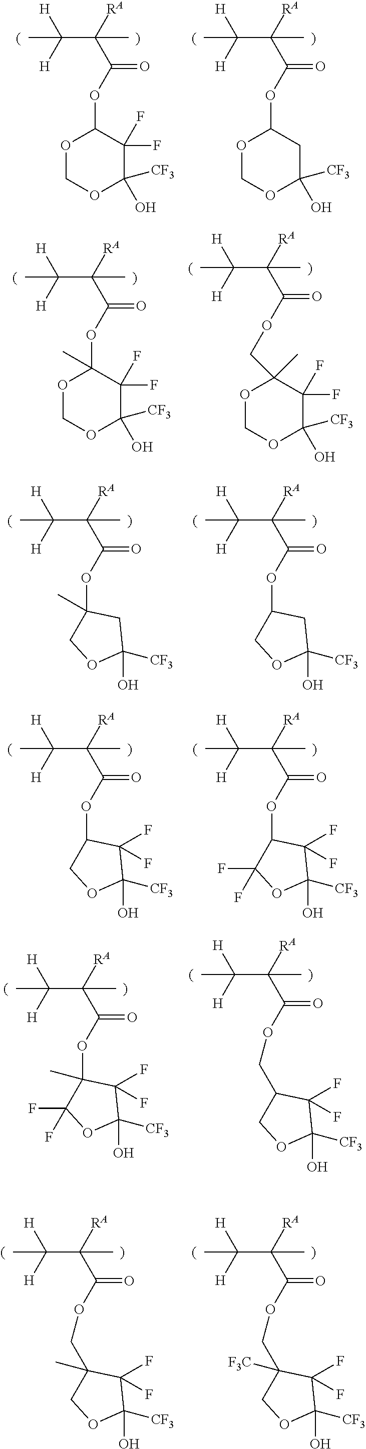

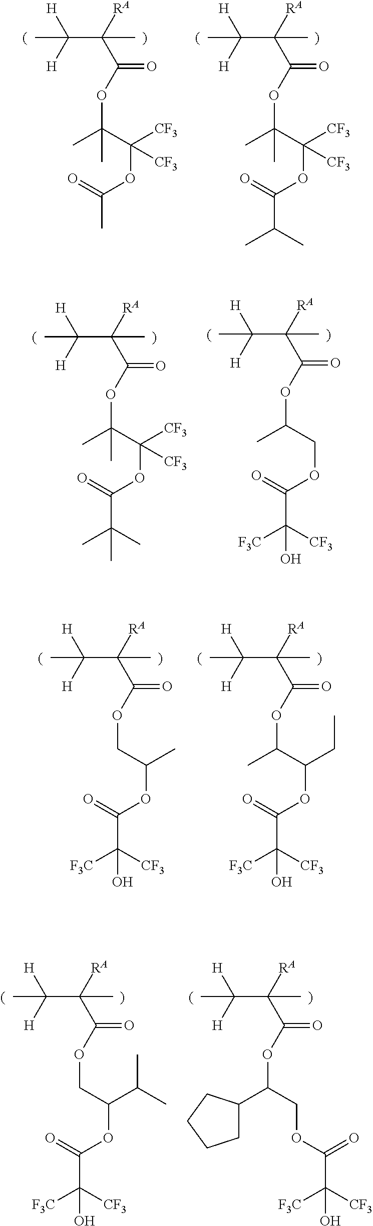

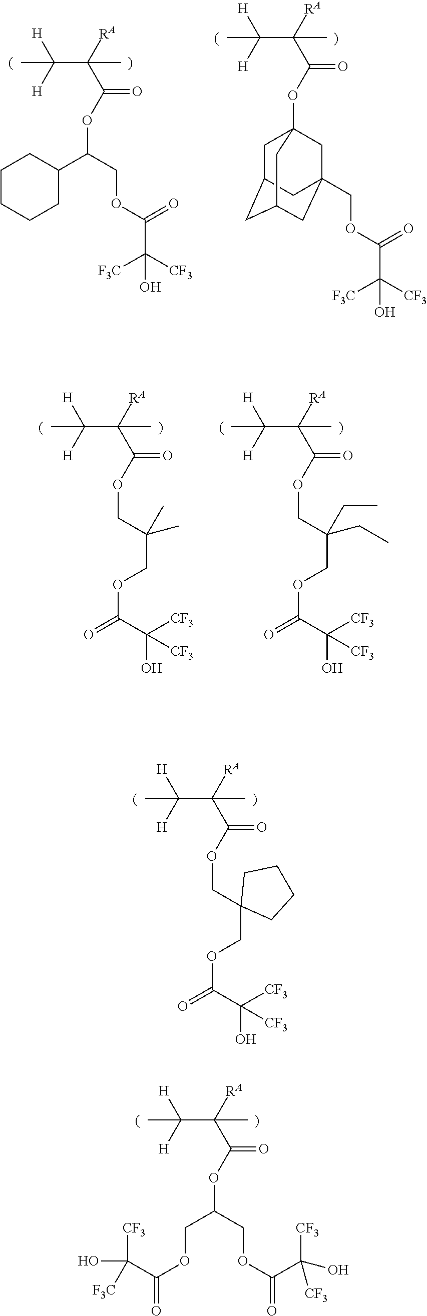

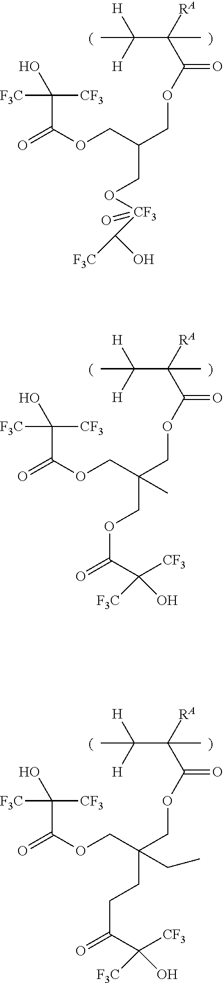

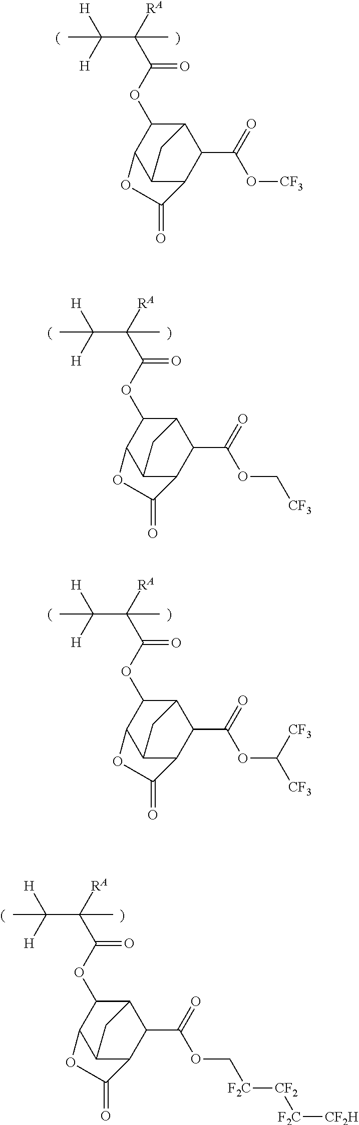

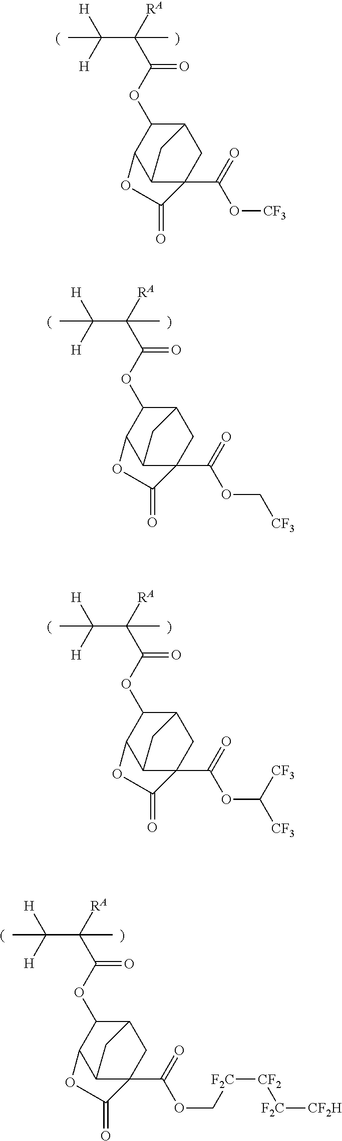

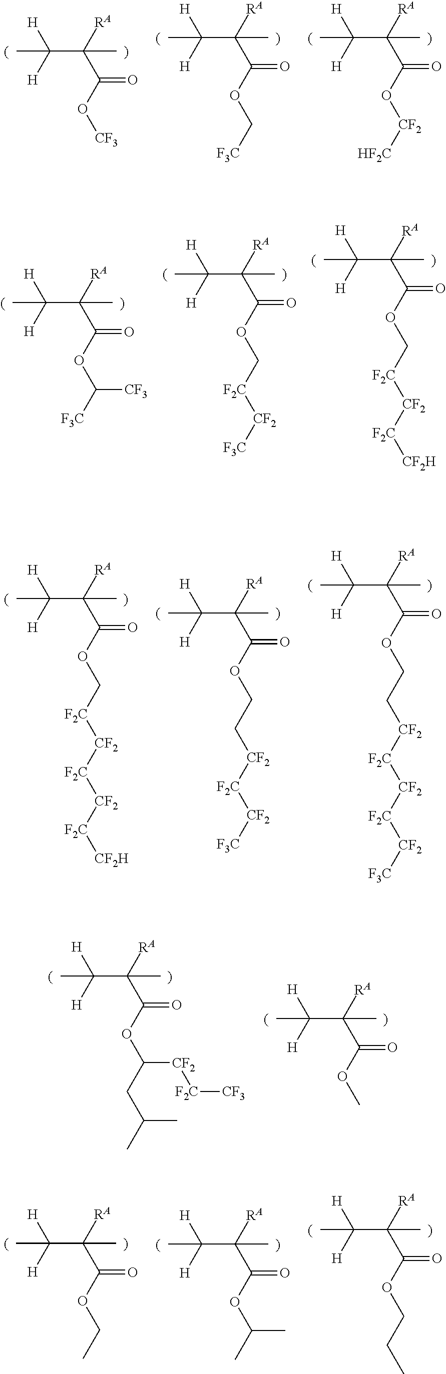

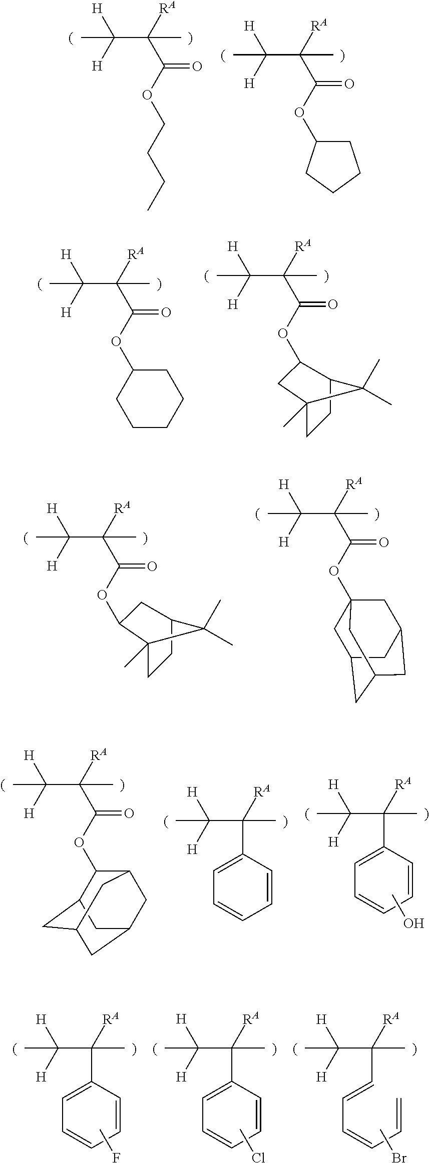

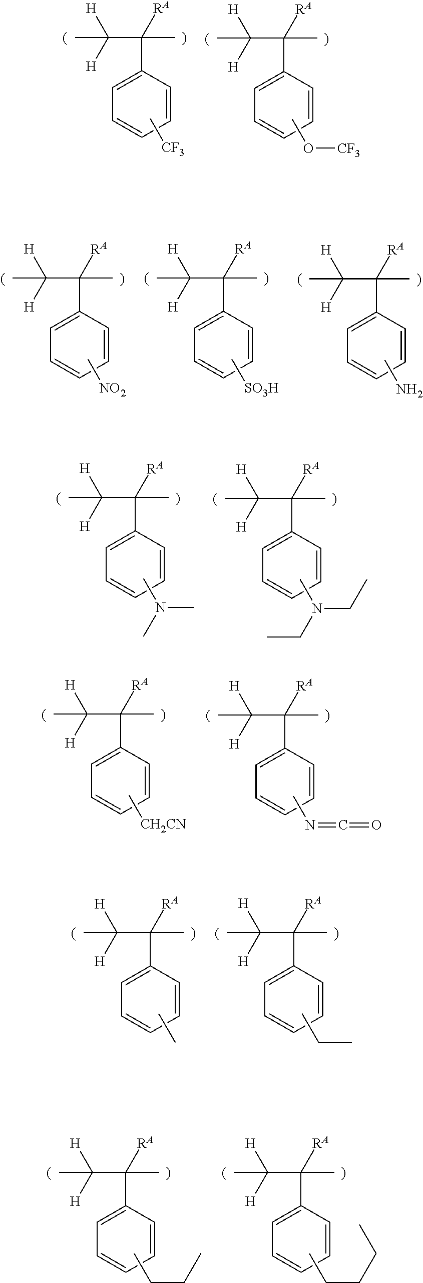

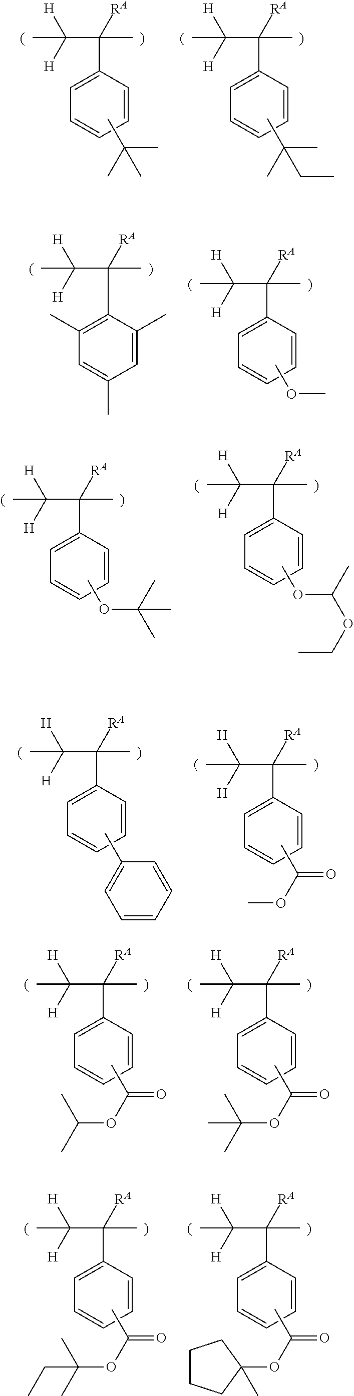

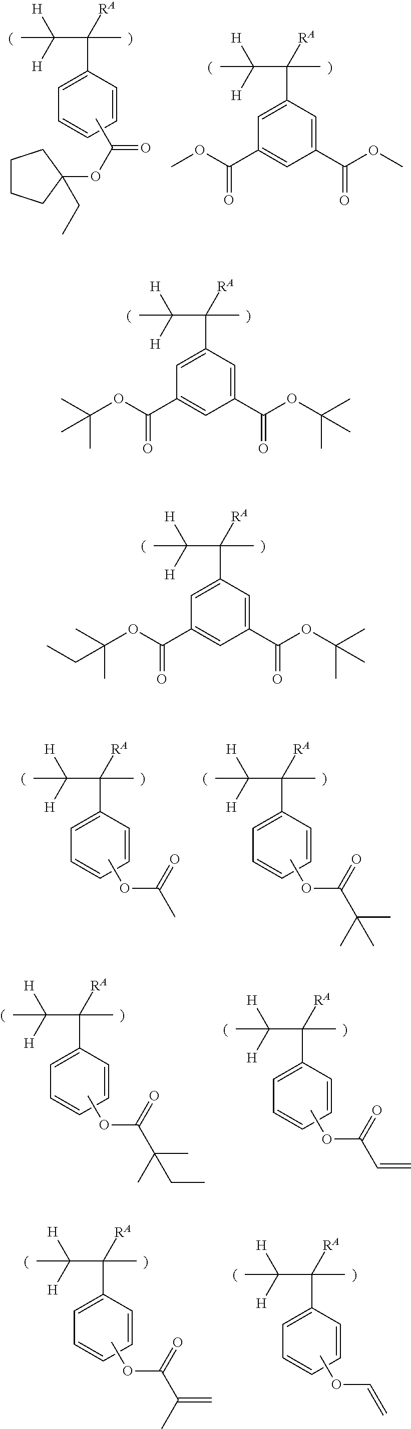

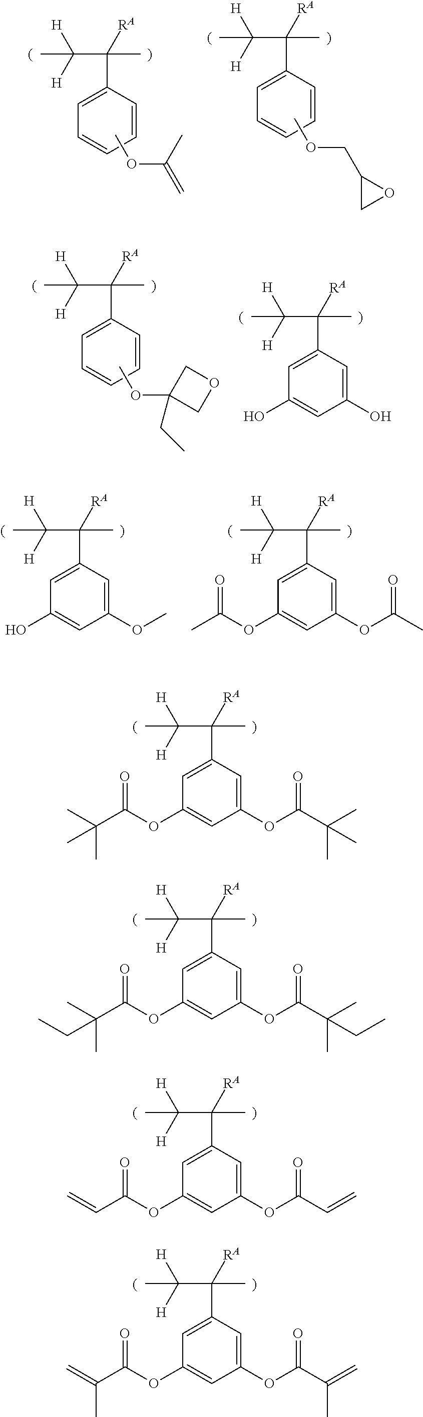

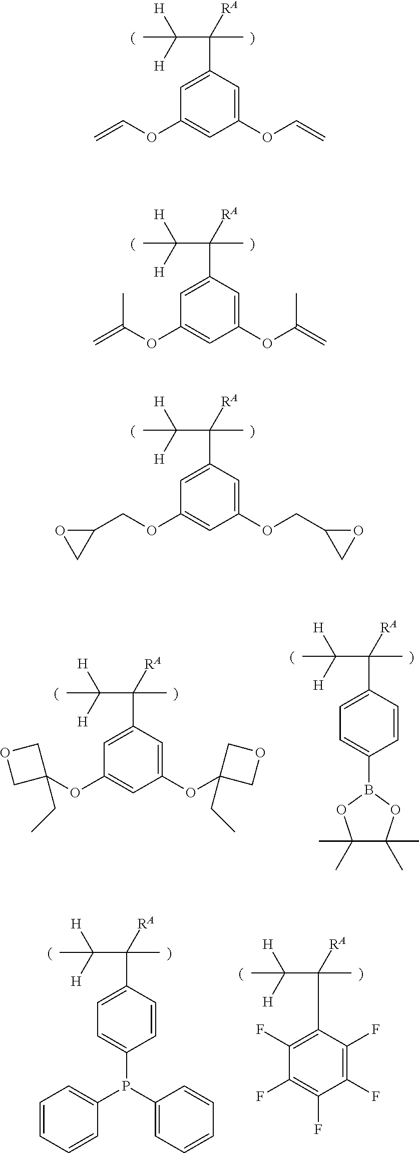

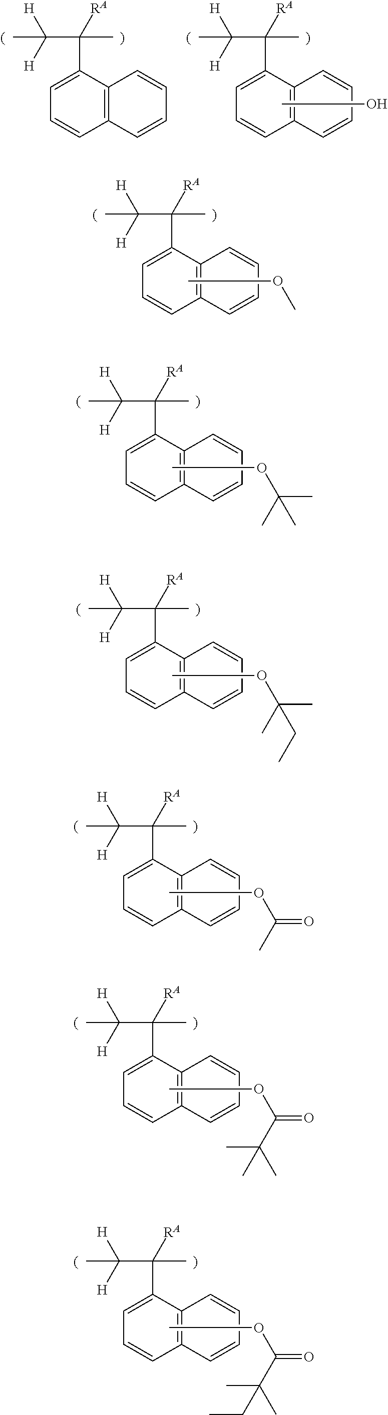

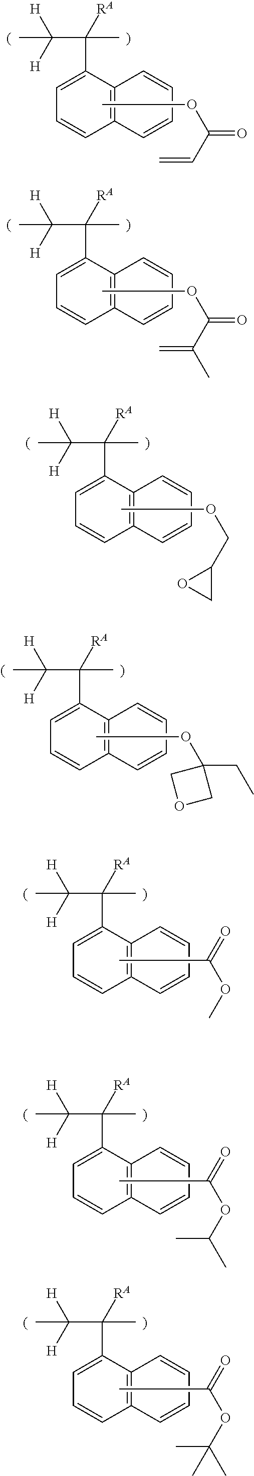

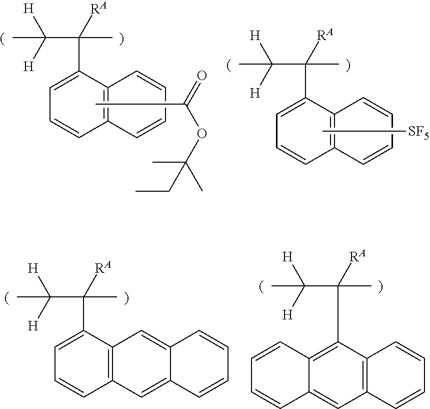

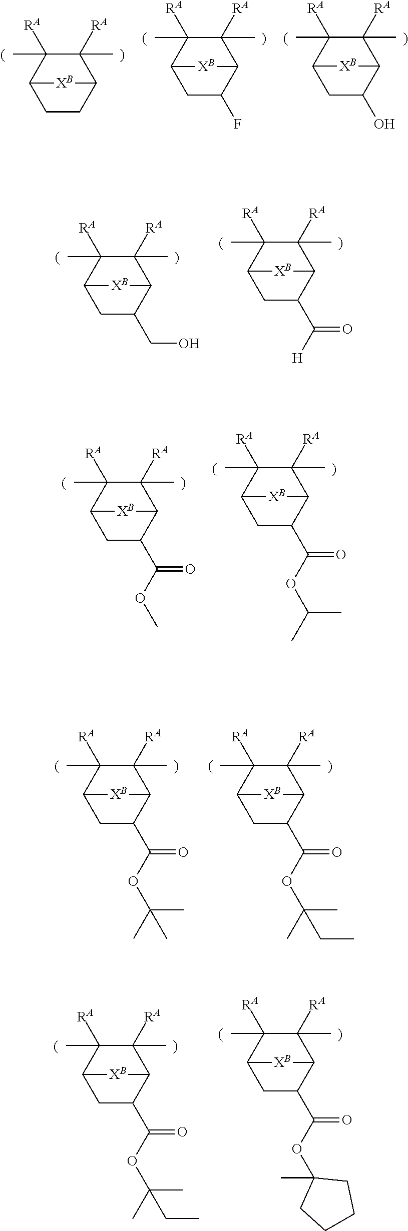

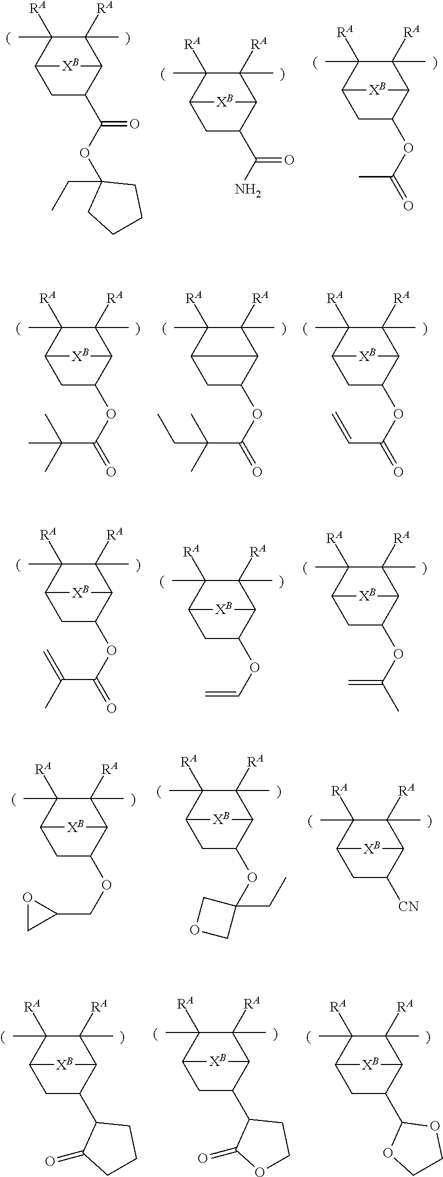

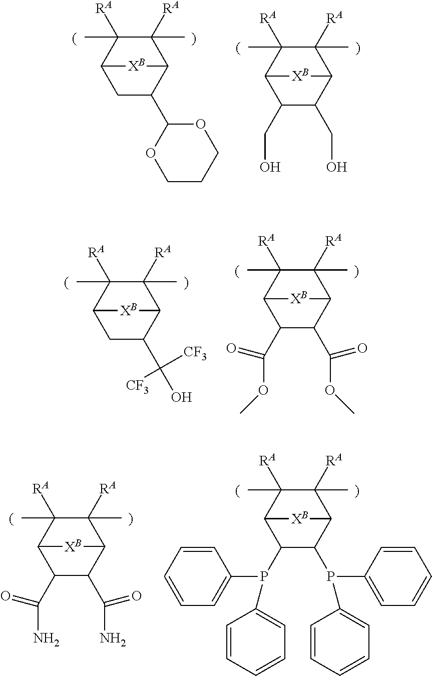

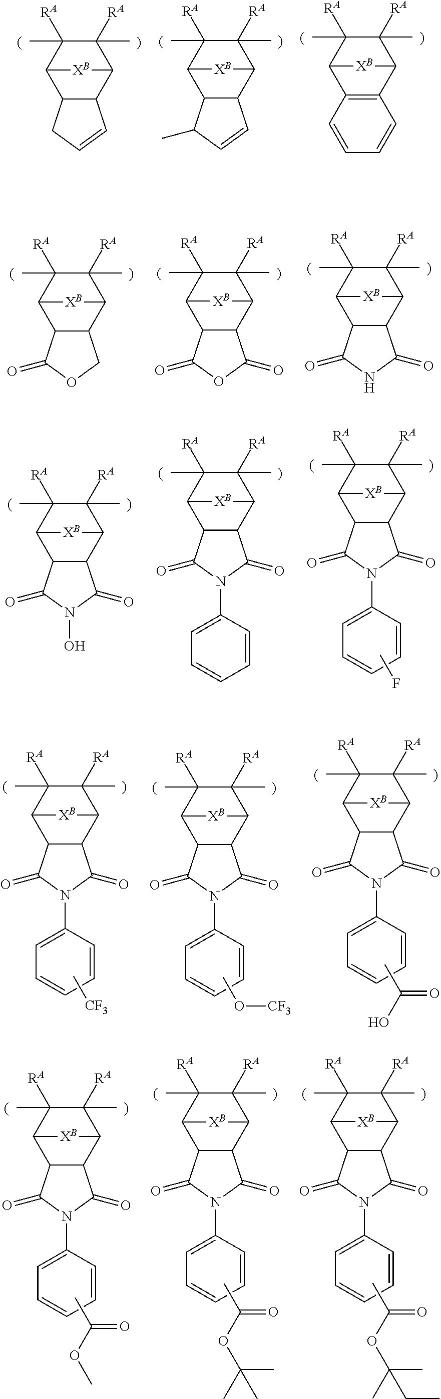

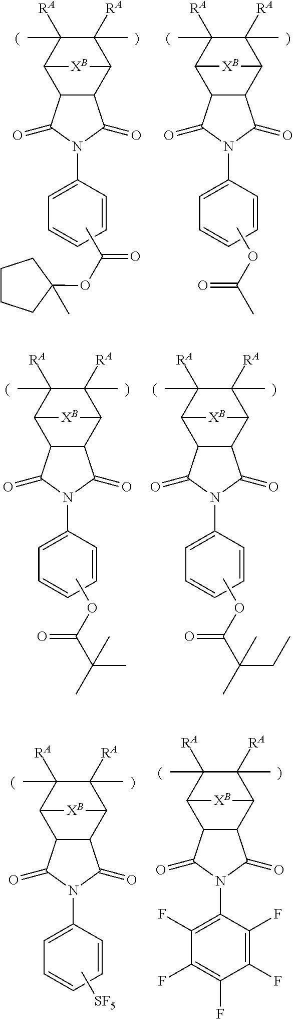

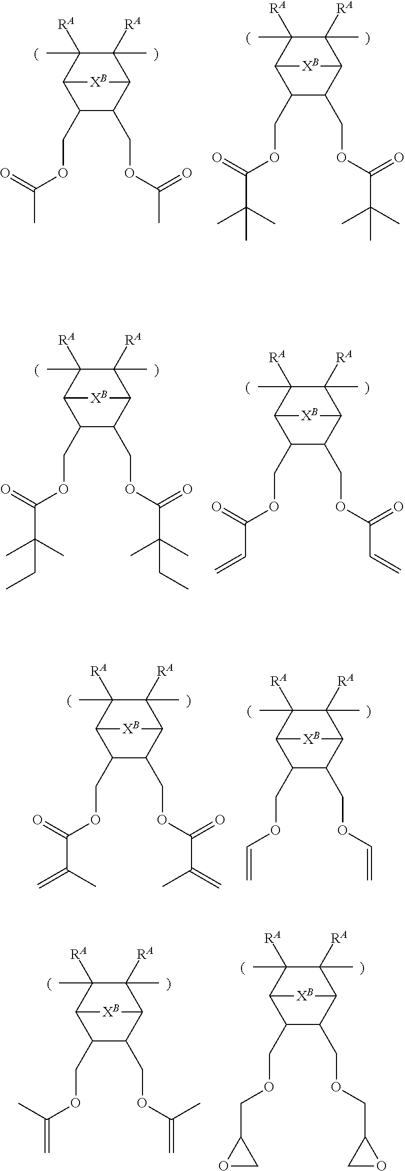

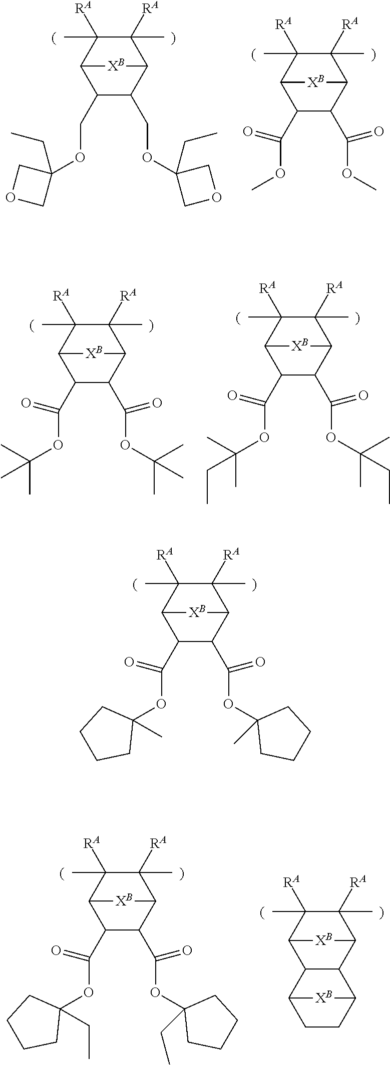

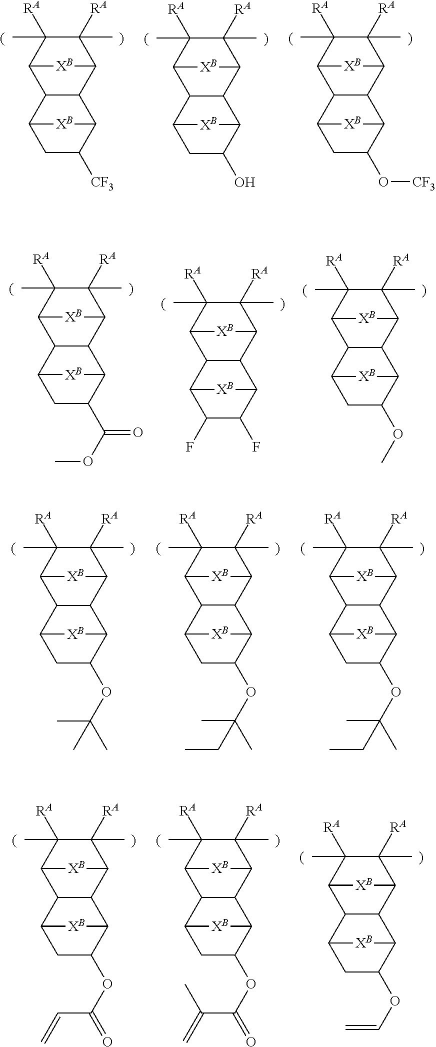

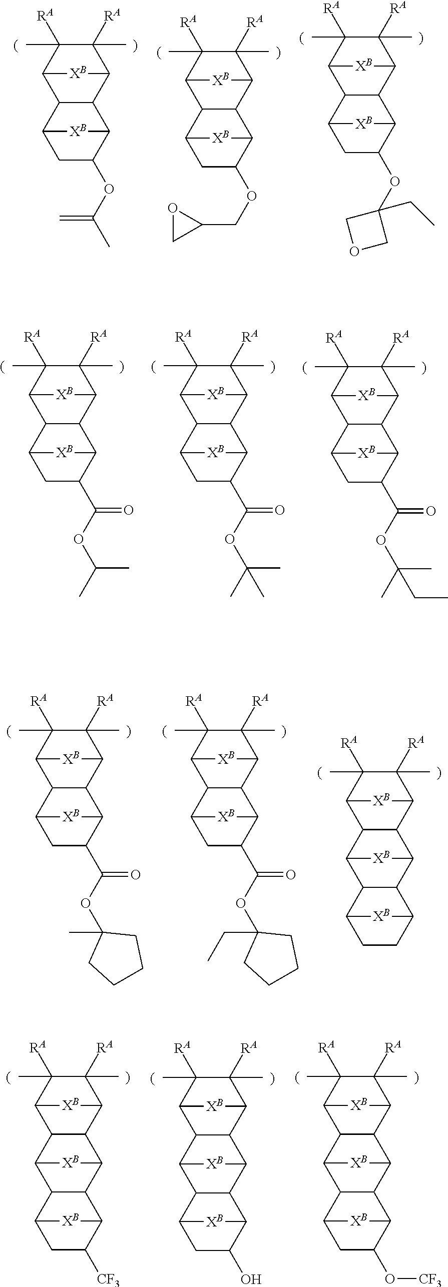

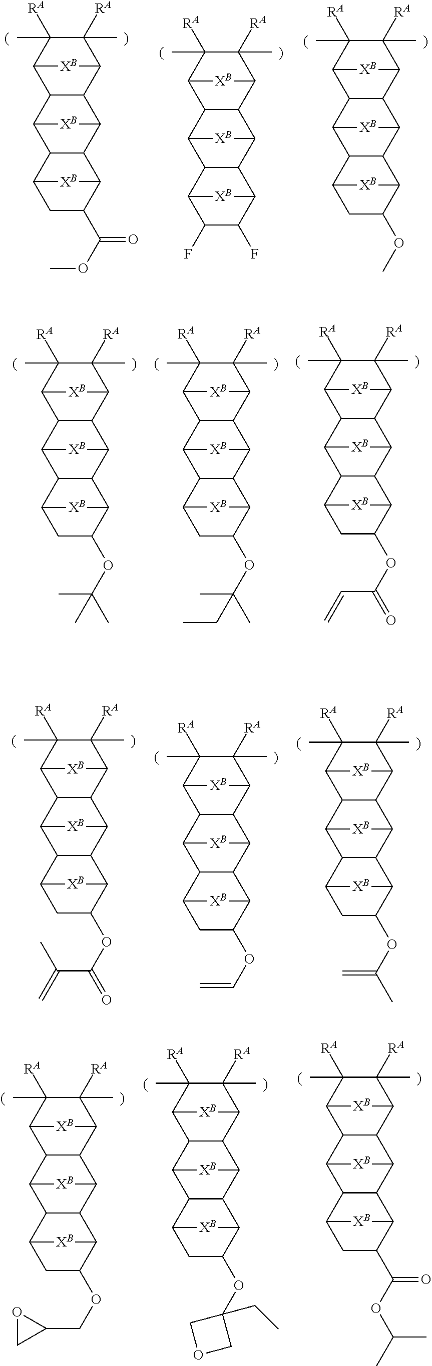

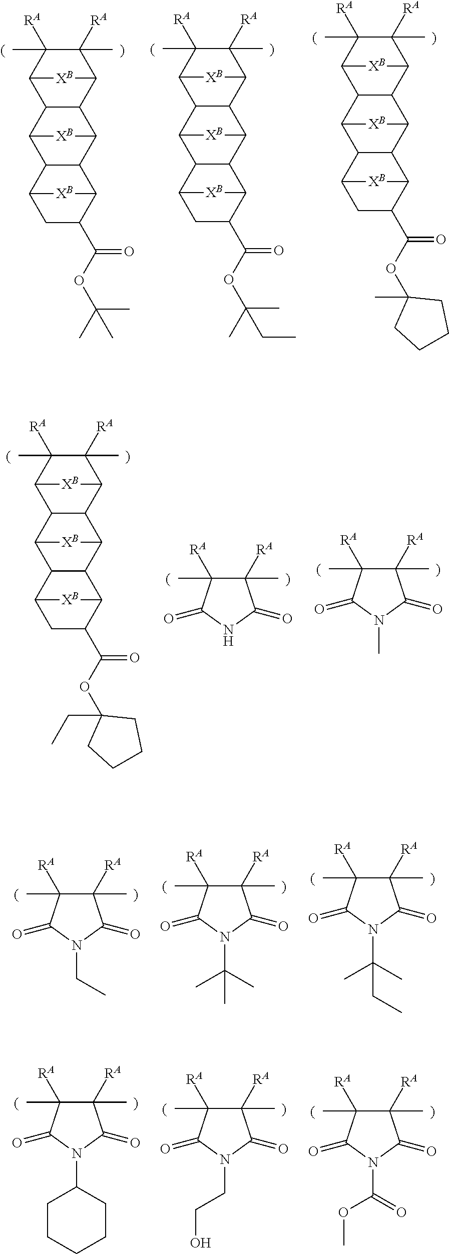

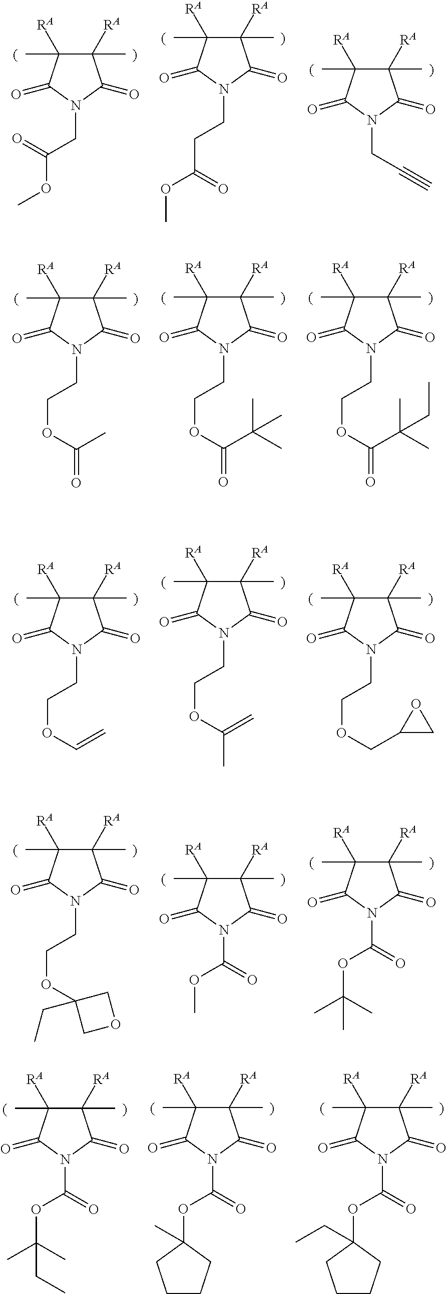

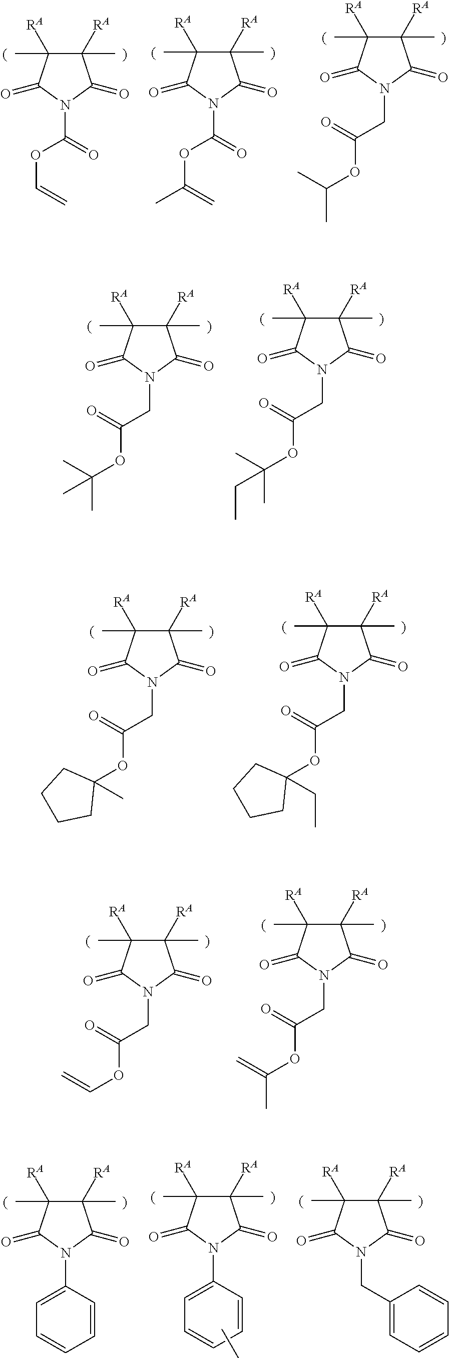

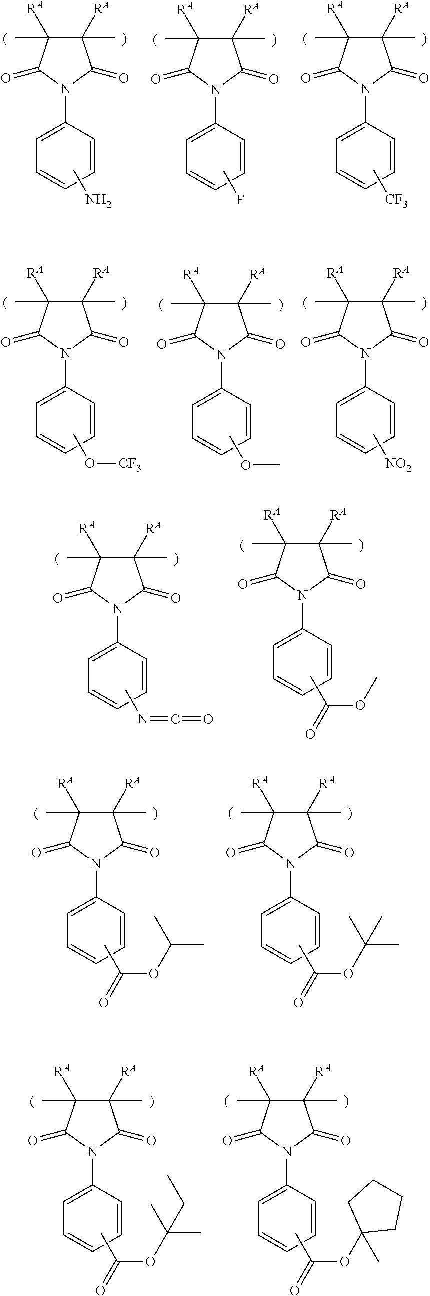

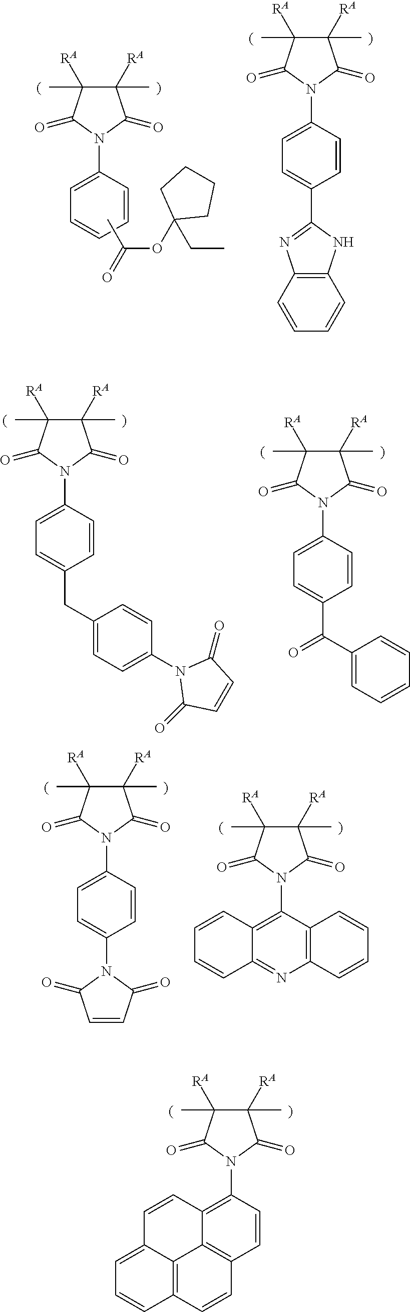

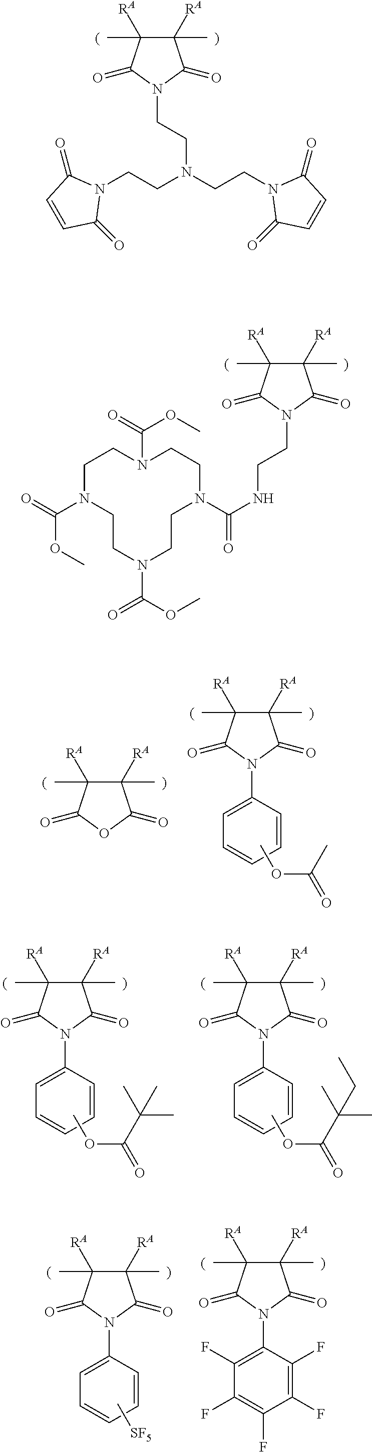

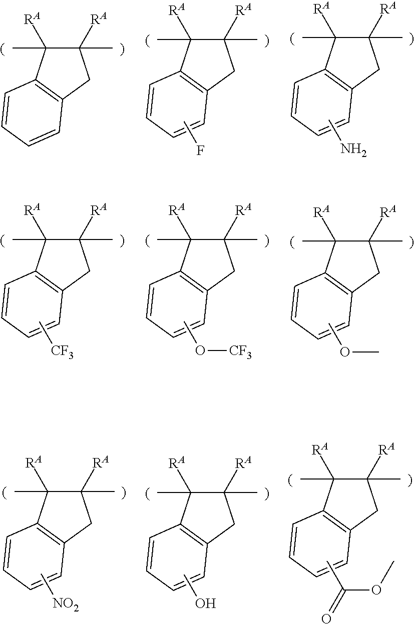

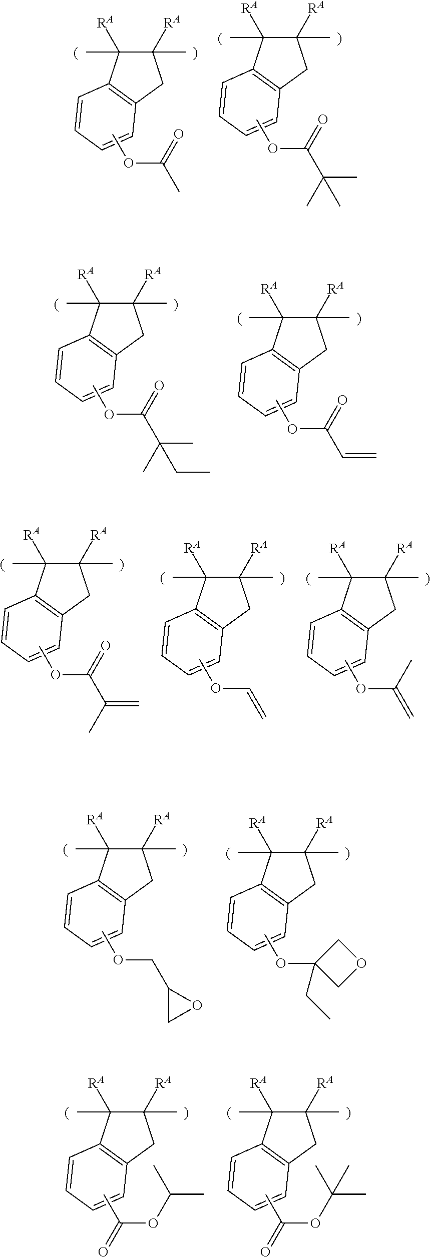

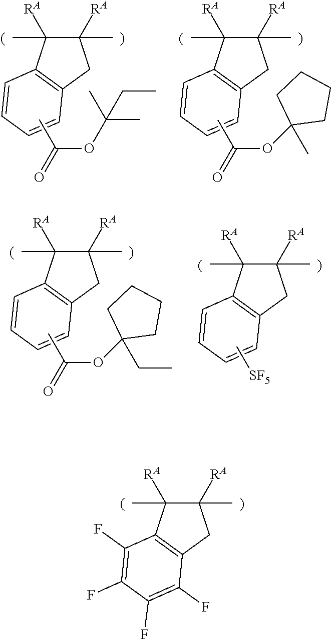

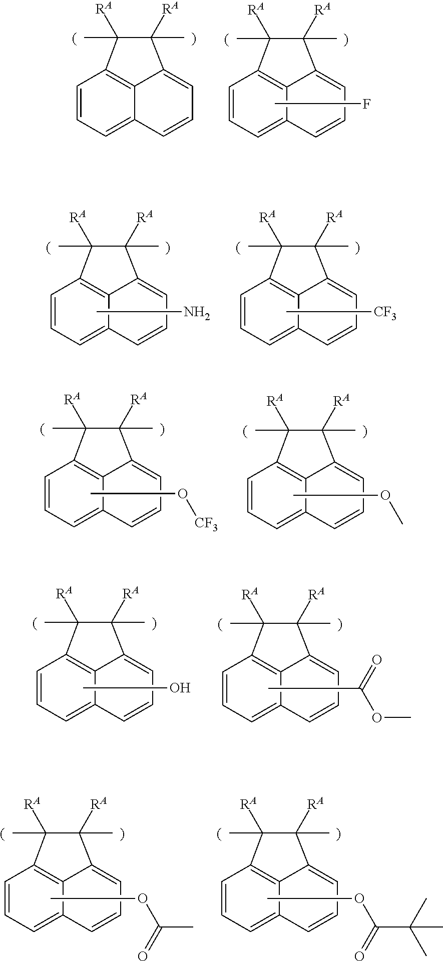

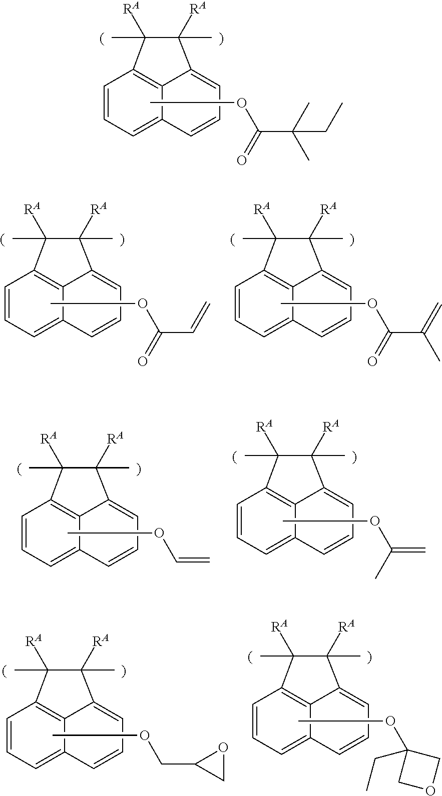

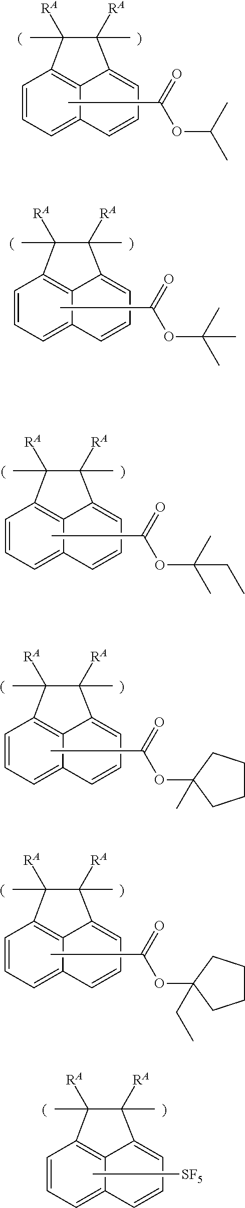

In the carboxy group-containing polymer, the carboxy group-containing repeat unit and another repeat unit are preferably present in a content ratio (molar ratio) of carboxy group-containing repeat unit: another repeat unit=10:90 to 90:10, more preferably 15:85 to 85:15, and still more preferably 20:80 to 80:20.

The carboxy group-containing polymer preferably has a weight average molecular weight (Mw) of 1000 to 500000, more preferably 3000 to 100000, and further preferably 3000 to 20000. In the invention, Mw and numerical average molecular weight (Mn) represent a value measured by gel permeation chromatography (GPC) versus polystyrene standards using tetrahydrofuran (THF) as a solvent, and the molecular weight distribution or dispersity (Mw/Mn) is a value determined therefrom. GPC is usually measured at room temperature around 23° C., but may be measured at higher or lower temperatures.

If the carboxy group-containing polymer has a wide Mw/Mn, which indicates the presence of lower and higher molecular weight polymer fractions, there is a possibility that foreign matter is left on the pattern or the pattern profile is degraded after exposure. The influences of Mw and Mw/Mn become stronger as the pattern rule becomes finer. Therefore, the carboxy group-containing polymer should preferably have a narrow dispersity (Mw/Mn) of 1.0 to 2.0 in order to provide a resist composition suitable for micropatterning to a small feature size.

Examples of the method of synthesizing the carboxy group-containing polymer include a method in which monomers corresponding to the foregoing repeat units are dissolved in an organic solvent, a radical polymerization initiator is added thereto, and the resulting mixture is heated for polymerization.

Examples of the organic solvent used in the polymerization reaction include toluene, benzene, THF, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of such a polymerization initiator added is preferably 0.01 to 25 mol % per total amount of monomers to be polymerized. The reaction temperature is preferably 50 to 150° C., and more preferably 60 to 100° C. The reaction time is preferably 2 to 24 hours, and more preferably 2 to 12 hours from the viewpoint of production efficiency.

The polymerization initiator may be added to the monomer solution before supply to a reaction vessel, or an initiator solution may be prepared separately from the monomer solution and each solution may be supplied to a reaction vessel independently. Radicals generated from the initiator during waiting time may promote a polymerization reaction to generate an ultrahigh polymer. Therefore, from the viewpoint of quality control, each of the monomer solution and the initiator solution is preferably prepared and added dropwise independently. Further, a known chain transfer agent such as dodecyl mercaptan or 2-mercaptoethanol may be used in combination for adjusting the molecular weight. In this case, the amount of such a chain transfer agent added is preferably 0.01 to 20 mol % per total amount of monomers to be polymerized.

The amount of each monomer in the monomer solution is to be appropriately set, for example, so as to achieve the foregoing preferred content ratio of the repeat unit.

In the resist composition, the content ratio of the hypervalent iodine compound to the carboxy group-containing compound (when the carboxy group-containing compound is a carboxy group-containing polymer, the content ratio of the hypervalent iodine compound to the carboxylic acid-containing repeat unit in the polymer) is, in terms of molar ratio, preferably hypervalent iodine compound: carboxy group-containing compound=10:90 to 90:10, more preferably 20:80 to 80:20, and still more preferably 30:70 to 70:30. The hypervalent iodine compound may be used alone or in admixture of two or more. The carboxy group-containing polymer may be used alone or in admixture of two or more having different composition ratios and different values of Mw and/or Mw/Mn. The carboxylic acid having the formula (a-2) may be used alone or in admixture of two or more. One of the carboxy group-containing polymer and the carboxylic acid having the formula (a-2) may be used, or they may be used in combination.

The total of the hypervalent iodine compound and the carboxy group-containing compound is preferably 30 to 100% by weight, more preferably 50 to 100% by weight, still more preferably 80 to 100% by weight, further preferably 90 to 100% by weight, further preferably 95 to 100% by weight, and most preferably 98 to 100% by weight, based on the overall solids of the inventive resist composition.

### [Solvent]

The resist composition contains a solvent. The solvent is not particularly limited as long as the hypervalent iodine compound, the carboxy group-containing compound, and other components described below are dissolvable therein and a film can be formed from the resulting solution. The solvent is preferably an organic solvent, and examples of the organic solvent include ketones such as cyclohexanone, methyl-2-n-pentyl ketone, and methyl isoamyl ketone; alcohols such as 3-methoxybutanol, 3-methyl-3-methoxybutanol, 1-methoxy-2-propanol, 1-ethoxy-2-propanol, diacetone alcohol, 4-methyl-2-pentanol, and methyl 2-hydroxyisobutyrate; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; carboxylic acids such as formic acid, acetic acid, and propionic acid, lactones such as γ-butyrolactone, and mixtures thereof.

In the resist composition, the solvent is preferably present in such an amount that the resist composition may have a solids concentration of 0.1 to 20% by weight, more preferably 0.1 to 15% by weight, even more preferably 0.1 to 10% by weight. As used herein, the term solids is a general term for all components in the resist composition excluding the solvent. The solvent may be used alone or in admixture of two or more.

### [Other Components]

The resist composition may further contain a surfactant. The surfactant is preferably a fluorine-based and/or silicone-based surfactant. Exemplary surfactants are described, for example, in US 2008/0248425, paragraph [0276]. Also useful are surfactants other than the fluorine-based and/or silicone-based surfactants, as described, for example, in US 2008/0248425, paragraph [0280].

When contained in the resist composition, the surfactant is preferably present in an amount of 0.0001 to 2% by weight based on the overall solids. The surfactant may be used alone or in admixture of two or more.

The resist composition may further contain a radical scavenger. When added, the radical scavenger is effective for controlling photo-reaction and adjusting sensitivity during photolithography.

Suitable radical scavengers include hindered phenols, quinones, hindered amines, and thiol compounds. Exemplary hindered phenols include dibutylhydroxytoluene (BHT) and 2,2′-methylenebis(4-methyl-6-tert-butylphenol). Exemplary quinones include 4-methoxyphenol (or methoquinone) and hydroquinone. Exemplary hindered amines include 2,2,6,6-tetramethylpiperidine and 2,2,6,6-tetramethylpiperidine-N-oxy radical. Exemplary thiol compounds include dodecanethiol and hexadecanethiol.

When contained in the resist composition, the radical scavenger is preferably present in an amount of 0.01 to 10% by weight based on the overall solids. The radical scavenger may be used alone or in admixture of two or more.

The resist composition may further contain a crosslinking agent. When added, the crosslinking agent promotes the crosslinking reaction during photolithography to improve the glass transition point of the pattern, thereby obtaining a pattern with excellent fine line resolution.

Suitable crosslinking agents include compounds having a carbon-carbon unsaturated bond as a functional group, such as vinyl, (meth)acrylate, allyl, alkynyl, and aromatic ring. Exemplary compounds having a vinyl group include straight, branched, and cyclic alkenes, each of which may have a substituent. Exemplary compounds having a (meth)acrylate group include acrylic acid, methacrylic acid, an acrylic acid ester, and a methacrylic acid ester, each of which may have a substituent. Exemplary compounds having an allyl group include an allyl alcohol, an allyl ether, an allyl ester, an allyl amide, an allylamine, and an allyl group-containing isocyanurate, each of which may have a substituent. Exemplary compounds having an alkynyl group include straight, branched, and cyclic alkynes, an alkynyl alcohol, an alkynyl ether, an alkynyl ester, an alkynyl amide, an alkynyl amine, and an alkynyl group-containing isocyanurate, each of which may have a substituent. Exemplary compounds having an aromatic ring include arenes, heteroarenes, styrene, stilbene, phenylacetylene, acenaphthylene, and chalcone, each of which may have a substituent. The crosslinking agent may have only one of the functional groups described above, or may have a plurality of the functional groups. The number of the functional groups contained in the crosslinking agent is preferably 1 or more and 10 or less, and more preferably 2 or more and 8 or less.

When contained in the resist composition, the crosslinking agent is preferably present in an amount of 0.01 to 50% by weight based on the overall solids. The crosslinking agent may be used alone or in admixture of two or more.

When the resist composition contains the crosslinking agent, the resist composition may further contain a photopolymerization initiator (photoradical generator). The photopolymerization initiator can generate radicals by irradiation with high-energy radiation to promote crosslinking of the crosslinking agent.

Exemplary photopolymerization initiators include benzophenone derivatives such as benzophenone, methyl O-benzoylbenzoate, 4-benzoyl-4′-methyl diphenyl ketone, dibenzyl ketone, and fluorenone; acetophenone derivatives such as 2,2′-diethoxyacetophenone, 2-hydroxy-2-methylpropiophenone, 2,2-dimethoxy-1,2-diphenylethane-1-one, 1-hydroxycyclohexyl phenyl ketone, 2-methyl-1-[4-(methylthio)phenyl]-2-morpholinopropane-1-one, 2-hydroxy-1-{4-[4-(2-hydroxy-2-methylpropionyl)-benzyl]-phenyl}-2-methylpropane-1-one, and methyl phenylglyoxylate; thioxanthone derivatives such as thioxanthone, 2-methylthioxanthone, 2-isopropylthioxanthone, 4-isopropylthioxanthone, 2-chlorothioxanthone, and diethylthioxanthone; benzyl derivatives such as benzyl, benzyl dimethyl ketal, and benzyl-β-methoxyethyl acetal; benzoin derivatives such as benzoin, benzoin methyl ether, and 2-hydroxy-2-methyl-1-phenylpropane-1-one; oxime-based compounds such as 1-phenyl-1,2-butanedione-2-(O-methoxycarbonyl) oxime, 1-phenyl-1,2-propanedione-2-(O-methoxycarbonyl) oxime, 1-phenyl-1,2-propanedione-2-(O-ethoxycarbonyl) oxime, 1-phenyl-1,2-propanedione-2-(O-benzoyl) oxime, 1,3-diphenylpropanetrione-2-(O-ethoxycarbonyl) oxime, 1-phenyl-3-ethoxypropanetrione-2-(O-benzoyl) oxime 1,2-octanedione, 1-[4-(phenylthio)-2-(O-benzoyloxime)]ethanone, 1-[9-ethyl-6-(2-methylbenzoyl)-9H-carbazole-3-yl]-1-(O-acetyloxime); α-hydroxyketone compounds such as 2-hydroxy-2-methyl-1-phenylpropane-1-one, 1-[4-(2-hydroxyethoxy)phenyl]-2-hydroxy-2-methyl-1-propane-1-one, and 2-hydroxy-1-{4-[4-(2-hydroxy-2-methylpropionyl)-benzyl]phenyl}-2-methylpropane; α-aminoalkylphenone-based compounds such as 2-benzyl-2-dimethylamino-1-(4-morpholinophenyl)-butanone-1,2-dimethylamino-2-(4-methylbenzyl)-1-(4-morpholine-4-yl-phenyl) butane-1-one; phosphine oxide-based compounds such as bis(2,4,6-trimethylbenzoyl)-phenylphosphine oxide, bis(2,6-dimethoxybenzoyl)-2,4,4-trimethyl-pentylphosphine oxide, and 2,4,6-trimethylbenzoyldiphenylphosphine oxide; and titanocene compounds such as bis(n5-2,4-cyclopentadiene-1-yl)-bis(2,6-difluoro-3-(1H-pyrrole-1-yl)phenyl) titanium.

When contained in the resist composition, the photopolymerization initiator is preferably present in an amount of 0.1 to 10% by weight, more preferably 0.1 to 5% by weight, and most preferably 0.1 to 1% by weight, based on the overall solids. When the content is 0.1% by weight or more, the blending effect can be sufficiently obtained.

The resist composition contains the hypervalent iodine compound and the carboxy group-containing compound as main components, but not a polymer containing an acid labile group and a photoacid generator as used in conventional chemically amplified resist compositions. Nevertheless, the resist composition, especially when exposed to EB or EUV, can form a positive pattern, where the exposed region is dissolved in a developer, or a negative pattern, where the exposed region is not dissolved in a developer. Although its mechanism is not well understood, the following mechanism is presumed.

The hypervalent iodine compound is a three-coordinate compound having an aryl group and carboxylate ligands. When such a three-coordinate iodine compound is mixed with a carboxy group-containing compound, replacement of carboxylate ligands takes place as equilibration reaction. If the original carboxylate ligands are removed by any suitable means, a hypervalent iodine compound having new ligands is created. For example, if 1-iodonaphthylene diacetate as a hypervalent iodine compound is mixed with a carboxy group-containing compound, and the resulting low-boiling point acetic acid is removed, then ligand exchange is completed. Here, the carboxy group-containing compound is crosslinked with the hypervalent iodine compound to form a polymer.

The polymer crosslinked with the hypervalent iodine compound is generated during film formation. This is because even if synthesized in advance, such a crosslinked polymer is insoluble in most organic solvents, so that it is impossible to prepare their solution. This is presumed to be because the hypervalent iodine compound, which is originally low in solvent solubility due to the large polarization, further deteriorates in solubility by using a carboxy group-containing compound as a ligand. Therefore, it is desirable that the original low-molecular-weight carboxylic acid is removed during film formation and a subsequent bake step to complete a ligand exchange reaction and form a resist film in the step.

In the resist film obtained from the resist composition, the hypervalent iodine compound as the main component is decomposed with light to change the polarity, so that a pattern is formed in the development step. Although its mechanism is not well understood, the following mechanism is presumed.

The resist composition contains a polymer crosslinked with the hypervalent iodine compound, which is generated during film formation. The polymer is decomposed by light, and undergoes crosslinking or bond replacement, so that the molecular weight is increased or the polarity is converted. As a result, it is presumed that a negative pattern is formed, where the unexposed region is removed by a developer containing an organic acid.

The resist composition can be a negative tone also when developed with an aqueous alkali solution. However, an aqueous alkali solution can slightly decompose the crosslink newly formed in the exposed region or the bond after bond replacement. Therefore, the exposed region easily swells in a developer. On the other hand, in the present invention, it is considered that a developer containing an organic acid is used to prevent swelling, and makes it possible to form a pattern with excellent resolution.

From the foregoing presumption, the resist composition is regarded as falling in the concept of non-chemically amplified resist composition. The resist composition does not need a polymer containing an acid labile group or a photoacid generator as used in conventional chemically amplified resist compositions. Therefore, a small size pattern can be resolved without adverse effects from acid diffusion (for example, image blur).

The resist composition is quite effective in the EUV lithography. This is because an iodine atom having a high absorptivity to EUV radiation is included. That is, shot noise is reduced, and higher resolution and lower LWR are achievable.

As the EUV lithography resist composition capable of forming a small size pattern, a metal resist composition based on a metal (specifically tin) compound having a high absorptivity to EUV radiation like iodine atom is known, for example, from Patent Document 2. However, the metal resist composition suffers from many problems including a lack of solvent solubility, poor shelf stability, and defects in the form of post-etching residues due to the containment of metal elements, as discussed previously. In contrast, since the resist composition does not use metal elements, it is advantageous in defectiveness over the metal resist and eliminates the problem of solvent solubility. Furthermore, the resist composition, applicable to positive tone, has a wide range of use. For example, in a contact hole forming step, a metal resist that is subjected to negative development requires a reversal processing step after a pillar pattern is formed. However, a positive resist does not need such a step. Therefore, also from the viewpoint of process simplicity, the resist composition is regarded more useful than a metal resist.

### [Resist Pattern Forming Process]

The inventive resist pattern forming process includes the steps of:
(i) applying a resist composition containing: a hypervalent iodine compound; a carboxy group-containing compound; and a solvent onto a substrate or onto an underlayer film laminated on a substrate to form a resist film,
(ii) exposing the resist film to high-energy radiation, and
(iii) developing the exposed resist film with a developer containing an organic acid to form a negative pattern.

### Step (i)

The step (i) is a step of applying the above-described resist composition onto a substrate or onto an underlayer film laminated on a substrate to form a resist film. Specifically, the resist composition is applied onto a substrate for integrated circuit fabrication (e.g., Si, SiO₂, SiN, SION, TIN, WSi, BPSG, SOG, or organic antireflective coating) or onto an underlayer film laminated on the substrate, or onto a substrate for mask circuit fabrication (e.g., Cr, CrO, CrON, MoSi₂, or SiO₂) or onto an underlayer film laminated on the substrate, by any suitable technique such as spin coating, roll coating, flow coating, dip coating, spray coating or doctor coating. The coating is prebaked on a hot plate at a temperature of preferably 60 to 200° C. for 10 seconds to 30 minutes, more preferably at 80 to 180° C. for 30 seconds to 20 minutes to form a resist film having a thickness of 0.01 to 2 μm. The underlayer film means a film formed between the substrate and the resist film in the multilayer resist process. The underlayer film is not particularly limited, and a conventionally known film can be used.

The resist film preferably has a thickness of 10 to 70 nm, more preferably 20 to 50 nm.

### Step (ii)

The step (ii) is a step of exposing the resist film to high-energy radiation. Examples of the high-energy radiation include UV (g-ray (436 nm), h-ray (405 nm), i-ray (365 nm), and the like), deep UV, EB, EUV, X-ray, soft X-ray, excimer laser radiation (KrF and ArF excimer laser beam, and the like), γ-ray, and synchrotron radiation. The high-energy radiation is preferably i-ray, KrF excimer laser beam, ArF excimer laser beam, electron beam, or extreme ultraviolet ray. On use of UV, deep UV, EUV, X-ray, soft X-ray, excimer laser radiation, γ-ray, and synchrotron radiation as the high-energy radiation, the resist film is exposed thereto directly or through a mask having the desired pattern so as to reach a dose of preferably about 1 to 300 mJ/cm², more preferably about 10 to 200 mJ/cm². On use of EB as the high-energy radiation, imagewise writing is performed directly or through a mask having the desired pattern so as to reach a dose of preferably about 0.1 to 8000 μC/cm², more preferably about 0.5 to 5000 μC/cm². The resist composition is best suited for micropatterning using EB or EUV as the high-energy radiation.

After the exposure, PEB is performed as necessary. At this time, after the exposure, PEB is preferably performed on a hot plate or in an oven under the conditions of 30 to 200° C. for 10 seconds to 30 minutes, more preferably 60 to 180° C. for 30 seconds to 20 minutes.

Step (iii)

The step (iii) is a step of developing the exposed resist film with a developer containing an organic acid to form a negative pattern.

The organic acid contained in the developer preferably contains at least one selected from the compounds having any of the formulae (b-1) to (b-7).

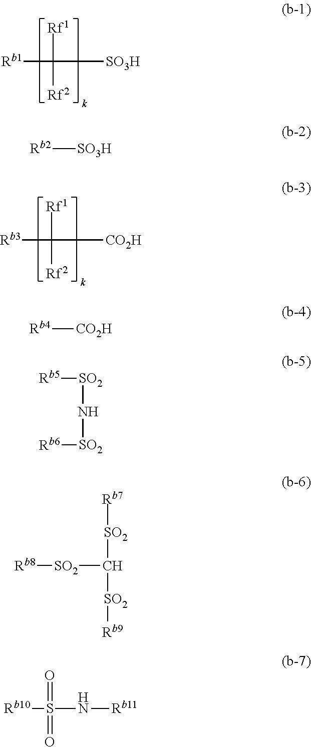

In the formulae (b-1) and (b-3), k is each independently 1, 2, 3, or 4. Rf¹ and Rf² are each independently a hydrogen atom, a fluorine atom, or a C₁-C₆ fluorine-containing alkyl group, excluding a case where all of Rf¹s and Rf²s are hydrogen atoms at the same time.

In the formula (b-1), R^{b1} is a hydrogen atom, a halogen atom, a hydroxy group, or a C₁-C₅₀ hydrocarbyl group which may contain a heteroatom.

In the formula (b-2), R^{b2} is a hydrogen atom, a halogen atom, a hydroxy group, or a C₁-C₅₀ hydrocarbyl group which may contain a heteroatom, excluding a case where hydrogen atoms on the carbon atoms at the α-position and the β-position of the sulfo group are substituted with a fluorine atom or a fluoroalkyl group.

In the formula (b-3), R^{b3} is a hydrogen atom, a halogen atom, a hydroxy group, or a C₁-C₅₀ hydrocarbyl group which may contain a heteroatom.

In the formula (b-4), R^{b4} is a hydrogen atom, a halogen atom, a hydroxy group, or a C₁-C₅₀ hydrocarbyl group which may contain a heteroatom, excluding a case where hydrogen atoms on the carbon atoms at the α-position and the β-position of the carboxy group are substituted with a fluorine atom or a fluoroalkyl group.

In the formula (b-5), R^{b5} and R^{b6} are each independently a C₁-C₅₀ hydrocarbyl group which may contain a heteroatom.

In the formula (b-6), R^{b7} to R^{b9} are each independently a C₁-C₅₀ hydrocarbyl group which may contain a heteroatom.

In the formula (b-7), R^{b10} is a fluorine atom or a C₁-C₁₀ fluorinated hydrocarbyl group, and the fluorinated hydrocarbyl group may contain a hydroxy group, an ether bond, or an ester bond. R^{b11} is a hydrogen atom or a C₁-C₂₀ hydrocarbyl group, and the hydrocarbyl group may contain a hydroxy group, an ether bond, or an ester bond. R^{b10} and R^{b11} may bond to each other to form a ring with the atoms to which they are attached.

The C₁-C₅₀ hydrocarbyl group of R^{b1}, R^{b2}, R^{b3}, R^{b4}, R^{b5}, R^{b6}, R^{b7}, R^{b8}, and R^{b9} may be saturated or unsaturated and straight, branched or cyclic. Examples thereof include C₁-C₅₀ alkyl groups such as methyl, ethyl, propyl, isopropyl, n-butyl, sec-butyl, tert-butyl, tert-pentyl, n-pentyl, n-hexyl, n-octyl, 2-ethylhexyl, n-nonyl, and n-decyl, C₃-C₅₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decyl, adamantyl, and adamantylmethyl, C₂— C₃₀ alkenyl groups such as vinyl, 1-propenyl, 2-propenyl, butenyl, and hexenyl, C₃-C₃₀ cyclic unsaturated hydrocarbyl groups such as cyclohexenyl, C₆-C₅₀ aryl groups such as phenyl, naphthyl, and anthracenyl, and combinations thereof. Also included are hydrocarbyl groups in which some or all of the hydrogen atoms are substituted by a moiety containing a heteroatom such as oxygen, sulfur, nitrogen or halogen, and some constituent —CH₂— is replaced by a moiety containing a heteroatom such as oxygen, sulfur or nitrogen, so that the group may contain hydroxy, cyano, halogen, carbonyl, ether bond, thioether bond, ester bond, sulfonic ester bond, carbonate bond, carbamate bond, lactone ring, sultone ring, or carboxylic anhydride (—C(═O)—O—C(═O)—).

The C₁-C₁₀ fluorinated hydrocarbyl group of R^{b10} is a group in which some or all of the hydrogen atoms of a C₁-C₁₀ hydrocarbyl group are substituted by a fluorine atom. The C₁-C₁₀ hydrocarbyl group may be saturated or unsaturated and straight, branched or cyclic. Examples thereof are the C₁-C₁₀ hydrocarbyl groups among those that are exemplified for the C₁-C₅₀ hydrocarbyl group of R^{b1}, R^{b2}, R^{b3}, R^{b4}, R^{b5}, R^{b6}, R^{b7}, R^{b8}, and R^{b9}.

The C₁-C₂₀ hydrocarbyl group of R^{b11} may be saturated or unsaturated and straight, branched or cyclic. Examples thereof are the C₁-C₂₀ hydrocarbyl groups among those that are exemplified for the C₁-C₅₀ hydrocarbyl group of R^{b1}, R^{b2}, R^{b3}, R^{b4}, R^{b5}, R^{b6}, R^{b7}, R^{b8}, and R^{b9}.

Examples of the compound having the formula (b-1) are shown below, but are not limited thereto. In the formulae, Ac is an acetyl group, and Rf¹ is the same as described

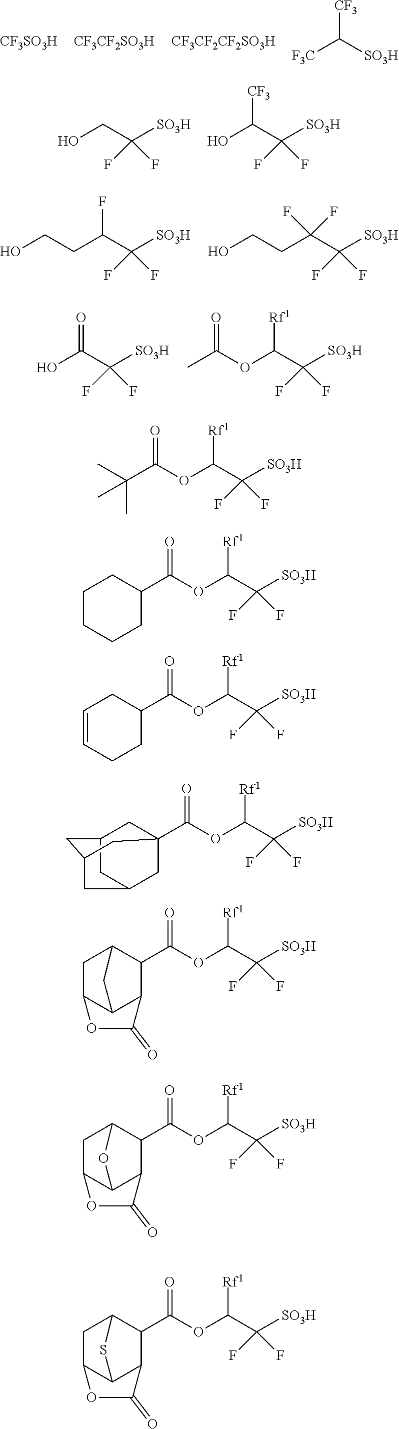

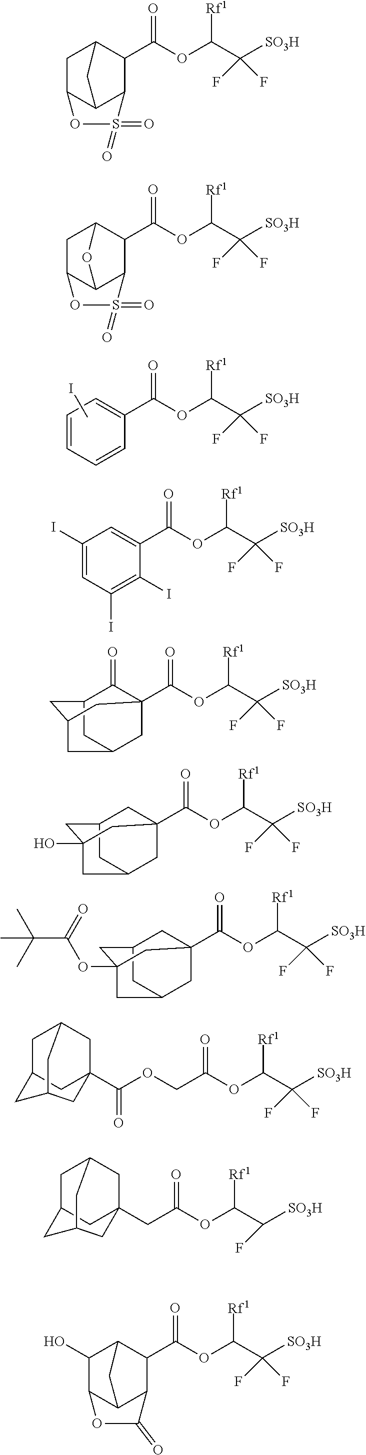

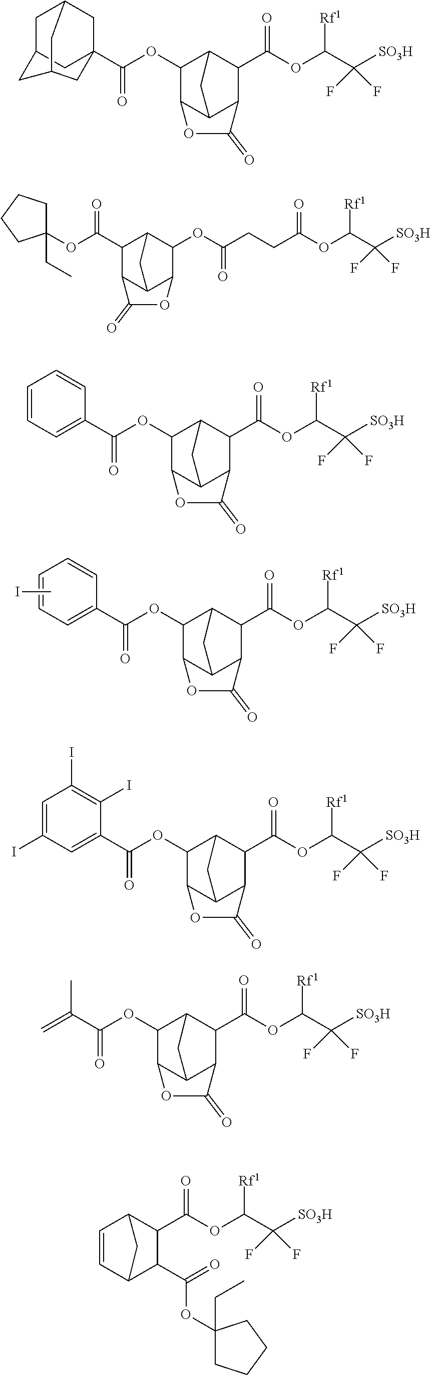

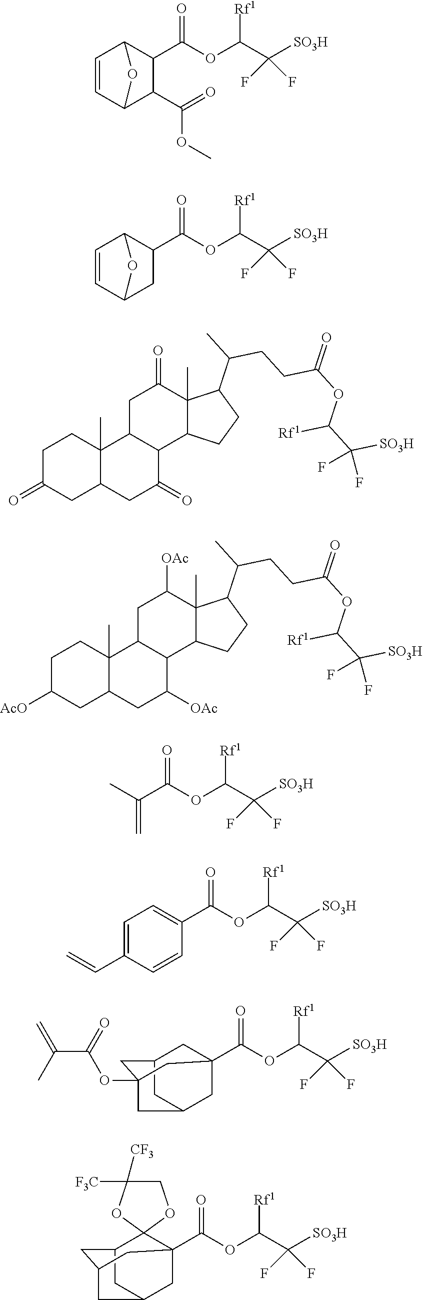

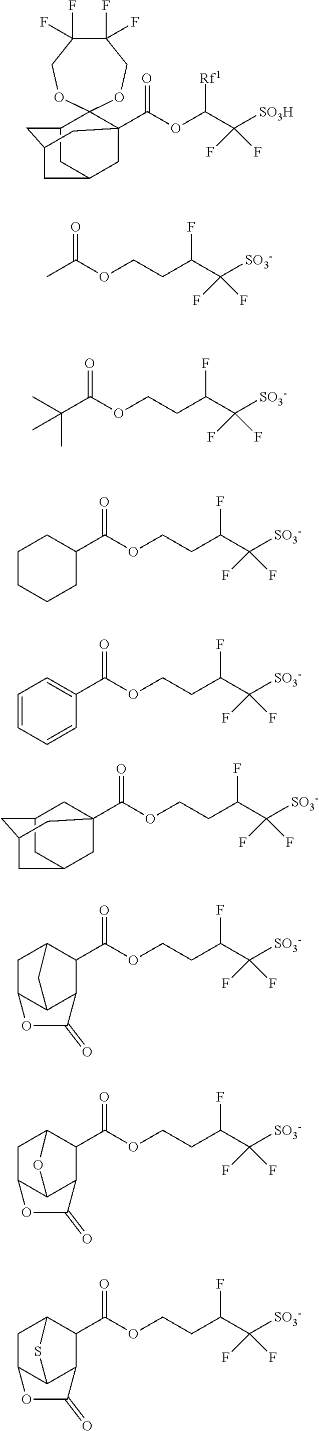

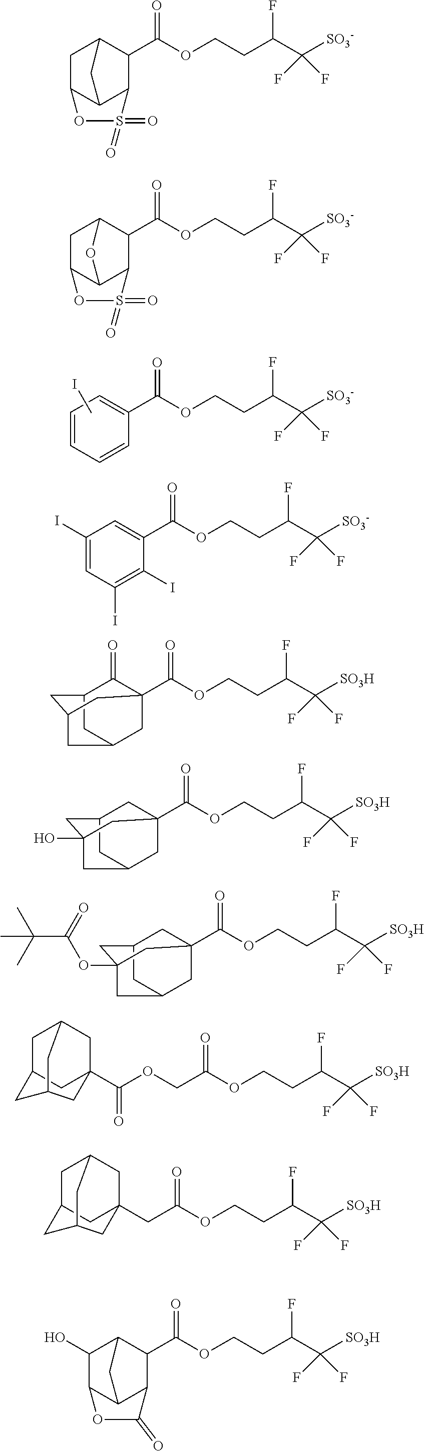

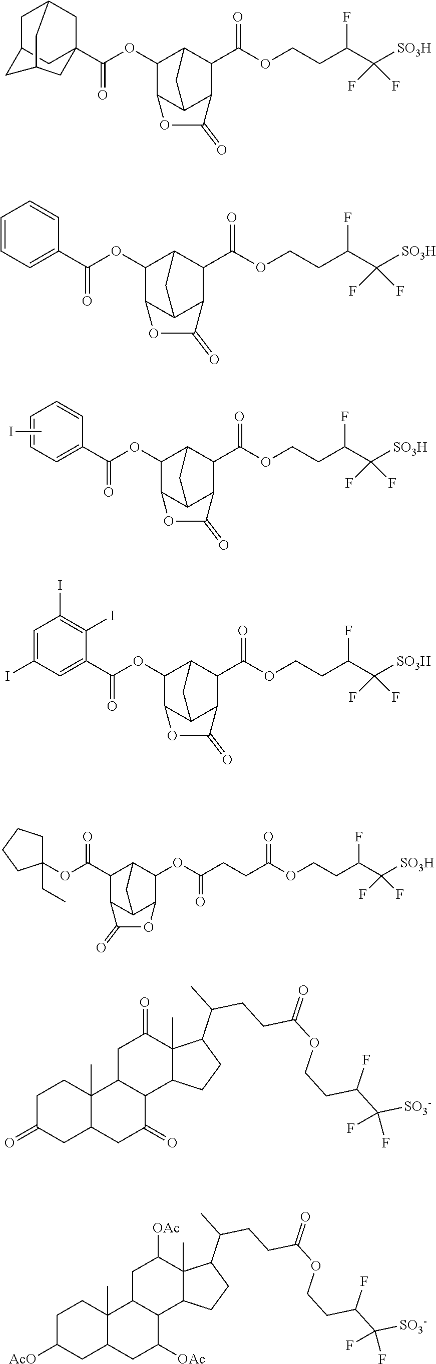

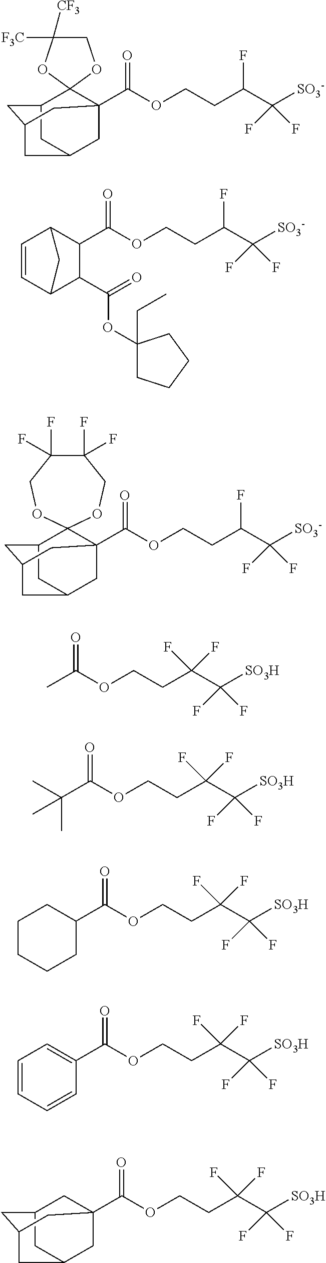

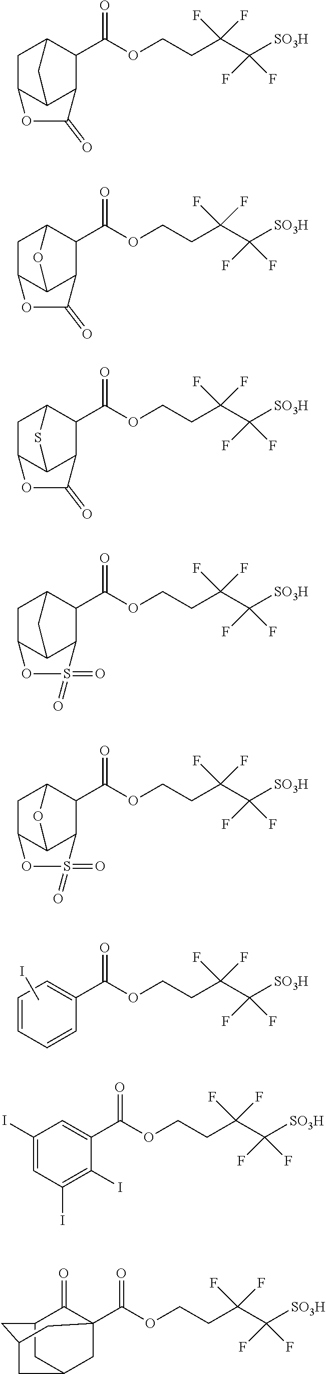

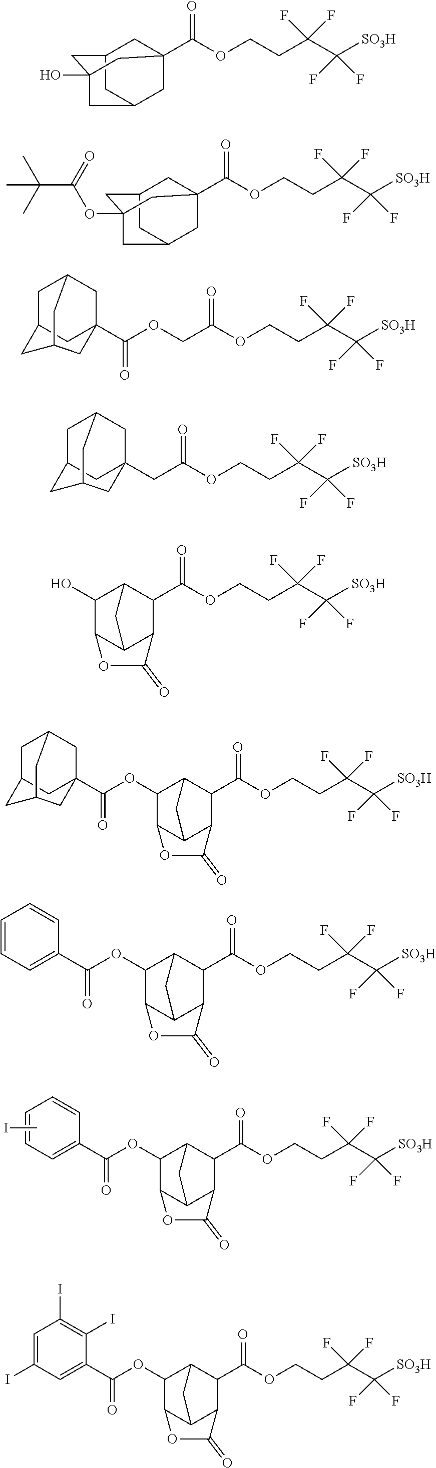

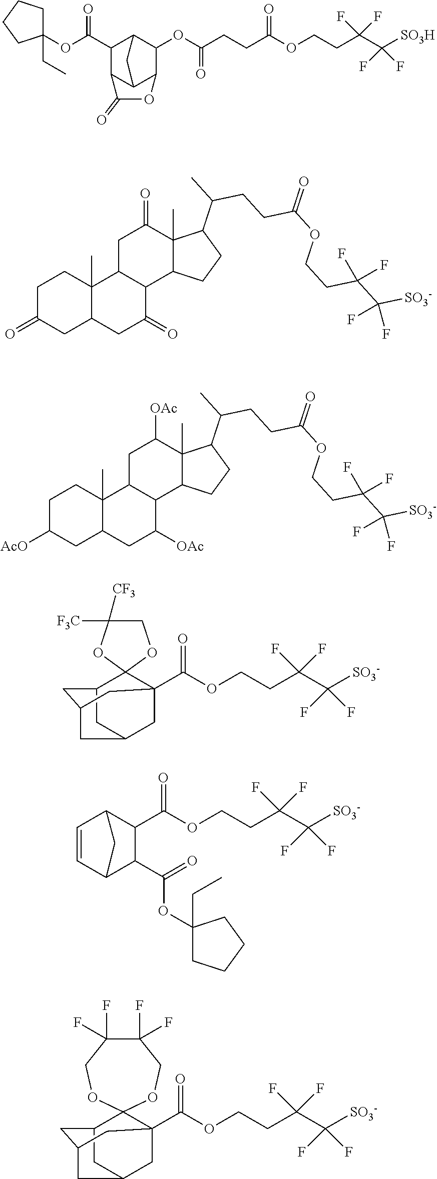

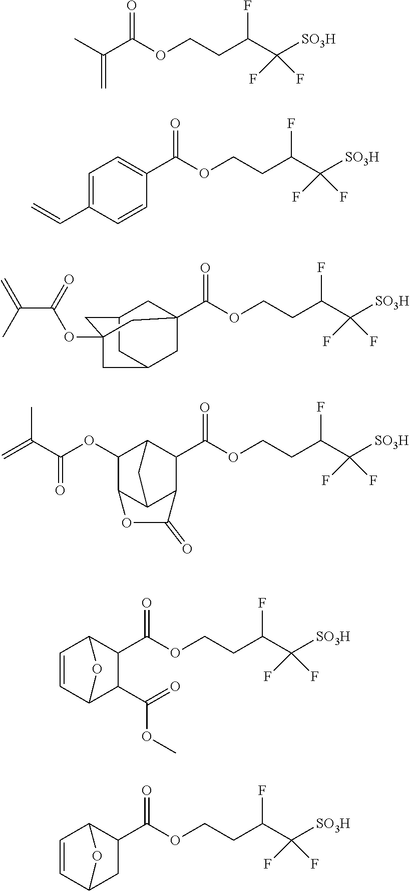

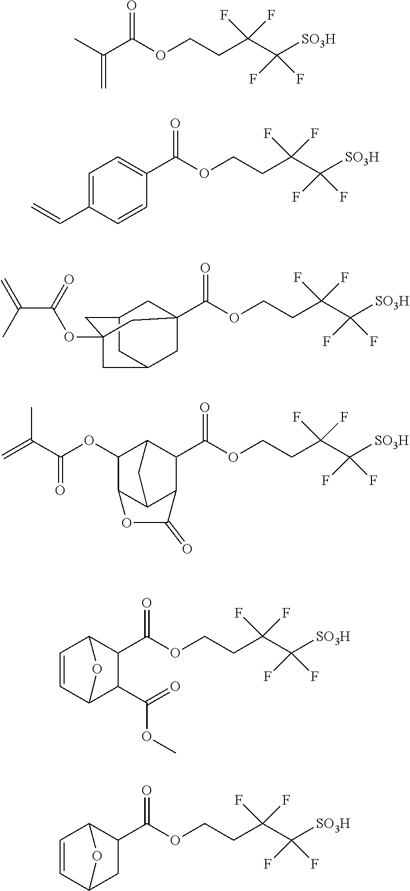 [SMILES: C=C(C)C(=O)OCCC(F)(F)C(F)(F)S(=O)(=O)O ; C=Cc1ccc(C(=O)OCCC(F)(F)C(F)(F)S(=O)(=O)O)cc1 ; C=C(C)C(=O)OC12CC3CC(C1)CC(C(=O)OCCC(F)(F)C(F)(F)S(=O)(=O)O)(C3)C2 ; C=C(C)C(=O)OC1C2CC3C1OC(=O)C3C2C(=O)OCCC(F)(F)C(F)(F)S(=O)(=O)O ; COC(=O)C1C2C=CC(O2)C1C(=O)OCCC(F)(F)C(F)(F)S(=O)(=O)O ; O=C(OCCC(F)(F)C(F)(F)S(=O)(=O)O)C1CC2C=CC1O2]

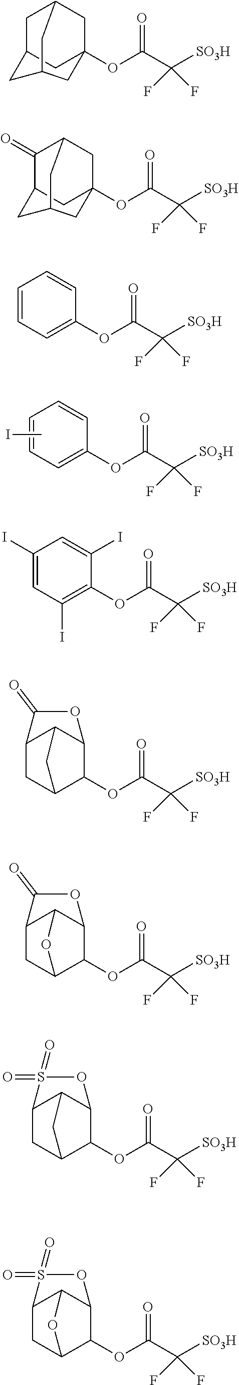

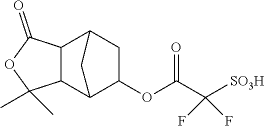 [SMILES: CC1(C)OC(=O)C2C3CC(OC(=O)C(F)(F)S(=O)(=O)O)C(C3)C21]

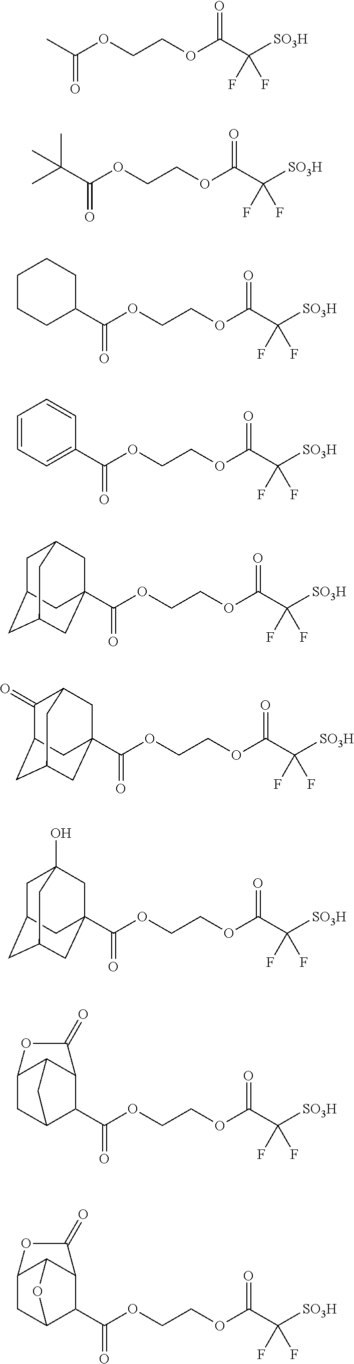

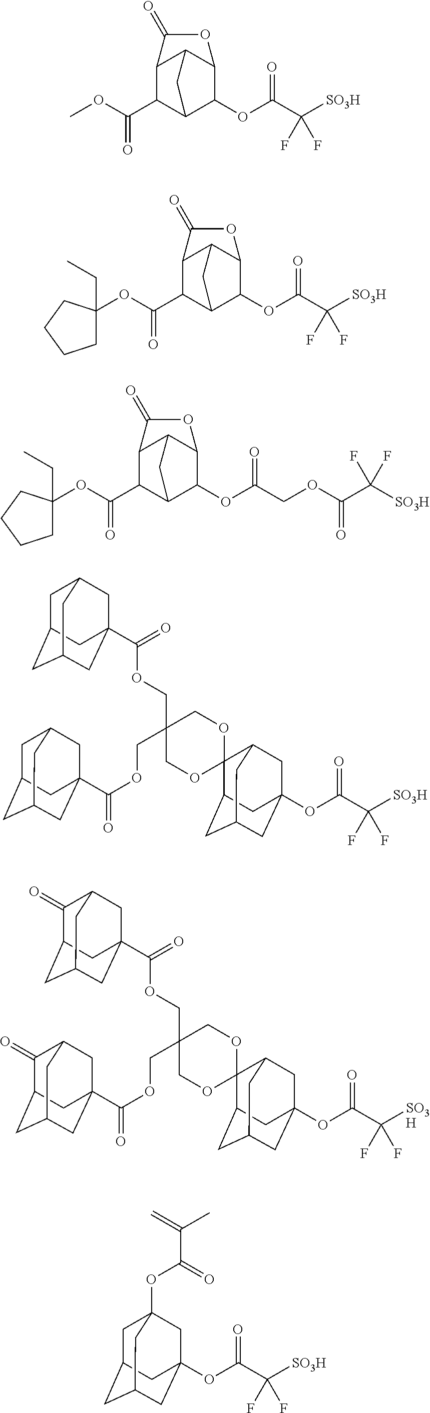 [SMILES: COC(=O)C1C2CC3C(OC(=O)C31)C2OC(=O)C(F)(F)S(=O)(=O)O ; CCC1(OC(=O)C2C3CC4C(OC(=O)C42)C3OC(=O)C(F)(F)S(=O)(=O)O)CCCC1 ; CCC1(OC(=O)C2C3CC4C(OC(=O)C42)C3OC(=O)COC(=O)C(F)(F)S(=O)(=O)O)CCCC1 ; O=C(OCC1(COC(=O)C23CC4CC(CC(C4)C2)C3)COC2(OC1)C1CC3CC2CC(OC(=O)C(F)(F)S(=O)(=O)O)(C3)C1)C12CC3CC(CC(C3)C1)C2 ; O=C1C2CC3CC1CC(C(=O)OCC1(COC(=O)C45CC6CC(C4)C(=O)C(C6)C5)COC4(OC1)C1CC5CC4CC(OC(=O)C(F)(F)S(=O)(=O)O)(C5)C1)(C3)C2 ; C=C(C)C(=O)OC12CC3CC(C1)CC(OC(=O)C(F)(F)S(=O)(=O)O)(C3)C2]

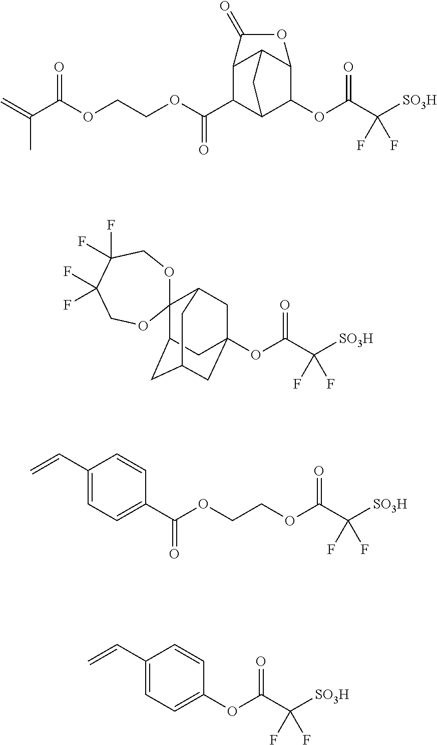 [SMILES: C=C(C)C(=O)OCCOC(=O)C1C2CC3C(OC(=O)C31)C2OC(=O)C(F)(F)S(=O)(=O)O ; O=C(OC12CC3CC(C1)C1(OCC(F)(F)C(F)(F)CO1)C(C3)C2)C(F)(F)S(=O)(=O)O ; C=Cc1ccc(C(=O)OCCOC(=O)C(F)(F)S(=O)(=O)O)cc1 ; C=Cc1ccc(OC(=O)C(F)(F)S(=O)(=O)O)cc1]

Examples of the compound having the formula (b-2) are shown below, but are not limited thereto.

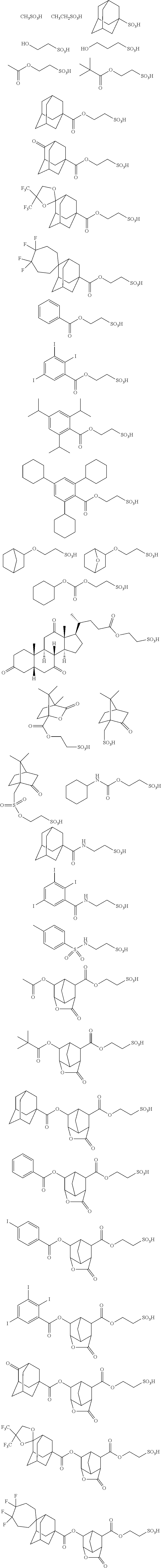

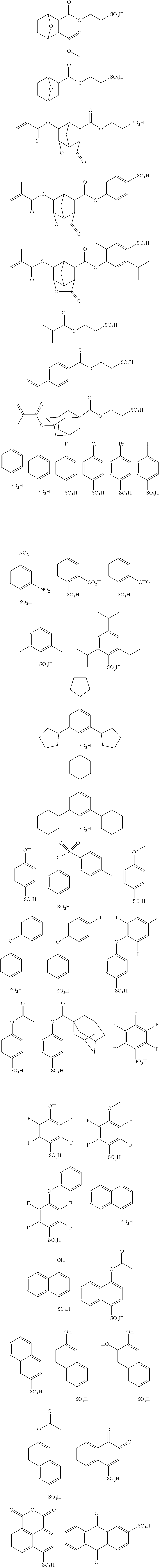

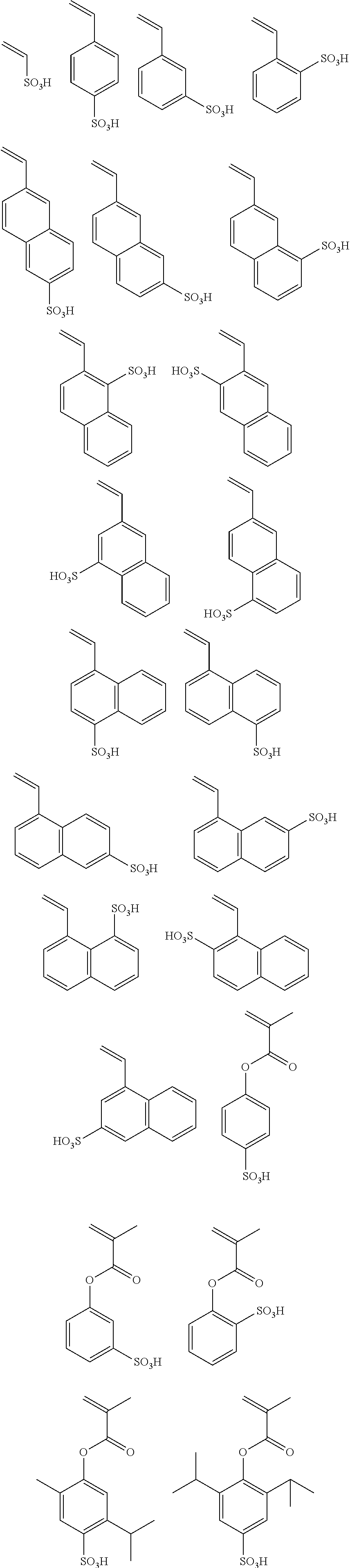

Examples of the compound having the formula (b-3) are shown below, but are not limited thereto.

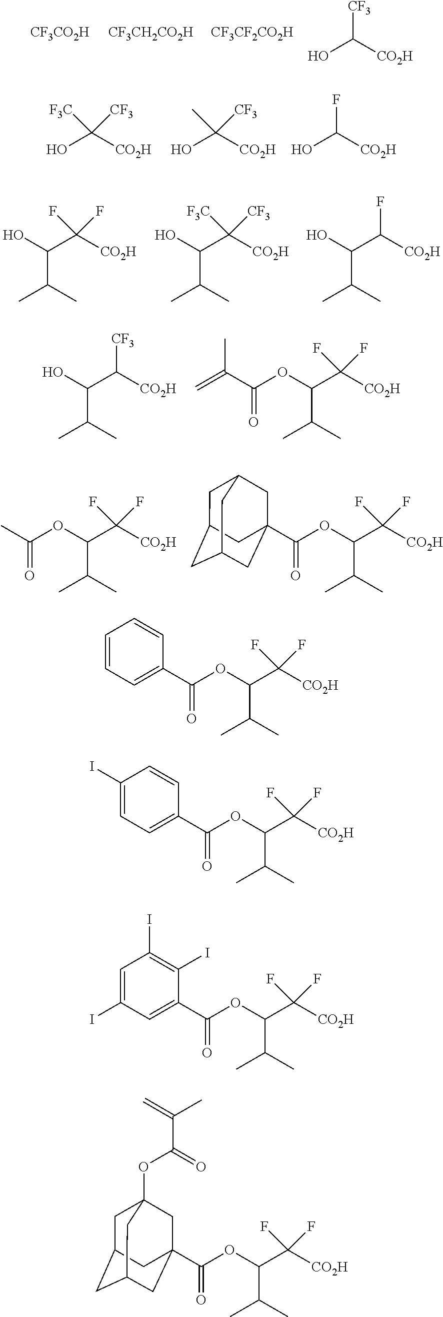

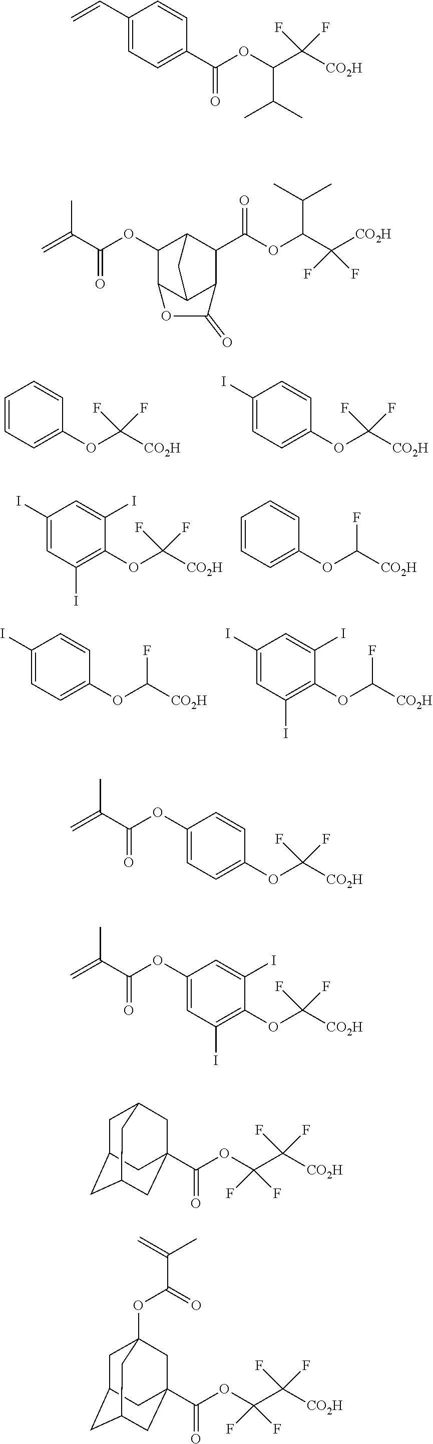

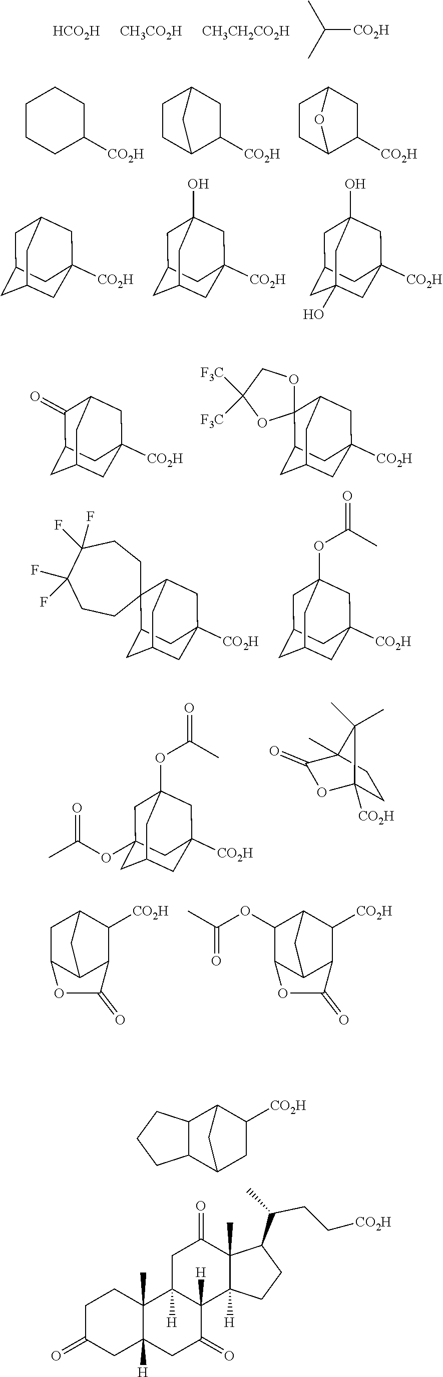

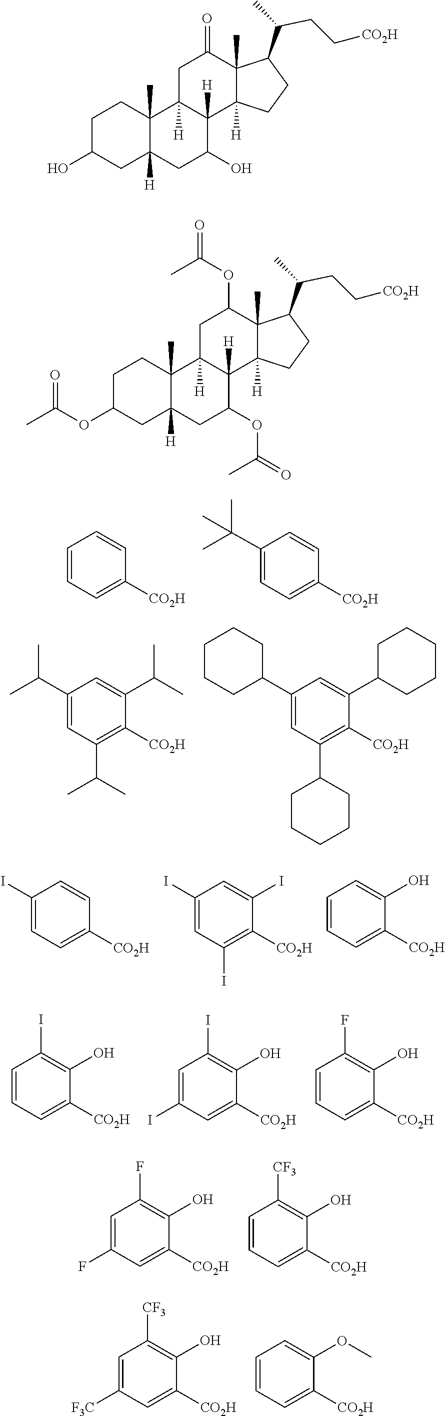

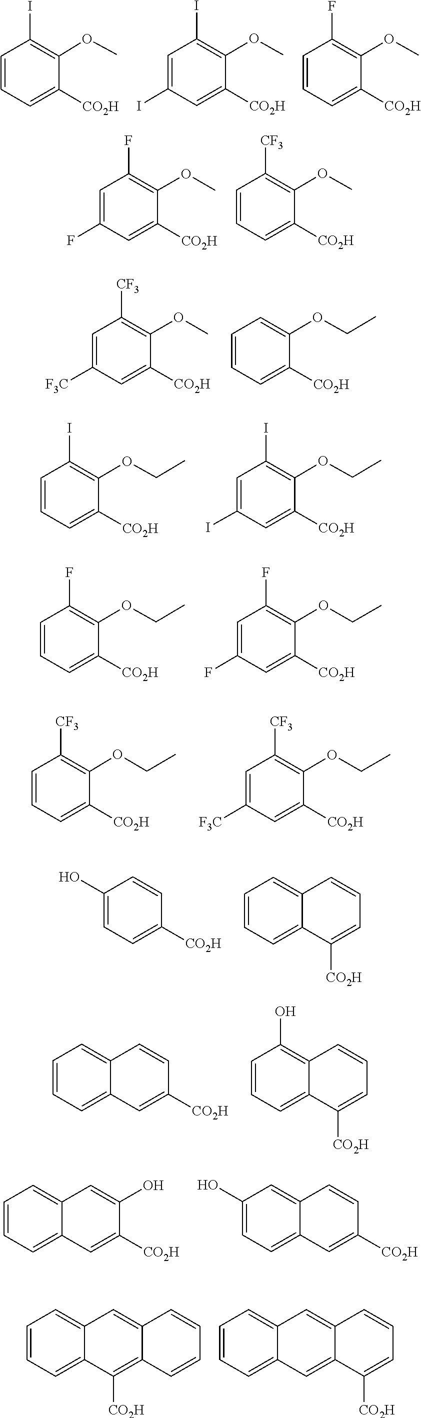

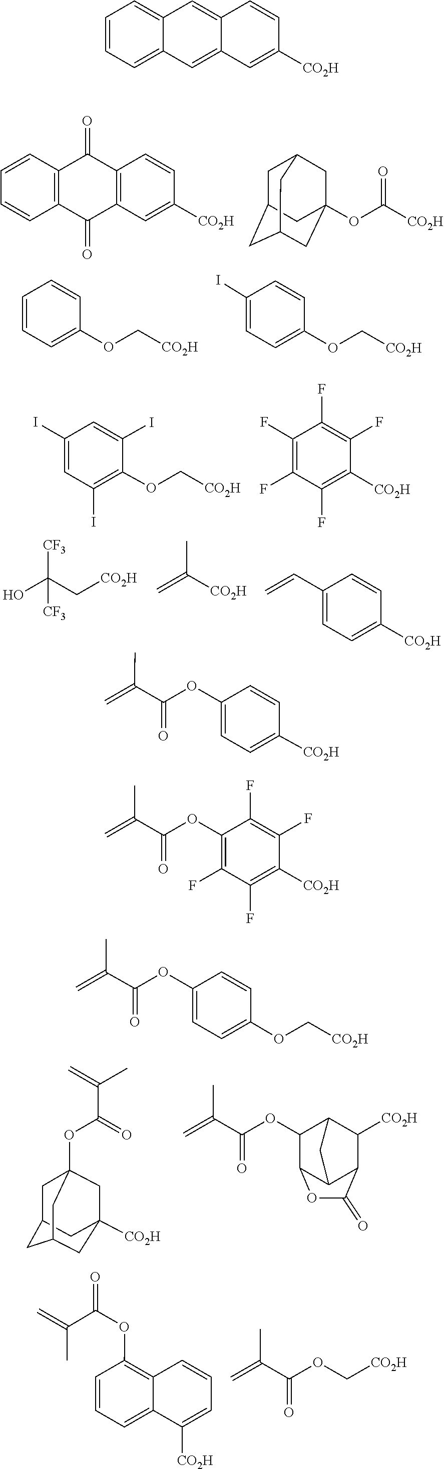

Examples of the compound having the formula (b-5) are shown below, but are not limited thereto.

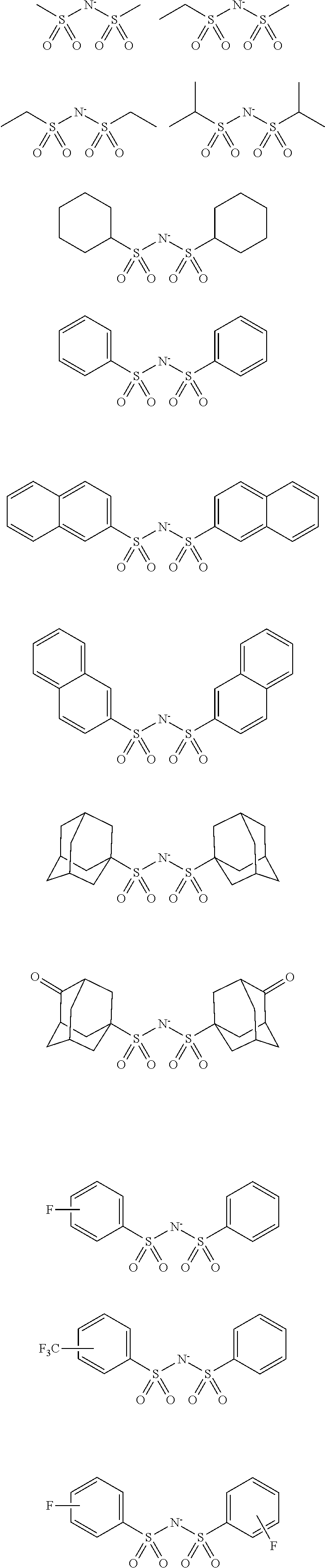

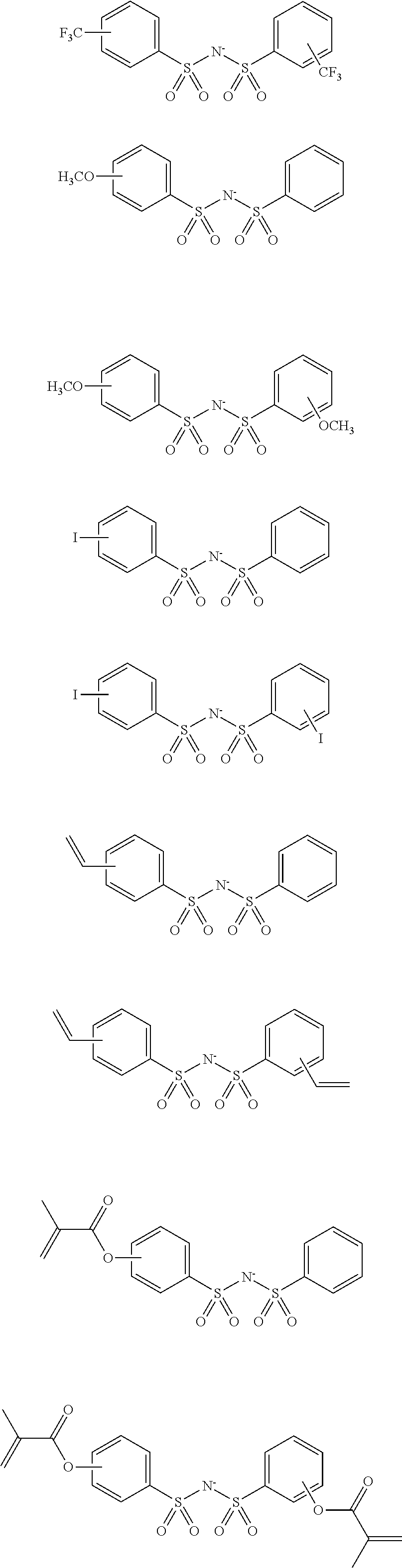

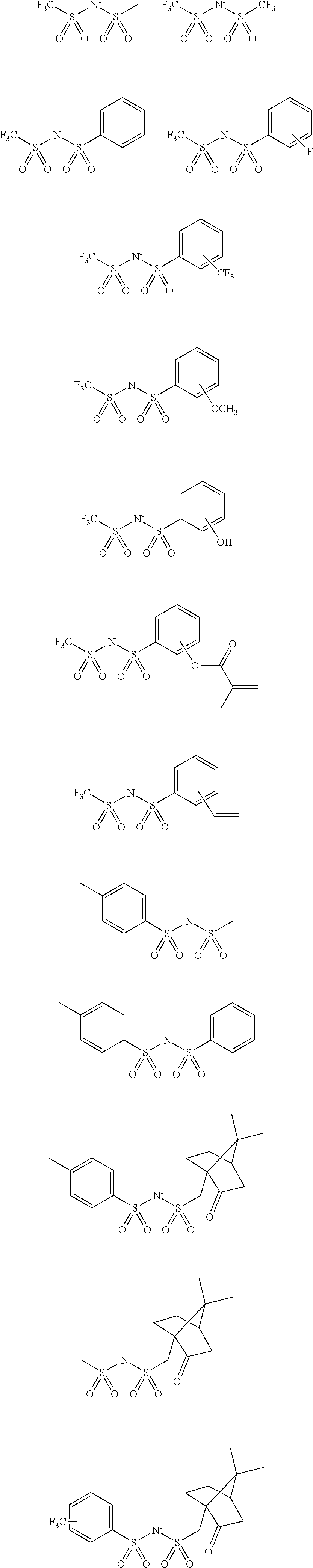

Examples of the compound having the formula (b-6) are shown below, but are not limited thereto.

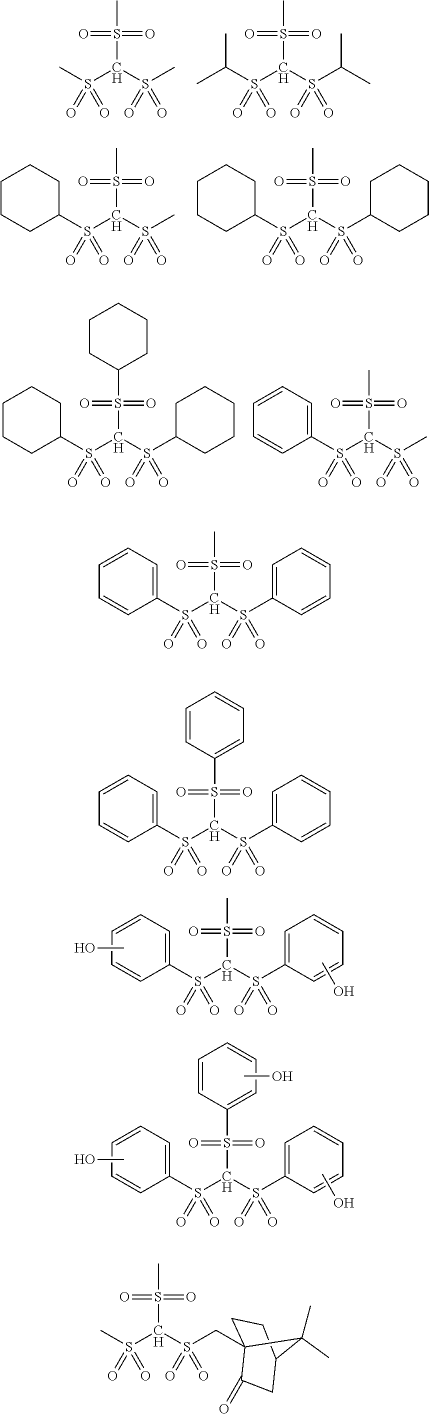

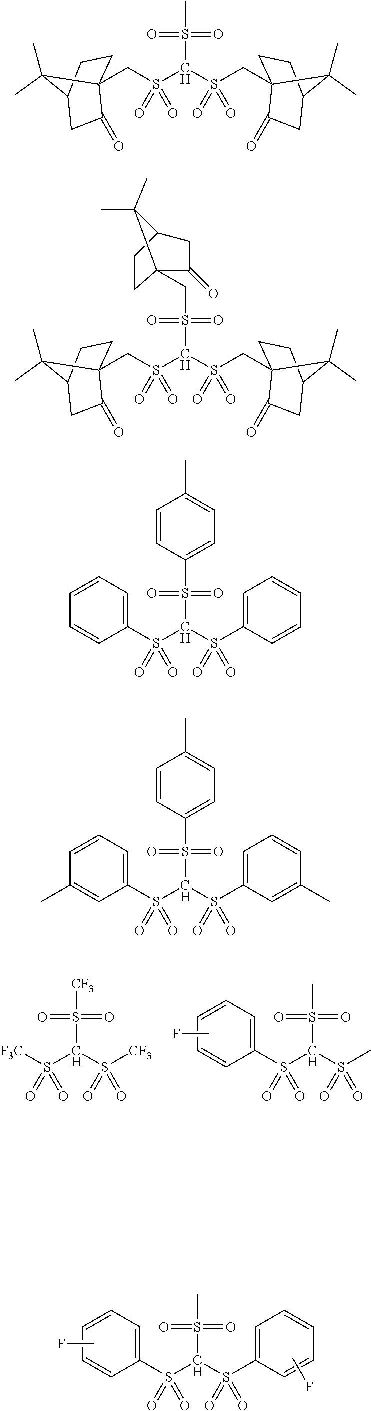

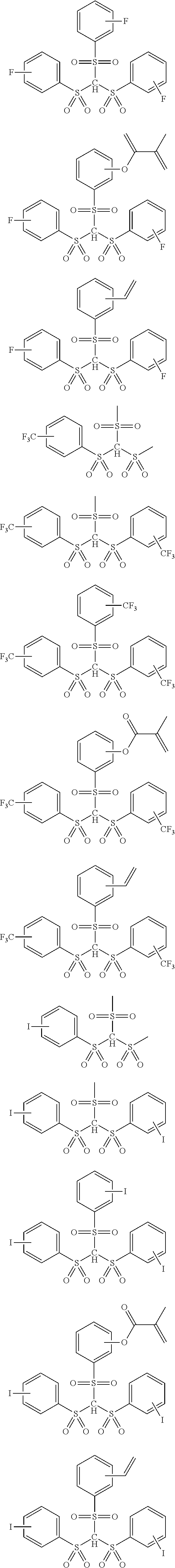

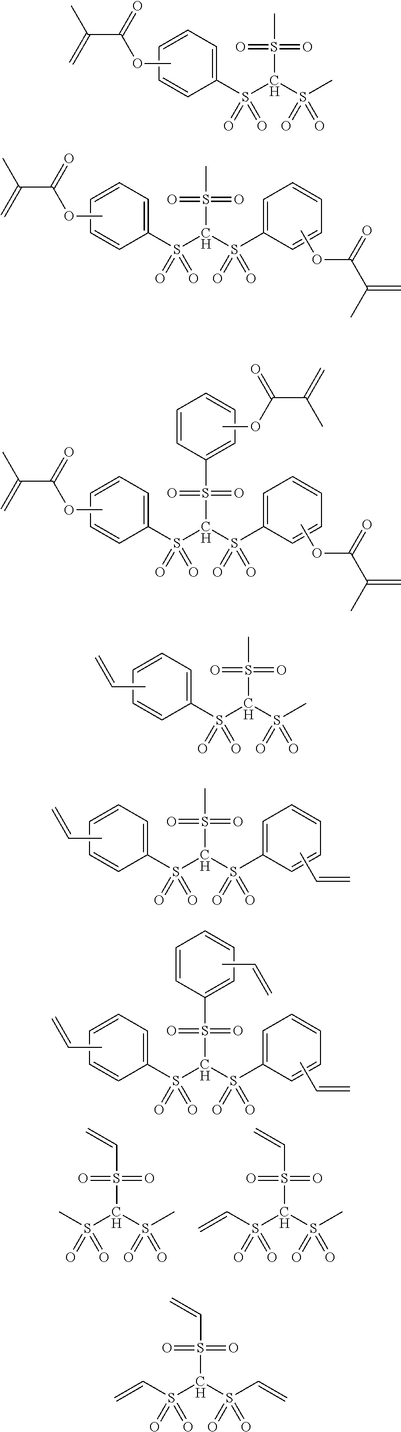

Examples of the compound having the formula (b-7) are shown below, but are not limited thereto.

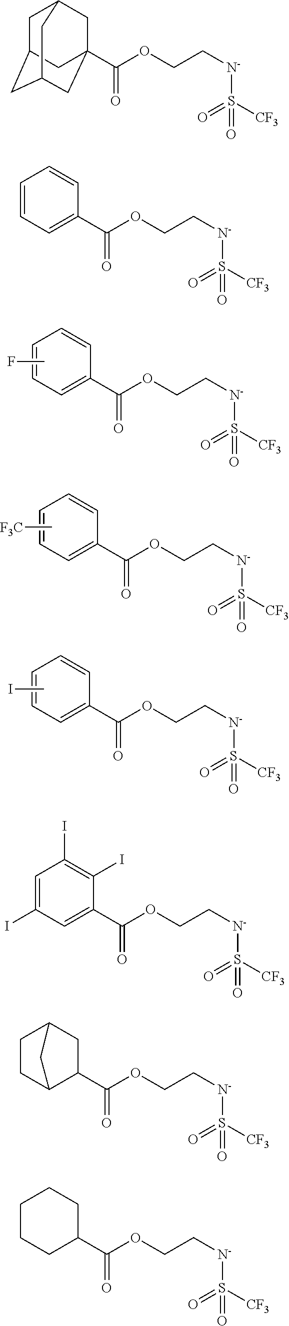

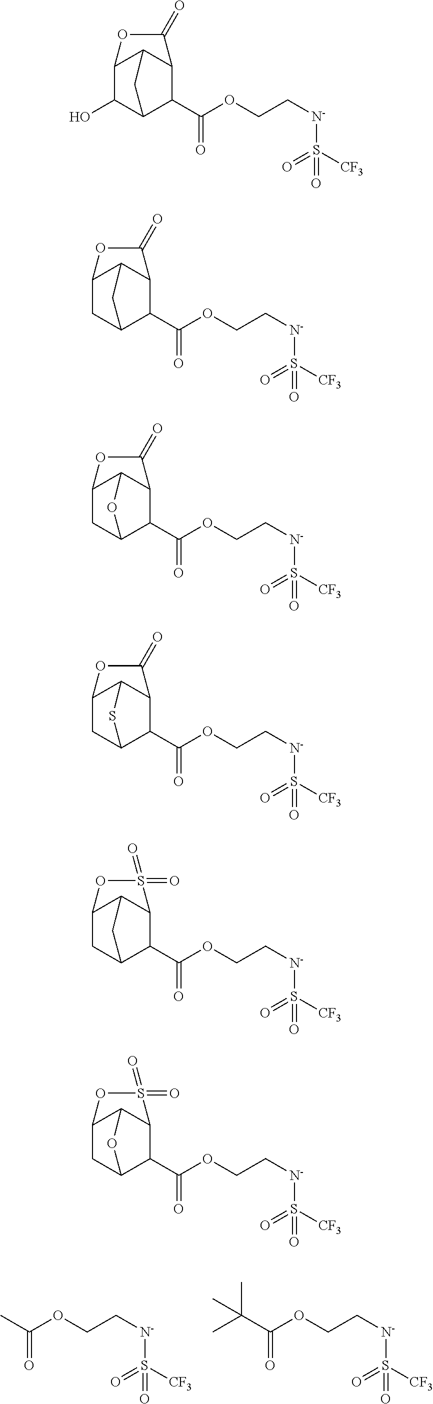

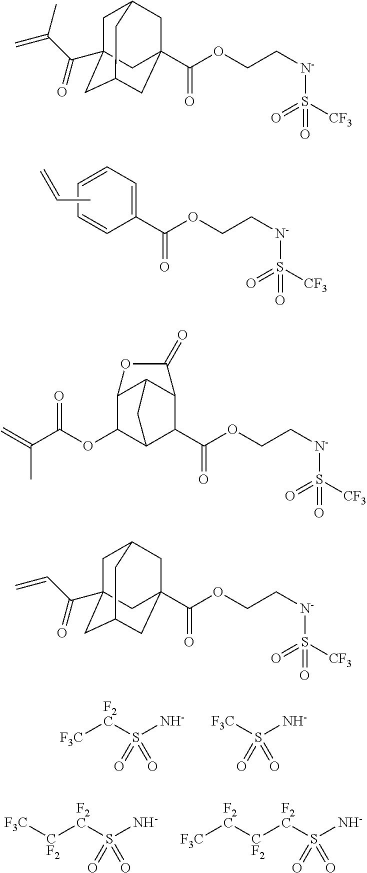

In the developer, the organic acid is preferably present in an amount of 0.01 to 100% by weight based on the overall developer. When the content is 0.01% by weight or more, the blending effect can be sufficiently obtained.

The developer may contain water or an organic solvent. Examples of the organic solvent include 2-octanone, 2-nonanone, 2-heptanone, 3-heptanone, 4-heptanone, 2-hexanone, 3-hexanone, diisobutyl ketone, 5-methyl-2-hexanone, methylcyclohexanone, acetophenone, methylacetophenone, isopropyl alcohol, isoamyl alcohol, n-butanol, tert-butyl alcohol, tert-pentyl alcohol, n-pentanol, cyclohexanol, formic acid, acetic acid, propionic acid, propyl acetate, butyl acetate, isobutyl acetate, pentyl acetate, butenyl acetate, isopentyl acetate, cyclohexyl acetate, 4-tert-butyl cyclohexyl acetate, octyl acetate, isobornyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, 1-propanol, 3-methoxybutanol, 3-methyl-3-methoxybutanol, 1-methoxy-2-propanol, 1-ethoxy-2-propanol, 3-methyl-1-butanol, diacetone alcohol, 4-methyl-2-pentanol, 3-methylcyclohexanol, 3,5,5-trimethylhexyl alcohol, 2,6-dimethyl-4-heptanol, toluene, anisole, and &-caprolactone. These organic solvents may be used alone or in admixture of two or more.

The water in the developer is added to dissolve an organic acid that is not liquid. The water is preferably present in an amount of 0 to 30% by weight, more preferably 0 to 5% by weight.

The organic solvent in the developer is added to dissolve an organic acid that is not liquid. The organic solvent is preferably present in an amount of 0 to 30% by weight, more preferably 0 to 10% by weight, and most preferably 0 to 5% by weight.

After the development, rinsing is performed as necessary. The rinse solution is preferably a solvent that is mixed with the developer and does not dissolve the resist film. As such a solvent, a C₃-C₁₀ alcohol, a C₈-C₁₂ ether compound, and a C₆-C₁₂ alkane, alkene, alkyne, or aromatic solvent are preferably used.

By performing rinsing, resist pattern collapse or defect occurrence can be reduced. Rinsing is not necessarily required. Rinsing can be omitted to reduce the amount of solvent used.

As described above, the resist composition has a difference in solubility between the exposed region and the unexposed region by exposure, and can form a positive or negative pattern. Therefore, it is possible to use a developer that dissolves the exposed region and does not dissolve the unexposed region, or it is possible to use a developer that dissolves the unexposed region and does not dissolve the exposed region. As described above, the inventive resist pattern forming process makes it possible to form a positive or negative pattern by appropriately selecting a developer, and can be widely applied to various micropatterning.

### EXAMPLES

Synthesis Examples, Examples and Comparative Examples are given below for illustrating the invention although the invention is not limited thereto.

### [1] Synthesis of Carboxy Group-Containing Polymer

The monomers a-1 to a-3, b-1 to b-4, and c-1 and c-2 used for the synthesis of the carboxy group-containing polymer are as follows.

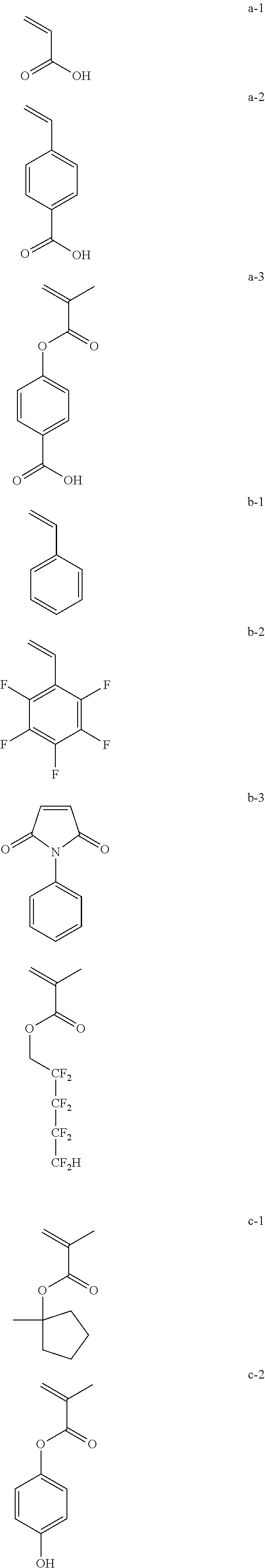

### Synthesis Example 1

### Synthesis of Polymer P-1

In a nitrogen atmosphere, a monomer a-1 (56 g), a monomer b-1 (36 g), V-601 (manufactured by FUJIFILM Wako Pure Chemical Corporation) (5.4 g), and MEK (180 g) were put into a flask to prepare a monomer-polymerization initiator solution. In another flask under a nitrogen atmosphere, 55 g of MEK was put and heated to 80° C. while stirred, and then the monomer-polymerization initiator solution was added dropwise over 4 hours. After completion of the dropwise addition, stir of the polymerization liquid was continued for 2 hours while the liquid temperature was maintained at 80° C., and then the polymerization liquid was cooled to room temperature. The obtained polymerization liquid was added dropwise to 4000 g of vigorously stirred hexane, and the precipitated polymer was separated by filtration. The obtained polymer was washed twice with hexane (1200 g), and then vacuum-dried at 50° C. for 20 hours to obtain a polymer P-1 in the form of a white powder (yield: 90 g, yield rate: 98%). The polymer P-1 had a value of Mw of 8000, and a value of Mw/Mn of 1.42. The values of Mw and Mn were measured by GPC versus polystyrene standards using THE as a solvent. Specifically, measurement was performed under the following conditions (the same applies hereinafter).
Apparatus: HLC-8320GPC
Column: TSK guardcolumn
   +TSK gel G4000HXL
   +TSKgel G2000HXL
   +TSKgel superH5000
Pump, column constant temperature: 40° C.
Eluent: THF
Detector: RI (refractive index) detector
Injection amount: 100 μL

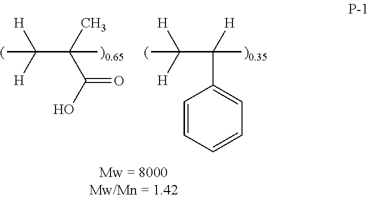

### Synthesis Examples 2 to 13

### Synthesis of Polymer P-2 to P-13

Polymers shown in Table 1 were synthesized in the same manner as in Synthesis Example 1 except that the kind and the compounding ratio of each monomer were changed.

TABLE 1

| Poly- | | Incorporation | | Incorporation | | |
|---|---|---|---|---|---|---|
| mer | Unit 1 | ratio (mol %) | Unit 2 | ratio (mol %) | Mw | Mw/Mn |
| P-1 | a-1 | 65 | b-1 | 35 | 8,000 | 1.42 |
| P-2 | a-1 | 50 | b-2 | 50 | 8,400 | 1.44 |
| P-3 | a-1 | 60 | b-3 | 40 | 8,100 | 1.39 |
| P-4 | a-1 | 60 | b-4 | 40 | 8,100 | 1.44 |
| P-5 | a-2 | 65 | b-1 | 35 | 8,000 | 1.46 |
| P-6 | a-2 | 50 | b-2 | 50 | 8,600 | 1.50 |
| P-7 | a-2 | 60 | b-3 | 40 | 7,900 | 1.48 |
| P-8 | a-2 | 65 | b-4 | 35 | 8,200 | 1.44 |
| P-9 | a-3 | 65 | b-1 | 35 | 8,700 | 1.43 |
| P-10 | a-3 | 50 | b-2 | 50 | 9,000 | 1.47 |
| P-11 | a-3 | 60 | b-3 | 40 | 7,500 | 1.44 |
| P-12 | a-3 | 65 | b-4 | 35 | 8,600 | 1.44 |
| P-13 | c-1 | 60 | c-2 | 40 | 8,500 | 1.41 |

### [2] Preparation of Resist Composition

### Examples 1-1 to 1-30 and Comparative Examples 1-1 to 1-2

Resist compositions (R-01 to R-30) were prepared by dissolving a hypervalent iodine compound and a carboxy group-containing compound in a solvent containing 0.01% by weight of a surfactant (PF-636, manufactured by OMNOVA Solutions Inc.) in accordance with the recipe shown in Table 2, and filtering the solution through a Teflon® filter having a pore size of 0.2 μm. Separately, resist compositions (CR-01 to CR-02) were prepared by dissolving a polymer, a photoacid generator, and a sensitivity modifier in a solvent containing 0.01% by weight of a surfactant (PF-636, manufactured by OMNOVA Solutions Inc.) in accordance with the recipe shown in Table 3, and filtering the solution through a Teflon® filter having a pore size of 0.2 μm.

TABLE 2

| | | | Hypervalent | Hypervalent | | | |
|---|---|---|---|---|---|---|---|
| | | Resist | iodine | iodine | Carboxylic | | |
| | | compo- | compound 1 | compound 2 | acid | Solvent 1 | Solvent 2 |
| | | sition | (pbw) | (pbw) | (pbw) | (pbw) | (pbw) |
| Example | 1-1 | R-01 | I-1 (10) | — | P-1 (9) | PGMEA (800) | AcOH (200) |
| | 1-2 | R-02 | I-1 (10) | — | P-2 (9) | PGMEA (800) | AcOH (200) |
| | 1-3 | R-03 | I-1 (10) | — | P-3 (11) | PGMEA (800) | AcOH (200) |
| | 1-4 | R-04 | I-1 (10) | — | P-4 (9) | PGMEA (800) | AcOH (200) |
| | 1-5 | R-05 | I-1 (10) | — | P-5 (12) | PGMEA (800) | AcOH (200) |
| | 1-6 | R-06 | I-1 (10) | — | P-6 (20) | PGMEA (800) | AcOH (200) |
| | 1-7 | R-07 | I-1 (10) | — | P-7 (15) | PGMEA (800) | AcOH (200) |
| | 1-8 | R-08 | I-1 (10) | — | P-8 (19) | PGMEA (800) | AcOH (200) |
| | 1-9 | R-09 | I-1 (10) | — | P-9 (21) | PGMEA (800) | AcOH (200) |
| | 1-10 | R-10 | I-1 (10) | — | P-10 (29) | PGMEA (800) | AcOH (200) |
| | 1-11 | R-11 | I-1 (10) | — | P-11 (24) | PGMEA (800) | AcOH (200) |
| | 1-12 | R-12 | I-1 (10) | — | P-12 (27) | PGMEA (800) | AcOH (200) |
| | 1-13 | R-13 | I-1 (5) | I-2 (5) | P-1 (9) | PGMEA (800) | AcOH (200) |
| | 1-14 | R-14 | I-2 (16) | — | P-2 (9) | PGMEA (800) | AcOH (200) |
| | 1-15 | R-15 | I-3 (27) | — | P-2 (9) | PGMEA (800) | AcOH (200) |
| | 1-16 | R-16 | I-4 (10) | — | P-2 (9) | PGMEA (800) | AcOH (200) |
| | 1-17 | R-17 | I-5 (11) | — | P-2 (9) | PGMEA (800) | AcOH (200) |
| | 1-18 | R-18 | I-6 (11) | — | P-2 (9) | PGMEA (800) | AcOH (200) |
| | 1-19 | R-19 | I-7 (23) | — | P-2 (9) | PGMEA (800) | AcOH (200) |
| | 1-20 | R-20 | I-8 (22) | — | P-2 (9) | PGMEA (800) | AcOH (200) |
| | 1-21 | R-21 | I-9 (22) | — | P-2 (9) | PGMEA (800) | AcOH (200) |
| | 1-22 | R-22 | I-10 (10) | — | P-2 (9) | PGMEA (800) | AcOH (200) |
| | 1-23 | R-23 | I-11 (10) | — | P-2 (9) | PGMEA (800) | AcOH (200) |
| | 1-24 | R-24 | I-12 (10) | — | P-2 (9) | PGMEA (800) | AcOH (200) |
| | 1-25 | R-25 | I-13 (10) | — | P-2 (9) | PGMEA (800) | AcOH (200) |
| | 1-26 | R-26 | I-1 (10) | — | m-1 (12) | PGMEA (800) | AcOH (200) |
| | 1-27 | R-27 | I-1 (10) | — | m-2 (10) | PGMEA (800) | AcOH (200) |
| | 1-28 | R-28 | I-1 (10) | — | m-3 (10) | PGMEA (800) | AcOH (200) |
| | 1-29 | R-29 | I-1 (10) | — | m-4 (10) | PGMEA (800) | AcOH (200) |
| | 1-30 | R-30 | I-1 (10) | — | m-5 (10) | PGMEA (800) | AcOH (200) |

TABLE 3

| | | | | Photoacid | Sensitivity | | |
|---|---|---|---|---|---|---|---|
| | | Resist | Polymer | generator | modifier | Solvent 1 | Solvent 2 |
| | | composition | (pbw) | (pbw) | (pbw) | (pbw) | (pbw) |
| Comparative | 1-1 | CR-01 | P-13(80) | PAG-1(19) | Q-1(6) | PGMEA(1890) | GBL(210) |
| Example | 1-2 | CR-02 | P-13(80) | PAG-1(19) | I-1(5) | PGMEA(1890) | GBL(210) |

In Tables 2 and 3, the hypervalent iodine compounds I-1 to I-13, the carboxylic acids m-1 to m-5, the photoacid generator PAG-1, the sensitivity modifier Q-1, and the solvents are identified below.

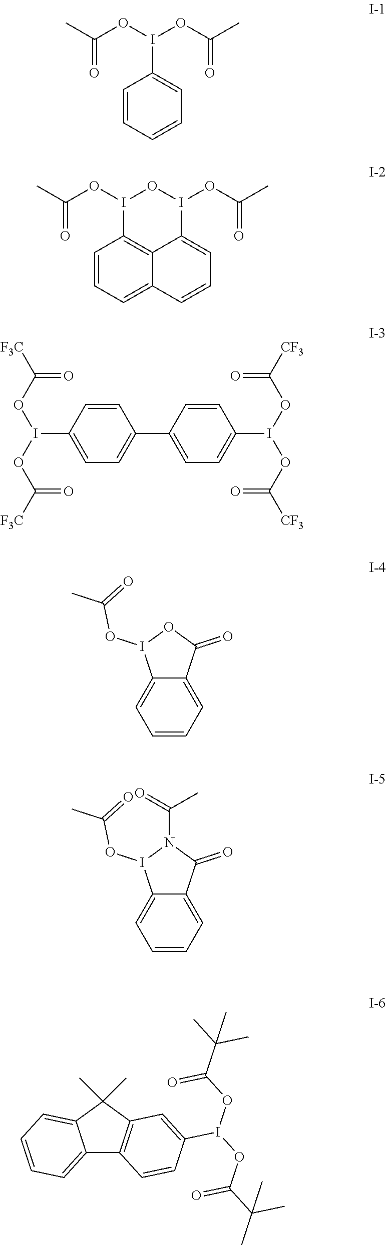

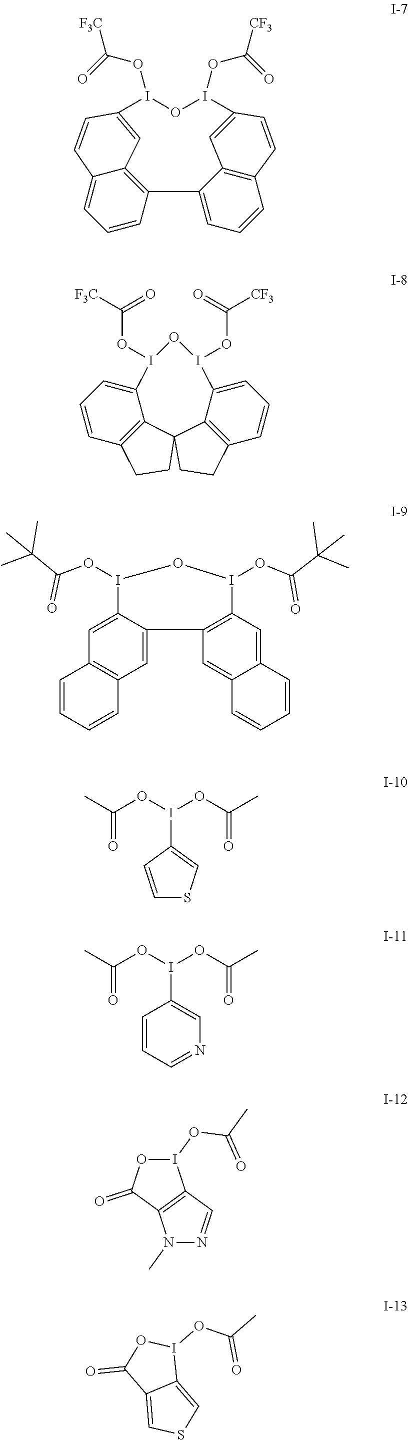

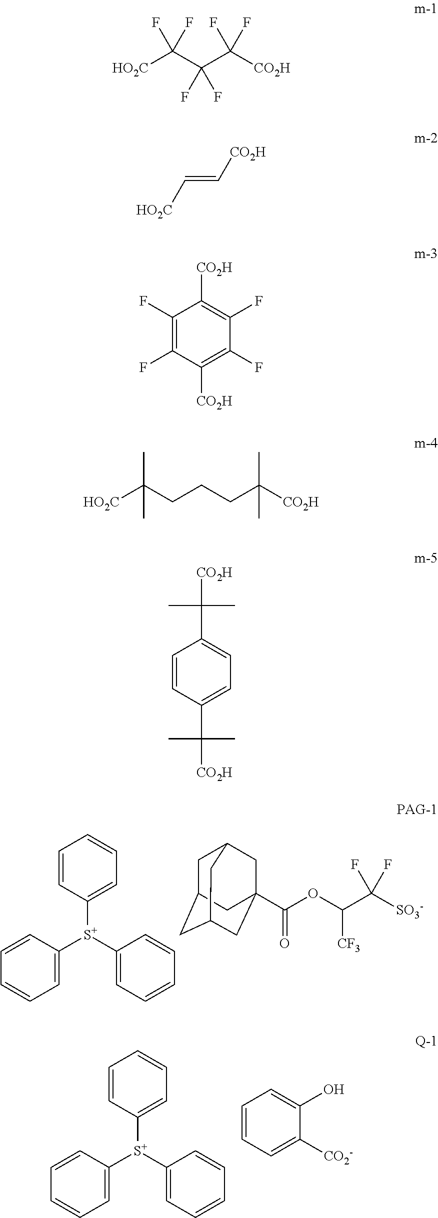

### Solvent:

PGMEA (propylene glycol monomethyl ether acetate)
AcOH (acetic acid)
GBL (γ-butyrolactone)
   [3] EUV lithography test (line-and-space pattern)

### Examples 2-1 to 2-37 and Comparative Examples 2-1 to 2-3

Each of the resist compositions (R-01 to R-30, CR-01 to CR-02) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 4 for 60 seconds to form a resist film of 40 nm thick. Using an EUV scanner NXE3400 (ASML, NA 0.33, ~ 0.9, 90° dipole illumination), the resist film was exposed to EUV through a mask bearing a 36-nm 1:1 line-and-space (LS) pattern. The resist film was baked (PEB) on a hotplate at the temperature shown in Table 4 for 60 seconds and developed in the developer shown in Table 4 for 30 seconds to form an LS pattern having a space width of 18 nm and a pitch of 36 nm. The acid in the developer described in Table 4 is as shown in Table 5.

The LS pattern was observed under CD-SEM (CG-6300, Hitachi High-Technologies Corp.) and evaluated for sensitivity, LWR and maximum resolution by the following methods. The results are shown in Table 4.

### [Evaluation of Sensitivity]

The optimum dose Eop (mJ/cm²) which provided an LS pattern with a space width of 18 nm and a pitch of 36 nm was determined and reported as sensitivity.

### [Evaluation of LWR]

An LS pattern was formed by exposure in the optimum dose (Eop). The space width was measured at longitudinally spaced apart 10 points, from which a 3-fold value (30) of the standard deviation (6) was determined and reported as LWR. A smaller value indicates a pattern having a lower roughness and more uniform space width.

### [Evaluation of Maximum Resolution]

An LS pattern was formed while increasing the exposure dose little by little from the optimum dose (Eop). The line width (nm) which could be resolved was determined and reported as maximum resolution. A smaller value indicates a pattern having a better maximum resolution and smaller feature size.

TABLE 4

| | | | | | | | Maximum |
|---|---|---|---|---|---|---|---|
| | | Resist | PAB/PEB | Developer | Eop | LWR | resolution |
| | | composition | (°C) | (wt %) | (mJ/cm²) | (nm) | (nm) |
| Example | 2-1 | R-01 | 110/90 | Acid 1 (100) | 40 | 3.5 | 12 |
| | 2-2 | R-01 | 110/90 | Acid 2 (100) | 38 | 3.5 | 13 |
| | 2-3 | R-01 | 110/90 | Acid 3 (100) | 35 | 3.7 | 13 |
| | 2-4 | R-01 | 110/90 | PGEE (80)/H₂O (10)/ | 32 | 3.7 | 13 |
| | | | | Acid 4 (10) | | | |
| | 2-5 | R-01 | 110/90 | PGEE (80)/H₂O (10)/ | 30 | 3.7 | 13 |
| | | | | Acid 5 (17) | | | |
| | 2-6 | R-01 | 110/90 | PGEE (80)/H₂O (10)/ | 32 | 3.8 | 13 |
| | | | | Acid 6 (10) | | | |
| | 2-7 | R-01 | 110/90 | PGMEA (98)/Acid 1 (2) | 42 | 3.5 | 14 |
| | 2-8 | R-01 | 110/90 | PGMEA (95)/Acid 1 (5) | 41 | 3.5 | 14 |
| | 2-9 | R-02 | 110/90 | Acid 1 (100) | 39 | 3.3 | 12 |
| | 2-10 | R-03 | 110/90 | Acid 1 (100) | 38 | 3.4 | 12 |
| | 2-11 | R-04 | 110/90 | Acid 1 (100) | 40 | 3.3 | 12 |
| | 2-12 | R-05 | 110/90 | Acid 1 (100) | 38 | 3.4 | 13 |
| | 2-13 | R-06 | 110/90 | Acid 1 (100) | 39 | 3.2 | 12 |
| | 2-14 | R-07 | 110/90 | Acid 1 (100) | 38 | 3.4 | 12 |
| | 2-15 | R-08 | 110/90 | Acid 1 (100) | 40 | 3.4 | 13 |
| | 2-16 | R-09 | 110/90 | Acid 1 (100) | 39 | 3.4 | 13 |
| | 2-17 | R-10 | 110/90 | Acid 1 (100) | 38 | 3.4 | 12 |
| | 2-18 | R-11 | 110/90 | Acid 1 (100) | 40 | 3.1 | 12 |
| | 2-19 | R-12 | 110/90 | Acid 1 (100) | 38 | 3.4 | 12 |
| | 2-20 | R-13 | 110/90 | Acid 1 (100) | 41 | 3.4 | 13 |
| | 2-21 | R-14 | 110/90 | Acid 1 (100) | 37 | 3.2 | 12 |
| | 2-22 | R-15 | 110/90 | Acid 1 (100) | 42 | 3.5 | 13 |
| | 2-23 | R-16 | 110/90 | Acid 1 (100) | 37 | 3.5 | 12 |
| | 2-24 | R-17 | 110/90 | Acid 1 (100) | 38 | 3.7 | 12 |
| | 2-25 | R-18 | 110/90 | Acid 1 (100) | 38 | 3.5 | 12 |
| | 2-26 | R-19 | 110/90 | Acid 1 (100) | 38 | 3.8 | 12 |
| | 2-27 | R-20 | 110/90 | Acid 1 (100) | 36 | 3.5 | 12 |
| | 2-28 | R-21 | 110/90 | Acid 1 (100) | 40 | 3.5 | 12 |
| | 2-29 | R-22 | 110/90 | Acid 1 (100) | 40 | 3.8 | 12 |
| | 2-30 | R-23 | 110/90 | Acid 1 (100) | 39 | 3.5 | 12 |
| | 2-31 | R-24 | 110/90 | Acid 1 (100) | 39 | 3.5 | 12 |
| | 2-32 | R-25 | 110/90 | Acid 1 (100) | 40 | 3.8 | 12 |
| | 2-33 | R-26 | 110/90 | Acid 1 (100) | 37 | 3.5 | 12 |
| | 2-34 | R-27 | 110/90 | Acid 1 (100) | 37 | 3.7 | 12 |
| | 2-35 | R-28 | 110/90 | Acid 1 (100) | 36 | 3.5 | 12 |
| | 2-36 | R-29 | 110/90 | Acid 1 (100) | 36 | 3.6 | 12 |
| | 2-37 | R-30 | 110/90 | Acid 1 (100) | 36 | 3.5 | 12 |
| Comparative | 2-1 | CR-01 | 105/90 | TMAH | 85 | 4.4 | 18 |
| Example | 2-2 | CR-02 | 105/90 | TMAH | 85 | 5.0 | 18 |
| | 2-3 | R-01 | 110/90 | TMAH | 40 | 4.2 | 15 |

TABLE 5

| | |
|---|---|
| Acid 1 | Acetic acid |
| Acid 2 | Propionic acid |
| Acid 3 | Trifluoroacetic acid |
| Acid 4 | Methanesulfonic acid |
| Acid 5 | p-toluenesulfonic acid hydrate |
| Acid 6 | 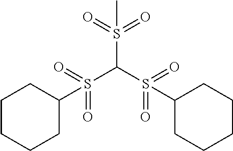 [SMILES: CS(=O)(=O)C(S(=O)(=O)C1CCCCC1)S(=O)(=O)C1CCCCC1] |

### Developer:

PGEE (propylene glycol ethyl ether)
PGMEA (propylene glycol monomethyl ether acetate)
TMAH (2.38 wt % tetramethylammonium hydroxide aqueous solution)

From the results shown in Table 4, it was found that a negative pattern was formed by performing development using a developer containing an organic acid. In addition, as compared with Comparative Example 2-1, it was found that higher resolution can be obtained than in development with TMAH. Also as compared with Comparative Examples 2-1 and 2-2, that is, chemically amplified resist compositions using an acid catalyst reaction, it was found that excellent sensitivity and resolution can be obtained. Therefore, it was found that the resist composition has excellent resolution in forming an LS pattern through EUV lithography.

### [4] EUV Lithography Test (Contact Hole Pattern)

### Examples 3-1 to 3-37 and Comparative Examples 3-1 to 3-3

Each of the resist compositions (R-01 to R-30, CR-01 to CR-02) was spin coated on a silicon substrate having a 20-nm coating of silicon-containing spin-on hard mask SHB-A940 (Shin-Etsu Chemical Co., Ltd., silicon content 43 wt %) and baked (PAB) on a hotplate at the temperature shown in Table 6 for 60 seconds to form a resist film of 50 nm thick. Using an EUV scanner NXE3400 (ASML, NA 0.33, ~ 0.9/0.6, quadrupole illumination), the resist film was exposed to EUV through a mask bearing a hole pattern with a pitch of 64 nm+20% bias (on-wafer size). After exposure, the resist film was baked (PEB) on a hotplate at the temperature shown in Table 5 for 60 seconds and developed in the developer shown in Table 6 for 30 seconds to form a hole pattern having a size of 32 nm.

The hole pattern was observed under CD-SEM (CG-6300, Hitachi High-Technologies Corp.) and evaluated for sensitivity, CDU and maximum resolution by the following methods. The results are shown in Table 6.

### [Evaluation of Sensitivity]

The optimum dose Eop (mJ/cm²) which provided a contact hole pattern with a size of 22 nm was determined and reported as sensitivity.

### [Evaluation of CDU]

The size of 50 holes which were printed at Eop was measured, from which a 3-fold value (36) of the standard deviation (c) was computed and reported as CDU. A smaller value of CDU indicates a hole pattern with more uniform hole diameter.

### [Evaluation of Maximum Resolution]

A hole pattern was formed while reducing the exposure dose little by little from the optimum dose (Eop). The hole diameter (nm) which could be resolved was determined and reported as maximum resolution. A smaller value indicates a pattern having a better maximum resolution and smaller hole diameter.

TABLE 6

| | | | | | | | Maximum |
|---|---|---|---|---|---|---|---|
| | | Resist | PAB/PEB | Developer | Eop | CDU | resolution |
| | | composition | (°C) | (wt %) | (mJ/cm²) | (nm) | (nm) |
| Example | 3-1 | R-01 | 110/90 | Acid 1 (100) | 34 | 2.6 | 22 |
| | 3-2 | R-01 | 110/90 | Acid 2 (100) | 28 | 2.4 | 24 |
| | 3-3 | R-01 | 110/90 | Acid 3 (100) | 29 | 2.4 | 24 |
| | 3-4 | R-01 | 110/90 | PGEE (80)/H₂O (10)/ | 26 | 2.1 | 24 |
| | | | | Acid 4 (10) | | | |
| | 3-5 | R-01 | 110/90 | PGEE (80)/H₂O (10)/ | 28 | 2.2 | 24 |
| | | | | Acid 5 (17) | | | |
| | 3-6 | R-01 | 110/90 | PGEE (80)/H₂O (10)/ | 34 | 2.4 | 24 |
| | | | | Acid 6 (10) | | | |
| | 3-7 | R-01 | 110/90 | PGMEA (98)/Acid 1 (2) | 34 | 2.4 | 24 |
| | 3-8 | R-01 | 110/90 | PGMEA (95)/Acid 1 (5) | 27 | 2.5 | 24 |
| | 3-9 | R-02 | 110/90 | Acid 1 (100) | 27 | 2.4 | 22 |
| | 3-10 | R-03 | 110/90 | Acid 1 (100) | 27 | 2.4 | 22 |
| | 3-11 | R-04 | 110/90 | Acid 1 (100) | 27 | 2.4 | 24 |
| | 3-12 | R-05 | 110/90 | Acid 1 (100) | 26 | 2.4 | 24 |
| | 3-13 | R-06 | 110/90 | Acid 1 (100) | 26 | 2.2 | 24 |
| | 3-14 | R-07 | 110/90 | Acid 1 (100) | 26 | 2.4 | 24 |
| | 3-15 | R-08 | 110/90 | Acid 1 (100) | 26 | 2.4 | 24 |
| | 3-16 | R-09 | 110/90 | Acid 1 (100) | 34 | 2.4 | 24 |
| | 3-17 | R-10 | 110/90 | Acid 1 (100) | 34 | 2.5 | 24 |
| | 3-18 | R-11 | 110/90 | Acid 1 (100) | 34 | 2.1 | 24 |
| | 3-19 | R-12 | 110/90 | Acid 1 (100) | 30 | 2.7 | 24 |
| | 3-20 | R-13 | 110/90 | Acid 1 (100) | 28 | 2.4 | 24 |
| | 3-21 | R-14 | 110/90 | Acid 1 (100) | 34 | 2.2 | 25 |
| | 3-22 | R-15 | 110/90 | Acid 1 (100) | 30 | 2.7 | 25 |
| | 3-23 | R-16 | 110/90 | Acid 1 (100) | 32 | 2.9 | 25 |
| | 3-24 | R-17 | 110/90 | Acid 1 (100) | 34 | 3.0 | 25 |
| | 3-25 | R-18 | 110/90 | Acid 1 (100) | 34 | 3.1 | 24 |
| | 3-26 | R-19 | 110/90 | Acid 1 (100) | 34 | 2.7 | 24 |
| | 3-27 | R-20 | 110/90 | Acid 1 (100) | 36 | 2.6 | 24 |
| | 3-28 | R-21 | 110/90 | Acid 1 (100) | 32 | 2.4 | 25 |
| | 3-29 | R-22 | 110/90 | Acid 1 (100) | 32 | 2.4 | 25 |
| | 3-30 | R-23 | 110/90 | Acid 1 (100) | 36 | 3.1 | 25 |
| | 3-31 | R-24 | 110/90 | Acid 1 (100) | 32 | 2.4 | 24 |
| | 3-32 | R-25 | 110/90 | Acid 1 (100) | 32 | 2.4 | 25 |
| | 3-33 | R-26 | 110/90 | Acid 1 (100) | 32 | 2.4 | 25 |
| | 3-34 | R-27 | 110/90 | Acid 1 (100) | 34 | 2.4 | 25 |
| | 3-35 | R-28 | 110/90 | Acid 1 (100) | 35 | 2.4 | 25 |
| | 3-36 | R-29 | 110/90 | Acid 1 (100) | 35 | 2.4 | 24 |
| | 3-37 | R-30 | 110/90 | Acid 1 (100) | 35 | 2.4 | 24 |
| Comparative | 3-1 | CR-01 | 105/90 | TMAH | 50 | 4.2 | 32 |
| Example | 3-2 | CR-02 | 105/90 | TMAH | 50 | 4.2 | 32 |
| | 3-3 | R-01 | 110/90 | TMAH | 34 | 3.1 | 26 |

From the results shown in Table 6, it was found that a negative pattern was formed by performing development using a developer containing an organic acid. In addition, as compared with Comparative Example 3-3, it was found that higher resolution can be obtained than in development with TMAH. Also as compared with Comparative Examples 3-1 and 3-2, that is, chemically amplified resist compositions using an acid catalyst reaction, it was found that excellent sensitivity and resolution can be obtained. Therefore, it was found that the inventive resist composition has excellent resolution in forming an LS pattern through EUV lithography.

Japanese Patent Application No. 2025-069671 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A resist pattern forming process comprising the steps of:
(i) applying a resist composition containing: a hypervalent iodine compound; a carboxy group-containing compound; and a solvent onto a substrate or onto an underlayer film laminated on a substrate to form a resist film,
(ii) exposing the resist film to high-energy radiation, and
(iii) developing the exposed resist film with a developer containing an organic acid to form a negative pattern.

2. The resist pattern forming process of claim 1 wherein the hypervalent iodine compound contains at least one selected from the compounds having any of the formulae (1) to (16): 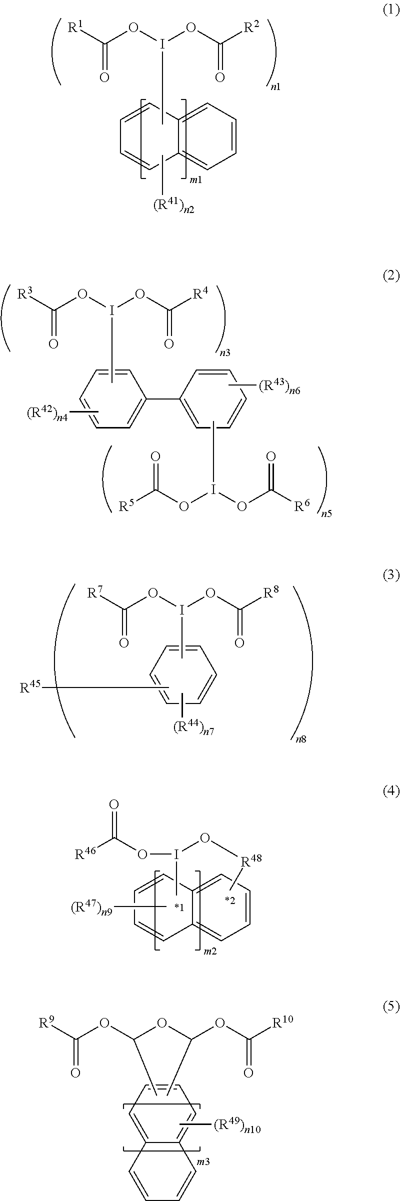 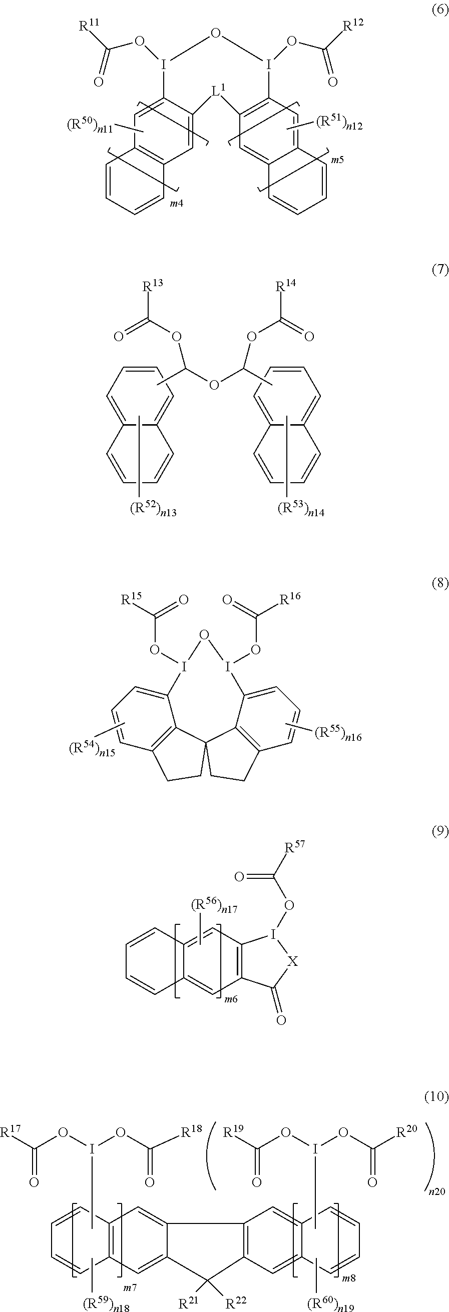 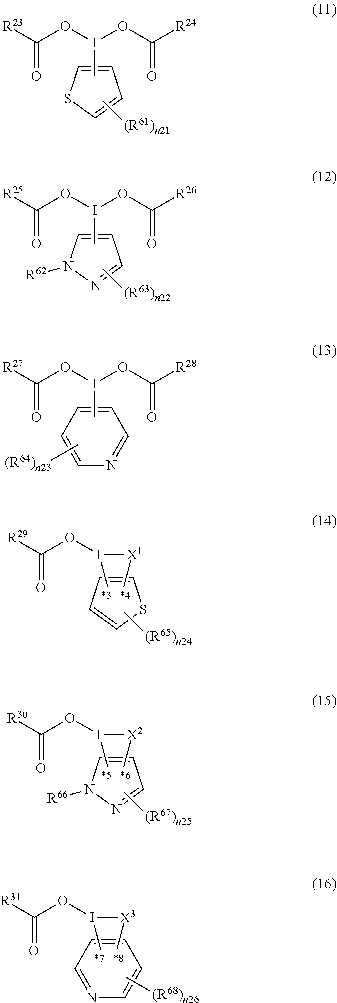
wherein
m1 is 0, 1, or 2; when m1 is 0, n1 is 1, 2, or 3, n2 is 0, 1, 2, 3, 4, or 5, and 1≤n1+n2≤6; when m1 is 1, n1 is 1, 2, or 3, n2 is 0, 1, 2, 3, 4, 5, 6, or 7, and 1≤n1+n2≤8; when m1 is 2, n1 is 1, 2, or 3, n2 is 0, 1, 2, 3, 4, 5, 6, 7, 8, or 9, and 1≤n1+n2≤10;
n3 is 1 or 2, n4 is 0, 1, 2, 3, or 4, and 1≤n3+n4≤5; n5 is 1 or 2, n6 is 0, 1, 2, 3, or 4, and 1≤n5+n6≤5;
n7 is 0, 1, 2, 3, or 4, and n8 is 1, 2, 3, or 4;
m2 is 0, 1, or 2; when m2 is 0, n9 is 0, 1, 2, 3, or 4; when m2 is 1, n9 is 0, 1, 2, 3, 4, 5, or 6; when m2 is 2, n9 is 0, 1, 2, 3, 4, 5, 6, 7, or 8;
m3 is 0, 1, or 2; when m3 is 0, n10 is 0, 1, 2, 3, or 4; when m3 is 1, n10 is 0, 1, 2, 3, 4, 5, or 6; when m3 is 2, n10 is 0, 1, 2, 3, 4, 5, 6, 7, or 8;
m4 is 0 or 1; when m4 is 0, n11 is 0, 1, 2, 3, or 4; when m4 is 1, n11 is 0, 1, 2, 3, 4, 5, or 6;
m5 is 0 or 1; when m5 is 0, n12 is 0, 1, 2, 3, or 4; when m5 is 1, n12 is 0, 1, 2, 3, 4, 5, or 6;
n13 and n14 are each independently 0, 1, 2, 3, 4, 5, or 6;
n15 and n16 are each independently 0, 1, 2, or 3;
m6 is 0, 1, or 2; when m6 is 0, n17 is 0, 1, 2, 3, or 4; when m6 is 1, n17 is 0, 1, 2, 3, 4, 5, or 6; when m6 is 2, n17 is 0, 1, 2, 3, 4, 5, 6, 7, or 8;
m7 is 0, 1, or 2; when m7 is 0, n18 is 0, 1, 2, or 3; when m7 is 1, n18 is 0, 1, 2, 3, 4, or 5; when m7 is 2, n18 is 0, 1, 2, 3, 4, 5, 6, or 7;
m8 is 0, 1, or 2; when m8 is 0, n19 is 0, 1, 2, or 3, and n20 is 0 or 1; when m8 is 1, n19 is 0, 1, 2, 3, 4, or 5, and n20 is 0 or 1; when m8 is 2, n19 is 0, 1, 2, 3, 4, 5, 6, or 7, and n20 is 0 or 1;
n21 is 0, 1, 2, or 3, n22 is 0, 1, or 2, n23 is 0, 1, 2, 3, or 4, n24 is 0, 1, or 2, n25 is 0 or 1, and n26 is 0, 1, 2, or 3;
R¹ to R³¹ are each independently a halogen atom or a C₁-C₁₀ hydrocarbyl group which may contain a heteroatom, and R²¹ and R²² may bond together to form a ring with the carbon atoms to which they are attached;
R⁴¹ to R⁴⁴, R⁴⁷, R⁴⁹ to R⁵⁶, R⁵⁹, R⁶⁰, and R⁶¹ to R⁶⁸ are each independently a halogen atom or a C₁-C₄₀ hydrocarbyl group which may contain a heteroatom; when n2 is 2 or more, each R⁴¹ may be the same or different from each other, and a plurality of R⁴¹s may bond to each other to form a ring with the carbon atoms of the aromatic ring to which they are attached; when n4 is 2 or more, each R⁴² may be the same or different from each other, and a plurality of R⁴²s may bond to each other to form a ring with the carbon atoms of the aromatic ring to which they are attached; when n6 is 2 or more, each R⁴³ may be the same or different from each other, and a plurality of R⁴³s may bond to each other to form a ring with the carbon atoms of the aromatic ring to which they are attached; when n7 is 2 or more, each R⁴⁴ may be the same or different from each other, and a plurality of R⁴⁴s may bond to each other to form a ring with the carbon atoms of the aromatic ring to which they are attached; when n9 is 2 or more, each R⁴⁷ may be the same or different from each other, and a plurality of R⁴⁷s may bond to each other to form a ring with the carbon atoms of the aromatic ring to which they are attached; when n10 is 2 or more, each R⁴⁹ may be the same or different from each other, and a plurality of R⁴⁹s may bond to each other to form a ring with the carbon atoms of the aromatic ring to which they are attached; when n11 is 2 or more, each R⁵⁰ may be the same or different from each other, and a plurality of R⁵⁰s may bond to each other to form a ring with the carbon atoms of the aromatic ring to which they are attached; when n12 is 2 or more, each R⁵¹ may be the same or different from each other, and a plurality of R⁵¹s may bond to each other to form a ring with the carbon atoms of the aromatic ring to which they are attached; when n13 is 2 or more, each R⁵² may be the same or different from each other, and a plurality of R⁵²s may bond to each other to form a ring with the carbon atoms of the aromatic ring to which they are attached; when n14 is 2 or more, each R⁵³ may be the same or different from each other, and a plurality of R⁵³s may bond to each other to form a ring with the carbon atoms of the aromatic ring to which they are attached; when n15 is 2 or more, each R⁵⁴ may be the same or different from each other, and a plurality of R⁵⁴s may bond to each other to form a ring with the carbon atoms of the aromatic ring to which they are attached; when n16 is 2 or more, each R⁵⁵ may be the same or different from each other, and a plurality of R⁵⁵s may bond to each other to form a ring with the carbon atoms of the aromatic ring to which they are attached; when n17 is 2 or more, each R⁵⁶ may be the same or different from each other, and a plurality of R⁵⁶s may bond to each other to form a ring with the carbon atoms of the aromatic ring to which they are attached; when n18 is 2 or more, each R⁵⁹ may be the same or different from each other, and a plurality of R⁵⁹s may bond to each other to form a ring with the carbon atoms of the aromatic ring to which they are attached; when n19 is 2 or more, each R⁶⁰ may be the same or different from each other, and a plurality of R⁶⁰s may bond to each other to form a ring with the carbon atoms of the aromatic ring to which they are attached; when n21 is 2 or more, each R⁶¹ may be the same or different from each other, and a plurality of R⁶¹s may bond to each other to form a ring with the carbon atoms of the aromatic ring to which they are attached; when n22 is 2 or more, each R⁶³ may be the same or different from each other, and a plurality of R⁶³s may bond to each other to form a ring with the carbon atoms of the aromatic ring to which they are attached; when n23 is 2 or more, each R⁶⁴ may be the same or different from each other, and a plurality of R⁶⁴s may bond to each other to form a ring with the carbon atoms of the aromatic ring to which they are attached; when n24 is 2 or more, each R⁶⁵ may be the same or different from each other, and a plurality of R⁶⁵s may bond to each other to form a ring with the carbon atoms of the aromatic ring to which they are attached; and when n26 is 2 or more, each R⁶⁸ may be the same or different from each other, and a plurality of R⁶⁸s may bond to each other to form a ring with the carbon atoms of the aromatic ring to which they are attached;
when n8 is 1, 3, or 4, R⁴⁵ is a C₁-C₄₀ (n8)-valent hydrocarbon group or a C₂— C₄₀ (n8)-valent heterocyclic group; when n8 is 2, R⁴⁵ is an ether bond, a carbonyl group, an azo group, a thioether bond, a carbonate bond, a carbamate bond, a sulfinyl group, a sulfonyl group, a thioketone bond, C₁-C₄₀ (n8)-valent hydrocarbon group, or a C₂— C₄₀ (n8)-valent heterocyclic group; and some or all of the hydrogen atoms of the (n8)-valent hydrocarbon group or the (n8)-valent heterocyclic group may be substituted with a heteroatom-containing moiety, some of —CH₂— of the (n8)-valent hydrocarbon group may be substituted with a heteroatom-containing moiety, and R⁴⁴ and R⁴⁵ may bond together to form a ring with the carbon atoms to which they are attached and the intervenient atoms;
R⁴⁸ is a carbonyl group or a C₁-C₁₀ hydrocarbylene group which may contain a heteroatom;
R⁵⁶ is a halogen atom or a C₁-C₁₀ hydrocarbyl group which may contain a heteroatom;
R⁵⁷ is a halogen atom or a C₁-C₁₀ hydrocarbyl group which may contain a heteroatom;
*1, *2, *3, *4, *5, *6, *7, and *8 each designate a point of attachment to a carbon atom or a heteroatom on the aromatic ring or the hetero ring in the formulae; provided that *1 and *2, *3 and *4, *5 and *6, and *7 and *8 each are bonded to adjacent atoms of the aromatic ring or adjacent atoms of the hetero ring;
L¹ is no bond, a single bond, —O—, —S—, —NH—, or —CH₂—;
X is —S— or —N(R⁵⁸)—; R⁵⁸ is a hydrogen atom, a halogen atom, or a C₁-C₂₀ hydrocarbyl group which may contain a heteroatom; and
X¹ and X² are each independently *—O—X¹¹— or *—X¹²—C(═O)—; X³ is *—O—X¹¹—, *—S—X¹¹—, or *—X¹²—C(═O)—; X¹¹ is a carbonyl group or a C₁-C₁₀ hydrocarbylene group which may contain a heteroatom; X¹² is —S— or —N(R⁶⁹)—; and R⁶⁹ is a hydrogen atom, a halogen atom, or a C₁-C₂₀ hydrocarbyl group which may contain a heteroatom.

3. The resist pattern forming process of claim 1 wherein the carboxy group-containing compound is a carboxy group-containing polymer comprising a repeat unit having the formula (a-1) or a carboxylic acid having the formula (a-2): 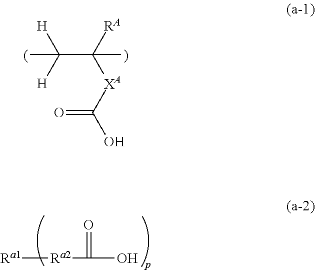
wherein
R^{A} is a hydrogen atom, a halogen atom, a methyl group, or a trifluoromethyl group,
X^{A} is a single bond, a phenylene group, a naphthylene group, or *—C(═O)—O—X^{A1}— wherein X^{A1} is a C₁-C₁₀ saturated hydrocarbylene group, a phenylene group, or a naphthylene group, the saturated hydrocarbylene group may contain a hydroxy group, an ether bond, an ester bond, or a lactone ring, and * designates a valence bond to a carbon atom in a main chain;
p is 1, 2, 3, or 4;
when p is 1, 3, or 4, R^{a1} is a C₁-C₄₀ p-valent hydrocarbon group or a C₂— C₄₀ p-valent heterocyclic group; when p is 2, R^{a1} is an ether bond, a carbonyl group, an azo group, a thioether bond, a carbonate bond, a carbamate bond, a sulfinyl group, a sulfonyl group, a C₁-C₄₀ p-valent hydrocarbon group, or a C₂— C₄₀ p-valent heterocyclic group; and some or all of the hydrogen atoms in the p-valent hydrocarbon group or the p-valent heterocyclic group may be substituted by a heteroatom-containing moiety, and some constituent —CH₂— in the p-valent hydrocarbon group may be replaced by a heteroatom-containing moiety; and
R^{a2} is a single bond or a C₁-C₂₀ hydrocarbylene group, and some or all of the hydrogen atoms in the hydrocarbylene group may be substituted by a heteroatom-containing moiety, and some constituent —CH₂— in the hydrocarbylene group may be replaced by a heteroatom-containing moiety, and when p is 2, 3, or 4, each R^{a2} may be the same or different from each other.

4. The resist pattern forming process of claim 1 wherein the organic acid comprises at least one selected from the compounds having any of the formulae (b-1) to (b-7): 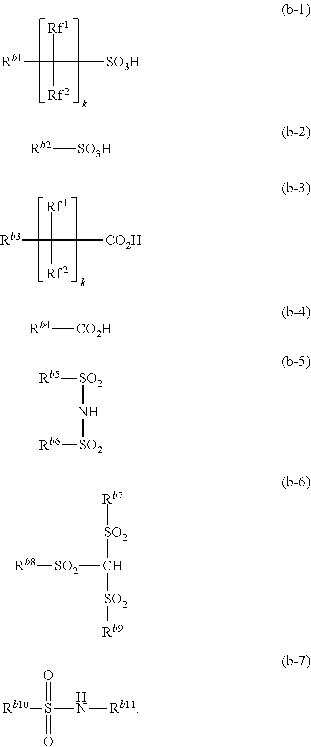
wherein
k is 1, 2, 3, or 4;
Rf¹ and Rf² are each independently a hydrogen atom, a fluorine atom, or a C₁-C₆ fluorine-containing alkyl group, excluding a case where all of Rf¹s and Rf²s are hydrogen atoms at the same time;
R^{b1} is a hydrogen atom, a halogen atom, a hydroxy group, or a C₁-C₅₀ hydrocarbyl group which may contain a heteroatom;
R^{b2} is a hydrogen atom, a halogen atom, a hydroxy group, or a C₁-C₅₀ hydrocarbyl group which may contain a heteroatom, excluding a case where hydrogen atoms on the carbon atoms at the α-position and the β-position of the sulfo group are substituted with a fluorine atom or a fluoroalkyl group;
R^{b3} is a hydrogen atom, a halogen atom, a hydroxy group, or a C₁-C₅₀ hydrocarbyl group which may contain a heteroatom;
R^{b4} is a hydrogen atom, a halogen atom, a hydroxy group, or a C₁-C₅₀ hydrocarbyl group which may contain a heteroatom, excluding a case where hydrogen atoms on the carbon atoms at the α-position and the β-position of the carboxy group are substituted with a fluorine atom or a fluoroalkyl group;
R^{b5} and R^{b6} are each independently a C₁-C₅₀ hydrocarbyl group which may contain a heteroatom;
R^{b7} to R^{b9} are each independently a C₁-C₅₀ hydrocarbyl group which may contain a heteroatom;
R^{b10} is a fluorine atom or a C₁-C₁₀ fluorinated hydrocarbyl group, and the fluorinated hydrocarbyl group may contain a hydroxy group, an ether bond, or an ester bond; R^{b11} is a hydrogen atom or a C₁-C₂₀ hydrocarbyl group, and the hydrocarbyl group may contain a hydroxy group, an ether bond, or an ester bond; and R^{b10} and Roll may bond to each other to form a ring with the atoms to which they are attached.

5. The resist pattern forming process of claim 1 wherein the high-energy radiation is i-ray, KrF excimer laser beam, ArF excimer laser beam, electron beam, or extreme ultraviolet ray.
